(19) United States
(12) Patent Application Publication
(10) Pub. No.: US 2026/0190611 A1
(43) Pub. Date: Jul. 2, 2026

(54) ORGANIC ELECTROLUMINESCENT DEVICE AND AN ORGANIC ELECTROLUMINESCENT COMPOUND

(71) Applicant: DuPont Specialty Materials Korea Ltd., Chungcheongnam-do (KR)

(72) Inventors: Hyun-Ju KANG, Gyeonggi-do (KR); So-Young JUNG, Gyeonggi-do (KR); Hee-Ryong KANG, Gyeonggi-do (KR); Bitnari KIM, Gyeonggi-do (KR); Mi-Ran SEO, Gyeonggi-do (KR); Sang-Hee CHO, Gyeonggi-do (KR); Hyo-Jung LEE, Gyeonggi-do (KR); Ji-Song JUN, Gyeonggi-do (KR); Tae-Jun HAN, Gyeonggi-do (KR); Du-Yong PARK, Gyeonggi-do (KR); So-Mi PARK, Gyeonggi-do (KR)

(21) Appl. No.: 19/417,449

(22) Filed: Dec. 12, 2025

(30) Foreign Application Priority Data
Dec. 27, 2024 (KR) 10-2024-0198940
Nov. 27, 2025 (KR) 10-2025-0183753

(51) Int. Cl. H10K 50/15; C07B 59/00; C09K 11/06; H10K 85/30; H10K 85/40; H10K 85/60

(52) U.S. Cl. CPC H10K 50/156; C07B 59/004; C09K 11/06; H10K 85/342; H10K 85/40; H10K 85/622; H10K 85/626; H10K 85/633; H10K 85/636; H10K 85/654; H10K 85/656; H10K 85/6574; H10K 85/6576; C07B 2200/05; C09K 2211/1011

(57) ABSTRACT

The present disclosure relates to an organic electroluminescent device comprising a first electrode; a second electrode opposing the first electrode; a light-emitting layer between the first electrode and the second electrode; a hole transport band between the first electrode and the light-emitting layer, wherein the hole transport band comprises a compound represented by Formula 1, and the light-emitting layer comprises a compound represented by Formulas 2 and 3. The organic electroluminescent device according to the present disclosure can exhibit high current efficiency by using the compounds represented by Formulas 1, 2, and 3.

### TECHNICAL FIELD

The present disclosure relates to an organic electroluminescent device and an organic electroluminescent compound.

### BACKGROUND ART

An electroluminescent device (EL device) is a self-light-emitting display device which has advantages in that it provides a wider viewing angle, a greater contrast ratio, and a faster response time. The first organic EL device was developed by Eastman Kodak in 1987 by using a low-molecular-weight aromatic diamine and aluminum complexes as materials for forming a light-emitting layer (see Appl. Phys. Lett. 51, 913, 1987).

An organic electroluminescent device is composed of a multi-layer structure including a hole injection layer, a hole transport layer, a light-emitting layer, an electron transport layer, and an electron injection layer, etc. to enhance the efficiency and stability thereof. Herein, selection of compounds included in the hole transport layer, etc. is recognized as one of the means to improve device characteristics such as hole transport efficiency to the light-emitting layer, current efficiency, and lifetime characteristics.

In order to improve luminous efficiency, driving voltage, and/or lifespan, various materials or concepts for a hole transport layer of an organic electroluminescent device have been proposed. However, these were not satisfactory in practical use. Accordingly, there has been a continuous need to develop organic electroluminescent devices having more improved performance, for example, improved driving voltage, luminous efficiency, current efficiency, and/or lifetime characteristics, compared to previously disclosed organic electroluminescent devices.

Meanwhile, Korean Patent Application Laid-Open Nos. 10-2024-0052660 and 10-2023-0174704 disclose organic electroluminescent devices comprising host compounds represented by benzophenanthrofuran or benzophenanthrothiophene, host compounds represented by triazinyl, and host compounds represented by phenanthrooxazole or phenanthrothiazole. Nevertheless, as described herein, there is no disclosure of an organic electroluminescent device having improved performance due to the inclusion of a specific combination of hole transport zone compounds and a plurality of host materials as in the present invention.

### DISCLOSURE OF INVENTION

### Problem to be Solved

The object of the present disclosure is to provide an organic electroluminescent device and an organic electroluminescent compound having improved current efficiency.

### Solution to Problem

As a result of intensive studies to solve the technical problems above, the present inventors found that the aforementioned object can be achieved by an organic electroluminescent device comprising a first electrode; a second electrode opposing the first electrode; a light-emitting layer between the first electrode and the second electrode; and a hole transport band between the first electrode and the light-emitting layer, wherein the hole transport band comprises a compound represented by the following Formula 1 and the light-emitting layer comprises a compound represented by the following Formula 2 and a compound represented by the following Formula 3, thereby completing the present invention.

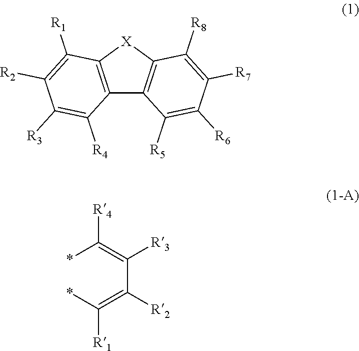

In Formulas 1 and 2,
X represents O, S, or CR₉R₁₀;
R₉ and R₁₀ each independently represent hydrogen, deuterium, halogen, cyano, a substituted or unsubstituted (C₁-C₃₀)alkyl, a substituted or unsubstituted (C₆-C₃₀)aryl, a substituted or unsubstituted (3- to 30-membered)heteroaryl, or a substituted or unsubstituted (C₃-C₃₀)cycloalkyl; or may be linked to the adjacent substituents to form a ring(s); and
R₁ to R₈ and R′₁ to R′₄ each independently represent hydrogen, deuterium, halogen, cyano, a substituted or unsubstituted (C₁-C₃₀)alkyl, a substituted or unsubstituted (C₆-C₃₀)aryl, a substituted or unsubstituted (3- to 30-membered)heteroaryl, a substituted or unsubstituted (C₃-C₃₀)cycloalkyl, a substituted or unsubstituted (C₁-C₃₀)alkoxy, a substituted or unsubstituted tri(C₁-C₃₀)alkylsilyl, a substituted or unsubstituted di(C₁-C₃₀)alkyl(C₆-C₃₀)arylsilyl, a substituted or unsubstituted (C₁-C₃₀)alkyldi(C₁-C₃₀)arylsilyl, a substituted or unsubstituted tri(C₆-C₃₀)arylsilyl, a substituted or unsubstituted fused ring of a (C₃-C₃₀)aliphatic ring and a (C₆-C₃₀)aromatic ring, a substituted or unsubstituted mono- or di-(C₁-C₃₀)alkylamino, a substituted or unsubstituted mono- or di-(C₆-C₃₀)arylamino, a substituted or unsubstituted (C₁-C₃₀)alkyl(C₆-C₃₀)arylamino, a substituted or unsubstituted mono- or di-(3- to 30-membered)heteroarylamino, or a substituted or unsubstituted (C₆-C₃₀)aryl(3- to 30-membered)heteroarylamino;
provided that one pair selected from R₅ and R₆, R₆ and R₇, and R₇ and R₈ is bonded together to form a ring with the *-* of Formula 1-A;
provided that at least one of R₁ to R₈ and R′₁ to R′₄ is represented by the following Formula A:

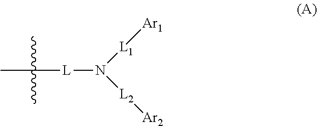

In Formula A,
L, L₁, and L₂ each independently represent a single bond, a substituted or unsubstituted (C₆-C₃₀)arylene, a substituted or unsubstituted (3- to 30-membered)heteroarylene, or a substituted or unsubstituted (C₃-C₃₀)cycloalkylene; and
Ar₁ and Ar₂ each independently represent a substituted or unsubstituted (C₆-C₃₀)aryl, or a substituted or unsubstituted (3- to 30-membered)heteroaryl,
provided that at least one of L, L₁, L₂, Ar₁, and Ar₂ necessarily represents a substituted or unsubstituted (C₃-C₃₀)cycloalkyl or a substituted or unsubstituted (C₁-C₃₀)alkyl.

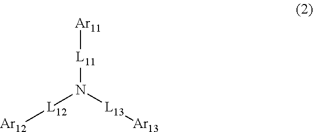

In Formula 2,
L₁₁ to L₁₃ each independently represent a single bond, a substituted or unsubstituted (C₆-C₃₀)arylene, or a substituted or unsubstituted (3- to 30-membered)heteroarylene;
Ar₁₁ represents a substituted or unsubstituted (3- to 30-membered)heteroaryl; and
Ar₁₂ and Ar₁₃ each independently represent a substituted or unsubstituted (C₁-C₃₀)alkyl, a substituted or unsubstituted (C₆-C₃₀)aryl, a substituted or unsubstituted (3- to 30-membered)heteroaryl, a substituted or unsubstituted (C₃-C₃₀)cycloalkyl, a substituted or unsubstituted (C₁-C₃₀)alkoxy, a substituted or unsubstituted tri(C₁-C₃₀)alkylsilyl, a substituted or unsubstituted di(C₁-C₃₀)alkyl(C₆-C₃₀)arylsilyl, a substituted or unsubstituted (C₁-C₃₀)alkyldi(C₆-C₃₀)arylsilyl, a substituted or unsubstituted tri(C₆-C₃₀)arylsilyl, a substituted or unsubstituted mono- or di-(C₁-C₃₀)alkylamino, a substituted or unsubstituted mono- or di-(C₂-C₃₀)alkenylamino, a substituted or unsubstituted (C₁-C₃₀)alkyl(C₂-C₃₀)alkenylamino, a substituted or unsubstituted mono- or di-(C₆-C₃₀)arylamino, a substituted or unsubstituted (C₁-C₃₀)alkyl(C₆-C₃₀)arylamino, a substituted or unsubstituted mono- or di-(3- to 30-membered)heteroarylamino, a substituted or unsubstituted (C₁-C₃₀)alkyl(3- to 30-membered)heteroarylamino, a substituted or unsubstituted (C₂-C₃₀)alkenyl(C₆-C₃₀)arylamino, a substituted or unsubstituted (C₂-C₃₀)alkenyl(3- to 30-membered)heteroarylamino, or a substituted or unsubstituted (C₆-C₃₀)aryl(3- to 30-membered)heteroarylamino.

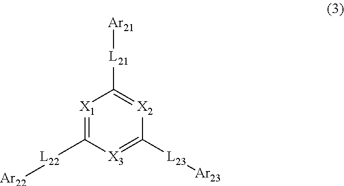

In Formula 3,
X₁ to X₃ each independently represent N or CR₂₁, provided that at least one of X₁ to X₃ is N;
each R₂₁ independently represents hydrogen or deuterium;
L₂₁ to L₂₃ each independently represent a single bond, a substituted or unsubstituted (C₆-C₃₀)arylene, or a substituted or unsubstituted (3- to 30-membered)heteroarylene; and
Ar₂₁ to Ar₂₃ each independently represent a substituted or unsubstituted (C₁-C₃₀)alkyl, a substituted or unsubstituted (C₃-C₃₀)cycloalkyl, a substituted or unsubstituted (3- to 7-membered)heterocycloalkyl, a substituted or unsubstituted fused ring of a (C₃-C₃₀)aliphatic ring and a (C₆-C₃₀)aromatic ring, a substituted or unsubstituted (C₆-C₃₀)aryl, or a substituted or unsubstituted (3- to 30-membered)heteroaryl;
provided that at least one of Ar₂₁ to Ar₂₃ represents a substituted or unsubstituted (3- to 30-membered)heteroaryl.

In addition, the present inventors found that the aforementioned object can be achieved by an organic electroluminescent compound represented by the following compounds, thereby completing the present invention.

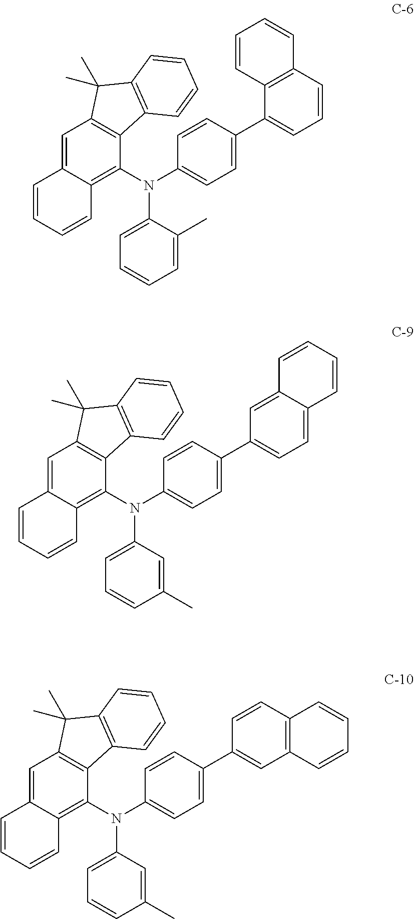 [SMILES: Cc1ccccc1N(c1ccc(-c2cccc3ccccc23)cc1)c1c2c(cc3ccccc13)C(C)(C)c1ccccc1-2 ; Cc1cccc(N(c2ccc(-c3ccc4ccccc4c3)cc2)c2c3c(cc4ccccc24)C(C)(C)c2ccccc2-3)c1 ; Cc1cccc(N(c2ccc(-c3ccc4ccccc4c3)cc2)c2c3c(cc4ccccc24)C(C)(C)c2ccccc2-3)c1]

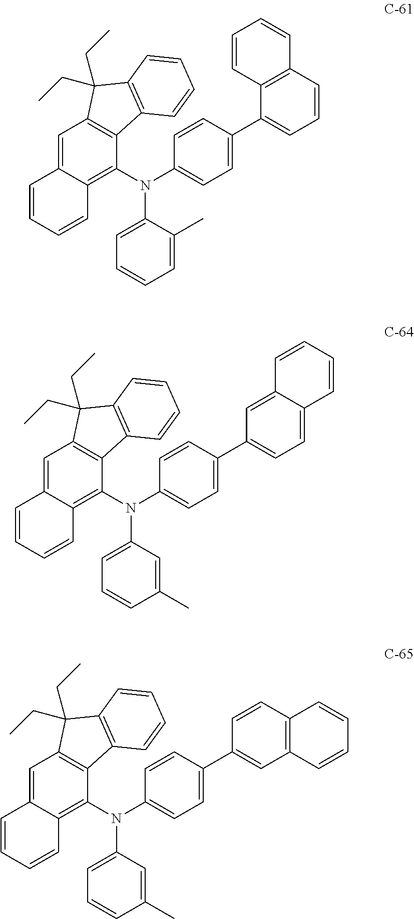 [SMILES: CCC1(CC)c2ccccc2-c2c1cc1ccccc1c2N(c1ccc(-c2cccc3ccccc23)cc1)c1ccccc1C ; CCC1(CC)c2ccccc2-c2c1cc1ccccc1c2N(c1ccc(-c2ccc3ccccc3c2)cc1)c1cccc(C)c1 ; CCC1(CC)c2ccccc2-c2c1cc1ccccc1c2N(c1ccc(-c2ccc3ccccc3c2)cc1)c1cccc(C)c1]

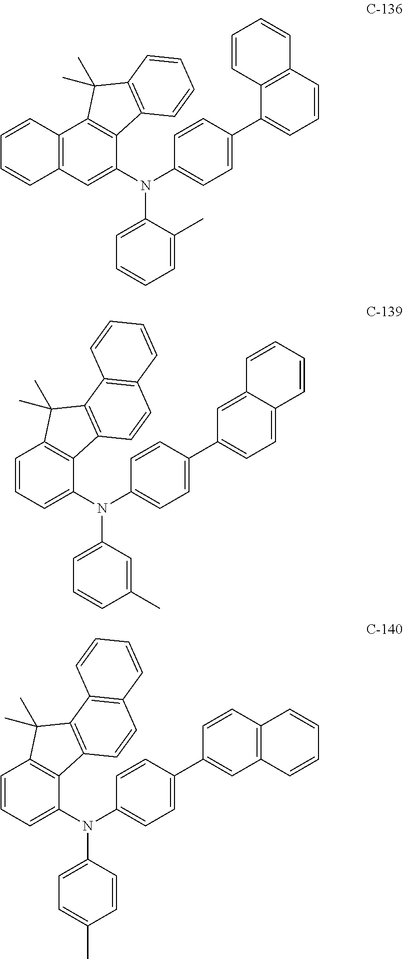

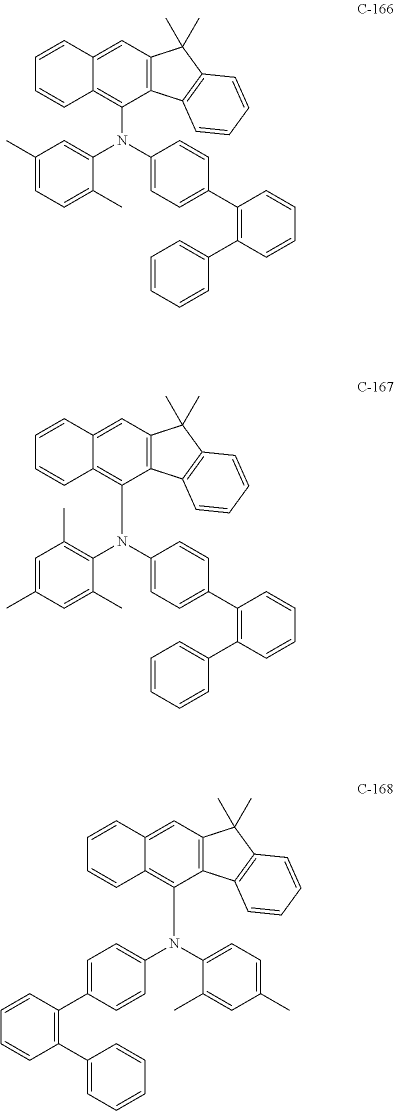 [SMILES: Cc1ccc(C)c(N(c2ccc(-c3ccccc3-c3ccccc3)cc2)c2c3c(cc4ccccc24)C(C)(C)c2ccccc2-3)c1 ; Cc1cc(C)c(N(c2ccc(-c3ccccc3-c3ccccc3)cc2)c2c3c(cc4ccccc24)C(C)(C)c2ccccc2-3)c(C)c1 ; Cc1ccc(N(c2ccc(-c3ccccc3-c3ccccc3)cc2)c2c3c(cc4ccccc24)C(C)(C)c2ccccc2-3)c(C)c1]

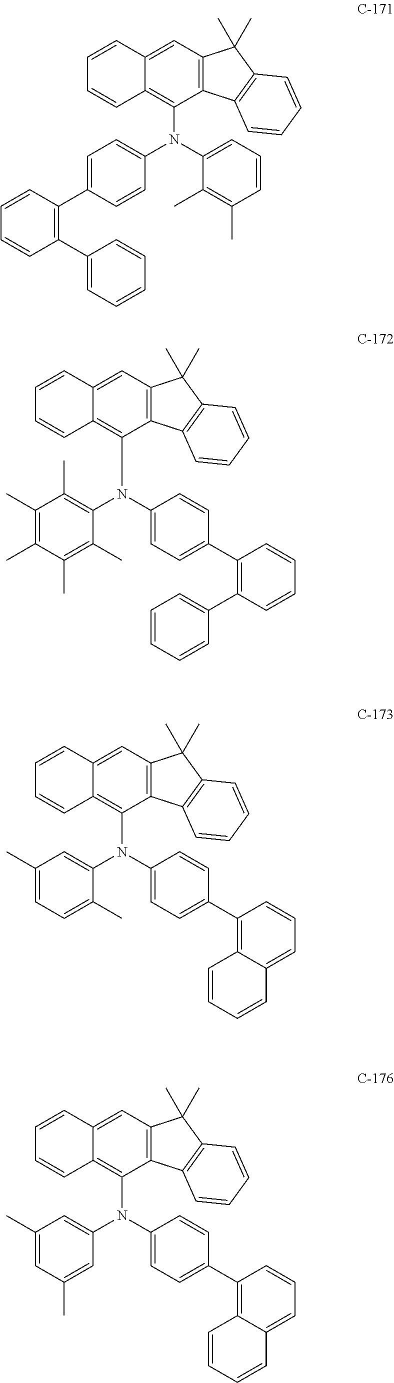 [SMILES: Cc1cccc(N(c2ccc(-c3ccccc3-c3ccccc3)cc2)c2c3c(cc4ccccc24)C(C)(C)c2ccccc2-3)c1C ; Cc1c(C)c(C)c(N(c2ccc(-c3ccccc3-c3ccccc3)cc2)c2c3c(cc4ccccc24)C(C)(C)c2ccccc2-3)c(C)c1C ; Cc1ccc(C)c(N(c2ccc(-c3cccc4ccccc34)cc2)c2c3c(cc4ccccc24)C(C)(C)c2ccccc2-3)c1 ; Cc1cc(C)cc(N(c2ccc(-c3cccc4ccccc34)cc2)c2c3c(cc4ccccc24)C(C)(C)c2ccccc2-3)c1]

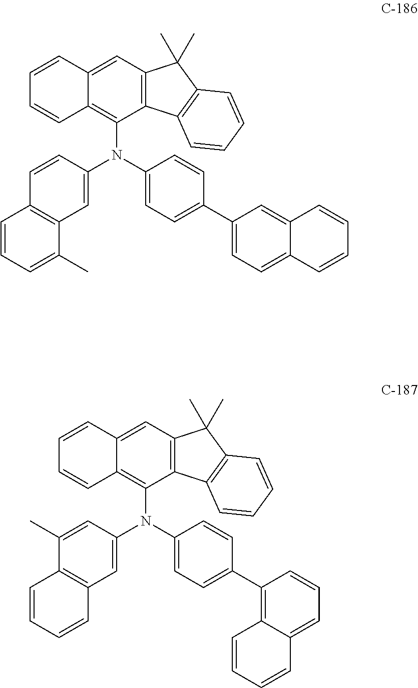 [SMILES: Cc1cccc2ccc(N(c3ccc(-c4ccc5ccccc5c4)cc3)c3c4c(cc5ccccc35)C(C)(C)c3ccccc3-4)cc12 ; Cc1cc(N(c2ccc(-c3cccc4ccccc34)cc2)c2c3c(cc4ccccc24)C(C)(C)c2ccccc2-3)cc2ccccc12]

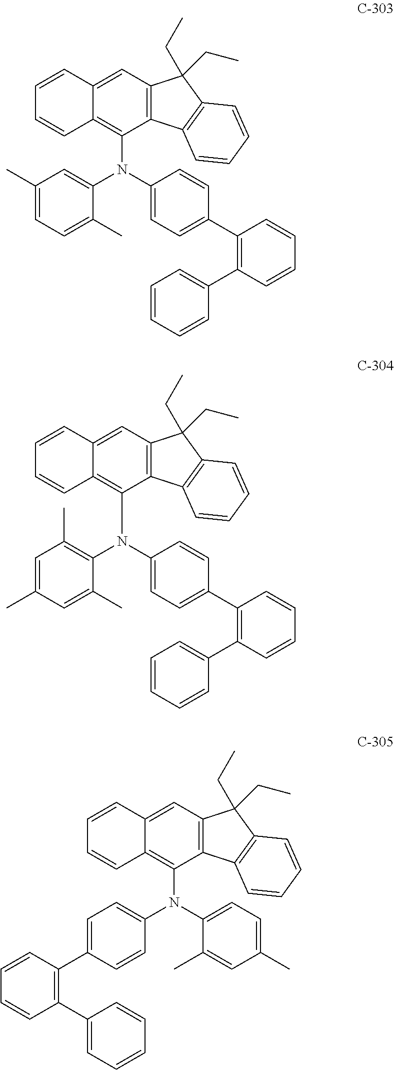

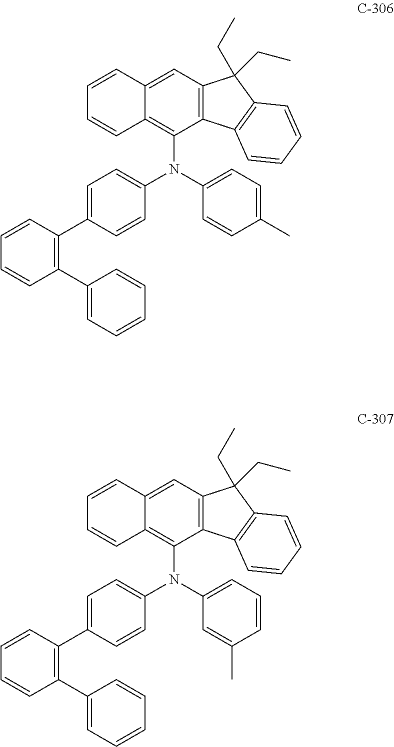 [SMILES: CCC1(CC)c2ccccc2-c2c1cc1ccccc1c2N(c1ccc(C)cc1)c1ccc(-c2ccccc2-c2ccccc2)cc1 ; CCC1(CC)c2ccccc2-c2c1cc1ccccc1c2N(c1ccc(-c2ccccc2-c2ccccc2)cc1)c1cccc(C)c1]

### Advantageous Effects of Invention

By using an organic electroluminescent compound according to the present disclosure, an organic electroluminescent device having improved current efficiency can be provided.

### EMBODIMENTS OF INVENTION

Hereinafter, the present disclosure will be described in detail. However, the following description is intended to explain the invention, and is not meant in any way to restrict the scope of the invention.

The term “organic electroluminescent compound”, as used in the present disclosure, means a compound that may be used in an organic electroluminescent device, and may be included in any layer constituting an organic electroluminescent device as necessary.

The present disclosure relates to an organic electroluminescent device comprising a first electrode; a second electrode opposing the first electrode; a light-emitting layer between the first electrode and the second electrode; and a hole transport band between the first electrode and the light-emitting layer, wherein the hole transport band comprises a compound represented by Formula 1 and the light-emitting layer comprises a compound represented by Formula 2 and a compound represented by Formula 3.

The term “organic electroluminescent material”, as used in the present disclosure, means a material that may be used in an organic electroluminescent device, and may include at least one compound. The organic electroluminescent material may be included in any layer constituting an organic electroluminescent device as necessary. For example, the organic electroluminescent material may be a hole injection material, a hole transport material, a hole auxiliary material, a light-emitting auxiliary material, an electron-blocking material, a light-emitting material (including host and dopant materials), an electron buffer material, a hole-blocking material, an electron transport material, an electron injection material, etc. The hole transport band material may be at least one selected from the group consisting of a hole transport material, a hole injection material, an electron-blocking material, a hole auxiliary material, and a light-emitting auxiliary material.

The organic electroluminescent material in the present disclosure may include at least one compound represented by Formula 1. The compound of Formula 1 may be included in at least one layer constituting the organic electroluminescent device, and may be included in at least one layer of layers constituting the hole transport band, but is not limited thereto. When the compound of Formula 1 is included in a hole transport layer, a hole auxiliary layer, an electron-blocking layer, a light-emitting layer, or a light-emitting auxiliary layer, it may be included as a hole transport material, a hole auxiliary material, an electron-blocking material, a host material, or a light-emitting auxiliary material.

The “plurality of host materials” in the present disclosure means a host material comprising a combination of at least two compounds, which may be comprised in any light-emitting layer constituting an organic electroluminescent device. It may mean both a material before being comprised in an organic electroluminescent device (for example, before vapor deposition) and a material after being comprised in an organic electroluminescent device (for example, after vapor deposition). For example, the plurality of host materials of the present disclosure is a combination of at least two host materials, and may selectively further comprise conventional materials comprised in an organic electroluminescent material. At least two compounds comprised in the plurality of host materials of the present disclosure may be comprised together in one light-emitting layer or may respectively be comprised in different light-emitting layers, using methods commonly employed in the art. For example, the at least two host materials may be mixture-evaporated or co-evaporated, or may be individually evaporated.

The “electron transport band”, as used in the present disclosure, means a zone where electrons move between the light-emitting layer and the cathode. For example, the electron transport band may include at least one of a hole-blocking layer, an electron transport layer, and an electron injection layer, preferably an electron transport layer and an electron injection layer. The hole-blocking layer serves to prevent holes from entering the cathode through the light-emitting layer in driving the organic electroluminescent device.

The “hole transport band”, as used in the present disclosure, means a zone where holes move between the first electrode and the light-emitting layer. For example, the hole transport band may include at least one of a hole injection layer, a hole transport layer, a hole auxiliary layer, a light-emitting auxiliary layer, and an electron-blocking layer. Each of the hole injection layer, the hole transport layer, the hole auxiliary layer, the light-emitting auxiliary layer, and the electron-blocking layer can be a single layer, or a multi-layer of which two or more layers or three or more layers are stacked. According to one example of the present disclosure, the hole transport band may include a first hole transport layer and a second hole transport layer, and may further comprise a third hole transport layer. The second hole transport layer and the third hole transport layer may be at least one layer of a plurality of hole transport layers and may include at least one of a hole auxiliary layer, a light-emitting auxiliary layer and an electron-blocking layer. In addition, according to another example of the present disclosure, the hole transport band may include a first hole transport layer and a second hole transport layer, the first hole transport layer may be placed between the first electrode and the light-emitting layer, the second hole transport layer may be placed between the first hole transport layer and the light-emitting layer, and the second hole transport layer may be a layer that functions as a hole transport layer, a light-emitting auxiliary layer, a hole auxiliary layer, and/or an electron-blocking layer. According to yet another example of the present disclosure, the hole transport band may include a first hole transport layer, a second hole transport layer, and a third hole transport layer, the first hole transport layer may be placed between the first electrode and the light-emitting layer, the second hole transport layer may be placed between the first hole transport layer and the light-emitting layer, the third hole transport layer may be placed between the second hole transport layer and the light-emitting layer, and the third hole transport layer may be a layer that functions as a hole transport layer, a light-emitting auxiliary layer, a hole auxiliary layer, and/or an electron-blocking layer.

The “(C₁-C₃₀)alkyl” in the present disclosure is meant to be a linear or branched alkyl having 1 to 30 carbon atoms constituting the chain, in which the number of carbon atoms is preferably 1 to 20, and more preferably 1 to 10. Specific examples of the alkyl may include methyl, ethyl, n-propyl, isopropyl, n-butyl, isobutyl, tert-butyl, etc.

The term “(C₃-C₃₀)cycloalkyl” in the present disclosure means a cyclic hydrocarbon substituent of saturated or partially unsaturated monocyclic or polycyclic rings, which is meant to be a mono- or polycyclic hydrocarbon having 3 to 30 ring skeleton carbon atoms, in which the number of carbon atoms is preferably 3 to 20, more preferably 3 to 7. Examples of the cycloalkyl may include cyclopropyl, cyclobutyl, cyclopentyl, cyclohexyl, etc. The monocyclic ring cycloalkyl includes cyclopropyl, cyclobutyl, cyclopentyl, cyclohexyl, cyclohexenyl, cyclohexadienyl, cycloheptyl, cycloheptatrienyl, cyclooctyl, etc. as non-limiting examples. The polycyclic ring cycloalkyl includes a spiro ring, fused ring, and cycloalkyl of crosslinked ring. The cycloalkyl ring may be fused into an aryl, heteroaryl, or heterocycloalkyl ring, and the cycloalkyl ring includes indanyl, tetrahydronaphthalenyl, benzocycloheptenyl, etc. as non-limiting examples. The cycloalkyl of crosslinked ring is meant to be a 5- to 20-membered, preferably 6- to 14-membered, and more preferably 7- to 10-membered all-carbon polycyclic group having any two rings sharing two carbon atoms that are not directly connected, which may include one or more double bonds, but none of the rings has a fully conjugated π-electron system. Depending on the number of rings formed, it can be classified as bicyclic, tricyclic, tetracyclic, or polycyclic crosslinked cycloalkyl, preferably bicyclic, tricyclic, or tetracyclic, and more preferably bicyclic or tricyclic. The cycloalkyl of crosslinked ring includes, for example, adamantyl, norbornyl, norbornenyl, bicyclo[1.1.1]pentyl, bicyclo[2.1.1]hexyl, bicyclo[2.2.1]heptanyl, bicyclo[2.2.2]octyl, etc.

The “(3- to 7-membered)heterocycloalkyl” in the present disclosure is meant to be a cycloalkyl having 3 to 7, preferably 5 to 7 ring skeleton atoms, and including at least one heteroatom selected from the group consisting of B, N, O, S, Si, and P, preferably the group consisting of O, S, and N, for example, which includes tetrahydrofuran, pyrrolidine, thiolane, tetrahydropyran, etc.

The “(C₆-C₃₀)aryl(ene)” is a monocyclic or fused ring radical derived from an aromatic hydrocarbon having 6 to 30 ring skeleton carbon atoms, in which the number of the ring skeleton carbon atoms is preferably 6 to 25, more preferably 6 to 18, and may be partially saturated. The aryl may include a spiro structure. Examples of the aryl may include phenyl, biphenyl, terphenyl, naphthyl, binaphthyl, phenylnaphthyl, naphthylphenyl, phenylterphenyl, fluorenyl, phenylfluorenyl, diphenylfluorenyl, dimethylfluorenyl, benzofluorenyl, dibenzofluorenyl, phenanthrenyl, phenylphenanthrenyl, anthracenyl, indenyl, triphenylenyl, pyrenyl, tetracenyl, perylenyl, chrysenyl, naphthacenyl, fluoranthenyl, spirobifluorenyl, etc. Specifically, examples of the aryl may include phenyl, 1-naphthyl, 2-naphthyl, 1-anthryl, 2-anthryl, 9-anthryl, benzanthryl, 1-phenanthryl, 2-phenanthryl, 3-phenanthryl, 4-phenanthryl, 9-phenanthryl, naphthacenyl, pyrenyl, 1-chrysenyl, 2-chrysenyl, 3-chrysenyl, 4-chrysenyl, 5-chrysenyl, 6-chrysenyl, benzo[c]phenanthryl, benzo[g]chrysenyl, 1-triphenylenyl, 2-triphenylenyl, 3-triphenylenyl, 4-triphenylenyl, 1-fluorenyl, 2-fluorenyl, 3-fluorenyl, 4-fluorenyl, 9-fluorenyl, benzo[a]fluorenyl, benzo[b]fluorenyl, benzo[c]fluorenyl, dibenzofluorenyl, 2-biphenyl, 3-biphenyl, 4-biphenyl, o-terphenyl, m-terphenyl-4-yl, m-terphenyl-3-yl, m-terphenyl-2-yl, p-terphenyl-4-yl, p-terphenyl-3-yl, p-terphenyl-2-yl, m-quaterphenyl, 3-fluoranthenyl, 4-fluoranthenyl, 8-fluoranthenyl, 9-fluoranthenyl, benzofluoranthenyl, o-tolyl, m-tolyl, p-tolyl, 2,3-xylyl, 3,4-xylyl, 2,5-xylyl, mesityl, o-cumenyl, m-cumenyl, p-cumenyl, p-tert-butylphenyl, p-(2-phenylpropyl)phenyl, 4′-methylbiphenyl, 4″-tert-butyl-p-terphenyl-4-yl, 9,9-dimethyl-1-fluorenyl, 9,9-dimethyl-2-fluorenyl, 9,9-dimethyl-3-fluorenyl, 9,9-dimethyl-4-fluorenyl, 9,9-diphenyl-1-fluorenyl, 9,9-diphenyl-2-fluorenyl, 9,9-diphenyl-3-fluorenyl, 9,9-diphenyl-4-fluorenyl, 11,11-dimethyl-1-benzo[a]fluorenyl, 11,11-dimethyl-2-benzo[a]fluorenyl, 11,11-dimethyl-3-benzo[a]fluorenyl, 11,11-dimethyl-4-benzo[a]fluorenyl, 11,11-dimethyl-5-benzo[a]fluorenyl, 11,11-dimethyl-6-benzo[a]fluorenyl, 11,11-dimethyl-7-benzo[a]fluorenyl, 11,11-dimethyl-8-benzo[a]fluorenyl, 11,11-dimethyl-9-benzo[a]fluorenyl, 11,11-dimethyl-10-benzo[a]fluorenyl, 11,11-dimethyl-1-benzo[b]fluorenyl, 11,11-dimethyl-2-benzo[b]fluorenyl, 11,11-dimethyl-3-benzo[b]fluorenyl, 11,11-dimethyl-4-benzo[b]fluorenyl, 11,11-dimethyl-5-benzo[b]fluorenyl, 11,11-dimethyl-6-benzo[b]fluorenyl, 11,11-dimethyl-7-benzo[b]fluorenyl, 11,11-dimethyl-8-benzo[b]fluorenyl, 11,11-dimethyl-9-benzo[b]fluorenyl, 11,11-dimethyl-10-benzo[b]fluorenyl, 11,11-dimethyl-1-benzo[c]fluorenyl, 11,11-dimethyl-2-benzo[c]fluorenyl, 11,11-dimethyl-3-benzo[c]fluorenyl, 11,11-dimethyl-4-benzo[c]fluorenyl, 11,11-dimethyl-5-benzo[c]fluorenyl, 11,11-dimethyl-6-benzo[c]fluorenyl, 11,11-dimethyl-7-benzo[c]fluorenyl, 11,11-dimethyl-8-benzo[c]fluorenyl, 11,11-dimethyl-9-benzo[c]fluorenyl, 11,11-dimethyl-10-benzo[c]fluorenyl, 11,11-diphenyl-1-benzo[a]fluorenyl, 11,11-diphenyl-2-benzo[a]fluorenyl, 11,11-diphenyl-3-benzo[a]fluorenyl, 11,11-diphenyl-4-benzo[a]fluorenyl, 11,11-diphenyl-5-benzo[a]fluorenyl, 11,11-diphenyl-6-benzo[a]fluorenyl, 11,11-diphenyl-7-benzo[a]fluorenyl, 11,11-diphenyl-8-benzo[a]fluorenyl, 11,11-diphenyl-9-benzo[a]fluorenyl, 11,11-diphenyl-10-benzo[a]fluorenyl, 11,11-diphenyl-1-benzo[b]fluorenyl, 11,11-diphenyl-2-benzo[b]fluorenyl, 11,11-diphenyl-3-benzo[b]fluorenyl, 11,11-diphenyl-4-benzo[b]fluorenyl, 11,11-diphenyl-5-benzo[b]fluorenyl, 11,11-diphenyl-6-benzo[b]fluorenyl, 11,11-diphenyl-7-benzo[b]fluorenyl, 11,11-diphenyl-8-benzo[b]fluorenyl, 11,11-diphenyl-9-benzo[b]fluorenyl, 11,11-diphenyl-10-benzo[b]fluorenyl, 11,11-diphenyl-1-benzo[c]fluorenyl, 11,11-diphenyl-2-benzo[c]fluorenyl, 11,11-diphenyl-3-benzo[c]fluorenyl, 11,11-diphenyl-4-benzo[c]fluorenyl, 11,11-diphenyl-5-benzo[c]fluorenyl, 11,11-diphenyl-6-benzo[c]fluorenyl, 11,11-diphenyl-7-benzo[c]fluorenyl, 11,11-diphenyl-8-benzo[c]fluorenyl, 11,11-diphenyl-9-benzo[c]fluorenyl, 11,11-diphenyl-10-benzo[c]fluorenyl, 9,9,10,10-tetramethyl-9,10-dihydro-1-phenanthrenyl, 9,9,10,10-tetramethyl-9,10-dihydro-2-phenanthrenyl, 9,9,10,10-tetramethyl-9,10-dihydro-3-phenanthrenyl, 9,9,10,10-tetramethyl-9,10-dihydro-4-phenanthrenyl, etc.

The term “(3- to 30-membered)heteroaryl(ene)”, as used in the present disclosure, means an aryl(ene) group having 3 to 30 ring skeleton atoms, and including at least one heteroatom selected from the group consisting of B, N, O, S, Si, P, Se, Te, and Ge, which may be a monocyclic-type or a fused ring-type condensed with at least one benzene ring, and may be partially saturated. The number of heteroatoms is preferably 1 to 4. Also, the heteroaryl(ene) in the present disclosure may include one formed by linking at least one heteroaryl or aryl group to a heteroaryl(ene) group via a single bond(s), and may include a spiro structure. Examples of the heteroaryl may include a monocyclic-type heteroaryl including furyl, thiophenyl, pyrrolyl, imidazolyl, pyrazolyl, thiazolyl, thiadiazolyl, isothiazolyl, isoxazolyl, oxazolyl, oxadiazolyl, triazinyl, tetrazinyl, triazolyl, tetrazolyl, furazanyl, pyridyl, pyrazinyl, pyrimidinyl, pyridazinyl, etc. and a fused ring-type heteroaryl including benzofuranyl, benzothiophenyl, isobenzofuranyl, dibenzofuranyl, benzophenanthrofuranyl, dibenzothiophenyl, benzoimidazolyl, benzothiazolyl, benzoisothiazolyl, benzophenanthrothiophenyl, benzoisoxazolyl, benzooxazolyl, phenanthrooxazolyl, phenanthrothiazolyl, isoindolyl, indolyl, benzoindolyl, indazolyl, benzothiadiazolyl, quinolyl, isoquinolyl, cinnolinyl, quinazolinyl, benzoquinazolinyl, quinoxalinyl, benzoquinoxalinyl, naphthyridinyl, carbazolyl, benzocarbazolyl, dibenzocarbazolyl, phenoxazinyl, phenothiazinyl, phenanthridinyl, benzodioxolyl, dihydroacridinyl, etc. More specifically, the example of the heteroaryl may include 1-pyrrolyl, 2-pyrrolyl, 3-pyrrolyl, pyrazinyl, 2-pyridinyl, 2-pyrimidinyl, 4-pyrimidinyl, 5-pyrimidinyl, 6-pyrimidinyl, 1,2,3-triazin-4-yl, 1,2,4-triazin-3-yl, 1,3,5-triazin-2-yl, 1-imidazolyl, 2-imidazolyl, 1-pyrazolyl, 1-indolidinyl, 2-indolidinyl, 3-indolidinyl, 5-indolidinyl, 6-indolidinyl, 7-indolidinyl, 8-indolidinyl, 2-imidazopyridinyl, 3-imidazopyridinyl, 5-imidazopyridinyl, 6-imidazopyridinyl, 7-imidazopyridinyl, 8-imidazopyridinyl, 3-pyridinyl, 4-pyridinyl, 1-indolyl, 2-indolyl, 3-indolyl, 4-indolyl, 5-indolyl, 6-indolyl, 7-indolyl, 1-isoindolyl, 2-isoindolyl, 3-isoindolyl, 4-isoindolyl, 5-isoindolyl, 6-isoindolyl, 7-isoindolyl, 2-furyl, 3-furyl, 2-benzofuranyl, 3-benzofuranyl, 4-benzofuranyl, 5-benzofuranyl, 6-benzofuranyl, 7-benzofuranyl, 1-isobenzofuranyl, 3-isobenzofuranyl, 4-isobenzofuranyl, 5-isobenzofuranyl, 6-isobenzofuranyl, 7-isobenzofuranyl, 2-quinolyl, 3-quinolyl, 4-quinolyl, 5-quinolyl, 6-quinolyl, 7-quinolyl, 8-quinolyl, 1-isoquinolyl, 3-isoquinolyl, 4-isoquinolyl, 5-isoquinolyl, 6-isoquinolyl, 7-isoquinolyl, 8-isoquinolyl, 2-quinoxalinyl, 5-quinoxalinyl, 6-quinoxalinyl, 1-carbazolyl, 2-carbazolyl, 3-carbazolyl, 4-carbazolyl, 9-carbazolyl, azacarbazolyl-1-yl, azacarbazolyl-2-yl, azacarbazolyl-3-yl, azacarbazolyl-4-yl, azacarbazolyl-5-yl, azacarbazolyl-6-yl, azacarbazolyl-7-yl, azacarbazolyl-8-yl, azacarbazolyl-9-yl, 1-phenanthridinyl, 2-phenanthridinyl, 3-phenanthridinyl, 4-phenanthridinyl, 6-phenanthridinyl, 7-phenanthridinyl, 8-phenanthridinyl, 9-phenanthridinyl, 10-phenanthridinyl, 1-acridinyl, 2-acridinyl, 3-acridinyl, 4-acridinyl, 9-acridinyl, 2-oxazolyl, 4-oxazolyl, 5-oxazolyl, 2-oxadiazolyl, 5-oxadiazolyl, 3-furazanyl, 2-thienyl, 3-thienyl, 2-methylpyrrol-1-yl, 2-methylpyrrol-3-yl, 2-methylpyrrol-4-yl, 2-methylpyrrol-5-yl, 3-methylpyrrol-1-yl, 3-methylpyrrol-2-yl, 3-methylpyrrol-4-yl, 3-methylpyrrol-5-yl, 2-tert-butylpyrrol-4-yl, 3-(2-phenylpropyl)pyrrol-1-yl, 2-methyl-1-indolyl, 4-methyl-1-indolyl, 2-methyl-3-indolyl, 4-methyl-3-indolyl, 2-tert-butyl-1-indolyl, 4-tert-butyl-1-indolyl, 2-tert-butyl-3-indolyl, 4-tert-butyl-3-indolyl, 1-dibenzofuranyl, 2-dibenzofuranyl, 3-dibenzofuranyl, 4-dibenzofuranyl, 1-dibenzothiophenyl, 2-dibenzothiophenyl, 3-dibenzothiophenyl, 4-dibenzothiophenyl, 1-naphtho[1,2-b]benzofuranyl, 2-naphtho[1,2-b]benzofuranyl, 3-naphtho[1,2-b]benzofuranyl, 4-naphtho[1,2-b]benzofuranyl, 5-naphtho[1,2-b]benzofuranyl, 6-naphtho[1,2-b]benzofuranyl, 7-naphtho[1,2-b]benzofuranyl, 8-naphtho[1,2-b]benzofuranyl, 9-naphtho[1,2-b]benzofuranyl, 10-naphtho[1,2-b]benzofuranyl, 1-naphtho[2,3-b]benzofuranyl, 2-naphtho[2,3-b]benzofuranyl, 3-naphtho[2,3-b]benzofuranyl, 4-naphtho[2,3-b]benzofuranyl, 5-naphtho[2,3-b]benzofuranyl, 6-naphtho[2,3-b]benzofuranyl, 7-naphtho[2,3-b]benzofuranyl, 8-naphtho[2,3-b]benzofuranyl, 9-naphtho[2,3-b]benzofuranyl, 10-naphtho[2,3-b]benzofuranyl, 1-naphtho[2,1-b]benzofuranyl, 2-naphtho[2,1-b]benzofuranyl, 3-naphtho[2,1-b]benzofuranyl, 4-naphtho[2,1-b]benzofuranyl, 5-naphtho[2,1-b]benzofuranyl, 6-naphtho[2,1-b]benzofuranyl, 7-naphtho[2,1-b]benzofuranyl, 8-naphtho[2,1-b]benzofuranyl, 9-naphtho[2,1-b]benzofuranyl, 10-naphtho[2,1-b]benzofuranyl, 1-naphtho[1,2-b]benzothiophenyl, 2-naphtho[1,2-b]benzothiophenyl, 3-naphtho[1,2-b]benzothiophenyl, 4-naphtho[1,2-b]benzothiophenyl, 5-naphtho[1,2-b]benzothiophenyl, 6-naphtho[1,2-b]benzothiophenyl, 7-naphtho[1,2-b]benzothiophenyl, 8-naphtho[1,2-b]benzothiophenyl, 9-naphtho[1,2-b]benzothiophenyl, 10-naphtho[1,2-b]benzothiophenyl, 1-naphtho[2,3-b]benzothiophenyl, 2-naphtho[2,3-b]benzothiophenyl, 3-naphtho[2,3-b]benzothiophenyl, 4-naphtho[2,3-b]benzothiophenyl, 5-naphtho[2,3-b]benzothiophenyl, 1-naphtho[2,1-b]benzothiophenyl, 2-naphtho[2,1-b]benzothiophenyl, 3-naphtho[2,1-b]benzothiophenyl, 4-naphtho[2,1-b]benzothiophenyl, 5-naphtho[2,1-b]benzothiophenyl, 6-naphtho[2,1-b]benzothiophenyl, 7-naphtho[2,1-b]benzothiophenyl, 8-naphtho[2,1-b]benzothiophenyl, 9-naphtho[2,1-b]benzothiophenyl, 10-naphtho[2,1-b]benzothiophenyl, 2-benzofuro[3,2-d]pyrimidinyl, 6-benzofuro[3,2-d]pyrimidinyl, 7-benzofuro[3,2-d]pyrimidinyl, 8-benzofuro[3,2-d]pyrimidinyl, 9-benzofuro[3,2-d]pyrimidinyl, 2-benzothio[3,2-d]pyrimidinyl, 6-benzothio[3,2-d]pyrimidinyl, 7-benzothio[3,2-d]pyrimidinyl, 8-benzothio[3,2-d]pyrimidinyl, 9-benzothio[3,2-d]pyrimidinyl, 2-benzofuro[3,2-d]pyrazinyl, 6-benzofuro[3,2-d]pyrazinyl, 7-benzofuro[3,2-d]pyrazinyl, 8-benzofuro[3,2-d]pyrazinyl, 9-benzofuro[3,2-d]pyrazinyl, 2-benzothio[3,2-d]pyrazinyl, 6-benzothio[3,2-d]pyrazinyl, 7-benzothio[3,2-d]pyrazinyl, 8-benzothio[3,2-d]pyrazinyl, 9-benzothio[3,2-d]pyrazinyl, 1-silafluorenyl, 2-silafluorenyl, 3-silafluorenyl, 4-silafluorenyl, 1-germafluorenyl, 2-germafluorenyl, 3-germafluorenyl, 4-germafluorenyl, 1-dibenzoselenophenyl, 2-dibenzoselenophenyl, 3-dibenzoselenophenyl, 4-dibenzoselenophenyl, etc. Additionally, “heteroaryl(ene)” can be classified into heteroaryl(ene) with electronic properties and heteroaryl(ene) with hole properties. A heteroaryl(ene) with electronic properties is an electron-rich substituent relative to the parent nucleus, and, for example, it may be a substituted or unsubstituted pyridinyl, a substituted or unsubstituted pyrimidinyl, a substituted or unsubstituted triazinyl, a substituted or unsubstituted quinazolinyl, a substituted or unsubstituted quinoxalinyl, a substituted or unsubstituted quinolyl, etc. Heteroaryl(ene), which has hole properties, is an electron-deficient substituent relative to the parent nucleus, and, for example, it may be a substituted or unsubstituted carbazolyl, a substituted or unsubstituted dibenzofuranyl, a substituted or unsubstituted dibenzothiophenyl, etc. The term “halogen” in the present disclosure includes F, Cl, Br, and I.

The term “a fused ring of a (C₃-C₃₀)aliphatic ring and a (C₆-C₃₀)aromatic ring”, as used in the present disclosure, means a functional group of a ring formed by fusing at least one aliphatic ring having 3 to 30, preferably 3 to 25, and more preferably 3 to 18 ring skeleton carbon atoms, and at least one aromatic ring having 6 to 30, preferably 6 to 25, and more preferably 6 to 18 ring skeleton carbon atoms. For example, the fused ring may be a fused ring of at least one benzene and at least one cyclohexane, or a fused ring of at least one naphthalene and at least one cyclopentane, etc. Herein, the carbon atoms in the fused ring of a (C₃-C₃₀)aliphatic ring and a (C₆-C₃₀)aromatic ring may be replaced with at least one heteroatom selected from B, N, O, S, Si, and P, preferably N, O, and S. The term “halogen” in the present disclosure includes F, Cl, Br, and I.

In addition, “ortho-” (“o-”), “meta-” (“m-”), and “para-” (“p-”) are each prefixes that indicate the relative positions of the substituents. The “ortho-” configuration describes a compound with substituents which are adjacent to each other, e.g., at the 1 and 2 positions on benzene. The “meta-” configuration describes the next substitution position of the immediately adjacent substitution position, e.g., a compound with substituents at the 1 and 3 positions on benzene. The “para-” configuration describes the next substitution position after the “meta-” position, e.g., a compound with substituents at the 1 and 4 positions on benzene.

The term “a ring formed in linking to an adjacent substituent”, as used in the present disclosure, means a substituted or unsubstituted 3- to 30-membered mono- or polycyclic alicyclic, aromatic ring, or a combination thereof, formed by linking or fusing two or more adjacent substituents, and preferably may be a substituted or unsubstituted 3- to 26-membered mono- or polycyclic, alicyclic, aromatic ring, or a combination thereof. Further, the ring formed may include at least one heteroatom selected from the group consisting of B, N, O, S, Si, and P, preferably, N, O, and S.

In addition, “substituted” in the expression “substituted or unsubstituted” means that a hydrogen atom in a certain functional group is replaced with another atom or functional group, i.e., a substituent. Unless otherwise specified, the substituent may replace hydrogen at a position where the substituent may be substituted without limitation, and when two or more hydrogen atoms in a functional group are each replaced with a substituent, each substituent may be the same or different. The maximum number of substituents that can be substituted for a certain functional group may be the total number of valences that can be substituted for each atom forming the functional group. Herein, the substituted alkyl, the substituted aryl(ene), the substituted heteroaryl(ene), the substituted cycloalkyl(ene), the substituted heterocycloalkyl(ene), the substituted alkoxy, the substituted trialkylsilyl, the substituted dialkylarylsilyl, the substituted alkyldiarylsilyl, the substituted triarylsilyl, the substituted fused ring of aliphatic ring and aromatic ring, the substituted mono- or di-alkylamino, the substituted mono- or di-alkenylamino, the substituted alkylalkenylamino, the substituted mono- or di-arylamino, the substituted alkylarylamino, the substituted alkylheteroarylamino, the substituted alkenylarylamino, the substituted alkenylheteroarylamino, the substituted mono- or di-heteroarylamino, and the substituted arylheteroarylamino each independently are substituted with at least one selected from the group consisting of deuterium, halogen, cyano, carboxyl, nitro, hydroxy, (C₁-C₃₀)alkyl, halo(C₁-C₃₀)alkyl, (C₂-C₃₀)alkenyl, (C₂-C₃₀)alkynyl, (C₁-C₃₀)alkoxy, (C₁-C₃₀)alkylthio, (C₃-C₃₀)cycloalkyl, (C₃-C₃₀)cycloalkenyl, (3- to 7-membered)heterocycloalkyl, (C₆-C₃₀)aryloxy, (C₆-C₃₀)arylthio, (3- to 30-membered)heteroaryl substituted or unsubstituted with (C₆-C₃₀)aryl, (C₆-C₃₀)aryl substituted or unsubstituted with (3- to 30-membered)heteroaryl, tri(C₁-C₃₀)alkylsilyl, tri(C₆-C₃₀)arylsilyl, di(C₁-C₃₀)alkyl(C₆-C₃₀)arylsilyl, (C₁-C₃₀)alkyldi(C₆-C₃₀)arylsilyl, a fused ring of a (C₃-C₃₀)aliphatic ring and a (C₆-C₃₀)aromatic ring, amino, mono- or di-(C₁-C₃₀)alkylamino, a substituted or unsubstituted mono- or di-(C₆-C₃₀)arylamino, (C₁-C₃₀)alkyl(C₆-C₃₀)arylamino, mono- or di-(3- to 30-membered)heteroarylamino, (C₁-C₃₀)alkyl(3- to 30-membered)heteroarylamino, (C₆-C₃₀)aryl(3- to 30-membered)heteroarylamino, (C₁-C₃₀)alkylcarbonyl, (C₁-C₃₀)alkoxycarbonyl, (C₆-C₃₀)arylcarbonyl, (C₆-C₃₀)arylphosphinyl, di(C₆-C₃₀)arylboronyl, di(C₁-C₃₀)alkylboronyl, (C₁-C₃₀)alkyl(C₆-C₃₀)arylboronyl, (C₆-C₃₀)ar(C₁-C₃₀)alkyl, (C₁-C₃₀)alkyl(C₆-C₃₀)aryl, and a combination thereof. According to one embodiment of the present disclosure, the substituted alkyl, etc. may each independently be substituted with at least one selected from the group consisting of deuterium, cyano, (C₁-C₃₀)alkyl, (C₃-C₃₀)cycloalkyl, (5- to 30-membered)heteroaryl substituted or unsubstituted with (C₆-C₃₀)aryl, (C₆-C₃₀)aryl substituted or unsubstituted with (5- to 30-membered)heteroaryl, a substituted or unsubstituted mono- or di-(C₆-C₃₀)arylamino, and a combination thereof. According to another embodiment of the present disclosure, the substituted alkyl, etc. may each independently be substituted with at least one selected from the group consisting of deuterium, cyano, (C₁-C_{2M})alkyl, (C₃-C₂₀)cycloalkyl, (5- to 20-membered)heteroaryl substituted or unsubstituted with (C₆-C₂₀)aryl, (C₆-C₂₀)aryl substituted or unsubstituted with (5- to 20-membered)heteroaryl, a substituted or unsubstituted mono- or di-(C₆-C₂₀)arylamino, and a combination thereof. For example, the substituted alkyl, etc. may each independently be substituted with at least one selected from the group consisting of deuterium, a cyano, a methyl unsubstituted or substituted with deuterium, an isopropyl unsubstituted or substituted with deuterium, a tert-butyl, a cyclohexyl unsubstituted or substituted with deuterium, a phenyl unsubstituted or substituted with deuterium, a naphthyl substituted or unsubstituted with deuterium, phenyl, or naphthyl unsubstituted or substituted with deuterium, a biphenyl, a phenanthrenyl, a dibenzofuranyl, a dibenzothiophenyl, a pyridyl, a diphenylamino, a carbazolyl, a norbornanyl, a bicyclo[2.2.1]heptyl, a cyclohexyl, and an adamantyl.

Herein, when no substituent is indicated in the formula or compound structure, it may mean that all positions that can be substituted are hydrogen or deuterium. That is, some hydrogen atoms may be deuterium, which is an isotope of hydrogen, in which the deuterium content may be 0% to 100%. Herein, when no substituent is indicated in the formula or compound structure, hydrogen and deuterium may coexist in the compound unless deuterium is explicitly excluded, such as when the deuterium content is 0%, the hydrogen content is 100%, or all substituents are specified as hydrogen. The deuterium, which may be represented as hydrogen-2, and the element symbol of which may also be written as D or ²H, is one of the isotopes of hydrogen and has a deuteron, consisting of one proton and one neutron, as its nucleus. The isotopes, which means elements with the same atomic number (Z) but different mass numbers (A), may also be interpreted as elements with the same number of protons but different numbers of neutrons.

Hereinafter, an organic electroluminescent device according to one embodiment will be described.

An organic electroluminescent device according to one embodiment comprises a first electrode; a second electrode opposing the first electrode; a light-emitting layer between the first electrode and the second electrode; and a hole transport band between the first electrode and the light-emitting layer, wherein the hole transport band comprises a compound represented by the following Formula 1.

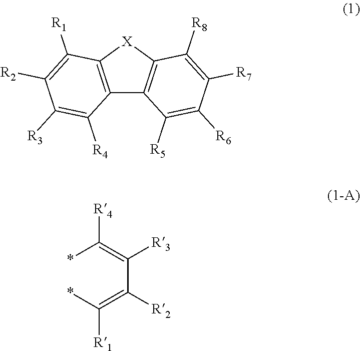

In Formula 1, X represents O, S, or CR₉R₁₀.

In Formula 1, R₉ and R₁₀ each independently represent hydrogen, deuterium, halogen, cyano, a substituted or unsubstituted (C₁-C₃₀)alkyl, a substituted or unsubstituted (C₆-C₃₀)aryl, a substituted or unsubstituted (3- to 30-membered)heteroaryl, or a substituted or unsubstituted (C₃-C₃₀)cycloalkyl; or may be linked to the adjacent substituents to form a ring(s). According to one embodiment of the present disclosure, R₉ and R₁₀ may each independently be hydrogen, deuterium, a substituted or unsubstituted (C₁-C₃₀)alkyl, a substituted or unsubstituted (C₆-C₃₀)aryl, or may be linked to the adjacent substituents to form a ring(s). For example, R₉ and R₁₀ may each independently be a methyl, an ethyl, or a phenyl, or may be linked together to form a cyclopentane ring, and each may independently be substituted with deuterium.

In Formulas 1 and 1-A, R₁ to R₈ and R′₁ to R′₄ each independently represent hydrogen, deuterium, halogen, cyano, a substituted or unsubstituted (C₁-C₃₀)alkyl, a substituted or unsubstituted (C₆-C₃₀)aryl, a substituted or unsubstituted (3- to 30-membered)heteroaryl, a substituted or unsubstituted (C₃-C₃₀)cycloalkyl, a substituted or unsubstituted (C₁-C₃₀)alkoxy, a substituted or unsubstituted tri(C₁-C₃₀)alkylsilyl, a substituted or unsubstituted di(C₁-C₃₀)alkyl(C₆-C₃₀)arylsilyl, a substituted or unsubstituted (C₁-C₃₀)alkyldi(C₆-C₃₀)arylsilyl, a substituted or unsubstituted tri(C₆-C₃₀)arylsilyl, a substituted or unsubstituted fused ring of a (C₃-C₃₀)aliphatic ring and a (C₆-C₃₀)aromatic ring, a substituted or unsubstituted mono- or di-(C₁-C₃₀)alkylamino, a substituted or unsubstituted mono- or di-(C₆-C₃₀)arylamino, a substituted or unsubstituted (C₁-C₃₀)alkyl(C₆-C₃₀)arylamino, a substituted or unsubstituted mono- or di-(3- to 30-membered)heteroarylamino, or a substituted or unsubstituted (C₆-C₃₀)aryl(3- to 30-membered)heteroarylamino; provided that one pair selected from R₅ and R₆, R₆ and R₇, and R₇ and R₈ is bonded together to form a ring with the *-* of Formula 1-A; provided that at least one of R₁ to R₈ and R′₁ to R′₄ is represented by the following Formula A. According to one embodiment of the present disclosure, R₁ to R₈ and R′₁ to R′₄ may each independently be hydrogen, deuterium, a substituted or unsubstituted (C₆-C₃₀)aryl, a substituted or unsubstituted mono- or di-(C₆-C₃₀)arylamino, a substituted or unsubstituted (C₆-C₃₀)aryl(3- to 30-membered)heteroarylamino or Formula A. According to another embodiment of the present disclosure, R₁ to R₈ and R′₁ to R′₄ may each independently be hydrogen, deuterium, a phenyl or the following Formula A, and may be substituted with deuterium. Provided that one pair selected from R₅ and R₆, R₆ and R₇, and R₇ and R₈ is bonded together to form a ring with the *-* of Formula 1-A.

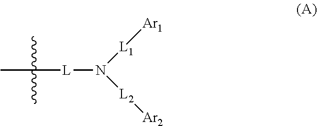

In Formula A, L, L₁, and L₂ each independently represent a single bond, a substituted or unsubstituted (C₆-C₃₀)arylene, a substituted or unsubstituted (3- to 30-membered)heteroarylene, or a substituted or unsubstituted (C₃-C₃₀)cycloalkylene. According to one embodiment of the present disclosure, L, L₁, and L₂ each independently represent a single bond, a substituted or unsubstituted (C₆-C₂₀)arylene, or a substituted or unsubstituted (3- to 20-membered)heteroarylene. According to another embodiment of the present disclosure, L, L₁, and L₂ each independently represent a single bond, or a substituted or unsubstituted (C₆-C₁₂)arylene. For example, L, L₁, and L₂ may each independently be a single bond; a phenylene unsubstituted or substituted with methyl unsubstituted or substituted with deuterium, tert-butyl, or naphthyl; a biphenylene unsubstituted or substituted with methyl, etc., and each may independently be substituted with deuterium.

In Formula A, Ar₁, and Ar₂ each independently represent a substituted or unsubstituted (C₆-C₃₀)aryl, or a substituted or unsubstituted (3- to 30-membered)heteroaryl. According to one embodiment of the present disclosure, Ar₁ and Ar₂ each independently represent a substituted or unsubstituted (C₆-C₂₀)aryl or a substituted or unsubstituted (3- to 20-membered)heteroaryl. According to another embodiment of the present disclosure, Ar₁ and Ar₂ each independently represent a substituted or unsubstituted (C₆-C₁₈)aryl. For example, Ar₁ and Ar₂ may each independently be a phenyl unsubstituted or substituted with methyl, ethyl, naphthyl unsubstituted or substituted with methyl, phenyl, or biphenyl, isopropyl unsubstituted or substituted with deuterium, tert-butyl, bicyclo[2,2,1]heptyl, adamantyl, or cyclohexyl; a biphenyl unsubstituted or substituted with phenyl unsubstituted or substituted with deuterium, isopropyl, tert-butyl, cyclopentyl, or naphthyl; a terphenyl unsubstituted or substituted with methyl or phenyl; a naphthyl unsubstituted or substituted with phenyl or methyl; or a substituted or unsubstituted quaterphenyl, etc., and each may independently be substituted with deuterium.

Provided that at least one of L, L₁, L₂, Ar₁, and Ar₂ is necessarily substituted with a substituted or unsubstituted (C₃-C₃₀)cycloalkyl or a substituted or unsubstituted (C₁-C₃₀)alkyl.

According to one embodiment of the present disclosure, at least one of L, L₁, L₂, Ar₁, and Ar₂ may be necessarily substituted with a substituted or unsubstituted (C₃-C₂₅)cycloalkyl or a substituted or unsubstituted (C₁-C₂₅)alkyl. For example, at least one of L, L₁, L₂, Ar, and Ar₂ may necessarily be substituted with a methyl unsubstituted or substituted with deuterium, an isopropyl unsubstituted or substituted with deuterium, a tert-butyl, a bicyclo[2,2,1]heptyl, a cyclohexyl, or an adamantyl, which may be substituted with deuterium.

According to one embodiment of the present disclosure, in the alkyl or cycloalkyl that are necessarily substituted in Formula 1, the cycloalkyl is a substituted or unsubstituted cyclohexyl, a substituted or unsubstituted norbornanyl, a substituted or unsubstituted adamantyl, or a substituted or unsubstituted cyclopentyl; and the alkyl is selected from the group consisting of methyl, ethyl, n-propyl, isopropyl, n-butyl, isobutyl, sec-butyl, tert-butyl, n-pentyl, tert-pentyl, neopentyl, isopentyl, sec-pentyl, and 3-pentyl, each of which is unsubstituted or substituted with deuterium.

According to one embodiment of the present disclosure, Formula 1 may be represented by the following Formula 1-1.

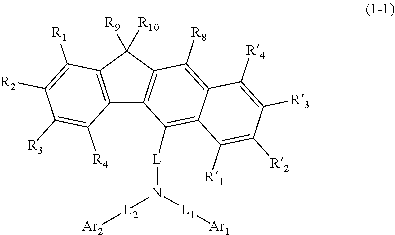

In Formula 1-1, R₁ to R₄, R₈ to R₁₀, R′₁ to R′₄, L, L₁, L₂, Ar₁, and Ar₂ are as defined above.

According to one embodiment of the present disclosure, R₉ and R₁₀ may each independently represent a methyl, an ethyl, a phenyl, or a group consisting of these.

According to one embodiment of the present disclosure, L may represent a single bond.

The compound represented by Formula 1 may be selected from the following compounds, but is not limited thereto.

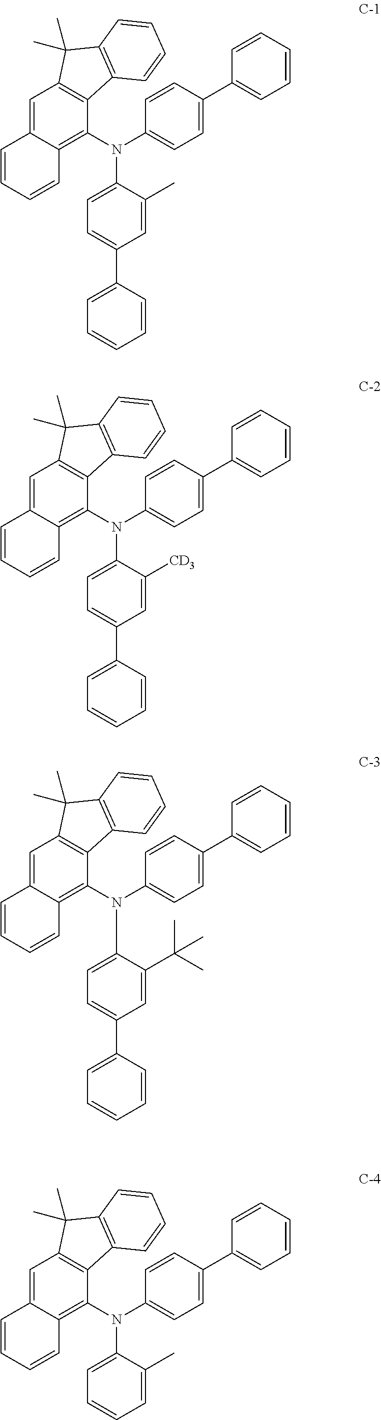

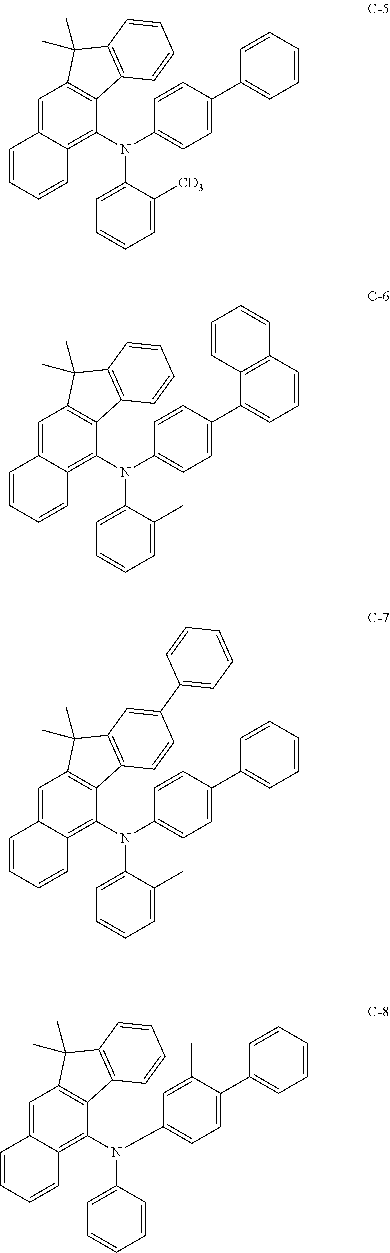 [SMILES: [2H]C([2H])([2H])c1ccccc1N(c1ccc(-c2ccccc2)cc1)c1c2c(cc3ccccc13)C(C)(C)c1ccccc1-2 ; Cc1ccccc1N(c1ccc(-c2cccc3ccccc23)cc1)c1c2c(cc3ccccc13)C(C)(C)c1ccccc1-2 ; Cc1ccccc1N(c1ccc(-c2ccccc2)cc1)c1c2c(cc3ccccc13)C(C)(C)c1cc(-c3ccccc3)ccc1-2 ; Cc1cc(N(c2ccccc2)c2c3c(cc4ccccc24)C(C)(C)c2ccccc2-3)ccc1-c1ccccc1]

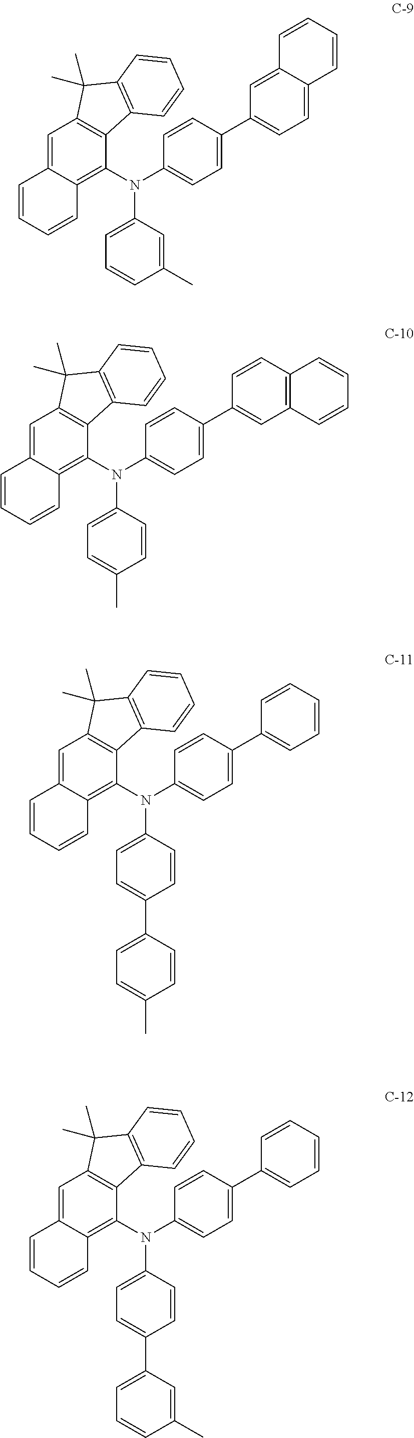 [SMILES: Cc1cccc(N(c2ccc(-c3ccc4ccccc4c3)cc2)c2c3c(cc4ccccc24)C(C)(C)c2ccccc2-3)c1 ; Cc1ccc(N(c2ccc(-c3ccc4ccccc4c3)cc2)c2c3c(cc4ccccc24)C(C)(C)c2ccccc2-3)cc1 ; Cc1ccc(-c2ccc(N(c3ccc(-c4ccccc4)cc3)c3c4c(cc5ccccc35)C(C)(C)c3ccccc3-4)cc2)cc1 ; Cc1cccc(-c2ccc(N(c3ccc(-c4ccccc4)cc3)c3c4c(cc5ccccc35)C(C)(C)c3ccccc3-4)cc2)c1]

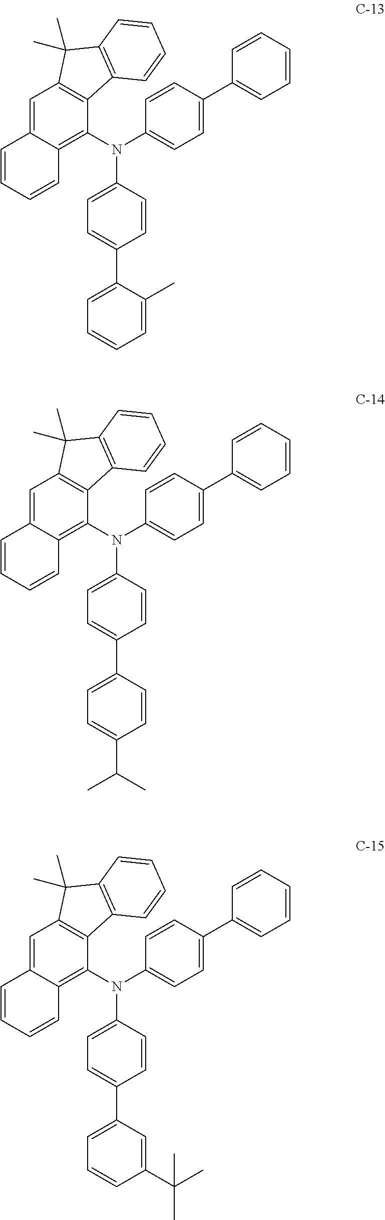 [SMILES: Cc1ccccc1-c1ccc(N(c2ccc(-c3ccccc3)cc2)c2c3c(cc4ccccc24)C(C)(C)c2ccccc2-3)cc1 ; CC(C)c1ccc(-c2ccc(N(c3ccc(-c4ccccc4)cc3)c3c4c(cc5ccccc35)C(C)(C)c3ccccc3-4)cc2)cc1 ; CC(C)(C)c1cccc(-c2ccc(N(c3ccc(-c4ccccc4)cc3)c3c4c(cc5ccccc35)C(C)(C)c3ccccc3-4)cc2)c1]

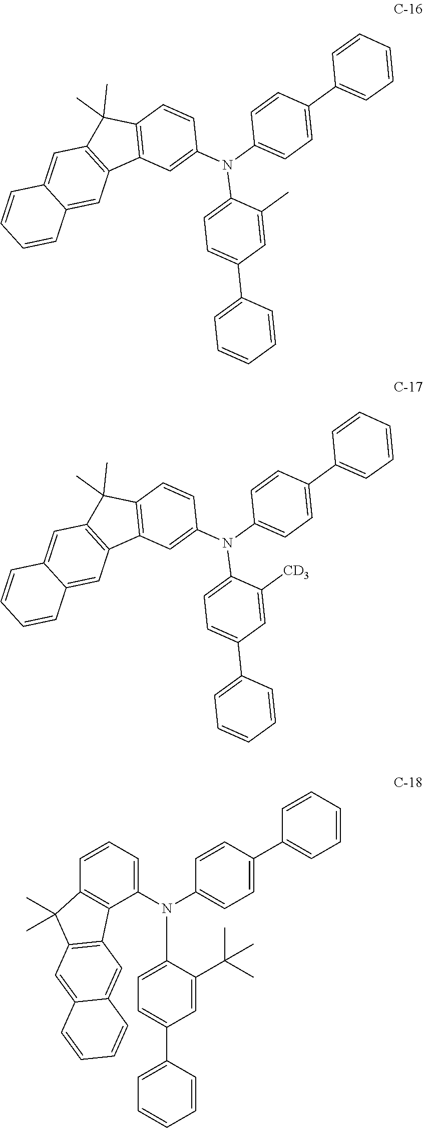 [SMILES: Cc1cc(-c2ccccc2)ccc1N(c1ccc(-c2ccccc2)cc1)c1ccc2c(c1)-c1cc3ccccc3cc1C2(C)C ; [2H]C([2H])([2H])c1cc(-c2ccccc2)ccc1N(c1ccc(-c2ccccc2)cc1)c1ccc2c(c1)-c1cc3ccccc3cc1C2(C)C ; CC(C)(C)c1cc(-c2ccccc2)ccc1N(c1ccc(-c2ccccc2)cc1)c1cccc2c1-c1cc3ccccc3cc1C2(C)C]

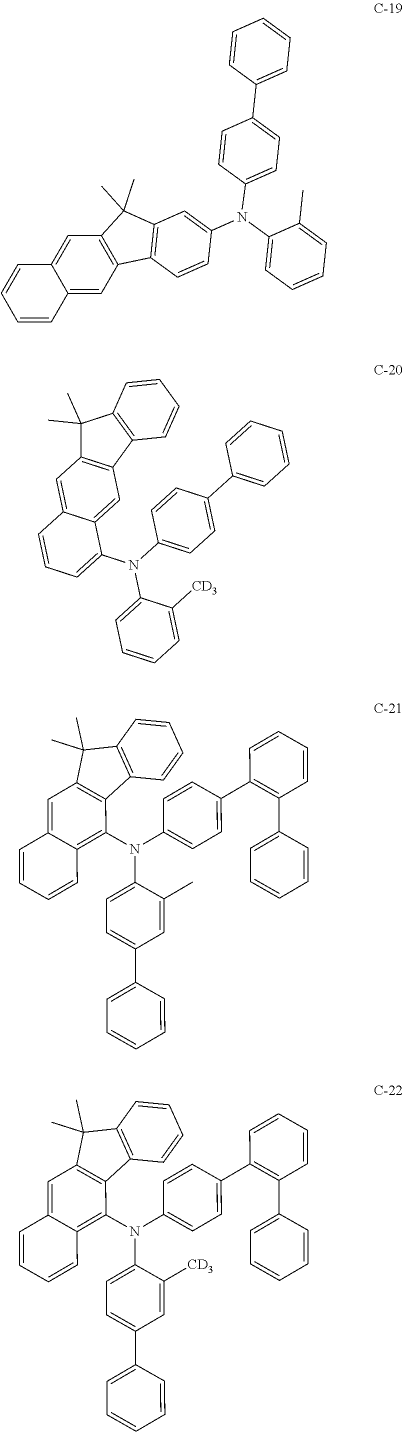 [SMILES: Cc1ccccc1N(c1ccc(-c2ccccc2)cc1)c1ccc2c(c1)C(C)(C)c1cc3ccccc3cc1-2 ; [2H]C([2H])([2H])c1ccccc1N(c1ccc(-c2ccccc2)cc1)c1cccc2cc3c(cc12)-c1ccccc1C3(C)C ; Cc1cc(-c2ccccc2)ccc1N(c1ccc(-c2ccccc2-c2ccccc2)cc1)c1c2c(cc3ccccc13)C(C)(C)c1ccccc1-2 ; [2H]C([2H])([2H])c1cc(-c2ccccc2)ccc1N(c1ccc(-c2ccccc2-c2ccccc2)cc1)c1c2c(cc3ccccc13)C(C)(C)c1ccccc1-2]

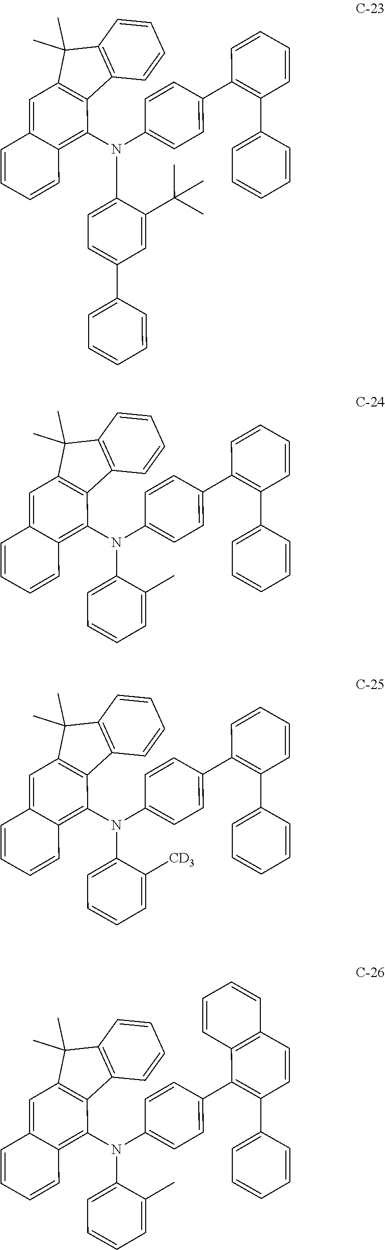 [SMILES: CC(C)(C)c1cc(-c2ccccc2)ccc1N(c1ccc(-c2ccccc2-c2ccccc2)cc1)c1c2c(cc3ccccc13)C(C)(C)c1ccccc1-2 ; Cc1ccccc1N(c1ccc(-c2ccccc2-c2ccccc2)cc1)c1c2c(cc3ccccc13)C(C)(C)c1ccccc1-2 ; [2H]C([2H])([2H])c1ccccc1N(c1ccc(-c2ccccc2-c2ccccc2)cc1)c1c2c(cc3ccccc13)C(C)(C)c1ccccc1-2 ; Cc1ccccc1N(c1ccc(-c2c(-c3ccccc3)ccc3ccccc23)cc1)c1c2c(cc3ccccc13)C(C)(C)c1ccccc1-2]

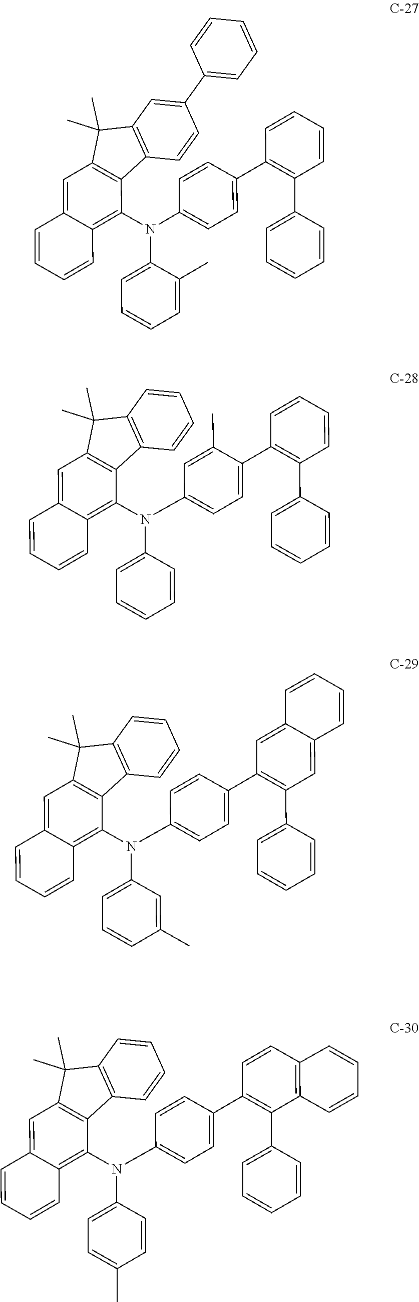 [SMILES: Cc1ccccc1N(c1ccc(-c2ccccc2-c2ccccc2)cc1)c1c2c(cc3ccccc13)C(C)(C)c1cc(-c3ccccc3)ccc1-2 ; Cc1cc(N(c2ccccc2)c2c3c(cc4ccccc24)C(C)(C)c2ccccc2-3)ccc1-c1ccccc1-c1ccccc1 ; Cc1cccc(N(c2ccc(-c3cc4ccccc4cc3-c3ccccc3)cc2)c2c3c(cc4ccccc24)C(C)(C)c2ccccc2-3)c1 ; Cc1ccc(N(c2ccc(-c3ccc4ccccc4c3-c3ccccc3)cc2)c2c3c(cc4ccccc24)C(C)(C)c2ccccc2-3)cc1]

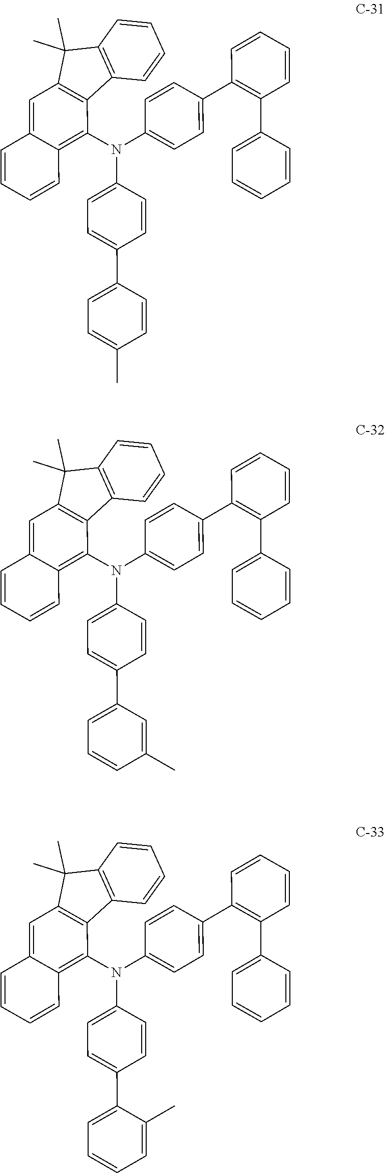 [SMILES: Cc1ccc(-c2ccc(N(c3ccc(-c4ccccc4-c4ccccc4)cc3)c3c4c(cc5ccccc35)C(C)(C)c3ccccc3-4)cc2)cc1 ; Cc1cccc(-c2ccc(N(c3ccc(-c4ccccc4-c4ccccc4)cc3)c3c4c(cc5ccccc35)C(C)(C)c3ccccc3-4)cc2)c1 ; Cc1ccccc1-c1ccc(N(c2ccc(-c3ccccc3-c3ccccc3)cc2)c2c3c(cc4ccccc24)C(C)(C)c2ccccc2-3)cc1]

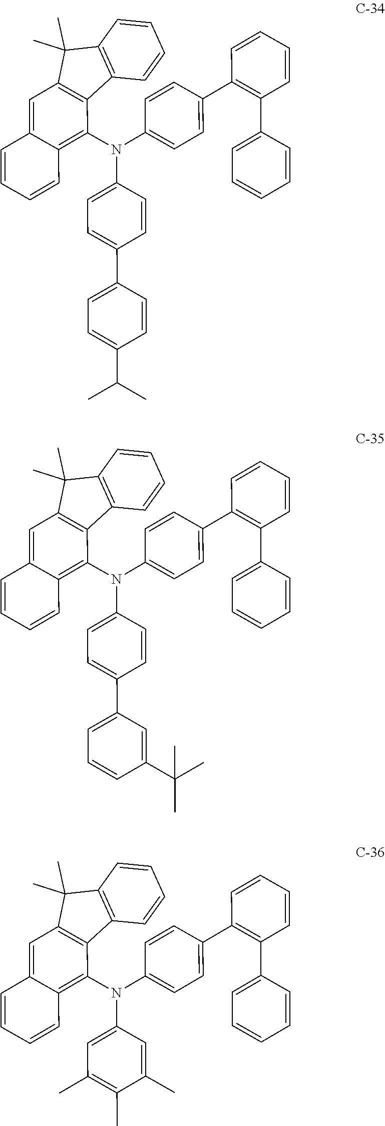 [SMILES: CC(C)c1ccc(-c2ccc(N(c3ccc(-c4ccccc4-c4ccccc4)cc3)c3c4c(cc5ccccc35)C(C)(C)c3ccccc3-4)cc2)cc1 ; CC(C)(C)c1cccc(-c2ccc(N(c3ccc(-c4ccccc4-c4ccccc4)cc3)c3c4c(cc5ccccc35)C(C)(C)c3ccccc3-4)cc2)c1 ; Cc1cc(N(c2ccc(-c3ccccc3-c3ccccc3)cc2)c2c3c(cc4ccccc24)C(C)(C)c2ccccc2-3)cc(C)c1C]

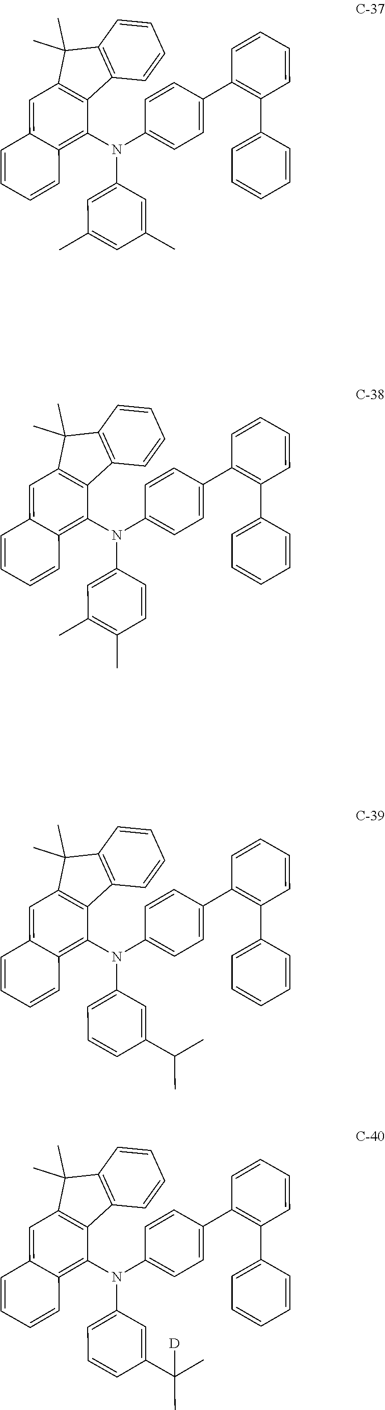 [SMILES: Cc1cc(C)cc(N(c2ccc(-c3ccccc3-c3ccccc3)cc2)c2c3c(cc4ccccc24)C(C)(C)c2ccccc2-3)c1 ; Cc1ccc(N(c2ccc(-c3ccccc3-c3ccccc3)cc2)c2c3c(cc4ccccc24)C(C)(C)c2ccccc2-3)cc1C ; CC(C)c1cccc(N(c2ccc(-c3ccccc3-c3ccccc3)cc2)c2c3c(cc4ccccc24)C(C)(C)c2ccccc2-3)c1 ; [2H]C(C)(C)c1cccc(N(c2ccc(-c3ccccc3-c3ccccc3)cc2)c2c3c(cc4ccccc24)C(C)(C)c2ccccc2-3)c1]

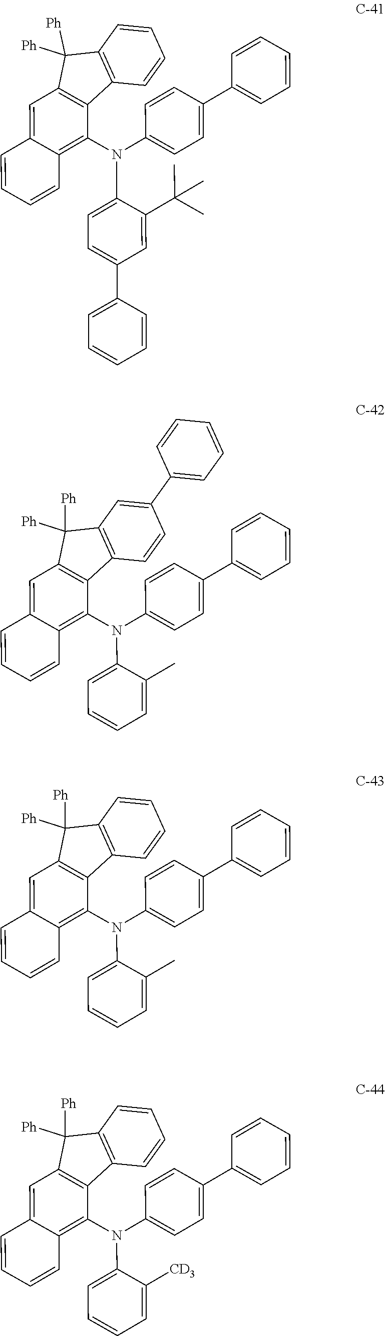 [SMILES: CC(C)(C)c1cc(-c2ccccc2)ccc1N(c1ccc(-c2ccccc2)cc1)c1c2c(cc3ccccc13)C(c1ccccc1)(c1ccccc1)c1ccccc1-2 ; Cc1ccccc1N(c1ccc(-c2ccccc2)cc1)c1c2c(cc3ccccc13)C(c1ccccc1)(c1ccccc1)c1cc(-c3ccccc3)ccc1-2 ; Cc1ccccc1N(c1ccc(-c2ccccc2)cc1)c1c2c(cc3ccccc13)C(c1ccccc1)(c1ccccc1)c1ccccc1-2 ; [2H]C([2H])([2H])c1ccccc1N(c1ccc(-c2ccccc2)cc1)c1c2c(cc3ccccc13)C(c1ccccc1)(c1ccccc1)c1ccccc1-2]

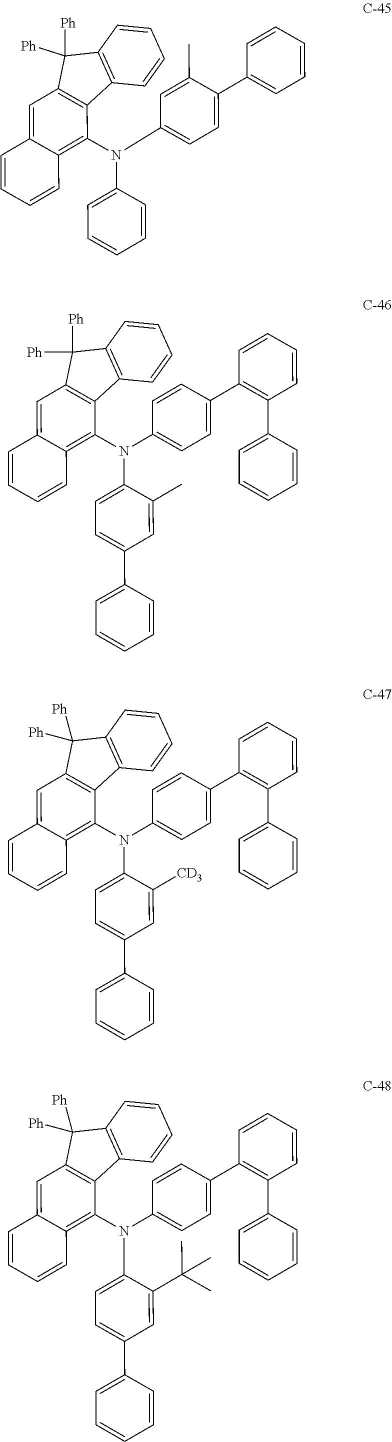 [SMILES: Cc1cc(N(c2ccccc2)c2c3c(cc4ccccc24)C(c2ccccc2)(c2ccccc2)c2ccccc2-3)ccc1-c1ccccc1 ; Cc1cc(-c2ccccc2)ccc1N(c1ccc(-c2ccccc2-c2ccccc2)cc1)c1c2c(cc3ccccc13)C(c1ccccc1)(c1ccccc1)c1ccccc1-2 ; [2H]C([2H])([2H])c1cc(-c2ccccc2)ccc1N(c1ccc(-c2ccccc2-c2ccccc2)cc1)c1c2c(cc3ccccc13)C(c1ccccc1)(c1ccccc1)c1ccccc1-2 ; CC(C)(C)c1cc(-c2ccccc2)ccc1N(c1ccc(-c2ccccc2-c2ccccc2)cc1)c1c2c(cc3ccccc13)C(c1ccccc1)(c1ccccc1)c1ccccc1-2]

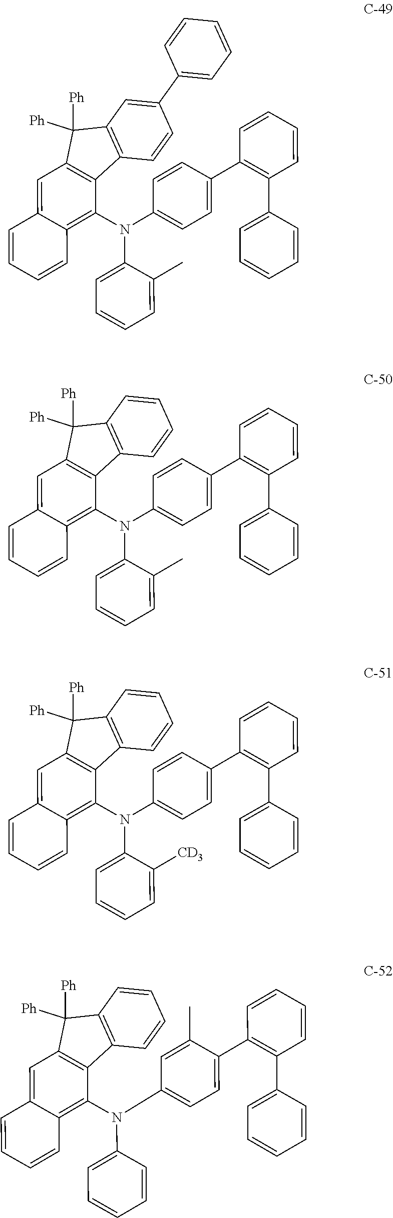 [SMILES: Cc1ccccc1N(c1ccc(-c2ccccc2-c2ccccc2)cc1)c1c2c(cc3ccccc13)C(c1ccccc1)(c1ccccc1)c1cc(-c3ccccc3)ccc1-2 ; Cc1ccccc1N(c1ccc(-c2ccccc2-c2ccccc2)cc1)c1c2c(cc3ccccc13)C(c1ccccc1)(c1ccccc1)c1ccccc1-2 ; [2H]C([2H])([2H])c1ccccc1N(c1ccc(-c2ccccc2-c2ccccc2)cc1)c1c2c(cc3ccccc13)C(c1ccccc1)(c1ccccc1)c1ccccc1-2 ; Cc1cc(N(c2ccccc2)c2c3c(cc4ccccc24)C(c2ccccc2)(c2ccccc2)c2ccccc2-3)ccc1-c1ccccc1-c1ccccc1]

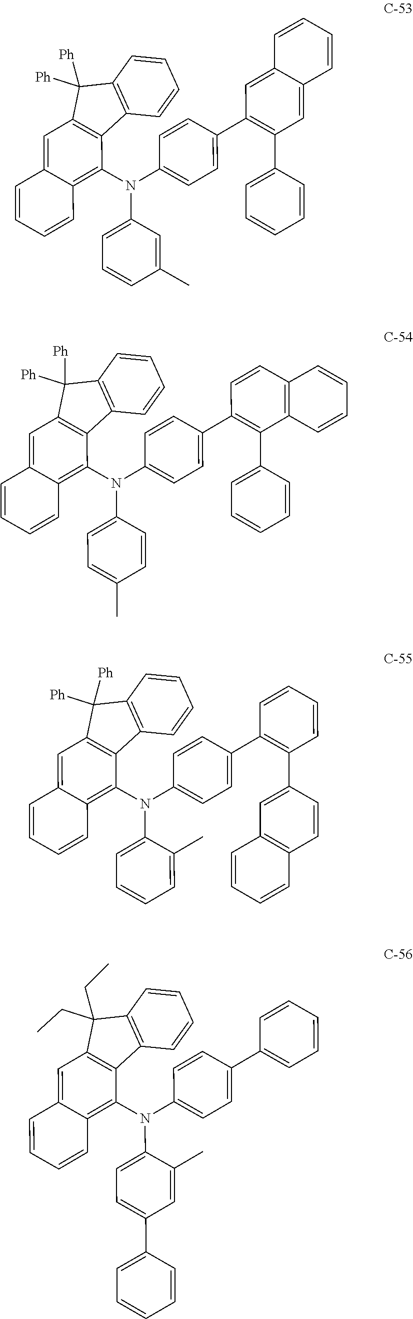 [SMILES: Cc1cccc(N(c2ccc(-c3cc4ccccc4cc3-c3ccccc3)cc2)c2c3c(cc4ccccc24)C(c2ccccc2)(c2ccccc2)c2ccccc2-3)c1 ; Cc1ccc(N(c2ccc(-c3ccc4ccccc4c3-c3ccccc3)cc2)c2c3c(cc4ccccc24)C(c2ccccc2)(c2ccccc2)c2ccccc2-3)cc1 ; Cc1ccccc1N(c1ccc(-c2ccccc2-c2ccc3ccccc3c2)cc1)c1c2c(cc3ccccc13)C(c1ccccc1)(c1ccccc1)c1ccccc1-2 ; CCC1(CC)c2ccccc2-c2c1cc1ccccc1c2N(c1ccc(-c2ccccc2)cc1)c1ccc(-c2ccccc2)cc1C]

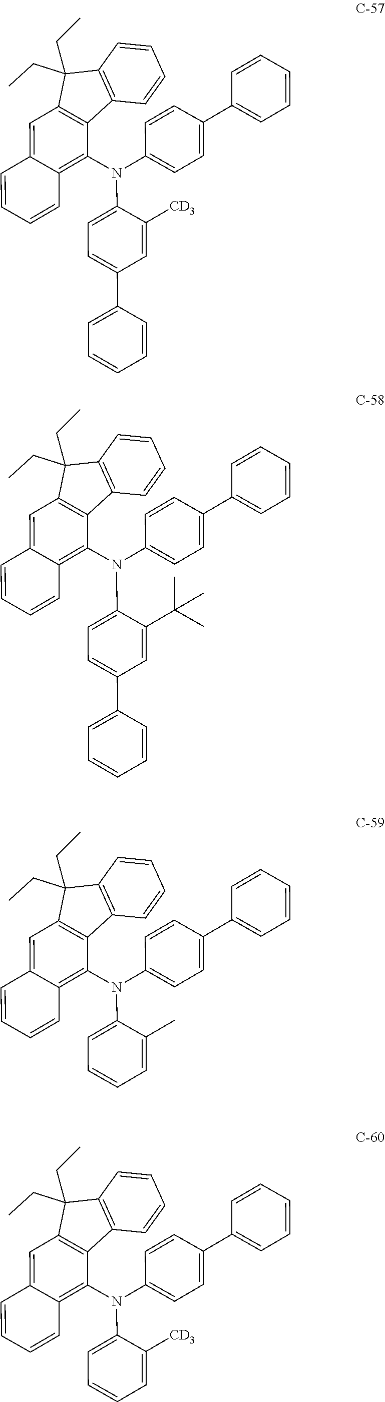 [SMILES: [2H]C([2H])([2H])c1cc(-c2ccccc2)ccc1N(c1ccc(-c2ccccc2)cc1)c1c2c(cc3ccccc13)C(CC)(CC)c1ccccc1-2 ; CCC1(CC)c2ccccc2-c2c1cc1ccccc1c2N(c1ccc(-c2ccccc2)cc1)c1ccc(-c2ccccc2)cc1C(C)(C)C ; CCC1(CC)c2ccccc2-c2c1cc1ccccc1c2N(c1ccc(-c2ccccc2)cc1)c1ccccc1C ; [2H]C([2H])([2H])c1ccccc1N(c1ccc(-c2ccccc2)cc1)c1c2c(cc3ccccc13)C(CC)(CC)c1ccccc1-2]

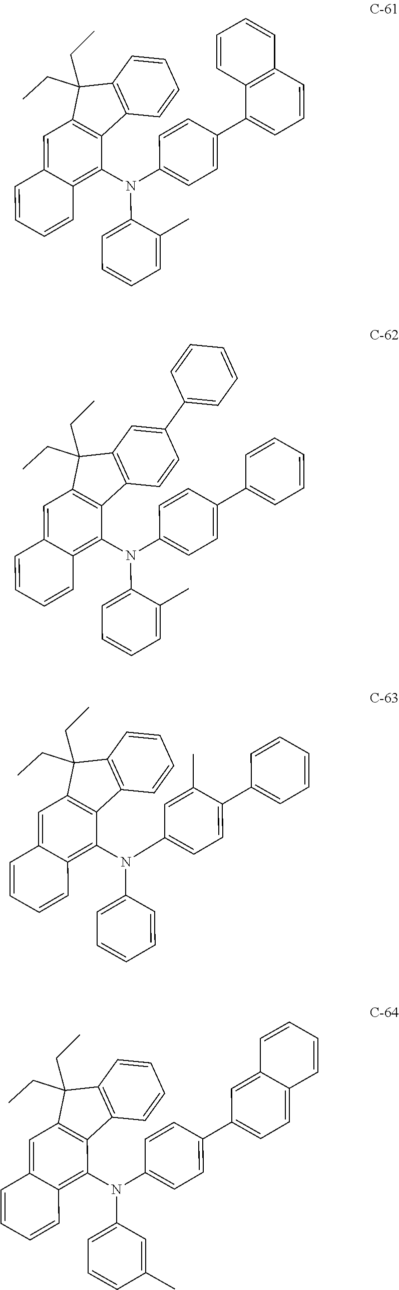 [SMILES: CCC1(CC)c2ccccc2-c2c1cc1ccccc1c2N(c1ccc(-c2cccc3ccccc23)cc1)c1ccccc1C ; CCC1(CC)c2cc(-c3ccccc3)ccc2-c2c1cc1ccccc1c2N(c1ccc(-c2ccccc2)cc1)c1ccccc1C ; CCC1(CC)c2ccccc2-c2c1cc1ccccc1c2N(c1ccccc1)c1ccc(-c2ccccc2)c(C)c1 ; CCC1(CC)c2ccccc2-c2c1cc1ccccc1c2N(c1ccc(-c2ccc3ccccc3c2)cc1)c1cccc(C)c1]

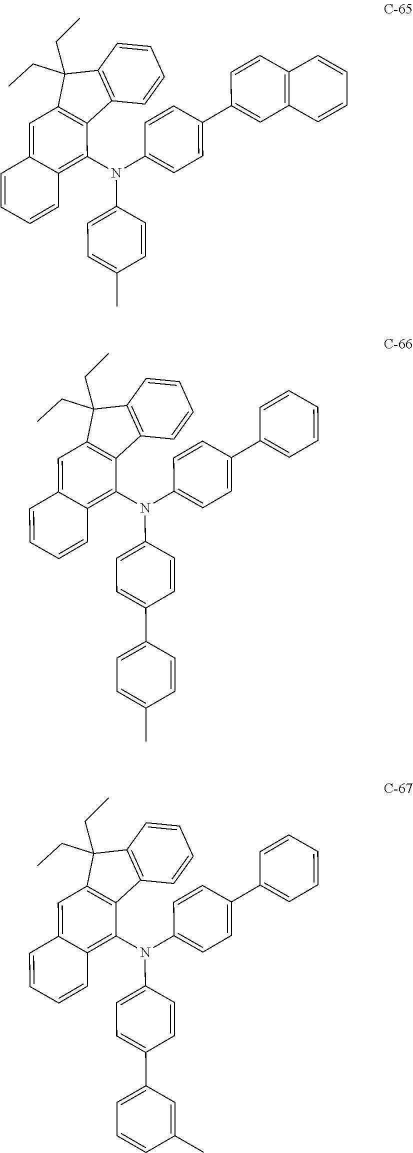 [SMILES: CCC1(CC)c2ccccc2-c2c1cc1ccccc1c2N(c1ccc(C)cc1)c1ccc(-c2ccc3ccccc3c2)cc1 ; CCC1(CC)c2ccccc2-c2c1cc1ccccc1c2N(c1ccc(-c2ccccc2)cc1)c1ccc(-c2ccc(C)cc2)cc1 ; CCC1(CC)c2ccccc2-c2c1cc1ccccc1c2N(c1ccc(-c2ccccc2)cc1)c1ccc(-c2cccc(C)c2)cc1]

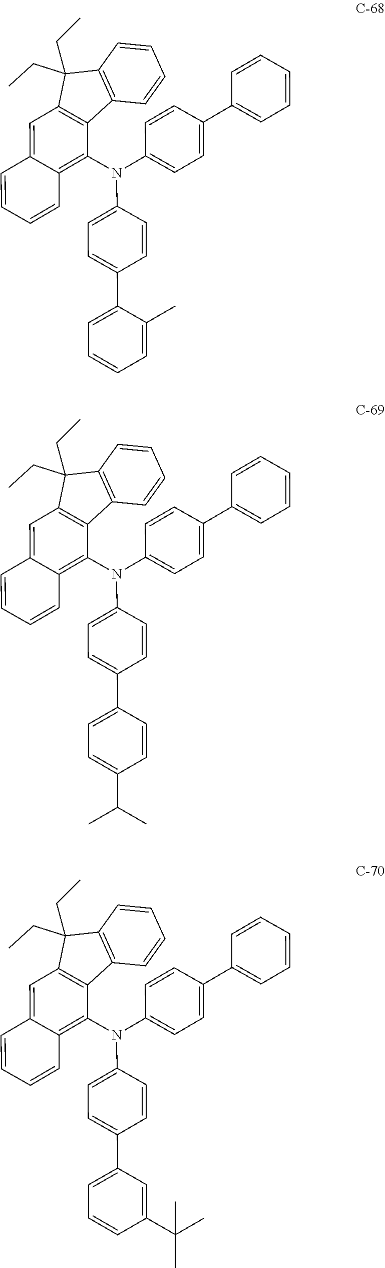 [SMILES: CCC1(CC)c2ccccc2-c2c1cc1ccccc1c2N(c1ccc(-c2ccccc2)cc1)c1ccc(-c2ccccc2C)cc1 ; CCC1(CC)c2ccccc2-c2c1cc1ccccc1c2N(c1ccc(-c2ccccc2)cc1)c1ccc(-c2ccc(C(C)C)cc2)cc1 ; CCC1(CC)c2ccccc2-c2c1cc1ccccc1c2N(c1ccc(-c2ccccc2)cc1)c1ccc(-c2cccc(C(C)(C)C)c2)cc1]

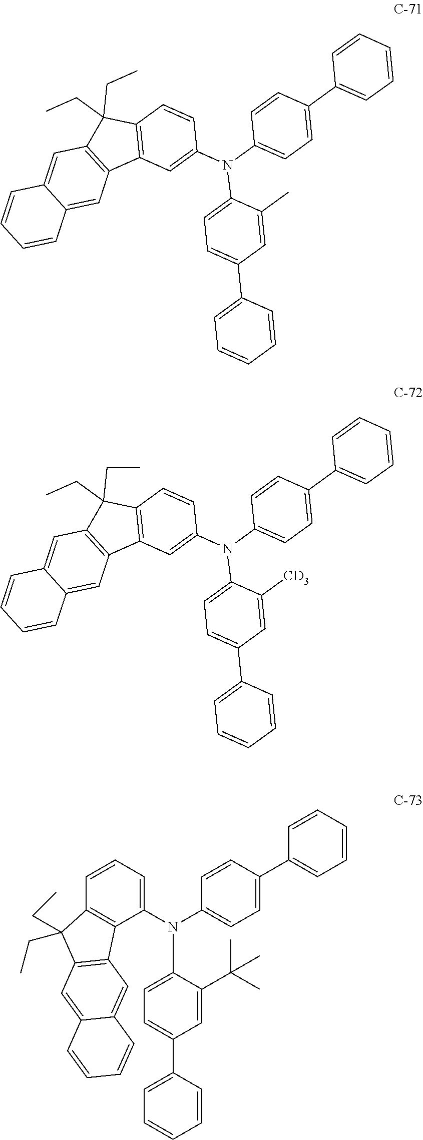 [SMILES: CCC1(CC)c2ccc(N(c3ccc(-c4ccccc4)cc3)c3ccc(-c4ccccc4)cc3C)cc2-c2cc3ccccc3cc21 ; [2H]C([2H])([2H])c1cc(-c2ccccc2)ccc1N(c1ccc(-c2ccccc2)cc1)c1ccc2c(c1)-c1cc3ccccc3cc1C2(CC)CC ; CCC1(CC)c2cc3ccccc3cc2-c2c(N(c3ccc(-c4ccccc4)cc3)c3ccc(-c4ccccc4)cc3C(C)(C)C)cccc21]

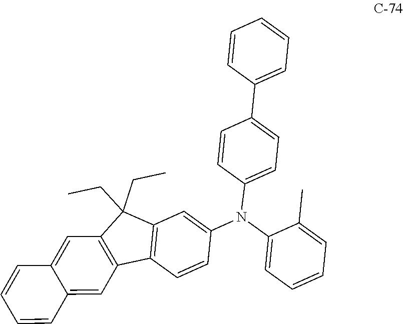 [SMILES: CCC1(CC)c2cc(N(c3ccc(-c4ccccc4)cc3)c3ccccc3C)ccc2-c2cc3ccccc3cc21]

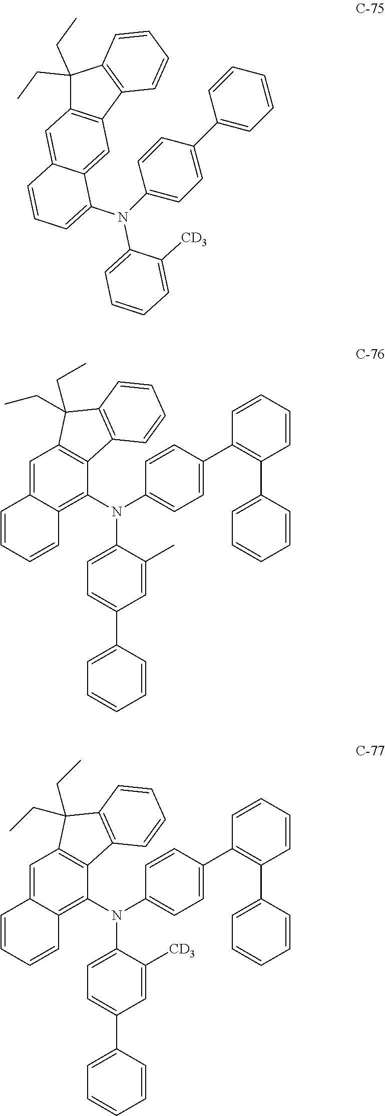 [SMILES: [2H]C([2H])([2H])c1ccccc1N(c1ccc(-c2ccccc2)cc1)c1cccc2cc3c(cc12)-c1ccccc1C3(CC)CC ; CCC1(CC)c2ccccc2-c2c1cc1ccccc1c2N(c1ccc(-c2ccccc2-c2ccccc2)cc1)c1ccc(-c2ccccc2)cc1C ; [2H]C([2H])([2H])c1cc(-c2ccccc2)ccc1N(c1ccc(-c2ccccc2-c2ccccc2)cc1)c1c2c(cc3ccccc13)C(CC)(CC)c1ccccc1-2]

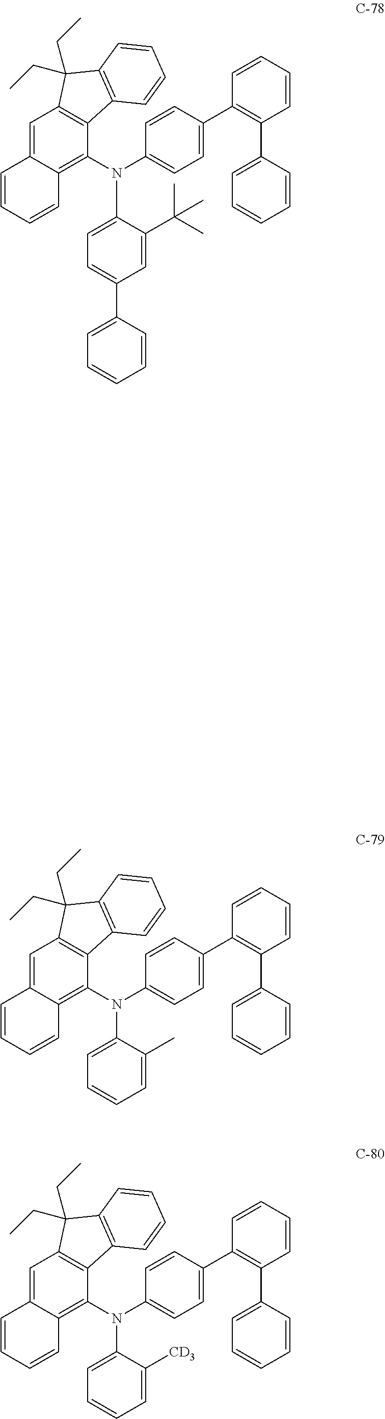 [SMILES: CCC1(CC)c2ccccc2-c2c1cc1ccccc1c2N(c1ccc(-c2ccccc2-c2ccccc2)cc1)c1ccc(-c2ccccc2)cc1C(C)(C)C ; CCC1(CC)c2ccccc2-c2c1cc1ccccc1c2N(c1ccc(-c2ccccc2-c2ccccc2)cc1)c1ccccc1C ; [2H]C([2H])([2H])c1ccccc1N(c1ccc(-c2ccccc2-c2ccccc2)cc1)c1c2c(cc3ccccc13)C(CC)(CC)c1ccccc1-2]

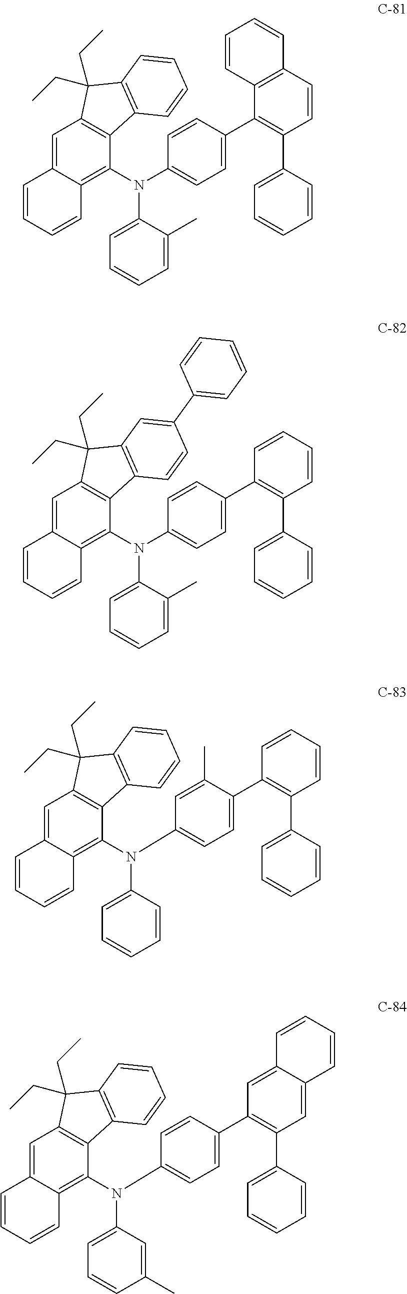 [SMILES: CCC1(CC)c2ccccc2-c2c1cc1ccccc1c2N(c1ccc(-c2c(-c3ccccc3)ccc3ccccc23)cc1)c1ccccc1C ; CCC1(CC)c2cc(-c3ccccc3)ccc2-c2c1cc1ccccc1c2N(c1ccc(-c2ccccc2-c2ccccc2)cc1)c1ccccc1C ; CCC1(CC)c2ccccc2-c2c1cc1ccccc1c2N(c1ccccc1)c1ccc(-c2ccccc2-c2ccccc2)c(C)c1 ; CCC1(CC)c2ccccc2-c2c1cc1ccccc1c2N(c1ccc(-c2cc3ccccc3cc2-c2ccccc2)cc1)c1cccc(C)c1]

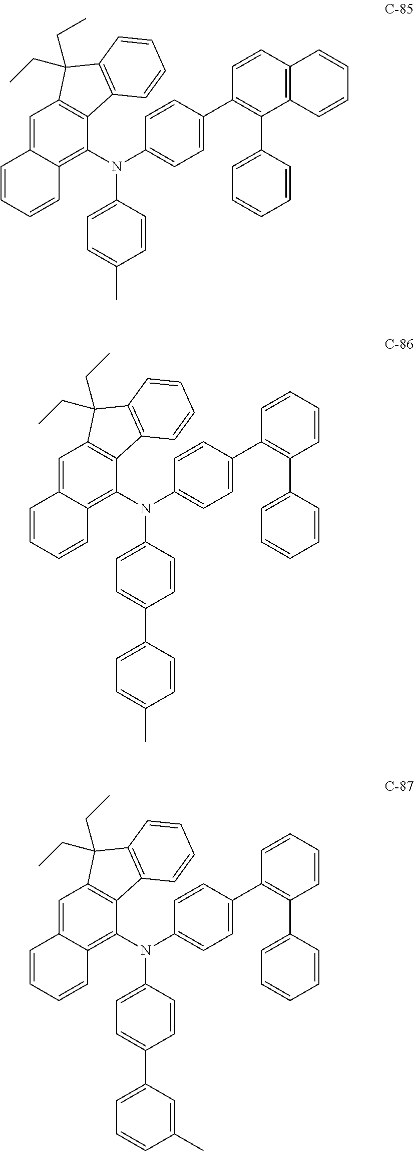 [SMILES: CCC1(CC)c2ccccc2-c2c1cc1ccccc1c2N(c1ccc(C)cc1)c1ccc(-c2ccc3ccccc3c2-c2ccccc2)cc1 ; CCC1(CC)c2ccccc2-c2c1cc1ccccc1c2N(c1ccc(-c2ccc(C)cc2)cc1)c1ccc(-c2ccccc2-c2ccccc2)cc1 ; CCC1(CC)c2ccccc2-c2c1cc1ccccc1c2N(c1ccc(-c2cccc(C)c2)cc1)c1ccc(-c2ccccc2-c2ccccc2)cc1]

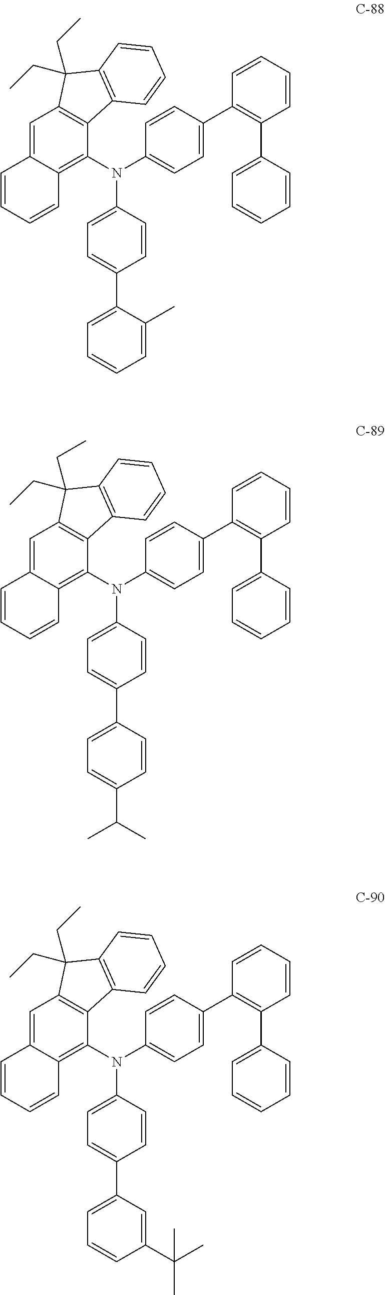 [SMILES: CCC1(CC)c2ccccc2-c2c1cc1ccccc1c2N(c1ccc(-c2ccccc2C)cc1)c1ccc(-c2ccccc2-c2ccccc2)cc1 ; CCC1(CC)c2ccccc2-c2c1cc1ccccc1c2N(c1ccc(-c2ccc(C(C)C)cc2)cc1)c1ccc(-c2ccccc2-c2ccccc2)cc1 ; CCC1(CC)c2ccccc2-c2c1cc1ccccc1c2N(c1ccc(-c2cccc(C(C)(C)C)c2)cc1)c1ccc(-c2ccccc2-c2ccccc2)cc1]

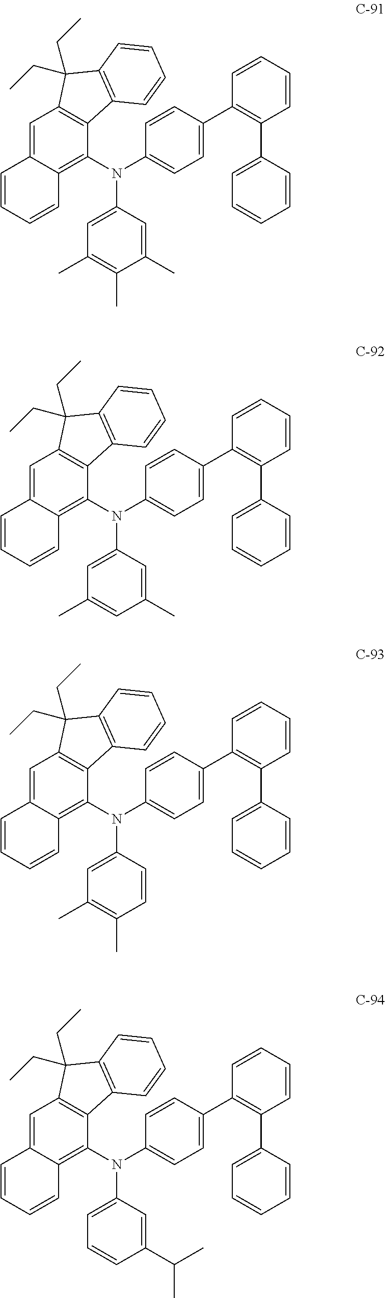 [SMILES: CCC1(CC)c2ccccc2-c2c1cc1ccccc1c2N(c1ccc(-c2ccccc2-c2ccccc2)cc1)c1cc(C)c(C)c(C)c1 ; CCC1(CC)c2ccccc2-c2c1cc1ccccc1c2N(c1ccc(-c2ccccc2-c2ccccc2)cc1)c1cc(C)cc(C)c1 ; CCC1(CC)c2ccccc2-c2c1cc1ccccc1c2N(c1ccc(-c2ccccc2-c2ccccc2)cc1)c1ccc(C)c(C)c1 ; CCC1(CC)c2ccccc2-c2c1cc1ccccc1c2N(c1ccc(-c2ccccc2-c2ccccc2)cc1)c1cccc(C(C)C)c1]

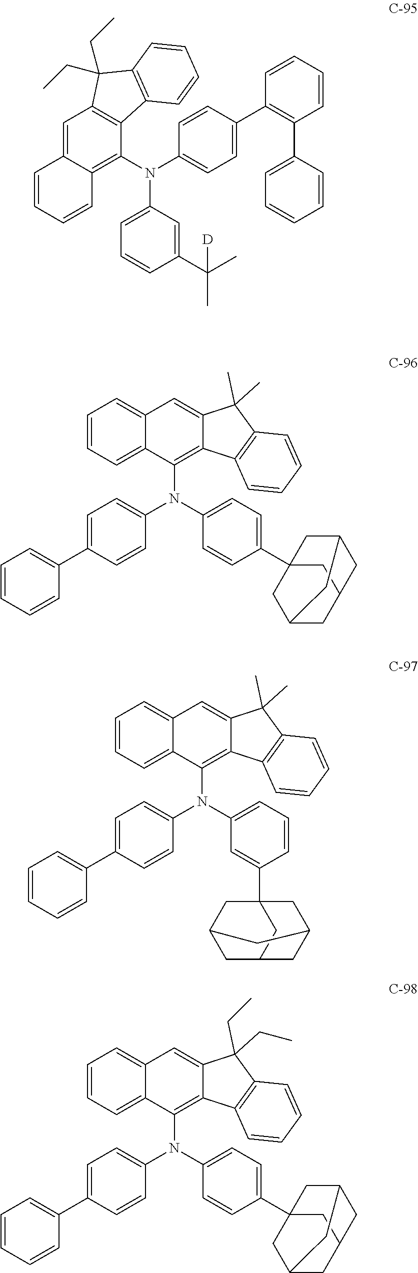

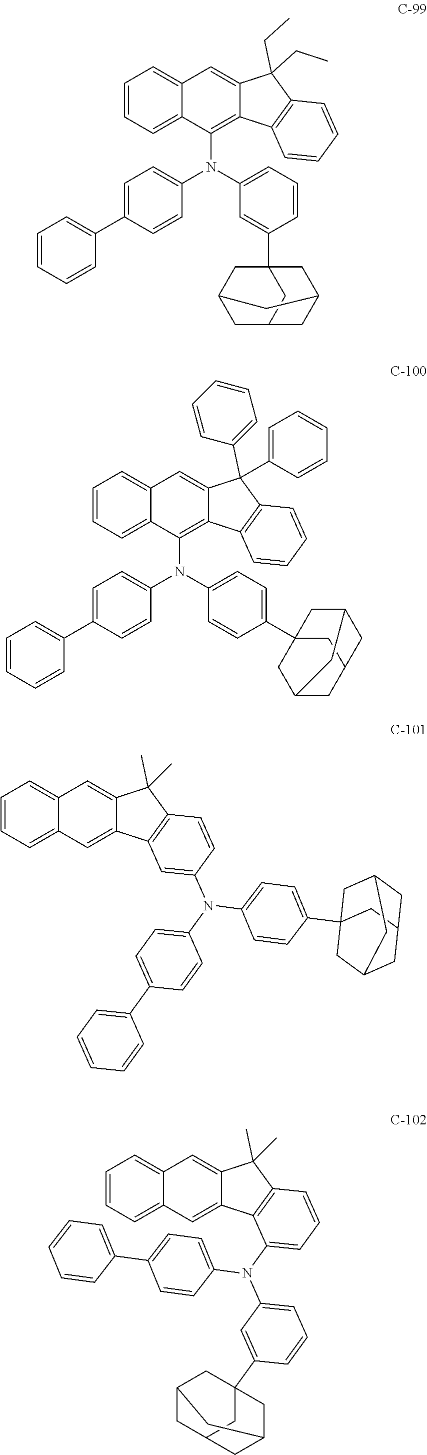 [SMILES: CCC1(CC)c2ccccc2-c2c1cc1ccccc1c2N(c1ccc(-c2ccccc2)cc1)c1cccc(C23CC4CC(CC(C4)C2)C3)c1 ; c1ccc(-c2ccc(N(c3ccc(C45CC6CC(CC(C6)C4)C5)cc3)c3c4c(cc5ccccc35)C(c3ccccc3)(c3ccccc3)c3ccccc3-4)cc2)cc1 ; CC1(C)c2ccc(N(c3ccc(-c4ccccc4)cc3)c3ccc(C45CC6CC(CC(C6)C4)C5)cc3)cc2-c2cc3ccccc3cc21 ; CC1(C)c2cc3ccccc3cc2-c2c(N(c3ccc(-c4ccccc4)cc3)c3cccc(C45CC6CC(CC(C6)C4)C5)c3)cccc21]

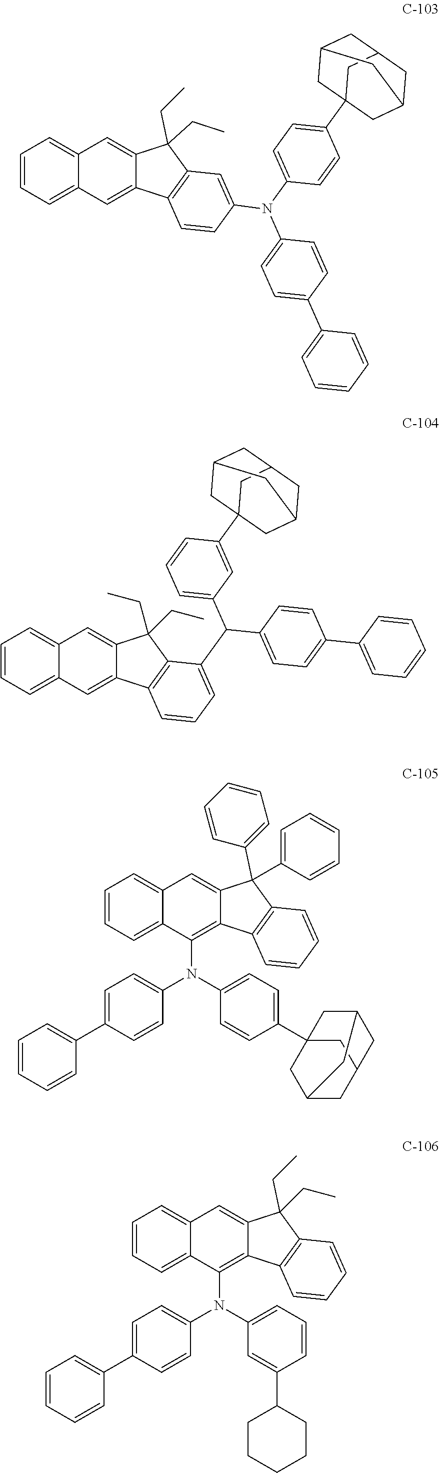

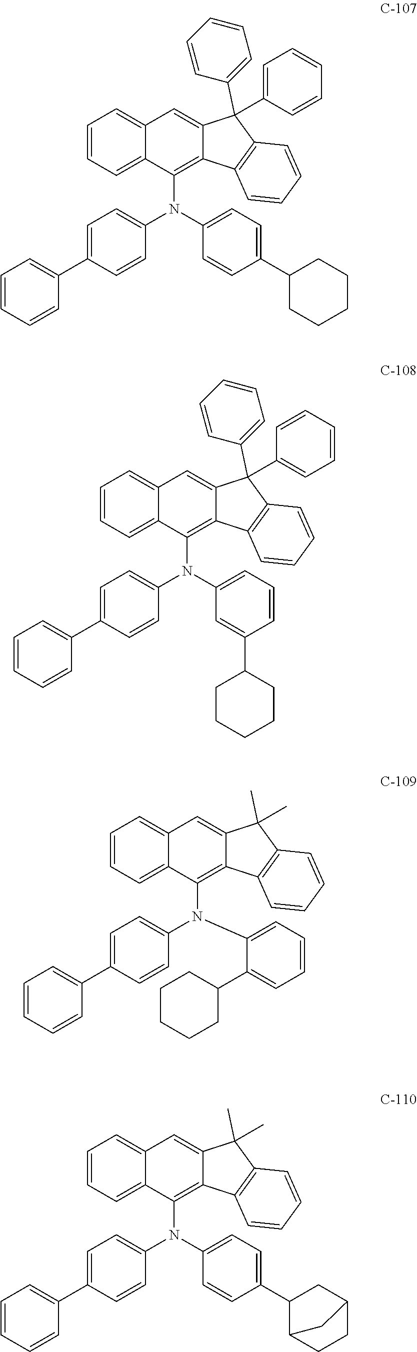 [SMILES: c1ccc(-c2ccc(N(c3ccc(C4CCCCC4)cc3)c3c4c(cc5ccccc35)C(c3ccccc3)(c3ccccc3)c3ccccc3-4)cc2)cc1 ; c1ccc(-c2ccc(N(c3cccc(C4CCCCC4)c3)c3c4c(cc5ccccc35)C(c3ccccc3)(c3ccccc3)c3ccccc3-4)cc2)cc1 ; CC1(C)c2ccccc2-c2c1cc1ccccc1c2N(c1ccc(-c2ccccc2)cc1)c1ccccc1C1CCCCC1 ; CC1(C)c2ccccc2-c2c1cc1ccccc1c2N(c1ccc(-c2ccccc2)cc1)c1ccc(C2CC3CCC2C3)cc1]

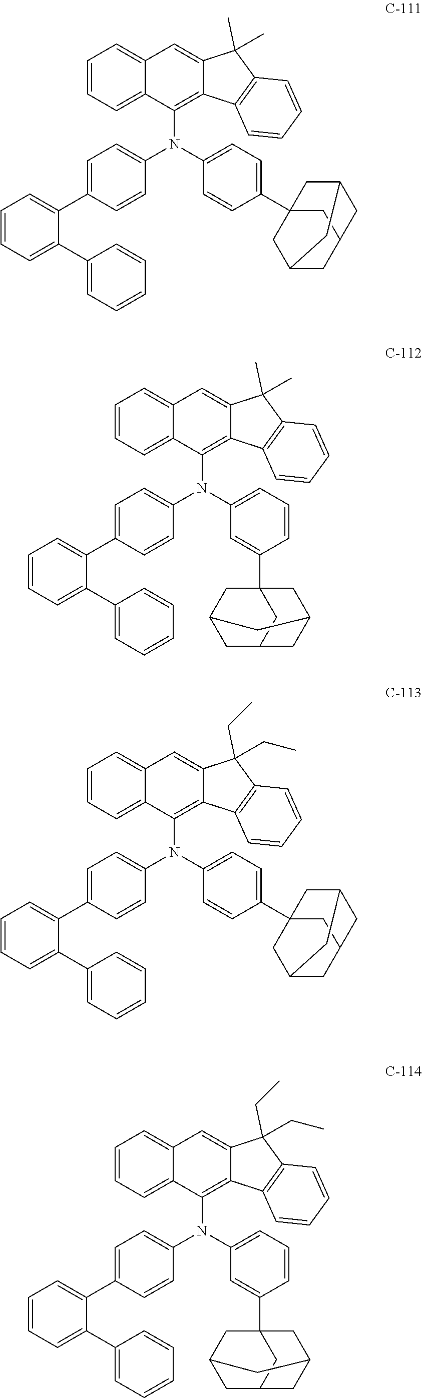 [SMILES: CC1(C)c2ccccc2-c2c1cc1ccccc1c2N(c1ccc(-c2ccccc2-c2ccccc2)cc1)c1ccc(C23CC4CC(CC(C4)C2)C3)cc1 ; CC1(C)c2ccccc2-c2c1cc1ccccc1c2N(c1ccc(-c2ccccc2-c2ccccc2)cc1)c1cccc(C23CC4CC(CC(C4)C2)C3)c1 ; CCC1(CC)c2ccccc2-c2c1cc1ccccc1c2N(c1ccc(-c2ccccc2-c2ccccc2)cc1)c1ccc(C23CC4CC(CC(C4)C2)C3)cc1 ; CCC1(CC)c2ccccc2-c2c1cc1ccccc1c2N(c1ccc(-c2ccccc2-c2ccccc2)cc1)c1cccc(C23CC4CC(CC(C4)C2)C3)c1]

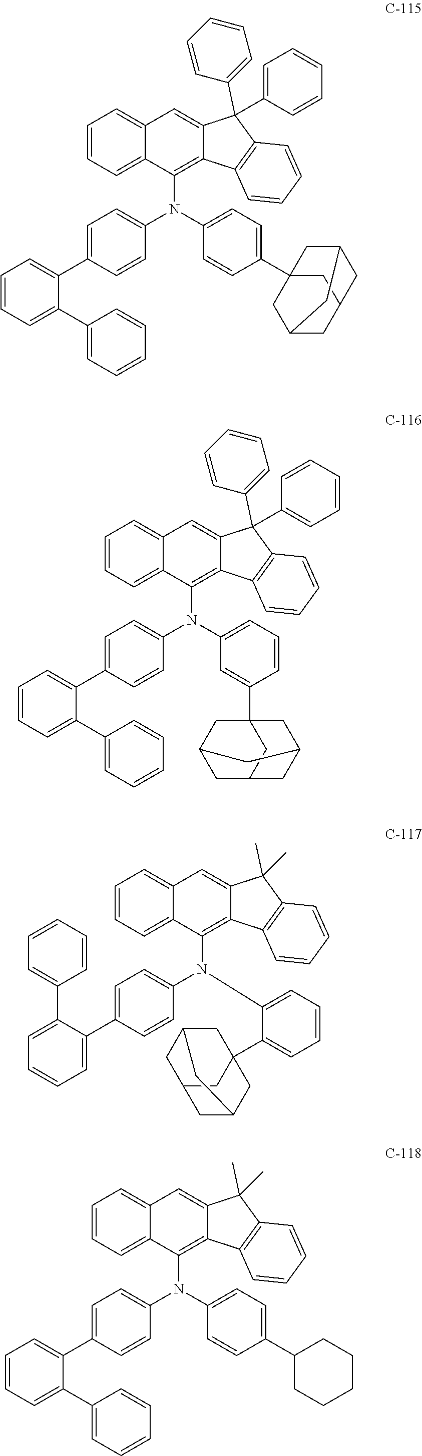 [SMILES: c1ccc(-c2ccccc2-c2ccc(N(c3ccc(C45CC6CC(CC(C6)C4)C5)cc3)c3c4c(cc5ccccc35)C(c3ccccc3)(c3ccccc3)c3ccccc3-4)cc2)cc1 ; c1ccc(-c2ccccc2-c2ccc(N(c3cccc(C45CC6CC(CC(C6)C4)C5)c3)c3c4c(cc5ccccc35)C(c3ccccc3)(c3ccccc3)c3ccccc3-4)cc2)cc1 ; CC1(C)c2ccccc2-c2c1cc1ccccc1c2N(c1ccc(-c2ccccc2-c2ccccc2)cc1)c1ccccc1C12CC3CC(CC(C3)C1)C2 ; CC1(C)c2ccccc2-c2c1cc1ccccc1c2N(c1ccc(-c2ccccc2-c2ccccc2)cc1)c1ccc(C2CCCCC2)cc1]

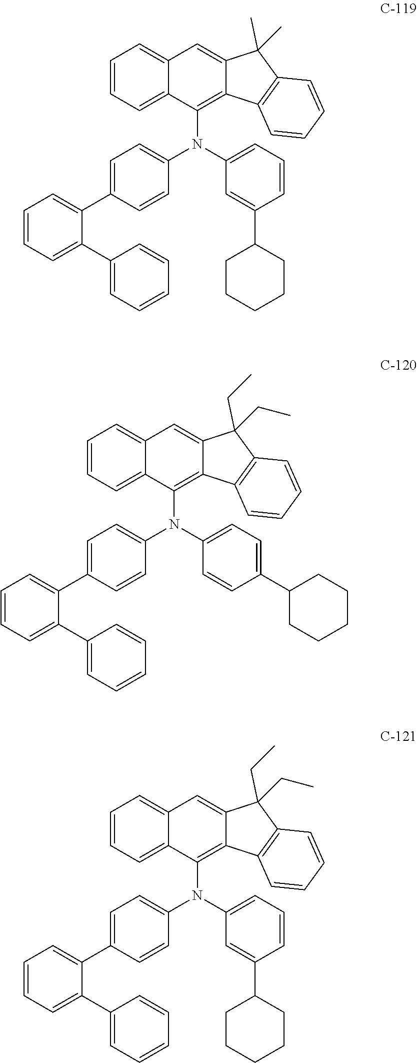 [SMILES: CC1(C)c2ccccc2-c2c1cc1ccccc1c2N(c1ccc(-c2ccccc2-c2ccccc2)cc1)c1cccc(C2CCCCC2)c1 ; CCC1(CC)c2ccccc2-c2c1cc1ccccc1c2N(c1ccc(-c2ccccc2-c2ccccc2)cc1)c1ccc(C2CCCCC2)cc1 ; CCC1(CC)c2ccccc2-c2c1cc1ccccc1c2N(c1ccc(-c2ccccc2-c2ccccc2)cc1)c1cccc(C2CCCCC2)c1]

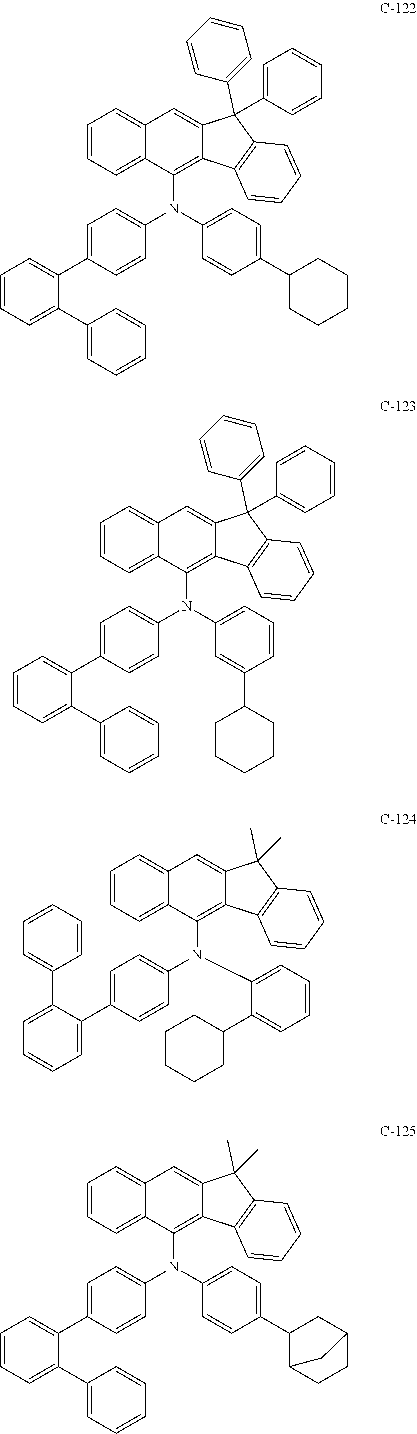 [SMILES: c1ccc(-c2ccccc2-c2ccc(N(c3ccc(C4CCCCC4)cc3)c3c4c(cc5ccccc35)C(c3ccccc3)(c3ccccc3)c3ccccc3-4)cc2)cc1 ; c1ccc(-c2ccccc2-c2ccc(N(c3cccc(C4CCCCC4)c3)c3c4c(cc5ccccc35)C(c3ccccc3)(c3ccccc3)c3ccccc3-4)cc2)cc1 ; CC1(C)c2ccccc2-c2c1cc1ccccc1c2N(c1ccc(-c2ccccc2-c2ccccc2)cc1)c1ccccc1C1CCCCC1 ; CC1(C)c2ccccc2-c2c1cc1ccccc1c2N(c1ccc(-c2ccccc2-c2ccccc2)cc1)c1ccc(C2CC3CCC2C3)cc1]

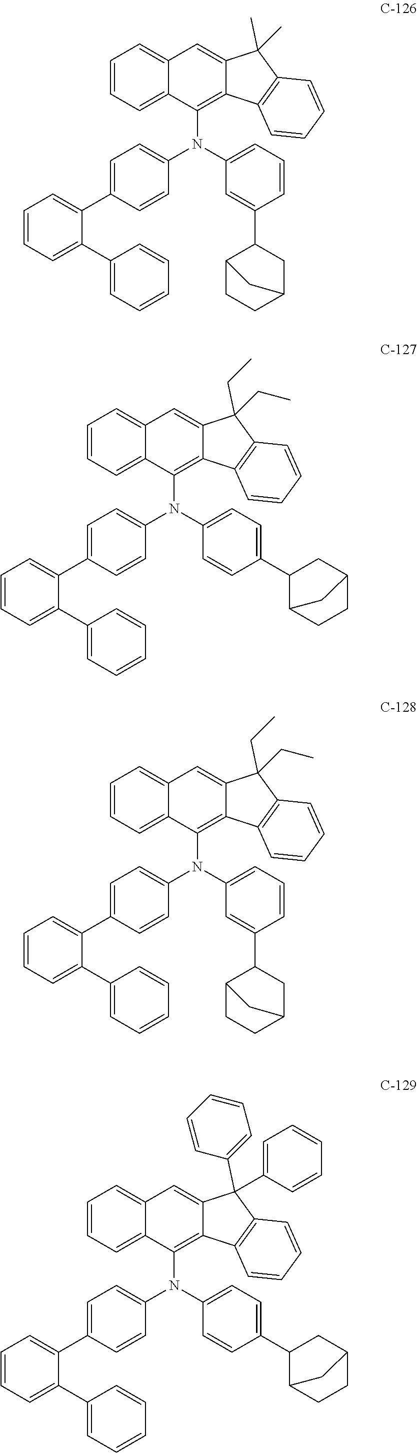 [SMILES: CC1(C)c2ccccc2-c2c1cc1ccccc1c2N(c1ccc(-c2ccccc2-c2ccccc2)cc1)c1cccc(C2CC3CCC2C3)c1 ; CCC1(CC)c2ccccc2-c2c1cc1ccccc1c2N(c1ccc(-c2ccccc2-c2ccccc2)cc1)c1ccc(C2CC3CCC2C3)cc1 ; CCC1(CC)c2ccccc2-c2c1cc1ccccc1c2N(c1ccc(-c2ccccc2-c2ccccc2)cc1)c1cccc(C2CC3CCC2C3)c1 ; c1ccc(-c2ccccc2-c2ccc(N(c3ccc(C4CC5CCC4C5)cc3)c3c4c(cc5ccccc35)C(c3ccccc3)(c3ccccc3)c3ccccc3-4)cc2)cc1]

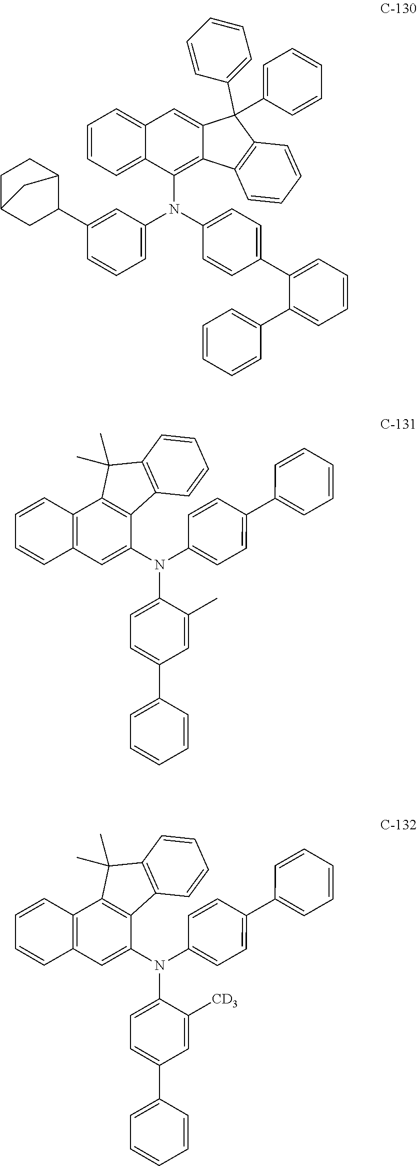 [SMILES: c1ccc(-c2ccccc2-c2ccc(N(c3cccc(C4CC5CCC4C5)c3)c3c4c(cc5ccccc35)C(c3ccccc3)(c3ccccc3)c3ccccc3-4)cc2)cc1 ; Cc1cc(-c2ccccc2)ccc1N(c1ccc(-c2ccccc2)cc1)c1cc2ccccc2c2c1-c1ccccc1C2(C)C ; [2H]C([2H])([2H])c1cc(-c2ccccc2)ccc1N(c1ccc(-c2ccccc2)cc1)c1cc2ccccc2c2c1-c1ccccc1C2(C)C]

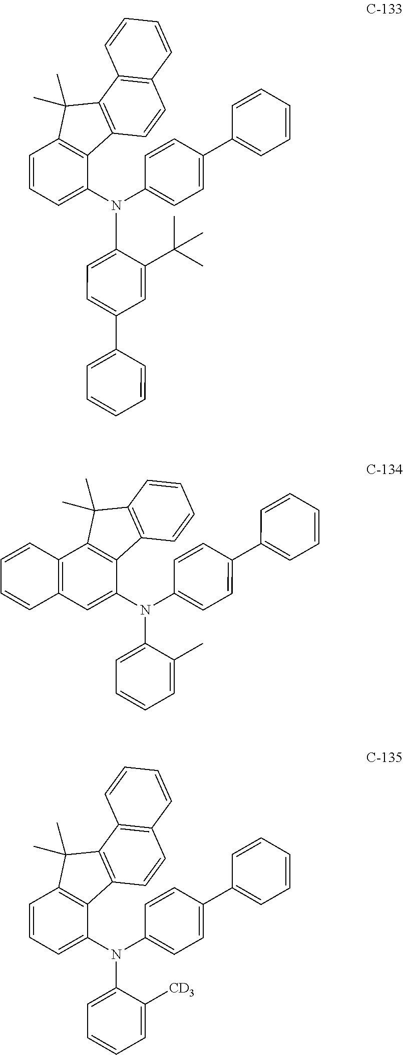 [SMILES: CC(C)(C)c1cc(-c2ccccc2)ccc1N(c1ccc(-c2ccccc2)cc1)c1cccc2c1-c1ccc3ccccc3c1C2(C)C ; Cc1ccccc1N(c1ccc(-c2ccccc2)cc1)c1cc2ccccc2c2c1-c1ccccc1C2(C)C ; [2H]C([2H])([2H])c1ccccc1N(c1ccc(-c2ccccc2)cc1)c1cccc2c1-c1ccc3ccccc3c1C2(C)C]

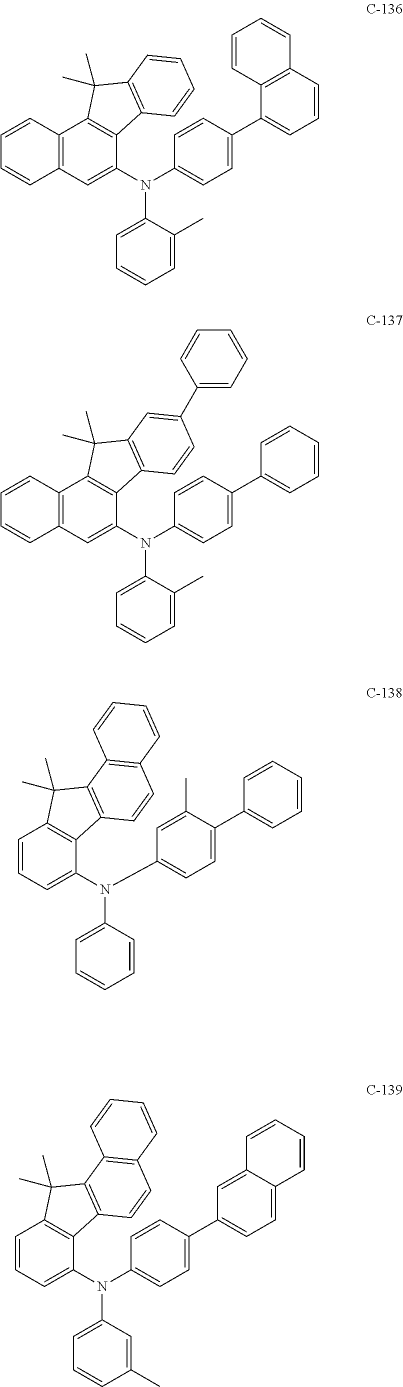 [SMILES: Cc1ccccc1N(c1ccc(-c2cccc3ccccc23)cc1)c1cc2ccccc2c2c1-c1ccccc1C2(C)C ; Cc1ccccc1N(c1ccc(-c2ccccc2)cc1)c1cc2ccccc2c2c1-c1ccc(-c3ccccc3)cc1C2(C)C ; Cc1cc(N(c2ccccc2)c2cccc3c2-c2ccc4ccccc4c2C3(C)C)ccc1-c1ccccc1 ; Cc1cccc(N(c2ccc(-c3ccc4ccccc4c3)cc2)c2cccc3c2-c2ccc4ccccc4c2C3(C)C)c1]

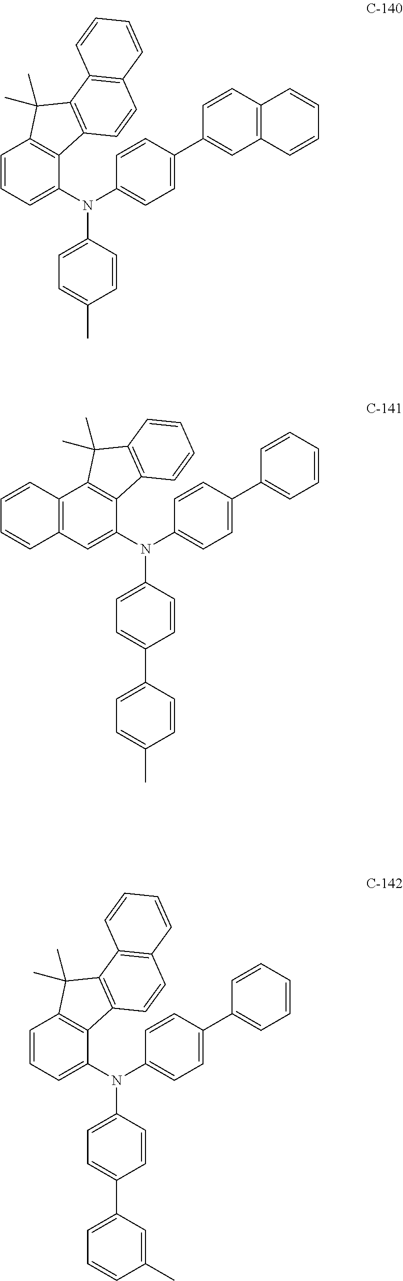 [SMILES: Cc1ccc(N(c2ccc(-c3ccc4ccccc4c3)cc2)c2cccc3c2-c2ccc4ccccc4c2C3(C)C)cc1 ; Cc1ccc(-c2ccc(N(c3ccc(-c4ccccc4)cc3)c3cc4ccccc4c4c3-c3ccccc3C4(C)C)cc2)cc1 ; Cc1cccc(-c2ccc(N(c3ccc(-c4ccccc4)cc3)c3cccc4c3-c3ccc5ccccc5c3C4(C)C)cc2)c1]

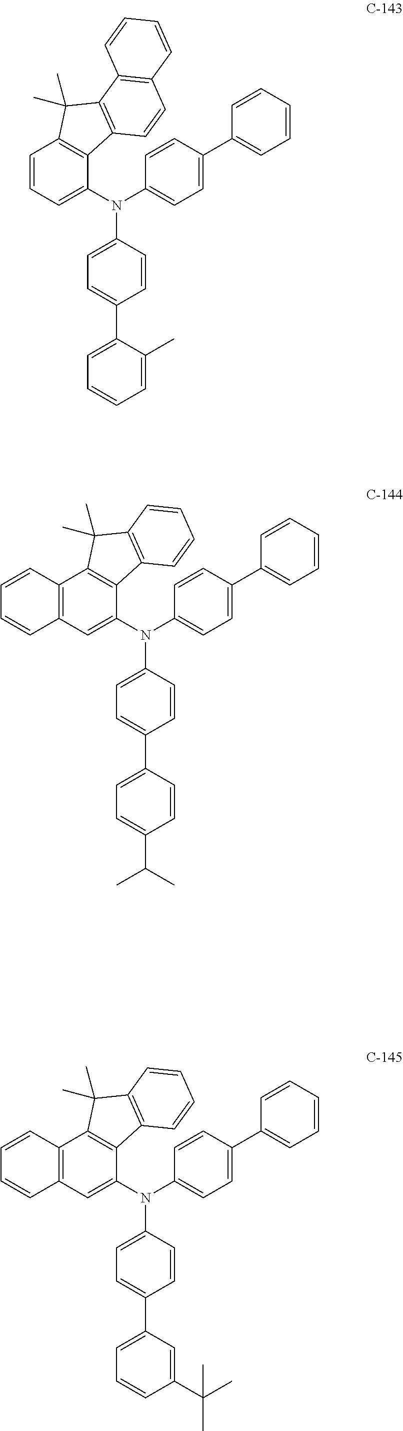 [SMILES: Cc1ccccc1-c1ccc(N(c2ccc(-c3ccccc3)cc2)c2cccc3c2-c2ccc4ccccc4c2C3(C)C)cc1 ; CC(C)c1ccc(-c2ccc(N(c3ccc(-c4ccccc4)cc3)c3cc4ccccc4c4c3-c3ccccc3C4(C)C)cc2)cc1 ; CC(C)(C)c1cccc(-c2ccc(N(c3ccc(-c4ccccc4)cc3)c3cc4ccccc4c4c3-c3ccccc3C4(C)C)cc2)c1]

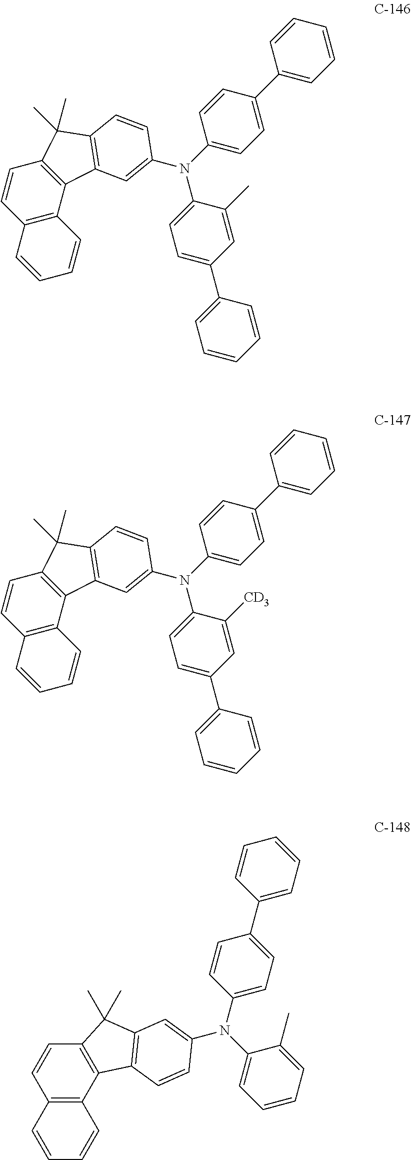 [SMILES: Cc1cc(-c2ccccc2)ccc1N(c1ccc(-c2ccccc2)cc1)c1ccc2c(c1)-c1c(ccc3ccccc13)C2(C)C ; [2H]C([2H])([2H])c1cc(-c2ccccc2)ccc1N(c1ccc(-c2ccccc2)cc1)c1ccc2c(c1)-c1c(ccc3ccccc13)C2(C)C ; Cc1ccccc1N(c1ccc(-c2ccccc2)cc1)c1ccc2c(c1)C(C)(C)c1ccc3ccccc3c1-2]

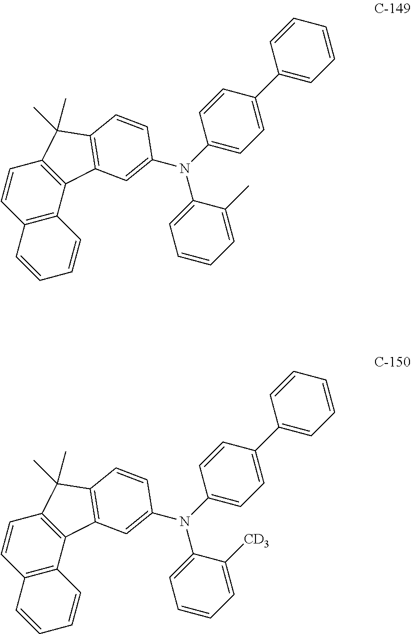 [SMILES: Cc1ccccc1N(c1ccc(-c2ccccc2)cc1)c1ccc2c(c1)-c1c(ccc3ccccc13)C2(C)C ; [2H]C([2H])([2H])c1ccccc1N(c1ccc(-c2ccccc2)cc1)c1ccc2c(c1)-c1c(ccc3ccccc13)C2(C)C]

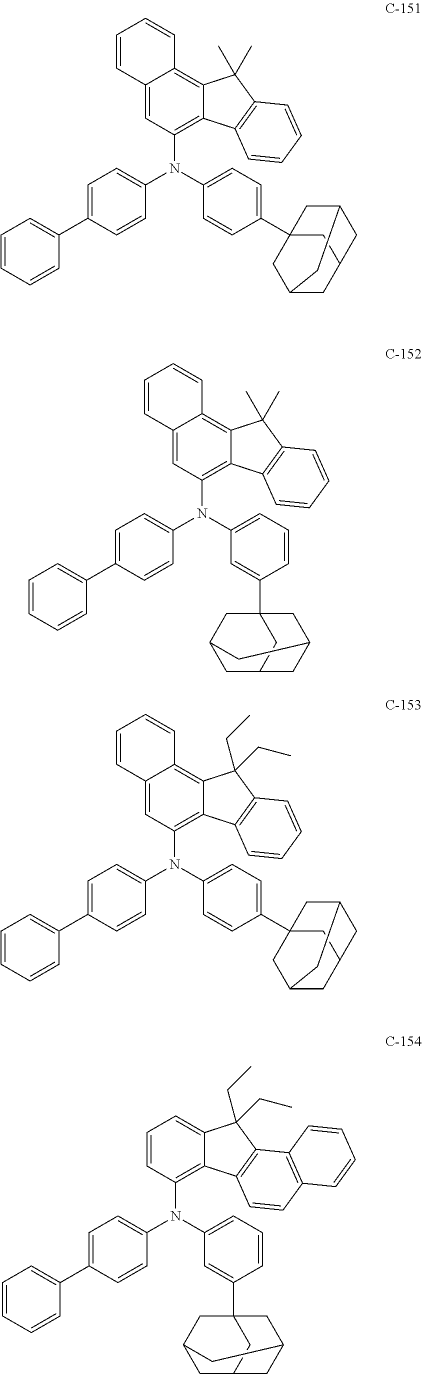

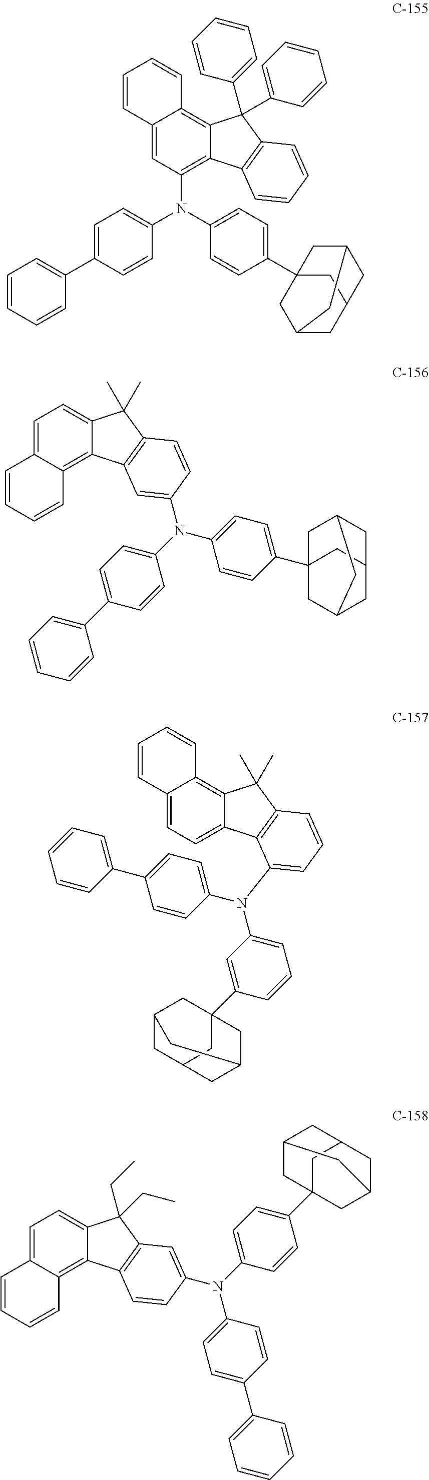 [SMILES: c1ccc(-c2ccc(N(c3ccc(C45CC6CC(CC(C6)C4)C5)cc3)c3cc4ccccc4c4c3-c3ccccc3C4(c3ccccc3)c3ccccc3)cc2)cc1 ; CC1(C)c2ccc(N(c3ccc(-c4ccccc4)cc3)c3ccc(C45CC6CC(CC(C6)C4)C5)cc3)cc2-c2c1ccc1ccccc21 ; CC1(C)c2cccc(N(c3ccc(-c4ccccc4)cc3)c3cccc(C45CC6CC(CC(C6)C4)C5)c3)c2-c2ccc3ccccc3c21 ; CCC1(CC)c2cc(N(c3ccc(-c4ccccc4)cc3)c3ccc(C45CC6CC(CC(C6)C4)C5)cc3)ccc2-c2c1ccc1ccccc21]

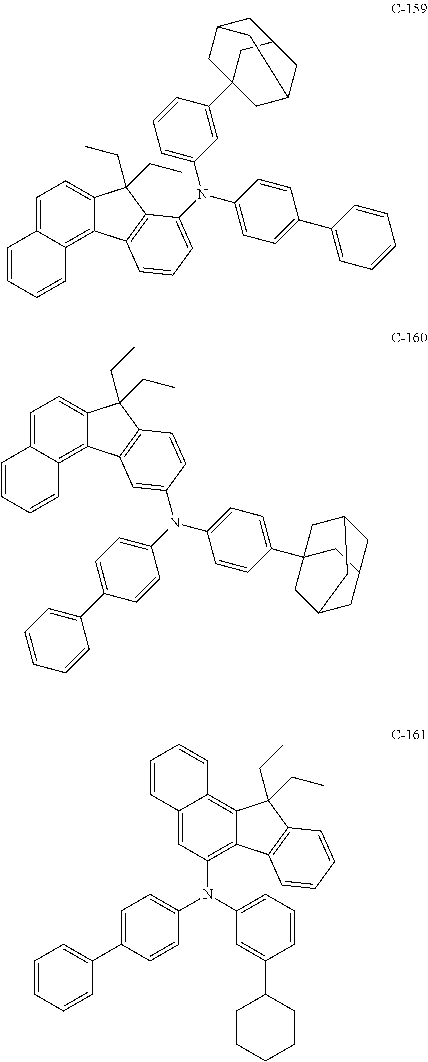 [SMILES: CCC1(CC)c2ccc3ccccc3c2-c2cccc(N(c3ccc(-c4ccccc4)cc3)c3cccc(C45CC6CC(CC(C6)C4)C5)c3)c21 ; CCC1(CC)c2ccc(N(c3ccc(-c4ccccc4)cc3)c3ccc(C45CC6CC(CC(C6)C4)C5)cc3)cc2-c2c1ccc1ccccc21 ; CCC1(CC)c2ccccc2-c2c(N(c3ccc(-c4ccccc4)cc3)c3cccc(C4CCCCC4)c3)cc3ccccc3c21]

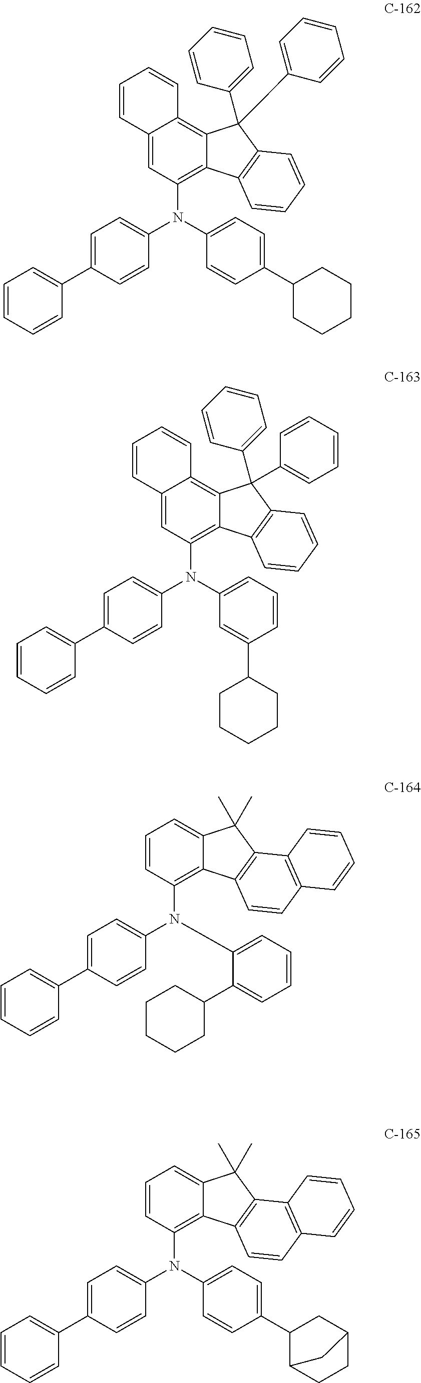 [SMILES: c1ccc(-c2ccc(N(c3ccc(C4CCCCC4)cc3)c3cc4ccccc4c4c3-c3ccccc3C4(c3ccccc3)c3ccccc3)cc2)cc1 ; c1ccc(-c2ccc(N(c3cccc(C4CCCCC4)c3)c3cc4ccccc4c4c3-c3ccccc3C4(c3ccccc3)c3ccccc3)cc2)cc1 ; CC1(C)c2cccc(N(c3ccc(-c4ccccc4)cc3)c3ccccc3C3CCCCC3)c2-c2ccc3ccccc3c21 ; CC1(C)c2cccc(N(c3ccc(-c4ccccc4)cc3)c3ccc(C4CC5CCC4C5)cc3)c2-c2ccc3ccccc3c21]

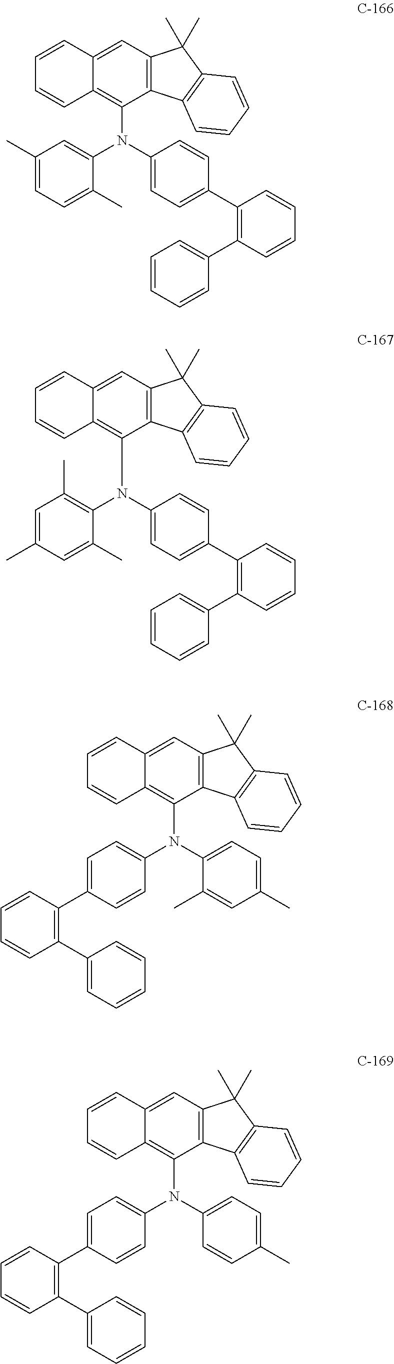

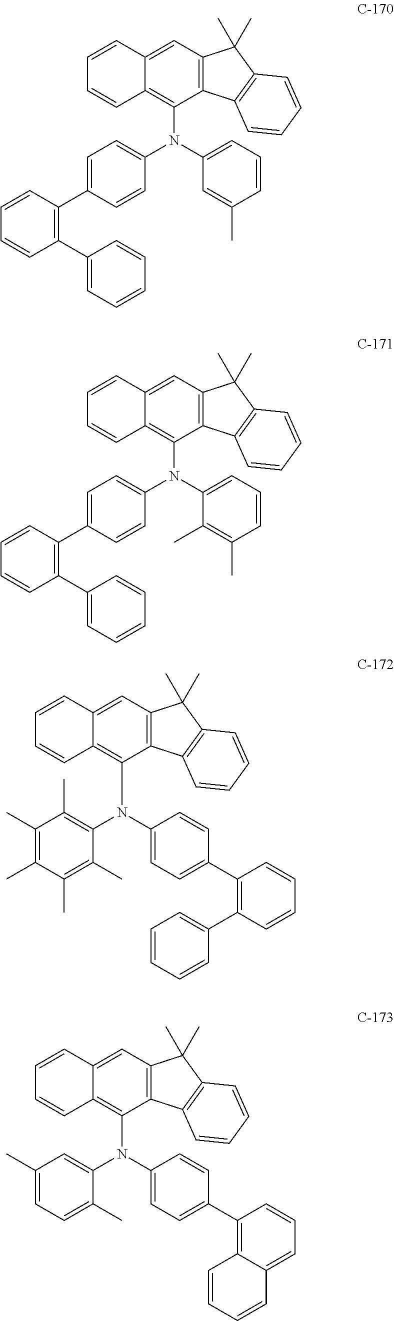 [SMILES: Cc1cccc(N(c2ccc(-c3ccccc3-c3ccccc3)cc2)c2c3c(cc4ccccc24)C(C)(C)c2ccccc2-3)c1 ; Cc1cccc(N(c2ccc(-c3ccccc3-c3ccccc3)cc2)c2c3c(cc4ccccc24)C(C)(C)c2ccccc2-3)c1C ; Cc1c(C)c(C)c(N(c2ccc(-c3ccccc3-c3ccccc3)cc2)c2c3c(cc4ccccc24)C(C)(C)c2ccccc2-3)c(C)c1C ; Cc1ccc(C)c(N(c2ccc(-c3cccc4ccccc34)cc2)c2c3c(cc4ccccc24)C(C)(C)c2ccccc2-3)c1]

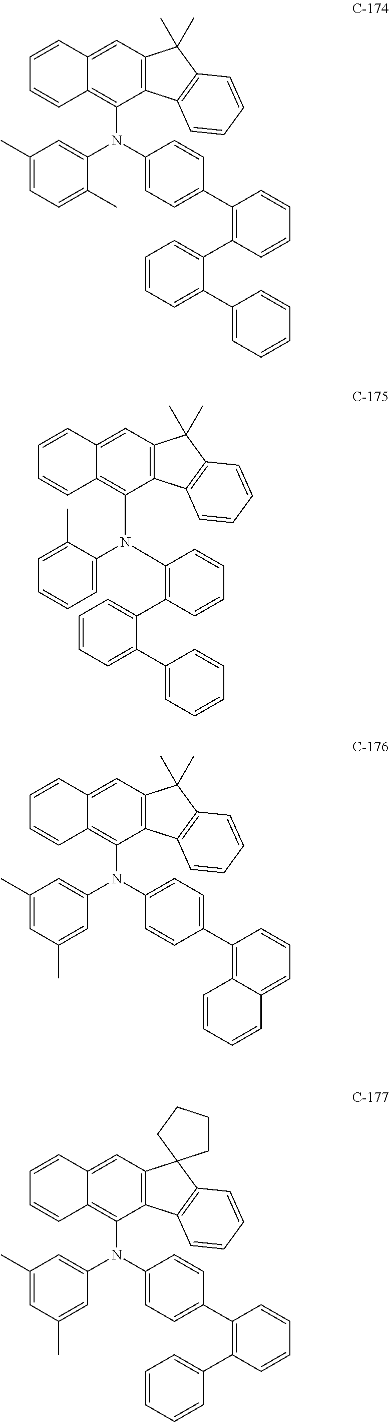

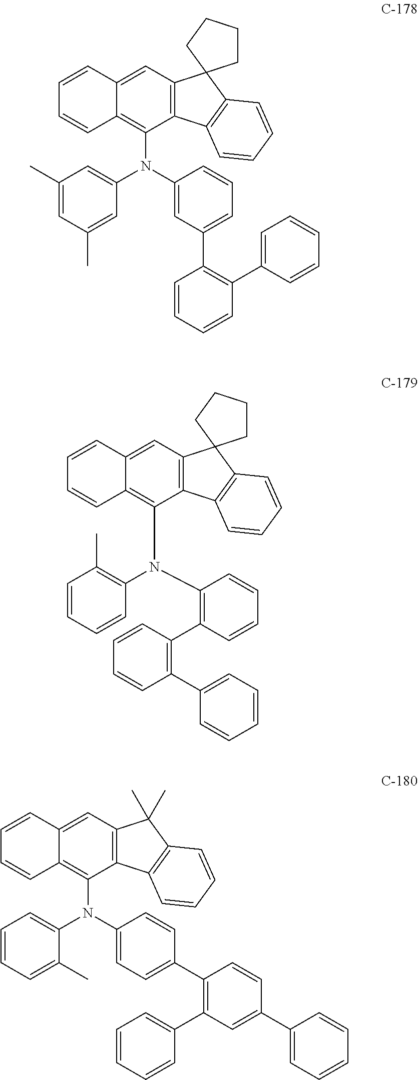 [SMILES: Cc1cc(C)cc(N(c2cccc(-c3ccccc3-c3ccccc3)c2)c2c3c(cc4ccccc24)C2(CCCC2)c2ccccc2-3)c1 ; Cc1ccccc1N(c1ccccc1-c1ccccc1-c1ccccc1)c1c2c(cc3ccccc13)C1(CCCC1)c1ccccc1-2 ; Cc1ccccc1N(c1ccc(-c2ccc(-c3ccccc3)cc2-c2ccccc2)cc1)c1c2c(cc3ccccc13)C(C)(C)c1ccccc1-2]

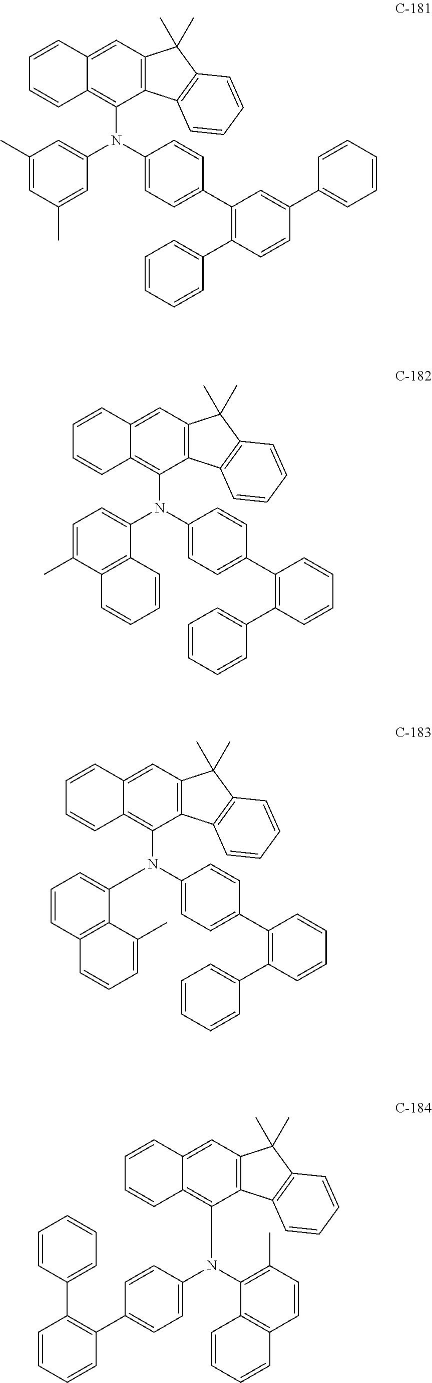 [SMILES: Cc1cc(C)cc(N(c2ccc(-c3cc(-c4ccccc4)ccc3-c3ccccc3)cc2)c2c3c(cc4ccccc24)C(C)(C)c2ccccc2-3)c1 ; Cc1ccc(N(c2ccc(-c3ccccc3-c3ccccc3)cc2)c2c3c(cc4ccccc24)C(C)(C)c2ccccc2-3)c2ccccc12 ; Cc1cccc2cccc(N(c3ccc(-c4ccccc4-c4ccccc4)cc3)c3c4c(cc5ccccc35)C(C)(C)c3ccccc3-4)c12 ; Cc1ccc2ccccc2c1N(c1ccc(-c2ccccc2-c2ccccc2)cc1)c1c2c(cc3ccccc13)C(C)(C)c1ccccc1-2]

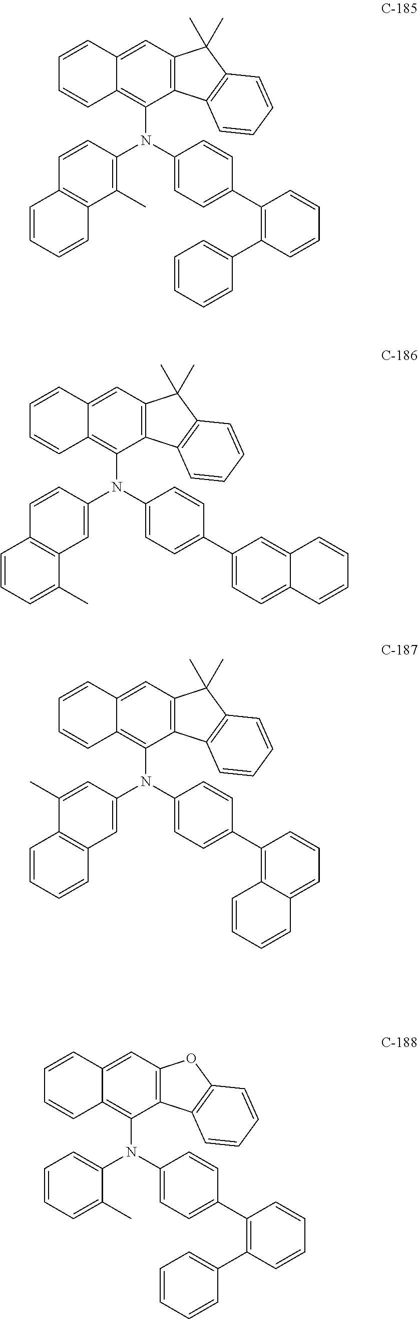 [SMILES: Cc1c(N(c2ccc(-c3ccccc3-c3ccccc3)cc2)c2c3c(cc4ccccc24)C(C)(C)c2ccccc2-3)ccc2ccccc12 ; Cc1cccc2ccc(N(c3ccc(-c4ccc5ccccc5c4)cc3)c3c4c(cc5ccccc35)C(C)(C)c3ccccc3-4)cc12 ; Cc1cc(N(c2ccc(-c3cccc4ccccc34)cc2)c2c3c(cc4ccccc24)C(C)(C)c2ccccc2-3)cc2ccccc12 ; Cc1ccccc1N(c1ccc(-c2ccccc2-c2ccccc2)cc1)c1c2ccccc2cc2oc3ccccc3c12]

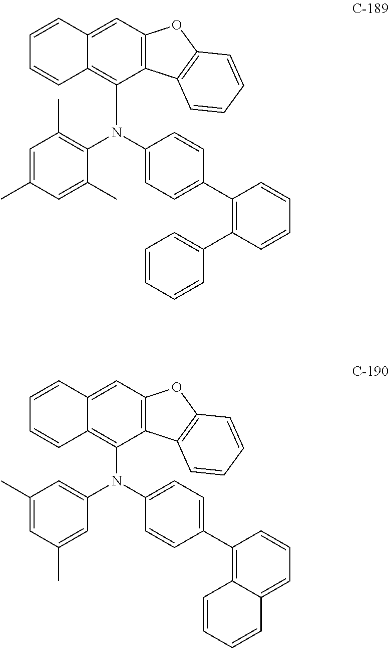 [SMILES: Cc1cc(C)c(N(c2ccc(-c3ccccc3-c3ccccc3)cc2)c2c3ccccc3cc3oc4ccccc4c23)c(C)c1 ; Cc1cc(C)cc(N(c2ccc(-c3cccc4ccccc34)cc2)c2c3ccccc3cc3oc4ccccc4c23)c1]

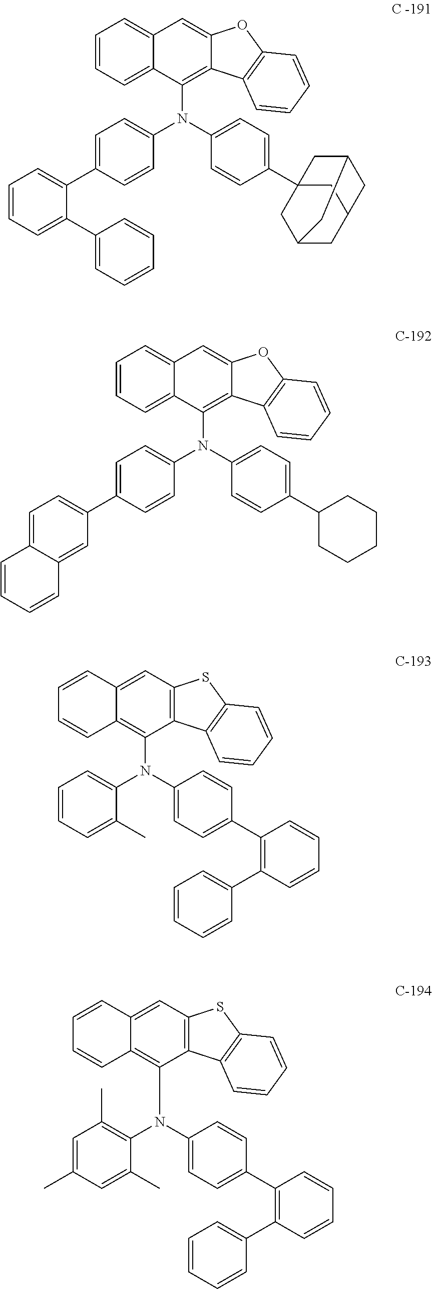 [SMILES: c1ccc(-c2ccccc2-c2ccc(N(c3ccc(C45CC6CC(CC(C6)C4)C5)cc3)c3c4ccccc4cc4oc5ccccc5c34)cc2)cc1 ; c1ccc2cc(-c3ccc(N(c4ccc(C5CCCCC5)cc4)c4c5ccccc5cc5oc6ccccc6c45)cc3)ccc2c1 ; Cc1ccccc1N(c1ccc(-c2ccccc2-c2ccccc2)cc1)c1c2ccccc2cc2sc3ccccc3c12 ; Cc1cc(C)c(N(c2ccc(-c3ccccc3-c3ccccc3)cc2)c2c3ccccc3cc3sc4ccccc4c23)c(C)c1]

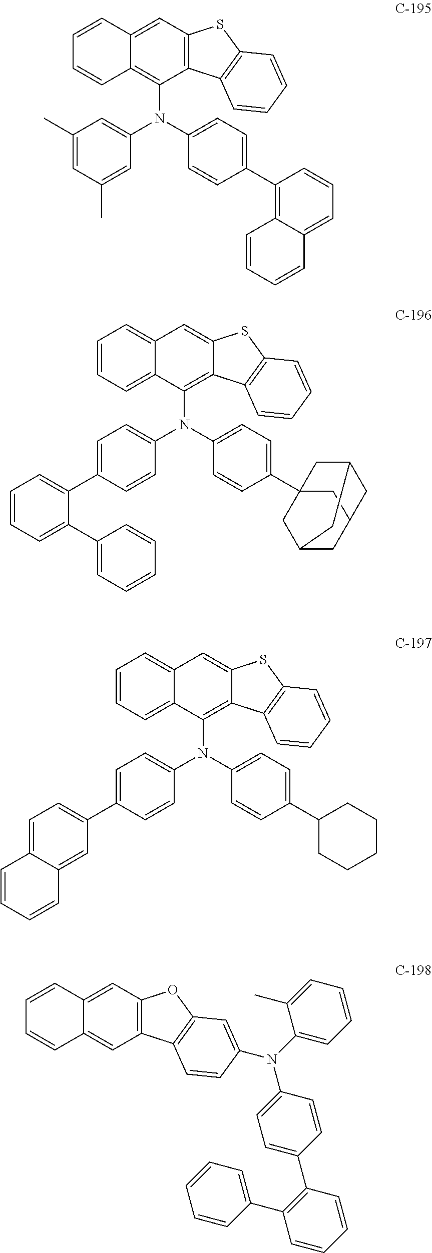 [SMILES: Cc1cc(C)cc(N(c2ccc(-c3cccc4ccccc34)cc2)c2c3ccccc3cc3sc4ccccc4c23)c1 ; c1ccc(-c2ccccc2-c2ccc(N(c3ccc(C45CC6CC(CC(C6)C4)C5)cc3)c3c4ccccc4cc4sc5ccccc5c34)cc2)cc1 ; c1ccc2cc(-c3ccc(N(c4ccc(C5CCCCC5)cc4)c4c5ccccc5cc5sc6ccccc6c45)cc3)ccc2c1 ; Cc1ccccc1N(c1ccc(-c2ccccc2-c2ccccc2)cc1)c1ccc2c(c1)oc1cc3ccccc3cc12]

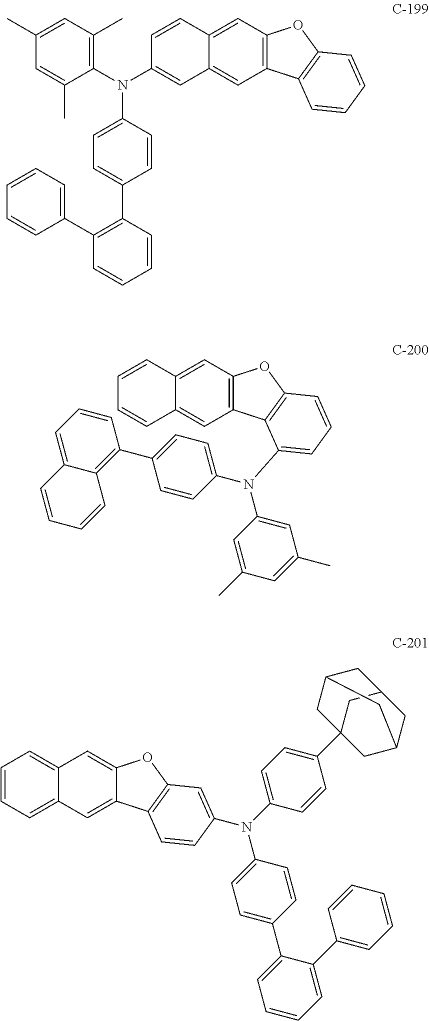 [SMILES: Cc1cc(C)c(N(c2ccc(-c3ccccc3-c3ccccc3)cc2)c2ccc3cc4oc5ccccc5c4cc3c2)c(C)c1 ; Cc1cc(C)cc(N(c2ccc(-c3cccc4ccccc34)cc2)c2cccc3oc4cc5ccccc5cc4c23)c1 ; c1ccc(-c2ccccc2-c2ccc(N(c3ccc(C45CC6CC(CC(C6)C4)C5)cc3)c3ccc4c(c3)oc3cc5ccccc5cc34)cc2)cc1]

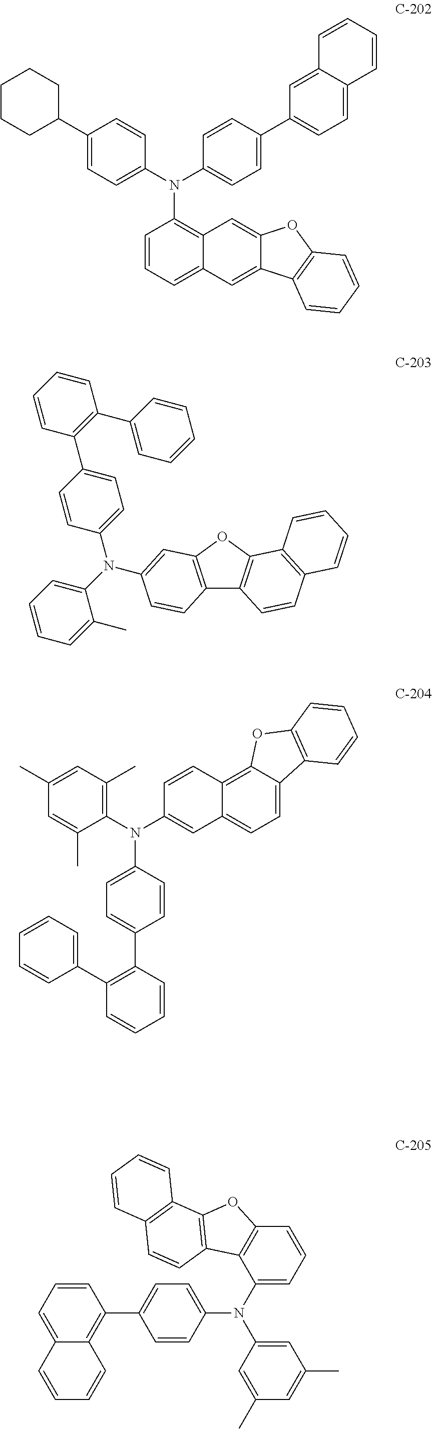 [SMILES: c1ccc2cc(-c3ccc(N(c4ccc(C5CCCCC5)cc4)c4cccc5cc6c(cc45)oc4ccccc46)cc3)ccc2c1 ; Cc1ccccc1N(c1ccc(-c2ccccc2-c2ccccc2)cc1)c1ccc2c(c1)oc1c3ccccc3ccc21 ; Cc1cc(C)c(N(c2ccc(-c3ccccc3-c3ccccc3)cc2)c2ccc3c(ccc4c5ccccc5oc34)c2)c(C)c1 ; Cc1cc(C)cc(N(c2ccc(-c3cccc4ccccc34)cc2)c2cccc3oc4c5ccccc5ccc4c23)c1]

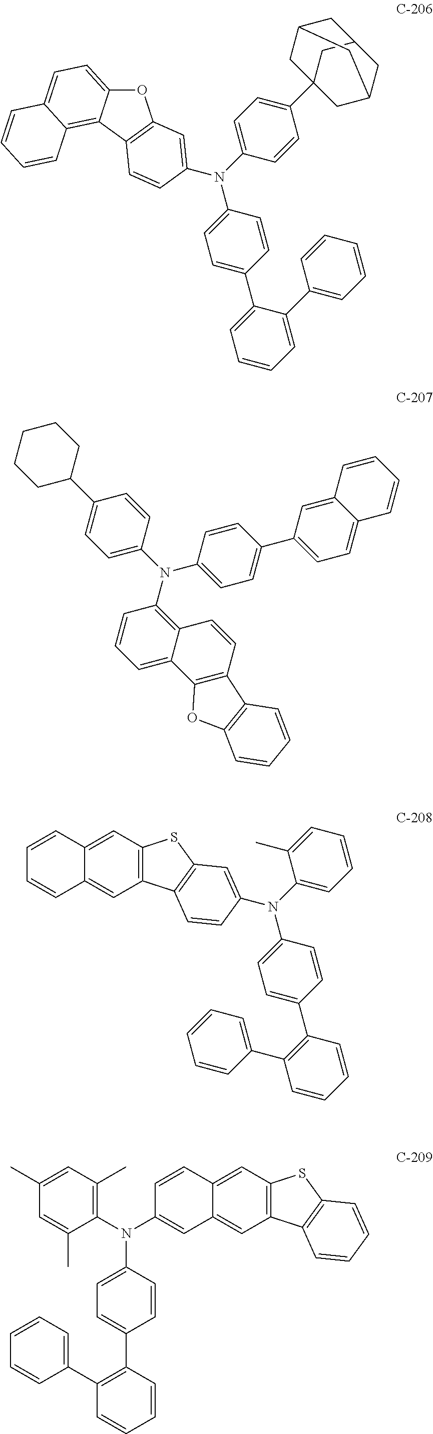 [SMILES: c1ccc(-c2ccccc2-c2ccc(N(c3ccc(C45CC6CC(CC(C6)C4)C5)cc3)c3ccc4c(c3)oc3ccc5ccccc5c34)cc2)cc1 ; c1ccc2cc(-c3ccc(N(c4ccc(C5CCCCC5)cc4)c4cccc5c4ccc4c6ccccc6oc54)cc3)ccc2c1 ; Cc1ccccc1N(c1ccc(-c2ccccc2-c2ccccc2)cc1)c1ccc2c(c1)sc1cc3ccccc3cc12 ; Cc1cc(C)c(N(c2ccc(-c3ccccc3-c3ccccc3)cc2)c2ccc3cc4sc5ccccc5c4cc3c2)c(C)c1]

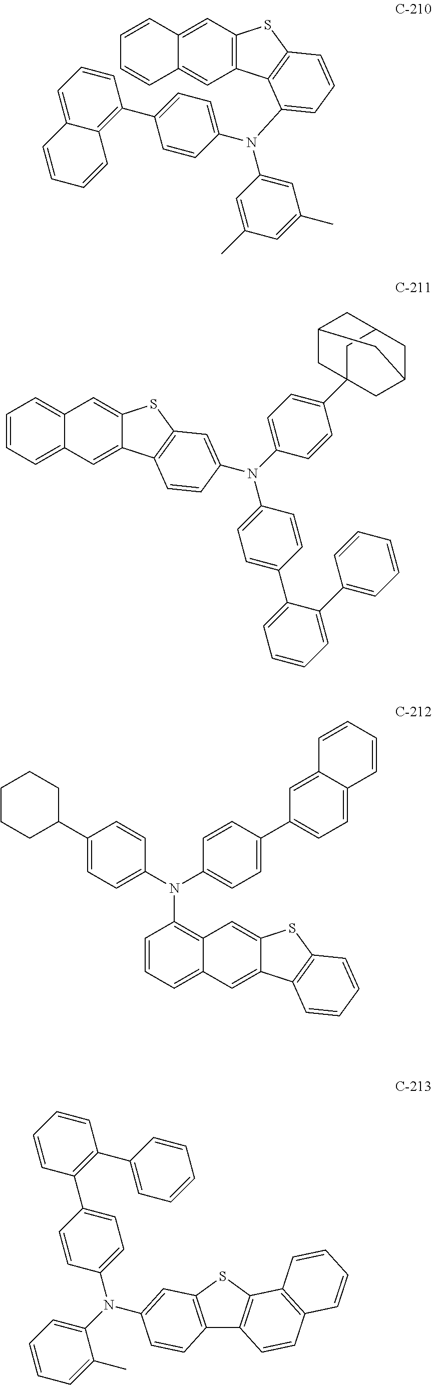 [SMILES: Cc1cc(C)cc(N(c2ccc(-c3cccc4ccccc34)cc2)c2cccc3sc4cc5ccccc5cc4c23)c1 ; c1ccc(-c2ccccc2-c2ccc(N(c3ccc(C45CC6CC(CC(C6)C4)C5)cc3)c3ccc4c(c3)sc3cc5ccccc5cc34)cc2)cc1 ; c1ccc2cc(-c3ccc(N(c4ccc(C5CCCCC5)cc4)c4cccc5cc6c(cc45)sc4ccccc46)cc3)ccc2c1 ; Cc1ccccc1N(c1ccc(-c2ccccc2-c2ccccc2)cc1)c1ccc2c(c1)sc1c3ccccc3ccc21]

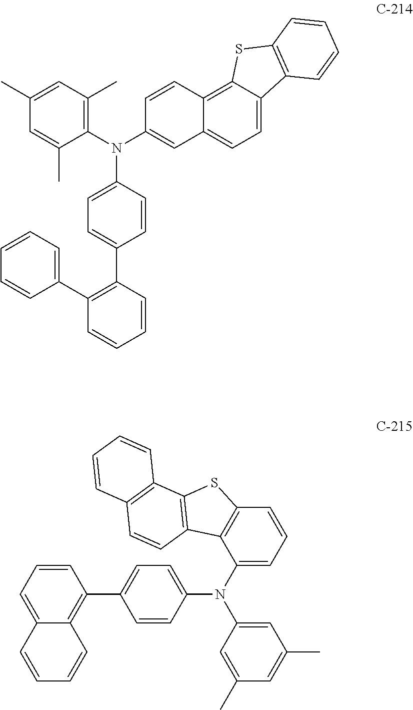 [SMILES: Cc1cc(C)c(N(c2ccc(-c3ccccc3-c3ccccc3)cc2)c2ccc3c(ccc4c5ccccc5sc34)c2)c(C)c1 ; Cc1cc(C)cc(N(c2ccc(-c3cccc4ccccc34)cc2)c2cccc3sc4c5ccccc5ccc4c23)c1]

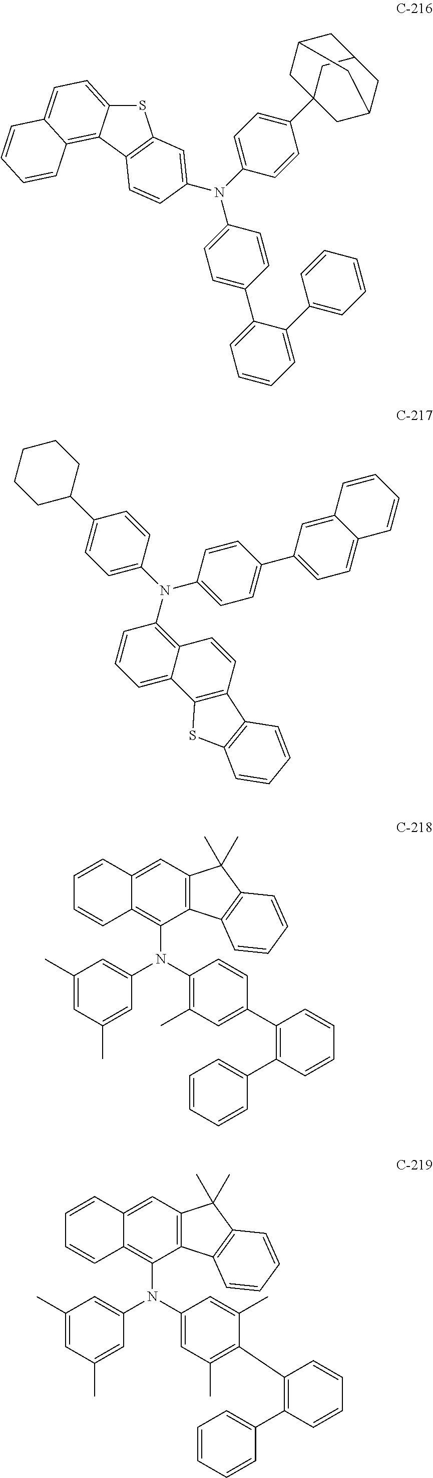 [SMILES: c1ccc(-c2ccccc2-c2ccc(N(c3ccc(C45CC6CC(CC(C6)C4)C5)cc3)c3ccc4c(c3)sc3ccc5ccccc5c34)cc2)cc1 ; c1ccc2cc(-c3ccc(N(c4ccc(C5CCCCC5)cc4)c4cccc5c4ccc4c6ccccc6sc54)cc3)ccc2c1 ; Cc1cc(C)cc(N(c2ccc(-c3ccccc3-c3ccccc3)cc2C)c2c3c(cc4ccccc24)C(C)(C)c2ccccc2-3)c1 ; Cc1cc(C)cc(N(c2cc(C)c(-c3ccccc3-c3ccccc3)c(C)c2)c2c3c(cc4ccccc24)C(C)(C)c2ccccc2-3)c1]

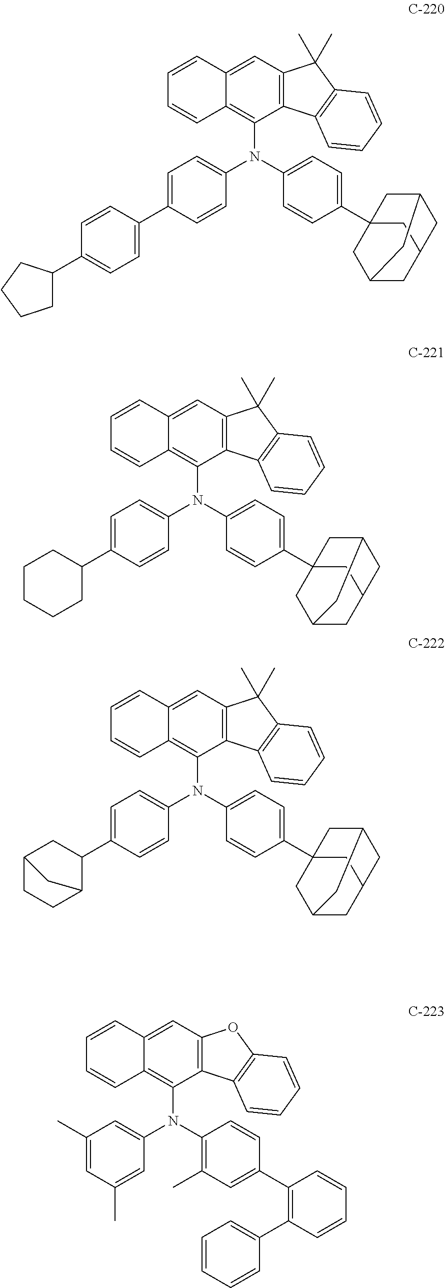 [SMILES: CC1(C)c2ccccc2-c2c1cc1ccccc1c2N(c1ccc(-c2ccc(C3CCCC3)cc2)cc1)c1ccc(C23CC4CC(CC(C4)C2)C3)cc1 ; CC1(C)c2ccccc2-c2c1cc1ccccc1c2N(c1ccc(C2CCCCC2)cc1)c1ccc(C23CC4CC(CC(C4)C2)C3)cc1 ; CC1(C)c2ccccc2-c2c1cc1ccccc1c2N(c1ccc(C2CC3CCC2C3)cc1)c1ccc(C23CC4CC(CC(C4)C2)C3)cc1 ; Cc1cc(C)cc(N(c2ccc(-c3ccccc3-c3ccccc3)cc2C)c2c3ccccc3cc3oc4ccccc4c23)c1]

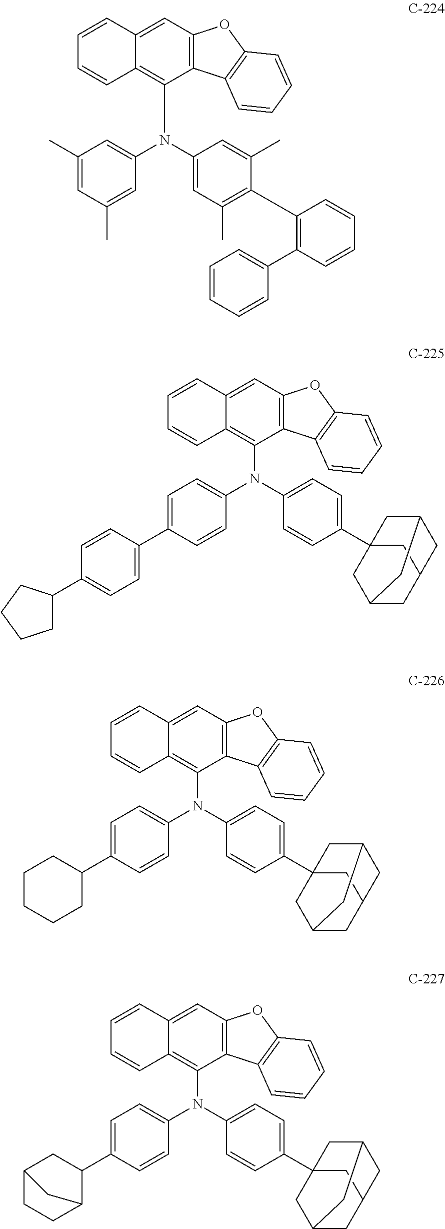 [SMILES: Cc1cc(C)cc(N(c2cc(C)c(-c3ccccc3-c3ccccc3)c(C)c2)c2c3ccccc3cc3oc4ccccc4c23)c1 ; c1ccc2c(N(c3ccc(-c4ccc(C5CCCC5)cc4)cc3)c3ccc(C45CC6CC(CC(C6)C4)C5)cc3)c3c(cc2c1)oc1ccccc13 ; c1ccc2c(N(c3ccc(C4CCCCC4)cc3)c3ccc(C45CC6CC(CC(C6)C4)C5)cc3)c3c(cc2c1)oc1ccccc13 ; c1ccc2c(N(c3ccc(C4CC5CCC4C5)cc3)c3ccc(C45CC6CC(CC(C6)C4)C5)cc3)c3c(cc2c1)oc1ccccc13]

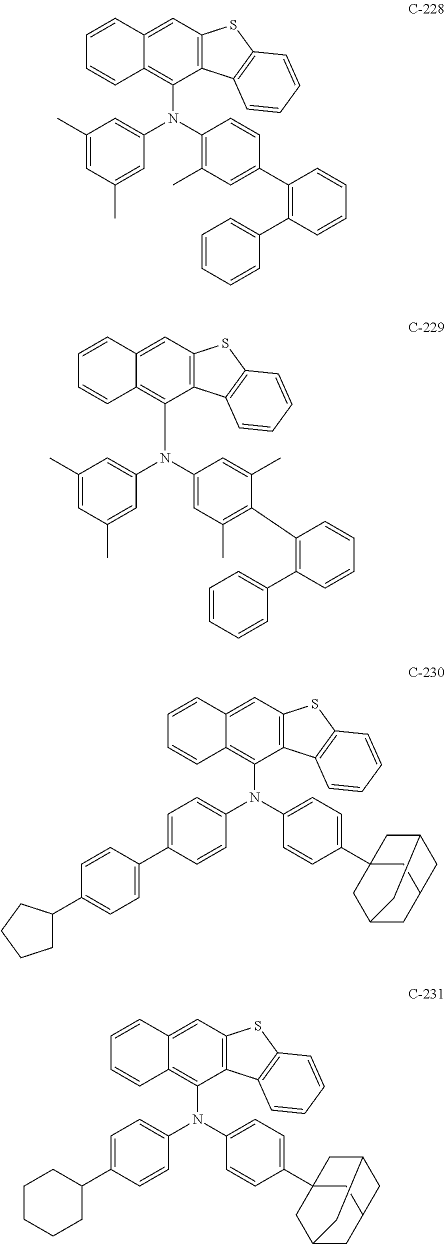 [SMILES: Cc1cc(C)cc(N(c2ccc(-c3ccccc3-c3ccccc3)cc2C)c2c3ccccc3cc3sc4ccccc4c23)c1 ; Cc1cc(C)cc(N(c2cc(C)c(-c3ccccc3-c3ccccc3)c(C)c2)c2c3ccccc3cc3sc4ccccc4c23)c1 ; c1ccc2c(N(c3ccc(-c4ccc(C5CCCC5)cc4)cc3)c3ccc(C45CC6CC(CC(C6)C4)C5)cc3)c3c(cc2c1)sc1ccccc13 ; c1ccc2c(N(c3ccc(C4CCCCC4)cc3)c3ccc(C45CC6CC(CC(C6)C4)C5)cc3)c3c(cc2c1)sc1ccccc13]

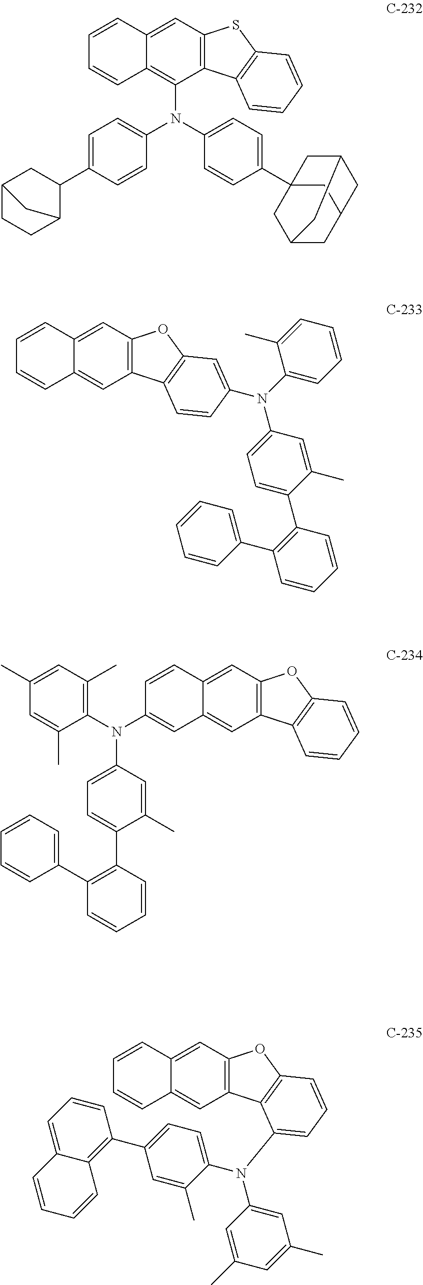

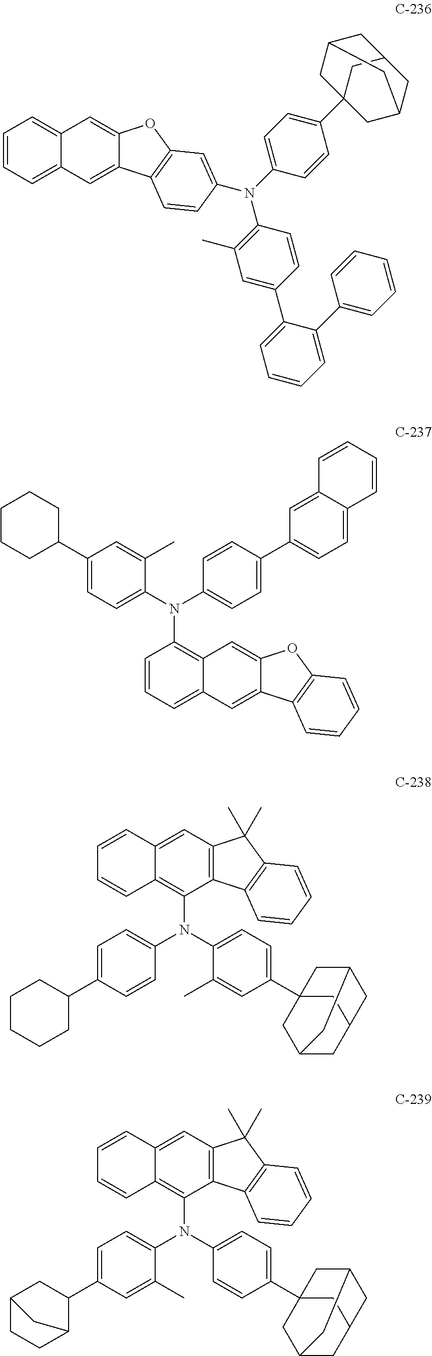 [SMILES: Cc1cc(-c2ccccc2-c2ccccc2)ccc1N(c1ccc(C23CC4CC(CC(C4)C2)C3)cc1)c1ccc2c(c1)oc1cc3ccccc3cc12 ; Cc1cc(C2CCCCC2)ccc1N(c1ccc(-c2ccc3ccccc3c2)cc1)c1cccc2cc3c(cc12)oc1ccccc13 ; Cc1cc(C23CC4CC(CC(C4)C2)C3)ccc1N(c1ccc(C2CCCCC2)cc1)c1c2c(cc3ccccc13)C(C)(C)c1ccccc1-2 ; Cc1cc(C2CC3CCC2C3)ccc1N(c1ccc(C23CC4CC(CC(C4)C2)C3)cc1)c1c2c(cc3ccccc13)C(C)(C)c1ccccc1-2]

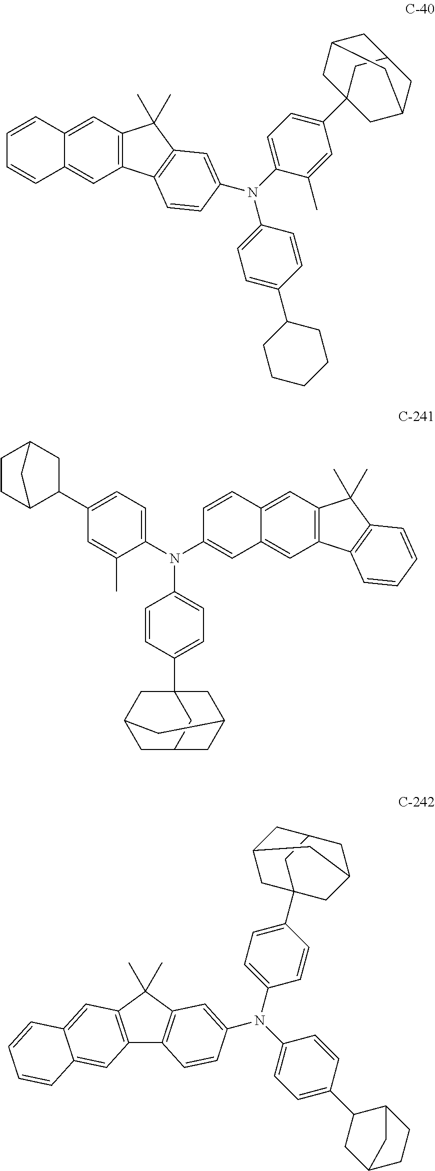 [SMILES: Cc1cc(C23CC4CC(CC(C4)C2)C3)ccc1N(c1ccc(C2CCCCC2)cc1)c1ccc2c(c1)C(C)(C)c1cc3ccccc3cc1-2 ; Cc1cc(C2CC3CCC2C3)ccc1N(c1ccc(C23CC4CC(CC(C4)C2)C3)cc1)c1ccc2cc3c(cc2c1)-c1ccccc1C3(C)C ; CC1(C)c2cc(N(c3ccc(C4CC5CCC4C5)cc3)c3ccc(C45CC6CC(CC(C6)C4)C5)cc3)ccc2-c2cc3ccccc3cc21]

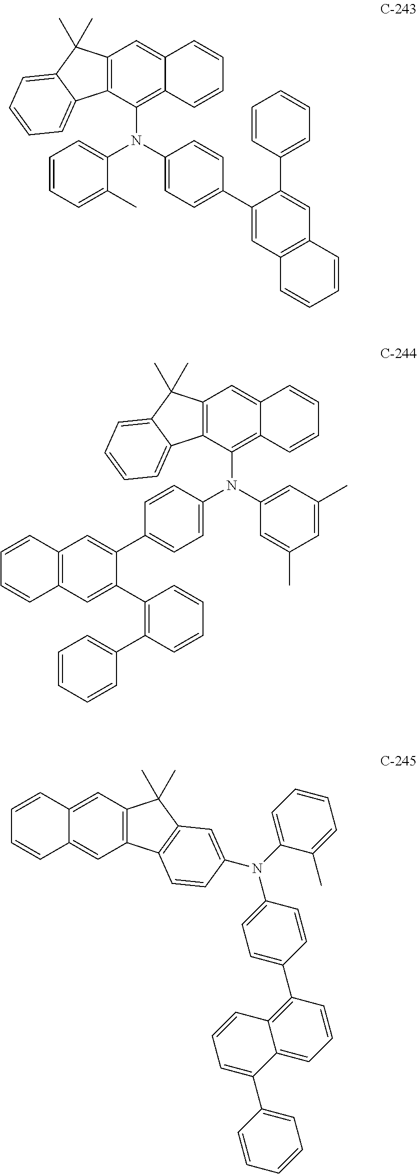 [SMILES: Cc1ccccc1N(c1ccc(-c2cc3ccccc3cc2-c2ccccc2)cc1)c1c2c(cc3ccccc13)C(C)(C)c1ccccc1-2 ; Cc1cc(C)cc(N(c2ccc(-c3cc4ccccc4cc3-c3ccccc3-c3ccccc3)cc2)c2c3c(cc4ccccc24)C(C)(C)c2ccccc2-3)c1 ; Cc1ccccc1N(c1ccc(-c2cccc3c(-c4ccccc4)cccc23)cc1)c1ccc2c(c1)C(C)(C)c1cc3ccccc3cc1-2]

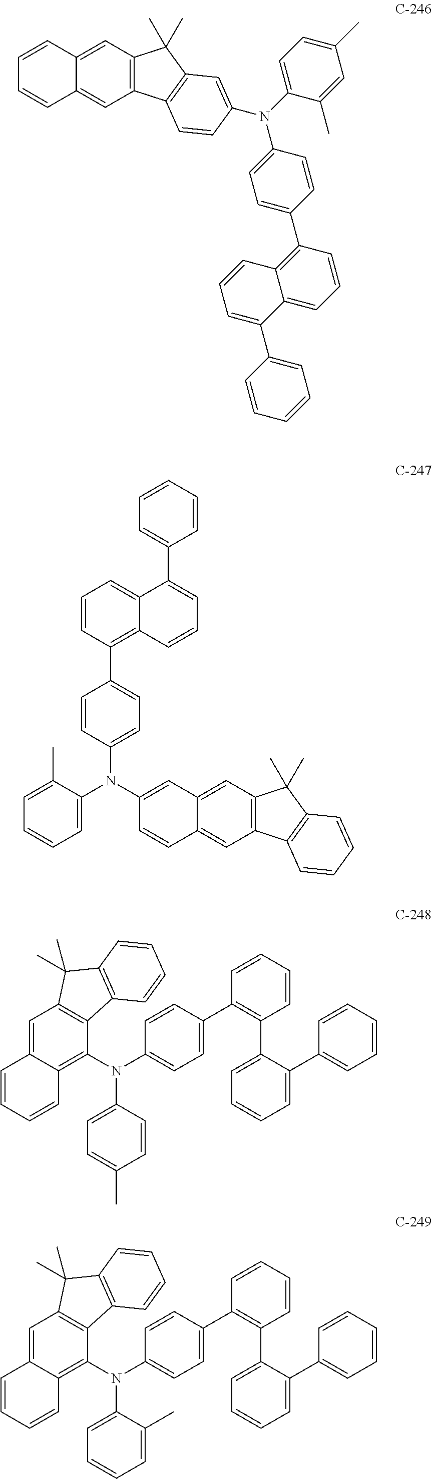

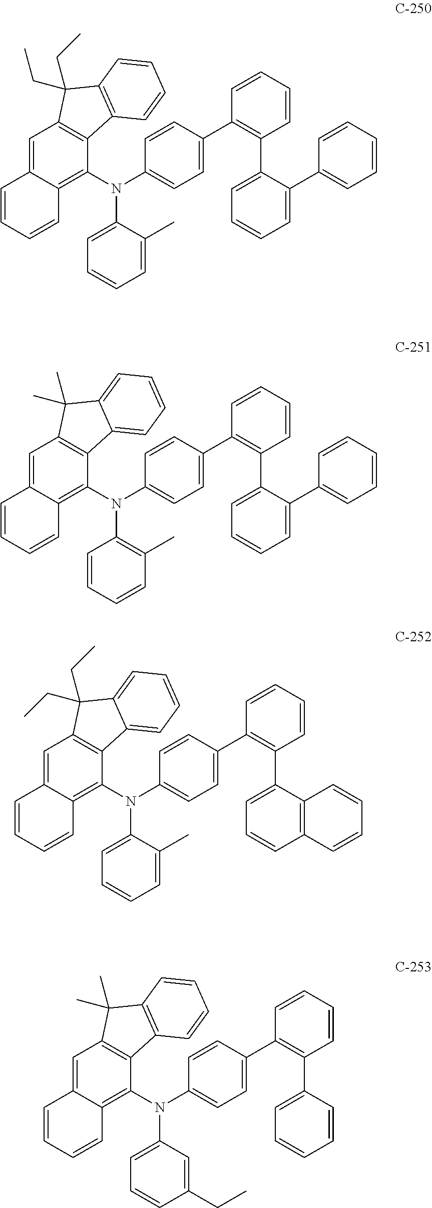 [SMILES: CCC1(CC)c2ccccc2-c2c1cc1ccccc1c2N(c1ccc(-c2ccccc2-c2ccccc2-c2ccccc2)cc1)c1ccccc1C ; Cc1ccccc1N(c1ccc(-c2ccccc2-c2ccccc2-c2ccccc2)cc1)c1c2c(cc3ccccc13)C(C)(C)c1ccccc1-2 ; CCC1(CC)c2ccccc2-c2c1cc1ccccc1c2N(c1ccc(-c2ccccc2-c2cccc3ccccc23)cc1)c1ccccc1C ; CCc1cccc(N(c2ccc(-c3ccccc3-c3ccccc3)cc2)c2c3c(cc4ccccc24)C(C)(C)c2ccccc2-3)c1]

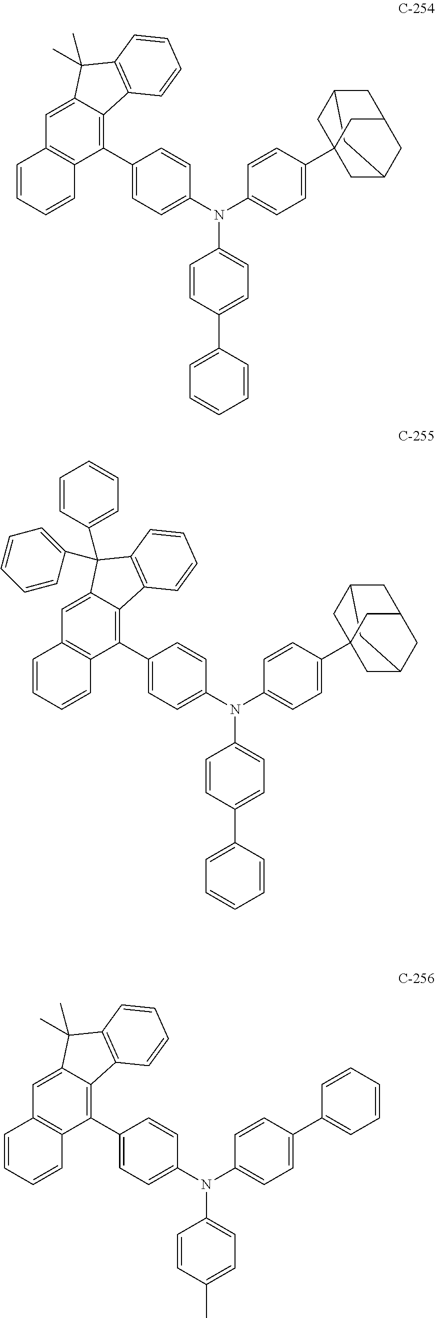 [SMILES: CC1(C)c2ccccc2-c2c1cc1ccccc1c2-c1ccc(N(c2ccc(-c3ccccc3)cc2)c2ccc(C34CC5CC(CC(C5)C3)C4)cc2)cc1 ; c1ccc(-c2ccc(N(c3ccc(-c4c5c(cc6ccccc46)C(c4ccccc4)(c4ccccc4)c4ccccc4-5)cc3)c3ccc(C45CC6CC(CC(C6)C4)C5)cc3)cc2)cc1 ; Cc1ccc(N(c2ccc(-c3ccccc3)cc2)c2ccc(-c3c4c(cc5ccccc35)C(C)(C)c3ccccc3-4)cc2)cc1]

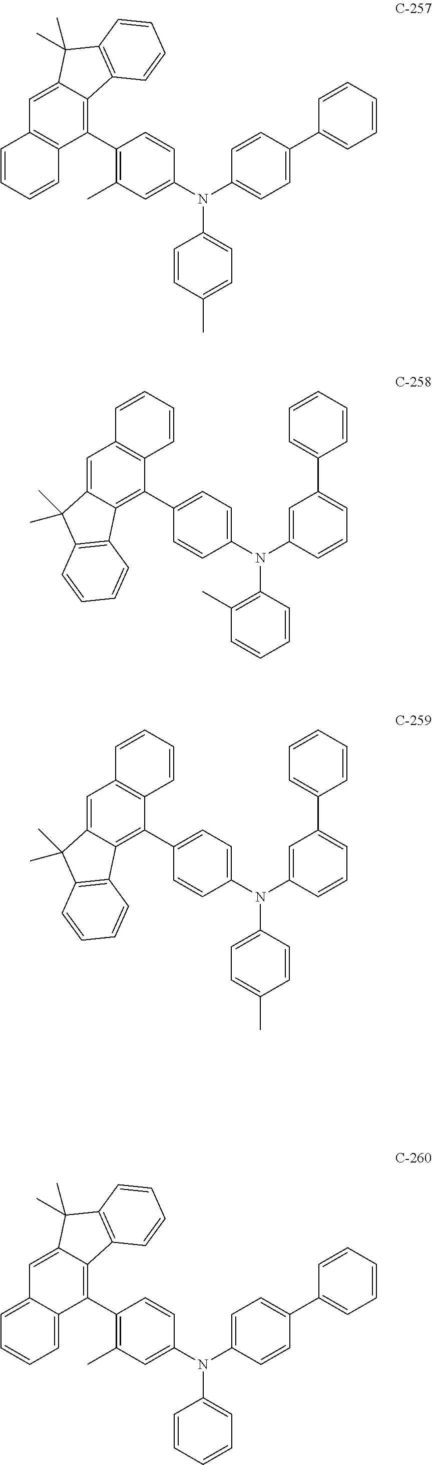 [SMILES: Cc1ccc(N(c2ccc(-c3ccccc3)cc2)c2ccc(-c3c4c(cc5ccccc35)C(C)(C)c3ccccc3-4)c(C)c2)cc1 ; Cc1ccccc1N(c1ccc(-c2c3c(cc4ccccc24)C(C)(C)c2ccccc2-3)cc1)c1cccc(-c2ccccc2)c1 ; Cc1ccc(N(c2ccc(-c3c4c(cc5ccccc35)C(C)(C)c3ccccc3-4)cc2)c2cccc(-c3ccccc3)c2)cc1 ; Cc1cc(N(c2ccccc2)c2ccc(-c3ccccc3)cc2)ccc1-c1c2c(cc3ccccc13)C(C)(C)c1ccccc1-2]

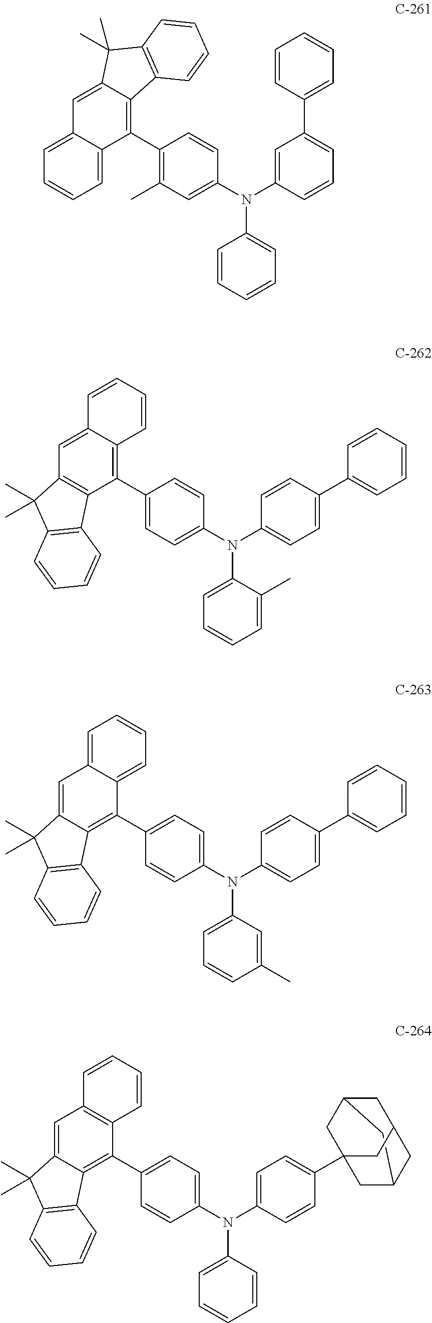 [SMILES: Cc1cc(N(c2ccccc2)c2cccc(-c3ccccc3)c2)ccc1-c1c2c(cc3ccccc13)C(C)(C)c1ccccc1-2 ; Cc1ccccc1N(c1ccc(-c2ccccc2)cc1)c1ccc(-c2c3c(cc4ccccc24)C(C)(C)c2ccccc2-3)cc1 ; Cc1cccc(N(c2ccc(-c3ccccc3)cc2)c2ccc(-c3c4c(cc5ccccc35)C(C)(C)c3ccccc3-4)cc2)c1 ; CC1(C)c2ccccc2-c2c1cc1ccccc1c2-c1ccc(N(c2ccccc2)c2ccc(C34CC5CC(CC(C5)C3)C4)cc2)cc1]

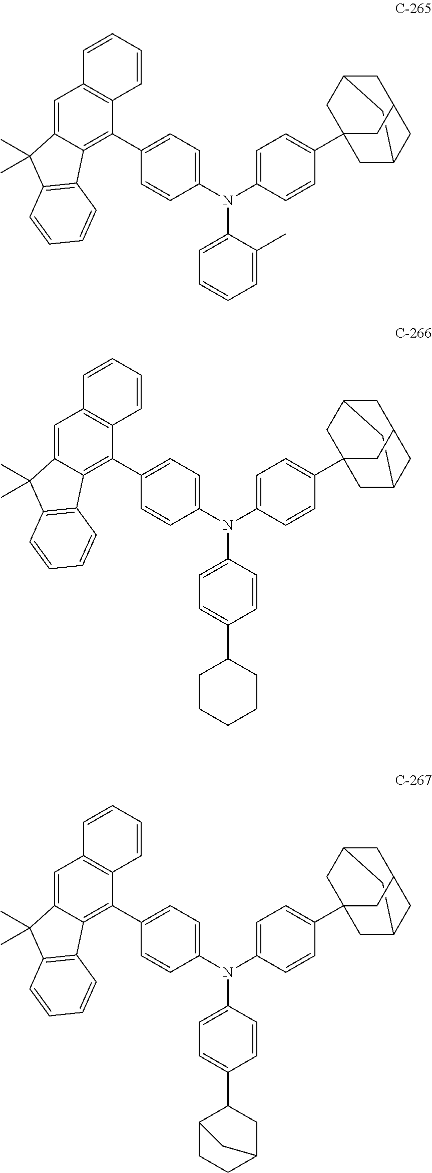 [SMILES: Cc1ccccc1N(c1ccc(-c2c3c(cc4ccccc24)C(C)(C)c2ccccc2-3)cc1)c1ccc(C23CC4CC(CC(C4)C2)C3)cc1 ; CC1(C)c2ccccc2-c2c1cc1ccccc1c2-c1ccc(N(c2ccc(C3CCCCC3)cc2)c2ccc(C34CC5CC(CC(C5)C3)C4)cc2)cc1 ; CC1(C)c2ccccc2-c2c1cc1ccccc1c2-c1ccc(N(c2ccc(C3CC4CCC3C4)cc2)c2ccc(C34CC5CC(CC(C5)C3)C4)cc2)cc1]

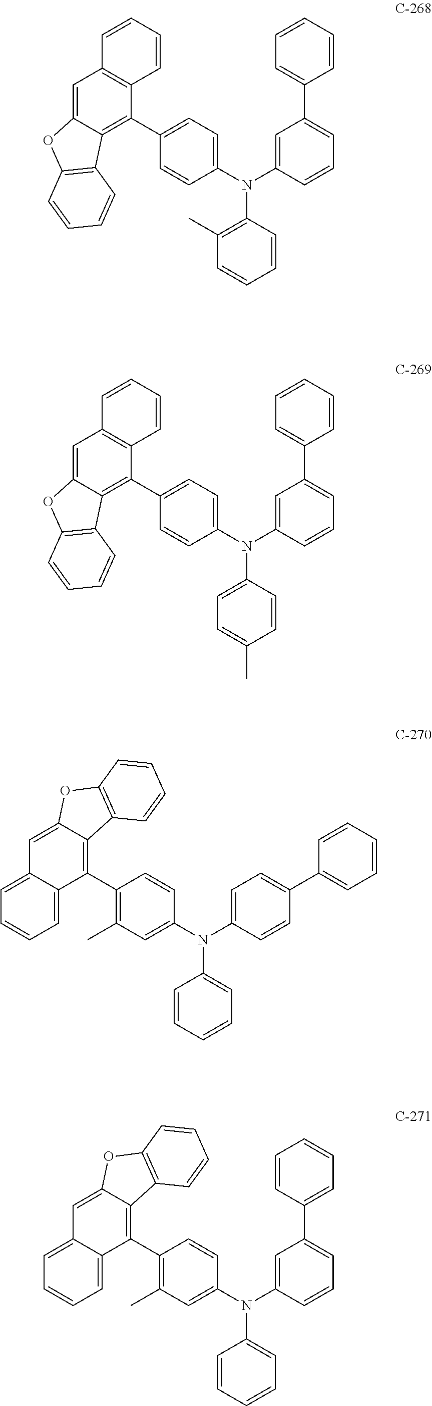 [SMILES: Cc1ccccc1N(c1ccc(-c2c3ccccc3cc3oc4ccccc4c23)cc1)c1cccc(-c2ccccc2)c1 ; Cc1ccc(N(c2ccc(-c3c4ccccc4cc4oc5ccccc5c34)cc2)c2cccc(-c3ccccc3)c2)cc1 ; Cc1cc(N(c2ccccc2)c2ccc(-c3ccccc3)cc2)ccc1-c1c2ccccc2cc2oc3ccccc3c12 ; Cc1cc(N(c2ccccc2)c2cccc(-c3ccccc3)c2)ccc1-c1c2ccccc2cc2oc3ccccc3c12]

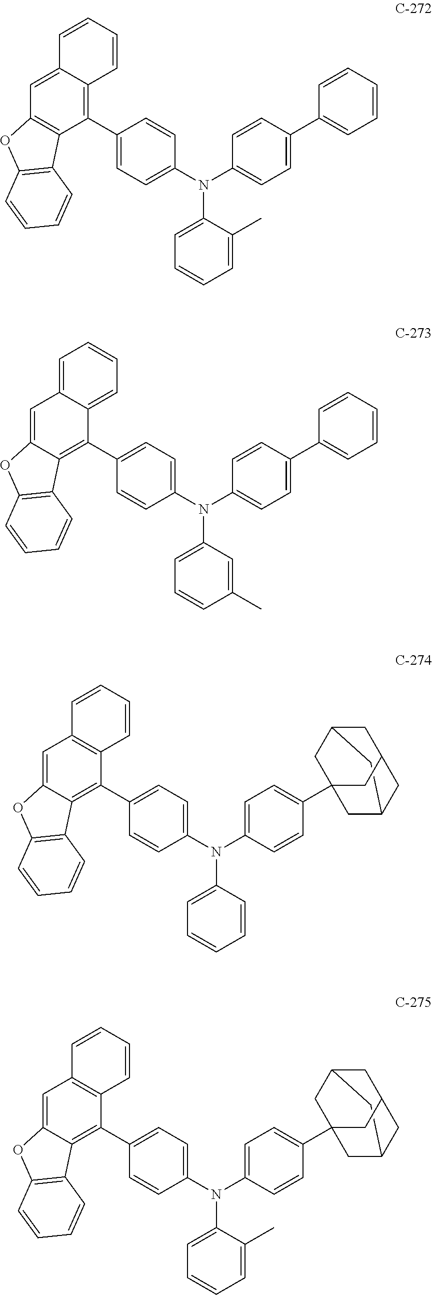 [SMILES: Cc1ccccc1N(c1ccc(-c2ccccc2)cc1)c1ccc(-c2c3ccccc3cc3oc4ccccc4c23)cc1 ; Cc1cccc(N(c2ccc(-c3ccccc3)cc2)c2ccc(-c3c4ccccc4cc4oc5ccccc5c34)cc2)c1 ; c1ccc(N(c2ccc(-c3c4ccccc4cc4oc5ccccc5c34)cc2)c2ccc(C34CC5CC(CC(C5)C3)C4)cc2)cc1 ; Cc1ccccc1N(c1ccc(-c2c3ccccc3cc3oc4ccccc4c23)cc1)c1ccc(C23CC4CC(CC(C4)C2)C3)cc1]

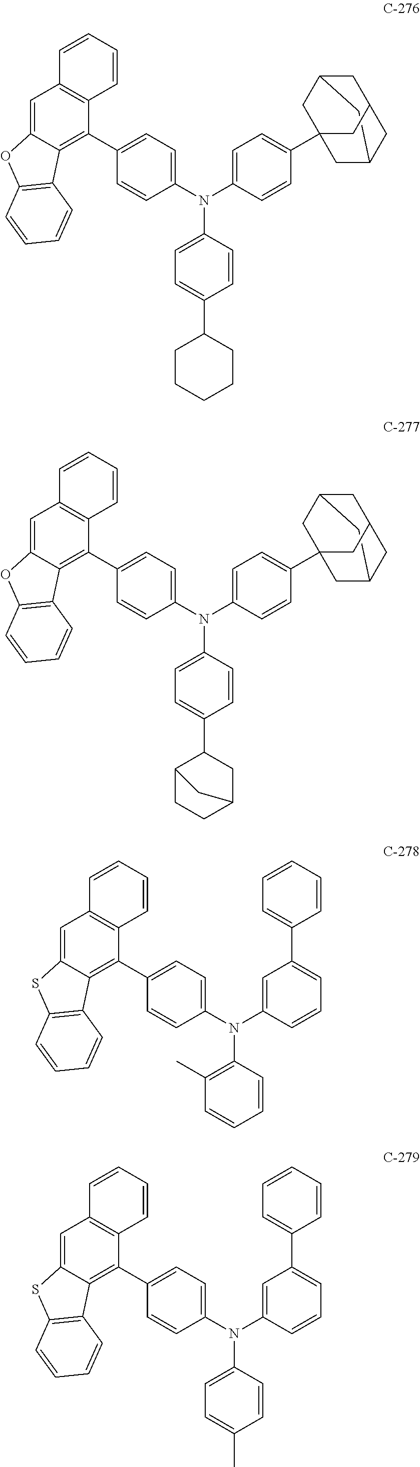 [SMILES: c1ccc2c(-c3ccc(N(c4ccc(C5CCCCC5)cc4)c4ccc(C56CC7CC(CC(C7)C5)C6)cc4)cc3)c3c(cc2c1)oc1ccccc13 ; c1ccc2c(-c3ccc(N(c4ccc(C5CC6CCC5C6)cc4)c4ccc(C56CC7CC(CC(C7)C5)C6)cc4)cc3)c3c(cc2c1)oc1ccccc13 ; Cc1ccccc1N(c1ccc(-c2c3ccccc3cc3sc4ccccc4c23)cc1)c1cccc(-c2ccccc2)c1 ; Cc1ccc(N(c2ccc(-c3c4ccccc4cc4sc5ccccc5c34)cc2)c2cccc(-c3ccccc3)c2)cc1]

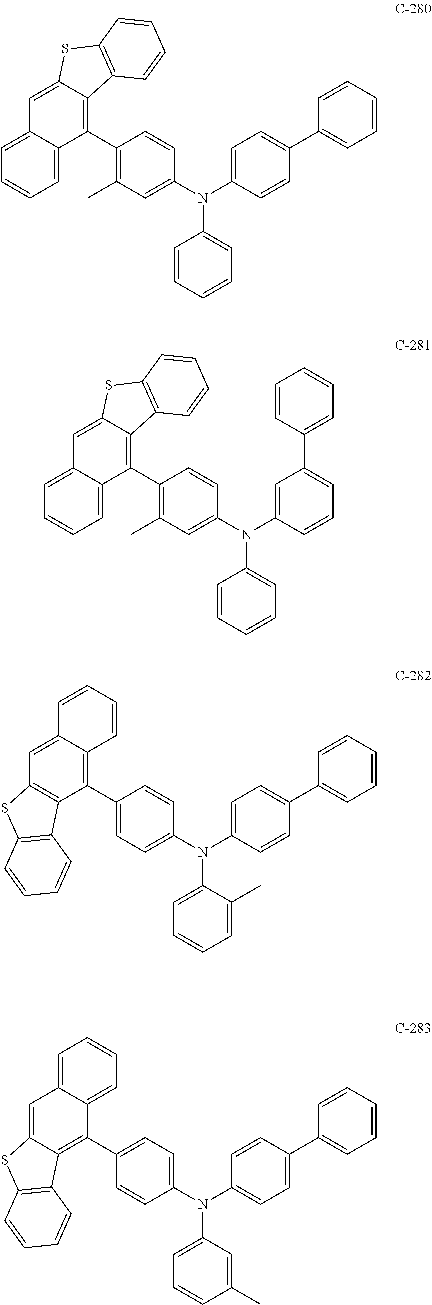 [SMILES: Cc1cc(N(c2ccccc2)c2ccc(-c3ccccc3)cc2)ccc1-c1c2ccccc2cc2sc3ccccc3c12 ; Cc1cc(N(c2ccccc2)c2cccc(-c3ccccc3)c2)ccc1-c1c2ccccc2cc2sc3ccccc3c12 ; Cc1ccccc1N(c1ccc(-c2ccccc2)cc1)c1ccc(-c2c3ccccc3cc3sc4ccccc4c23)cc1 ; Cc1cccc(N(c2ccc(-c3ccccc3)cc2)c2ccc(-c3c4ccccc4cc4sc5ccccc5c34)cc2)c1]

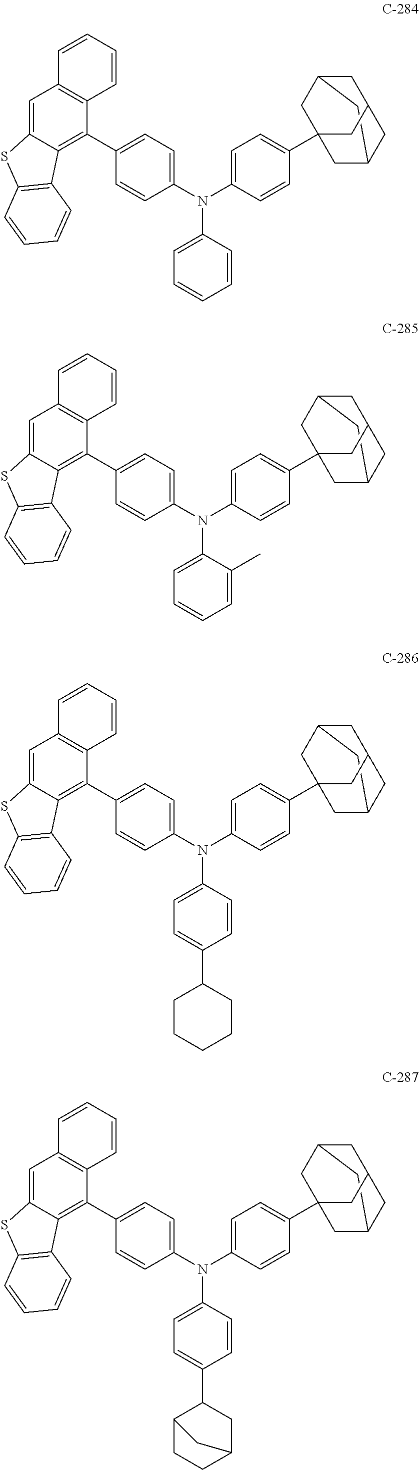 [SMILES: c1ccc(N(c2ccc(-c3c4ccccc4cc4sc5ccccc5c34)cc2)c2ccc(C34CC5CC(CC(C5)C3)C4)cc2)cc1 ; Cc1ccccc1N(c1ccc(-c2c3ccccc3cc3sc4ccccc4c23)cc1)c1ccc(C23CC4CC(CC(C4)C2)C3)cc1 ; c1ccc2c(-c3ccc(N(c4ccc(C5CCCCC5)cc4)c4ccc(C56CC7CC(CC(C7)C5)C6)cc4)cc3)c3c(cc2c1)sc1ccccc13 ; c1ccc2c(-c3ccc(N(c4ccc(C5CC6CCC5C6)cc4)c4ccc(C56CC7CC(CC(C7)C5)C6)cc4)cc3)c3c(cc2c1)sc1ccccc13]

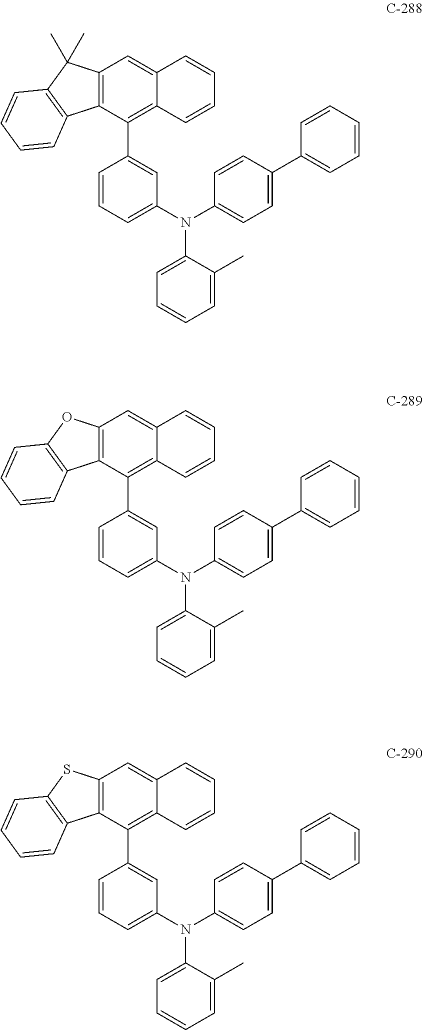 [SMILES: Cc1ccccc1N(c1ccc(-c2ccccc2)cc1)c1cccc(-c2c3c(cc4ccccc24)C(C)(C)c2ccccc2-3)c1 ; Cc1ccccc1N(c1ccc(-c2ccccc2)cc1)c1cccc(-c2c3ccccc3cc3oc4ccccc4c23)c1 ; Cc1ccccc1N(c1ccc(-c2ccccc2)cc1)c1cccc(-c2c3ccccc3cc3sc4ccccc4c23)c1]

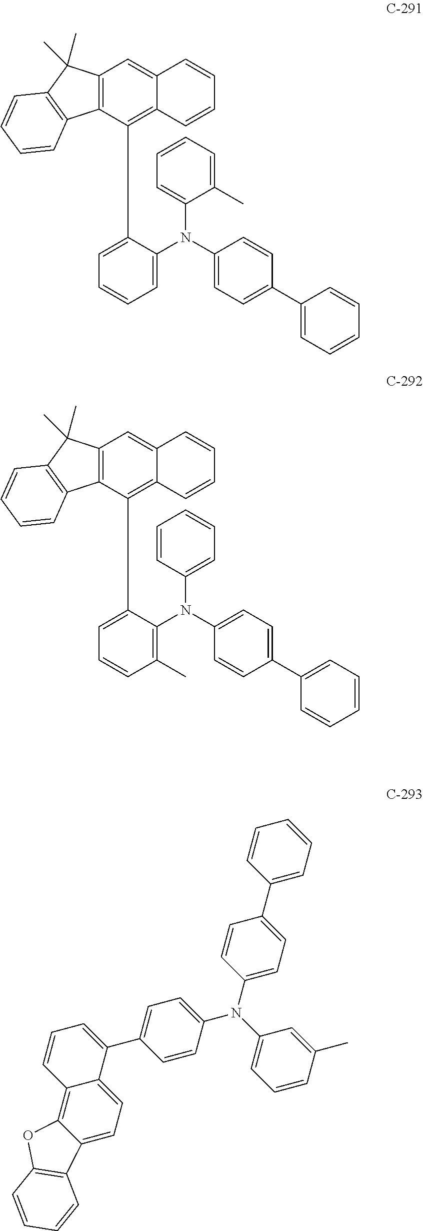 [SMILES: Cc1ccccc1N(c1ccc(-c2ccccc2)cc1)c1ccccc1-c1c2c(cc3ccccc13)C(C)(C)c1ccccc1-2 ; Cc1cccc(-c2c3c(cc4ccccc24)C(C)(C)c2ccccc2-3)c1N(c1ccccc1)c1ccc(-c2ccccc2)cc1 ; Cc1cccc(N(c2ccc(-c3ccccc3)cc2)c2ccc(-c3cccc4c3ccc3c5ccccc5oc43)cc2)c1]

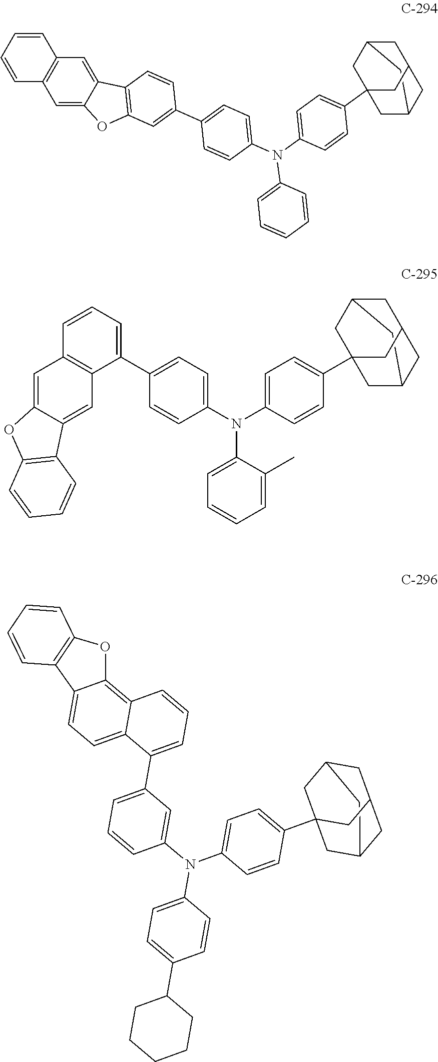 [SMILES: c1ccc(N(c2ccc(-c3ccc4c(c3)oc3cc5ccccc5cc34)cc2)c2ccc(C34CC5CC(CC(C5)C3)C4)cc2)cc1 ; Cc1ccccc1N(c1ccc(-c2cccc3cc4oc5ccccc5c4cc23)cc1)c1ccc(C23CC4CC(CC(C4)C2)C3)cc1 ; c1cc(-c2cccc3c2ccc2c4ccccc4oc32)cc(N(c2ccc(C3CCCCC3)cc2)c2ccc(C34CC5CC(CC(C5)C3)C4)cc2)c1]

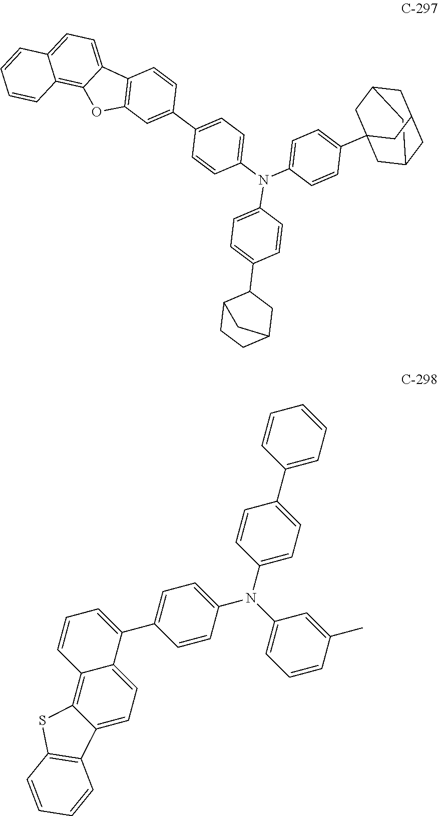 [SMILES: c1ccc2c(c1)ccc1c3ccc(-c4ccc(N(c5ccc(C6CC7CCC6C7)cc5)c5ccc(C67CC8CC(CC(C8)C6)C7)cc5)cc4)cc3oc21 ; Cc1cccc(N(c2ccc(-c3ccccc3)cc2)c2ccc(-c3cccc4c3ccc3c5ccccc5sc43)cc2)c1]

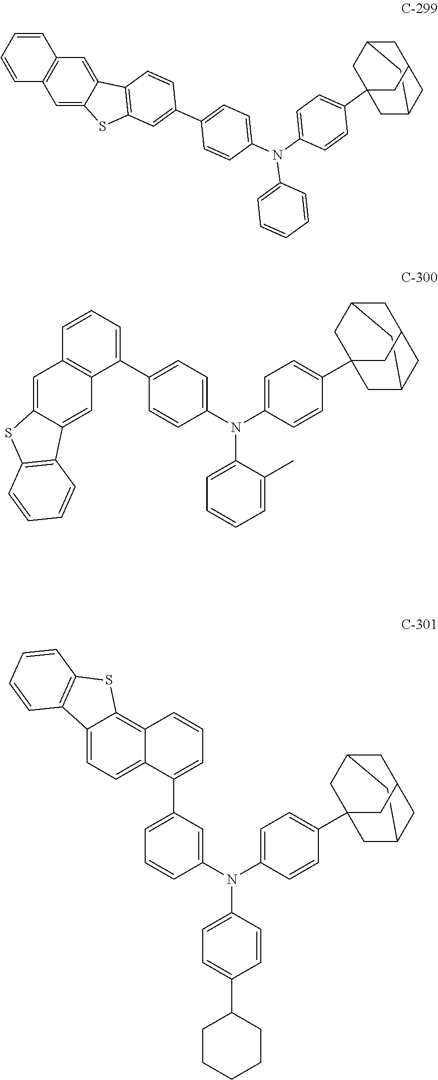 [SMILES: c1ccc(N(c2ccc(-c3ccc4c(c3)sc3cc5ccccc5cc34)cc2)c2ccc(C34CC5CC(CC(C5)C3)C4)cc2)cc1 ; Cc1ccccc1N(c1ccc(-c2cccc3cc4sc5ccccc5c4cc23)cc1)c1ccc(C23CC4CC(CC(C4)C2)C3)cc1 ; c1cc(-c2cccc3c2ccc2c4ccccc4sc32)cc(N(c2ccc(C3CCCCC3)cc2)c2ccc(C34CC5CC(CC(C5)C3)C4)cc2)c1]

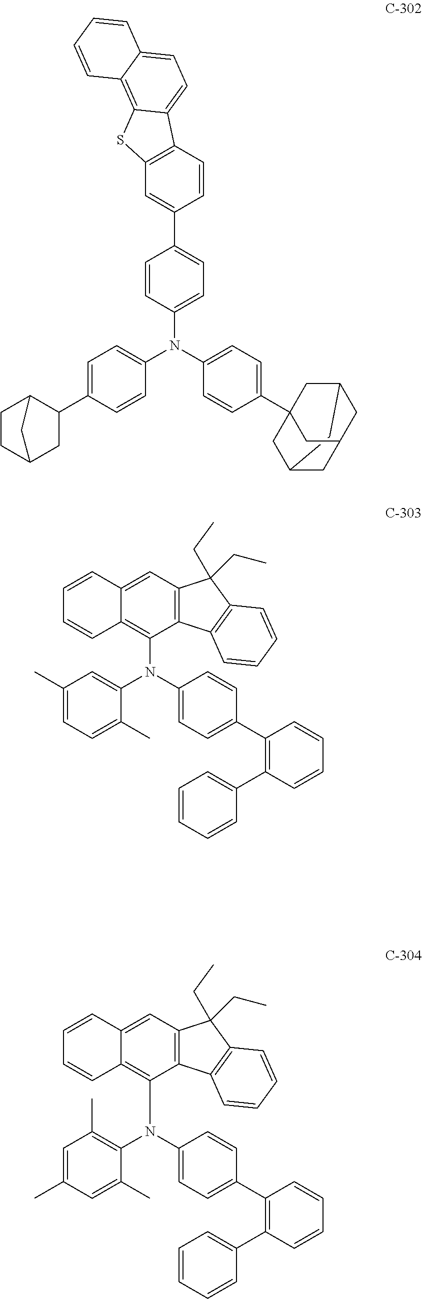 [SMILES: c1ccc2c(c1)ccc1c3ccc(-c4ccc(N(c5ccc(C6CC7CCC6C7)cc5)c5ccc(C67CC8CC(CC(C8)C6)C7)cc5)cc4)cc3sc21 ; CCC1(CC)c2ccccc2-c2c1cc1ccccc1c2N(c1ccc(-c2ccccc2-c2ccccc2)cc1)c1cc(C)ccc1C ; CCC1(CC)c2ccccc2-c2c1cc1ccccc1c2N(c1ccc(-c2ccccc2-c2ccccc2)cc1)c1c(C)cc(C)cc1C]

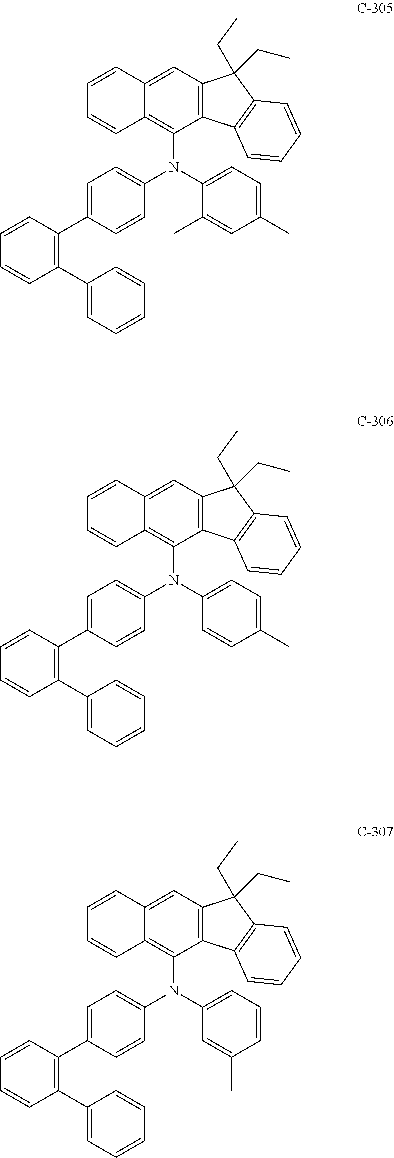 [SMILES: CCC1(CC)c2ccccc2-c2c1cc1ccccc1c2N(c1ccc(-c2ccccc2-c2ccccc2)cc1)c1ccc(C)cc1C ; CCC1(CC)c2ccccc2-c2c1cc1ccccc1c2N(c1ccc(C)cc1)c1ccc(-c2ccccc2-c2ccccc2)cc1 ; CCC1(CC)c2ccccc2-c2c1cc1ccccc1c2N(c1ccc(-c2ccccc2-c2ccccc2)cc1)c1cccc(C)c1]

In each of the compounds above, hydrogen can be replaced by deuterium.

The compound represented by Formula 1 according to the present disclosure may be synthesized by referring to synthetic methods known to one skilled in the art, and in particular, as synthetic method disclosed in a number of patent documents can be used. For example, it may be synthesized by referring to synthetic methods disclosed in Korean Patent Application Laid-Open Nos. 2015-0066202 (published on Jun. 16, 2015) and 2017-0124957 (published on Nov. 13, 2017), etc., but is not limited thereto.

In the above organic electroluminescent device, the light-emitting layer comprises a compound represented by the following Formula 2.

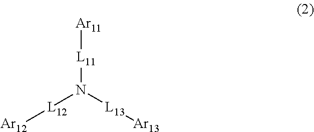

In Formula 2, L₁₁ to L₁₃ each independently represent a single bond, a substituted or unsubstituted (C₆-C₃₀)arylene, or a substituted or unsubstituted (3- to 30-membered)heteroarylene. According to one embodiment of the present disclosure, L₁₁ to L₁₃ may each independently be a single bond, a substituted or unsubstituted (C₆-C₂₀)arylene, or a substituted or unsubstituted (3- to 20-membered)heteroarylene. For example, L₁₁ to L₁₃ may each independently be a single bond, a phenylene unsubstituted or substituted with deuterium, a biphenylene unsubstituted or substituted with deuterium, a terphenylene unsubstituted or substituted with deuterium, a naphthylene unsubstituted or substituted with deuterium, a phenanthrenylene, a dibenzofuranylene, a dibenzothiophenylene, a carbazolylene, or a pyridylene, and each may independently be substituted with deuterium.

In Formula 2, Ar₁₁ represents a substituted or unsubstituted (3- to 30-membered)heteroaryl. According to one embodiment of the present disclosure, Ar₁₁ may be a substituted or unsubstituted (3- to 25-membered)heteroaryl. According to another embodiment of the present disclosure, Ar₁₁ may be a substituted or unsubstituted (3- to 30-membered)heteroaryl having 4 or more rings. According to another embodiment of the present disclosure, Ar₁₁ may be a substituted or unsubstituted (3- to 30-membered)heteroaryl having 4 or more fused rings, which necessarily include an oxygen atom. According to another embodiment of the present disclosure, Ar₁₁ may be represented by the following Formula 2-1 or 2-2.

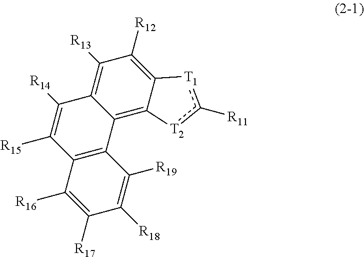

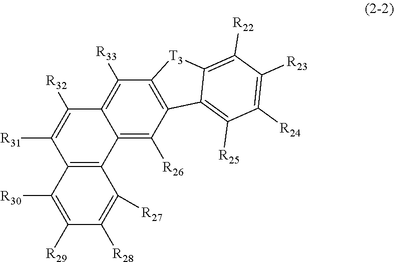

In Formulas 2-1 and 2-2, T₁ and T₂ each independently represent —N═, —NR₂₀—, —O—, or —S—, provided that one of T₁ and T₂ represents —N═, and the other one of T₁ and T₂ represents —NR₂O—, —O—, or —S—. For example, T₁ and T₂ each may independently be —N═, —O—, or —S—.

In Formula 2-2, T₃ represents O or S. For example, T₃ may be O.

In Formula 2-1, R₁ represents a substituted or unsubstituted (C₆-C₃₀)aryl or a substituted or unsubstituted (3- to 30-membered)heteroaryl. According to one embodiment of the present disclosure, R₁ may be a substituted or unsubstituted (C₆-C₁₅)aryl or a substituted or unsubstituted (3- to 10-membered)heteroaryl. For example, R₁ may be a phenyl, a naphthyl, a biphenyl, or a pyridyl, and may be further substituted with deuterium.

In Formulas 2-1 and 2-2, R₁₂ to R₁₁ and R₂₂ to R₃₃ each independently are connected to L₁₁, or represent hydrogen, deuterium, halogen, cyano, a substituted or unsubstituted (C₁-C₃₀)alkyl, a substituted or unsubstituted (C₆-C₃₀)aryl, a substituted or unsubstituted (3- to 30-membered)heteroaryl, a substituted or unsubstituted (C₃-C₃₀)cycloalkyl, a substituted or unsubstituted (C₁-C₃₀)alkoxy, a substituted or unsubstituted tri(C₁-C₃₀)alkylsilyl, a substituted or unsubstituted di(C₁-C₃₀)alkyl(C₆-C₃₀)arylsilyl, a substituted or unsubstituted (C₁-C₃₀)alkyldi(C₆-C₃₀)arylsilyl, a substituted or unsubstituted tri(C₆-C₃₀)arylsilyl, a substituted or unsubstituted fused ring of a (C₃-C₃₀)aliphatic ring and a (C₆-C₃₀)aromatic ring, a substituted or unsubstituted mono- or di-(C₁-C₃₀)alkylamino, a substituted or unsubstituted mono- or di-(C₂-C₃₀)alkenylamino, a substituted or unsubstituted (C₁-C₃₀)alkyl(C₂-C₃₀)alkenylamino, a substituted or unsubstituted (C₁-C₃₀)alkyl(C₆-C₃₀)arylamino, a substituted or unsubstituted (C₁-C₃₀)alkyl(3- to 30-membered)heteroarylamino, a substituted or unsubstituted (C₂-C₃₀)alkenyl(C₆-C₃₀)arylamino, a substituted or unsubstituted (C₂-C₃₀)alkenyl(3- to 30-membered)heteroarylamino, a substituted or unsubstituted mono- or di-(C₆-C₃₀)arylamino, a substituted or unsubstituted mono- or di-(3- to 30-membered)heteroarylamino, or a substituted or unsubstituted (C₆-C₃₀)aryl(3- to 30-membered)heteroarylamino; or may be linked to the adjacent substituents to form a ring(s). According to one embodiment of the present disclosure, R₁₂ to R₁₉ and R₂₂ to R₃₃ may each independently be hydrogen, deuterium, a substituted or unsubstituted (C₁-C₃₀)alkyl, a substituted or unsubstituted (C₆-C₃₀)aryl, a substituted or unsubstituted (3- to 30-membered)heteroaryl, a substituted or unsubstituted (C₃-C₃₀)cycloalkyl, a substituted or unsubstituted fused ring of a (C₃-C₃₀)aliphatic ring and a (C₆-C₃₀)aromatic ring, a substituted or unsubstituted (C₁-C₃₀)alkyl(C₆-C₃₀)arylamino, a substituted or unsubstituted (C₁-C₃₀)alkyl(3- to 30-membered)heteroarylamino, a substituted or unsubstituted mono- or di-(C₆-C₃₀)arylamino, a substituted or unsubstituted mono- or di-(3- to 30-membered)heteroarylamino, or a substituted or unsubstituted (C₆-C₃₀)aryl(3- to 30-membered)heteroarylamino, or may be linked to the adjacent substituents to form a ring(s). For example, R₁₂ to R₁₉ and R₂₂ to R₃₃ may each independently be hydrogen or deuterium.

Provided that any one of R₁₂ to R₁₉ in Formula 2-1 is connected to L₁₁, and any one of R₂₂ to R₃₃ in Formula 2-2 is connected to L₁₁.

In Formula 2, Ar₁₂ and Ar₁₃ each independently represent a substituted or unsubstituted (C₁-C₃₀)alkyl, a substituted or unsubstituted (C₆-C₃₀)aryl, a substituted or unsubstituted (3- to 30-membered)heteroaryl, a substituted or unsubstituted (C₃-C₃₀)cycloalkyl, a substituted or unsubstituted (C₁-C₃₀)alkoxy, a substituted or unsubstituted tri(C₁-C₃₀)alkylsilyl, a substituted or unsubstituted di(C₁-C₃₀)alkyl(C₆-C₃₀)arylsilyl, a substituted or unsubstituted (C₁-C₃₀)alkyldi(C₆-C₃₀)arylsilyl, a substituted or unsubstituted tri(C₆-C₃₀)arylsilyl, a substituted or unsubstituted mono- or di-(C₁-C₃₀)alkylamino, a substituted or unsubstituted mono- or di-(C₂-C₃₀)alkenylamino, a substituted or unsubstituted (C₁-C₃₀)alkyl(C₂-C₃₀)alkenylamino, a substituted or unsubstituted mono- or di-(C₆-C₃₀)arylamino, a substituted or unsubstituted (C₁-C₃₀)alkyl(C₆-C₃₀)arylamino, a substituted or unsubstituted mono- or di-(3- to 30-membered)heteroarylamino, a substituted or unsubstituted (C₁-C₃₀)alkyl(3- to 30-membered)heteroarylamino, a substituted or unsubstituted (C₂-C₃₀)alkenyl(C₆-C₃₀)arylamino, a substituted or unsubstituted (C₂-C₃₀)alkenyl(3- to 30-membered)heteroarylamino, or a substituted or unsubstituted (C₆-C₃₀)aryl(3- to 30-membered)heteroarylamino. According to one embodiment of the present disclosure, Ar₁₂ and Ar₁₃ may each independently be a substituted or unsubstituted (C₁-C₃₀)alkyl, a substituted or unsubstituted (C₆-C₃₀)aryl, a substituted or unsubstituted (3- to 30-membered)heteroaryl, a substituted or unsubstituted (C₃-C₃₀)cycloalkyl, a substituted or unsubstituted mono- or di-(C₆-C₃₀)arylamino, or a substituted or unsubstituted (C₆-C₃₀)aryl(3- to 30-membered)heteroarylamino. According to another embodiment of the present disclosure, Ar₁₂ and Ar₁₃ may each independently be a substituted or unsubstituted (C₆-C₃₀)aryl, a substituted or unsubstituted (3- to 30-membered)heteroaryl, a substituted or unsubstituted mono- or di-(C₆-C₃₀)arylamino, or a substituted or unsubstituted (C₆-C₃₀)aryl(3- to 30-membered)heteroarylamino. For example, Ar₁₂ and Ar₁₃ may be a phenyl unsubstituted or substituted with a phenyl unsubstituted or substituted with deuterium, cyano, phenyl unsubstituted or substituted with deuterium, biphenyl, naphthyl unsubstituted or substituted with deuterium or phenyl, phenanthrenyl, dibenzofuranyl, or carbazolyl; a biphenyl unsubstituted or substituted with deuterium or phenyl; a naphthyl unsubstituted or substituted with deuterium, phenyl unsubstituted or substituted with deuterium, or pyridyl; a phenanthrenyl unsubstituted or substituted with deuterium, phenyl, or pyridyl; a dimethylfluorenyl; a dimethylbenzofluorenyl; a diphenylfluorenyl unsubstituted or substituted with deuterium; an o-terphenyl unsubstituted or substituted with deuterium; m-terphenyl; a p-terphenyl unsubstituted or substituted with deuterium; a 2,6-dimethylphenyl; a tert-butyl phenyl; a fluoranthenyl; an anthracenyl; a spirobifluorenyl; a quaterphenyl unsubstituted or substituted with deuterium; a triphenylenyl unsubstituted or substituted with deuterium; a dibenzofuranyl unsubstituted or substituted with deuterium, phenyl, or a pyridyl; a dibenzothiophenyl unsubstituted or substituted with deuterium or phenyl; a pyridyl unsubstituted or substituted with phenyl; a benzonaphthofuranyl; a benzonaphthothiophenyl; a carbazolyl unsubstituted or substituted with phenyl, or a biphenyl; a phenoxazinyl; a benzoimidazolyl unsubstituted or substituted with phenyl; a triphenylsilyl; a dibenzoselenophenyl; a 14-membered heteroaryl substituted with a methyl; a 22-membered heteroaryl; a benzophenanthrenyl; a benzonaphthoselenophenyl; a diphenyl amino; a phenylbiphenyl amino; a phenyl dibenzofuranyl amino; a phenyl dibenzothiophenyl amino; or a phenyl pyridyl amino, and may be further substituted with deuterium.

The compound represented by Formula 2 may be selected from the following compounds, but is not limited thereto.

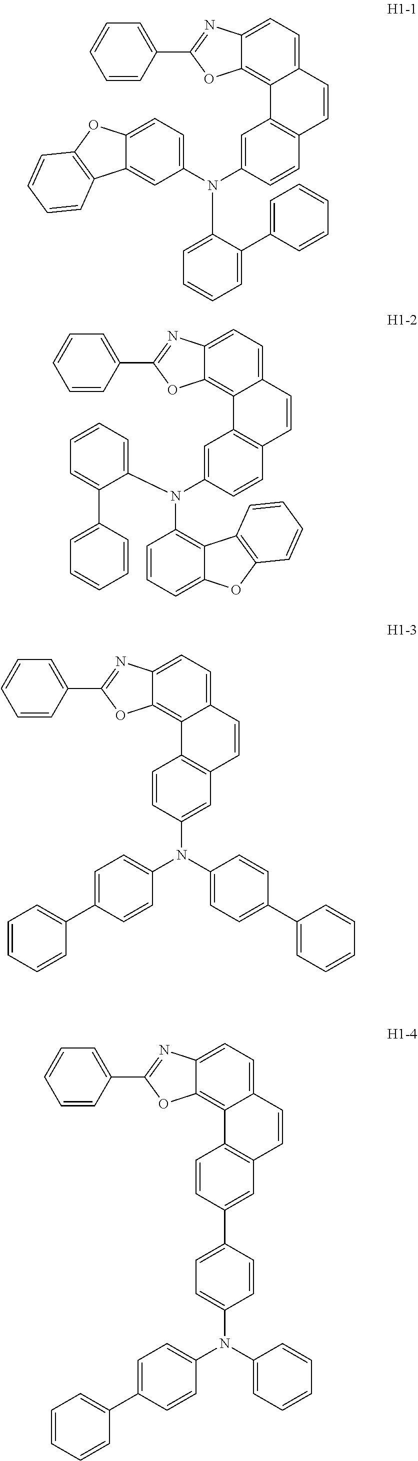

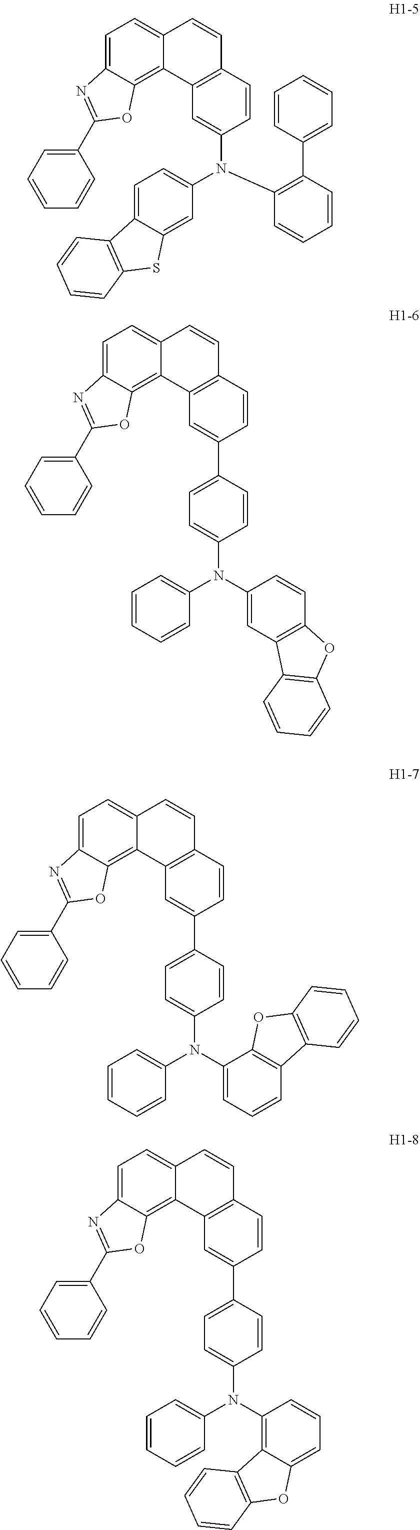

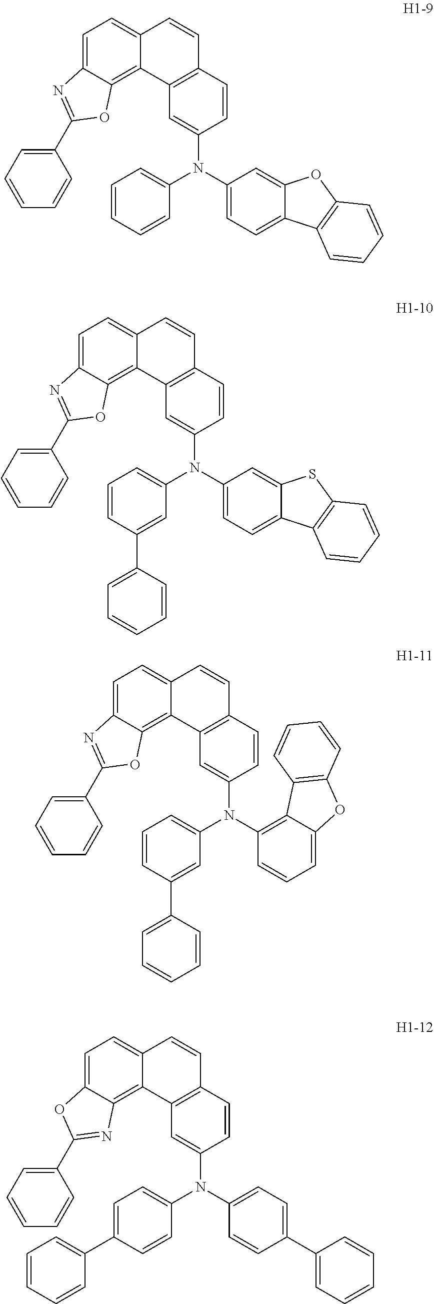

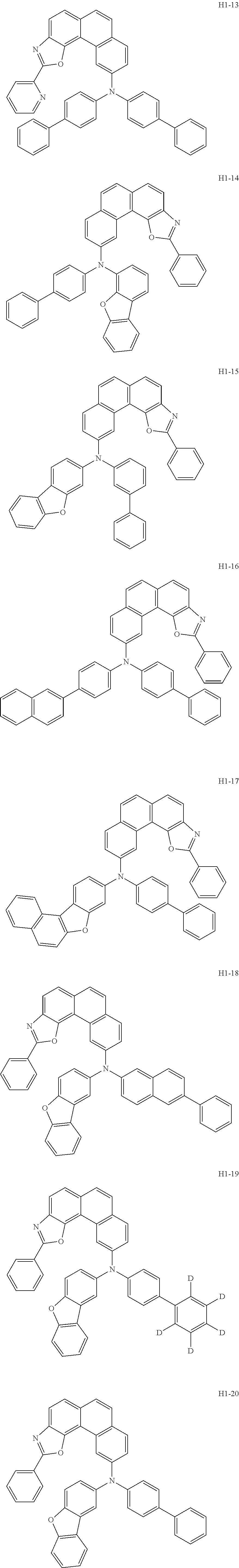

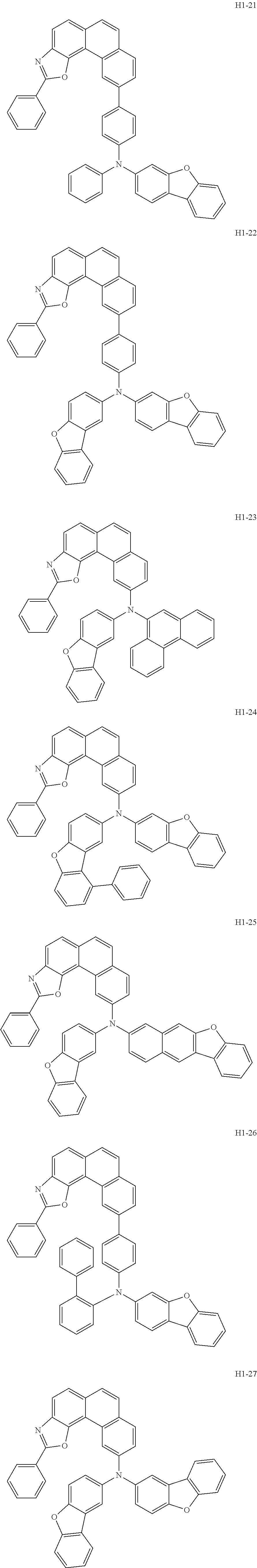

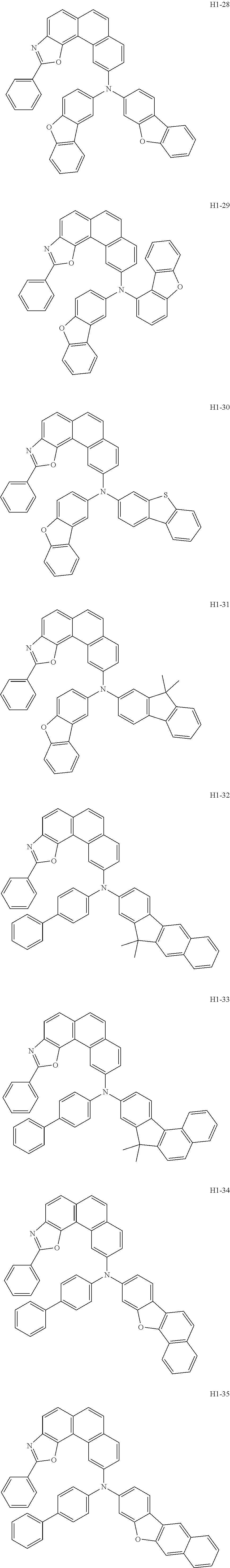

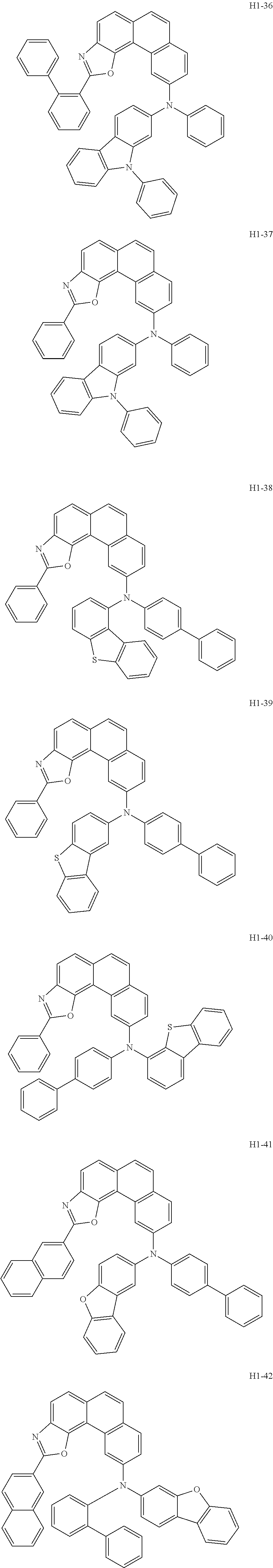

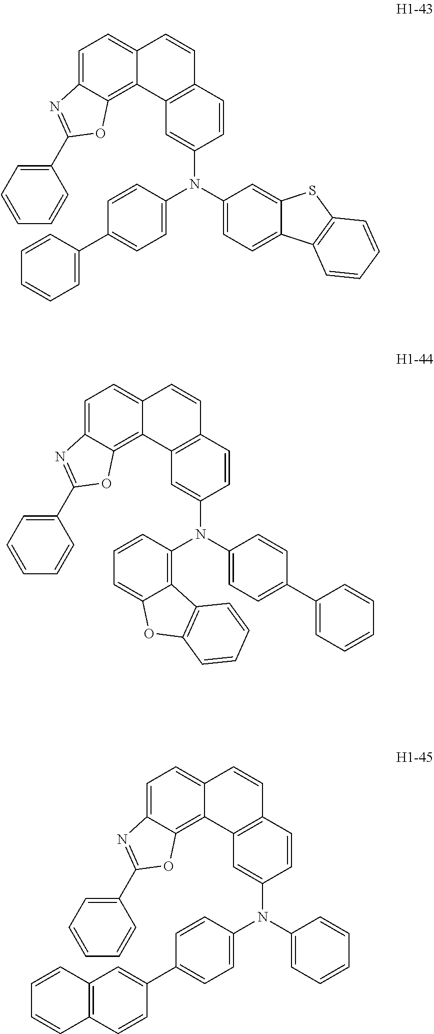 [SMILES: c1ccc(-c2ccc(N(c3ccc4c(c3)sc3ccccc34)c3ccc4ccc5ccc6nc(-c7ccccc7)oc6c5c4c3)cc2)cc1 ; c1ccc(-c2ccc(N(c3ccc4ccc5ccc6nc(-c7ccccc7)oc6c5c4c3)c3cccc4oc5ccccc5c34)cc2)cc1 ; c1ccc(-c2nc3ccc4ccc5ccc(N(c6ccccc6)c6ccc(-c7ccc8ccccc8c7)cc6)cc5c4c3o2)cc1]

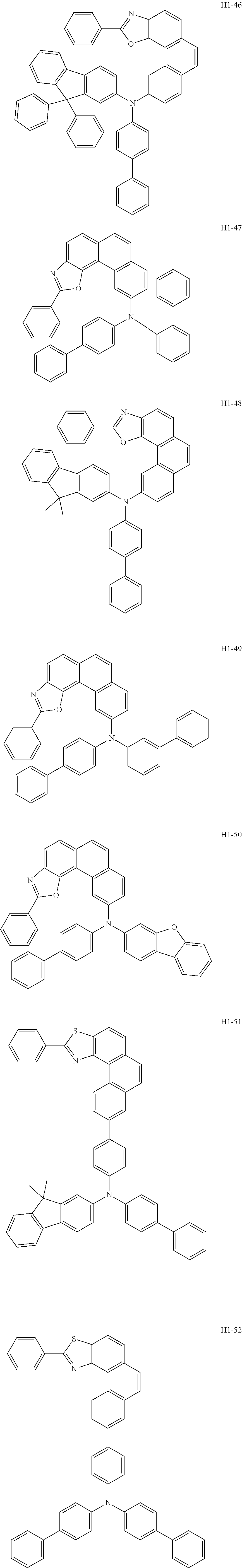

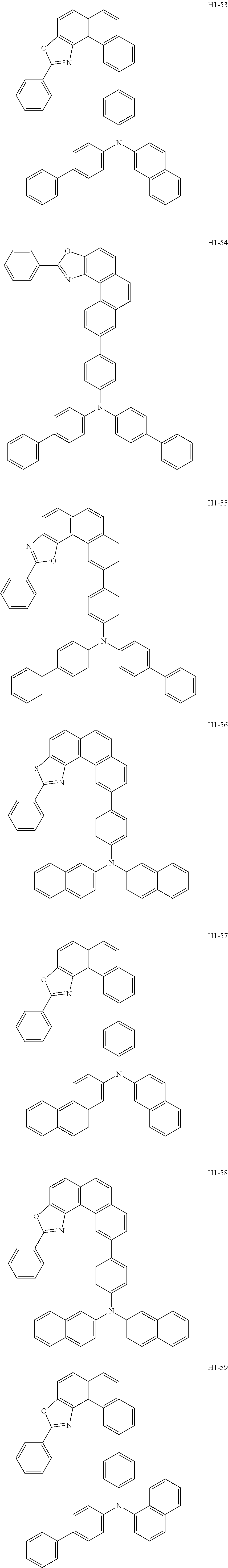

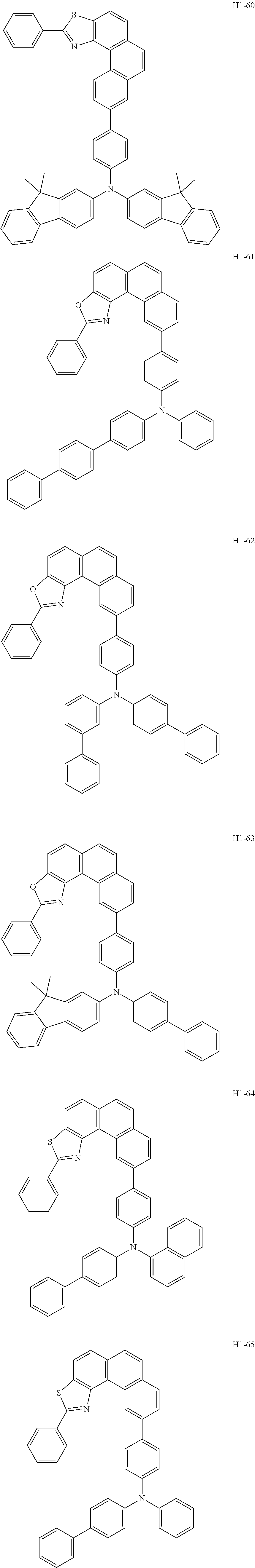

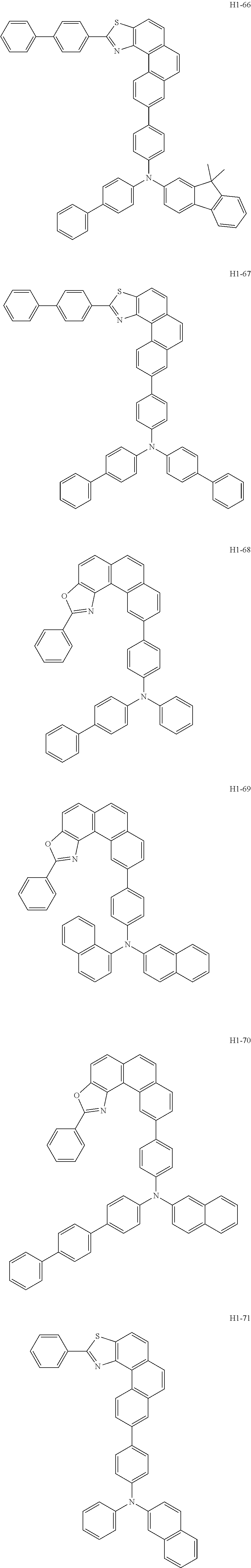

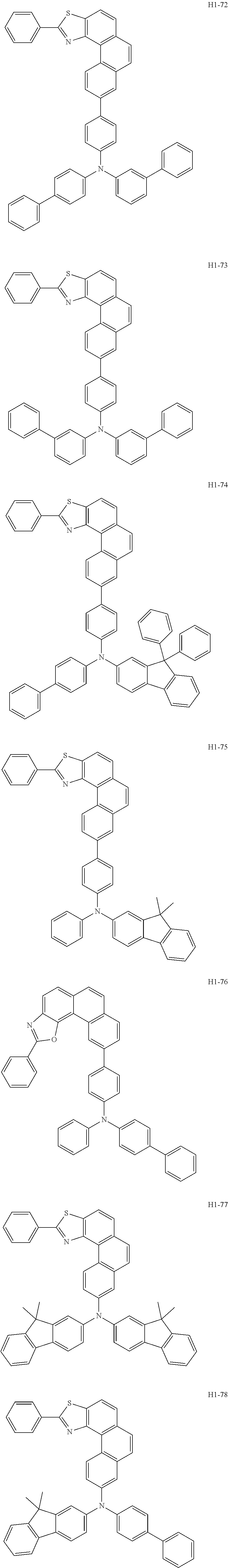

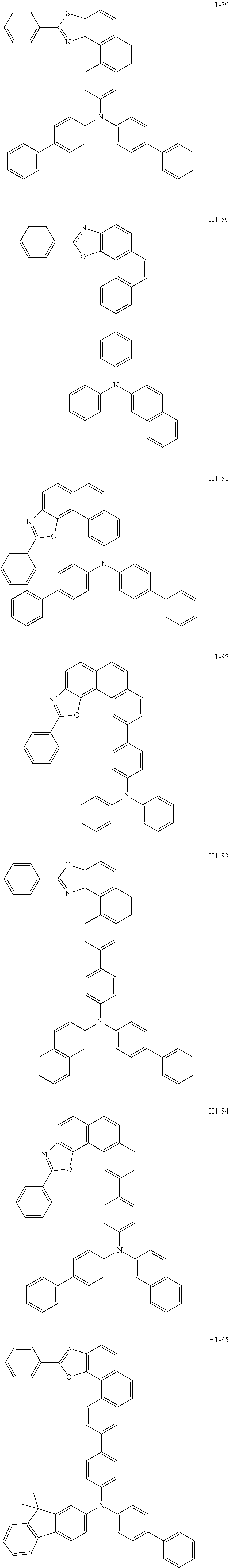

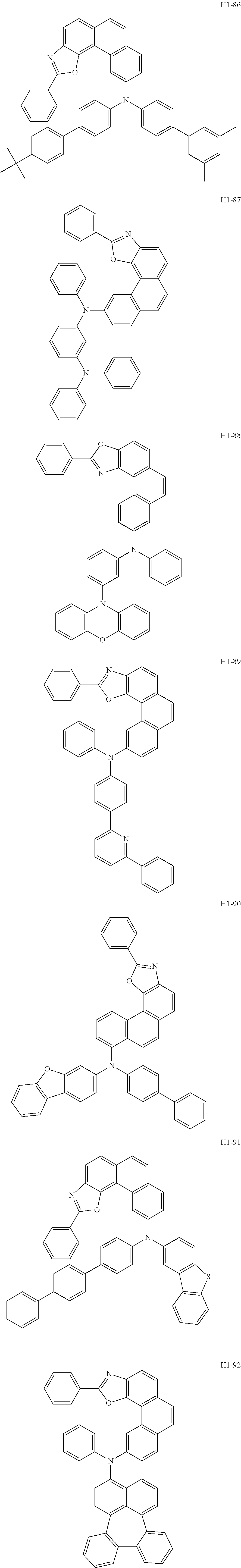

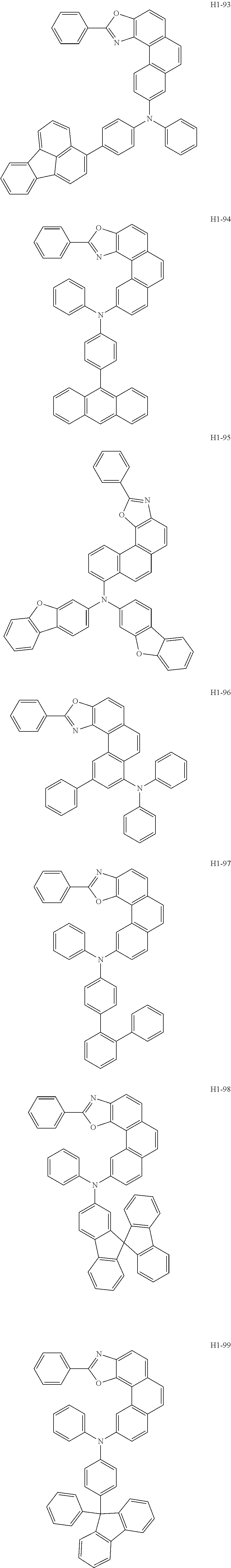

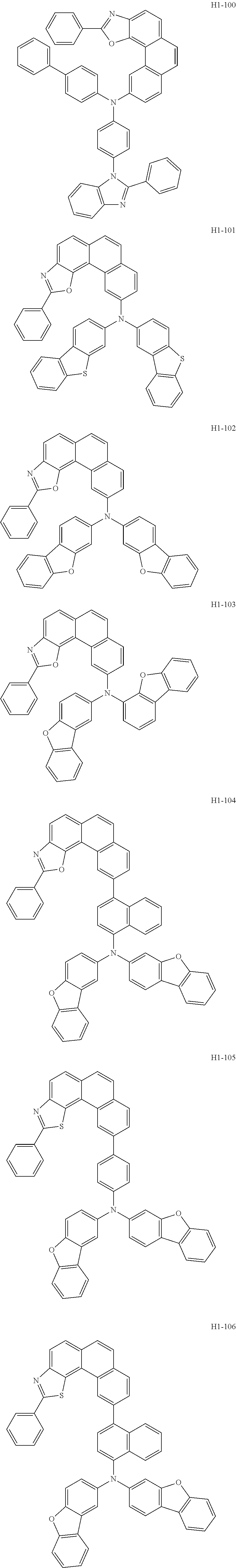

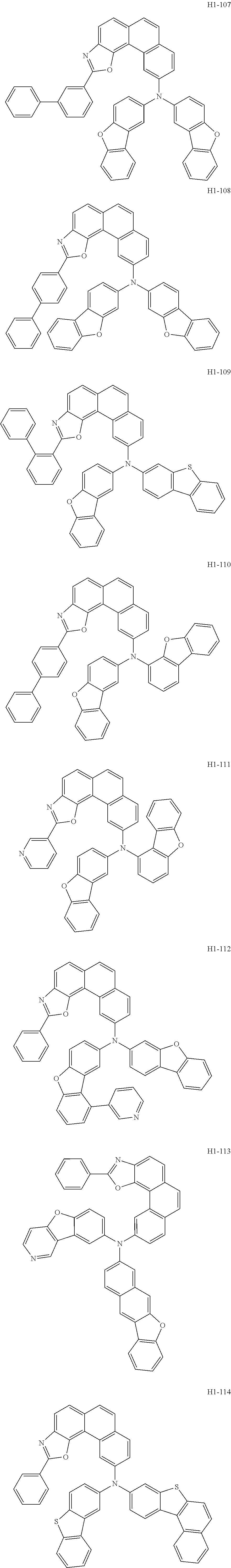

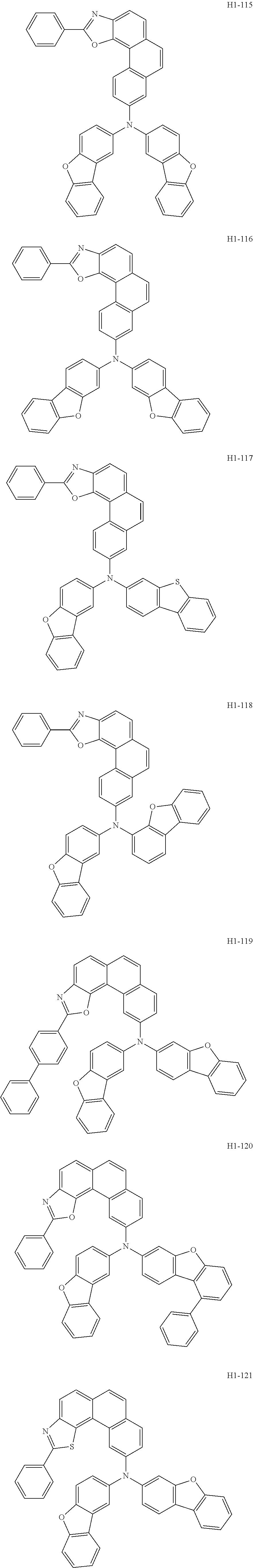

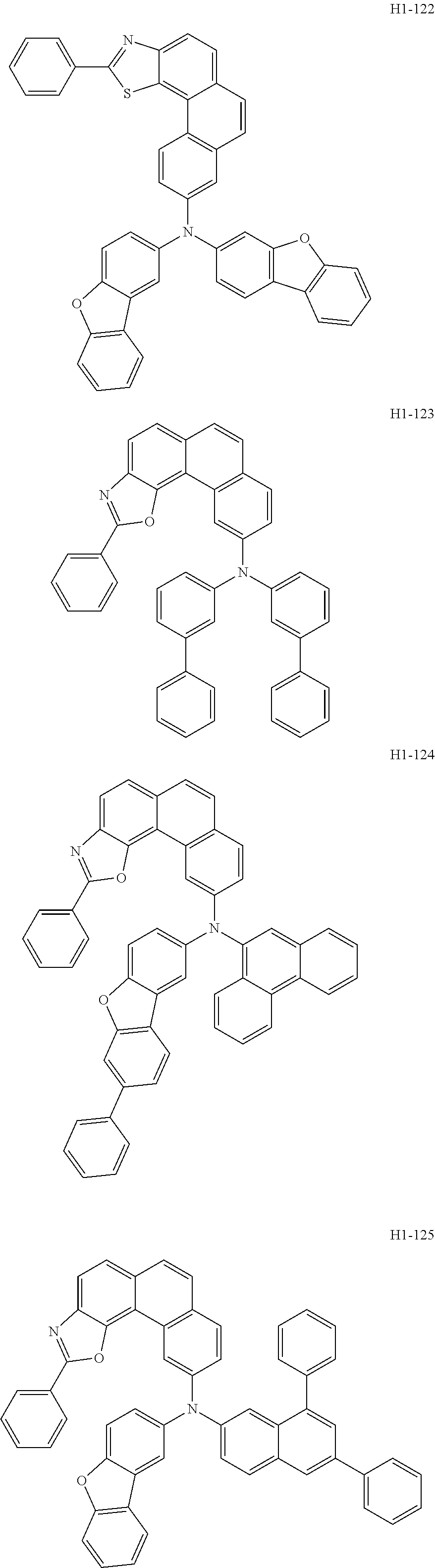

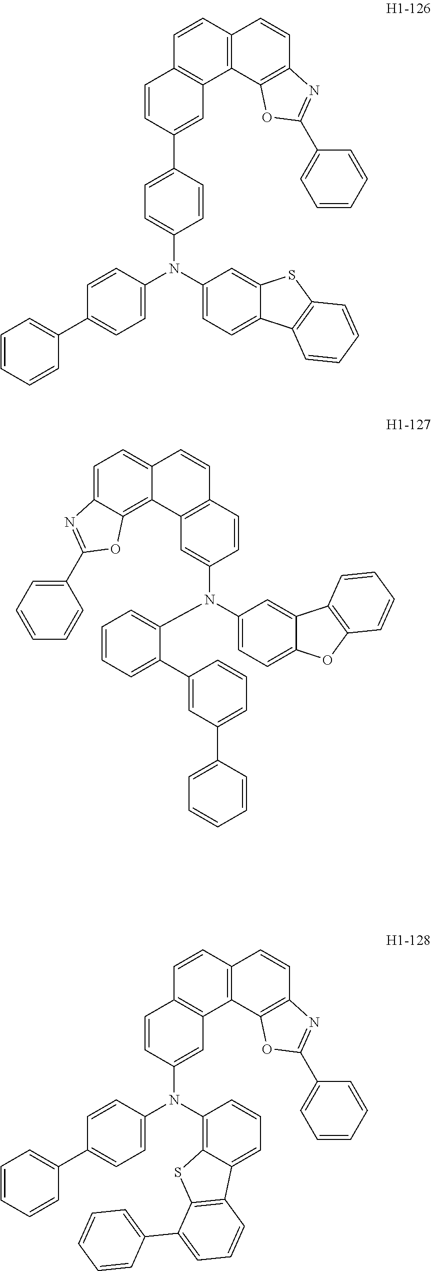 [SMILES: c1ccc(-c2ccc(N(c3ccc(-c4ccc5ccc6ccc7nc(-c8ccccc8)oc7c6c5c4)cc3)c3ccc4c(c3)sc3ccccc34)cc2)cc1 ; c1ccc(-c2cccc(-c3ccccc3N(c3ccc4oc5ccccc5c4c3)c3ccc4ccc5ccc6nc(-c7ccccc7)oc6c5c4c3)c2)cc1 ; c1ccc(-c2ccc(N(c3ccc4ccc5ccc6nc(-c7ccccc7)oc6c5c4c3)c3cccc4c3sc3c(-c5ccccc5)cccc34)cc2)cc1]

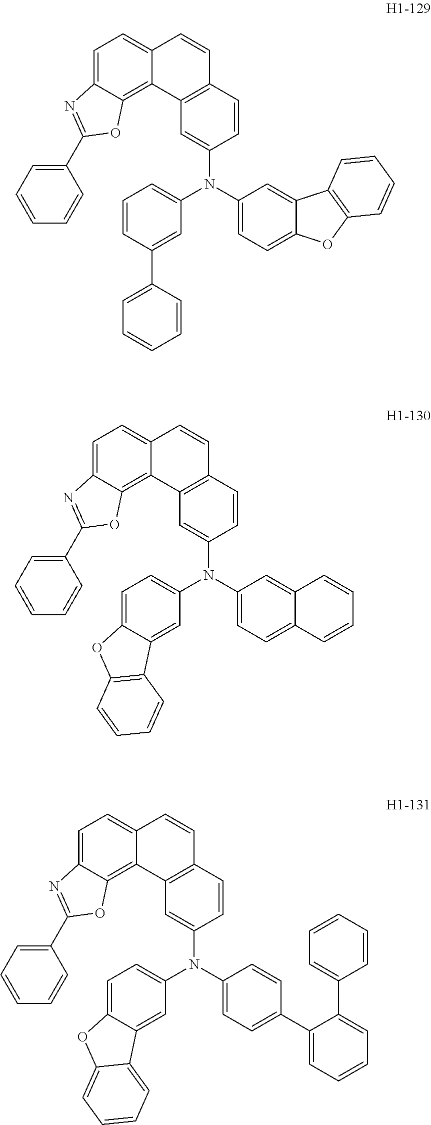 [SMILES: c1ccc(-c2cccc(N(c3ccc4oc5ccccc5c4c3)c3ccc4ccc5ccc6nc(-c7ccccc7)oc6c5c4c3)c2)cc1 ; c1ccc(-c2nc3ccc4ccc5ccc(N(c6ccc7ccccc7c6)c6ccc7oc8ccccc8c7c6)cc5c4c3o2)cc1 ; c1ccc(-c2nc3ccc4ccc5ccc(N(c6ccc(-c7ccccc7-c7ccccc7)cc6)c6ccc7oc8ccccc8c7c6)cc5c4c3o2)cc1]

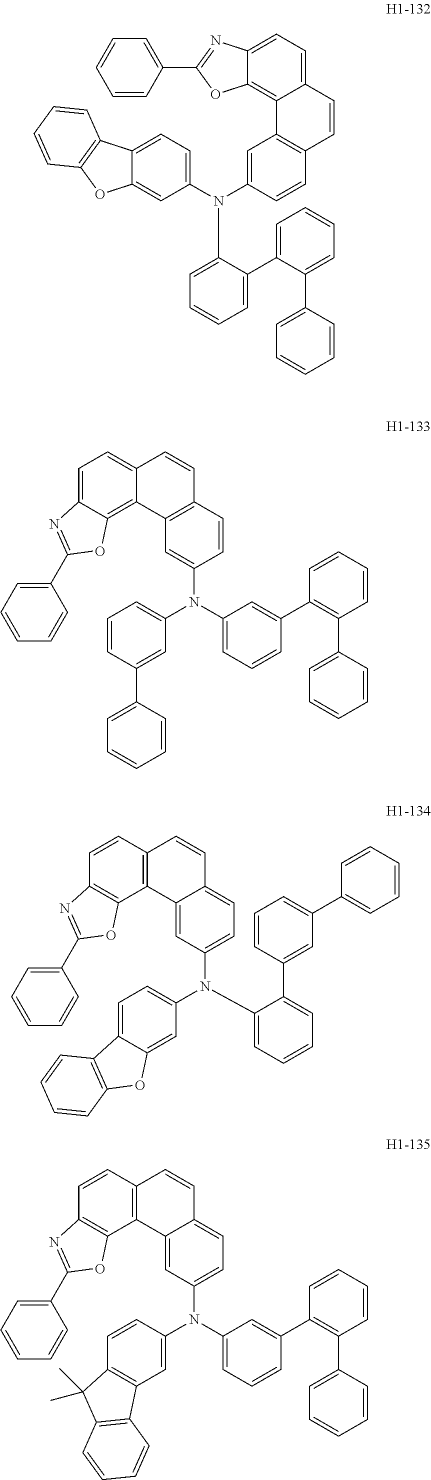 [SMILES: c1ccc(-c2nc3ccc4ccc5ccc(N(c6ccc7c(c6)oc6ccccc67)c6ccccc6-c6ccccc6-c6ccccc6)cc5c4c3o2)cc1 ; c1ccc(-c2cccc(N(c3cccc(-c4ccccc4-c4ccccc4)c3)c3ccc4ccc5ccc6nc(-c7ccccc7)oc6c5c4c3)c2)cc1 ; c1ccc(-c2cccc(-c3ccccc3N(c3ccc4c(c3)oc3ccccc34)c3ccc4ccc5ccc6nc(-c7ccccc7)oc6c5c4c3)c2)cc1 ; CC1(C)c2ccccc2-c2cc(N(c3cccc(-c4ccccc4-c4ccccc4)c3)c3ccc4ccc5ccc6nc(-c7ccccc7)oc6c5c4c3)ccc21]

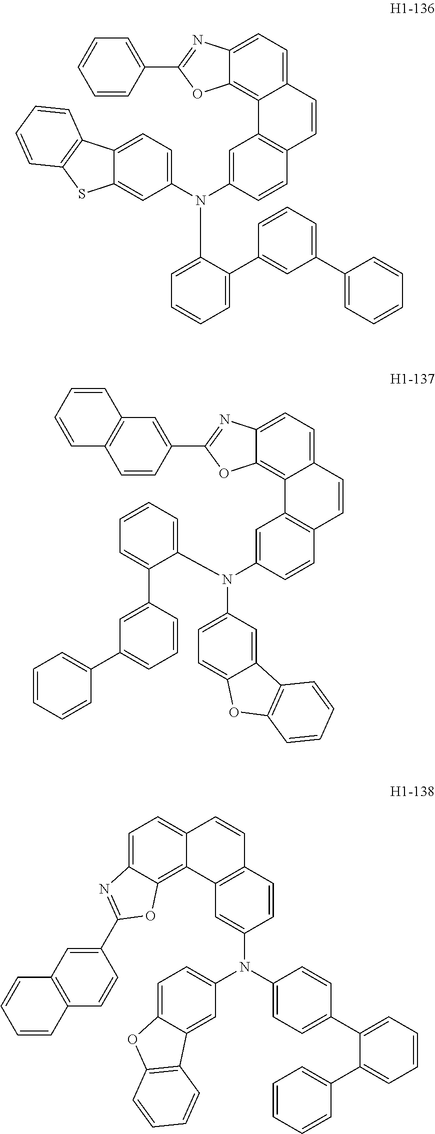 [SMILES: c1ccc(-c2cccc(-c3ccccc3N(c3ccc4c(c3)sc3ccccc34)c3ccc4ccc5ccc6nc(-c7ccccc7)oc6c5c4c3)c2)cc1 ; c1ccc(-c2cccc(-c3ccccc3N(c3ccc4oc5ccccc5c4c3)c3ccc4ccc5ccc6nc(-c7ccc8ccccc8c7)oc6c5c4c3)c2)cc1 ; c1ccc(-c2ccccc2-c2ccc(N(c3ccc4oc5ccccc5c4c3)c3ccc4ccc5ccc6nc(-c7ccc8ccccc8c7)oc6c5c4c3)cc2)cc1]

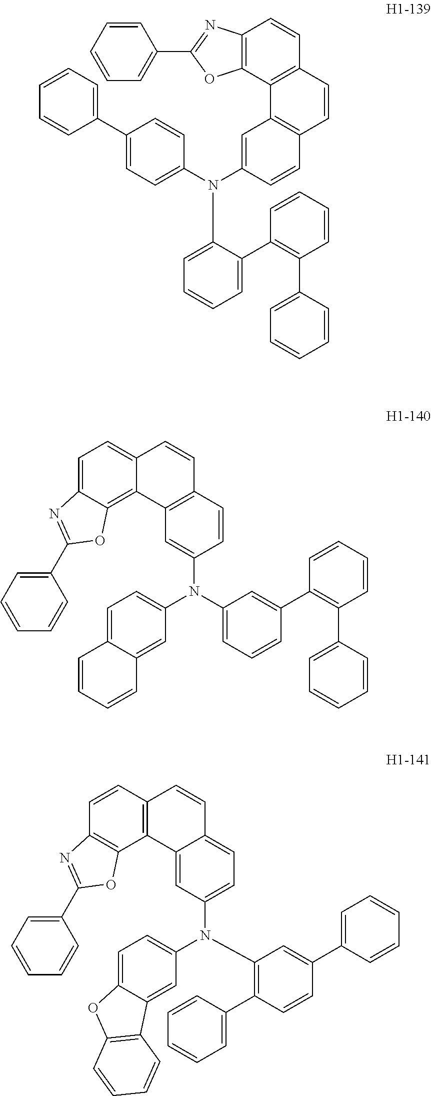 [SMILES: c1ccc(-c2ccc(N(c3ccc4ccc5ccc6nc(-c7ccccc7)oc6c5c4c3)c3ccccc3-c3ccccc3-c3ccccc3)cc2)cc1 ; c1ccc(-c2nc3ccc4ccc5ccc(N(c6cccc(-c7ccccc7-c7ccccc7)c6)c6ccc7ccccc7c6)cc5c4c3o2)cc1 ; c1ccc(-c2ccc(-c3ccccc3)c(N(c3ccc4oc5ccccc5c4c3)c3ccc4ccc5ccc6nc(-c7ccccc7)oc6c5c4c3)c2)cc1]

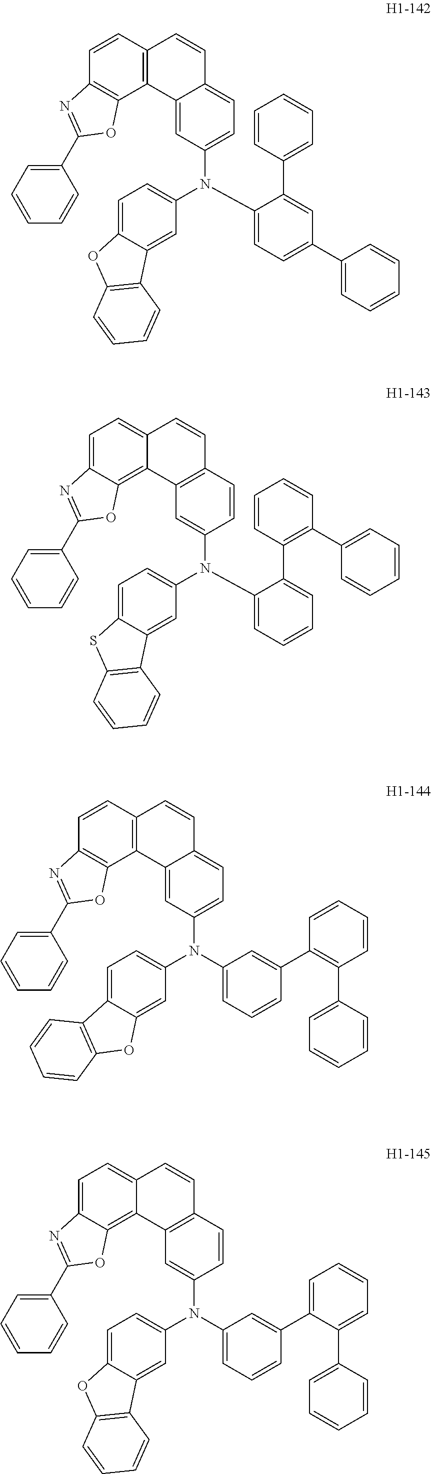 [SMILES: c1ccc(-c2ccc(N(c3ccc4oc5ccccc5c4c3)c3ccc4ccc5ccc6nc(-c7ccccc7)oc6c5c4c3)c(-c3ccccc3)c2)cc1 ; c1ccc(-c2nc3ccc4ccc5ccc(N(c6ccc7sc8ccccc8c7c6)c6ccccc6-c6ccccc6-c6ccccc6)cc5c4c3o2)cc1 ; c1ccc(-c2nc3ccc4ccc5ccc(N(c6cccc(-c7ccccc7-c7ccccc7)c6)c6ccc7c(c6)oc6ccccc67)cc5c4c3o2)cc1 ; c1ccc(-c2nc3ccc4ccc5ccc(N(c6cccc(-c7ccccc7-c7ccccc7)c6)c6ccc7oc8ccccc8c7c6)cc5c4c3o2)cc1]

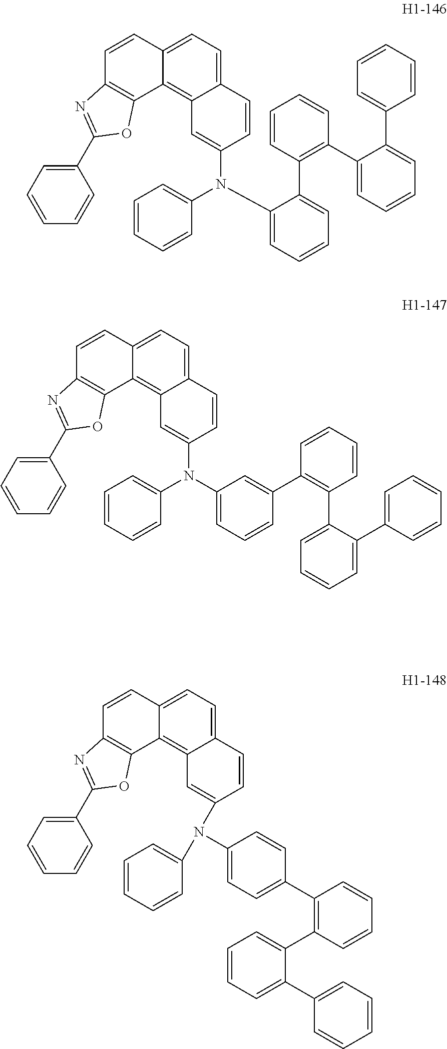 [SMILES: c1ccc(-c2nc3ccc4ccc5ccc(N(c6ccccc6)c6ccccc6-c6ccccc6-c6ccccc6-c6ccccc6)cc5c4c3o2)cc1 ; c1ccc(-c2nc3ccc4ccc5ccc(N(c6ccccc6)c6cccc(-c7ccccc7-c7ccccc7-c7ccccc7)c6)cc5c4c3o2)cc1 ; c1ccc(-c2nc3ccc4ccc5ccc(N(c6ccccc6)c6ccc(-c7ccccc7-c7ccccc7-c7ccccc7)cc6)cc5c4c3o2)cc1]

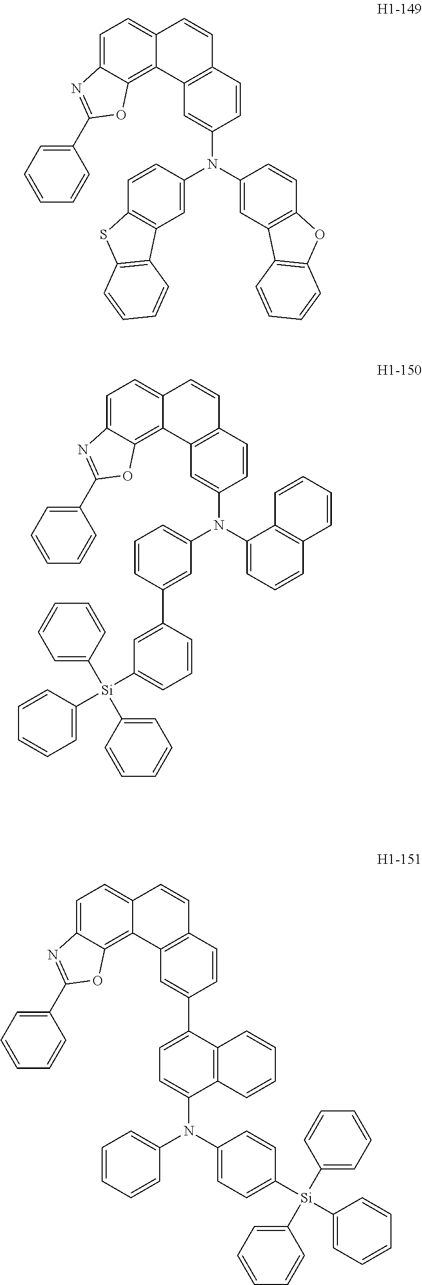 [SMILES: c1ccc(-c2nc3ccc4ccc5ccc(N(c6ccc7oc8ccccc8c7c6)c6ccc7sc8ccccc8c7c6)cc5c4c3o2)cc1 ; c1ccc(-c2nc3ccc4ccc5ccc(N(c6cccc(-c7cccc([Si](c8ccccc8)(c8ccccc8)c8ccccc8)c7)c6)c6cccc7ccccc67)cc5c4c3o2)cc1 ; c1ccc(-c2nc3ccc4ccc5ccc(-c6ccc(N(c7ccccc7)c7ccc([Si](c8ccccc8)(c8ccccc8)c8ccccc8)cc7)c7ccccc67)cc5c4c3o2)cc1]

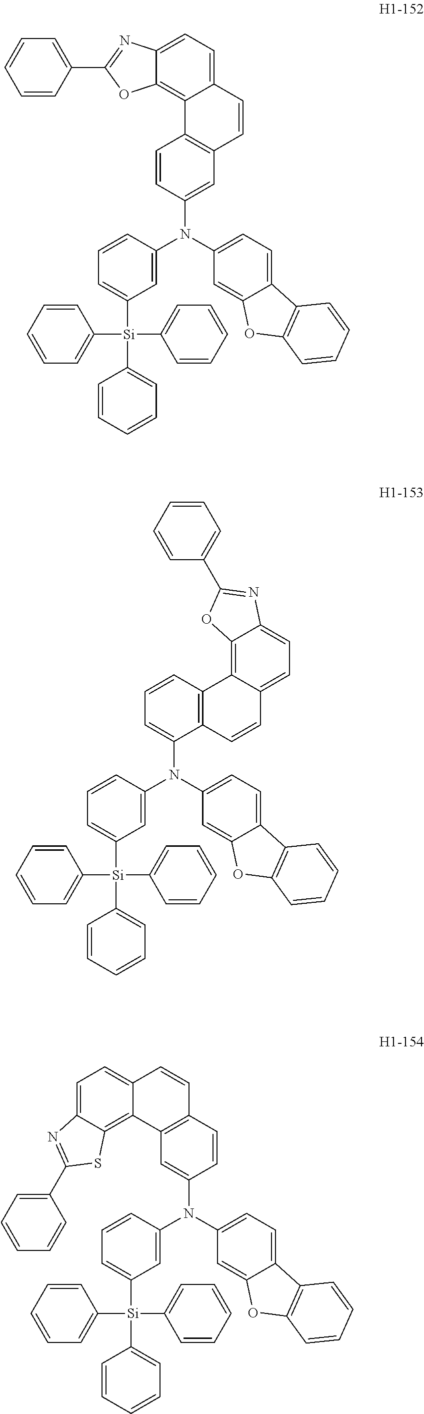 [SMILES: c1ccc(-c2nc3ccc4ccc5cc(N(c6cccc([Si](c7ccccc7)(c7ccccc7)c7ccccc7)c6)c6ccc7c(c6)oc6ccccc67)ccc5c4c3o2)cc1 ; c1ccc(-c2nc3ccc4ccc5c(N(c6cccc([Si](c7ccccc7)(c7ccccc7)c7ccccc7)c6)c6ccc7c(c6)oc6ccccc67)cccc5c4c3o2)cc1 ; c1ccc(-c2nc3ccc4ccc5ccc(N(c6cccc([Si](c7ccccc7)(c7ccccc7)c7ccccc7)c6)c6ccc7c(c6)oc6ccccc67)cc5c4c3s2)cc1]

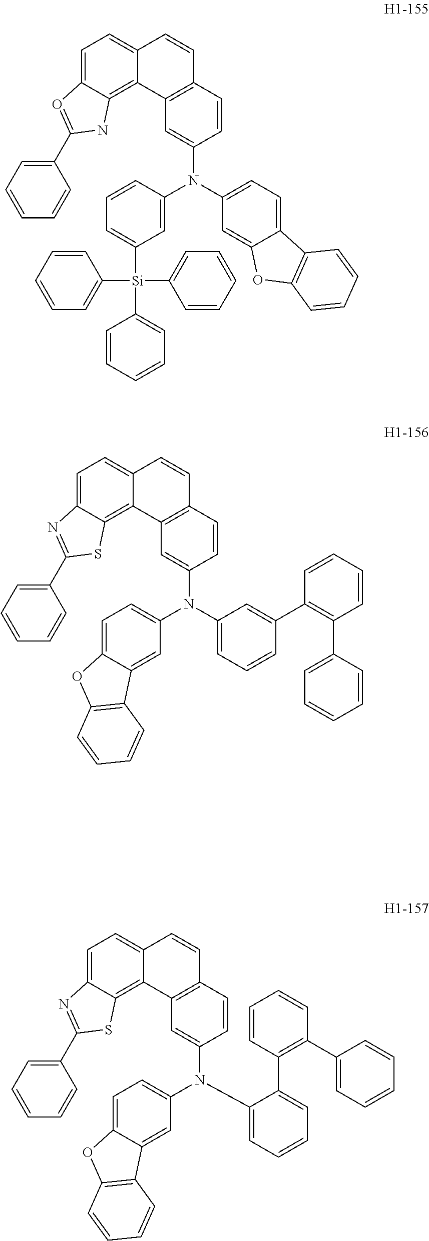

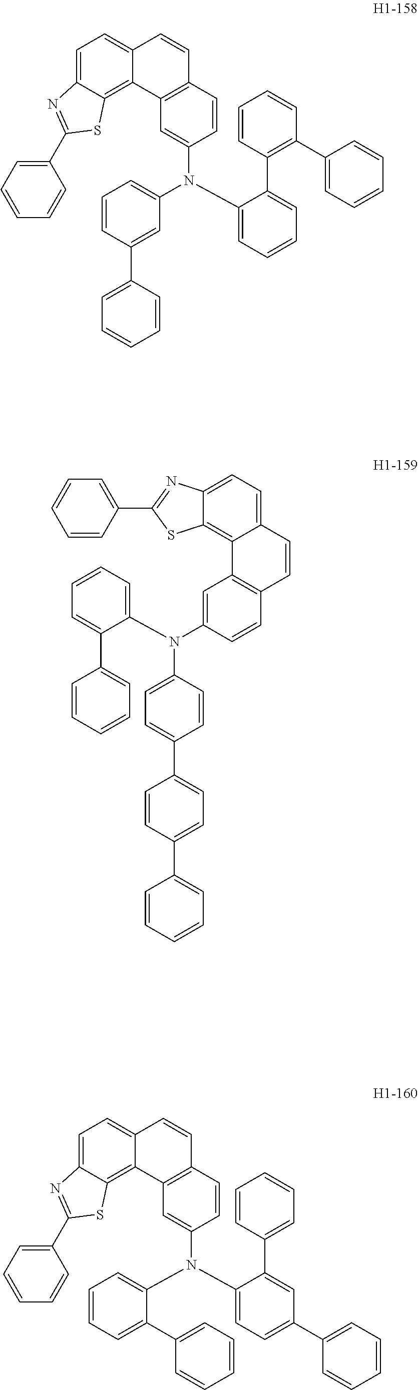 [SMILES: c1ccc(-c2cccc(N(c3ccc4ccc5ccc6nc(-c7ccccc7)sc6c5c4c3)c3ccccc3-c3ccccc3-c3ccccc3)c2)cc1 ; c1ccc(-c2ccc(-c3ccc(N(c4ccc5ccc6ccc7nc(-c8ccccc8)sc7c6c5c4)c4ccccc4-c4ccccc4)cc3)cc2)cc1 ; c1ccc(-c2ccc(N(c3ccc4ccc5ccc6nc(-c7ccccc7)sc6c5c4c3)c3ccccc3-c3ccccc3)c(-c3ccccc3)c2)cc1]

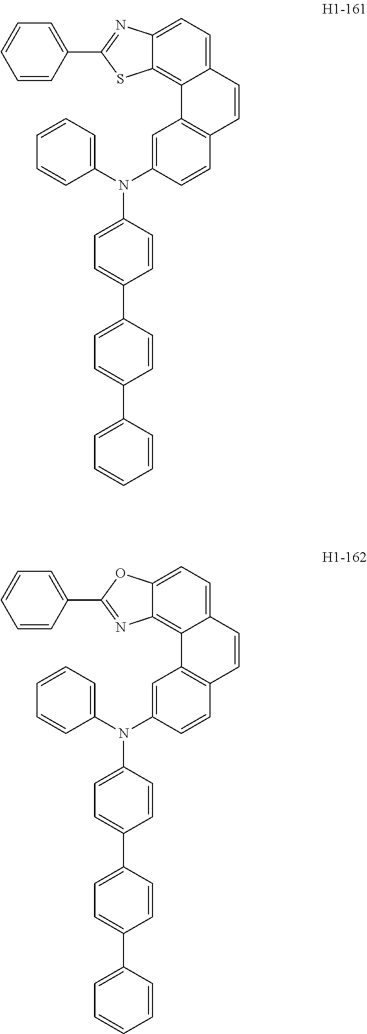 [SMILES: c1ccc(-c2ccc(-c3ccc(N(c4ccccc4)c4ccc5ccc6ccc7nc(-c8ccccc8)sc7c6c5c4)cc3)cc2)cc1 ; c1ccc(-c2ccc(-c3ccc(N(c4ccccc4)c4ccc5ccc6ccc7oc(-c8ccccc8)nc7c6c5c4)cc3)cc2)cc1]

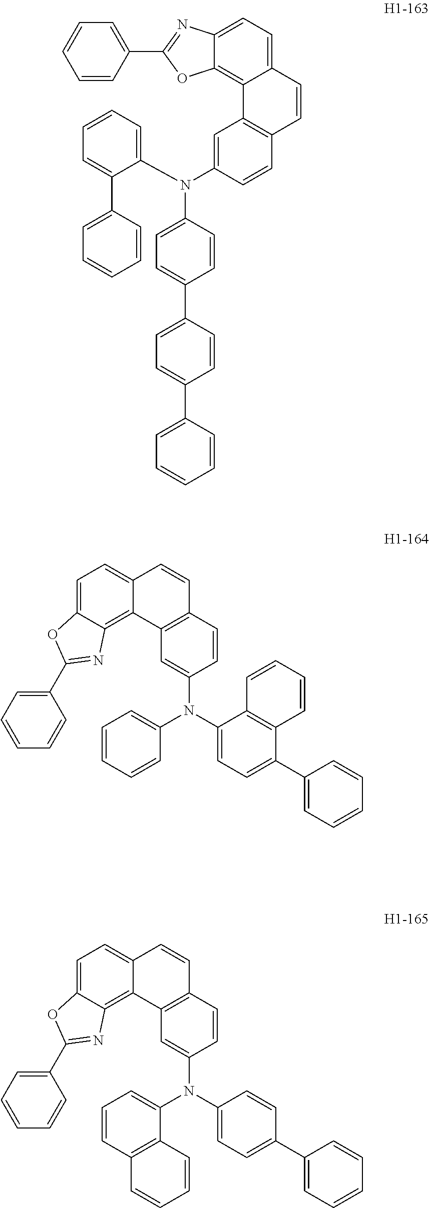 [SMILES: c1ccc(-c2ccc(-c3ccc(N(c4ccc5ccc6ccc7nc(-c8ccccc8)oc7c6c5c4)c4ccccc4-c4ccccc4)cc3)cc2)cc1 ; c1ccc(-c2nc3c(ccc4ccc5ccc(N(c6ccccc6)c6ccc(-c7ccccc7)c7ccccc67)cc5c43)o2)cc1 ; c1ccc(-c2ccc(N(c3ccc4ccc5ccc6oc(-c7ccccc7)nc6c5c4c3)c3cccc4ccccc34)cc2)cc1]

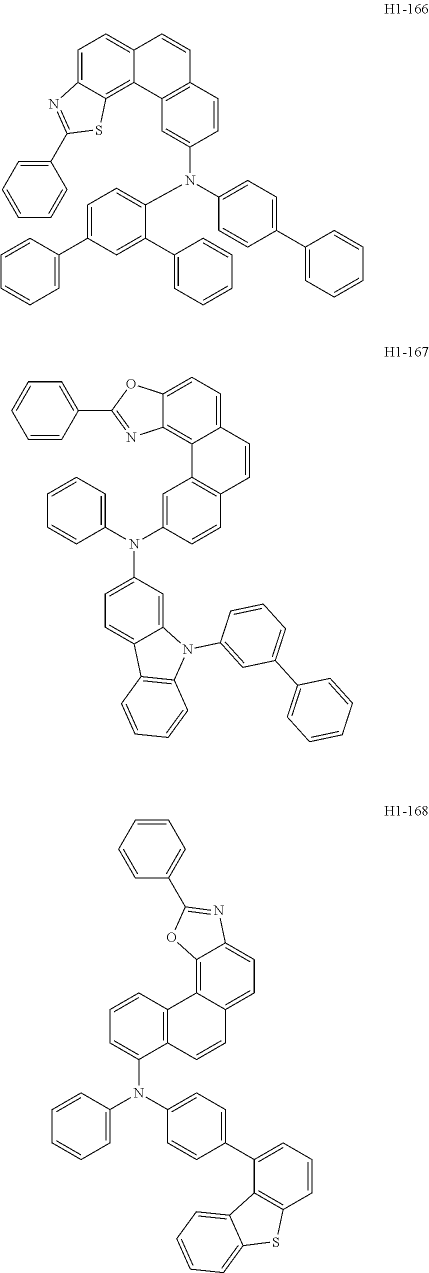 [SMILES: c1ccc(-c2ccc(N(c3ccc4ccc5ccc6nc(-c7ccccc7)sc6c5c4c3)c3ccc(-c4ccccc4)cc3-c3ccccc3)cc2)cc1 ; c1ccc(-c2cccc(-n3c4ccccc4c4ccc(N(c5ccccc5)c5ccc6ccc7ccc8oc(-c9ccccc9)nc8c7c6c5)cc43)c2)cc1 ; c1ccc(-c2nc3ccc4ccc5c(N(c6ccccc6)c6ccc(-c7cccc8sc9ccccc9c78)cc6)cccc5c4c3o2)cc1]

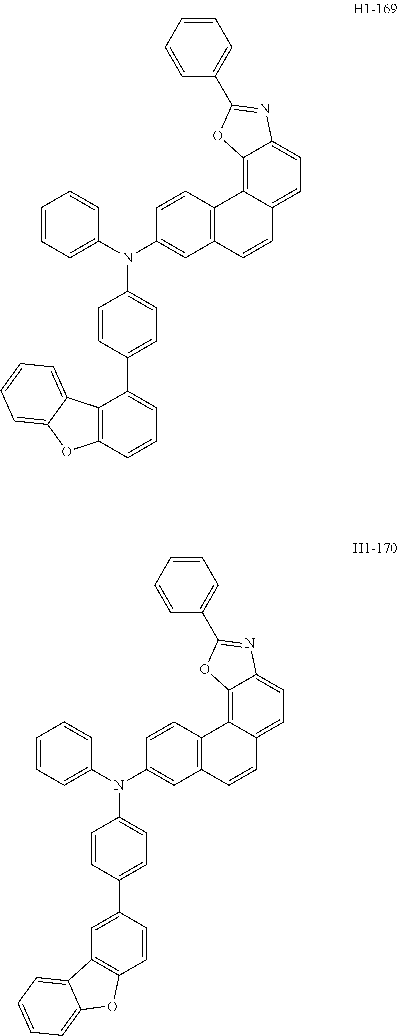 [SMILES: c1ccc(-c2nc3ccc4ccc5cc(N(c6ccccc6)c6ccc(-c7cccc8oc9ccccc9c78)cc6)ccc5c4c3o2)cc1 ; c1ccc(-c2nc3ccc4ccc5cc(N(c6ccccc6)c6ccc(-c7ccc8oc9ccccc9c8c7)cc6)ccc5c4c3o2)cc1]

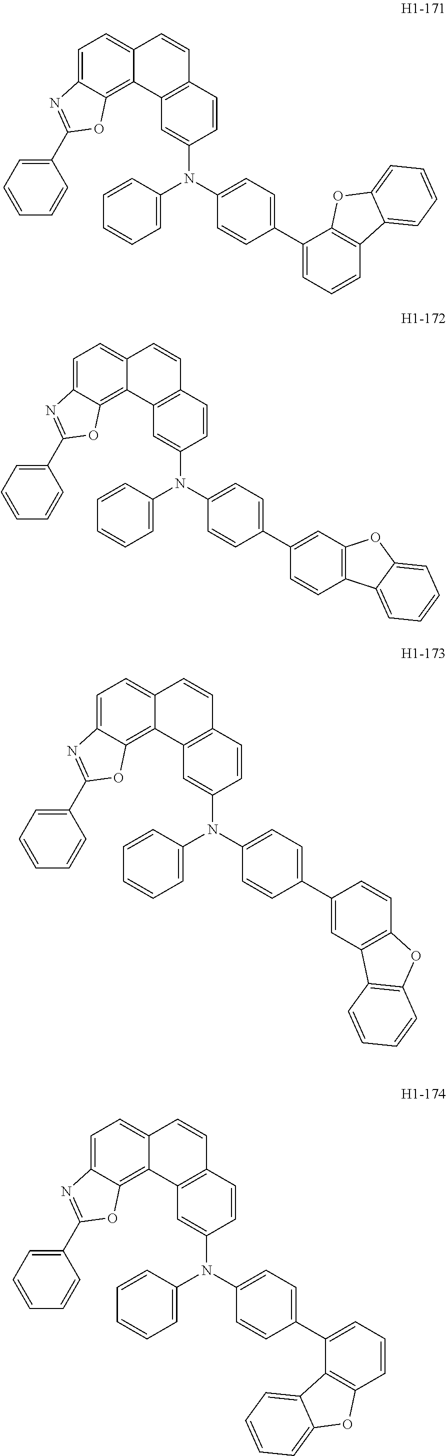 [SMILES: c1ccc(-c2nc3ccc4ccc5ccc(N(c6ccccc6)c6ccc(-c7cccc8c7oc7ccccc78)cc6)cc5c4c3o2)cc1 ; c1ccc(-c2nc3ccc4ccc5ccc(N(c6ccccc6)c6ccc(-c7ccc8c(c7)oc7ccccc78)cc6)cc5c4c3o2)cc1 ; c1ccc(-c2nc3ccc4ccc5ccc(N(c6ccccc6)c6ccc(-c7ccc8oc9ccccc9c8c7)cc6)cc5c4c3o2)cc1 ; c1ccc(-c2nc3ccc4ccc5ccc(N(c6ccccc6)c6ccc(-c7cccc8oc9ccccc9c78)cc6)cc5c4c3o2)cc1]

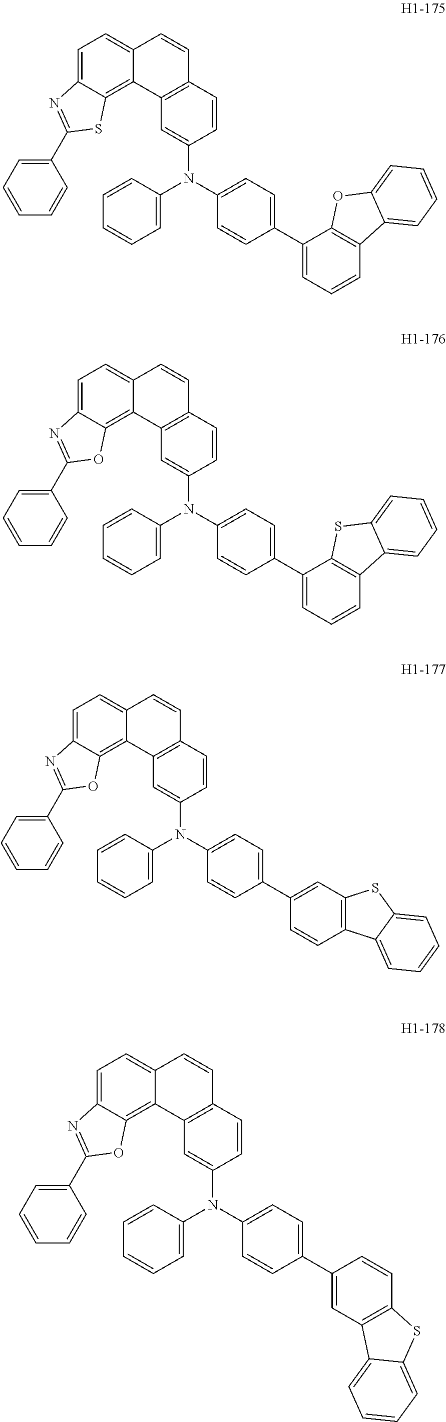 [SMILES: c1ccc(-c2nc3ccc4ccc5ccc(N(c6ccccc6)c6ccc(-c7cccc8c7oc7ccccc78)cc6)cc5c4c3s2)cc1 ; c1ccc(-c2nc3ccc4ccc5ccc(N(c6ccccc6)c6ccc(-c7cccc8c7sc7ccccc78)cc6)cc5c4c3o2)cc1 ; c1ccc(-c2nc3ccc4ccc5ccc(N(c6ccccc6)c6ccc(-c7ccc8c(c7)sc7ccccc78)cc6)cc5c4c3o2)cc1 ; c1ccc(-c2nc3ccc4ccc5ccc(N(c6ccccc6)c6ccc(-c7ccc8sc9ccccc9c8c7)cc6)cc5c4c3o2)cc1]

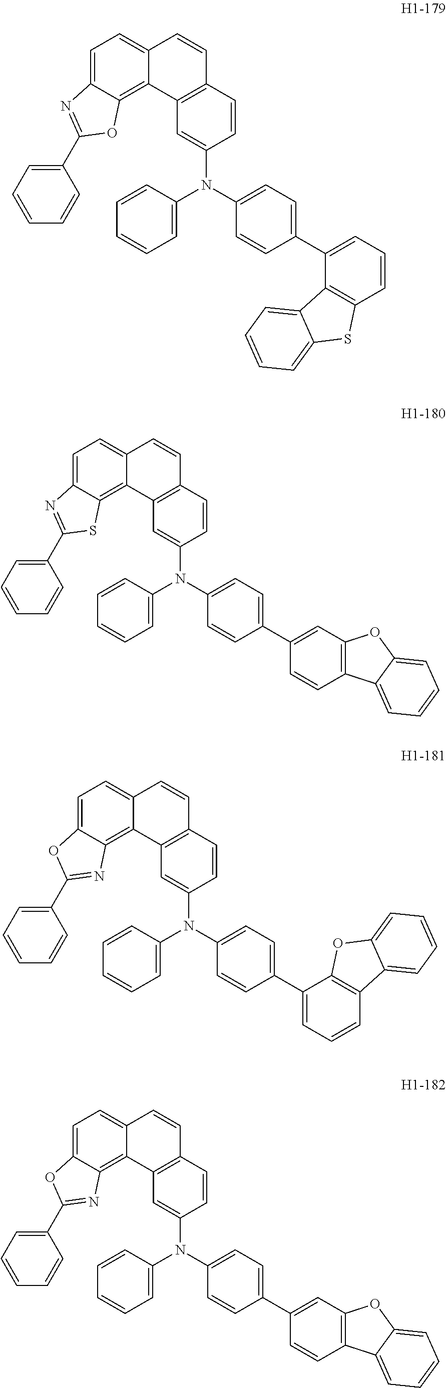 [SMILES: c1ccc(-c2nc3ccc4ccc5ccc(N(c6ccccc6)c6ccc(-c7cccc8sc9ccccc9c78)cc6)cc5c4c3o2)cc1 ; c1ccc(-c2nc3ccc4ccc5ccc(N(c6ccccc6)c6ccc(-c7ccc8c(c7)oc7ccccc78)cc6)cc5c4c3s2)cc1 ; c1ccc(-c2nc3c(ccc4ccc5ccc(N(c6ccccc6)c6ccc(-c7cccc8c7oc7ccccc78)cc6)cc5c43)o2)cc1 ; c1ccc(-c2nc3c(ccc4ccc5ccc(N(c6ccccc6)c6ccc(-c7ccc8c(c7)oc7ccccc78)cc6)cc5c43)o2)cc1]

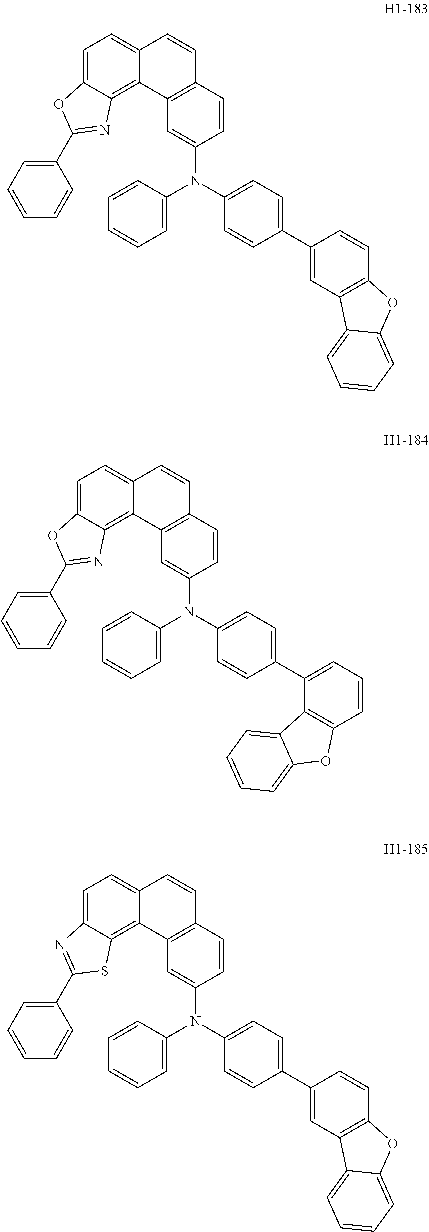 [SMILES: c1ccc(-c2nc3c(ccc4ccc5ccc(N(c6ccccc6)c6ccc(-c7ccc8oc9ccccc9c8c7)cc6)cc5c43)o2)cc1 ; c1ccc(-c2nc3c(ccc4ccc5ccc(N(c6ccccc6)c6ccc(-c7cccc8oc9ccccc9c78)cc6)cc5c43)o2)cc1 ; c1ccc(-c2nc3ccc4ccc5ccc(N(c6ccccc6)c6ccc(-c7ccc8oc9ccccc9c8c7)cc6)cc5c4c3s2)cc1]

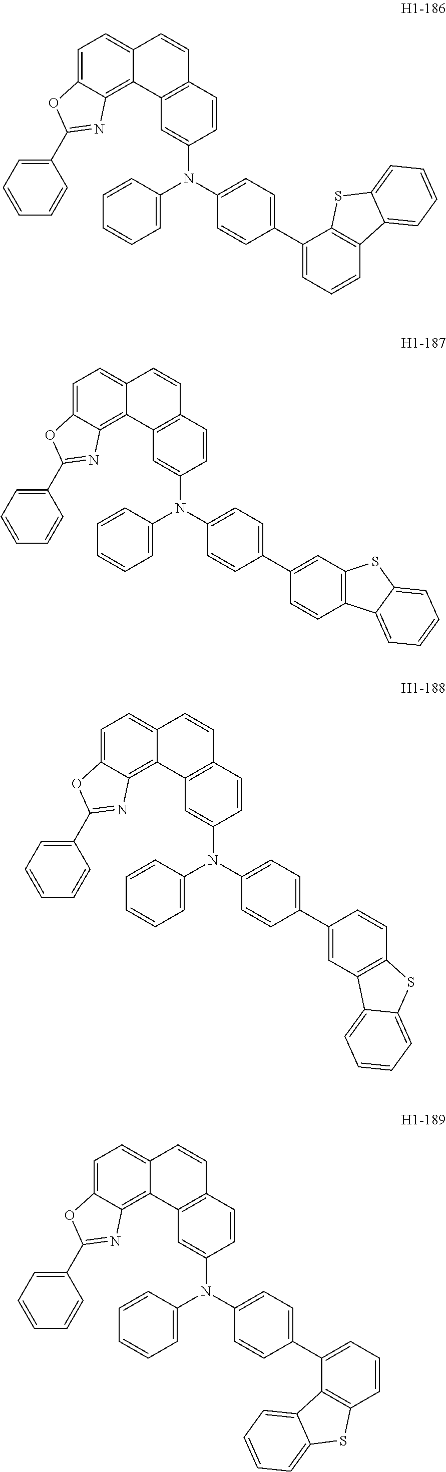 [SMILES: c1ccc(-c2nc3c(ccc4ccc5ccc(N(c6ccccc6)c6ccc(-c7cccc8c7sc7ccccc78)cc6)cc5c43)o2)cc1 ; c1ccc(-c2nc3c(ccc4ccc5ccc(N(c6ccccc6)c6ccc(-c7ccc8c(c7)sc7ccccc78)cc6)cc5c43)o2)cc1 ; c1ccc(-c2nc3c(ccc4ccc5ccc(N(c6ccccc6)c6ccc(-c7ccc8sc9ccccc9c8c7)cc6)cc5c43)o2)cc1 ; c1ccc(-c2nc3c(ccc4ccc5ccc(N(c6ccccc6)c6ccc(-c7cccc8sc9ccccc9c78)cc6)cc5c43)o2)cc1]

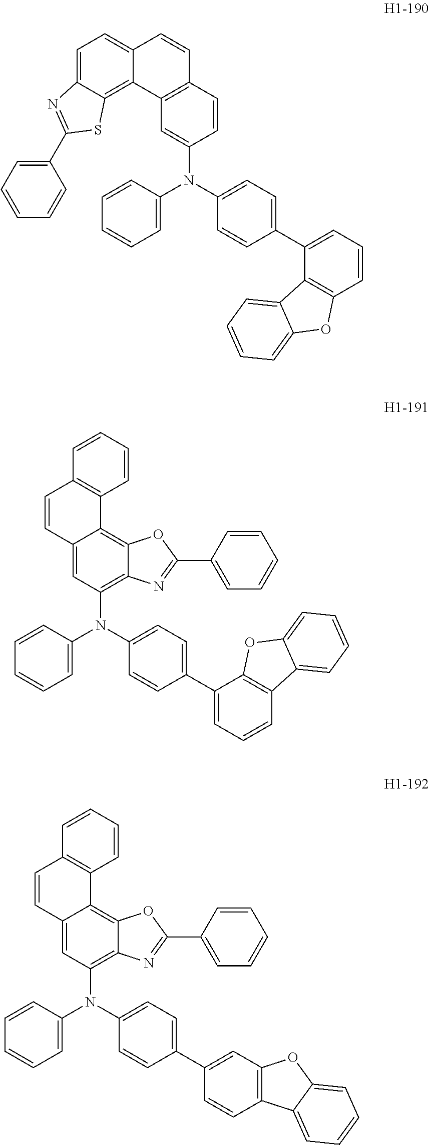 [SMILES: c1ccc(-c2nc3ccc4ccc5ccc(N(c6ccccc6)c6ccc(-c7cccc8oc9ccccc9c78)cc6)cc5c4c3s2)cc1 ; c1ccc(-c2nc3c(N(c4ccccc4)c4ccc(-c5cccc6c5oc5ccccc56)cc4)cc4ccc5ccccc5c4c3o2)cc1 ; c1ccc(-c2nc3c(N(c4ccccc4)c4ccc(-c5ccc6c(c5)oc5ccccc56)cc4)cc4ccc5ccccc5c4c3o2)cc1]

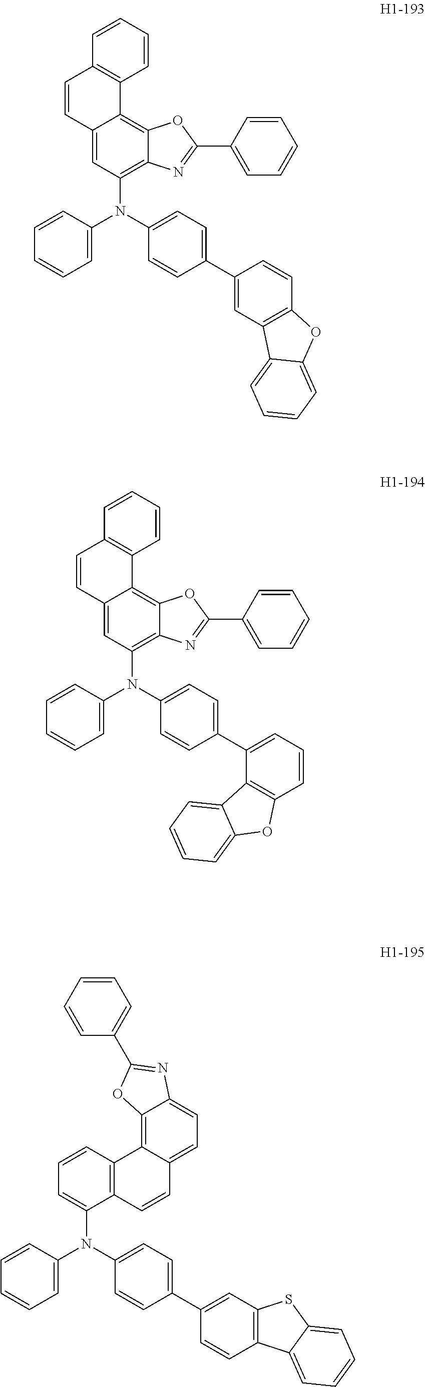 [SMILES: c1ccc(-c2nc3c(N(c4ccccc4)c4ccc(-c5ccc6oc7ccccc7c6c5)cc4)cc4ccc5ccccc5c4c3o2)cc1 ; c1ccc(-c2nc3c(N(c4ccccc4)c4ccc(-c5cccc6oc7ccccc7c56)cc4)cc4ccc5ccccc5c4c3o2)cc1 ; c1ccc(-c2nc3ccc4ccc5c(N(c6ccccc6)c6ccc(-c7ccc8c(c7)sc7ccccc78)cc6)cccc5c4c3o2)cc1]

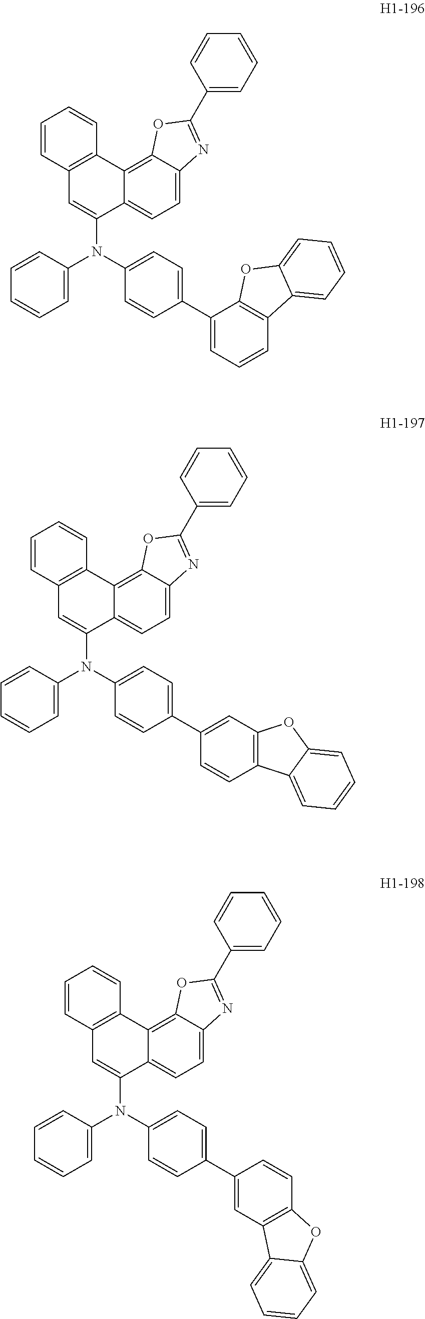 [SMILES: c1ccc(-c2nc3ccc4c(N(c5ccccc5)c5ccc(-c6cccc7c6oc6ccccc67)cc5)cc5ccccc5c4c3o2)cc1 ; c1ccc(-c2nc3ccc4c(N(c5ccccc5)c5ccc(-c6ccc7c(c6)oc6ccccc67)cc5)cc5ccccc5c4c3o2)cc1 ; c1ccc(-c2nc3ccc4c(N(c5ccccc5)c5ccc(-c6ccc7oc8ccccc8c7c6)cc5)cc5ccccc5c4c3o2)cc1]

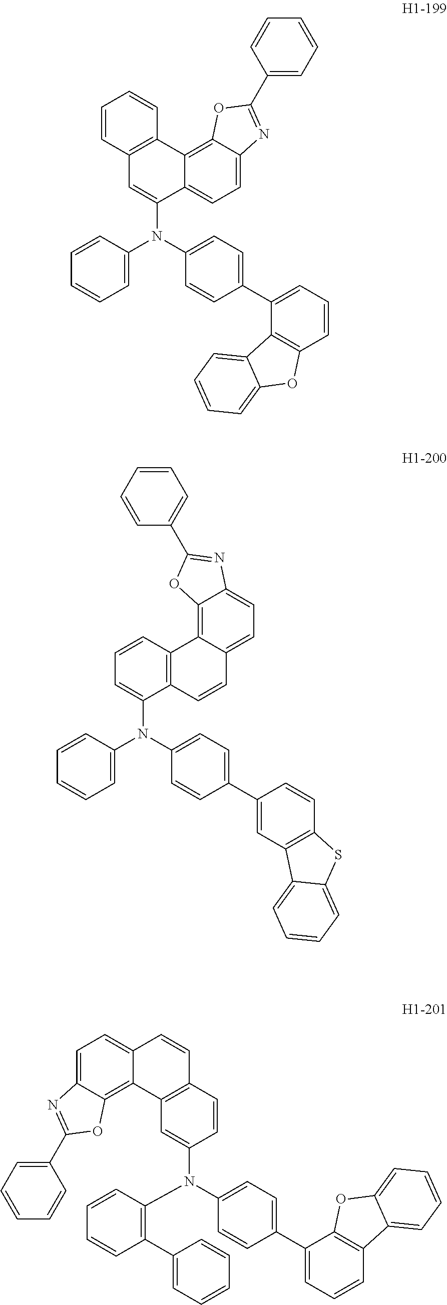 [SMILES: c1ccc(-c2nc3ccc4c(N(c5ccccc5)c5ccc(-c6cccc7oc8ccccc8c67)cc5)cc5ccccc5c4c3o2)cc1 ; c1ccc(-c2nc3ccc4ccc5c(N(c6ccccc6)c6ccc(-c7ccc8sc9ccccc9c8c7)cc6)cccc5c4c3o2)cc1 ; c1ccc(-c2nc3ccc4ccc5ccc(N(c6ccc(-c7cccc8c7oc7ccccc78)cc6)c6ccccc6-c6ccccc6)cc5c4c3o2)cc1]

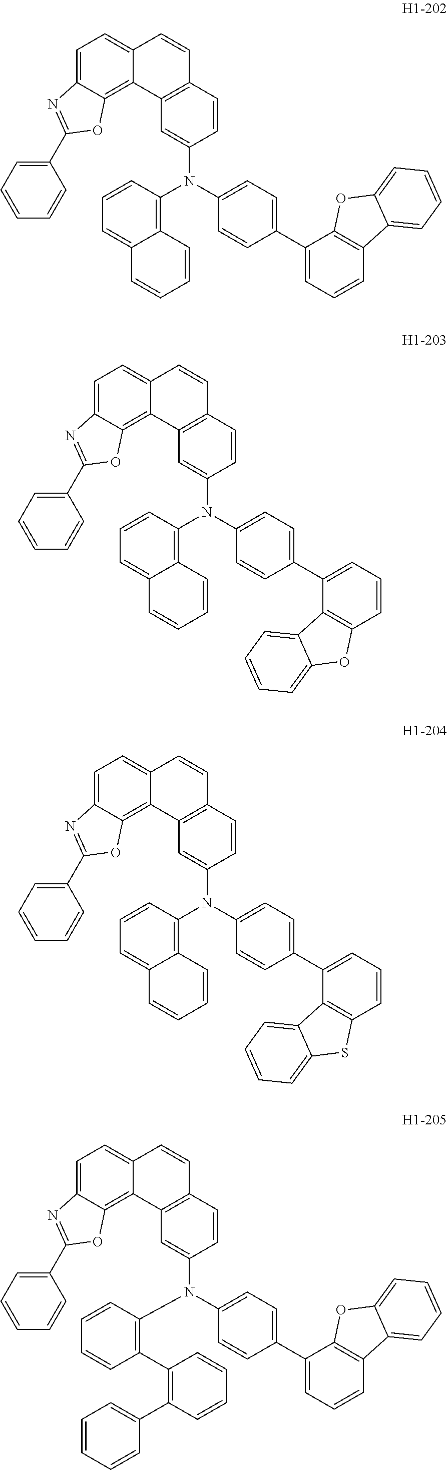 [SMILES: c1ccc(-c2nc3ccc4ccc5ccc(N(c6ccc(-c7cccc8c7oc7ccccc78)cc6)c6cccc7ccccc67)cc5c4c3o2)cc1 ; c1ccc(-c2nc3ccc4ccc5ccc(N(c6ccc(-c7cccc8oc9ccccc9c78)cc6)c6cccc7ccccc67)cc5c4c3o2)cc1 ; c1ccc(-c2nc3ccc4ccc5ccc(N(c6ccc(-c7cccc8sc9ccccc9c78)cc6)c6cccc7ccccc67)cc5c4c3o2)cc1 ; c1ccc(-c2nc3ccc4ccc5ccc(N(c6ccc(-c7cccc8c7oc7ccccc78)cc6)c6ccccc6-c6ccccc6-c6ccccc6)cc5c4c3o2)cc1]

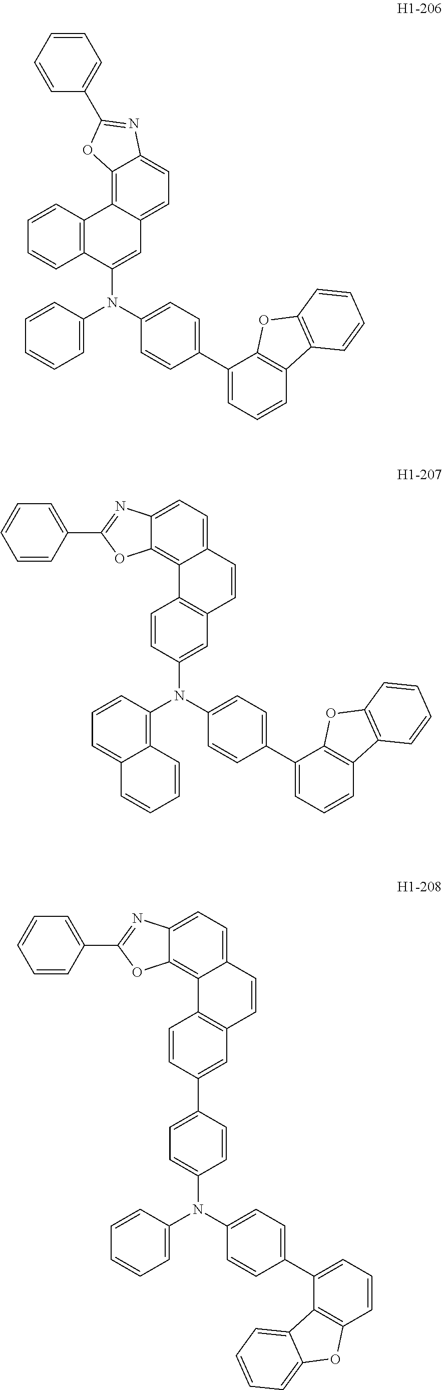 [SMILES: c1ccc(-c2nc3ccc4cc(N(c5ccccc5)c5ccc(-c6cccc7c6oc6ccccc67)cc5)c5ccccc5c4c3o2)cc1 ; c1ccc(-c2nc3ccc4ccc5cc(N(c6ccc(-c7cccc8c7oc7ccccc78)cc6)c6cccc7ccccc67)ccc5c4c3o2)cc1 ; c1ccc(-c2nc3ccc4ccc5cc(-c6ccc(N(c7ccccc7)c7ccc(-c8cccc9oc%10ccccc%10c89)cc7)cc6)ccc5c4c3o2)cc1]

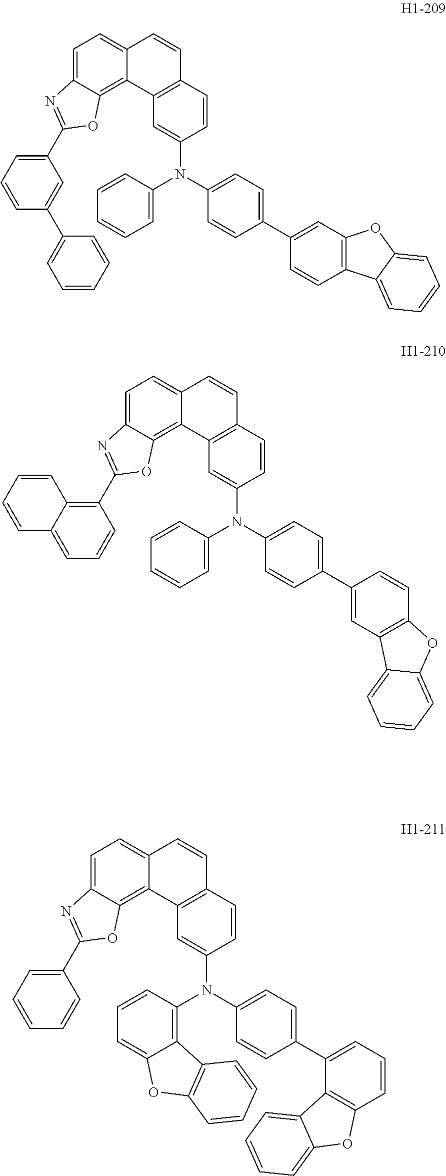 [SMILES: c1ccc(-c2cccc(-c3nc4ccc5ccc6ccc(N(c7ccccc7)c7ccc(-c8ccc9c(c8)oc8ccccc89)cc7)cc6c5c4o3)c2)cc1 ; c1ccc(N(c2ccc(-c3ccc4oc5ccccc5c4c3)cc2)c2ccc3ccc4ccc5nc(-c6cccc7ccccc67)oc5c4c3c2)cc1 ; c1ccc(-c2nc3ccc4ccc5ccc(N(c6ccc(-c7cccc8oc9ccccc9c78)cc6)c6cccc7oc8ccccc8c67)cc5c4c3o2)cc1]

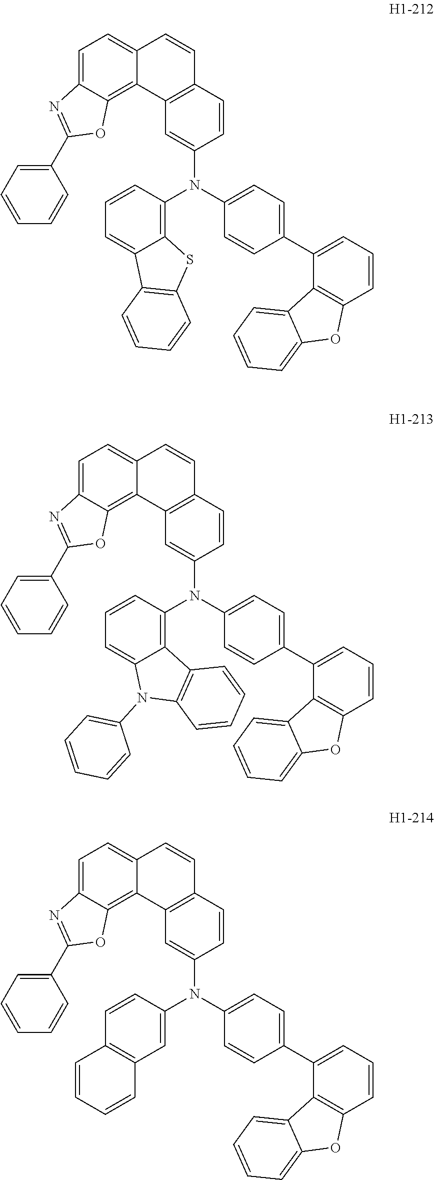 [SMILES: c1ccc(-c2nc3ccc4ccc5ccc(N(c6ccc(-c7cccc8oc9ccccc9c78)cc6)c6cccc7c6sc6ccccc67)cc5c4c3o2)cc1 ; c1ccc(-c2nc3ccc4ccc5ccc(N(c6ccc(-c7cccc8oc9ccccc9c78)cc6)c6cccc7c6c6ccccc6n7-c6ccccc6)cc5c4c3o2)cc1 ; c1ccc(-c2nc3ccc4ccc5ccc(N(c6ccc(-c7cccc8oc9ccccc9c78)cc6)c6ccc7ccccc7c6)cc5c4c3o2)cc1]

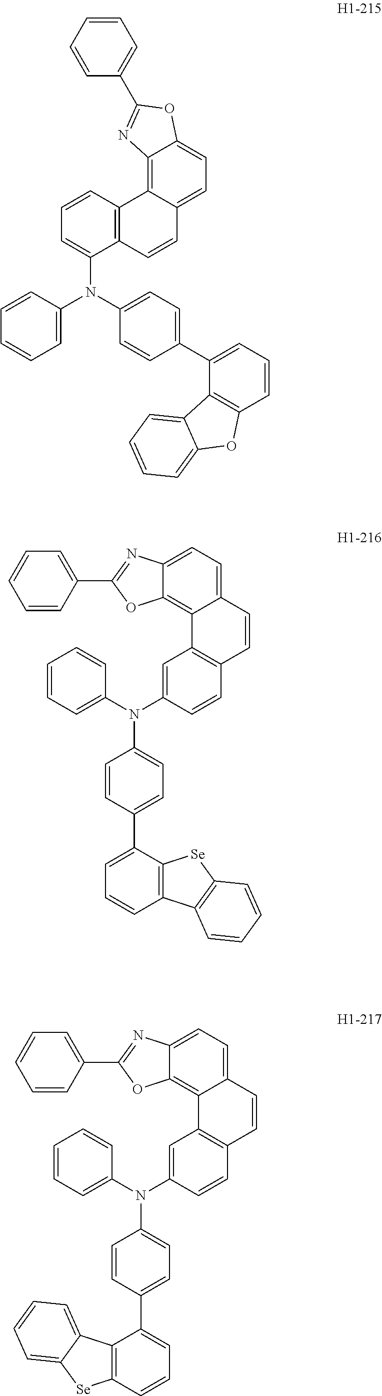 [SMILES: c1ccc(-c2nc3c(ccc4ccc5c(N(c6ccccc6)c6ccc(-c7cccc8oc9ccccc9c78)cc6)cccc5c43)o2)cc1 ; c1ccc(-c2nc3ccc4ccc5ccc(N(c6ccccc6)c6ccc(-c7cccc8c7[se]c7ccccc78)cc6)cc5c4c3o2)cc1 ; c1ccc(-c2nc3ccc4ccc5ccc(N(c6ccccc6)c6ccc(-c7cccc8[se]c9ccccc9c78)cc6)cc5c4c3o2)cc1]

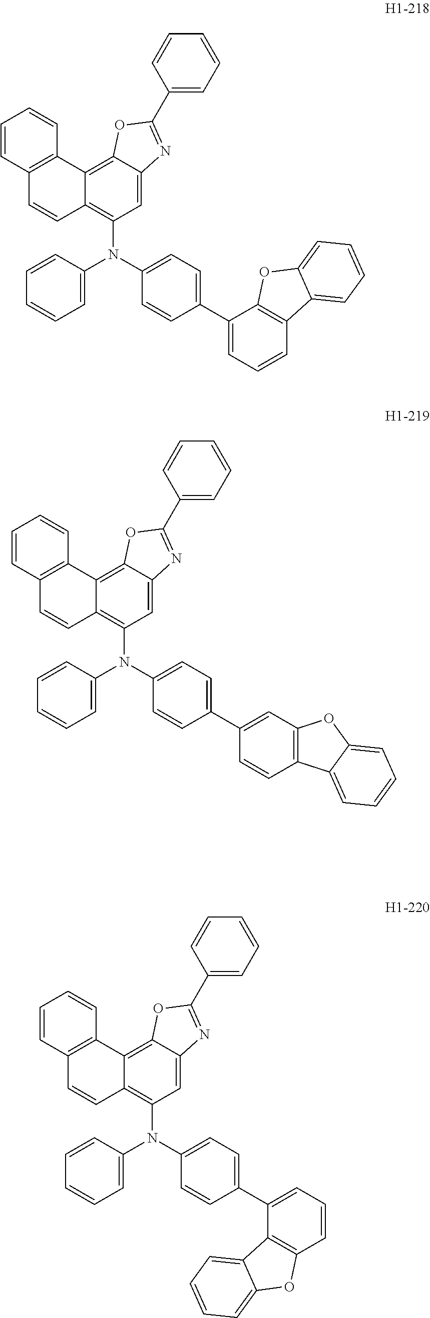 [SMILES: c1ccc(-c2nc3cc(N(c4ccccc4)c4ccc(-c5cccc6c5oc5ccccc56)cc4)c4ccc5ccccc5c4c3o2)cc1 ; c1ccc(-c2nc3cc(N(c4ccccc4)c4ccc(-c5ccc6c(c5)oc5ccccc56)cc4)c4ccc5ccccc5c4c3o2)cc1 ; c1ccc(-c2nc3cc(N(c4ccccc4)c4ccc(-c5cccc6oc7ccccc7c56)cc4)c4ccc5ccccc5c4c3o2)cc1]

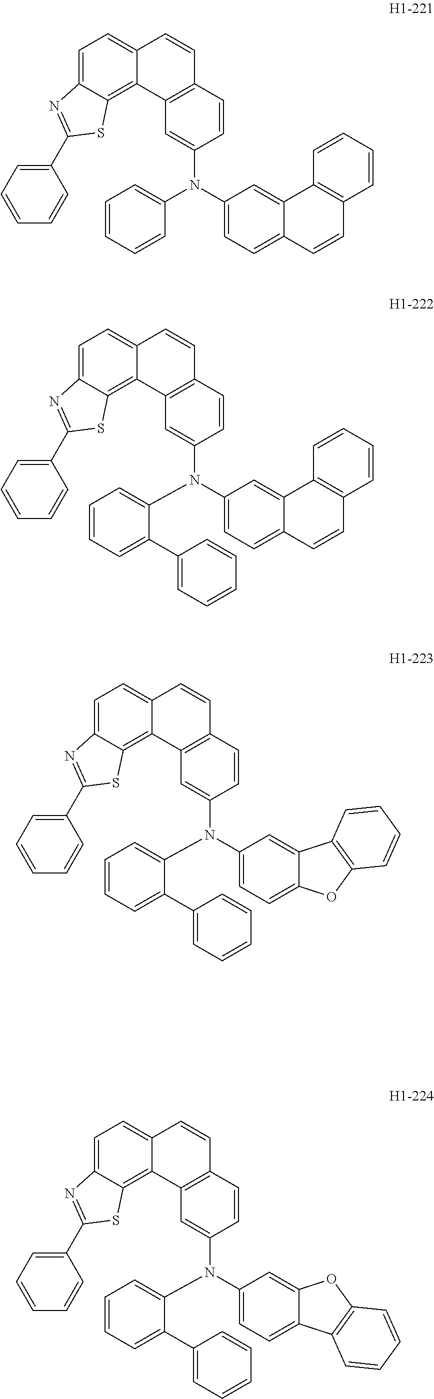 [SMILES: c1ccc(-c2nc3ccc4ccc5ccc(N(c6ccccc6)c6ccc7ccc8ccccc8c7c6)cc5c4c3s2)cc1 ; c1ccc(-c2nc3ccc4ccc5ccc(N(c6ccc7ccc8ccccc8c7c6)c6ccccc6-c6ccccc6)cc5c4c3s2)cc1 ; c1ccc(-c2nc3ccc4ccc5ccc(N(c6ccc7oc8ccccc8c7c6)c6ccccc6-c6ccccc6)cc5c4c3s2)cc1 ; c1ccc(-c2nc3ccc4ccc5ccc(N(c6ccc7c(c6)oc6ccccc67)c6ccccc6-c6ccccc6)cc5c4c3s2)cc1]

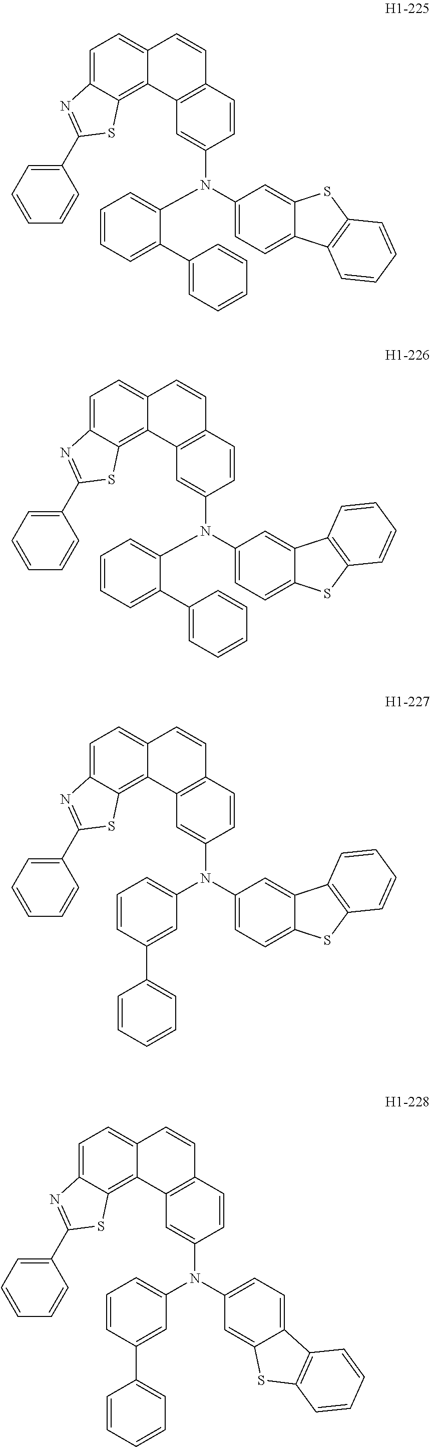 [SMILES: c1ccc(-c2nc3ccc4ccc5ccc(N(c6ccc7c(c6)sc6ccccc67)c6ccccc6-c6ccccc6)cc5c4c3s2)cc1 ; c1ccc(-c2nc3ccc4ccc5ccc(N(c6ccc7sc8ccccc8c7c6)c6ccccc6-c6ccccc6)cc5c4c3s2)cc1 ; c1ccc(-c2cccc(N(c3ccc4sc5ccccc5c4c3)c3ccc4ccc5ccc6nc(-c7ccccc7)sc6c5c4c3)c2)cc1 ; c1ccc(-c2cccc(N(c3ccc4c(c3)sc3ccccc34)c3ccc4ccc5ccc6nc(-c7ccccc7)sc6c5c4c3)c2)cc1]

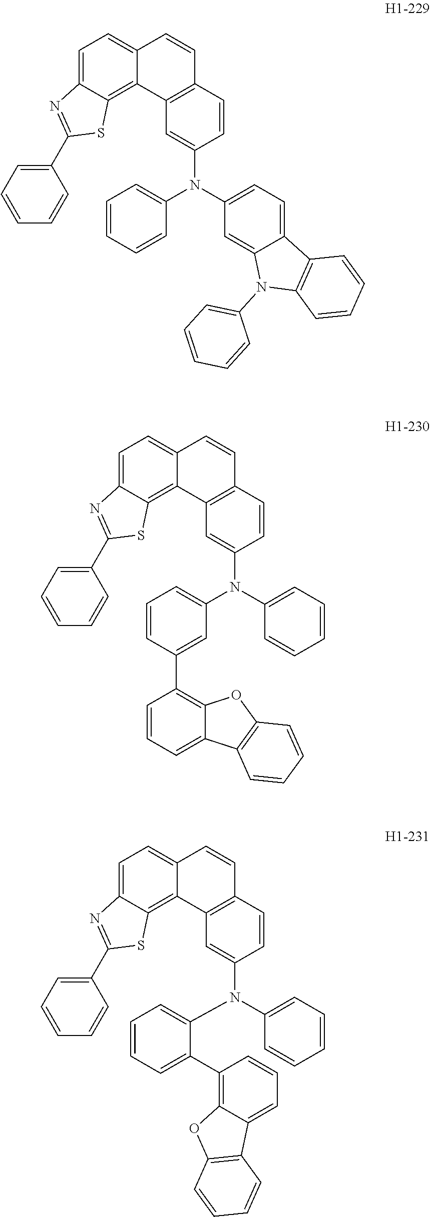 [SMILES: c1ccc(-c2nc3ccc4ccc5ccc(N(c6ccccc6)c6ccc7c8ccccc8n(-c8ccccc8)c7c6)cc5c4c3s2)cc1 ; c1ccc(-c2nc3ccc4ccc5ccc(N(c6ccccc6)c6cccc(-c7cccc8c7oc7ccccc78)c6)cc5c4c3s2)cc1 ; c1ccc(-c2nc3ccc4ccc5ccc(N(c6ccccc6)c6ccccc6-c6cccc7c6oc6ccccc67)cc5c4c3s2)cc1]

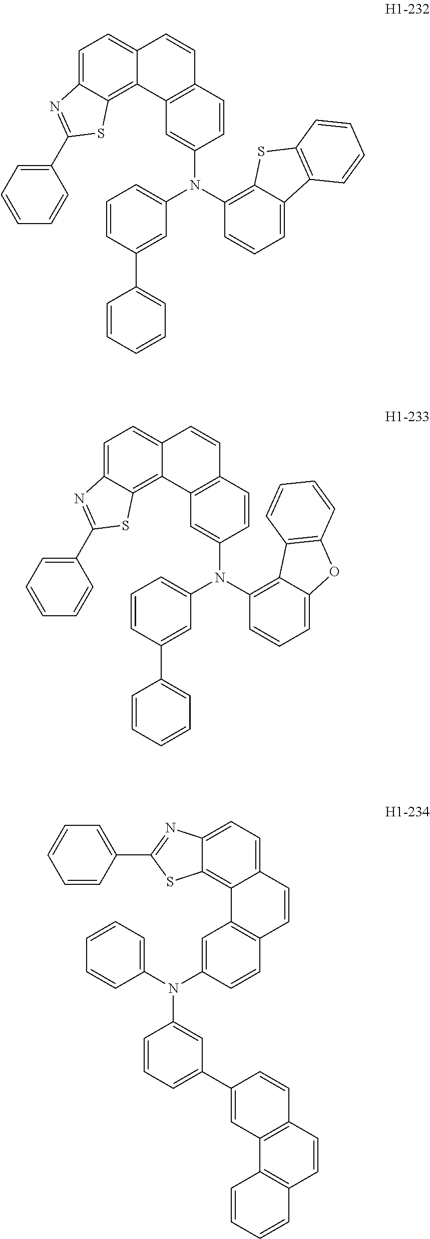 [SMILES: c1ccc(-c2cccc(N(c3ccc4ccc5ccc6nc(-c7ccccc7)sc6c5c4c3)c3cccc4c3sc3ccccc34)c2)cc1 ; c1ccc(-c2cccc(N(c3ccc4ccc5ccc6nc(-c7ccccc7)sc6c5c4c3)c3cccc4oc5ccccc5c34)c2)cc1 ; c1ccc(-c2nc3ccc4ccc5ccc(N(c6ccccc6)c6cccc(-c7ccc8ccc9ccccc9c8c7)c6)cc5c4c3s2)cc1]

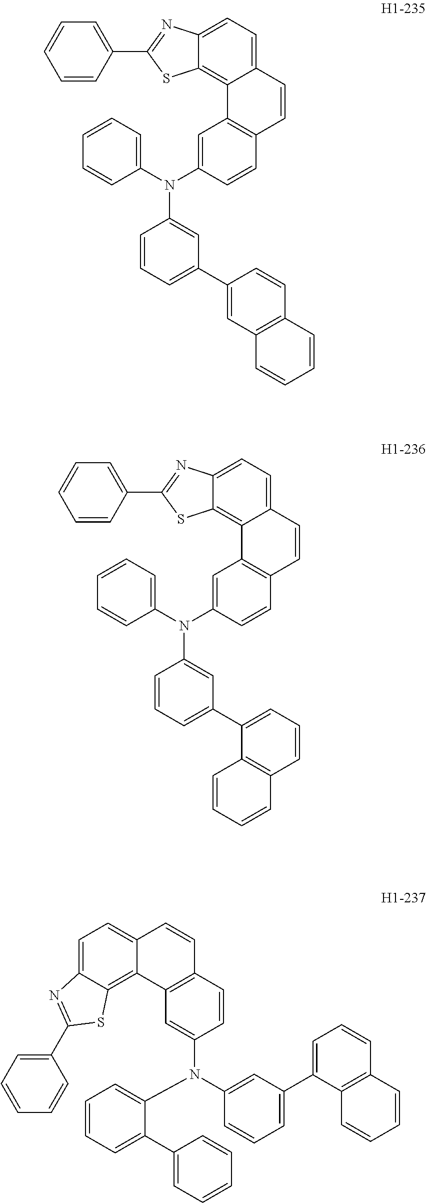 [SMILES: c1ccc(-c2nc3ccc4ccc5ccc(N(c6ccccc6)c6cccc(-c7ccc8ccccc8c7)c6)cc5c4c3s2)cc1 ; c1ccc(-c2nc3ccc4ccc5ccc(N(c6ccccc6)c6cccc(-c7cccc8ccccc78)c6)cc5c4c3s2)cc1 ; c1ccc(-c2nc3ccc4ccc5ccc(N(c6cccc(-c7cccc8ccccc78)c6)c6ccccc6-c6ccccc6)cc5c4c3s2)cc1]

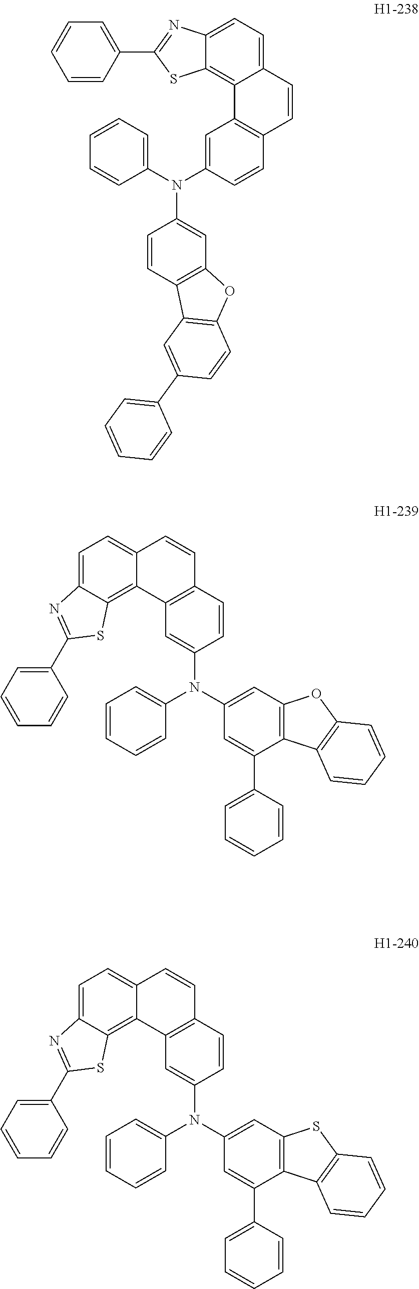 [SMILES: c1ccc(-c2ccc3oc4cc(N(c5ccccc5)c5ccc6ccc7ccc8nc(-c9ccccc9)sc8c7c6c5)ccc4c3c2)cc1 ; c1ccc(-c2nc3ccc4ccc5ccc(N(c6ccccc6)c6cc(-c7ccccc7)c7c(c6)oc6ccccc67)cc5c4c3s2)cc1 ; c1ccc(-c2nc3ccc4ccc5ccc(N(c6ccccc6)c6cc(-c7ccccc7)c7c(c6)sc6ccccc67)cc5c4c3s2)cc1]

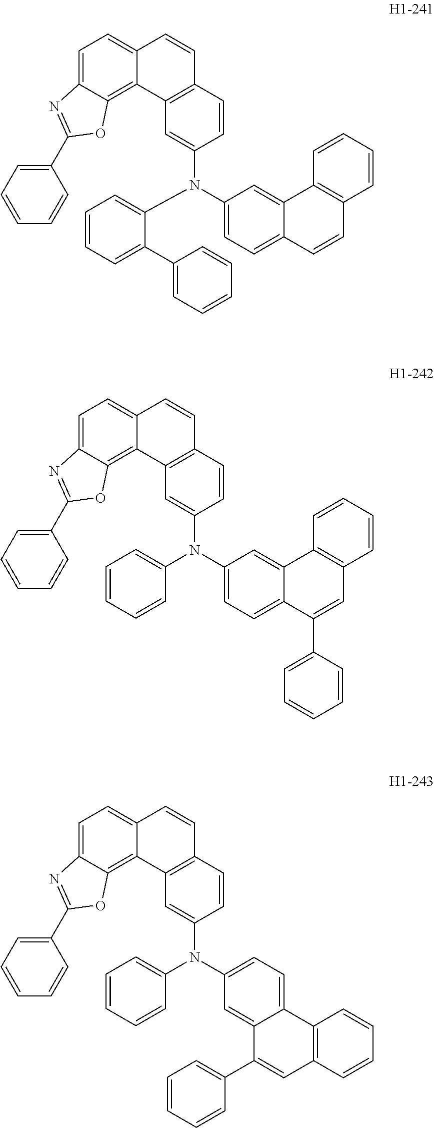 [SMILES: c1ccc(-c2nc3ccc4ccc5ccc(N(c6ccc7ccc8ccccc8c7c6)c6ccccc6-c6ccccc6)cc5c4c3o2)cc1 ; c1ccc(-c2nc3ccc4ccc5ccc(N(c6ccccc6)c6ccc7c(-c8ccccc8)cc8ccccc8c7c6)cc5c4c3o2)cc1 ; c1ccc(-c2nc3ccc4ccc5ccc(N(c6ccccc6)c6ccc7c(c6)c(-c6ccccc6)cc6ccccc67)cc5c4c3o2)cc1]

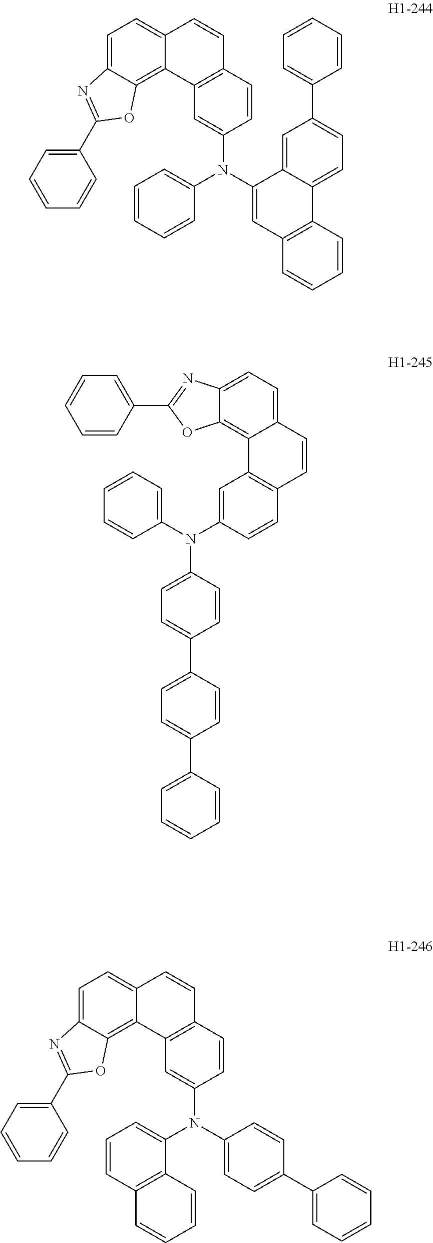 [SMILES: c1ccc(-c2ccc3c(c2)c(N(c2ccccc2)c2ccc4ccc5ccc6nc(-c7ccccc7)oc6c5c4c2)cc2ccccc23)cc1 ; c1ccc(-c2ccc(-c3ccc(N(c4ccccc4)c4ccc5ccc6ccc7nc(-c8ccccc8)oc7c6c5c4)cc3)cc2)cc1 ; c1ccc(-c2ccc(N(c3ccc4ccc5ccc6nc(-c7ccccc7)oc6c5c4c3)c3cccc4ccccc34)cc2)cc1]

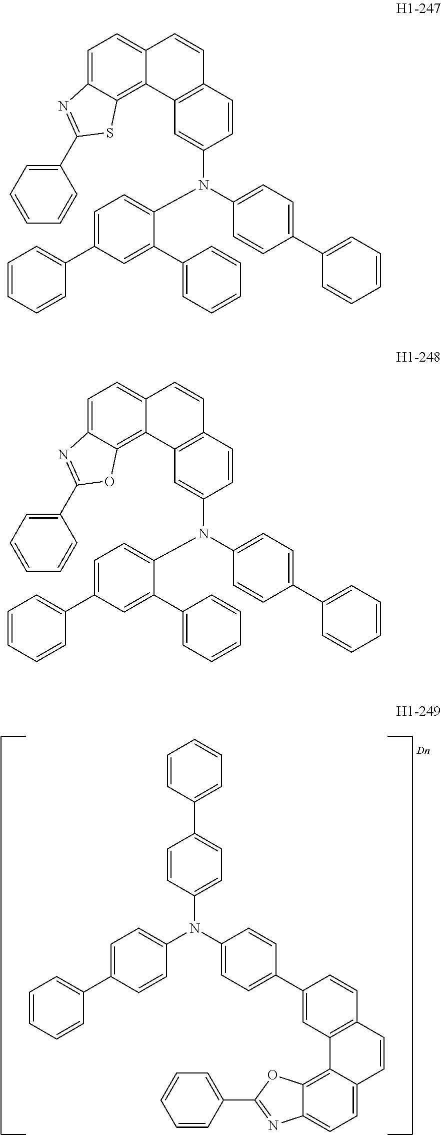

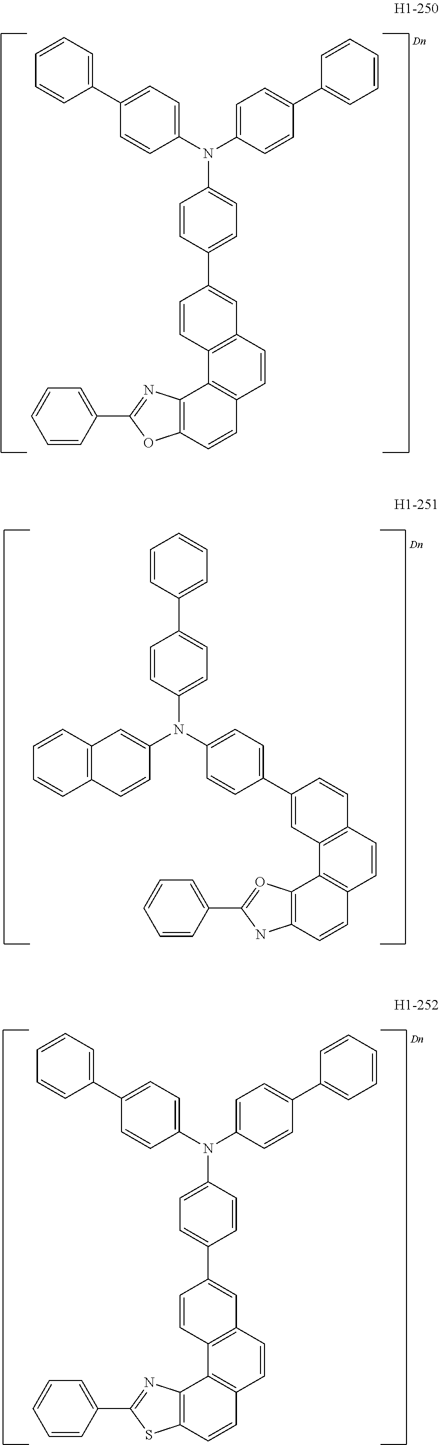

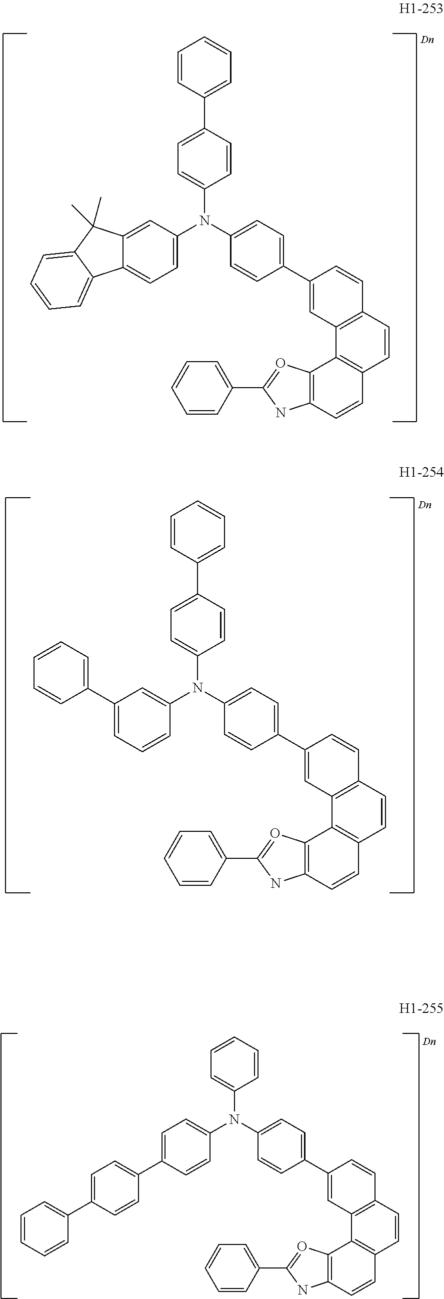

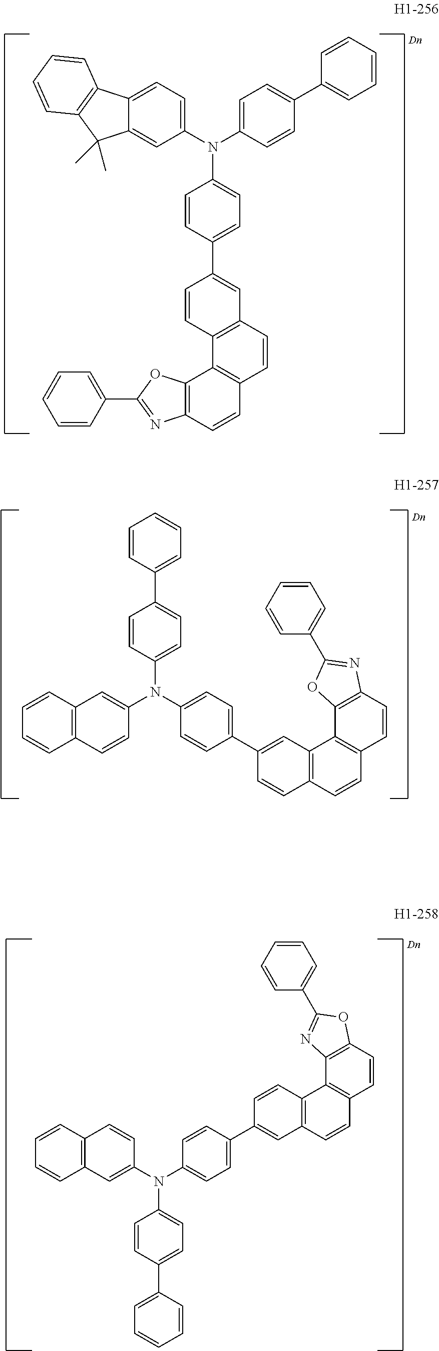

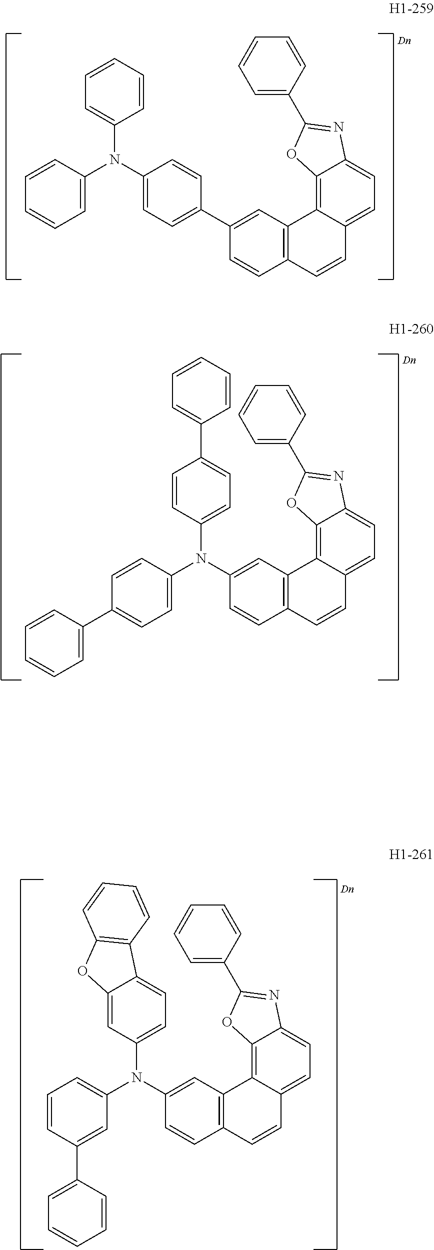

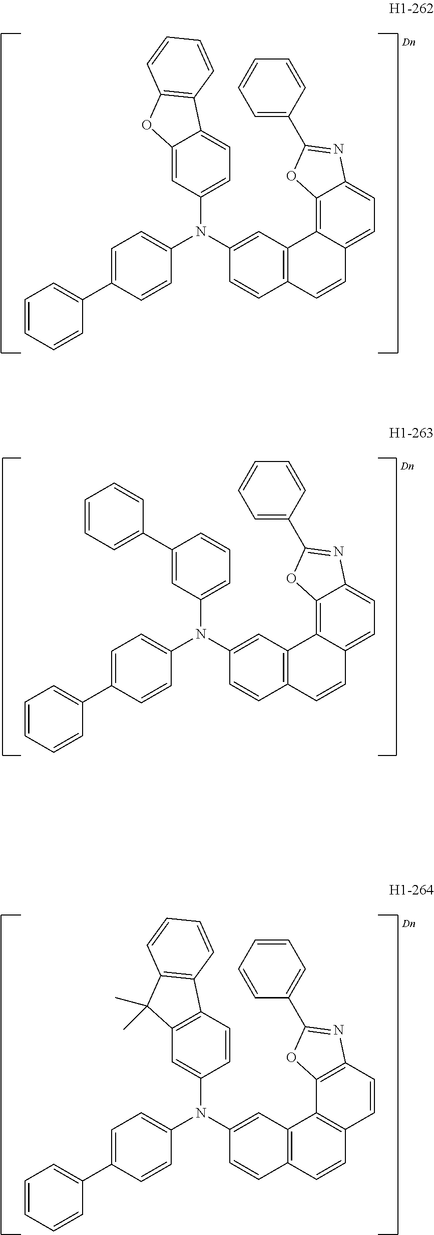

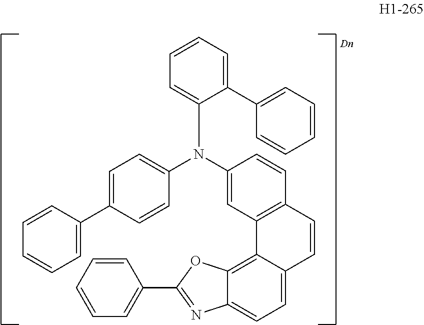

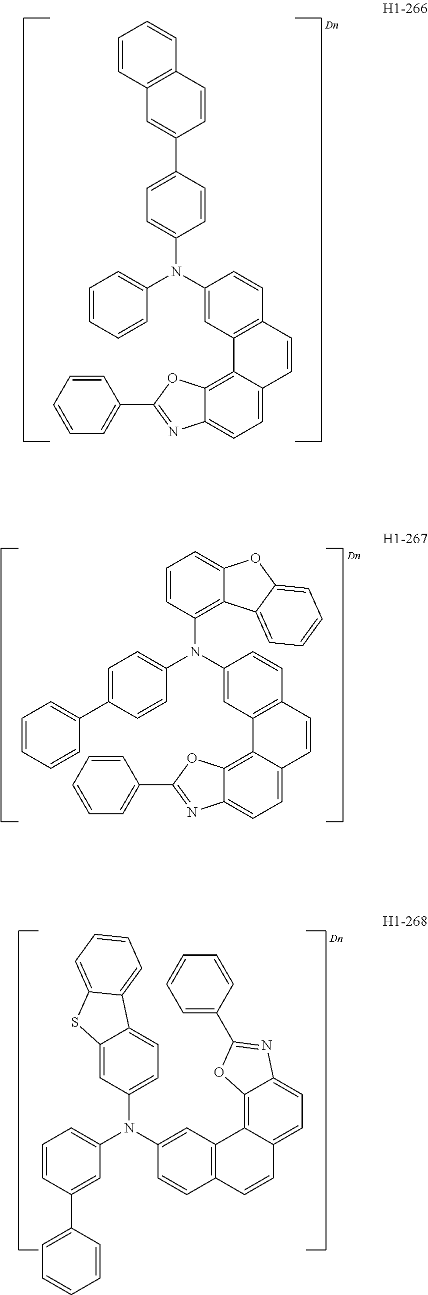

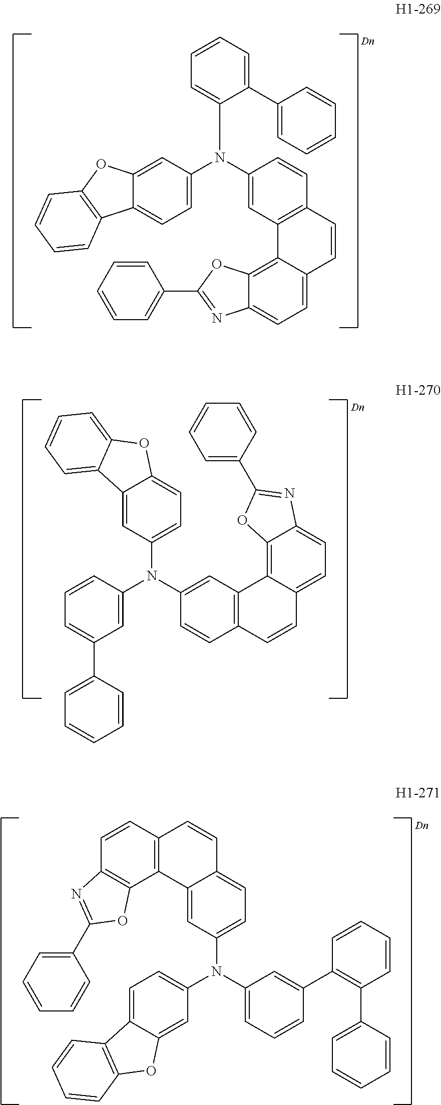

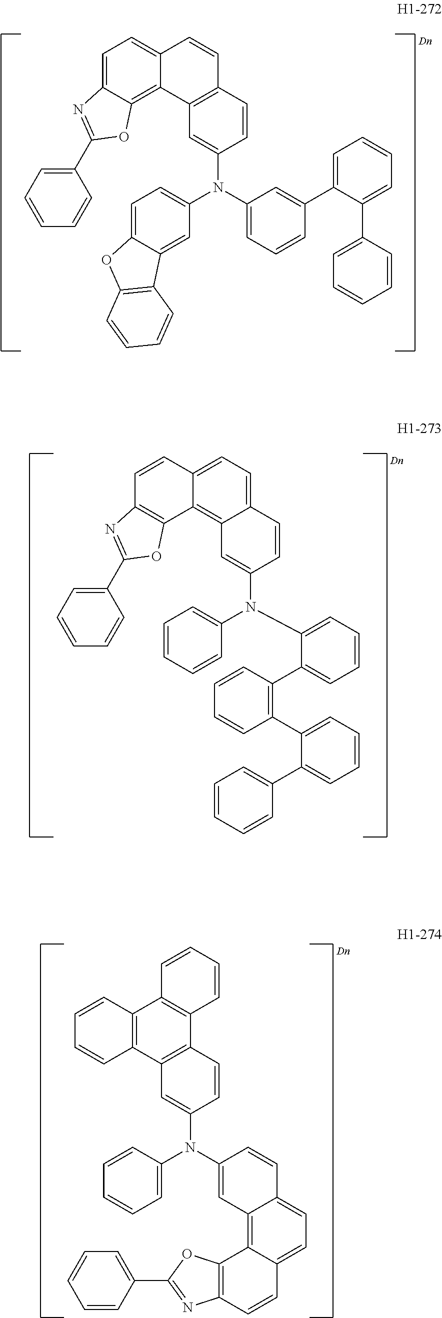

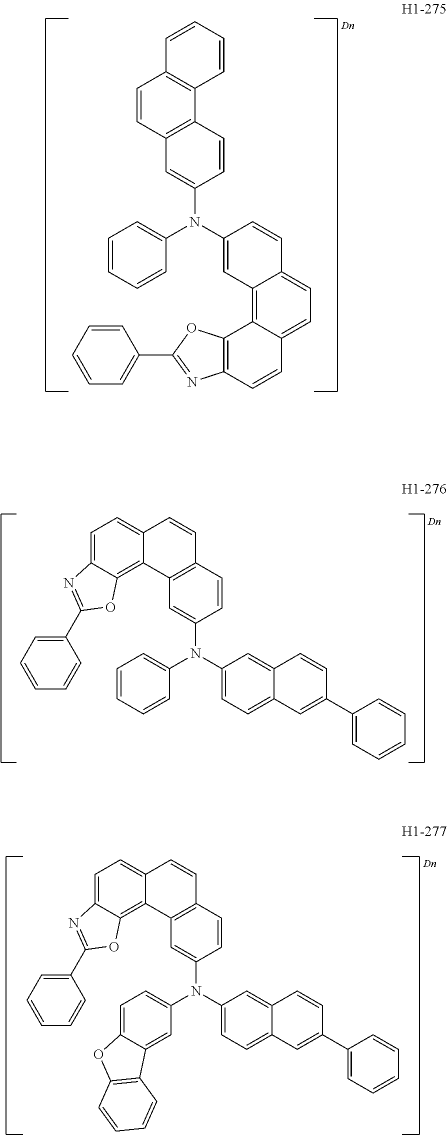

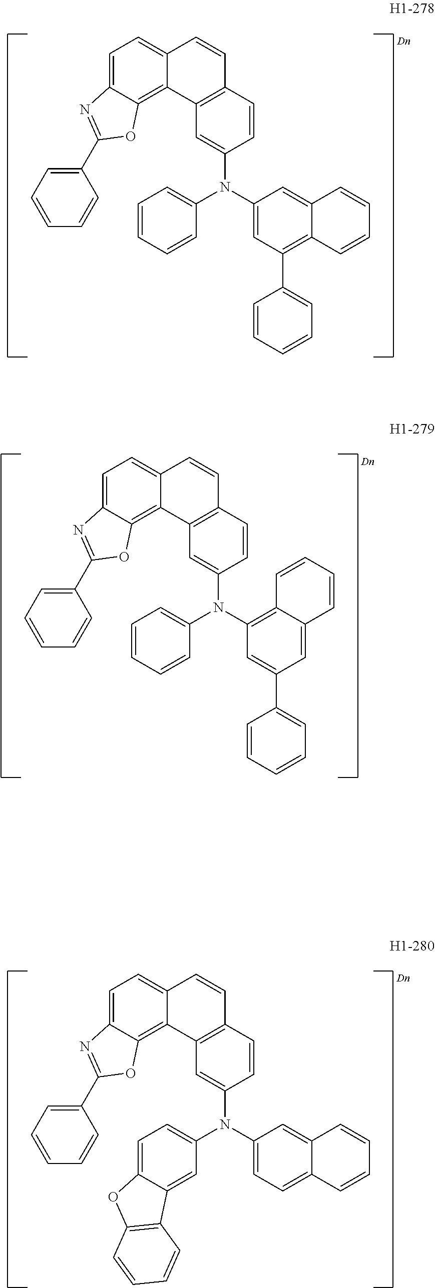

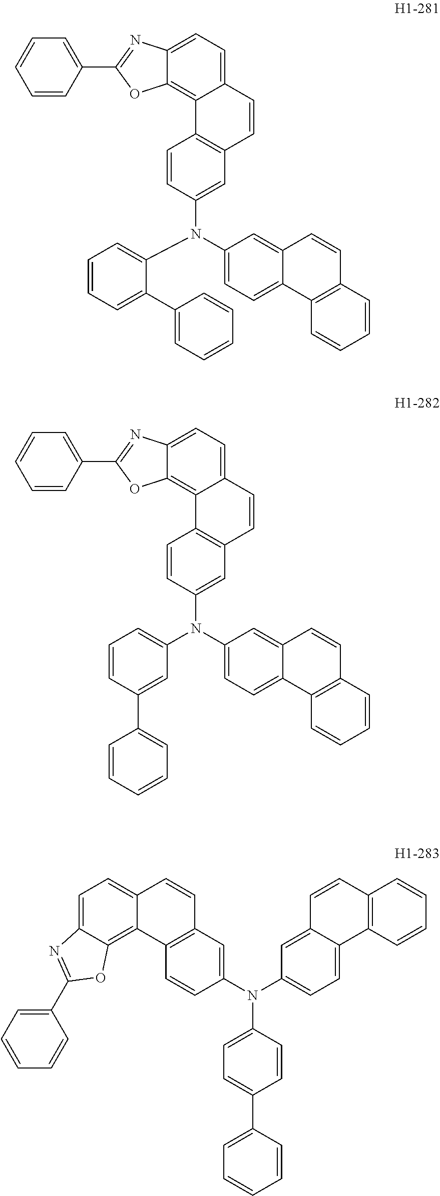 [SMILES: c1ccc(-c2nc3ccc4ccc5cc(N(c6ccc7c(ccc8ccccc87)c6)c6ccccc6-c6ccccc6)ccc5c4c3o2)cc1 ; c1ccc(-c2cccc(N(c3ccc4c(ccc5ccccc54)c3)c3ccc4c(ccc5ccc6nc(-c7ccccc7)oc6c54)c3)c2)cc1 ; c1ccc(-c2ccc(N(c3ccc4c(ccc5ccccc54)c3)c3ccc4c(ccc5ccc6nc(-c7ccccc7)oc6c54)c3)cc2)cc1]

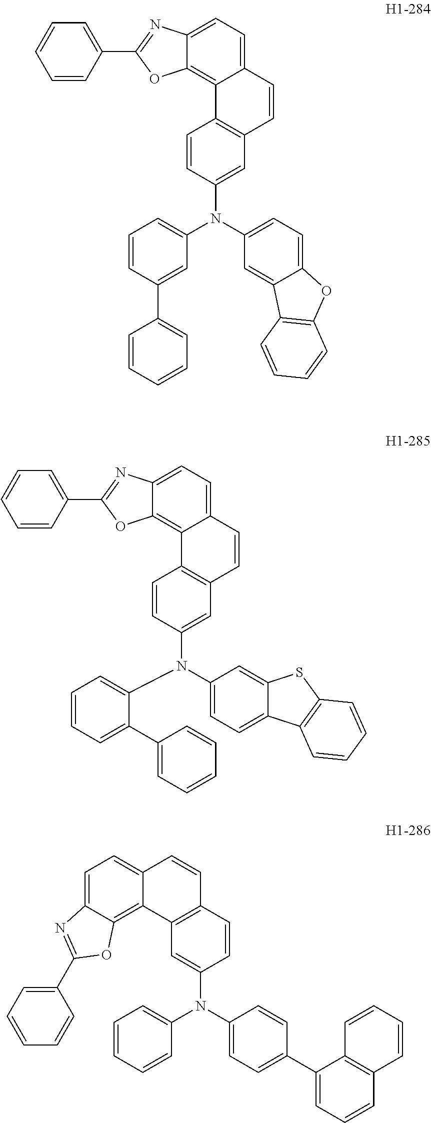 [SMILES: c1ccc(-c2cccc(N(c3ccc4c(ccc5ccc6nc(-c7ccccc7)oc6c54)c3)c3ccc4oc5ccccc5c4c3)c2)cc1 ; c1ccc(-c2nc3ccc4ccc5cc(N(c6ccc7c(c6)sc6ccccc67)c6ccccc6-c6ccccc6)ccc5c4c3o2)cc1 ; c1ccc(-c2nc3ccc4ccc5ccc(N(c6ccccc6)c6ccc(-c7cccc8ccccc78)cc6)cc5c4c3o2)cc1]

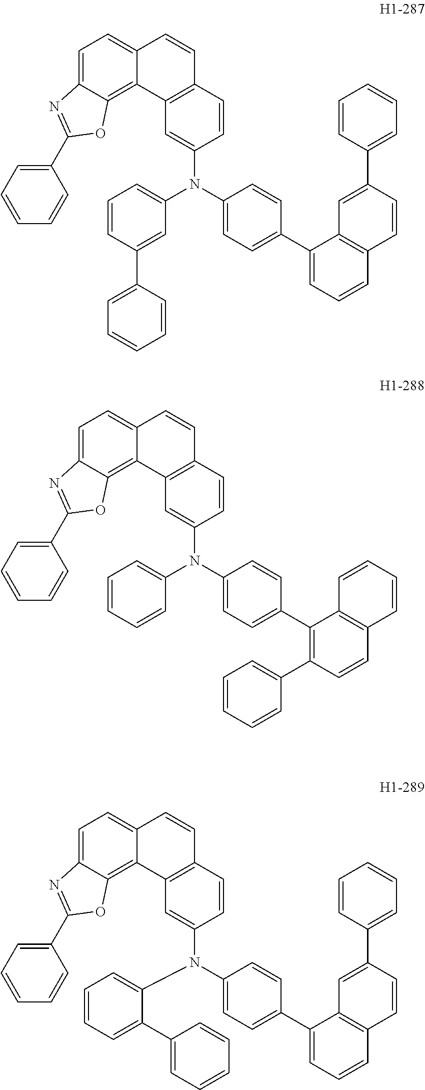 [SMILES: c1ccc(-c2cccc(N(c3ccc(-c4cccc5ccc(-c6ccccc6)cc45)cc3)c3ccc4ccc5ccc6nc(-c7ccccc7)oc6c5c4c3)c2)cc1 ; c1ccc(-c2nc3ccc4ccc5ccc(N(c6ccccc6)c6ccc(-c7c(-c8ccccc8)ccc8ccccc78)cc6)cc5c4c3o2)cc1 ; c1ccc(-c2ccc3cccc(-c4ccc(N(c5ccc6ccc7ccc8nc(-c9ccccc9)oc8c7c6c5)c5ccccc5-c5ccccc5)cc4)c3c2)cc1]

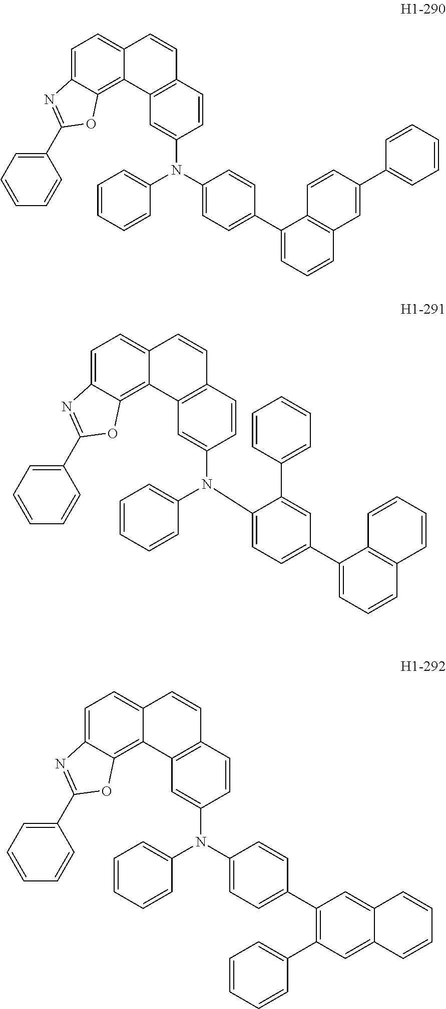 [SMILES: c1ccc(-c2ccc3c(-c4ccc(N(c5ccccc5)c5ccc6ccc7ccc8nc(-c9ccccc9)oc8c7c6c5)cc4)cccc3c2)cc1 ; c1ccc(-c2nc3ccc4ccc5ccc(N(c6ccccc6)c6ccc(-c7cccc8ccccc78)cc6-c6ccccc6)cc5c4c3o2)cc1 ; c1ccc(-c2nc3ccc4ccc5ccc(N(c6ccccc6)c6ccc(-c7cc8ccccc8cc7-c7ccccc7)cc6)cc5c4c3o2)cc1]

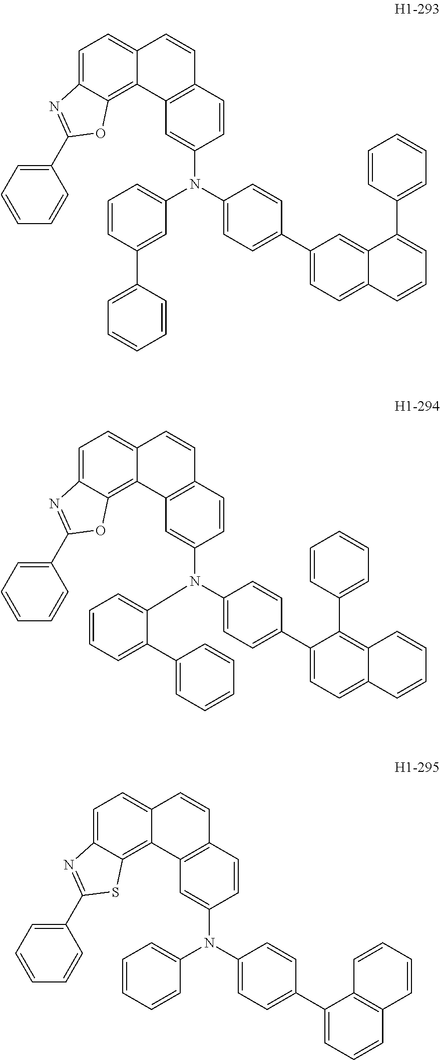 [SMILES: c1ccc(-c2cccc(N(c3ccc(-c4ccc5cccc(-c6ccccc6)c5c4)cc3)c3ccc4ccc5ccc6nc(-c7ccccc7)oc6c5c4c3)c2)cc1 ; c1ccc(-c2nc3ccc4ccc5ccc(N(c6ccc(-c7ccc8ccccc8c7-c7ccccc7)cc6)c6ccccc6-c6ccccc6)cc5c4c3o2)cc1 ; c1ccc(-c2nc3ccc4ccc5ccc(N(c6ccccc6)c6ccc(-c7cccc8ccccc78)cc6)cc5c4c3s2)cc1]

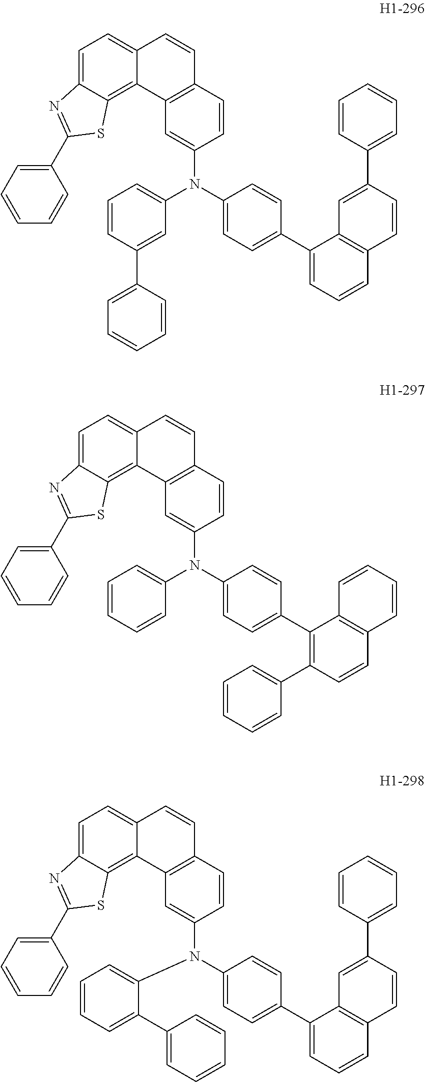 [SMILES: c1ccc(-c2cccc(N(c3ccc(-c4cccc5ccc(-c6ccccc6)cc45)cc3)c3ccc4ccc5ccc6nc(-c7ccccc7)sc6c5c4c3)c2)cc1 ; c1ccc(-c2nc3ccc4ccc5ccc(N(c6ccccc6)c6ccc(-c7c(-c8ccccc8)ccc8ccccc78)cc6)cc5c4c3s2)cc1 ; c1ccc(-c2ccc3cccc(-c4ccc(N(c5ccc6ccc7ccc8nc(-c9ccccc9)sc8c7c6c5)c5ccccc5-c5ccccc5)cc4)c3c2)cc1]

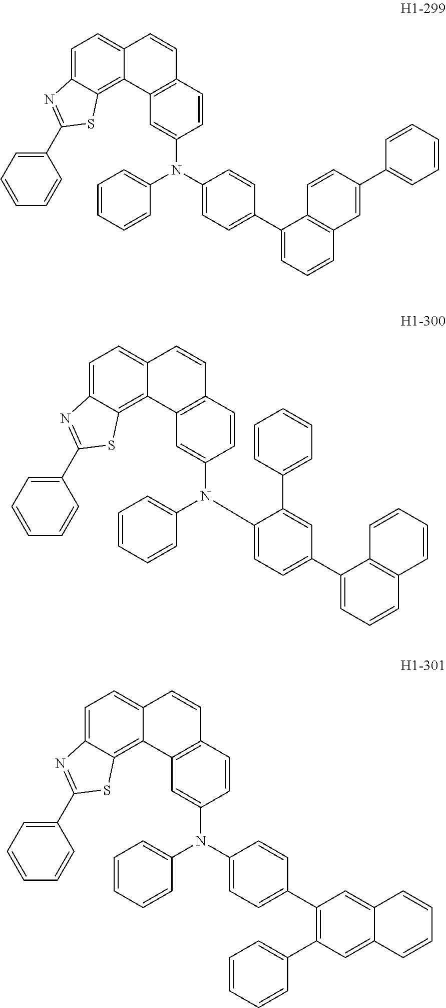 [SMILES: c1ccc(-c2ccc3c(-c4ccc(N(c5ccccc5)c5ccc6ccc7ccc8nc(-c9ccccc9)sc8c7c6c5)cc4)cccc3c2)cc1 ; c1ccc(-c2nc3ccc4ccc5ccc(N(c6ccccc6)c6ccc(-c7cccc8ccccc78)cc6-c6ccccc6)cc5c4c3s2)cc1 ; c1ccc(-c2nc3ccc4ccc5ccc(N(c6ccccc6)c6ccc(-c7cc8ccccc8cc7-c7ccccc7)cc6)cc5c4c3s2)cc1]

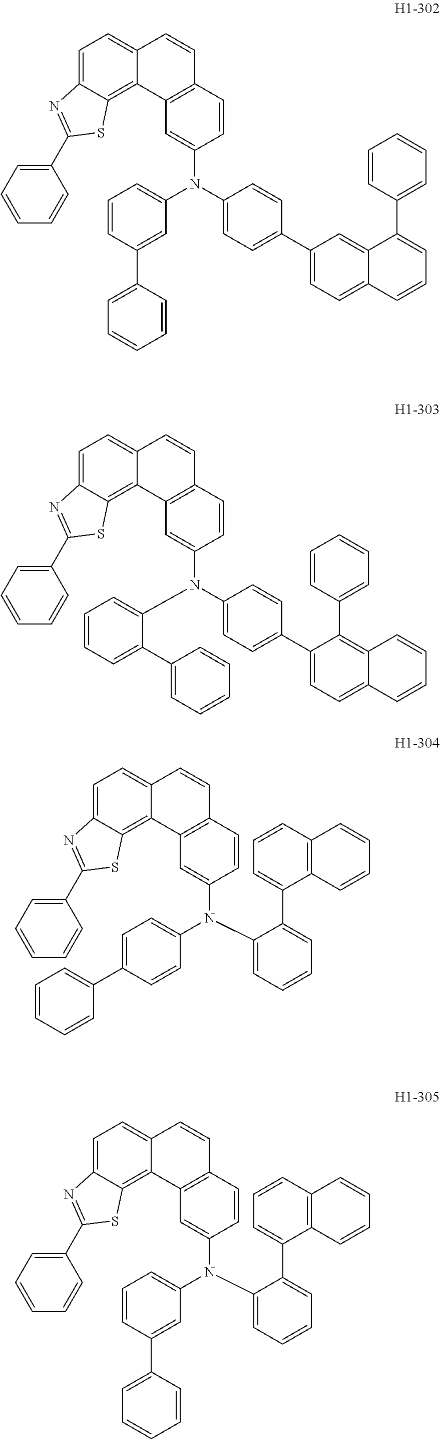 [SMILES: c1ccc(-c2cccc(N(c3ccc(-c4ccc5cccc(-c6ccccc6)c5c4)cc3)c3ccc4ccc5ccc6nc(-c7ccccc7)sc6c5c4c3)c2)cc1 ; c1ccc(-c2nc3ccc4ccc5ccc(N(c6ccc(-c7ccc8ccccc8c7-c7ccccc7)cc6)c6ccccc6-c6ccccc6)cc5c4c3s2)cc1 ; c1ccc(-c2ccc(N(c3ccc4ccc5ccc6nc(-c7ccccc7)sc6c5c4c3)c3ccccc3-c3cccc4ccccc34)cc2)cc1 ; c1ccc(-c2cccc(N(c3ccc4ccc5ccc6nc(-c7ccccc7)sc6c5c4c3)c3ccccc3-c3cccc4ccccc34)c2)cc1]

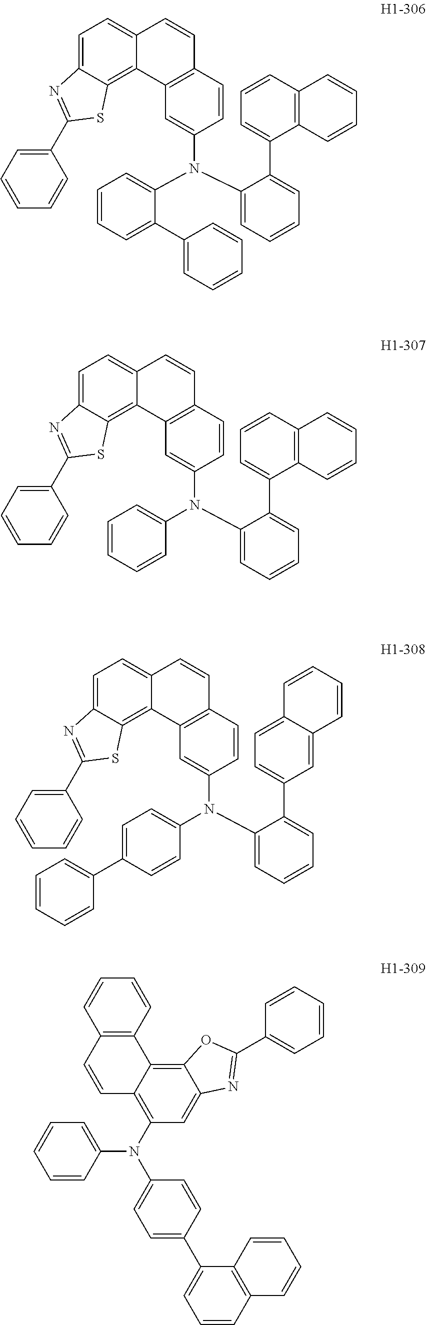 [SMILES: c1ccc(-c2nc3ccc4ccc5ccc(N(c6ccccc6-c6ccccc6)c6ccccc6-c6cccc7ccccc67)cc5c4c3s2)cc1 ; c1ccc(-c2nc3ccc4ccc5ccc(N(c6ccccc6)c6ccccc6-c6cccc7ccccc67)cc5c4c3s2)cc1 ; c1ccc(-c2ccc(N(c3ccc4ccc5ccc6nc(-c7ccccc7)sc6c5c4c3)c3ccccc3-c3ccc4ccccc4c3)cc2)cc1 ; c1ccc(-c2nc3cc(N(c4ccccc4)c4ccc(-c5cccc6ccccc56)cc4)c4ccc5ccccc5c4c3o2)cc1]

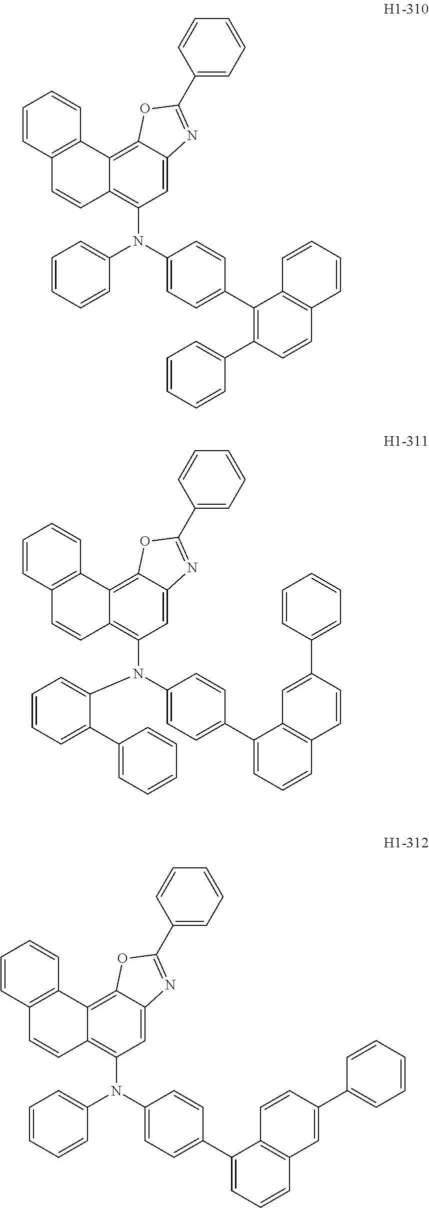

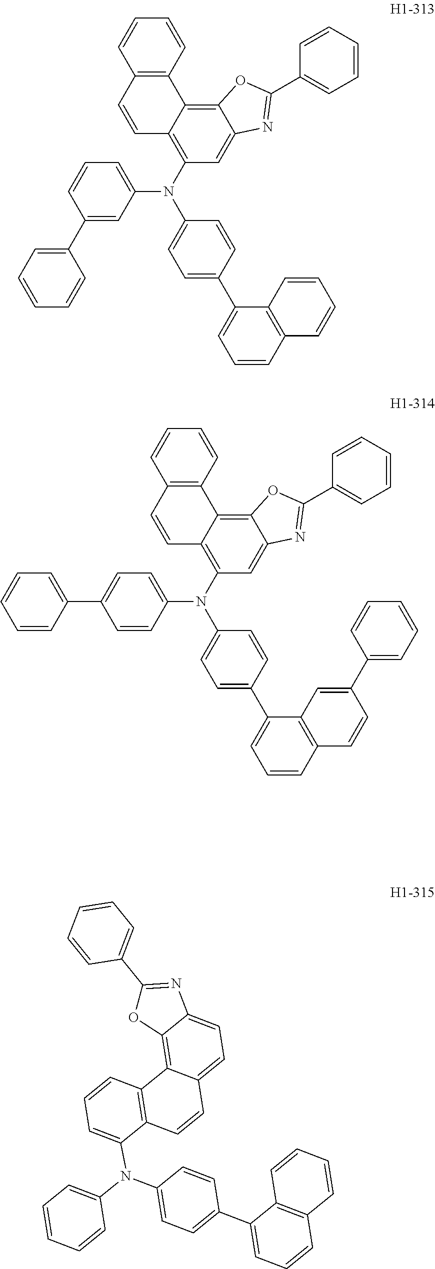 [SMILES: c1ccc(-c2cccc(N(c3ccc(-c4cccc5ccccc45)cc3)c3cc4nc(-c5ccccc5)oc4c4c3ccc3ccccc34)c2)cc1 ; c1ccc(-c2ccc(N(c3ccc(-c4cccc5ccc(-c6ccccc6)cc45)cc3)c3cc4nc(-c5ccccc5)oc4c4c3ccc3ccccc34)cc2)cc1 ; c1ccc(-c2nc3ccc4ccc5c(N(c6ccccc6)c6ccc(-c7cccc8ccccc78)cc6)cccc5c4c3o2)cc1]

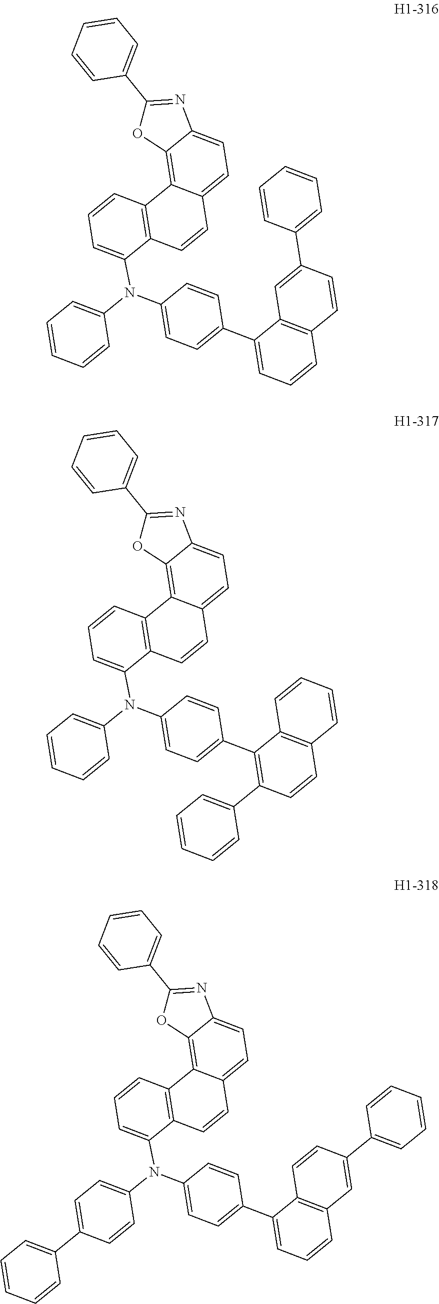 [SMILES: c1ccc(-c2ccc3cccc(-c4ccc(N(c5ccccc5)c5cccc6c5ccc5ccc7nc(-c8ccccc8)oc7c56)cc4)c3c2)cc1 ; c1ccc(-c2nc3ccc4ccc5c(N(c6ccccc6)c6ccc(-c7c(-c8ccccc8)ccc8ccccc78)cc6)cccc5c4c3o2)cc1 ; c1ccc(-c2ccc(N(c3ccc(-c4cccc5cc(-c6ccccc6)ccc45)cc3)c3cccc4c3ccc3ccc5nc(-c6ccccc6)oc5c34)cc2)cc1]

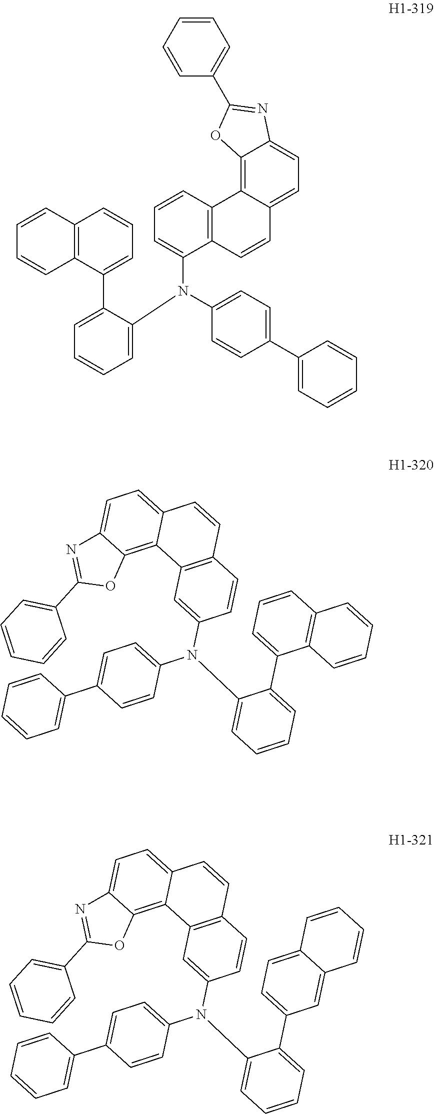 [SMILES: c1ccc(-c2ccc(N(c3ccccc3-c3cccc4ccccc34)c3cccc4c3ccc3ccc5nc(-c6ccccc6)oc5c34)cc2)cc1 ; c1ccc(-c2ccc(N(c3ccc4ccc5ccc6nc(-c7ccccc7)oc6c5c4c3)c3ccccc3-c3cccc4ccccc34)cc2)cc1 ; c1ccc(-c2ccc(N(c3ccc4ccc5ccc6nc(-c7ccccc7)oc6c5c4c3)c3ccccc3-c3ccc4ccccc4c3)cc2)cc1]

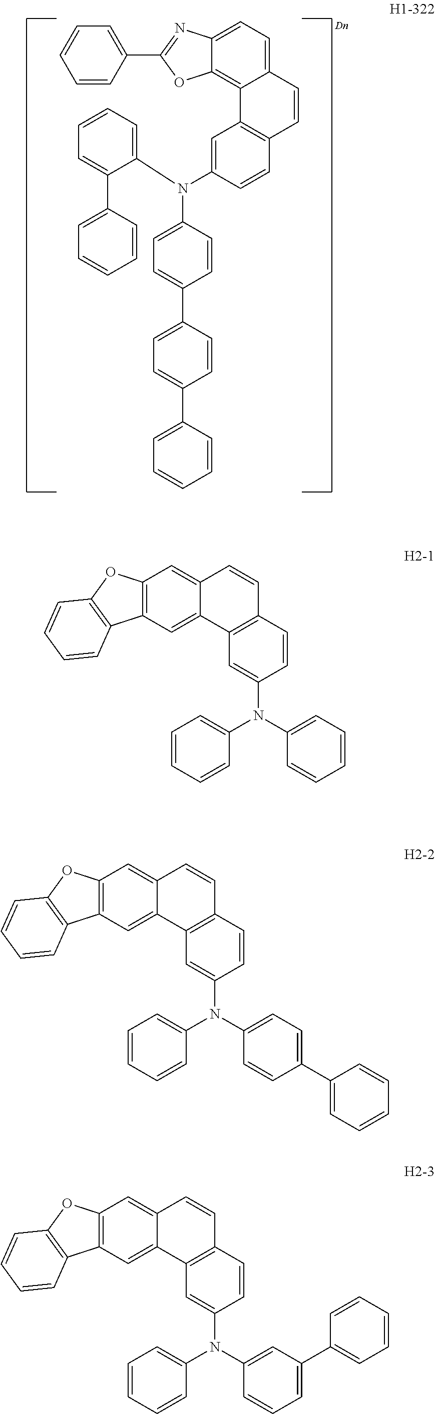

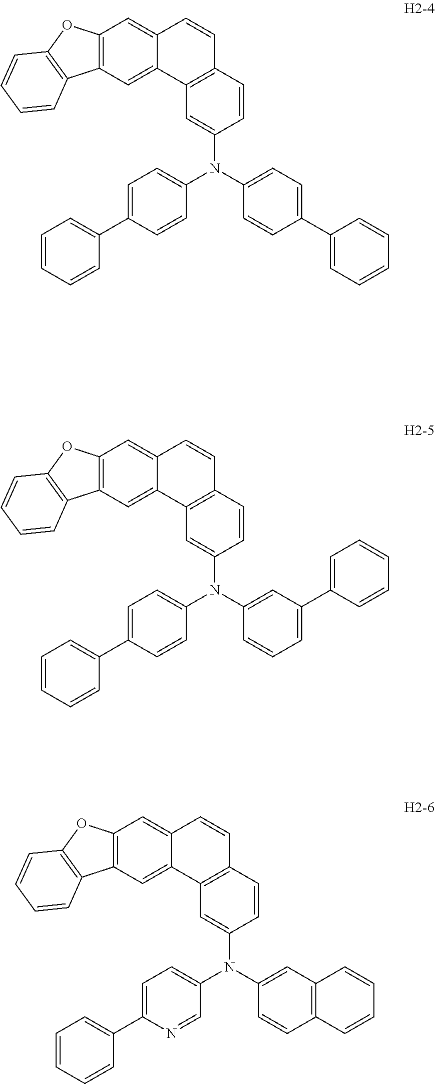 [SMILES: c1ccc(-c2ccc(N(c3ccc(-c4ccccc4)cc3)c3ccc4ccc5cc6oc7ccccc7c6cc5c4c3)cc2)cc1 ; c1ccc(-c2ccc(N(c3cccc(-c4ccccc4)c3)c3ccc4ccc5cc6oc7ccccc7c6cc5c4c3)cc2)cc1 ; c1ccc(-c2ccc(N(c3ccc4ccccc4c3)c3ccc4ccc5cc6oc7ccccc7c6cc5c4c3)cn2)cc1]

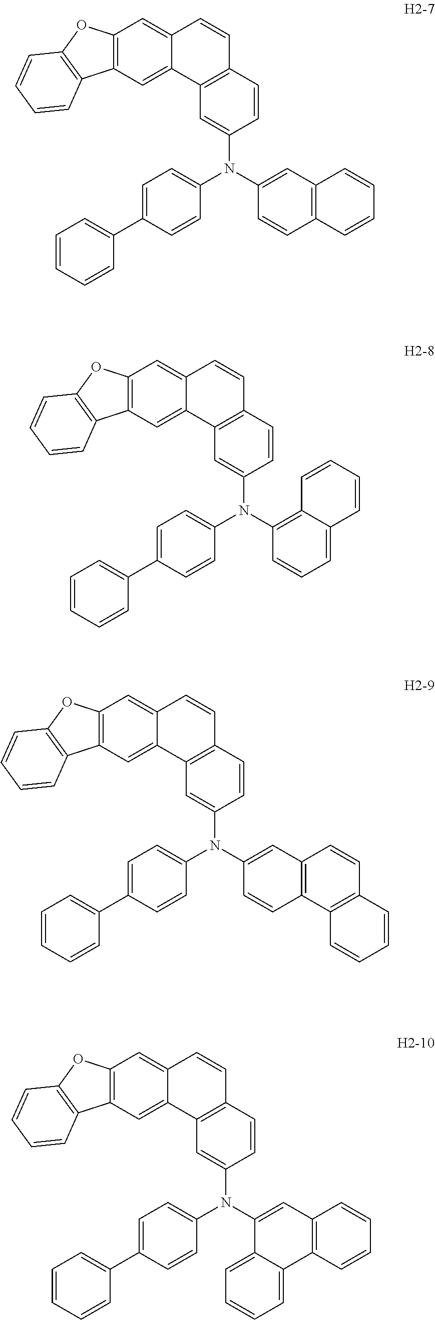 [SMILES: c1ccc(-c2ccc(N(c3ccc4ccccc4c3)c3ccc4ccc5cc6oc7ccccc7c6cc5c4c3)cc2)cc1 ; c1ccc(-c2ccc(N(c3ccc4ccc5cc6oc7ccccc7c6cc5c4c3)c3cccc4ccccc34)cc2)cc1 ; c1ccc(-c2ccc(N(c3ccc4c(ccc5ccccc54)c3)c3ccc4ccc5cc6oc7ccccc7c6cc5c4c3)cc2)cc1 ; c1ccc(-c2ccc(N(c3ccc4ccc5cc6oc7ccccc7c6cc5c4c3)c3cc4ccccc4c4ccccc34)cc2)cc1]

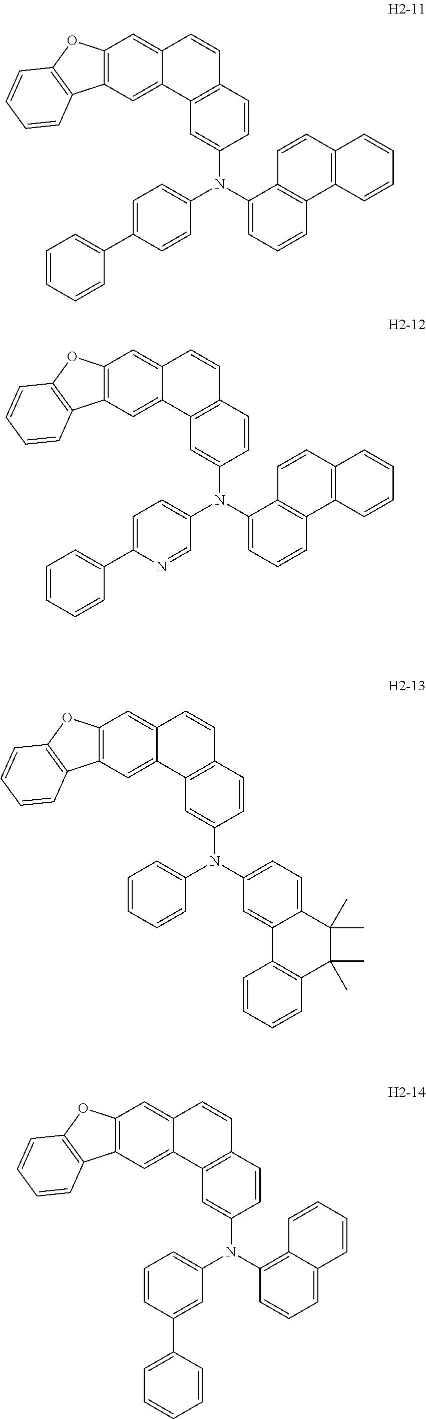 [SMILES: c1ccc(-c2ccc(N(c3ccc4ccc5cc6oc7ccccc7c6cc5c4c3)c3cccc4c3ccc3ccccc34)cc2)cc1 ; c1ccc(-c2ccc(N(c3ccc4ccc5cc6oc7ccccc7c6cc5c4c3)c3cccc4c3ccc3ccccc34)cn2)cc1 ; CC1(C)c2ccccc2-c2cc(N(c3ccccc3)c3ccc4ccc5cc6oc7ccccc7c6cc5c4c3)ccc2C1(C)C ; c1ccc(-c2cccc(N(c3ccc4ccc5cc6oc7ccccc7c6cc5c4c3)c3cccc4ccccc34)c2)cc1]

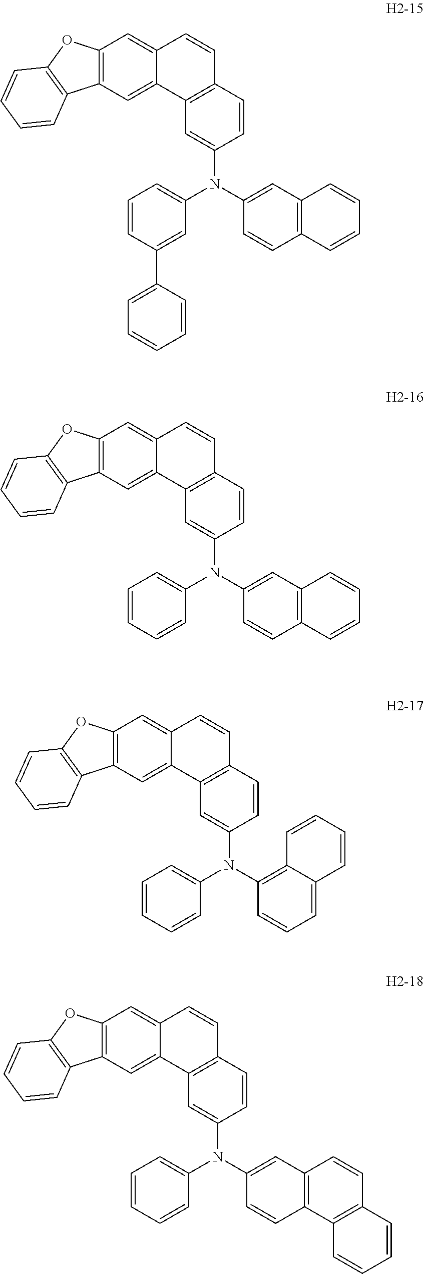 [SMILES: c1ccc(-c2cccc(N(c3ccc4ccccc4c3)c3ccc4ccc5cc6oc7ccccc7c6cc5c4c3)c2)cc1 ; c1ccc(N(c2ccc3ccccc3c2)c2ccc3ccc4cc5oc6ccccc6c5cc4c3c2)cc1 ; c1ccc(N(c2ccc3ccc4cc5oc6ccccc6c5cc4c3c2)c2cccc3ccccc23)cc1 ; c1ccc(N(c2ccc3c(ccc4ccccc43)c2)c2ccc3ccc4cc5oc6ccccc6c5cc4c3c2)cc1]

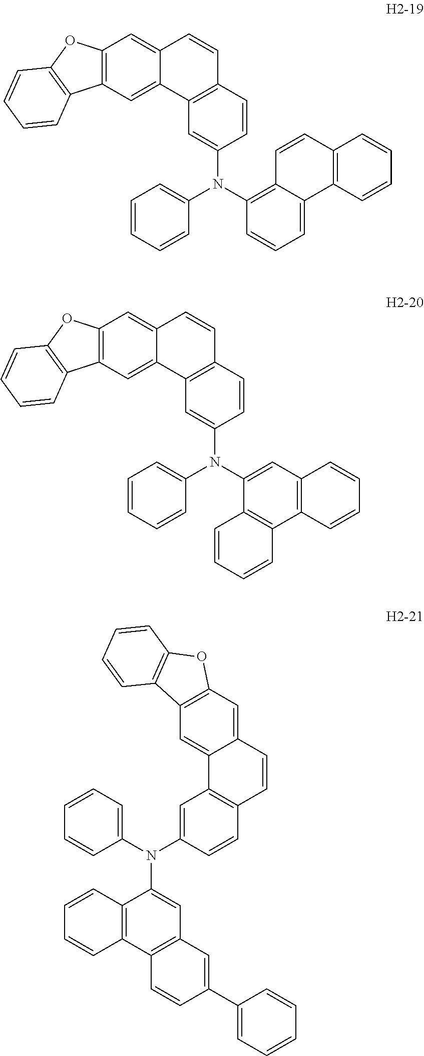 [SMILES: c1ccc(N(c2ccc3ccc4cc5oc6ccccc6c5cc4c3c2)c2cccc3c2ccc2ccccc23)cc1 ; c1ccc(N(c2ccc3ccc4cc5oc6ccccc6c5cc4c3c2)c2cc3ccccc3c3ccccc23)cc1 ; c1ccc(-c2ccc3c(c2)cc(N(c2ccccc2)c2ccc4ccc5cc6oc7ccccc7c6cc5c4c2)c2ccccc23)cc1]

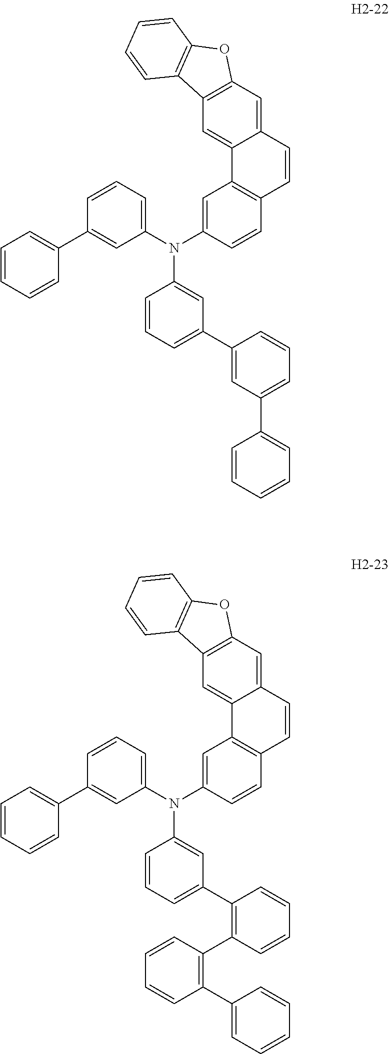 [SMILES: c1ccc(-c2cccc(-c3cccc(N(c4cccc(-c5ccccc5)c4)c4ccc5ccc6cc7oc8ccccc8c7cc6c5c4)c3)c2)cc1 ; c1ccc(-c2cccc(N(c3cccc(-c4ccccc4-c4ccccc4-c4ccccc4)c3)c3ccc4ccc5cc6oc7ccccc7c6cc5c4c3)c2)cc1]

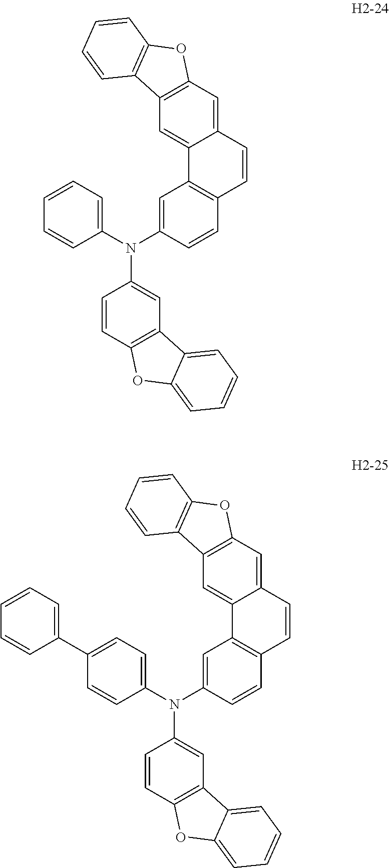 [SMILES: c1ccc(N(c2ccc3ccc4cc5oc6ccccc6c5cc4c3c2)c2ccc3oc4ccccc4c3c2)cc1 ; c1ccc(-c2ccc(N(c3ccc4ccc5cc6oc7ccccc7c6cc5c4c3)c3ccc4oc5ccccc5c4c3)cc2)cc1]

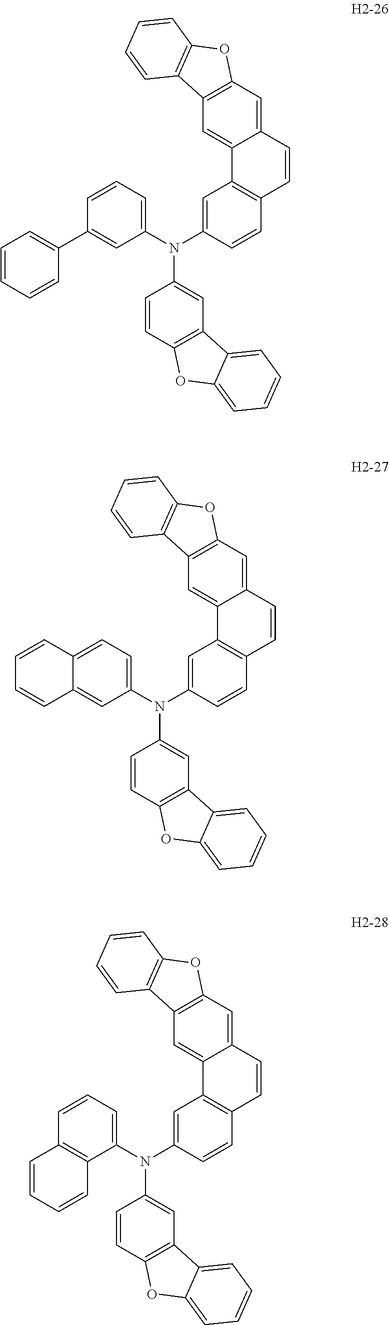 [SMILES: c1ccc(-c2cccc(N(c3ccc4ccc5cc6oc7ccccc7c6cc5c4c3)c3ccc4oc5ccccc5c4c3)c2)cc1 ; c1ccc2cc(N(c3ccc4ccc5cc6oc7ccccc7c6cc5c4c3)c3ccc4oc5ccccc5c4c3)ccc2c1 ; c1ccc2c(N(c3ccc4ccc5cc6oc7ccccc7c6cc5c4c3)c3ccc4oc5ccccc5c4c3)cccc2c1]

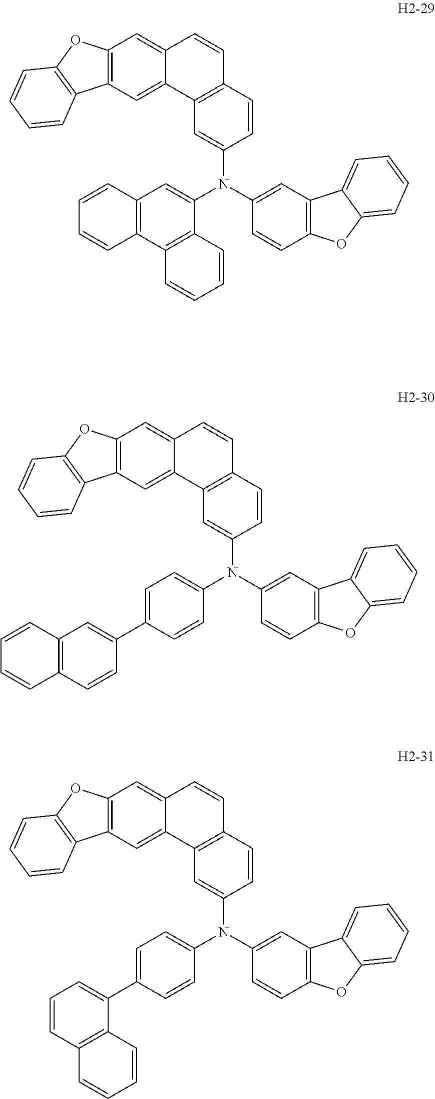 [SMILES: c1ccc2c(c1)cc(N(c1ccc3ccc4cc5oc6ccccc6c5cc4c3c1)c1ccc3oc4ccccc4c3c1)c1ccccc12 ; c1ccc2cc(-c3ccc(N(c4ccc5ccc6cc7oc8ccccc8c7cc6c5c4)c4ccc5oc6ccccc6c5c4)cc3)ccc2c1 ; c1ccc2c(-c3ccc(N(c4ccc5ccc6cc7oc8ccccc8c7cc6c5c4)c4ccc5oc6ccccc6c5c4)cc3)cccc2c1]

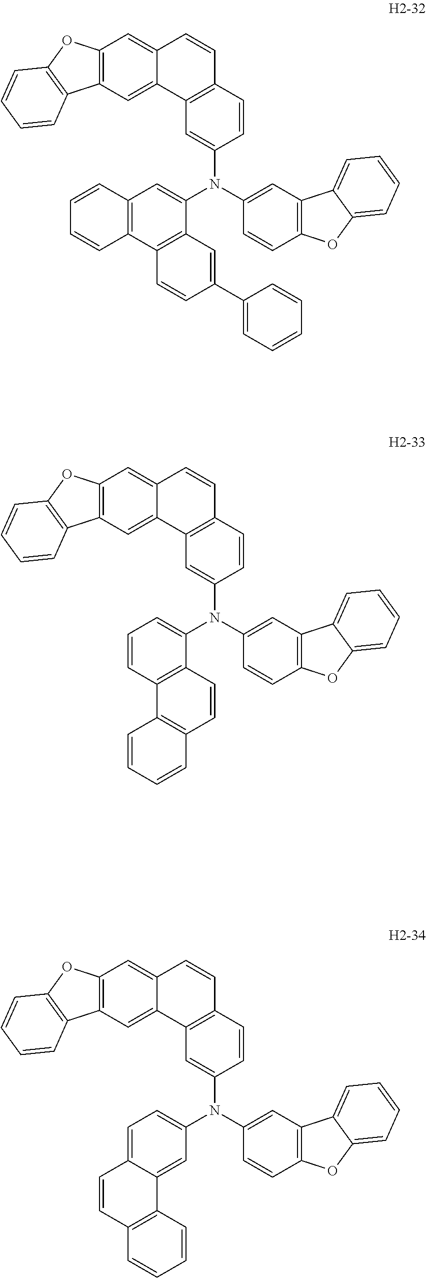 [SMILES: c1ccc(-c2ccc3c(c2)c(N(c2ccc4ccc5cc6oc7ccccc7c6cc5c4c2)c2ccc4oc5ccccc5c4c2)cc2ccccc23)cc1 ; c1ccc2c(c1)ccc1c(N(c3ccc4ccc5cc6oc7ccccc7c6cc5c4c3)c3ccc4oc5ccccc5c4c3)cccc12 ; c1ccc2c(c1)ccc1ccc(N(c3ccc4ccc5cc6oc7ccccc7c6cc5c4c3)c3ccc4oc5ccccc5c4c3)cc12]

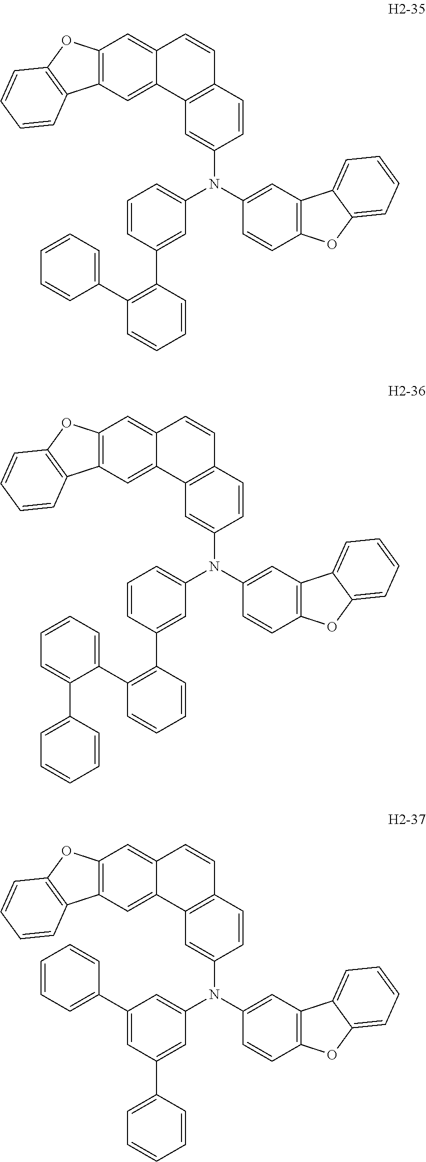 [SMILES: c1ccc(-c2ccccc2-c2cccc(N(c3ccc4ccc5cc6oc7ccccc7c6cc5c4c3)c3ccc4oc5ccccc5c4c3)c2)cc1 ; c1ccc(-c2ccccc2-c2ccccc2-c2cccc(N(c3ccc4ccc5cc6oc7ccccc7c6cc5c4c3)c3ccc4oc5ccccc5c4c3)c2)cc1 ; c1ccc(-c2cc(-c3ccccc3)cc(N(c3ccc4ccc5cc6oc7ccccc7c6cc5c4c3)c3ccc4oc5ccccc5c4c3)c2)cc1]

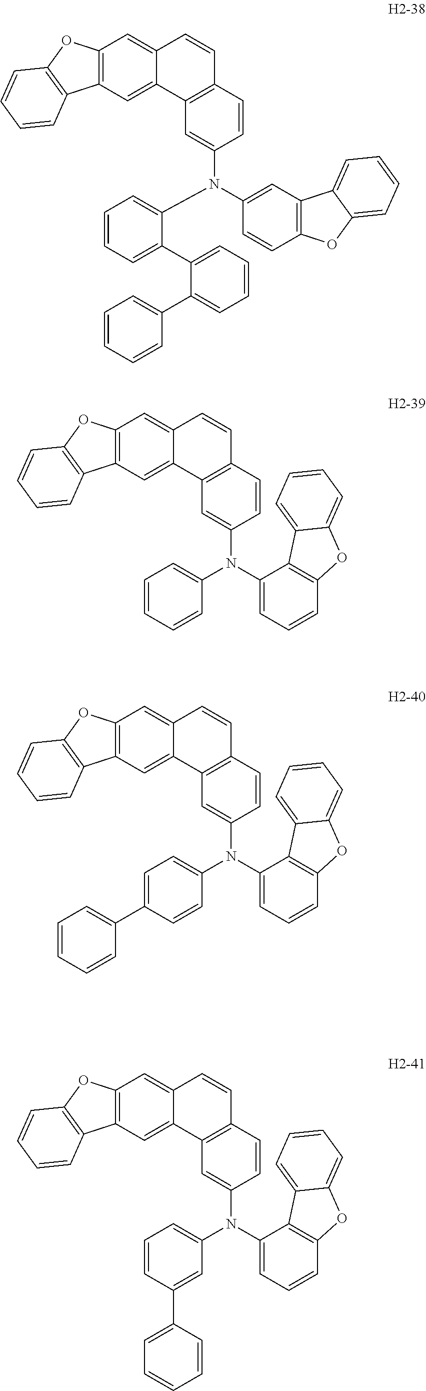 [SMILES: c1ccc(-c2ccccc2-c2ccccc2N(c2ccc3ccc4cc5oc6ccccc6c5cc4c3c2)c2ccc3oc4ccccc4c3c2)cc1 ; c1ccc(N(c2ccc3ccc4cc5oc6ccccc6c5cc4c3c2)c2cccc3oc4ccccc4c23)cc1 ; c1ccc(-c2ccc(N(c3ccc4ccc5cc6oc7ccccc7c6cc5c4c3)c3cccc4oc5ccccc5c34)cc2)cc1 ; c1ccc(-c2cccc(N(c3ccc4ccc5cc6oc7ccccc7c6cc5c4c3)c3cccc4oc5ccccc5c34)c2)cc1]

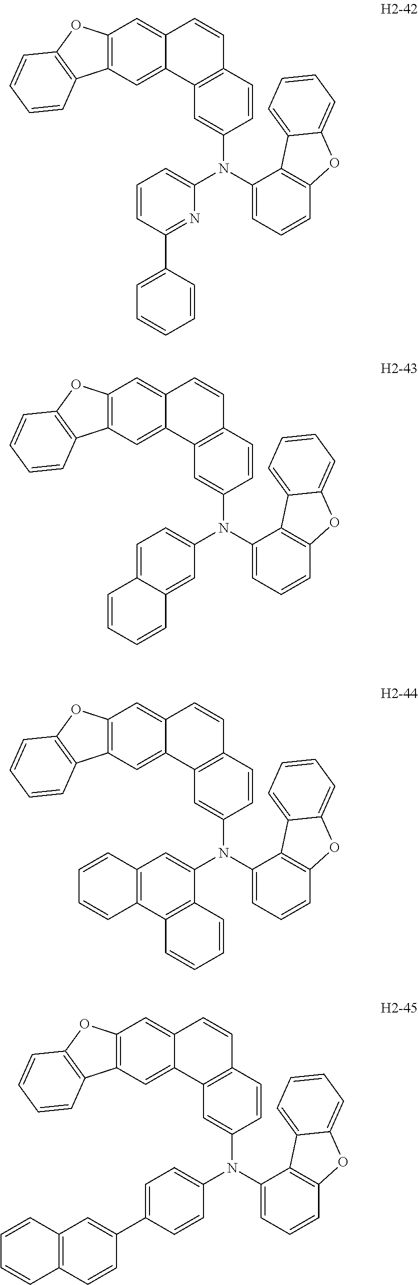 [SMILES: c1ccc(-c2cccc(N(c3ccc4ccc5cc6oc7ccccc7c6cc5c4c3)c3cccc4oc5ccccc5c34)n2)cc1 ; c1ccc2cc(N(c3ccc4ccc5cc6oc7ccccc7c6cc5c4c3)c3cccc4oc5ccccc5c34)ccc2c1 ; c1ccc2c(c1)cc(N(c1ccc3ccc4cc5oc6ccccc6c5cc4c3c1)c1cccc3oc4ccccc4c13)c1ccccc12 ; c1ccc2cc(-c3ccc(N(c4ccc5ccc6cc7oc8ccccc8c7cc6c5c4)c4cccc5oc6ccccc6c45)cc3)ccc2c1]

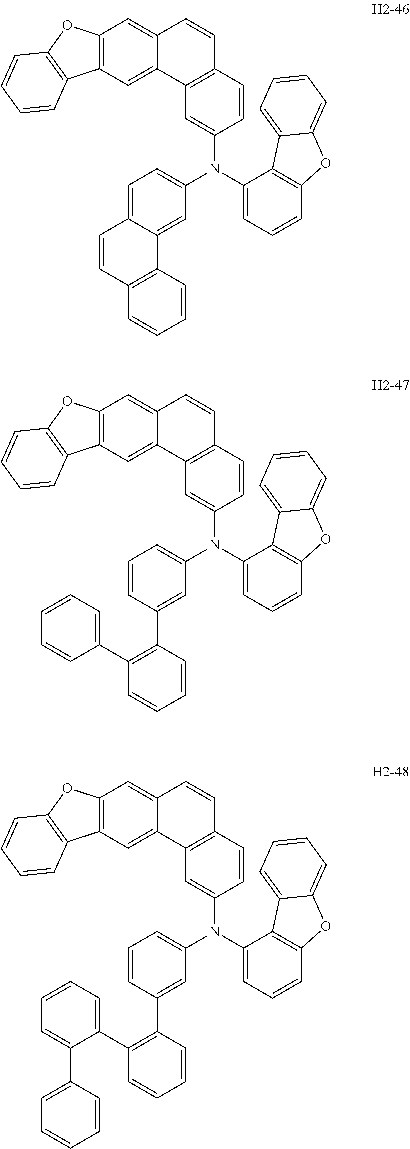 [SMILES: c1ccc2c(c1)ccc1ccc(N(c3ccc4ccc5cc6oc7ccccc7c6cc5c4c3)c3cccc4oc5ccccc5c34)cc12 ; c1ccc(-c2ccccc2-c2cccc(N(c3ccc4ccc5cc6oc7ccccc7c6cc5c4c3)c3cccc4oc5ccccc5c34)c2)cc1 ; c1ccc(-c2ccccc2-c2ccccc2-c2cccc(N(c3ccc4ccc5cc6oc7ccccc7c6cc5c4c3)c3cccc4oc5ccccc5c34)c2)cc1]

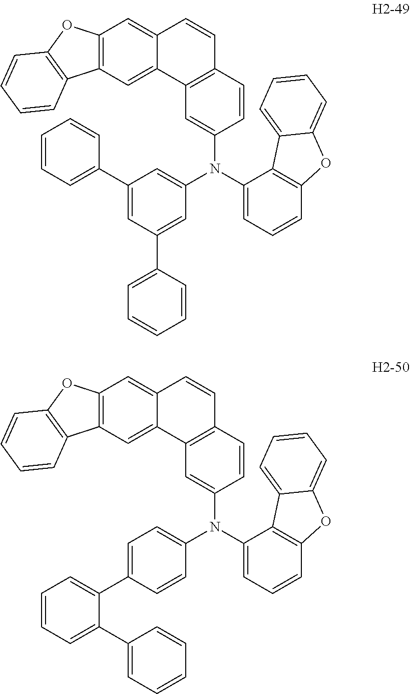 [SMILES: c1ccc(-c2cc(-c3ccccc3)cc(N(c3ccc4ccc5cc6oc7ccccc7c6cc5c4c3)c3cccc4oc5ccccc5c34)c2)cc1 ; c1ccc(-c2ccccc2-c2ccc(N(c3ccc4ccc5cc6oc7ccccc7c6cc5c4c3)c3cccc4oc5ccccc5c34)cc2)cc1]

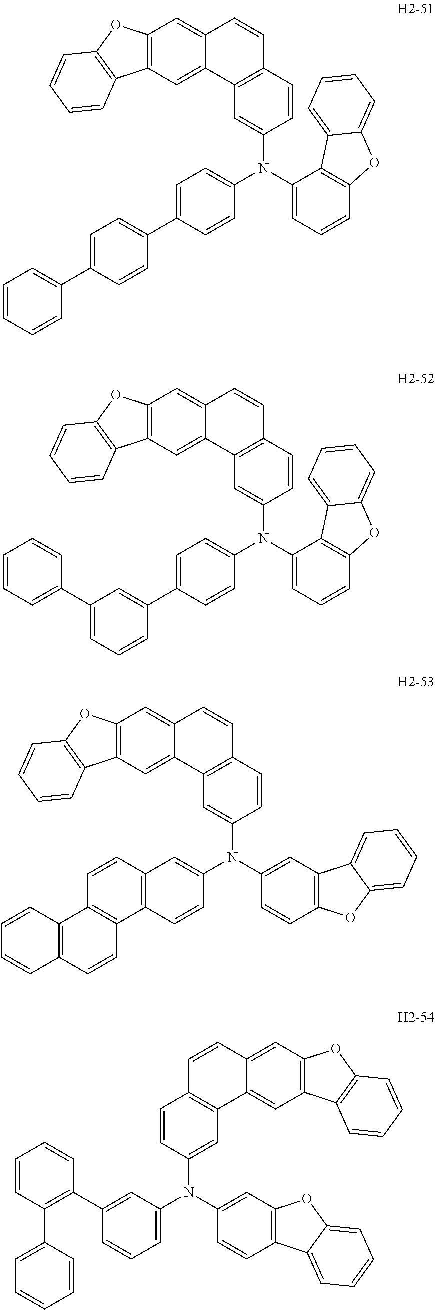 [SMILES: c1ccc(-c2ccc(-c3ccc(N(c4ccc5ccc6cc7oc8ccccc8c7cc6c5c4)c4cccc5oc6ccccc6c45)cc3)cc2)cc1 ; c1ccc(-c2cccc(-c3ccc(N(c4ccc5ccc6cc7oc8ccccc8c7cc6c5c4)c4cccc5oc6ccccc6c45)cc3)c2)cc1 ; c1ccc2c(c1)ccc1c3ccc(N(c4ccc5ccc6cc7oc8ccccc8c7cc6c5c4)c4ccc5oc6ccccc6c5c4)cc3ccc21 ; c1ccc(-c2ccccc2-c2cccc(N(c3ccc4c(c3)oc3ccccc34)c3ccc4ccc5cc6oc7ccccc7c6cc5c4c3)c2)cc1]

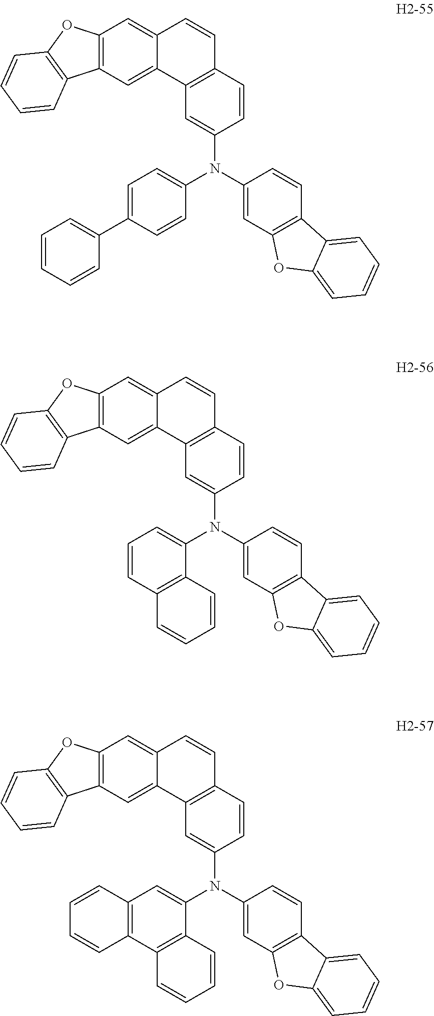 [SMILES: c1ccc(-c2ccc(N(c3ccc4c(c3)oc3ccccc34)c3ccc4ccc5cc6oc7ccccc7c6cc5c4c3)cc2)cc1 ; c1ccc2c(N(c3ccc4c(c3)oc3ccccc34)c3ccc4ccc5cc6oc7ccccc7c6cc5c4c3)cccc2c1 ; c1ccc2c(c1)cc(N(c1ccc3c(c1)oc1ccccc13)c1ccc3ccc4cc5oc6ccccc6c5cc4c3c1)c1ccccc12]

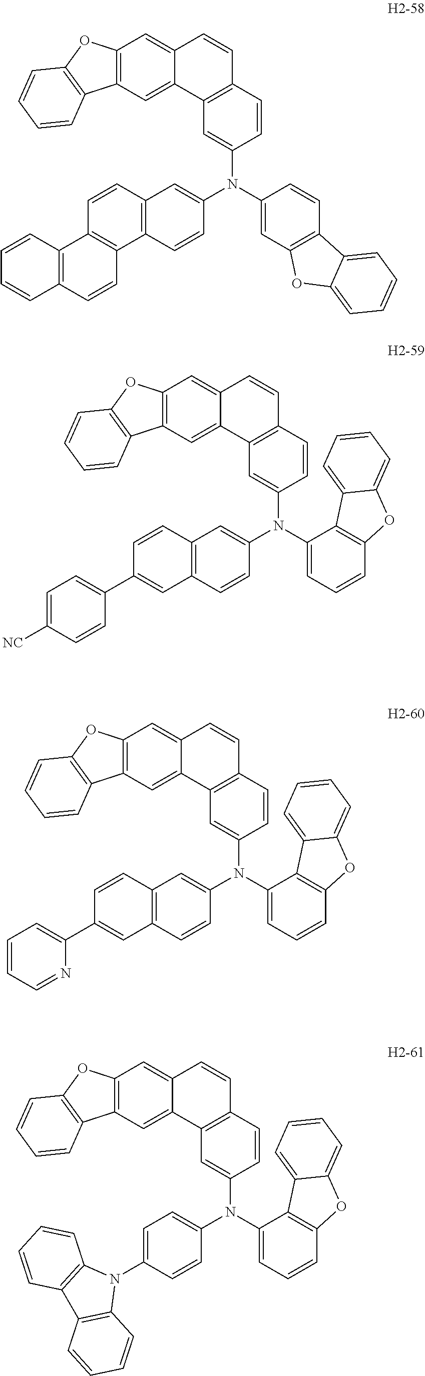 [SMILES: c1ccc2c(c1)ccc1c3ccc(N(c4ccc5c(c4)oc4ccccc45)c4ccc5ccc6cc7oc8ccccc8c7cc6c5c4)cc3ccc21 ; N#Cc1ccc(-c2ccc3cc(N(c4ccc5ccc6cc7oc8ccccc8c7cc6c5c4)c4cccc5oc6ccccc6c45)ccc3c2)cc1 ; c1ccc(-c2ccc3cc(N(c4ccc5ccc6cc7oc8ccccc8c7cc6c5c4)c4cccc5oc6ccccc6c45)ccc3c2)nc1 ; c1ccc2c(c1)oc1cc3ccc4ccc(N(c5ccc(-n6c7ccccc7c7ccccc76)cc5)c5cccc6oc7ccccc7c56)cc4c3cc12]

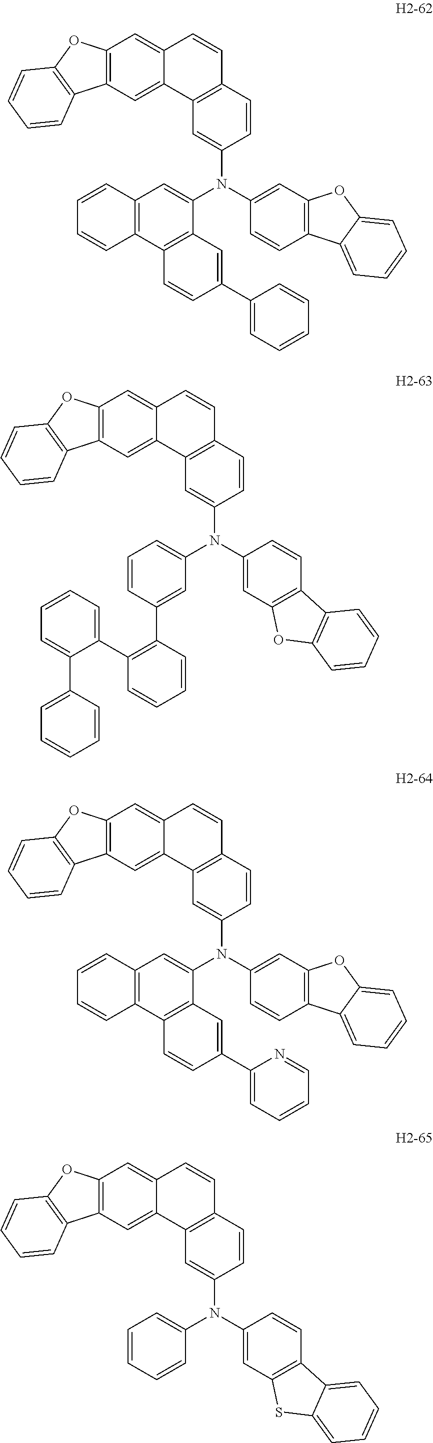 [SMILES: c1ccc(-c2ccc3c(c2)c(N(c2ccc4c(c2)oc2ccccc24)c2ccc4ccc5cc6oc7ccccc7c6cc5c4c2)cc2ccccc23)cc1 ; c1ccc(-c2ccccc2-c2ccccc2-c2cccc(N(c3ccc4c(c3)oc3ccccc34)c3ccc4ccc5cc6oc7ccccc7c6cc5c4c3)c2)cc1 ; c1ccc(-c2ccc3c(c2)c(N(c2ccc4c(c2)oc2ccccc24)c2ccc4ccc5cc6oc7ccccc7c6cc5c4c2)cc2ccccc23)nc1 ; c1ccc(N(c2ccc3c(c2)sc2ccccc23)c2ccc3ccc4cc5oc6ccccc6c5cc4c3c2)cc1]

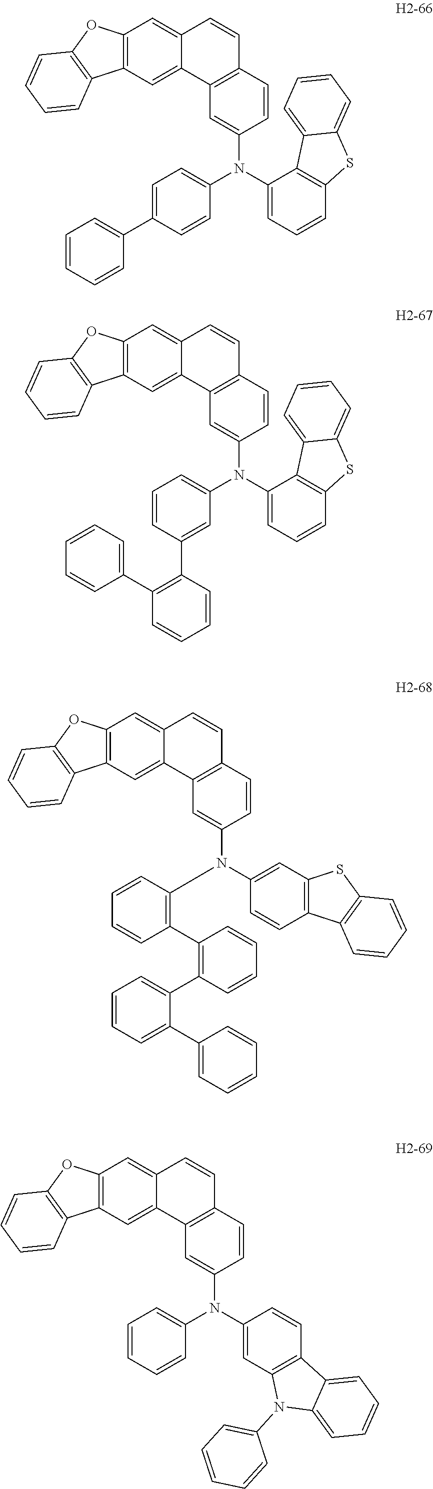

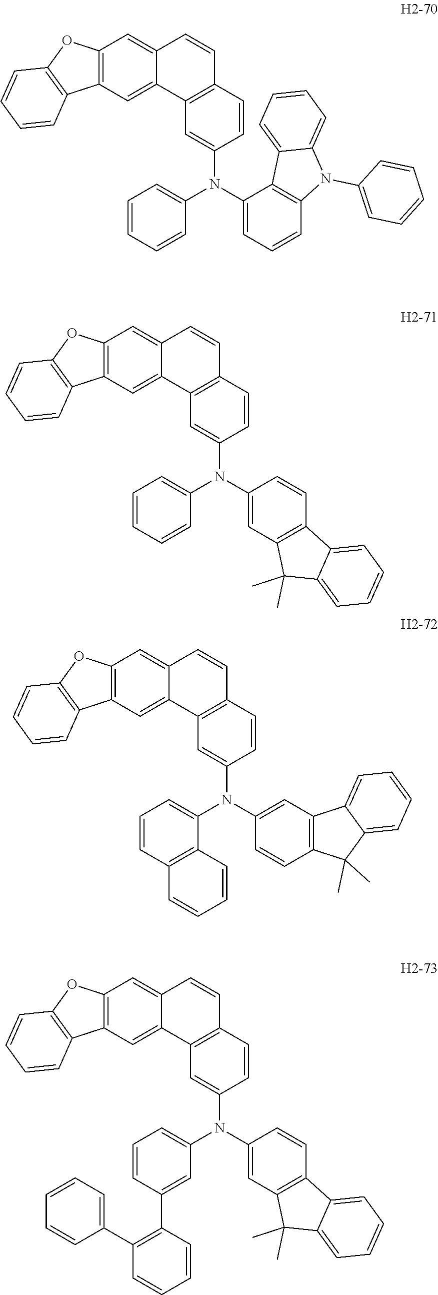 [SMILES: c1ccc(N(c2ccc3ccc4cc5oc6ccccc6c5cc4c3c2)c2cccc3c2c2ccccc2n3-c2ccccc2)cc1 ; CC1(C)c2ccccc2-c2ccc(N(c3ccccc3)c3ccc4ccc5cc6oc7ccccc7c6cc5c4c3)cc21 ; CC1(C)c2ccccc2-c2cc(N(c3ccc4ccc5cc6oc7ccccc7c6cc5c4c3)c3cccc4ccccc34)ccc21 ; CC1(C)c2ccccc2-c2ccc(N(c3cccc(-c4ccccc4-c4ccccc4)c3)c3ccc4ccc5cc6oc7ccccc7c6cc5c4c3)cc21]

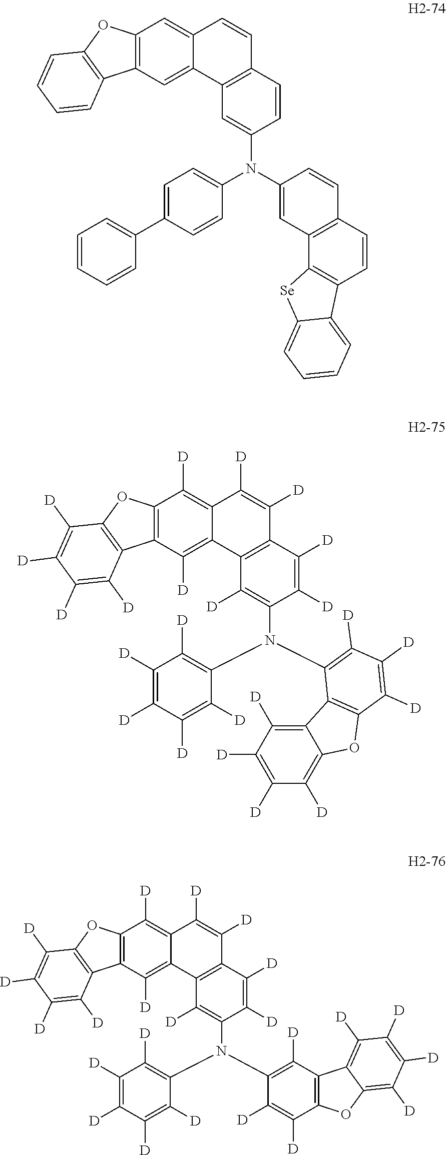 [SMILES: c1ccc(-c2ccc(N(c3ccc4ccc5cc6oc7ccccc7c6cc5c4c3)c3ccc4ccc5c6ccccc6[se]c5c4c3)cc2)cc1 ; [2H]c1c([2H])c([2H])c(N(c2c([2H])c([2H])c3c([2H])c([2H])c4c([2H])c5oc6c([2H])c([2H])c([2H])c([2H])c6c5c([2H])c4c3c2[2H])c2c([2H])c([2H])c([2H])c3oc4c([2H])c([2H])c([2H])c([2H])c4c23)c([2H])c1[2H] ; [2H]c1c([2H])c([2H])c(N(c2c([2H])c([2H])c3oc4c([2H])c([2H])c([2H])c([2H])c4c3c2[2H])c2c([2H])c([2H])c3c([2H])c([2H])c4c([2H])c5oc6c([2H])c([2H])c([2H])c([2H])c6c5c([2H])c4c3c2[2H])c([2H])c1[2H]]

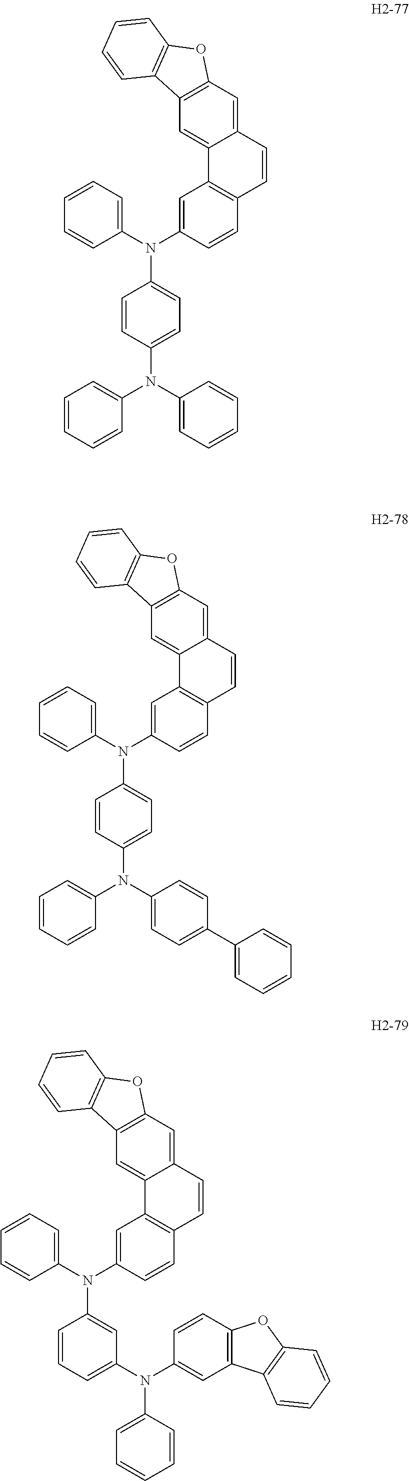 [SMILES: c1ccc(N(c2ccccc2)c2ccc(N(c3ccccc3)c3ccc4ccc5cc6oc7ccccc7c6cc5c4c3)cc2)cc1 ; c1ccc(-c2ccc(N(c3ccccc3)c3ccc(N(c4ccccc4)c4ccc5ccc6cc7oc8ccccc8c7cc6c5c4)cc3)cc2)cc1 ; c1ccc(N(c2cccc(N(c3ccccc3)c3ccc4oc5ccccc5c4c3)c2)c2ccc3ccc4cc5oc6ccccc6c5cc4c3c2)cc1]

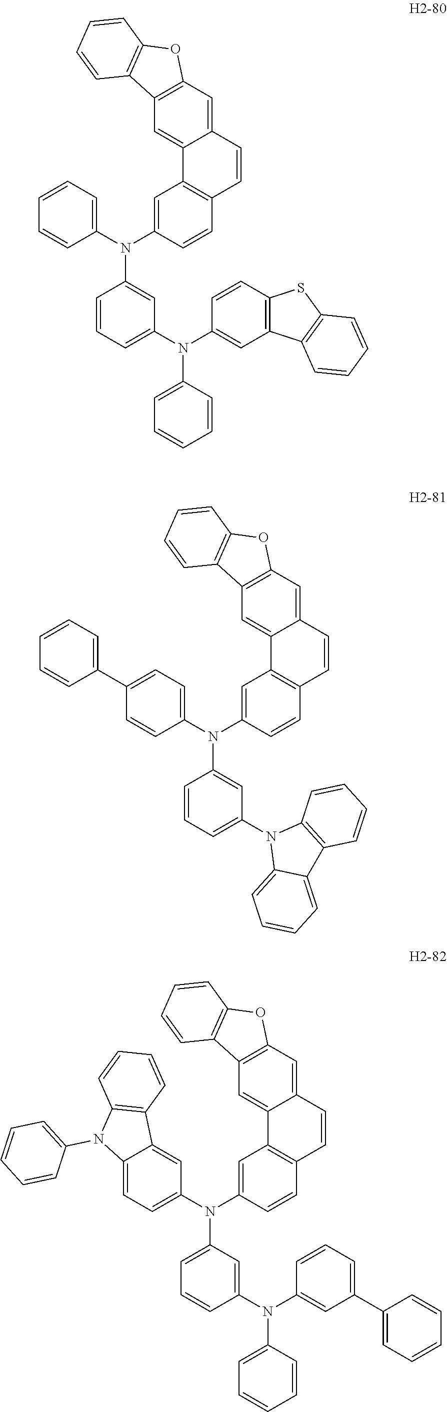 [SMILES: c1ccc(N(c2cccc(N(c3ccccc3)c3ccc4sc5ccccc5c4c3)c2)c2ccc3ccc4cc5oc6ccccc6c5cc4c3c2)cc1 ; c1ccc(-c2ccc(N(c3cccc(-n4c5ccccc5c5ccccc54)c3)c3ccc4ccc5cc6oc7ccccc7c6cc5c4c3)cc2)cc1 ; c1ccc(-c2cccc(N(c3ccccc3)c3cccc(N(c4ccc5ccc6cc7oc8ccccc8c7cc6c5c4)c4ccc5c(c4)c4ccccc4n5-c4ccccc4)c3)c2)cc1]

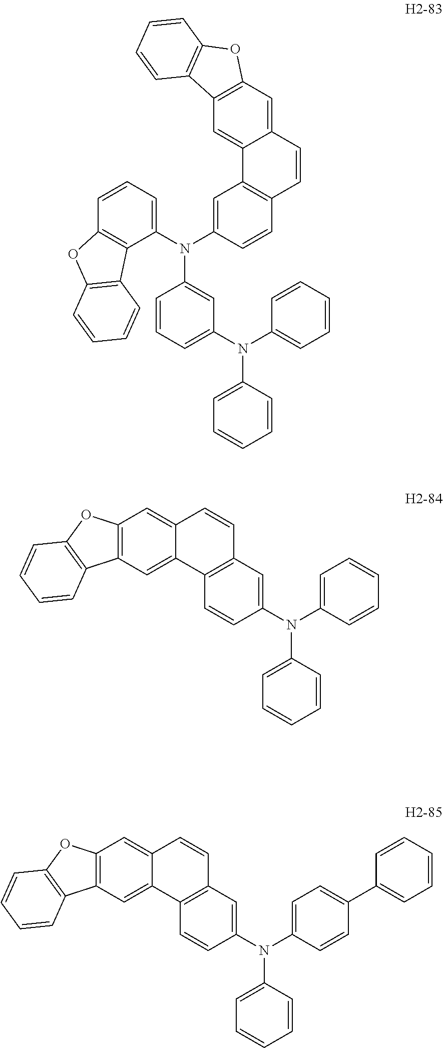 [SMILES: c1ccc(N(c2ccccc2)c2cccc(N(c3ccc4ccc5cc6oc7ccccc7c6cc5c4c3)c3cccc4oc5ccccc5c34)c2)cc1 ; c1ccc(N(c2ccccc2)c2ccc3c(ccc4cc5oc6ccccc6c5cc43)c2)cc1 ; c1ccc(-c2ccc(N(c3ccccc3)c3ccc4c(ccc5cc6oc7ccccc7c6cc54)c3)cc2)cc1]

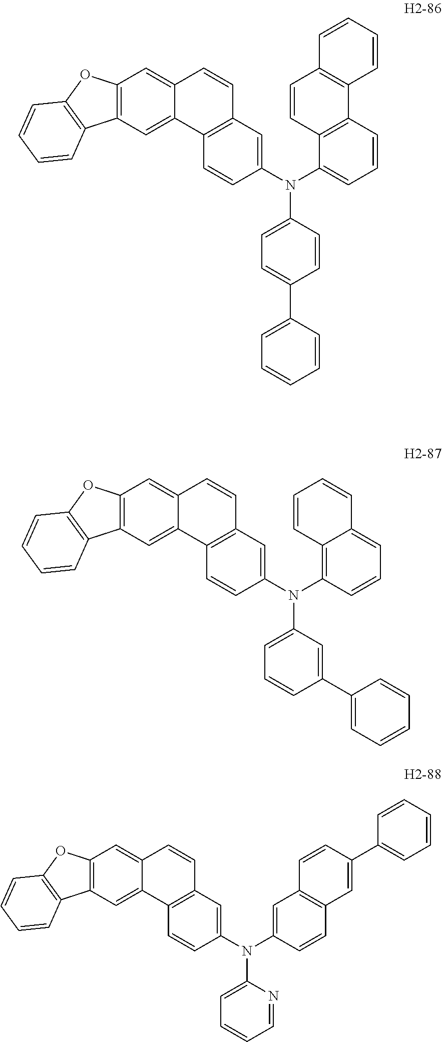 [SMILES: c1ccc(-c2ccc(N(c3ccc4c(ccc5cc6oc7ccccc7c6cc54)c3)c3cccc4c3ccc3ccccc34)cc2)cc1 ; c1ccc(-c2cccc(N(c3ccc4c(ccc5cc6oc7ccccc7c6cc54)c3)c3cccc4ccccc34)c2)cc1 ; c1ccc(-c2ccc3cc(N(c4ccc5c(ccc6cc7oc8ccccc8c7cc65)c4)c4ccccn4)ccc3c2)cc1]

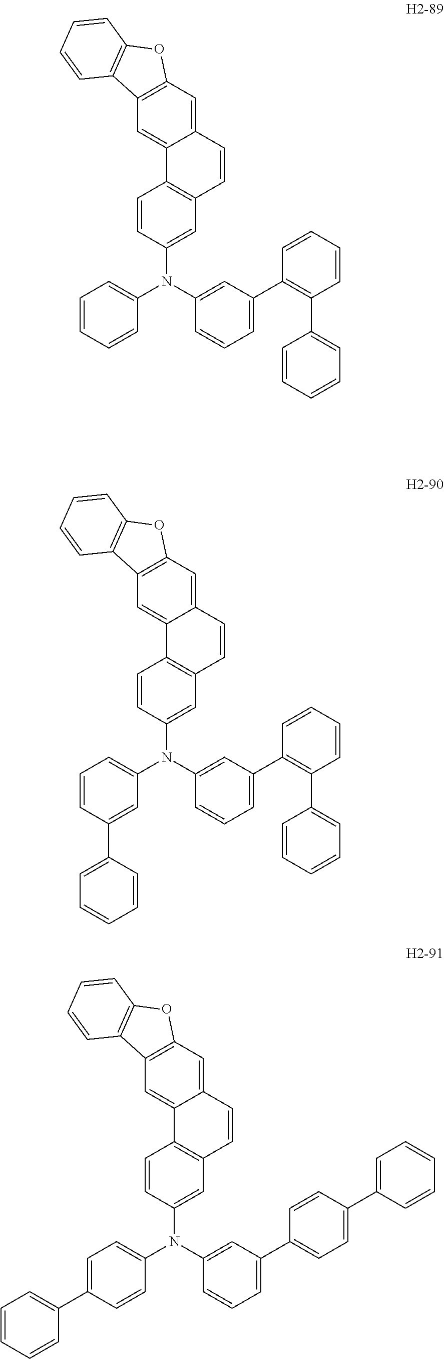 [SMILES: c1ccc(-c2ccccc2-c2cccc(N(c3ccccc3)c3ccc4c(ccc5cc6oc7ccccc7c6cc54)c3)c2)cc1 ; c1ccc(-c2cccc(N(c3cccc(-c4ccccc4-c4ccccc4)c3)c3ccc4c(ccc5cc6oc7ccccc7c6cc54)c3)c2)cc1 ; c1ccc(-c2ccc(-c3cccc(N(c4ccc(-c5ccccc5)cc4)c4ccc5c(ccc6cc7oc8ccccc8c7cc65)c4)c3)cc2)cc1]

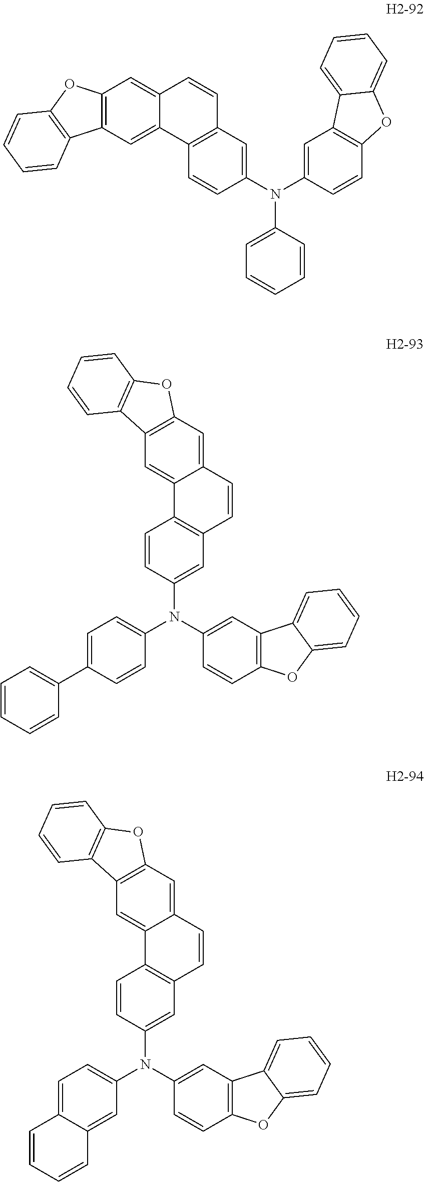 [SMILES: c1ccc(N(c2ccc3c(ccc4cc5oc6ccccc6c5cc43)c2)c2ccc3oc4ccccc4c3c2)cc1 ; c1ccc(-c2ccc(N(c3ccc4c(ccc5cc6oc7ccccc7c6cc54)c3)c3ccc4oc5ccccc5c4c3)cc2)cc1 ; c1ccc2cc(N(c3ccc4c(ccc5cc6oc7ccccc7c6cc54)c3)c3ccc4oc5ccccc5c4c3)ccc2c1]

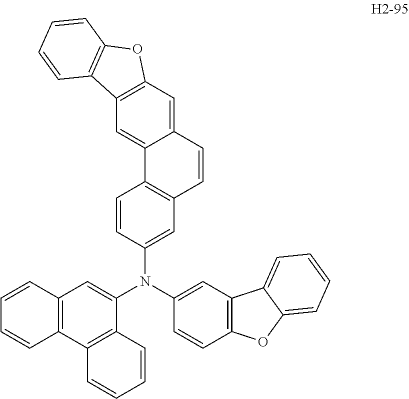 [SMILES: c1ccc2c(c1)cc(N(c1ccc3c(ccc4cc5oc6ccccc6c5cc43)c1)c1ccc3oc4ccccc4c3c1)c1ccccc12]

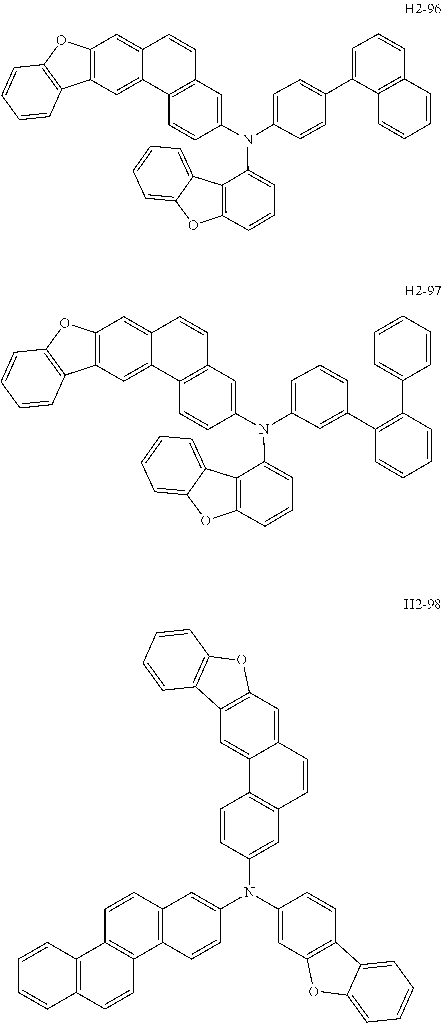 [SMILES: c1ccc2c(-c3ccc(N(c4ccc5c(ccc6cc7oc8ccccc8c7cc65)c4)c4cccc5oc6ccccc6c45)cc3)cccc2c1 ; c1ccc(-c2ccccc2-c2cccc(N(c3ccc4c(ccc5cc6oc7ccccc7c6cc54)c3)c3cccc4oc5ccccc5c34)c2)cc1 ; c1ccc2c(c1)ccc1c3ccc(N(c4ccc5c(ccc6cc7oc8ccccc8c7cc65)c4)c4ccc5c(c4)oc4ccccc45)cc3ccc21]

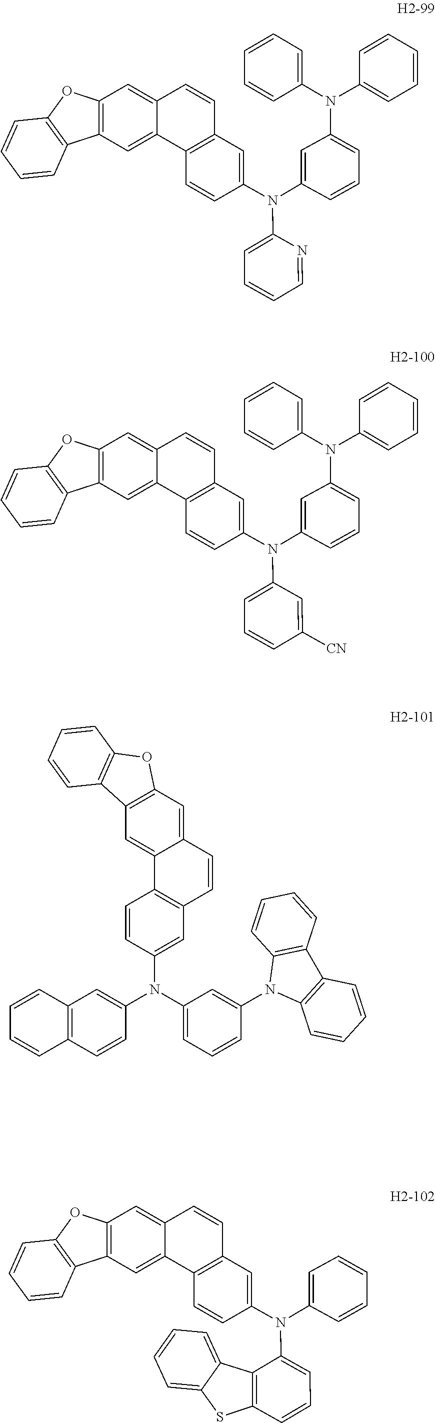 [SMILES: c1ccc(N(c2ccccc2)c2cccc(N(c3ccc4c(ccc5cc6oc7ccccc7c6cc54)c3)c3ccccn3)c2)cc1 ; N#Cc1cccc(N(c2cccc(N(c3ccccc3)c3ccccc3)c2)c2ccc3c(ccc4cc5oc6ccccc6c5cc43)c2)c1 ; c1cc(N(c2ccc3ccccc3c2)c2ccc3c(ccc4cc5oc6ccccc6c5cc43)c2)cc(-n2c3ccccc3c3ccccc32)c1 ; c1ccc(N(c2ccc3c(ccc4cc5oc6ccccc6c5cc43)c2)c2cccc3sc4ccccc4c23)cc1]

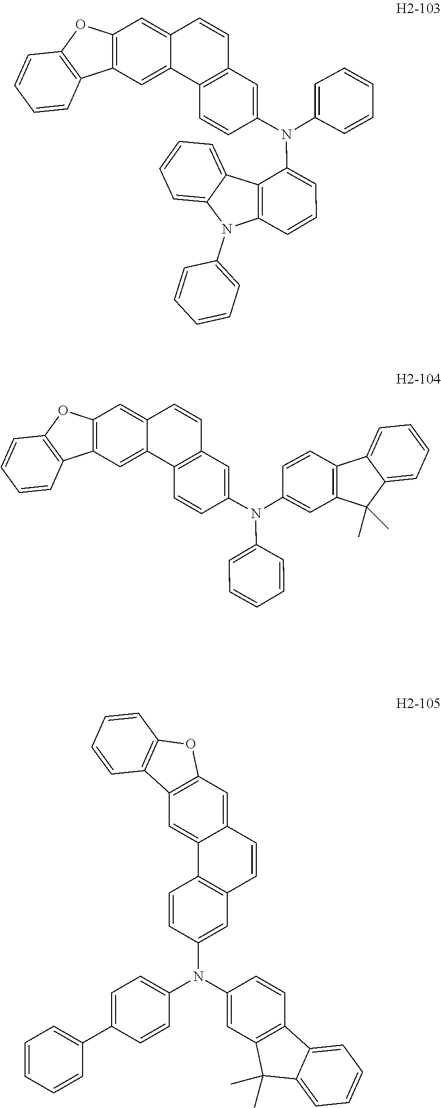 [SMILES: c1ccc(N(c2ccc3c(ccc4cc5oc6ccccc6c5cc43)c2)c2cccc3c2c2ccccc2n3-c2ccccc2)cc1 ; CC1(C)c2ccccc2-c2ccc(N(c3ccccc3)c3ccc4c(ccc5cc6oc7ccccc7c6cc54)c3)cc21 ; CC1(C)c2ccccc2-c2ccc(N(c3ccc(-c4ccccc4)cc3)c3ccc4c(ccc5cc6oc7ccccc7c6cc54)c3)cc21]

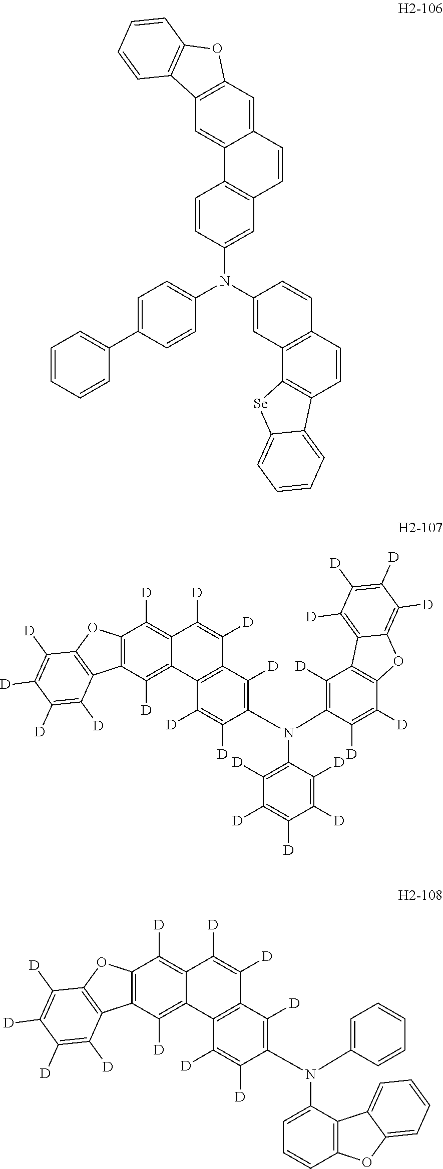 [SMILES: c1ccc(-c2ccc(N(c3ccc4c(ccc5cc6oc7ccccc7c6cc54)c3)c3ccc4ccc5c6ccccc6[se]c5c4c3)cc2)cc1 ; [2H]c1c([2H])c([2H])c(N(c2c([2H])c([2H])c3c(c2[2H])c([2H])c([2H])c2c([2H])c4oc5c([2H])c([2H])c([2H])c([2H])c5c4c([2H])c23)c2c([2H])c([2H])c3oc4c([2H])c([2H])c([2H])c([2H])c4c3c2[2H])c([2H])c1[2H] ; [2H]c1c([2H])c([2H])c2c(oc3c([2H])c4c([2H])c([2H])c5c([2H])c(N(c6ccccc6)c6cccc7oc8ccccc8c67)c([2H])c([2H])c5c4c([2H])c32)c1[2H]]

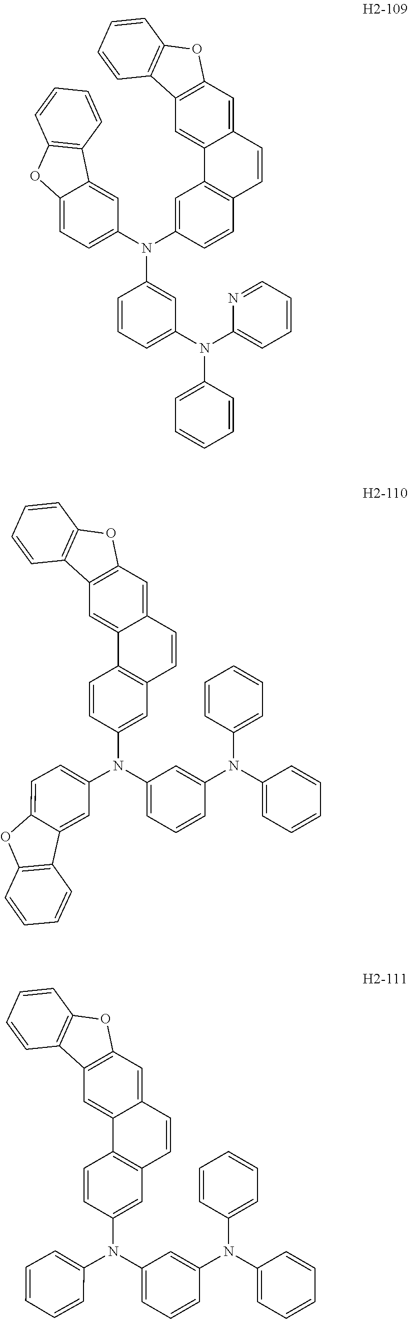 [SMILES: c1ccc(N(c2cccc(N(c3ccc4ccc5cc6oc7ccccc7c6cc5c4c3)c3ccc4oc5ccccc5c4c3)c2)c2ccccn2)cc1 ; c1ccc(N(c2ccccc2)c2cccc(N(c3ccc4c(ccc5cc6oc7ccccc7c6cc54)c3)c3ccc4oc5ccccc5c4c3)c2)cc1 ; c1ccc(N(c2ccccc2)c2cccc(N(c3ccccc3)c3ccc4c(ccc5cc6oc7ccccc7c6cc54)c3)c2)cc1]

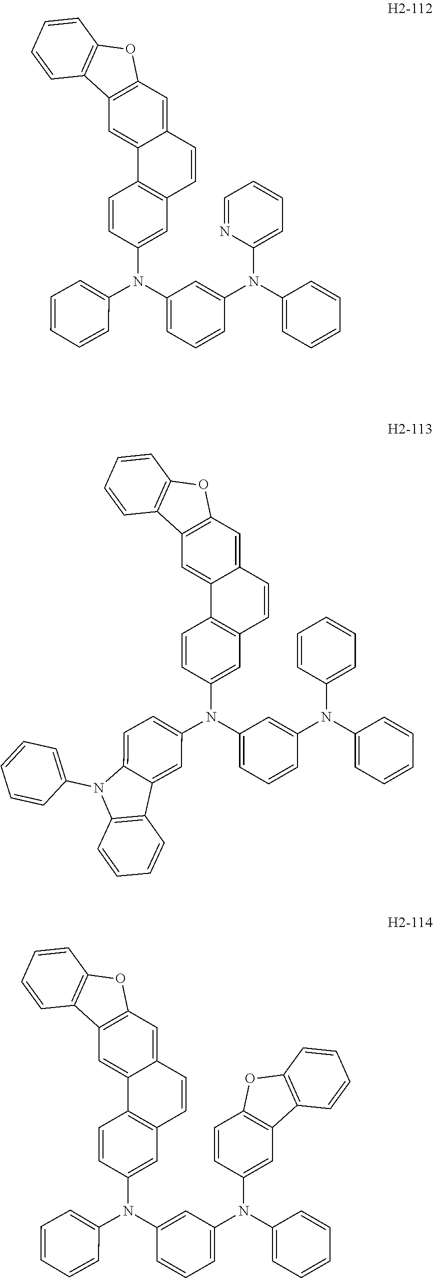 [SMILES: c1ccc(N(c2cccc(N(c3ccccc3)c3ccccn3)c2)c2ccc3c(ccc4cc5oc6ccccc6c5cc43)c2)cc1 ; c1ccc(N(c2ccccc2)c2cccc(N(c3ccc4c(ccc5cc6oc7ccccc7c6cc54)c3)c3ccc4c(c3)c3ccccc3n4-c3ccccc3)c2)cc1 ; c1ccc(N(c2cccc(N(c3ccccc3)c3ccc4oc5ccccc5c4c3)c2)c2ccc3c(ccc4cc5oc6ccccc6c5cc43)c2)cc1]

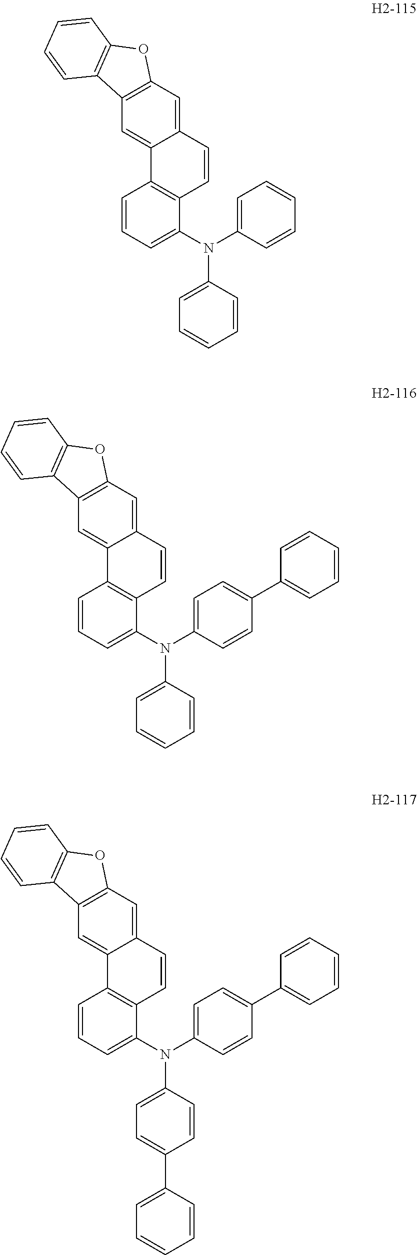 [SMILES: c1ccc(N(c2ccccc2)c2cccc3c2ccc2cc4oc5ccccc5c4cc23)cc1 ; c1ccc(-c2ccc(N(c3ccccc3)c3cccc4c3ccc3cc5oc6ccccc6c5cc34)cc2)cc1 ; c1ccc(-c2ccc(N(c3ccc(-c4ccccc4)cc3)c3cccc4c3ccc3cc5oc6ccccc6c5cc34)cc2)cc1]

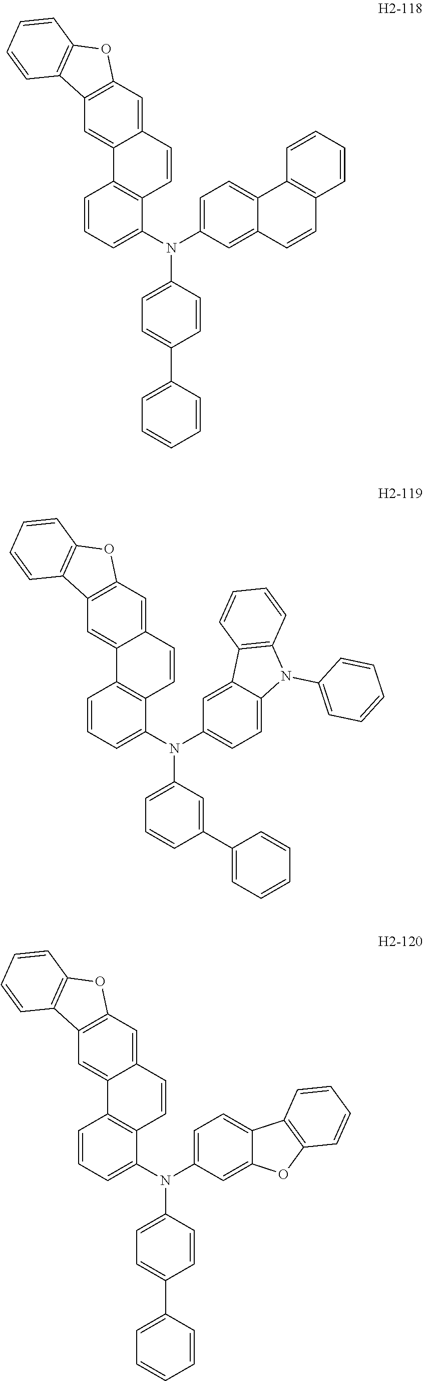 [SMILES: c1ccc(-c2ccc(N(c3ccc4c(ccc5ccccc54)c3)c3cccc4c3ccc3cc5oc6ccccc6c5cc34)cc2)cc1 ; c1ccc(-c2cccc(N(c3ccc4c(c3)c3ccccc3n4-c3ccccc3)c3cccc4c3ccc3cc5oc6ccccc6c5cc34)c2)cc1 ; c1ccc(-c2ccc(N(c3ccc4c(c3)oc3ccccc34)c3cccc4c3ccc3cc5oc6ccccc6c5cc34)cc2)cc1]

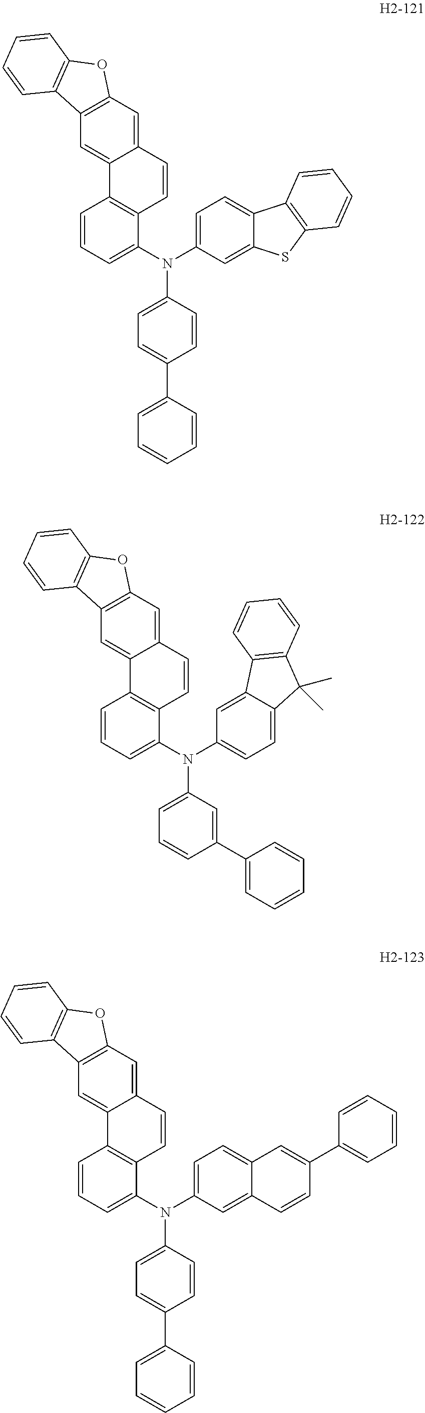 [SMILES: c1ccc(-c2ccc(N(c3ccc4c(c3)sc3ccccc34)c3cccc4c3ccc3cc5oc6ccccc6c5cc34)cc2)cc1 ; CC1(C)c2ccccc2-c2cc(N(c3cccc(-c4ccccc4)c3)c3cccc4c3ccc3cc5oc6ccccc6c5cc34)ccc21 ; c1ccc(-c2ccc(N(c3ccc4cc(-c5ccccc5)ccc4c3)c3cccc4c3ccc3cc5oc6ccccc6c5cc34)cc2)cc1]

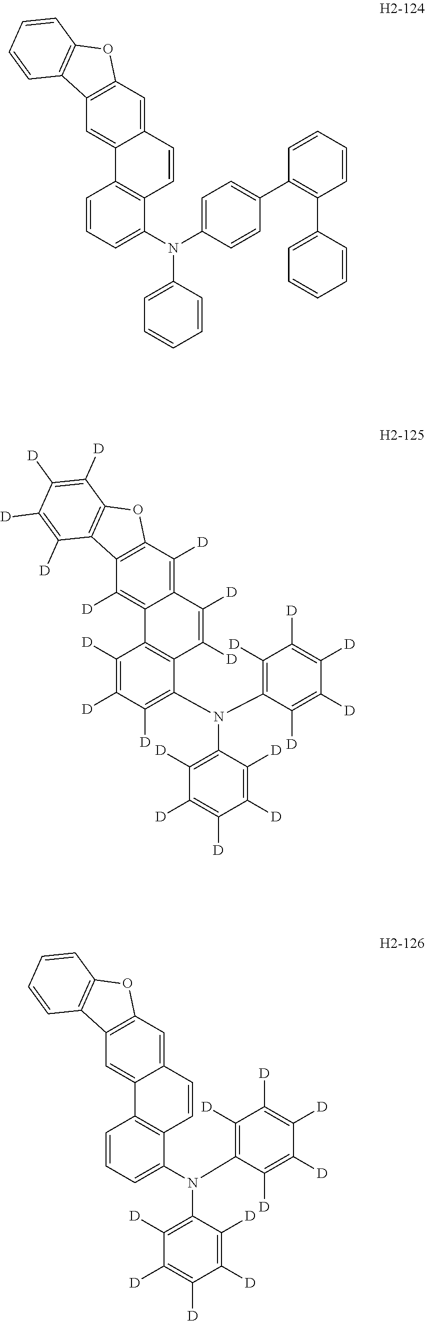 [SMILES: c1ccc(-c2ccccc2-c2ccc(N(c3ccccc3)c3cccc4c3ccc3cc5oc6ccccc6c5cc34)cc2)cc1 ; [2H]c1c([2H])c([2H])c(N(c2c([2H])c([2H])c([2H])c([2H])c2[2H])c2c([2H])c([2H])c([2H])c3c2c([2H])c([2H])c2c([2H])c4oc5c([2H])c([2H])c([2H])c([2H])c5c4c([2H])c23)c([2H])c1[2H] ; [2H]c1c([2H])c([2H])c(N(c2c([2H])c([2H])c([2H])c([2H])c2[2H])c2cccc3c2ccc2cc4oc5ccccc5c4cc23)c([2H])c1[2H]]

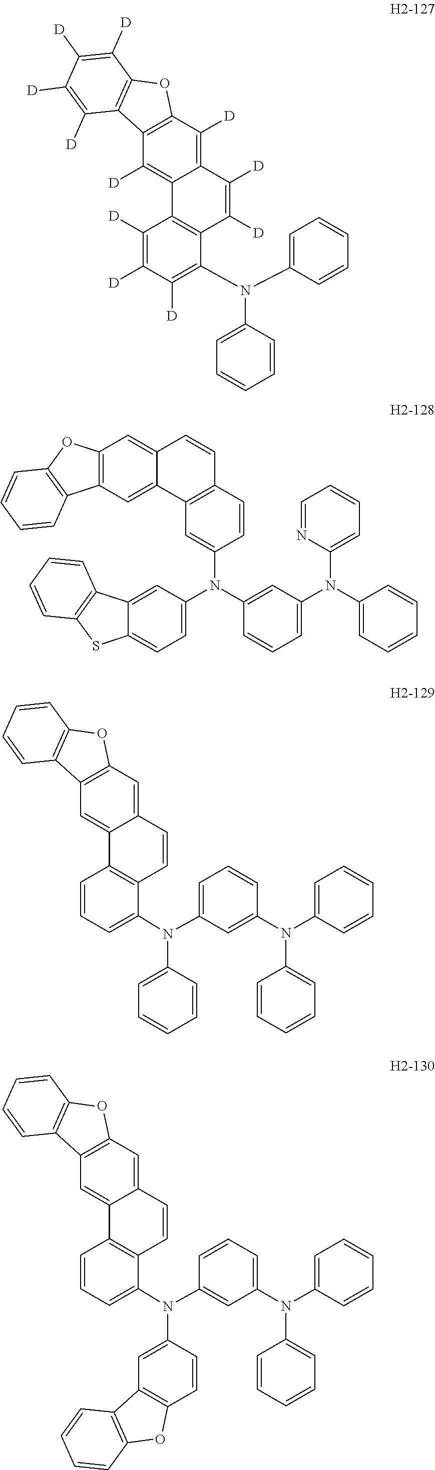 [SMILES: [2H]c1c([2H])c([2H])c2c(oc3c([2H])c4c([2H])c([2H])c5c(N(c6ccccc6)c6ccccc6)c([2H])c([2H])c([2H])c5c4c([2H])c32)c1[2H] ; c1ccc(N(c2cccc(N(c3ccc4ccc5cc6oc7ccccc7c6cc5c4c3)c3ccc4sc5ccccc5c4c3)c2)c2ccccn2)cc1 ; c1ccc(N(c2ccccc2)c2cccc(N(c3ccccc3)c3cccc4c3ccc3cc5oc6ccccc6c5cc34)c2)cc1 ; c1ccc(N(c2ccccc2)c2cccc(N(c3ccc4oc5ccccc5c4c3)c3cccc4c3ccc3cc5oc6ccccc6c5cc34)c2)cc1]

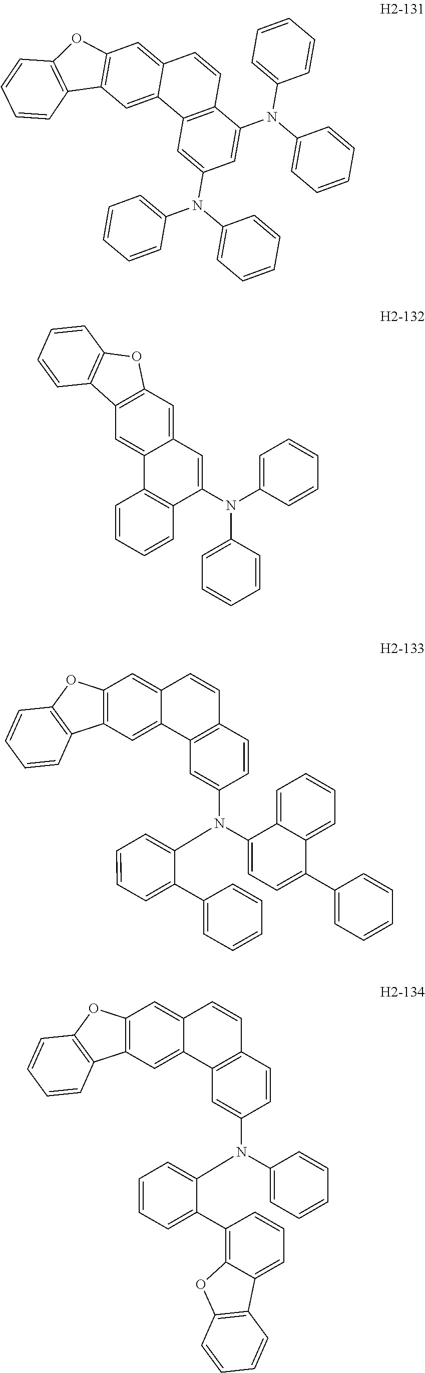 [SMILES: c1ccc(N(c2ccccc2)c2cc(N(c3ccccc3)c3ccccc3)c3ccc4cc5oc6ccccc6c5cc4c3c2)cc1 ; c1ccc(N(c2ccccc2)c2cc3cc4oc5ccccc5c4cc3c3ccccc23)cc1 ; c1ccc(-c2ccccc2N(c2ccc3ccc4cc5oc6ccccc6c5cc4c3c2)c2ccc(-c3ccccc3)c3ccccc23)cc1 ; c1ccc(N(c2ccc3ccc4cc5oc6ccccc6c5cc4c3c2)c2ccccc2-c2cccc3c2oc2ccccc23)cc1]

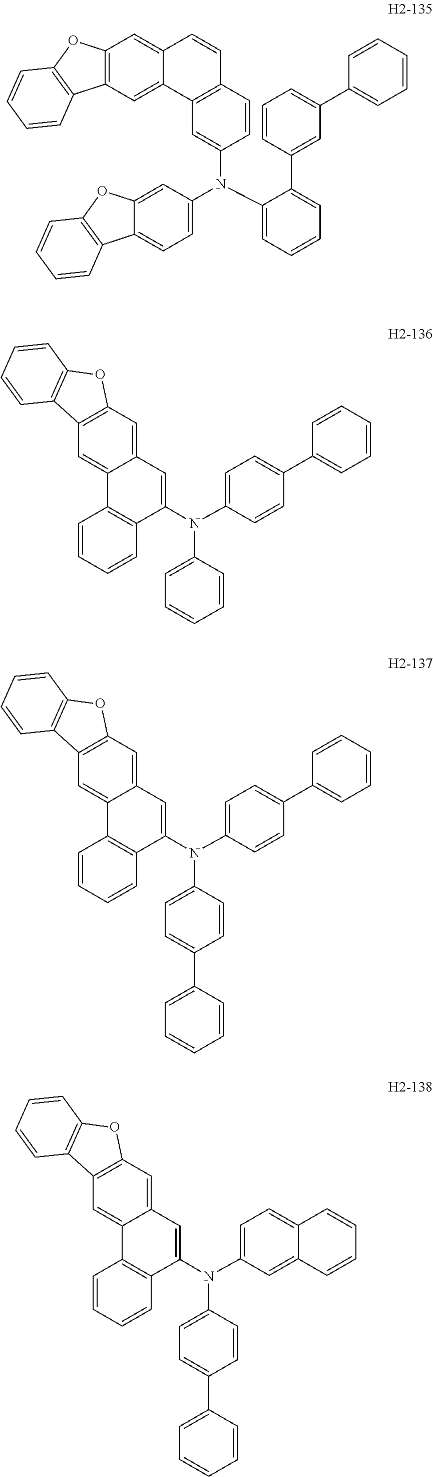 [SMILES: c1ccc(-c2cccc(-c3ccccc3N(c3ccc4c(c3)oc3ccccc34)c3ccc4ccc5cc6oc7ccccc7c6cc5c4c3)c2)cc1 ; c1ccc(-c2ccc(N(c3ccccc3)c3cc4cc5oc6ccccc6c5cc4c4ccccc34)cc2)cc1 ; c1ccc(-c2ccc(N(c3ccc(-c4ccccc4)cc3)c3cc4cc5oc6ccccc6c5cc4c4ccccc34)cc2)cc1 ; c1ccc(-c2ccc(N(c3ccc4ccccc4c3)c3cc4cc5oc6ccccc6c5cc4c4ccccc34)cc2)cc1]

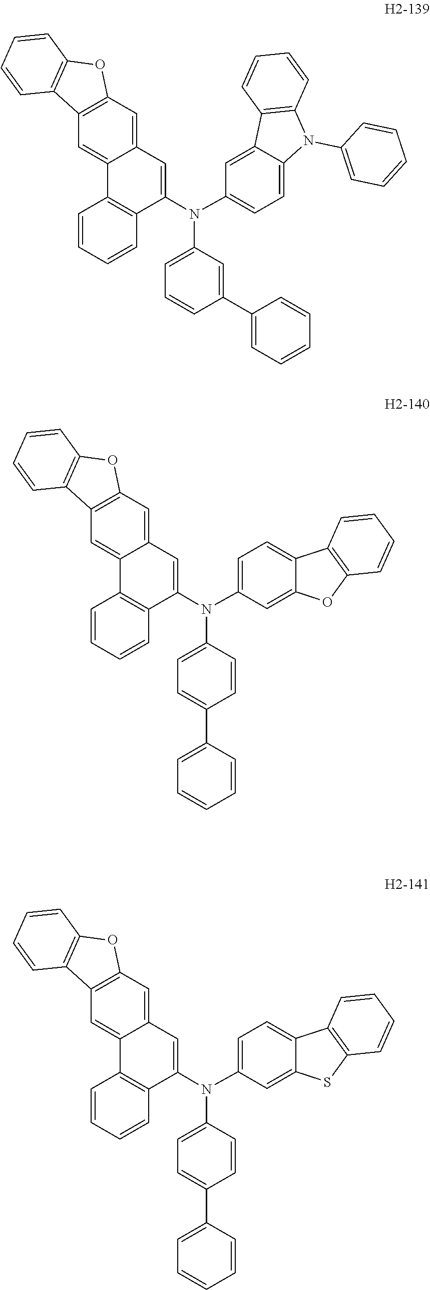 [SMILES: c1ccc(-c2cccc(N(c3ccc4c(c3)c3ccccc3n4-c3ccccc3)c3cc4cc5oc6ccccc6c5cc4c4ccccc34)c2)cc1 ; c1ccc(-c2ccc(N(c3ccc4c(c3)oc3ccccc34)c3cc4cc5oc6ccccc6c5cc4c4ccccc34)cc2)cc1 ; c1ccc(-c2ccc(N(c3ccc4c(c3)sc3ccccc34)c3cc4cc5oc6ccccc6c5cc4c4ccccc34)cc2)cc1]

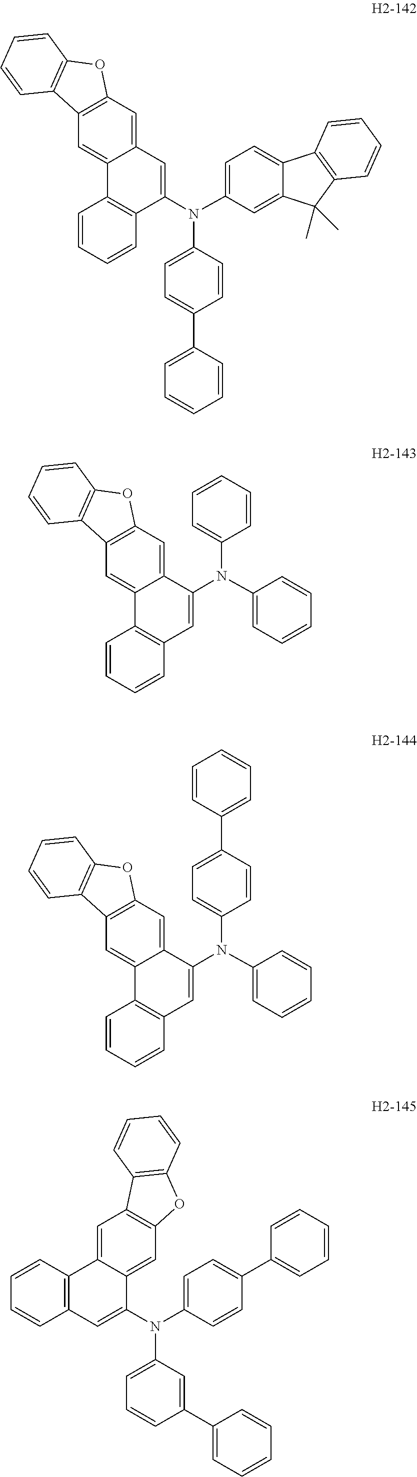 [SMILES: CC1(C)c2ccccc2-c2ccc(N(c3ccc(-c4ccccc4)cc3)c3cc4cc5oc6ccccc6c5cc4c4ccccc34)cc21 ; c1ccc(N(c2ccccc2)c2cc3ccccc3c3cc4c(cc23)oc2ccccc24)cc1 ; c1ccc(-c2ccc(N(c3ccccc3)c3cc4ccccc4c4cc5c(cc34)oc3ccccc35)cc2)cc1 ; c1ccc(-c2ccc(N(c3cccc(-c4ccccc4)c3)c3cc4ccccc4c4cc5c(cc34)oc3ccccc35)cc2)cc1]

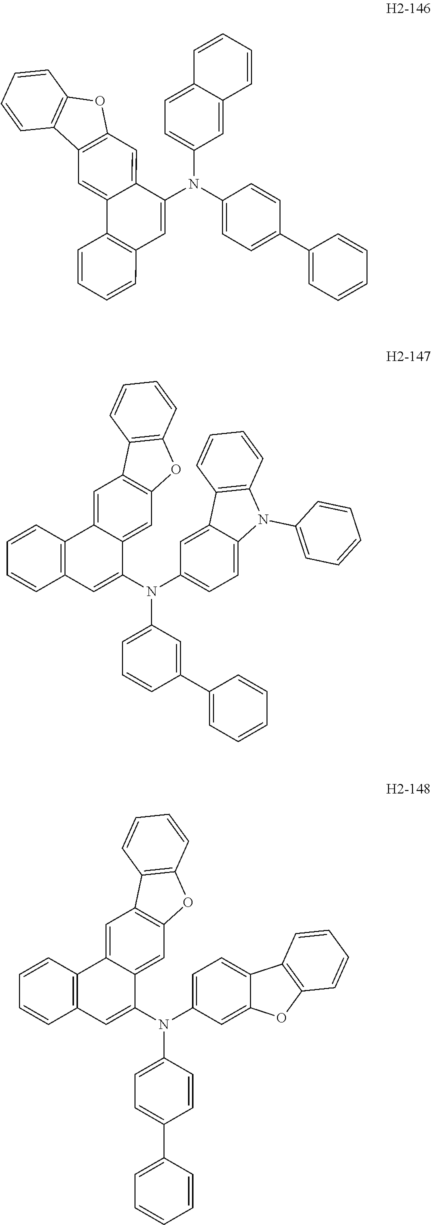 [SMILES: c1ccc(-c2ccc(N(c3ccc4ccccc4c3)c3cc4ccccc4c4cc5c(cc34)oc3ccccc35)cc2)cc1 ; c1ccc(-c2cccc(N(c3ccc4c(c3)c3ccccc3n4-c3ccccc3)c3cc4ccccc4c4cc5c(cc34)oc3ccccc35)c2)cc1 ; c1ccc(-c2ccc(N(c3ccc4c(c3)oc3ccccc34)c3cc4ccccc4c4cc5c(cc34)oc3ccccc35)cc2)cc1]

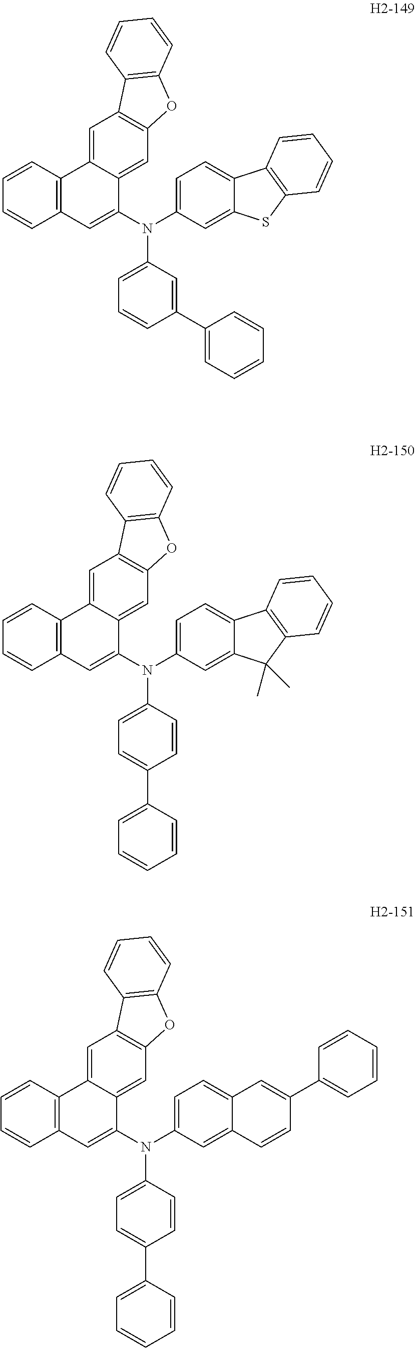 [SMILES: c1ccc(-c2cccc(N(c3ccc4c(c3)sc3ccccc34)c3cc4ccccc4c4cc5c(cc34)oc3ccccc35)c2)cc1 ; CC1(C)c2ccccc2-c2ccc(N(c3ccc(-c4ccccc4)cc3)c3cc4ccccc4c4cc5c(cc34)oc3ccccc35)cc21 ; c1ccc(-c2ccc(N(c3ccc4cc(-c5ccccc5)ccc4c3)c3cc4ccccc4c4cc5c(cc34)oc3ccccc35)cc2)cc1]

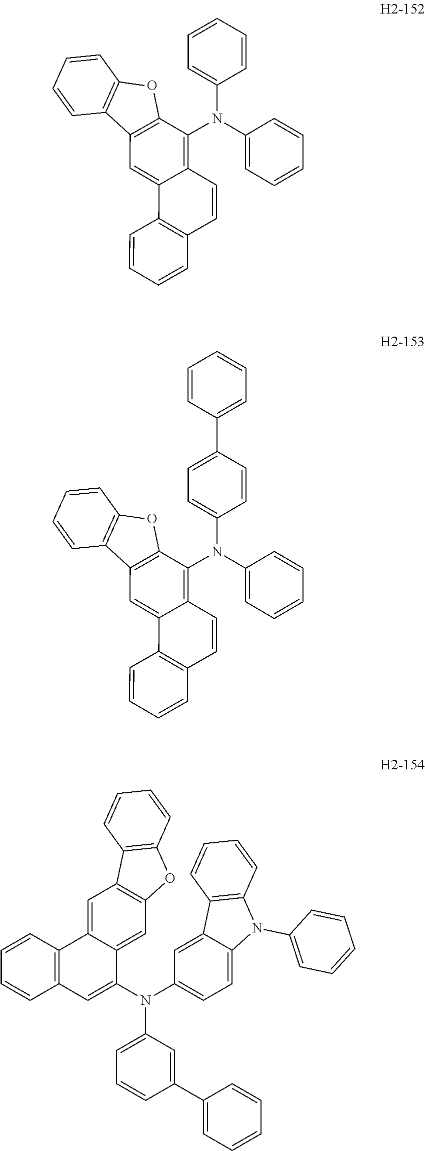 [SMILES: c1ccc(N(c2ccccc2)c2c3ccc4ccccc4c3cc3c2oc2ccccc23)cc1 ; c1ccc(-c2ccc(N(c3ccccc3)c3c4ccc5ccccc5c4cc4c3oc3ccccc34)cc2)cc1 ; c1ccc(-c2cccc(N(c3ccc4c(c3)c3ccccc3n4-c3ccccc3)c3cc4ccccc4c4cc5c(cc34)oc3ccccc35)c2)cc1]

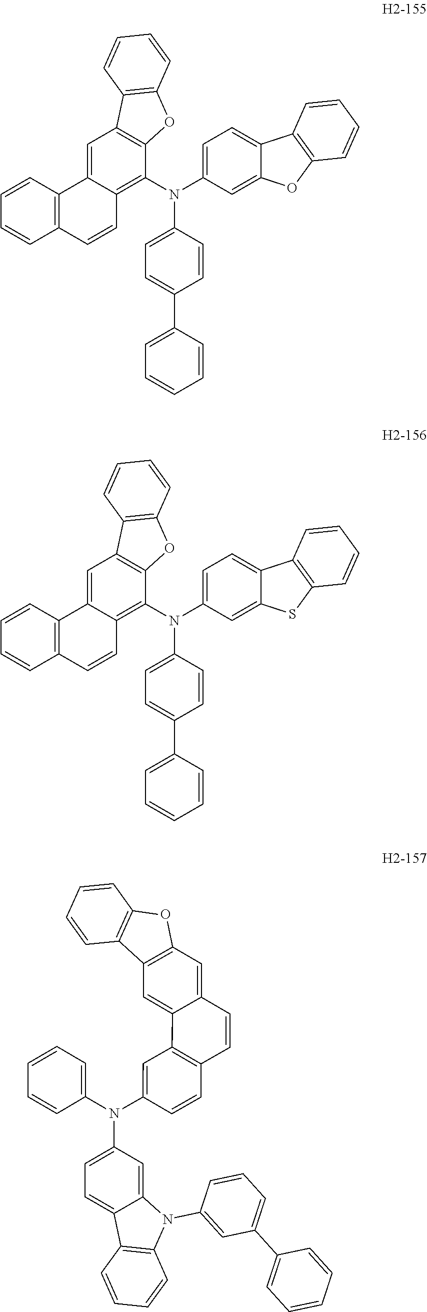 [SMILES: c1ccc(-c2ccc(N(c3ccc4c(c3)oc3ccccc34)c3c4ccc5ccccc5c4cc4c3oc3ccccc34)cc2)cc1 ; c1ccc(-c2ccc(N(c3ccc4c(c3)sc3ccccc34)c3c4ccc5ccccc5c4cc4c3oc3ccccc34)cc2)cc1 ; c1ccc(-c2cccc(-n3c4ccccc4c4ccc(N(c5ccccc5)c5ccc6ccc7cc8oc9ccccc9c8cc7c6c5)cc43)c2)cc1]

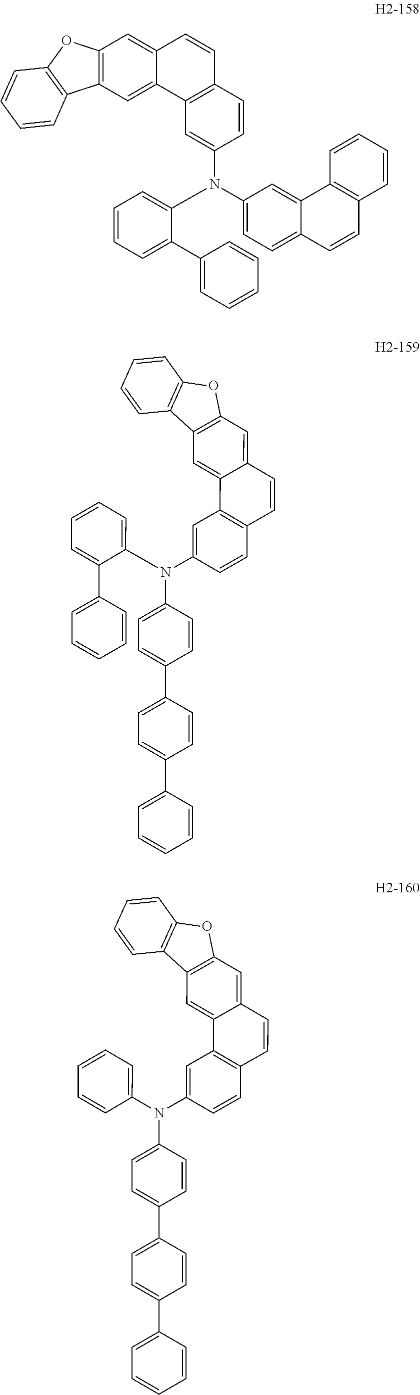 [SMILES: c1ccc(-c2ccccc2N(c2ccc3ccc4ccccc4c3c2)c2ccc3ccc4cc5oc6ccccc6c5cc4c3c2)cc1 ; c1ccc(-c2ccc(-c3ccc(N(c4ccc5ccc6cc7oc8ccccc8c7cc6c5c4)c4ccccc4-c4ccccc4)cc3)cc2)cc1 ; c1ccc(-c2ccc(-c3ccc(N(c4ccccc4)c4ccc5ccc6cc7oc8ccccc8c7cc6c5c4)cc3)cc2)cc1]

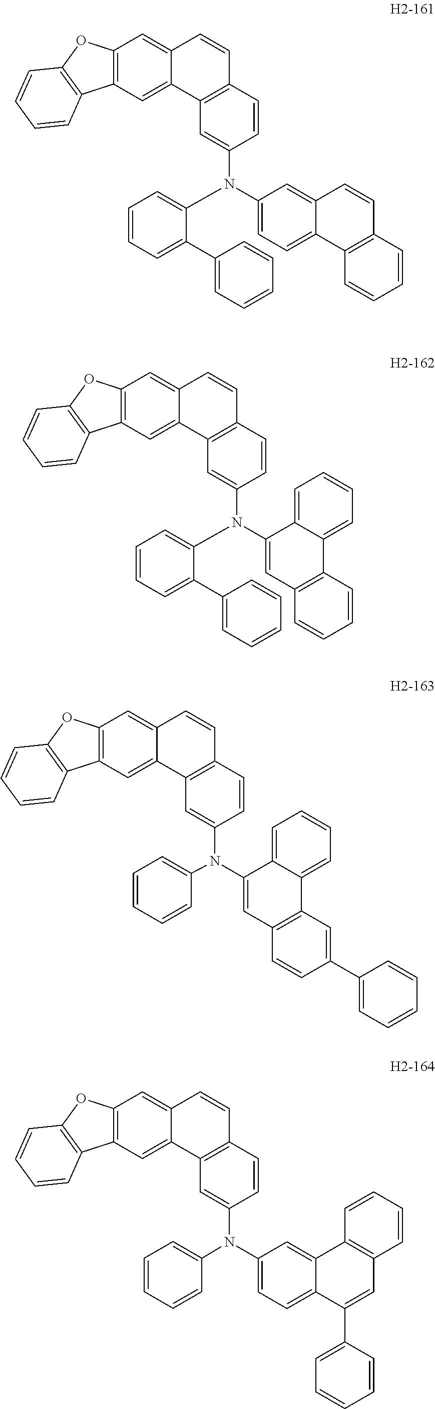 [SMILES: c1ccc(-c2ccccc2N(c2ccc3c(ccc4ccccc43)c2)c2ccc3ccc4cc5oc6ccccc6c5cc4c3c2)cc1 ; c1ccc(-c2ccccc2N(c2ccc3ccc4cc5oc6ccccc6c5cc4c3c2)c2cc3ccccc3c3ccccc23)cc1 ; c1ccc(-c2ccc3cc(N(c4ccccc4)c4ccc5ccc6cc7oc8ccccc8c7cc6c5c4)c4ccccc4c3c2)cc1 ; c1ccc(-c2cc3ccccc3c3cc(N(c4ccccc4)c4ccc5ccc6cc7oc8ccccc8c7cc6c5c4)ccc23)cc1]

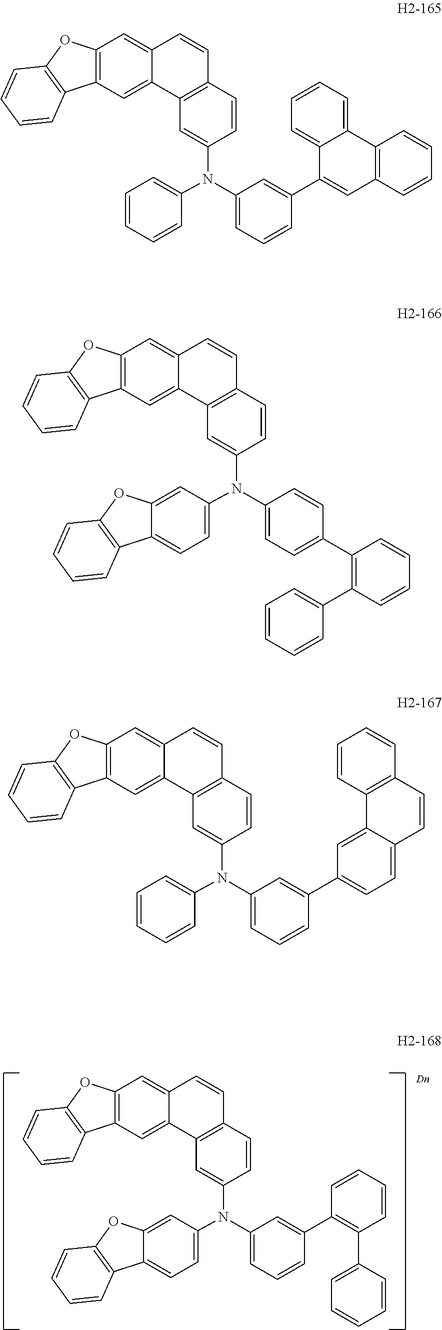

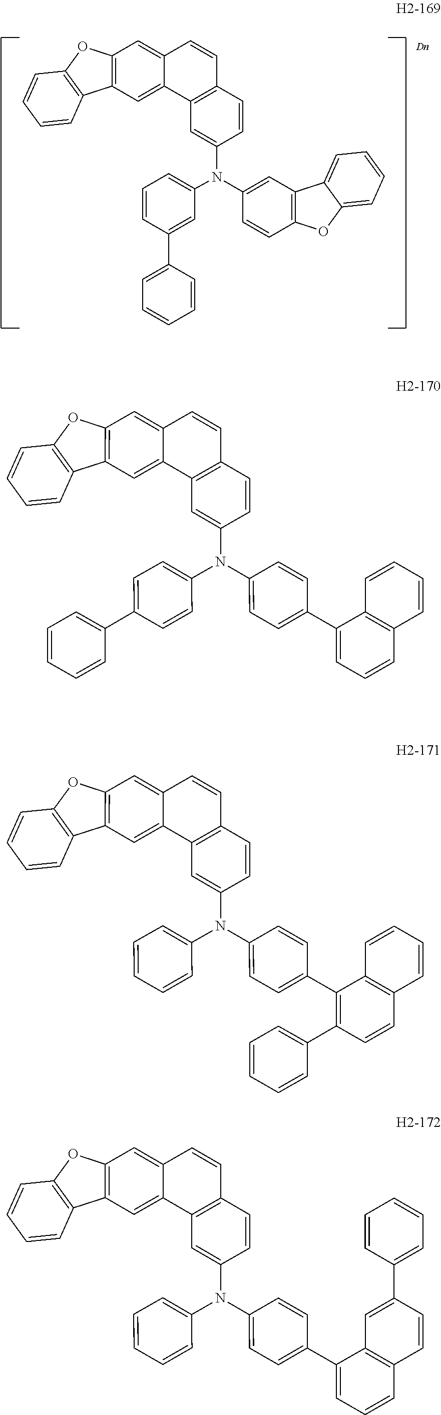

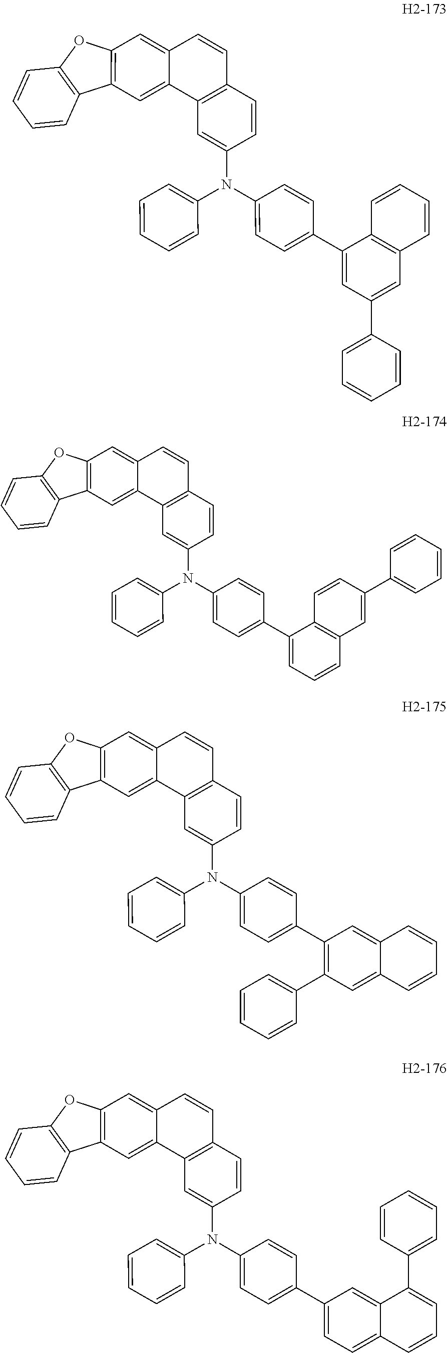 [SMILES: c1ccc(-c2cc(-c3ccc(N(c4ccccc4)c4ccc5ccc6cc7oc8ccccc8c7cc6c5c4)cc3)c3ccccc3c2)cc1 ; c1ccc(-c2ccc3c(-c4ccc(N(c5ccccc5)c5ccc6ccc7cc8oc9ccccc9c8cc7c6c5)cc4)cccc3c2)cc1 ; c1ccc(-c2cc3ccccc3cc2-c2ccc(N(c3ccccc3)c3ccc4ccc5cc6oc7ccccc7c6cc5c4c3)cc2)cc1 ; c1ccc(-c2cccc3ccc(-c4ccc(N(c5ccccc5)c5ccc6ccc7cc8oc9ccccc9c8cc7c6c5)cc4)cc23)cc1]

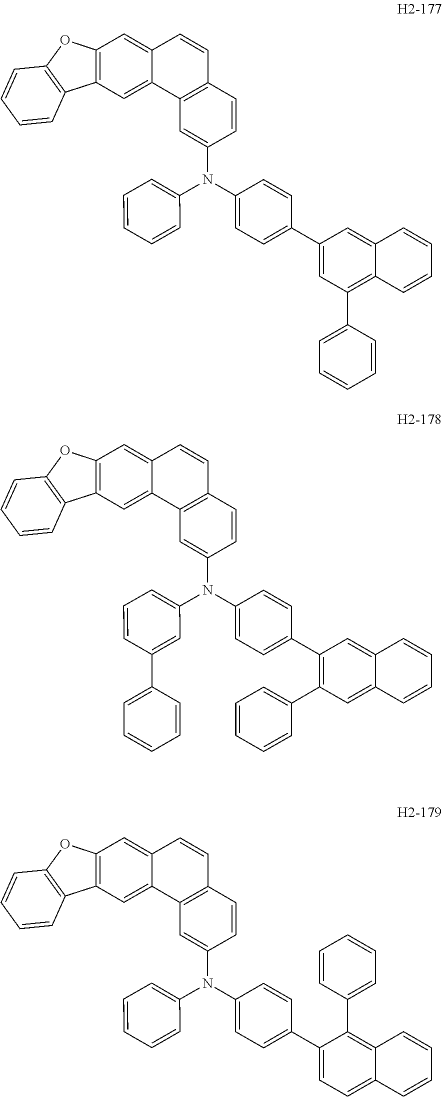 [SMILES: c1ccc(-c2cc(-c3ccc(N(c4ccccc4)c4ccc5ccc6cc7oc8ccccc8c7cc6c5c4)cc3)cc3ccccc23)cc1 ; c1ccc(-c2cccc(N(c3ccc(-c4cc5ccccc5cc4-c4ccccc4)cc3)c3ccc4ccc5cc6oc7ccccc7c6cc5c4c3)c2)cc1 ; c1ccc(-c2c(-c3ccc(N(c4ccccc4)c4ccc5ccc6cc7oc8ccccc8c7cc6c5c4)cc3)ccc3ccccc23)cc1]

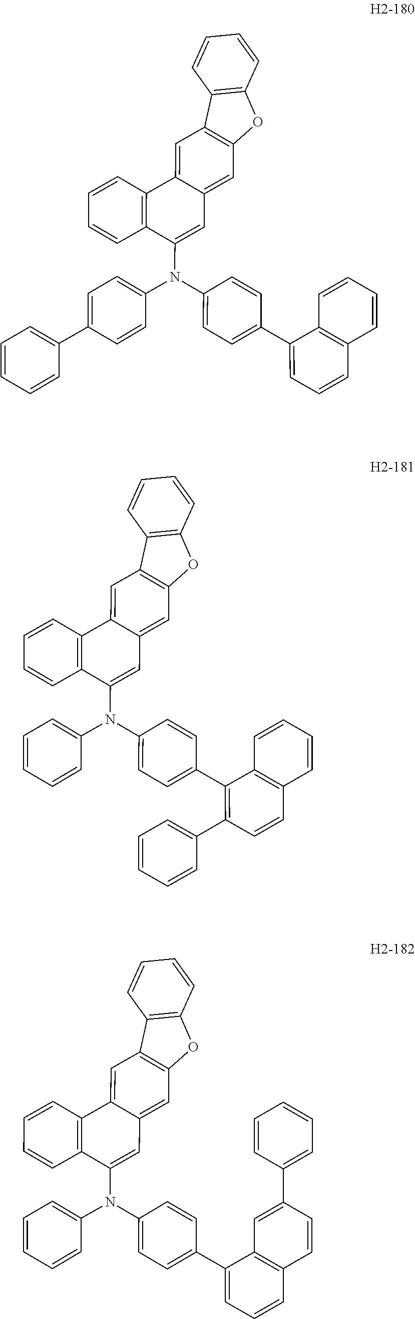 [SMILES: c1ccc(-c2ccc(N(c3ccc(-c4cccc5ccccc45)cc3)c3cc4cc5oc6ccccc6c5cc4c4ccccc34)cc2)cc1 ; c1ccc(-c2ccc3ccccc3c2-c2ccc(N(c3ccccc3)c3cc4cc5oc6ccccc6c5cc4c4ccccc34)cc2)cc1 ; c1ccc(-c2ccc3cccc(-c4ccc(N(c5ccccc5)c5cc6cc7oc8ccccc8c7cc6c6ccccc56)cc4)c3c2)cc1]

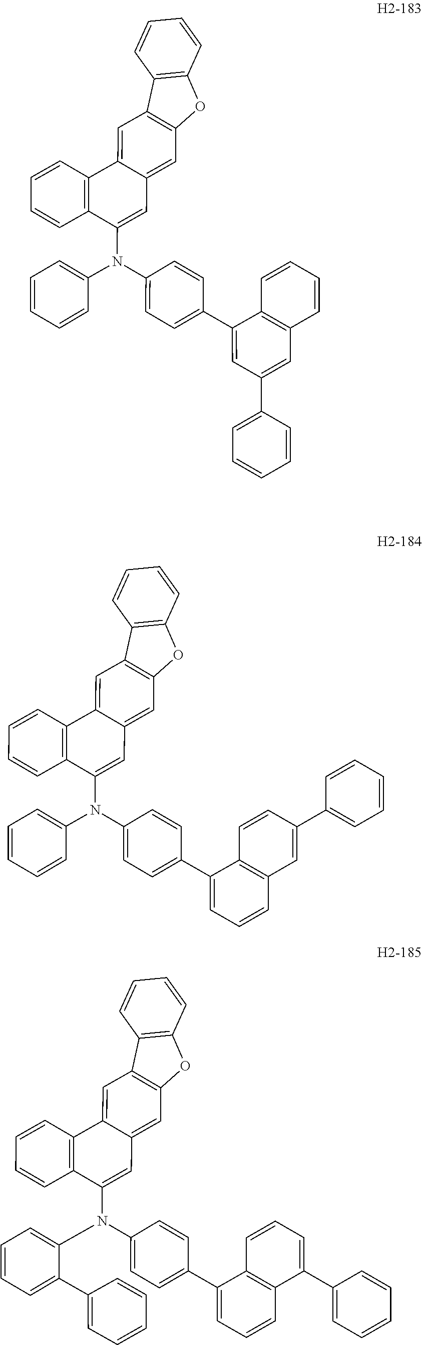 [SMILES: c1ccc(-c2cc(-c3ccc(N(c4ccccc4)c4cc5cc6oc7ccccc7c6cc5c5ccccc45)cc3)c3ccccc3c2)cc1 ; c1ccc(-c2ccc3c(-c4ccc(N(c5ccccc5)c5cc6cc7oc8ccccc8c7cc6c6ccccc56)cc4)cccc3c2)cc1 ; c1ccc(-c2ccccc2N(c2ccc(-c3cccc4c(-c5ccccc5)cccc34)cc2)c2cc3cc4oc5ccccc5c4cc3c3ccccc23)cc1]

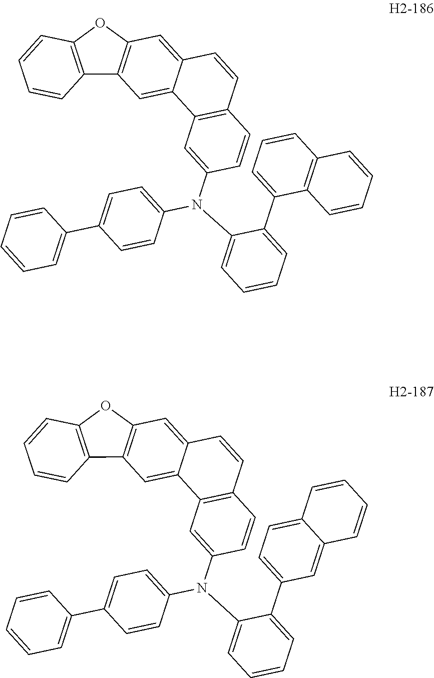 [SMILES: c1ccc(-c2ccc(N(c3ccc4ccc5cc6oc7ccccc7c6cc5c4c3)c3ccccc3-c3cccc4ccccc34)cc2)cc1 ; c1ccc(-c2ccc(N(c3ccc4ccc5cc6oc7ccccc7c6cc5c4c3)c3ccccc3-c3ccc4ccccc4c3)cc2)cc1]

In the compounds above, Dₙ means that n hydrogen atoms are replaced with deuterium, wherein n is an integer from 1 to the maximum number of hydrogen atoms in the compound.

The compound represented by Formula 2 according to the present disclosure may be synthesized by referring to synthetic methods known to one skilled in the art, and in particular, as synthetic method disclosed in a number of patent documents can be used. For example, the compound represented by Formula 2-1 according to the present disclosure may be synthesized by referring to synthetic methods disclosed in Korean Patent Application Laid-Open Nos. 2017-0022865 (published on Mar. 2, 2017) and 2018-0099487 (published on Sep. 6, 2018), etc., but is not limited thereto. For example, the compound represented by Formula 2-2 may be prepared as shown in the following Reaction Scheme 2, but is not limited thereto, and can also be prepared via a synthetic method known to those skilled in the art.

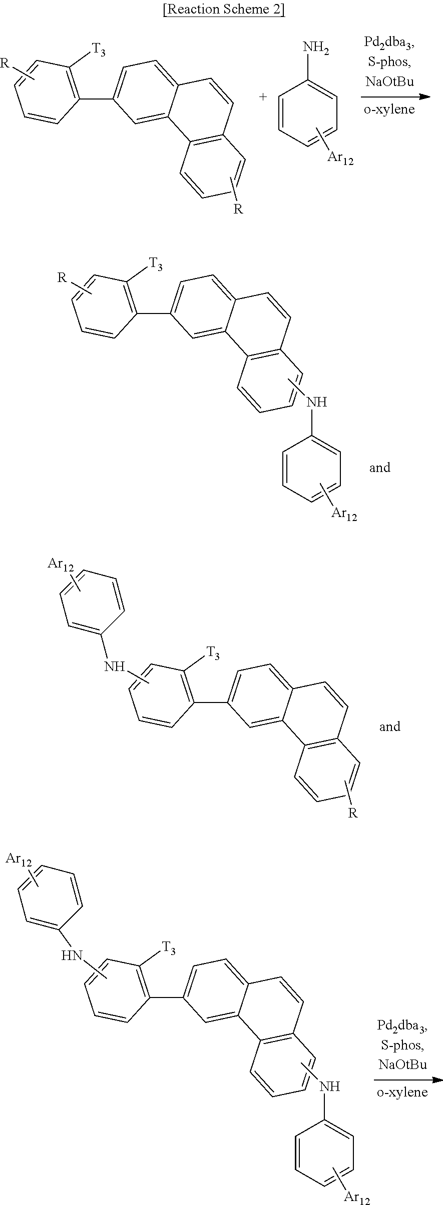

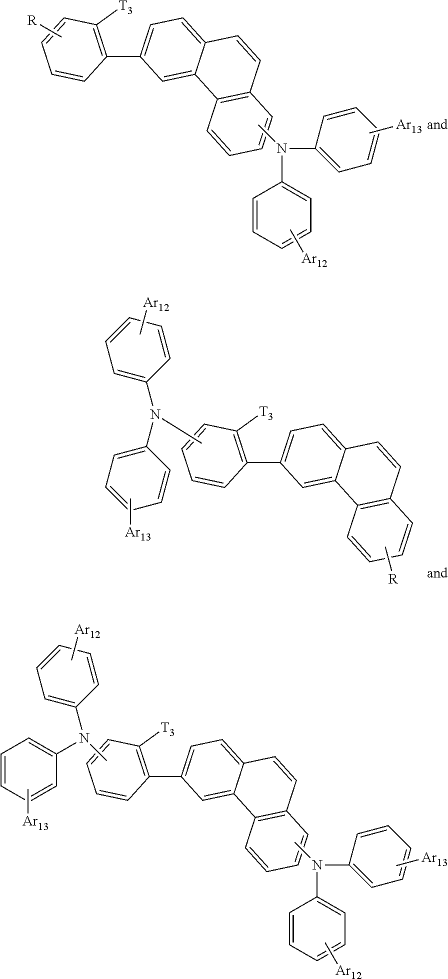

In Reaction Scheme 2 above, Ar₁₂ and Ar₁₃ are as defined in Formula 2, T₃ is as defined in Formula 2-2, and R is as defined in R₂₂ to R₃₃ of Formula 2-2.

In addition, the light-emitting layer of the organic electroluminescent device comprises not only the compound represented by Formula 2, but also the compound represented by the following Formula 3.

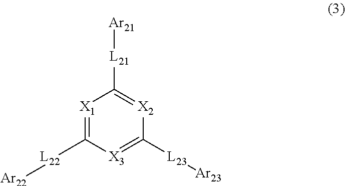

In Formula 3, X₁ to X₃ each independently represent N or CR₂₁, provided that at least one of X₁ to X₃ is N. For example, X₁ to X₃ are each independently N.

In Formula 3, each R₂₁ independently represents hydrogen or deuterium.

In Formula 3, L₂₁ to L₂₃ each independently represent a single bond, a substituted or unsubstituted (C₆-C₃₀)arylene, or a substituted or unsubstituted (3- to 30-membered)heteroarylene. According to one embodiment of the present disclosure, L₂₁ to L₂₃ may each independently be a single bond, a substituted or unsubstituted (C₆-C₂₀)arylene, or a substituted or unsubstituted (3- to 20-membered)heteroarylene. For example, L₂₁ to L₂₃ may each independently be a single bond, a phenylene unsubstituted or substituted with deuterium, a biphenylene unsubstituted or substituted with deuterium, a terphenylene, a naphthylene unsubstituted or substituted with deuterium, a phenanthrenylene, a dibenzofuranylene, or a dibenzothiophenylene, and may be further substituted with deuterium.

In Formula 3, Ar₂₁ to Ar₂₃ each independently represent a substituted or unsubstituted (C₁-C₃₀)alkyl, a substituted or unsubstituted (C₃-C₃₀)cycloalkyl, a substituted or unsubstituted (3- to 7-membered)heterocycloalkyl, a substituted or unsubstituted fused ring of a (C₃-C₃₀)aliphatic ring and a (C₆-C₃₀)aromatic ring, a substituted or unsubstituted (C₆-C₃₀)aryl, a substituted or unsubstituted (3- to 30-membered)heteroaryl, provided that at least one of Ar₂₁ to Ar₂₃ represents a substituted or unsubstituted (3- to 30-membered)heteroaryl. According to one embodiment of the present disclosure, Ar₂₁ to Ar₂₃ may each independently be a substituted or unsubstituted (C₆-C₃₀)aryl, or a substituted or unsubstituted (3- to 30-membered)heteroaryl. According to another embodiment of the present disclosure, at least one of Ar₂₁ to Ar₂₃ may each independently be a substituted or unsubstituted (3- to 30-membered)heteroaryl, preferably a substituted or unsubstituted dibenzofuranyl, a substituted or unsubstituted dibenzothiophenyl, or a substituted or unsubstituted carbazolylaryl. For example, Ar₂₁ to Ar₂₃ may each independently be a phenyl unsubstituted or substituted with deuterium, a naphthyl unsubstituted or substituted with deuterium, or a naphthyl unsubstituted or substituted with phenyl, phenanthrenyl, or dibenzofuranyl; a biphenyl unsubstituted or substituted with deuterium, naphthyl, or dibenzofuranyl; a triphenylenyl; a triphenylsilyl; an o-terphenyl; an m-terphenyl; a p-terphenyl unsubstituted or substituted with deuterium; a phenanthrenyl unsubstituted or substituted with phenyl, or naphthyl; a benzophenanthrenyl unsubstituted or substituted with deuterium; a naphthyl unsubstituted or substituted with deuterium, phenyl unsubstituted or substituted with deuterium, naphthyl unsubstituted or substituted with deuterium, biphenyl unsubstituted or substituted with deuterium, dibenzofuranyl, or dibenzothiophenyl; a quaterphenyl; a fluoranthenyl; a dibenzofuranyl unsubstituted or substituted with deuterium, phenyl, biphenyl, naphthyl, phenanthrenyl, or triphenylenyl; or a dibenzothiophenyl unsubstituted or substituted with phenyl, and may be further substituted with deuterium.

According to one embodiment of the present disclosure, Formula 3 may be represented by any one of the following Formulas 3-1 to 3-4.

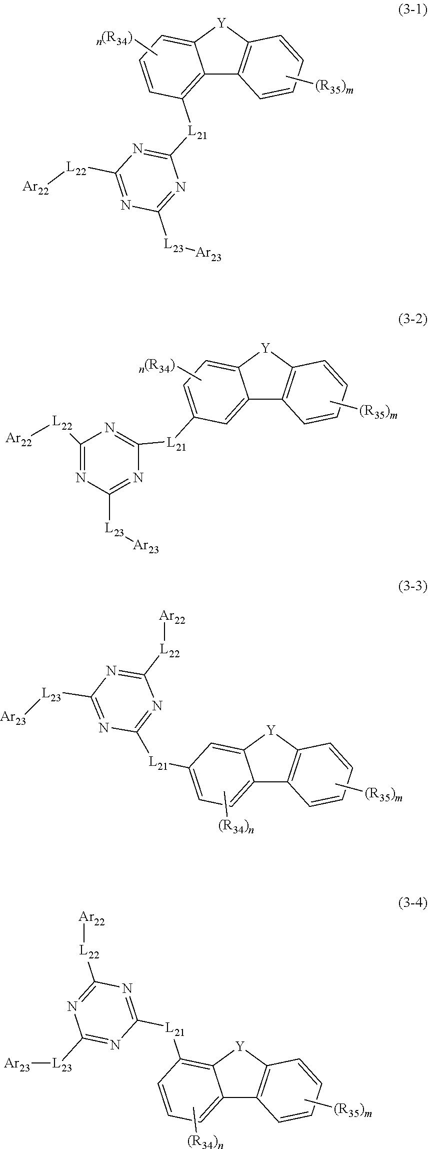

In Formulas 3-1 to 3-4, Y represents O, S, or NR₃₆. For example, Y is O or S.

In Formulas 3-1 to 3-4, R₃₄ to R₃₆ each independently represent hydrogen, deuterium, halogen, cyano, a substituted or unsubstituted (C₁-C₃₀)alkyl, a substituted or unsubstituted (C₆-C₃₀)aryl, a substituted or unsubstituted (3- to 30-membered)heteroaryl, a substituted or unsubstituted (C₃-C₃₀)cycloalkyl, a substituted or unsubstituted (C₁-C₃₀)alkoxy, a substituted or unsubstituted tri(C₁-C₃₀)alkylsilyl, a substituted or unsubstituted di(C₁-C₃₀)alkyl(C₆-C₃₀)arylsilyl, a substituted or unsubstituted (C₁-C₃₀)alkyldi(C₆-C₃₀)arylsilyl, a substituted or unsubstituted tri(C₆-C₃₀)arylsilyl, a substituted or unsubstituted mono- or di-(C₁-C₃₀)alkylamino, a substituted or unsubstituted mono- or di-(C₆-C₃₀)arylamino, or a substituted or unsubstituted (C₁-C₃₀)alkyl(C₆-C₃₀)arylamino; or may be linked to the adjacent substituents to form a ring(s). According to one embodiment of the present disclosure, R₃₄ to R₃₆ may each independently be hydrogen, deuterium, or a substituted or unsubstituted (C₆-C₃₀)aryl. According to another embodiment of the present disclosure, R₃₄ to R₃₆ may each independently be hydrogen, deuterium, or a substituted or unsubstituted (C₆-C₂₀)aryl. For example, R₃₄ to R₃₆ may each independently be hydrogen; deuterium; a phenyl unsubstituted or substituted with naphthyl; a naphthyl unsubstituted or substituted with phenyl; a biphenyl; or a phenanthrenyl, and may be further substituted with deuterium.

In Formulas 3-1 to 3-4, L₂₁ to L₂₃, Ar₂₂, and Ar₂₃ are the same as defined in Formula 3.

In Formulas 3-1 to 3-4, n is an integer of 1 to 3, m is an integer of 1 to 4, and when n and m are integers of 2 or greater, each of R₃₄ and each of R₃₅ may be the same as or different from each other.

The compound represented by Formula 3 may be selected from the following compounds, but is not limited thereto.

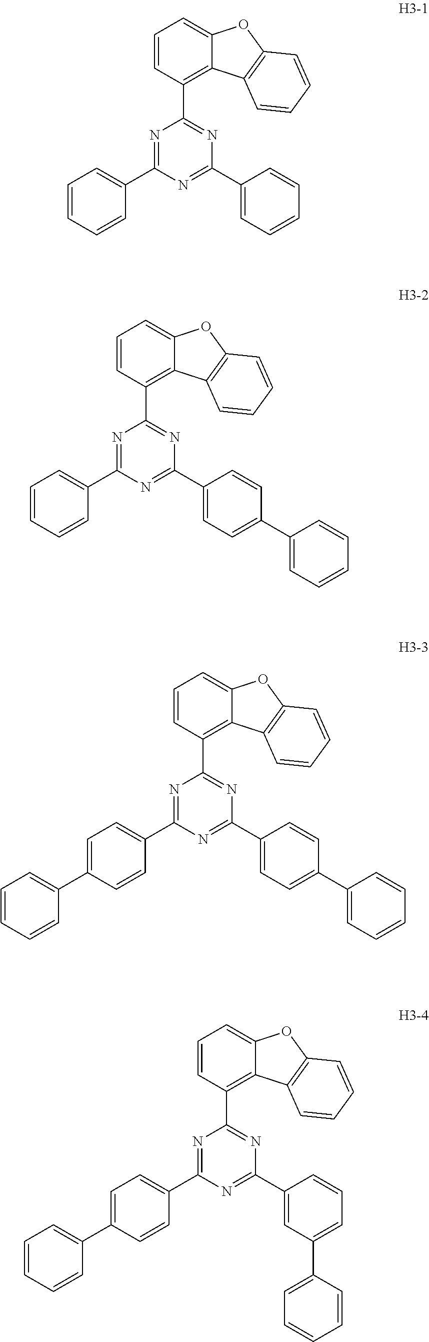 [SMILES: c1ccc(-c2nc(-c3ccccc3)nc(-c3cccc4oc5ccccc5c34)n2)cc1 ; c1ccc(-c2ccc(-c3nc(-c4ccccc4)nc(-c4cccc5oc6ccccc6c45)n3)cc2)cc1 ; c1ccc(-c2ccc(-c3nc(-c4ccc(-c5ccccc5)cc4)nc(-c4cccc5oc6ccccc6c45)n3)cc2)cc1 ; c1ccc(-c2ccc(-c3nc(-c4cccc(-c5ccccc5)c4)nc(-c4cccc5oc6ccccc6c45)n3)cc2)cc1]

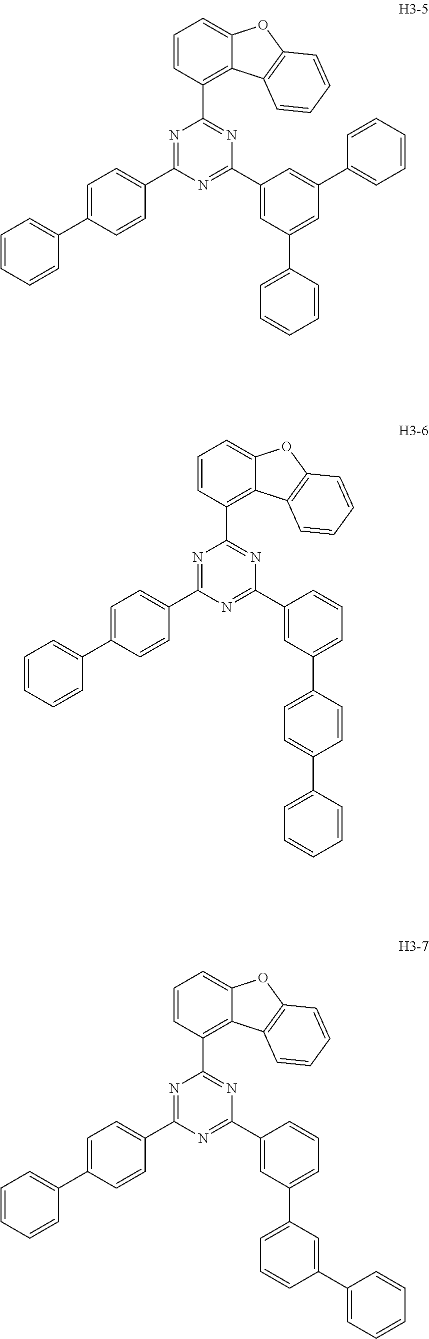 [SMILES: c1ccc(-c2ccc(-c3nc(-c4cc(-c5ccccc5)cc(-c5ccccc5)c4)nc(-c4cccc5oc6ccccc6c45)n3)cc2)cc1 ; c1ccc(-c2ccc(-c3cccc(-c4nc(-c5ccc(-c6ccccc6)cc5)nc(-c5cccc6oc7ccccc7c56)n4)c3)cc2)cc1 ; c1ccc(-c2ccc(-c3nc(-c4cccc(-c5cccc(-c6ccccc6)c5)c4)nc(-c4cccc5oc6ccccc6c45)n3)cc2)cc1]

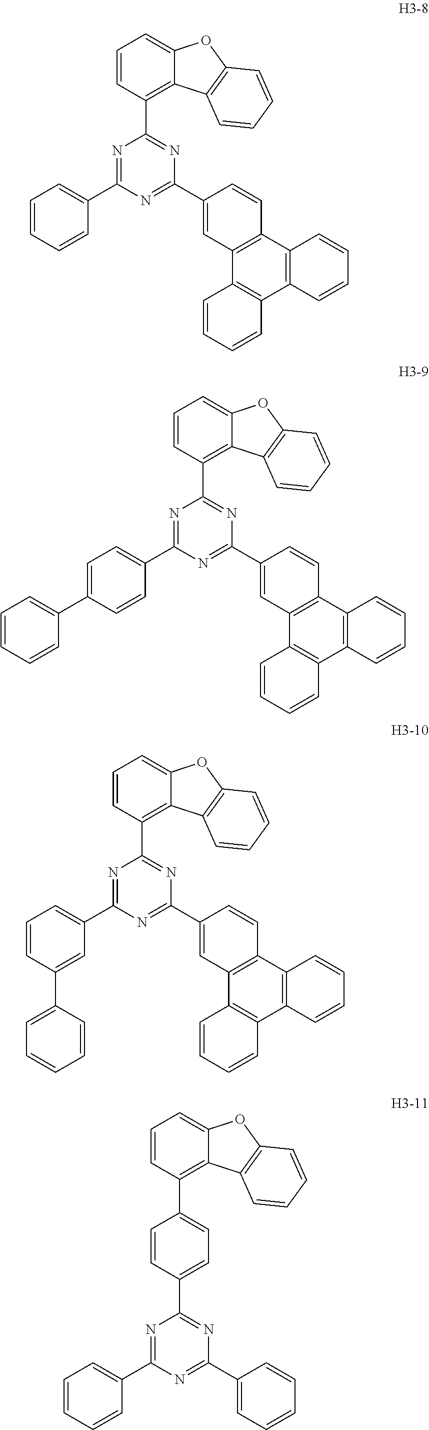 [SMILES: c1ccc(-c2nc(-c3ccc4c5ccccc5c5ccccc5c4c3)nc(-c3cccc4oc5ccccc5c34)n2)cc1 ; c1ccc(-c2ccc(-c3nc(-c4ccc5c6ccccc6c6ccccc6c5c4)nc(-c4cccc5oc6ccccc6c45)n3)cc2)cc1 ; c1ccc(-c2cccc(-c3nc(-c4ccc5c6ccccc6c6ccccc6c5c4)nc(-c4cccc5oc6ccccc6c45)n3)c2)cc1 ; c1ccc(-c2nc(-c3ccccc3)nc(-c3ccc(-c4cccc5oc6ccccc6c45)cc3)n2)cc1]

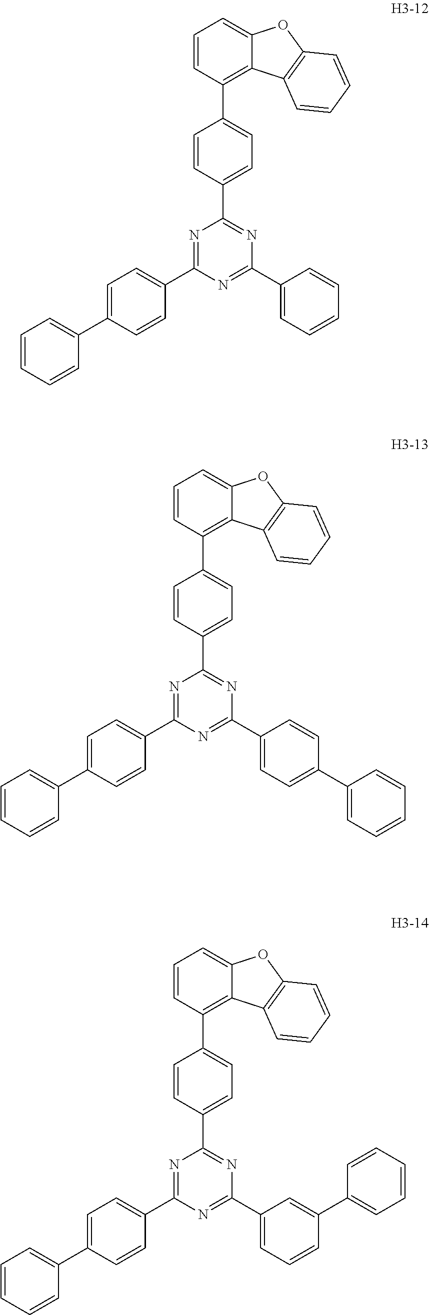 [SMILES: c1ccc(-c2ccc(-c3nc(-c4ccccc4)nc(-c4ccc(-c5cccc6oc7ccccc7c56)cc4)n3)cc2)cc1 ; c1ccc(-c2ccc(-c3nc(-c4ccc(-c5ccccc5)cc4)nc(-c4ccc(-c5cccc6oc7ccccc7c56)cc4)n3)cc2)cc1 ; c1ccc(-c2ccc(-c3nc(-c4ccc(-c5cccc6oc7ccccc7c56)cc4)nc(-c4cccc(-c5ccccc5)c4)n3)cc2)cc1]

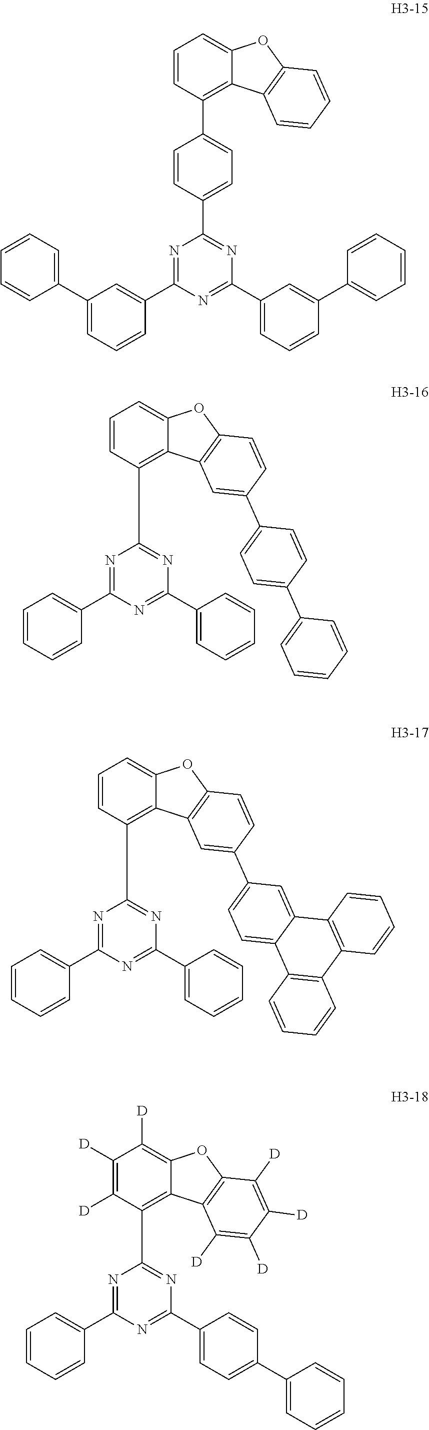 [SMILES: c1ccc(-c2cccc(-c3nc(-c4ccc(-c5cccc6oc7ccccc7c56)cc4)nc(-c4cccc(-c5ccccc5)c4)n3)c2)cc1 ; c1ccc(-c2ccc(-c3ccc4oc5cccc(-c6nc(-c7ccccc7)nc(-c7ccccc7)n6)c5c4c3)cc2)cc1 ; c1ccc(-c2nc(-c3ccccc3)nc(-c3cccc4oc5ccc(-c6ccc7c8ccccc8c8ccccc8c7c6)cc5c34)n2)cc1 ; [2H]c1c([2H])c([2H])c2c(oc3c([2H])c([2H])c([2H])c(-c4nc(-c5ccccc5)nc(-c5ccc(-c6ccccc6)cc5)n4)c32)c1[2H]]

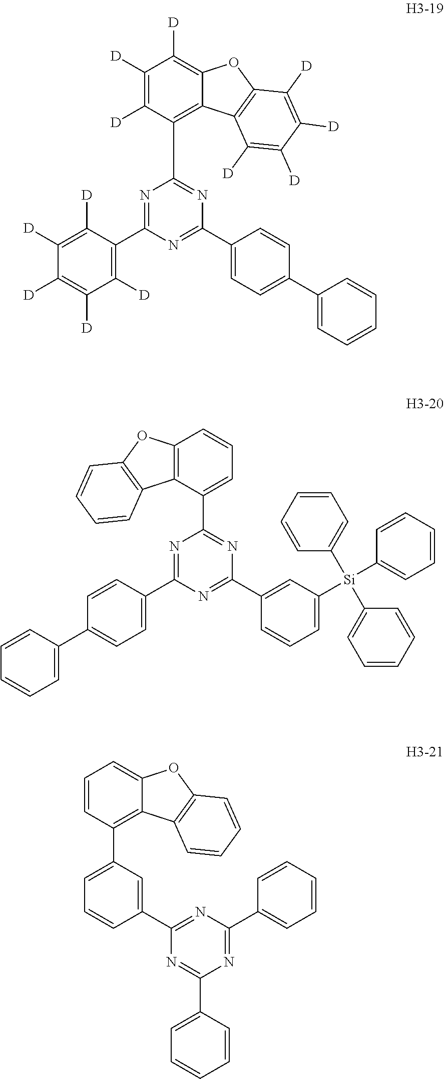 [SMILES: [2H]c1c([2H])c([2H])c(-c2nc(-c3ccc(-c4ccccc4)cc3)nc(-c3c([2H])c([2H])c([2H])c4oc5c([2H])c([2H])c([2H])c([2H])c5c34)n2)c([2H])c1[2H] ; c1ccc(-c2ccc(-c3nc(-c4cccc([Si](c5ccccc5)(c5ccccc5)c5ccccc5)c4)nc(-c4cccc5oc6ccccc6c45)n3)cc2)cc1 ; c1ccc(-c2nc(-c3ccccc3)nc(-c3cccc(-c4cccc5oc6ccccc6c45)c3)n2)cc1]

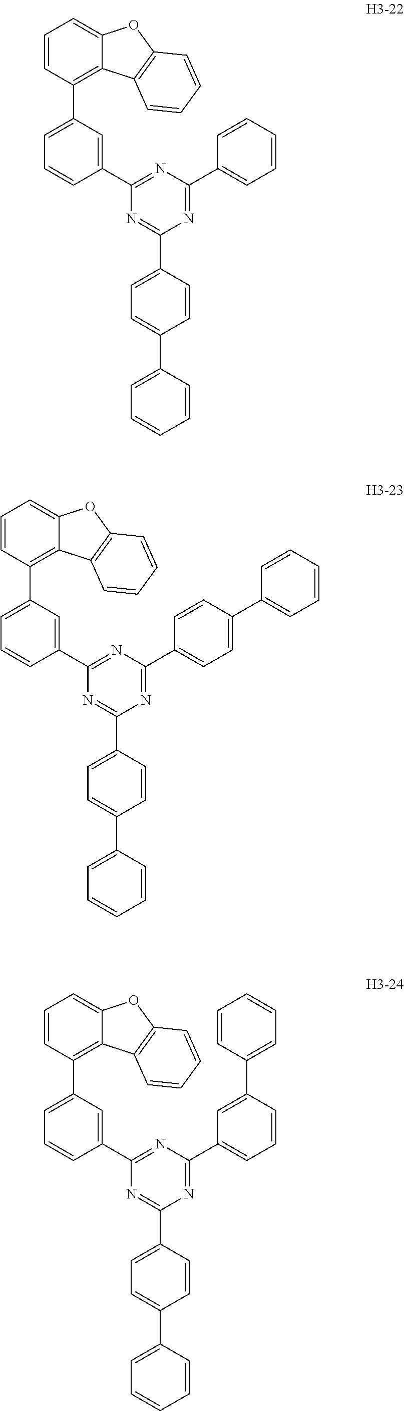 [SMILES: c1ccc(-c2ccc(-c3nc(-c4ccccc4)nc(-c4cccc(-c5cccc6oc7ccccc7c56)c4)n3)cc2)cc1 ; c1ccc(-c2ccc(-c3nc(-c4ccc(-c5ccccc5)cc4)nc(-c4cccc(-c5cccc6oc7ccccc7c56)c4)n3)cc2)cc1 ; c1ccc(-c2ccc(-c3nc(-c4cccc(-c5ccccc5)c4)nc(-c4cccc(-c5cccc6oc7ccccc7c56)c4)n3)cc2)cc1]

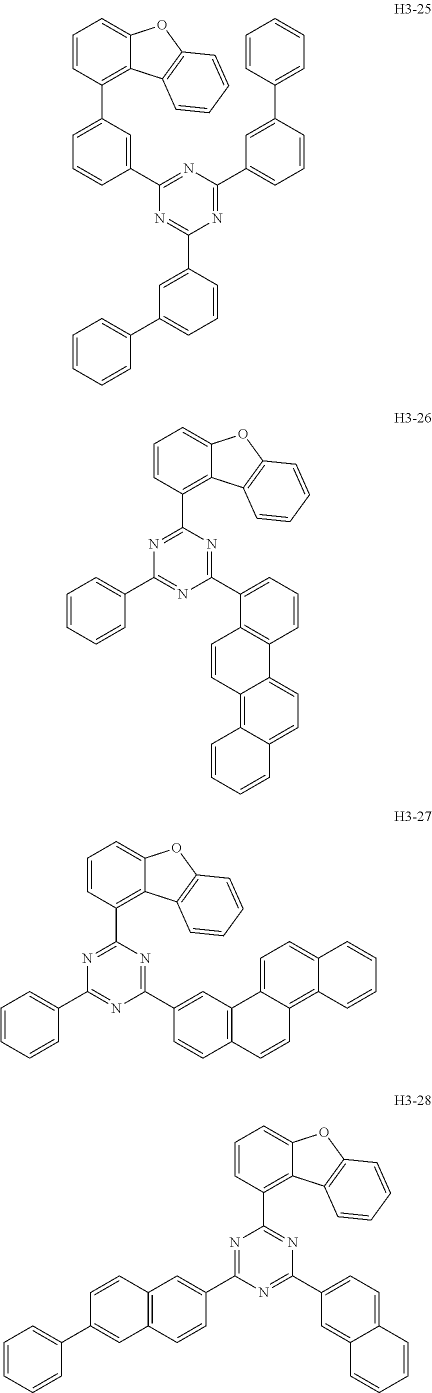 [SMILES: c1ccc(-c2cccc(-c3nc(-c4cccc(-c5ccccc5)c4)nc(-c4cccc(-c5cccc6oc7ccccc7c56)c4)n3)c2)cc1 ; c1ccc(-c2nc(-c3cccc4c3ccc3c5ccccc5ccc43)nc(-c3cccc4oc5ccccc5c34)n2)cc1 ; c1ccc(-c2nc(-c3ccc4ccc5c6ccccc6ccc5c4c3)nc(-c3cccc4oc5ccccc5c34)n2)cc1 ; c1ccc(-c2ccc3cc(-c4nc(-c5ccc6ccccc6c5)nc(-c5cccc6oc7ccccc7c56)n4)ccc3c2)cc1]

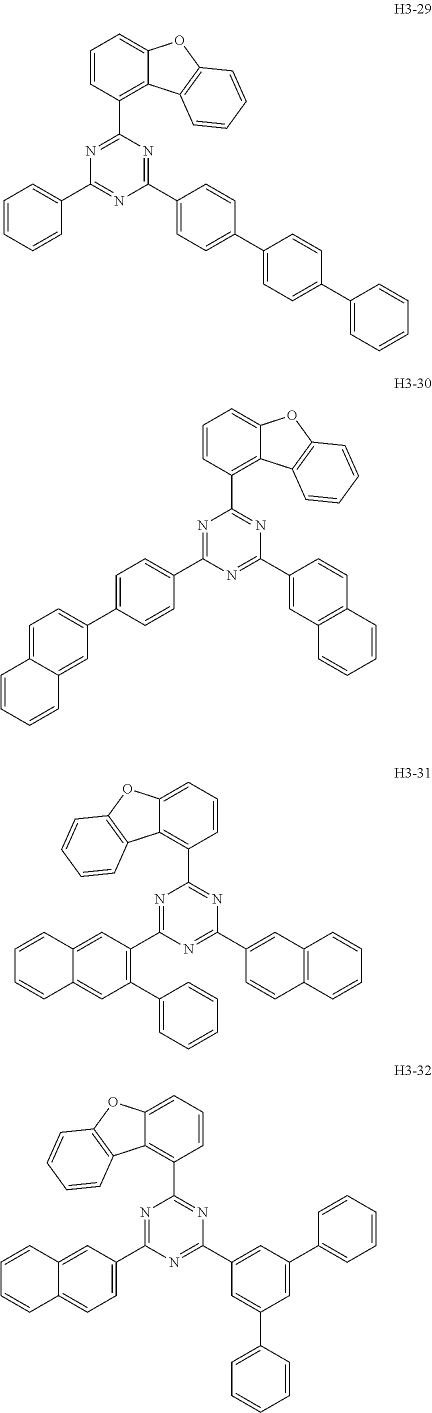 [SMILES: c1ccc(-c2ccc(-c3ccc(-c4nc(-c5ccccc5)nc(-c5cccc6oc7ccccc7c56)n4)cc3)cc2)cc1 ; c1ccc2cc(-c3ccc(-c4nc(-c5ccc6ccccc6c5)nc(-c5cccc6oc7ccccc7c56)n4)cc3)ccc2c1 ; c1ccc(-c2cc3ccccc3cc2-c2nc(-c3ccc4ccccc4c3)nc(-c3cccc4oc5ccccc5c34)n2)cc1 ; c1ccc(-c2cc(-c3ccccc3)cc(-c3nc(-c4ccc5ccccc5c4)nc(-c4cccc5oc6ccccc6c45)n3)c2)cc1]

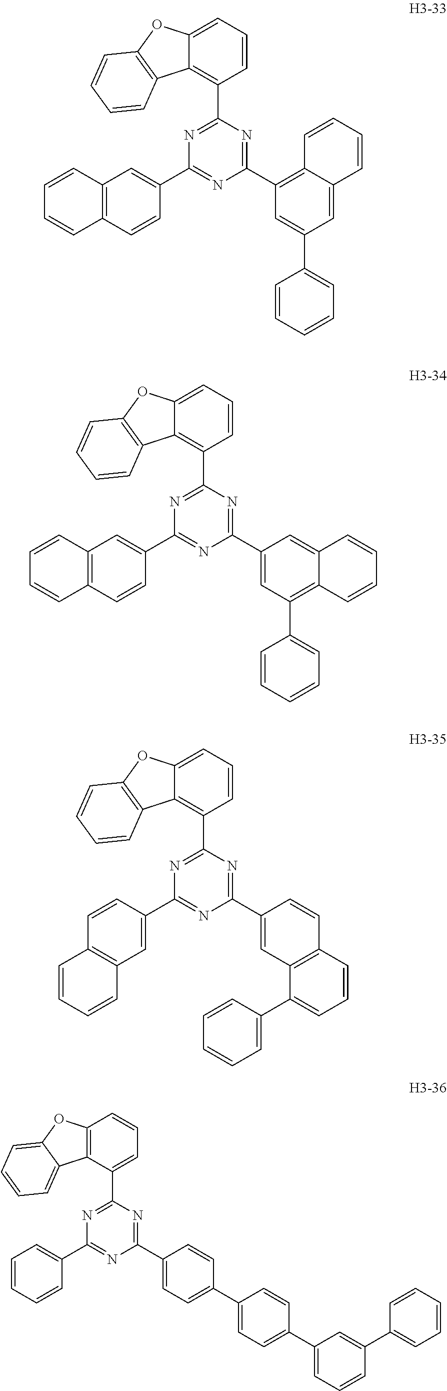 [SMILES: c1ccc(-c2cc(-c3nc(-c4ccc5ccccc5c4)nc(-c4cccc5oc6ccccc6c45)n3)c3ccccc3c2)cc1 ; c1ccc(-c2cc(-c3nc(-c4ccc5ccccc5c4)nc(-c4cccc5oc6ccccc6c45)n3)cc3ccccc23)cc1 ; c1ccc(-c2cccc3ccc(-c4nc(-c5ccc6ccccc6c5)nc(-c5cccc6oc7ccccc7c56)n4)cc23)cc1 ; c1ccc(-c2cccc(-c3ccc(-c4ccc(-c5nc(-c6ccccc6)nc(-c6cccc7oc8ccccc8c67)n5)cc4)cc3)c2)cc1]

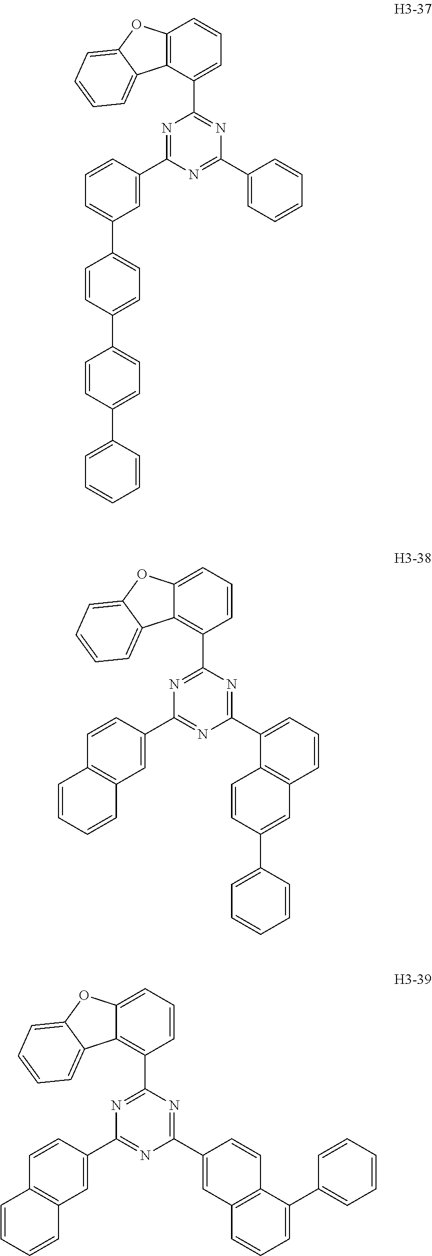 [SMILES: c1ccc(-c2ccc(-c3ccc(-c4cccc(-c5nc(-c6ccccc6)nc(-c6cccc7oc8ccccc8c67)n5)c4)cc3)cc2)cc1 ; c1ccc(-c2ccc3c(-c4nc(-c5ccc6ccccc6c5)nc(-c5cccc6oc7ccccc7c56)n4)cccc3c2)cc1 ; c1ccc(-c2cccc3cc(-c4nc(-c5ccc6ccccc6c5)nc(-c5cccc6oc7ccccc7c56)n4)ccc23)cc1]

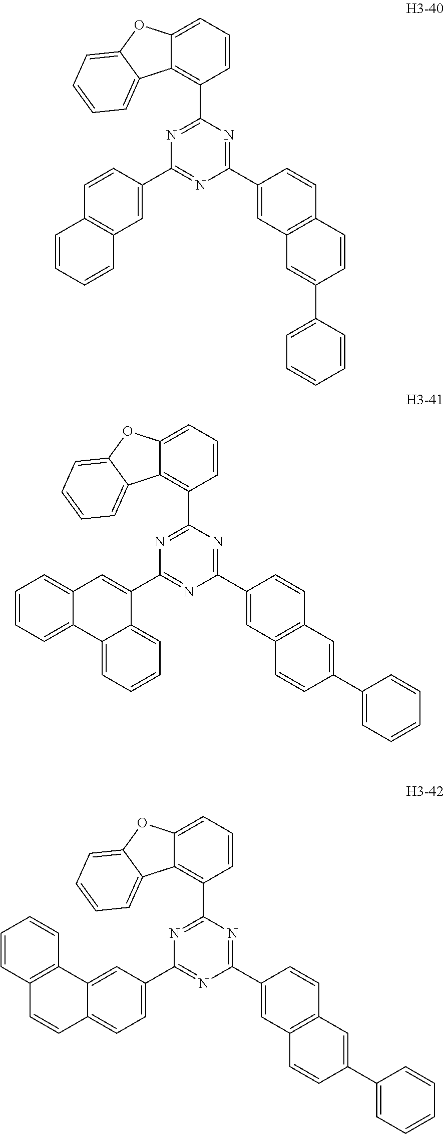 [SMILES: c1ccc(-c2ccc3ccc(-c4nc(-c5ccc6ccccc6c5)nc(-c5cccc6oc7ccccc7c56)n4)cc3c2)cc1 ; c1ccc(-c2ccc3cc(-c4nc(-c5cc6ccccc6c6ccccc56)nc(-c5cccc6oc7ccccc7c56)n4)ccc3c2)cc1 ; c1ccc(-c2ccc3cc(-c4nc(-c5ccc6ccc7ccccc7c6c5)nc(-c5cccc6oc7ccccc7c56)n4)ccc3c2)cc1]

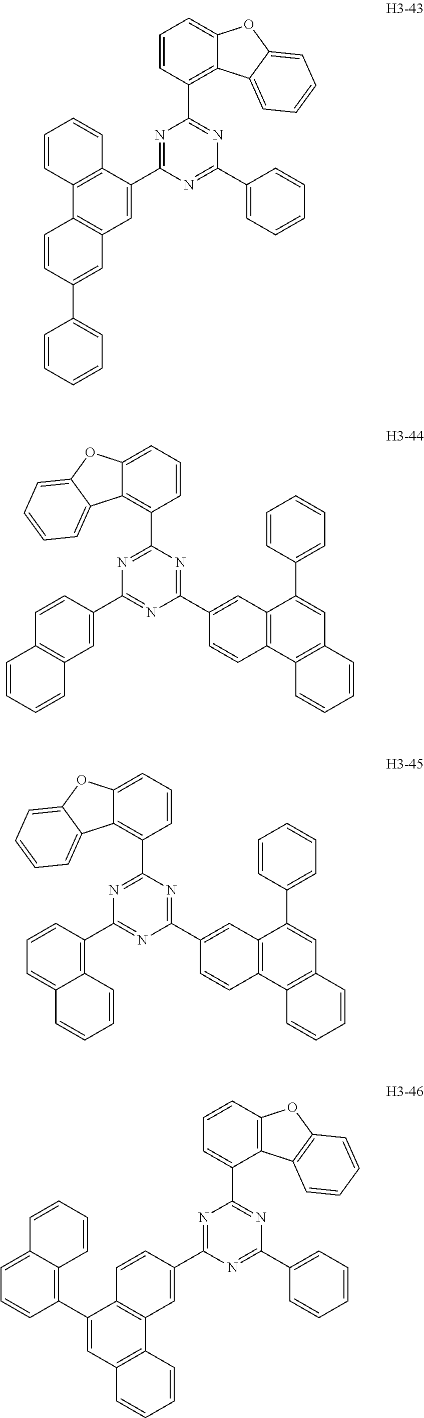 [SMILES: c1ccc(-c2ccc3c(c2)cc(-c2nc(-c4ccccc4)nc(-c4cccc5oc6ccccc6c45)n2)c2ccccc23)cc1 ; c1ccc(-c2cc3ccccc3c3ccc(-c4nc(-c5ccc6ccccc6c5)nc(-c5cccc6oc7ccccc7c56)n4)cc23)cc1 ; c1ccc(-c2cc3ccccc3c3ccc(-c4nc(-c5cccc6ccccc56)nc(-c5cccc6oc7ccccc7c56)n4)cc23)cc1 ; c1ccc(-c2nc(-c3ccc4c(-c5cccc6ccccc56)cc5ccccc5c4c3)nc(-c3cccc4oc5ccccc5c34)n2)cc1]

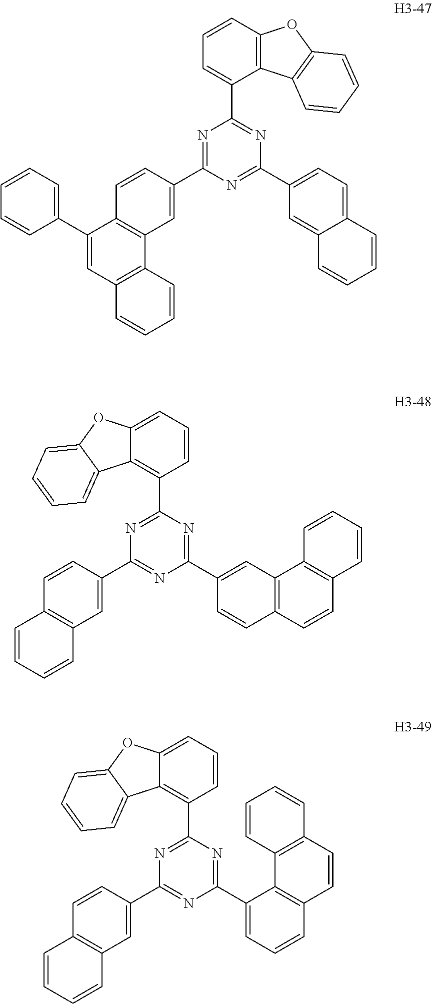 [SMILES: c1ccc(-c2cc3ccccc3c3cc(-c4nc(-c5ccc6ccccc6c5)nc(-c5cccc6oc7ccccc7c56)n4)ccc23)cc1 ; c1ccc2cc(-c3nc(-c4ccc5ccc6ccccc6c5c4)nc(-c4cccc5oc6ccccc6c45)n3)ccc2c1 ; c1ccc2cc(-c3nc(-c4cccc5ccc6ccccc6c45)nc(-c4cccc5oc6ccccc6c45)n3)ccc2c1]

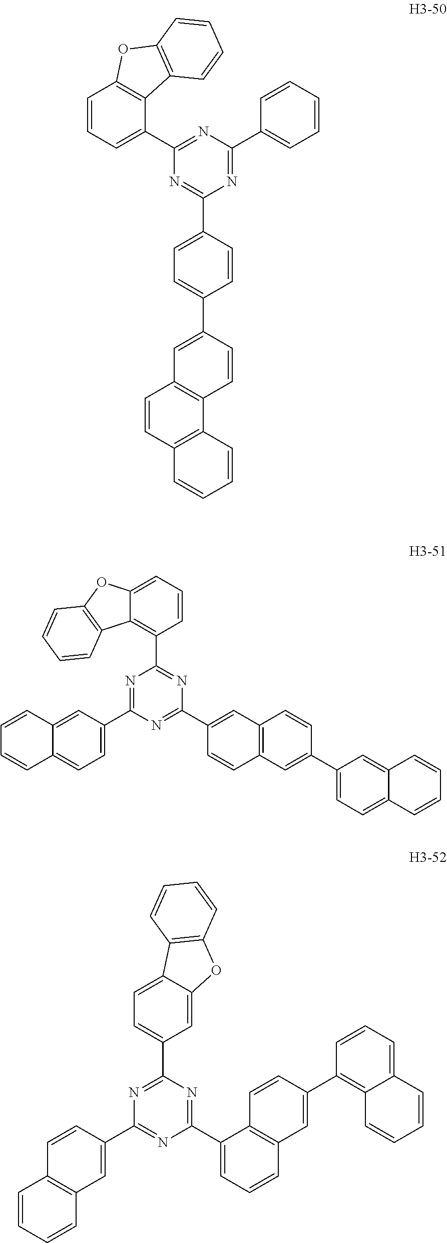 [SMILES: c1ccc(-c2nc(-c3ccc(-c4ccc5c(ccc6ccccc65)c4)cc3)nc(-c3cccc4oc5ccccc5c34)n2)cc1 ; c1ccc2cc(-c3ccc4cc(-c5nc(-c6ccc7ccccc7c6)nc(-c6cccc7oc8ccccc8c67)n5)ccc4c3)ccc2c1 ; c1ccc2cc(-c3nc(-c4ccc5c(c4)oc4ccccc45)nc(-c4cccc5cc(-c6cccc7ccccc67)ccc45)n3)ccc2c1]

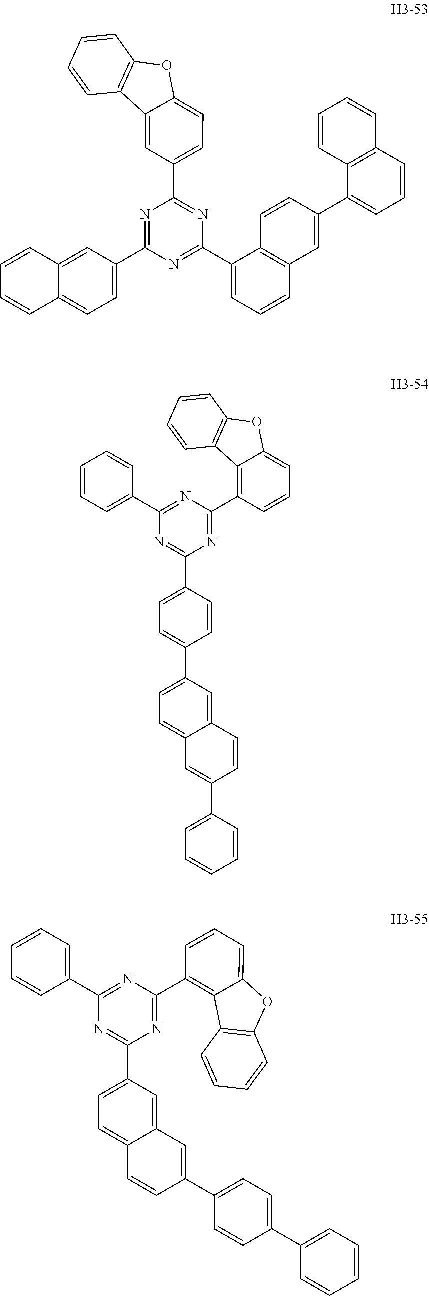 [SMILES: c1ccc2cc(-c3nc(-c4ccc5oc6ccccc6c5c4)nc(-c4cccc5cc(-c6cccc7ccccc67)ccc45)n3)ccc2c1 ; c1ccc(-c2ccc3cc(-c4ccc(-c5nc(-c6ccccc6)nc(-c6cccc7oc8ccccc8c67)n5)cc4)ccc3c2)cc1 ; c1ccc(-c2ccc(-c3ccc4ccc(-c5nc(-c6ccccc6)nc(-c6cccc7oc8ccccc8c67)n5)cc4c3)cc2)cc1]

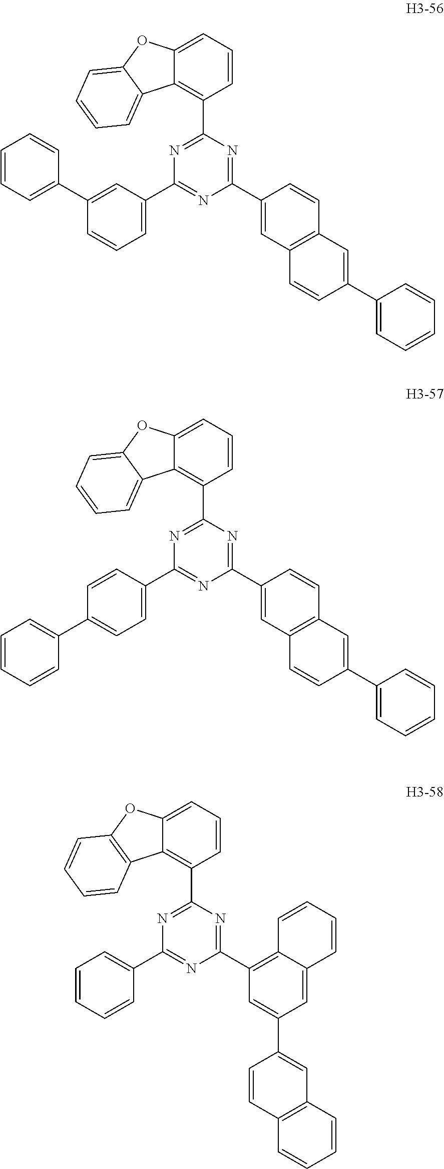 [SMILES: c1ccc(-c2cccc(-c3nc(-c4ccc5cc(-c6ccccc6)ccc5c4)nc(-c4cccc5oc6ccccc6c45)n3)c2)cc1 ; c1ccc(-c2ccc(-c3nc(-c4ccc5cc(-c6ccccc6)ccc5c4)nc(-c4cccc5oc6ccccc6c45)n3)cc2)cc1 ; c1ccc(-c2nc(-c3cc(-c4ccc5ccccc5c4)cc4ccccc34)nc(-c3cccc4oc5ccccc5c34)n2)cc1]

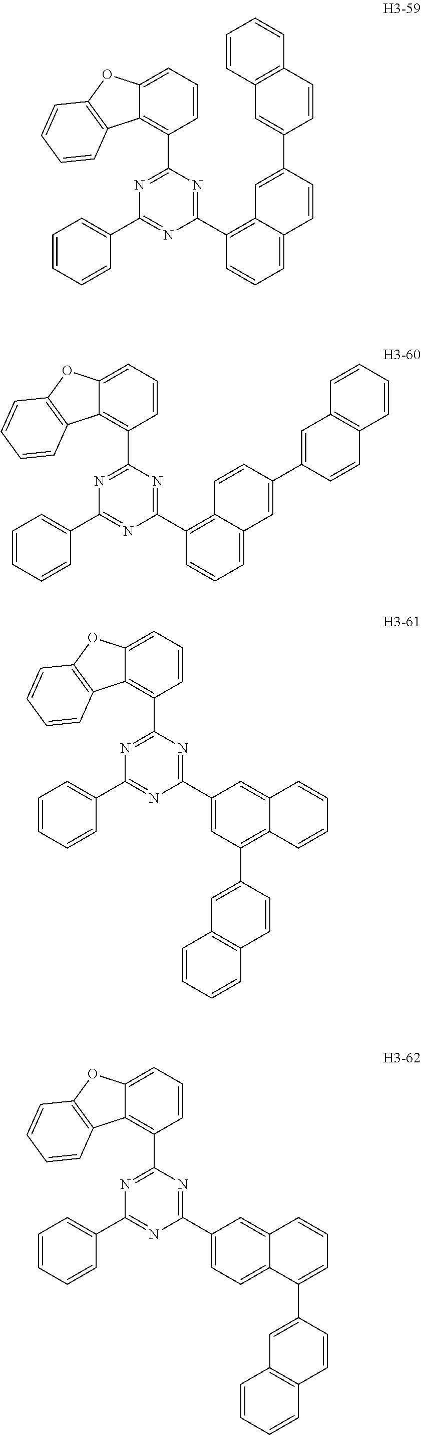 [SMILES: c1ccc(-c2nc(-c3cccc4ccc(-c5ccc6ccccc6c5)cc34)nc(-c3cccc4oc5ccccc5c34)n2)cc1 ; c1ccc(-c2nc(-c3cccc4cc(-c5ccc6ccccc6c5)ccc34)nc(-c3cccc4oc5ccccc5c34)n2)cc1 ; c1ccc(-c2nc(-c3cc(-c4ccc5ccccc5c4)c4ccccc4c3)nc(-c3cccc4oc5ccccc5c34)n2)cc1 ; c1ccc(-c2nc(-c3ccc4c(-c5ccc6ccccc6c5)cccc4c3)nc(-c3cccc4oc5ccccc5c34)n2)cc1]

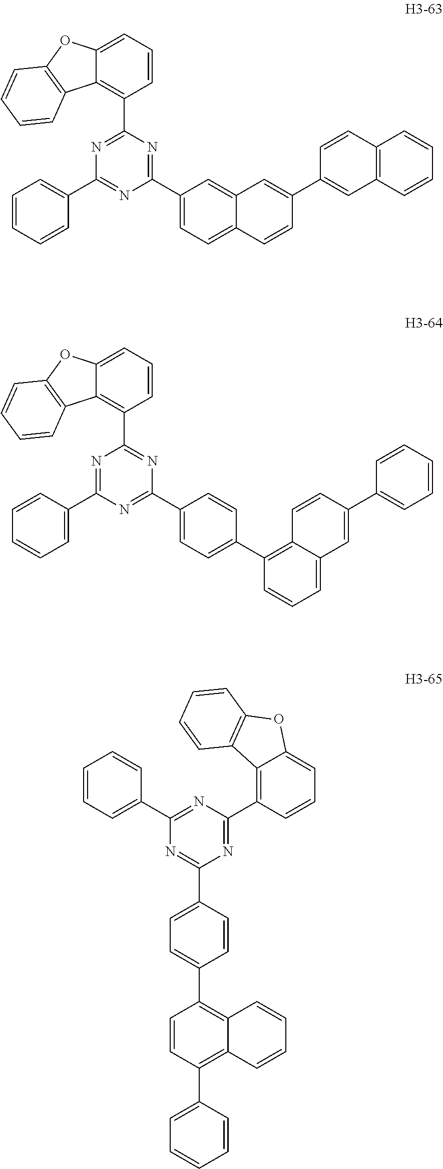 [SMILES: c1ccc(-c2nc(-c3ccc4ccc(-c5ccc6ccccc6c5)cc4c3)nc(-c3cccc4oc5ccccc5c34)n2)cc1 ; c1ccc(-c2ccc3c(-c4ccc(-c5nc(-c6ccccc6)nc(-c6cccc7oc8ccccc8c67)n5)cc4)cccc3c2)cc1 ; c1ccc(-c2nc(-c3ccc(-c4ccc(-c5ccccc5)c5ccccc45)cc3)nc(-c3cccc4oc5ccccc5c34)n2)cc1]

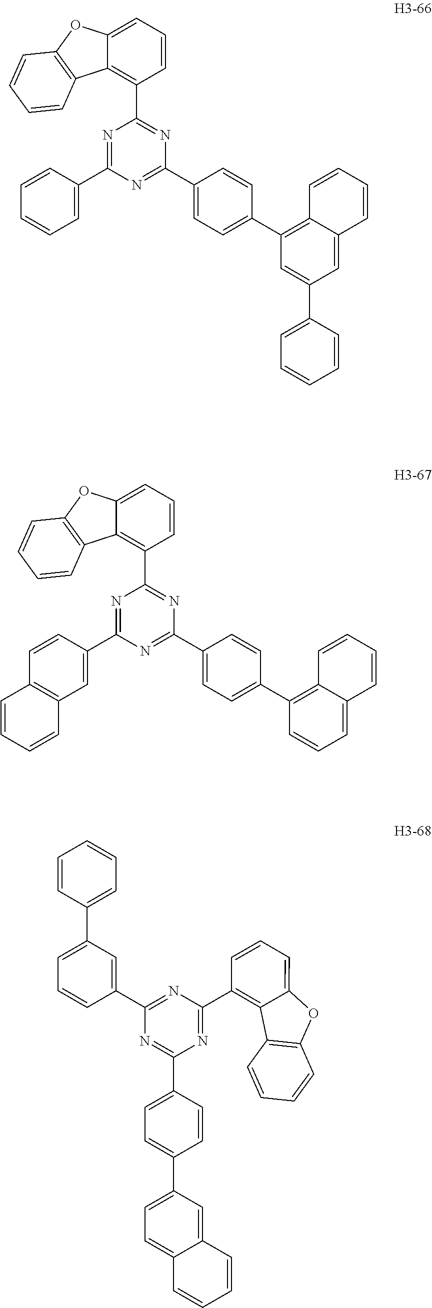 [SMILES: c1ccc(-c2cc(-c3ccc(-c4nc(-c5ccccc5)nc(-c5cccc6oc7ccccc7c56)n4)cc3)c3ccccc3c2)cc1 ; c1ccc2cc(-c3nc(-c4ccc(-c5cccc6ccccc56)cc4)nc(-c4cccc5oc6ccccc6c45)n3)ccc2c1 ; c1ccc(-c2cccc(-c3nc(-c4ccc(-c5ccc6ccccc6c5)cc4)nc(-c4cccc5oc6ccccc6c45)n3)c2)cc1]

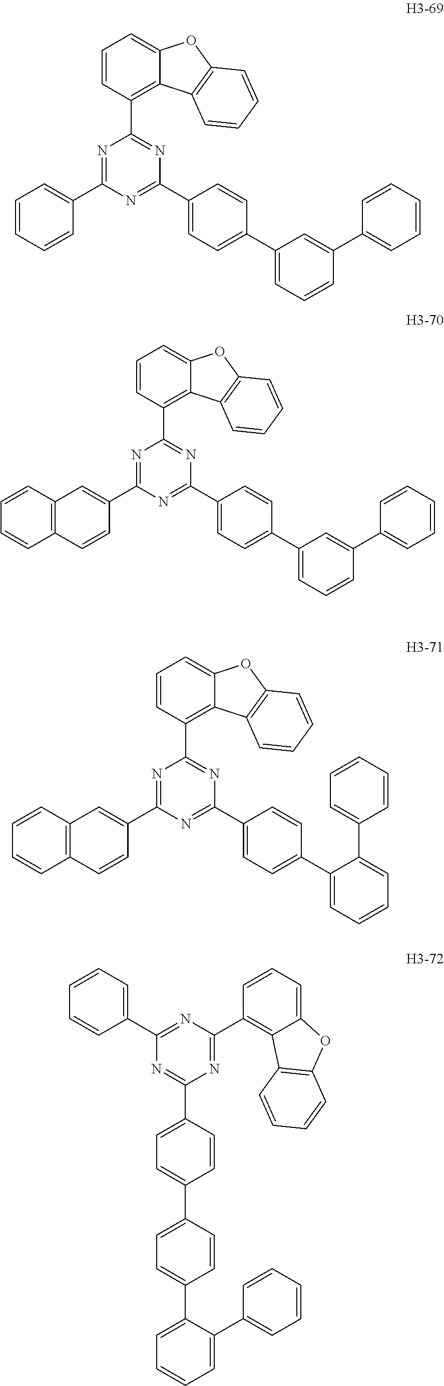 [SMILES: c1ccc(-c2cccc(-c3ccc(-c4nc(-c5ccccc5)nc(-c5cccc6oc7ccccc7c56)n4)cc3)c2)cc1 ; c1ccc(-c2cccc(-c3ccc(-c4nc(-c5ccc6ccccc6c5)nc(-c5cccc6oc7ccccc7c56)n4)cc3)c2)cc1 ; c1ccc(-c2ccccc2-c2ccc(-c3nc(-c4ccc5ccccc5c4)nc(-c4cccc5oc6ccccc6c45)n3)cc2)cc1 ; c1ccc(-c2nc(-c3ccc(-c4ccc(-c5ccccc5-c5ccccc5)cc4)cc3)nc(-c3cccc4oc5ccccc5c34)n2)cc1]

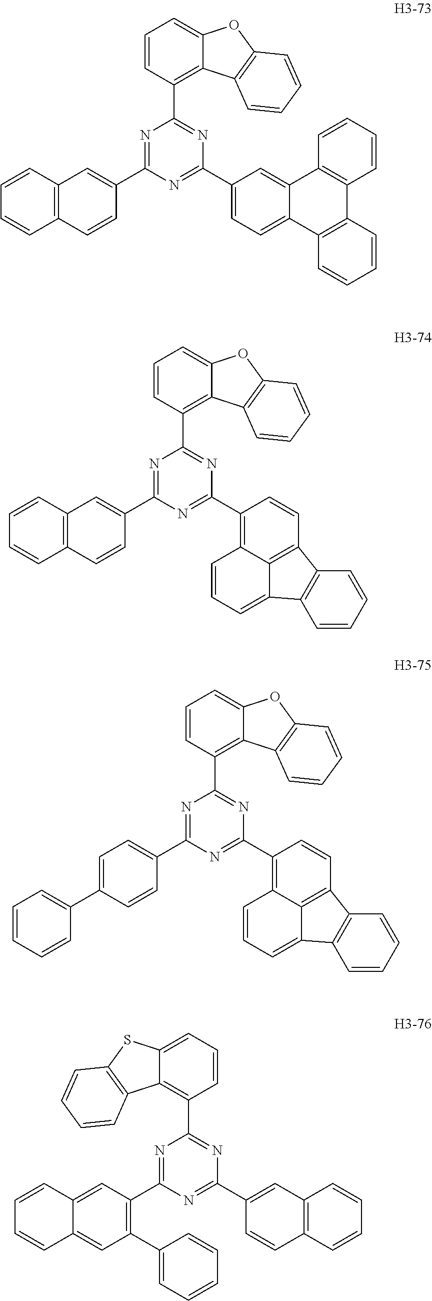 [SMILES: c1ccc2cc(-c3nc(-c4ccc5c6ccccc6c6ccccc6c5c4)nc(-c4cccc5oc6ccccc6c45)n3)ccc2c1 ; c1ccc2c(c1)-c1cccc3c(-c4nc(-c5ccc6ccccc6c5)nc(-c5cccc6oc7ccccc7c56)n4)ccc-2c13 ; c1ccc(-c2ccc(-c3nc(-c4ccc5c6c(cccc46)-c4ccccc4-5)nc(-c4cccc5oc6ccccc6c45)n3)cc2)cc1 ; c1ccc(-c2cc3ccccc3cc2-c2nc(-c3ccc4ccccc4c3)nc(-c3cccc4sc5ccccc5c34)n2)cc1]

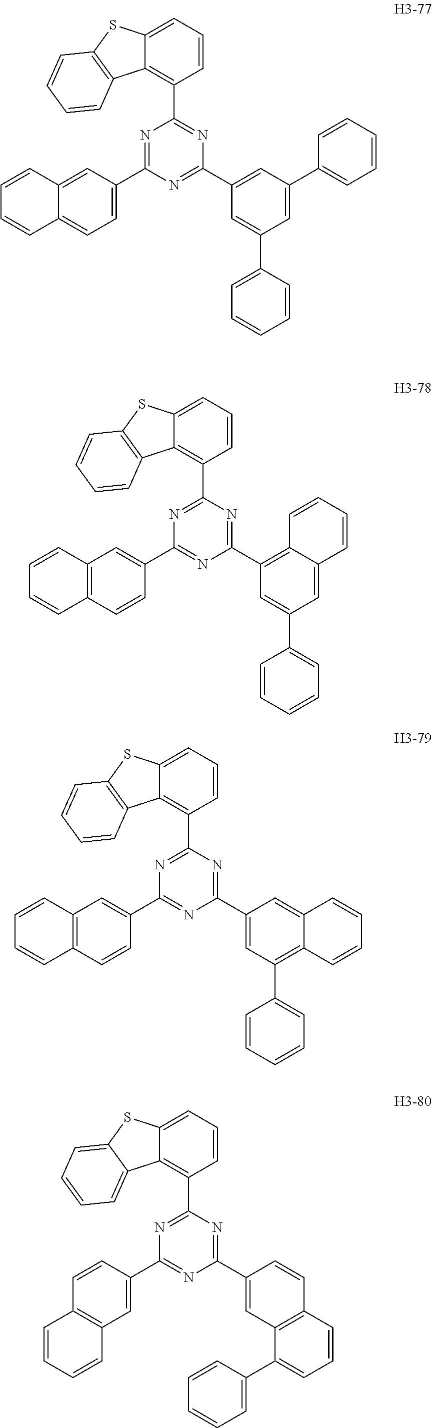 [SMILES: c1ccc(-c2cc(-c3ccccc3)cc(-c3nc(-c4ccc5ccccc5c4)nc(-c4cccc5sc6ccccc6c45)n3)c2)cc1 ; c1ccc(-c2cc(-c3nc(-c4ccc5ccccc5c4)nc(-c4cccc5sc6ccccc6c45)n3)c3ccccc3c2)cc1 ; c1ccc(-c2cc(-c3nc(-c4ccc5ccccc5c4)nc(-c4cccc5sc6ccccc6c45)n3)cc3ccccc23)cc1 ; c1ccc(-c2cccc3ccc(-c4nc(-c5ccc6ccccc6c5)nc(-c5cccc6sc7ccccc7c56)n4)cc23)cc1]

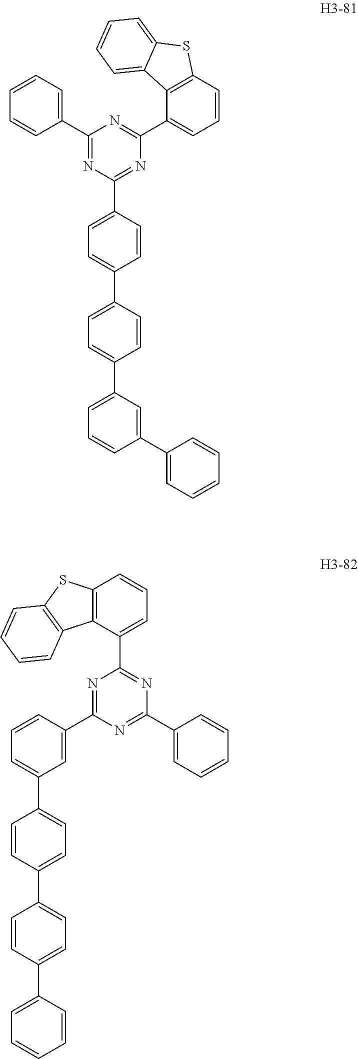 [SMILES: c1ccc(-c2cccc(-c3ccc(-c4ccc(-c5nc(-c6ccccc6)nc(-c6cccc7sc8ccccc8c67)n5)cc4)cc3)c2)cc1 ; c1ccc(-c2ccc(-c3ccc(-c4cccc(-c5nc(-c6ccccc6)nc(-c6cccc7sc8ccccc8c67)n5)c4)cc3)cc2)cc1]

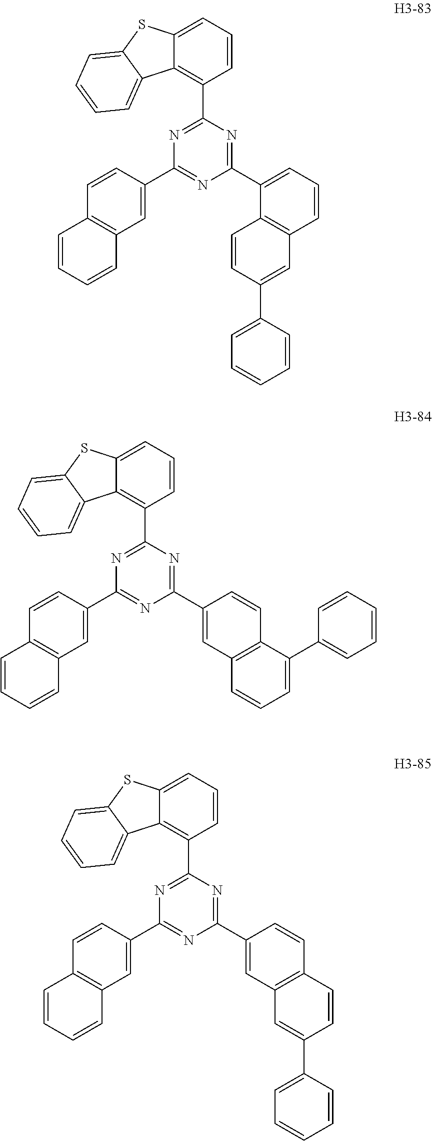 [SMILES: c1ccc(-c2ccc3c(-c4nc(-c5ccc6ccccc6c5)nc(-c5cccc6sc7ccccc7c56)n4)cccc3c2)cc1 ; c1ccc(-c2cccc3cc(-c4nc(-c5ccc6ccccc6c5)nc(-c5cccc6sc7ccccc7c56)n4)ccc23)cc1 ; c1ccc(-c2ccc3ccc(-c4nc(-c5ccc6ccccc6c5)nc(-c5cccc6sc7ccccc7c56)n4)cc3c2)cc1]

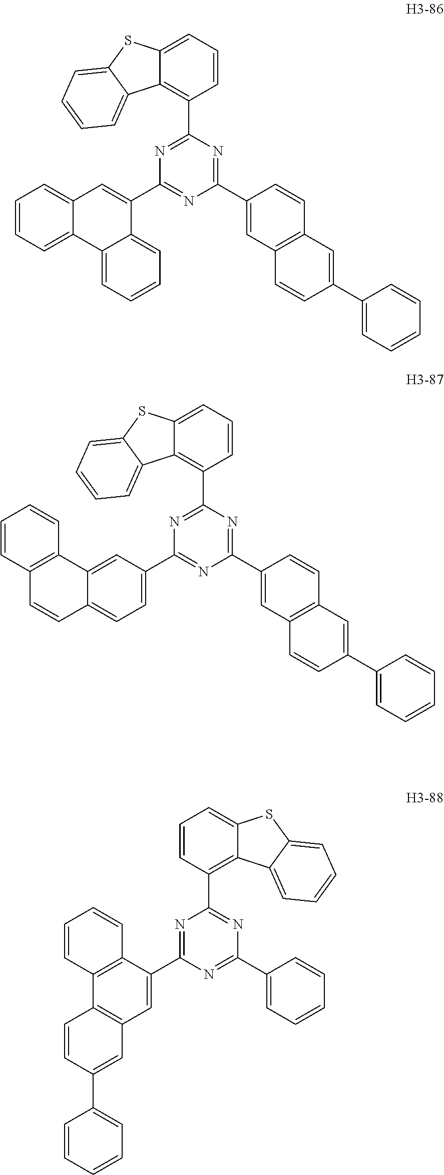 [SMILES: c1ccc(-c2ccc3cc(-c4nc(-c5cc6ccccc6c6ccccc56)nc(-c5cccc6sc7ccccc7c56)n4)ccc3c2)cc1 ; c1ccc(-c2ccc3cc(-c4nc(-c5ccc6ccc7ccccc7c6c5)nc(-c5cccc6sc7ccccc7c56)n4)ccc3c2)cc1 ; c1ccc(-c2ccc3c(c2)cc(-c2nc(-c4ccccc4)nc(-c4cccc5sc6ccccc6c45)n2)c2ccccc23)cc1]

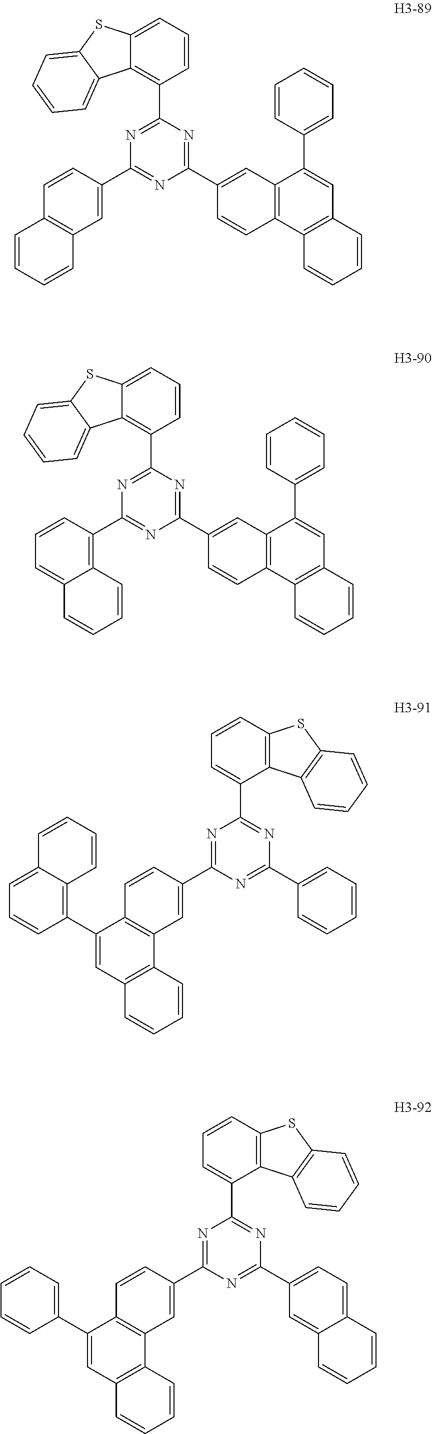 [SMILES: c1ccc(-c2cc3ccccc3c3ccc(-c4nc(-c5ccc6ccccc6c5)nc(-c5cccc6sc7ccccc7c56)n4)cc23)cc1 ; c1ccc(-c2cc3ccccc3c3ccc(-c4nc(-c5cccc6ccccc56)nc(-c5cccc6sc7ccccc7c56)n4)cc23)cc1 ; c1ccc(-c2nc(-c3ccc4c(-c5cccc6ccccc56)cc5ccccc5c4c3)nc(-c3cccc4sc5ccccc5c34)n2)cc1 ; c1ccc(-c2cc3ccccc3c3cc(-c4nc(-c5ccc6ccccc6c5)nc(-c5cccc6sc7ccccc7c56)n4)ccc23)cc1]

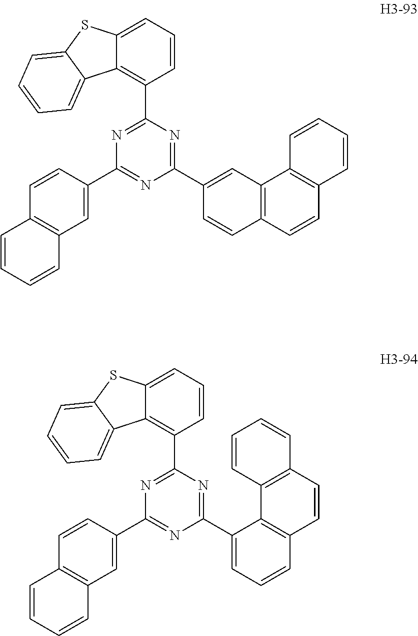 [SMILES: c1ccc2cc(-c3nc(-c4ccc5ccc6ccccc6c5c4)nc(-c4cccc5sc6ccccc6c45)n3)ccc2c1 ; c1ccc2cc(-c3nc(-c4cccc5ccc6ccccc6c45)nc(-c4cccc5sc6ccccc6c45)n3)ccc2c1]

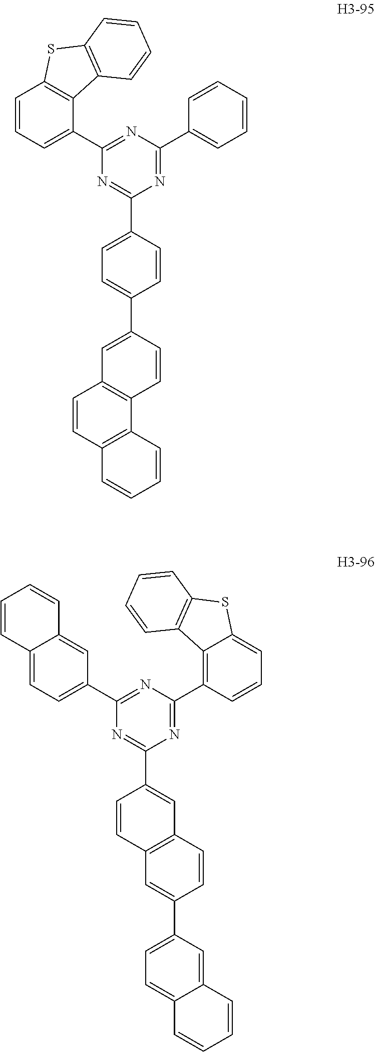 [SMILES: c1ccc(-c2nc(-c3ccc(-c4ccc5c(ccc6ccccc65)c4)cc3)nc(-c3cccc4sc5ccccc5c34)n2)cc1 ; c1ccc2cc(-c3ccc4cc(-c5nc(-c6ccc7ccccc7c6)nc(-c6cccc7sc8ccccc8c67)n5)ccc4c3)ccc2c1]

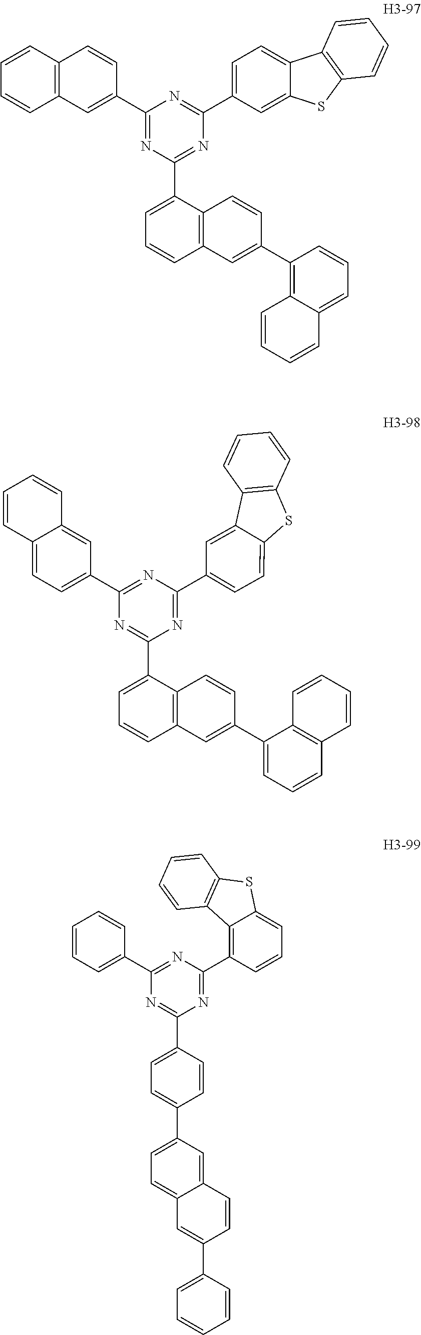 [SMILES: c1ccc2cc(-c3nc(-c4ccc5c(c4)sc4ccccc45)nc(-c4cccc5cc(-c6cccc7ccccc67)ccc45)n3)ccc2c1 ; c1ccc2cc(-c3nc(-c4ccc5sc6ccccc6c5c4)nc(-c4cccc5cc(-c6cccc7ccccc67)ccc45)n3)ccc2c1 ; c1ccc(-c2ccc3cc(-c4ccc(-c5nc(-c6ccccc6)nc(-c6cccc7sc8ccccc8c67)n5)cc4)ccc3c2)cc1]

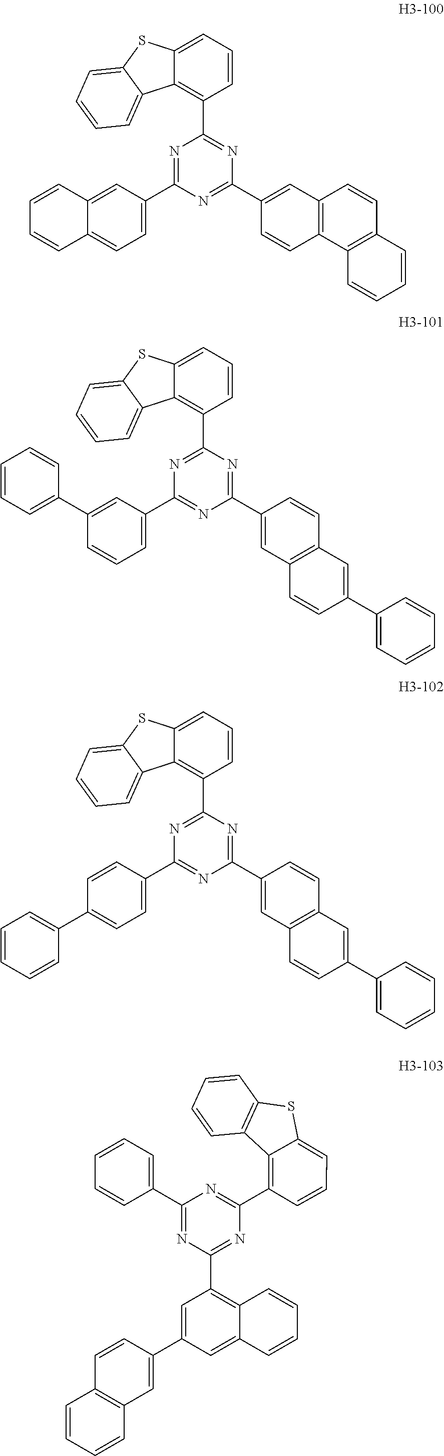 [SMILES: c1ccc2cc(-c3nc(-c4ccc5c(ccc6ccccc65)c4)nc(-c4cccc5sc6ccccc6c45)n3)ccc2c1 ; c1ccc(-c2cccc(-c3nc(-c4ccc5cc(-c6ccccc6)ccc5c4)nc(-c4cccc5sc6ccccc6c45)n3)c2)cc1 ; c1ccc(-c2ccc(-c3nc(-c4ccc5cc(-c6ccccc6)ccc5c4)nc(-c4cccc5sc6ccccc6c45)n3)cc2)cc1 ; c1ccc(-c2nc(-c3cc(-c4ccc5ccccc5c4)cc4ccccc34)nc(-c3cccc4sc5ccccc5c34)n2)cc1]

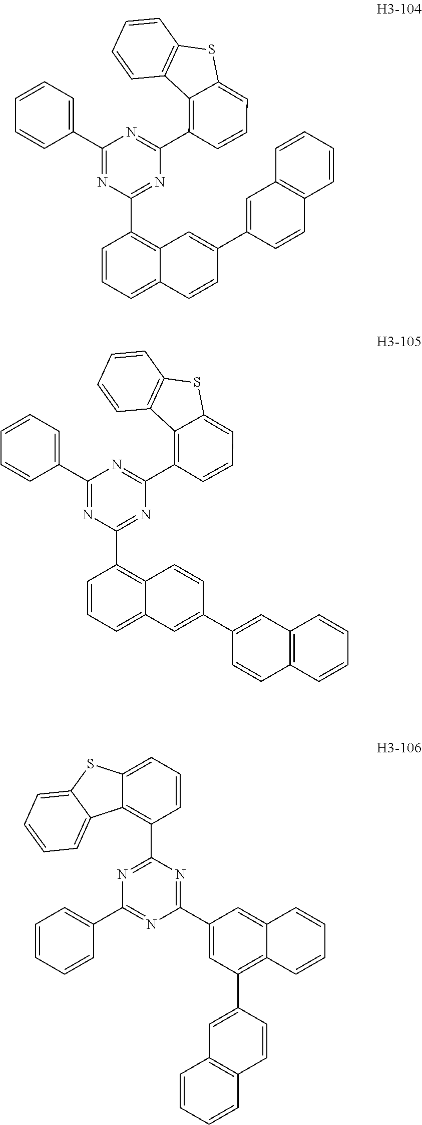 [SMILES: c1ccc(-c2nc(-c3cccc4ccc(-c5ccc6ccccc6c5)cc34)nc(-c3cccc4sc5ccccc5c34)n2)cc1 ; c1ccc(-c2nc(-c3cccc4cc(-c5ccc6ccccc6c5)ccc34)nc(-c3cccc4sc5ccccc5c34)n2)cc1 ; c1ccc(-c2nc(-c3cc(-c4ccc5ccccc5c4)c4ccccc4c3)nc(-c3cccc4sc5ccccc5c34)n2)cc1]

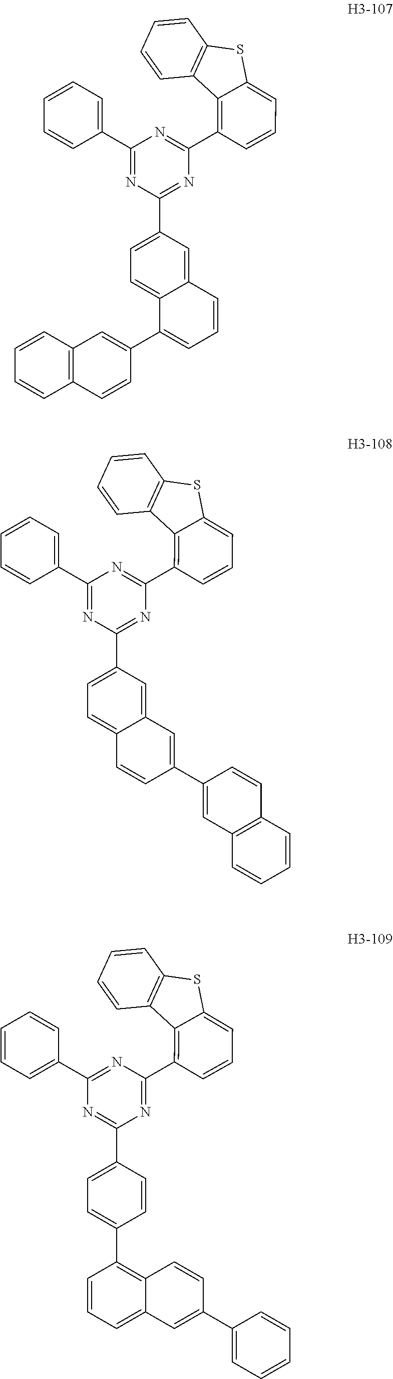 [SMILES: c1ccc(-c2nc(-c3ccc4c(-c5ccc6ccccc6c5)cccc4c3)nc(-c3cccc4sc5ccccc5c34)n2)cc1 ; c1ccc(-c2nc(-c3ccc4ccc(-c5ccc6ccccc6c5)cc4c3)nc(-c3cccc4sc5ccccc5c34)n2)cc1 ; c1ccc(-c2ccc3c(-c4ccc(-c5nc(-c6ccccc6)nc(-c6cccc7sc8ccccc8c67)n5)cc4)cccc3c2)cc1]

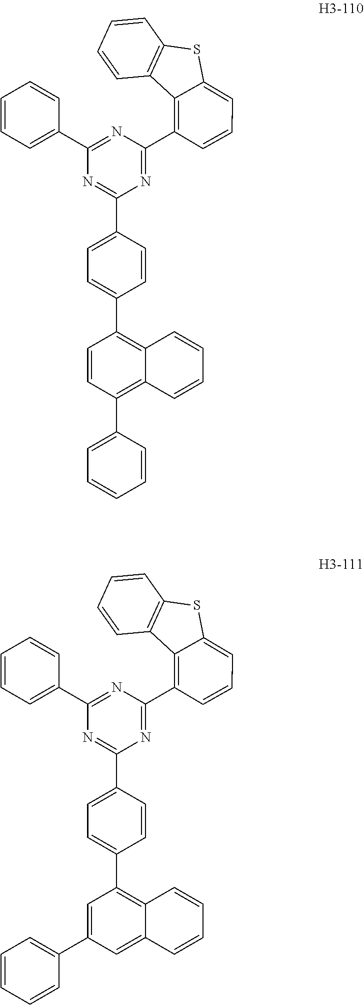 [SMILES: c1ccc(-c2nc(-c3ccc(-c4ccc(-c5ccccc5)c5ccccc45)cc3)nc(-c3cccc4sc5ccccc5c34)n2)cc1 ; c1ccc(-c2cc(-c3ccc(-c4nc(-c5ccccc5)nc(-c5cccc6sc7ccccc7c56)n4)cc3)c3ccccc3c2)cc1]

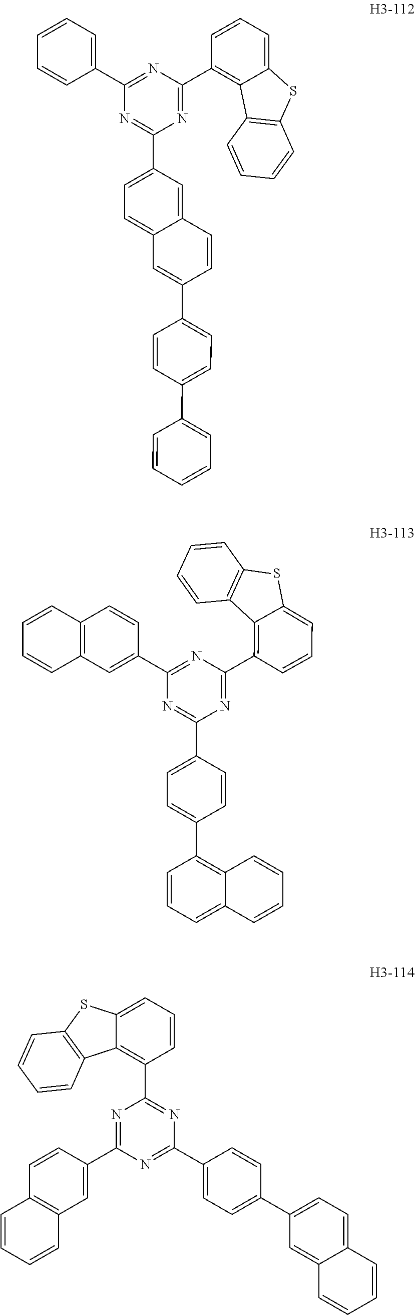 [SMILES: c1ccc(-c2ccc(-c3ccc4cc(-c5nc(-c6ccccc6)nc(-c6cccc7sc8ccccc8c67)n5)ccc4c3)cc2)cc1 ; c1ccc2cc(-c3nc(-c4ccc(-c5cccc6ccccc56)cc4)nc(-c4cccc5sc6ccccc6c45)n3)ccc2c1 ; c1ccc2cc(-c3ccc(-c4nc(-c5ccc6ccccc6c5)nc(-c5cccc6sc7ccccc7c56)n4)cc3)ccc2c1]

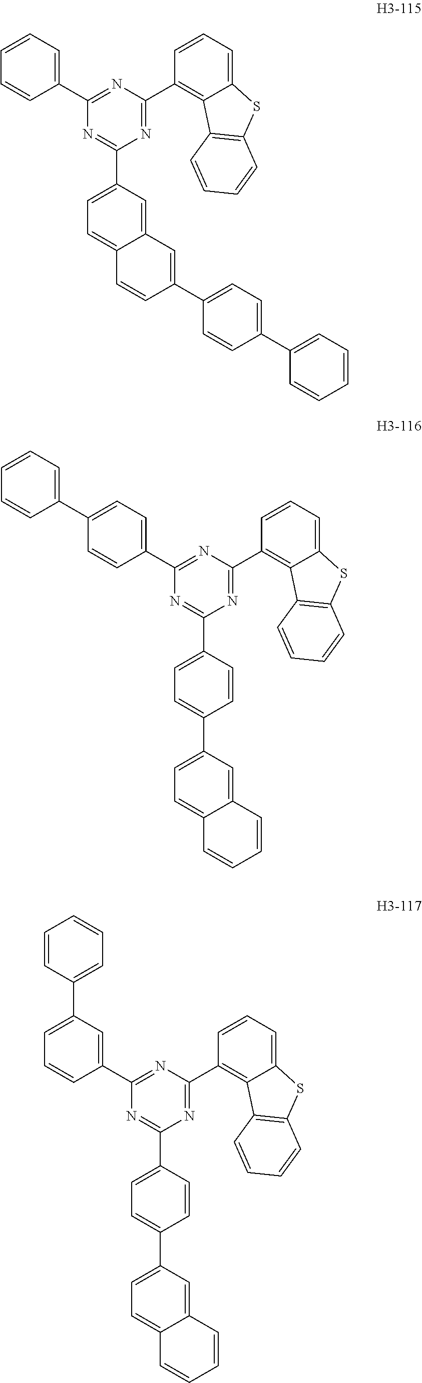 [SMILES: c1ccc(-c2ccc(-c3ccc4ccc(-c5nc(-c6ccccc6)nc(-c6cccc7sc8ccccc8c67)n5)cc4c3)cc2)cc1 ; c1ccc(-c2ccc(-c3nc(-c4ccc(-c5ccc6ccccc6c5)cc4)nc(-c4cccc5sc6ccccc6c45)n3)cc2)cc1 ; c1ccc(-c2cccc(-c3nc(-c4ccc(-c5ccc6ccccc6c5)cc4)nc(-c4cccc5sc6ccccc6c45)n3)c2)cc1]

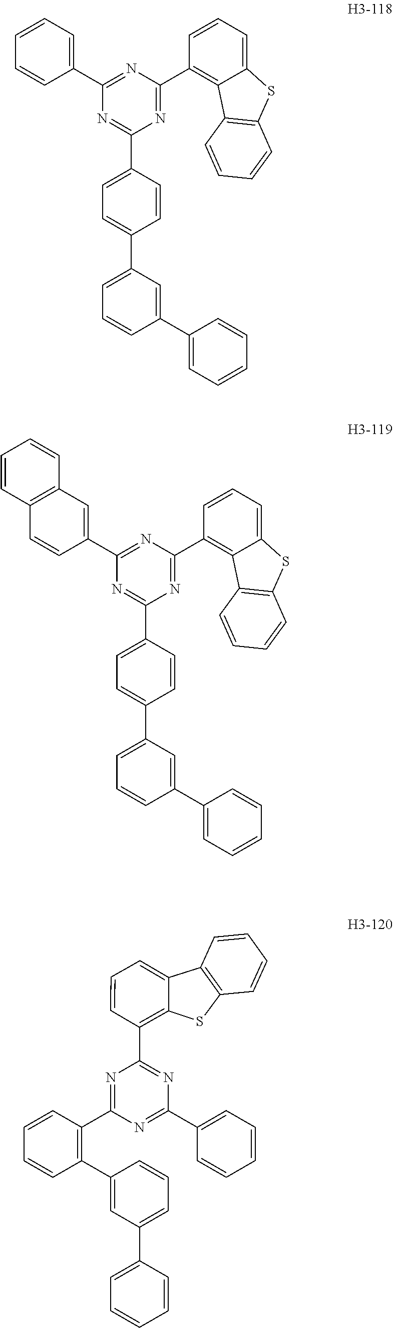 [SMILES: c1ccc(-c2cccc(-c3ccc(-c4nc(-c5ccccc5)nc(-c5cccc6sc7ccccc7c56)n4)cc3)c2)cc1 ; c1ccc(-c2cccc(-c3ccc(-c4nc(-c5ccc6ccccc6c5)nc(-c5cccc6sc7ccccc7c56)n4)cc3)c2)cc1 ; c1ccc(-c2cccc(-c3ccccc3-c3nc(-c4ccccc4)nc(-c4cccc5c4sc4ccccc45)n3)c2)cc1]

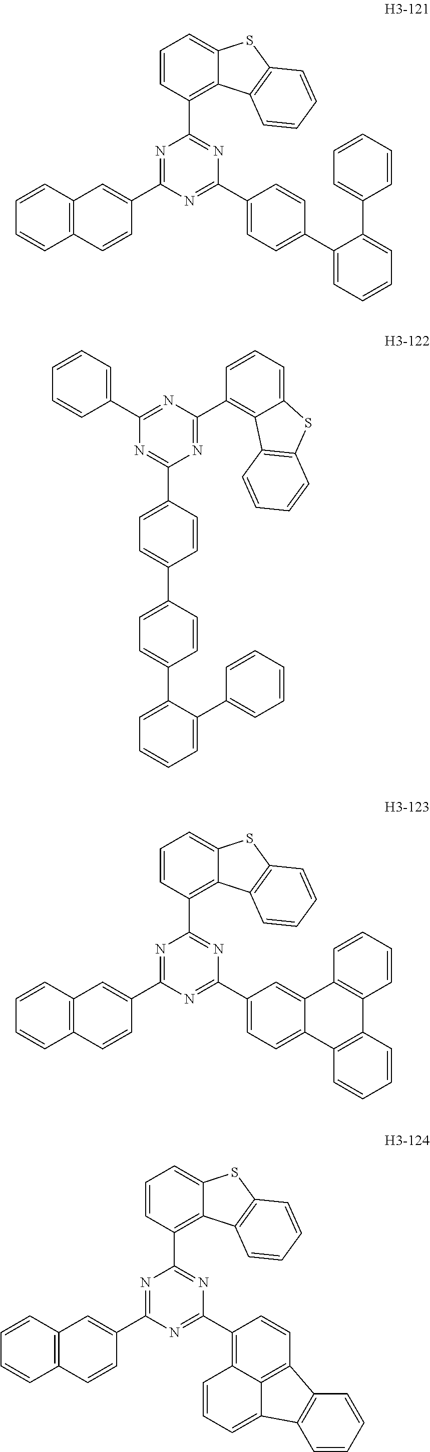 [SMILES: c1ccc(-c2ccccc2-c2ccc(-c3nc(-c4ccc5ccccc5c4)nc(-c4cccc5sc6ccccc6c45)n3)cc2)cc1 ; c1ccc(-c2nc(-c3ccc(-c4ccc(-c5ccccc5-c5ccccc5)cc4)cc3)nc(-c3cccc4sc5ccccc5c34)n2)cc1 ; c1ccc2cc(-c3nc(-c4ccc5c6ccccc6c6ccccc6c5c4)nc(-c4cccc5sc6ccccc6c45)n3)ccc2c1 ; c1ccc2c(c1)-c1cccc3c(-c4nc(-c5ccc6ccccc6c5)nc(-c5cccc6sc7ccccc7c56)n4)ccc-2c13]

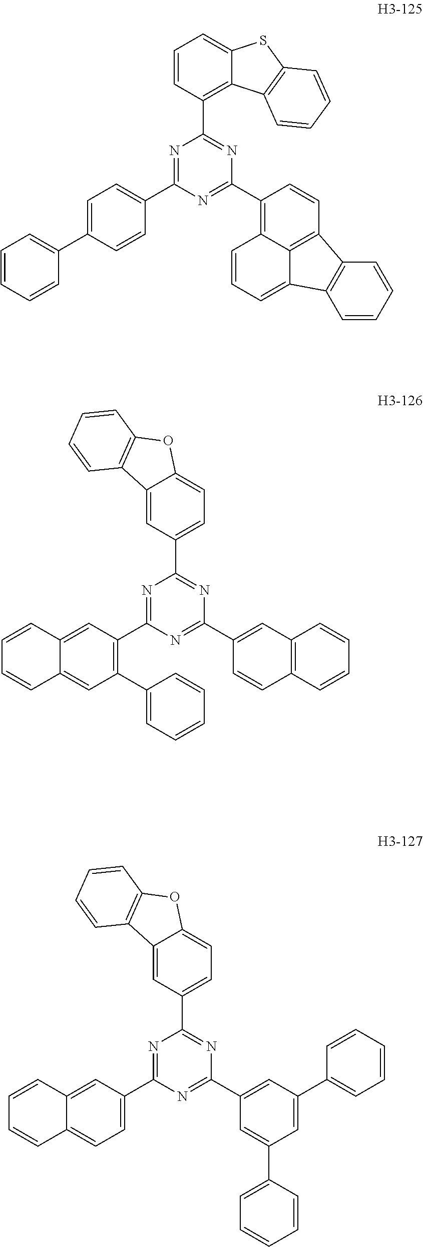 [SMILES: c1ccc(-c2ccc(-c3nc(-c4ccc5c6c(cccc46)-c4ccccc4-5)nc(-c4cccc5sc6ccccc6c45)n3)cc2)cc1 ; c1ccc(-c2cc3ccccc3cc2-c2nc(-c3ccc4ccccc4c3)nc(-c3ccc4oc5ccccc5c4c3)n2)cc1 ; c1ccc(-c2cc(-c3ccccc3)cc(-c3nc(-c4ccc5ccccc5c4)nc(-c4ccc5oc6ccccc6c5c4)n3)c2)cc1]

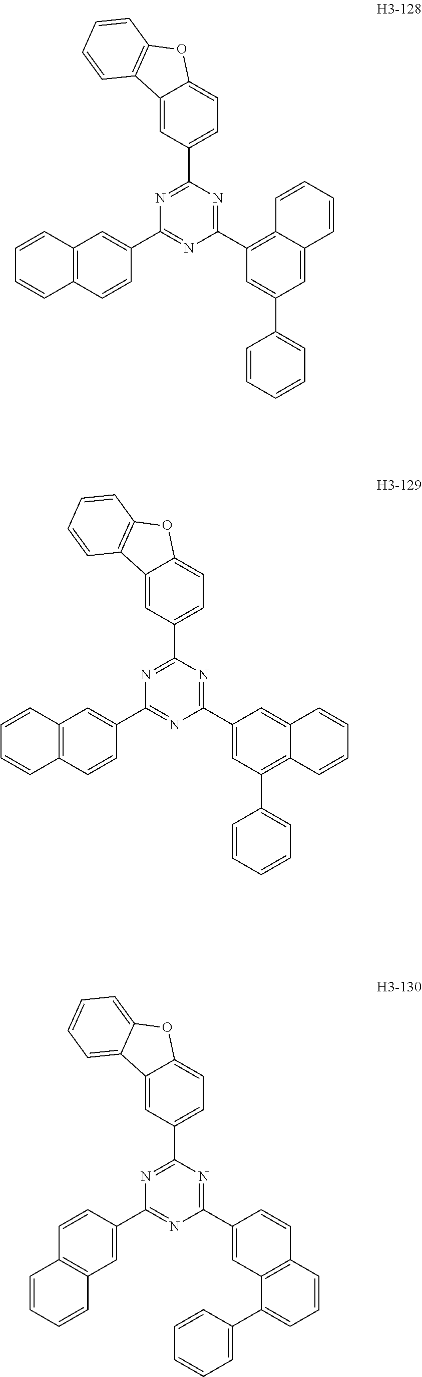 [SMILES: c1ccc(-c2cc(-c3nc(-c4ccc5ccccc5c4)nc(-c4ccc5oc6ccccc6c5c4)n3)c3ccccc3c2)cc1 ; c1ccc(-c2cc(-c3nc(-c4ccc5ccccc5c4)nc(-c4ccc5oc6ccccc6c5c4)n3)cc3ccccc23)cc1 ; c1ccc(-c2cccc3ccc(-c4nc(-c5ccc6ccccc6c5)nc(-c5ccc6oc7ccccc7c6c5)n4)cc23)cc1]

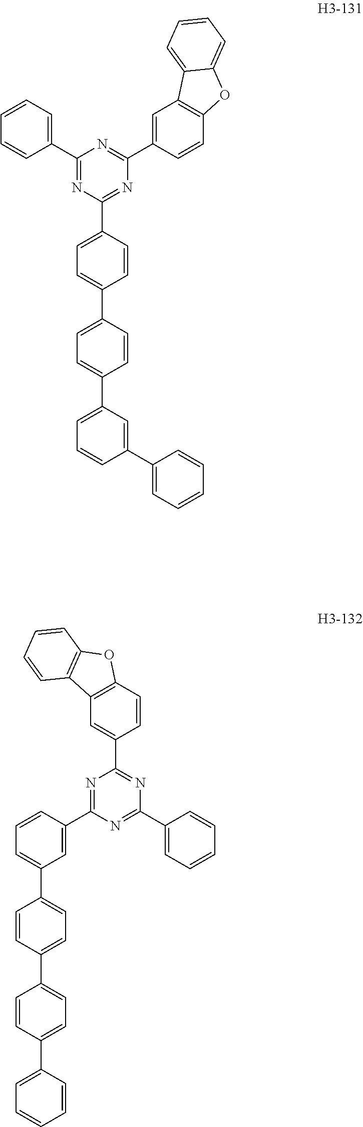 [SMILES: c1ccc(-c2cccc(-c3ccc(-c4ccc(-c5nc(-c6ccccc6)nc(-c6ccc7oc8ccccc8c7c6)n5)cc4)cc3)c2)cc1 ; c1ccc(-c2ccc(-c3ccc(-c4cccc(-c5nc(-c6ccccc6)nc(-c6ccc7oc8ccccc8c7c6)n5)c4)cc3)cc2)cc1]

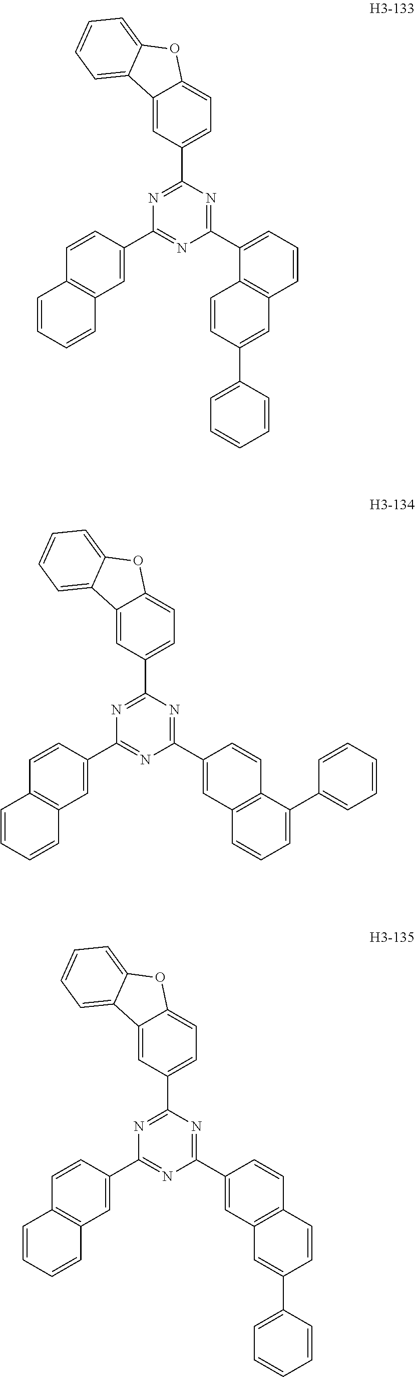 [SMILES: c1ccc(-c2ccc3c(-c4nc(-c5ccc6ccccc6c5)nc(-c5ccc6oc7ccccc7c6c5)n4)cccc3c2)cc1 ; c1ccc(-c2cccc3cc(-c4nc(-c5ccc6ccccc6c5)nc(-c5ccc6oc7ccccc7c6c5)n4)ccc23)cc1 ; c1ccc(-c2ccc3ccc(-c4nc(-c5ccc6ccccc6c5)nc(-c5ccc6oc7ccccc7c6c5)n4)cc3c2)cc1]

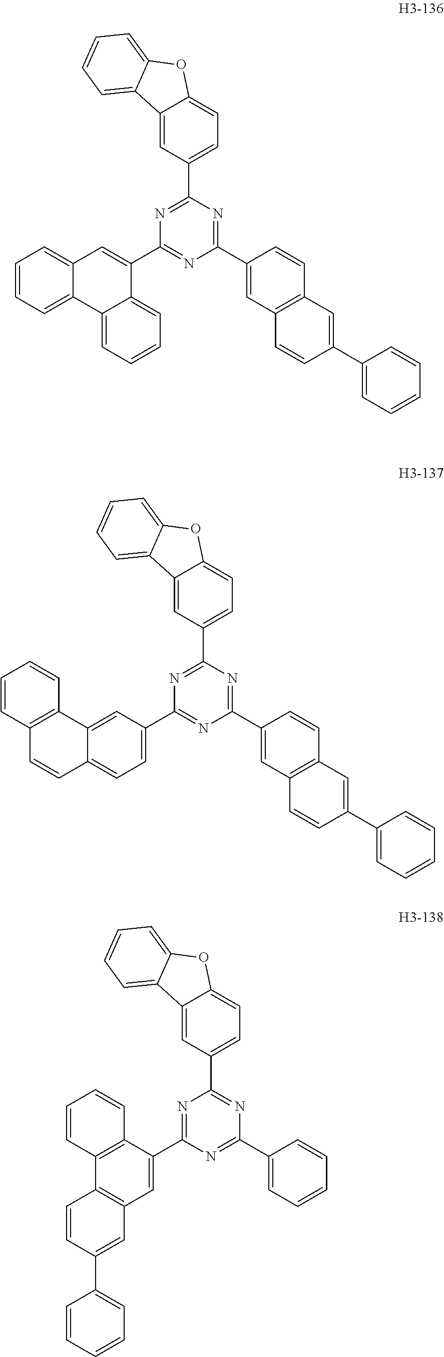 [SMILES: c1ccc(-c2ccc3cc(-c4nc(-c5ccc6oc7ccccc7c6c5)nc(-c5cc6ccccc6c6ccccc56)n4)ccc3c2)cc1 ; c1ccc(-c2ccc3cc(-c4nc(-c5ccc6ccc7ccccc7c6c5)nc(-c5ccc6oc7ccccc7c6c5)n4)ccc3c2)cc1 ; c1ccc(-c2ccc3c(c2)cc(-c2nc(-c4ccccc4)nc(-c4ccc5oc6ccccc6c5c4)n2)c2ccccc23)cc1]

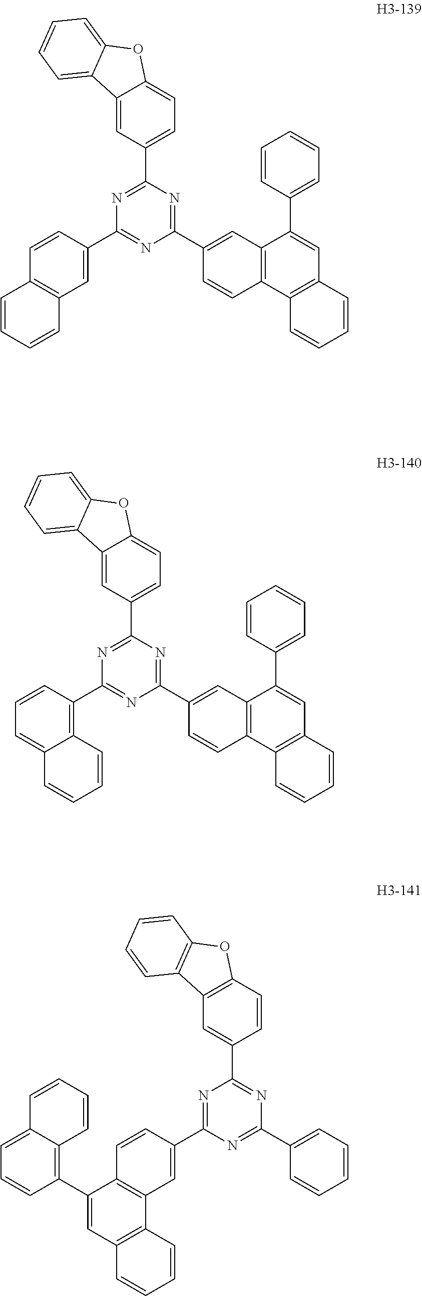 [SMILES: c1ccc(-c2cc3ccccc3c3ccc(-c4nc(-c5ccc6ccccc6c5)nc(-c5ccc6oc7ccccc7c6c5)n4)cc23)cc1 ; c1ccc(-c2cc3ccccc3c3ccc(-c4nc(-c5ccc6oc7ccccc7c6c5)nc(-c5cccc6ccccc56)n4)cc23)cc1 ; c1ccc(-c2nc(-c3ccc4oc5ccccc5c4c3)nc(-c3ccc4c(-c5cccc6ccccc56)cc5ccccc5c4c3)n2)cc1]

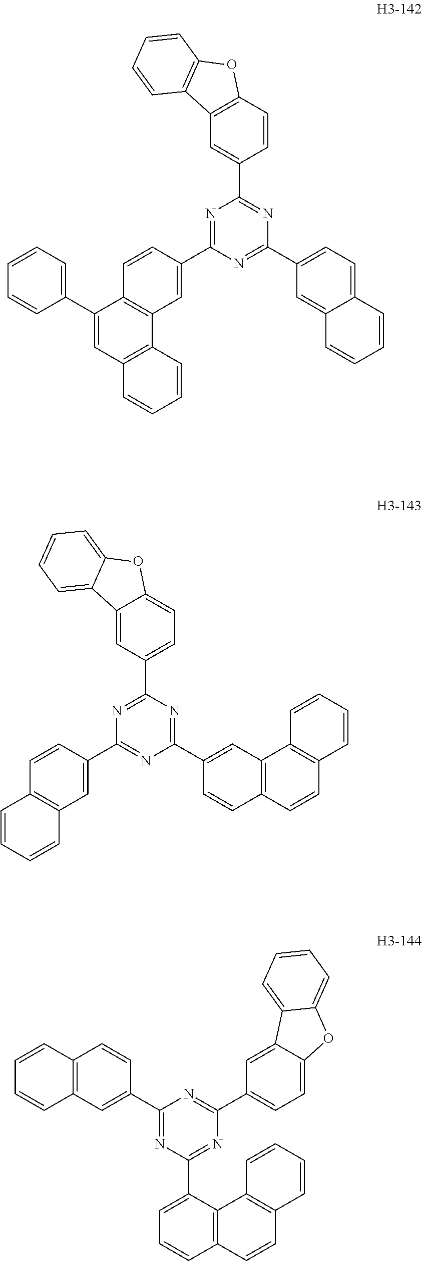 [SMILES: c1ccc(-c2cc3ccccc3c3cc(-c4nc(-c5ccc6ccccc6c5)nc(-c5ccc6oc7ccccc7c6c5)n4)ccc23)cc1 ; c1ccc2cc(-c3nc(-c4ccc5ccc6ccccc6c5c4)nc(-c4ccc5oc6ccccc6c5c4)n3)ccc2c1 ; c1ccc2cc(-c3nc(-c4ccc5oc6ccccc6c5c4)nc(-c4cccc5ccc6ccccc6c45)n3)ccc2c1]

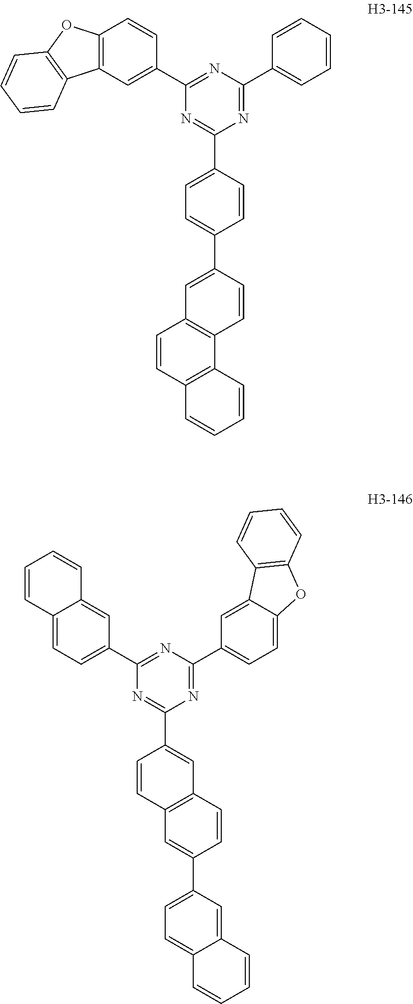 [SMILES: c1ccc(-c2nc(-c3ccc(-c4ccc5c(ccc6ccccc65)c4)cc3)nc(-c3ccc4oc5ccccc5c4c3)n2)cc1 ; c1ccc2cc(-c3ccc4cc(-c5nc(-c6ccc7ccccc7c6)nc(-c6ccc7oc8ccccc8c7c6)n5)ccc4c3)ccc2c1]

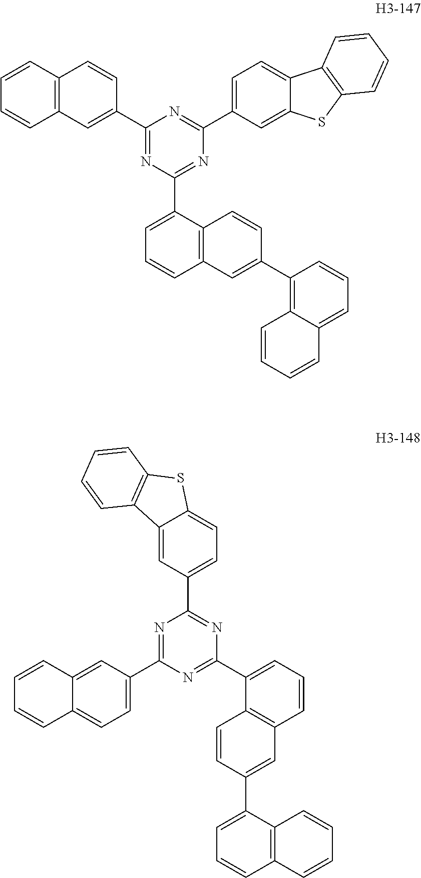 [SMILES: c1ccc2cc(-c3nc(-c4ccc5c(c4)sc4ccccc45)nc(-c4cccc5cc(-c6cccc7ccccc67)ccc45)n3)ccc2c1 ; c1ccc2cc(-c3nc(-c4ccc5sc6ccccc6c5c4)nc(-c4cccc5cc(-c6cccc7ccccc67)ccc45)n3)ccc2c1]

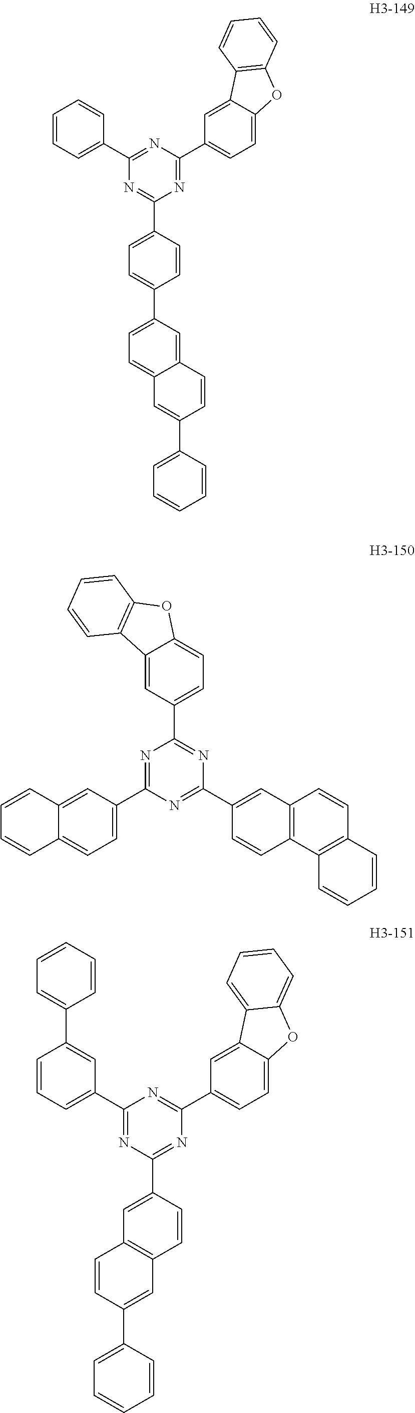 [SMILES: c1ccc(-c2ccc3cc(-c4ccc(-c5nc(-c6ccccc6)nc(-c6ccc7oc8ccccc8c7c6)n5)cc4)ccc3c2)cc1 ; c1ccc2cc(-c3nc(-c4ccc5c(ccc6ccccc65)c4)nc(-c4ccc5oc6ccccc6c5c4)n3)ccc2c1 ; c1ccc(-c2cccc(-c3nc(-c4ccc5cc(-c6ccccc6)ccc5c4)nc(-c4ccc5oc6ccccc6c5c4)n3)c2)cc1]

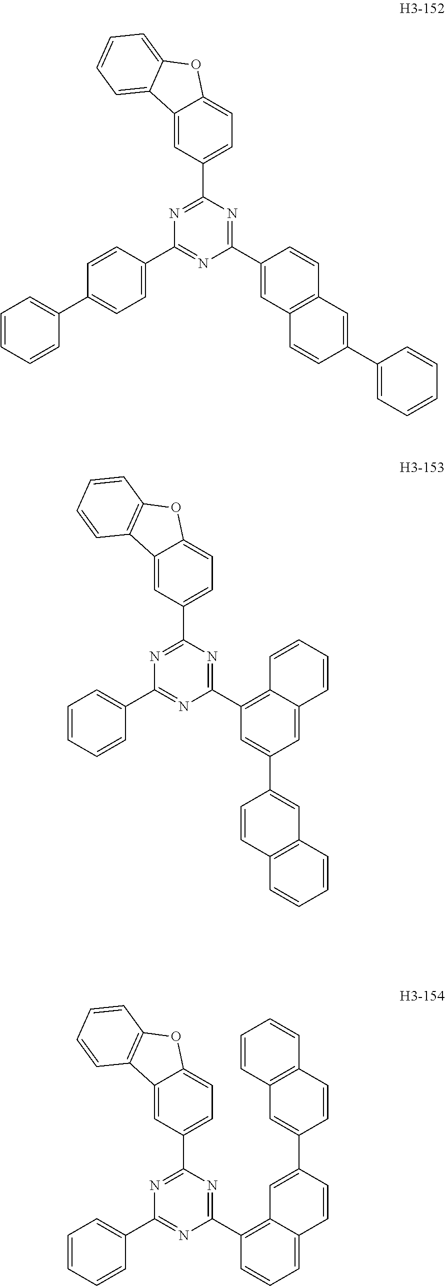 [SMILES: c1ccc(-c2ccc(-c3nc(-c4ccc5cc(-c6ccccc6)ccc5c4)nc(-c4ccc5oc6ccccc6c5c4)n3)cc2)cc1 ; c1ccc(-c2nc(-c3ccc4oc5ccccc5c4c3)nc(-c3cc(-c4ccc5ccccc5c4)cc4ccccc34)n2)cc1 ; c1ccc(-c2nc(-c3ccc4oc5ccccc5c4c3)nc(-c3cccc4ccc(-c5ccc6ccccc6c5)cc34)n2)cc1]

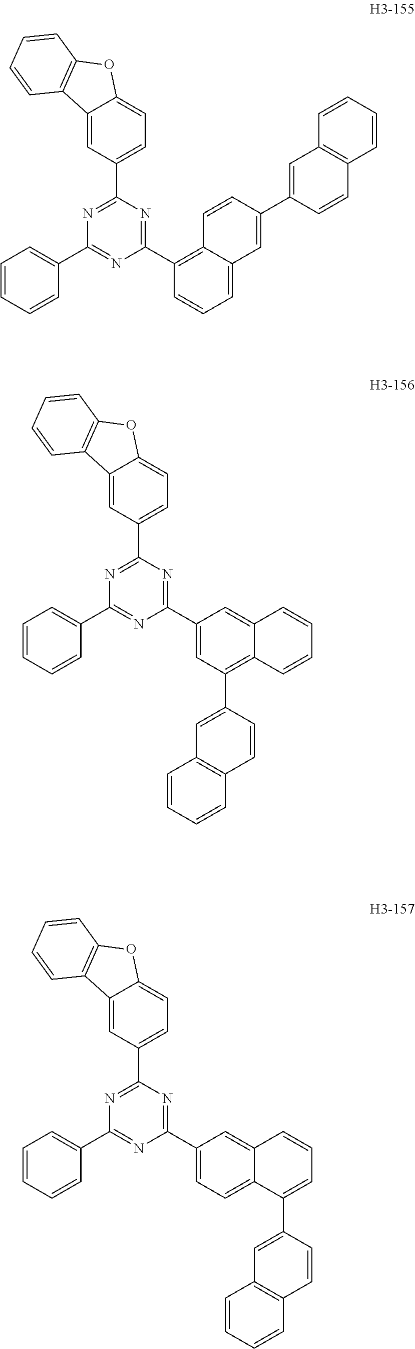 [SMILES: c1ccc(-c2nc(-c3ccc4oc5ccccc5c4c3)nc(-c3cccc4cc(-c5ccc6ccccc6c5)ccc34)n2)cc1 ; c1ccc(-c2nc(-c3cc(-c4ccc5ccccc5c4)c4ccccc4c3)nc(-c3ccc4oc5ccccc5c4c3)n2)cc1 ; c1ccc(-c2nc(-c3ccc4c(-c5ccc6ccccc6c5)cccc4c3)nc(-c3ccc4oc5ccccc5c4c3)n2)cc1]

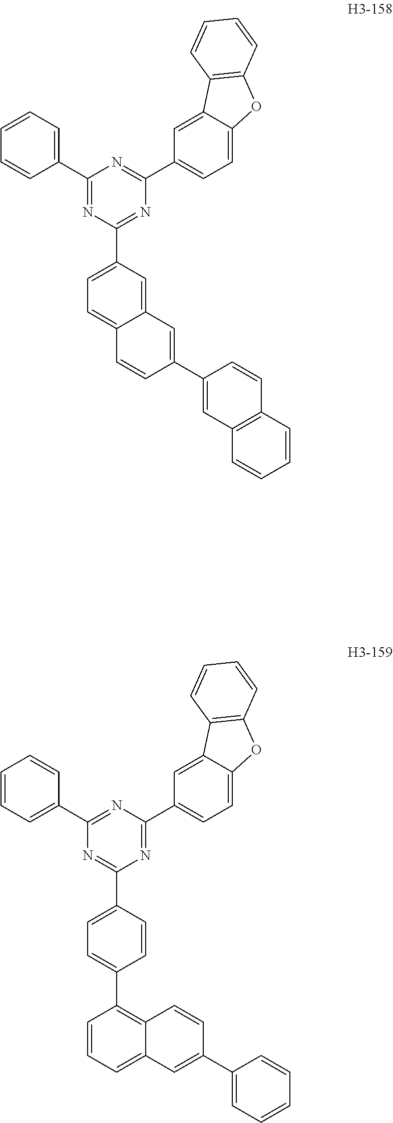 [SMILES: c1ccc(-c2nc(-c3ccc4ccc(-c5ccc6ccccc6c5)cc4c3)nc(-c3ccc4oc5ccccc5c4c3)n2)cc1 ; c1ccc(-c2ccc3c(-c4ccc(-c5nc(-c6ccccc6)nc(-c6ccc7oc8ccccc8c7c6)n5)cc4)cccc3c2)cc1]

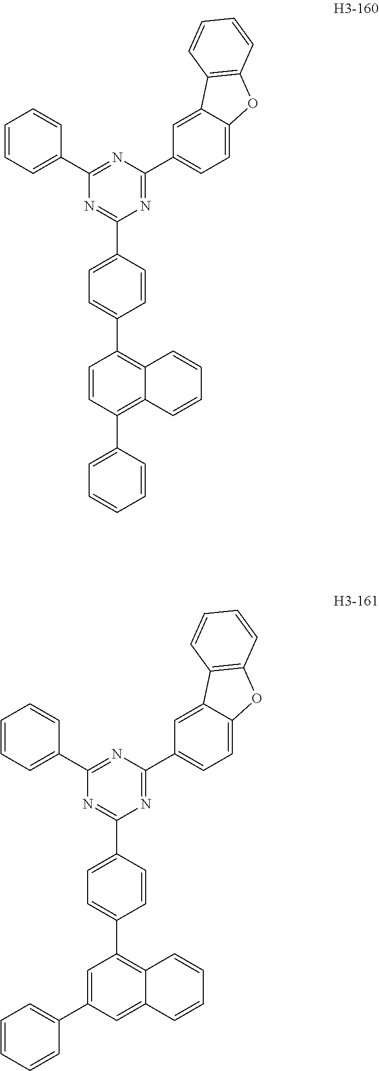 [SMILES: c1ccc(-c2nc(-c3ccc(-c4ccc(-c5ccccc5)c5ccccc45)cc3)nc(-c3ccc4oc5ccccc5c4c3)n2)cc1 ; c1ccc(-c2cc(-c3ccc(-c4nc(-c5ccccc5)nc(-c5ccc6oc7ccccc7c6c5)n4)cc3)c3ccccc3c2)cc1]

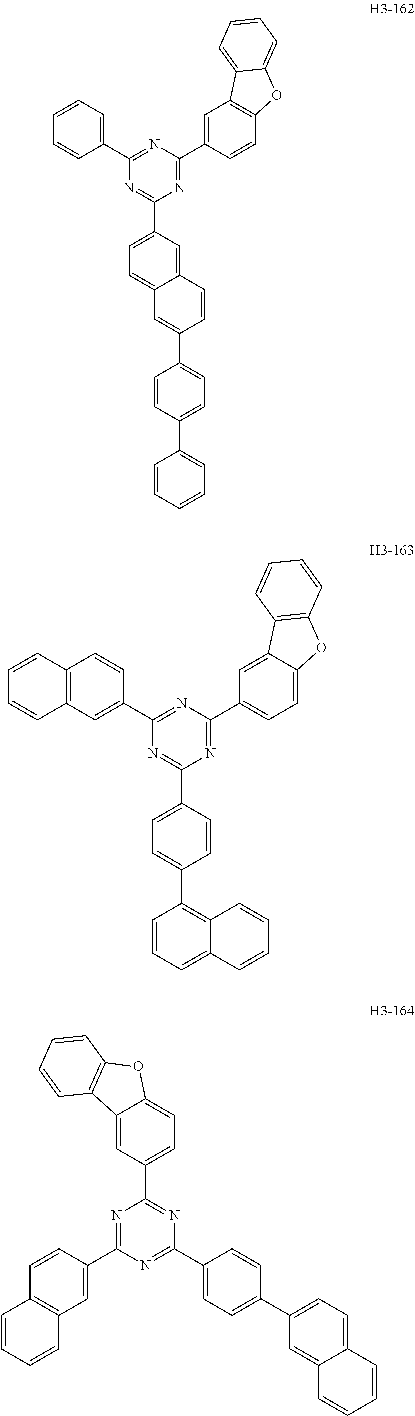 [SMILES: c1ccc(-c2ccc(-c3ccc4cc(-c5nc(-c6ccccc6)nc(-c6ccc7oc8ccccc8c7c6)n5)ccc4c3)cc2)cc1 ; c1ccc2cc(-c3nc(-c4ccc(-c5cccc6ccccc56)cc4)nc(-c4ccc5oc6ccccc6c5c4)n3)ccc2c1 ; c1ccc2cc(-c3ccc(-c4nc(-c5ccc6ccccc6c5)nc(-c5ccc6oc7ccccc7c6c5)n4)cc3)ccc2c1]

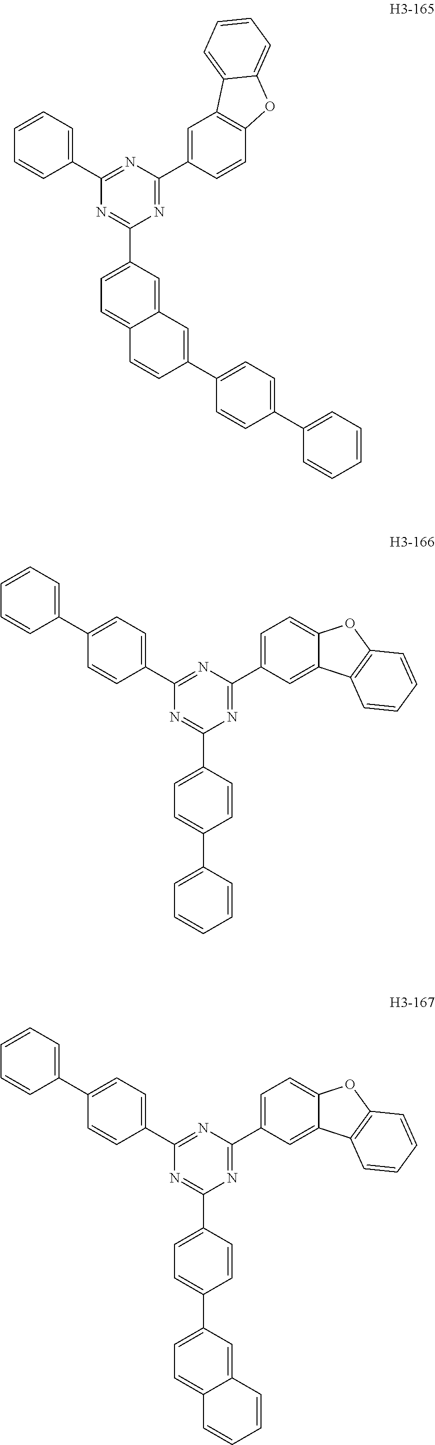 [SMILES: c1ccc(-c2ccc(-c3ccc4ccc(-c5nc(-c6ccccc6)nc(-c6ccc7oc8ccccc8c7c6)n5)cc4c3)cc2)cc1 ; c1ccc(-c2ccc(-c3nc(-c4ccc(-c5ccccc5)cc4)nc(-c4ccc5oc6ccccc6c5c4)n3)cc2)cc1 ; c1ccc(-c2ccc(-c3nc(-c4ccc(-c5ccc6ccccc6c5)cc4)nc(-c4ccc5oc6ccccc6c5c4)n3)cc2)cc1]

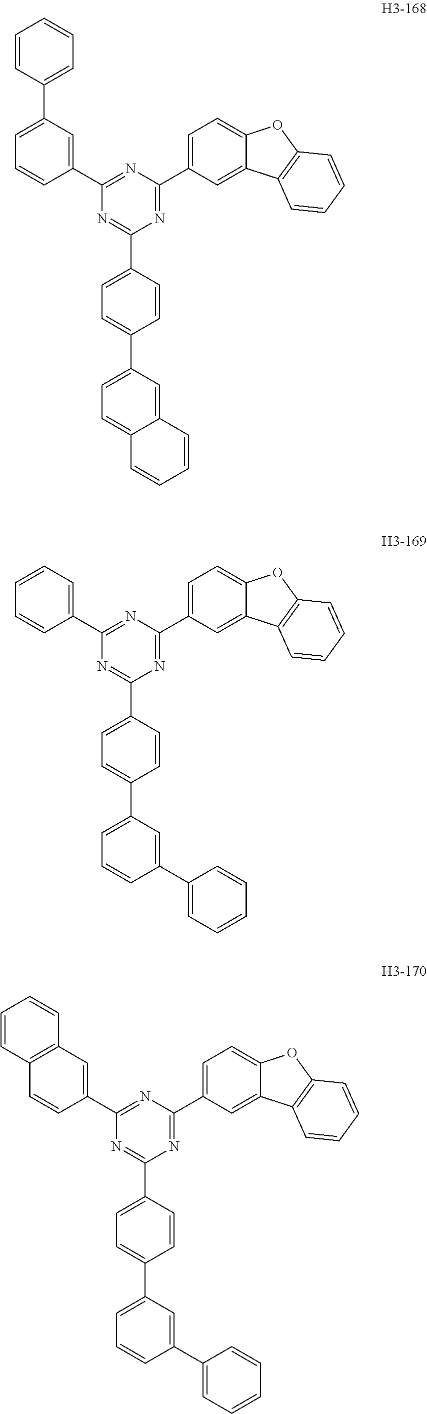 [SMILES: c1ccc(-c2cccc(-c3nc(-c4ccc(-c5ccc6ccccc6c5)cc4)nc(-c4ccc5oc6ccccc6c5c4)n3)c2)cc1 ; c1ccc(-c2cccc(-c3ccc(-c4nc(-c5ccccc5)nc(-c5ccc6oc7ccccc7c6c5)n4)cc3)c2)cc1 ; c1ccc(-c2cccc(-c3ccc(-c4nc(-c5ccc6ccccc6c5)nc(-c5ccc6oc7ccccc7c6c5)n4)cc3)c2)cc1]

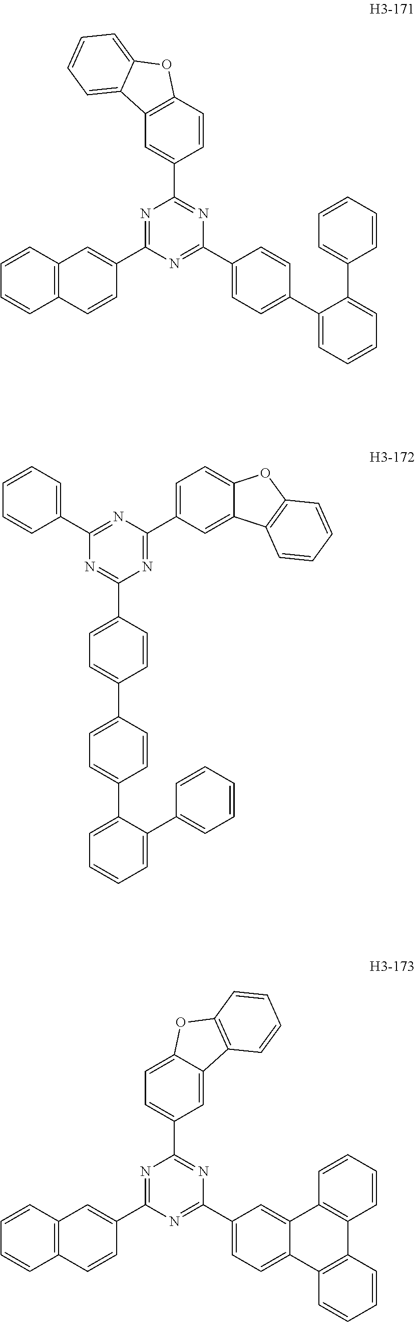 [SMILES: c1ccc(-c2ccccc2-c2ccc(-c3nc(-c4ccc5ccccc5c4)nc(-c4ccc5oc6ccccc6c5c4)n3)cc2)cc1 ; c1ccc(-c2nc(-c3ccc(-c4ccc(-c5ccccc5-c5ccccc5)cc4)cc3)nc(-c3ccc4oc5ccccc5c4c3)n2)cc1 ; c1ccc2cc(-c3nc(-c4ccc5oc6ccccc6c5c4)nc(-c4ccc5c6ccccc6c6ccccc6c5c4)n3)ccc2c1]

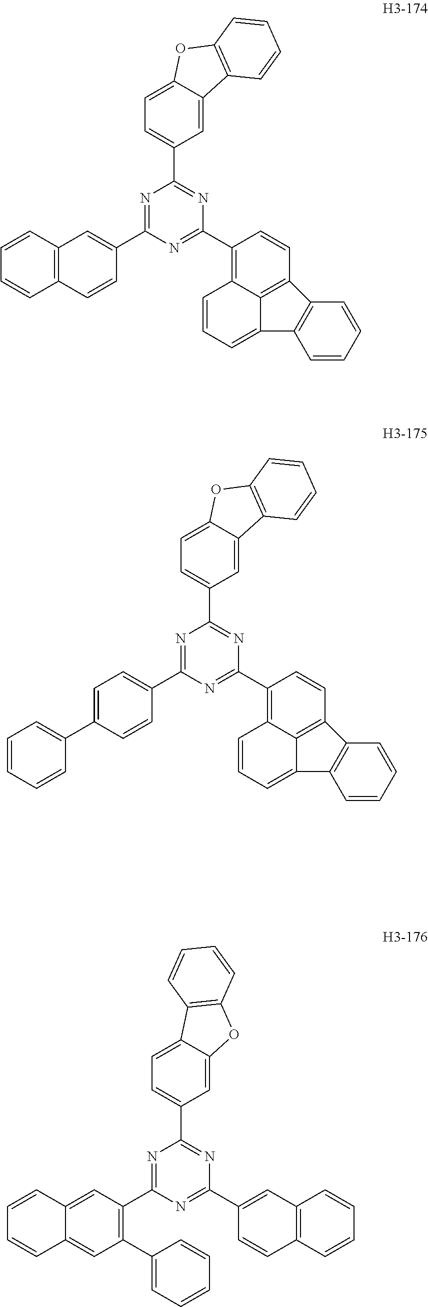 [SMILES: c1ccc2c(c1)-c1cccc3c(-c4nc(-c5ccc6ccccc6c5)nc(-c5ccc6oc7ccccc7c6c5)n4)ccc-2c13 ; c1ccc(-c2ccc(-c3nc(-c4ccc5oc6ccccc6c5c4)nc(-c4ccc5c6c(cccc46)-c4ccccc4-5)n3)cc2)cc1 ; c1ccc(-c2cc3ccccc3cc2-c2nc(-c3ccc4ccccc4c3)nc(-c3ccc4c(c3)oc3ccccc34)n2)cc1]

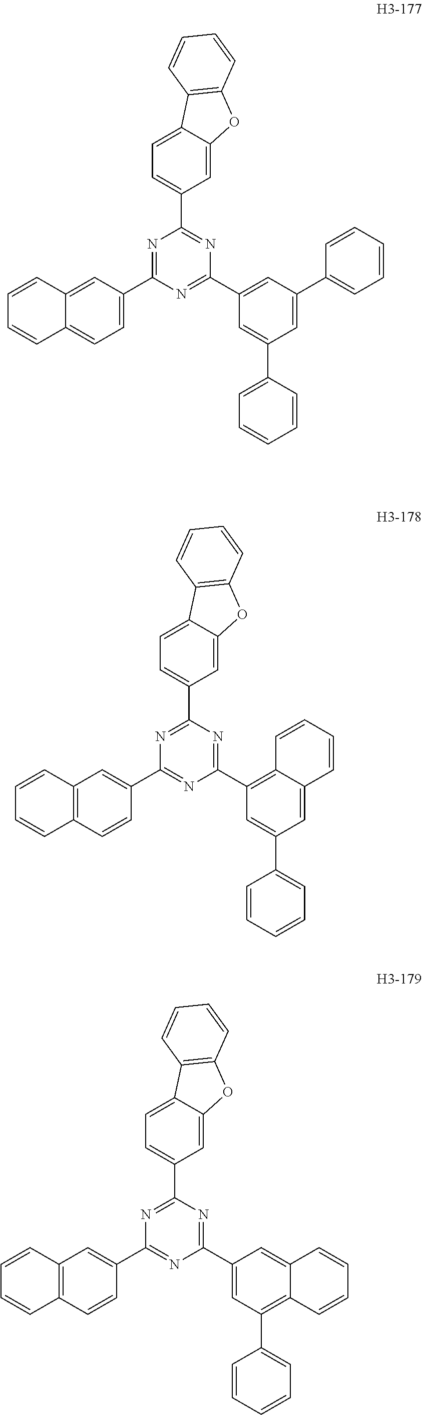 [SMILES: c1ccc(-c2cc(-c3ccccc3)cc(-c3nc(-c4ccc5ccccc5c4)nc(-c4ccc5c(c4)oc4ccccc45)n3)c2)cc1 ; c1ccc(-c2cc(-c3nc(-c4ccc5ccccc5c4)nc(-c4ccc5c(c4)oc4ccccc45)n3)c3ccccc3c2)cc1 ; c1ccc(-c2cc(-c3nc(-c4ccc5ccccc5c4)nc(-c4ccc5c(c4)oc4ccccc45)n3)cc3ccccc23)cc1]

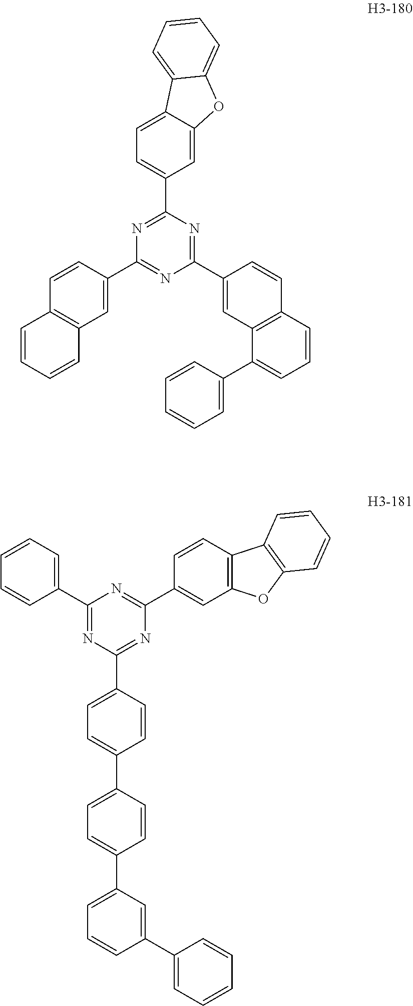 [SMILES: c1ccc(-c2cccc3ccc(-c4nc(-c5ccc6ccccc6c5)nc(-c5ccc6c(c5)oc5ccccc56)n4)cc23)cc1 ; c1ccc(-c2cccc(-c3ccc(-c4ccc(-c5nc(-c6ccccc6)nc(-c6ccc7c(c6)oc6ccccc67)n5)cc4)cc3)c2)cc1]

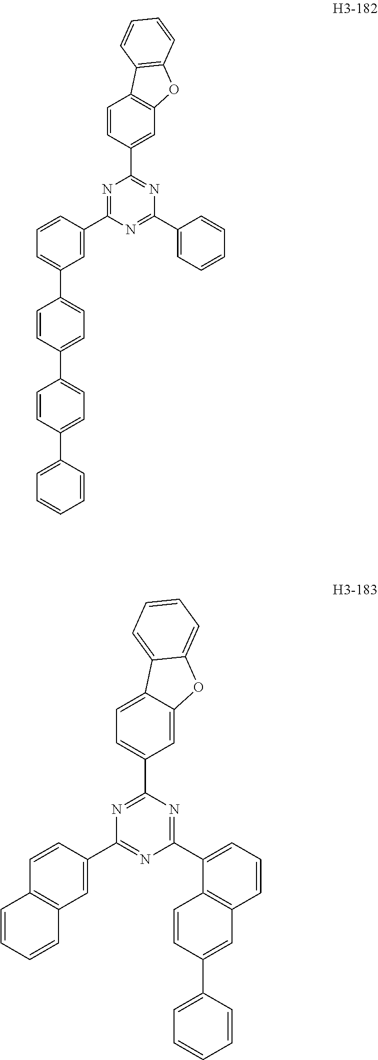 [SMILES: c1ccc(-c2ccc(-c3ccc(-c4cccc(-c5nc(-c6ccccc6)nc(-c6ccc7c(c6)oc6ccccc67)n5)c4)cc3)cc2)cc1 ; c1ccc(-c2ccc3c(-c4nc(-c5ccc6ccccc6c5)nc(-c5ccc6c(c5)oc5ccccc56)n4)cccc3c2)cc1]

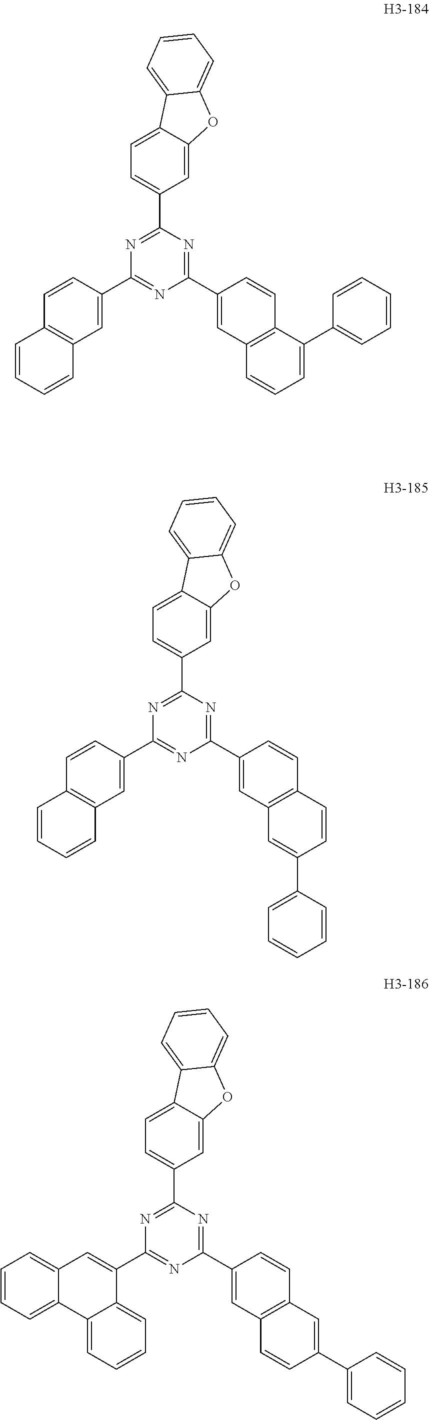 [SMILES: c1ccc(-c2cccc3cc(-c4nc(-c5ccc6ccccc6c5)nc(-c5ccc6c(c5)oc5ccccc56)n4)ccc23)cc1 ; c1ccc(-c2ccc3ccc(-c4nc(-c5ccc6ccccc6c5)nc(-c5ccc6c(c5)oc5ccccc56)n4)cc3c2)cc1 ; c1ccc(-c2ccc3cc(-c4nc(-c5ccc6c(c5)oc5ccccc56)nc(-c5cc6ccccc6c6ccccc56)n4)ccc3c2)cc1]

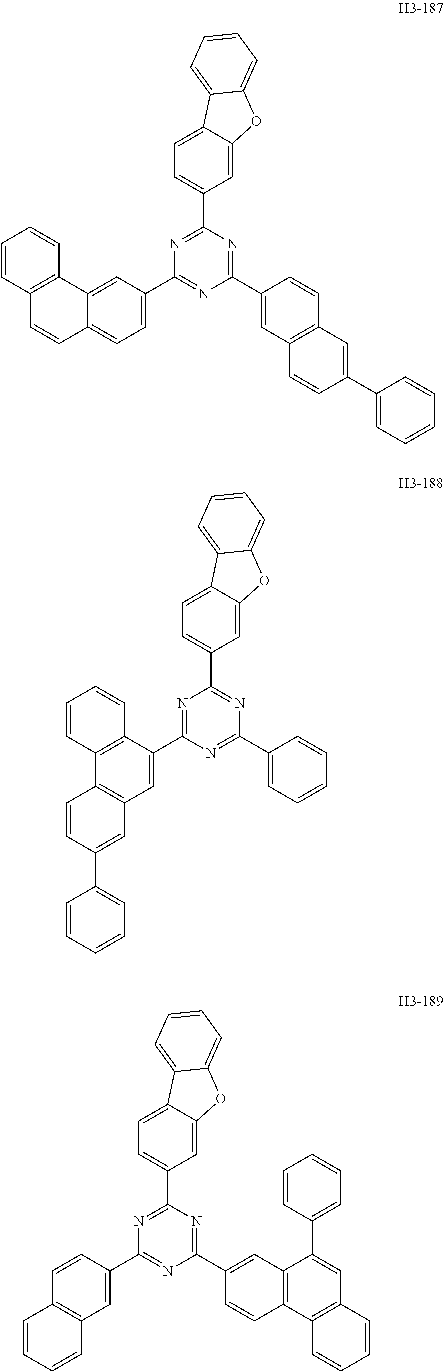 [SMILES: c1ccc(-c2ccc3cc(-c4nc(-c5ccc6c(c5)oc5ccccc56)nc(-c5ccc6ccc7ccccc7c6c5)n4)ccc3c2)cc1 ; c1ccc(-c2ccc3c(c2)cc(-c2nc(-c4ccccc4)nc(-c4ccc5c(c4)oc4ccccc45)n2)c2ccccc23)cc1 ; c1ccc(-c2cc3ccccc3c3ccc(-c4nc(-c5ccc6ccccc6c5)nc(-c5ccc6c(c5)oc5ccccc56)n4)cc23)cc1]

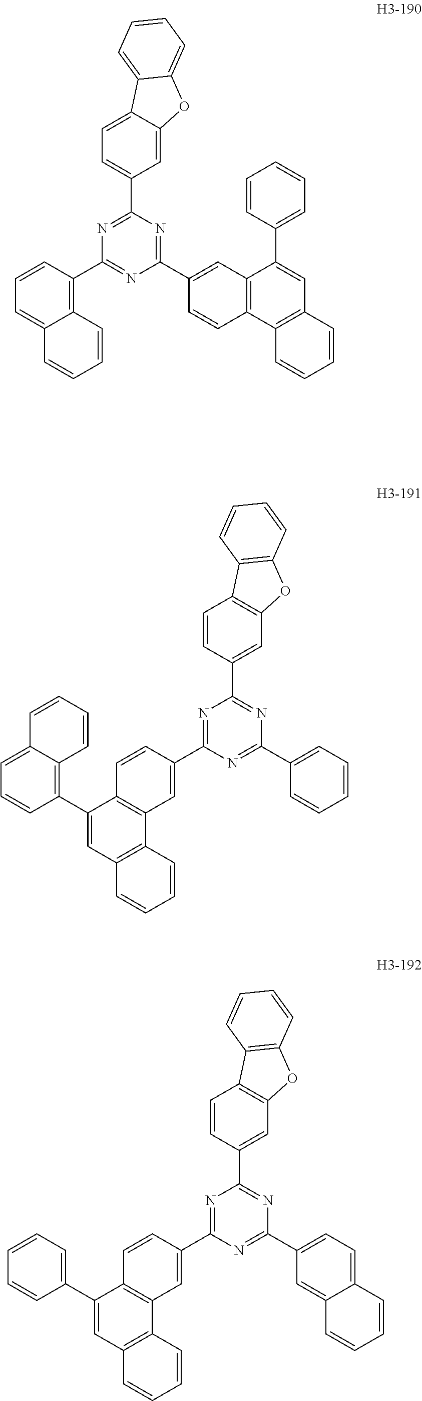 [SMILES: c1ccc(-c2cc3ccccc3c3ccc(-c4nc(-c5ccc6c(c5)oc5ccccc56)nc(-c5cccc6ccccc56)n4)cc23)cc1 ; c1ccc(-c2nc(-c3ccc4c(c3)oc3ccccc34)nc(-c3ccc4c(-c5cccc6ccccc56)cc5ccccc5c4c3)n2)cc1 ; c1ccc(-c2cc3ccccc3c3cc(-c4nc(-c5ccc6ccccc6c5)nc(-c5ccc6c(c5)oc5ccccc56)n4)ccc23)cc1]

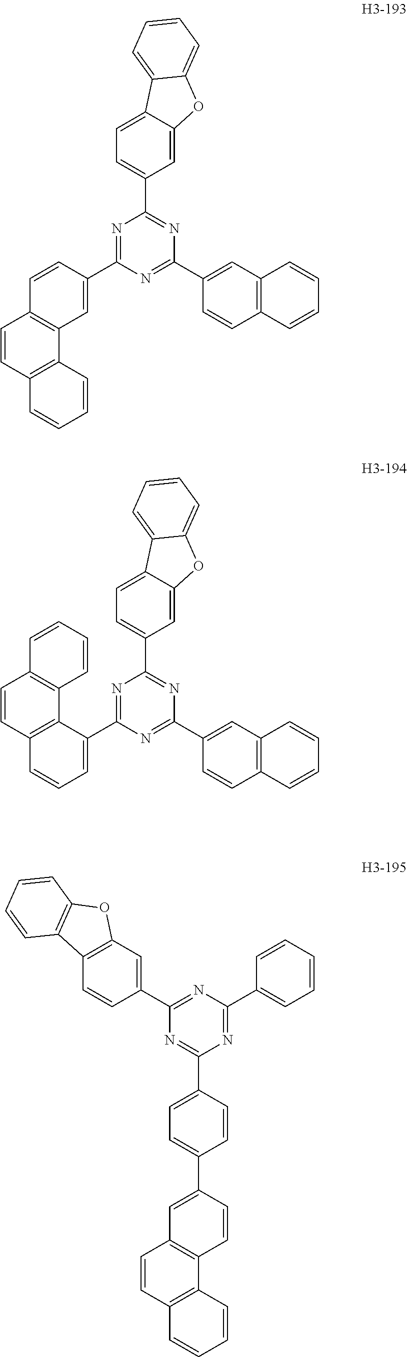 [SMILES: c1ccc2cc(-c3nc(-c4ccc5c(c4)oc4ccccc45)nc(-c4ccc5ccc6ccccc6c5c4)n3)ccc2c1 ; c1ccc2cc(-c3nc(-c4ccc5c(c4)oc4ccccc45)nc(-c4cccc5ccc6ccccc6c45)n3)ccc2c1 ; c1ccc(-c2nc(-c3ccc(-c4ccc5c(ccc6ccccc65)c4)cc3)nc(-c3ccc4c(c3)oc3ccccc34)n2)cc1]

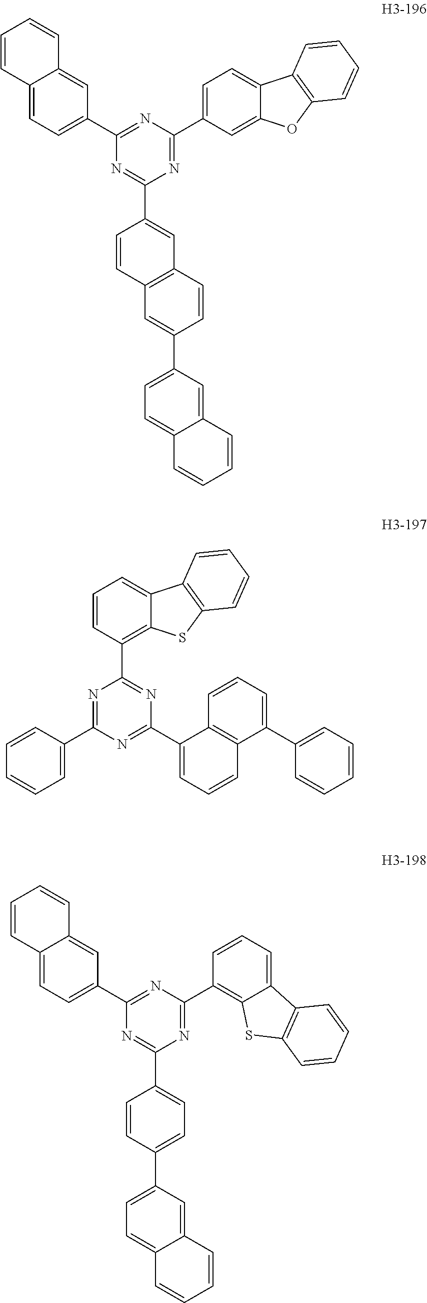 [SMILES: c1ccc2cc(-c3ccc4cc(-c5nc(-c6ccc7ccccc7c6)nc(-c6ccc7c(c6)oc6ccccc67)n5)ccc4c3)ccc2c1 ; c1ccc(-c2nc(-c3cccc4c(-c5ccccc5)cccc34)nc(-c3cccc4c3sc3ccccc34)n2)cc1 ; c1ccc2cc(-c3ccc(-c4nc(-c5ccc6ccccc6c5)nc(-c5cccc6c5sc5ccccc56)n4)cc3)ccc2c1]

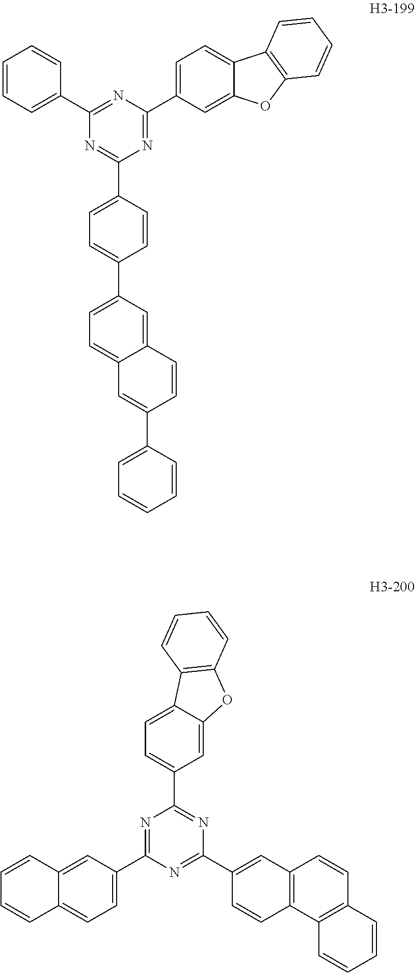 [SMILES: c1ccc(-c2ccc3cc(-c4ccc(-c5nc(-c6ccccc6)nc(-c6ccc7c(c6)oc6ccccc67)n5)cc4)ccc3c2)cc1 ; c1ccc2cc(-c3nc(-c4ccc5c(ccc6ccccc65)c4)nc(-c4ccc5c(c4)oc4ccccc45)n3)ccc2c1]

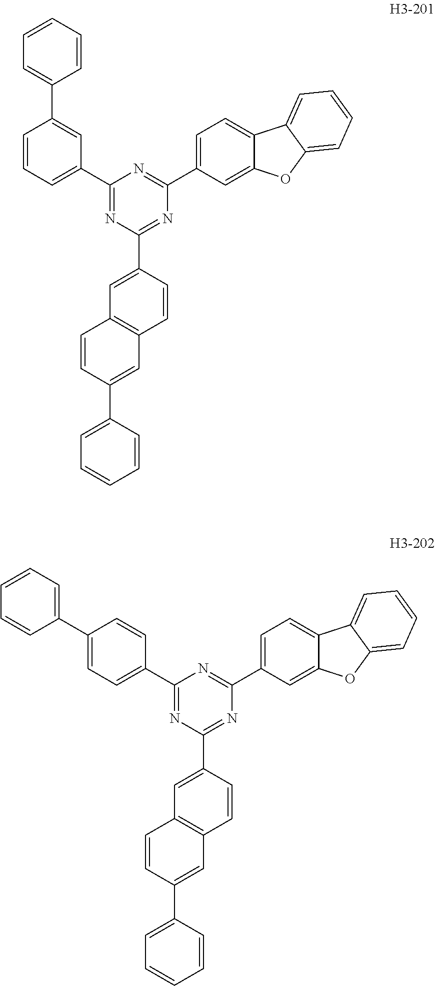 [SMILES: c1ccc(-c2cccc(-c3nc(-c4ccc5cc(-c6ccccc6)ccc5c4)nc(-c4ccc5c(c4)oc4ccccc45)n3)c2)cc1 ; c1ccc(-c2ccc(-c3nc(-c4ccc5cc(-c6ccccc6)ccc5c4)nc(-c4ccc5c(c4)oc4ccccc45)n3)cc2)cc1]

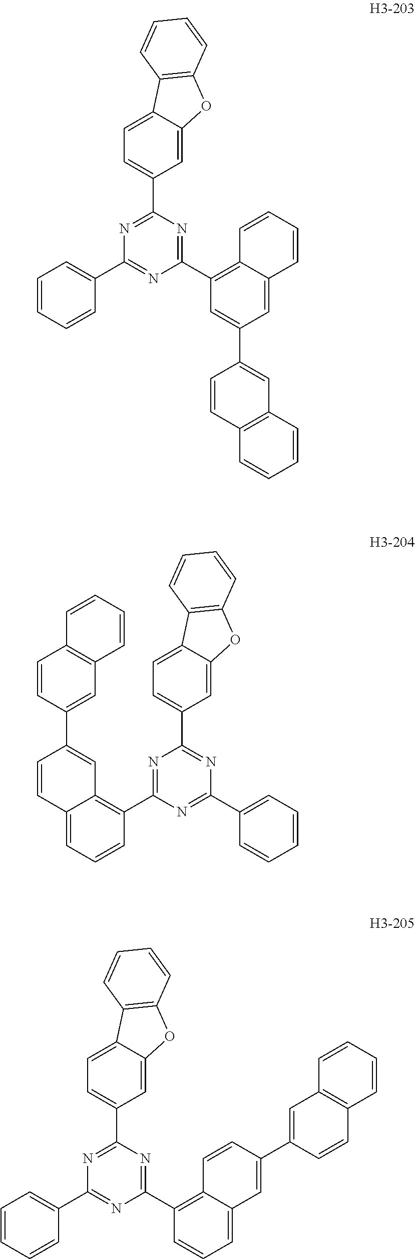 [SMILES: c1ccc(-c2nc(-c3ccc4c(c3)oc3ccccc34)nc(-c3cc(-c4ccc5ccccc5c4)cc4ccccc34)n2)cc1 ; c1ccc(-c2nc(-c3ccc4c(c3)oc3ccccc34)nc(-c3cccc4ccc(-c5ccc6ccccc6c5)cc34)n2)cc1 ; c1ccc(-c2nc(-c3ccc4c(c3)oc3ccccc34)nc(-c3cccc4cc(-c5ccc6ccccc6c5)ccc34)n2)cc1]

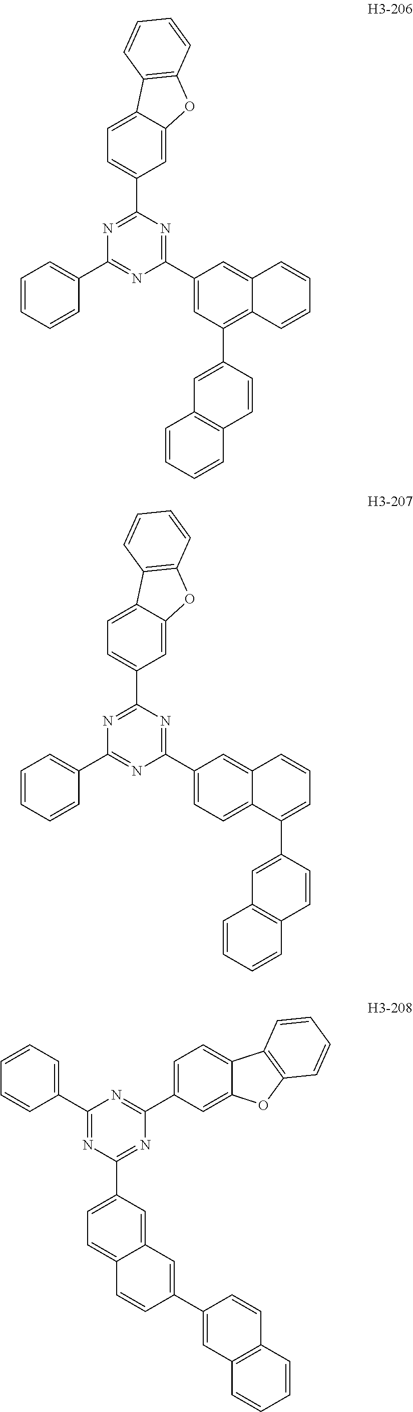

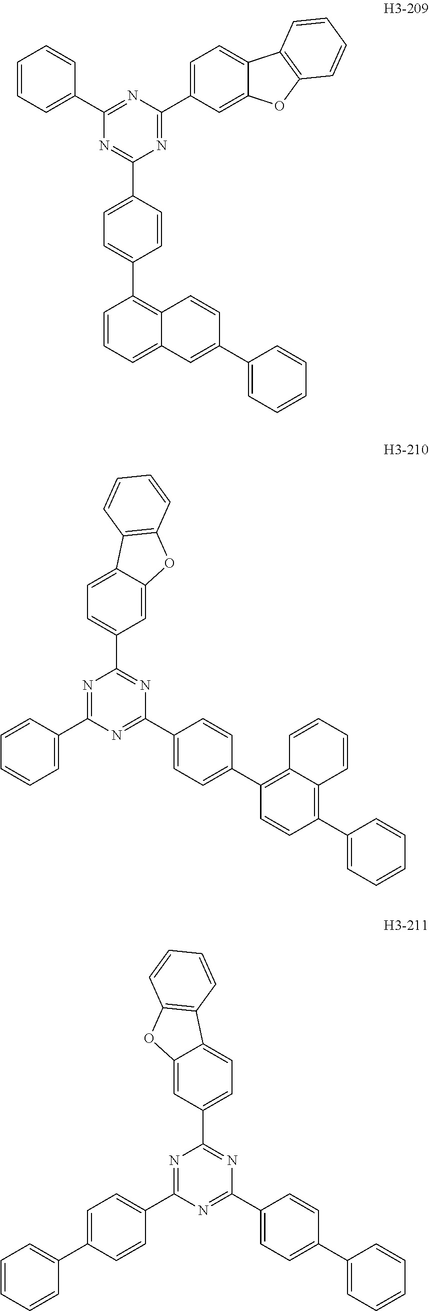 [SMILES: c1ccc(-c2ccc3c(-c4ccc(-c5nc(-c6ccccc6)nc(-c6ccc7c(c6)oc6ccccc67)n5)cc4)cccc3c2)cc1 ; c1ccc(-c2nc(-c3ccc(-c4ccc(-c5ccccc5)c5ccccc45)cc3)nc(-c3ccc4c(c3)oc3ccccc34)n2)cc1 ; c1ccc(-c2ccc(-c3nc(-c4ccc(-c5ccccc5)cc4)nc(-c4ccc5c(c4)oc4ccccc45)n3)cc2)cc1]

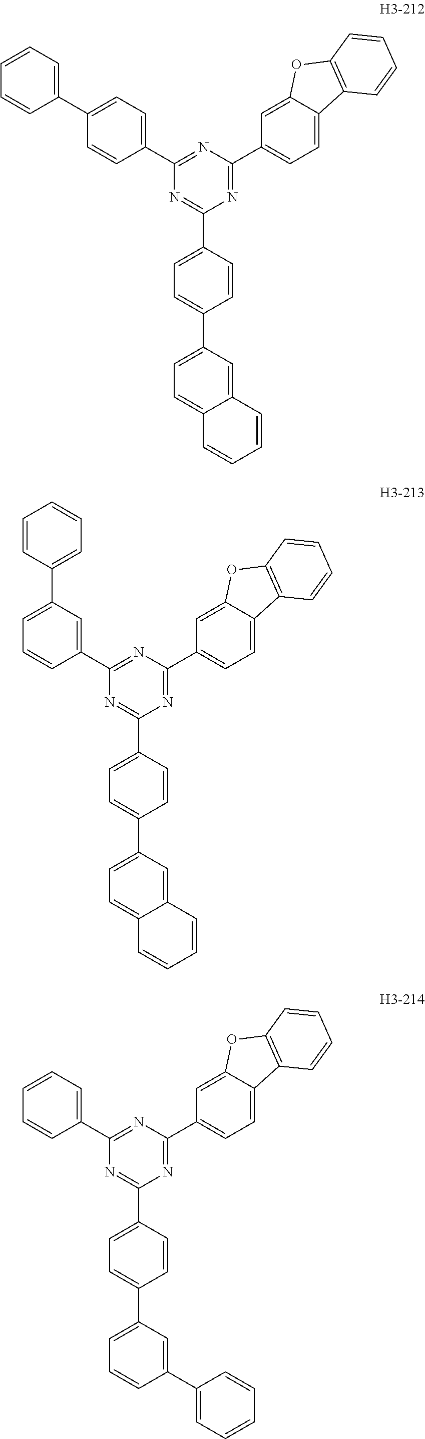 [SMILES: c1ccc(-c2ccc(-c3nc(-c4ccc(-c5ccc6ccccc6c5)cc4)nc(-c4ccc5c(c4)oc4ccccc45)n3)cc2)cc1 ; c1ccc(-c2cccc(-c3nc(-c4ccc(-c5ccc6ccccc6c5)cc4)nc(-c4ccc5c(c4)oc4ccccc45)n3)c2)cc1 ; c1ccc(-c2cccc(-c3ccc(-c4nc(-c5ccccc5)nc(-c5ccc6c(c5)oc5ccccc56)n4)cc3)c2)cc1]

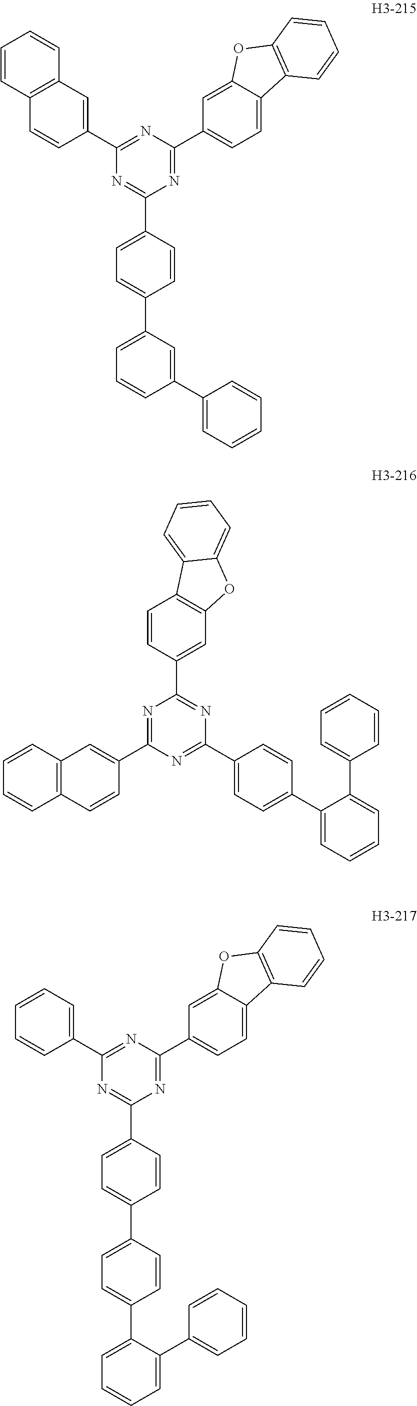 [SMILES: c1ccc(-c2cccc(-c3ccc(-c4nc(-c5ccc6ccccc6c5)nc(-c5ccc6c(c5)oc5ccccc56)n4)cc3)c2)cc1 ; c1ccc(-c2ccccc2-c2ccc(-c3nc(-c4ccc5ccccc5c4)nc(-c4ccc5c(c4)oc4ccccc45)n3)cc2)cc1 ; c1ccc(-c2nc(-c3ccc(-c4ccc(-c5ccccc5-c5ccccc5)cc4)cc3)nc(-c3ccc4c(c3)oc3ccccc34)n2)cc1]

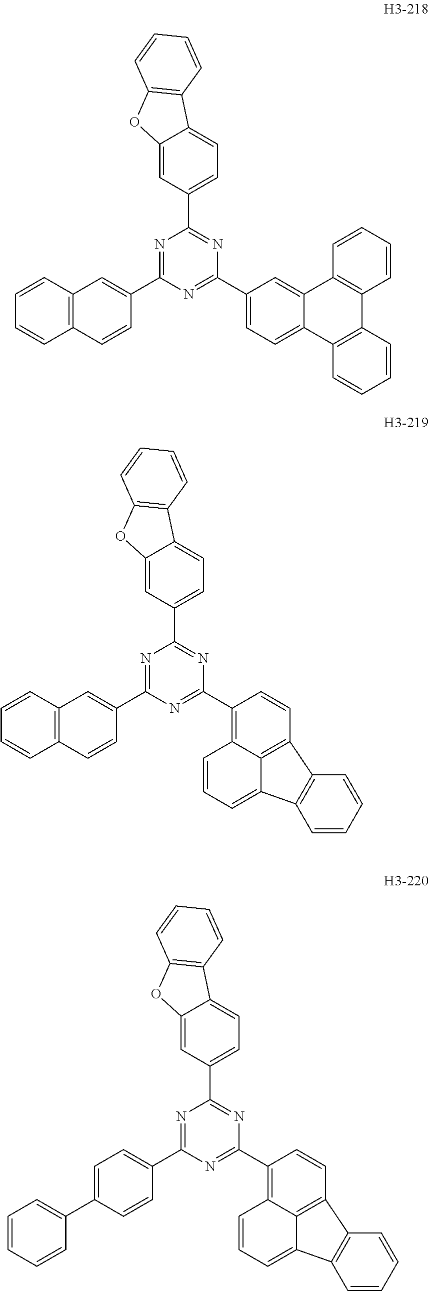 [SMILES: c1ccc2cc(-c3nc(-c4ccc5c(c4)oc4ccccc45)nc(-c4ccc5c6ccccc6c6ccccc6c5c4)n3)ccc2c1 ; c1ccc2c(c1)-c1cccc3c(-c4nc(-c5ccc6ccccc6c5)nc(-c5ccc6c(c5)oc5ccccc56)n4)ccc-2c13 ; c1ccc(-c2ccc(-c3nc(-c4ccc5c(c4)oc4ccccc45)nc(-c4ccc5c6c(cccc46)-c4ccccc4-5)n3)cc2)cc1]

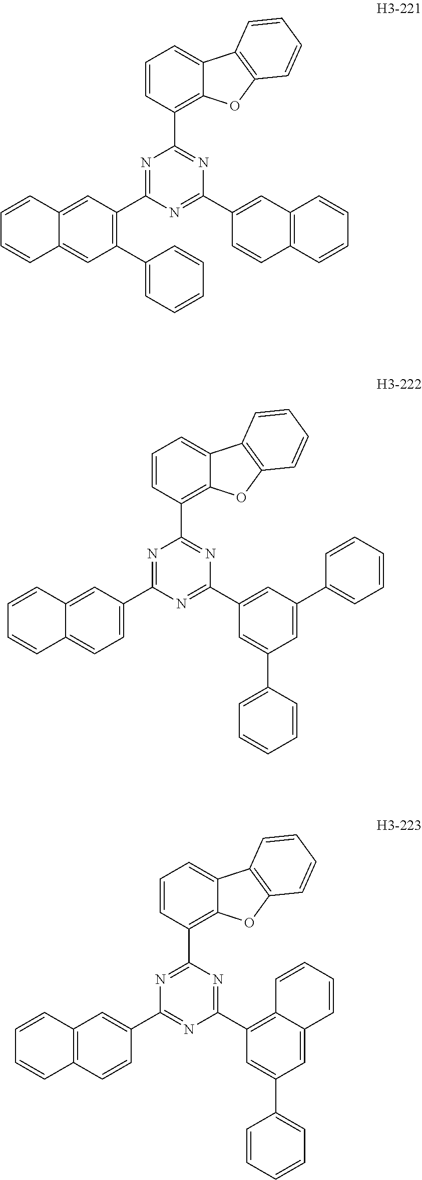 [SMILES: c1ccc(-c2cc3ccccc3cc2-c2nc(-c3ccc4ccccc4c3)nc(-c3cccc4c3oc3ccccc34)n2)cc1 ; c1ccc(-c2cc(-c3ccccc3)cc(-c3nc(-c4ccc5ccccc5c4)nc(-c4cccc5c4oc4ccccc45)n3)c2)cc1 ; c1ccc(-c2cc(-c3nc(-c4ccc5ccccc5c4)nc(-c4cccc5c4oc4ccccc45)n3)c3ccccc3c2)cc1]

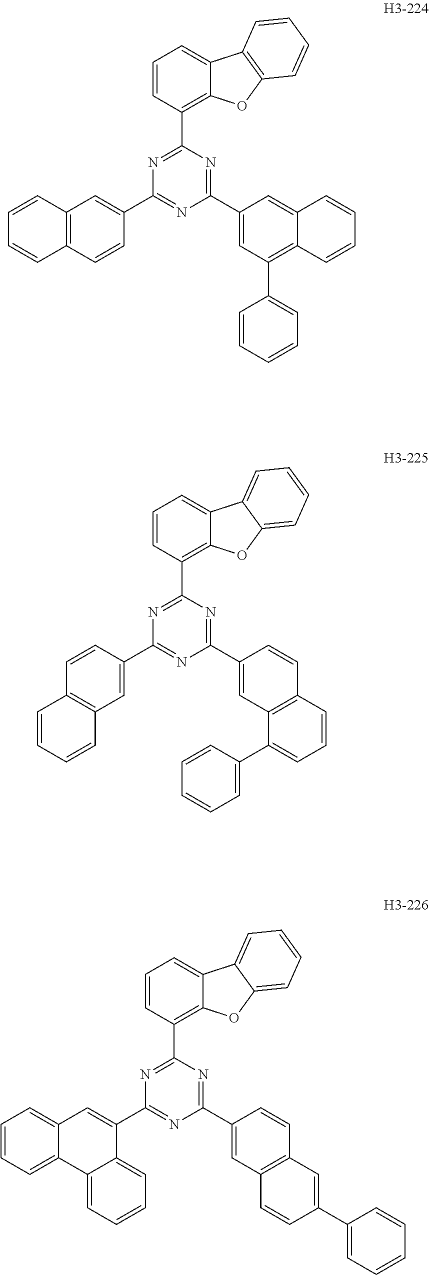 [SMILES: c1ccc(-c2cc(-c3nc(-c4ccc5ccccc5c4)nc(-c4cccc5c4oc4ccccc45)n3)cc3ccccc23)cc1 ; c1ccc(-c2cccc3ccc(-c4nc(-c5ccc6ccccc6c5)nc(-c5cccc6c5oc5ccccc56)n4)cc23)cc1 ; c1ccc(-c2ccc3cc(-c4nc(-c5cc6ccccc6c6ccccc56)nc(-c5cccc6c5oc5ccccc56)n4)ccc3c2)cc1]

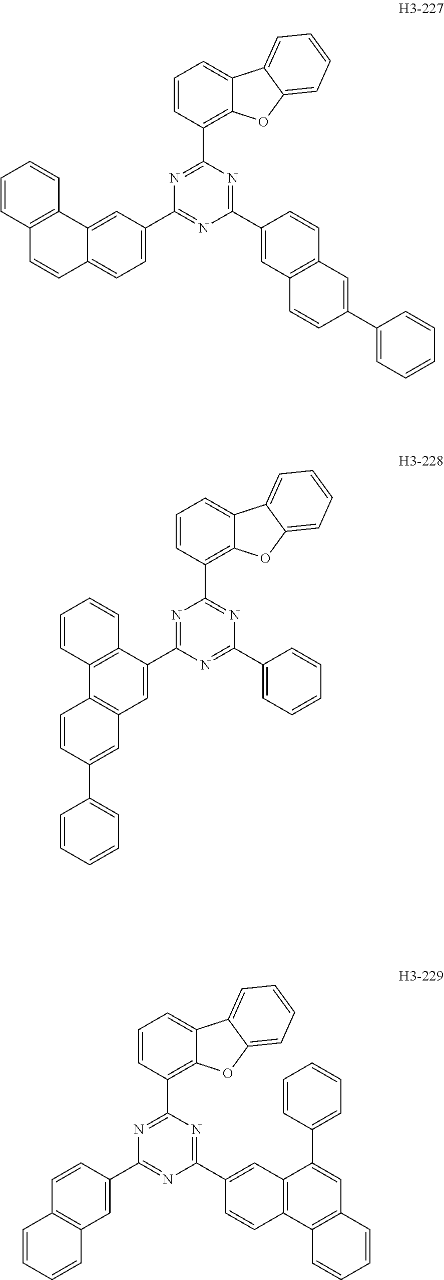 [SMILES: c1ccc(-c2ccc3cc(-c4nc(-c5ccc6ccc7ccccc7c6c5)nc(-c5cccc6c5oc5ccccc56)n4)ccc3c2)cc1 ; c1ccc(-c2ccc3c(c2)cc(-c2nc(-c4ccccc4)nc(-c4cccc5c4oc4ccccc45)n2)c2ccccc23)cc1 ; c1ccc(-c2cc3ccccc3c3ccc(-c4nc(-c5ccc6ccccc6c5)nc(-c5cccc6c5oc5ccccc56)n4)cc23)cc1]

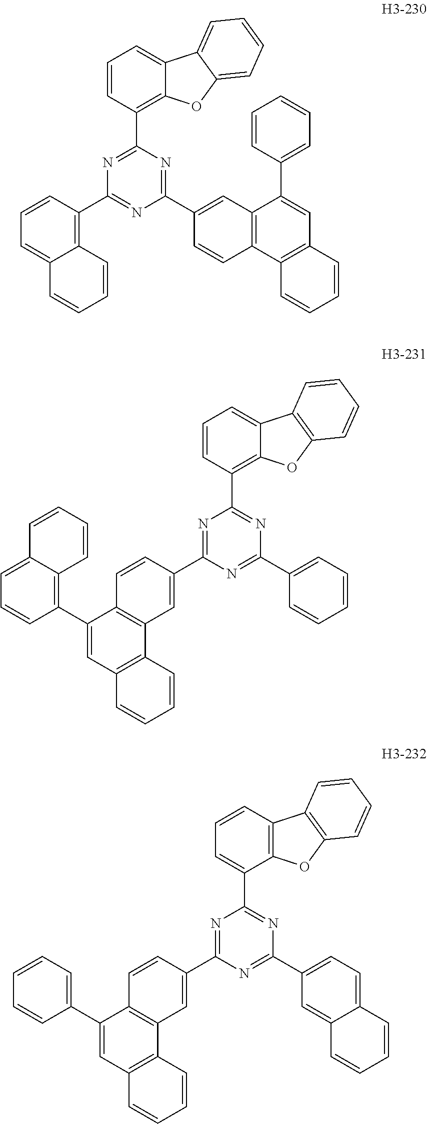 [SMILES: c1ccc(-c2cc3ccccc3c3ccc(-c4nc(-c5cccc6ccccc56)nc(-c5cccc6c5oc5ccccc56)n4)cc23)cc1 ; c1ccc(-c2nc(-c3ccc4c(-c5cccc6ccccc56)cc5ccccc5c4c3)nc(-c3cccc4c3oc3ccccc34)n2)cc1 ; c1ccc(-c2cc3ccccc3c3cc(-c4nc(-c5ccc6ccccc6c5)nc(-c5cccc6c5oc5ccccc56)n4)ccc23)cc1]

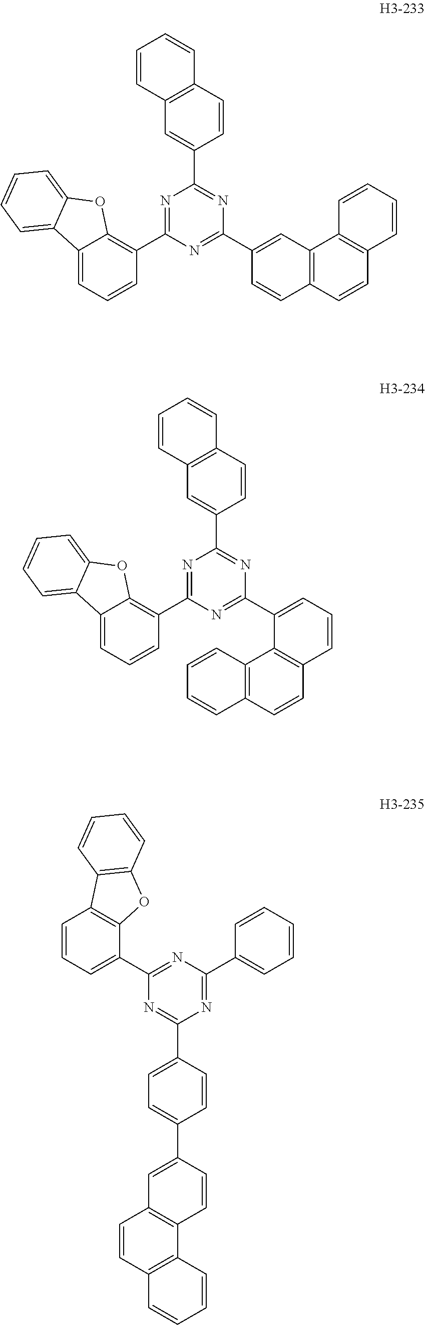 [SMILES: c1ccc2cc(-c3nc(-c4ccc5ccc6ccccc6c5c4)nc(-c4cccc5c4oc4ccccc45)n3)ccc2c1 ; c1ccc2cc(-c3nc(-c4cccc5c4oc4ccccc45)nc(-c4cccc5ccc6ccccc6c45)n3)ccc2c1 ; c1ccc(-c2nc(-c3ccc(-c4ccc5c(ccc6ccccc65)c4)cc3)nc(-c3cccc4c3oc3ccccc34)n2)cc1]

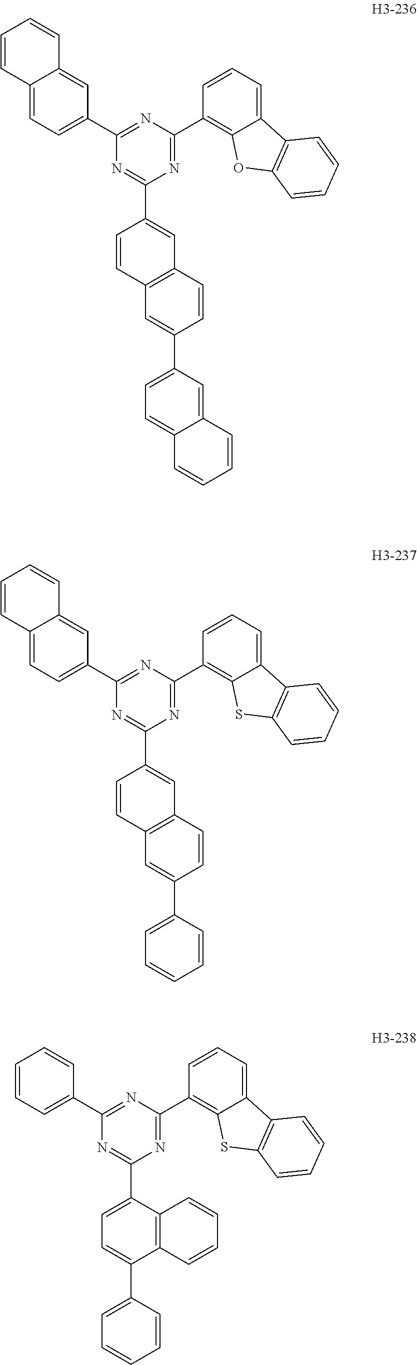 [SMILES: c1ccc2cc(-c3ccc4cc(-c5nc(-c6ccc7ccccc7c6)nc(-c6cccc7c6oc6ccccc67)n5)ccc4c3)ccc2c1 ; c1ccc(-c2ccc3cc(-c4nc(-c5ccc6ccccc6c5)nc(-c5cccc6c5sc5ccccc56)n4)ccc3c2)cc1 ; c1ccc(-c2nc(-c3ccc(-c4ccccc4)c4ccccc34)nc(-c3cccc4c3sc3ccccc34)n2)cc1]

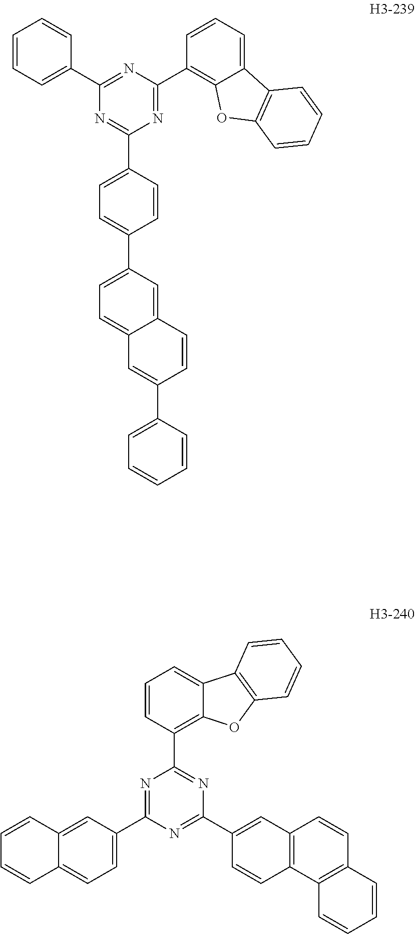 [SMILES: c1ccc(-c2ccc3cc(-c4ccc(-c5nc(-c6ccccc6)nc(-c6cccc7c6oc6ccccc67)n5)cc4)ccc3c2)cc1 ; c1ccc2cc(-c3nc(-c4ccc5c(ccc6ccccc65)c4)nc(-c4cccc5c4oc4ccccc45)n3)ccc2c1]

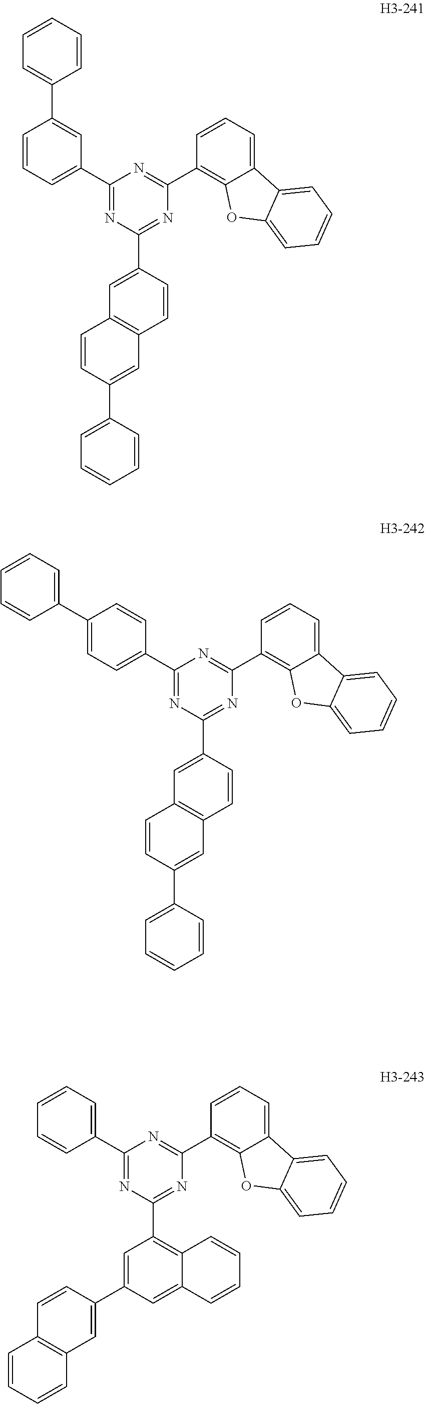 [SMILES: c1ccc(-c2cccc(-c3nc(-c4ccc5cc(-c6ccccc6)ccc5c4)nc(-c4cccc5c4oc4ccccc45)n3)c2)cc1 ; c1ccc(-c2ccc(-c3nc(-c4ccc5cc(-c6ccccc6)ccc5c4)nc(-c4cccc5c4oc4ccccc45)n3)cc2)cc1 ; c1ccc(-c2nc(-c3cc(-c4ccc5ccccc5c4)cc4ccccc34)nc(-c3cccc4c3oc3ccccc34)n2)cc1]

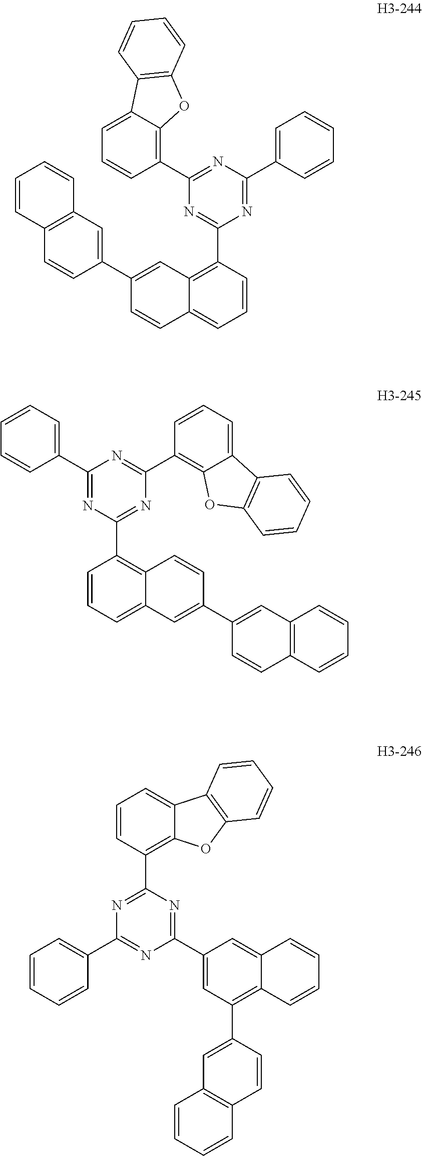 [SMILES: c1ccc(-c2nc(-c3cccc4ccc(-c5ccc6ccccc6c5)cc34)nc(-c3cccc4c3oc3ccccc34)n2)cc1 ; c1ccc(-c2nc(-c3cccc4cc(-c5ccc6ccccc6c5)ccc34)nc(-c3cccc4c3oc3ccccc34)n2)cc1 ; c1ccc(-c2nc(-c3cc(-c4ccc5ccccc5c4)c4ccccc4c3)nc(-c3cccc4c3oc3ccccc34)n2)cc1]

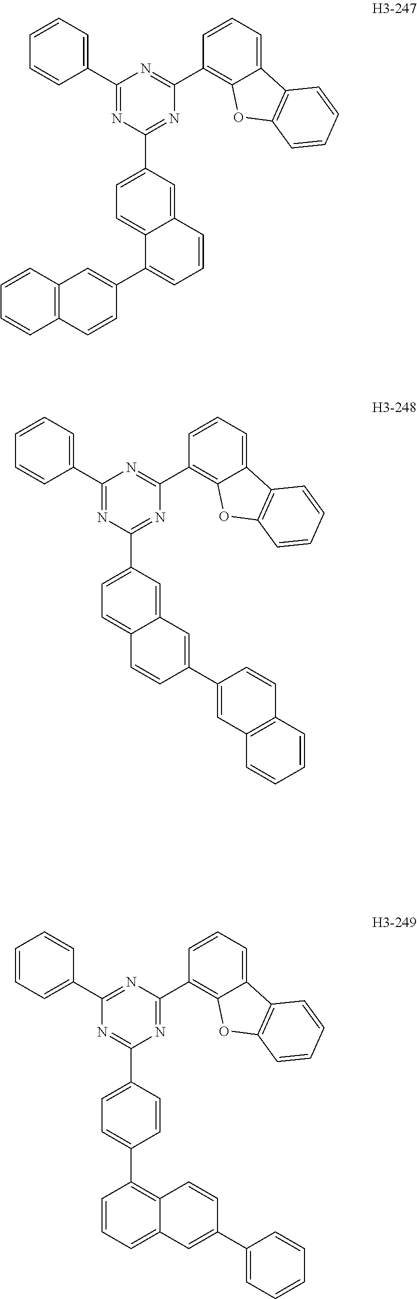 [SMILES: c1ccc(-c2nc(-c3ccc4c(-c5ccc6ccccc6c5)cccc4c3)nc(-c3cccc4c3oc3ccccc34)n2)cc1 ; c1ccc(-c2nc(-c3ccc4ccc(-c5ccc6ccccc6c5)cc4c3)nc(-c3cccc4c3oc3ccccc34)n2)cc1 ; c1ccc(-c2ccc3c(-c4ccc(-c5nc(-c6ccccc6)nc(-c6cccc7c6oc6ccccc67)n5)cc4)cccc3c2)cc1]

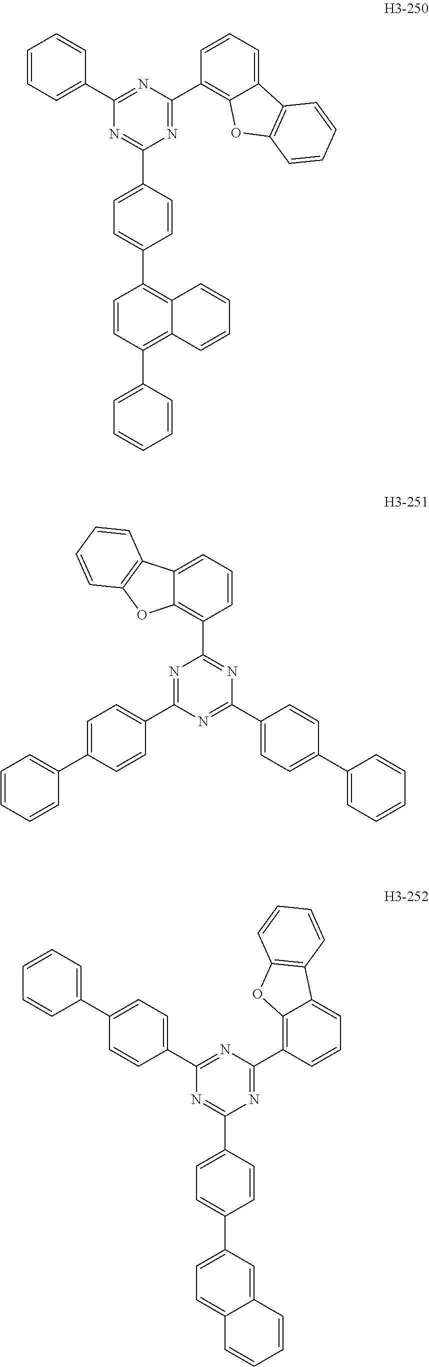 [SMILES: c1ccc(-c2nc(-c3ccc(-c4ccc(-c5ccccc5)c5ccccc45)cc3)nc(-c3cccc4c3oc3ccccc34)n2)cc1 ; c1ccc(-c2ccc(-c3nc(-c4ccc(-c5ccccc5)cc4)nc(-c4cccc5c4oc4ccccc45)n3)cc2)cc1 ; c1ccc(-c2ccc(-c3nc(-c4ccc(-c5ccc6ccccc6c5)cc4)nc(-c4cccc5c4oc4ccccc45)n3)cc2)cc1]

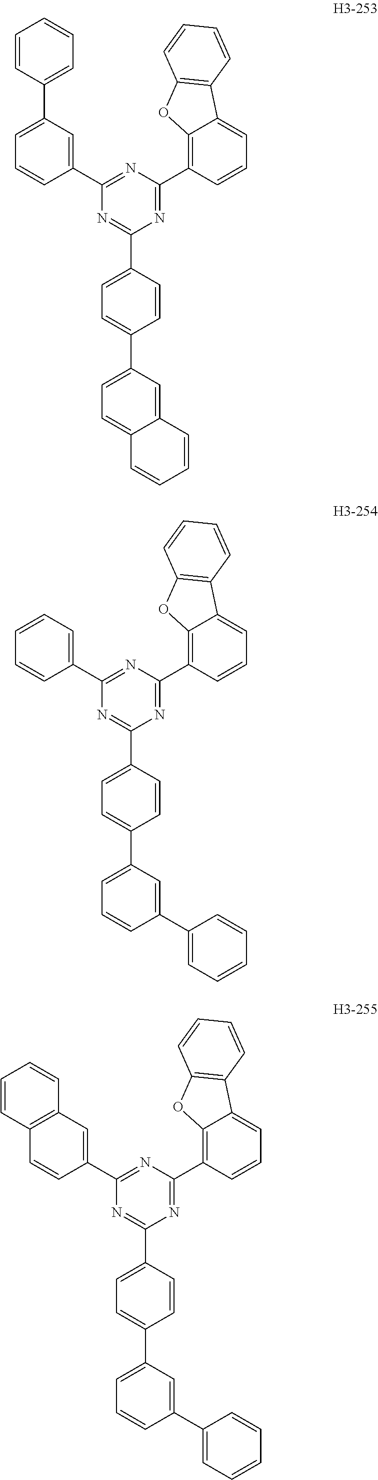

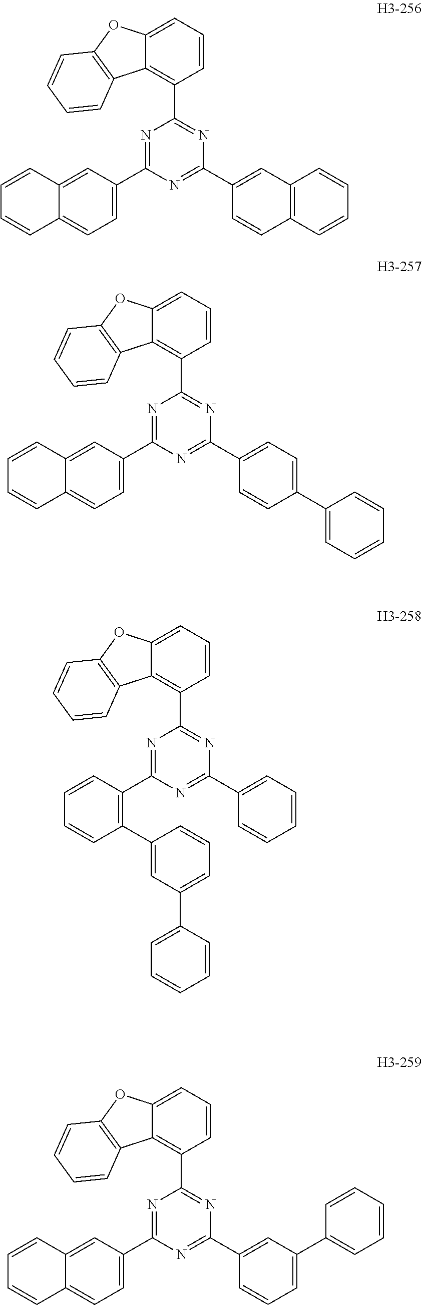 [SMILES: c1ccc2cc(-c3nc(-c4ccc5ccccc5c4)nc(-c4cccc5oc6ccccc6c45)n3)ccc2c1 ; c1ccc(-c2ccc(-c3nc(-c4ccc5ccccc5c4)nc(-c4cccc5oc6ccccc6c45)n3)cc2)cc1 ; c1ccc(-c2cccc(-c3ccccc3-c3nc(-c4ccccc4)nc(-c4cccc5oc6ccccc6c45)n3)c2)cc1 ; c1ccc(-c2cccc(-c3nc(-c4ccc5ccccc5c4)nc(-c4cccc5oc6ccccc6c45)n3)c2)cc1]

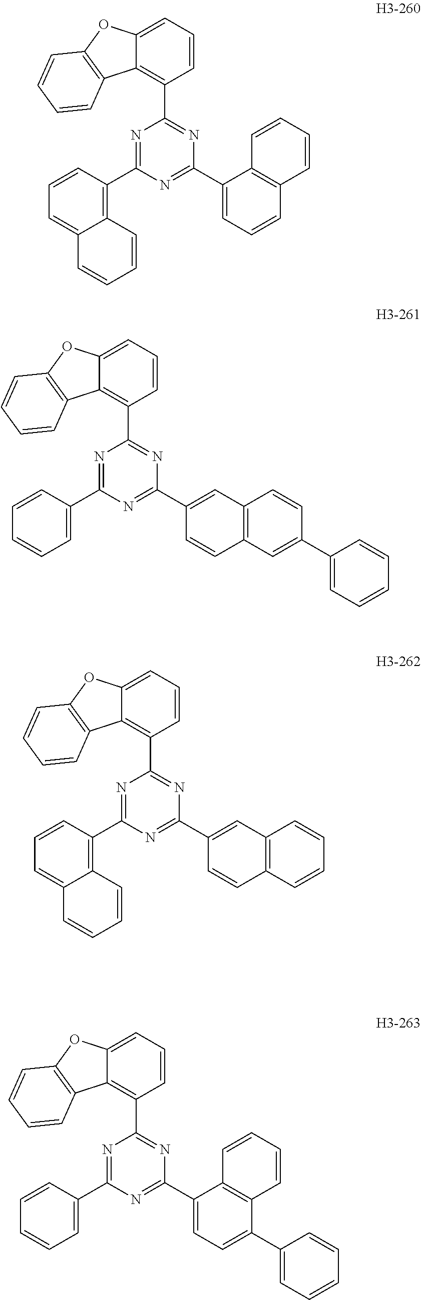 [SMILES: c1ccc2c(-c3nc(-c4cccc5ccccc45)nc(-c4cccc5oc6ccccc6c45)n3)cccc2c1 ; c1ccc(-c2ccc3cc(-c4nc(-c5ccccc5)nc(-c5cccc6oc7ccccc7c56)n4)ccc3c2)cc1 ; c1ccc2cc(-c3nc(-c4cccc5ccccc45)nc(-c4cccc5oc6ccccc6c45)n3)ccc2c1 ; c1ccc(-c2nc(-c3ccc(-c4ccccc4)c4ccccc34)nc(-c3cccc4oc5ccccc5c34)n2)cc1]

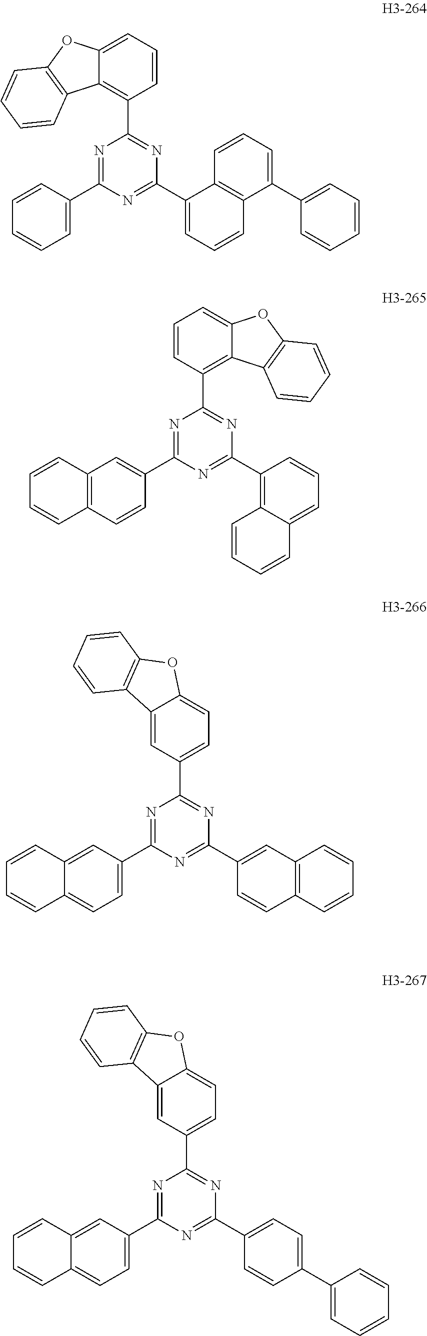 [SMILES: c1ccc(-c2nc(-c3cccc4c(-c5ccccc5)cccc34)nc(-c3cccc4oc5ccccc5c34)n2)cc1 ; c1ccc2cc(-c3nc(-c4cccc5ccccc45)nc(-c4cccc5oc6ccccc6c45)n3)ccc2c1 ; c1ccc2cc(-c3nc(-c4ccc5ccccc5c4)nc(-c4ccc5oc6ccccc6c5c4)n3)ccc2c1 ; c1ccc(-c2ccc(-c3nc(-c4ccc5ccccc5c4)nc(-c4ccc5oc6ccccc6c5c4)n3)cc2)cc1]

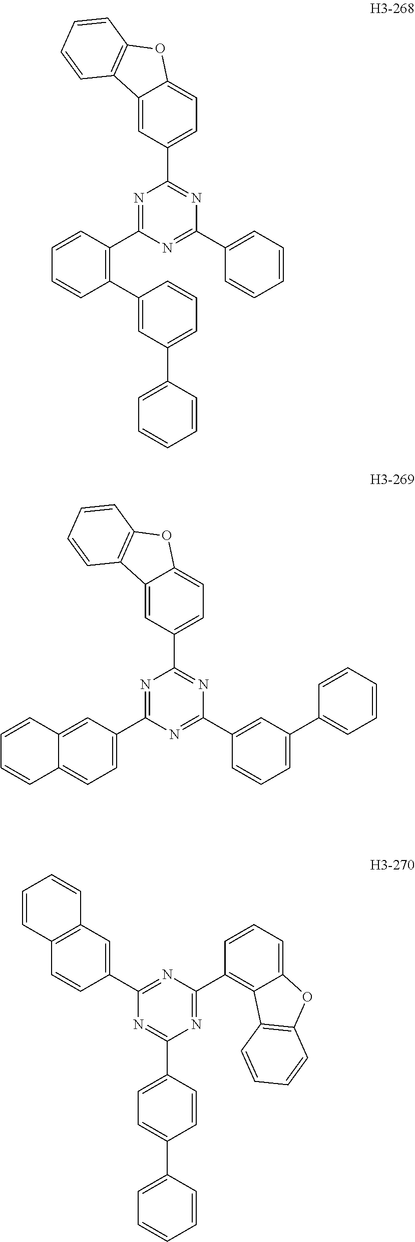 [SMILES: c1ccc(-c2cccc(-c3ccccc3-c3nc(-c4ccccc4)nc(-c4ccc5oc6ccccc6c5c4)n3)c2)cc1 ; c1ccc(-c2cccc(-c3nc(-c4ccc5ccccc5c4)nc(-c4ccc5oc6ccccc6c5c4)n3)c2)cc1 ; c1ccc(-c2ccc(-c3nc(-c4ccc5ccccc5c4)nc(-c4cccc5oc6ccccc6c45)n3)cc2)cc1]

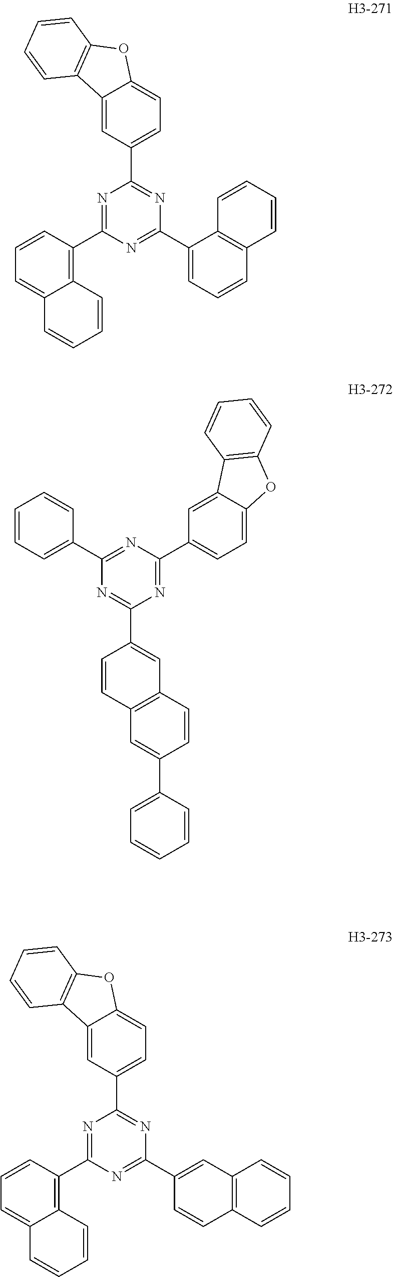 [SMILES: c1ccc2c(-c3nc(-c4ccc5oc6ccccc6c5c4)nc(-c4cccc5ccccc45)n3)cccc2c1 ; c1ccc(-c2ccc3cc(-c4nc(-c5ccccc5)nc(-c5ccc6oc7ccccc7c6c5)n4)ccc3c2)cc1 ; c1ccc2cc(-c3nc(-c4ccc5oc6ccccc6c5c4)nc(-c4cccc5ccccc45)n3)ccc2c1]

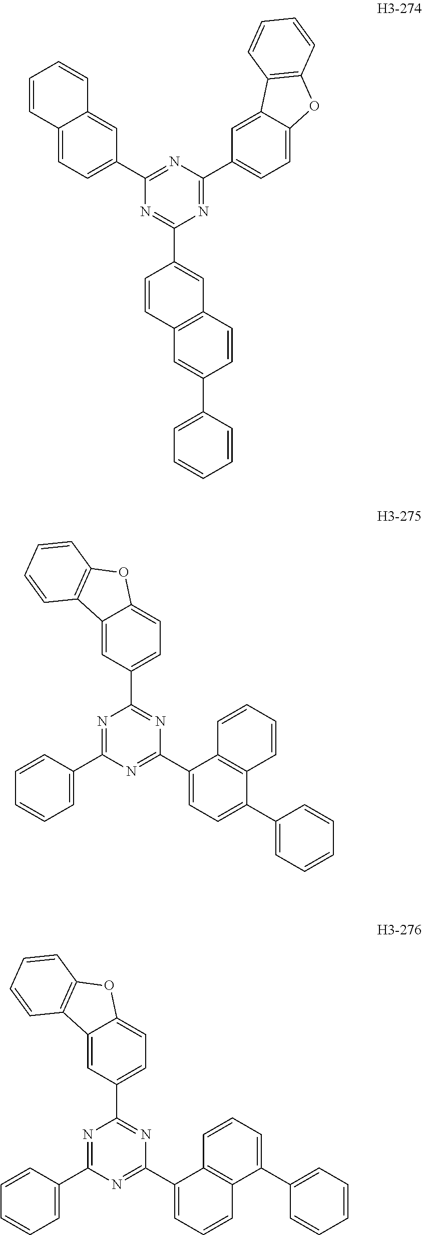 [SMILES: c1ccc(-c2ccc3cc(-c4nc(-c5ccc6ccccc6c5)nc(-c5ccc6oc7ccccc7c6c5)n4)ccc3c2)cc1 ; c1ccc(-c2nc(-c3ccc4oc5ccccc5c4c3)nc(-c3ccc(-c4ccccc4)c4ccccc34)n2)cc1 ; c1ccc(-c2nc(-c3ccc4oc5ccccc5c4c3)nc(-c3cccc4c(-c5ccccc5)cccc34)n2)cc1]

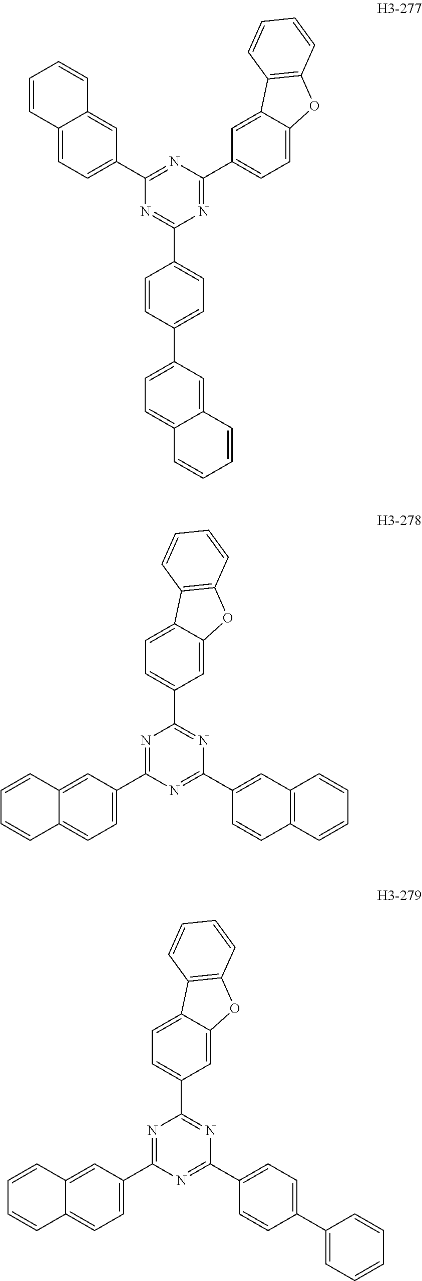 [SMILES: c1ccc2cc(-c3ccc(-c4nc(-c5ccc6ccccc6c5)nc(-c5ccc6oc7ccccc7c6c5)n4)cc3)ccc2c1 ; c1ccc2cc(-c3nc(-c4ccc5ccccc5c4)nc(-c4ccc5c(c4)oc4ccccc45)n3)ccc2c1 ; c1ccc(-c2ccc(-c3nc(-c4ccc5ccccc5c4)nc(-c4ccc5c(c4)oc4ccccc45)n3)cc2)cc1]

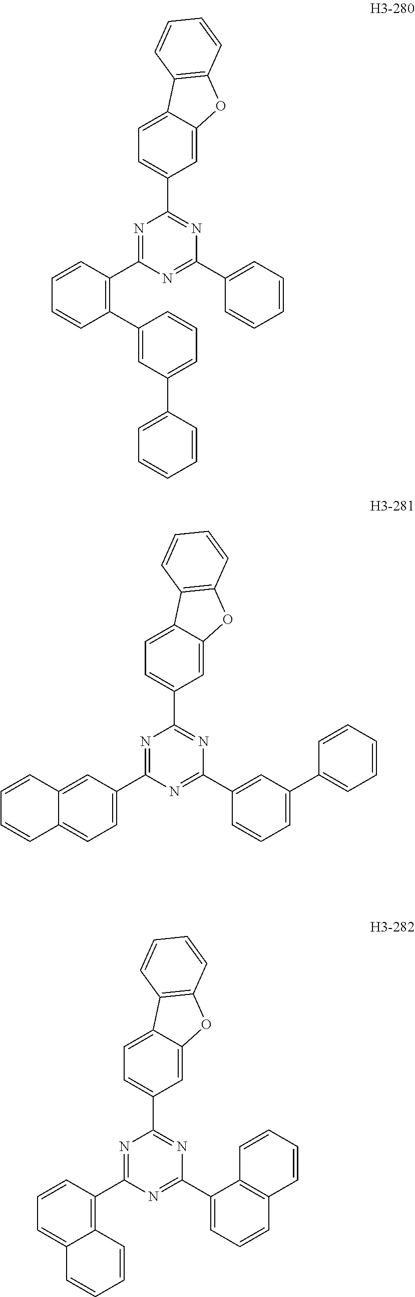 [SMILES: c1ccc(-c2cccc(-c3ccccc3-c3nc(-c4ccccc4)nc(-c4ccc5c(c4)oc4ccccc45)n3)c2)cc1 ; c1ccc(-c2cccc(-c3nc(-c4ccc5ccccc5c4)nc(-c4ccc5c(c4)oc4ccccc45)n3)c2)cc1 ; c1ccc2c(-c3nc(-c4ccc5c(c4)oc4ccccc45)nc(-c4cccc5ccccc45)n3)cccc2c1]

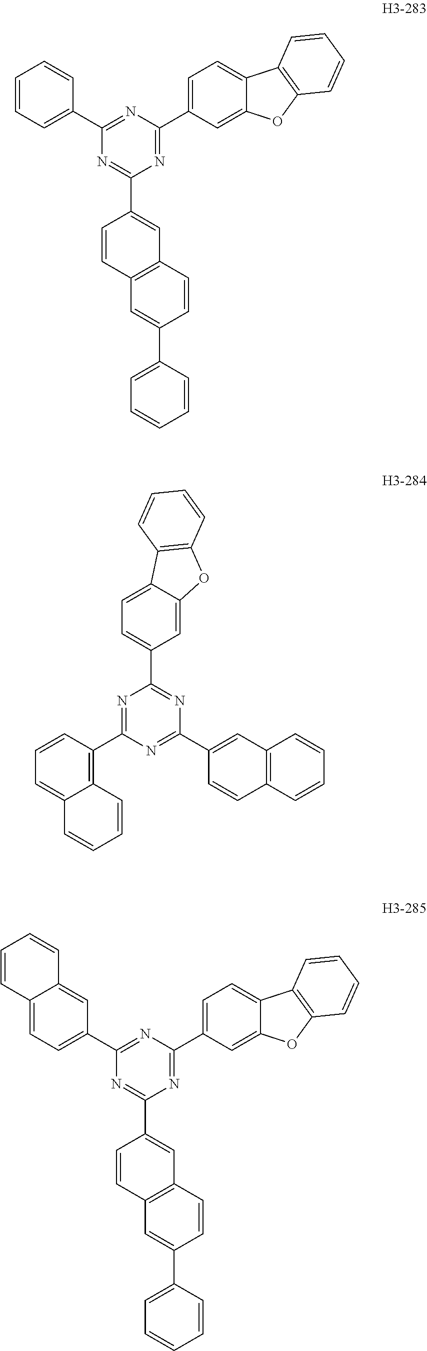 [SMILES: c1ccc(-c2ccc3cc(-c4nc(-c5ccccc5)nc(-c5ccc6c(c5)oc5ccccc56)n4)ccc3c2)cc1 ; c1ccc2cc(-c3nc(-c4ccc5c(c4)oc4ccccc45)nc(-c4cccc5ccccc45)n3)ccc2c1 ; c1ccc(-c2ccc3cc(-c4nc(-c5ccc6ccccc6c5)nc(-c5ccc6c(c5)oc5ccccc56)n4)ccc3c2)cc1]

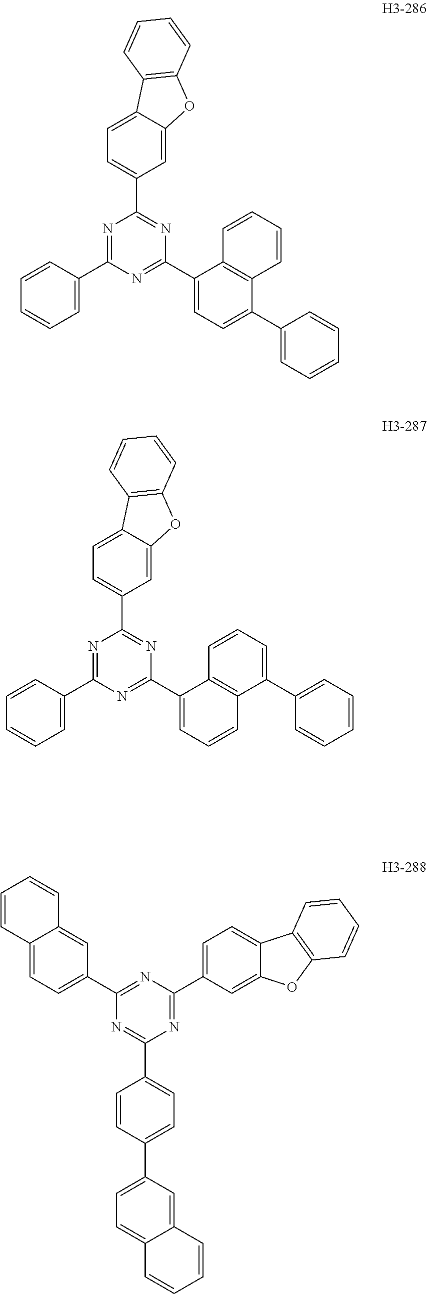 [SMILES: c1ccc(-c2nc(-c3ccc4c(c3)oc3ccccc34)nc(-c3ccc(-c4ccccc4)c4ccccc34)n2)cc1 ; c1ccc(-c2nc(-c3ccc4c(c3)oc3ccccc34)nc(-c3cccc4c(-c5ccccc5)cccc34)n2)cc1 ; c1ccc2cc(-c3ccc(-c4nc(-c5ccc6ccccc6c5)nc(-c5ccc6c(c5)oc5ccccc56)n4)cc3)ccc2c1]

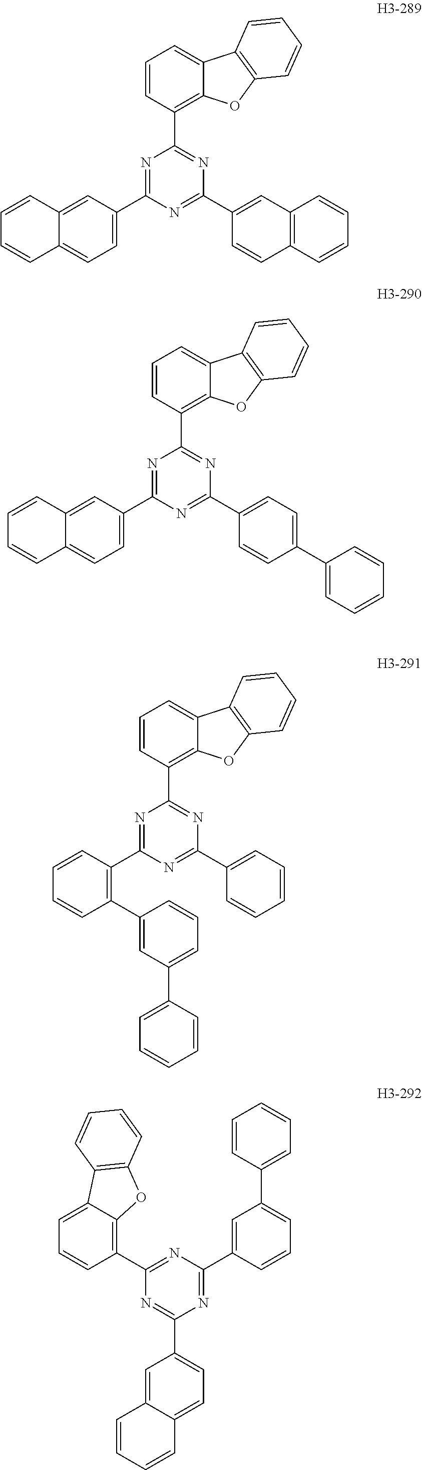 [SMILES: c1ccc2cc(-c3nc(-c4ccc5ccccc5c4)nc(-c4cccc5c4oc4ccccc45)n3)ccc2c1 ; c1ccc(-c2ccc(-c3nc(-c4ccc5ccccc5c4)nc(-c4cccc5c4oc4ccccc45)n3)cc2)cc1 ; c1ccc(-c2cccc(-c3ccccc3-c3nc(-c4ccccc4)nc(-c4cccc5c4oc4ccccc45)n3)c2)cc1 ; c1ccc(-c2cccc(-c3nc(-c4ccc5ccccc5c4)nc(-c4cccc5c4oc4ccccc45)n3)c2)cc1]

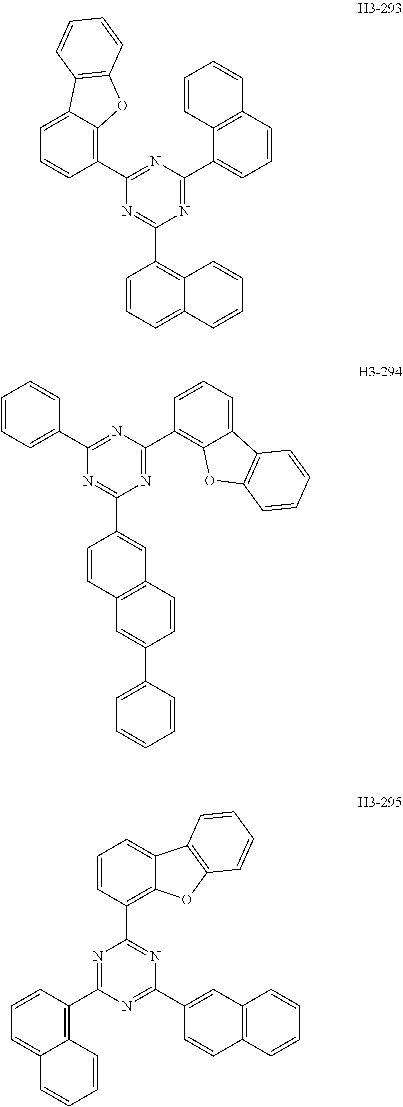 [SMILES: c1ccc2c(-c3nc(-c4cccc5ccccc45)nc(-c4cccc5c4oc4ccccc45)n3)cccc2c1 ; c1ccc(-c2ccc3cc(-c4nc(-c5ccccc5)nc(-c5cccc6c5oc5ccccc56)n4)ccc3c2)cc1 ; c1ccc2cc(-c3nc(-c4cccc5ccccc45)nc(-c4cccc5c4oc4ccccc45)n3)ccc2c1]

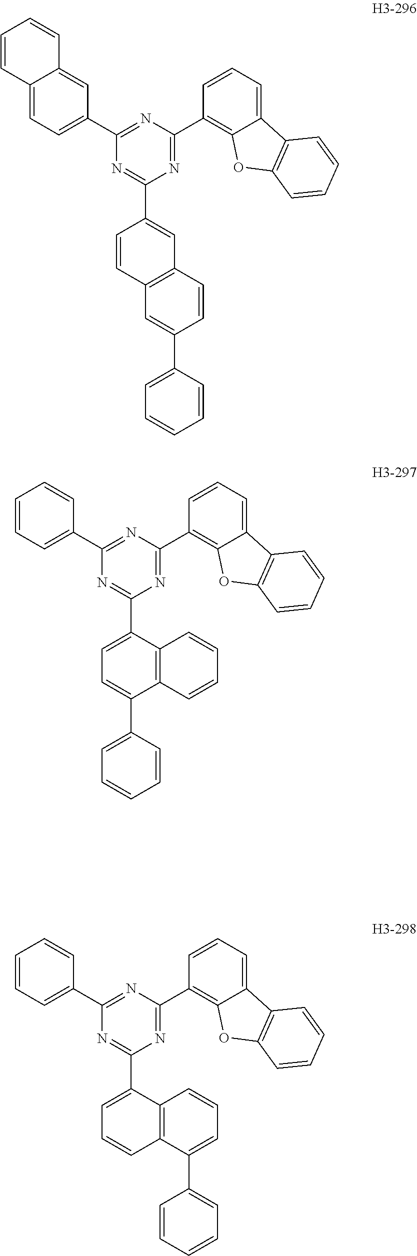 [SMILES: c1ccc(-c2ccc3cc(-c4nc(-c5ccc6ccccc6c5)nc(-c5cccc6c5oc5ccccc56)n4)ccc3c2)cc1 ; c1ccc(-c2nc(-c3ccc(-c4ccccc4)c4ccccc34)nc(-c3cccc4c3oc3ccccc34)n2)cc1 ; c1ccc(-c2nc(-c3cccc4c(-c5ccccc5)cccc34)nc(-c3cccc4c3oc3ccccc34)n2)cc1]

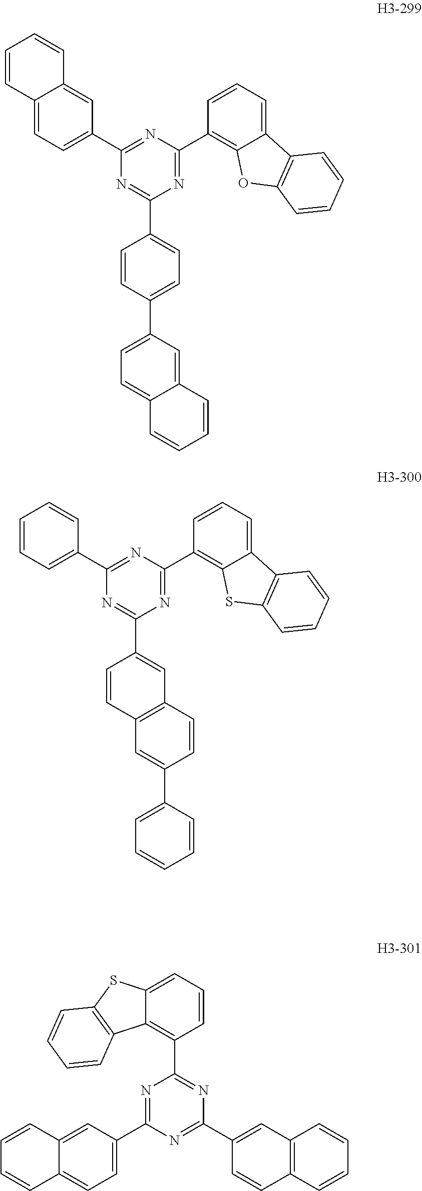 [SMILES: c1ccc2cc(-c3ccc(-c4nc(-c5ccc6ccccc6c5)nc(-c5cccc6c5oc5ccccc56)n4)cc3)ccc2c1 ; c1ccc(-c2ccc3cc(-c4nc(-c5ccccc5)nc(-c5cccc6c5sc5ccccc56)n4)ccc3c2)cc1 ; c1ccc2cc(-c3nc(-c4ccc5ccccc5c4)nc(-c4cccc5sc6ccccc6c45)n3)ccc2c1]

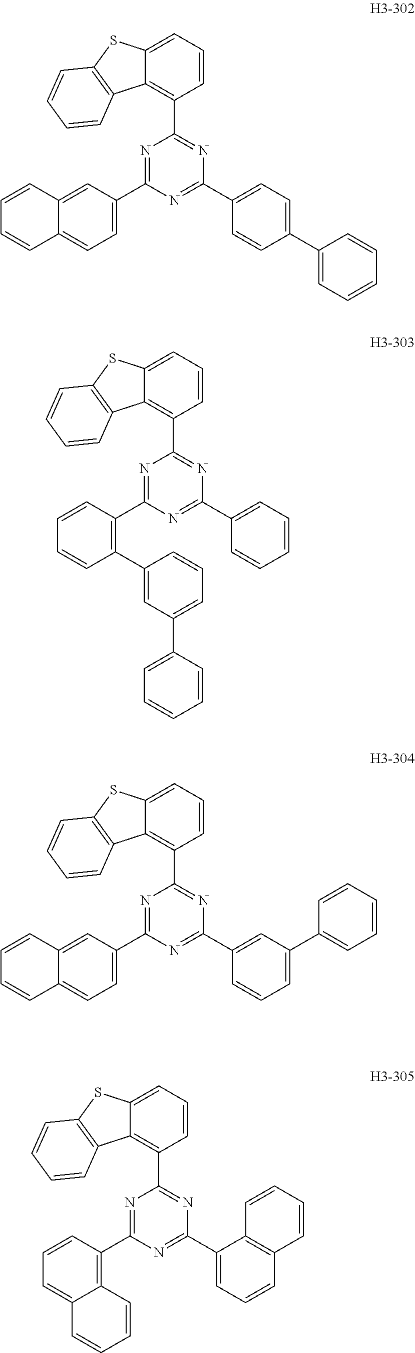 [SMILES: c1ccc(-c2ccc(-c3nc(-c4ccc5ccccc5c4)nc(-c4cccc5sc6ccccc6c45)n3)cc2)cc1 ; c1ccc(-c2cccc(-c3ccccc3-c3nc(-c4ccccc4)nc(-c4cccc5sc6ccccc6c45)n3)c2)cc1 ; c1ccc(-c2cccc(-c3nc(-c4ccc5ccccc5c4)nc(-c4cccc5sc6ccccc6c45)n3)c2)cc1 ; c1ccc2c(-c3nc(-c4cccc5ccccc45)nc(-c4cccc5sc6ccccc6c45)n3)cccc2c1]

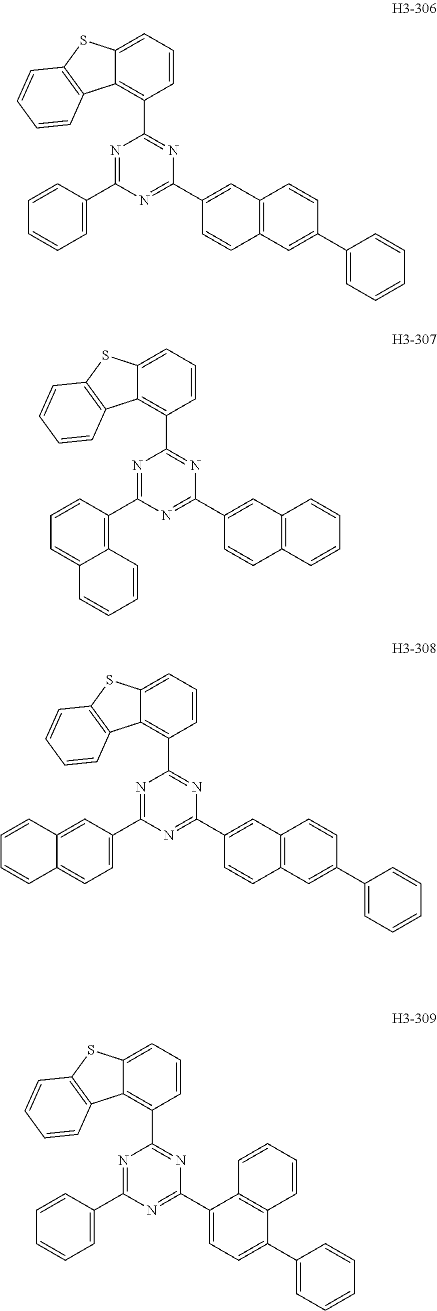 [SMILES: c1ccc(-c2ccc3cc(-c4nc(-c5ccccc5)nc(-c5cccc6sc7ccccc7c56)n4)ccc3c2)cc1 ; c1ccc2cc(-c3nc(-c4cccc5ccccc45)nc(-c4cccc5sc6ccccc6c45)n3)ccc2c1 ; c1ccc(-c2ccc3cc(-c4nc(-c5ccc6ccccc6c5)nc(-c5cccc6sc7ccccc7c56)n4)ccc3c2)cc1 ; c1ccc(-c2nc(-c3ccc(-c4ccccc4)c4ccccc34)nc(-c3cccc4sc5ccccc5c34)n2)cc1]

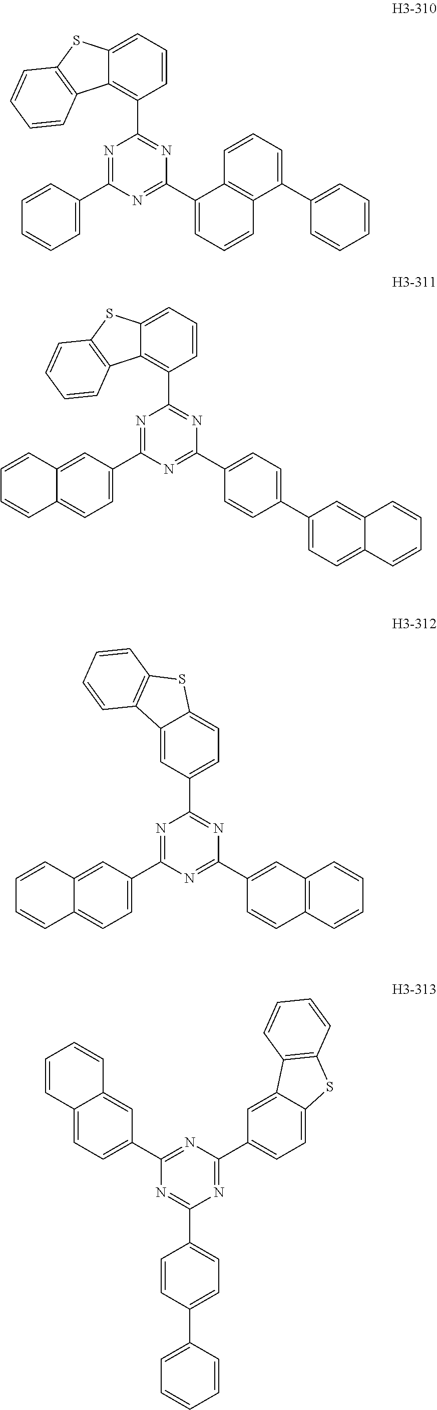 [SMILES: c1ccc(-c2nc(-c3cccc4c(-c5ccccc5)cccc34)nc(-c3cccc4sc5ccccc5c34)n2)cc1 ; c1ccc2cc(-c3ccc(-c4nc(-c5ccc6ccccc6c5)nc(-c5cccc6sc7ccccc7c56)n4)cc3)ccc2c1 ; c1ccc2cc(-c3nc(-c4ccc5ccccc5c4)nc(-c4ccc5sc6ccccc6c5c4)n3)ccc2c1 ; c1ccc(-c2ccc(-c3nc(-c4ccc5ccccc5c4)nc(-c4ccc5sc6ccccc6c5c4)n3)cc2)cc1]

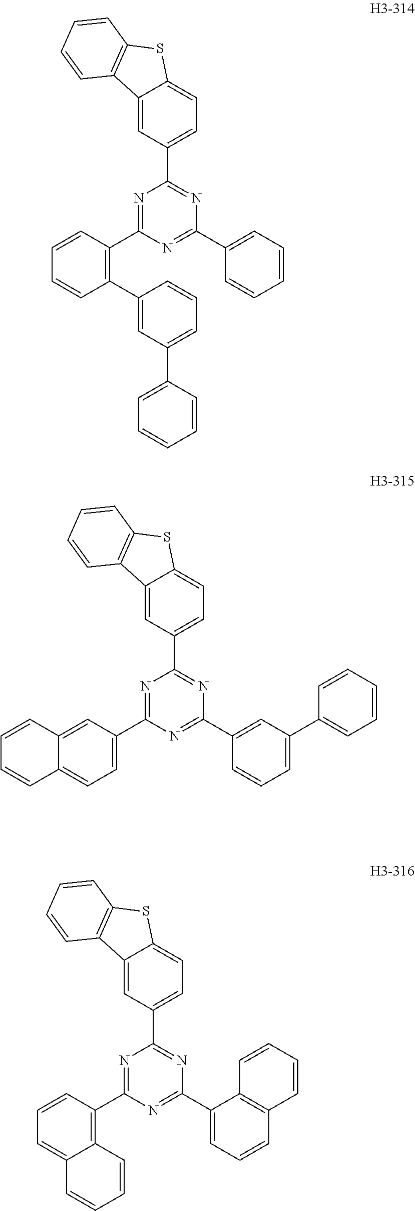 [SMILES: c1ccc(-c2cccc(-c3ccccc3-c3nc(-c4ccccc4)nc(-c4ccc5sc6ccccc6c5c4)n3)c2)cc1 ; c1ccc(-c2cccc(-c3nc(-c4ccc5ccccc5c4)nc(-c4ccc5sc6ccccc6c5c4)n3)c2)cc1 ; c1ccc2c(-c3nc(-c4ccc5sc6ccccc6c5c4)nc(-c4cccc5ccccc45)n3)cccc2c1]

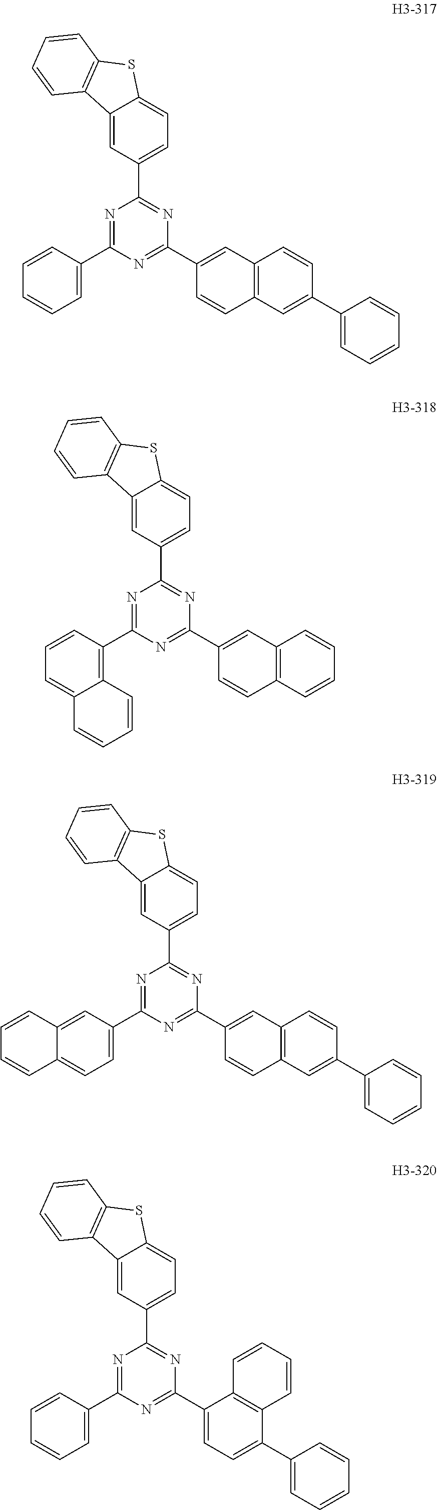 [SMILES: c1ccc(-c2ccc3cc(-c4nc(-c5ccccc5)nc(-c5ccc6sc7ccccc7c6c5)n4)ccc3c2)cc1 ; c1ccc2cc(-c3nc(-c4ccc5sc6ccccc6c5c4)nc(-c4cccc5ccccc45)n3)ccc2c1 ; c1ccc(-c2ccc3cc(-c4nc(-c5ccc6ccccc6c5)nc(-c5ccc6sc7ccccc7c6c5)n4)ccc3c2)cc1 ; c1ccc(-c2nc(-c3ccc4sc5ccccc5c4c3)nc(-c3ccc(-c4ccccc4)c4ccccc34)n2)cc1]

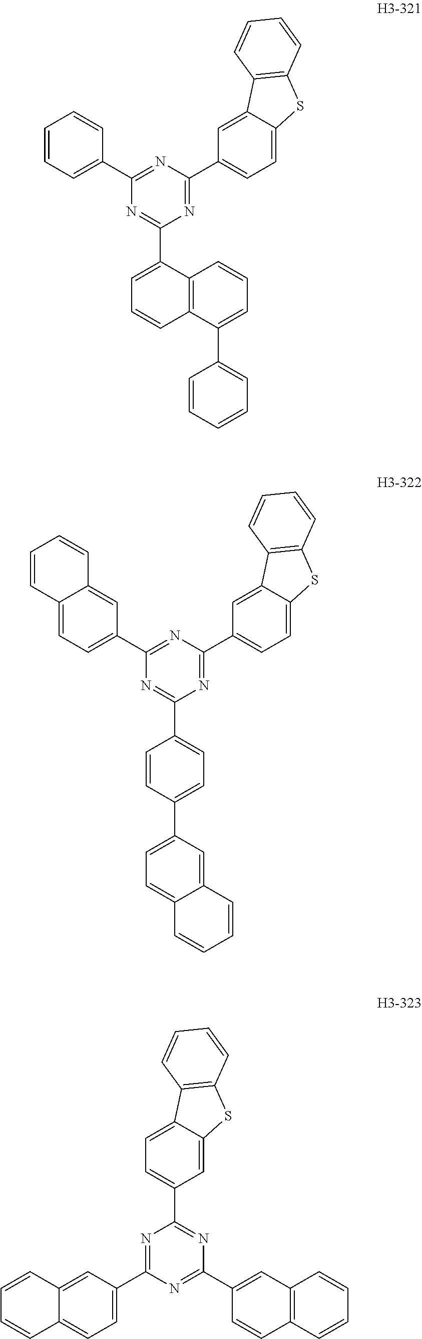 [SMILES: c1ccc(-c2nc(-c3ccc4sc5ccccc5c4c3)nc(-c3cccc4c(-c5ccccc5)cccc34)n2)cc1 ; c1ccc2cc(-c3ccc(-c4nc(-c5ccc6ccccc6c5)nc(-c5ccc6sc7ccccc7c6c5)n4)cc3)ccc2c1 ; c1ccc2cc(-c3nc(-c4ccc5ccccc5c4)nc(-c4ccc5c(c4)sc4ccccc45)n3)ccc2c1]

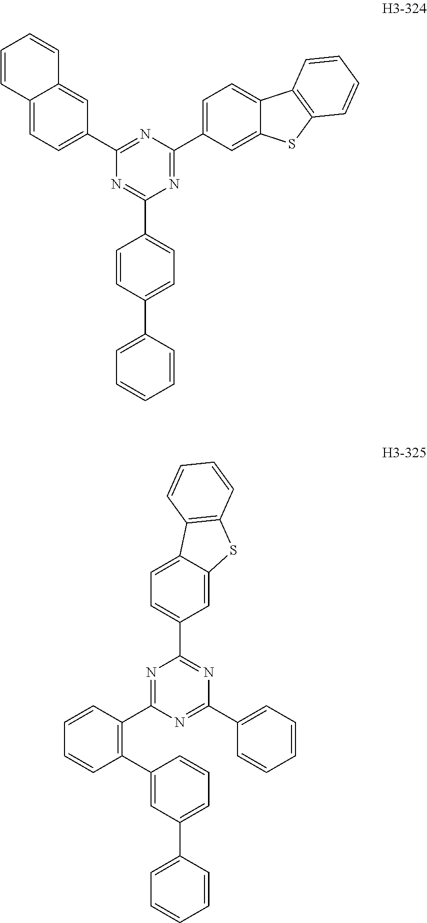 [SMILES: c1ccc(-c2ccc(-c3nc(-c4ccc5ccccc5c4)nc(-c4ccc5c(c4)sc4ccccc45)n3)cc2)cc1 ; c1ccc(-c2cccc(-c3ccccc3-c3nc(-c4ccccc4)nc(-c4ccc5c(c4)sc4ccccc45)n3)c2)cc1]

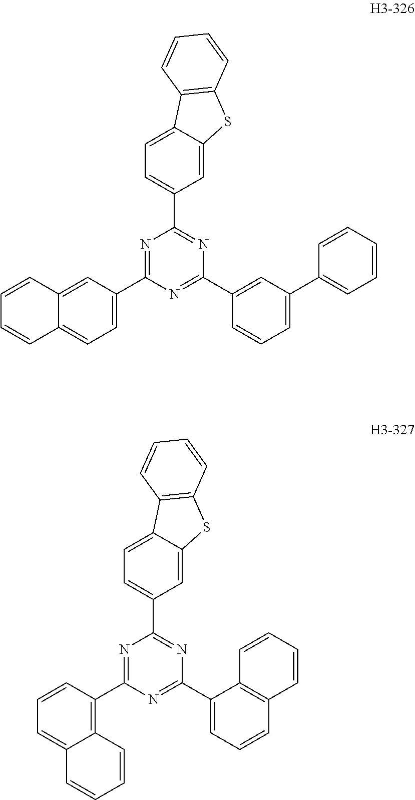 [SMILES: c1ccc(-c2cccc(-c3nc(-c4ccc5ccccc5c4)nc(-c4ccc5c(c4)sc4ccccc45)n3)c2)cc1 ; c1ccc2c(-c3nc(-c4ccc5c(c4)sc4ccccc45)nc(-c4cccc5ccccc45)n3)cccc2c1]

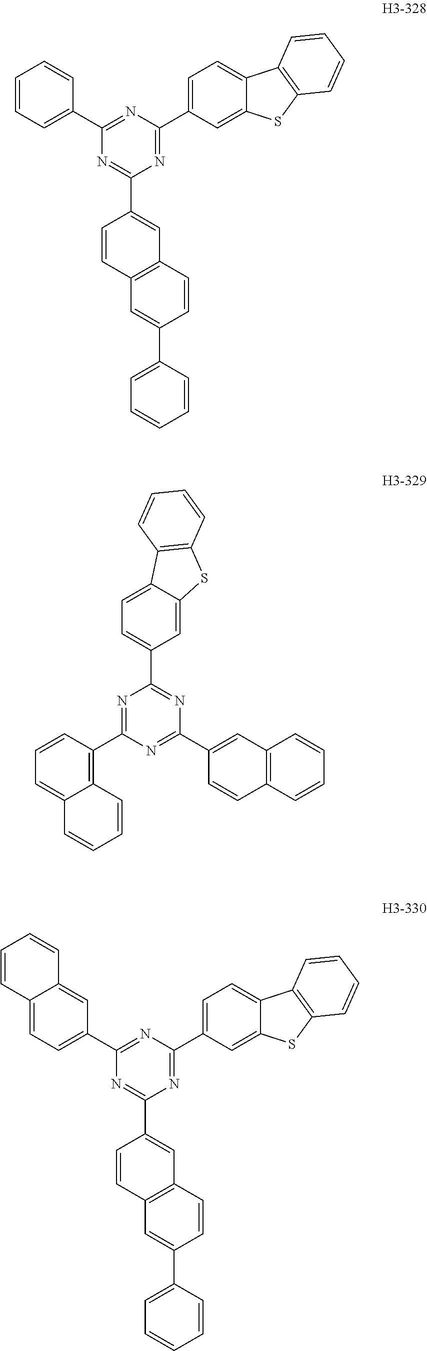 [SMILES: c1ccc(-c2ccc3cc(-c4nc(-c5ccccc5)nc(-c5ccc6c(c5)sc5ccccc56)n4)ccc3c2)cc1 ; c1ccc2cc(-c3nc(-c4ccc5c(c4)sc4ccccc45)nc(-c4cccc5ccccc45)n3)ccc2c1 ; c1ccc(-c2ccc3cc(-c4nc(-c5ccc6ccccc6c5)nc(-c5ccc6c(c5)sc5ccccc56)n4)ccc3c2)cc1]

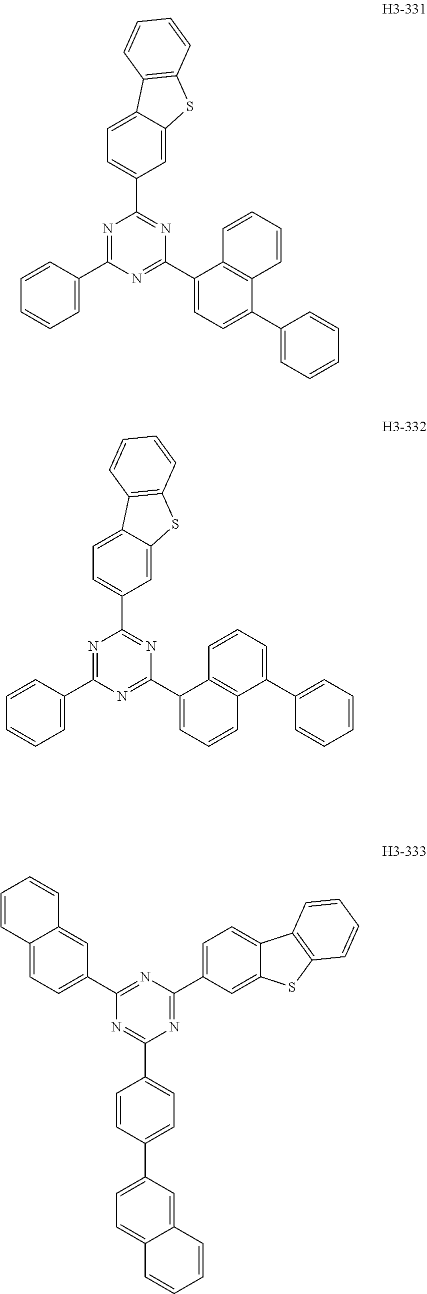 [SMILES: c1ccc(-c2nc(-c3ccc4c(c3)sc3ccccc34)nc(-c3ccc(-c4ccccc4)c4ccccc34)n2)cc1 ; c1ccc(-c2nc(-c3ccc4c(c3)sc3ccccc34)nc(-c3cccc4c(-c5ccccc5)cccc34)n2)cc1 ; c1ccc2cc(-c3ccc(-c4nc(-c5ccc6ccccc6c5)nc(-c5ccc6c(c5)sc5ccccc56)n4)cc3)ccc2c1]

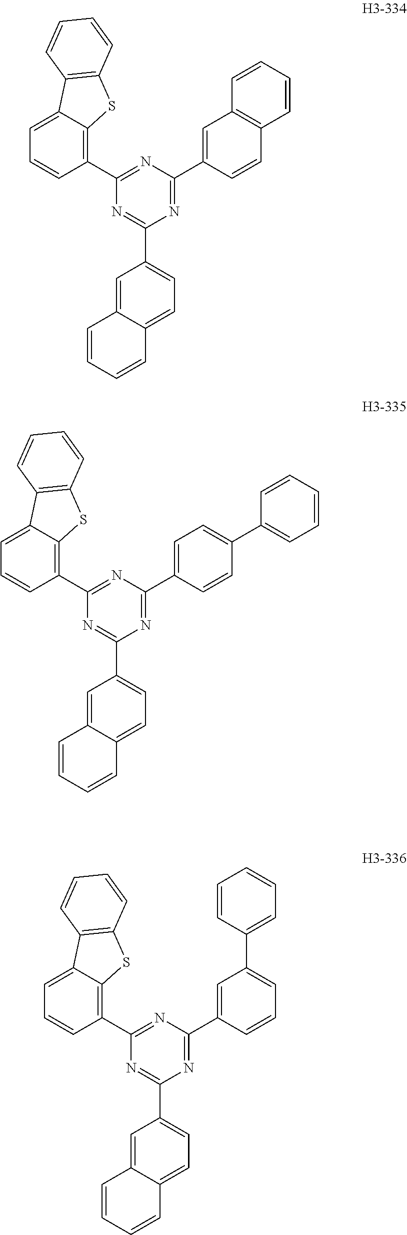 [SMILES: c1ccc2cc(-c3nc(-c4ccc5ccccc5c4)nc(-c4cccc5c4sc4ccccc45)n3)ccc2c1 ; c1ccc(-c2ccc(-c3nc(-c4ccc5ccccc5c4)nc(-c4cccc5c4sc4ccccc45)n3)cc2)cc1 ; c1ccc(-c2cccc(-c3nc(-c4ccc5ccccc5c4)nc(-c4cccc5c4sc4ccccc45)n3)c2)cc1]

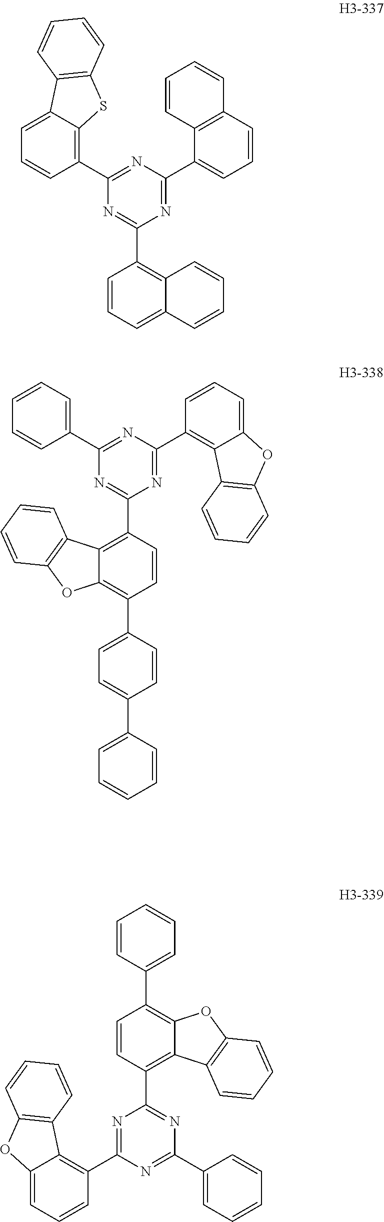 [SMILES: c1ccc2c(-c3nc(-c4cccc5ccccc45)nc(-c4cccc5c4sc4ccccc45)n3)cccc2c1 ; c1ccc(-c2ccc(-c3ccc(-c4nc(-c5ccccc5)nc(-c5cccc6oc7ccccc7c56)n4)c4c3oc3ccccc34)cc2)cc1 ; c1ccc(-c2nc(-c3cccc4oc5ccccc5c34)nc(-c3ccc(-c4ccccc4)c4oc5ccccc5c34)n2)cc1]

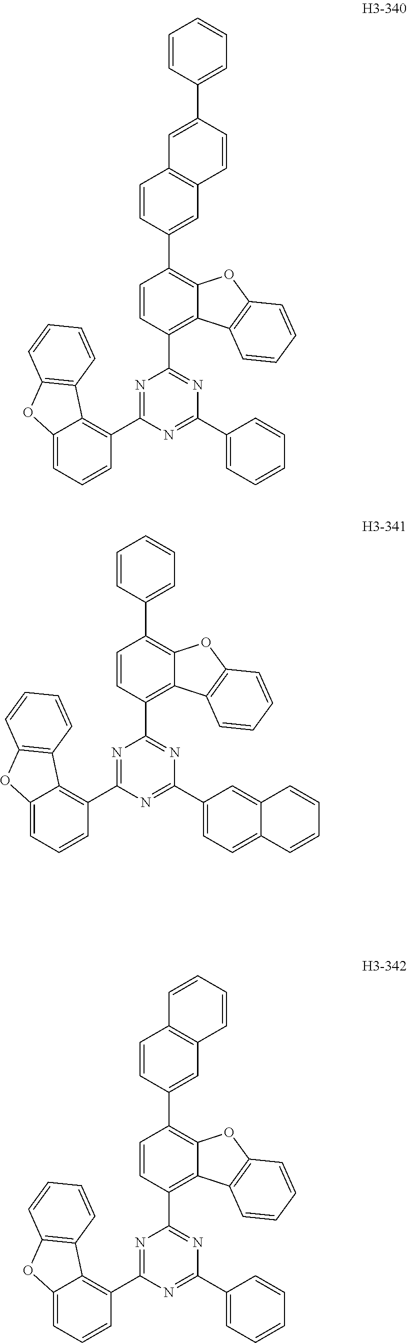 [SMILES: c1ccc(-c2ccc3cc(-c4ccc(-c5nc(-c6ccccc6)nc(-c6cccc7oc8ccccc8c67)n5)c5c4oc4ccccc45)ccc3c2)cc1 ; c1ccc(-c2ccc(-c3nc(-c4ccc5ccccc5c4)nc(-c4cccc5oc6ccccc6c45)n3)c3c2oc2ccccc23)cc1 ; c1ccc(-c2nc(-c3cccc4oc5ccccc5c34)nc(-c3ccc(-c4ccc5ccccc5c4)c4oc5ccccc5c34)n2)cc1]

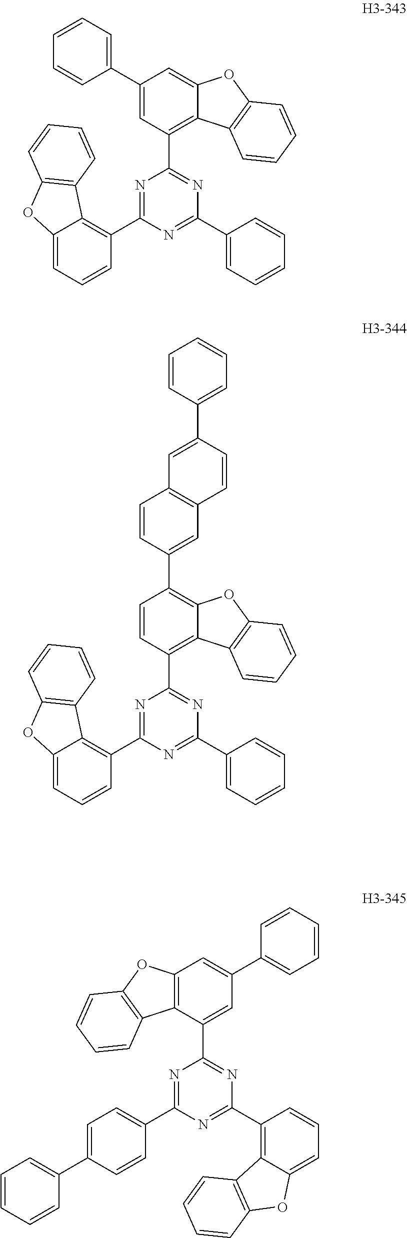 [SMILES: c1ccc(-c2cc(-c3nc(-c4ccccc4)nc(-c4cccc5oc6ccccc6c45)n3)c3c(c2)oc2ccccc23)cc1 ; c1ccc(-c2ccc3cc(-c4ccc(-c5nc(-c6ccccc6)nc(-c6cccc7oc8ccccc8c67)n5)c5c4oc4ccccc45)ccc3c2)cc1 ; c1ccc(-c2ccc(-c3nc(-c4cccc5oc6ccccc6c45)nc(-c4cc(-c5ccccc5)cc5oc6ccccc6c45)n3)cc2)cc1]

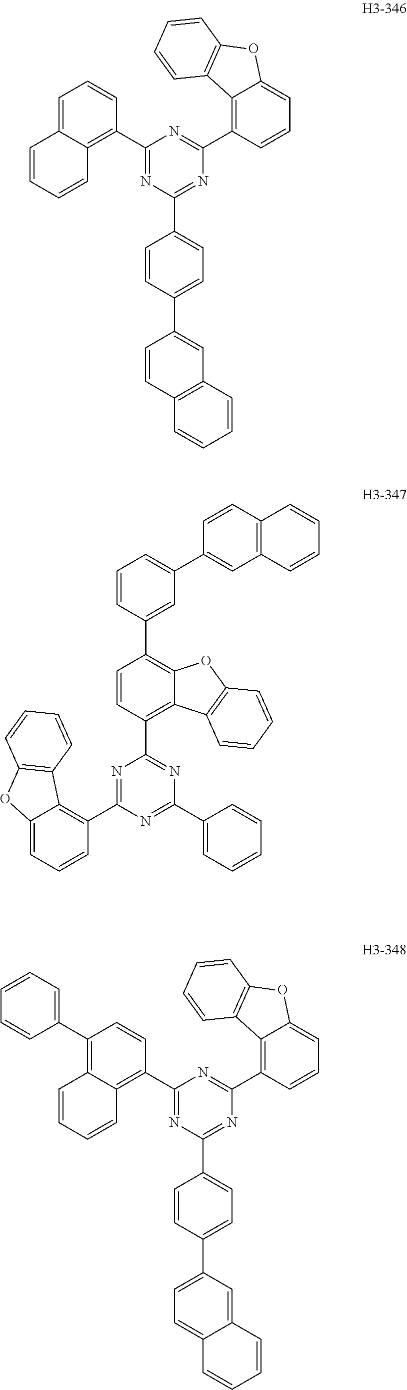 [SMILES: c1ccc2cc(-c3ccc(-c4nc(-c5cccc6ccccc56)nc(-c5cccc6oc7ccccc7c56)n4)cc3)ccc2c1 ; c1ccc(-c2nc(-c3cccc4oc5ccccc5c34)nc(-c3ccc(-c4cccc(-c5ccc6ccccc6c5)c4)c4oc5ccccc5c34)n2)cc1 ; c1ccc(-c2ccc(-c3nc(-c4ccc(-c5ccc6ccccc6c5)cc4)nc(-c4cccc5oc6ccccc6c45)n3)c3ccccc23)cc1]

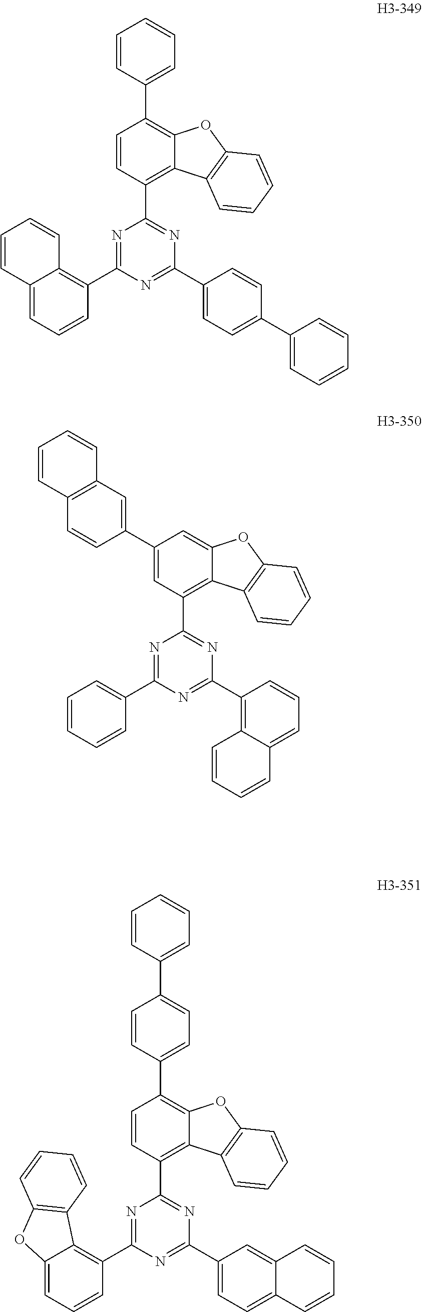 [SMILES: c1ccc(-c2ccc(-c3nc(-c4cccc5ccccc45)nc(-c4ccc(-c5ccccc5)c5oc6ccccc6c45)n3)cc2)cc1 ; c1ccc(-c2nc(-c3cccc4ccccc34)nc(-c3cc(-c4ccc5ccccc5c4)cc4oc5ccccc5c34)n2)cc1 ; c1ccc(-c2ccc(-c3ccc(-c4nc(-c5ccc6ccccc6c5)nc(-c5cccc6oc7ccccc7c56)n4)c4c3oc3ccccc34)cc2)cc1]

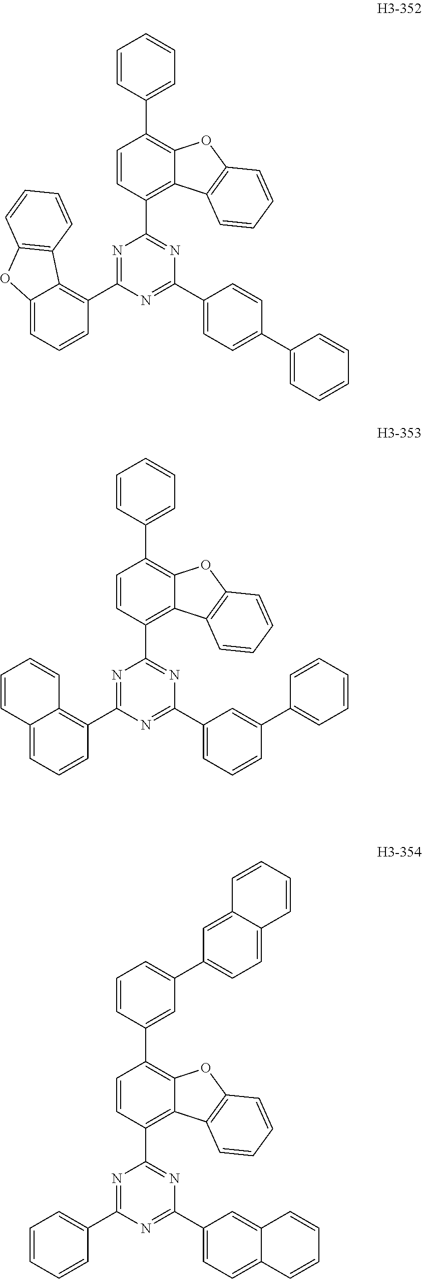 [SMILES: c1ccc(-c2ccc(-c3nc(-c4cccc5oc6ccccc6c45)nc(-c4ccc(-c5ccccc5)c5oc6ccccc6c45)n3)cc2)cc1 ; c1ccc(-c2cccc(-c3nc(-c4cccc5ccccc45)nc(-c4ccc(-c5ccccc5)c5oc6ccccc6c45)n3)c2)cc1 ; c1ccc(-c2nc(-c3ccc4ccccc4c3)nc(-c3ccc(-c4cccc(-c5ccc6ccccc6c5)c4)c4oc5ccccc5c34)n2)cc1]

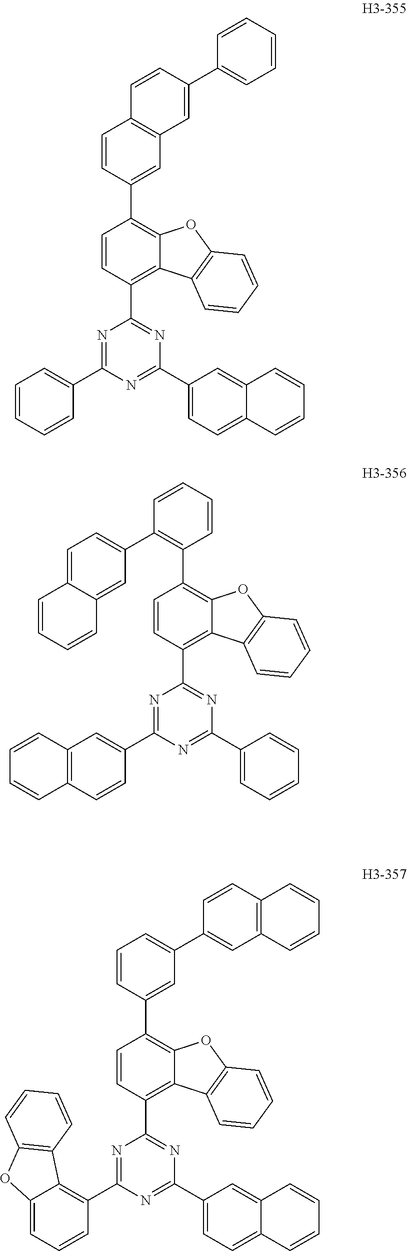 [SMILES: c1ccc(-c2ccc3ccc(-c4ccc(-c5nc(-c6ccccc6)nc(-c6ccc7ccccc7c6)n5)c5c4oc4ccccc45)cc3c2)cc1 ; c1ccc(-c2nc(-c3ccc4ccccc4c3)nc(-c3ccc(-c4ccccc4-c4ccc5ccccc5c4)c4oc5ccccc5c34)n2)cc1 ; c1cc(-c2ccc3ccccc3c2)cc(-c2ccc(-c3nc(-c4ccc5ccccc5c4)nc(-c4cccc5oc6ccccc6c45)n3)c3c2oc2ccccc23)c1]

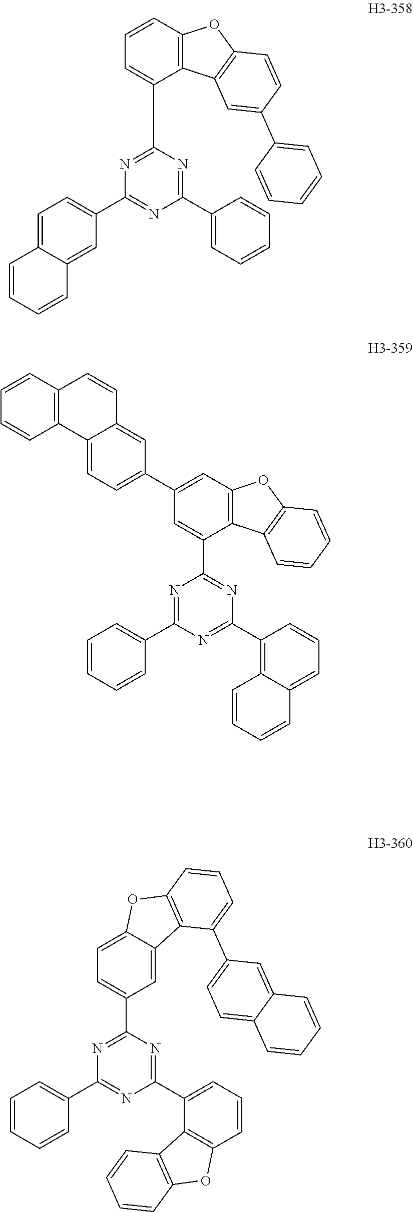 [SMILES: c1ccc(-c2ccc3oc4cccc(-c5nc(-c6ccccc6)nc(-c6ccc7ccccc7c6)n5)c4c3c2)cc1 ; c1ccc(-c2nc(-c3cccc4ccccc34)nc(-c3cc(-c4ccc5c(ccc6ccccc65)c4)cc4oc5ccccc5c34)n2)cc1 ; c1ccc(-c2nc(-c3ccc4oc5cccc(-c6ccc7ccccc7c6)c5c4c3)nc(-c3cccc4oc5ccccc5c34)n2)cc1]

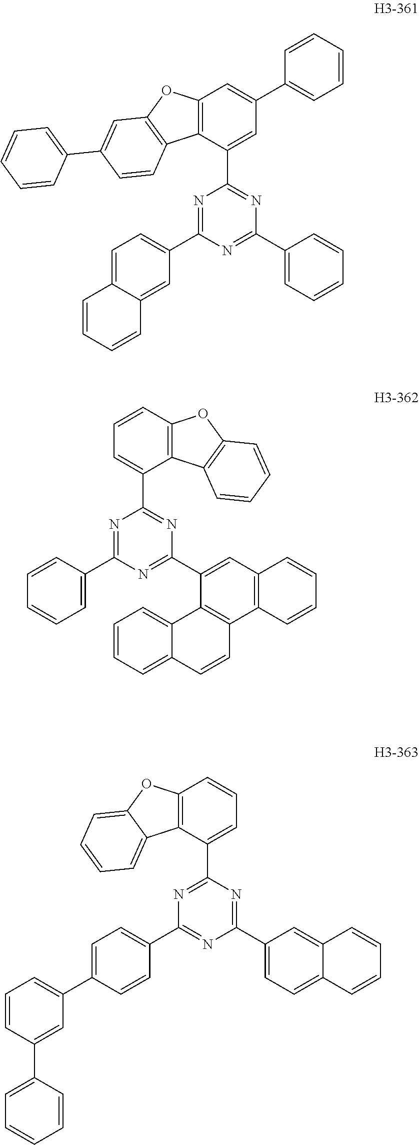 [SMILES: c1ccc(-c2ccc3c(c2)oc2cc(-c4ccccc4)cc(-c4nc(-c5ccccc5)nc(-c5ccc6ccccc6c5)n4)c23)cc1 ; c1ccc(-c2nc(-c3cccc4oc5ccccc5c34)nc(-c3cc4ccccc4c4ccc5ccccc5c34)n2)cc1 ; c1ccc(-c2cccc(-c3ccc(-c4nc(-c5ccc6ccccc6c5)nc(-c5cccc6oc7ccccc7c56)n4)cc3)c2)cc1]

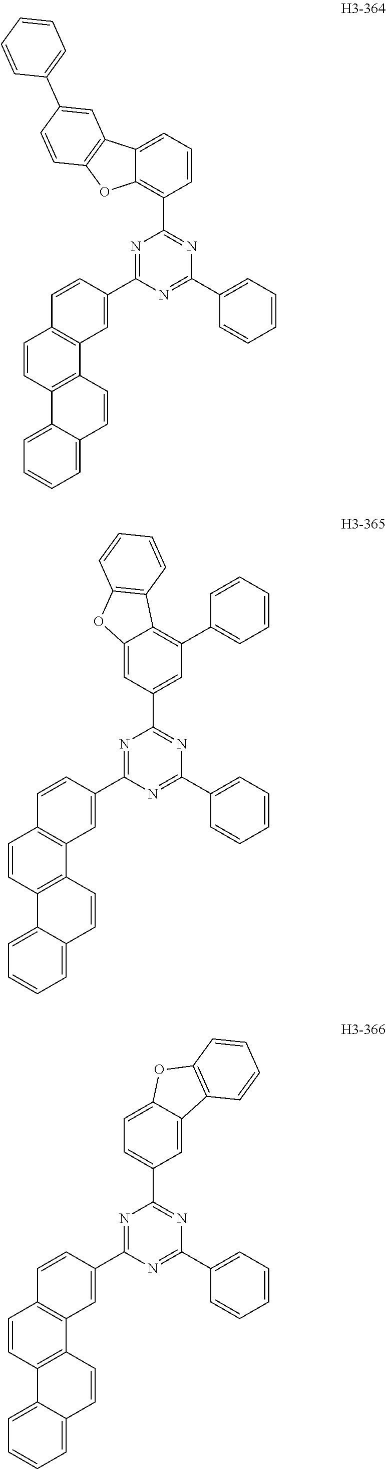 [SMILES: c1ccc(-c2ccc3oc4c(-c5nc(-c6ccccc6)nc(-c6ccc7ccc8c9ccccc9ccc8c7c6)n5)cccc4c3c2)cc1 ; c1ccc(-c2nc(-c3cc(-c4ccccc4)c4c(c3)oc3ccccc34)nc(-c3ccc4ccc5c6ccccc6ccc5c4c3)n2)cc1 ; c1ccc(-c2nc(-c3ccc4ccc5c6ccccc6ccc5c4c3)nc(-c3ccc4oc5ccccc5c4c3)n2)cc1]

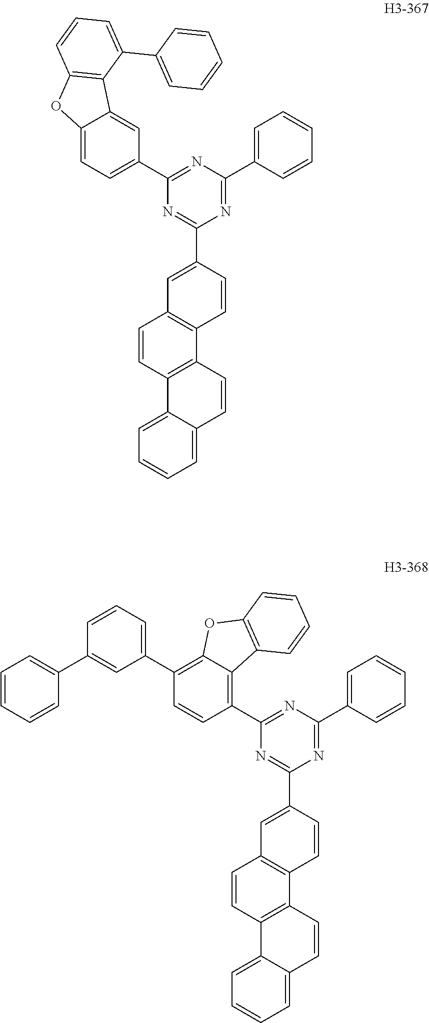 [SMILES: c1ccc(-c2nc(-c3ccc4c(ccc5c6ccccc6ccc45)c3)nc(-c3ccc4oc5cccc(-c6ccccc6)c5c4c3)n2)cc1 ; c1ccc(-c2cccc(-c3ccc(-c4nc(-c5ccccc5)nc(-c5ccc6c(ccc7c8ccccc8ccc67)c5)n4)c4c3oc3ccccc34)c2)cc1]

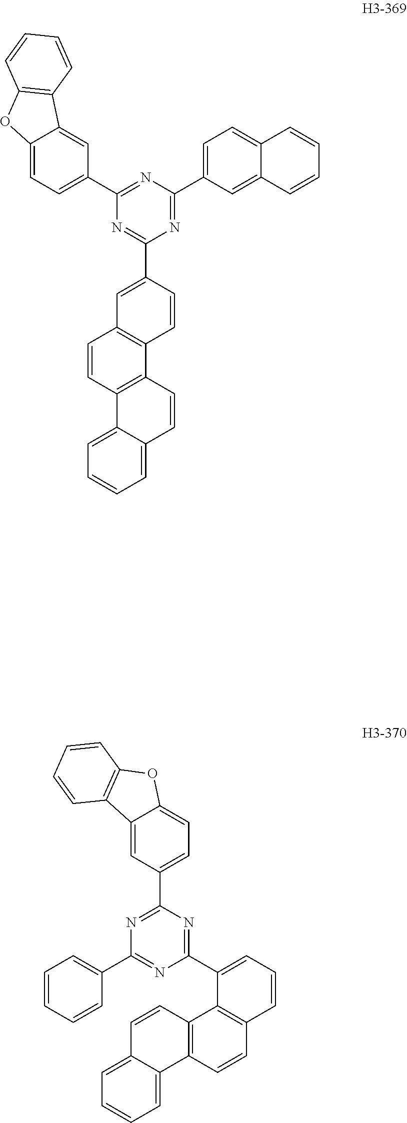 [SMILES: c1ccc2cc(-c3nc(-c4ccc5c(ccc6c7ccccc7ccc56)c4)nc(-c4ccc5oc6ccccc6c5c4)n3)ccc2c1 ; c1ccc(-c2nc(-c3ccc4oc5ccccc5c4c3)nc(-c3cccc4ccc5c6ccccc6ccc5c34)n2)cc1]

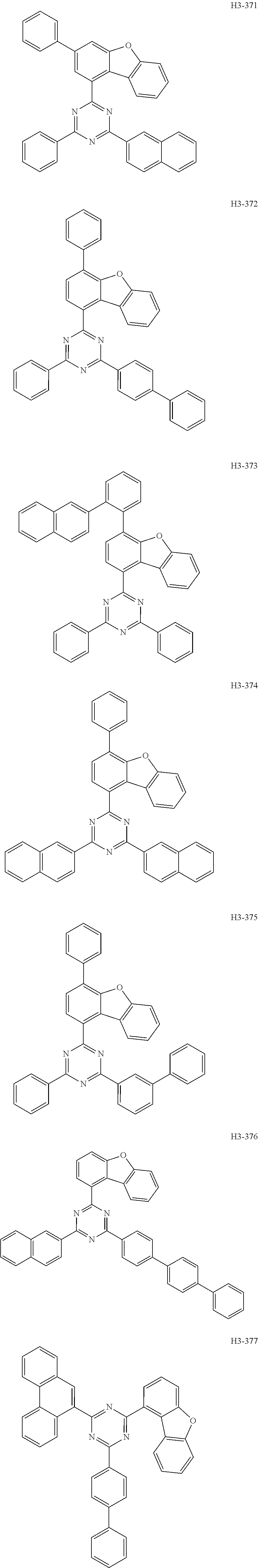

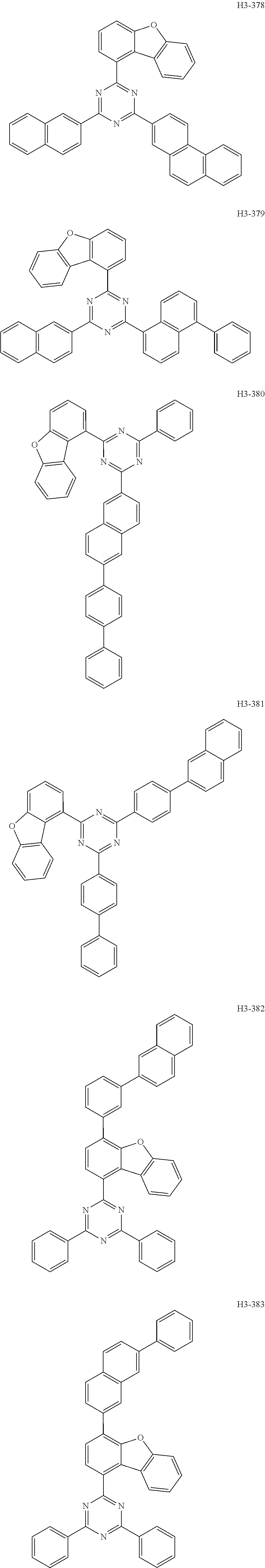 [SMILES: c1ccc2cc(-c3nc(-c4ccc5c(ccc6ccccc65)c4)nc(-c4cccc5oc6ccccc6c45)n3)ccc2c1 ; c1ccc(-c2cccc3c(-c4nc(-c5ccc6ccccc6c5)nc(-c5cccc6oc7ccccc7c56)n4)cccc23)cc1 ; c1ccc(-c2ccc(-c3ccc4cc(-c5nc(-c6ccccc6)nc(-c6cccc7oc8ccccc8c67)n5)ccc4c3)cc2)cc1 ; c1ccc(-c2ccc(-c3nc(-c4ccc(-c5ccc6ccccc6c5)cc4)nc(-c4cccc5oc6ccccc6c45)n3)cc2)cc1 ; c1ccc(-c2nc(-c3ccccc3)nc(-c3ccc(-c4cccc(-c5ccc6ccccc6c5)c4)c4oc5ccccc5c34)n2)cc1 ; c1ccc(-c2ccc3ccc(-c4ccc(-c5nc(-c6ccccc6)nc(-c6ccccc6)n5)c5c4oc4ccccc45)cc3c2)cc1]

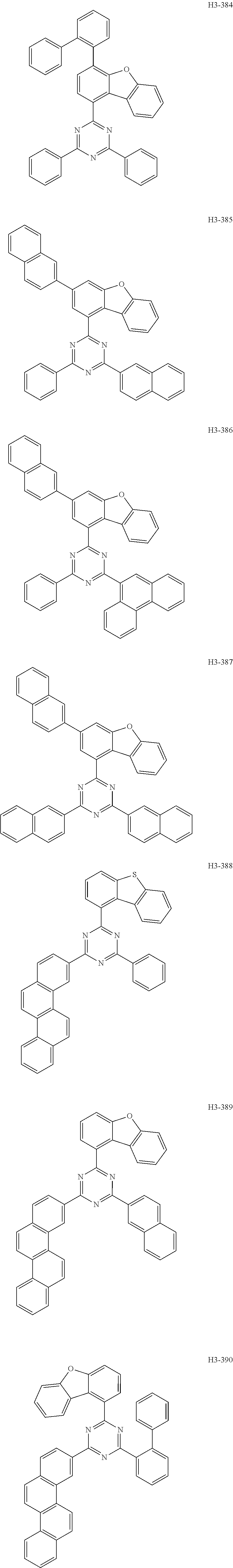

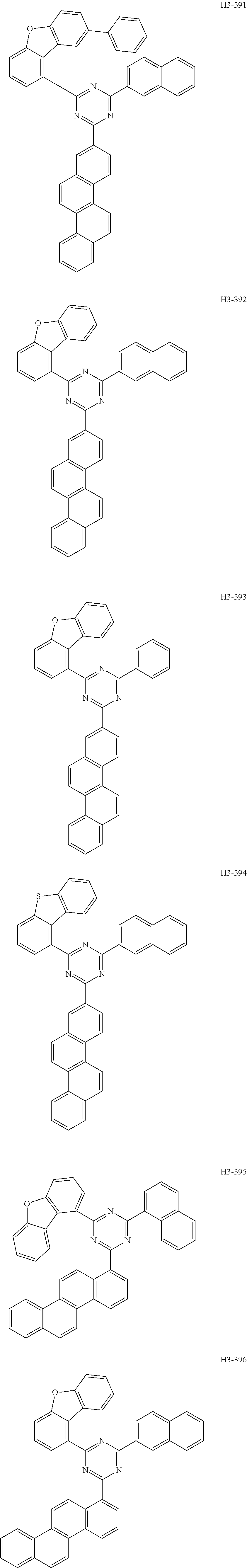

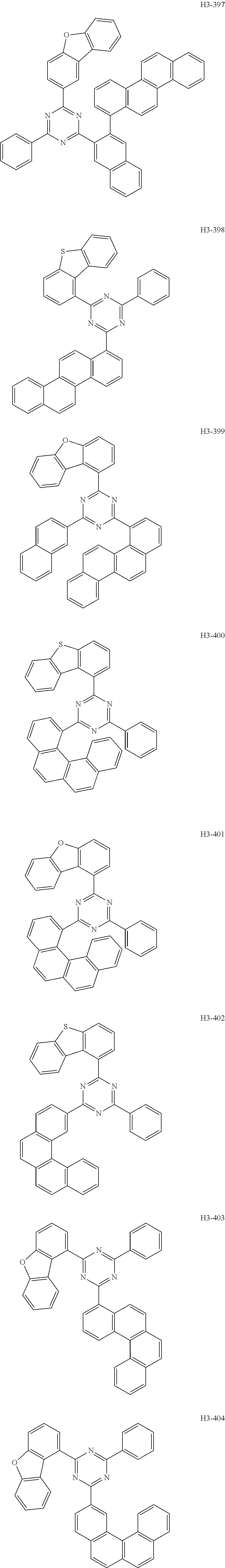

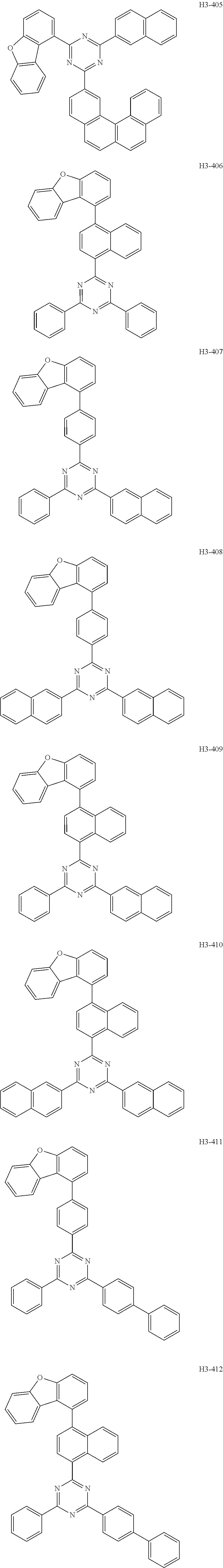

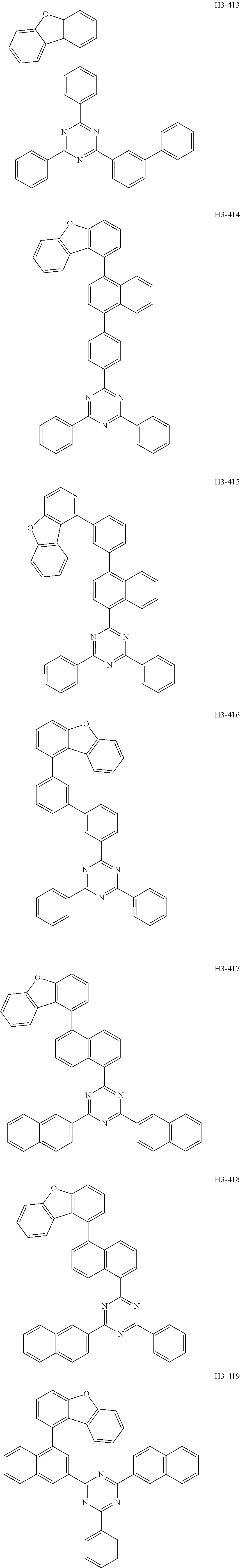

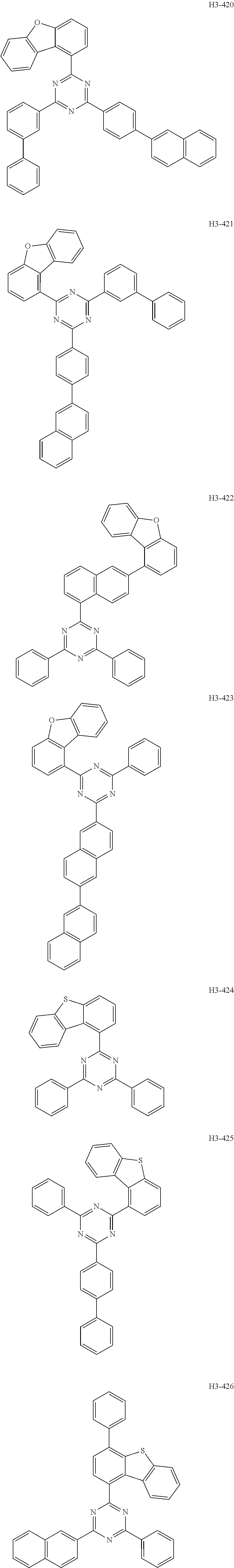

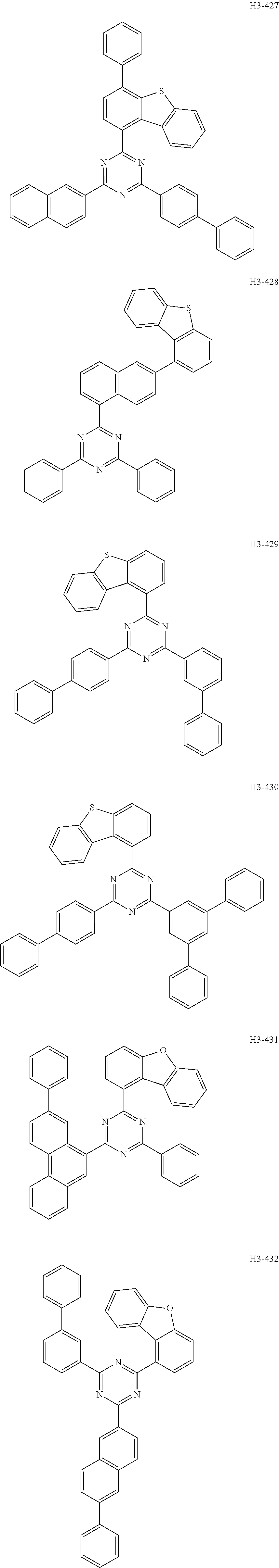 [SMILES: c1ccc(-c2ccc(-c3nc(-c4ccc5ccccc5c4)nc(-c4ccc(-c5ccccc5)c5sc6ccccc6c45)n3)cc2)cc1 ; c1ccc(-c2nc(-c3ccccc3)nc(-c3cccc4cc(-c5cccc6sc7ccccc7c56)ccc34)n2)cc1 ; c1ccc(-c2ccc(-c3nc(-c4cccc(-c5ccccc5)c4)nc(-c4cccc5sc6ccccc6c45)n3)cc2)cc1 ; c1ccc(-c2ccc(-c3nc(-c4cc(-c5ccccc5)cc(-c5ccccc5)c4)nc(-c4cccc5sc6ccccc6c45)n3)cc2)cc1 ; c1ccc(-c2ccc3c(c2)c(-c2nc(-c4ccccc4)nc(-c4cccc5oc6ccccc6c45)n2)cc2ccccc23)cc1 ; c1ccc(-c2cccc(-c3nc(-c4ccc5cc(-c6ccccc6)ccc5c4)nc(-c4cccc5oc6ccccc6c45)n3)c2)cc1]

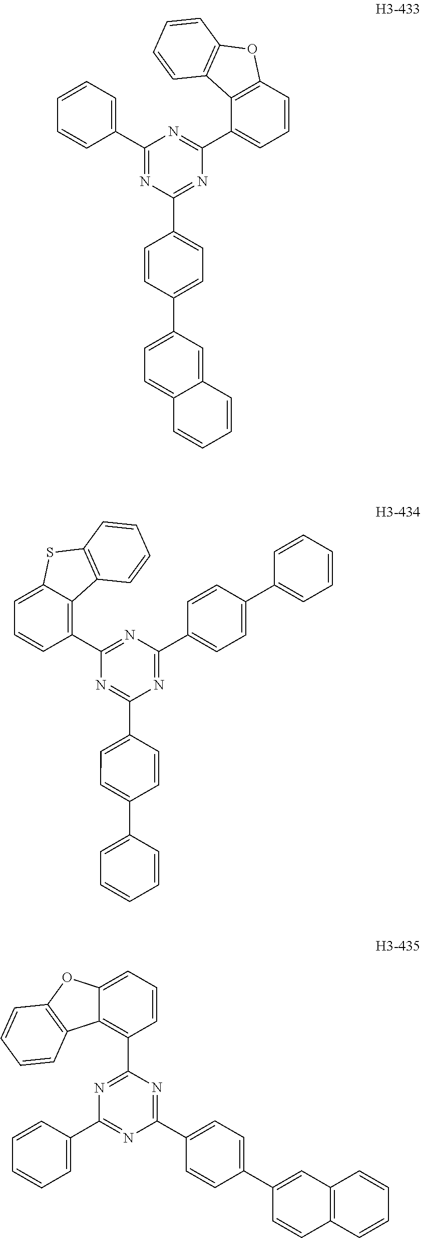 [SMILES: c1ccc(-c2nc(-c3ccc(-c4ccc5ccccc5c4)cc3)nc(-c3cccc4oc5ccccc5c34)n2)cc1 ; c1ccc(-c2ccc(-c3nc(-c4ccc(-c5ccccc5)cc4)nc(-c4cccc5sc6ccccc6c45)n3)cc2)cc1 ; c1ccc(-c2nc(-c3ccc(-c4ccc5ccccc5c4)cc3)nc(-c3cccc4oc5ccccc5c34)n2)cc1]

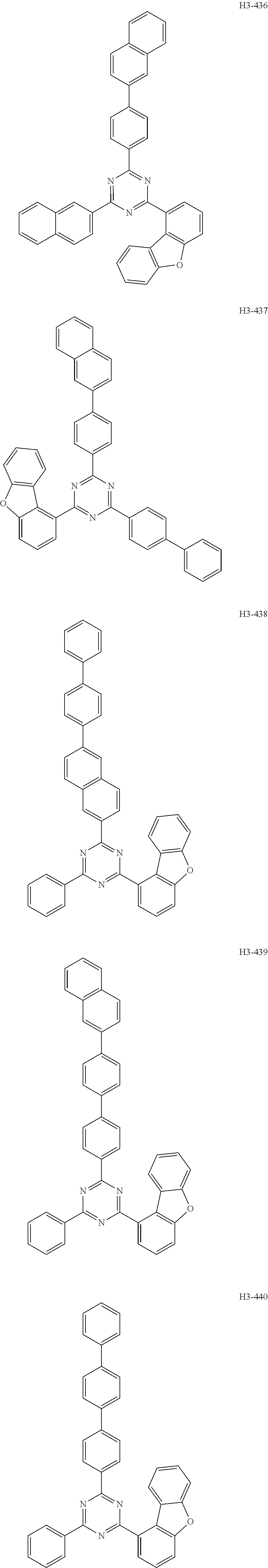 [SMILES: c1ccc2cc(-c3ccc(-c4nc(-c5ccc6ccccc6c5)nc(-c5cccc6oc7ccccc7c56)n4)cc3)ccc2c1 ; c1ccc(-c2ccc(-c3nc(-c4ccc(-c5ccc6ccccc6c5)cc4)nc(-c4cccc5oc6ccccc6c45)n3)cc2)cc1 ; c1ccc(-c2ccc(-c3ccc4cc(-c5nc(-c6ccccc6)nc(-c6cccc7oc8ccccc8c67)n5)ccc4c3)cc2)cc1 ; c1ccc(-c2nc(-c3ccc(-c4ccc(-c5ccc6ccccc6c5)cc4)cc3)nc(-c3cccc4oc5ccccc5c34)n2)cc1 ; c1ccc(-c2ccc(-c3ccc(-c4nc(-c5ccccc5)nc(-c5cccc6oc7ccccc7c56)n4)cc3)cc2)cc1]

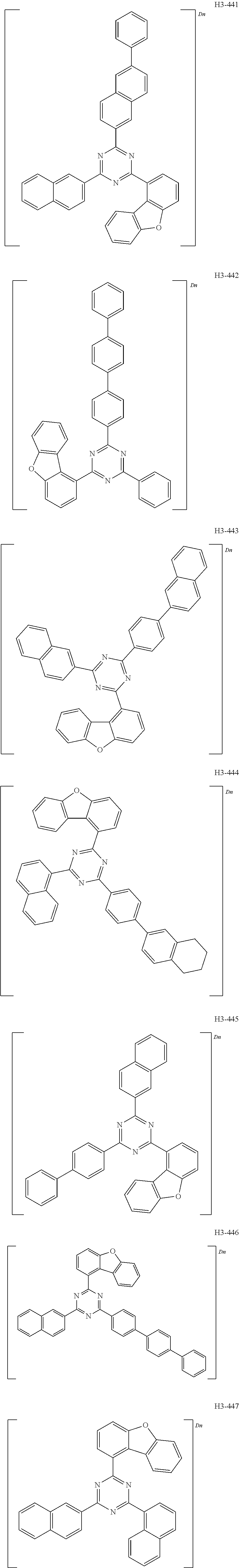

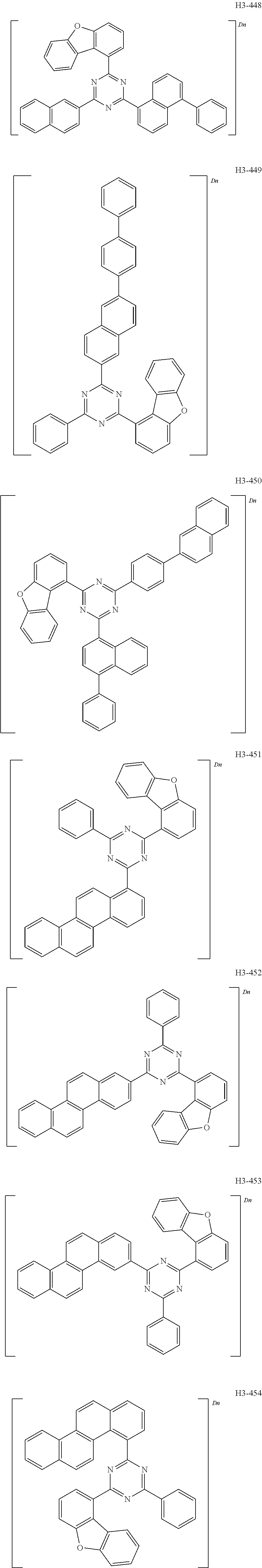

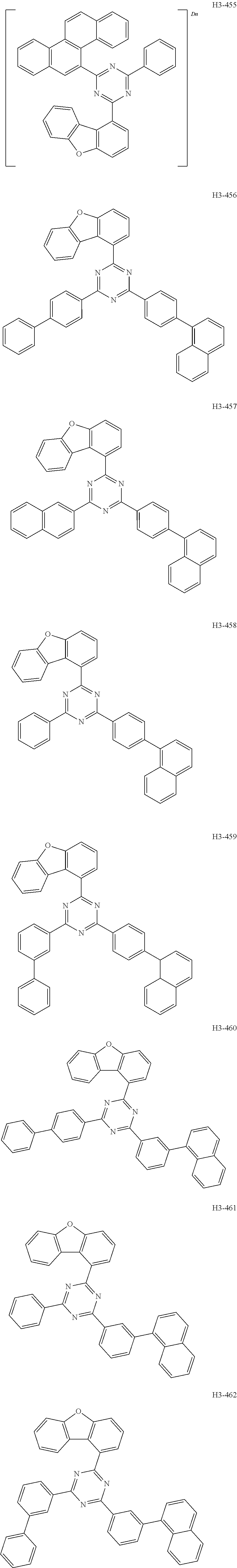

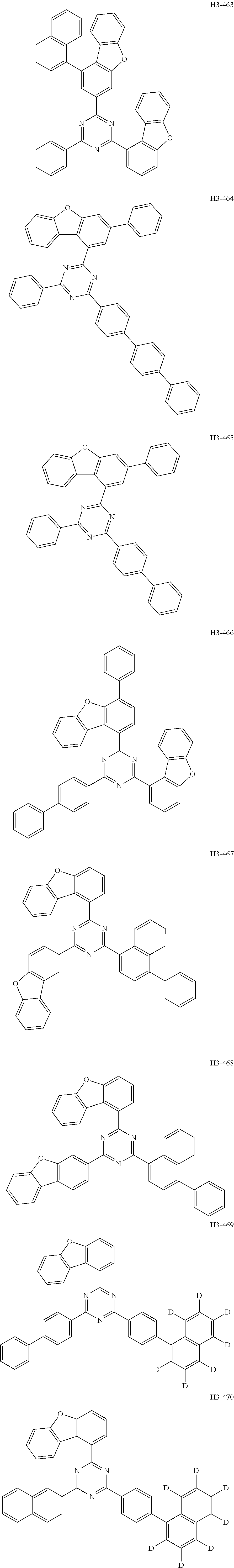

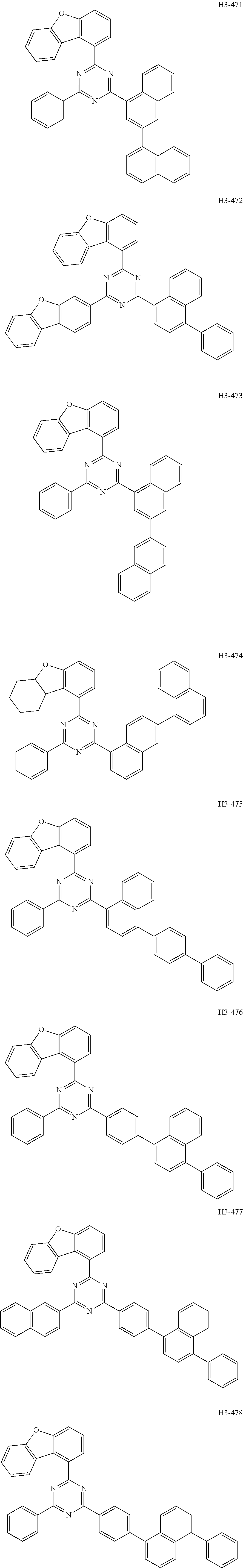

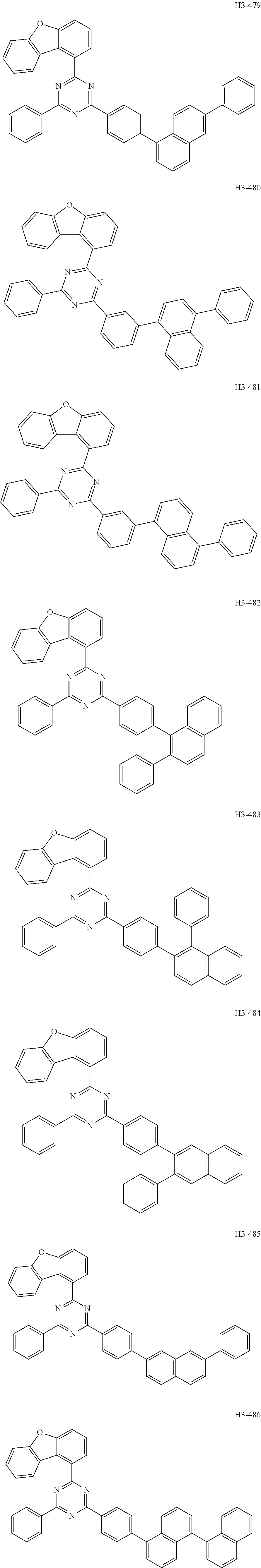

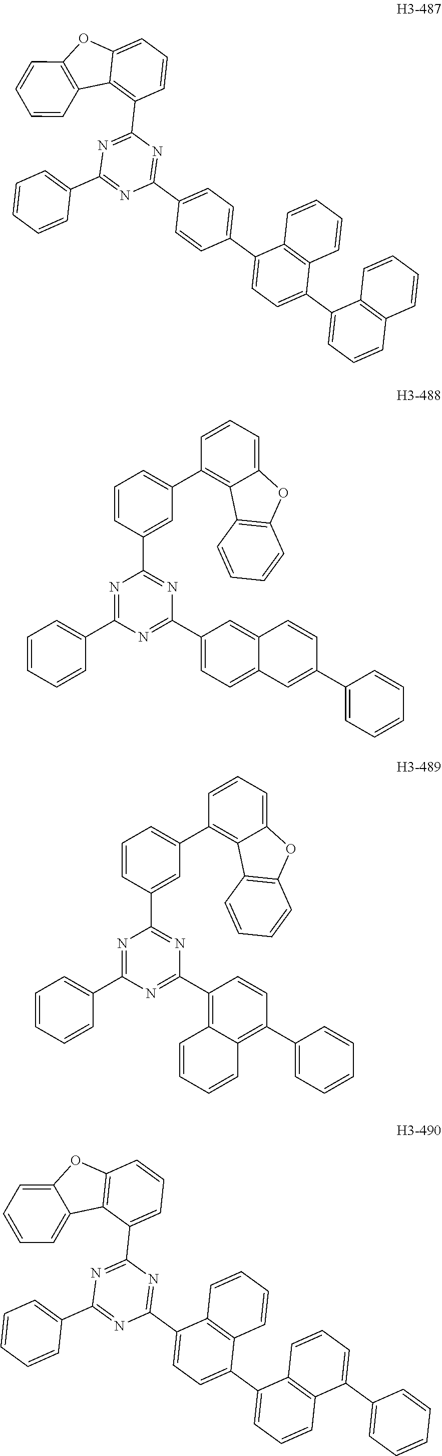 [SMILES: c1ccc(-c2nc(-c3ccc(-c4ccc(-c5cccc6ccccc56)c5ccccc45)cc3)nc(-c3cccc4oc5ccccc5c34)n2)cc1 ; c1ccc(-c2ccc3cc(-c4nc(-c5ccccc5)nc(-c5cccc(-c6cccc7oc8ccccc8c67)c5)n4)ccc3c2)cc1 ; c1ccc(-c2nc(-c3cccc(-c4cccc5oc6ccccc6c45)c3)nc(-c3ccc(-c4ccccc4)c4ccccc34)n2)cc1 ; c1ccc(-c2nc(-c3ccc(-c4cccc5c(-c6ccccc6)cccc45)c4ccccc34)nc(-c3cccc4oc5ccccc5c34)n2)cc1]

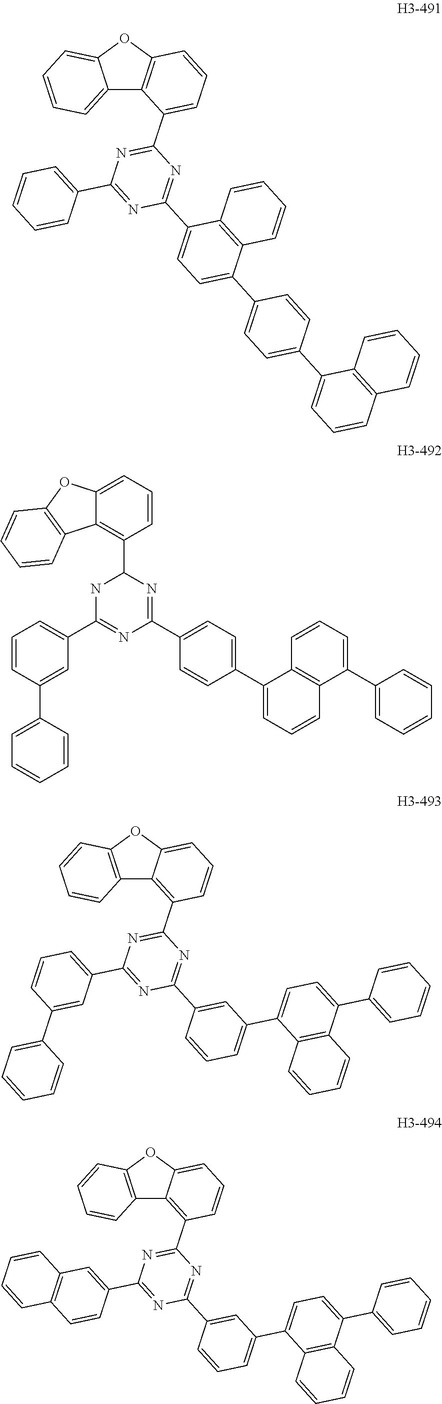

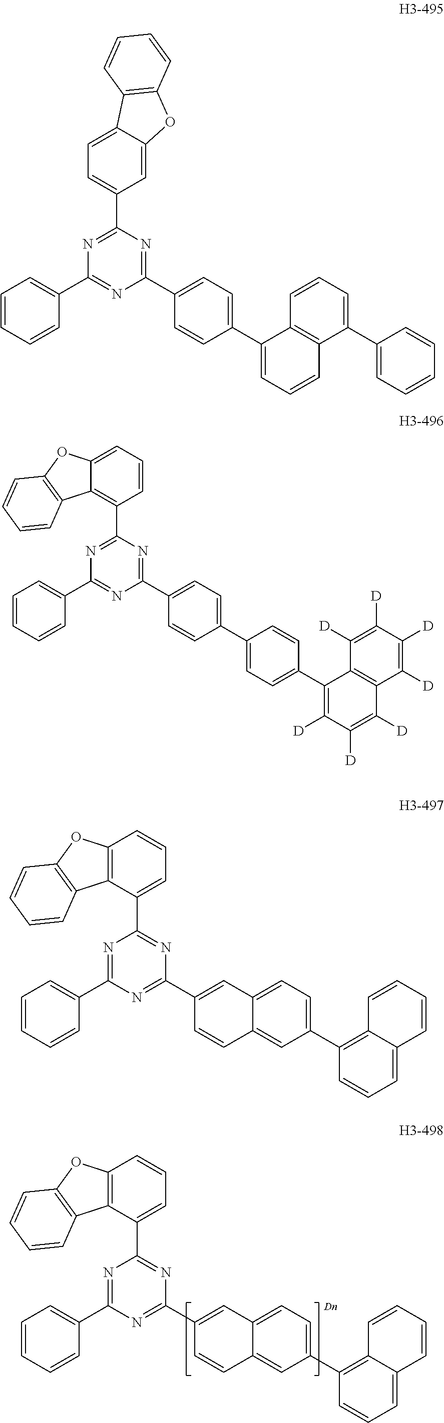

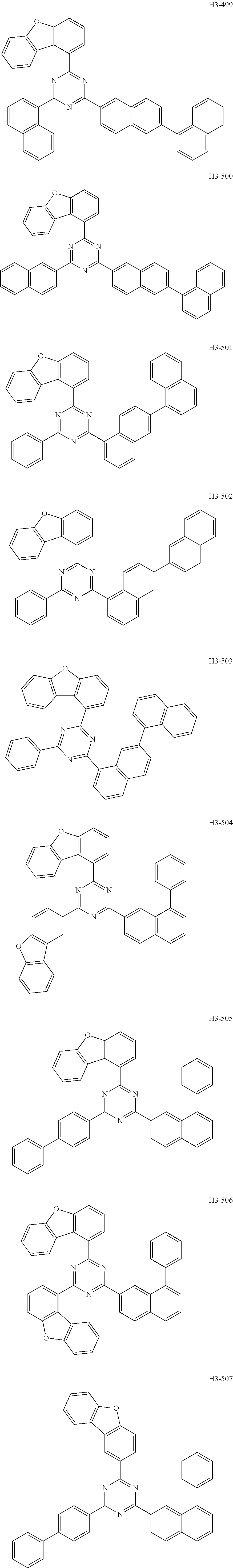

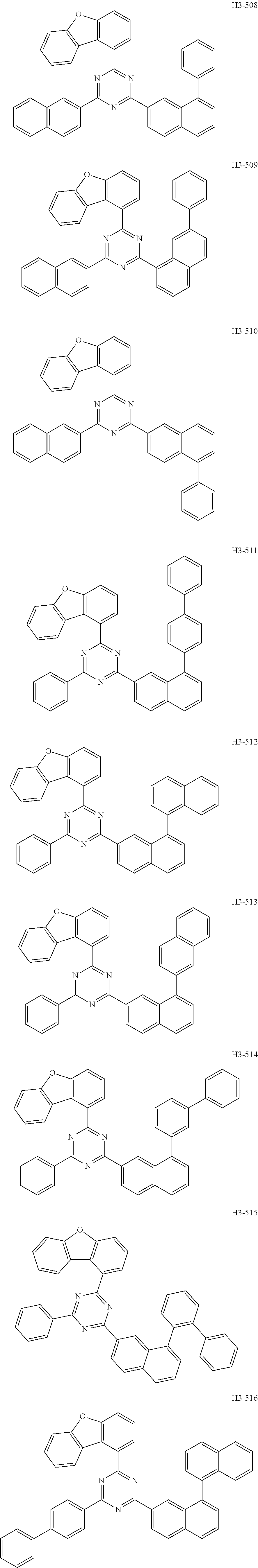

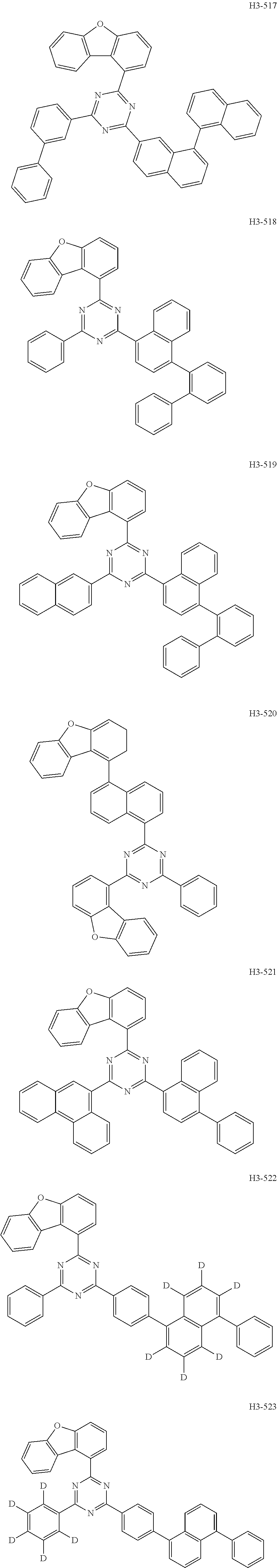

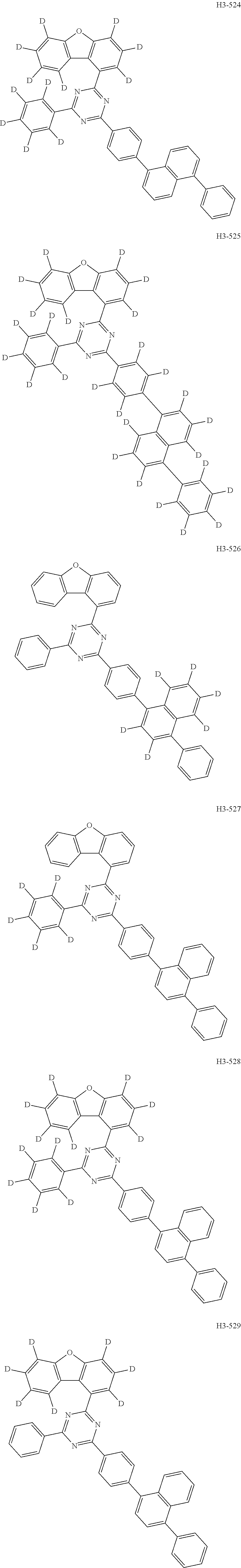

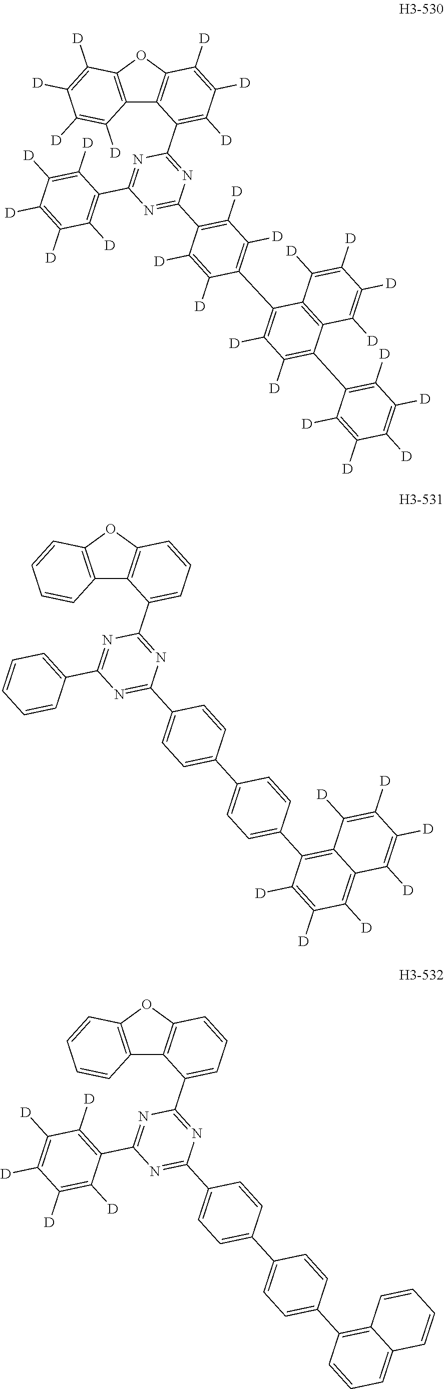 [SMILES: [2H]c1c([2H])c([2H])c(-c2nc(-c3c([2H])c([2H])c(-c4c([2H])c([2H])c(-c5c([2H])c([2H])c([2H])c([2H])c5[2H])c5c([2H])c([2H])c([2H])c([2H])c45)c([2H])c3[2H])nc(-c3c([2H])c([2H])c([2H])c4oc5c([2H])c([2H])c([2H])c([2H])c5c34)n2)c([2H])c1[2H] ; [2H]c1c([2H])c([2H])c2c(-c3ccc(-c4ccc(-c5nc(-c6ccccc6)nc(-c6cccc7oc8ccccc8c67)n5)cc4)cc3)c([2H])c([2H])c([2H])c2c1[2H] ; [2H]c1c([2H])c([2H])c(-c2nc(-c3ccc(-c4ccc(-c5cccc6ccccc56)cc4)cc3)nc(-c3cccc4oc5ccccc5c34)n2)c([2H])c1[2H]]

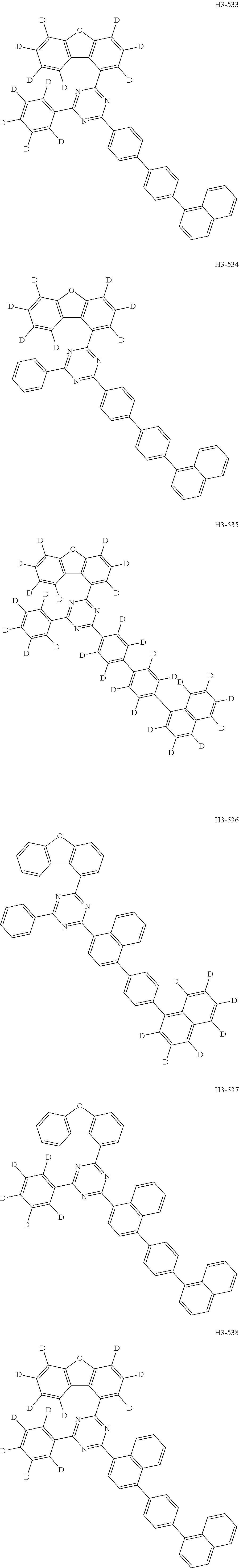

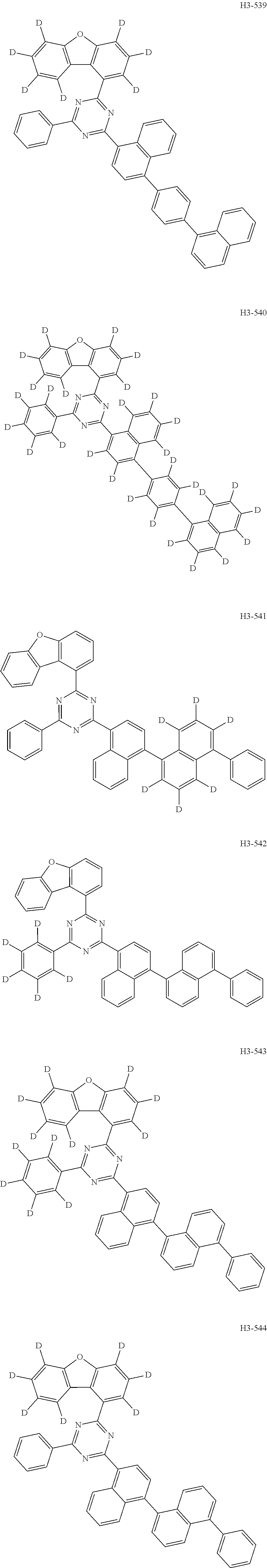

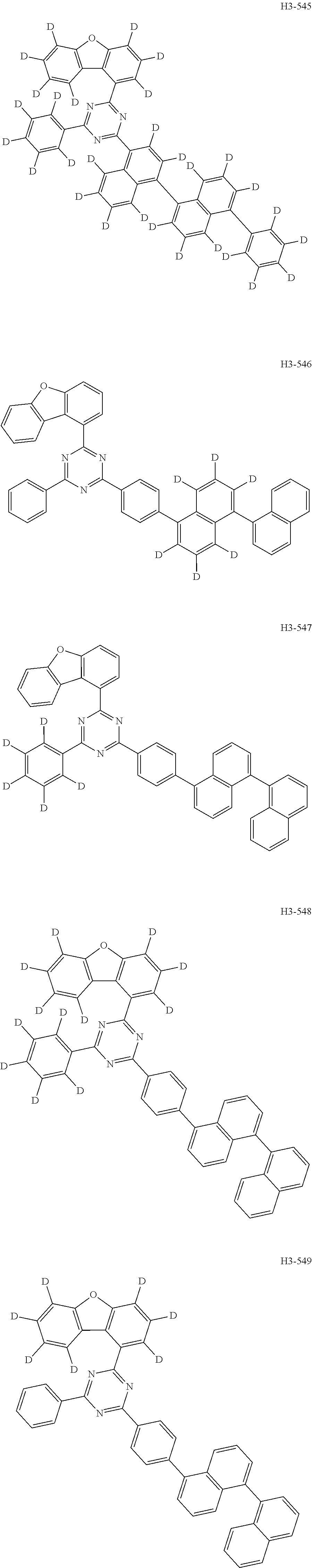

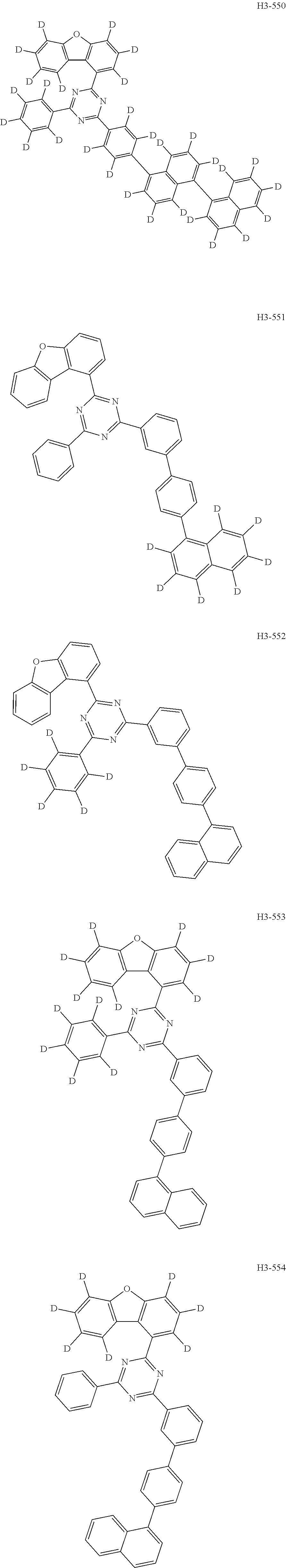

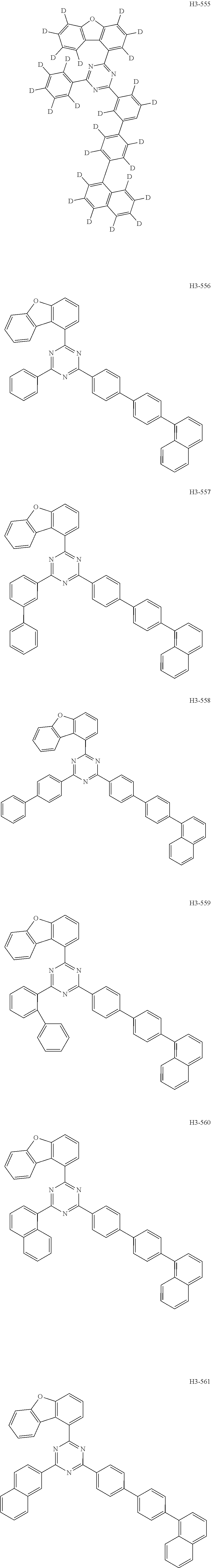

In the compounds above, Dₙ means that n hydrogen atoms are replaced with deuterium, wherein n is an integer from 1 to the maximum number of hydrogen atoms in the compound.

The compound represented by Formula 3 according to the present disclosure may be synthesized by referring to synthetic methods disclosed in Korean Patent Application Laid-Open Nos. 2021-0124018 (published on Oct. 14, 2021) and 2021-0006283 (published on Jan. 18, 2021), etc., but is not limited thereto.

The layer comprising the compound represented by Formula 1 in the hole transport band of the above organic electroluminescent device may be a hole transport layer, a hole auxiliary layer, an electron-blocking layer, or a light-emitting auxiliary layer.

The light-emitting layer of the above organic electroluminescent device may further comprise an additional compound different from the compounds represented by Formulas 2 and 3.

In the above organic electroluminescent device, the light-emitting layer may include a light-emitting layer that emits red light.

According to one embodiment of the present disclosure, the present invention comprises an organic electroluminescent compound represented by the following compounds.

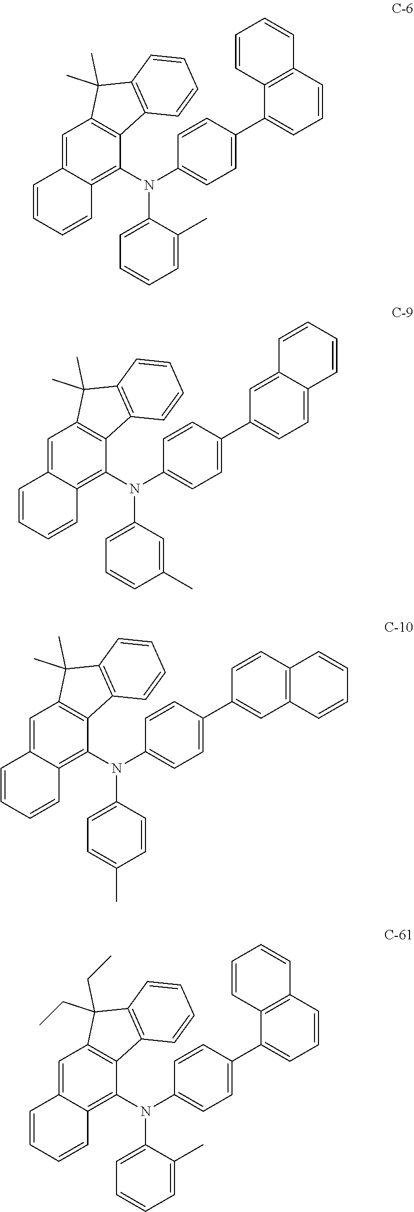 [SMILES: Cc1ccccc1N(c1ccc(-c2cccc3ccccc23)cc1)c1c2c(cc3ccccc13)C(C)(C)c1ccccc1-2 ; Cc1cccc(N(c2ccc(-c3ccc4ccccc4c3)cc2)c2c3c(cc4ccccc24)C(C)(C)c2ccccc2-3)c1 ; Cc1ccc(N(c2ccc(-c3ccc4ccccc4c3)cc2)c2c3c(cc4ccccc24)C(C)(C)c2ccccc2-3)cc1 ; CCC1(CC)c2ccccc2-c2c1cc1ccccc1c2N(c1ccc(-c2cccc3ccccc23)cc1)c1ccccc1C]

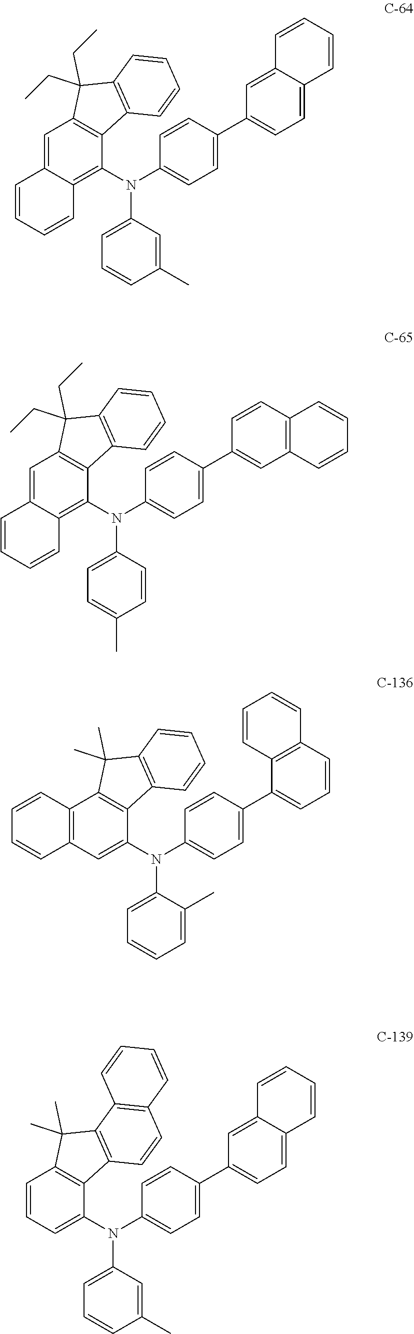 [SMILES: CCC1(CC)c2ccccc2-c2c1cc1ccccc1c2N(c1ccc(-c2ccc3ccccc3c2)cc1)c1cccc(C)c1 ; CCC1(CC)c2ccccc2-c2c1cc1ccccc1c2N(c1ccc(C)cc1)c1ccc(-c2ccc3ccccc3c2)cc1 ; Cc1ccccc1N(c1ccc(-c2cccc3ccccc23)cc1)c1cc2ccccc2c2c1-c1ccccc1C2(C)C ; Cc1cccc(N(c2ccc(-c3ccc4ccccc4c3)cc2)c2cccc3c2-c2ccc4ccccc4c2C3(C)C)c1]

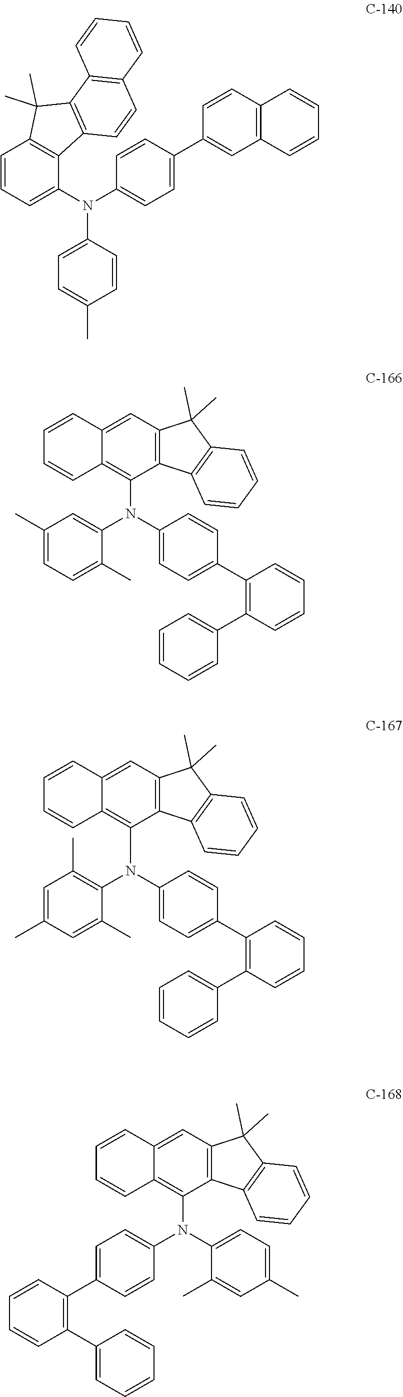 [SMILES: Cc1ccc(N(c2ccc(-c3ccc4ccccc4c3)cc2)c2cccc3c2-c2ccc4ccccc4c2C3(C)C)cc1 ; Cc1ccc(C)c(N(c2ccc(-c3ccccc3-c3ccccc3)cc2)c2c3c(cc4ccccc24)C(C)(C)c2ccccc2-3)c1 ; Cc1cc(C)c(N(c2ccc(-c3ccccc3-c3ccccc3)cc2)c2c3c(cc4ccccc24)C(C)(C)c2ccccc2-3)c(C)c1 ; Cc1ccc(N(c2ccc(-c3ccccc3-c3ccccc3)cc2)c2c3c(cc4ccccc24)C(C)(C)c2ccccc2-3)c(C)c1]

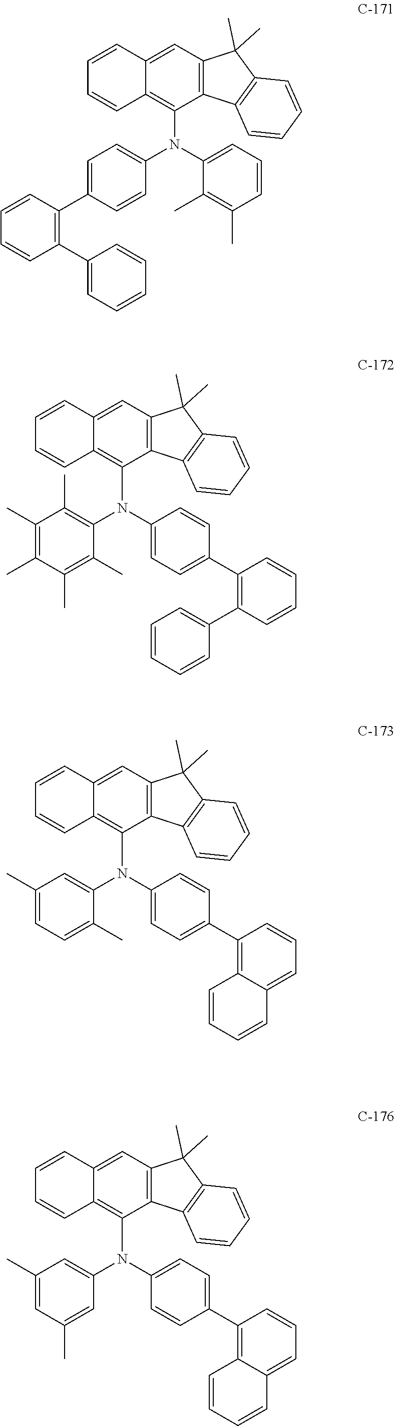 [SMILES: Cc1cccc(N(c2ccc(-c3ccccc3-c3ccccc3)cc2)c2c3c(cc4ccccc24)C(C)(C)c2ccccc2-3)c1C ; Cc1c(C)c(C)c(N(c2ccc(-c3ccccc3-c3ccccc3)cc2)c2c3c(cc4ccccc24)C(C)(C)c2ccccc2-3)c(C)c1C ; Cc1ccc(C)c(N(c2ccc(-c3cccc4ccccc34)cc2)c2c3c(cc4ccccc24)C(C)(C)c2ccccc2-3)c1 ; Cc1cc(C)cc(N(c2ccc(-c3cccc4ccccc34)cc2)c2c3c(cc4ccccc24)C(C)(C)c2ccccc2-3)c1]

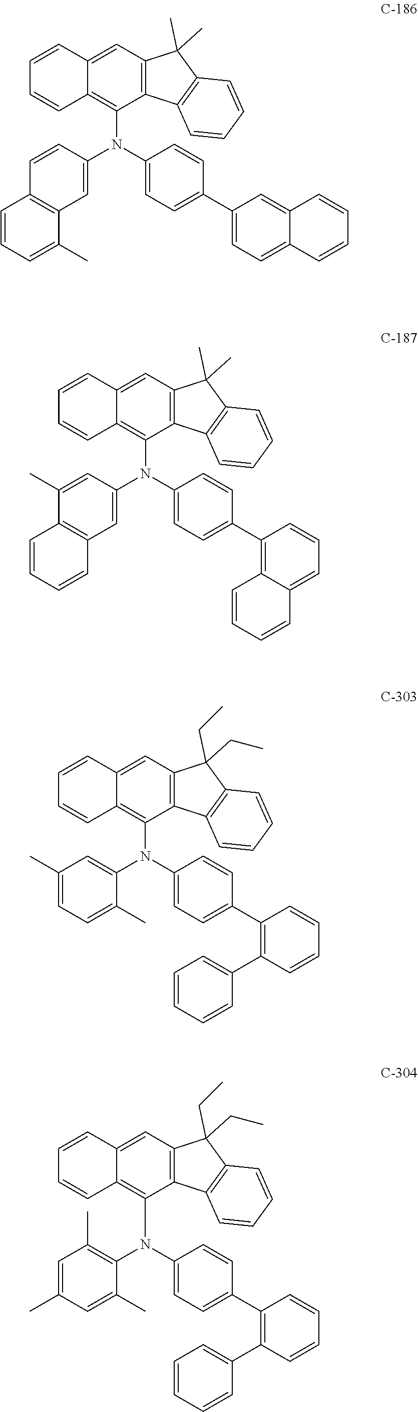 [SMILES: Cc1cccc2ccc(N(c3ccc(-c4ccc5ccccc5c4)cc3)c3c4c(cc5ccccc35)C(C)(C)c3ccccc3-4)cc12 ; Cc1cc(N(c2ccc(-c3cccc4ccccc34)cc2)c2c3c(cc4ccccc24)C(C)(C)c2ccccc2-3)cc2ccccc12 ; CCC1(CC)c2ccccc2-c2c1cc1ccccc1c2N(c1ccc(-c2ccccc2-c2ccccc2)cc1)c1cc(C)ccc1C ; CCC1(CC)c2ccccc2-c2c1cc1ccccc1c2N(c1ccc(-c2ccccc2-c2ccccc2)cc1)c1c(C)cc(C)cc1C]

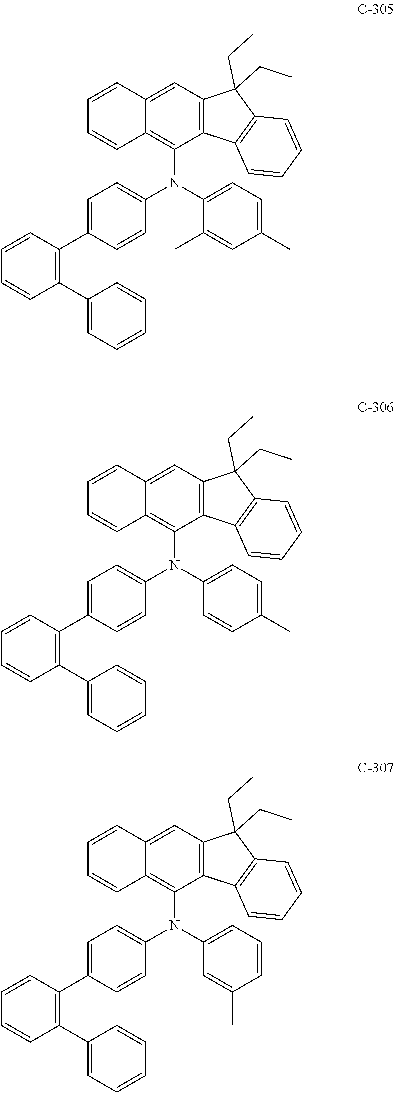 [SMILES: CCC1(CC)c2ccccc2-c2c1cc1ccccc1c2N(c1ccc(-c2ccccc2-c2ccccc2)cc1)c1ccc(C)cc1C ; CCC1(CC)c2ccccc2-c2c1cc1ccccc1c2N(c1ccc(C)cc1)c1ccc(-c2ccccc2-c2ccccc2)cc1 ; CCC1(CC)c2ccccc2-c2c1cc1ccccc1c2N(c1ccc(-c2ccccc2-c2ccccc2)cc1)c1cccc(C)c1]

According to one embodiment of the present disclosure, the present disclosure may comprise an organic electroluminescent material comprising the organic electroluminescent compound described above.

According to one embodiment of the present disclosure, the present disclosure may comprise an organic electroluminescent device comprising the organic electroluminescent compound described above.

According to one embodiment of the present disclosure, the present disclosure may include an organic electroluminescent device comprising the organic electroluminescent compound described above in at least one layer selected from a light-emitting layer, a first hole transport layer, a second hole transport layer, a hole auxiliary layer, an electron-blocking layer, and a light-emitting auxiliary layer.

The compounds C-6, C-9, C-10, C-61, C-64, C-65, C-136, C-139, C-140, C-166, C-167, C-168, C-171, C-172, C-173, C-176, C-186, C-187, C-303, C-304, C-305, C-306, and C-307 according to the present disclosure may be synthesized by referring to synthetic methods known to one skilled in the art, and in particular, as synthetic method disclosed in a number of patent documents can be used. For example, it may be synthesized by referring to synthetic methods disclosed in Korean Patent Application Laid-Open Nos. 2015-0066202 (published on Jun. 16, 2015) and 2017-0124957 (published on Nov. 13, 2017), etc., but is not limited thereto.

An organic electroluminescent device according to one embodiment of the present disclosure may comprise an organic electroluminescent compound represented by Formula 1 and comprising at least one deuterium in at least one layer of a light-emitting layer, a first hole transport layer, a second hole transport layer, a hole auxiliary layer, an electron-blocking layer, and a light-emitting auxiliary layer. The light-emitting layer may include one or more hosts and one or more dopants. If necessary, the light-emitting layer may include a co-host material, i.e., two or more plurality of host materials.

The host used in the present invention may be a phosphorescent host compound or a fluorescent host compound, and these host compounds are not particularly limited.

As the dopant included in the organic electroluminescent device of the present disclosure, one or more phosphorescent or fluorescent dopants may be used, and a phosphorescent dopant is preferred. The phosphorescent dopant material applied to the organic electroluminescent device of the present disclosure is not particularly limited, but may be a complex compound(s) of a metal atom(s) selected from iridium (Ir), osmium (Os), copper (Cu), and platinum (Pt), in some cases preferably, an ortho-metallated complex compound(s) of a metal atom(s) selected from iridium (Ir), osmium (Os), copper (Cu), and platinum (Pt), and in some cases more preferably, ortho-metallated iridium complex compound(s).

The dopant included in the organic electroluminescent device of the present disclosure may use the compound represented by the following Formula 101 or 102, but is not limited thereto.

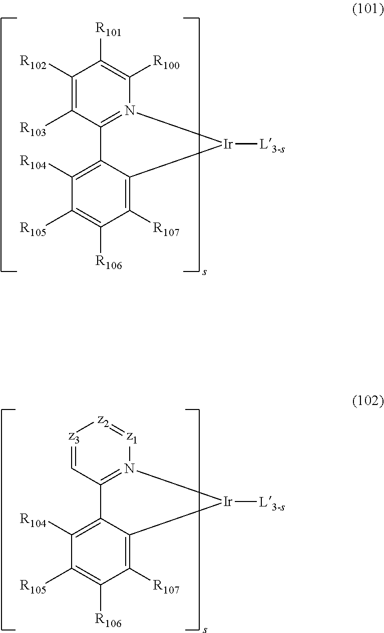

In Formula 101 and 102,
L′ is any one selected from the following Structures 1 to 3:

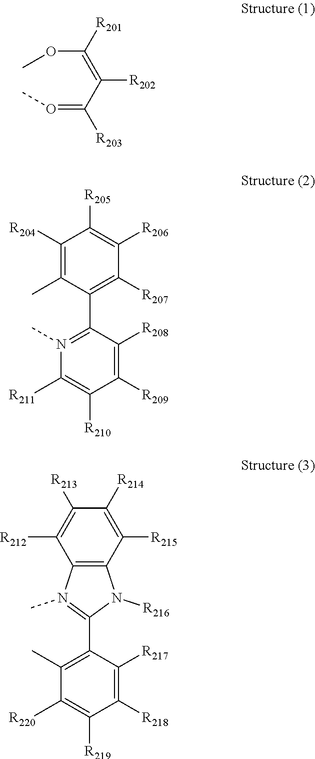

R₁₀₀ to R₁₀₃ each independently represent hydrogen, deuterium, halogen, (C₁-C₃₀)alkyl substituted or unsubstituted with deuterium and/or halogen, a substituted or unsubstituted (C₃-C₃₀)cycloalkyl, a substituted or unsubstituted (C₆-C₃₀)aryl, cyano, a substituted or unsubstituted (3- to 30-membered)heteroaryl, or a substituted or unsubstituted (C₁-C₃₀)alkoxy; or may be linked to the adjacent substituents to form a ring(s), for example, to form a ring(s) with a pyridine, e.g., a substituted or unsubstituted quinoline, a substituted or unsubstituted isoquinoline, a substituted or unsubstituted thienopyridine, a substituted or unsubstituted benzofuropyridine, a substituted or unsubstituted benzothienopyridine, a substituted or unsubstituted indenopyridine, a substituted or unsubstituted benzofuroquinoline, a substituted or unsubstituted benzothienoquinoline, or a substituted or unsubstituted indenoquinoline;
R₁₀₄ to R₁₀₇ each independently represent hydrogen, deuterium, halogen, (C₁-C₃₀)alkyl substituted or unsubstituted with deuterium and/or halogen, a substituted or unsubstituted (C₃-C₃₀)cycloalkyl, a substituted or unsubstituted (C₆-C₃₀)aryl, a substituted or unsubstituted (3- to 30-membered)heteroaryl, cyano, a substituted or unsubstituted (C₁-C₃₀)alkoxy, or a substituted or unsubstituted di(C₁-C₃₀)alkylamino; or may be linked to an adjacent substituent(s) to form a substituted or unsubstituted ring(s), for example, to form a ring(s) with a benzene, e.g., a substituted or unsubstituted naphthalene, a substituted or unsubstituted fluorene, a substituted or unsubstituted dibenzothiophene, a substituted or unsubstituted dibenzofuran, a substituted or unsubstituted indenopyridine, a substituted or unsubstituted benzofuropyridine, or a substituted or unsubstituted benzothienopyridine;
R₂₀₁ to R₂₂₀ each independently represent hydrogen, deuterium, halogen, (C₁-C₃₀)alkyl substituted or unsubstituted with deuterium and/or halogen, a substituted or unsubstituted (C₃-C₃₀)cycloalkyl, a substituted or unsubstituted (C₆-C₃₀)aryl, a substituted or unsubstituted (C₁-C₃₀)alkoxy, or a substituted or unsubstituted di(C₁-C₃₀)alkylamino; or may be linked to an adjacent substituent(s) to form a substituted or unsubstituted ring(s); for example, to form a ring(s), e.g., a substituted or unsubstituted pentane, a substituted or unsubstituted propane, a substituted or unsubstituted isobutane, a substituted or unsubstituted 3-methylpentane, or a substituted or unsubstituted trifluoro2-methyl propane;
Z₁ to Z₃ each independently represent N or CK₁;
K₁ each independently represent hydrogen, deuterium, halogen, (C₁-C₃₀)alkyl substituted or unsubstituted with deuterium and/or halogen, a substituted or unsubstituted (C₃-C₃₀)cycloalkyl, a substituted or unsubstituted (C₆-C₃₀)aryl, cyano, a substituted or unsubstituted (3- to 30-membered)heteroaryl, or a substituted or unsubstituted (C₁-C₃₀)alkoxy; or may be linked to an adjacent substituent(s) to form a substituted or unsubstituted ring(s), for example, to form a ring(s), e.g., a substituted or unsubstituted benzo quinazoline, a substituted or unsubstituted benzo quinoxaline, a substituted or unsubstituted quinoxaline, a substituted or unsubstituted benzothienopyrimidine, a substituted or unsubstituted benzothienopyridine, a substituted or unsubstituted thienopyridine, a substituted or unsubstituted thienopyrimidine, or a substituted or unsubstituted benzothienopyridazine; and
s represents an integer of 1 to 3.

Specifically, specific examples of the dopant compound include the following, but are not limited thereto.

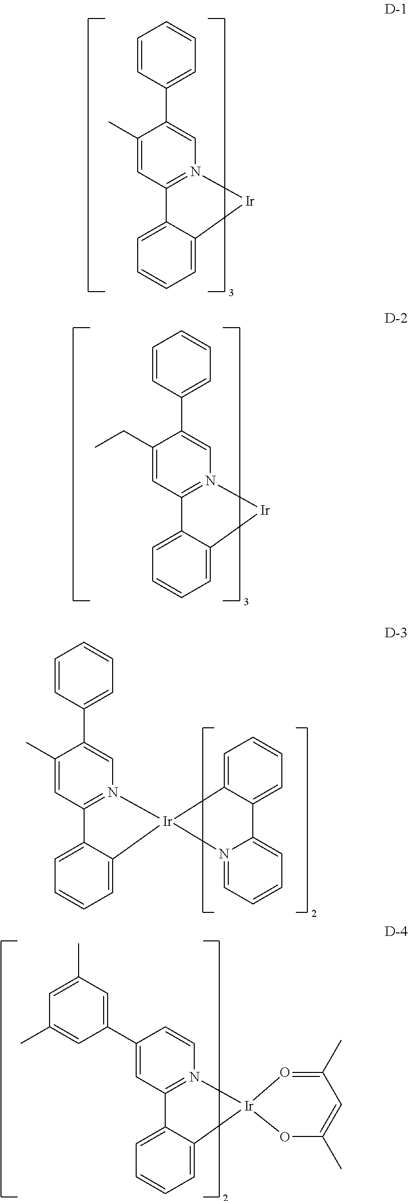

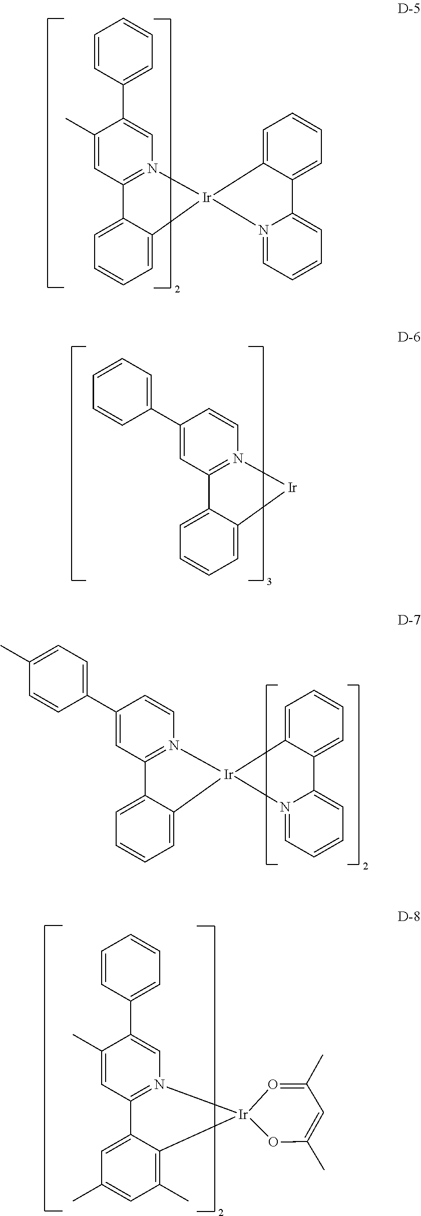

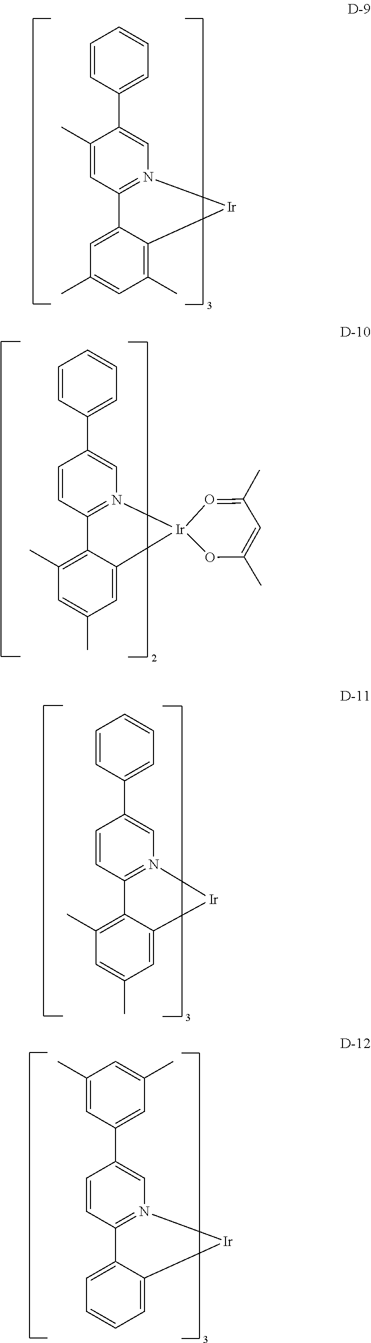

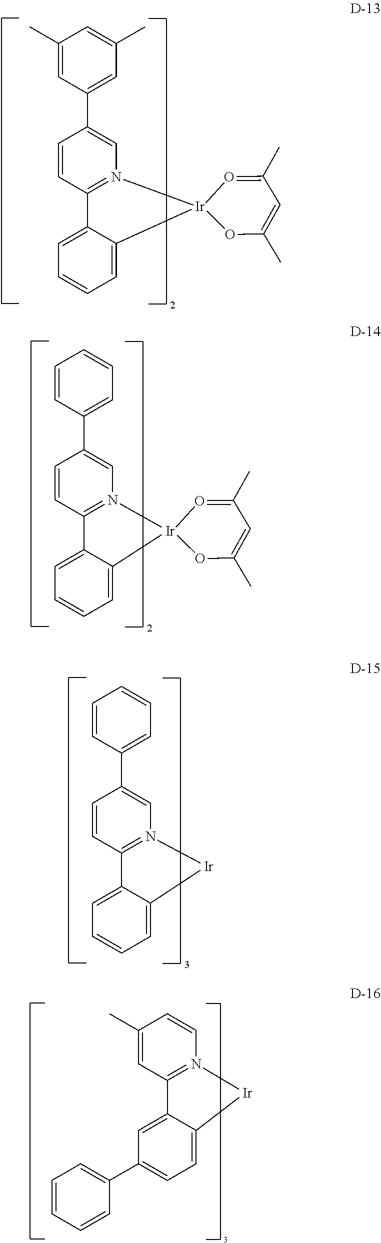

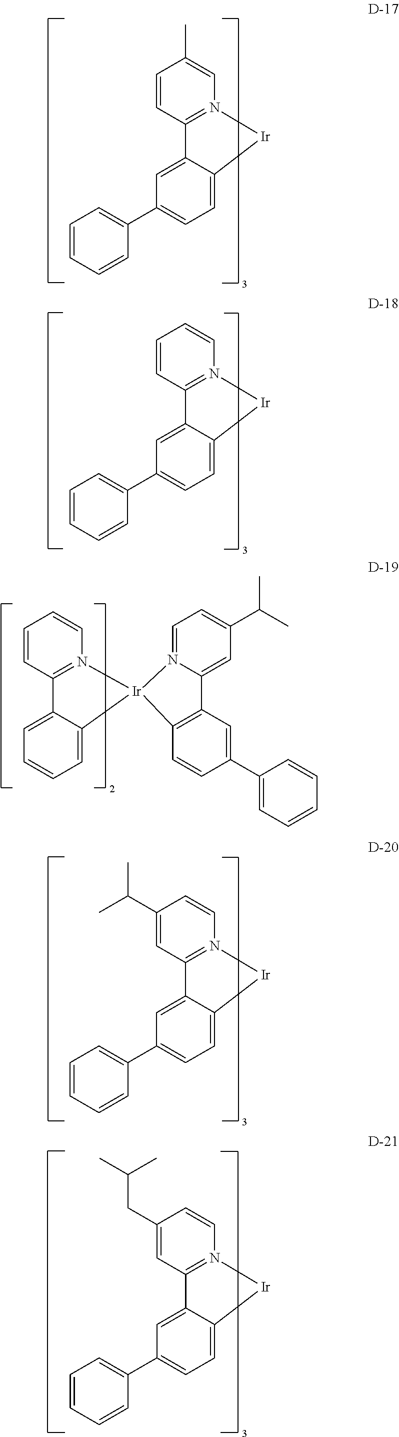

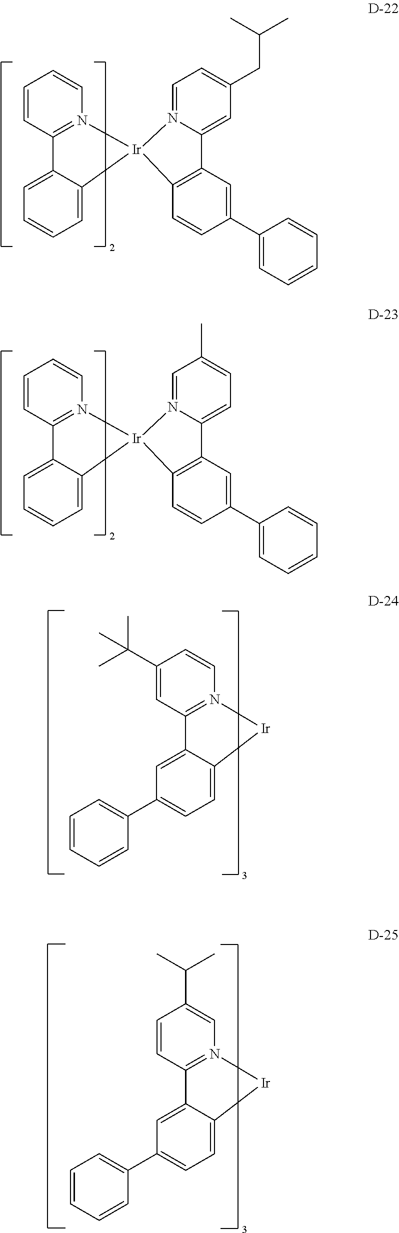

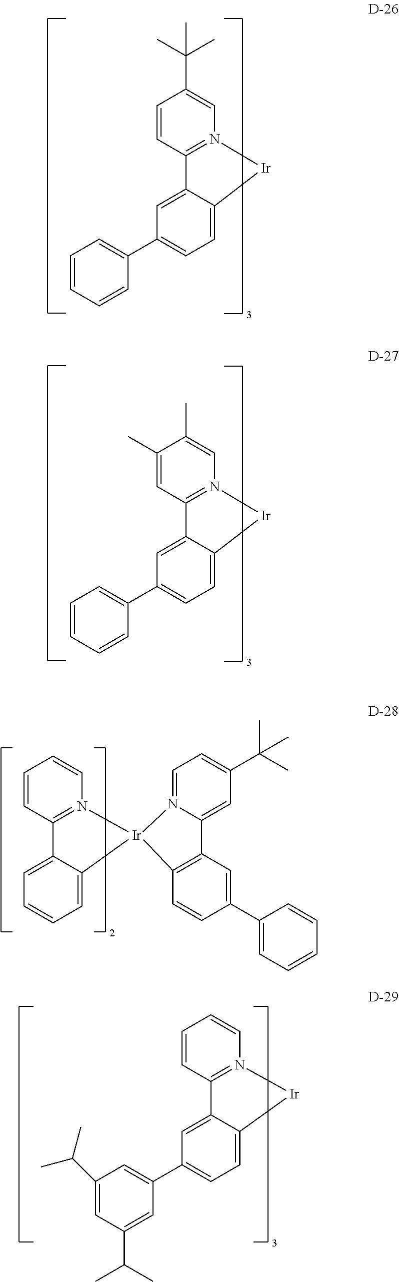

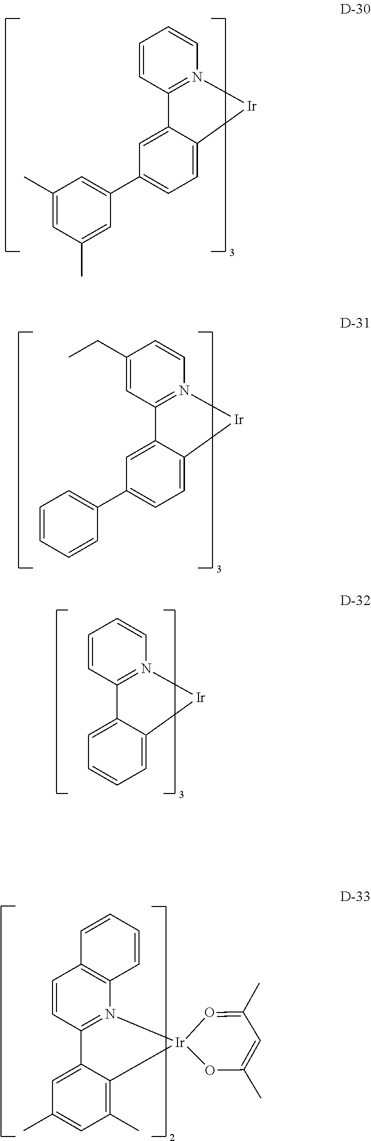

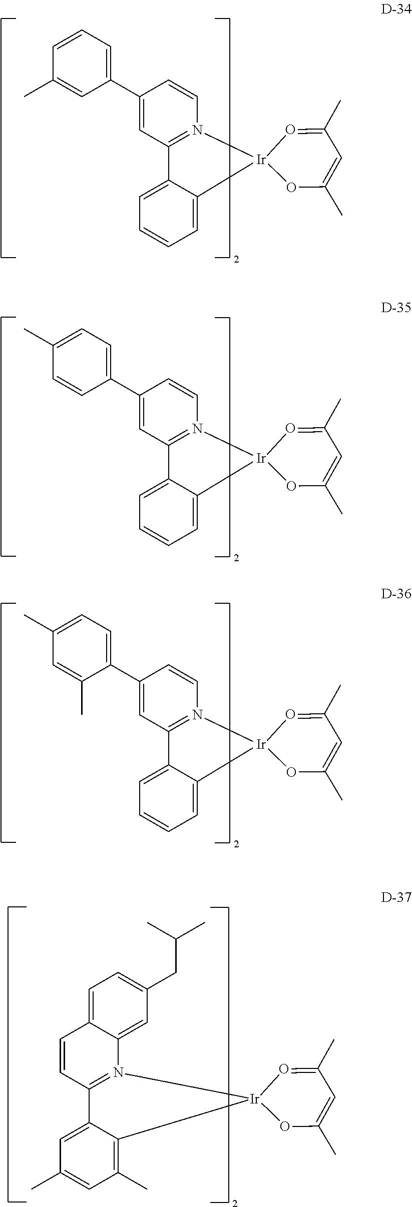

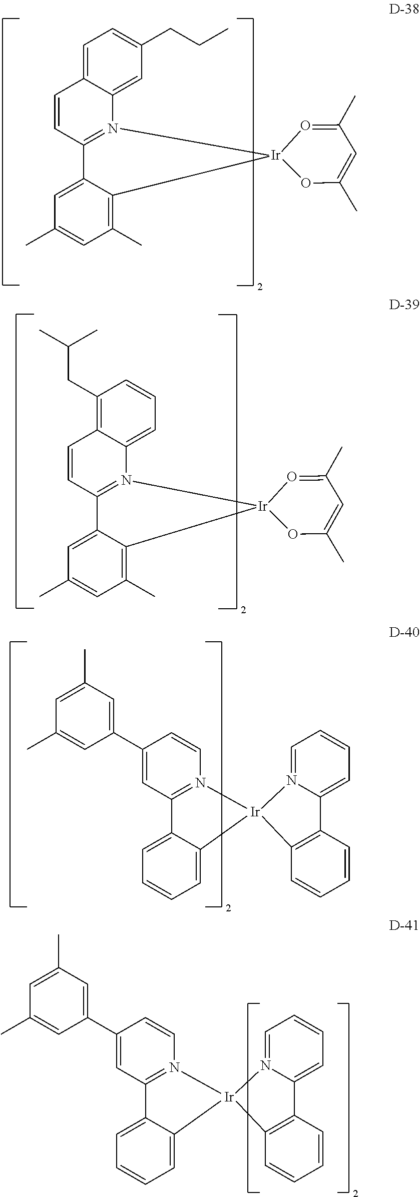

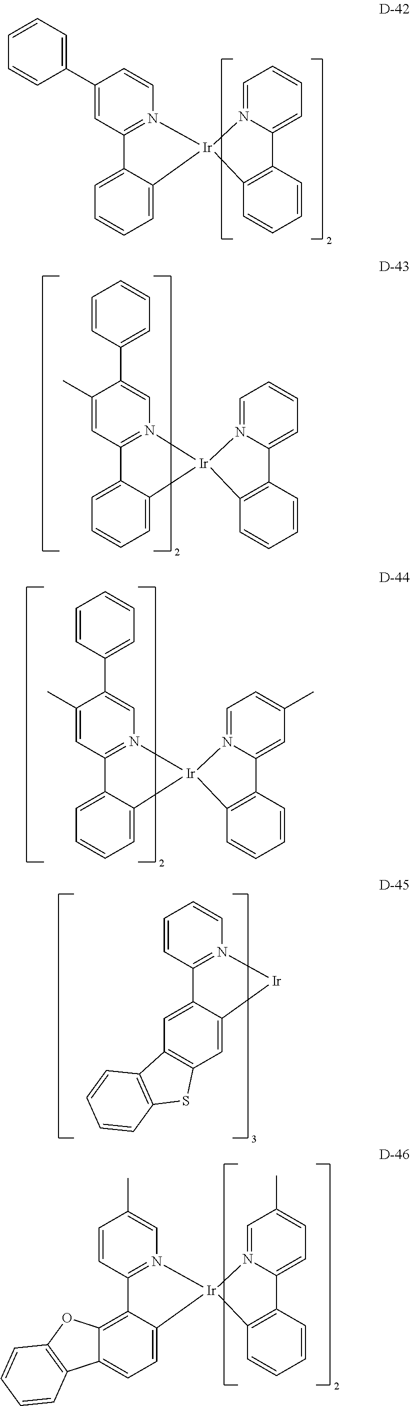

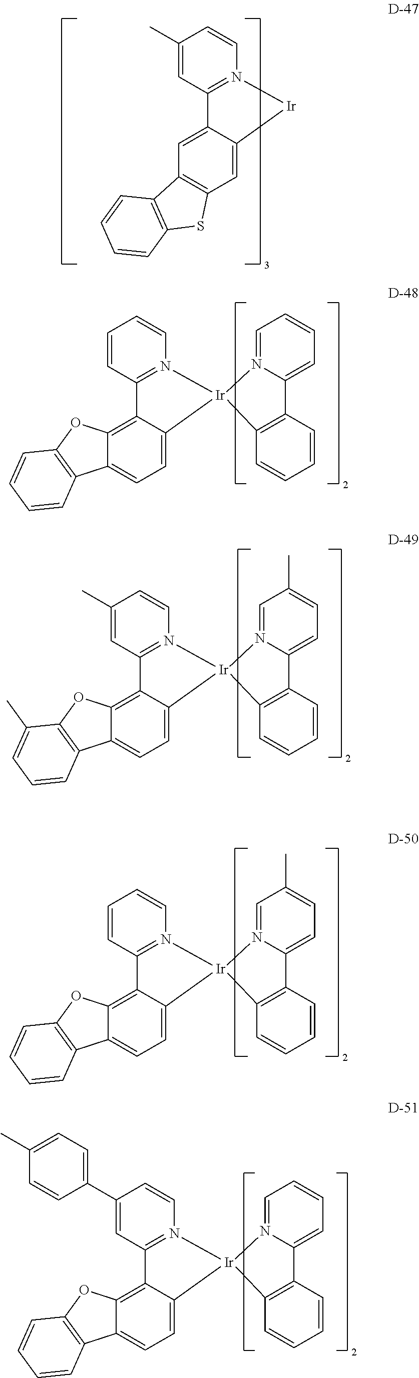

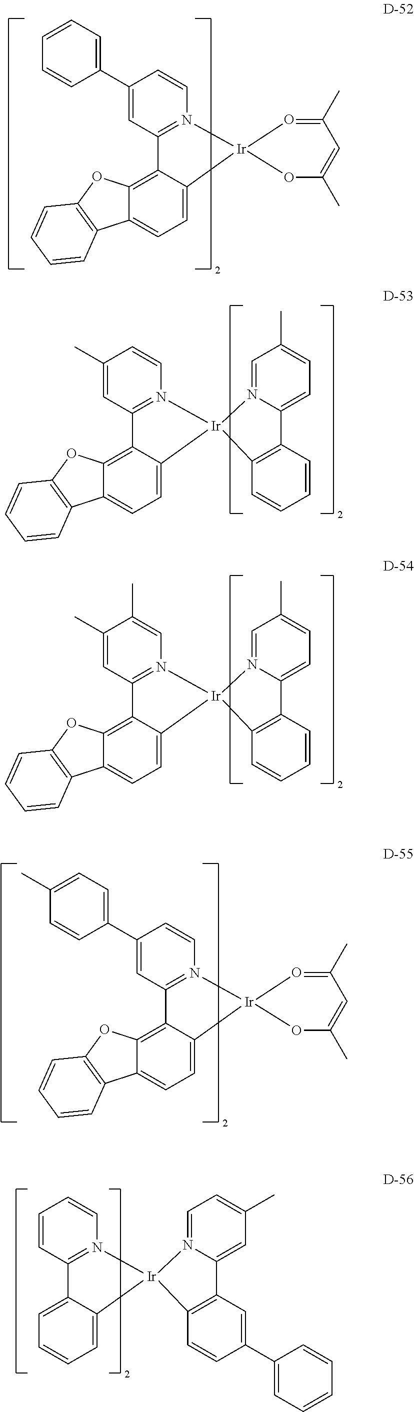

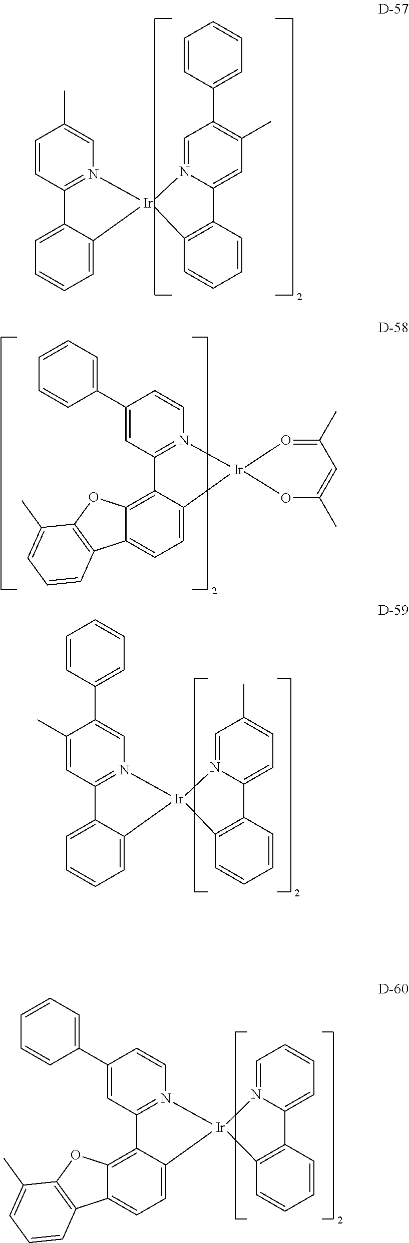

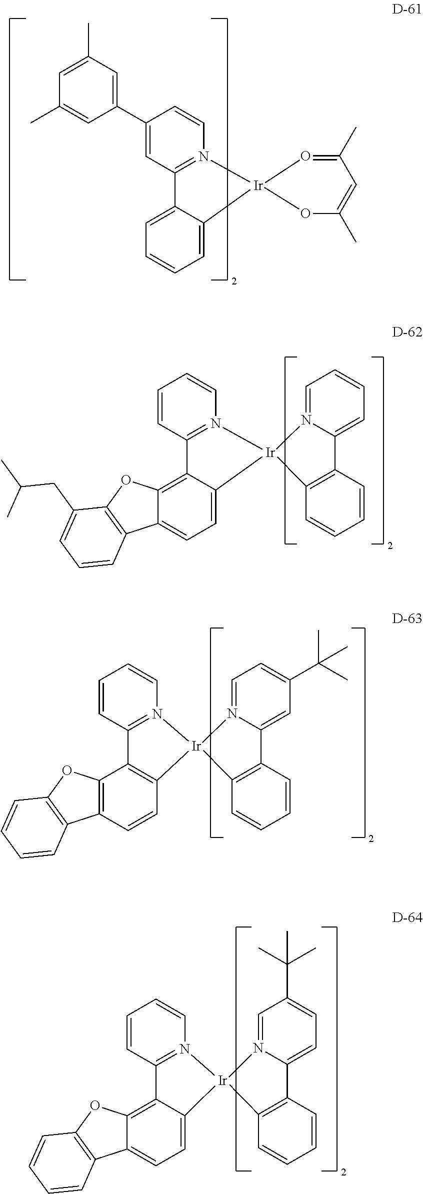

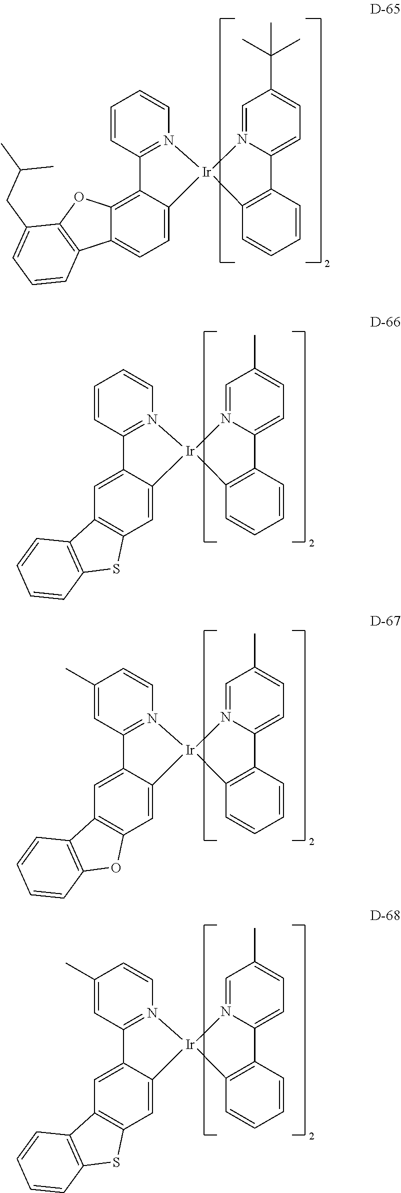

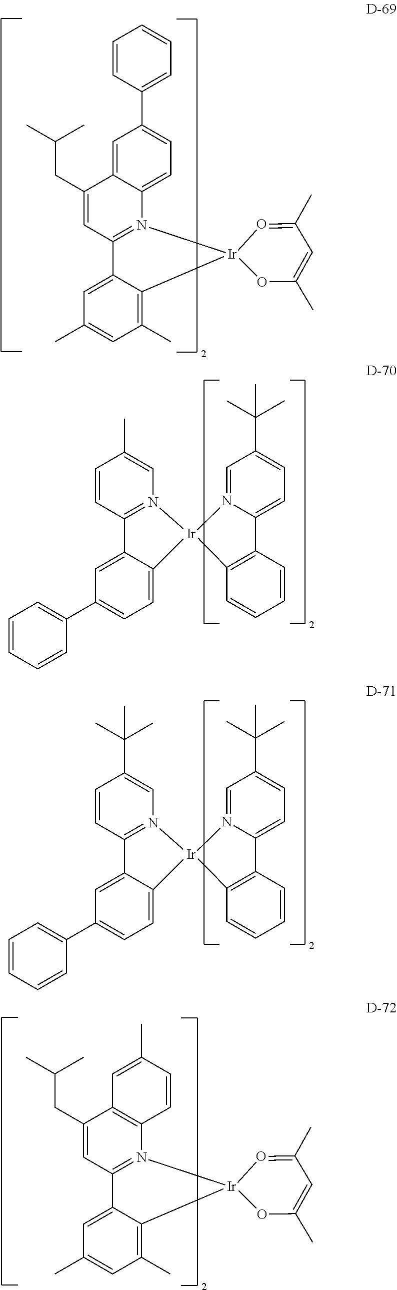

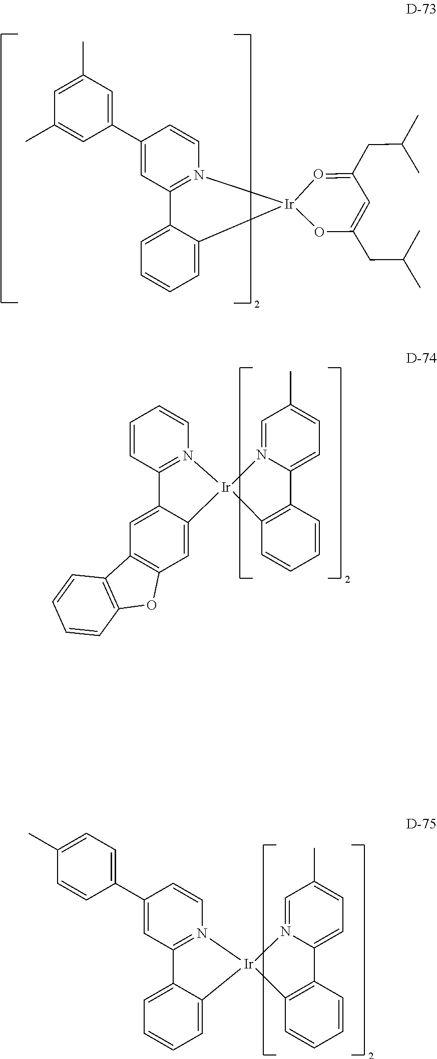

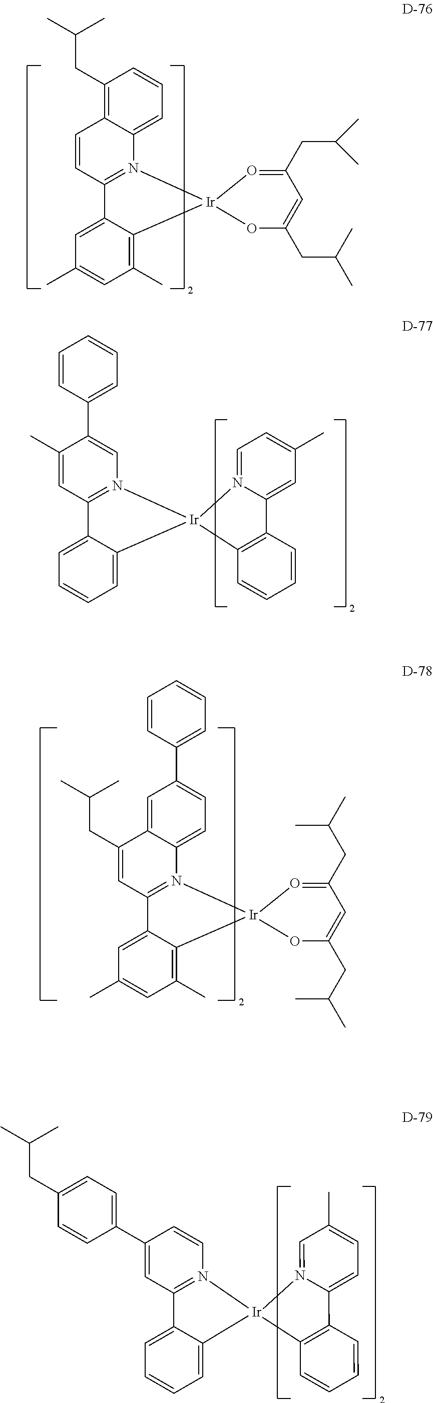

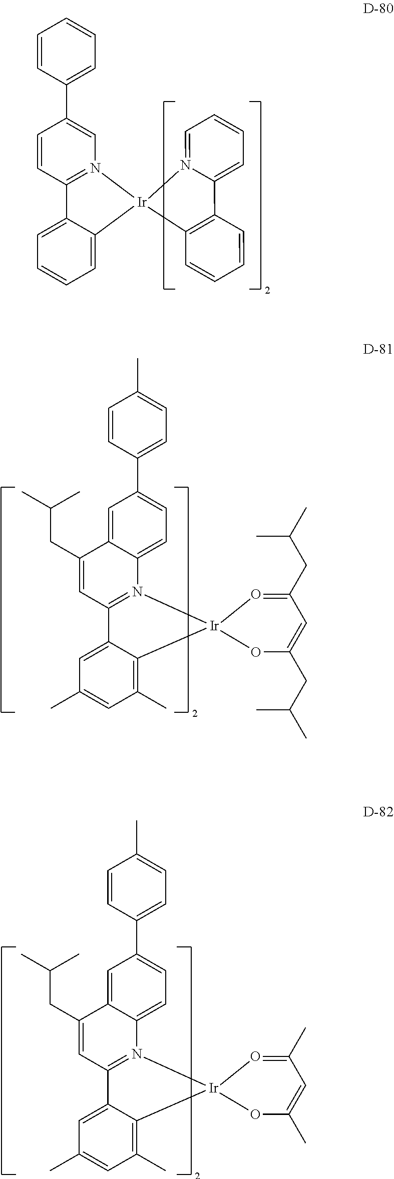

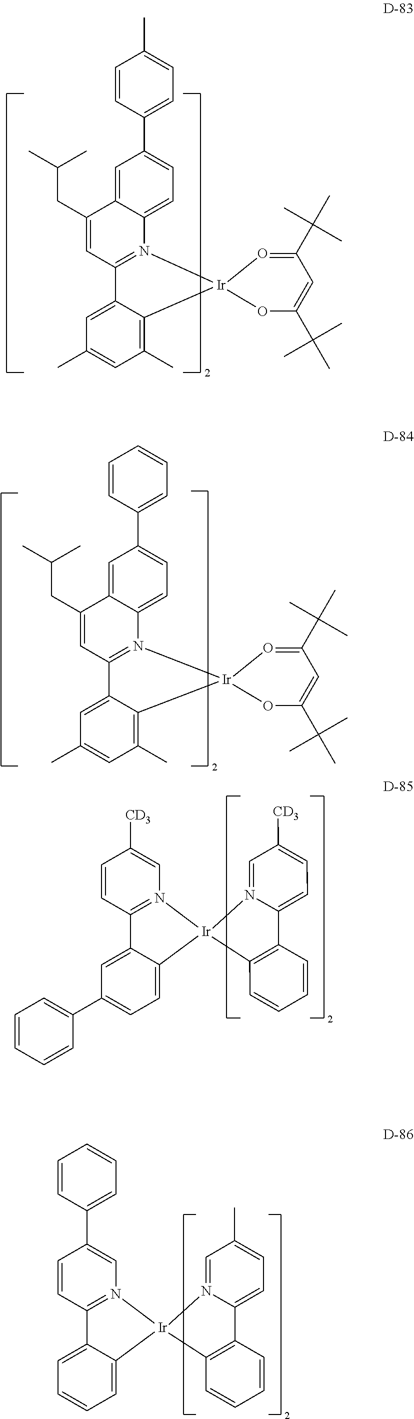

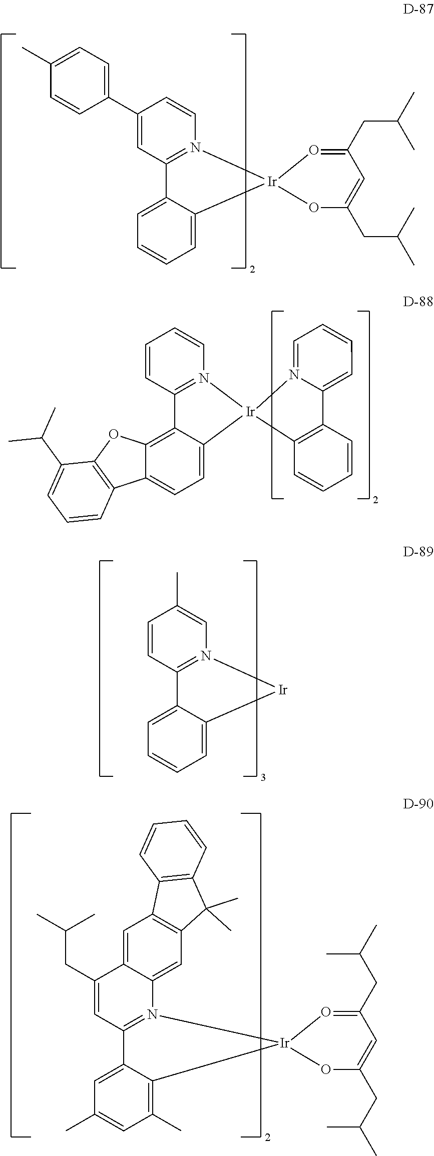

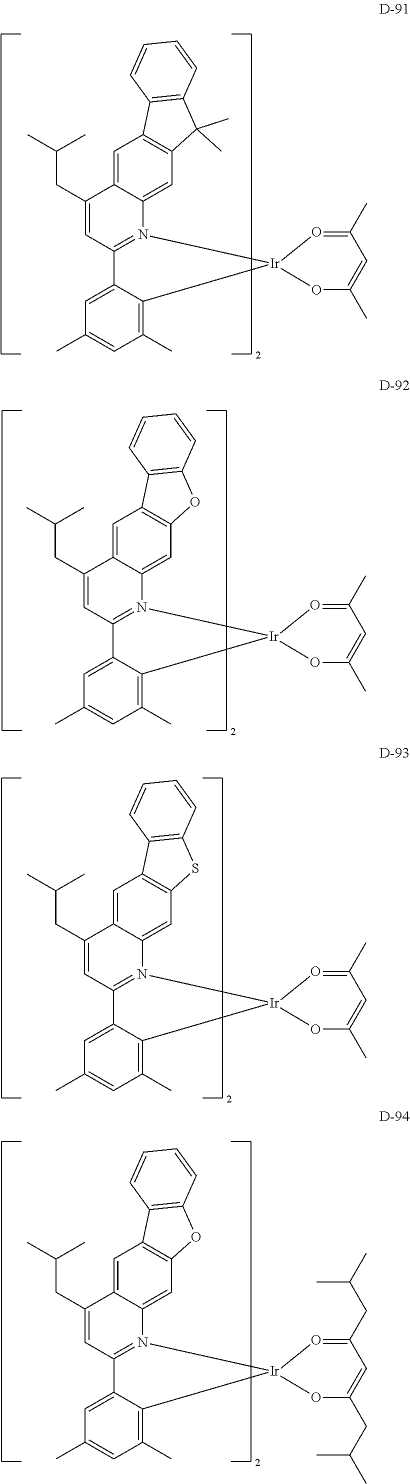

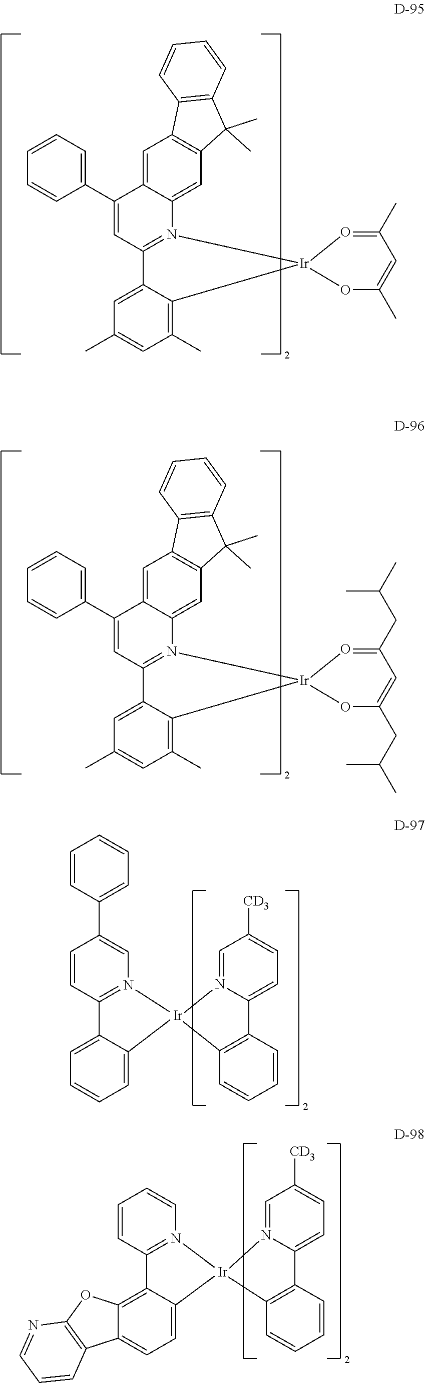

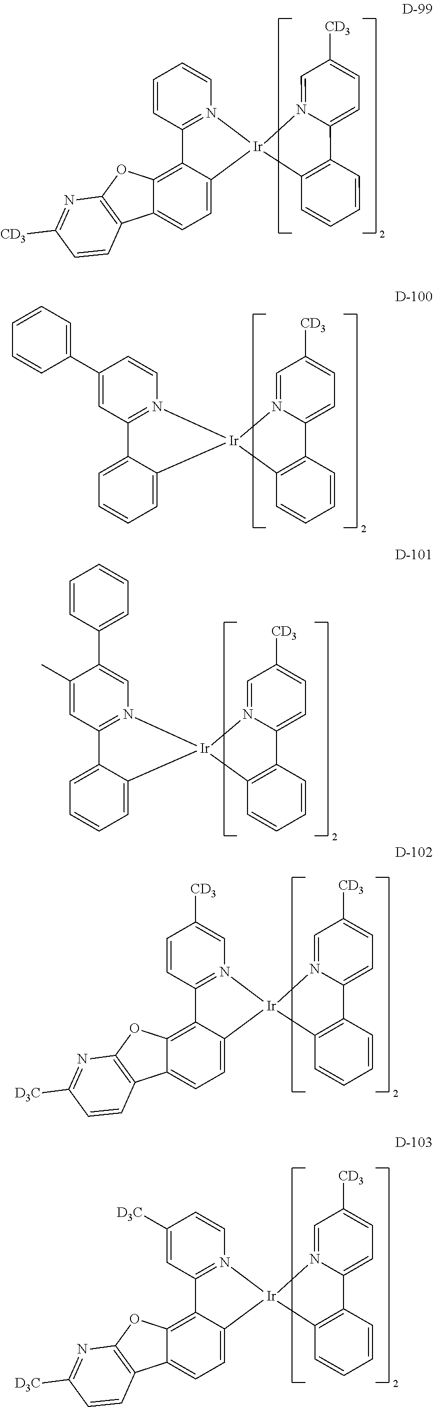

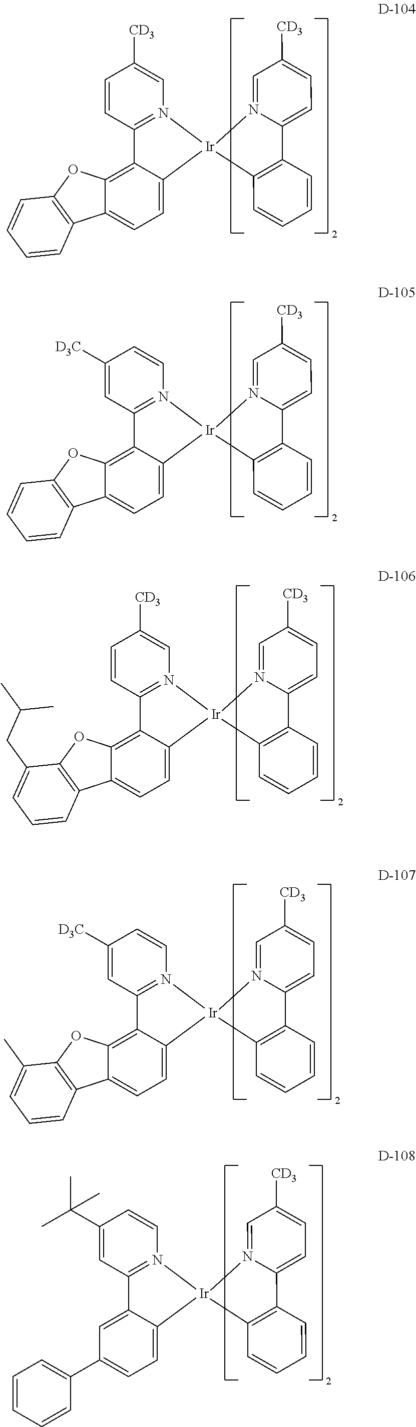

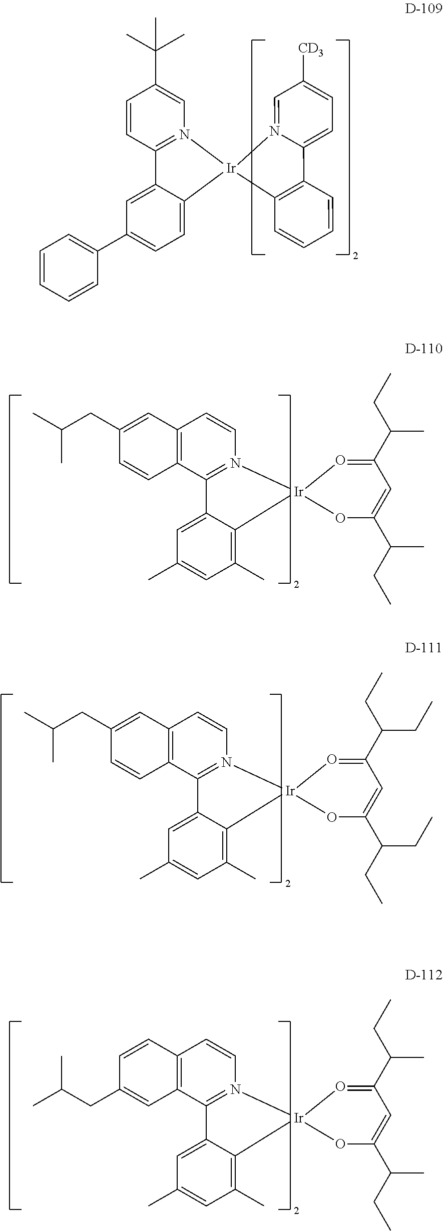

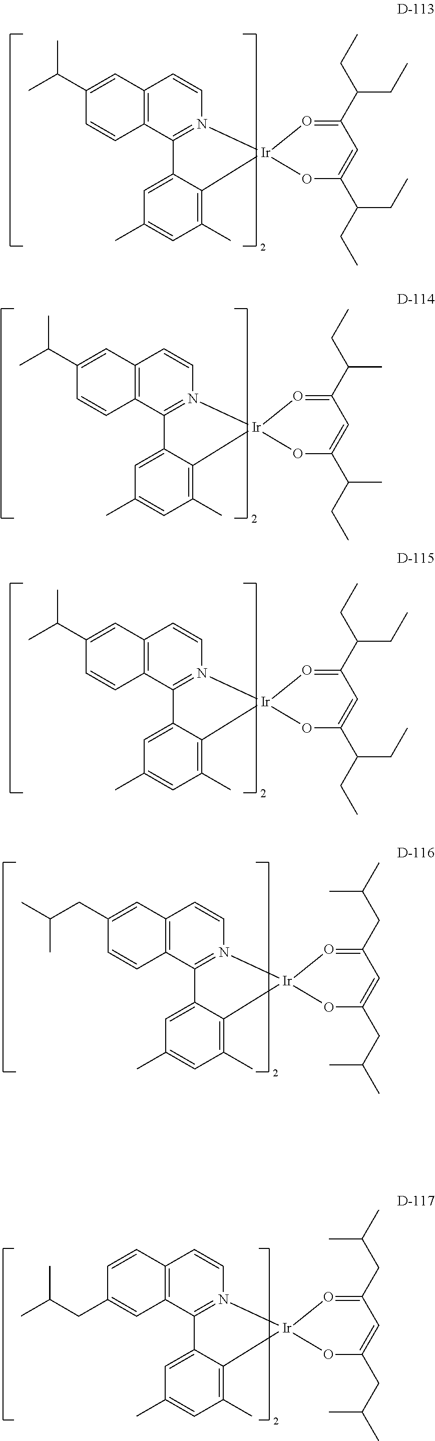

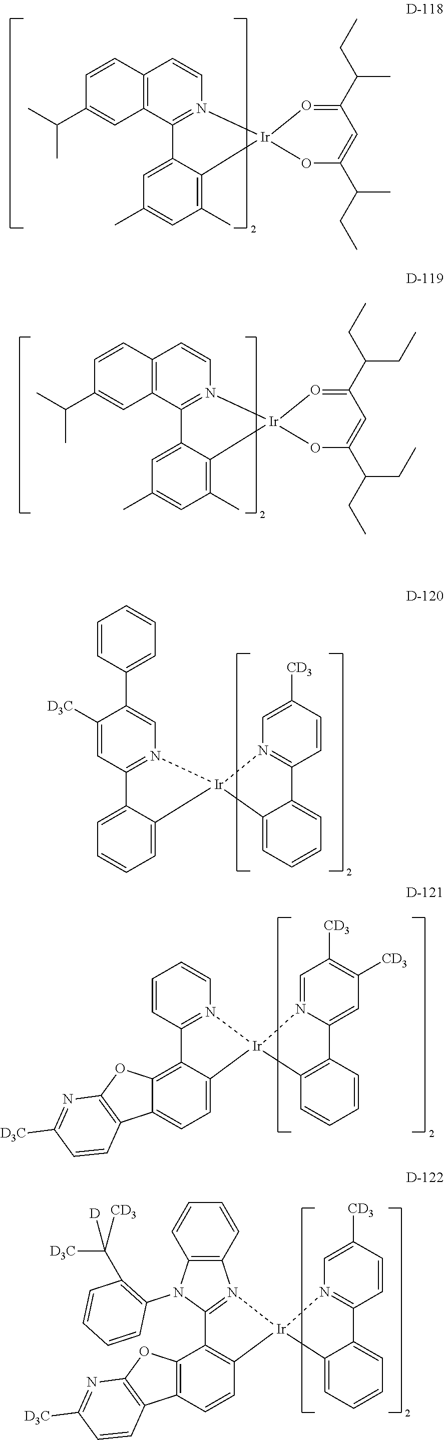

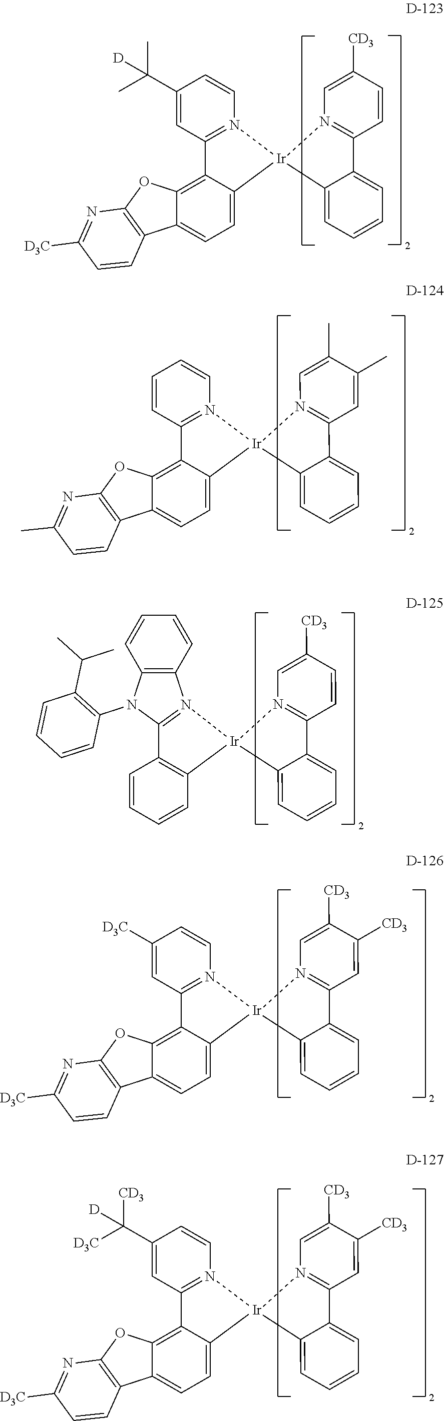

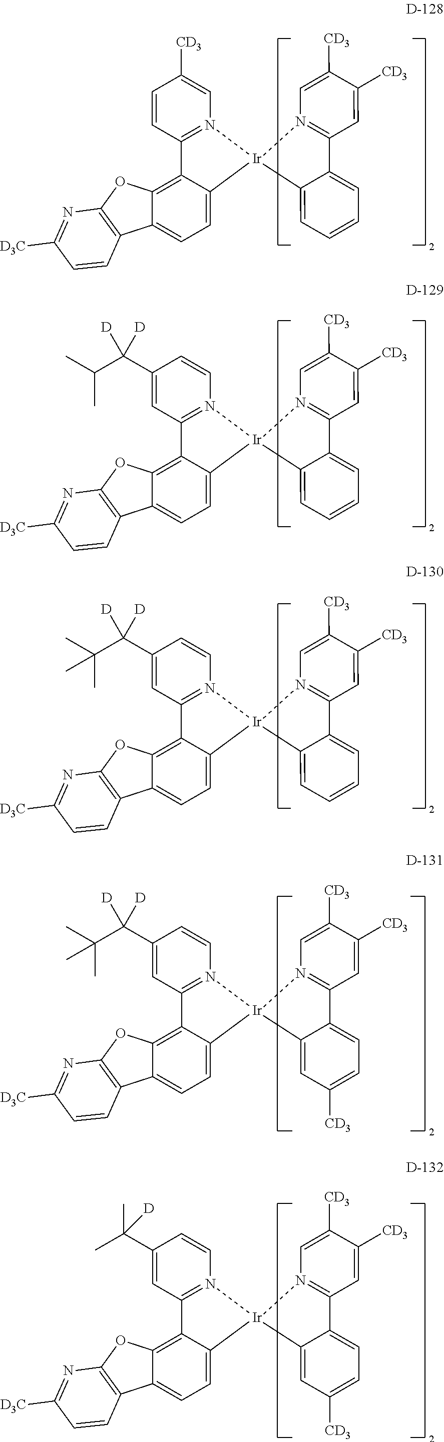

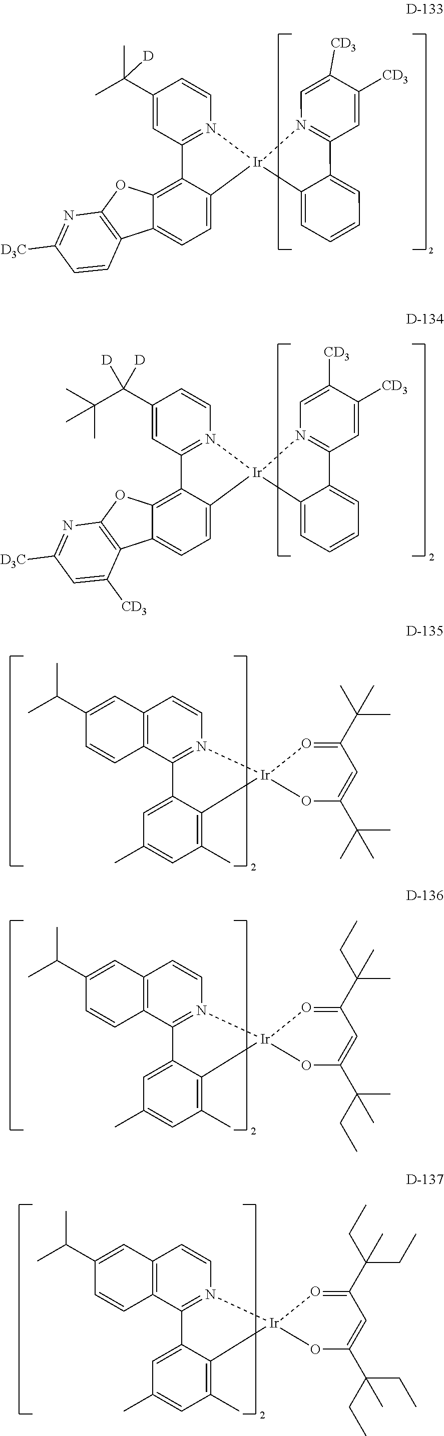

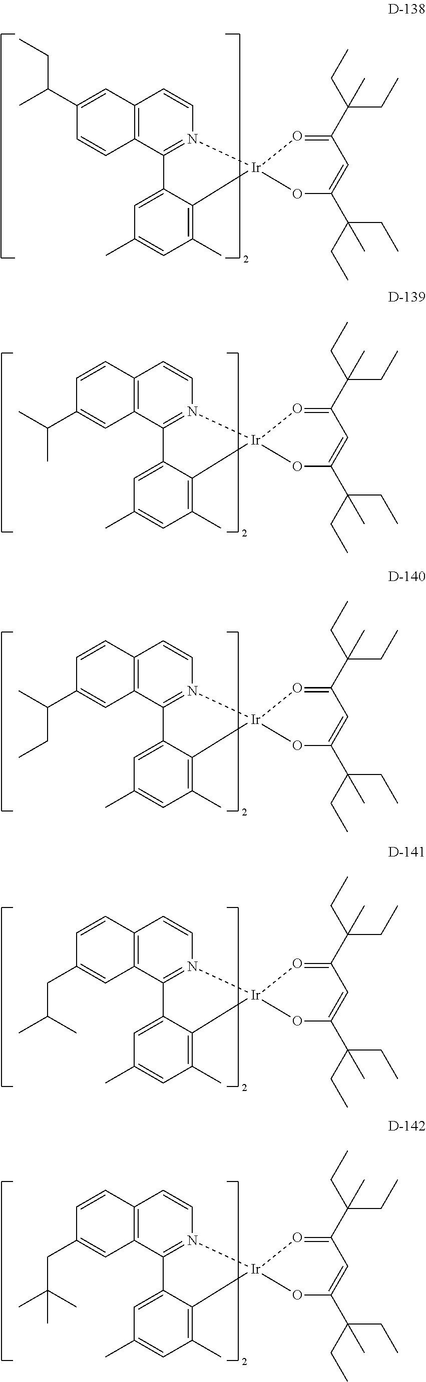

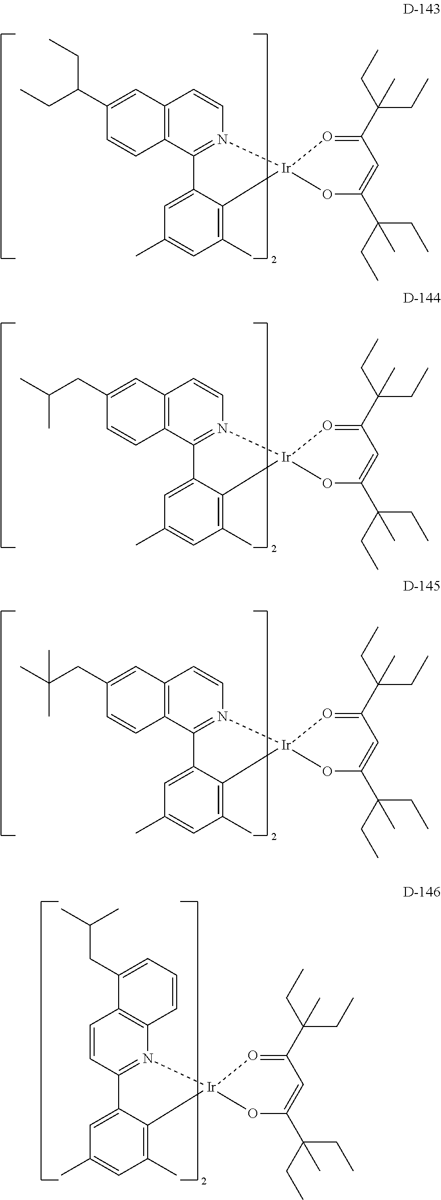

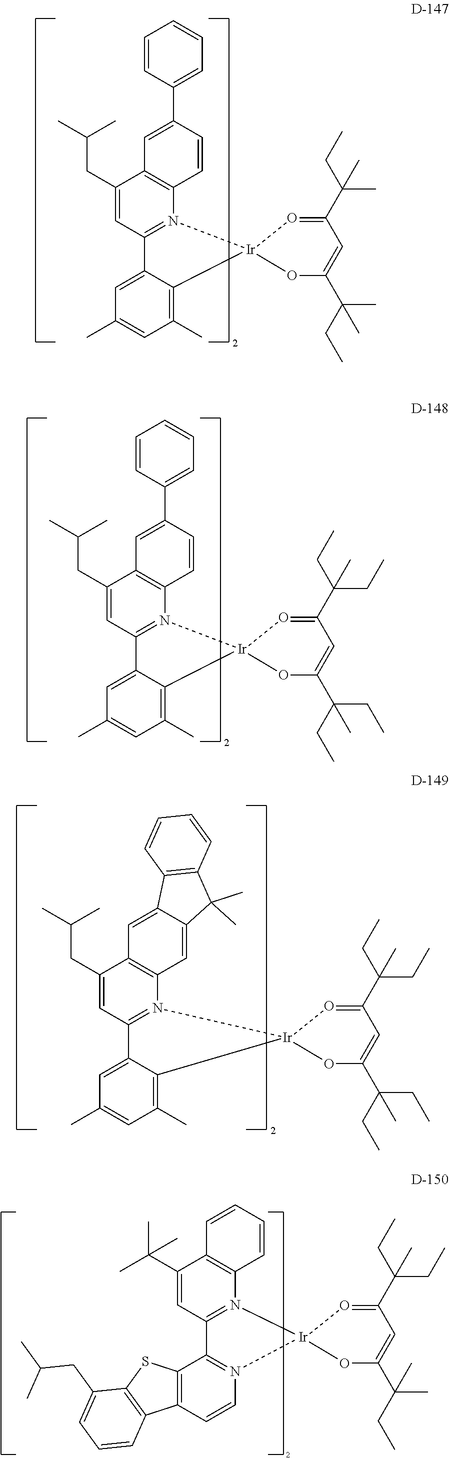

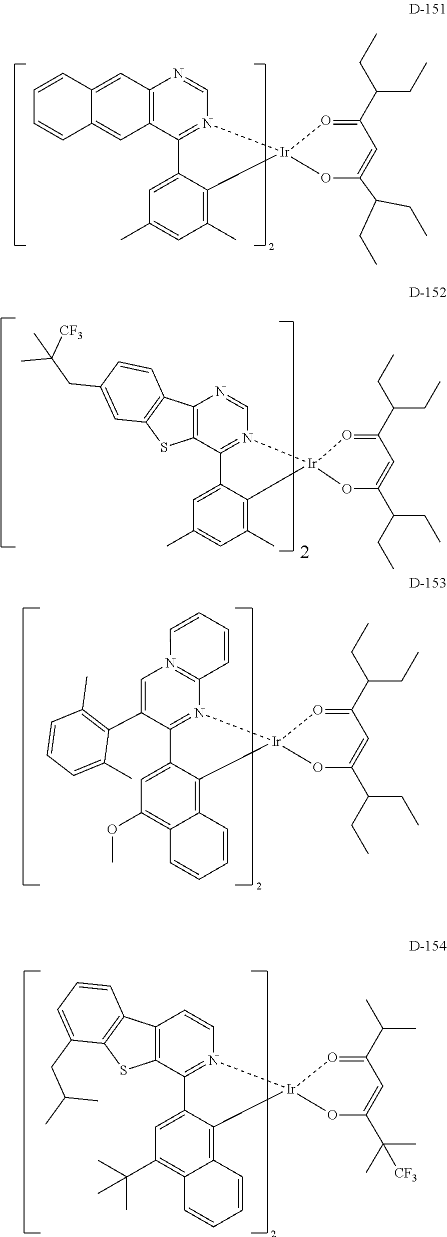

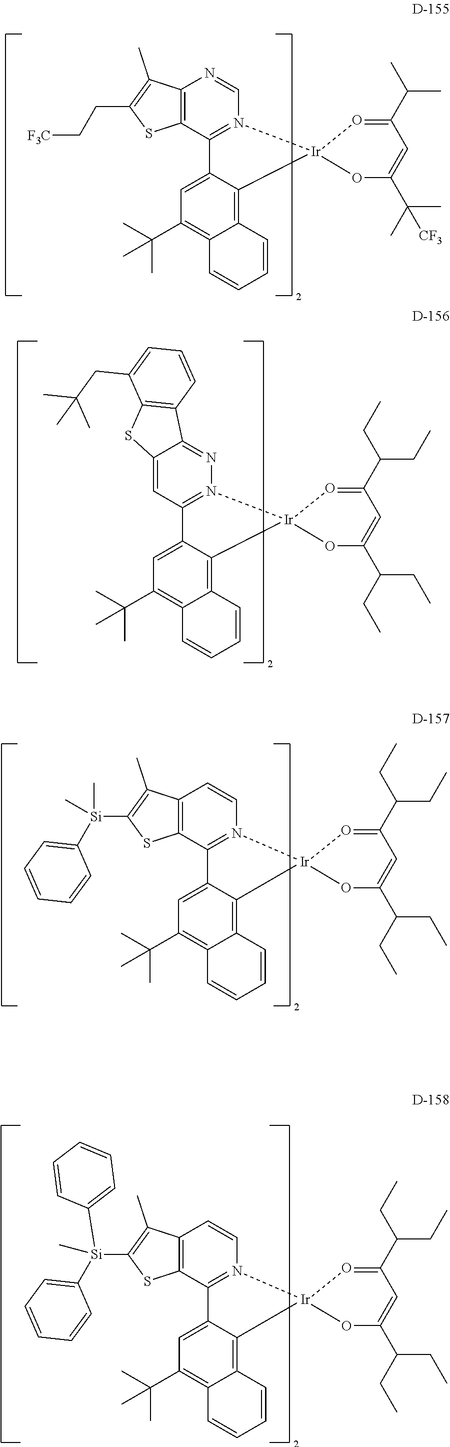

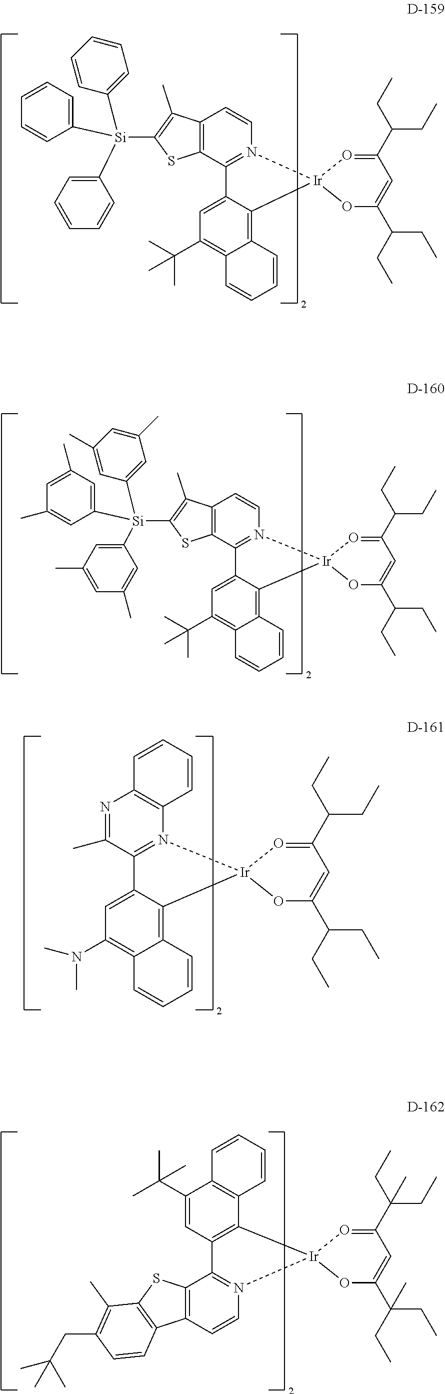

An organic electroluminescent device according to the present disclosure has an anode; a cathode; and at least one organic layer interposed between the anode and the cathode. The organic layer includes a light-emitting layer, and may further include at least one layer selected from a hole injection layer, a hole transport layer, a hole auxiliary layer, a light-emitting auxiliary layer, an electron transport layer, an electron buffer layer, an electron injection layer, an interlayer, a hole-blocking layer, and an electron-blocking layer. Each of the layers may be additionally composed of multiple layers.

The anode and cathode may each be formed of a transparent conductive material or a semi-transparent or reflective conductive material. The organic electroluminescent device may be a top emission type, a bottom emission type or a dual-side emission type according to the kinds of the material forming the anode and cathode. In addition, the hole injection layer may be further doped with a p-dopant, and the electron injection layer may be additionally doped with an n-dopant.

The organic layer may further include at least one compound selected from the group consisting of arylamine-based compounds and styrylarylamine-based compounds. Also, the organic layer may further include at least one metal selected from the group consisting of metals of Group 1, metals of Group 2, transition metals of the 4^{th} period, transition metals of the 5^{th} period, lanthanides, and organic metals of the d-transition elements of the Periodic Table, or at least one complex compound including such metals.

In addition, the organic electroluminescent device of the present disclosure may emit white light by further including one or more light-emitting layers including a blue, red, or green light-emitting compound known in the art in addition to the compound of the present disclosure. Additionally, if necessary, a yellow or orange light-emitting layer may be further included.

In the organic electroluminescent device of the present disclosure, preferably, at least one layer (hereinafter, “a surface layer”) selected from a chalcogenide layer, a halogenated metal layer, and a metal oxide layer may be placed on at least one of an inner surface(s) of a pair of electrodes. Specifically, a chalcogenide (including oxides) layer of silicon and aluminum is preferably placed on an anode surface of a light-emitting medium layer side, and a halogenated metal layer or a metal oxide layer is preferably placed on a cathode surface of a light-emitting medium layer side. The operation stability for the organic electroluminescent device may be obtained by the surface layer. Preferably, the chalcogenide includes SiOₓ (1≤X≤2), AlOₓ (1≤X≤1.5), SiON, SiAlON, etc.; the halogenated metal includes LiF, MgF₂, CaF₂, a rare earth metal fluoride, etc.; and the metal oxide includes Cs₂O, Li₂O, MgO, SrO, BaO, CaO, etc.

A hole injection layer, a hole transport layer, an electron-blocking layer, or a combination thereof can be used between the anode and the light-emitting layer. The hole injection layer may use a plurality of layers in order to lower the hole injection barrier (or hole injection voltage) from the anode to the hole transport layer or the electron-blocking layer, wherein each of the layers may use two compounds simultaneously. Also, the hole transport layer or the electron-blocking layer may use a plurality of layers.

An electron buffer layer, a hole-blocking layer, an electron transport layer, an electron injection layer, or a combination thereof can be used between the light-emitting layer and the cathode. The electron buffer layer may use a plurality of layers in order to control the injection of the electron and improve the interfacial properties between the light-emitting layer and the electron injection layer, wherein each of the layers may use two compounds simultaneously. Also, the hole-blocking layer or the electron transport layer may use a plurality of layers, wherein each of the layers may use a plurality of compounds.

The light-emitting auxiliary layer may be placed between the anode and the light-emitting layer, or between the cathode and the light-emitting layer. When the light-emitting auxiliary layer is placed between the anode and the light-emitting layer, it can be used for promoting the hole injection and/or the hole transport, or for preventing the overflow of electrons. When the light-emitting auxiliary layer is placed between the cathode and the light-emitting layer, it can be used for promoting the electron injection and/or the electron transport, or for preventing the overflow of holes. In addition, the hole auxiliary layer is placed between the hole transport layer (or hole injection layer) and the light-emitting layer, and may be effective to promote or block the hole transport rate (or the hole injection rate), thereby enabling the charge balance to be controlled. Also, the electron-blocking layer is placed between the hole transport layer (or hole injection layer) and the light-emitting layer, and can confine the excitons within the light-emitting layer by blocking the overflow of electrons from the light-emitting layer to prevent a light-emitting leakage. When an organic electroluminescent device includes two or more hole transport layers, the layer which is further included may use as the hole auxiliary layer or the electron-blocking layer. The light-emitting auxiliary layer, the hole auxiliary layer, or the electron-blocking layer has an effect of improving the efficiency and/or the lifespan of the organic electroluminescent device.

In addition, in the organic electroluminescent device of the present disclosure, a mixed region of an electron transport compound and a reductive dopant, or a mixed region of a hole transport compound and an oxidative dopant, may be placed on at least one surface of a pair of electrodes. In this case, the electron transport compound is reduced to an anion, and thus it becomes easier to inject and transport electrons from the mixed region to a light-emitting medium. Furthermore, the hole transport compound is oxidized to a cation, and thus it becomes easier to inject and transport holes from the mixed region to a light-emitting medium. Preferably, the oxidative dopant includes various Lewis acids and acceptor compounds, and the reductive dopant includes alkali metals, alkali metal compounds, alkaline earth metals, rare-earth metals, and mixtures thereof. Also, a reductive dopant layer may be employed as a charge generation layer to manufacture an organic electroluminescent device having two or more light-emitting layers and emitting white light.

The organic electroluminescent device according to one embodiment of the present disclosure may be an organic electroluminescent device having a tandem structure. In the case of a tandem organic electroluminescent device according to one embodiment, a single light-emitting unit (light-emitting part) may be formed in a structure in which two or more units are connected by a charge generation layer. The organic electroluminescent device may include a plurality of two or more light-emitting units, for example, a plurality of three or more light-emitting units, having first and second electrodes opposed to each other on a substrate and a light-emitting layer stacked between the first and second electrodes to emit light in a specific wavelength range. The organic electroluminescent device may include a plurality of light-emitting units, and each of the light-emitting units may include a hole transport band, a light-emitting layer and an electron transport band, and the hole transport band may include a hole injection layer and a hole transport layer, and the electron transport band may include an electron transport layer and an electron injection layer. According to one embodiment, three or more light-emitting layers may be included in the light-emitting unit. A plurality of light-emitting units may emit the same color or different colors. Additionally, one light-emitting unit may include one or more light-emitting layers, and the plurality of light-emitting layers may be light-emitting layers of the same or different colors. It may include one or more charge generation layers placed between each of light-emitting unit. The charge generation layer refers to the layer in which holes and electrons are generated when voltage is applied. When there are three or more light-emitting units, a charge generation layer may be placed between each of light-emitting unit. Here, the plurality of charge generation layers may be the same as or different from each other. By disposing the charge generation layer between light-emitting units, current efficiency is increased in each of light-emitting unit and charges can be smoothly distributed. Specifically, the charge generation layer is provided between two adjacent stacks and can serve to drive a tandem organic electroluminescent device using only a pair of anodes and cathodes without a separate internal electrode placed between the stacks.

The charge generation layer may be composed of an N-type charge generation layer and a P-type charge generation layer, and the N-type charge generation layer may be doped with an alkali metals, an alkaline earth metals, or compounds of alkali metals and alkaline earth metals. The alkali metals may include one selected from the group consisting of Li, Na, K, Rb, Cs, Fr, Yb, and combinations thereof, and the alkaline earth metals may include one selected from the group consisting of Be, Mg, Ca, Sr, Ba, Ra, and combinations thereof. The P-type charge generation layer may be composed of metals or organic materials doped with a P-type dopant. For example, the metals may be composed of one or two or more alloys selected from the group consisting of Al, Cu, Fe, Pb, Zn, Au, Pt, W, In, Mo, Ni, and Ti. Additionally, commonly used materials may be used as the P-type dopant and host materials used in the P-type doped organic materials.

The organic electroluminescent material according to one embodiment of the present disclosure may be used as a light-emitting material for a white organic light-emitting device. The white organic light-emitting device has been suggested various structures such as side-by-side structure, a stacking structure depending on the arrangement of R (red), G (green) or YG (yellowish green), B (blue) light-emitting units, or a color conversion material (CCM) method, etc. In addition, the organic electroluminescent material according to one embodiment of the present disclosure may also be used the organic electroluminescent device comprising a QD (quantum dot).

In order to form each layer of the organic electroluminescent device of the present disclosure, dry film-forming methods such as vacuum evaporation, sputtering, plasma, ion plating methods, etc. or wet film-forming methods such as inkjet printing, nozzle printing, slot coating, spin coating, dip coating, flow coating methods, etc. can be applied. When the first and second host compounds of the present disclosure are used to form a film, the process is performed by co-deposition or mixed deposition.

When using a wet film-forming method, a thin film may be formed by dissolving or diffusing materials forming each layer into any suitable solvent such as ethanol, chloroform, tetrahydrofuran, dioxane, etc. The solvent may be any solvent where the materials forming each layer can be dissolved or diffused, and where there are no problems in film-formation capability.

In addition, it is possible to produce display devices such as smartphones, tablets, notebooks, PCs, TVs, or display devices for vehicles, or lighting devices such as outdoor or indoor lighting by using the organic electroluminescent device of the present disclosure.

Hereinafter, for a detailed understanding of the present disclosure, a representative compound of the present disclosure is used to examine the preparation method of the compound according to the present disclosure and its physical properties, and the current efficiency of an OLED including an organic electroluminescent compound according to the present disclosure. The following examples are intended only to explain the properties of compounds according to the present disclosure and OLEDs including the same for a detailed understanding of the present disclosure, and the present disclosure is not limited to the following examples.

Hereinafter, for a detailed understanding of the present disclosure, a method for preparing a compound according to the present disclosure will be described using a synthetic method of a representative compound or intermediate compound of the present disclosure as an example.

### [Example 1] Synthesis of Compound H1-145

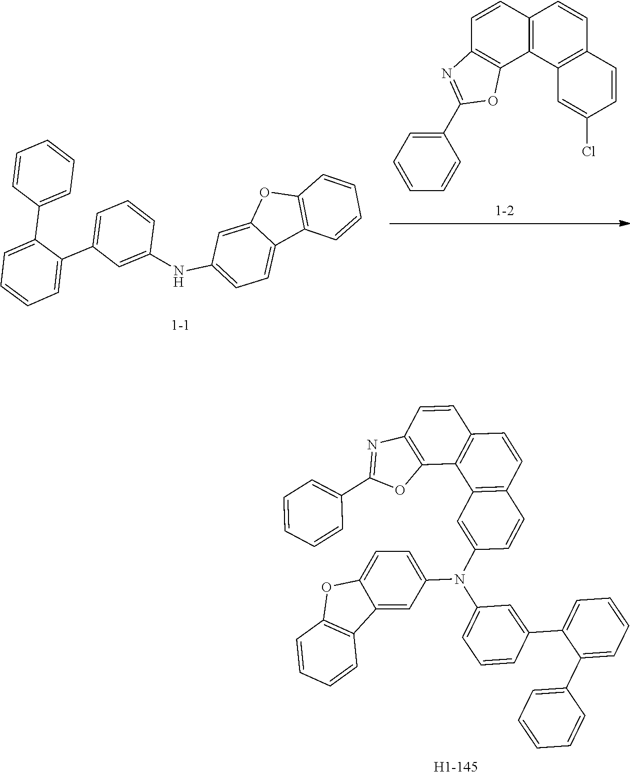

Compound 1-1 (15 g, 36.4 mmol), Compound 1-2 (10.9 g, 33.1 mmol), Pd₂(dba)₃ (1.56 g, 1.7 mmol), SPhos (1.35 g, 3.31 mmol), NaOtBu (6.36 g, 66.2 mmol), and 170 mL of xylene were mixed in a flask and stirred at 130° C. for 2 hours. After completion of the reaction, the mixture was cooled to room temperature, and the organic layer was extracted with ethyl acetate, and the remaining moisture was removed with magnesium sulfate. Thereafter, the organic layer was dried and separated by column chromatography to obtain Compound H1-145 (4.3 g, yield: 18%).

| | MW | M.P. |
|---|---|---|
| H1-145 | 704.83 | 230° C. |

### [Example 2] Synthesis of Compound H3-463

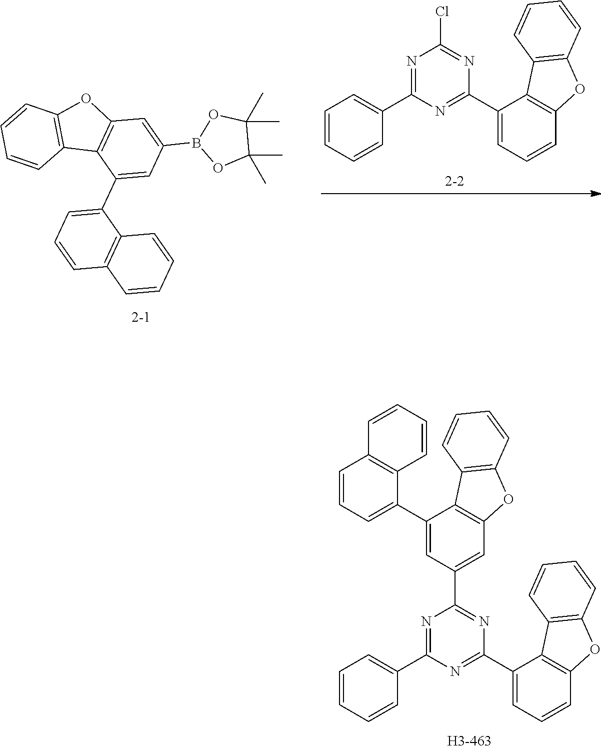

Compound 2-1 (10 g, 23.79 mmol), Compound 2-2 (8.5 g, 23.79 mmol), tetrakis(triphenylphosphine)palladium (0.8 g, 0.71 mmol), potassium carbonate (8.2 g, 59.48 mmol), 120 mL of toluene, 30 mL of ethanol, and 30 mL of distilled water were added to a flask, and the mixture was stirred at 120° C. for 2 hours. After completion of the reaction, the mixture was cooled to room temperature, and the organic layer was extracted with ethyl acetate. The extracted organic layer was dried over magnesium sulfate, and the solvent was removed using a rotary evaporator. The residue was then purified by column chromatography to obtain Compound H3-463 (1.8 g, yield: 12%).

| | MW | M.P. |
|---|---|---|
| H3-463 | 615.69 | 231° C. |

### [Example 3] Synthesis of Compound H2-159

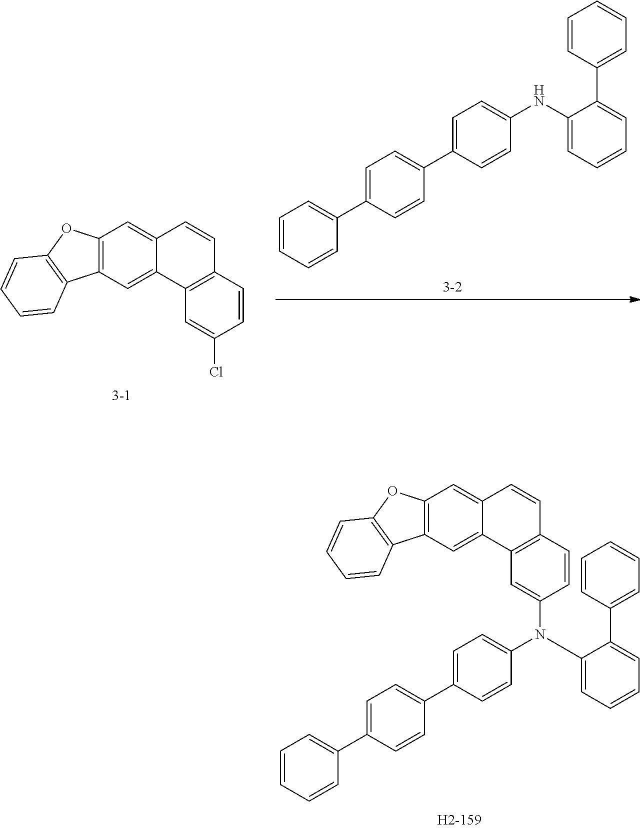 [SMILES: Clc1ccc2ccc3cc4oc5ccccc5c4cc3c2c1 ; c1ccc(-c2ccc(-c3ccc(Nc4ccccc4-c4ccccc4)cc3)cc2)cc1 ; c1ccc(-c2ccc(-c3ccc(N(c4ccc5ccc6cc7oc8ccccc8c7cc6c5c4)c4ccccc4-c4ccccc4)cc3)cc2)cc1]

Compound 3-1 (5.08 g, 16.77 mmol), Compound 3-2 (7.0 g, 17.66 mmol), Pd₂(dba)₃ (0.77 g, 0.84 mmol), SPhos (0.7 g, 1.68 mmol), and NaOtBu (2.42 g, 25.15 mmol) were dissolved in 84 mL of o-xylene in a flask and stirred under reflux at 160° C. for 4 hours. After completion of the reaction, the mixture was cooled to room temperature, and the layers were separated (EA/H₂O), filtered with celite, filtered with a silica filter to form a solid, and filtered to obtain Compound H2-159 (4.7 g, yield: 40%).

| | MW | M.P. |
|---|---|---|
| H2-159 | 663.8 | 257° C. |

### [Example 4] Synthesis of Compound H3-466

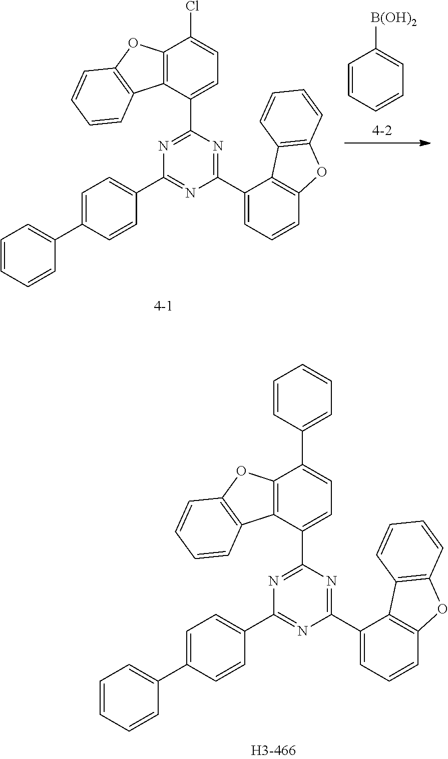

Compound 4-1 (14 g, 23.3 mmol), Compound 4-2 (3.5 g, 27.96 mmol), Pd₂(dba)₃ (1 g, 1.165 mmol), and SPhos (765 mg, 1.86 mmol) were dissolved in 120 mL of xylene in a flask and stirred under reflux at 160° C. for 1 hour. After completion of the reaction, the mixture was washed with distilled water, and the organic layer was extracted with ethyl acetate. The extracted organic layer was dried over magnesium sulfate, and the solvent was removed using a rotary evaporator. The residue was then purified by column chromatography to obtain Compound H3-466 (3 g, yield: 20%).

| | MW | M.P. |
|---|---|---|
| H3-466 | 641.73 | 242.2° C. |

### [Example 5] Synthesis of Compound H3-467

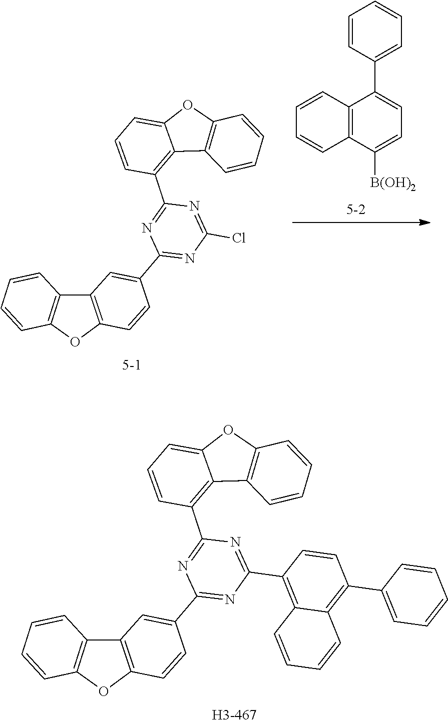

Compound 5-1 (5 g, 11.16 mmol), Compound 5-2 (2.8 g, 11.27 mmol), tetrakis(triphenylphosphine)palladium(0) (0.64 g, 0.56 mmol), potassium carbonate (3.8 g, 27.9 mmol), 60 mL of o-xylene, 15 mL of ethanol, and 15 mL of distilled water were added to a flask and stirred under reflux for 3 hours. After completion of the reaction, the mixture was added dropwise to methanol, and the resulting solid was filtered. The resulting solid was purified by column chromatography to obtain Compound H3-467 (5.5 g, yield: 80%).

| | MW | M.P. |
|---|---|---|
| H3-467 | 615.69 | 241° C. |

### [Example 6] Synthesis of Compound C-24

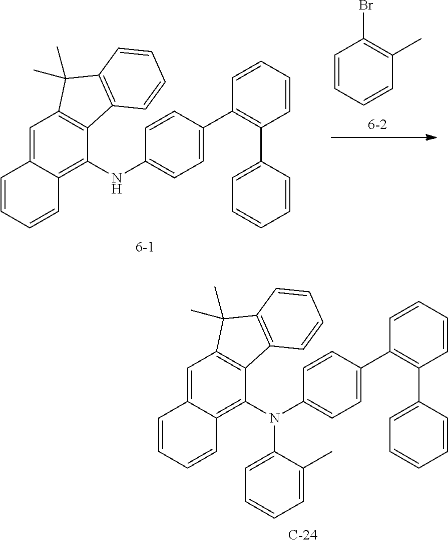

Compound 6-1 (11 g, 22.56 mmol), Compound 6-2 (7.72 g, 45.11 mmol), Pd₂(dba)₃ (1.03 g, 1.128 mmol), NaOtBu (6.5 g, 67.68 mmol), and P(tBu)₃ (456 mg, 2.256 mmol) were dissolved in toluene (113 mL, 0.2 M) in a flask and refluxed at 120° C. for 12 hours. After completion of the reaction, the mixture was cooled to room temperature, and the organic layer was extracted with ethyl acetate, and the remaining moisture was removed with magnesium sulfate. Thereafter, the organic layer was dried and separated by column chromatography to obtain Compound C-24 (11.4 g, yield: 87%).

| | MW | M.P. |
|---|---|---|
| C-24 | 577.97 | 193° C. |

### [Example 7] Synthesis of Compound H3-345

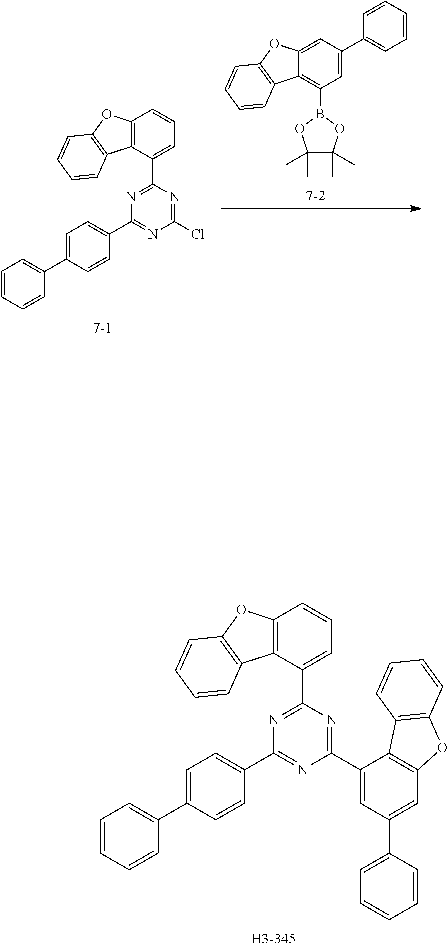 [SMILES: Clc1nc(-c2ccc(-c3ccccc3)cc2)nc(-c2cccc3oc4ccccc4c23)n1 ; CC1(C)OB(c2cc(-c3ccccc3)cc3oc4ccccc4c23)OC1(C)C ; c1ccc(-c2ccc(-c3nc(-c4cccc5oc6ccccc6c45)nc(-c4cc(-c5ccccc5)cc5oc6ccccc6c45)n3)cc2)cc1]

Compound 7-1 (5.8 g, 13.37 mmol), Compound 7-2 (4.9 g, 13.37 mmol), tetrakis(triphenylphosphine)palladium (0.77 g, 0.67 mmol), potassium carbonate (5.5 g, 40.10 mmol), 80 mL of toluene, 20 mL of ethanol, and 20 mL of distilled water were added to the reaction vessel, and the mixture was stirred at 120° C. for 2 hours. After completion of the reaction, the mixture was cooled to room temperature, and the organic layer was extracted with ethyl acetate. The extracted organic layer was dried over magnesium sulfate and the solvent was removed using a rotary evaporator. The residue was then purified by column chromatography to obtain Compound H3-345 (5.6 g, yield: 64%).

| | MW | M.P. |
|---|---|---|
| H3-345 | 651.7 | 199.8° C. |

### [Example 8] Synthesis of Compound H3-456

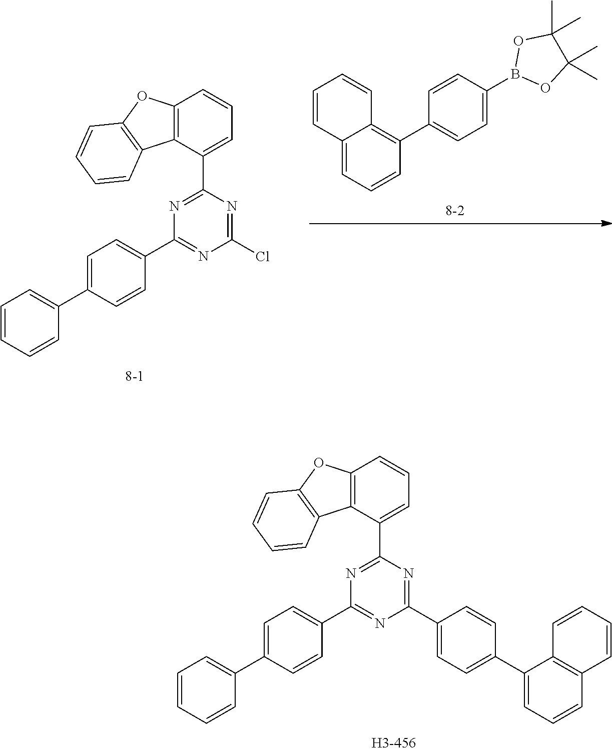 [SMILES: Clc1nc(-c2ccc(-c3ccccc3)cc2)nc(-c2cccc3oc4ccccc4c23)n1 ; CC1(C)OB(c2ccc(-c3cccc4ccccc34)cc2)OC1(C)C ; c1ccc(-c2ccc(-c3nc(-c4ccc(-c5cccc6ccccc56)cc4)nc(-c4cccc5oc6ccccc6c45)n3)cc2)cc1]

Compound 8-1 (9.8 g, 22.59 mmol), Compound 8-2 (7.46 g, 22.59 mmol), tetrakis(triphenylphosphine)palladium (1.3 g, 1.129 mmol), potassium carbonate (9.3 g, 67.76 mmol), 120 mL of toluene, 30 mL of ethanol, and 30 mL of distilled water were added to the reaction vessel, and the mixture was stirred at 120° C. for 2 hours. After completion of the reaction, the mixture was cooled to room temperature, and the organic layer was extracted with ethyl acetate. The extracted organic layer was dried over magnesium sulfate, and the solvent was removed using a rotary evaporator. The residue was then purified by column chromatography to obtain Compound H3-456 (6.8 g, yield: 50%).

| | MW | M.P. |
|---|---|---|
| H3-456 | 601.6 | 209.4° C. |

### [Example 9] Synthesis of Compound H1-163

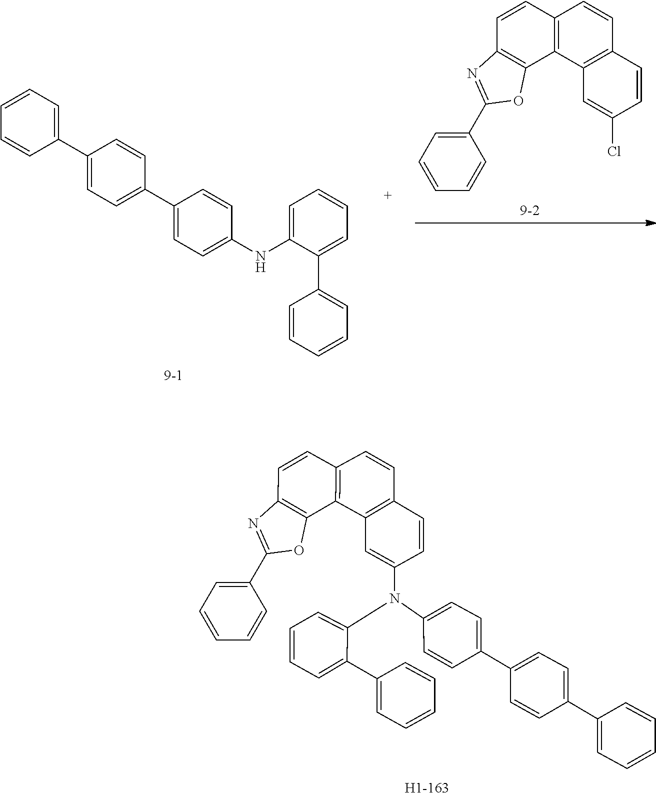 [SMILES: c1ccc(-c2ccc(-c3ccc(Nc4ccccc4-c4ccccc4)cc3)cc2)cc1 ; Clc1ccc2ccc3ccc4nc(-c5ccccc5)oc4c3c2c1 ; c1ccc(-c2ccc(-c3ccc(N(c4ccc5ccc6ccc7nc(-c8ccccc8)oc7c6c5c4)c4ccccc4-c4ccccc4)cc3)cc2)cc1]

Compound 9-1 (7.6 g, 23.05 mmol), Compound 9-2 (10.08 g, 25.35 mmol), Pd₂(dba)₃ (1.06 g, 1.15 mmol), SPhos (0.95 g, 2.30 mmol), NaOtBu (3.32 g, 34.57 mmol), and 115 mL of xylene were mixed in a flask and stirred at 130° C. for 2 hours. After completion of the reaction, the mixture was cooled to room temperature, and the organic layer was extracted with ethyl acetate. The remaining moisture was removed with magnesium sulfate, and the solvent was removed using a rotary evaporator. The residue was then purified by column chromatography to obtain Compound H1-163 (11.2 g, yield: 70%).

| | MW | M.P. |
|---|---|---|
| H1-163 | 690.8 | 223.3° C. |

### [Device Examples 1-1 to 11-1] Preparation of OLEDs According to the Present Disclosure

An OLED according to the present disclosure was produced. First, a transparent electrode indium tin oxide (ITO) thin film (10 Ω/sq) on a glass substrate for an OLED (GEOMATEC CO., LTD., Japan) was subjected to an ultrasonic washing with acetone and isopropyl alcohol sequentially, and thereafter it was stored in isopropyl alcohol and used. Next, the ITO substrate was mounted on a substrate holder of a vacuum vapor deposition apparatus. Compound HI-1 in Table 2 was then introduced into a cell of the vacuum vapor deposition apparatus, while Compound HT-1 was introduced into another cell. The two materials were evaporated at different rates, and Compound HI-1 was deposited in a doping amount of 3 wt % based on the total amount of Compounds HI-1 and HT-1 to form a hole injection layer having a thickness of 10 nm. Compound HT-1 was then deposited as a first hole transport layer having a thickness of 80 nm on the hole injection layer. The compound in Table 1 below was then introduced into another cell of the vacuum vapor deposition apparatus and was evaporated by applying an electric current to the cell to thereby form a second hole transport layer having a thickness of 60 nm on the first hole transport layer. After formation of the hole injection layer and the hole transport layers, a light-emitting layer was formed thereon as follows: The compounds described in Table 1 below were introduced into two cells of the vacuum vapor deposition apparatus as a host, and Compound D-39 was introduced into another cell as a dopant. The host compounds were evaporated at a ratio of 1:1, and the dopant material was evaporated at a different ratio, simultaneously, and the dopant was deposited in a doping amount of 3 wt % based on the total amount of the hosts and dopant to form a light-emitting layer having a thickness of 40 nm on the second hole transport layer. Next, Compound ET-1 and Compound EI-1 were then deposited as an electron transport layer at a weight ratio of 50:50 to a thickness of 35 nm on the light-emitting layer. After deposition of Compound EI-1 as an electron injection layer having a thickness of 2 nm on the electron transport layer, an Al cathode having a thickness of 80 nm was deposited on the electron injection layer by another vacuum vapor deposition apparatus. Thus, an OLED was produced. Each compound was purified by vacuum sublimation under 10⁻⁶ Torr.

### [Device Comparative Examples 1-1 to 11-1 and 1-2 to 11-2] Preparation of OLEDs not According to the Present Disclosure

OLEDs were produced in the same manner as in Device Example 1-1, except that the compounds of Table 1 below were used as the materials for the second hole transport layer.

The current efficiency at a luminance of 1,000 nit of the organic electroluminescent devices according to Device Examples 1-1 to 11-1 and Device Comparative Examples 1-1 to 11-1 and 1-2 to 11-2 produced as described above was measured, and the results thereof are shown in Table 1 below.

TABLE 1

| | | | Current |
|---|---|---|---|
| | Second Hole | | Efficiency |
| | Transport Layer | Host | [cd/A] |
| Device Example 1-1 | C-24 | H1-144:H3-28 | 33.7 |
| Device Comparative | HT2-1 | H1-144:H3-28 | 31.8 |
| Example 1-1 | | | |
| Device Comparative | HT2-2 | H1-144:H3-28 | 28.9 |
| Example 1-2 | | | |
| Device Example 2-1 | C-24 | H1-163:H3-463 | 33.5 |
| Device Comparative | HT2-1 | H1-163:H3-463 | 29.9 |
| Example 2-1 | | | |
| Device Comparative | HT2-2 | H1-163:H3-463 | 28.1 |
| Example 2-2 | | | |
| Device Example 3-1 | C-24 | H1-163:H3-466 | 34.9 |
| Device Comparative | HT2-1 | H1-163:H3-466 | 30.1 |
| Example 3-1 | | | |
| Device Comparative | HT2-2 | H1-163:H3-466 | 27.8 |
| Example 3-2 | | | |
| Device Example 4-1 | C-24 | H1-163:H3-345 | 34.1 |
| Device Comparative | HT2-1 | H1-163:H3-345 | 30.5 |
| Example 4-1 | | | |
| Device Comparative | HT2-2 | H1-163:H3-345 | 28.3 |
| Example 4-2 | | | |
| Device Example 5-1 | C-24 | H1-163:H3-456 | 34.2 |
| Device Comparative | HT2-1 | H1-163:H3-456 | 30.7 |
| Example 5-1 | | | |
| Device Comparative | HT2-2 | H1-163:H3-456 | 28.4 |
| Example 5-2 | | | |
| Device Example 6-1 | C-24 | H1-163:H3-467 | 33.5 |
| Device Comparative | HT2-1 | H1-163:H3-467 | 30.0 |
| Example 6-1 | | | |
| Device Comparative | HT2-2 | H1-163:H3-467 | 28.6 |
| Example 6-2 | | | |
| Device Example 7-1 | C-24 | H2-159:H3-463 | 33.6 |
| Device Comparative | HT2-1 | H2-159:H3-463 | 30.6 |
| Example 7-1 | | | |
| Device Comparative | HT2-2 | H2-159:H3-463 | 29.3 |
| Example 7-2 | | | |
| Device Example 8-1 | C-24 | H2-159:H3-466 | 33.9 |
| Device Comparative | HT2-1 | H2-159:H3-466 | 30.3 |
| Example 8-1 | | | |
| Device Comparative | HT2-2 | H2-159:H3-466 | 28.9 |
| Example 8-2 | | | |
| Device Example 9-1 | C-24 | H2-159:H3-345 | 34.0 |
| Device Comparative | HT2-1 | H2-159:H3-345 | 31.0 |
| Example 9-1 | | | |
| Device Comparative | HT2-2 | H2-159:H3-345 | 29.4 |
| Example 9-2 | | | |
| Device Example 10-1 | C-24 | H2-159:H3-456 | 34.1 |
| Device Comparative | HT2-1 | H2-159:H3-456 | 30.6 |
| Example 10-1 | | | |
| Device Comparative | HT2-2 | H2-159:H3-456 | 29.2 |
| Example 10-2 | | | |
| Device Example 11-1 | C-24 | H2-159:H3-467 | 33.8 |
| Device Comparative | HT2-1 | H2-159:H3-467 | 30.7 |
| Example 11-1 | | | |
| Device Comparative | HT2-2 | H2-159:H3-467 | 29.3 |
| Example 11-2 | | | |

From Table 1 above, it can be seen that the organic electroluminescent device according to the present disclosure exhibits high current efficiency properties compared to the organic electroluminescent device not according to present disclosure.

TABLE 2
Compounds used in Device Comparative Examples 1-1 to 11-1 and 1-2
to 11-2 and Device Examples 1-1 to 11-1

| | | |
|---|---|---|
| Hole Injection Layer/Hole Transport Layer | 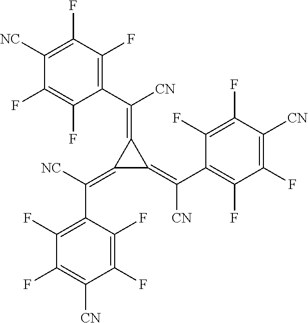 | HI-1 |
| | 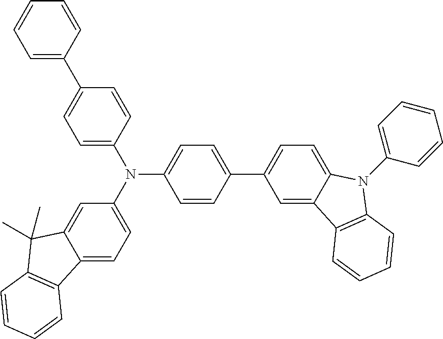 | HT-1 |
| | 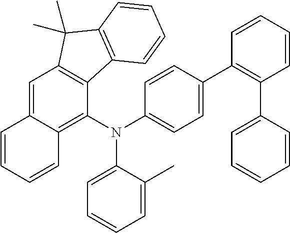 | C-24 |
| | 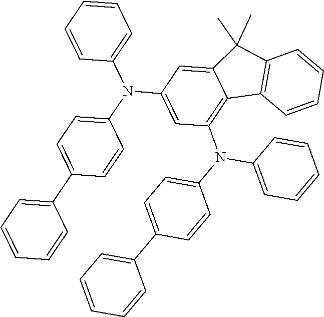 | HT2-1 |
| | 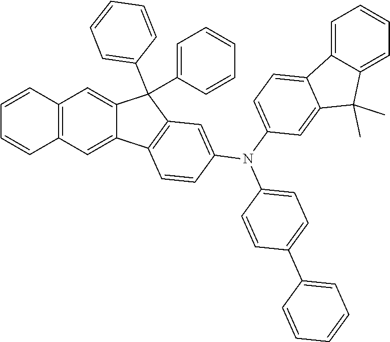 | HT2-2 |
| Light-Emitting Layer | 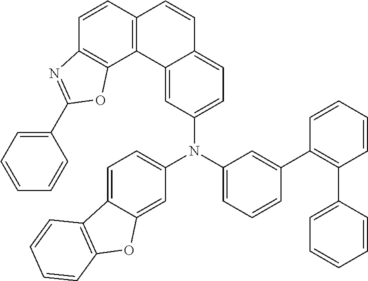 | H1-144 |
| | 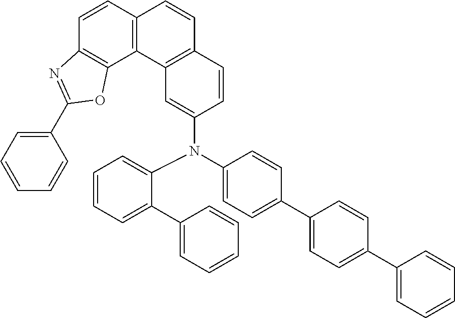 | H1-163 |
| | 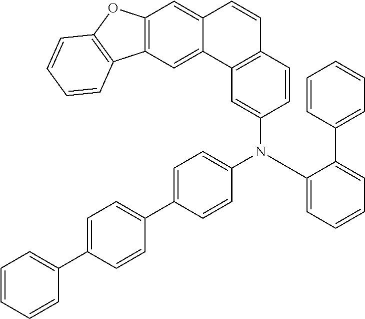 | H2-159 |
| | 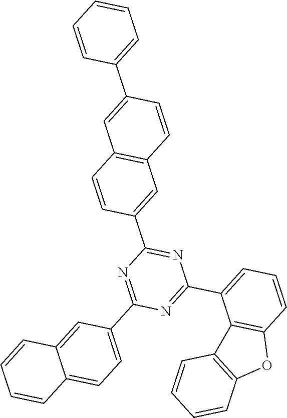 | H3-28 |
| | 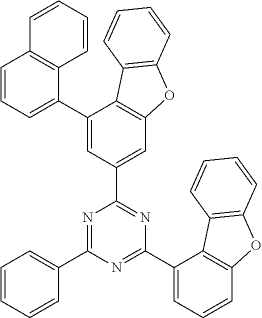 | H3-463 |
| | 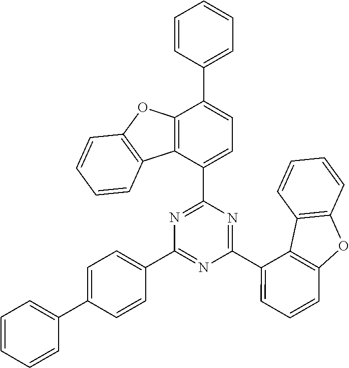 | H3-466 |
| | 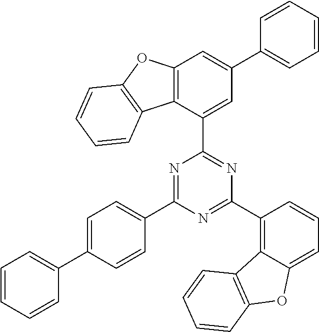 | H3-345 |
| | 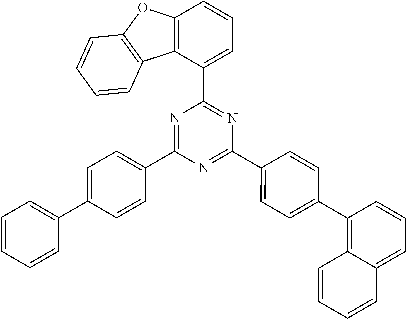 | H3-456 |
| | 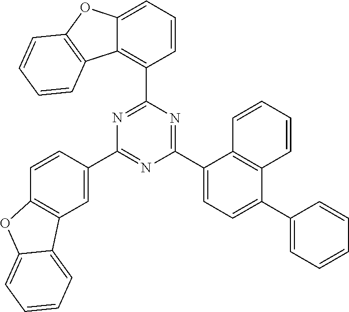 | H3-467 |
| | 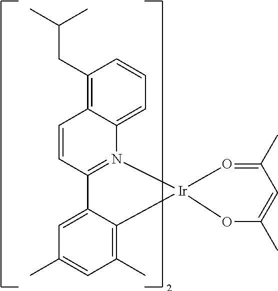 | D-39 |
| Electron Transport Layer/ Electron Injection Layer | 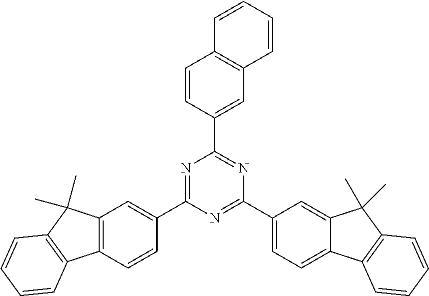 | ET-1 |
| | 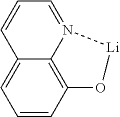 | EI-1 |

### [Device Examples 12-1 and 12-2] Preparation of OLEDs According to the Present Disclosure

An OLED according to the present disclosure was produced. First, a transparent electrode indium tin oxide (ITO) thin film (10 Ω/sq) on a glass substrate for an OLED (GEOMATEC CO., LTD., Japan) was subjected to an ultrasonic washing with acetone and isopropyl alcohol sequentially, and thereafter it was stored in isopropyl alcohol and used. Next, the ITO substrate was mounted on a substrate holder of a vacuum vapor deposition apparatus. Compound HI-1 in Table 5 was then introduced into a cell of the vacuum vapor deposition apparatus, while Compound HT-3 was introduced into another cell. The two materials were evaporated at different rates, and Compound HI-1 was deposited in a doping amount of 3 wt % based on the total amount of Compounds HI-1 and HT-3 to form a hole injection layer having a thickness of 10 nm. Compound HT-3 was then deposited as a first hole transport layer having a thickness of 90 nm on the hole injection layer. The compound in Table 3 below was then introduced into another cell of the vacuum vapor deposition apparatus and was evaporated by applying an electric current to the cell to thereby form a second hole transport layer having a thickness of 60 nm on the first hole transport layer. Compound HT-4 was then introduced into another cell of the vacuum vapor deposition apparatus and was evaporated by applying an electric current to the cell to thereby form a third hole transport layer having a thickness of 5 nm on the second hole transport layer. After formation of the hole injection layer and the hole transport layers, a light-emitting layer was formed thereon as follows: The compounds described in Table 3 below were introduced into two cells of the vacuum vapor deposition apparatus as a host, and Compound D-162 was introduced into another cell as a dopant. The host compounds were evaporated at a ratio of 35:65, and the dopant material was evaporated at a different ratio, simultaneously, and the dopant was deposited in a doping amount of 2 wt % based on the total amount of the hosts and dopant to form a light-emitting layer having a thickness of 40 nm on the third hole transport layer. Next, Compound ET-2 was deposited as a buffer layer with a thickness of 5 nm on the light-emitting layer. Next, Compound ET-3 and Compound EI-1 were then deposited as an electron transport layer at a weight ratio of 2:1 to a thickness of 25 nm on the buffer layer. After deposition of Yb as an electron injection layer having a thickness of 2 nm on the electron transport layer, an Al cathode having a thickness of 80 nm was deposited on the electron injection layer by another vacuum vapor deposition apparatus. Thus, an OLED was produced. Each compound was purified by vacuum sublimation under 10⁻⁶ Torr.

The current efficiency at a luminance of 5,000 nit of the organic electroluminescent devices according to Device Examples described above was measured, and the results thereof are shown in Table 3 below.

TABLE 3

| | | | Current |
|---|---|---|---|
| | Second Hole | | Efficiency |
| | Transport Layer | Host | [cd/A] |
| Device Example 12-1 | C-24 | H1-322:H3-556 | 35.6 |
| Device Example 12-2 | C-37 | H1-322:H3-556 | 35.5 |

From Table 3 above, it can be seen that the current efficiency of the organic electroluminescent device including the compound according to the present disclosure as a hole transport band and host material is excellent.

### [Device Examples 13-1 to 13-5] Preparation of OLEDs According to the Present Disclosure

An OLED according to the present disclosure was produced. First, a transparent electrode indium tin oxide (ITO) thin film (10 Ω/sq) on a glass substrate for an OLED (GEOMATEC CO., LTD., Japan) was subjected to an ultrasonic washing with acetone and isopropyl alcohol sequentially, and thereafter it was stored in isopropyl alcohol and used. Next, the ITO substrate was mounted on a substrate holder of a vacuum vapor deposition apparatus. Compound HI-1 in Table 5 was then introduced into a cell of the vacuum vapor deposition apparatus, while Compound HT-5 was introduced into another cell. The two materials were evaporated at different rates, and Compound HI-1 was deposited in a doping amount of 3 wt % based on the total amount of Compounds HI-1 and HT-5 to form a hole injection layer having a thickness of 10 nm. Compound HT-5 was then deposited as a first hole transport layer having a thickness of 80 nm on the hole injection layer. The compound in Table 4 below was then introduced into another cell of the vacuum vapor deposition apparatus and was evaporated by applying an electric current to the cell to thereby form a second hole transport layer having a thickness of 55 nm on the first hole transport layer. Compound HT-6 was then introduced into another cell of the vacuum vapor deposition apparatus and was evaporated by applying an electric current to the cell to thereby form a third hole transport layer having a thickness of 5 nm on the second hole transport layer. After formation of the hole injection layer and the hole transport layers, a light-emitting layer was formed thereon as follows: The compounds described in Table 4 below were introduced into two cells of the vacuum vapor deposition apparatus as a host, and Compound D-162 was introduced into another cell as a dopant. The host compounds were evaporated at a ratio of 1:1, and the dopant material was evaporated at a different ratio, simultaneously, and the dopant was deposited in a doping amount of 3 wt % based on the total amount of the hosts and dopant to form a light-emitting layer having a thickness of 40 nm on the third hole transport layer. Next, Compound ET-4 was deposited as a buffer layer with a thickness of 5 nm on the light-emitting layer. Next, Compound ET-5 and Compound EI-1 were then deposited as an electron transport layer at a weight ratio of 50:50 to a thickness of 30 nm on the buffer layer. After deposition of Compound EI-1 as an electron injection layer having a thickness of 2 nm on the electron transport layer, an Al cathode having a thickness of 80 nm was deposited on the electron injection layer by another vacuum vapor deposition apparatus. Thus, an OLED was produced. Each compound was purified by vacuum sublimation under 10⁻⁶ Torr.

The current efficiency at a luminance of 5,000 nit of the organic electroluminescent devices according to Device Examples described above was measured, and the results thereof are shown in Table 4 below.

TABLE 4

| | | | Current |
|---|---|---|---|
| | Second Hole | | Efficiency |
| | Transport Layer | Host | [cd/A] |
| Device Example 13-1 | C-168 | H1-163:H3-466 | 34.9 |
| Device Example 13-2 | C-166 | H1-163:H3-466 | 34.6 |
| Device Example 13-3 | C-169 | H1-163:H3-466 | 33.5 |
| Device Example 13-4 | C-304 | H1-163:H3-466 | 34.3 |
| Device Example 13-5 | C-170 | H1-163:H3-466 | 34.1 |

From Table 4 above, it can be seen that the current efficiency of the organic electroluminescent device including the compound according to the present disclosure as a hole transport band and host material is excellent.

TABLE 5
Compounds used in Device Examples 12-1, 12-2, and 13-1 to 13-5

| | | |
|---|---|---|
| Hole Injection Layer/Hole Transport Layer | 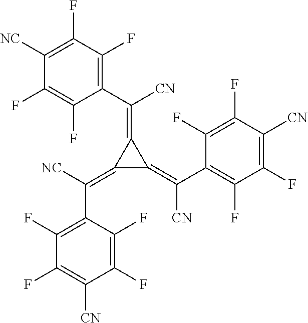 [SMILES: N#CC(=C1C(=C(C#N)c2c(F)c(F)c(C#N)c(F)c2F)C1=C(C#N)c1c(F)c(F)c(C#N)c(F)c1F)c1c(F)c(F)c(C#N)c(F)c1F] | HI-1 |
| | 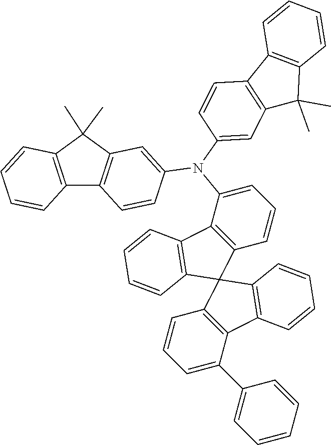 [SMILES: CC1(C)c2ccccc2-c2ccc(N(c3ccc4c(c3)C(C)(C)c3ccccc3-4)c3cccc4c3-c3ccccc3C43c4ccccc4-c4c(-c5ccccc5)cccc43)cc21] | HT-3 |
| | 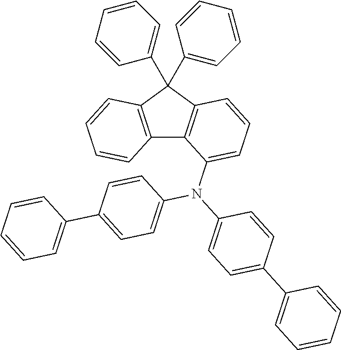 [SMILES: c1ccc(-c2ccc(N(c3ccc(-c4ccccc4)cc3)c3cccc4c3-c3ccccc3C4(c3ccccc3)c3ccccc3)cc2)cc1] | HT-4 |
| | 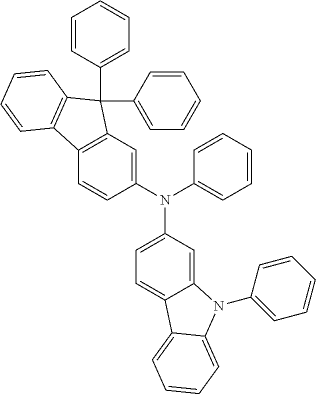 [SMILES: c1ccc(N(c2ccc3c(c2)C(c2ccccc2)(c2ccccc2)c2ccccc2-3)c2ccc3c4ccccc4n(-c4ccccc4)c3c2)cc1] | HT-5 |
| | 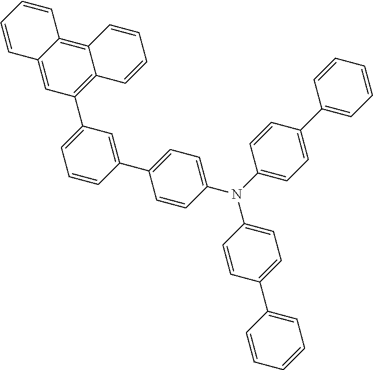 [SMILES: c1ccc(-c2ccc(N(c3ccc(-c4ccccc4)cc3)c3ccc(-c4cccc(-c5cc6ccccc6c6ccccc56)c4)cc3)cc2)cc1] | HT-6 |
| | 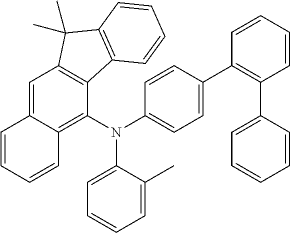 [SMILES: Cc1ccccc1N(c1ccc(-c2ccccc2-c2ccccc2)cc1)c1c2c(cc3ccccc13)C(C)(C)c1ccccc1-2] | C-24 |
| | 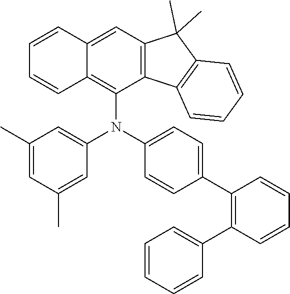 [SMILES: Cc1cc(C)cc(N(c2ccc(-c3ccccc3-c3ccccc3)cc2)c2c3c(cc4ccccc24)C(C)(C)c2ccccc2-3)c1] | C-37 |
| | 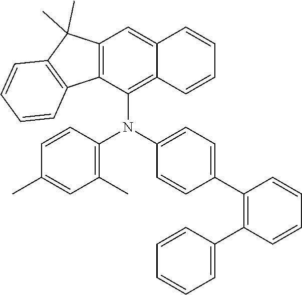 [SMILES: Cc1ccc(N(c2ccc(-c3ccccc3-c3ccccc3)cc2)c2c3c(cc4ccccc24)C(C)(C)c2ccccc2-3)c(C)c1] | C-168 |
| | 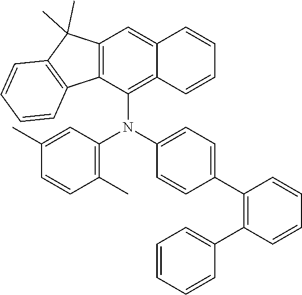 [SMILES: Cc1ccc(C)c(N(c2ccc(-c3ccccc3-c3ccccc3)cc2)c2c3c(cc4ccccc24)C(C)(C)c2ccccc2-3)c1] | C-166 |
| | 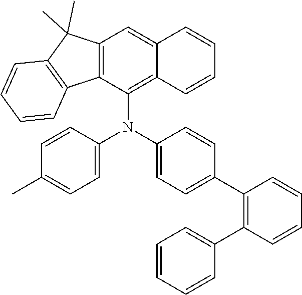 [SMILES: Cc1ccc(N(c2ccc(-c3ccccc3-c3ccccc3)cc2)c2c3c(cc4ccccc24)C(C)(C)c2ccccc2-3)cc1] | C-169 |
| | 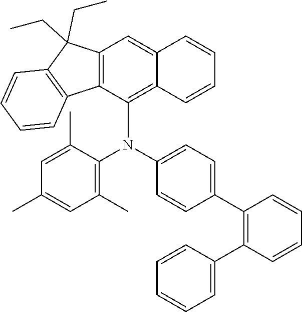 [SMILES: CCC1(CC)c2ccccc2-c2c1cc1ccccc1c2N(c1ccc(-c2ccccc2-c2ccccc2)cc1)c1c(C)cc(C)cc1C] | C-304 |
| | 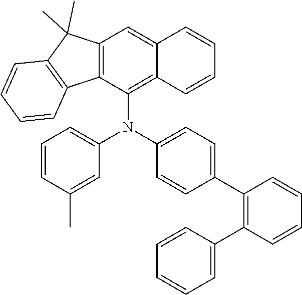 [SMILES: Cc1cccc(N(c2ccc(-c3ccccc3-c3ccccc3)cc2)c2c3c(cc4ccccc24)C(C)(C)c2ccccc2-3)c1] | C-170 |
| Light-Emitting Layer | 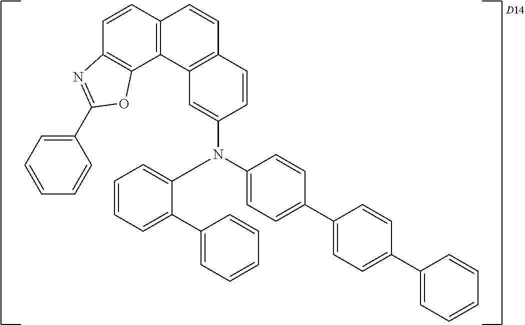 | H1-322 |
| | 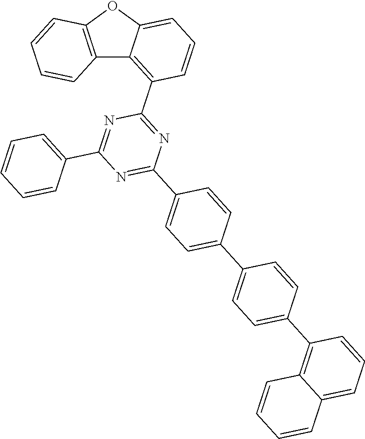 [SMILES: c1ccc(-c2nc(-c3ccc(-c4ccc(-c5cccc6ccccc56)cc4)cc3)nc(-c3cccc4oc5ccccc5c34)n2)cc1] | H3-556 |
| | 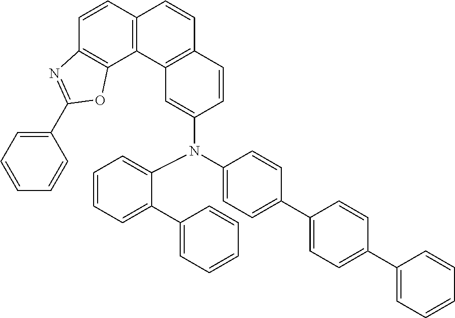 [SMILES: c1ccc(-c2ccc(-c3ccc(N(c4ccc5ccc6ccc7nc(-c8ccccc8)oc7c6c5c4)c4ccccc4-c4ccccc4)cc3)cc2)cc1] | H1-163 |
| | 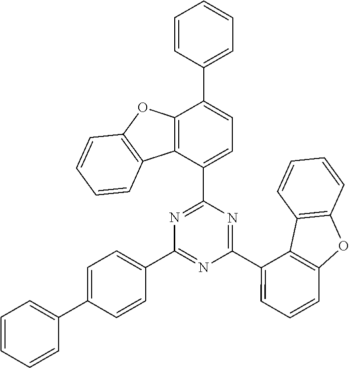 [SMILES: c1ccc(-c2ccc(-c3nc(-c4cccc5oc6ccccc6c45)nc(-c4ccc(-c5ccccc5)c5oc6ccccc6c45)n3)cc2)cc1] | H3-466 |
| | 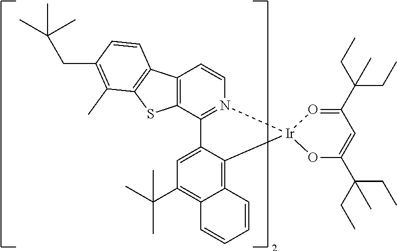 | D-162 |
| Buffer Layer/ Electron Transport Layer/ Electron Injection Layer | 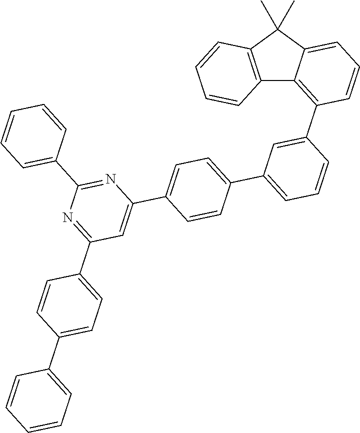 [SMILES: CC1(C)c2ccccc2-c2c(-c3cccc(-c4ccc(-c5cc(-c6ccc(-c7ccccc7)cc6)nc(-c6ccccc6)n5)cc4)c3)cccc21] | ET-2 |
| | 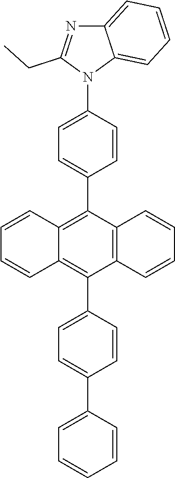 [SMILES: CCc1nc2ccccc2n1-c1ccc(-c2c3ccccc3c(-c3ccc(-c4ccccc4)cc3)c3ccccc23)cc1] | ET-3 |
| | 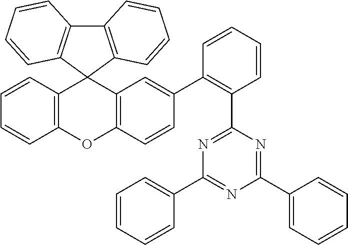 [SMILES: c1ccc(-c2nc(-c3ccccc3)nc(-c3ccccc3-c3ccc4c(c3)C3(c5ccccc5O4)c4ccccc4-c4ccccc43)n2)cc1] | ET-4 |
| | 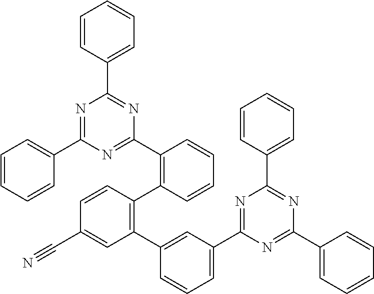 [SMILES: N#Cc1ccc(-c2ccccc2-c2nc(-c3ccccc3)nc(-c3ccccc3)n2)c(-c2cccc(-c3nc(-c4ccccc4)nc(-c4ccccc4)n3)c2)c1] | ET-5 |
| | 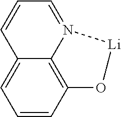 | EI-1 |

1. An organic electroluminescent device comprising a first electrode; a second electrode opposing the first electrode; a light-emitting layer between the first electrode and the second electrode; and a hole transport band between the first electrode and the light-emitting layer,
wherein the hole transport band comprises a compound represented by the following Formula 1, and
the light-emitting layer comprises a compound represented by the following Formula 2 and a compound represented by the following Formula 3: 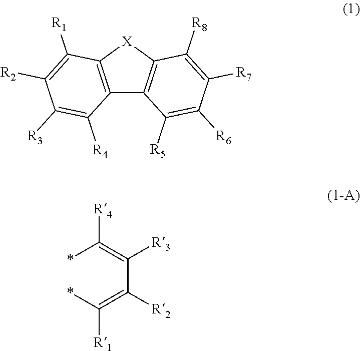
wherein in Formulas 1 and 1-A,
X represents O, S, or CR₉R₁₀;
R₉ and R₁₀ each independently represent hydrogen, deuterium, halogen, cyano, a substituted or unsubstituted (C₁-C₃₀)alkyl, a substituted or unsubstituted (C₆-C₃₀)aryl, a substituted or unsubstituted (3- to 30-membered)heteroaryl, or a substituted or unsubstituted (C₃-C₃₀)cycloalkyl; or may be linked to the adjacent substituents to form a ring(s); and
R₁ to R₃ and R′₁ to R′₄ each independently represent hydrogen, deuterium, halogen, cyano, a substituted or unsubstituted (C₁-C₃₀)alkyl, a substituted or unsubstituted (C₆-C₃₀)aryl, a substituted or unsubstituted (3- to 30-membered)heteroaryl, a substituted or unsubstituted (C₃-C₃₀)cycloalkyl, a substituted or unsubstituted (C₁-C₃₀)alkoxy, a substituted or unsubstituted tri(C₁-C₃₀)alkylsilyl, a substituted or unsubstituted di(C₁-C₃₀)alkyl(C₆-C₃₀)arylsilyl, a substituted or unsubstituted (C₁-C₃₀)alkyldi(C₁-C₃₀)arylsilyl, a substituted or unsubstituted tri(C₆-C₃₀)arylsilyl, a substituted or unsubstituted fused ring of a (C₃-C₃₀)aliphatic ring and a (C₆-C₃₀)aromatic ring, a substituted or unsubstituted mono- or di-(C₁-C₃₀)alkylamino, a substituted or unsubstituted mono- or di-(C₆-C₃₀)arylamino, a substituted or unsubstituted (C₁-C₃₀)alkyl(C₆-C₃₀)arylamino, a substituted or unsubstituted mono- or di-(3- to 30-membered)heteroarylamino, or a substituted or unsubstituted (C₆-C₃₀)aryl(3- to 30-membered)heteroarylamino;
provided that one pair selected from R₅ and R₆, R₆ and R₇, and R₇ and R₈ is bonded together to form a ring with the *-* of Formula 1-A;
provided that at least one of R₁ to R₈ and R′₁ to R′₄ is represented by the following Formula A; 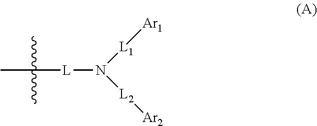
Wherein in Formula A,
L, L₁, and L₂ each independently represent a single bond, a substituted or unsubstituted (C₆-C₃₀)arylene, a substituted or unsubstituted (3- to 30-membered)heteroarylene, or a substituted or unsubstituted (C₃-C₃₀)cycloalkylene; and
Ar₁ and Ar₂ each independently represent a substituted or unsubstituted (C₆-C₃₀)aryl, or a substituted or unsubstituted (3- to 30-membered)heteroaryl,
provided that at least one of L, L₁, L₂, Ar₁, and Ar₂ is necessarily substituted with a substituted or unsubstituted (C₃-C₃₀)cycloalkyl or a substituted or unsubstituted (C₁-C₃₀)alkyl; and 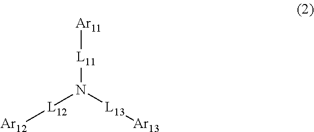
Wherein in Formula 2,
L₁₁ to L₁₃ each independently represent a single bond, a substituted or unsubstituted (C₆-C₃₀)arylene, or a substituted or unsubstituted (3- to 30-membered)heteroarylene;
Ar₁₁ represents a substituted or unsubstituted (3- to 30-membered)heteroaryl; and
Ar₁₂ and Ar₁₃ each independently represent a substituted or unsubstituted (C₁-C₃₀)alkyl, a substituted or unsubstituted (C₆-C₃₀)aryl, a substituted or unsubstituted (3- to 30-membered)heteroaryl, a substituted or unsubstituted (C₃-C₃₀)cycloalkyl, a substituted or unsubstituted (C₁-C₃₀)alkoxy, a substituted or unsubstituted tri(C₁-C₃₀)alkylsilyl, a substituted or unsubstituted di(C₁-C₃₀)alkyl(C₆-C₃₀)arylsilyl, a substituted or unsubstituted (C₁-C₃₀)alkyldi(C₆-C₃₀)arylsilyl, a substituted or unsubstituted tri(C₆-C₃₀)arylsilyl, a substituted or unsubstituted mono- or di-(C₁-C₃₀)alkylamino, a substituted or unsubstituted mono- or di-(C₂-C₃₀)alkenylamino, a substituted or unsubstituted (C₁-C₃₀)alkyl(C₂-C₃₀)alkenylamino, a substituted or unsubstituted mono- or di-(C₆-C₃₀)arylamino, a substituted or unsubstituted (C₁-C₃₀)alkyl(C₆-C₃₀)arylamino, a substituted or unsubstituted mono- or di-(3- to 30-membered)heteroarylamino, a substituted or unsubstituted (C₁-C₃₀)alkyl(3- to 30-membered)heteroarylamino, a substituted or unsubstituted (C₂-C₃₀)alkenyl(C₆-C₃₀)arylamino, a substituted or unsubstituted (C₂-C₃₀)alkenyl(3- to 30-membered)heteroarylamino, or a substituted or unsubstituted (C₆-C₃₀)aryl(3- to 30-membered)heteroarylamino; 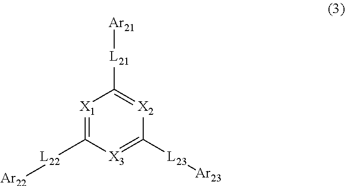
Wherein in Formula 3,
X₁ to X₃ each independently represent N or CR₂₁, provided that at least one of X₁ to X₃ is N;
each R₂₁ independently represents hydrogen or deuterium;
L₂₁ to L₂₃ each independently represent a single bond, a substituted or unsubstituted (C₆-C₃₀)arylene, or a substituted or unsubstituted (3- to 30-membered)heteroarylene; and
Ar₂₁ to Ar₂₃ each independently represent a substituted or unsubstituted (C₁-C₃₀)alkyl, a substituted or unsubstituted (C₃-C₃₀)cycloalkyl, a substituted or unsubstituted (3- to 7-membered)heterocycloalkyl, a substituted or unsubstituted fused ring of a (C₃-C₃₀)aliphatic ring and a (C₆-C₃₀)aromatic ring, a substituted or unsubstituted (C₆-C₃₀)aryl, or a substituted or unsubstituted (3- to 30-membered)heteroaryl;
provided that at least one of Ar₂₁ to Ar₂₃ represents a substituted or unsubstituted (3- to 30-membered)heteroaryl.

2. The organic electroluminescent device according to claim 1, wherein the substituted alkyl, the substituted aryl(ene), the substituted heteroaryl(ene), the substituted cycloalkyl(ene), the substituted heterocycloalkyl(ene), the substituted alkoxy, the substituted trialkylsilyl, the substituted dialkylarylsilyl, the substituted alkyldiarylsilyl, the substituted triarylsilyl, the substituted fused ring of aliphatic ring and aromatic ring, the substituted mono- or di-alkylamino, the substituted mono- or di-alkenylamino, the substituted alkylalkenylamino, the substituted mono- or di-arylamino, the substituted alkylarylamino, the substituted alkylheteroarylamino, the substituted alkenylarylamino, the substituted alkenylheteroarylamino, the substituted mono- or di-heteroarylamino, and the substituted arylheteroarylamino each independently are substituted with at least one selected from the group consisting of deuterium, halogen, cyano, carboxyl, nitro, hydroxy, (C₁-C₃₀)alkyl, halo(C₁-C₃₀)alkyl, (C₂-C₃₀)alkenyl, (C₂-C₃₀)alkynyl, (C₁-C₃₀)alkoxy, (C₁-C₃₀)alkylthio, (C₃-C₃₀)cycloalkyl, (C₃-C₃₀)cycloalkenyl, (3- to 7-membered)heterocycloalkyl, (C₆-C₃₀)aryloxy, (C₆-C₃₀)arylthio, (3- to 30-membered)heteroaryl substituted or unsubstituted with (C₆-C₃₀)aryl, (C₆-C₃₀)aryl substituted or unsubstituted with (3- to 30-membered)heteroaryl, tri(C₁-C₃₀)alkylsilyl, tri(C₆-C₃₀)arylsilyl, di(C₁-C₃₀)alkyl(C₆-C₃₀)arylsilyl, (C₁-C₃₀)alkyldi(C₆-C₃₀)arylsilyl, a fused ring of a (C₃-C₃₀)aliphatic ring and a (C₆-C₃₀)aromatic ring, amino, mono- or di-(C₁-C₃₀)alkylamino, a substituted or unsubstituted mono- or di-(C₆-C₃₀)arylamino, (C₁-C₃₀)alkyl(C₆-C₃₀)arylamino, mono- or di-(3- to 30-membered)heteroarylamino, (C₁-C₃₀)alkyl(3- to 30-membered)heteroarylamino, (C₆-C₃₀)aryl(3- to 30-membered)heteroarylamino, (C₁-C₃₀)alkylcarbonyl, (C₁-C₃₀)alkoxycarbonyl, (C₆-C₃₀)arylcarbonyl, (C₆-C₃₀)arylphosphinyl, di(C₆-C₃₀)arylboronyl, di(C₁-C₃₀)alkylboronyl, (C₁-C₃₀)alkyl(C₆-C₃₀)arylboronyl, (C₆-C₃₀)ar(C₁-C₃₀)alkyl, (C₁-C₃₀)alkyl(C₆-C₃₀)aryl, and a combination thereof.

3. The organic electroluminescent device according to claim 1, wherein Formula 1 is represented by the following Formula 1-1: 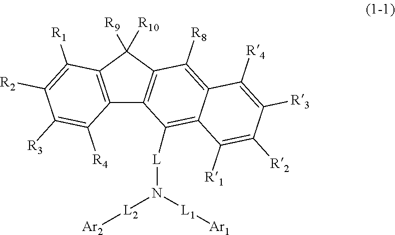
Wherein in Formula 1-1,
R₁ to R₄, R₈ to R₁₀, R′₁ to R′₄, L, L₁, L₂, Ar₁, and Ar₂ are as defined in claim 1.

4. The organic electroluminescent device according to claim 1, wherein, in the alkyl or cycloalkyl that are necessarily substituted in Formula 1,
the cycloalkyl is a substituted or unsubstituted cyclohexyl, a substituted or unsubstituted norbornanyl, a substituted or unsubstituted adamantyl, or a substituted or unsubstituted cyclopentyl; and
the alkyl is selected from the group consisting of methyl, ethyl, n-propyl, isopropyl, n-butyl, isobutyl, sec-butyl, tert-butyl, n-pentyl, tert-pentyl, neopentyl, isopentyl, sec-pentyl, and 3-pentyl, each of which is unsubstituted or substituted with deuterium.

5. The organic electroluminescent device according to claim 1, wherein Ar₁₁ in Formula 2 is a substituted or unsubstituted (3- to 30-membered)heteroaryl having four or more fused rings and necessarily comprising an oxygen atom.

6. The organic electroluminescent device according to claim 1, wherein Ar₁₁ in Formula 2 is represented by the following Formula 2-1 or 2-2: 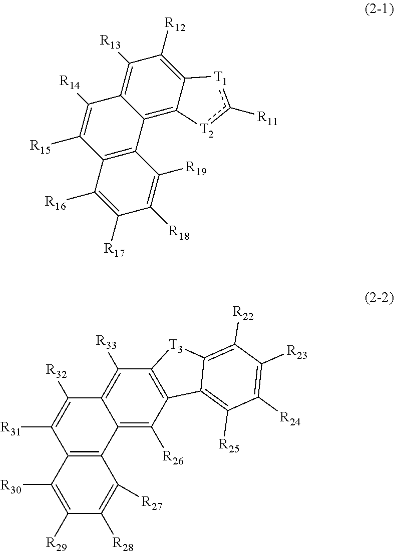
Wherein in Formulas 2-1 and 2-2,
T₁ and T₂ each independently represent —N═, —NR₂O—, —O—, or —S—, provided that one of T₁ and T₂ represents —N═, and the other one of T₁ and T₂ represents —NR₂₀—, —O—, or —S—;
T₃ represents O or S;
R₁₁ represents a substituted or unsubstituted (C₆-C₃₀)aryl, or a substituted or unsubstituted (3- to 30-membered)heteroaryl;
R₁₂ to R₁₉ and R₂₂ to R₃₃ each independently are connected to L₁₁, or represent hydrogen, deuterium, halogen, cyano, a substituted or unsubstituted (C₁-C₃₀)alkyl, a substituted or unsubstituted (C₆-C₃₀)aryl, a substituted or unsubstituted (3- to 30-membered)heteroaryl, a substituted or unsubstituted (C₃-C₃₀)cycloalkyl, a substituted or unsubstituted (C₁-C₃₀)alkoxy, a substituted or unsubstituted tri(C₁-C₃₀)alkylsilyl, a substituted or unsubstituted di(C₁-C₃₀)alkyl(C₆-C₃₀)arylsilyl, a substituted or unsubstituted (C₁-C₃₀)alkyldi(C₆-C₃₀)arylsilyl, a substituted or unsubstituted tri(C₆-C₃₀)arylsilyl, a substituted or unsubstituted fused ring of a (C₃-C₃₀)aliphatic ring and a (C₆-C₃₀)aromatic ring, a substituted or unsubstituted mono- or di-(C₁-C₃₀)alkylamino, a substituted or unsubstituted mono- or di-(C₂-C₃₀)alkenylamino, a substituted or unsubstituted (C₁-C₃₀)alkyl(C₂-C₃₀)alkenylamino, a substituted or unsubstituted (C₁-C₃₀)alkyl(C₆-C₃₀)arylamino, a substituted or unsubstituted (C₁-C₃₀)alkyl(3- to 30-membered)heteroarylamino, a substituted or unsubstituted (C₂-C₃₀)alkenyl(C₆-C₃₀)arylamino, a substituted or unsubstituted (C₂-C₃₀)alkenyl(3- to 30-membered)heteroarylamino, a substituted or unsubstituted mono- or di-(C₆-C₃₀)arylamino, a substituted or unsubstituted mono- or di-(3- to 30-membered)heteroarylamino, or a substituted or unsubstituted (C₆-C₃₀)aryl(3- to 30-membered)heteroarylamino; or may be linked to the adjacent substituents to form a ring(s),
provided that any one of R₁₂ to R₁₉ in Formula 2-1 is connected to L₁₁, and
any one of R₂₂ to R₃₃ in Formula 2-2 is connected to L₁₁.

7. The organic electroluminescent device according to claim 1, wherein Formula 3 is represented by any one of the following Formulas 3-1 to 3-4: 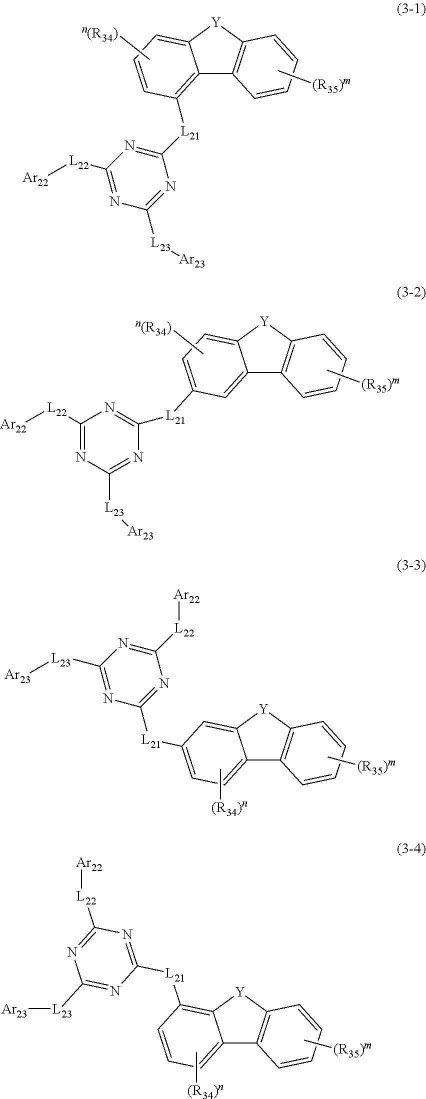
wherein in Formula 3-1 to 3-4,
Y represents O, S, or NR₃₆;
R₃₄ to R₃₆ each independently represent hydrogen, deuterium, halogen, cyano, a substituted or unsubstituted (C₁-C₃₀)alkyl, a substituted or unsubstituted (C₆-C₃₀)aryl, a substituted or unsubstituted (3- to 30-membered)heteroaryl, a substituted or unsubstituted (C₃-C₃₀)cycloalkyl, a substituted or unsubstituted (C₁-C₃₀)alkoxy, a substituted or unsubstituted tri(C₁-C₃₀)alkylsilyl, a substituted or unsubstituted di(C₁-C₃₀)alkyl(C₆-C₃₀)arylsilyl, a substituted or unsubstituted (C₁-C₃₀)alkyldi(C₆-C₃₀)arylsilyl, a substituted or unsubstituted tri(C₆-C₃₀)arylsilyl, a substituted or unsubstituted mono- or di-(C₁-C₃₀)alkylamino, a substituted or unsubstituted mono- or di-(C₆-C₃₀)arylamino, or a substituted or unsubstituted (C₁-C₃₀)alkyl(C₆-C₃₀)arylamino; or may be linked to the adjacent substituents to form a ring(s);
L₂₁ to L₂₃, Ar₂₂, and Ar₂₃ are the same as defined in claim 1;
n is an integer of 1 to 3, m is an integer of 1 to 4; and
when n and m are integers of 2 or greater, each of R₃₄ and each of R₃₅ may be the same or different.

8. The organic electroluminescent device according to claim 1, wherein the compound represented by Formula 1 is selected from the following compounds: 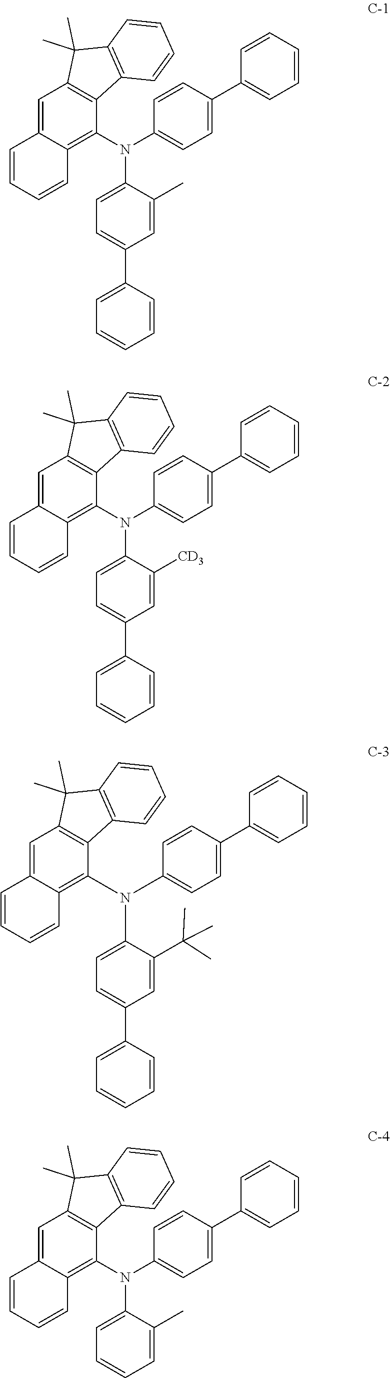 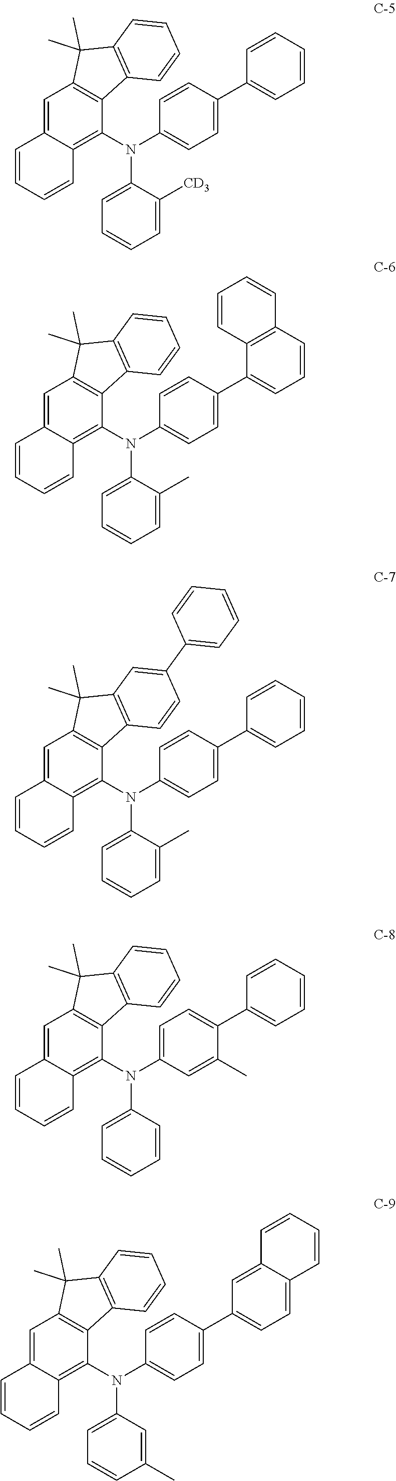 [SMILES: [2H]C([2H])([2H])c1ccccc1N(c1ccc(-c2ccccc2)cc1)c1c2c(cc3ccccc13)C(C)(C)c1ccccc1-2 ; Cc1ccccc1N(c1ccc(-c2cccc3ccccc23)cc1)c1c2c(cc3ccccc13)C(C)(C)c1ccccc1-2 ; Cc1ccccc1N(c1ccc(-c2ccccc2)cc1)c1c2c(cc3ccccc13)C(C)(C)c1cc(-c3ccccc3)ccc1-2 ; Cc1cc(N(c2ccccc2)c2c3c(cc4ccccc24)C(C)(C)c2ccccc2-3)ccc1-c1ccccc1 ; Cc1cccc(N(c2ccc(-c3ccc4ccccc4c3)cc2)c2c3c(cc4ccccc24)C(C)(C)c2ccccc2-3)c1] 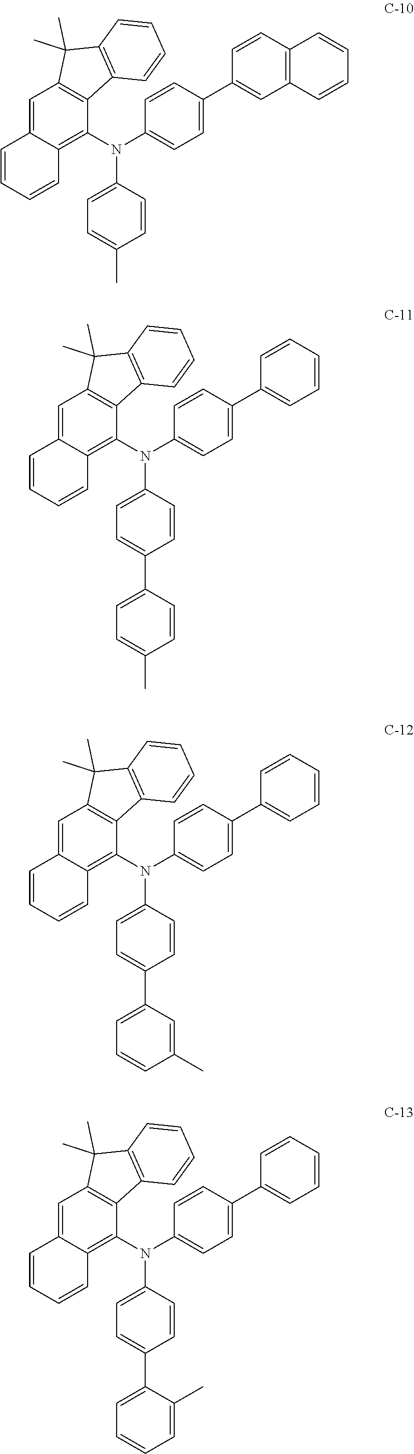 [SMILES: Cc1ccc(N(c2ccc(-c3ccc4ccccc4c3)cc2)c2c3c(cc4ccccc24)C(C)(C)c2ccccc2-3)cc1 ; Cc1ccc(-c2ccc(N(c3ccc(-c4ccccc4)cc3)c3c4c(cc5ccccc35)C(C)(C)c3ccccc3-4)cc2)cc1 ; Cc1cccc(-c2ccc(N(c3ccc(-c4ccccc4)cc3)c3c4c(cc5ccccc35)C(C)(C)c3ccccc3-4)cc2)c1 ; Cc1ccccc1-c1ccc(N(c2ccc(-c3ccccc3)cc2)c2c3c(cc4ccccc24)C(C)(C)c2ccccc2-3)cc1] 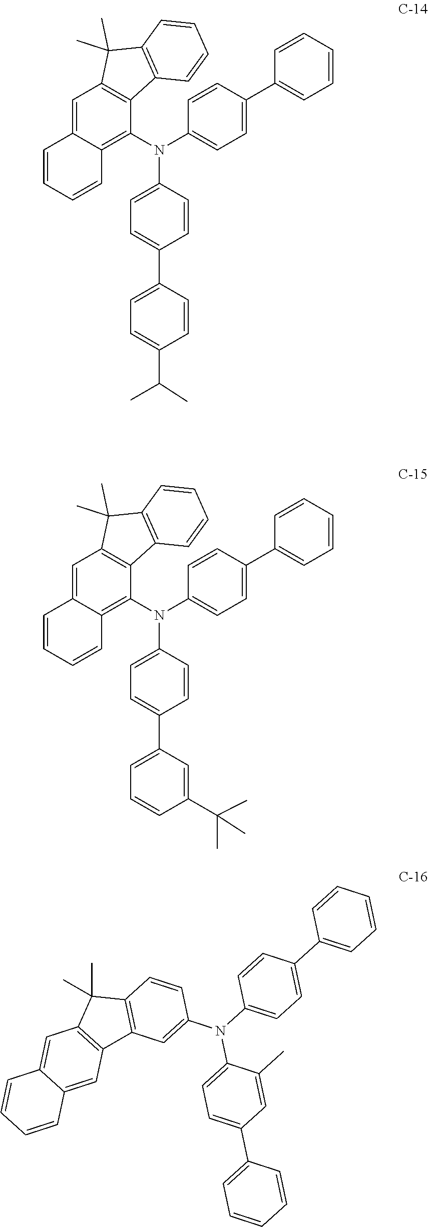 [SMILES: CC(C)c1ccc(-c2ccc(N(c3ccc(-c4ccccc4)cc3)c3c4c(cc5ccccc35)C(C)(C)c3ccccc3-4)cc2)cc1 ; CC(C)(C)c1cccc(-c2ccc(N(c3ccc(-c4ccccc4)cc3)c3c4c(cc5ccccc35)C(C)(C)c3ccccc3-4)cc2)c1 ; Cc1cc(-c2ccccc2)ccc1N(c1ccc(-c2ccccc2)cc1)c1ccc2c(c1)-c1cc3ccccc3cc1C2(C)C] 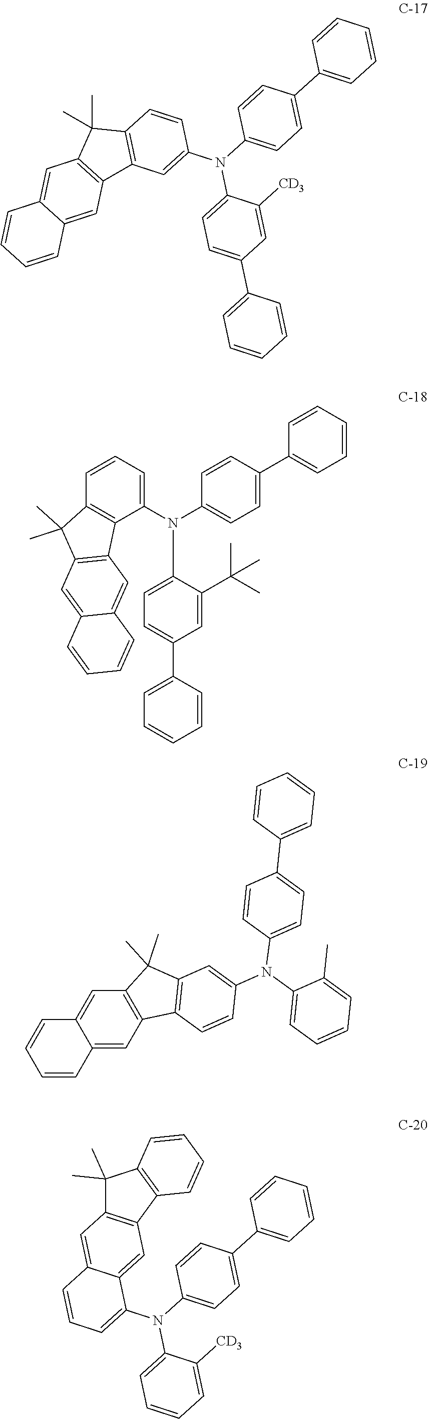 [SMILES: [2H]C([2H])([2H])c1cc(-c2ccccc2)ccc1N(c1ccc(-c2ccccc2)cc1)c1ccc2c(c1)-c1cc3ccccc3cc1C2(C)C ; CC(C)(C)c1cc(-c2ccccc2)ccc1N(c1ccc(-c2ccccc2)cc1)c1cccc2c1-c1cc3ccccc3cc1C2(C)C ; Cc1ccccc1N(c1ccc(-c2ccccc2)cc1)c1ccc2c(c1)C(C)(C)c1cc3ccccc3cc1-2 ; [2H]C([2H])([2H])c1ccccc1N(c1ccc(-c2ccccc2)cc1)c1cccc2cc3c(cc12)-c1ccccc1C3(C)C] 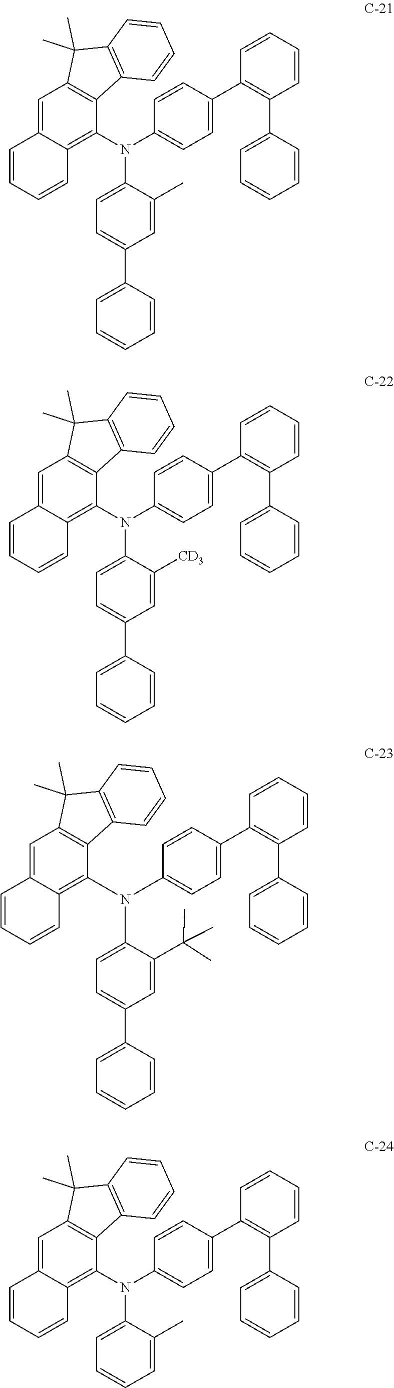 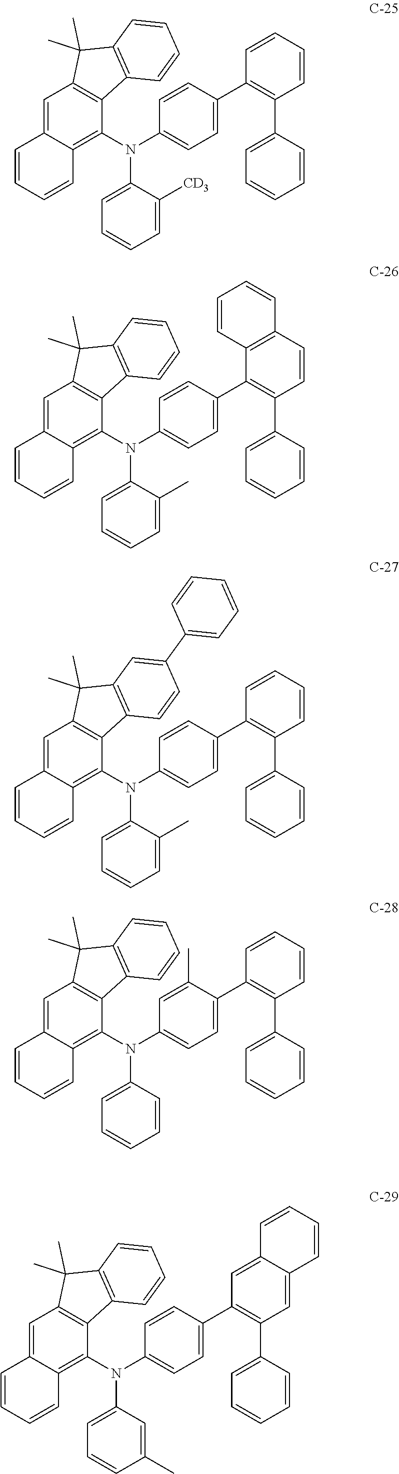 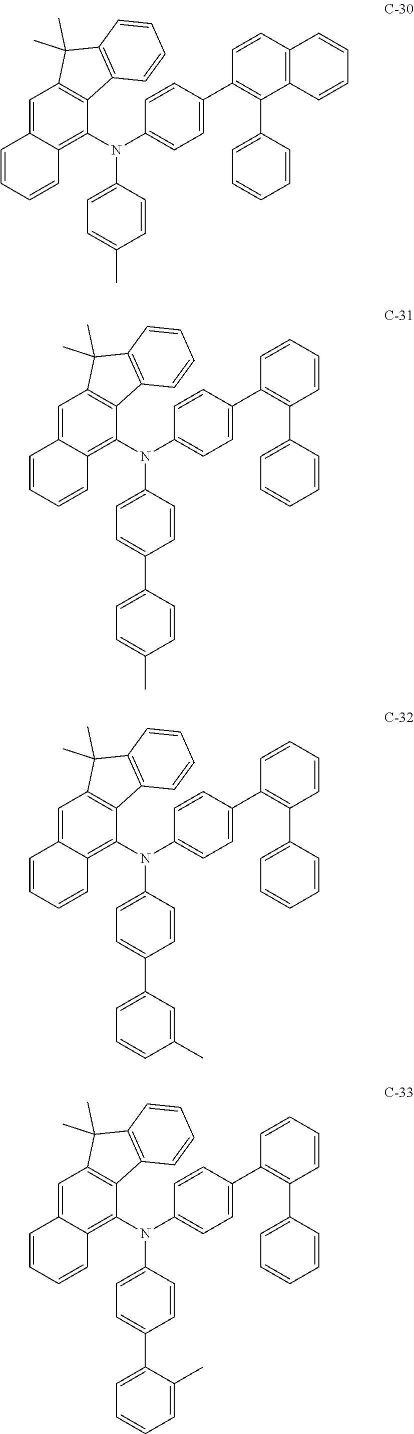 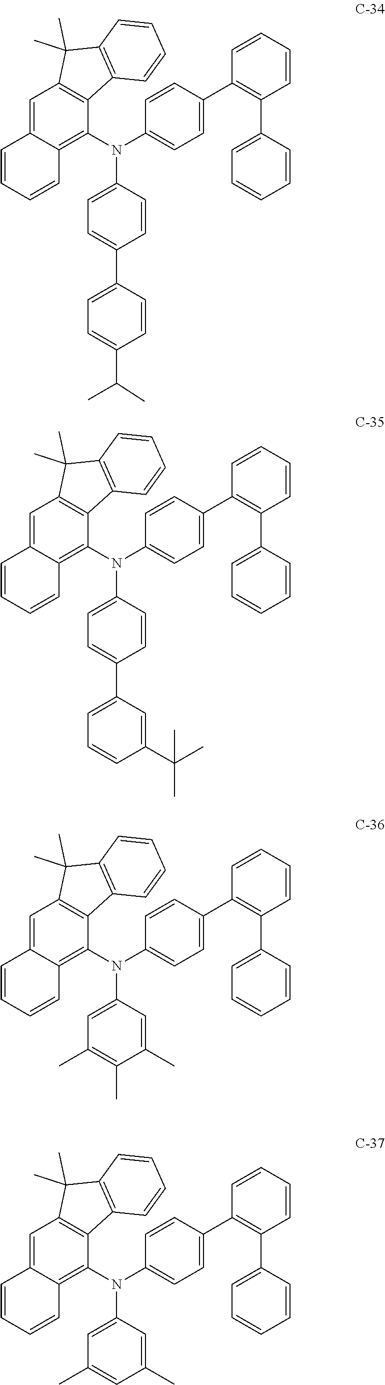 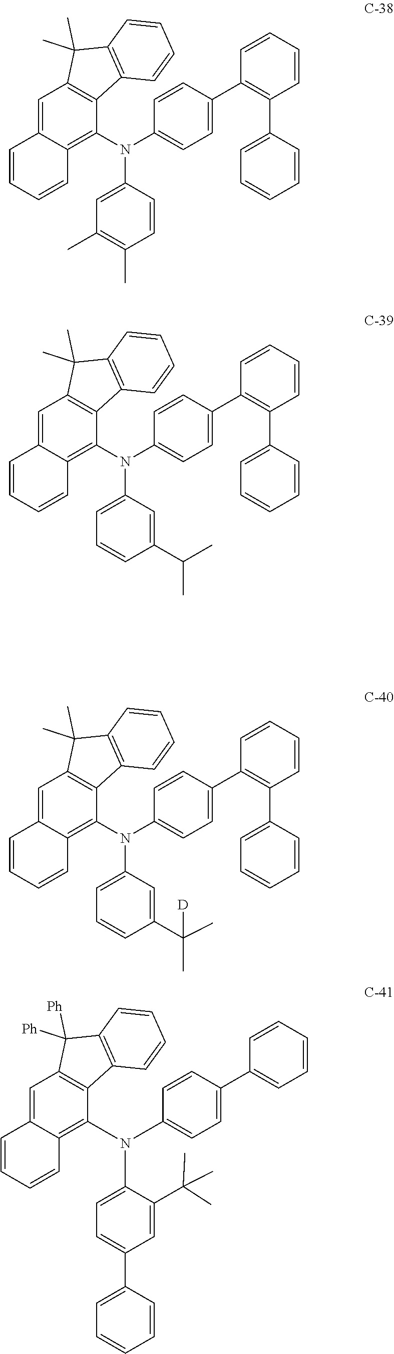 [SMILES: Cc1ccc(N(c2ccc(-c3ccccc3-c3ccccc3)cc2)c2c3c(cc4ccccc24)C(C)(C)c2ccccc2-3)cc1C ; CC(C)c1cccc(N(c2ccc(-c3ccccc3-c3ccccc3)cc2)c2c3c(cc4ccccc24)C(C)(C)c2ccccc2-3)c1 ; [2H]C(C)(C)c1cccc(N(c2ccc(-c3ccccc3-c3ccccc3)cc2)c2c3c(cc4ccccc24)C(C)(C)c2ccccc2-3)c1 ; CC(C)(C)c1cc(-c2ccccc2)ccc1N(c1ccc(-c2ccccc2)cc1)c1c2c(cc3ccccc13)C(c1ccccc1)(c1ccccc1)c1ccccc1-2] 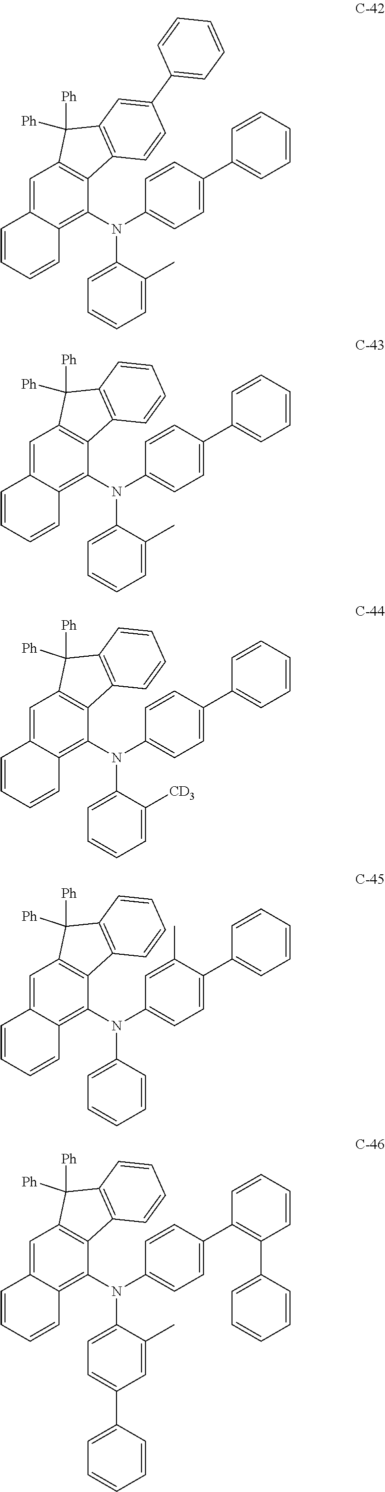 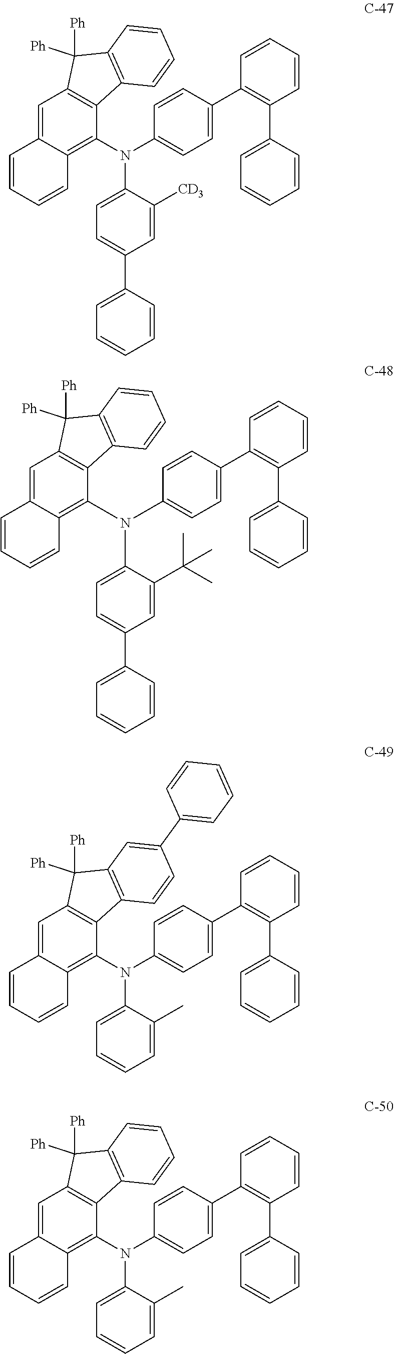 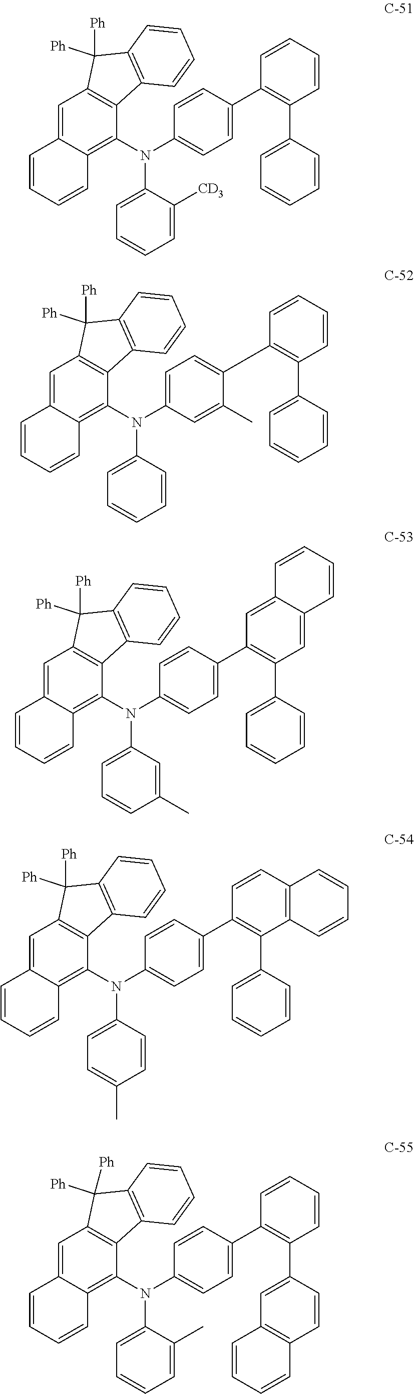 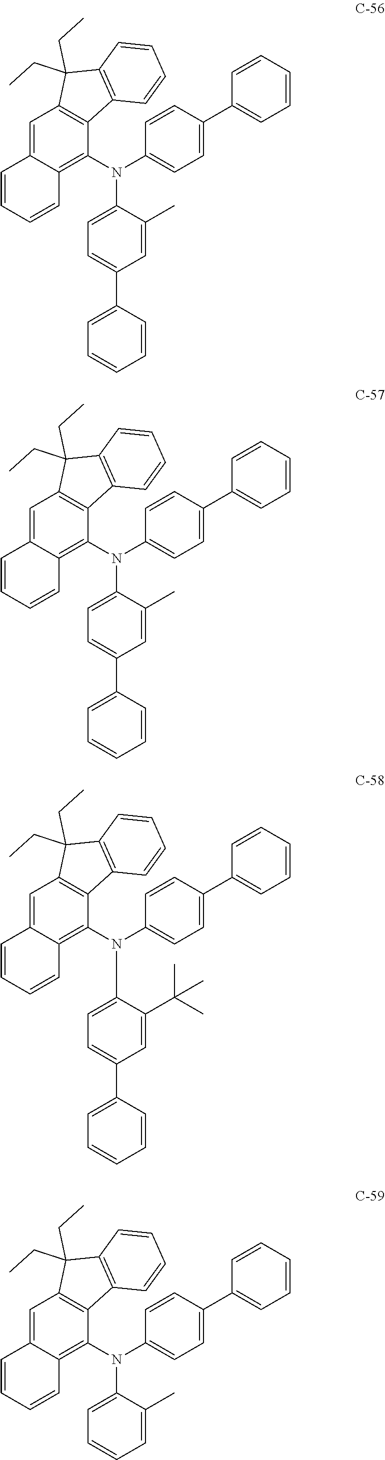 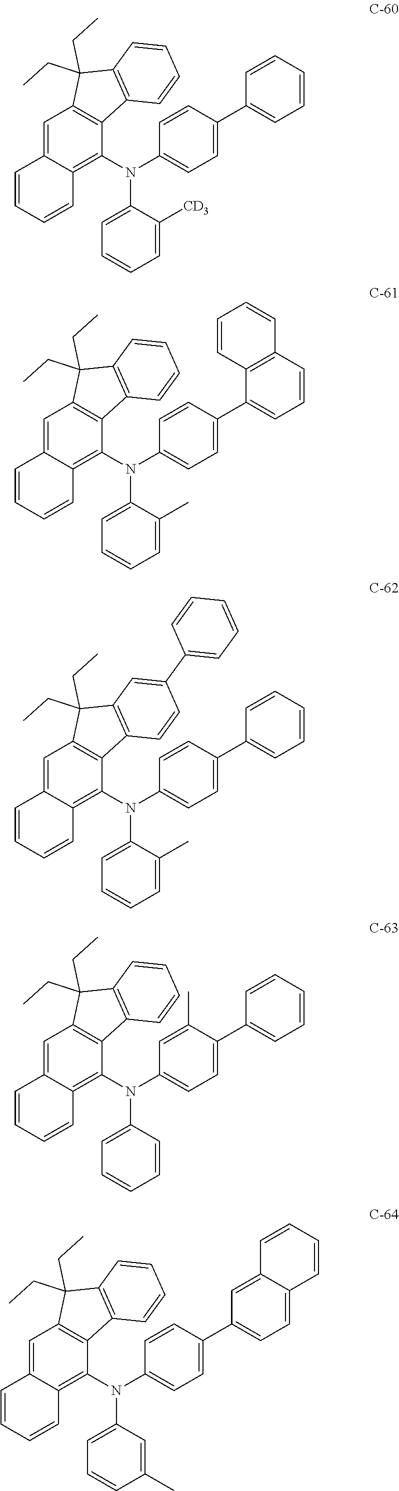 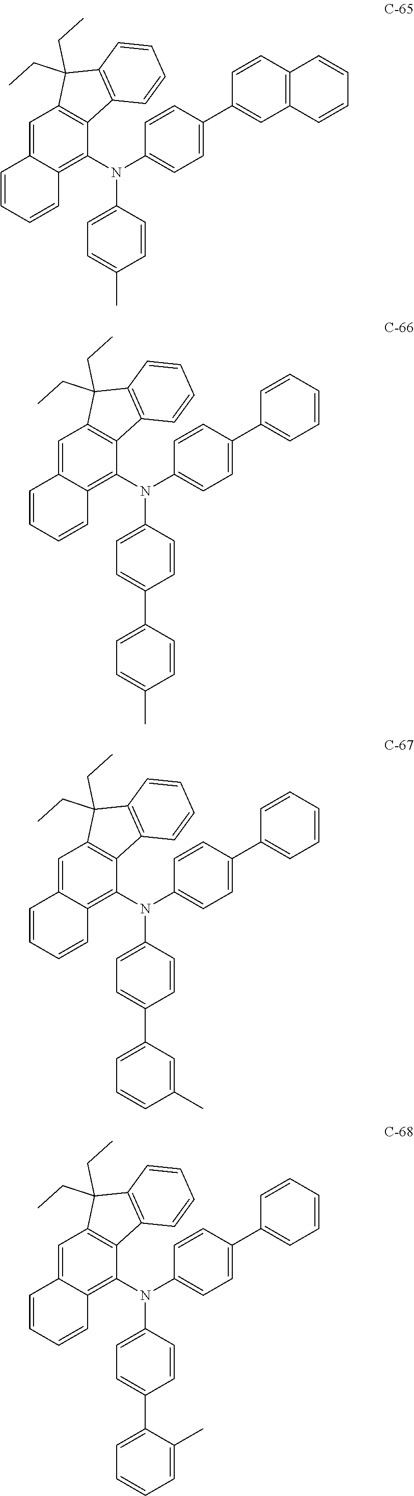 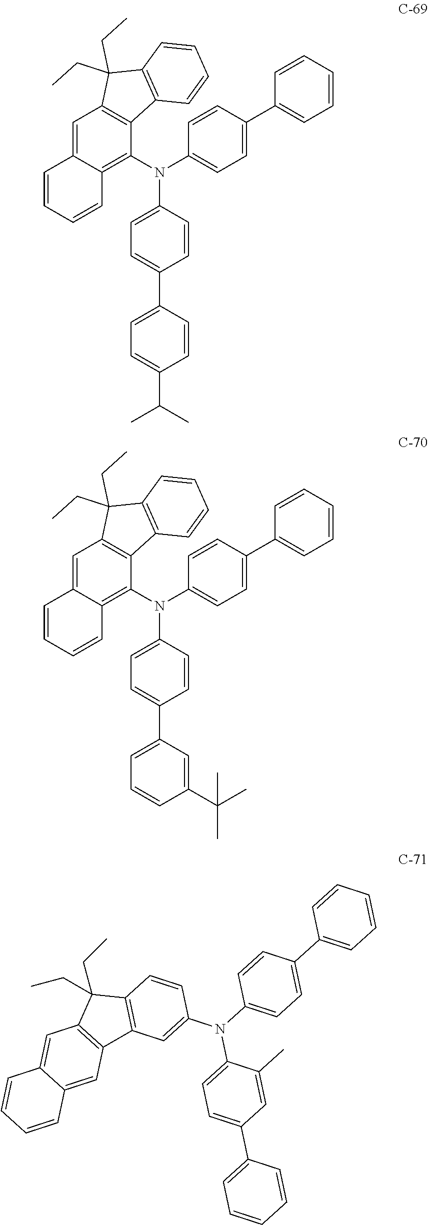 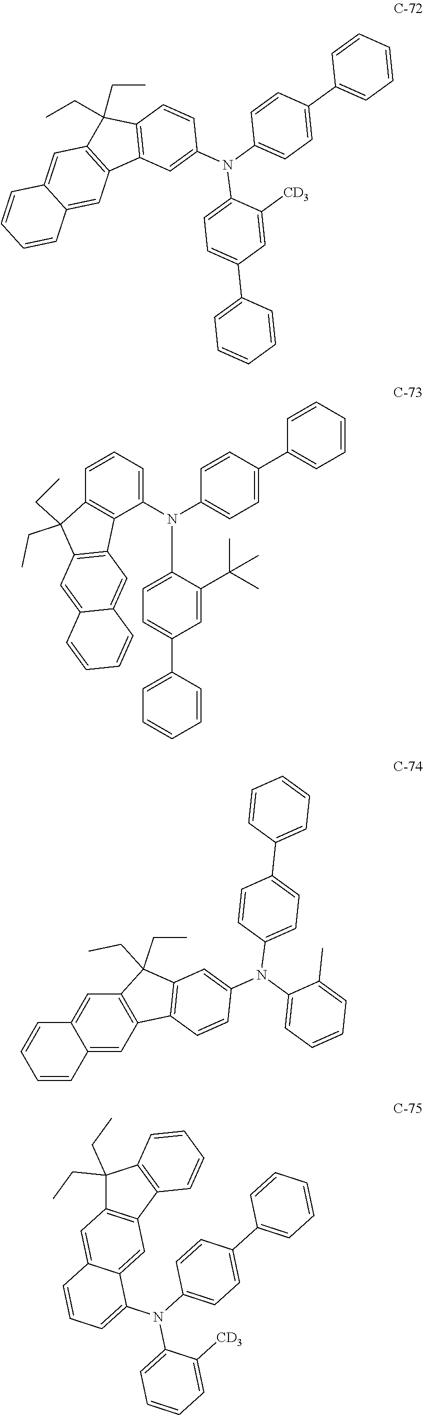 [SMILES: [2H]C([2H])([2H])c1cc(-c2ccccc2)ccc1N(c1ccc(-c2ccccc2)cc1)c1ccc2c(c1)-c1cc3ccccc3cc1C2(CC)CC ; CCC1(CC)c2cc3ccccc3cc2-c2c(N(c3ccc(-c4ccccc4)cc3)c3ccc(-c4ccccc4)cc3C(C)(C)C)cccc21 ; CCC1(CC)c2cc(N(c3ccc(-c4ccccc4)cc3)c3ccccc3C)ccc2-c2cc3ccccc3cc21 ; [2H]C([2H])([2H])c1ccccc1N(c1ccc(-c2ccccc2)cc1)c1cccc2cc3c(cc12)-c1ccccc1C3(CC)CC] 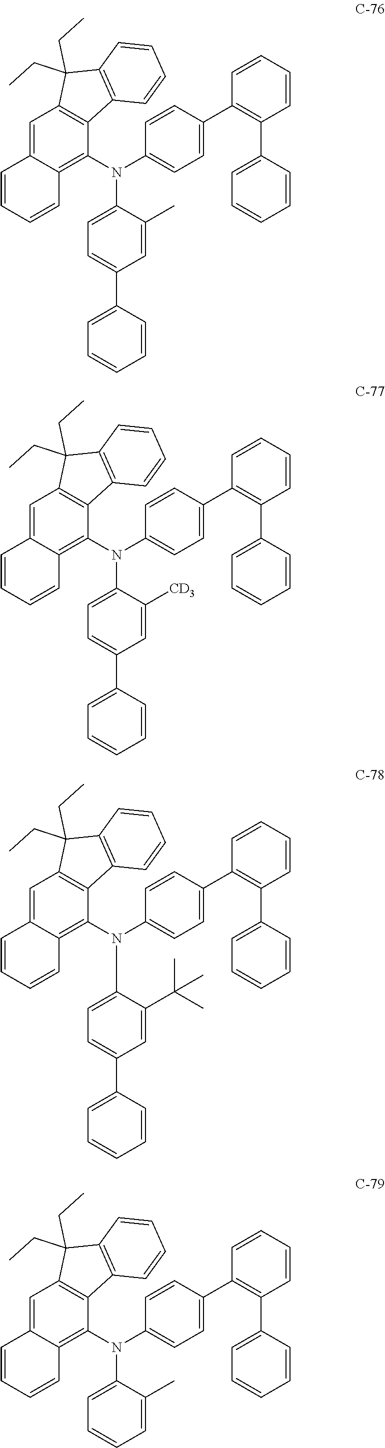 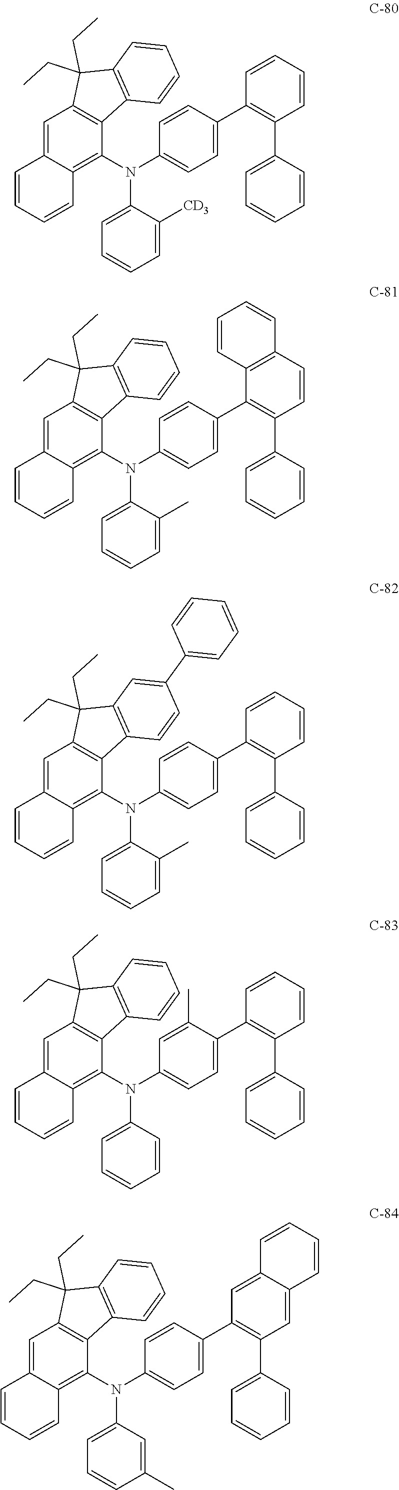 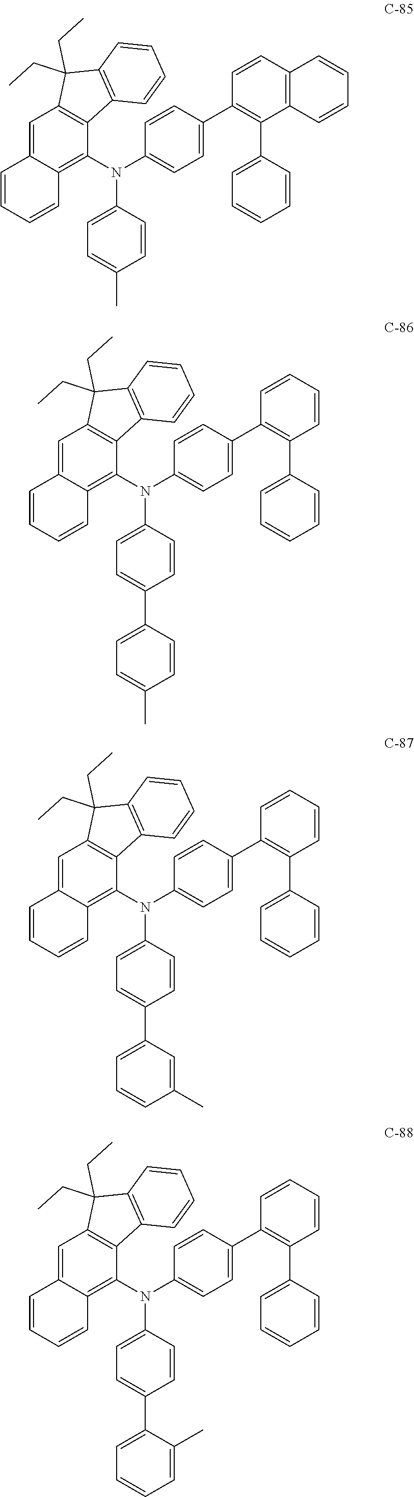 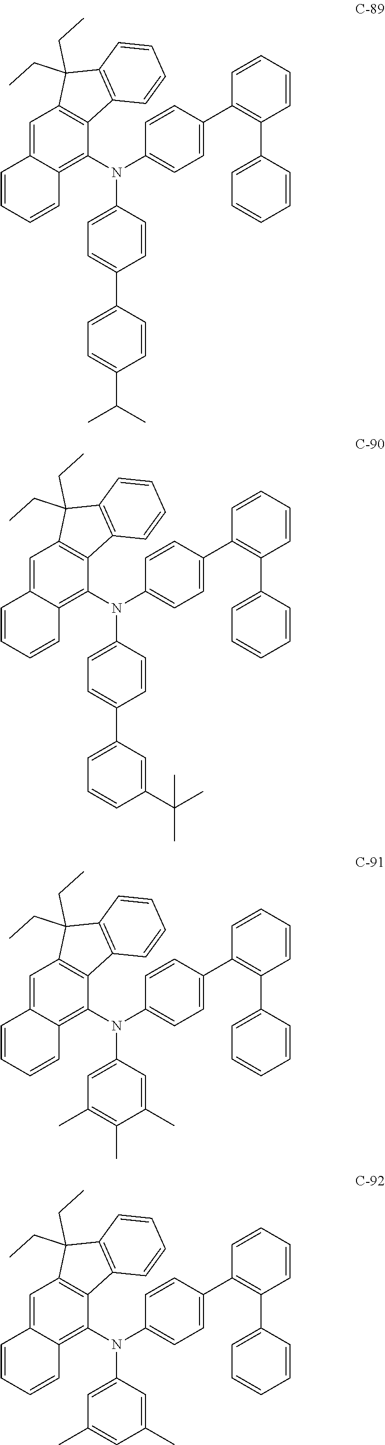 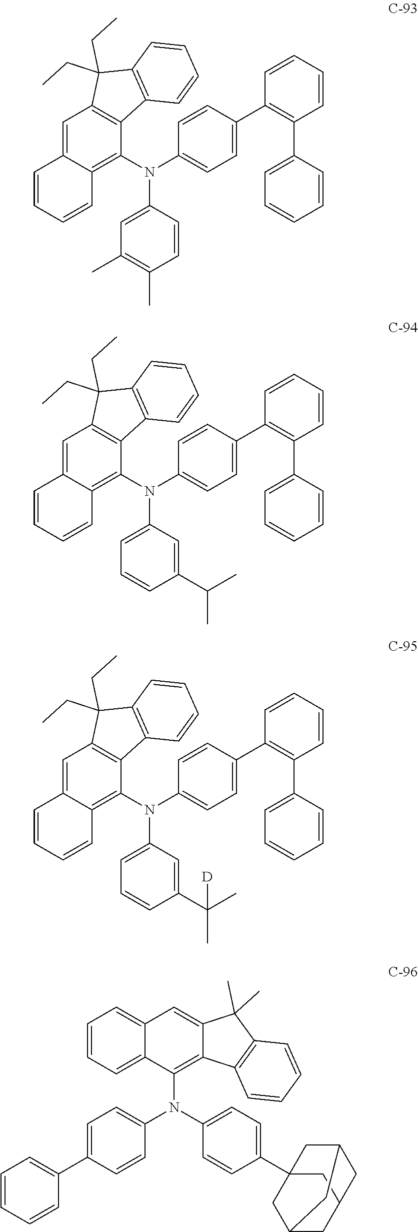 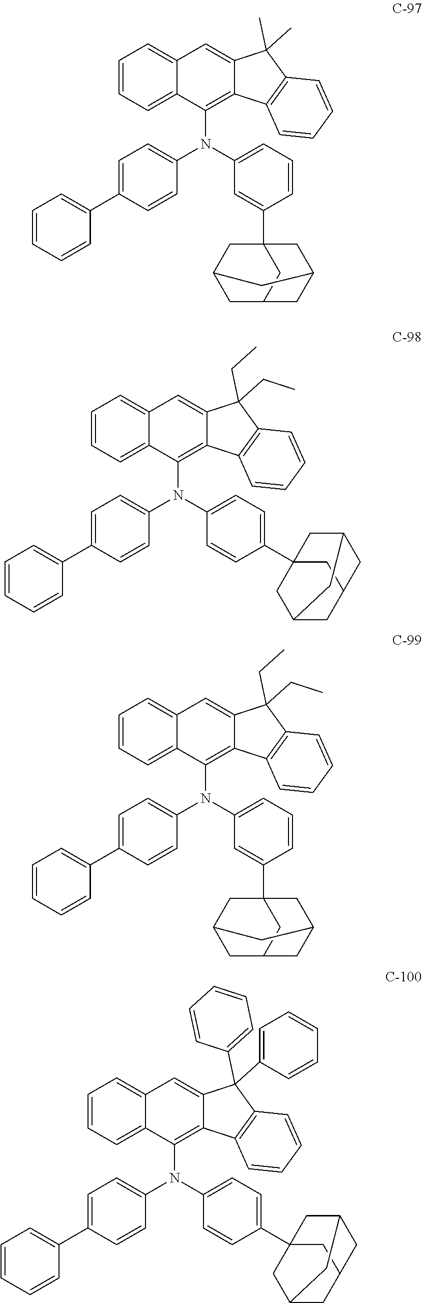 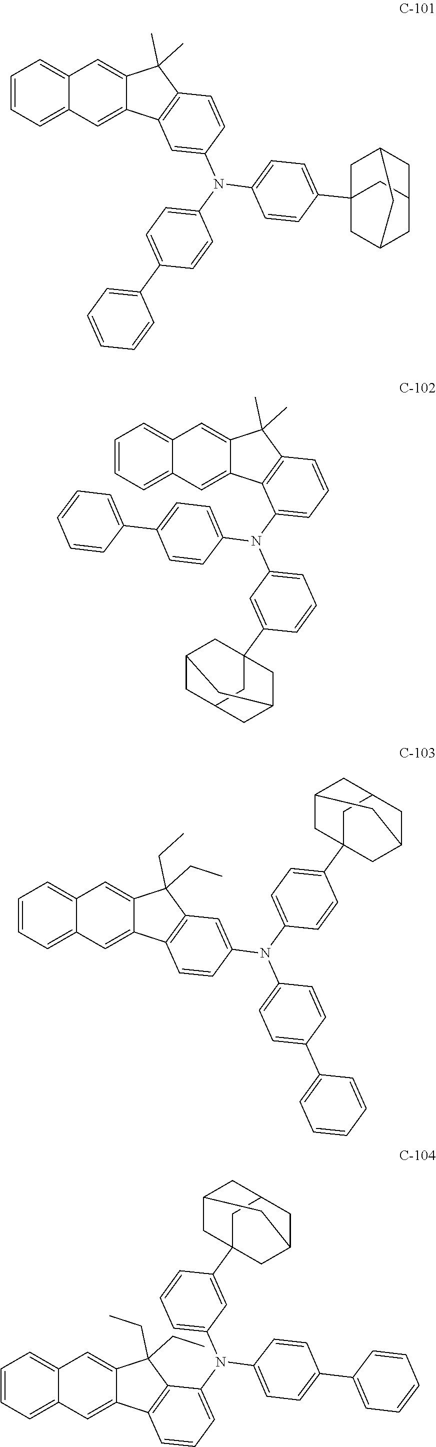 [SMILES: CC1(C)c2ccc(N(c3ccc(-c4ccccc4)cc3)c3ccc(C45CC6CC(CC(C6)C4)C5)cc3)cc2-c2cc3ccccc3cc21 ; CC1(C)c2cc3ccccc3cc2-c2c(N(c3ccc(-c4ccccc4)cc3)c3cccc(C45CC6CC(CC(C6)C4)C5)c3)cccc21 ; CCC1(CC)c2cc(N(c3ccc(-c4ccccc4)cc3)c3ccc(C45CC6CC(CC(C6)C4)C5)cc3)ccc2-c2cc3ccccc3cc21 ; CCC1(CC)c2cc3ccccc3cc2-c2cccc(N(c3ccc(-c4ccccc4)cc3)c3cccc(C45CC6CC(CC(C6)C4)C5)c3)c21] 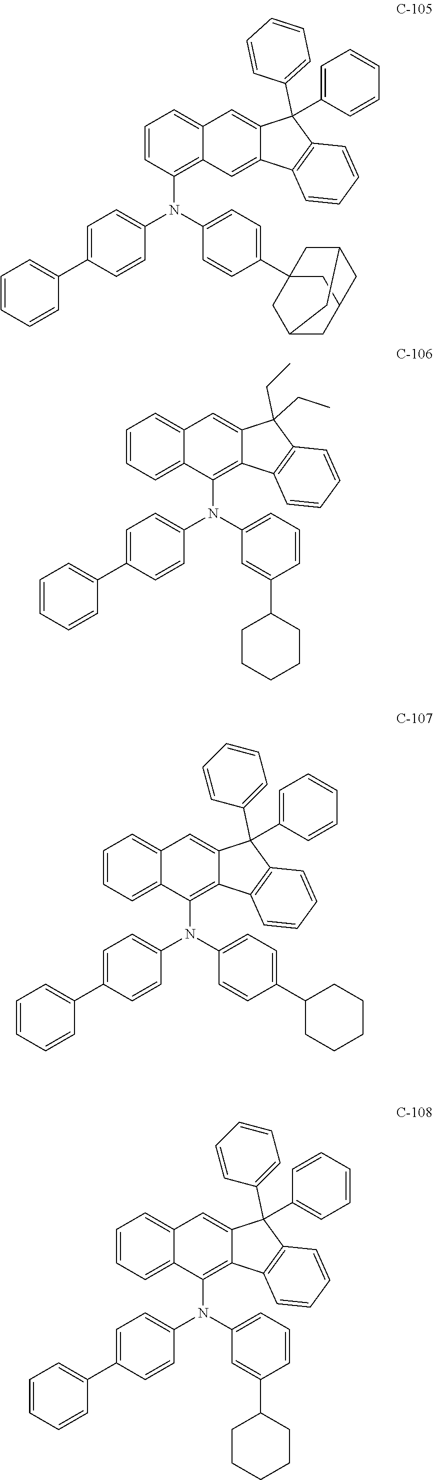 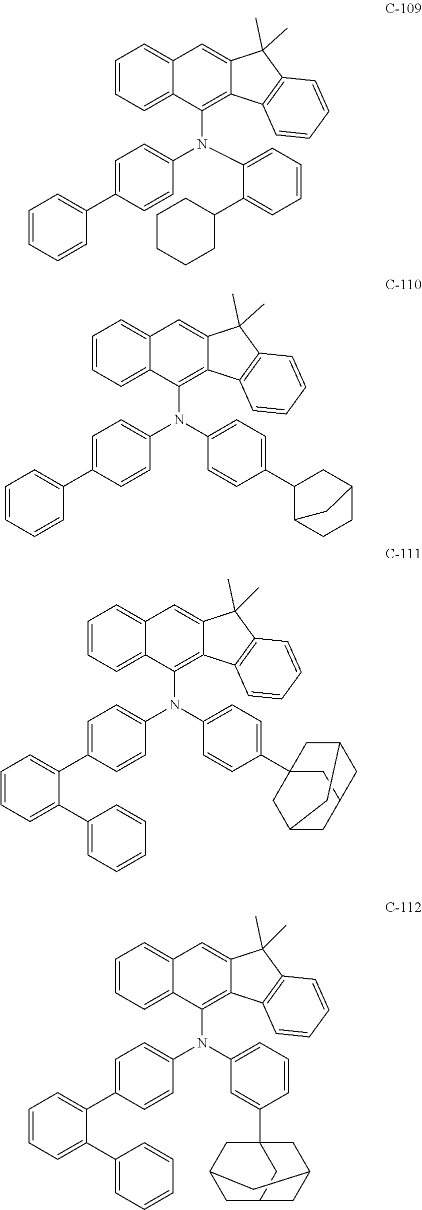 [SMILES: CC1(C)c2ccccc2-c2c1cc1ccccc1c2N(c1ccc(-c2ccccc2)cc1)c1ccccc1C1CCCCC1 ; CC1(C)c2ccccc2-c2c1cc1ccccc1c2N(c1ccc(-c2ccccc2)cc1)c1ccc(C2CC3CCC2C3)cc1 ; CC1(C)c2ccccc2-c2c1cc1ccccc1c2N(c1ccc(-c2ccccc2-c2ccccc2)cc1)c1ccc(C23CC4CC(CC(C4)C2)C3)cc1 ; CC1(C)c2ccccc2-c2c1cc1ccccc1c2N(c1ccc(-c2ccccc2-c2ccccc2)cc1)c1cccc(C23CC4CC(CC(C4)C2)C3)c1] 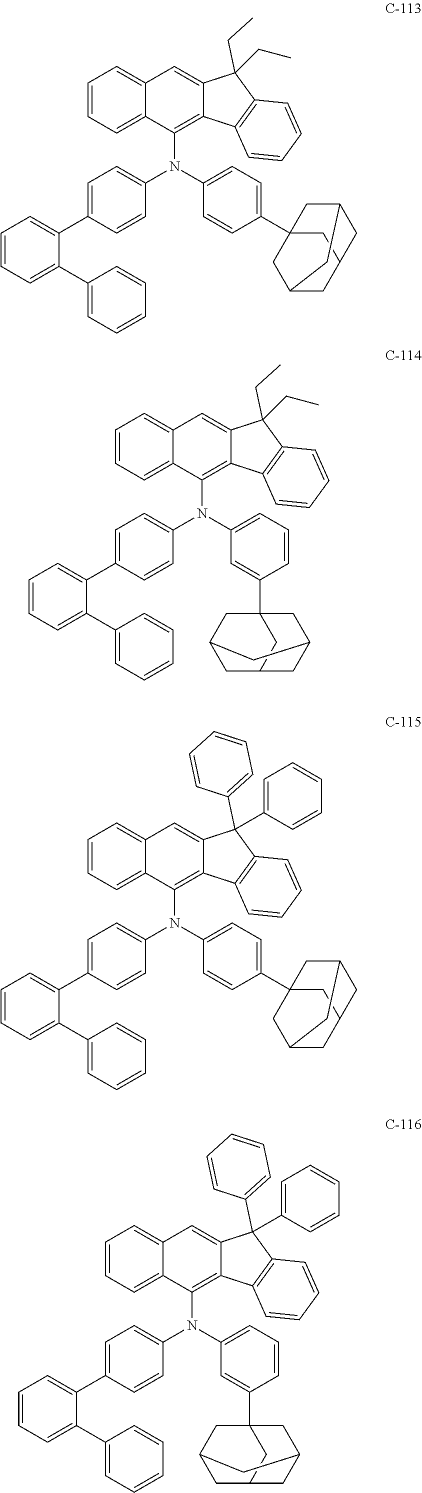 [SMILES: CCC1(CC)c2ccccc2-c2c1cc1ccccc1c2N(c1ccc(-c2ccccc2-c2ccccc2)cc1)c1ccc(C23CC4CC(CC(C4)C2)C3)cc1 ; CCC1(CC)c2ccccc2-c2c1cc1ccccc1c2N(c1ccc(-c2ccccc2-c2ccccc2)cc1)c1cccc(C23CC4CC(CC(C4)C2)C3)c1 ; c1ccc(-c2ccccc2-c2ccc(N(c3ccc(C45CC6CC(CC(C6)C4)C5)cc3)c3c4c(cc5ccccc35)C(c3ccccc3)(c3ccccc3)c3ccccc3-4)cc2)cc1 ; c1ccc(-c2ccccc2-c2ccc(N(c3cccc(C45CC6CC(CC(C6)C4)C5)c3)c3c4c(cc5ccccc35)C(c3ccccc3)(c3ccccc3)c3ccccc3-4)cc2)cc1] 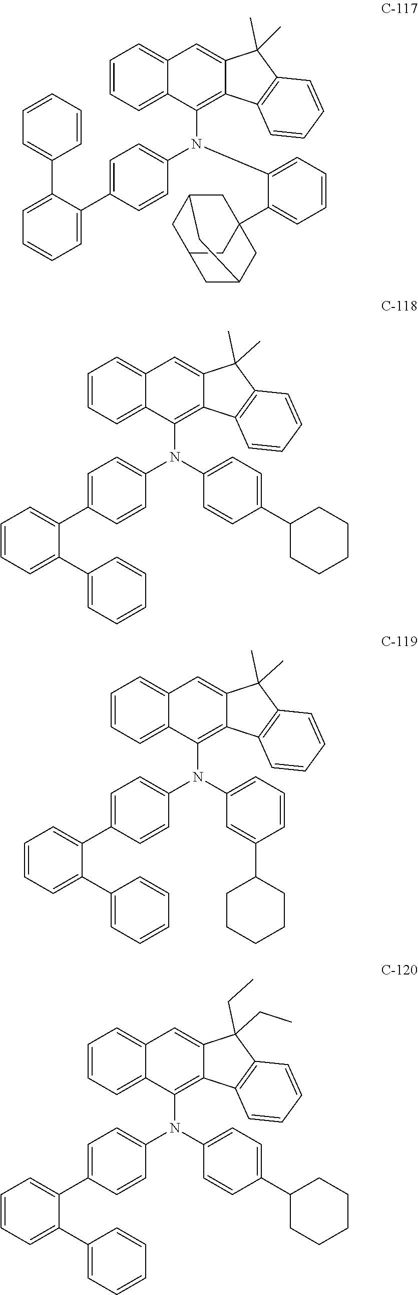 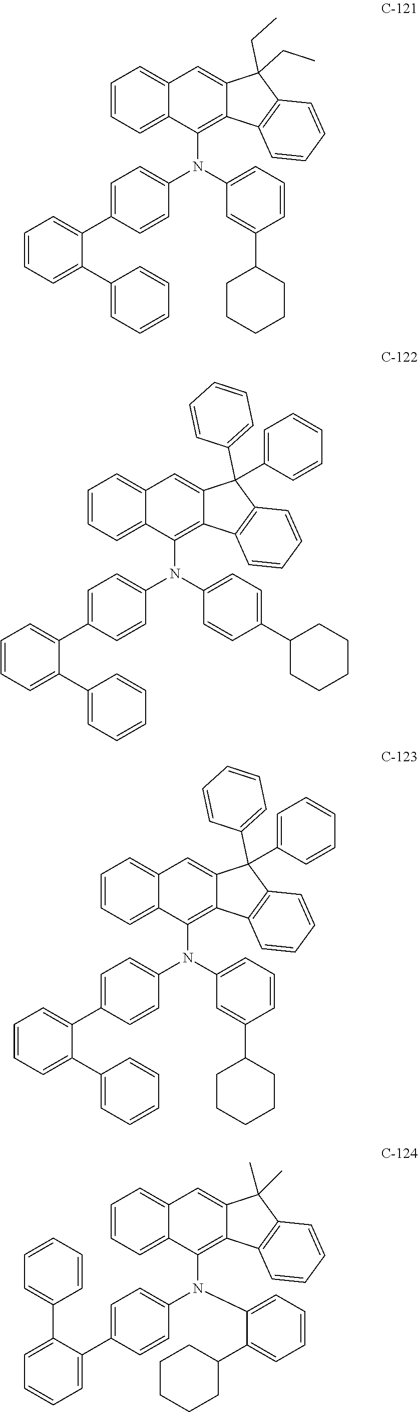 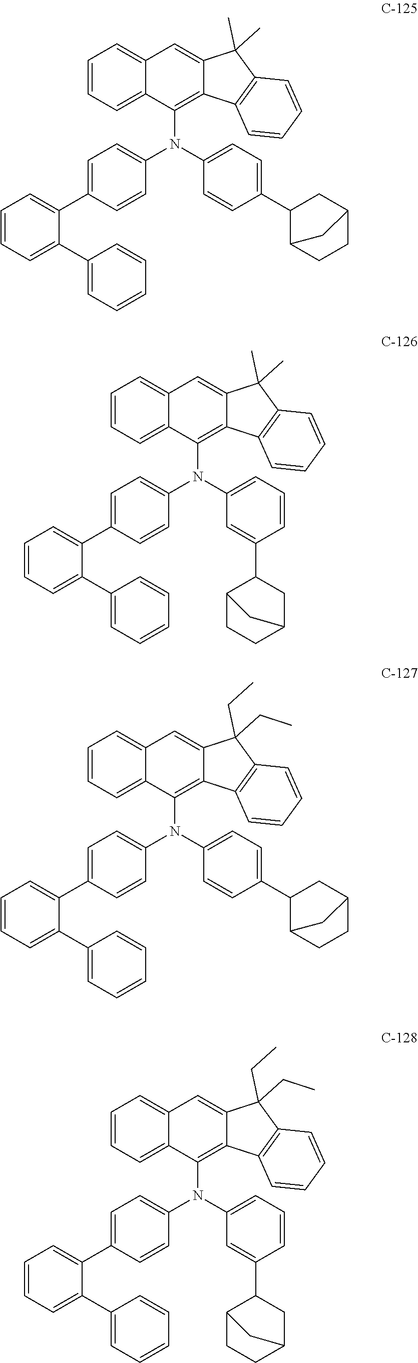 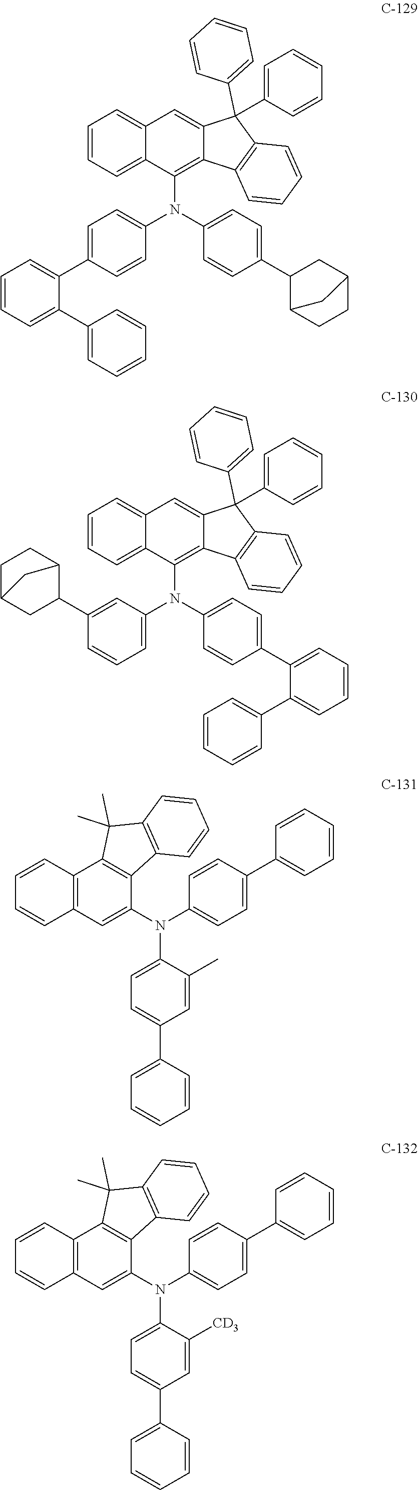 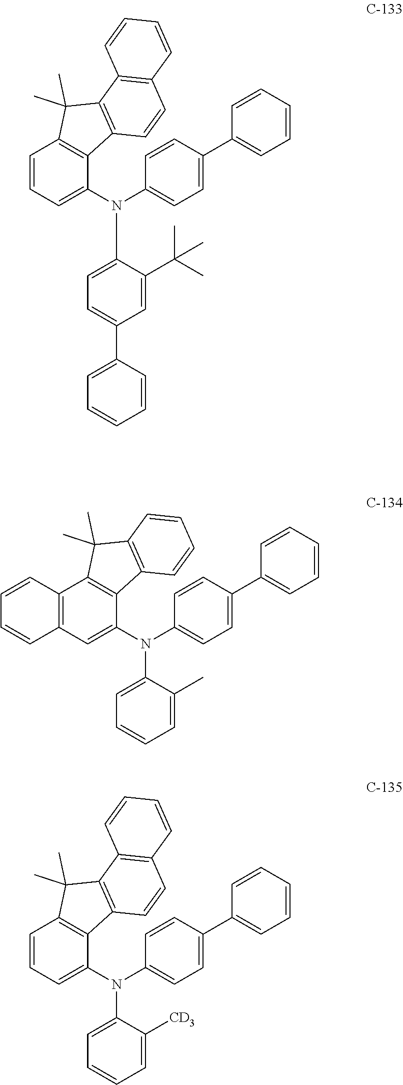 [SMILES: CC(C)(C)c1cc(-c2ccccc2)ccc1N(c1ccc(-c2ccccc2)cc1)c1cccc2c1-c1ccc3ccccc3c1C2(C)C ; Cc1ccccc1N(c1ccc(-c2ccccc2)cc1)c1cc2ccccc2c2c1-c1ccccc1C2(C)C ; [2H]C([2H])([2H])c1ccccc1N(c1ccc(-c2ccccc2)cc1)c1cccc2c1-c1ccc3ccccc3c1C2(C)C] 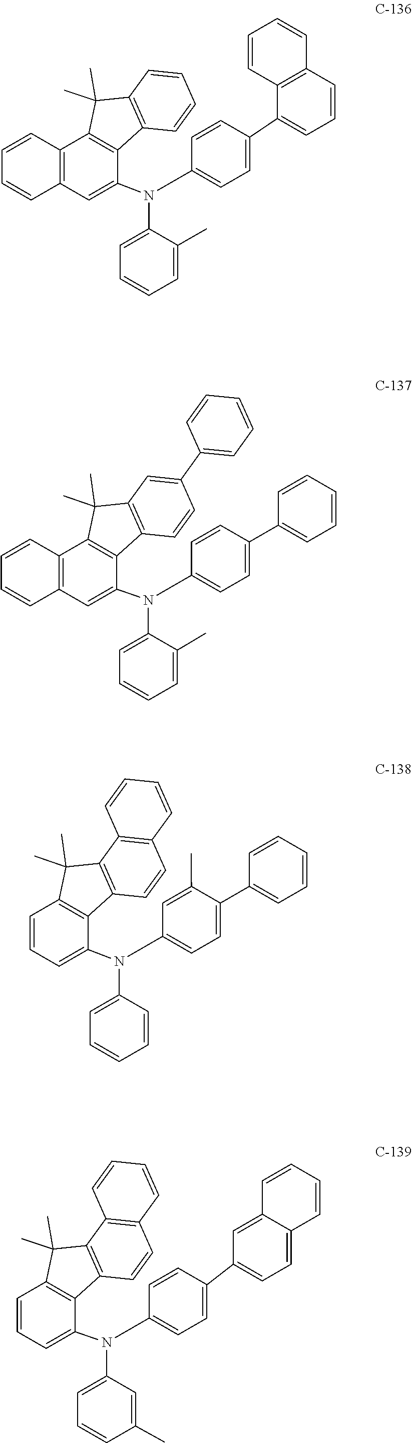 [SMILES: Cc1ccccc1N(c1ccc(-c2cccc3ccccc23)cc1)c1cc2ccccc2c2c1-c1ccccc1C2(C)C ; Cc1ccccc1N(c1ccc(-c2ccccc2)cc1)c1cc2ccccc2c2c1-c1ccc(-c3ccccc3)cc1C2(C)C ; Cc1cc(N(c2ccccc2)c2cccc3c2-c2ccc4ccccc4c2C3(C)C)ccc1-c1ccccc1 ; Cc1cccc(N(c2ccc(-c3ccc4ccccc4c3)cc2)c2cccc3c2-c2ccc4ccccc4c2C3(C)C)c1] 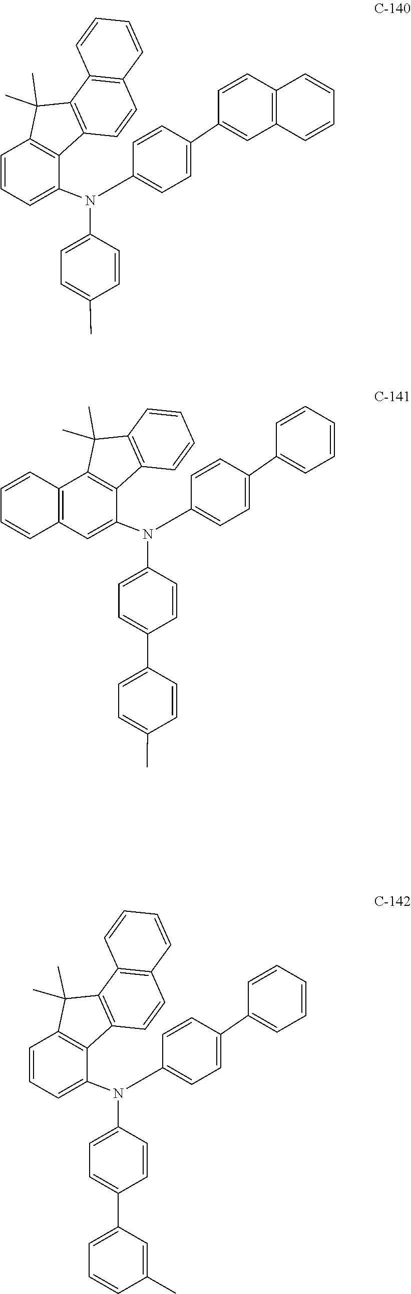 [SMILES: Cc1ccc(N(c2ccc(-c3ccc4ccccc4c3)cc2)c2cccc3c2-c2ccc4ccccc4c2C3(C)C)cc1 ; Cc1ccc(-c2ccc(N(c3ccc(-c4ccccc4)cc3)c3cc4ccccc4c4c3-c3ccccc3C4(C)C)cc2)cc1 ; Cc1cccc(-c2ccc(N(c3ccc(-c4ccccc4)cc3)c3cccc4c3-c3ccc5ccccc5c3C4(C)C)cc2)c1] 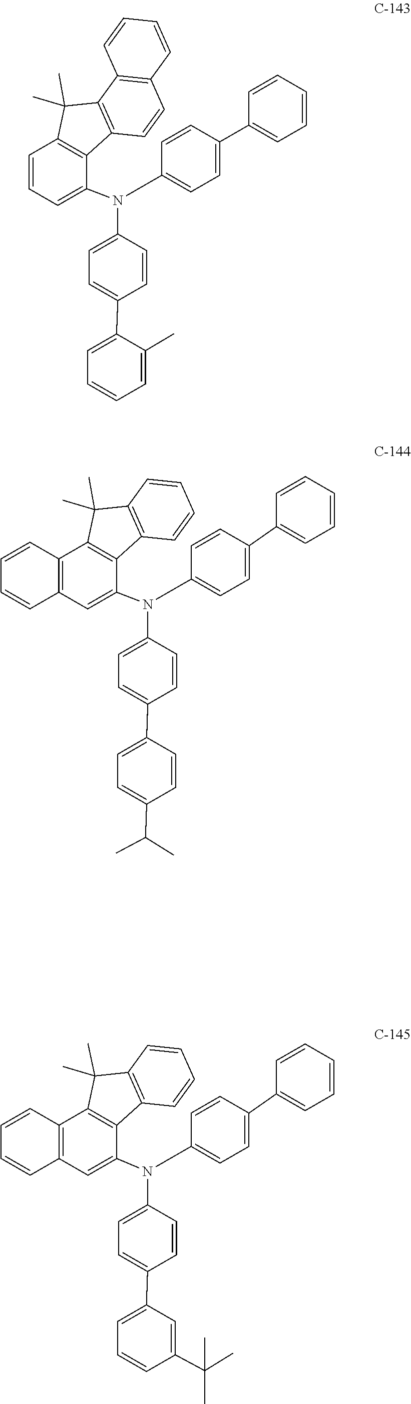 [SMILES: Cc1ccccc1-c1ccc(N(c2ccc(-c3ccccc3)cc2)c2cccc3c2-c2ccc4ccccc4c2C3(C)C)cc1 ; CC(C)c1ccc(-c2ccc(N(c3ccc(-c4ccccc4)cc3)c3cc4ccccc4c4c3-c3ccccc3C4(C)C)cc2)cc1 ; CC(C)(C)c1cccc(-c2ccc(N(c3ccc(-c4ccccc4)cc3)c3cc4ccccc4c4c3-c3ccccc3C4(C)C)cc2)c1] 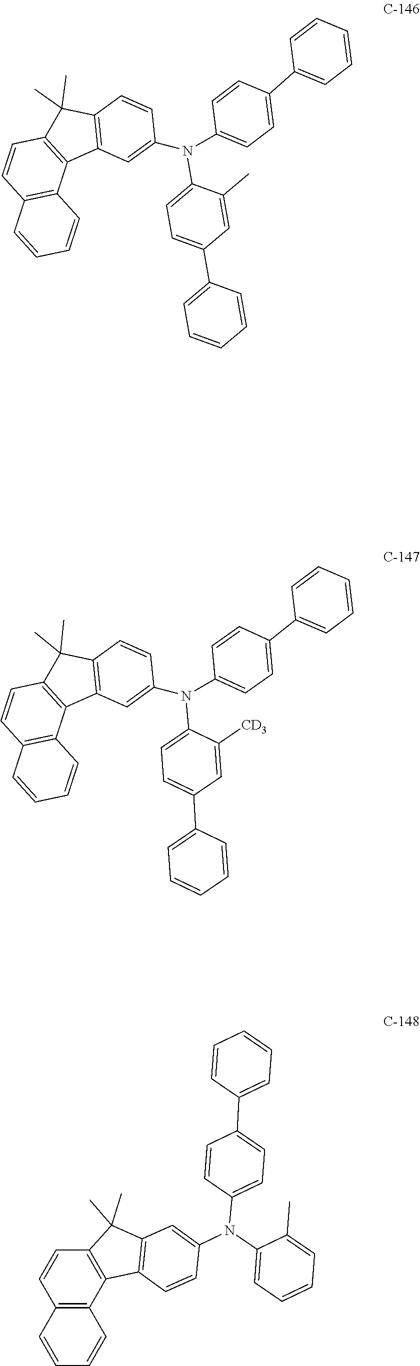 [SMILES: Cc1cc(-c2ccccc2)ccc1N(c1ccc(-c2ccccc2)cc1)c1ccc2c(c1)-c1c(ccc3ccccc13)C2(C)C ; [2H]C([2H])([2H])c1cc(-c2ccccc2)ccc1N(c1ccc(-c2ccccc2)cc1)c1ccc2c(c1)-c1c(ccc3ccccc13)C2(C)C ; Cc1ccccc1N(c1ccc(-c2ccccc2)cc1)c1ccc2c(c1)C(C)(C)c1ccc3ccccc3c1-2] 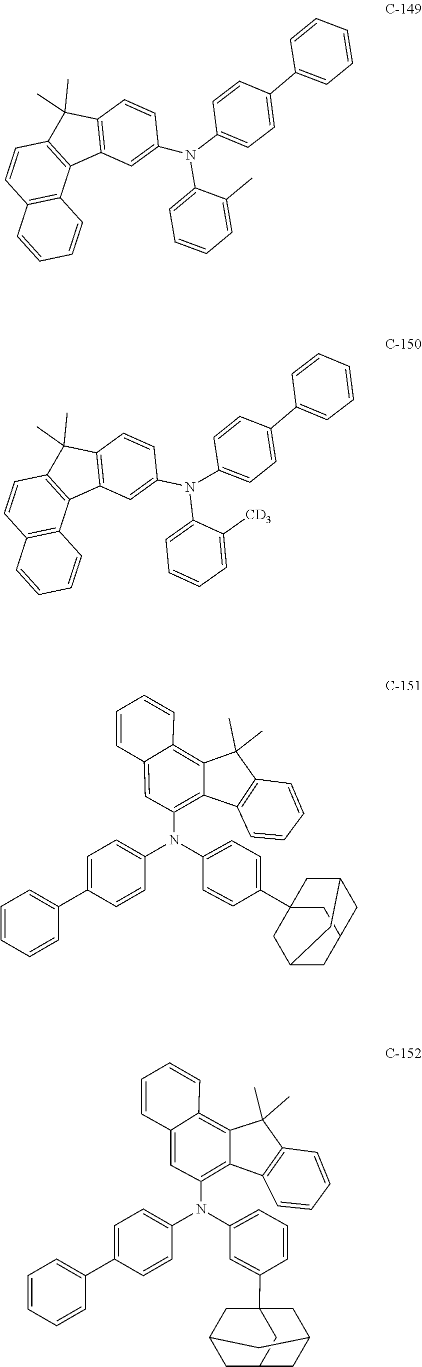 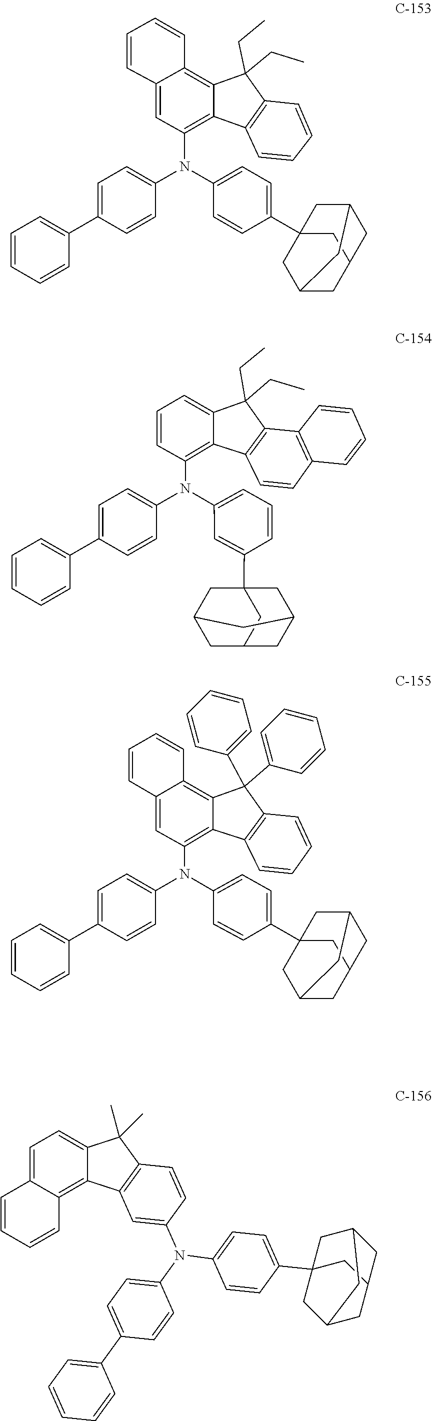 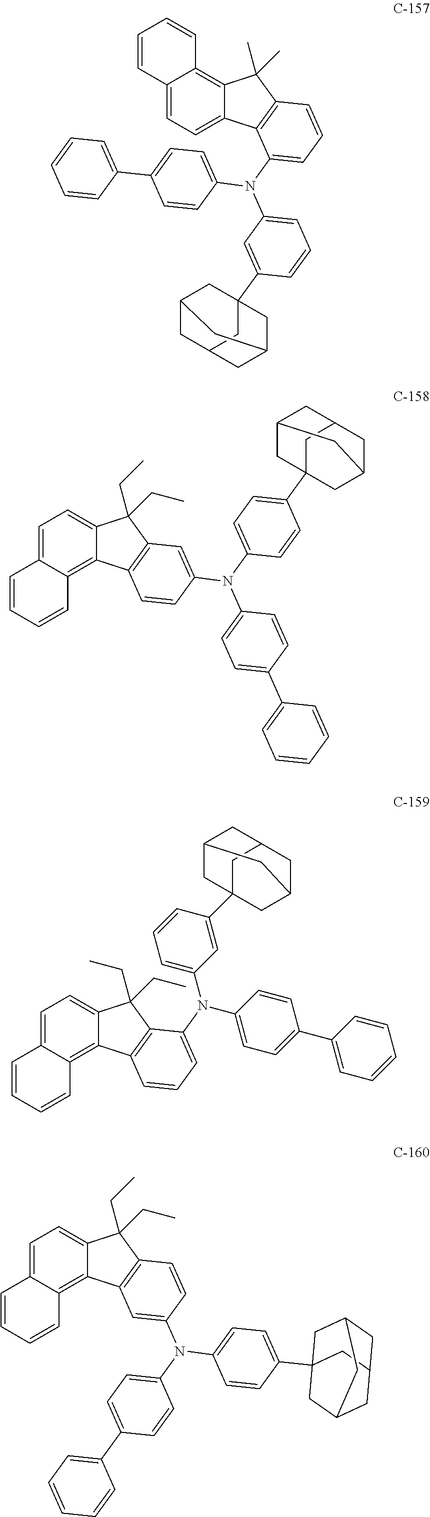 [SMILES: CC1(C)c2cccc(N(c3ccc(-c4ccccc4)cc3)c3cccc(C45CC6CC(CC(C6)C4)C5)c3)c2-c2ccc3ccccc3c21 ; CCC1(CC)c2cc(N(c3ccc(-c4ccccc4)cc3)c3ccc(C45CC6CC(CC(C6)C4)C5)cc3)ccc2-c2c1ccc1ccccc21 ; CCC1(CC)c2ccc3ccccc3c2-c2cccc(N(c3ccc(-c4ccccc4)cc3)c3cccc(C45CC6CC(CC(C6)C4)C5)c3)c21 ; CCC1(CC)c2ccc(N(c3ccc(-c4ccccc4)cc3)c3ccc(C45CC6CC(CC(C6)C4)C5)cc3)cc2-c2c1ccc1ccccc21] 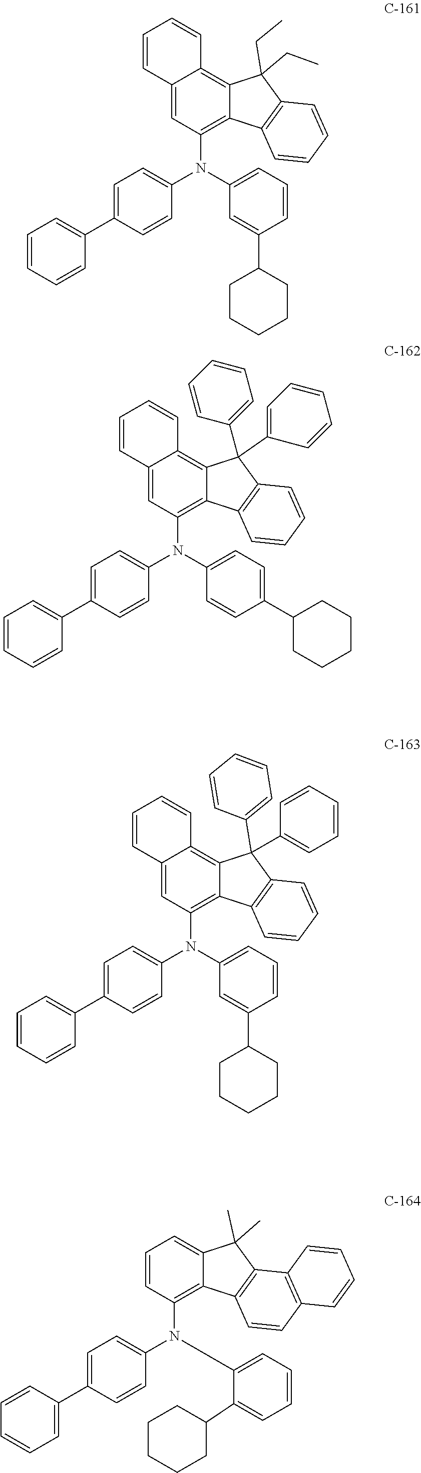 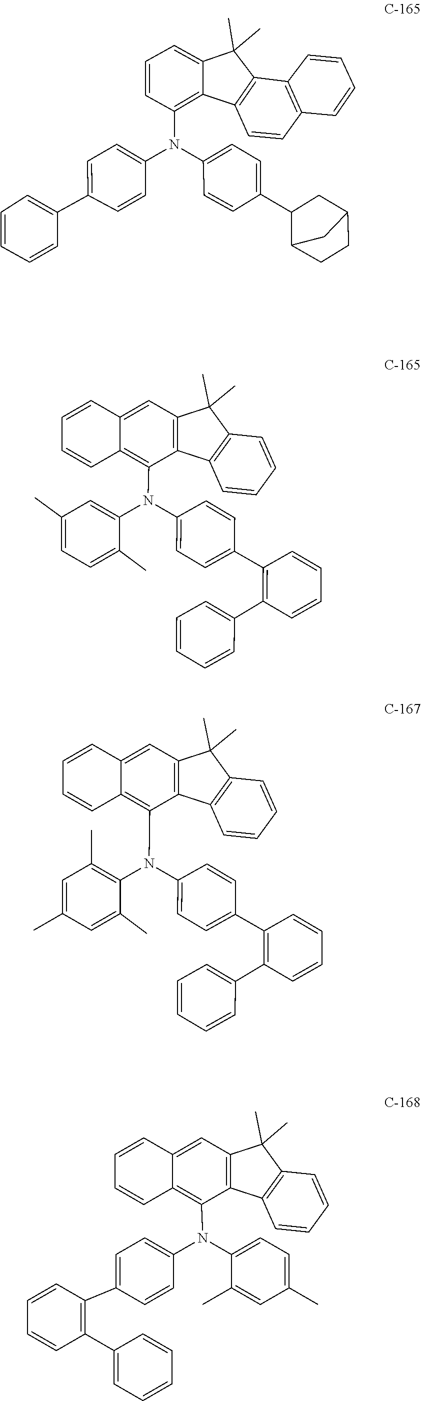 [SMILES: CC1(C)c2cccc(N(c3ccc(-c4ccccc4)cc3)c3ccc(C4CC5CCC4C5)cc3)c2-c2ccc3ccccc3c21 ; Cc1ccc(C)c(N(c2ccc(-c3ccccc3-c3ccccc3)cc2)c2c3c(cc4ccccc24)C(C)(C)c2ccccc2-3)c1 ; Cc1cc(C)c(N(c2ccc(-c3ccccc3-c3ccccc3)cc2)c2c3c(cc4ccccc24)C(C)(C)c2ccccc2-3)c(C)c1 ; Cc1ccc(N(c2ccc(-c3ccccc3-c3ccccc3)cc2)c2c3c(cc4ccccc24)C(C)(C)c2ccccc2-3)c(C)c1] 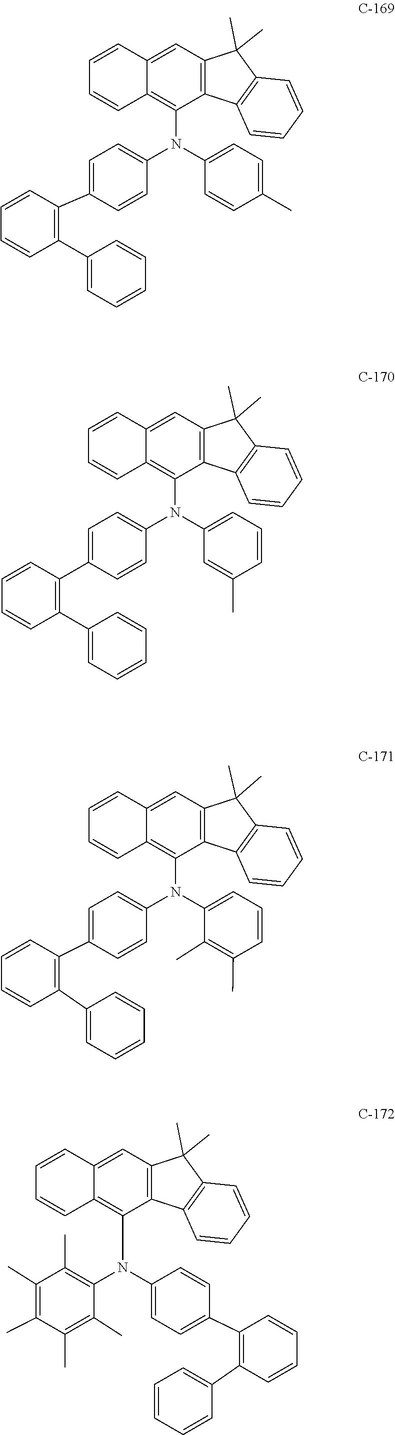 [SMILES: Cc1ccc(N(c2ccc(-c3ccccc3-c3ccccc3)cc2)c2c3c(cc4ccccc24)C(C)(C)c2ccccc2-3)cc1 ; Cc1cccc(N(c2ccc(-c3ccccc3-c3ccccc3)cc2)c2c3c(cc4ccccc24)C(C)(C)c2ccccc2-3)c1 ; Cc1cccc(N(c2ccc(-c3ccccc3-c3ccccc3)cc2)c2c3c(cc4ccccc24)C(C)(C)c2ccccc2-3)c1C ; Cc1c(C)c(C)c(N(c2ccc(-c3ccccc3-c3ccccc3)cc2)c2c3c(cc4ccccc24)C(C)(C)c2ccccc2-3)c(C)c1C] 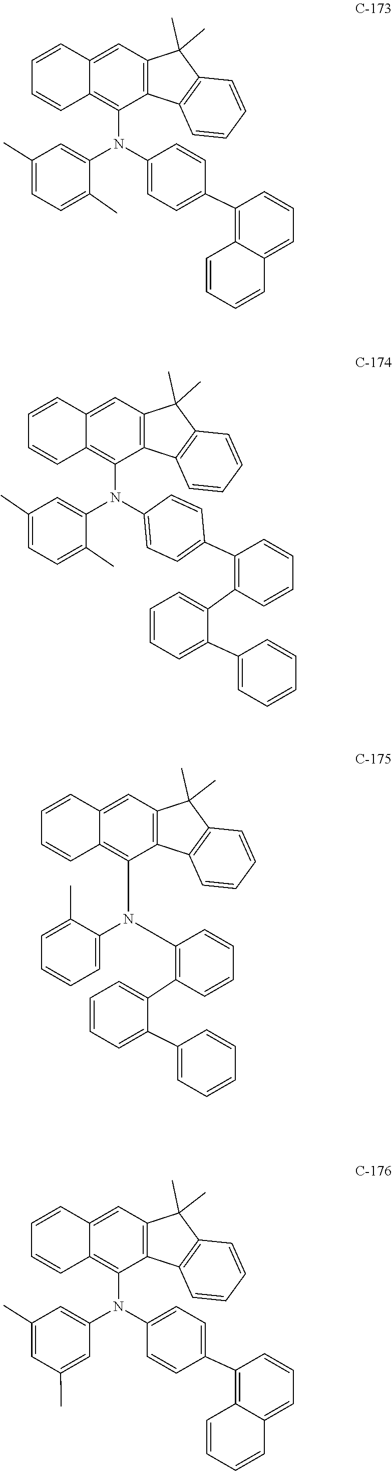 [SMILES: Cc1ccc(C)c(N(c2ccc(-c3cccc4ccccc34)cc2)c2c3c(cc4ccccc24)C(C)(C)c2ccccc2-3)c1 ; Cc1ccc(C)c(N(c2ccc(-c3ccccc3-c3ccccc3-c3ccccc3)cc2)c2c3c(cc4ccccc24)C(C)(C)c2ccccc2-3)c1 ; Cc1ccccc1N(c1ccccc1-c1ccccc1-c1ccccc1)c1c2c(cc3ccccc13)C(C)(C)c1ccccc1-2 ; Cc1cc(C)cc(N(c2ccc(-c3cccc4ccccc34)cc2)c2c3c(cc4ccccc24)C(C)(C)c2ccccc2-3)c1] 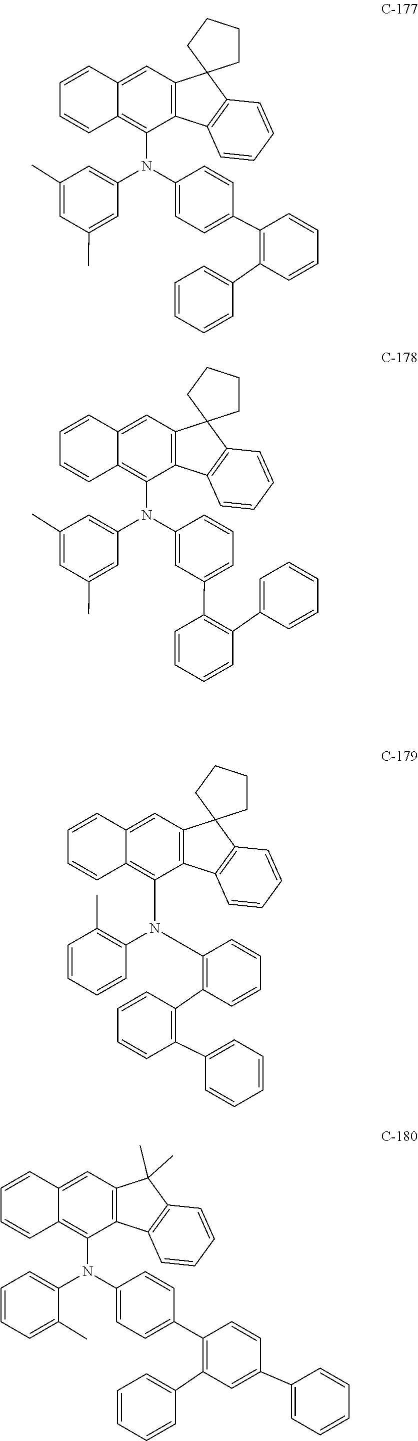 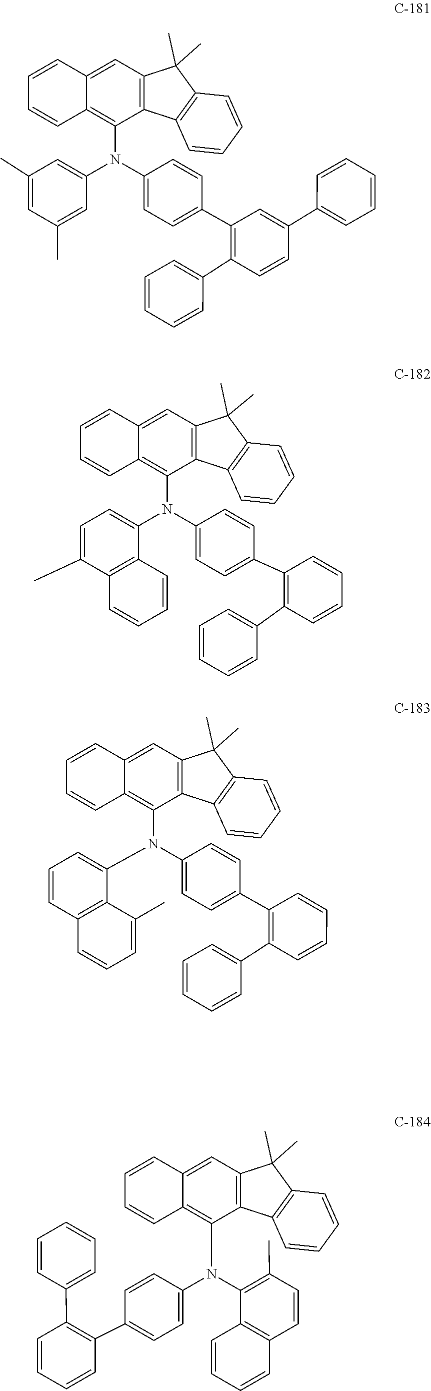 [SMILES: Cc1cc(C)cc(N(c2ccc(-c3cc(-c4ccccc4)ccc3-c3ccccc3)cc2)c2c3c(cc4ccccc24)C(C)(C)c2ccccc2-3)c1 ; Cc1ccc(N(c2ccc(-c3ccccc3-c3ccccc3)cc2)c2c3c(cc4ccccc24)C(C)(C)c2ccccc2-3)c2ccccc12 ; Cc1cccc2cccc(N(c3ccc(-c4ccccc4-c4ccccc4)cc3)c3c4c(cc5ccccc35)C(C)(C)c3ccccc3-4)c12 ; Cc1ccc2ccccc2c1N(c1ccc(-c2ccccc2-c2ccccc2)cc1)c1c2c(cc3ccccc13)C(C)(C)c1ccccc1-2] 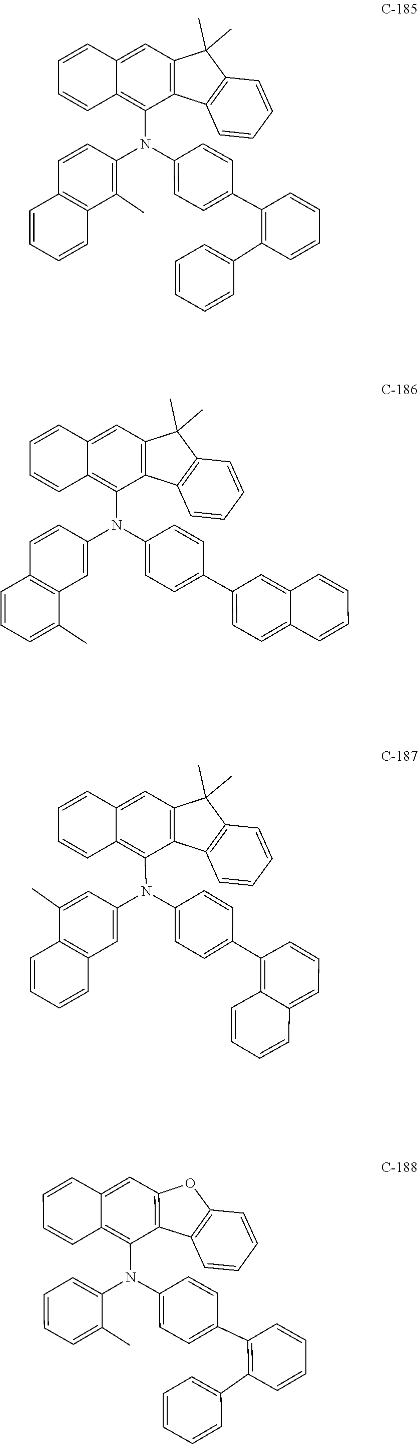 [SMILES: Cc1c(N(c2ccc(-c3ccccc3-c3ccccc3)cc2)c2c3c(cc4ccccc24)C(C)(C)c2ccccc2-3)ccc2ccccc12 ; Cc1cccc2ccc(N(c3ccc(-c4ccc5ccccc5c4)cc3)c3c4c(cc5ccccc35)C(C)(C)c3ccccc3-4)cc12 ; Cc1cc(N(c2ccc(-c3cccc4ccccc34)cc2)c2c3c(cc4ccccc24)C(C)(C)c2ccccc2-3)cc2ccccc12 ; Cc1ccccc1N(c1ccc(-c2ccccc2-c2ccccc2)cc1)c1c2ccccc2cc2oc3ccccc3c12] 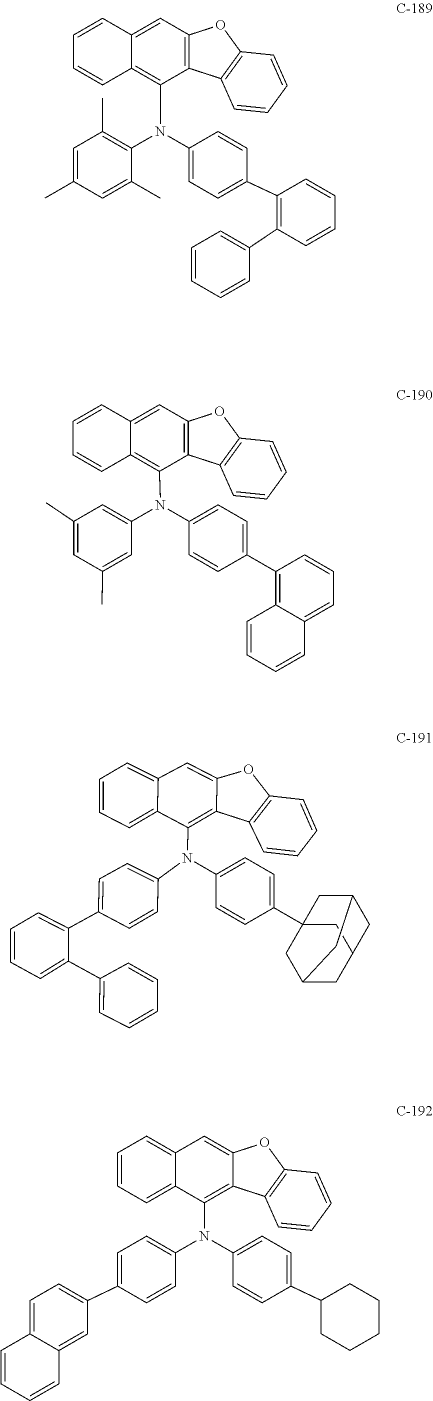 [SMILES: Cc1cc(C)c(N(c2ccc(-c3ccccc3-c3ccccc3)cc2)c2c3ccccc3cc3oc4ccccc4c23)c(C)c1 ; Cc1cc(C)cc(N(c2ccc(-c3cccc4ccccc34)cc2)c2c3ccccc3cc3oc4ccccc4c23)c1 ; c1ccc(-c2ccccc2-c2ccc(N(c3ccc(C45CC6CC(CC(C6)C4)C5)cc3)c3c4ccccc4cc4oc5ccccc5c34)cc2)cc1 ; c1ccc2cc(-c3ccc(N(c4ccc(C5CCCCC5)cc4)c4c5ccccc5cc5oc6ccccc6c45)cc3)ccc2c1] 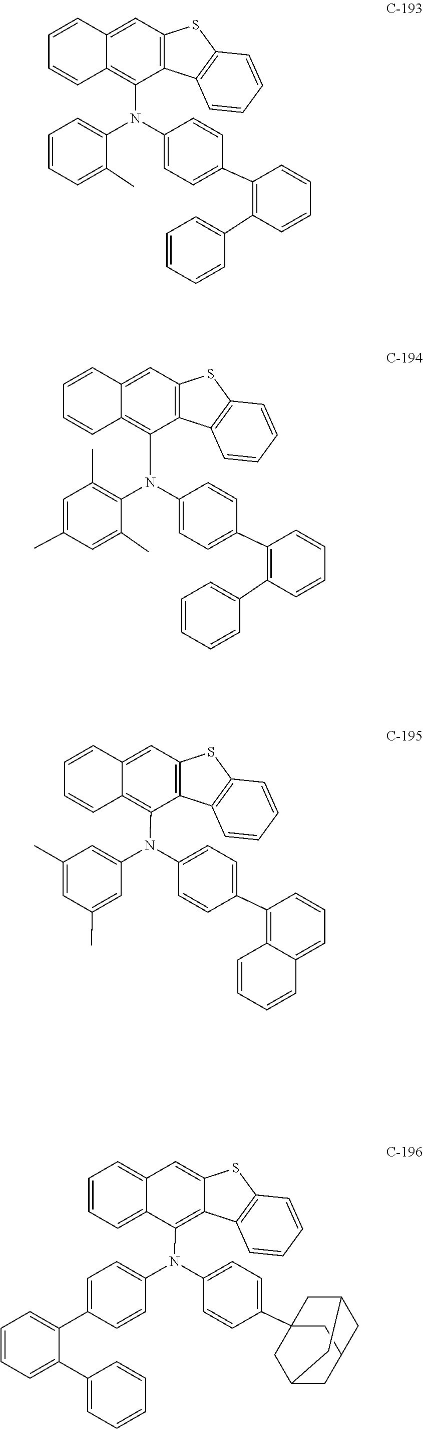 [SMILES: Cc1ccccc1N(c1ccc(-c2ccccc2-c2ccccc2)cc1)c1c2ccccc2cc2sc3ccccc3c12 ; Cc1cc(C)c(N(c2ccc(-c3ccccc3-c3ccccc3)cc2)c2c3ccccc3cc3sc4ccccc4c23)c(C)c1 ; Cc1cc(C)cc(N(c2ccc(-c3cccc4ccccc34)cc2)c2c3ccccc3cc3sc4ccccc4c23)c1 ; c1ccc(-c2ccccc2-c2ccc(N(c3ccc(C45CC6CC(CC(C6)C4)C5)cc3)c3c4ccccc4cc4sc5ccccc5c34)cc2)cc1] 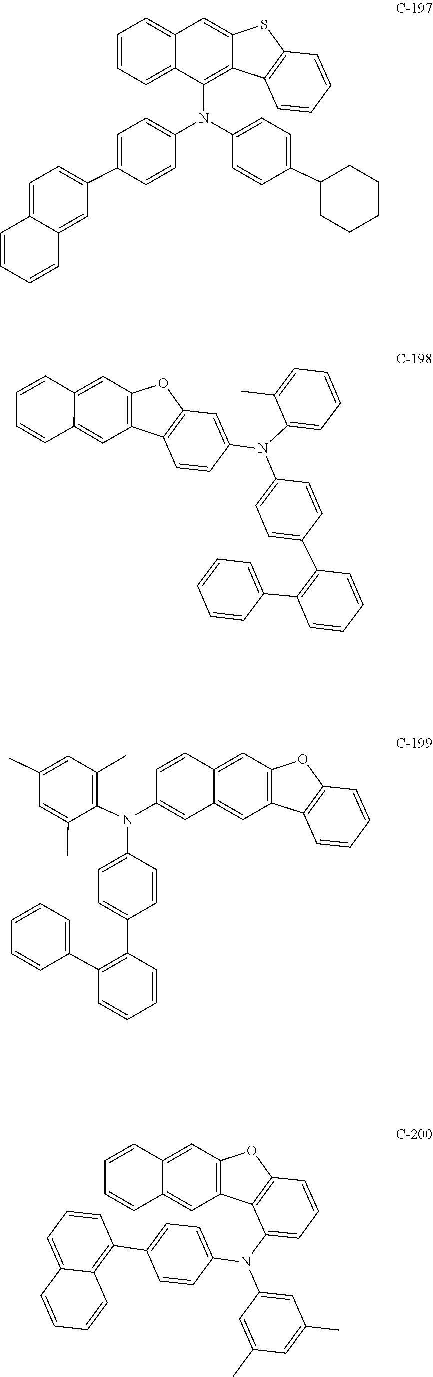 [SMILES: c1ccc2cc(-c3ccc(N(c4ccc(C5CCCCC5)cc4)c4c5ccccc5cc5sc6ccccc6c45)cc3)ccc2c1 ; Cc1ccccc1N(c1ccc(-c2ccccc2-c2ccccc2)cc1)c1ccc2c(c1)oc1cc3ccccc3cc12 ; Cc1cc(C)c(N(c2ccc(-c3ccccc3-c3ccccc3)cc2)c2ccc3cc4oc5ccccc5c4cc3c2)c(C)c1 ; Cc1cc(C)cc(N(c2ccc(-c3cccc4ccccc34)cc2)c2cccc3oc4cc5ccccc5cc4c23)c1] 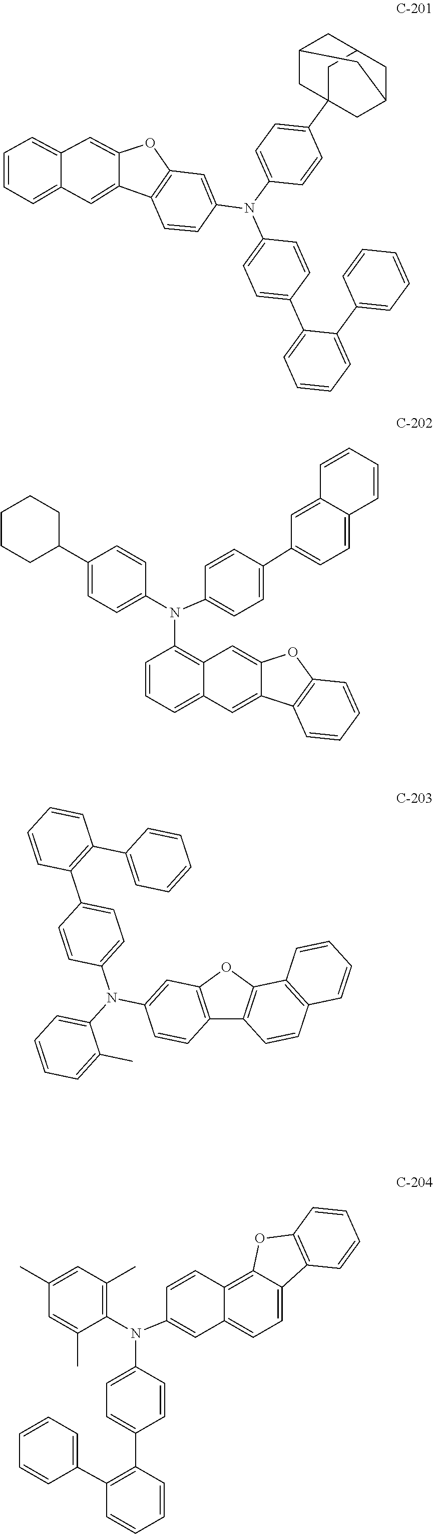 [SMILES: c1ccc(-c2ccccc2-c2ccc(N(c3ccc(C45CC6CC(CC(C6)C4)C5)cc3)c3ccc4c(c3)oc3cc5ccccc5cc34)cc2)cc1 ; c1ccc2cc(-c3ccc(N(c4ccc(C5CCCCC5)cc4)c4cccc5cc6c(cc45)oc4ccccc46)cc3)ccc2c1 ; Cc1ccccc1N(c1ccc(-c2ccccc2-c2ccccc2)cc1)c1ccc2c(c1)oc1c3ccccc3ccc21 ; Cc1cc(C)c(N(c2ccc(-c3ccccc3-c3ccccc3)cc2)c2ccc3c(ccc4c5ccccc5oc34)c2)c(C)c1] 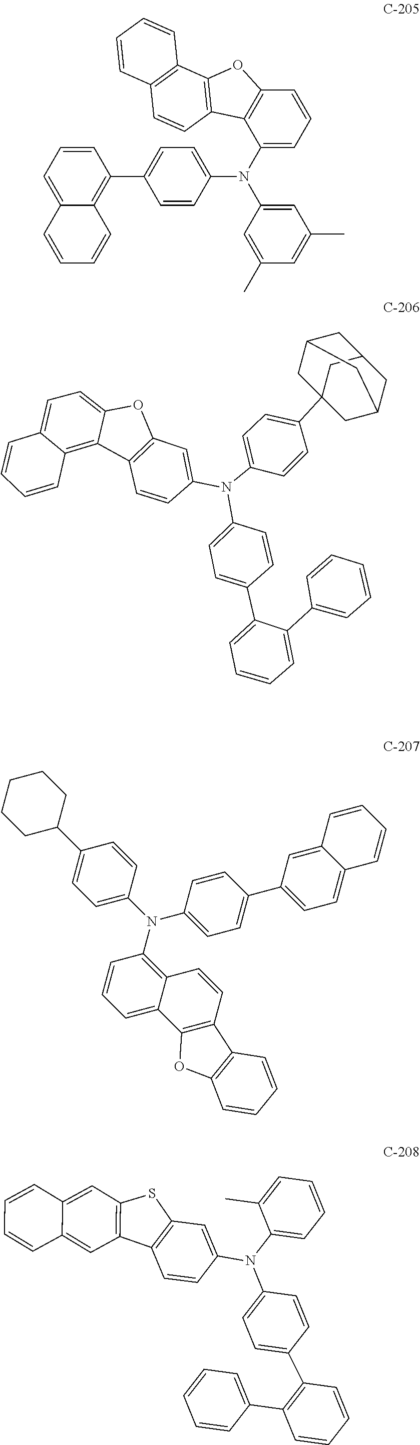 [SMILES: Cc1cc(C)cc(N(c2ccc(-c3cccc4ccccc34)cc2)c2cccc3oc4c5ccccc5ccc4c23)c1 ; c1ccc(-c2ccccc2-c2ccc(N(c3ccc(C45CC6CC(CC(C6)C4)C5)cc3)c3ccc4c(c3)oc3ccc5ccccc5c34)cc2)cc1 ; c1ccc2cc(-c3ccc(N(c4ccc(C5CCCCC5)cc4)c4cccc5c4ccc4c6ccccc6oc54)cc3)ccc2c1 ; Cc1ccccc1N(c1ccc(-c2ccccc2-c2ccccc2)cc1)c1ccc2c(c1)sc1cc3ccccc3cc12] 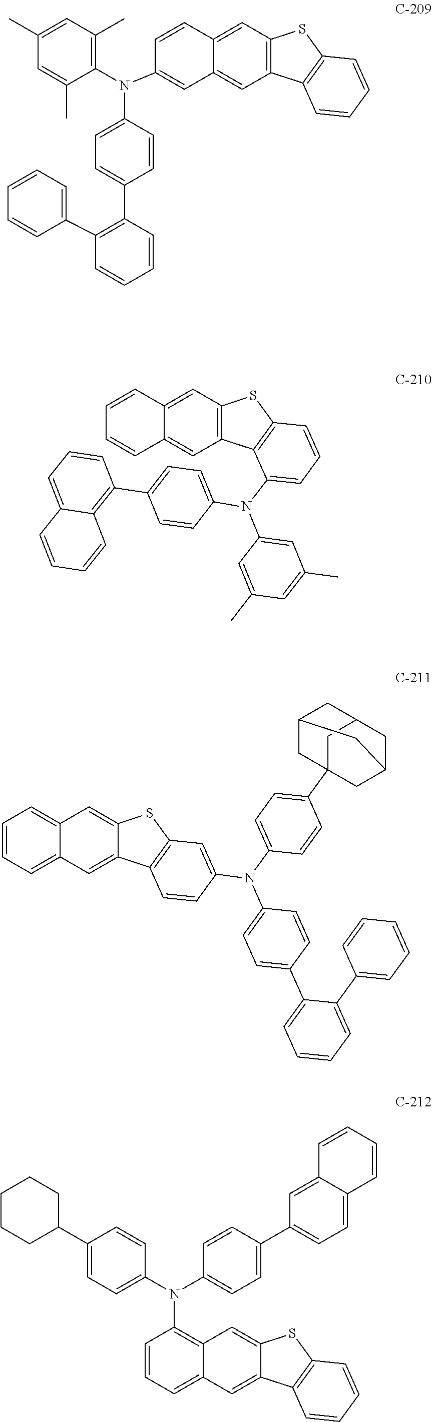 [SMILES: Cc1cc(C)c(N(c2ccc(-c3ccccc3-c3ccccc3)cc2)c2ccc3cc4sc5ccccc5c4cc3c2)c(C)c1 ; Cc1cc(C)cc(N(c2ccc(-c3cccc4ccccc34)cc2)c2cccc3sc4cc5ccccc5cc4c23)c1 ; c1ccc(-c2ccccc2-c2ccc(N(c3ccc(C45CC6CC(CC(C6)C4)C5)cc3)c3ccc4c(c3)sc3cc5ccccc5cc34)cc2)cc1 ; c1ccc2cc(-c3ccc(N(c4ccc(C5CCCCC5)cc4)c4cccc5cc6c(cc45)sc4ccccc46)cc3)ccc2c1] 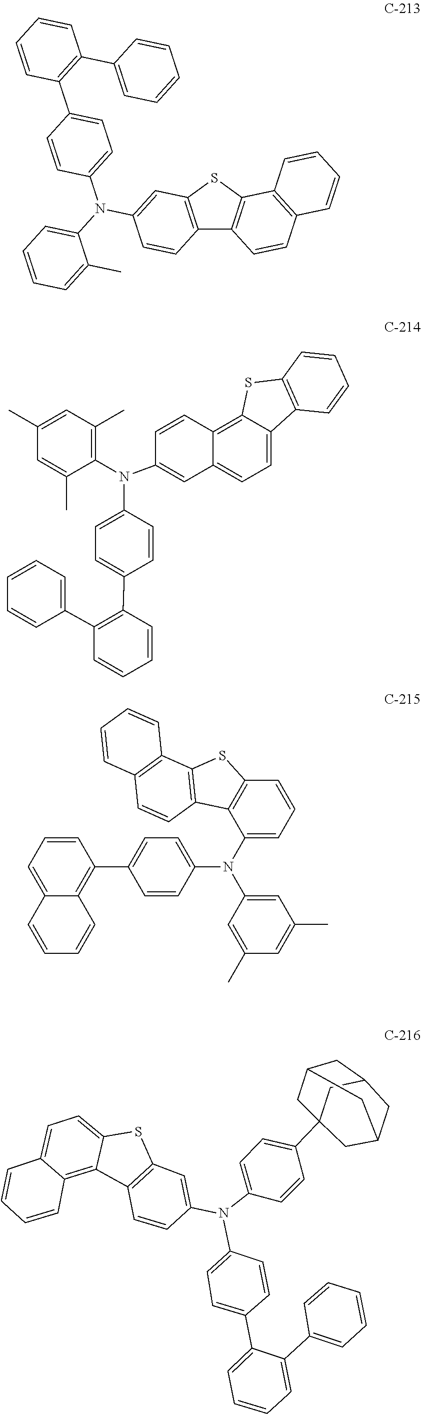 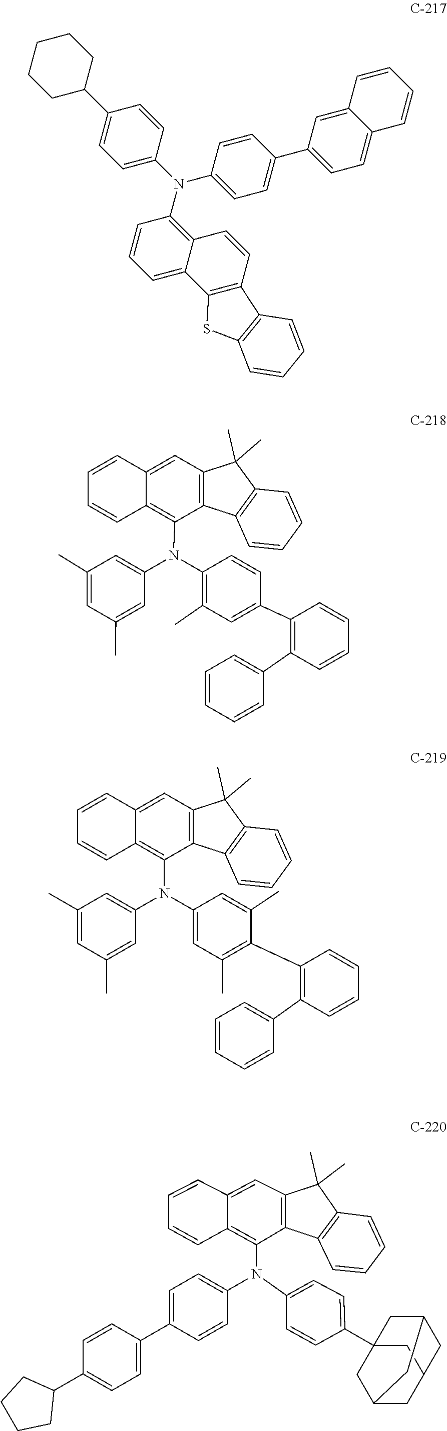 [SMILES: c1ccc2cc(-c3ccc(N(c4ccc(C5CCCCC5)cc4)c4cccc5c4ccc4c6ccccc6sc54)cc3)ccc2c1 ; Cc1cc(C)cc(N(c2ccc(-c3ccccc3-c3ccccc3)cc2C)c2c3c(cc4ccccc24)C(C)(C)c2ccccc2-3)c1 ; Cc1cc(C)cc(N(c2cc(C)c(-c3ccccc3-c3ccccc3)c(C)c2)c2c3c(cc4ccccc24)C(C)(C)c2ccccc2-3)c1 ; CC1(C)c2ccccc2-c2c1cc1ccccc1c2N(c1ccc(-c2ccc(C3CCCC3)cc2)cc1)c1ccc(C23CC4CC(CC(C4)C2)C3)cc1] 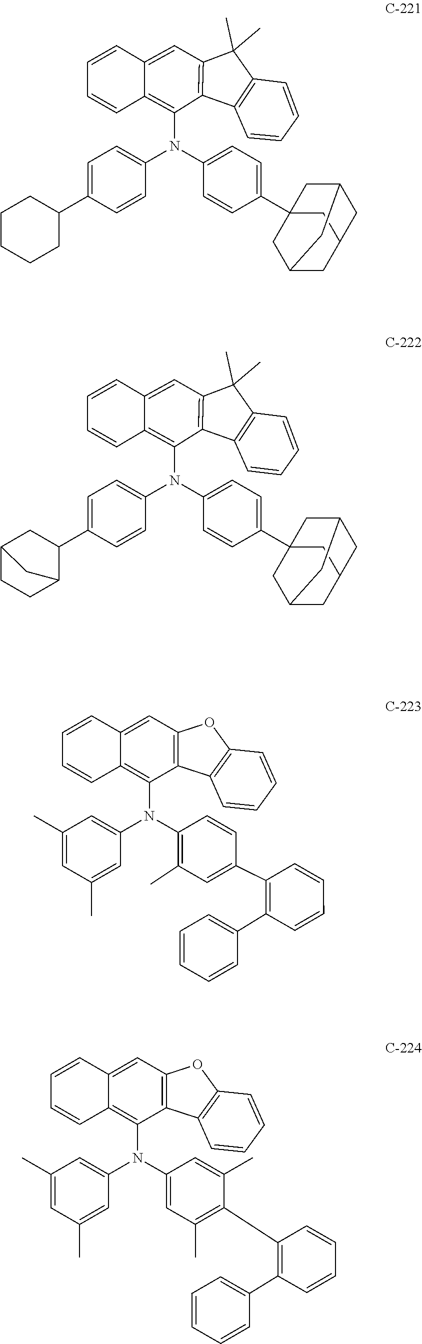 [SMILES: CC1(C)c2ccccc2-c2c1cc1ccccc1c2N(c1ccc(C2CCCCC2)cc1)c1ccc(C23CC4CC(CC(C4)C2)C3)cc1 ; CC1(C)c2ccccc2-c2c1cc1ccccc1c2N(c1ccc(C2CC3CCC2C3)cc1)c1ccc(C23CC4CC(CC(C4)C2)C3)cc1 ; Cc1cc(C)cc(N(c2ccc(-c3ccccc3-c3ccccc3)cc2C)c2c3ccccc3cc3oc4ccccc4c23)c1 ; Cc1cc(C)cc(N(c2cc(C)c(-c3ccccc3-c3ccccc3)c(C)c2)c2c3ccccc3cc3oc4ccccc4c23)c1] 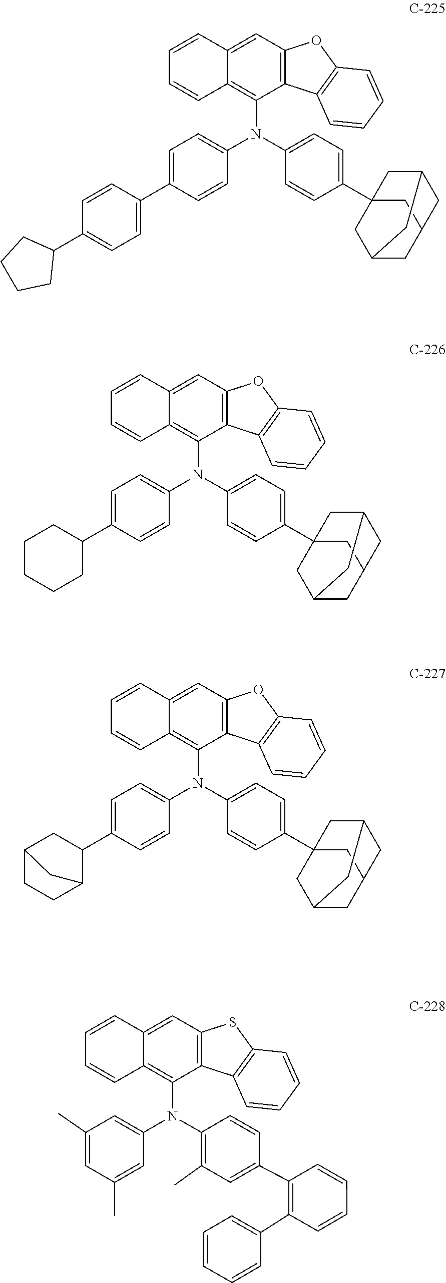 [SMILES: c1ccc2c(N(c3ccc(-c4ccc(C5CCCC5)cc4)cc3)c3ccc(C45CC6CC(CC(C6)C4)C5)cc3)c3c(cc2c1)oc1ccccc13 ; c1ccc2c(N(c3ccc(C4CCCCC4)cc3)c3ccc(C45CC6CC(CC(C6)C4)C5)cc3)c3c(cc2c1)oc1ccccc13 ; c1ccc2c(N(c3ccc(C4CC5CCC4C5)cc3)c3ccc(C45CC6CC(CC(C6)C4)C5)cc3)c3c(cc2c1)oc1ccccc13 ; Cc1cc(C)cc(N(c2ccc(-c3ccccc3-c3ccccc3)cc2C)c2c3ccccc3cc3sc4ccccc4c23)c1] 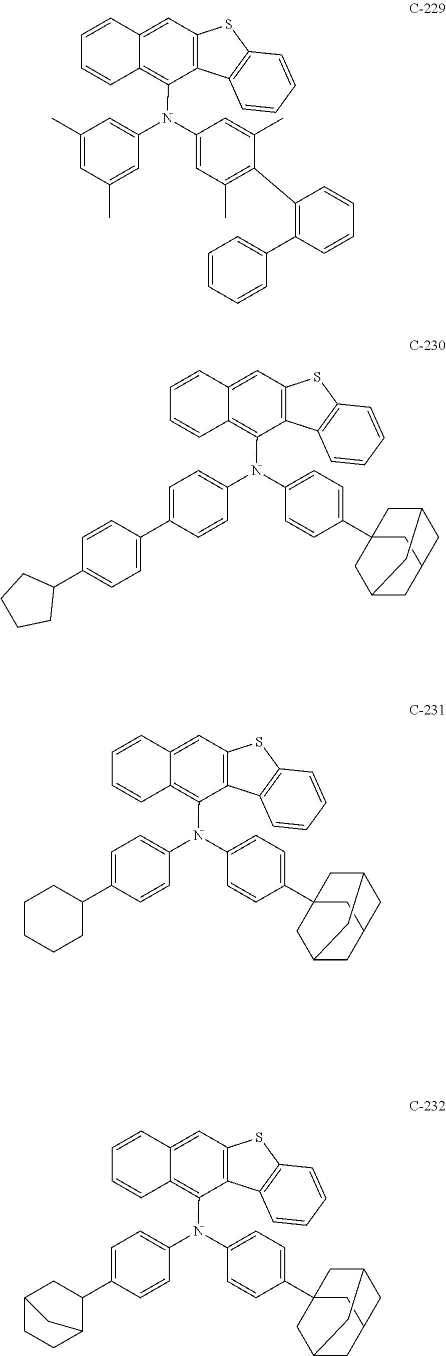 [SMILES: Cc1cc(C)cc(N(c2cc(C)c(-c3ccccc3-c3ccccc3)c(C)c2)c2c3ccccc3cc3sc4ccccc4c23)c1 ; c1ccc2c(N(c3ccc(-c4ccc(C5CCCC5)cc4)cc3)c3ccc(C45CC6CC(CC(C6)C4)C5)cc3)c3c(cc2c1)sc1ccccc13 ; c1ccc2c(N(c3ccc(C4CCCCC4)cc3)c3ccc(C45CC6CC(CC(C6)C4)C5)cc3)c3c(cc2c1)sc1ccccc13 ; c1ccc2c(N(c3ccc(C4CC5CCC4C5)cc3)c3ccc(C45CC6CC(CC(C6)C4)C5)cc3)c3c(cc2c1)sc1ccccc13] 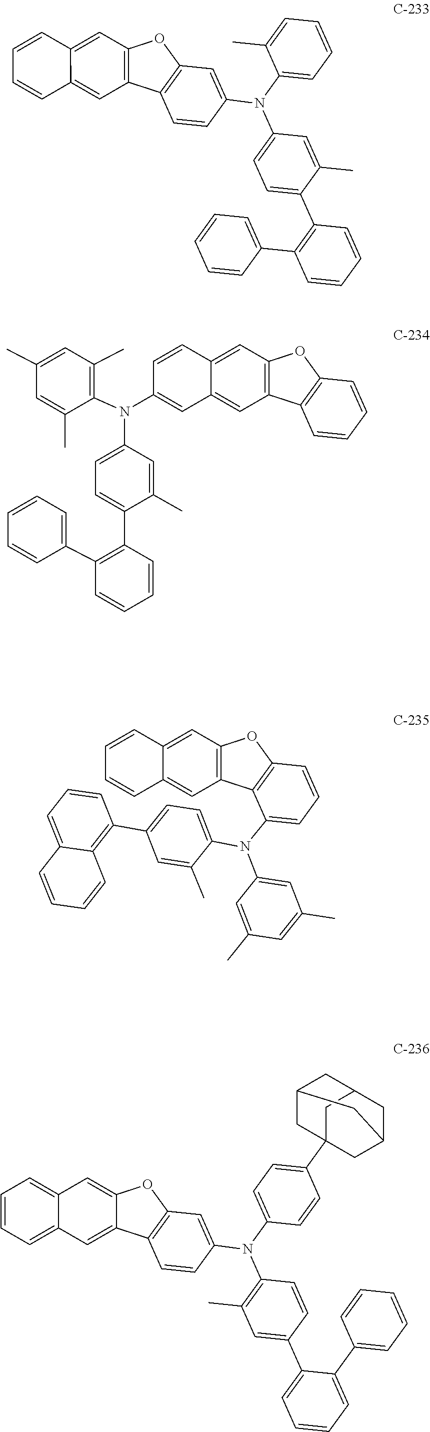 [SMILES: Cc1cc(N(c2ccc3c(c2)oc2cc4ccccc4cc23)c2ccccc2C)ccc1-c1ccccc1-c1ccccc1 ; Cc1cc(C)c(N(c2ccc(-c3ccccc3-c3ccccc3)c(C)c2)c2ccc3cc4oc5ccccc5c4cc3c2)c(C)c1 ; Cc1cc(C)cc(N(c2ccc(-c3cccc4ccccc34)cc2C)c2cccc3oc4cc5ccccc5cc4c23)c1 ; Cc1cc(-c2ccccc2-c2ccccc2)ccc1N(c1ccc(C23CC4CC(CC(C4)C2)C3)cc1)c1ccc2c(c1)oc1cc3ccccc3cc12] 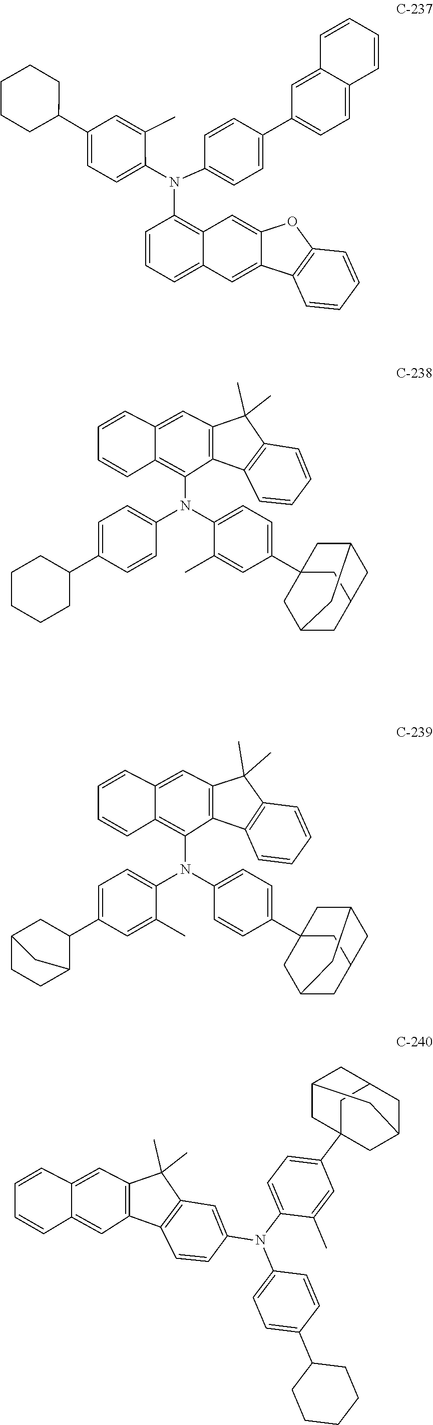 [SMILES: Cc1cc(C2CCCCC2)ccc1N(c1ccc(-c2ccc3ccccc3c2)cc1)c1cccc2cc3c(cc12)oc1ccccc13 ; Cc1cc(C23CC4CC(CC(C4)C2)C3)ccc1N(c1ccc(C2CCCCC2)cc1)c1c2c(cc3ccccc13)C(C)(C)c1ccccc1-2 ; Cc1cc(C2CC3CCC2C3)ccc1N(c1ccc(C23CC4CC(CC(C4)C2)C3)cc1)c1c2c(cc3ccccc13)C(C)(C)c1ccccc1-2 ; Cc1cc(C23CC4CC(CC(C4)C2)C3)ccc1N(c1ccc(C2CCCCC2)cc1)c1ccc2c(c1)C(C)(C)c1cc3ccccc3cc1-2] 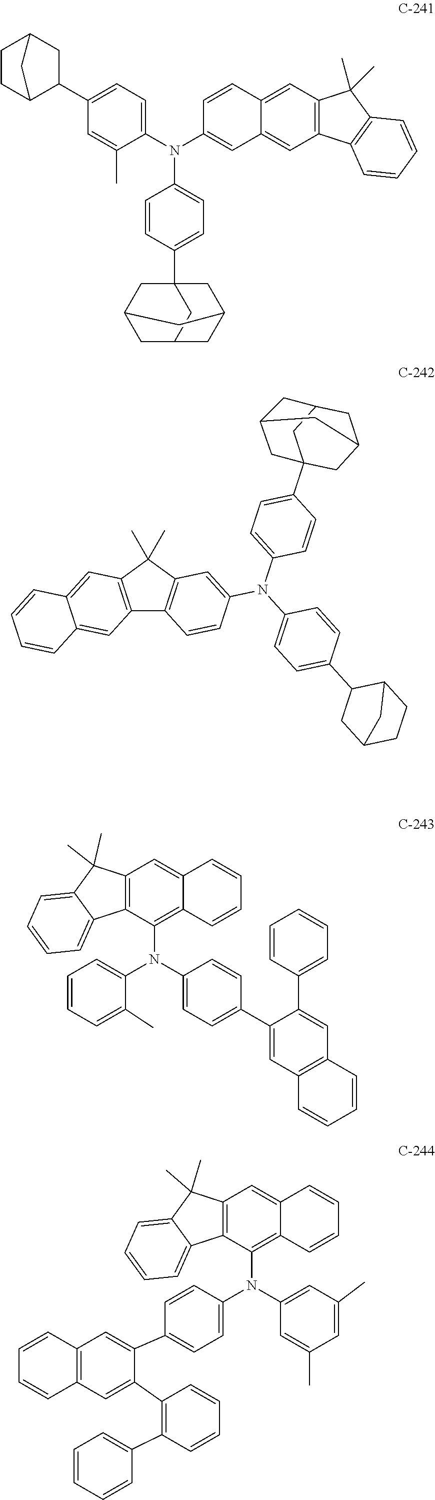 [SMILES: Cc1cc(C2CC3CCC2C3)ccc1N(c1ccc(C23CC4CC(CC(C4)C2)C3)cc1)c1ccc2cc3c(cc2c1)-c1ccccc1C3(C)C ; CC1(C)c2cc(N(c3ccc(C4CC5CCC4C5)cc3)c3ccc(C45CC6CC(CC(C6)C4)C5)cc3)ccc2-c2cc3ccccc3cc21 ; Cc1ccccc1N(c1ccc(-c2cc3ccccc3cc2-c2ccccc2)cc1)c1c2c(cc3ccccc13)C(C)(C)c1ccccc1-2 ; Cc1cc(C)cc(N(c2ccc(-c3cc4ccccc4cc3-c3ccccc3-c3ccccc3)cc2)c2c3c(cc4ccccc24)C(C)(C)c2ccccc2-3)c1] 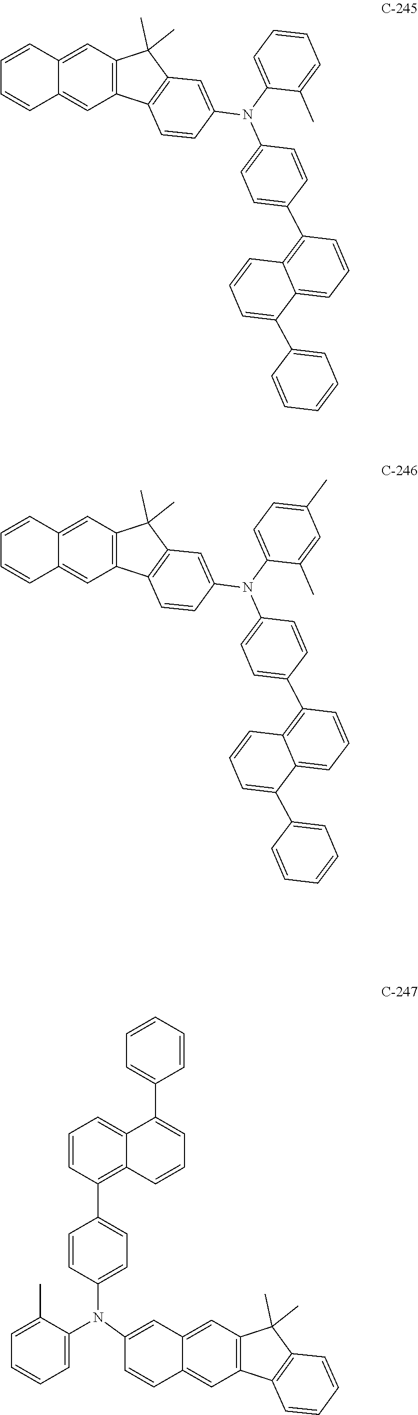 [SMILES: Cc1ccccc1N(c1ccc(-c2cccc3c(-c4ccccc4)cccc23)cc1)c1ccc2c(c1)C(C)(C)c1cc3ccccc3cc1-2 ; Cc1ccc(N(c2ccc(-c3cccc4c(-c5ccccc5)cccc34)cc2)c2ccc3c(c2)C(C)(C)c2cc4ccccc4cc2-3)c(C)c1 ; Cc1ccccc1N(c1ccc(-c2cccc3c(-c4ccccc4)cccc23)cc1)c1ccc2cc3c(cc2c1)C(C)(C)c1ccccc1-3] 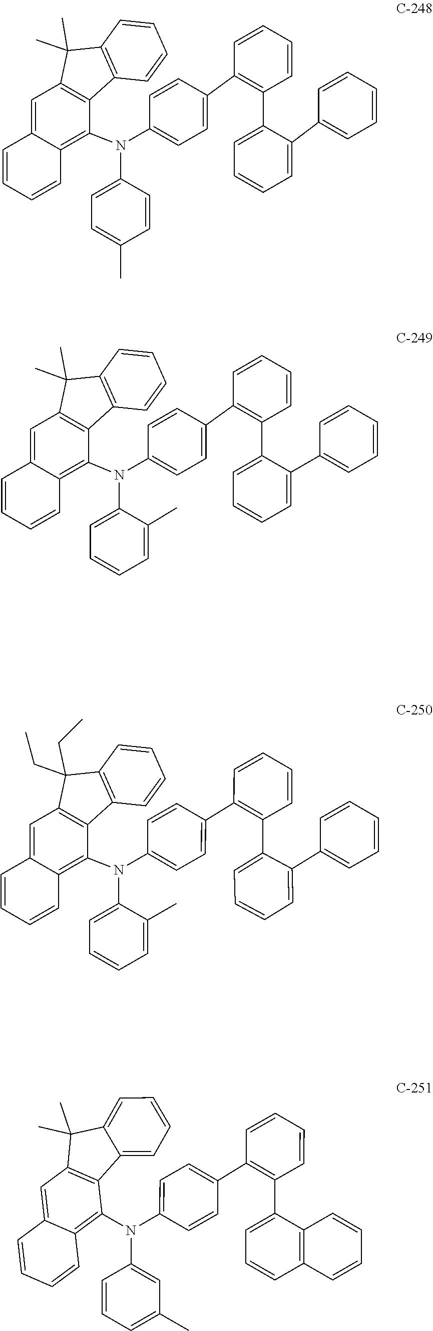 [SMILES: Cc1ccc(N(c2ccc(-c3ccccc3-c3ccccc3-c3ccccc3)cc2)c2c3c(cc4ccccc24)C(C)(C)c2ccccc2-3)cc1 ; Cc1ccccc1N(c1ccc(-c2ccccc2-c2ccccc2-c2ccccc2)cc1)c1c2c(cc3ccccc13)C(C)(C)c1ccccc1-2 ; CCC1(CC)c2ccccc2-c2c1cc1ccccc1c2N(c1ccc(-c2ccccc2-c2ccccc2-c2ccccc2)cc1)c1ccccc1C ; Cc1cccc(N(c2ccc(-c3ccccc3-c3cccc4ccccc34)cc2)c2c3c(cc4ccccc24)C(C)(C)c2ccccc2-3)c1] 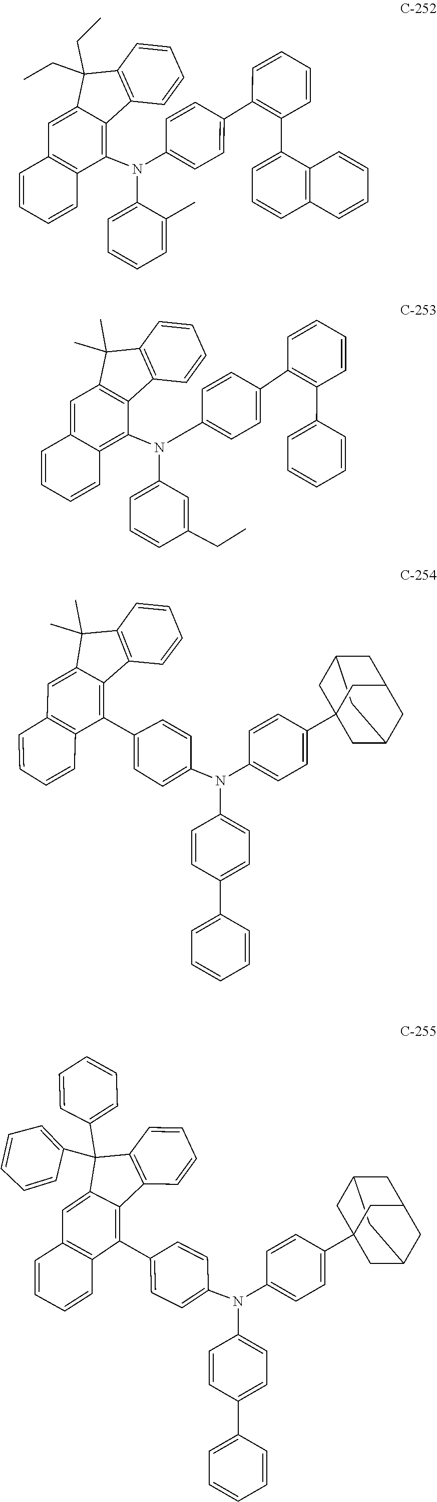 [SMILES: CCC1(CC)c2ccccc2-c2c1cc1ccccc1c2N(c1ccc(-c2ccccc2-c2cccc3ccccc23)cc1)c1ccccc1C ; CCc1cccc(N(c2ccc(-c3ccccc3-c3ccccc3)cc2)c2c3c(cc4ccccc24)C(C)(C)c2ccccc2-3)c1 ; CC1(C)c2ccccc2-c2c1cc1ccccc1c2-c1ccc(N(c2ccc(-c3ccccc3)cc2)c2ccc(C34CC5CC(CC(C5)C3)C4)cc2)cc1 ; c1ccc(-c2ccc(N(c3ccc(-c4c5c(cc6ccccc46)C(c4ccccc4)(c4ccccc4)c4ccccc4-5)cc3)c3ccc(C45CC6CC(CC(C6)C4)C5)cc3)cc2)cc1] 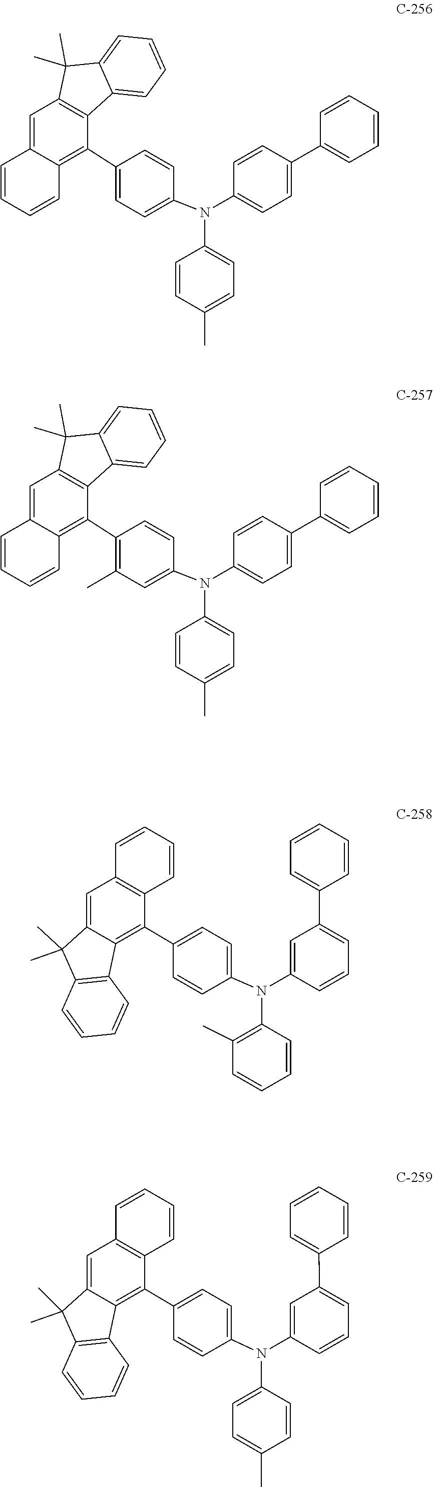 [SMILES: Cc1ccc(N(c2ccc(-c3ccccc3)cc2)c2ccc(-c3c4c(cc5ccccc35)C(C)(C)c3ccccc3-4)cc2)cc1 ; Cc1ccc(N(c2ccc(-c3ccccc3)cc2)c2ccc(-c3c4c(cc5ccccc35)C(C)(C)c3ccccc3-4)c(C)c2)cc1 ; Cc1ccccc1N(c1ccc(-c2c3c(cc4ccccc24)C(C)(C)c2ccccc2-3)cc1)c1cccc(-c2ccccc2)c1 ; Cc1ccc(N(c2ccc(-c3c4c(cc5ccccc35)C(C)(C)c3ccccc3-4)cc2)c2cccc(-c3ccccc3)c2)cc1] 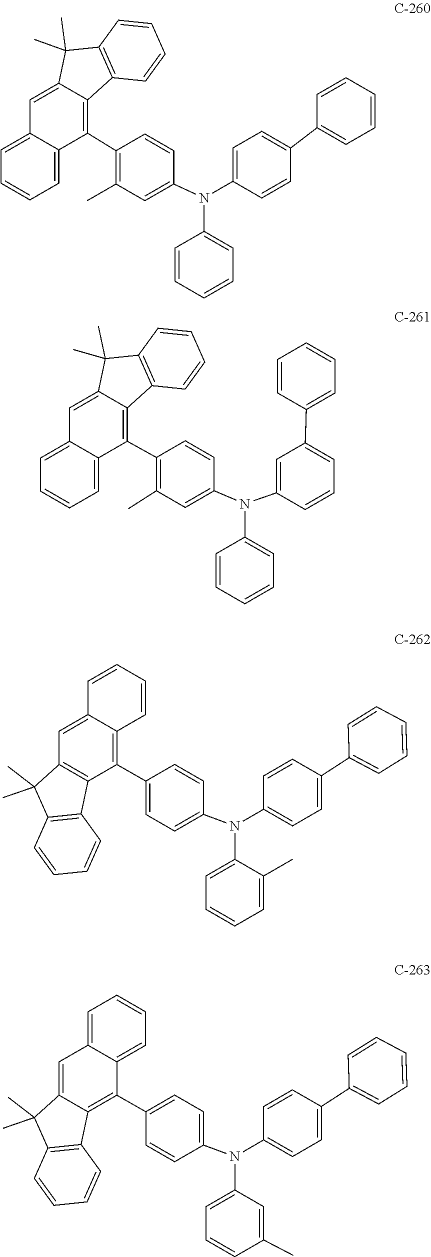 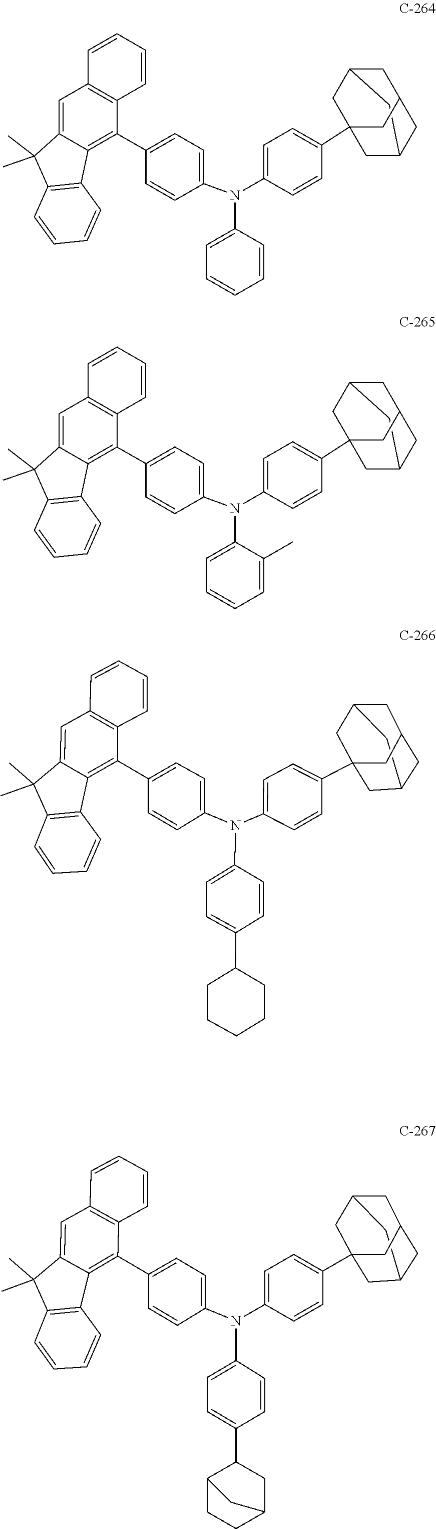 [SMILES: CC1(C)c2ccccc2-c2c1cc1ccccc1c2-c1ccc(N(c2ccccc2)c2ccc(C34CC5CC(CC(C5)C3)C4)cc2)cc1 ; Cc1ccccc1N(c1ccc(-c2c3c(cc4ccccc24)C(C)(C)c2ccccc2-3)cc1)c1ccc(C23CC4CC(CC(C4)C2)C3)cc1 ; CC1(C)c2ccccc2-c2c1cc1ccccc1c2-c1ccc(N(c2ccc(C3CCCCC3)cc2)c2ccc(C34CC5CC(CC(C5)C3)C4)cc2)cc1 ; CC1(C)c2ccccc2-c2c1cc1ccccc1c2-c1ccc(N(c2ccc(C3CC4CCC3C4)cc2)c2ccc(C34CC5CC(CC(C5)C3)C4)cc2)cc1] 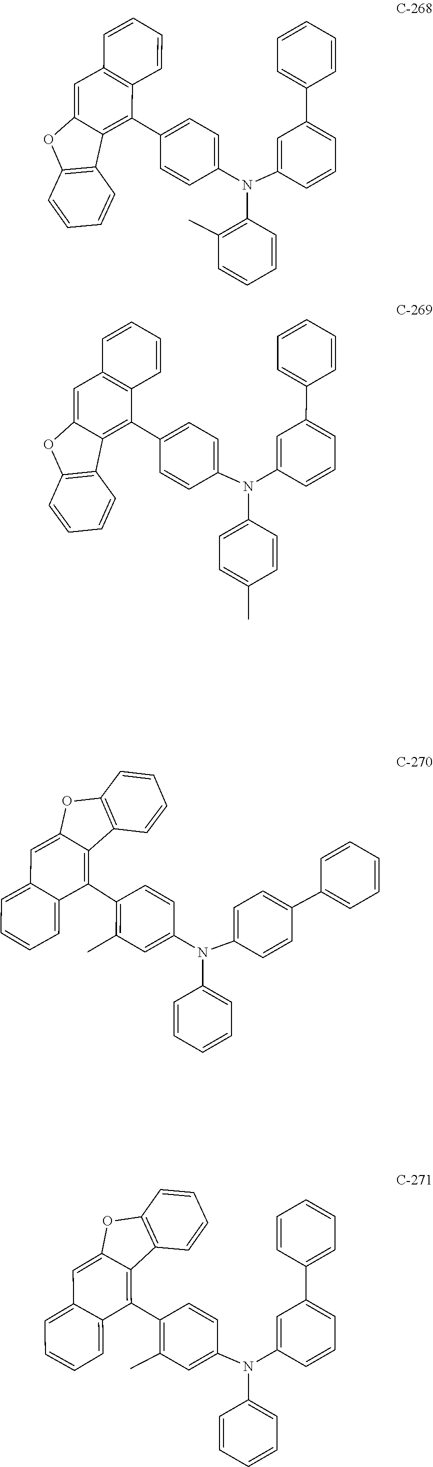 [SMILES: Cc1ccccc1N(c1ccc(-c2c3ccccc3cc3oc4ccccc4c23)cc1)c1cccc(-c2ccccc2)c1 ; Cc1ccc(N(c2ccc(-c3c4ccccc4cc4oc5ccccc5c34)cc2)c2cccc(-c3ccccc3)c2)cc1 ; Cc1cc(N(c2ccccc2)c2ccc(-c3ccccc3)cc2)ccc1-c1c2ccccc2cc2oc3ccccc3c12 ; Cc1cc(N(c2ccccc2)c2cccc(-c3ccccc3)c2)ccc1-c1c2ccccc2cc2oc3ccccc3c12] 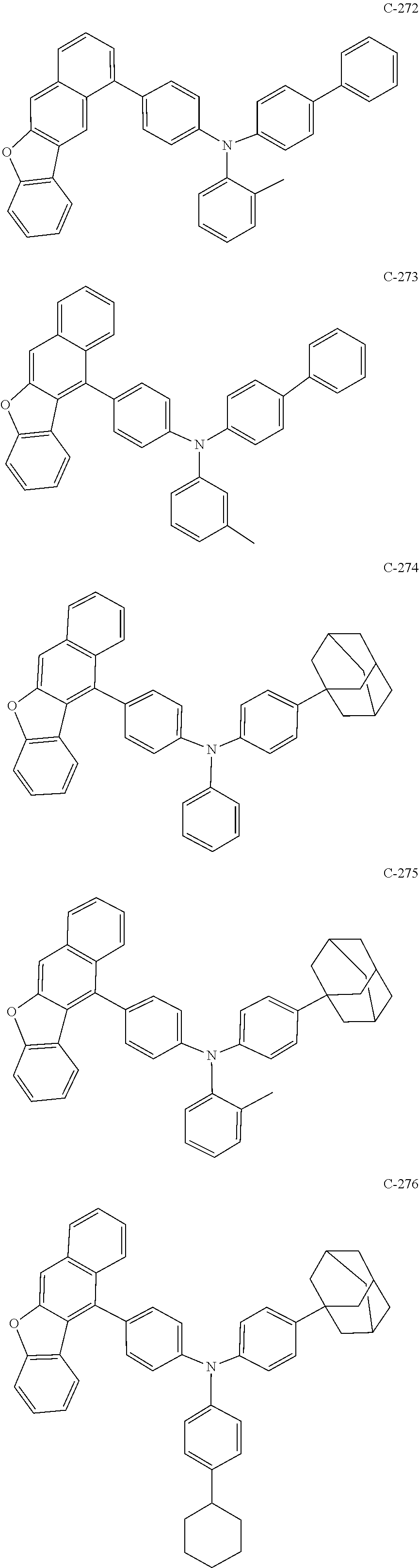 [SMILES: Cc1ccccc1N(c1ccc(-c2ccccc2)cc1)c1ccc(-c2cccc3cc4oc5ccccc5c4cc23)cc1 ; Cc1cccc(N(c2ccc(-c3ccccc3)cc2)c2ccc(-c3c4ccccc4cc4oc5ccccc5c34)cc2)c1 ; c1ccc(N(c2ccc(-c3c4ccccc4cc4oc5ccccc5c34)cc2)c2ccc(C34CC5CC(CC(C5)C3)C4)cc2)cc1 ; Cc1ccccc1N(c1ccc(-c2c3ccccc3cc3oc4ccccc4c23)cc1)c1ccc(C23CC4CC(CC(C4)C2)C3)cc1 ; c1ccc2c(-c3ccc(N(c4ccc(C5CCCCC5)cc4)c4ccc(C56CC7CC(CC(C7)C5)C6)cc4)cc3)c3c(cc2c1)oc1ccccc13] 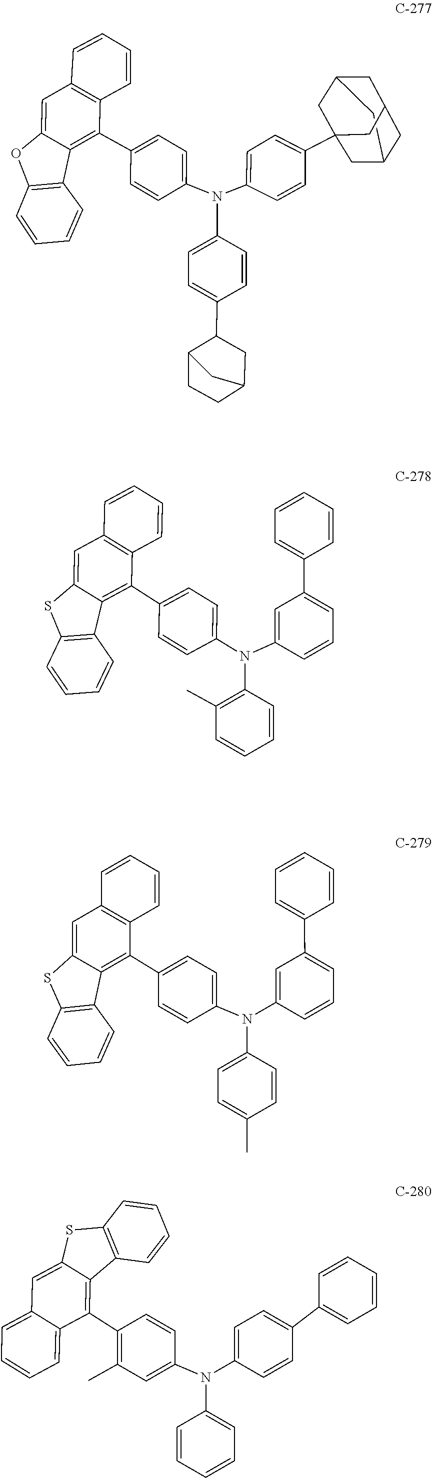 [SMILES: c1ccc2c(-c3ccc(N(c4ccc(C5CC6CCC5C6)cc4)c4ccc(C56CC7CC(CC(C7)C5)C6)cc4)cc3)c3c(cc2c1)oc1ccccc13 ; Cc1ccccc1N(c1ccc(-c2c3ccccc3cc3sc4ccccc4c23)cc1)c1cccc(-c2ccccc2)c1 ; Cc1ccc(N(c2ccc(-c3c4ccccc4cc4sc5ccccc5c34)cc2)c2cccc(-c3ccccc3)c2)cc1 ; Cc1cc(N(c2ccccc2)c2ccc(-c3ccccc3)cc2)ccc1-c1c2ccccc2cc2sc3ccccc3c12] 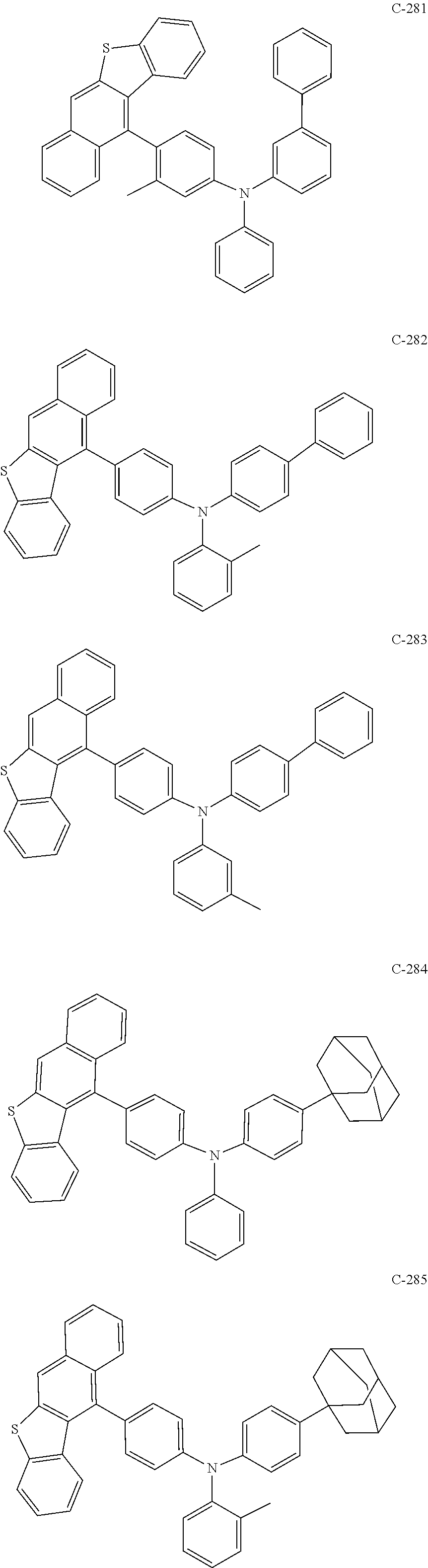 [SMILES: Cc1cc(N(c2ccccc2)c2cccc(-c3ccccc3)c2)ccc1-c1c2ccccc2cc2sc3ccccc3c12 ; Cc1ccccc1N(c1ccc(-c2ccccc2)cc1)c1ccc(-c2c3ccccc3cc3sc4ccccc4c23)cc1 ; Cc1cccc(N(c2ccc(-c3ccccc3)cc2)c2ccc(-c3c4ccccc4cc4sc5ccccc5c34)cc2)c1 ; c1ccc(N(c2ccc(-c3c4ccccc4cc4sc5ccccc5c34)cc2)c2ccc(C34CC5CC(CC(C5)C3)C4)cc2)cc1 ; Cc1ccccc1N(c1ccc(-c2c3ccccc3cc3sc4ccccc4c23)cc1)c1ccc(C23CC4CC(CC(C4)C2)C3)cc1] 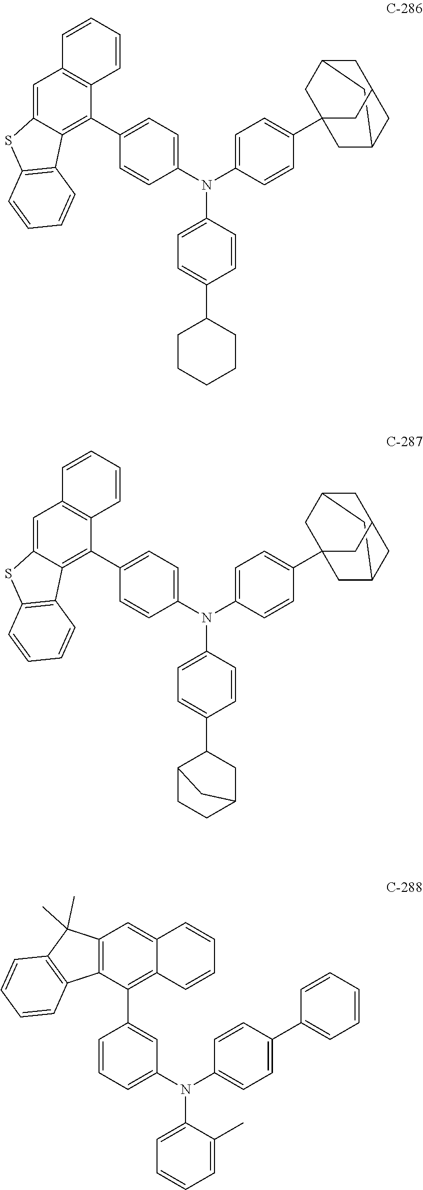 [SMILES: c1ccc2c(-c3ccc(N(c4ccc(C5CCCCC5)cc4)c4ccc(C56CC7CC(CC(C7)C5)C6)cc4)cc3)c3c(cc2c1)sc1ccccc13 ; c1ccc2c(-c3ccc(N(c4ccc(C5CC6CCC5C6)cc4)c4ccc(C56CC7CC(CC(C7)C5)C6)cc4)cc3)c3c(cc2c1)sc1ccccc13 ; Cc1ccccc1N(c1ccc(-c2ccccc2)cc1)c1cccc(-c2c3c(cc4ccccc24)C(C)(C)c2ccccc2-3)c1] 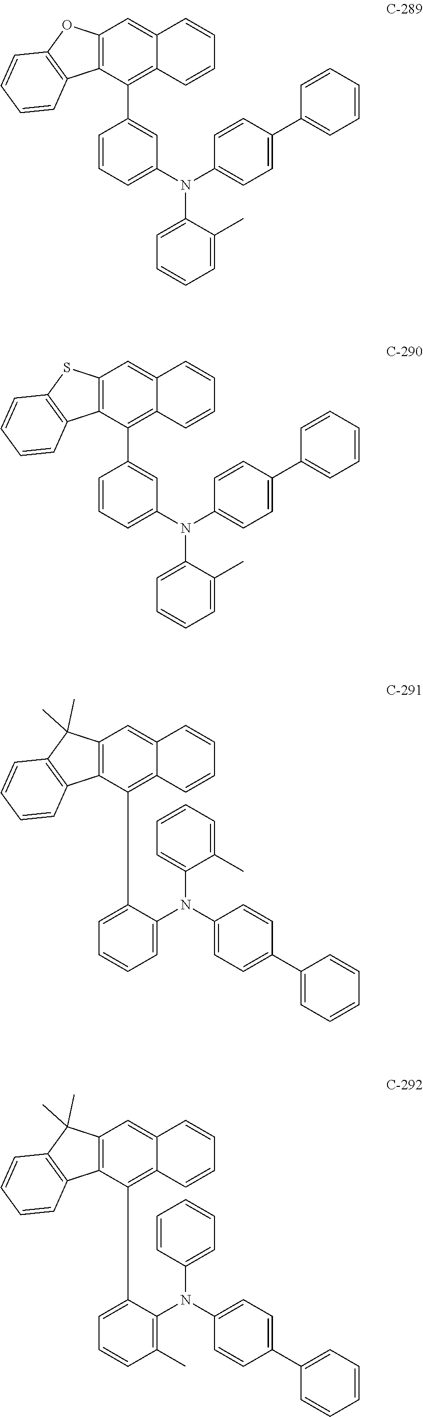 [SMILES: Cc1ccccc1N(c1ccc(-c2ccccc2)cc1)c1cccc(-c2c3ccccc3cc3oc4ccccc4c23)c1 ; Cc1ccccc1N(c1ccc(-c2ccccc2)cc1)c1cccc(-c2c3ccccc3cc3sc4ccccc4c23)c1 ; Cc1ccccc1N(c1ccc(-c2ccccc2)cc1)c1ccccc1-c1c2c(cc3ccccc13)C(C)(C)c1ccccc1-2 ; Cc1cccc(-c2c3c(cc4ccccc24)C(C)(C)c2ccccc2-3)c1N(c1ccccc1)c1ccc(-c2ccccc2)cc1] 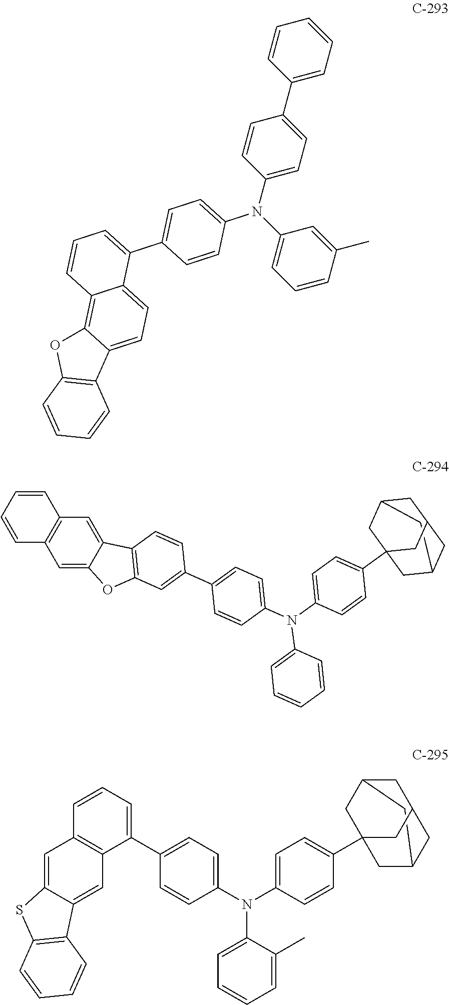 [SMILES: Cc1cccc(N(c2ccc(-c3ccccc3)cc2)c2ccc(-c3cccc4c3ccc3c5ccccc5oc43)cc2)c1 ; c1ccc(N(c2ccc(-c3ccc4c(c3)oc3cc5ccccc5cc34)cc2)c2ccc(C34CC5CC(CC(C5)C3)C4)cc2)cc1 ; Cc1ccccc1N(c1ccc(-c2cccc3cc4sc5ccccc5c4cc23)cc1)c1ccc(C23CC4CC(CC(C4)C2)C3)cc1] 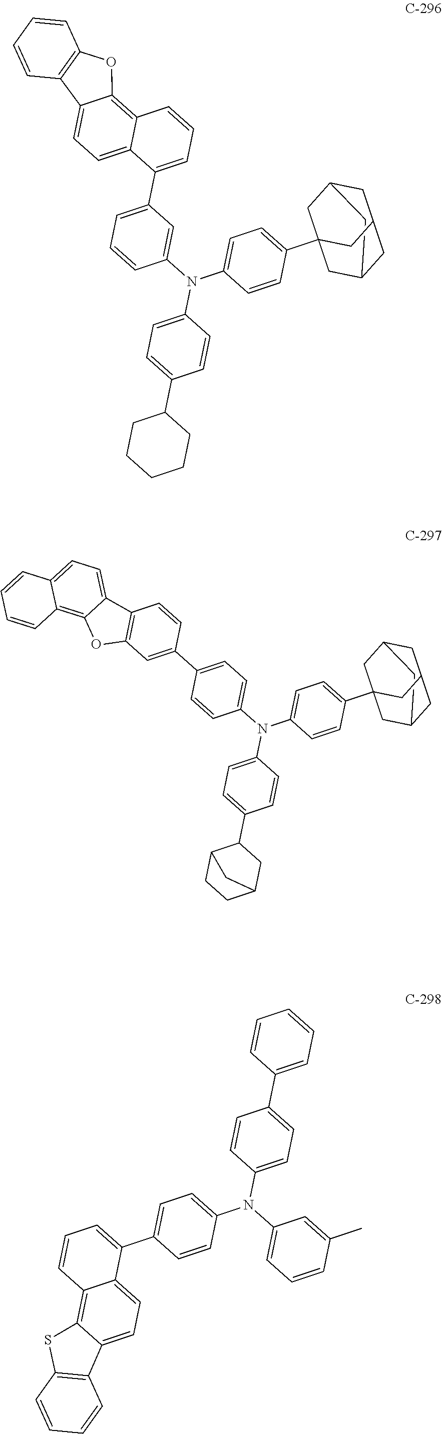 [SMILES: c1cc(-c2cccc3c2ccc2c4ccccc4oc32)cc(N(c2ccc(C3CCCCC3)cc2)c2ccc(C34CC5CC(CC(C5)C3)C4)cc2)c1 ; c1ccc2c(c1)ccc1c3ccc(-c4ccc(N(c5ccc(C6CC7CCC6C7)cc5)c5ccc(C67CC8CC(CC(C8)C6)C7)cc5)cc4)cc3oc21 ; Cc1cccc(N(c2ccc(-c3ccccc3)cc2)c2ccc(-c3cccc4c3ccc3c5ccccc5sc43)cc2)c1] 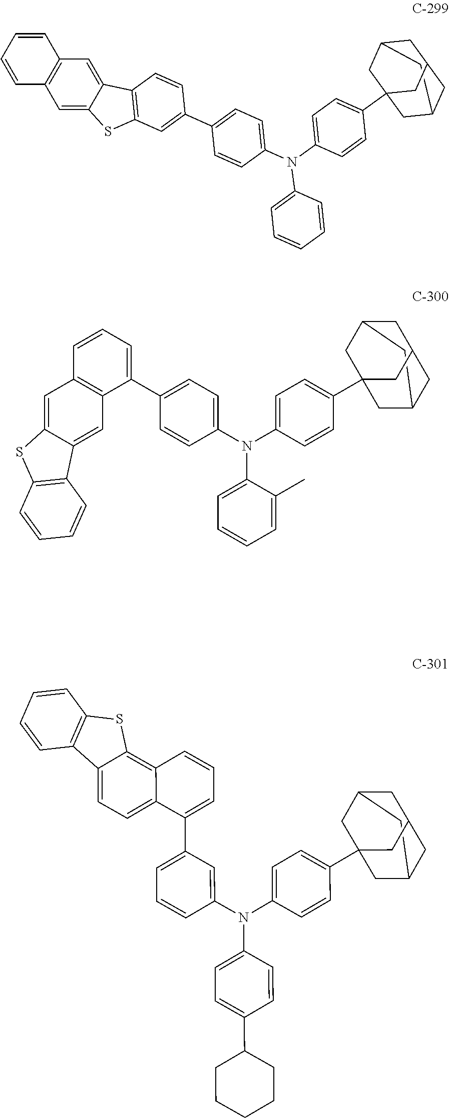 [SMILES: c1ccc(N(c2ccc(-c3ccc4c(c3)sc3cc5ccccc5cc34)cc2)c2ccc(C34CC5CC(CC(C5)C3)C4)cc2)cc1 ; Cc1ccccc1N(c1ccc(-c2cccc3cc4sc5ccccc5c4cc23)cc1)c1ccc(C23CC4CC(CC(C4)C2)C3)cc1 ; c1cc(-c2cccc3c2ccc2c4ccccc4sc32)cc(N(c2ccc(C3CCCCC3)cc2)c2ccc(C34CC5CC(CC(C5)C3)C4)cc2)c1] 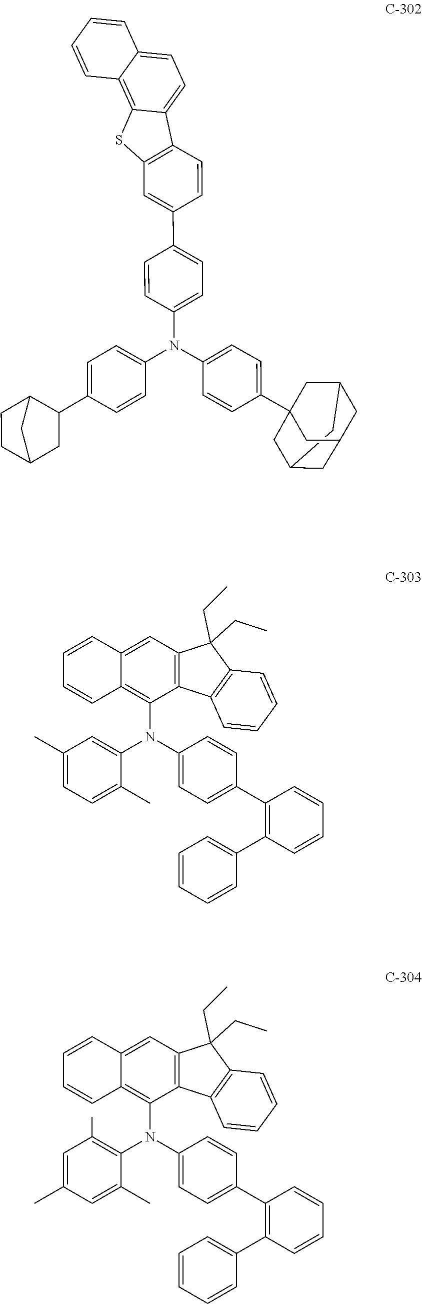 [SMILES: c1ccc2c(c1)ccc1c3ccc(-c4ccc(N(c5ccc(C6CC7CCC6C7)cc5)c5ccc(C67CC8CC(CC(C8)C6)C7)cc5)cc4)cc3sc21 ; CCC1(CC)c2ccccc2-c2c1cc1ccccc1c2N(c1ccc(-c2ccccc2-c2ccccc2)cc1)c1cc(C)ccc1C ; CCC1(CC)c2ccccc2-c2c1cc1ccccc1c2N(c1ccc(-c2ccccc2-c2ccccc2)cc1)c1c(C)cc(C)cc1C] 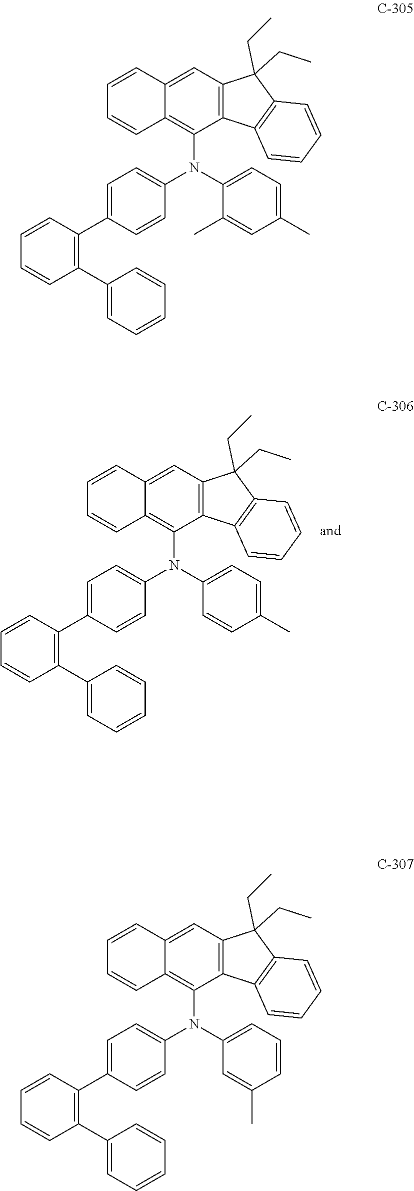 [SMILES: CCC1(CC)c2ccccc2-c2c1cc1ccccc1c2N(c1ccc(-c2ccccc2-c2ccccc2)cc1)c1ccc(C)cc1C ; CCC1(CC)c2ccccc2-c2c1cc1ccccc1c2N(c1ccc(C)cc1)c1ccc(-c2ccccc2-c2ccccc2)cc1 ; CCC1(CC)c2ccccc2-c2c1cc1ccccc1c2N(c1ccc(-c2ccccc2-c2ccccc2)cc1)c1cccc(C)c1]
wherein in each of the compounds described above, hydrogen may be replaced with deuterium.

9. The organic electroluminescent device according to claim 1, wherein the compound represented by Formula 2 is selected from the following compounds: 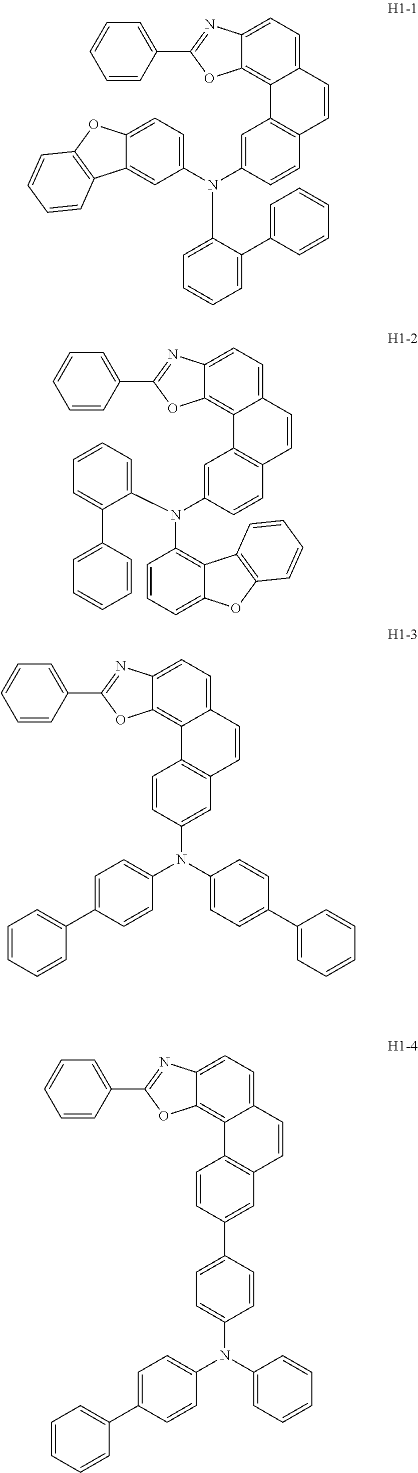 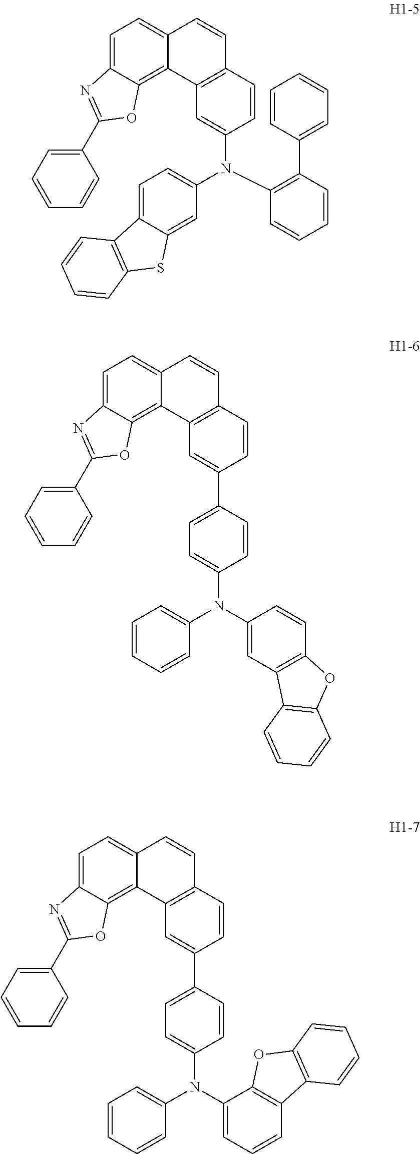 [SMILES: c1ccc(-c2nc3ccc4ccc5ccc(N(c6ccc7c(c6)sc6ccccc67)c6ccccc6-c6ccccc6)cc5c4c3o2)cc1 ; c1ccc(-c2nc3ccc4ccc5ccc(-c6ccc(N(c7ccccc7)c7ccc8oc9ccccc9c8c7)cc6)cc5c4c3o2)cc1 ; c1ccc(-c2nc3ccc4ccc5ccc(-c6ccc(N(c7ccccc7)c7cccc8c7oc7ccccc78)cc6)cc5c4c3o2)cc1] 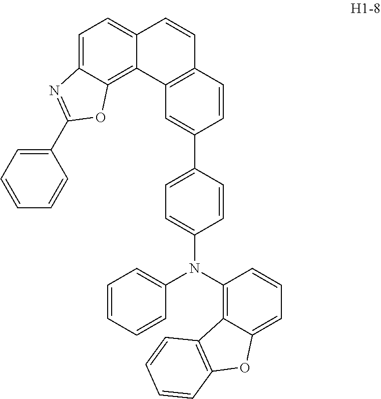 [SMILES: c1ccc(-c2nc3ccc4ccc5ccc(-c6ccc(N(c7ccccc7)c7cccc8oc9ccccc9c78)cc6)cc5c4c3o2)cc1] 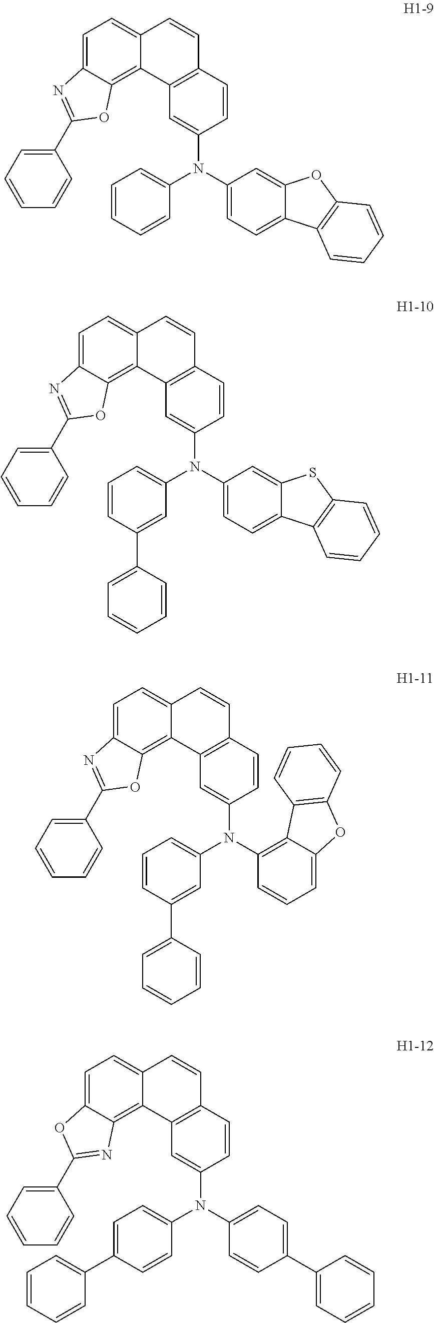 [SMILES: c1ccc(-c2nc3ccc4ccc5ccc(N(c6ccccc6)c6ccc7c(c6)oc6ccccc67)cc5c4c3o2)cc1 ; c1ccc(-c2cccc(N(c3ccc4c(c3)sc3ccccc34)c3ccc4ccc5ccc6nc(-c7ccccc7)oc6c5c4c3)c2)cc1 ; c1ccc(-c2cccc(N(c3ccc4ccc5ccc6nc(-c7ccccc7)oc6c5c4c3)c3cccc4oc5ccccc5c34)c2)cc1 ; c1ccc(-c2ccc(N(c3ccc(-c4ccccc4)cc3)c3ccc4ccc5ccc6oc(-c7ccccc7)nc6c5c4c3)cc2)cc1] 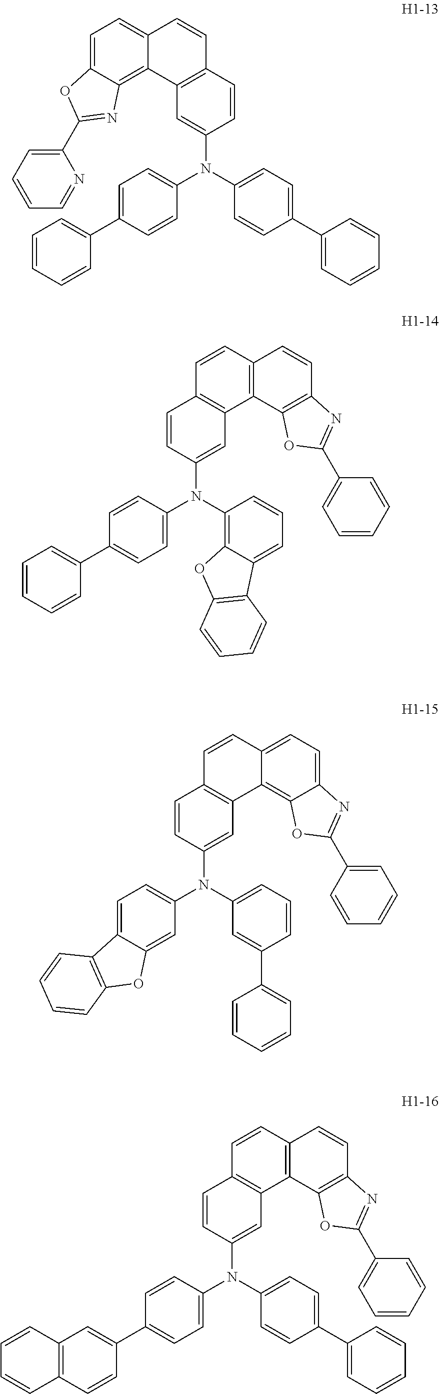 [SMILES: c1ccc(-c2ccc(N(c3ccc(-c4ccccc4)cc3)c3ccc4ccc5ccc6oc(-c7ccccn7)nc6c5c4c3)cc2)cc1 ; c1ccc(-c2ccc(N(c3ccc4ccc5ccc6nc(-c7ccccc7)oc6c5c4c3)c3cccc4c3oc3ccccc34)cc2)cc1 ; c1ccc(-c2cccc(N(c3ccc4c(c3)oc3ccccc34)c3ccc4ccc5ccc6nc(-c7ccccc7)oc6c5c4c3)c2)cc1 ; c1ccc(-c2ccc(N(c3ccc(-c4ccc5ccccc5c4)cc3)c3ccc4ccc5ccc6nc(-c7ccccc7)oc6c5c4c3)cc2)cc1] 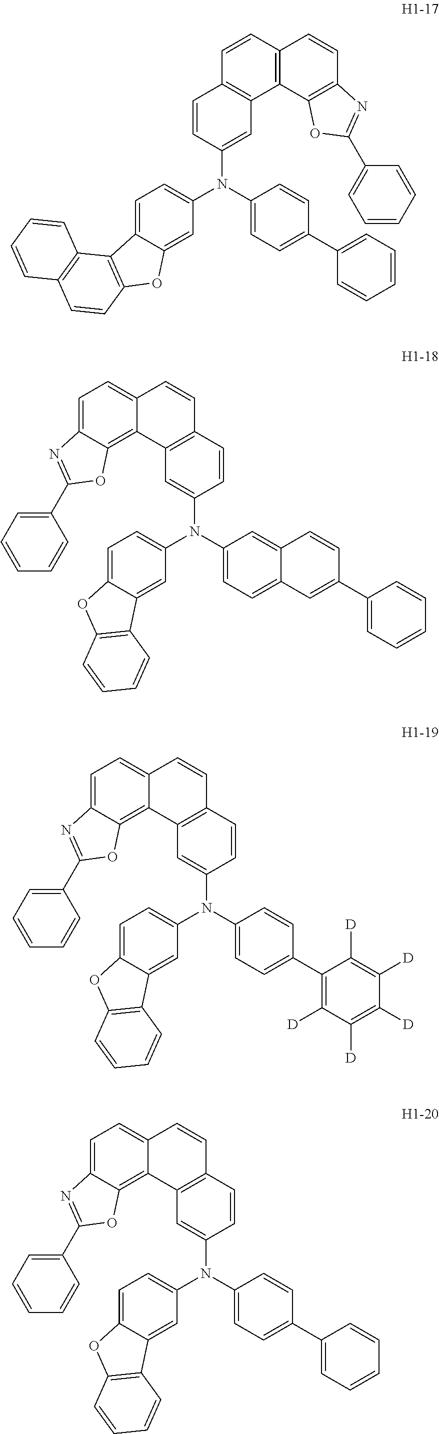 [SMILES: c1ccc(-c2ccc(N(c3ccc4c(c3)oc3ccc5ccccc5c34)c3ccc4ccc5ccc6nc(-c7ccccc7)oc6c5c4c3)cc2)cc1 ; c1ccc(-c2ccc3cc(N(c4ccc5oc6ccccc6c5c4)c4ccc5ccc6ccc7nc(-c8ccccc8)oc7c6c5c4)ccc3c2)cc1 ; [2H]c1c([2H])c([2H])c(-c2ccc(N(c3ccc4oc5ccccc5c4c3)c3ccc4ccc5ccc6nc(-c7ccccc7)oc6c5c4c3)cc2)c([2H])c1[2H] ; c1ccc(-c2ccc(N(c3ccc4oc5ccccc5c4c3)c3ccc4ccc5ccc6nc(-c7ccccc7)oc6c5c4c3)cc2)cc1] 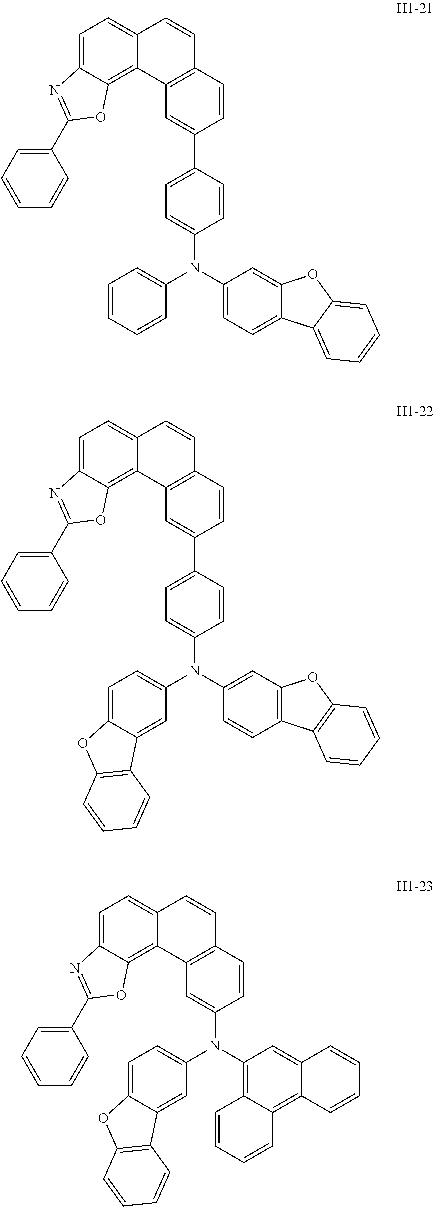 [SMILES: c1ccc(-c2nc3ccc4ccc5ccc(-c6ccc(N(c7ccccc7)c7ccc8c(c7)oc7ccccc78)cc6)cc5c4c3o2)cc1 ; c1ccc(-c2nc3ccc4ccc5ccc(-c6ccc(N(c7ccc8c(c7)oc7ccccc78)c7ccc8oc9ccccc9c8c7)cc6)cc5c4c3o2)cc1 ; c1ccc(-c2nc3ccc4ccc5ccc(N(c6ccc7oc8ccccc8c7c6)c6cc7ccccc7c7ccccc67)cc5c4c3o2)cc1] 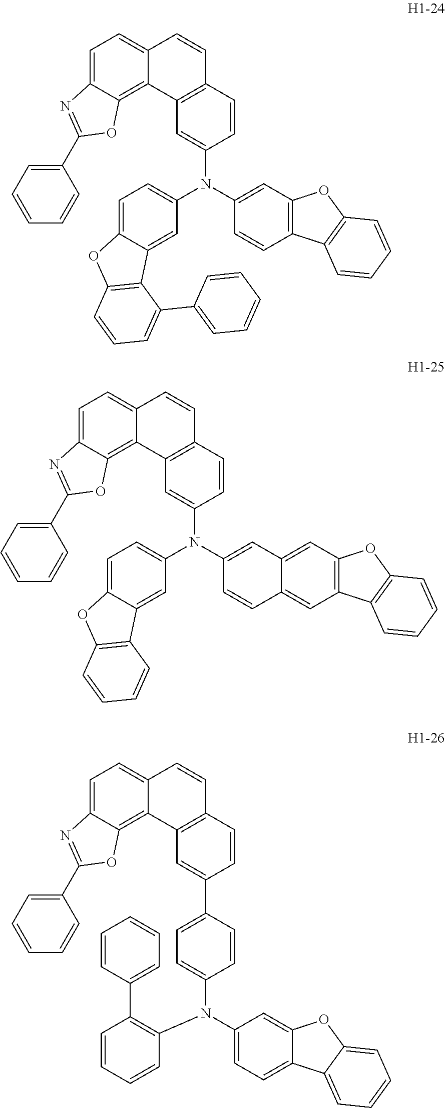 [SMILES: c1ccc(-c2nc3ccc4ccc5ccc(N(c6ccc7c(c6)oc6ccccc67)c6ccc7oc8cccc(-c9ccccc9)c8c7c6)cc5c4c3o2)cc1 ; c1ccc(-c2nc3ccc4ccc5ccc(N(c6ccc7cc8c(cc7c6)oc6ccccc68)c6ccc7oc8ccccc8c7c6)cc5c4c3o2)cc1 ; c1ccc(-c2nc3ccc4ccc5ccc(-c6ccc(N(c7ccc8c(c7)oc7ccccc78)c7ccccc7-c7ccccc7)cc6)cc5c4c3o2)cc1] 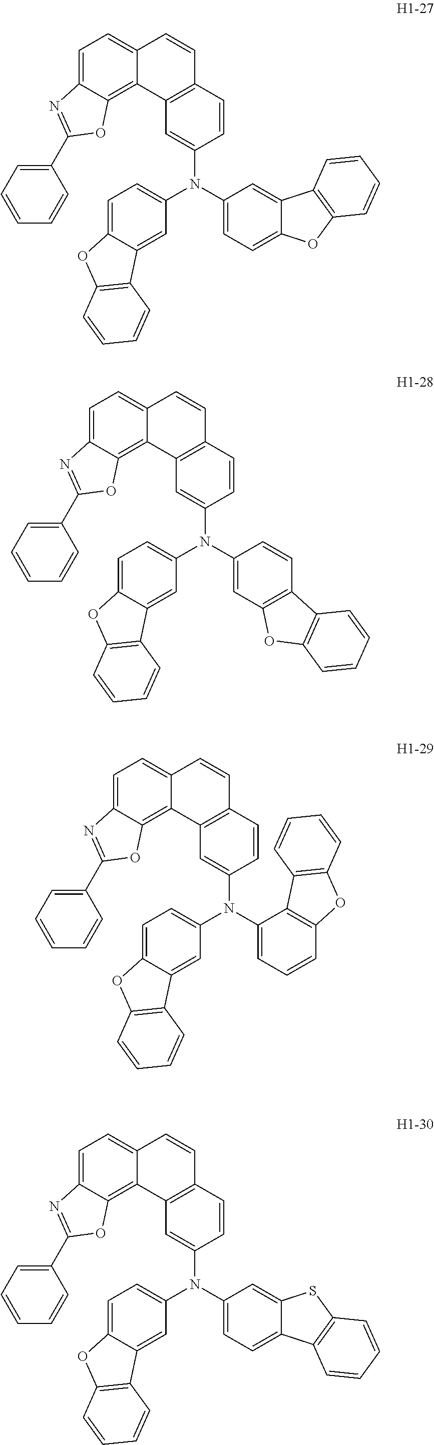 [SMILES: c1ccc(-c2nc3ccc4ccc5ccc(N(c6ccc7oc8ccccc8c7c6)c6ccc7oc8ccccc8c7c6)cc5c4c3o2)cc1 ; c1ccc(-c2nc3ccc4ccc5ccc(N(c6ccc7c(c6)oc6ccccc67)c6ccc7oc8ccccc8c7c6)cc5c4c3o2)cc1 ; c1ccc(-c2nc3ccc4ccc5ccc(N(c6ccc7oc8ccccc8c7c6)c6cccc7oc8ccccc8c67)cc5c4c3o2)cc1 ; c1ccc(-c2nc3ccc4ccc5ccc(N(c6ccc7c(c6)sc6ccccc67)c6ccc7oc8ccccc8c7c6)cc5c4c3o2)cc1] 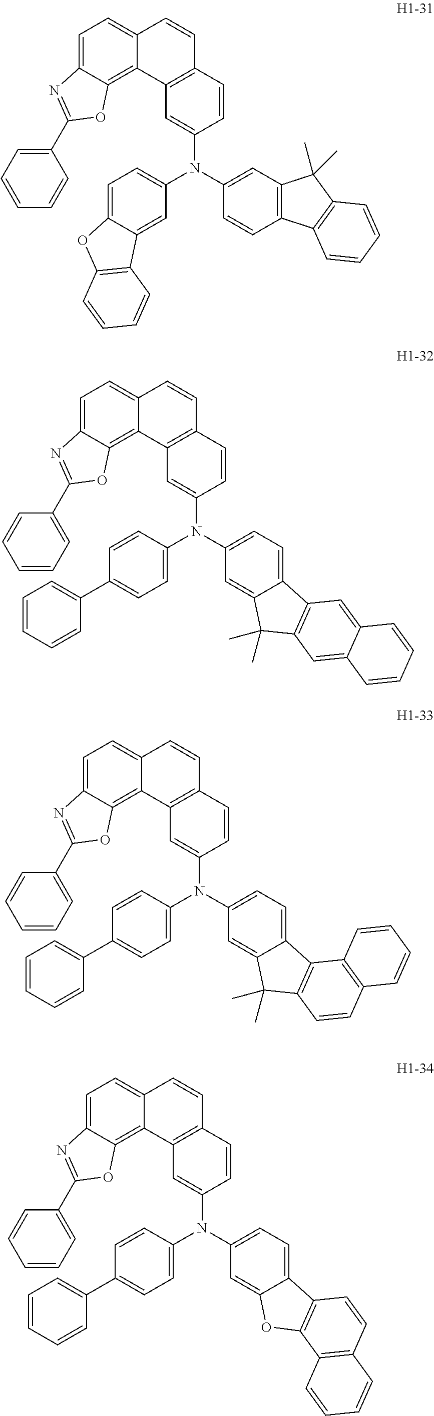 [SMILES: CC1(C)c2ccccc2-c2ccc(N(c3ccc4oc5ccccc5c4c3)c3ccc4ccc5ccc6nc(-c7ccccc7)oc6c5c4c3)cc21 ; CC1(C)c2cc(N(c3ccc(-c4ccccc4)cc3)c3ccc4ccc5ccc6nc(-c7ccccc7)oc6c5c4c3)ccc2-c2cc3ccccc3cc21 ; CC1(C)c2cc(N(c3ccc(-c4ccccc4)cc3)c3ccc4ccc5ccc6nc(-c7ccccc7)oc6c5c4c3)ccc2-c2c1ccc1ccccc21 ; c1ccc(-c2ccc(N(c3ccc4c(c3)oc3c5ccccc5ccc43)c3ccc4ccc5ccc6nc(-c7ccccc7)oc6c5c4c3)cc2)cc1] 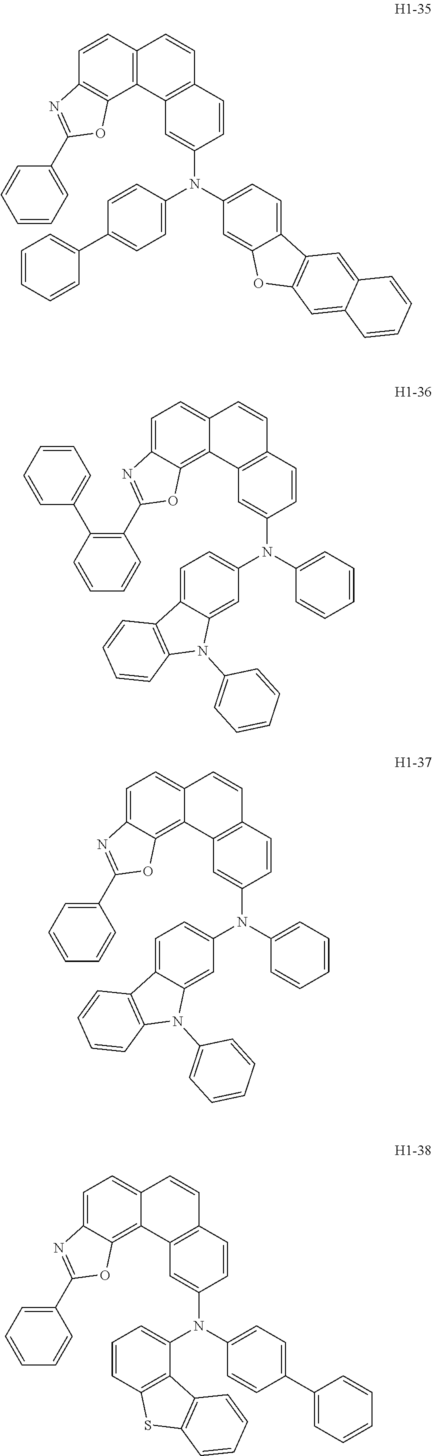 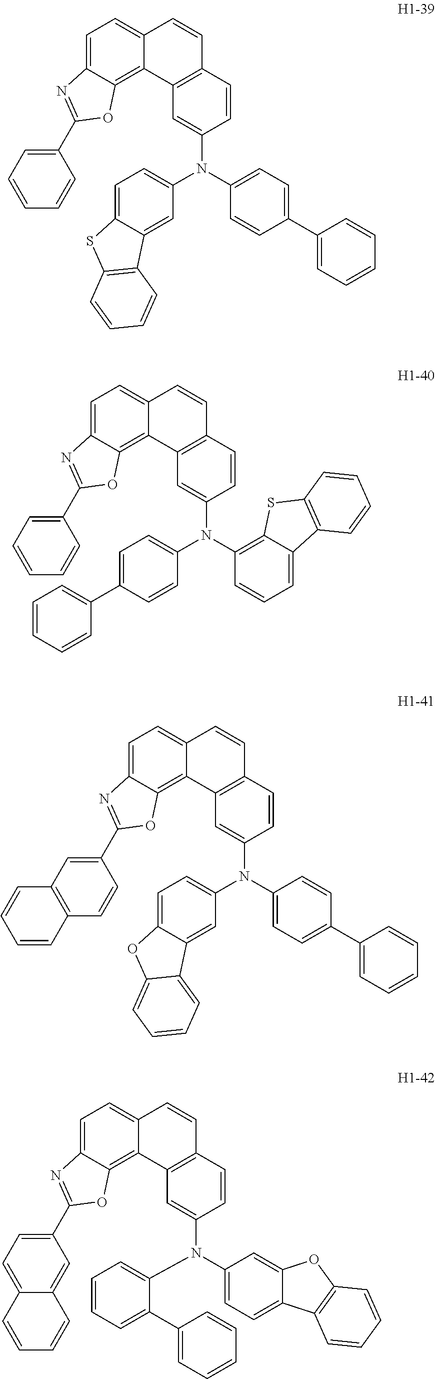 [SMILES: c1ccc(-c2ccc(N(c3ccc4sc5ccccc5c4c3)c3ccc4ccc5ccc6nc(-c7ccccc7)oc6c5c4c3)cc2)cc1 ; c1ccc(-c2ccc(N(c3ccc4ccc5ccc6nc(-c7ccccc7)oc6c5c4c3)c3cccc4c3sc3ccccc34)cc2)cc1 ; c1ccc(-c2ccc(N(c3ccc4oc5ccccc5c4c3)c3ccc4ccc5ccc6nc(-c7ccc8ccccc8c7)oc6c5c4c3)cc2)cc1 ; c1ccc(-c2ccccc2N(c2ccc3c(c2)oc2ccccc23)c2ccc3ccc4ccc5nc(-c6ccc7ccccc7c6)oc5c4c3c2)cc1] 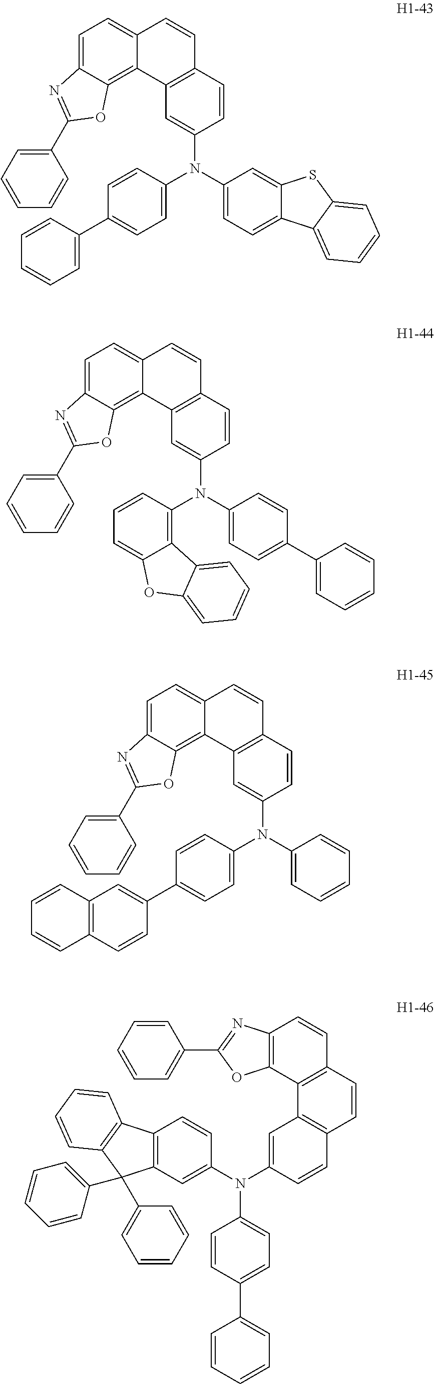 [SMILES: c1ccc(-c2ccc(N(c3ccc4c(c3)sc3ccccc34)c3ccc4ccc5ccc6nc(-c7ccccc7)oc6c5c4c3)cc2)cc1 ; c1ccc(-c2ccc(N(c3ccc4ccc5ccc6nc(-c7ccccc7)oc6c5c4c3)c3cccc4oc5ccccc5c34)cc2)cc1 ; c1ccc(-c2nc3ccc4ccc5ccc(N(c6ccccc6)c6ccc(-c7ccc8ccccc8c7)cc6)cc5c4c3o2)cc1 ; c1ccc(-c2ccc(N(c3ccc4c(c3)C(c3ccccc3)(c3ccccc3)c3ccccc3-4)c3ccc4ccc5ccc6nc(-c7ccccc7)oc6c5c4c3)cc2)cc1] 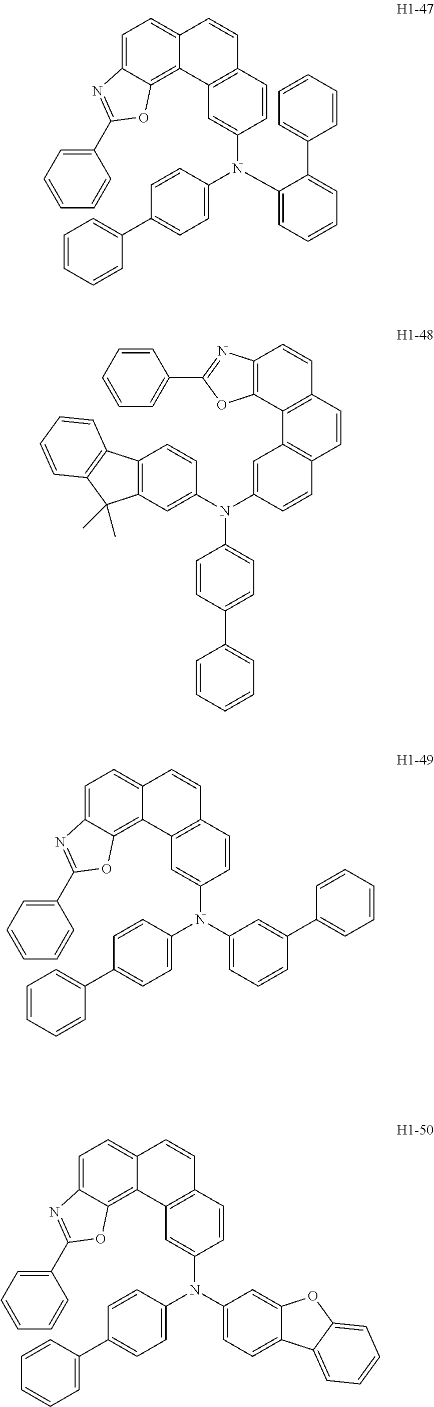 [SMILES: c1ccc(-c2ccc(N(c3ccc4ccc5ccc6nc(-c7ccccc7)oc6c5c4c3)c3ccccc3-c3ccccc3)cc2)cc1 ; CC1(C)c2ccccc2-c2ccc(N(c3ccc(-c4ccccc4)cc3)c3ccc4ccc5ccc6nc(-c7ccccc7)oc6c5c4c3)cc21 ; c1ccc(-c2ccc(N(c3cccc(-c4ccccc4)c3)c3ccc4ccc5ccc6nc(-c7ccccc7)oc6c5c4c3)cc2)cc1 ; c1ccc(-c2ccc(N(c3ccc4c(c3)oc3ccccc34)c3ccc4ccc5ccc6nc(-c7ccccc7)oc6c5c4c3)cc2)cc1] 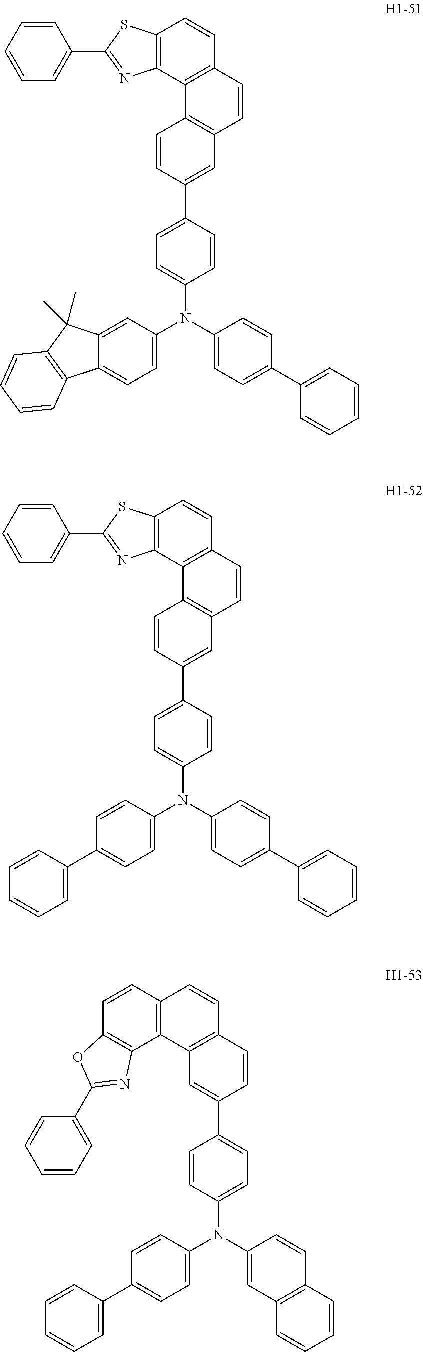 [SMILES: CC1(C)c2ccccc2-c2ccc(N(c3ccc(-c4ccccc4)cc3)c3ccc(-c4ccc5c(ccc6ccc7sc(-c8ccccc8)nc7c65)c4)cc3)cc21 ; c1ccc(-c2ccc(N(c3ccc(-c4ccccc4)cc3)c3ccc(-c4ccc5c(ccc6ccc7sc(-c8ccccc8)nc7c65)c4)cc3)cc2)cc1 ; c1ccc(-c2ccc(N(c3ccc(-c4ccc5ccc6ccc7oc(-c8ccccc8)nc7c6c5c4)cc3)c3ccc4ccccc4c3)cc2)cc1] 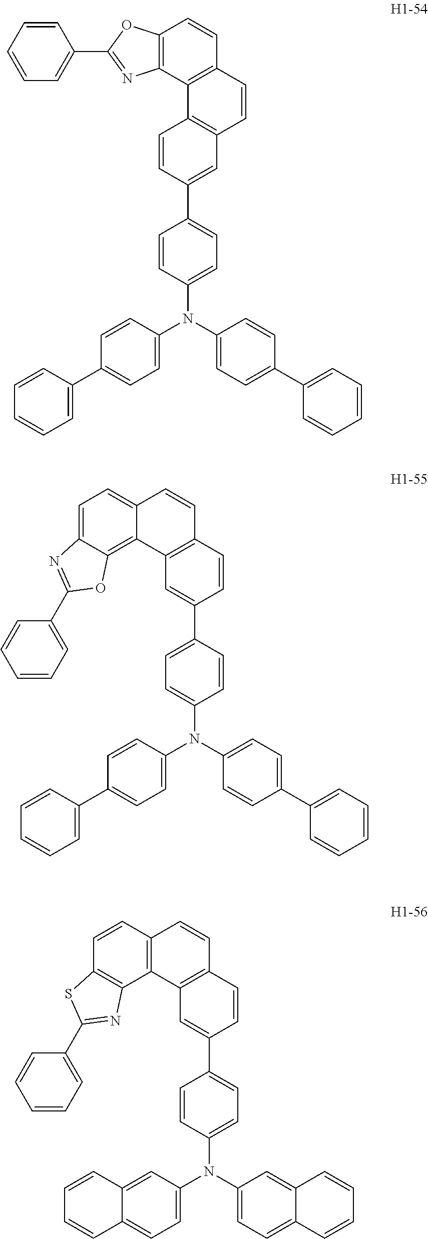 [SMILES: c1ccc(-c2ccc(N(c3ccc(-c4ccccc4)cc3)c3ccc(-c4ccc5c(ccc6ccc7oc(-c8ccccc8)nc7c65)c4)cc3)cc2)cc1 ; c1ccc(-c2ccc(N(c3ccc(-c4ccccc4)cc3)c3ccc(-c4ccc5ccc6ccc7nc(-c8ccccc8)oc7c6c5c4)cc3)cc2)cc1 ; c1ccc(-c2nc3c(ccc4ccc5ccc(-c6ccc(N(c7ccc8ccccc8c7)c7ccc8ccccc8c7)cc6)cc5c43)s2)cc1] 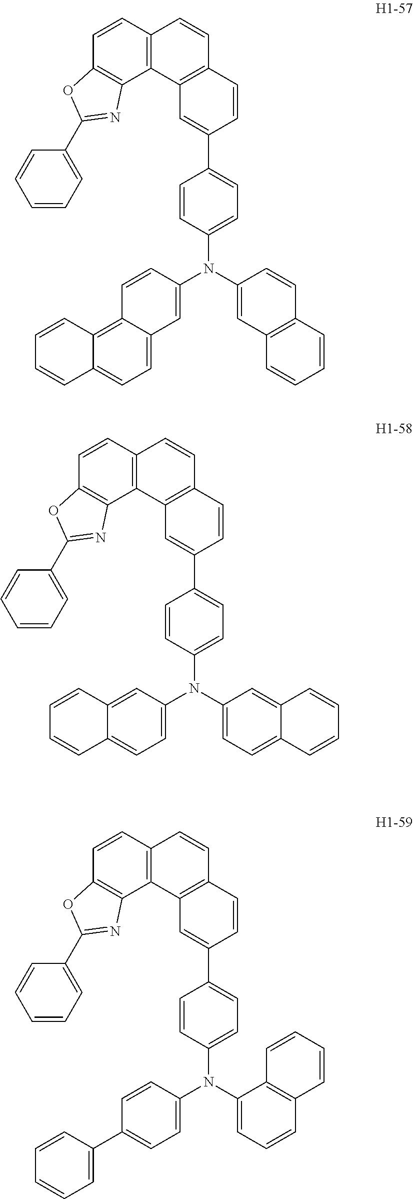 [SMILES: c1ccc(-c2nc3c(ccc4ccc5ccc(-c6ccc(N(c7ccc8ccccc8c7)c7ccc8c(ccc9ccccc98)c7)cc6)cc5c43)o2)cc1 ; c1ccc(-c2nc3c(ccc4ccc5ccc(-c6ccc(N(c7ccc8ccccc8c7)c7ccc8ccccc8c7)cc6)cc5c43)o2)cc1 ; c1ccc(-c2ccc(N(c3ccc(-c4ccc5ccc6ccc7oc(-c8ccccc8)nc7c6c5c4)cc3)c3cccc4ccccc34)cc2)cc1] 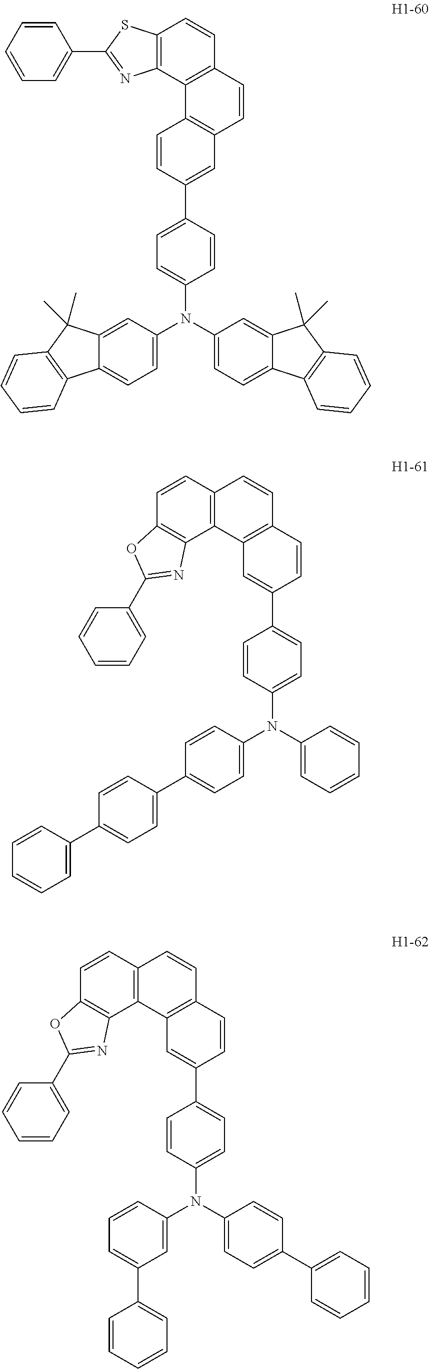 [SMILES: CC1(C)c2ccccc2-c2ccc(N(c3ccc(-c4ccc5c(ccc6ccc7sc(-c8ccccc8)nc7c65)c4)cc3)c3ccc4c(c3)C(C)(C)c3ccccc3-4)cc21 ; c1ccc(-c2ccc(-c3ccc(N(c4ccccc4)c4ccc(-c5ccc6ccc7ccc8oc(-c9ccccc9)nc8c7c6c5)cc4)cc3)cc2)cc1 ; c1ccc(-c2ccc(N(c3ccc(-c4ccc5ccc6ccc7oc(-c8ccccc8)nc7c6c5c4)cc3)c3cccc(-c4ccccc4)c3)cc2)cc1] 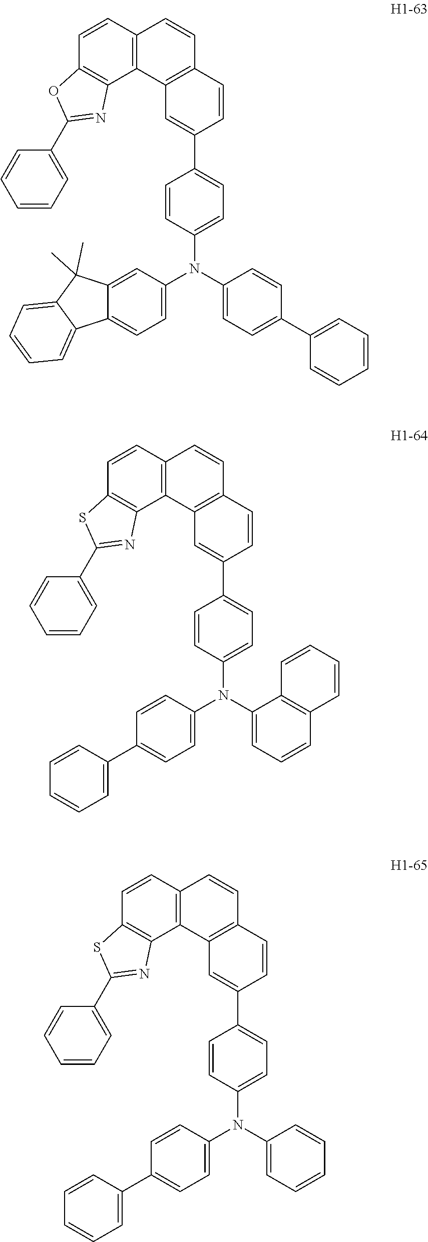 [SMILES: CC1(C)c2ccccc2-c2ccc(N(c3ccc(-c4ccccc4)cc3)c3ccc(-c4ccc5ccc6ccc7oc(-c8ccccc8)nc7c6c5c4)cc3)cc21 ; c1ccc(-c2ccc(N(c3ccc(-c4ccc5ccc6ccc7sc(-c8ccccc8)nc7c6c5c4)cc3)c3cccc4ccccc34)cc2)cc1 ; c1ccc(-c2ccc(N(c3ccccc3)c3ccc(-c4ccc5ccc6ccc7sc(-c8ccccc8)nc7c6c5c4)cc3)cc2)cc1] 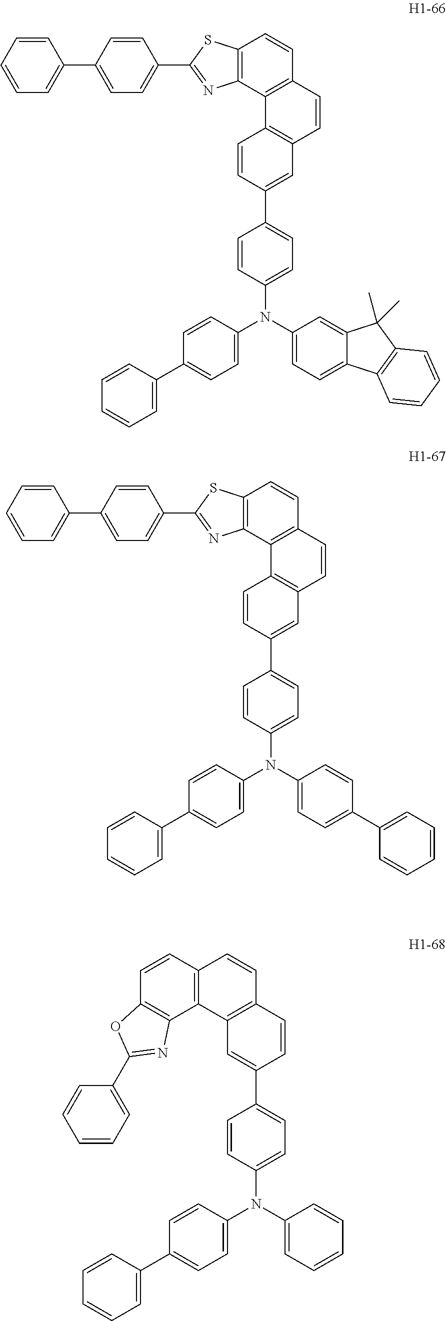 [SMILES: CC1(C)c2ccccc2-c2ccc(N(c3ccc(-c4ccccc4)cc3)c3ccc(-c4ccc5c(ccc6ccc7sc(-c8ccc(-c9ccccc9)cc8)nc7c65)c4)cc3)cc21 ; c1ccc(-c2ccc(-c3nc4c(ccc5ccc6cc(-c7ccc(N(c8ccc(-c9ccccc9)cc8)c8ccc(-c9ccccc9)cc8)cc7)ccc6c54)s3)cc2)cc1 ; c1ccc(-c2ccc(N(c3ccccc3)c3ccc(-c4ccc5ccc6ccc7oc(-c8ccccc8)nc7c6c5c4)cc3)cc2)cc1] 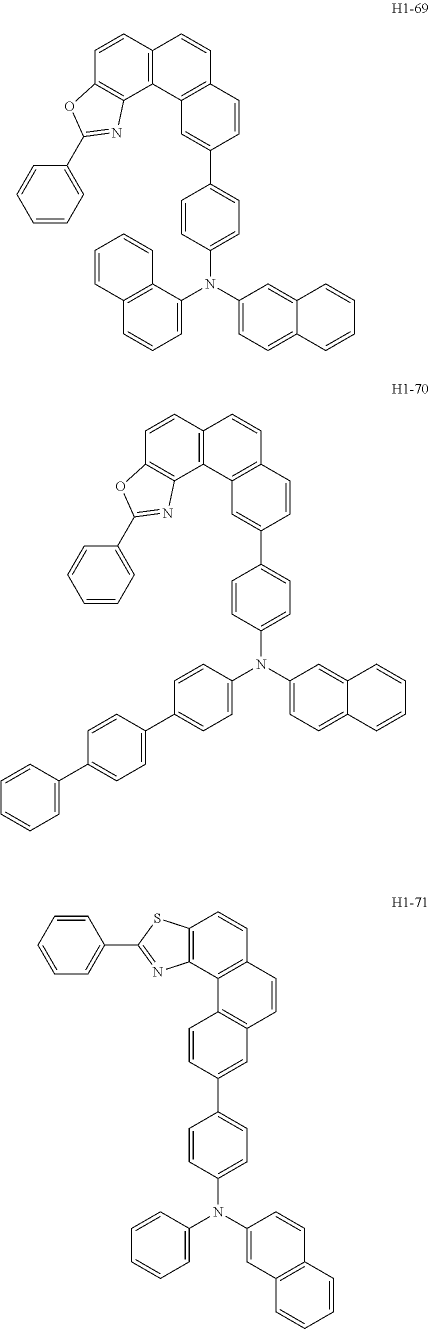 [SMILES: c1ccc(-c2nc3c(ccc4ccc5ccc(-c6ccc(N(c7ccc8ccccc8c7)c7cccc8ccccc78)cc6)cc5c43)o2)cc1 ; c1ccc(-c2ccc(-c3ccc(N(c4ccc(-c5ccc6ccc7ccc8oc(-c9ccccc9)nc8c7c6c5)cc4)c4ccc5ccccc5c4)cc3)cc2)cc1 ; c1ccc(-c2nc3c(ccc4ccc5cc(-c6ccc(N(c7ccccc7)c7ccc8ccccc8c7)cc6)ccc5c43)s2)cc1] 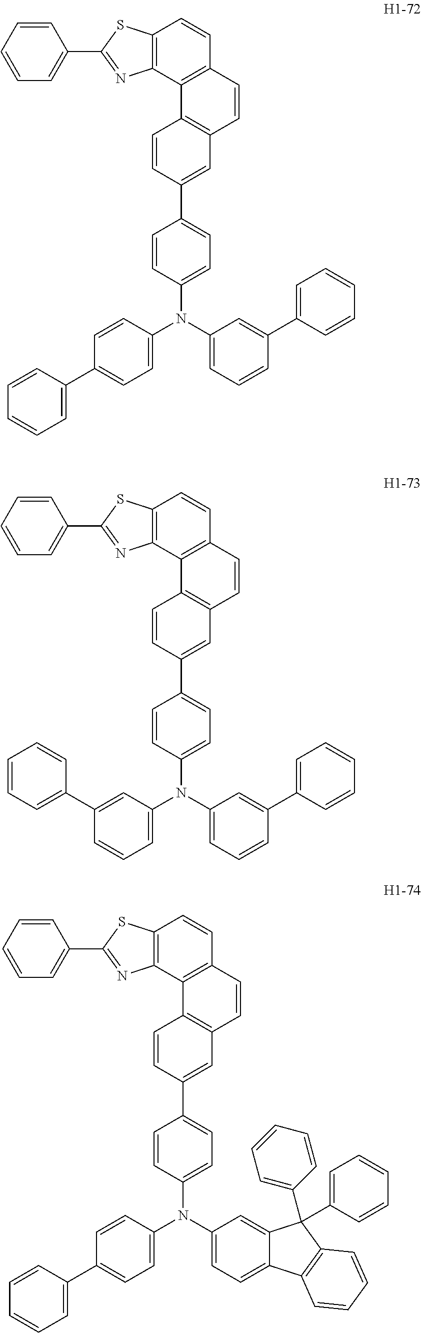 [SMILES: c1ccc(-c2ccc(N(c3ccc(-c4ccc5c(ccc6ccc7sc(-c8ccccc8)nc7c65)c4)cc3)c3cccc(-c4ccccc4)c3)cc2)cc1 ; c1ccc(-c2cccc(N(c3ccc(-c4ccc5c(ccc6ccc7sc(-c8ccccc8)nc7c65)c4)cc3)c3cccc(-c4ccccc4)c3)c2)cc1 ; c1ccc(-c2ccc(N(c3ccc(-c4ccc5c(ccc6ccc7sc(-c8ccccc8)nc7c65)c4)cc3)c3ccc4c(c3)C(c3ccccc3)(c3ccccc3)c3ccccc3-4)cc2)cc1] 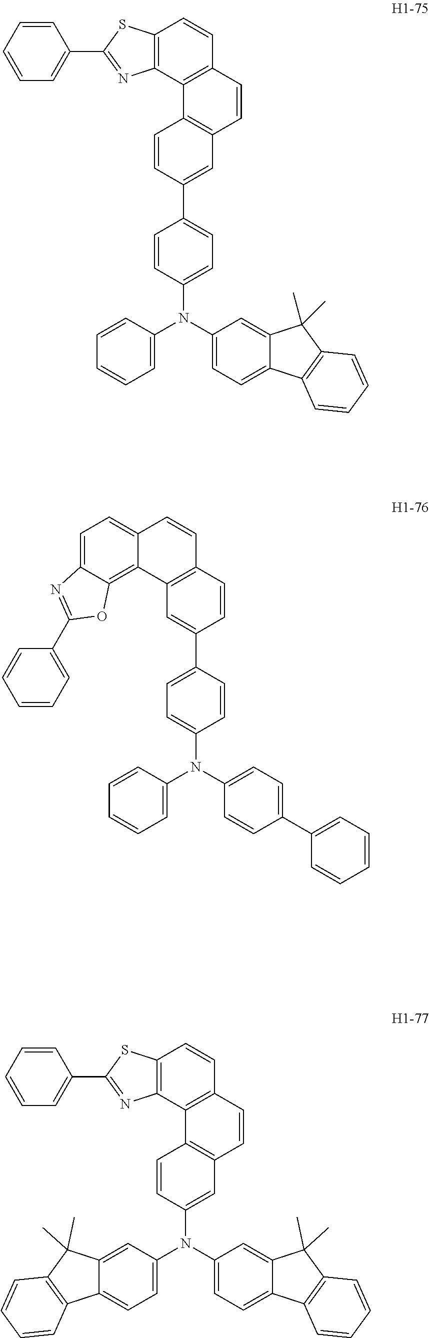 [SMILES: CC1(C)c2ccccc2-c2ccc(N(c3ccccc3)c3ccc(-c4ccc5c(ccc6ccc7sc(-c8ccccc8)nc7c65)c4)cc3)cc21 ; c1ccc(-c2ccc(N(c3ccccc3)c3ccc(-c4ccc5ccc6ccc7nc(-c8ccccc8)oc7c6c5c4)cc3)cc2)cc1 ; CC1(C)c2ccccc2-c2ccc(N(c3ccc4c(c3)C(C)(C)c3ccccc3-4)c3ccc4c(ccc5ccc6sc(-c7ccccc7)nc6c54)c3)cc21] 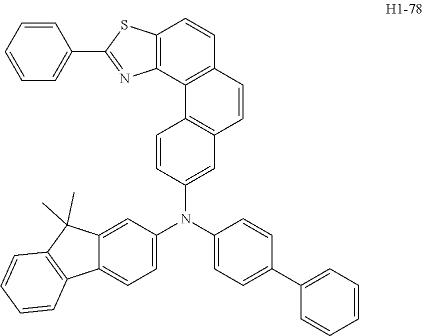 [SMILES: CC1(C)c2ccccc2-c2ccc(N(c3ccc(-c4ccccc4)cc3)c3ccc4c(ccc5ccc6sc(-c7ccccc7)nc6c54)c3)cc21] 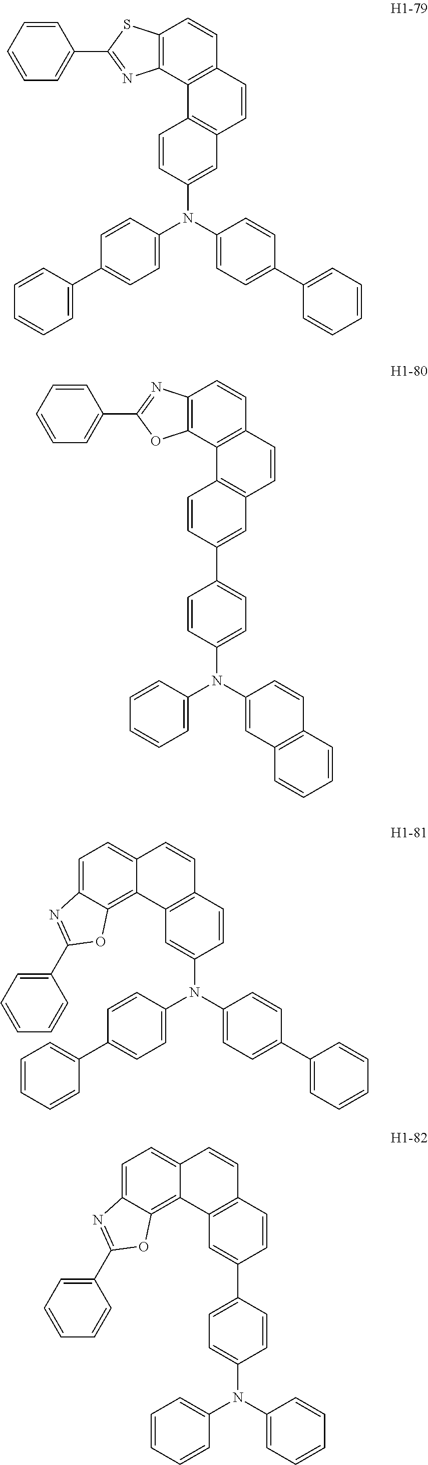 [SMILES: c1ccc(-c2ccc(N(c3ccc(-c4ccccc4)cc3)c3ccc4c(ccc5ccc6sc(-c7ccccc7)nc6c54)c3)cc2)cc1 ; c1ccc(-c2nc3ccc4ccc5cc(-c6ccc(N(c7ccccc7)c7ccc8ccccc8c7)cc6)ccc5c4c3o2)cc1 ; c1ccc(-c2ccc(N(c3ccc(-c4ccccc4)cc3)c3ccc4ccc5ccc6nc(-c7ccccc7)oc6c5c4c3)cc2)cc1 ; c1ccc(-c2nc3ccc4ccc5ccc(-c6ccc(N(c7ccccc7)c7ccccc7)cc6)cc5c4c3o2)cc1] 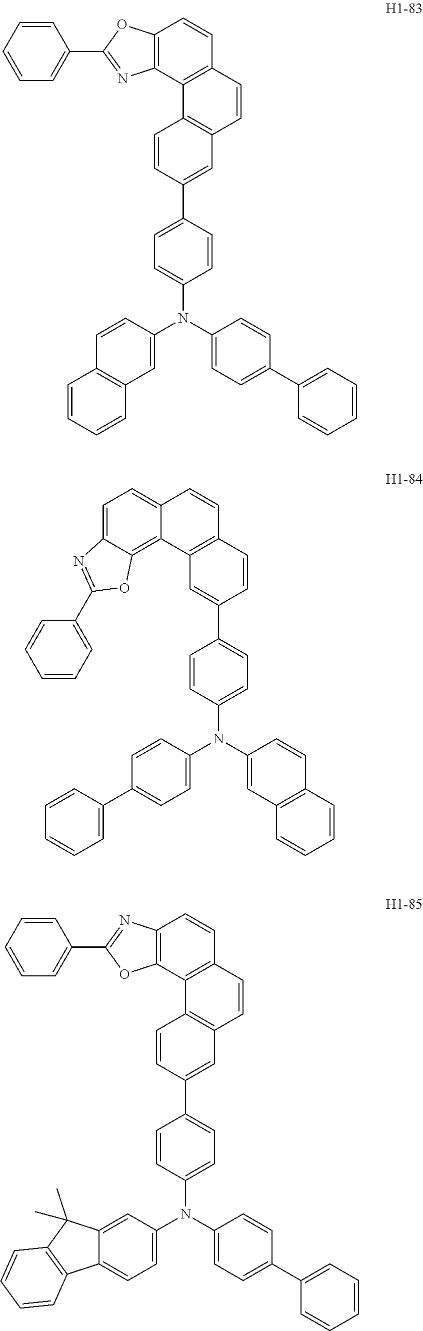 [SMILES: c1ccc(-c2ccc(N(c3ccc(-c4ccc5c(ccc6ccc7oc(-c8ccccc8)nc7c65)c4)cc3)c3ccc4ccccc4c3)cc2)cc1 ; c1ccc(-c2ccc(N(c3ccc(-c4ccc5ccc6ccc7nc(-c8ccccc8)oc7c6c5c4)cc3)c3ccc4ccccc4c3)cc2)cc1 ; CC1(C)c2ccccc2-c2ccc(N(c3ccc(-c4ccccc4)cc3)c3ccc(-c4ccc5c(ccc6ccc7nc(-c8ccccc8)oc7c65)c4)cc3)cc21] 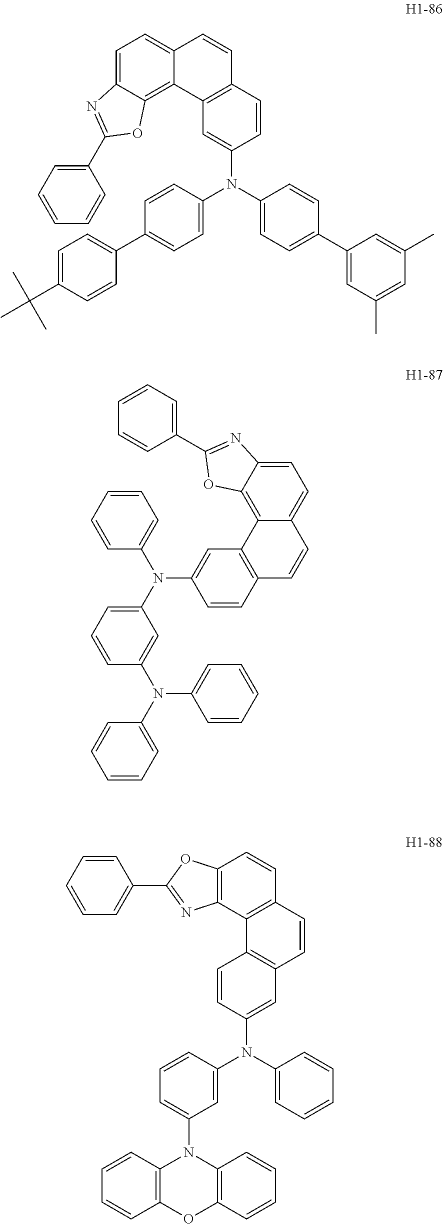 [SMILES: Cc1cc(C)cc(-c2ccc(N(c3ccc(-c4ccc(C(C)(C)C)cc4)cc3)c3ccc4ccc5ccc6nc(-c7ccccc7)oc6c5c4c3)cc2)c1 ; c1ccc(-c2nc3ccc4ccc5ccc(N(c6ccccc6)c6cccc(N(c7ccccc7)c7ccccc7)c6)cc5c4c3o2)cc1 ; c1ccc(-c2nc3c(ccc4ccc5cc(N(c6ccccc6)c6cccc(N7c8ccccc8Oc8ccccc87)c6)ccc5c43)o2)cc1] 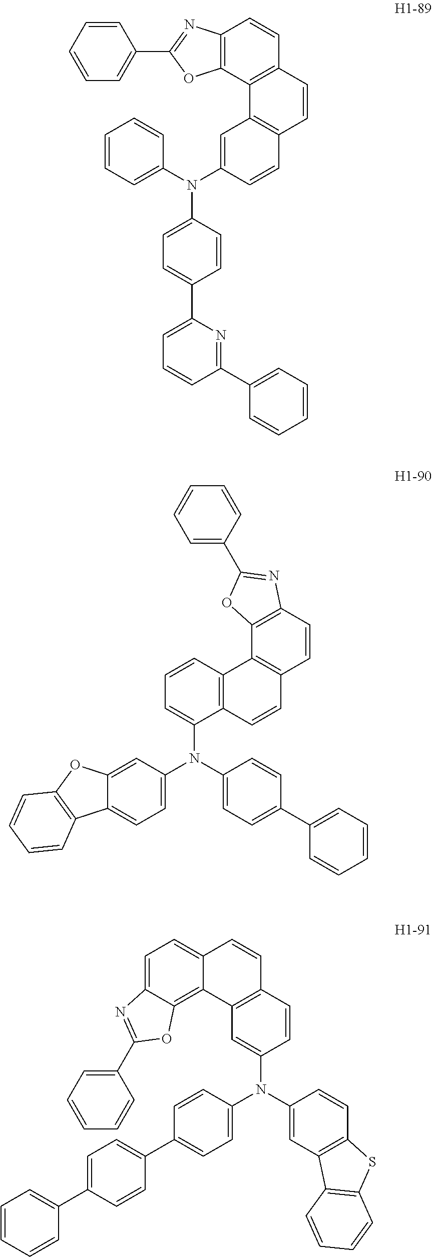 [SMILES: c1ccc(-c2cccc(-c3ccc(N(c4ccccc4)c4ccc5ccc6ccc7nc(-c8ccccc8)oc7c6c5c4)cc3)n2)cc1 ; c1ccc(-c2ccc(N(c3ccc4c(c3)oc3ccccc34)c3cccc4c3ccc3ccc5nc(-c6ccccc6)oc5c34)cc2)cc1 ; c1ccc(-c2ccc(-c3ccc(N(c4ccc5sc6ccccc6c5c4)c4ccc5ccc6ccc7nc(-c8ccccc8)oc7c6c5c4)cc3)cc2)cc1] 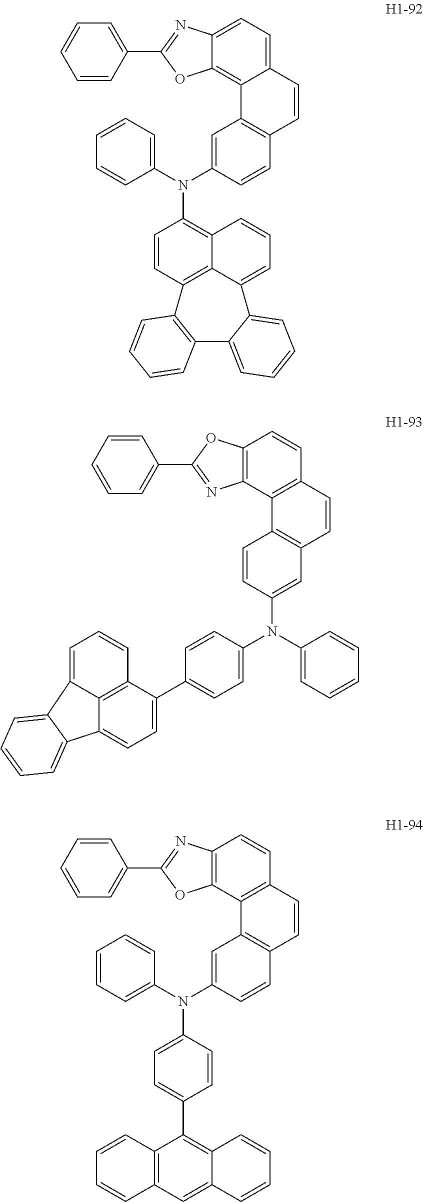 [SMILES: c1ccc(-c2nc3ccc4ccc5ccc(N(c6ccccc6)c6ccc7c8c(cccc68)-c6ccccc6-c6ccccc6-7)cc5c4c3o2)cc1 ; c1ccc(-c2nc3c(ccc4ccc5cc(N(c6ccccc6)c6ccc(-c7ccc8c9c(cccc79)-c7ccccc7-8)cc6)ccc5c43)o2)cc1 ; c1ccc(-c2nc3ccc4ccc5ccc(N(c6ccccc6)c6ccc(-c7c8ccccc8cc8ccccc78)cc6)cc5c4c3o2)cc1] 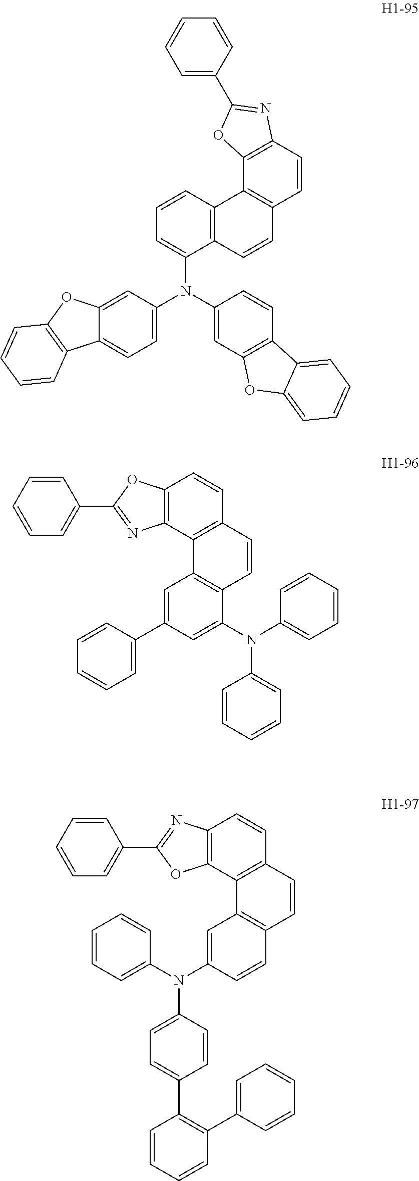 [SMILES: c1ccc(-c2nc3ccc4ccc5c(N(c6ccc7c(c6)oc6ccccc67)c6ccc7c(c6)oc6ccccc67)cccc5c4c3o2)cc1 ; c1ccc(-c2cc(N(c3ccccc3)c3ccccc3)c3ccc4ccc5oc(-c6ccccc6)nc5c4c3c2)cc1 ; c1ccc(-c2nc3ccc4ccc5ccc(N(c6ccccc6)c6ccc(-c7ccccc7-c7ccccc7)cc6)cc5c4c3o2)cc1] 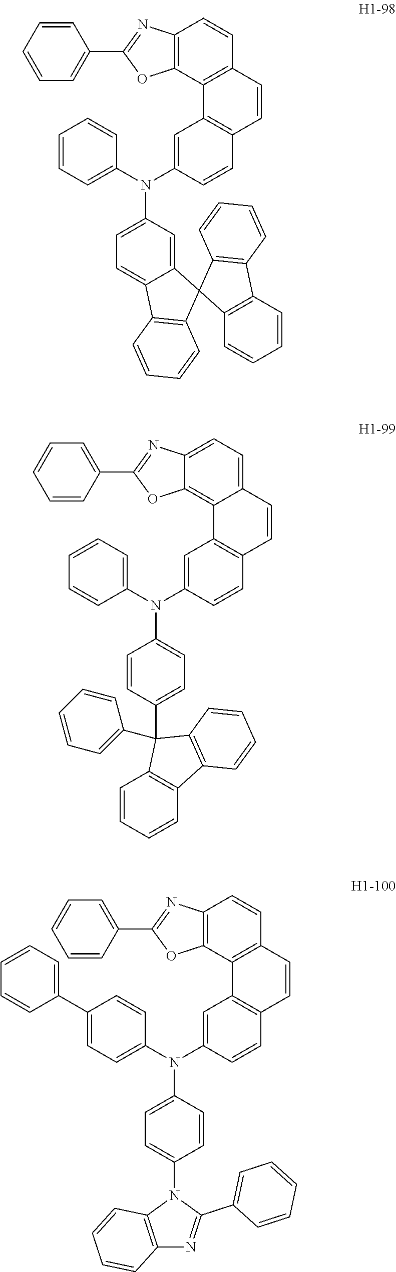 [SMILES: c1ccc(-c2nc3ccc4ccc5ccc(N(c6ccccc6)c6ccc7c(c6)C6(c8ccccc8-c8ccccc86)c6ccccc6-7)cc5c4c3o2)cc1 ; c1ccc(-c2nc3ccc4ccc5ccc(N(c6ccccc6)c6ccc(C7(c8ccccc8)c8ccccc8-c8ccccc87)cc6)cc5c4c3o2)cc1 ; c1ccc(-c2ccc(N(c3ccc(-n4c(-c5ccccc5)nc5ccccc54)cc3)c3ccc4ccc5ccc6nc(-c7ccccc7)oc6c5c4c3)cc2)cc1] 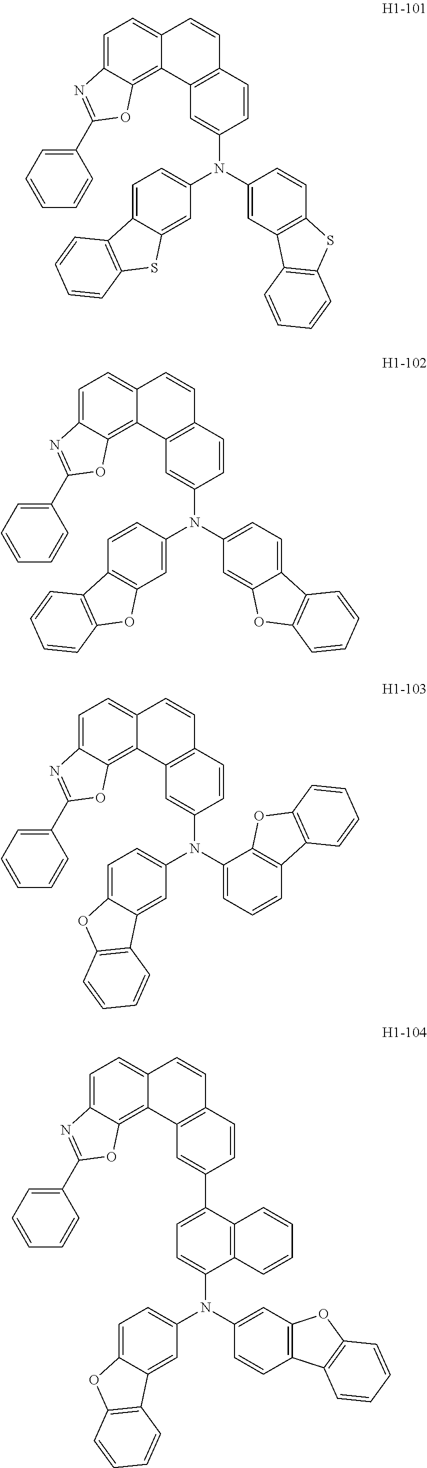 [SMILES: c1ccc(-c2nc3ccc4ccc5ccc(N(c6ccc7c(c6)sc6ccccc67)c6ccc7sc8ccccc8c7c6)cc5c4c3o2)cc1 ; c1ccc(-c2nc3ccc4ccc5ccc(N(c6ccc7c(c6)oc6ccccc67)c6ccc7c(c6)oc6ccccc67)cc5c4c3o2)cc1 ; c1ccc(-c2nc3ccc4ccc5ccc(N(c6ccc7oc8ccccc8c7c6)c6cccc7c6oc6ccccc67)cc5c4c3o2)cc1 ; c1ccc(-c2nc3ccc4ccc5ccc(-c6ccc(N(c7ccc8c(c7)oc7ccccc78)c7ccc8oc9ccccc9c8c7)c7ccccc67)cc5c4c3o2)cc1] 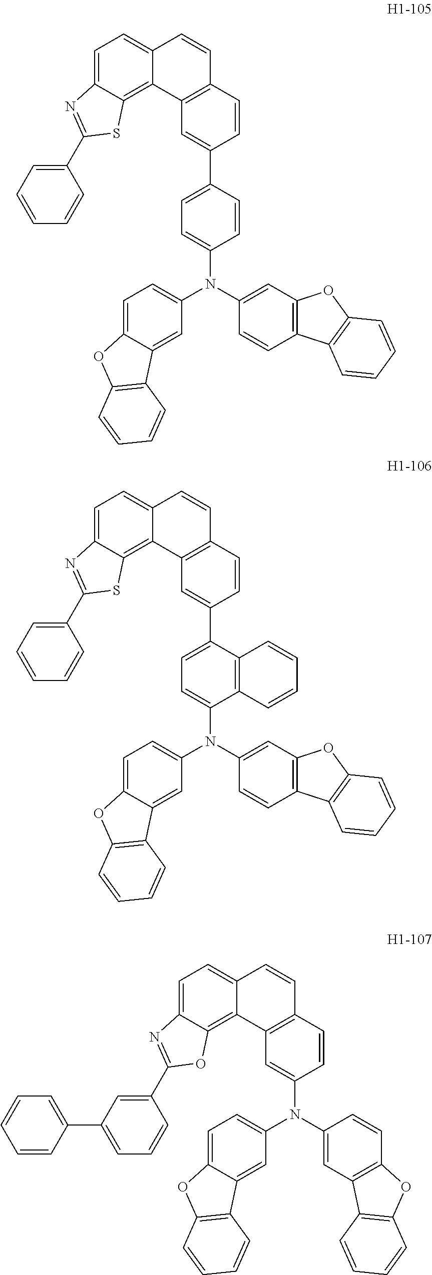 [SMILES: c1ccc(-c2nc3ccc4ccc5ccc(-c6ccc(N(c7ccc8c(c7)oc7ccccc78)c7ccc8oc9ccccc9c8c7)cc6)cc5c4c3s2)cc1 ; c1ccc(-c2nc3ccc4ccc5ccc(-c6ccc(N(c7ccc8c(c7)oc7ccccc78)c7ccc8oc9ccccc9c8c7)c7ccccc67)cc5c4c3s2)cc1 ; c1ccc(-c2cccc(-c3nc4ccc5ccc6ccc(N(c7ccc8oc9ccccc9c8c7)c7ccc8oc9ccccc9c8c7)cc6c5c4o3)c2)cc1] 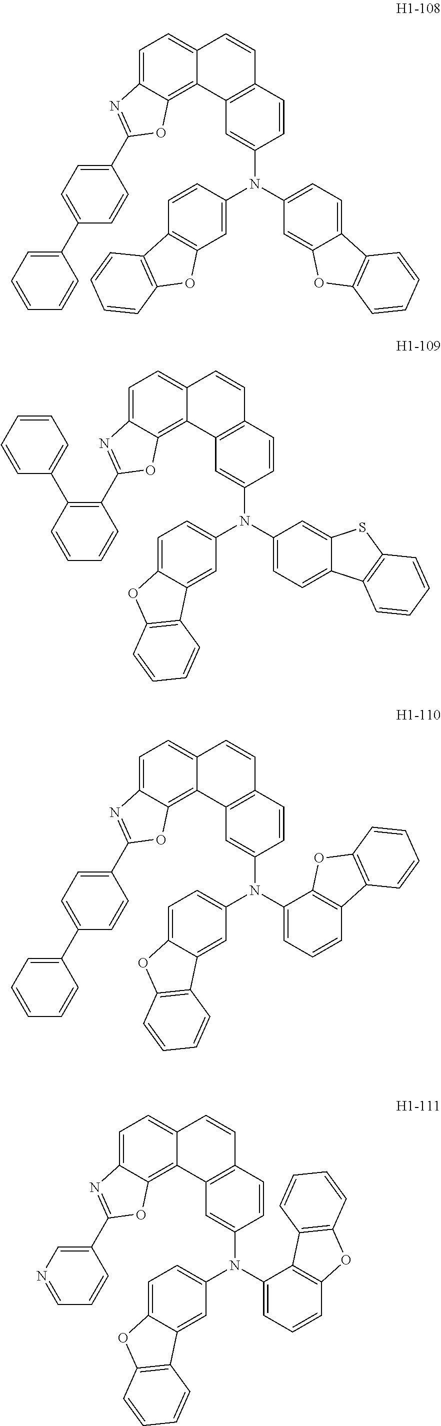 [SMILES: c1ccc(-c2ccc(-c3nc4ccc5ccc6ccc(N(c7ccc8c(c7)oc7ccccc78)c7ccc8c(c7)oc7ccccc78)cc6c5c4o3)cc2)cc1 ; c1ccc(-c2ccccc2-c2nc3ccc4ccc5ccc(N(c6ccc7c(c6)sc6ccccc67)c6ccc7oc8ccccc8c7c6)cc5c4c3o2)cc1 ; c1ccc(-c2ccc(-c3nc4ccc5ccc6ccc(N(c7ccc8oc9ccccc9c8c7)c7cccc8c7oc7ccccc78)cc6c5c4o3)cc2)cc1 ; c1cncc(-c2nc3ccc4ccc5ccc(N(c6ccc7oc8ccccc8c7c6)c6cccc7oc8ccccc8c67)cc5c4c3o2)c1] 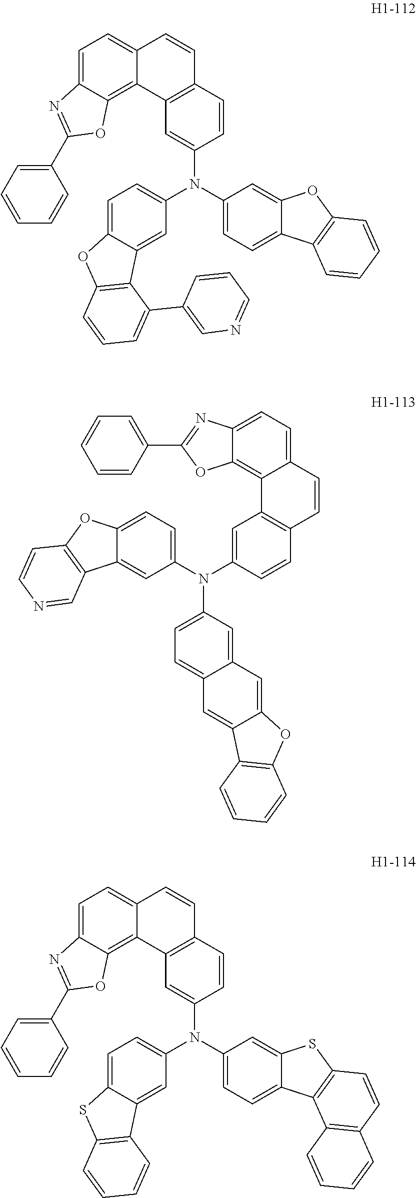 [SMILES: c1ccc(-c2nc3ccc4ccc5ccc(N(c6ccc7c(c6)oc6ccccc67)c6ccc7oc8cccc(-c9cccnc9)c8c7c6)cc5c4c3o2)cc1 ; c1ccc(-c2nc3ccc4ccc5ccc(N(c6ccc7cc8c(cc7c6)oc6ccccc68)c6ccc7oc8ccncc8c7c6)cc5c4c3o2)cc1 ; c1ccc(-c2nc3ccc4ccc5ccc(N(c6ccc7c(c6)sc6ccc8ccccc8c67)c6ccc7sc8ccccc8c7c6)cc5c4c3o2)cc1] 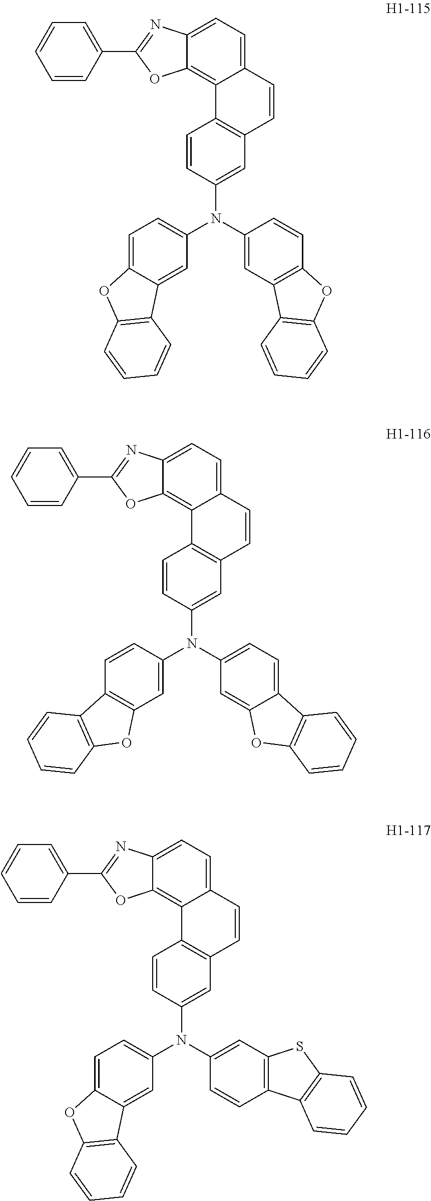 [SMILES: c1ccc(-c2nc3ccc4ccc5cc(N(c6ccc7oc8ccccc8c7c6)c6ccc7oc8ccccc8c7c6)ccc5c4c3o2)cc1 ; c1ccc(-c2nc3ccc4ccc5cc(N(c6ccc7c(c6)oc6ccccc67)c6ccc7c(c6)oc6ccccc67)ccc5c4c3o2)cc1 ; c1ccc(-c2nc3ccc4ccc5cc(N(c6ccc7c(c6)sc6ccccc67)c6ccc7oc8ccccc8c7c6)ccc5c4c3o2)cc1] 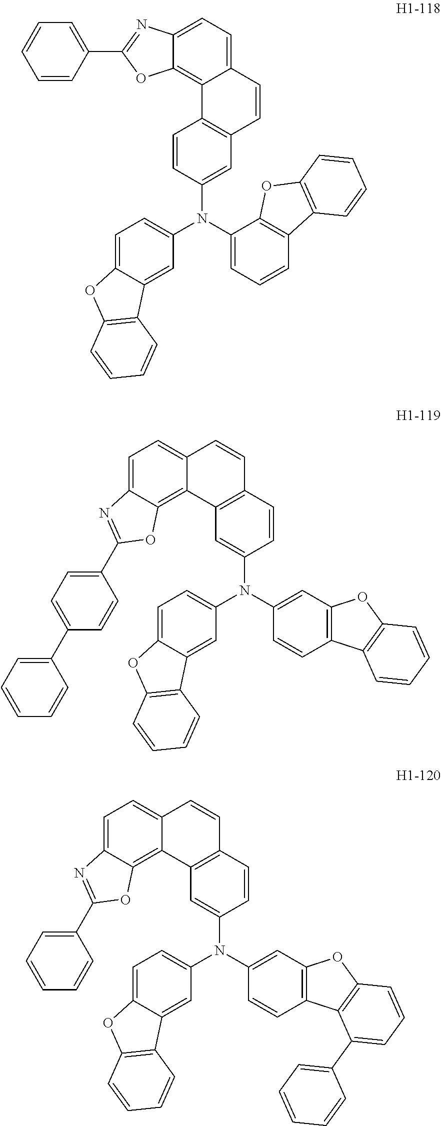 [SMILES: c1ccc(-c2nc3ccc4ccc5cc(N(c6ccc7oc8ccccc8c7c6)c6cccc7c6oc6ccccc67)ccc5c4c3o2)cc1 ; c1ccc(-c2ccc(-c3nc4ccc5ccc6ccc(N(c7ccc8c(c7)oc7ccccc78)c7ccc8oc9ccccc9c8c7)cc6c5c4o3)cc2)cc1 ; c1ccc(-c2nc3ccc4ccc5ccc(N(c6ccc7c(c6)oc6cccc(-c8ccccc8)c67)c6ccc7oc8ccccc8c7c6)cc5c4c3o2)cc1] 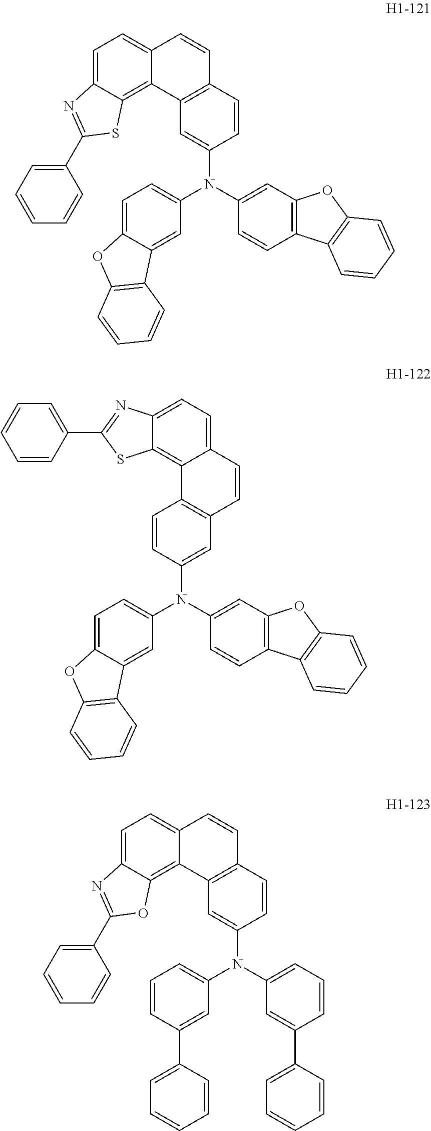 [SMILES: c1ccc(-c2nc3ccc4ccc5ccc(N(c6ccc7c(c6)oc6ccccc67)c6ccc7oc8ccccc8c7c6)cc5c4c3s2)cc1 ; c1ccc(-c2nc3ccc4ccc5cc(N(c6ccc7c(c6)oc6ccccc67)c6ccc7oc8ccccc8c7c6)ccc5c4c3s2)cc1 ; c1ccc(-c2cccc(N(c3cccc(-c4ccccc4)c3)c3ccc4ccc5ccc6nc(-c7ccccc7)oc6c5c4c3)c2)cc1] 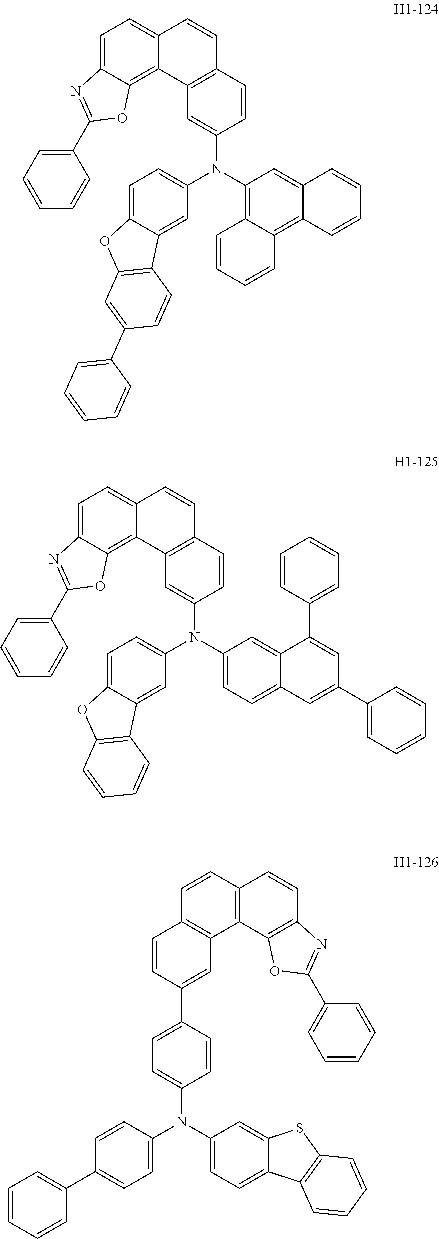 [SMILES: c1ccc(-c2ccc3c(c2)oc2ccc(N(c4ccc5ccc6ccc7nc(-c8ccccc8)oc7c6c5c4)c4cc5ccccc5c5ccccc45)cc23)cc1 ; c1ccc(-c2cc(-c3ccccc3)c3cc(N(c4ccc5oc6ccccc6c5c4)c4ccc5ccc6ccc7nc(-c8ccccc8)oc7c6c5c4)ccc3c2)cc1 ; c1ccc(-c2ccc(N(c3ccc(-c4ccc5ccc6ccc7nc(-c8ccccc8)oc7c6c5c4)cc3)c3ccc4c(c3)sc3ccccc34)cc2)cc1] 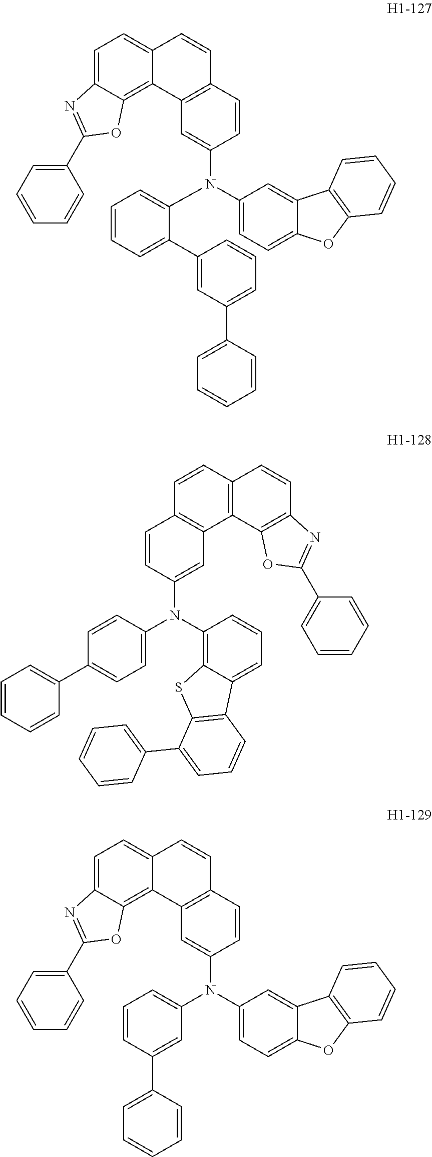 [SMILES: c1ccc(-c2cccc(-c3ccccc3N(c3ccc4oc5ccccc5c4c3)c3ccc4ccc5ccc6nc(-c7ccccc7)oc6c5c4c3)c2)cc1 ; c1ccc(-c2ccc(N(c3ccc4ccc5ccc6nc(-c7ccccc7)oc6c5c4c3)c3cccc4c3sc3c(-c5ccccc5)cccc34)cc2)cc1 ; c1ccc(-c2cccc(N(c3ccc4oc5ccccc5c4c3)c3ccc4ccc5ccc6nc(-c7ccccc7)oc6c5c4c3)c2)cc1] 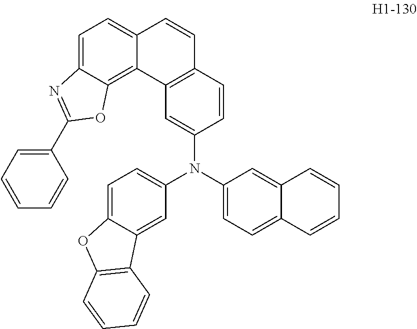 [SMILES: c1ccc(-c2nc3ccc4ccc5ccc(N(c6ccc7ccccc7c6)c6ccc7oc8ccccc8c7c6)cc5c4c3o2)cc1] 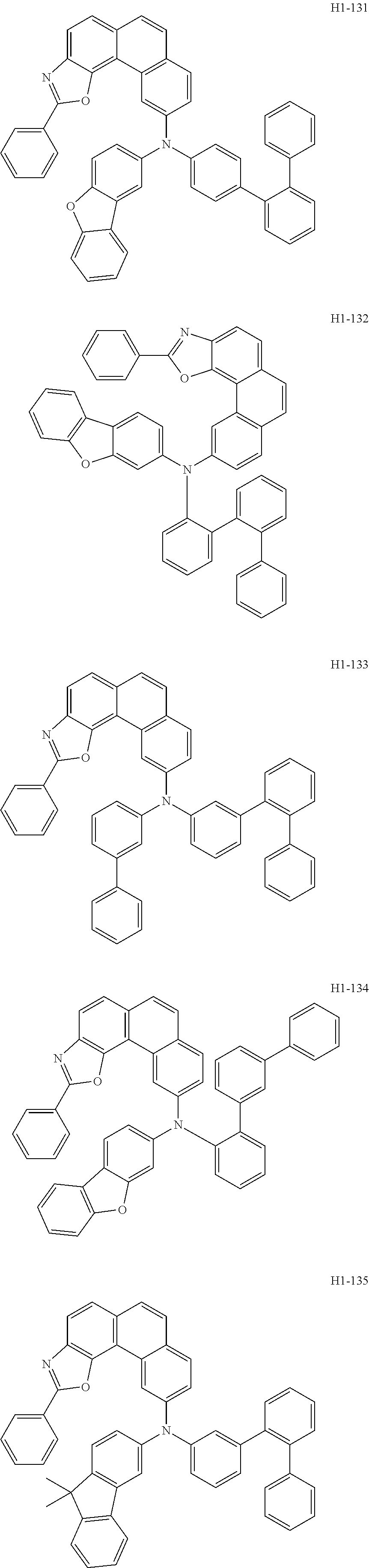 [SMILES: c1ccc(-c2nc3ccc4ccc5ccc(N(c6ccc(-c7ccccc7-c7ccccc7)cc6)c6ccc7oc8ccccc8c7c6)cc5c4c3o2)cc1 ; c1ccc(-c2nc3ccc4ccc5ccc(N(c6ccc7c(c6)oc6ccccc67)c6ccccc6-c6ccccc6-c6ccccc6)cc5c4c3o2)cc1 ; c1ccc(-c2cccc(N(c3cccc(-c4ccccc4-c4ccccc4)c3)c3ccc4ccc5ccc6nc(-c7ccccc7)oc6c5c4c3)c2)cc1 ; c1ccc(-c2cccc(-c3ccccc3N(c3ccc4c(c3)oc3ccccc34)c3ccc4ccc5ccc6nc(-c7ccccc7)oc6c5c4c3)c2)cc1 ; CC1(C)c2ccccc2-c2cc(N(c3cccc(-c4ccccc4-c4ccccc4)c3)c3ccc4ccc5ccc6nc(-c7ccccc7)oc6c5c4c3)ccc21] 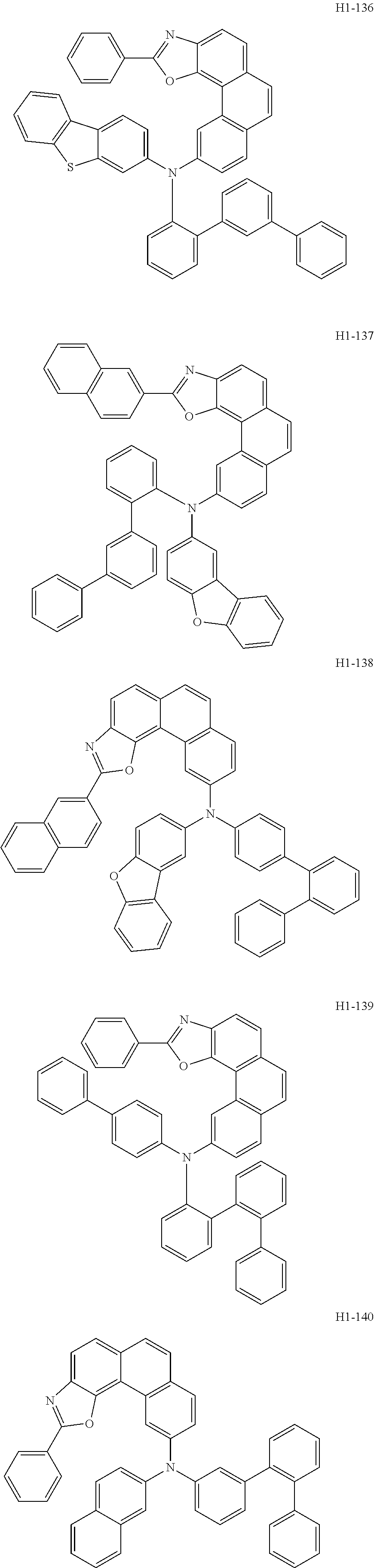 [SMILES: c1ccc(-c2cccc(-c3ccccc3N(c3ccc4c(c3)sc3ccccc34)c3ccc4ccc5ccc6nc(-c7ccccc7)oc6c5c4c3)c2)cc1 ; c1ccc(-c2cccc(-c3ccccc3N(c3ccc4oc5ccccc5c4c3)c3ccc4ccc5ccc6nc(-c7ccc8ccccc8c7)oc6c5c4c3)c2)cc1 ; c1ccc(-c2ccccc2-c2ccc(N(c3ccc4oc5ccccc5c4c3)c3ccc4ccc5ccc6nc(-c7ccc8ccccc8c7)oc6c5c4c3)cc2)cc1 ; c1ccc(-c2ccc(N(c3ccc4ccc5ccc6nc(-c7ccccc7)oc6c5c4c3)c3ccccc3-c3ccccc3-c3ccccc3)cc2)cc1 ; c1ccc(-c2nc3ccc4ccc5ccc(N(c6cccc(-c7ccccc7-c7ccccc7)c6)c6ccc7ccccc7c6)cc5c4c3o2)cc1] 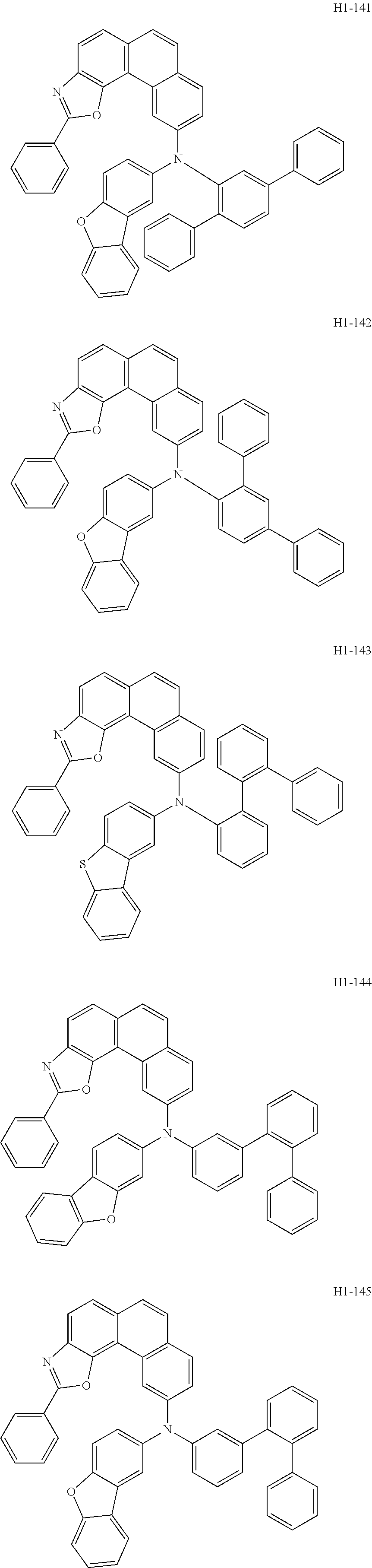 [SMILES: c1ccc(-c2ccc(-c3ccccc3)c(N(c3ccc4oc5ccccc5c4c3)c3ccc4ccc5ccc6nc(-c7ccccc7)oc6c5c4c3)c2)cc1 ; c1ccc(-c2ccc(N(c3ccc4oc5ccccc5c4c3)c3ccc4ccc5ccc6nc(-c7ccccc7)oc6c5c4c3)c(-c3ccccc3)c2)cc1 ; c1ccc(-c2nc3ccc4ccc5ccc(N(c6ccc7sc8ccccc8c7c6)c6ccccc6-c6ccccc6-c6ccccc6)cc5c4c3o2)cc1 ; c1ccc(-c2nc3ccc4ccc5ccc(N(c6cccc(-c7ccccc7-c7ccccc7)c6)c6ccc7c(c6)oc6ccccc67)cc5c4c3o2)cc1 ; c1ccc(-c2nc3ccc4ccc5ccc(N(c6cccc(-c7ccccc7-c7ccccc7)c6)c6ccc7oc8ccccc8c7c6)cc5c4c3o2)cc1] 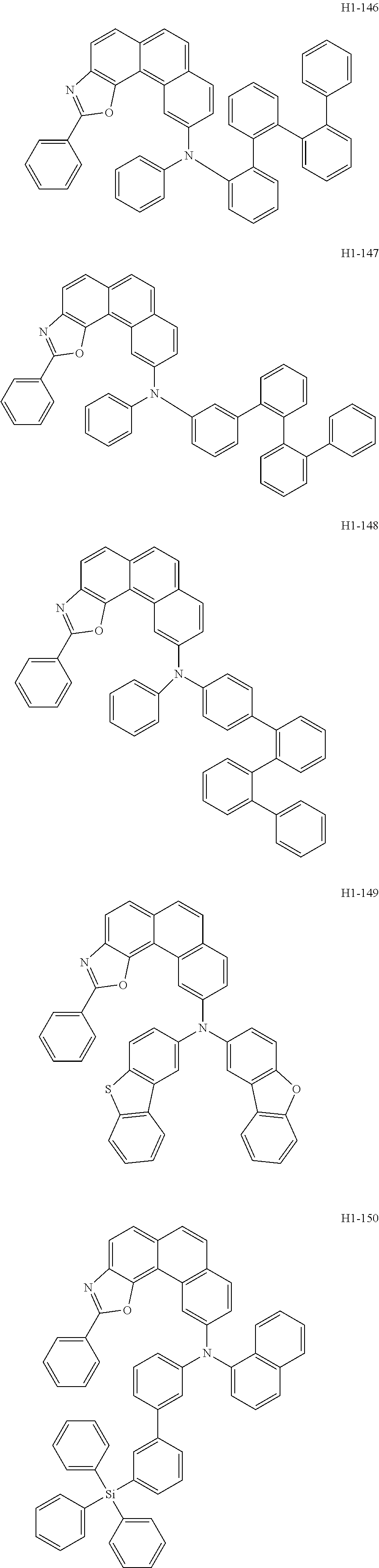 [SMILES: c1ccc(-c2nc3ccc4ccc5ccc(N(c6ccccc6)c6ccccc6-c6ccccc6-c6ccccc6-c6ccccc6)cc5c4c3o2)cc1 ; c1ccc(-c2nc3ccc4ccc5ccc(N(c6ccccc6)c6cccc(-c7ccccc7-c7ccccc7-c7ccccc7)c6)cc5c4c3o2)cc1 ; c1ccc(-c2nc3ccc4ccc5ccc(N(c6ccccc6)c6ccc(-c7ccccc7-c7ccccc7-c7ccccc7)cc6)cc5c4c3o2)cc1 ; c1ccc(-c2nc3ccc4ccc5ccc(N(c6ccc7oc8ccccc8c7c6)c6ccc7sc8ccccc8c7c6)cc5c4c3o2)cc1 ; c1ccc(-c2nc3ccc4ccc5ccc(N(c6cccc(-c7cccc([Si](c8ccccc8)(c8ccccc8)c8ccccc8)c7)c6)c6cccc7ccccc67)cc5c4c3o2)cc1] 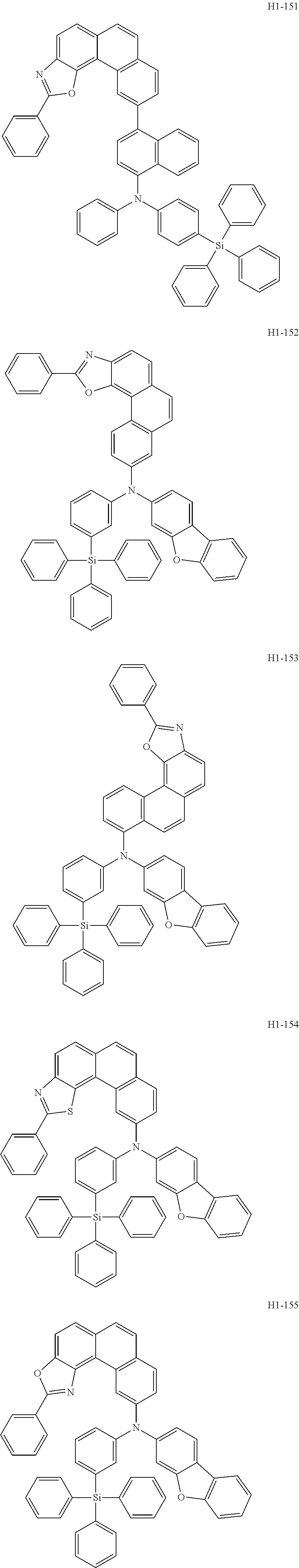 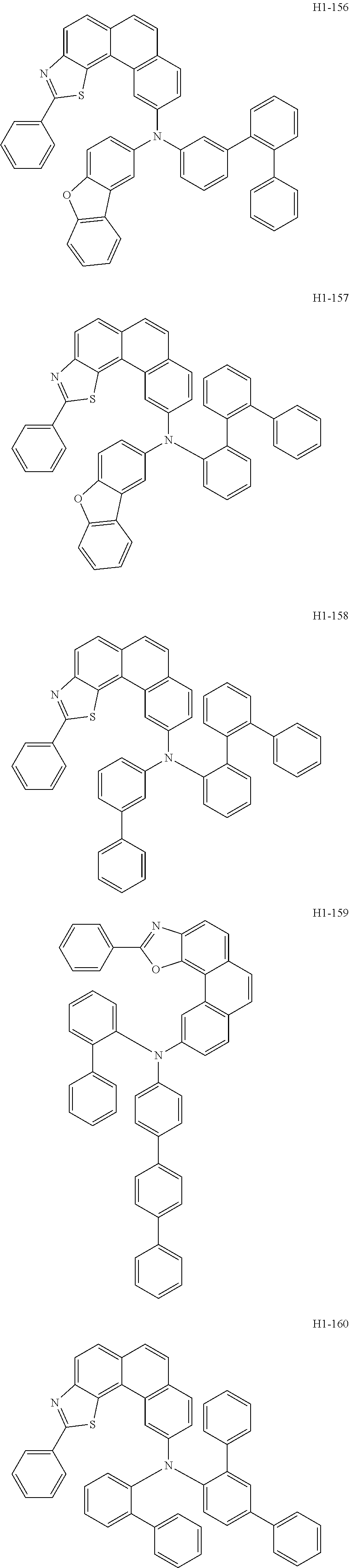 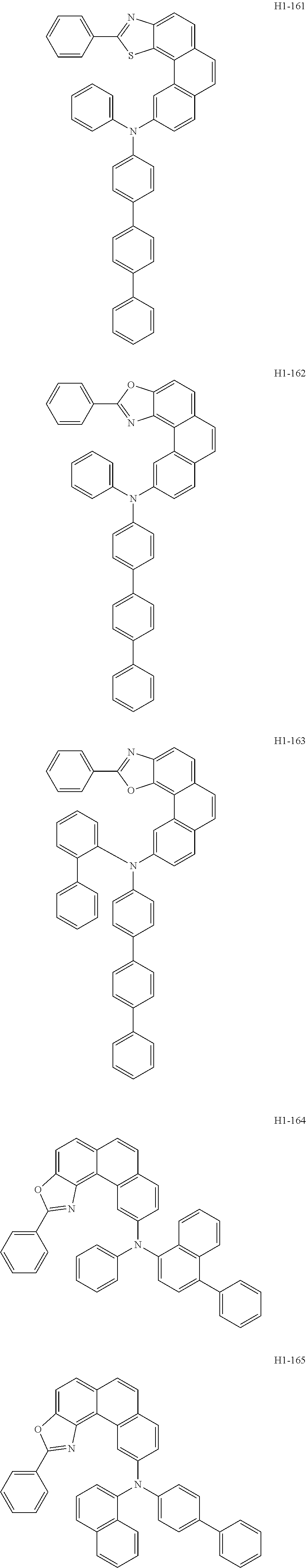 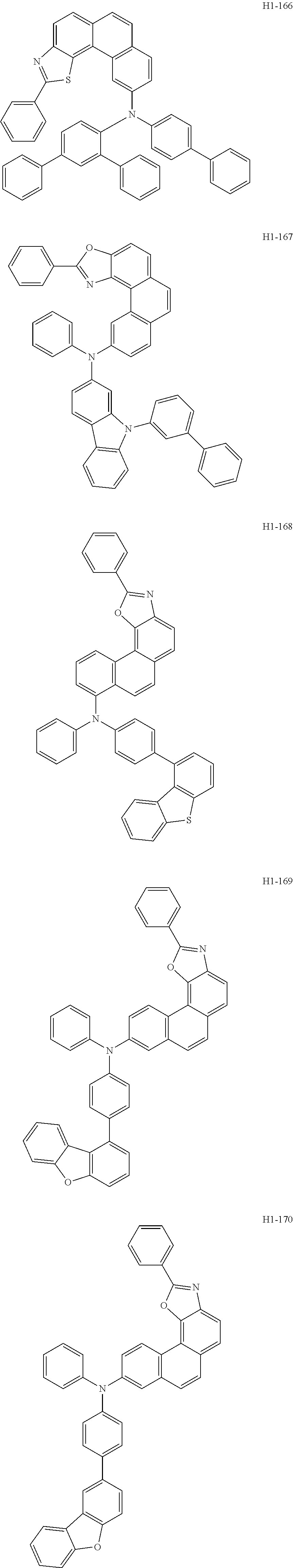 [SMILES: c1ccc(-c2ccc(N(c3ccc4ccc5ccc6nc(-c7ccccc7)sc6c5c4c3)c3ccc(-c4ccccc4)cc3-c3ccccc3)cc2)cc1 ; c1ccc(-c2cccc(-n3c4ccccc4c4ccc(N(c5ccccc5)c5ccc6ccc7ccc8oc(-c9ccccc9)nc8c7c6c5)cc43)c2)cc1 ; c1ccc(-c2nc3ccc4ccc5c(N(c6ccccc6)c6ccc(-c7cccc8sc9ccccc9c78)cc6)cccc5c4c3o2)cc1 ; c1ccc(-c2nc3ccc4ccc5cc(N(c6ccccc6)c6ccc(-c7cccc8oc9ccccc9c78)cc6)ccc5c4c3o2)cc1 ; c1ccc(-c2nc3ccc4ccc5cc(N(c6ccccc6)c6ccc(-c7ccc8oc9ccccc9c8c7)cc6)ccc5c4c3o2)cc1] 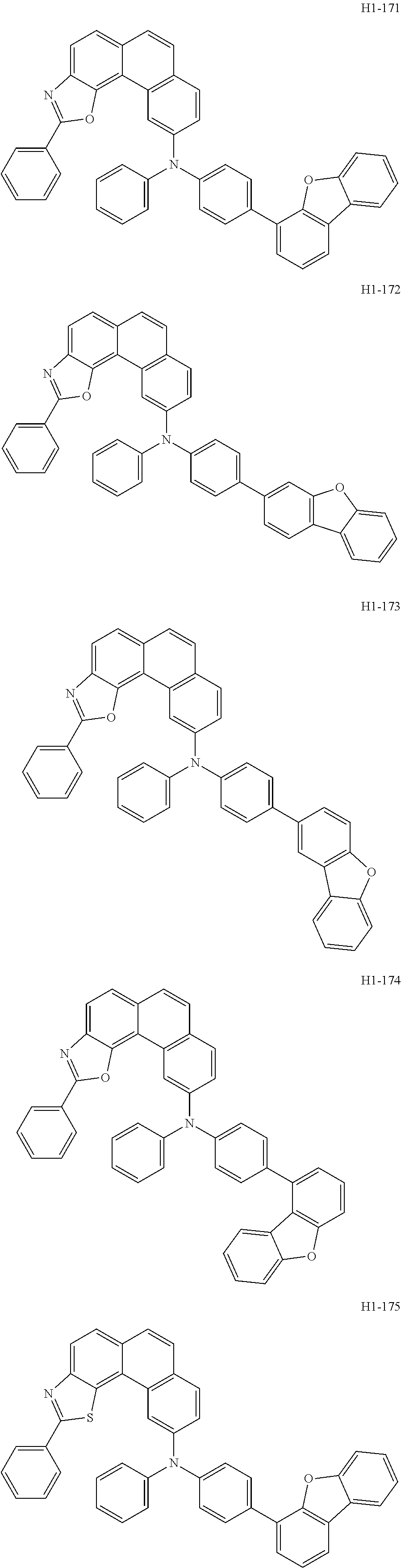 [SMILES: c1ccc(-c2nc3ccc4ccc5ccc(N(c6ccccc6)c6ccc(-c7cccc8c7oc7ccccc78)cc6)cc5c4c3o2)cc1 ; c1ccc(-c2nc3ccc4ccc5ccc(N(c6ccccc6)c6ccc(-c7ccc8c(c7)oc7ccccc78)cc6)cc5c4c3o2)cc1 ; c1ccc(-c2nc3ccc4ccc5ccc(N(c6ccccc6)c6ccc(-c7ccc8oc9ccccc9c8c7)cc6)cc5c4c3o2)cc1 ; c1ccc(-c2nc3ccc4ccc5ccc(N(c6ccccc6)c6ccc(-c7cccc8oc9ccccc9c78)cc6)cc5c4c3o2)cc1 ; c1ccc(-c2nc3ccc4ccc5ccc(N(c6ccccc6)c6ccc(-c7cccc8c7oc7ccccc78)cc6)cc5c4c3s2)cc1] 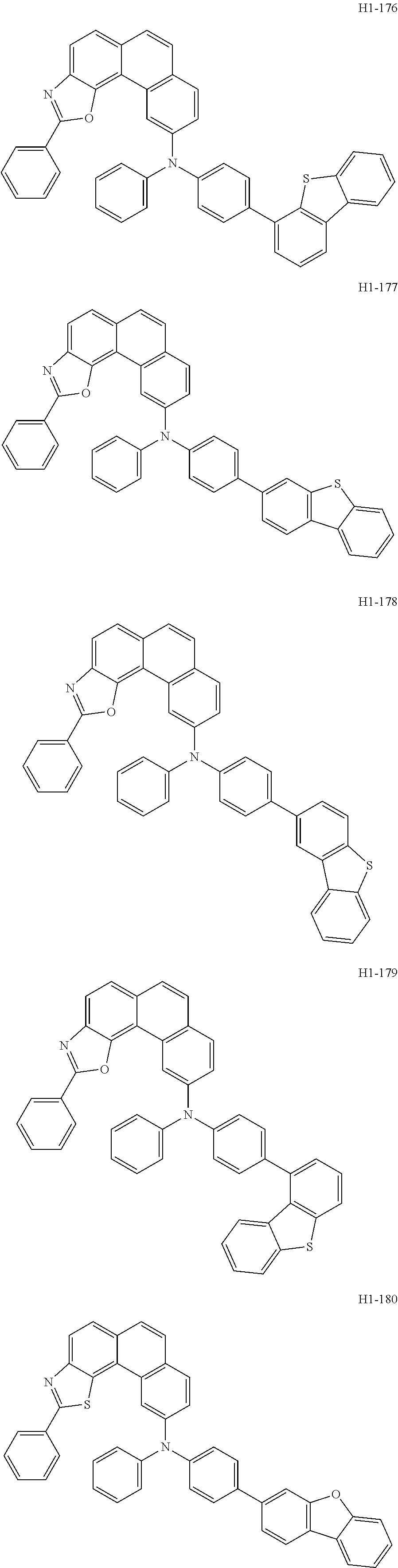 [SMILES: c1ccc(-c2nc3ccc4ccc5ccc(N(c6ccccc6)c6ccc(-c7cccc8c7sc7ccccc78)cc6)cc5c4c3o2)cc1 ; c1ccc(-c2nc3ccc4ccc5ccc(N(c6ccccc6)c6ccc(-c7ccc8c(c7)sc7ccccc78)cc6)cc5c4c3o2)cc1 ; c1ccc(-c2nc3ccc4ccc5ccc(N(c6ccccc6)c6ccc(-c7ccc8sc9ccccc9c8c7)cc6)cc5c4c3o2)cc1 ; c1ccc(-c2nc3ccc4ccc5ccc(N(c6ccccc6)c6ccc(-c7cccc8sc9ccccc9c78)cc6)cc5c4c3o2)cc1 ; c1ccc(-c2nc3ccc4ccc5ccc(N(c6ccccc6)c6ccc(-c7ccc8c(c7)oc7ccccc78)cc6)cc5c4c3s2)cc1] 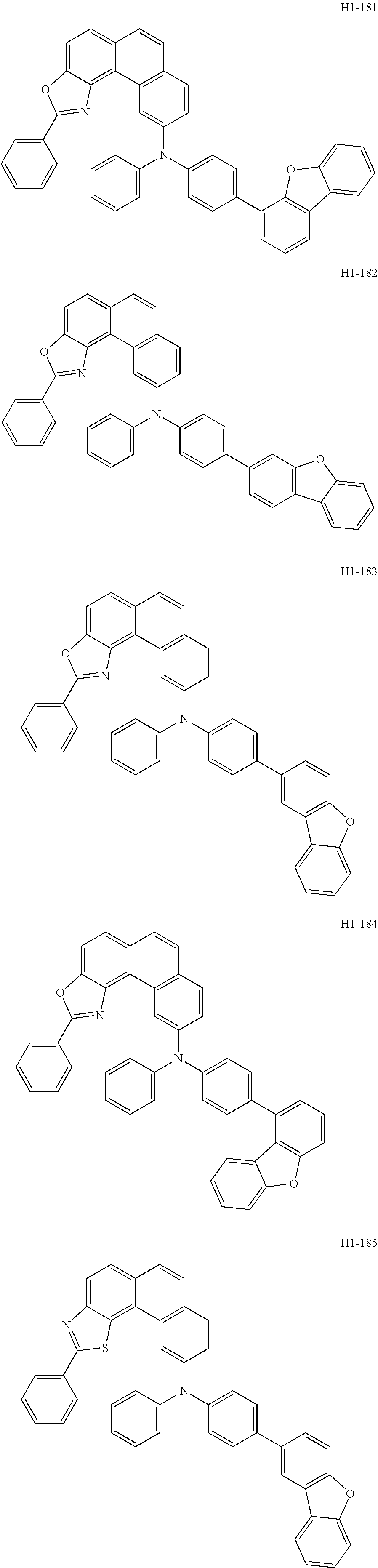 [SMILES: c1ccc(-c2nc3c(ccc4ccc5ccc(N(c6ccccc6)c6ccc(-c7cccc8c7oc7ccccc78)cc6)cc5c43)o2)cc1 ; c1ccc(-c2nc3c(ccc4ccc5ccc(N(c6ccccc6)c6ccc(-c7ccc8c(c7)oc7ccccc78)cc6)cc5c43)o2)cc1 ; c1ccc(-c2nc3c(ccc4ccc5ccc(N(c6ccccc6)c6ccc(-c7ccc8oc9ccccc9c8c7)cc6)cc5c43)o2)cc1 ; c1ccc(-c2nc3c(ccc4ccc5ccc(N(c6ccccc6)c6ccc(-c7cccc8oc9ccccc9c78)cc6)cc5c43)o2)cc1 ; c1ccc(-c2nc3ccc4ccc5ccc(N(c6ccccc6)c6ccc(-c7ccc8oc9ccccc9c8c7)cc6)cc5c4c3s2)cc1] 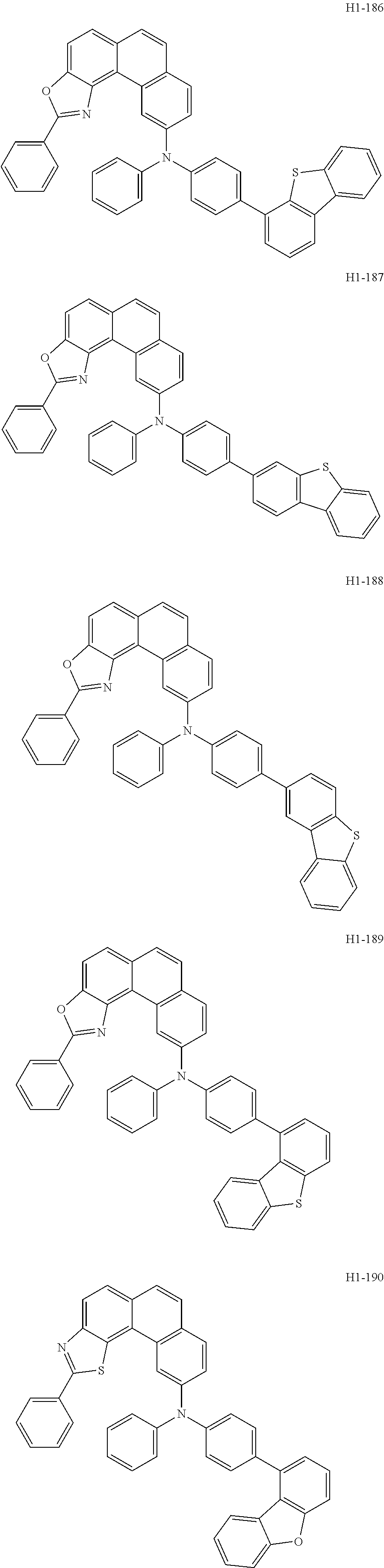 [SMILES: c1ccc(-c2nc3c(ccc4ccc5ccc(N(c6ccccc6)c6ccc(-c7cccc8c7sc7ccccc78)cc6)cc5c43)o2)cc1 ; c1ccc(-c2nc3c(ccc4ccc5ccc(N(c6ccccc6)c6ccc(-c7ccc8c(c7)sc7ccccc78)cc6)cc5c43)o2)cc1 ; c1ccc(-c2nc3c(ccc4ccc5ccc(N(c6ccccc6)c6ccc(-c7ccc8sc9ccccc9c8c7)cc6)cc5c43)o2)cc1 ; c1ccc(-c2nc3c(ccc4ccc5ccc(N(c6ccccc6)c6ccc(-c7cccc8sc9ccccc9c78)cc6)cc5c43)o2)cc1 ; c1ccc(-c2nc3ccc4ccc5ccc(N(c6ccccc6)c6ccc(-c7cccc8oc9ccccc9c78)cc6)cc5c4c3s2)cc1] 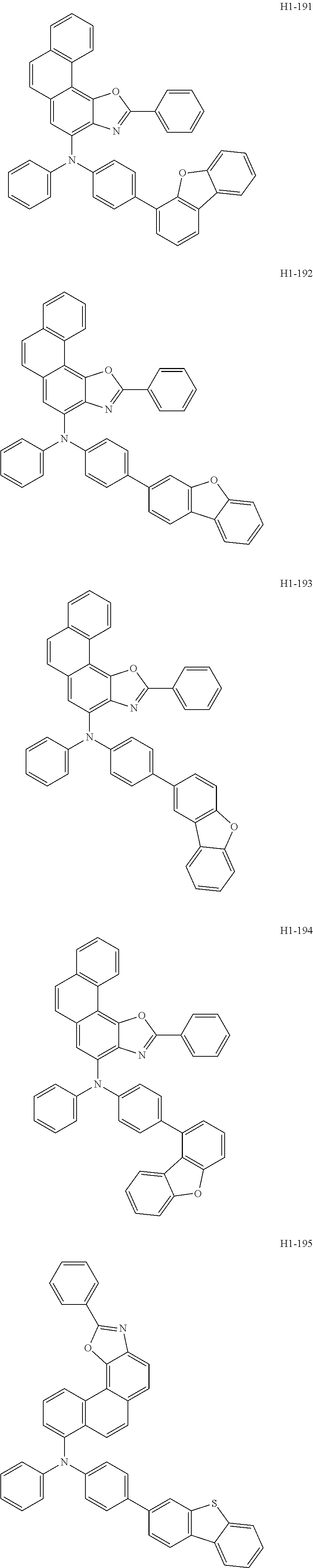 [SMILES: c1ccc(-c2nc3c(N(c4ccccc4)c4ccc(-c5cccc6c5oc5ccccc56)cc4)cc4ccc5ccccc5c4c3o2)cc1 ; c1ccc(-c2nc3c(N(c4ccccc4)c4ccc(-c5ccc6c(c5)oc5ccccc56)cc4)cc4ccc5ccccc5c4c3o2)cc1 ; c1ccc(-c2nc3c(N(c4ccccc4)c4ccc(-c5ccc6oc7ccccc7c6c5)cc4)cc4ccc5ccccc5c4c3o2)cc1 ; c1ccc(-c2nc3c(N(c4ccccc4)c4ccc(-c5cccc6oc7ccccc7c56)cc4)cc4ccc5ccccc5c4c3o2)cc1 ; c1ccc(-c2nc3ccc4ccc5c(N(c6ccccc6)c6ccc(-c7ccc8c(c7)sc7ccccc78)cc6)cccc5c4c3o2)cc1] 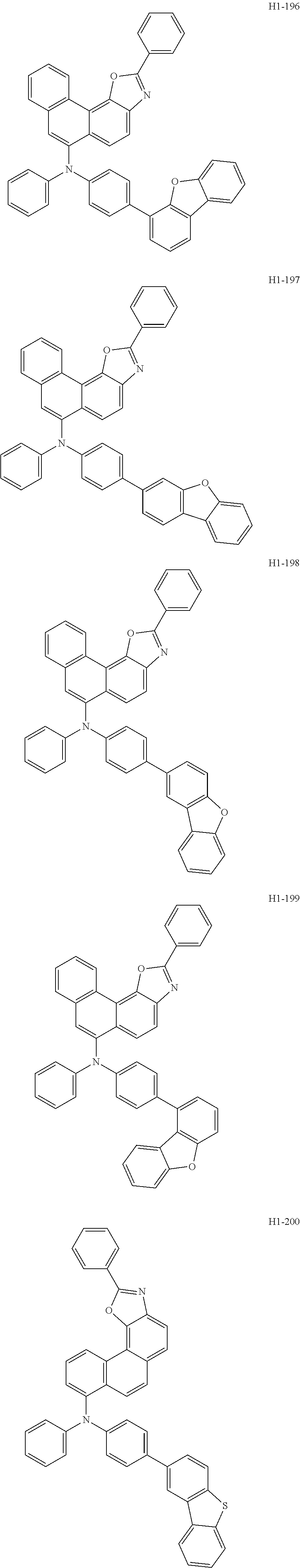 [SMILES: c1ccc(-c2nc3ccc4c(N(c5ccccc5)c5ccc(-c6cccc7c6oc6ccccc67)cc5)cc5ccccc5c4c3o2)cc1 ; c1ccc(-c2nc3ccc4c(N(c5ccccc5)c5ccc(-c6ccc7c(c6)oc6ccccc67)cc5)cc5ccccc5c4c3o2)cc1 ; c1ccc(-c2nc3ccc4c(N(c5ccccc5)c5ccc(-c6ccc7oc8ccccc8c7c6)cc5)cc5ccccc5c4c3o2)cc1 ; c1ccc(-c2nc3ccc4c(N(c5ccccc5)c5ccc(-c6cccc7oc8ccccc8c67)cc5)cc5ccccc5c4c3o2)cc1 ; c1ccc(-c2nc3ccc4ccc5c(N(c6ccccc6)c6ccc(-c7ccc8sc9ccccc9c8c7)cc6)cccc5c4c3o2)cc1] 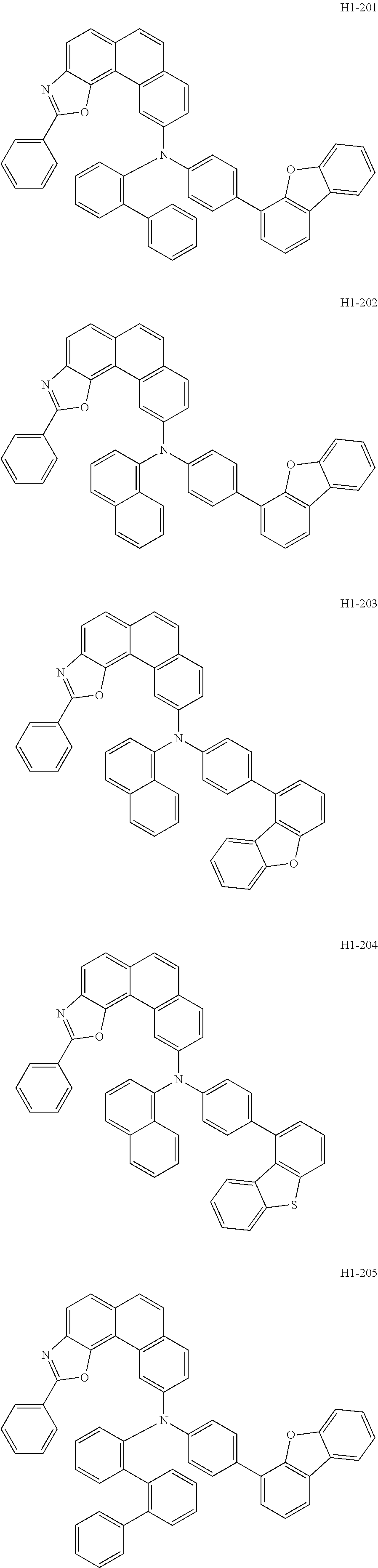 [SMILES: c1ccc(-c2nc3ccc4ccc5ccc(N(c6ccc(-c7cccc8c7oc7ccccc78)cc6)c6ccccc6-c6ccccc6)cc5c4c3o2)cc1 ; c1ccc(-c2nc3ccc4ccc5ccc(N(c6ccc(-c7cccc8c7oc7ccccc78)cc6)c6cccc7ccccc67)cc5c4c3o2)cc1 ; c1ccc(-c2nc3ccc4ccc5ccc(N(c6ccc(-c7cccc8oc9ccccc9c78)cc6)c6cccc7ccccc67)cc5c4c3o2)cc1 ; c1ccc(-c2nc3ccc4ccc5ccc(N(c6ccc(-c7cccc8sc9ccccc9c78)cc6)c6cccc7ccccc67)cc5c4c3o2)cc1 ; c1ccc(-c2nc3ccc4ccc5ccc(N(c6ccc(-c7cccc8c7oc7ccccc78)cc6)c6ccccc6-c6ccccc6-c6ccccc6)cc5c4c3o2)cc1] 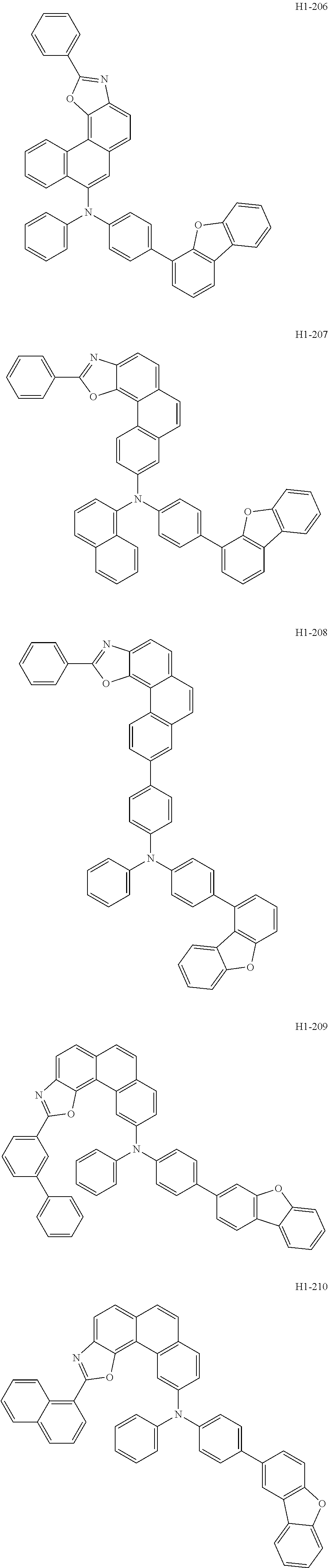 [SMILES: c1ccc(-c2nc3ccc4cc(N(c5ccccc5)c5ccc(-c6cccc7c6oc6ccccc67)cc5)c5ccccc5c4c3o2)cc1 ; c1ccc(-c2nc3ccc4ccc5cc(N(c6ccc(-c7cccc8c7oc7ccccc78)cc6)c6cccc7ccccc67)ccc5c4c3o2)cc1 ; c1ccc(-c2nc3ccc4ccc5cc(-c6ccc(N(c7ccccc7)c7ccc(-c8cccc9oc%10ccccc%10c89)cc7)cc6)ccc5c4c3o2)cc1 ; c1ccc(-c2cccc(-c3nc4ccc5ccc6ccc(N(c7ccccc7)c7ccc(-c8ccc9c(c8)oc8ccccc89)cc7)cc6c5c4o3)c2)cc1 ; c1ccc(N(c2ccc(-c3ccc4oc5ccccc5c4c3)cc2)c2ccc3ccc4ccc5nc(-c6cccc7ccccc67)oc5c4c3c2)cc1] 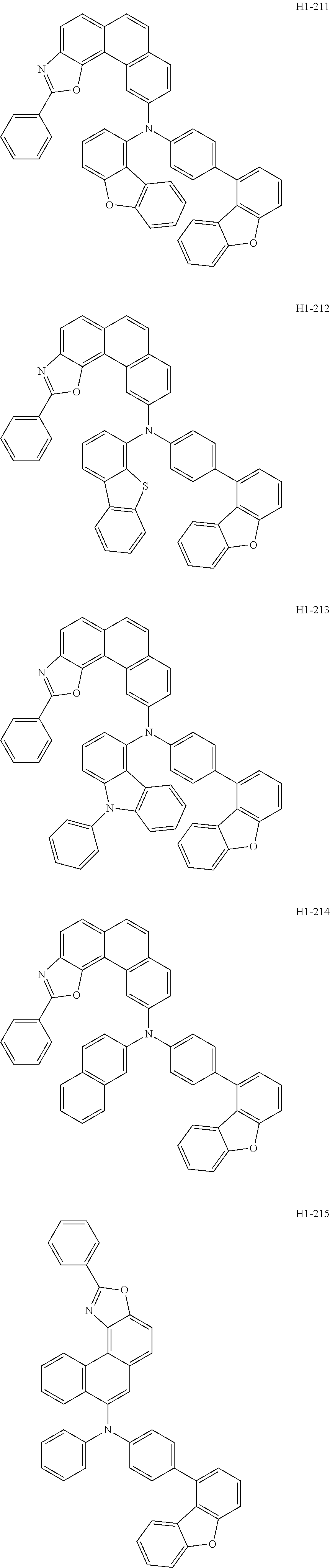 [SMILES: c1ccc(-c2nc3ccc4ccc5ccc(N(c6ccc(-c7cccc8oc9ccccc9c78)cc6)c6cccc7oc8ccccc8c67)cc5c4c3o2)cc1 ; c1ccc(-c2nc3ccc4ccc5ccc(N(c6ccc(-c7cccc8oc9ccccc9c78)cc6)c6cccc7c6sc6ccccc67)cc5c4c3o2)cc1 ; c1ccc(-c2nc3ccc4ccc5ccc(N(c6ccc(-c7cccc8oc9ccccc9c78)cc6)c6cccc7c6c6ccccc6n7-c6ccccc6)cc5c4c3o2)cc1 ; c1ccc(-c2nc3ccc4ccc5ccc(N(c6ccc(-c7cccc8oc9ccccc9c78)cc6)c6ccc7ccccc7c6)cc5c4c3o2)cc1 ; c1ccc(-c2nc3c(ccc4cc(N(c5ccccc5)c5ccc(-c6cccc7oc8ccccc8c67)cc5)c5ccccc5c43)o2)cc1] 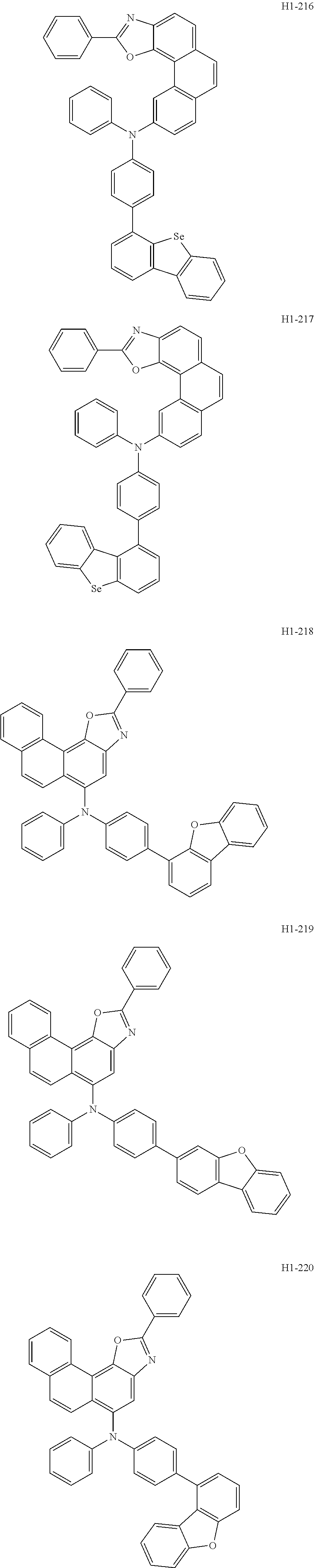 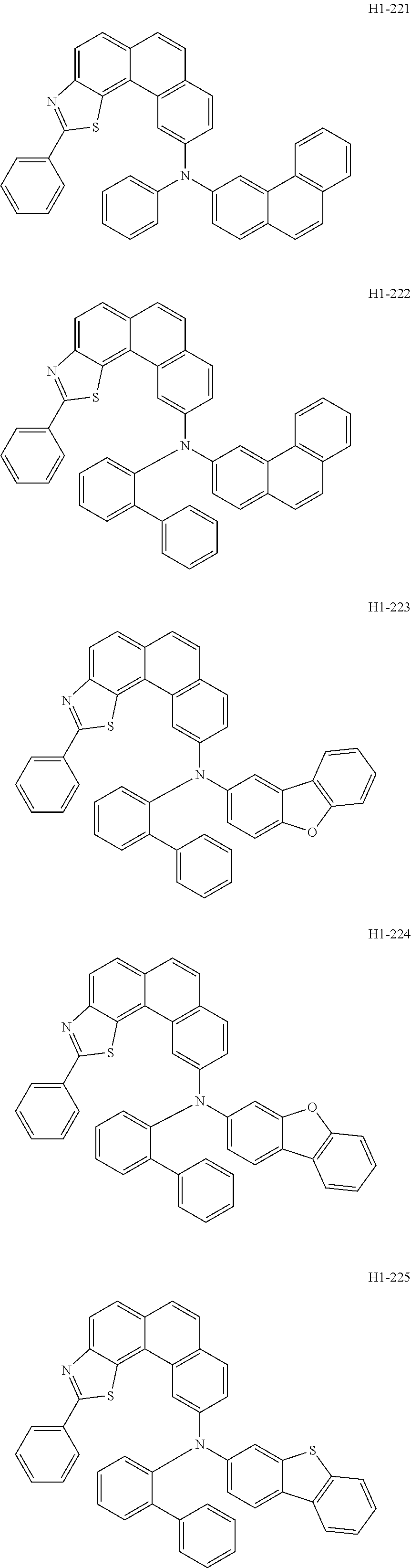 [SMILES: c1ccc(-c2nc3ccc4ccc5ccc(N(c6ccccc6)c6ccc7ccc8ccccc8c7c6)cc5c4c3s2)cc1 ; c1ccc(-c2nc3ccc4ccc5ccc(N(c6ccc7ccc8ccccc8c7c6)c6ccccc6-c6ccccc6)cc5c4c3s2)cc1 ; c1ccc(-c2nc3ccc4ccc5ccc(N(c6ccc7oc8ccccc8c7c6)c6ccccc6-c6ccccc6)cc5c4c3s2)cc1 ; c1ccc(-c2nc3ccc4ccc5ccc(N(c6ccc7c(c6)oc6ccccc67)c6ccccc6-c6ccccc6)cc5c4c3s2)cc1 ; c1ccc(-c2nc3ccc4ccc5ccc(N(c6ccc7c(c6)sc6ccccc67)c6ccccc6-c6ccccc6)cc5c4c3s2)cc1] 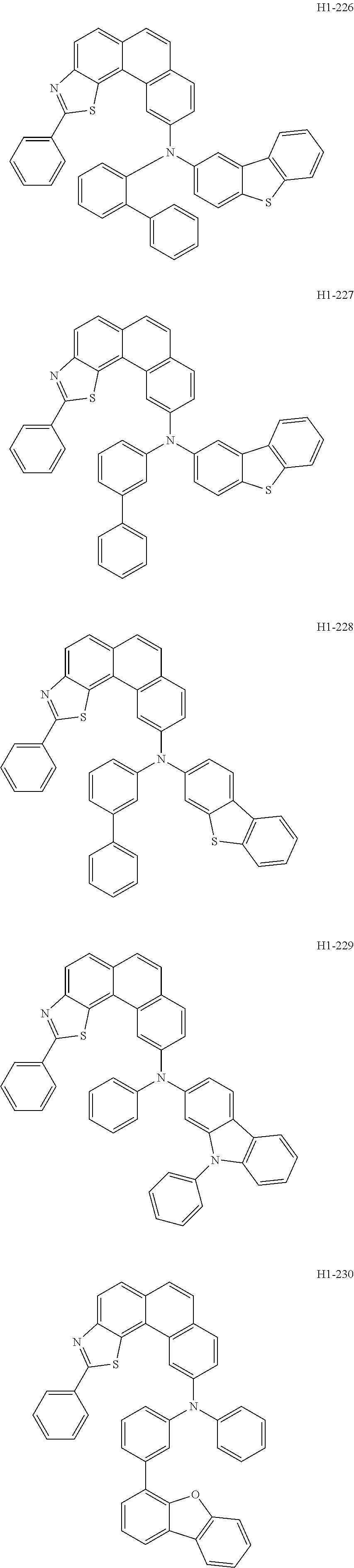 [SMILES: c1ccc(-c2nc3ccc4ccc5ccc(N(c6ccc7sc8ccccc8c7c6)c6ccccc6-c6ccccc6)cc5c4c3s2)cc1 ; c1ccc(-c2cccc(N(c3ccc4sc5ccccc5c4c3)c3ccc4ccc5ccc6nc(-c7ccccc7)sc6c5c4c3)c2)cc1 ; c1ccc(-c2cccc(N(c3ccc4c(c3)sc3ccccc34)c3ccc4ccc5ccc6nc(-c7ccccc7)sc6c5c4c3)c2)cc1 ; c1ccc(-c2nc3ccc4ccc5ccc(N(c6ccccc6)c6ccc7c8ccccc8n(-c8ccccc8)c7c6)cc5c4c3s2)cc1 ; c1ccc(-c2nc3ccc4ccc5ccc(N(c6ccccc6)c6cccc(-c7cccc8c7oc7ccccc78)c6)cc5c4c3s2)cc1] 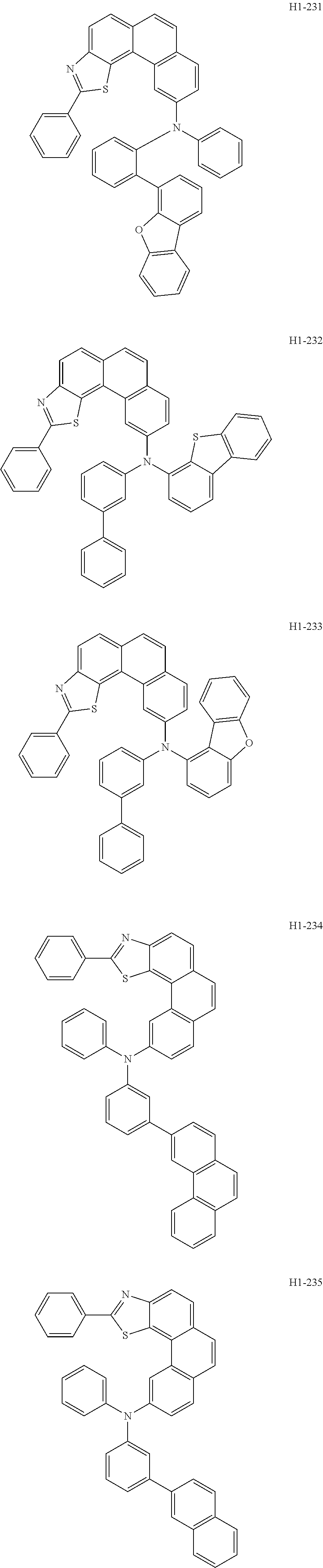 [SMILES: c1ccc(-c2nc3ccc4ccc5ccc(N(c6ccccc6)c6ccccc6-c6cccc7c6oc6ccccc67)cc5c4c3s2)cc1 ; c1ccc(-c2cccc(N(c3ccc4ccc5ccc6nc(-c7ccccc7)sc6c5c4c3)c3cccc4c3sc3ccccc34)c2)cc1 ; c1ccc(-c2cccc(N(c3ccc4ccc5ccc6nc(-c7ccccc7)sc6c5c4c3)c3cccc4oc5ccccc5c34)c2)cc1 ; c1ccc(-c2nc3ccc4ccc5ccc(N(c6ccccc6)c6cccc(-c7ccc8ccc9ccccc9c8c7)c6)cc5c4c3s2)cc1 ; c1ccc(-c2nc3ccc4ccc5ccc(N(c6ccccc6)c6cccc(-c7ccc8ccccc8c7)c6)cc5c4c3s2)cc1] 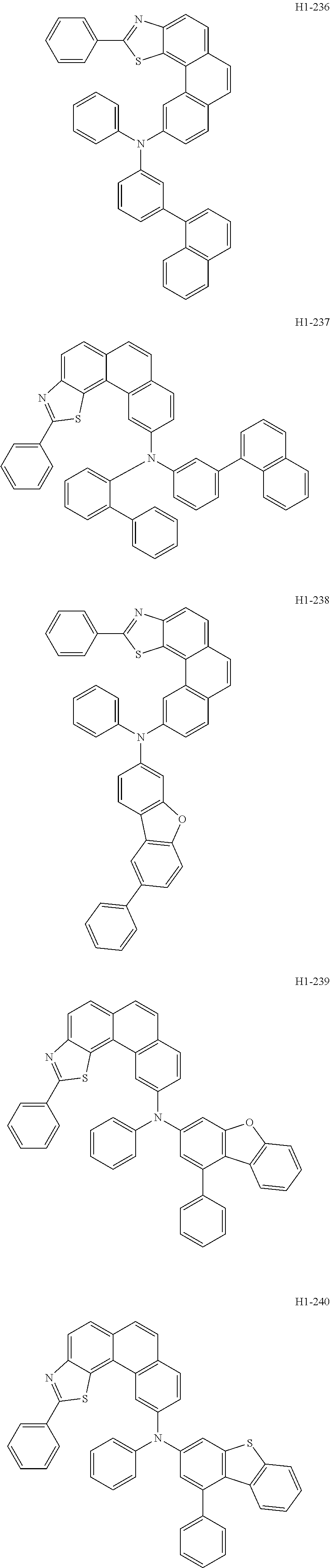 [SMILES: c1ccc(-c2nc3ccc4ccc5ccc(N(c6ccccc6)c6cccc(-c7cccc8ccccc78)c6)cc5c4c3s2)cc1 ; c1ccc(-c2nc3ccc4ccc5ccc(N(c6cccc(-c7cccc8ccccc78)c6)c6ccccc6-c6ccccc6)cc5c4c3s2)cc1 ; c1ccc(-c2ccc3oc4cc(N(c5ccccc5)c5ccc6ccc7ccc8nc(-c9ccccc9)sc8c7c6c5)ccc4c3c2)cc1 ; c1ccc(-c2nc3ccc4ccc5ccc(N(c6ccccc6)c6cc(-c7ccccc7)c7c(c6)oc6ccccc67)cc5c4c3s2)cc1 ; c1ccc(-c2nc3ccc4ccc5ccc(N(c6ccccc6)c6cc(-c7ccccc7)c7c(c6)sc6ccccc67)cc5c4c3s2)cc1] 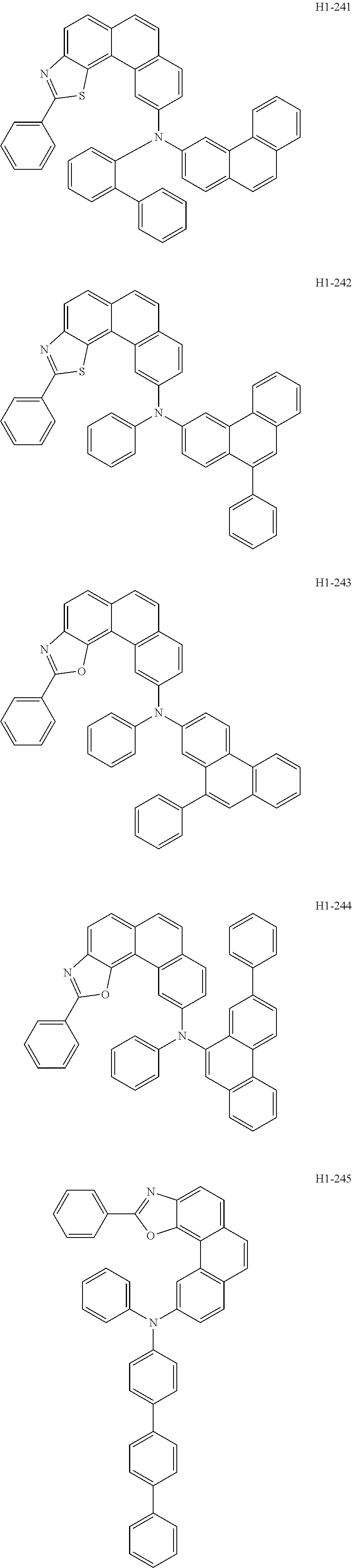 [SMILES: c1ccc(-c2nc3ccc4ccc5ccc(N(c6ccc7ccc8ccccc8c7c6)c6ccccc6-c6ccccc6)cc5c4c3s2)cc1 ; c1ccc(-c2nc3ccc4ccc5ccc(N(c6ccccc6)c6ccc7c(-c8ccccc8)cc8ccccc8c7c6)cc5c4c3s2)cc1 ; c1ccc(-c2nc3ccc4ccc5ccc(N(c6ccccc6)c6ccc7c(c6)c(-c6ccccc6)cc6ccccc67)cc5c4c3o2)cc1 ; c1ccc(-c2ccc3c(c2)c(N(c2ccccc2)c2ccc4ccc5ccc6nc(-c7ccccc7)oc6c5c4c2)cc2ccccc23)cc1 ; c1ccc(-c2ccc(-c3ccc(N(c4ccccc4)c4ccc5ccc6ccc7nc(-c8ccccc8)oc7c6c5c4)cc3)cc2)cc1] 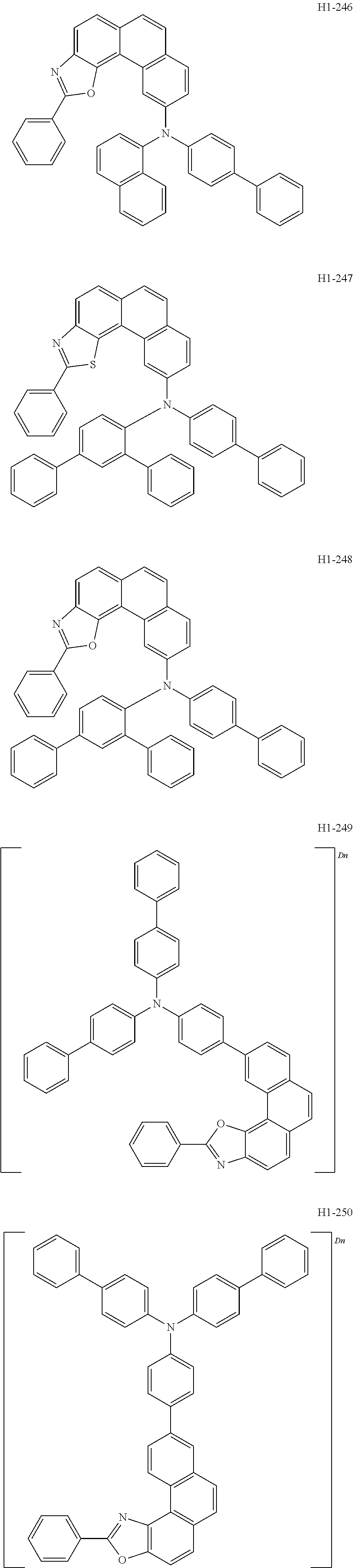 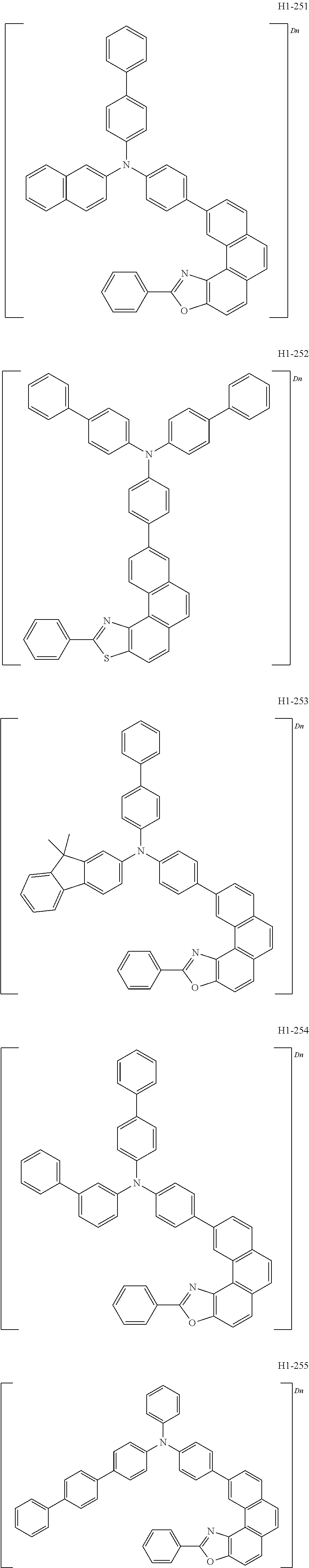 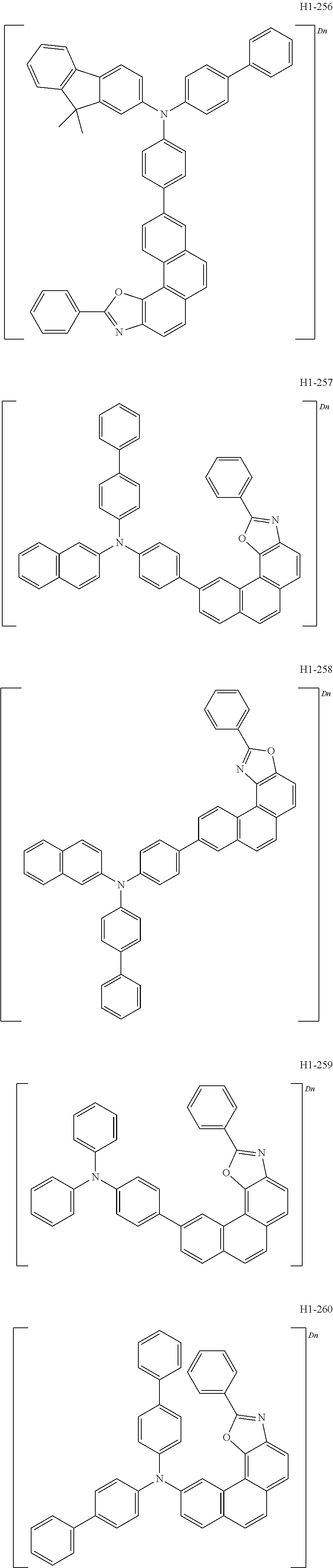 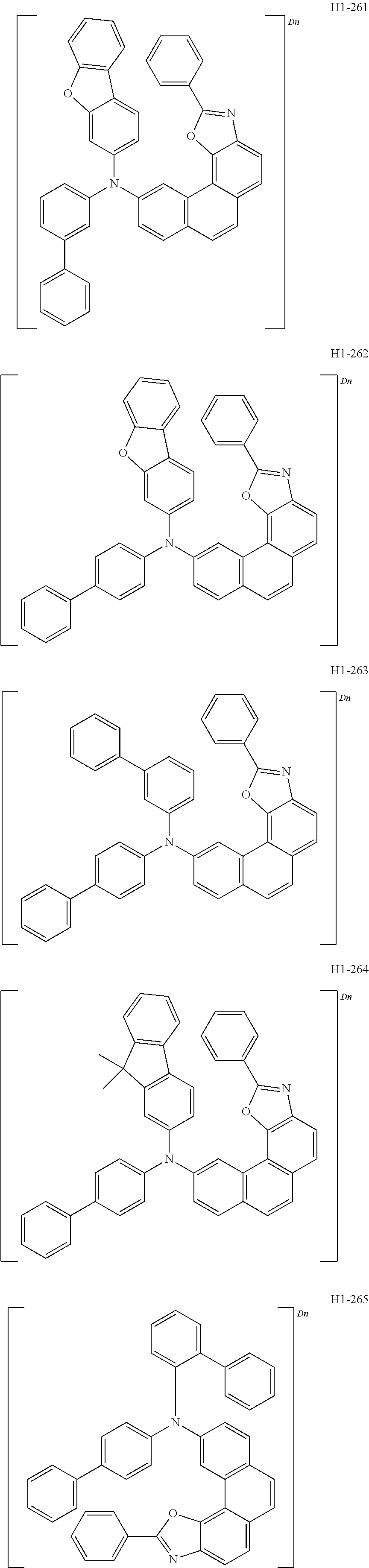 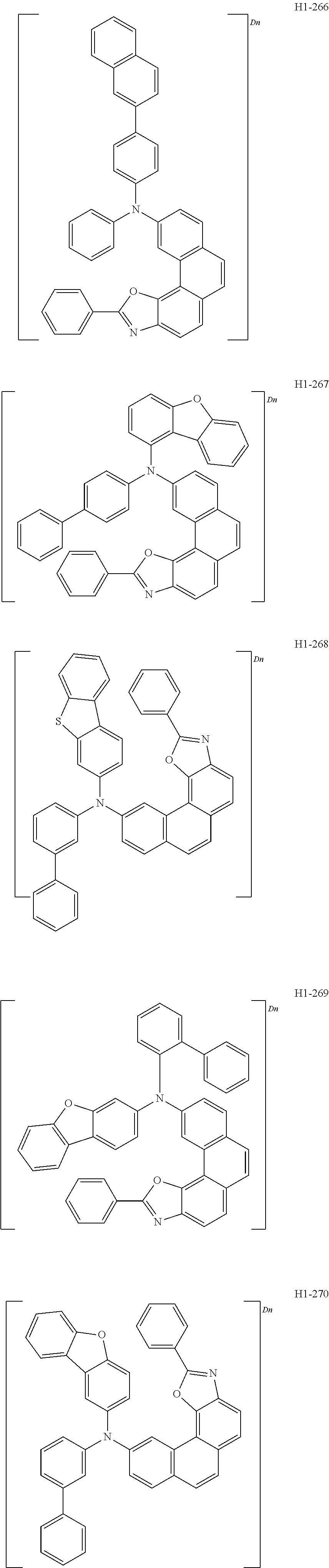 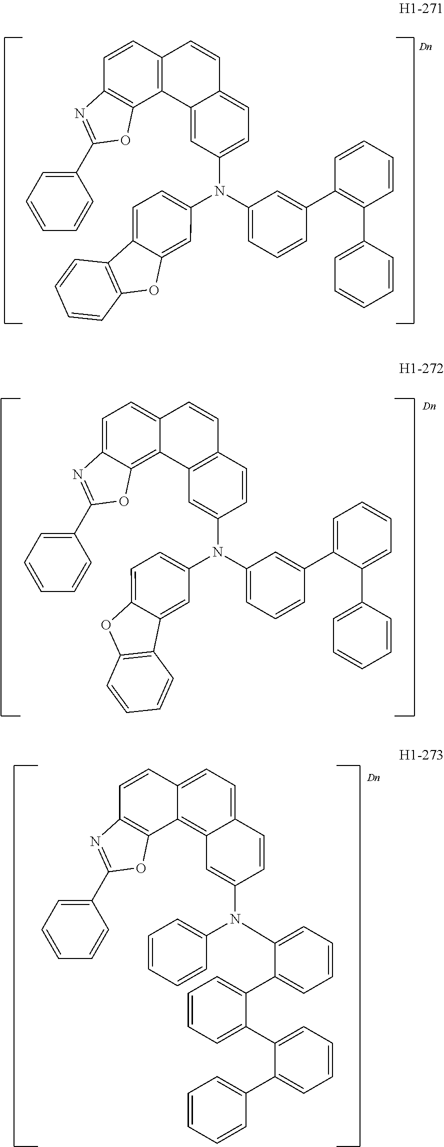 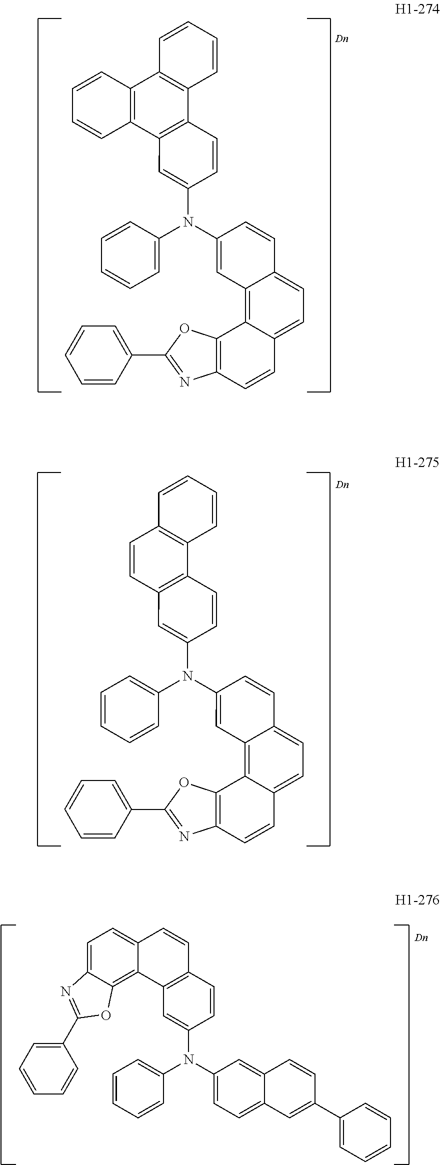 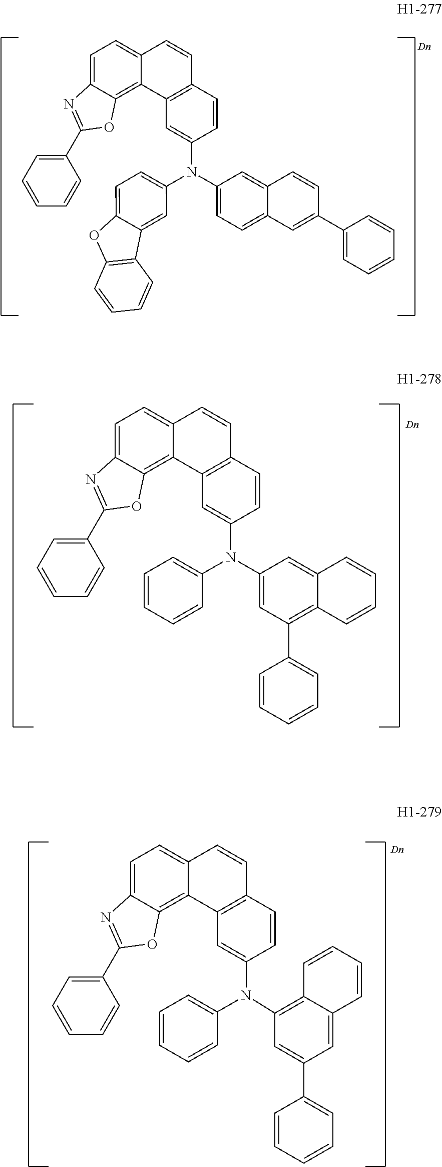 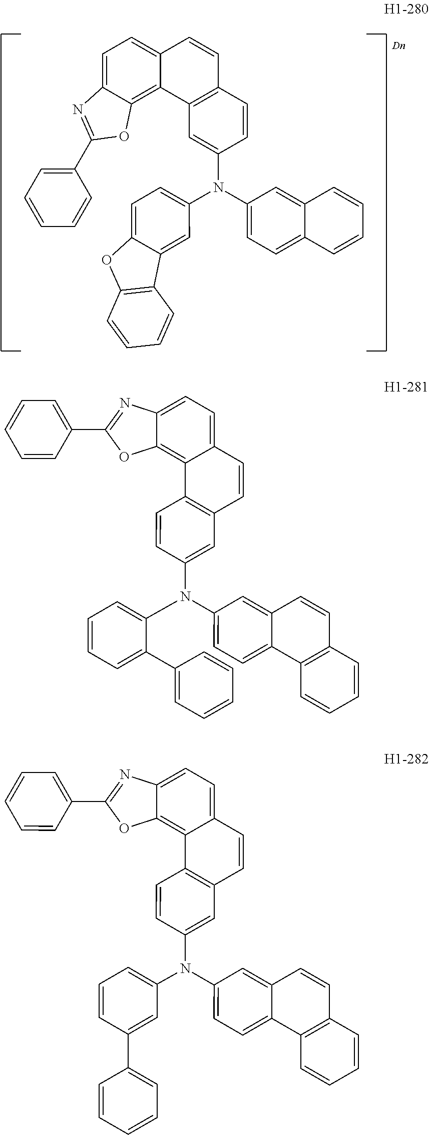 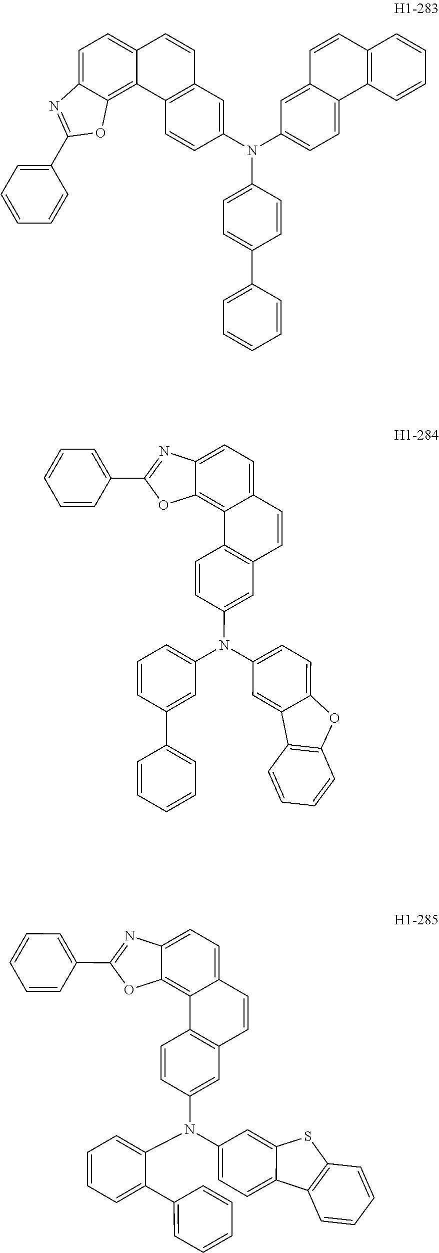 [SMILES: c1ccc(-c2ccc(N(c3ccc4c(ccc5ccccc54)c3)c3ccc4c(ccc5ccc6nc(-c7ccccc7)oc6c54)c3)cc2)cc1 ; c1ccc(-c2cccc(N(c3ccc4c(ccc5ccc6nc(-c7ccccc7)oc6c54)c3)c3ccc4oc5ccccc5c4c3)c2)cc1 ; c1ccc(-c2nc3ccc4ccc5cc(N(c6ccc7c(c6)sc6ccccc67)c6ccccc6-c6ccccc6)ccc5c4c3o2)cc1] 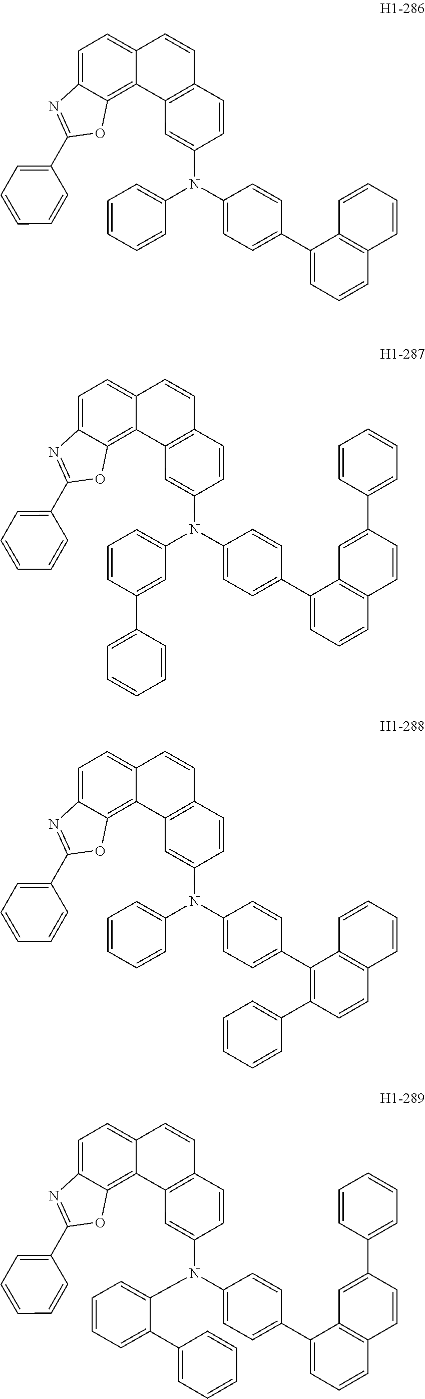 [SMILES: c1ccc(-c2nc3ccc4ccc5ccc(N(c6ccccc6)c6ccc(-c7cccc8ccccc78)cc6)cc5c4c3o2)cc1 ; c1ccc(-c2cccc(N(c3ccc(-c4cccc5ccc(-c6ccccc6)cc45)cc3)c3ccc4ccc5ccc6nc(-c7ccccc7)oc6c5c4c3)c2)cc1 ; c1ccc(-c2nc3ccc4ccc5ccc(N(c6ccccc6)c6ccc(-c7c(-c8ccccc8)ccc8ccccc78)cc6)cc5c4c3o2)cc1 ; c1ccc(-c2ccc3cccc(-c4ccc(N(c5ccc6ccc7ccc8nc(-c9ccccc9)oc8c7c6c5)c5ccccc5-c5ccccc5)cc4)c3c2)cc1] 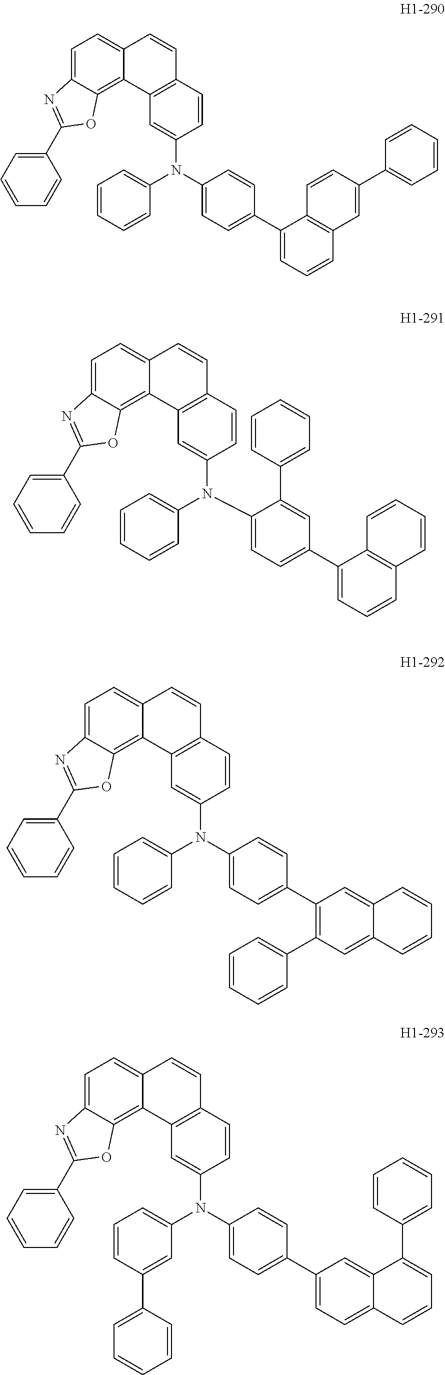 [SMILES: c1ccc(-c2ccc3c(-c4ccc(N(c5ccccc5)c5ccc6ccc7ccc8nc(-c9ccccc9)oc8c7c6c5)cc4)cccc3c2)cc1 ; c1ccc(-c2nc3ccc4ccc5ccc(N(c6ccccc6)c6ccc(-c7cccc8ccccc78)cc6-c6ccccc6)cc5c4c3o2)cc1 ; c1ccc(-c2nc3ccc4ccc5ccc(N(c6ccccc6)c6ccc(-c7cc8ccccc8cc7-c7ccccc7)cc6)cc5c4c3o2)cc1 ; c1ccc(-c2cccc(N(c3ccc(-c4ccc5cccc(-c6ccccc6)c5c4)cc3)c3ccc4ccc5ccc6nc(-c7ccccc7)oc6c5c4c3)c2)cc1] 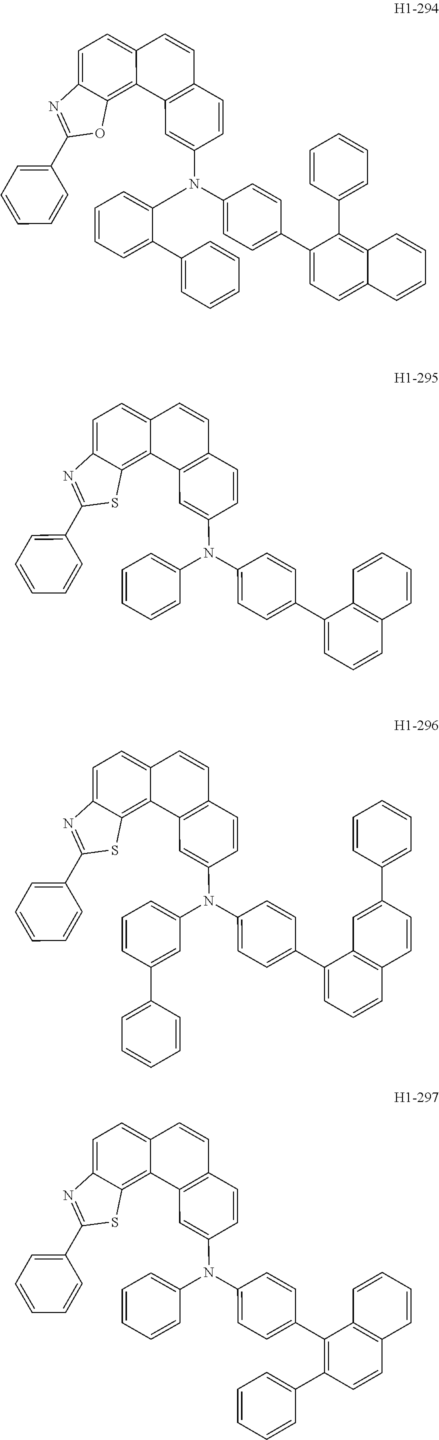 [SMILES: c1ccc(-c2nc3ccc4ccc5ccc(N(c6ccc(-c7ccc8ccccc8c7-c7ccccc7)cc6)c6ccccc6-c6ccccc6)cc5c4c3o2)cc1 ; c1ccc(-c2nc3ccc4ccc5ccc(N(c6ccccc6)c6ccc(-c7cccc8ccccc78)cc6)cc5c4c3s2)cc1 ; c1ccc(-c2cccc(N(c3ccc(-c4cccc5ccc(-c6ccccc6)cc45)cc3)c3ccc4ccc5ccc6nc(-c7ccccc7)sc6c5c4c3)c2)cc1 ; c1ccc(-c2nc3ccc4ccc5ccc(N(c6ccccc6)c6ccc(-c7c(-c8ccccc8)ccc8ccccc78)cc6)cc5c4c3s2)cc1] 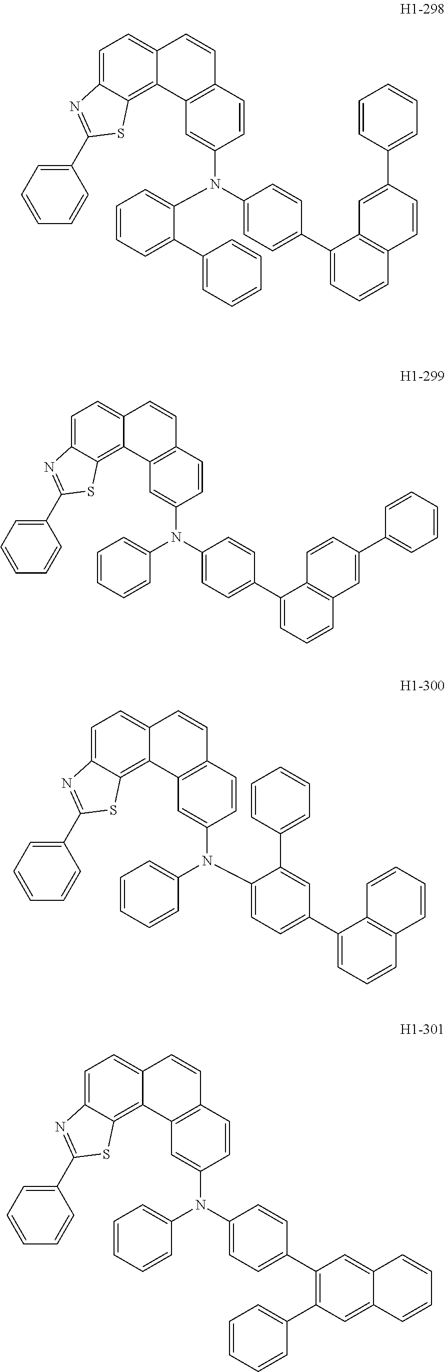 [SMILES: c1ccc(-c2ccc3cccc(-c4ccc(N(c5ccc6ccc7ccc8nc(-c9ccccc9)sc8c7c6c5)c5ccccc5-c5ccccc5)cc4)c3c2)cc1 ; c1ccc(-c2ccc3c(-c4ccc(N(c5ccccc5)c5ccc6ccc7ccc8nc(-c9ccccc9)sc8c7c6c5)cc4)cccc3c2)cc1 ; c1ccc(-c2nc3ccc4ccc5ccc(N(c6ccccc6)c6ccc(-c7cccc8ccccc78)cc6-c6ccccc6)cc5c4c3s2)cc1 ; c1ccc(-c2nc3ccc4ccc5ccc(N(c6ccccc6)c6ccc(-c7cc8ccccc8cc7-c7ccccc7)cc6)cc5c4c3s2)cc1] 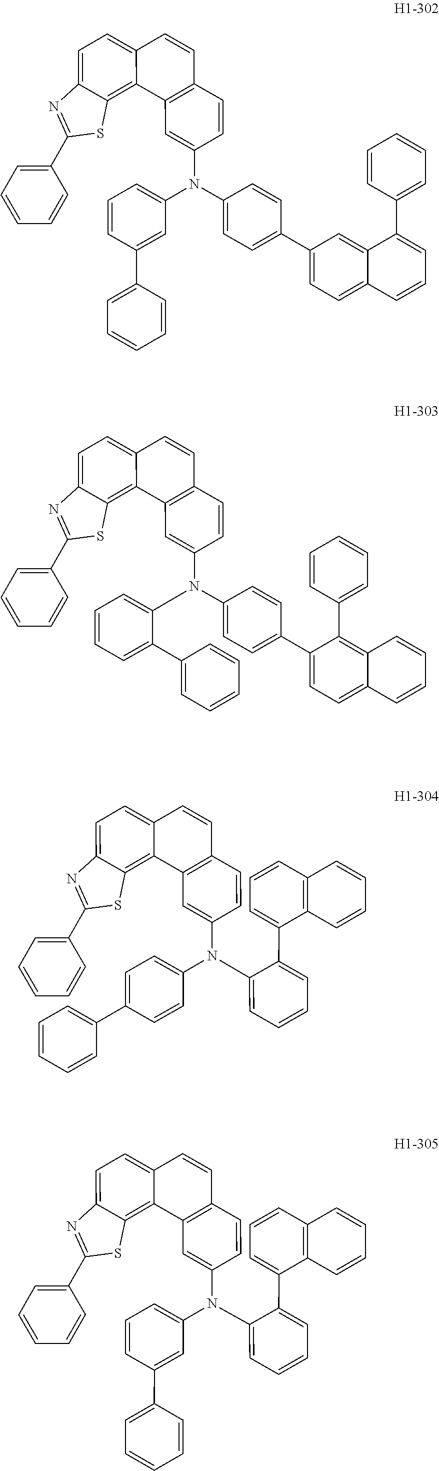 [SMILES: c1ccc(-c2cccc(N(c3ccc(-c4ccc5cccc(-c6ccccc6)c5c4)cc3)c3ccc4ccc5ccc6nc(-c7ccccc7)sc6c5c4c3)c2)cc1 ; c1ccc(-c2nc3ccc4ccc5ccc(N(c6ccc(-c7ccc8ccccc8c7-c7ccccc7)cc6)c6ccccc6-c6ccccc6)cc5c4c3s2)cc1 ; c1ccc(-c2ccc(N(c3ccc4ccc5ccc6nc(-c7ccccc7)sc6c5c4c3)c3ccccc3-c3cccc4ccccc34)cc2)cc1 ; c1ccc(-c2cccc(N(c3ccc4ccc5ccc6nc(-c7ccccc7)sc6c5c4c3)c3ccccc3-c3cccc4ccccc34)c2)cc1] 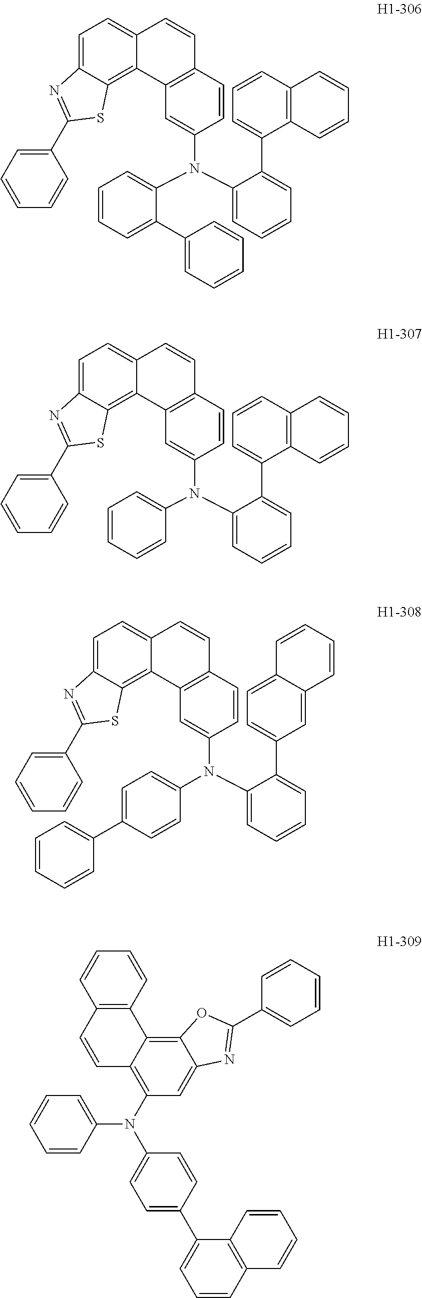 [SMILES: c1ccc(-c2nc3ccc4ccc5ccc(N(c6ccccc6-c6ccccc6)c6ccccc6-c6cccc7ccccc67)cc5c4c3s2)cc1 ; c1ccc(-c2nc3ccc4ccc5ccc(N(c6ccccc6)c6ccccc6-c6cccc7ccccc67)cc5c4c3s2)cc1 ; c1ccc(-c2ccc(N(c3ccc4ccc5ccc6nc(-c7ccccc7)sc6c5c4c3)c3ccccc3-c3ccc4ccccc4c3)cc2)cc1 ; c1ccc(-c2nc3cc(N(c4ccccc4)c4ccc(-c5cccc6ccccc56)cc4)c4ccc5ccccc5c4c3o2)cc1] 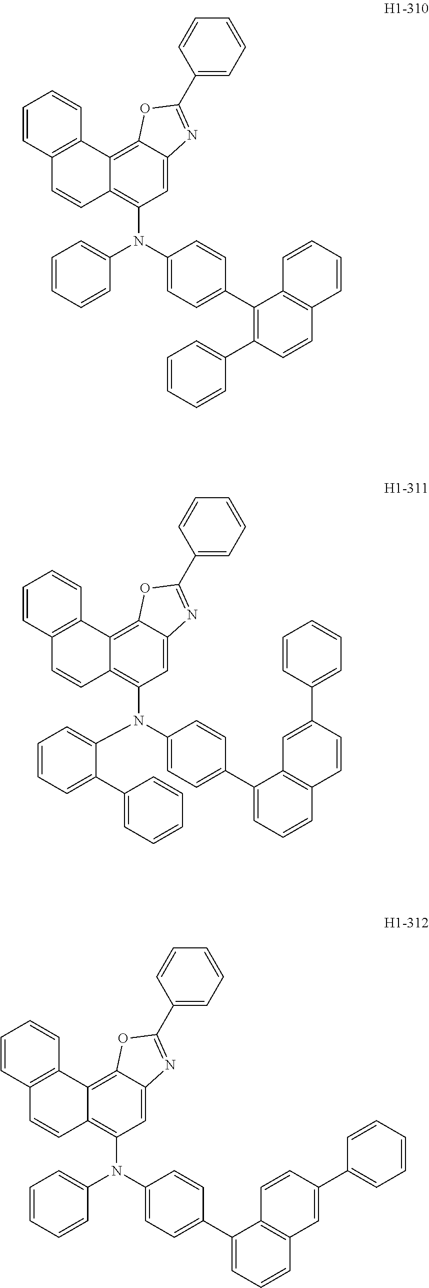 [SMILES: c1ccc(-c2nc3cc(N(c4ccccc4)c4ccc(-c5c(-c6ccccc6)ccc6ccccc56)cc4)c4ccc5ccccc5c4c3o2)cc1 ; c1ccc(-c2ccc3cccc(-c4ccc(N(c5ccccc5-c5ccccc5)c5cc6nc(-c7ccccc7)oc6c6c5ccc5ccccc56)cc4)c3c2)cc1 ; c1ccc(-c2ccc3c(-c4ccc(N(c5ccccc5)c5cc6nc(-c7ccccc7)oc6c6c5ccc5ccccc56)cc4)cccc3c2)cc1] 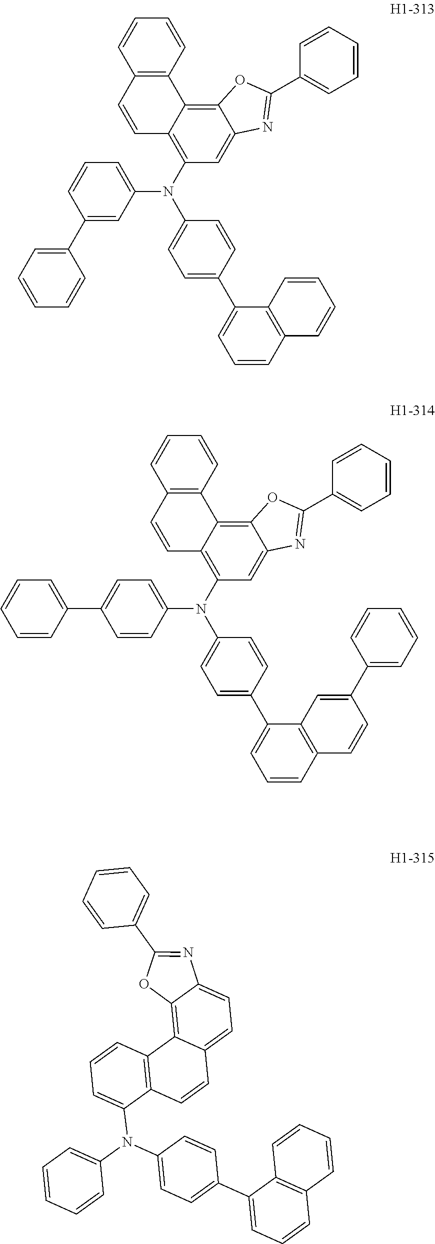 [SMILES: c1ccc(-c2cccc(N(c3ccc(-c4cccc5ccccc45)cc3)c3cc4nc(-c5ccccc5)oc4c4c3ccc3ccccc34)c2)cc1 ; c1ccc(-c2ccc(N(c3ccc(-c4cccc5ccc(-c6ccccc6)cc45)cc3)c3cc4nc(-c5ccccc5)oc4c4c3ccc3ccccc34)cc2)cc1 ; c1ccc(-c2nc3ccc4ccc5c(N(c6ccccc6)c6ccc(-c7cccc8ccccc78)cc6)cccc5c4c3o2)cc1] 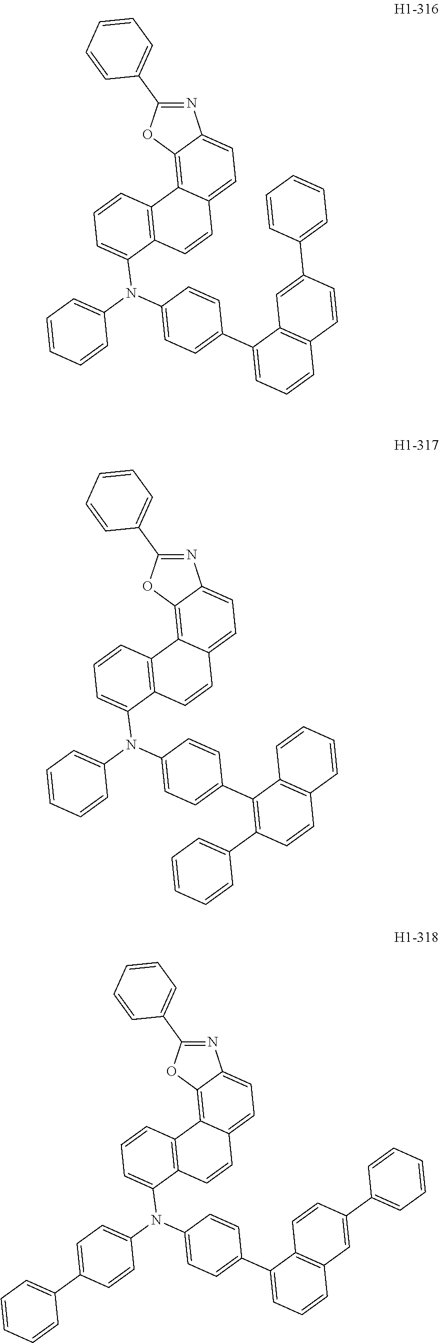 [SMILES: c1ccc(-c2ccc3cccc(-c4ccc(N(c5ccccc5)c5cccc6c5ccc5ccc7nc(-c8ccccc8)oc7c56)cc4)c3c2)cc1 ; c1ccc(-c2nc3ccc4ccc5c(N(c6ccccc6)c6ccc(-c7c(-c8ccccc8)ccc8ccccc78)cc6)cccc5c4c3o2)cc1 ; c1ccc(-c2ccc(N(c3ccc(-c4cccc5cc(-c6ccccc6)ccc45)cc3)c3cccc4c3ccc3ccc5nc(-c6ccccc6)oc5c34)cc2)cc1] 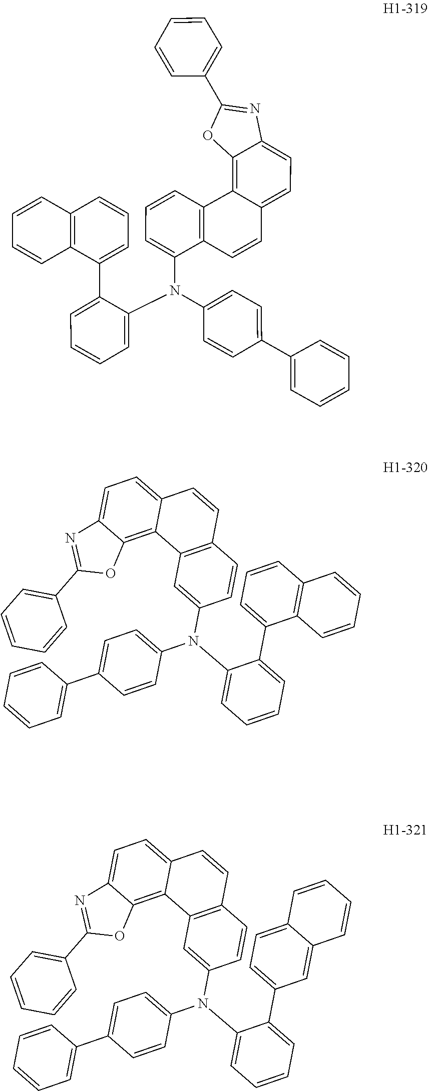 [SMILES: c1ccc(-c2ccc(N(c3ccccc3-c3cccc4ccccc34)c3cccc4c3ccc3ccc5nc(-c6ccccc6)oc5c34)cc2)cc1 ; c1ccc(-c2ccc(N(c3ccc4ccc5ccc6nc(-c7ccccc7)oc6c5c4c3)c3ccccc3-c3cccc4ccccc34)cc2)cc1 ; c1ccc(-c2ccc(N(c3ccc4ccc5ccc6nc(-c7ccccc7)oc6c5c4c3)c3ccccc3-c3ccc4ccccc4c3)cc2)cc1] 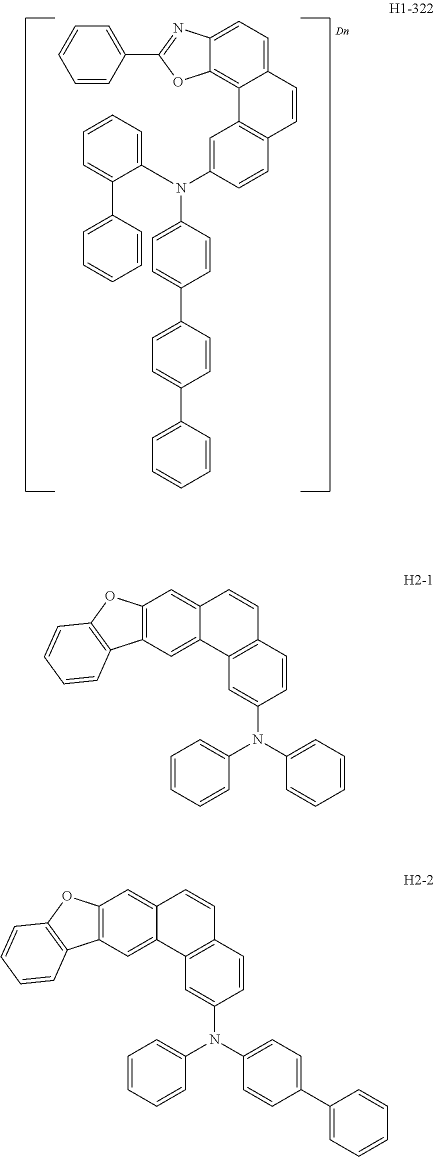 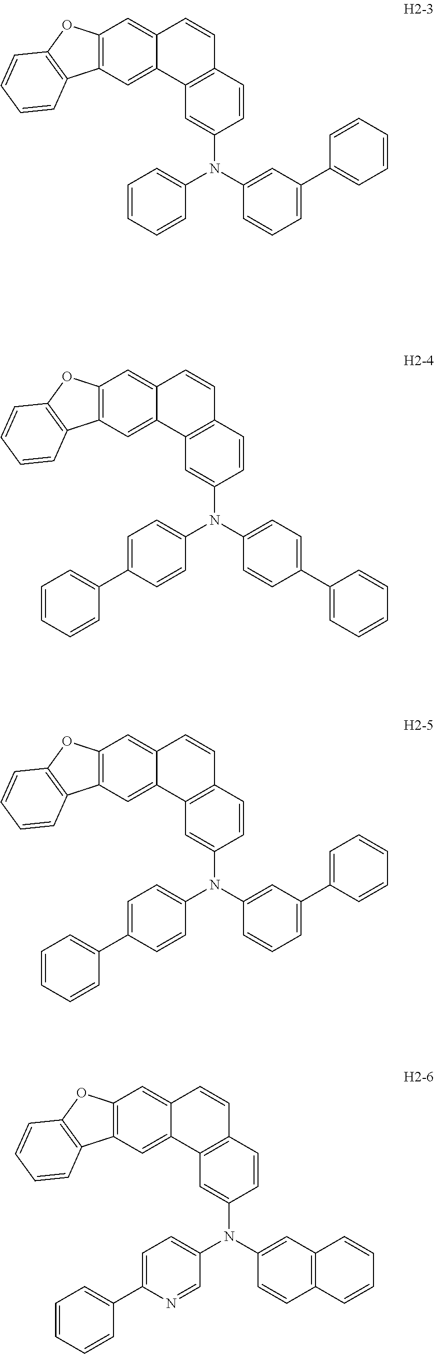 [SMILES: c1ccc(-c2cccc(N(c3ccccc3)c3ccc4ccc5cc6oc7ccccc7c6cc5c4c3)c2)cc1 ; c1ccc(-c2ccc(N(c3ccc(-c4ccccc4)cc3)c3ccc4ccc5cc6oc7ccccc7c6cc5c4c3)cc2)cc1 ; c1ccc(-c2ccc(N(c3cccc(-c4ccccc4)c3)c3ccc4ccc5cc6oc7ccccc7c6cc5c4c3)cc2)cc1 ; c1ccc(-c2ccc(N(c3ccc4ccccc4c3)c3ccc4ccc5cc6oc7ccccc7c6cc5c4c3)cn2)cc1] 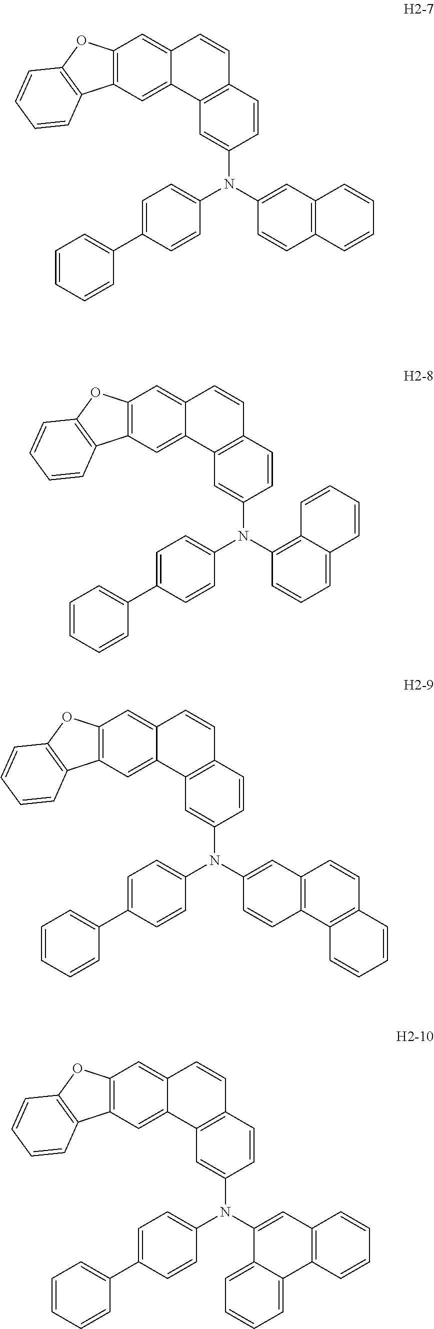 [SMILES: c1ccc(-c2ccc(N(c3ccc4ccccc4c3)c3ccc4ccc5cc6oc7ccccc7c6cc5c4c3)cc2)cc1 ; c1ccc(-c2ccc(N(c3ccc4ccc5cc6oc7ccccc7c6cc5c4c3)c3cccc4ccccc34)cc2)cc1 ; c1ccc(-c2ccc(N(c3ccc4c(ccc5ccccc54)c3)c3ccc4ccc5cc6oc7ccccc7c6cc5c4c3)cc2)cc1 ; c1ccc(-c2ccc(N(c3ccc4ccc5cc6oc7ccccc7c6cc5c4c3)c3cc4ccccc4c4ccccc34)cc2)cc1] 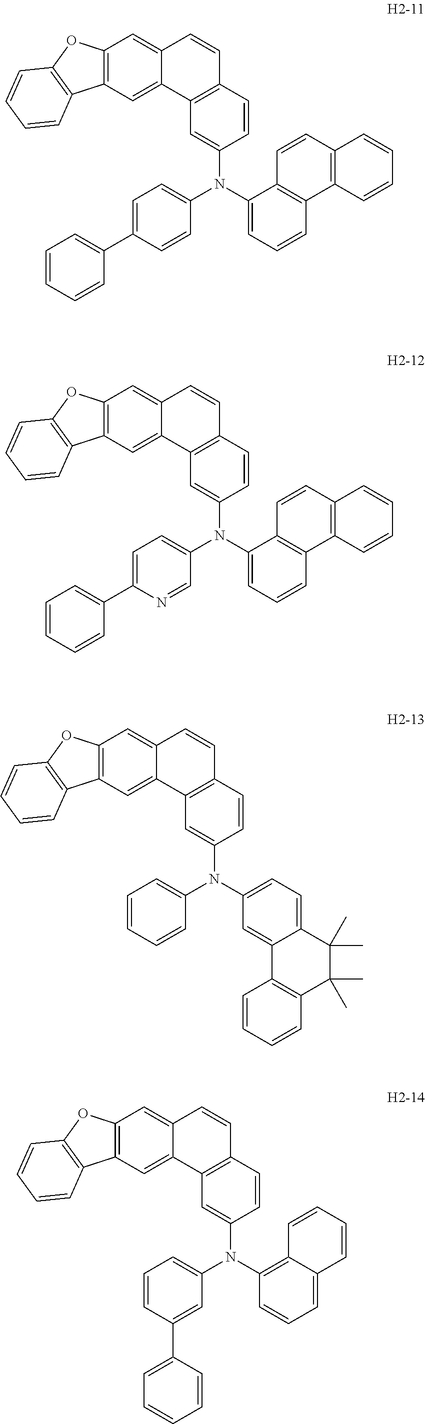 [SMILES: c1ccc(-c2ccc(N(c3ccc4ccc5cc6oc7ccccc7c6cc5c4c3)c3cccc4c3ccc3ccccc34)cc2)cc1 ; c1ccc(-c2ccc(N(c3ccc4ccc5cc6oc7ccccc7c6cc5c4c3)c3cccc4c3ccc3ccccc34)cn2)cc1 ; CC1(C)c2ccccc2-c2cc(N(c3ccccc3)c3ccc4ccc5cc6oc7ccccc7c6cc5c4c3)ccc2C1(C)C ; c1ccc(-c2cccc(N(c3ccc4ccc5cc6oc7ccccc7c6cc5c4c3)c3cccc4ccccc34)c2)cc1] 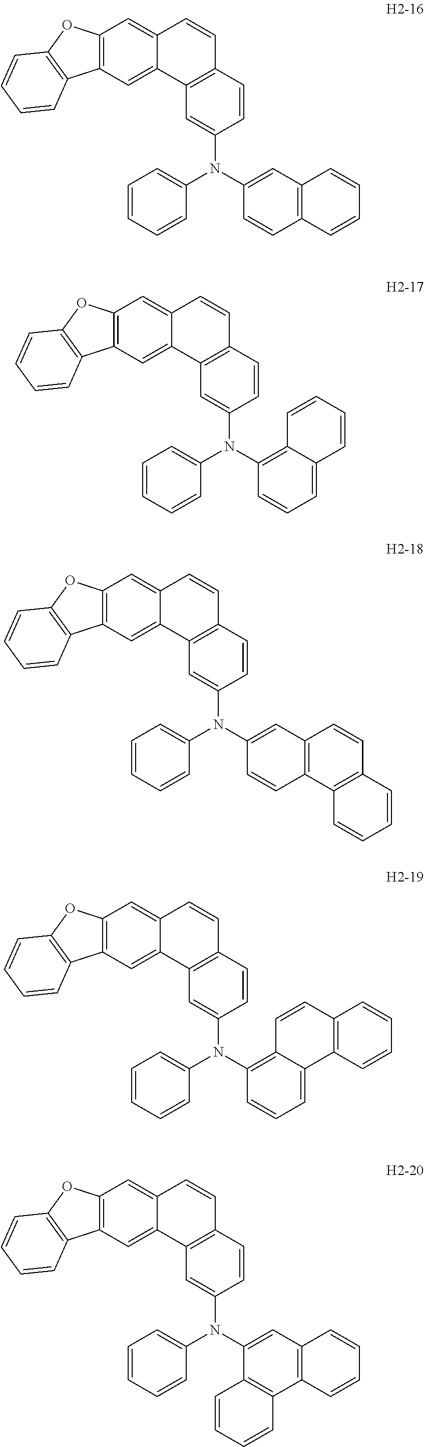 [SMILES: c1ccc(N(c2ccc3ccccc3c2)c2ccc3ccc4cc5oc6ccccc6c5cc4c3c2)cc1 ; c1ccc(N(c2ccc3ccc4cc5oc6ccccc6c5cc4c3c2)c2cccc3ccccc23)cc1 ; c1ccc(N(c2ccc3c(ccc4ccccc43)c2)c2ccc3ccc4cc5oc6ccccc6c5cc4c3c2)cc1 ; c1ccc(N(c2ccc3ccc4cc5oc6ccccc6c5cc4c3c2)c2cccc3c2ccc2ccccc23)cc1 ; c1ccc(N(c2ccc3ccc4cc5oc6ccccc6c5cc4c3c2)c2cc3ccccc3c3ccccc23)cc1] 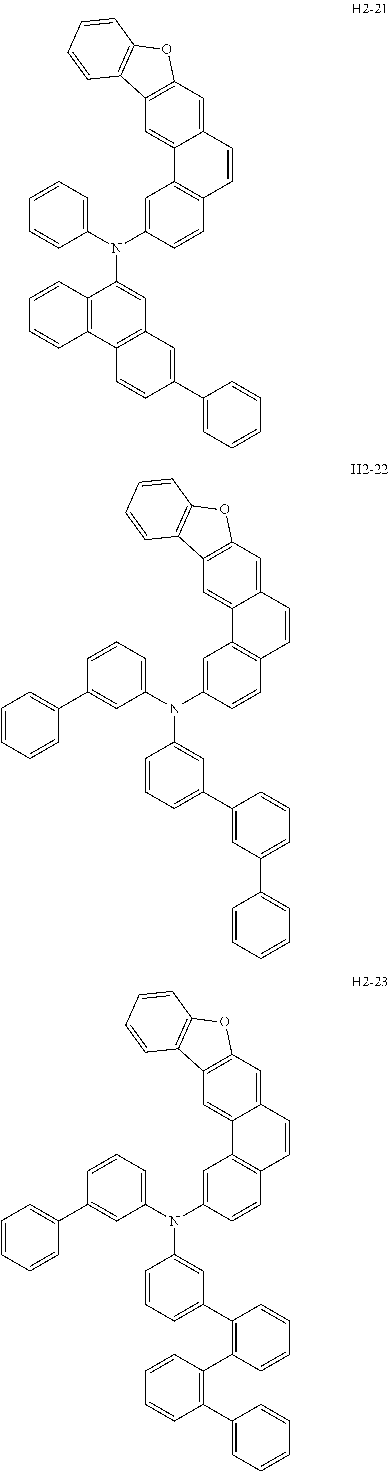 [SMILES: c1ccc(-c2ccc3c(c2)cc(N(c2ccccc2)c2ccc4ccc5cc6oc7ccccc7c6cc5c4c2)c2ccccc23)cc1 ; c1ccc(-c2cccc(-c3cccc(N(c4cccc(-c5ccccc5)c4)c4ccc5ccc6cc7oc8ccccc8c7cc6c5c4)c3)c2)cc1 ; c1ccc(-c2cccc(N(c3cccc(-c4ccccc4-c4ccccc4-c4ccccc4)c3)c3ccc4ccc5cc6oc7ccccc7c6cc5c4c3)c2)cc1] 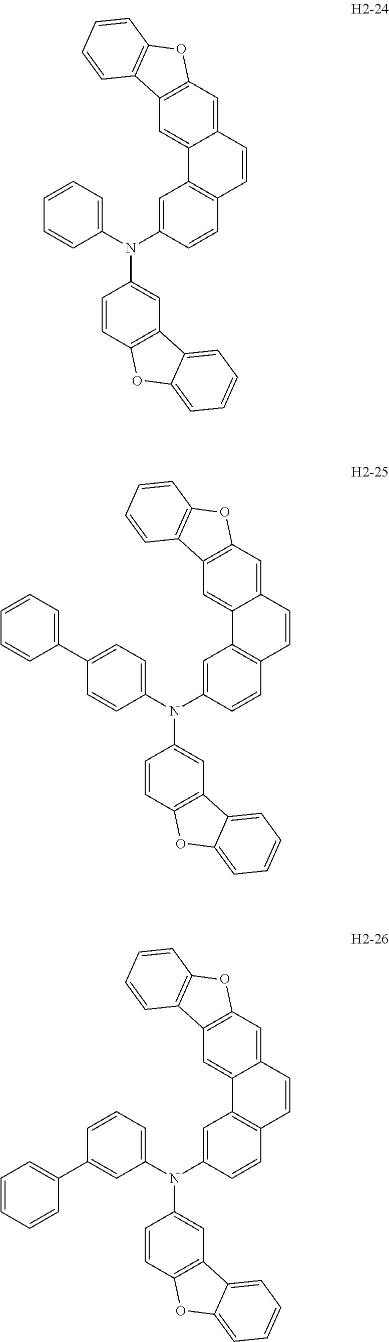 [SMILES: c1ccc(N(c2ccc3ccc4cc5oc6ccccc6c5cc4c3c2)c2ccc3oc4ccccc4c3c2)cc1 ; c1ccc(-c2ccc(N(c3ccc4ccc5cc6oc7ccccc7c6cc5c4c3)c3ccc4oc5ccccc5c4c3)cc2)cc1 ; c1ccc(-c2cccc(N(c3ccc4ccc5cc6oc7ccccc7c6cc5c4c3)c3ccc4oc5ccccc5c4c3)c2)cc1] 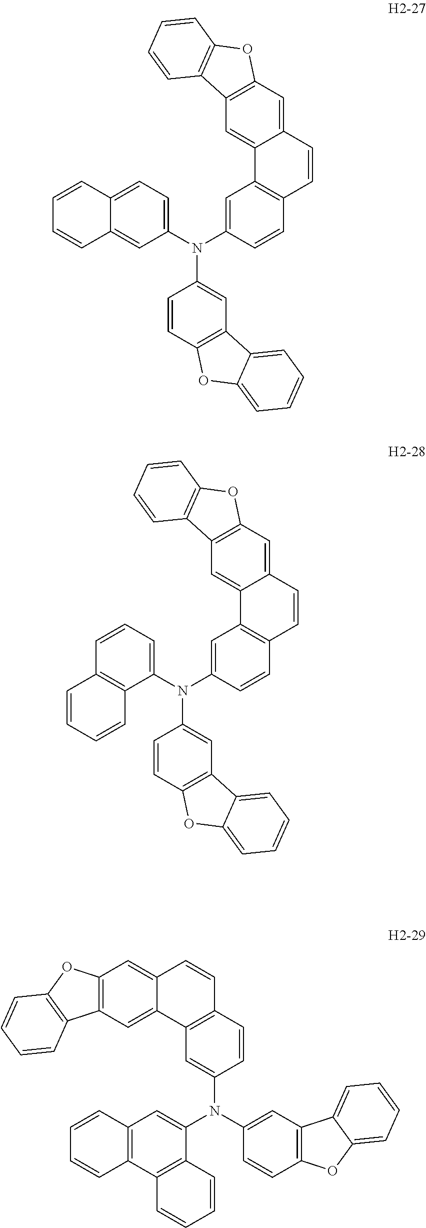 [SMILES: c1ccc2cc(N(c3ccc4ccc5cc6oc7ccccc7c6cc5c4c3)c3ccc4oc5ccccc5c4c3)ccc2c1 ; c1ccc2c(N(c3ccc4ccc5cc6oc7ccccc7c6cc5c4c3)c3ccc4oc5ccccc5c4c3)cccc2c1 ; c1ccc2c(c1)cc(N(c1ccc3ccc4cc5oc6ccccc6c5cc4c3c1)c1ccc3oc4ccccc4c3c1)c1ccccc12] 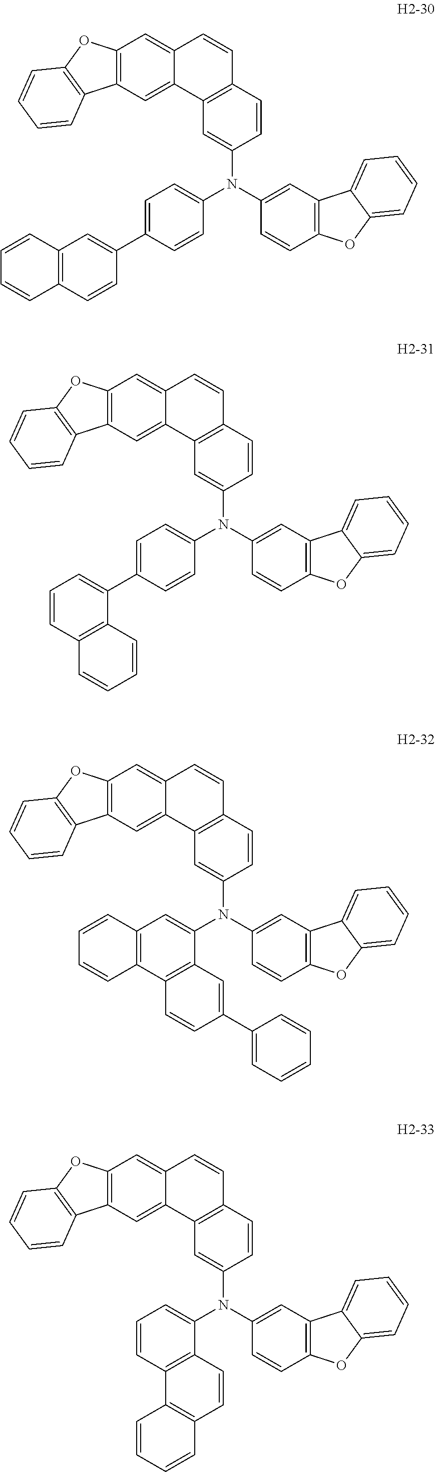 [SMILES: c1ccc2cc(-c3ccc(N(c4ccc5ccc6cc7oc8ccccc8c7cc6c5c4)c4ccc5oc6ccccc6c5c4)cc3)ccc2c1 ; c1ccc2c(-c3ccc(N(c4ccc5ccc6cc7oc8ccccc8c7cc6c5c4)c4ccc5oc6ccccc6c5c4)cc3)cccc2c1 ; c1ccc(-c2ccc3c(c2)c(N(c2ccc4ccc5cc6oc7ccccc7c6cc5c4c2)c2ccc4oc5ccccc5c4c2)cc2ccccc23)cc1 ; c1ccc2c(c1)ccc1c(N(c3ccc4ccc5cc6oc7ccccc7c6cc5c4c3)c3ccc4oc5ccccc5c4c3)cccc12] 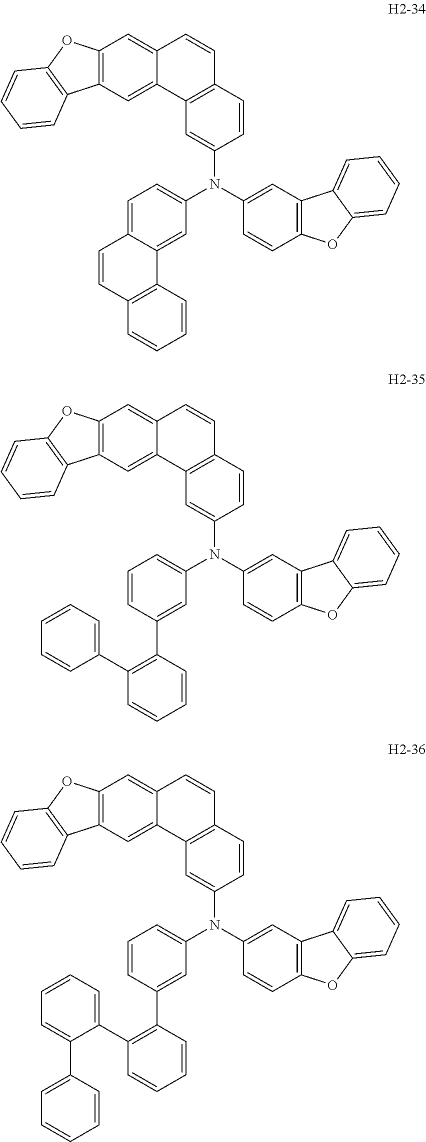 [SMILES: c1ccc2c(c1)ccc1ccc(N(c3ccc4ccc5cc6oc7ccccc7c6cc5c4c3)c3ccc4oc5ccccc5c4c3)cc12 ; c1ccc(-c2ccccc2-c2cccc(N(c3ccc4ccc5cc6oc7ccccc7c6cc5c4c3)c3ccc4oc5ccccc5c4c3)c2)cc1 ; c1ccc(-c2ccccc2-c2ccccc2-c2cccc(N(c3ccc4ccc5cc6oc7ccccc7c6cc5c4c3)c3ccc4oc5ccccc5c4c3)c2)cc1] 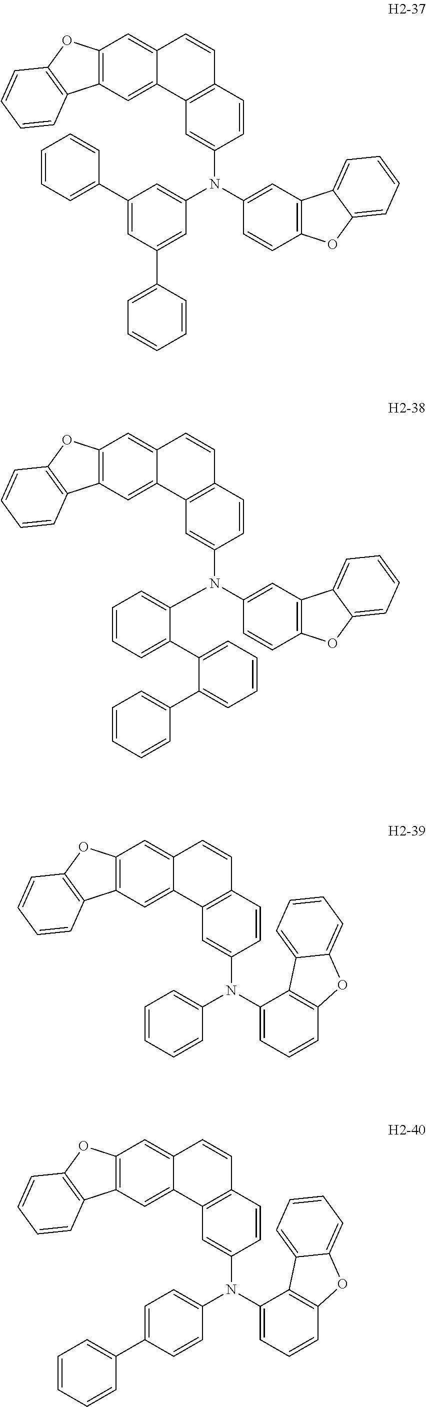 [SMILES: c1ccc(-c2cc(-c3ccccc3)cc(N(c3ccc4ccc5cc6oc7ccccc7c6cc5c4c3)c3ccc4oc5ccccc5c4c3)c2)cc1 ; c1ccc(-c2ccccc2-c2ccccc2N(c2ccc3ccc4cc5oc6ccccc6c5cc4c3c2)c2ccc3oc4ccccc4c3c2)cc1 ; c1ccc(N(c2ccc3ccc4cc5oc6ccccc6c5cc4c3c2)c2cccc3oc4ccccc4c23)cc1 ; c1ccc(-c2ccc(N(c3ccc4ccc5cc6oc7ccccc7c6cc5c4c3)c3cccc4oc5ccccc5c34)cc2)cc1] 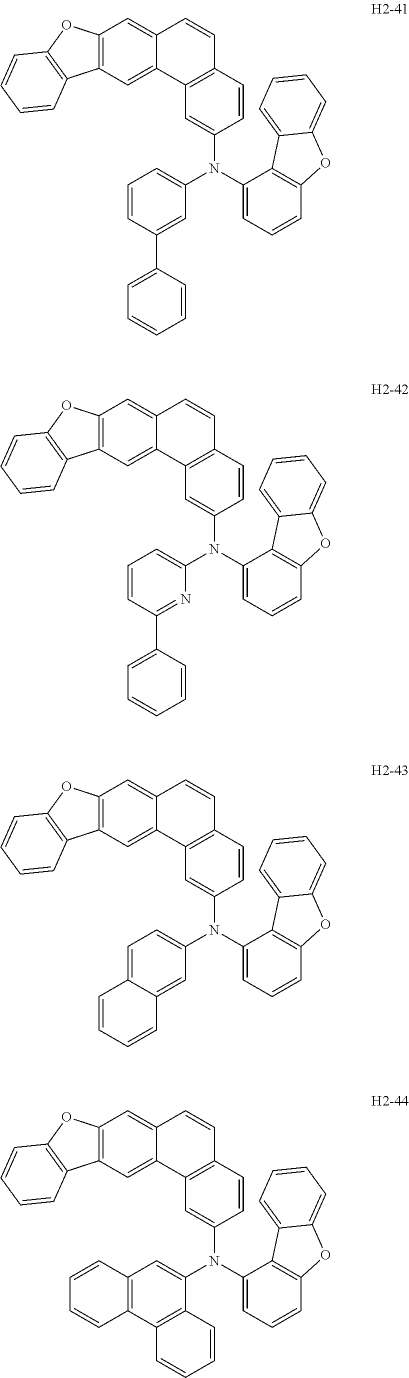 [SMILES: c1ccc(-c2cccc(N(c3ccc4ccc5cc6oc7ccccc7c6cc5c4c3)c3cccc4oc5ccccc5c34)c2)cc1 ; c1ccc(-c2cccc(N(c3ccc4ccc5cc6oc7ccccc7c6cc5c4c3)c3cccc4oc5ccccc5c34)n2)cc1 ; c1ccc2cc(N(c3ccc4ccc5cc6oc7ccccc7c6cc5c4c3)c3cccc4oc5ccccc5c34)ccc2c1 ; c1ccc2c(c1)cc(N(c1ccc3ccc4cc5oc6ccccc6c5cc4c3c1)c1cccc3oc4ccccc4c13)c1ccccc12] 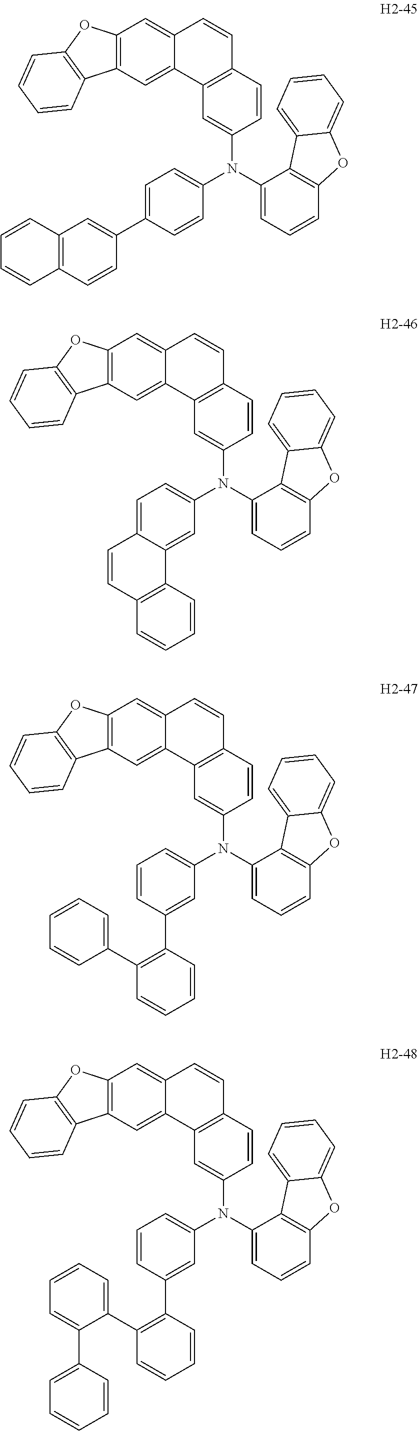 [SMILES: c1ccc2cc(-c3ccc(N(c4ccc5ccc6cc7oc8ccccc8c7cc6c5c4)c4cccc5oc6ccccc6c45)cc3)ccc2c1 ; c1ccc2c(c1)ccc1ccc(N(c3ccc4ccc5cc6oc7ccccc7c6cc5c4c3)c3cccc4oc5ccccc5c34)cc12 ; c1ccc(-c2ccccc2-c2cccc(N(c3ccc4ccc5cc6oc7ccccc7c6cc5c4c3)c3cccc4oc5ccccc5c34)c2)cc1 ; c1ccc(-c2ccccc2-c2ccccc2-c2cccc(N(c3ccc4ccc5cc6oc7ccccc7c6cc5c4c3)c3cccc4oc5ccccc5c34)c2)cc1] 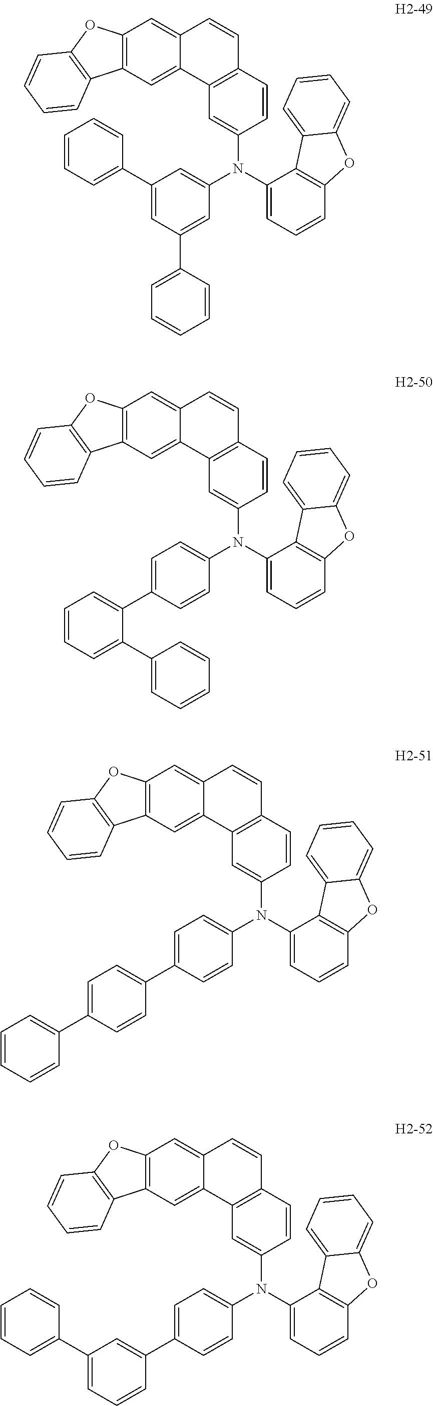 [SMILES: c1ccc(-c2cc(-c3ccccc3)cc(N(c3ccc4ccc5cc6oc7ccccc7c6cc5c4c3)c3cccc4oc5ccccc5c34)c2)cc1 ; c1ccc(-c2ccccc2-c2ccc(N(c3ccc4ccc5cc6oc7ccccc7c6cc5c4c3)c3cccc4oc5ccccc5c34)cc2)cc1 ; c1ccc(-c2ccc(-c3ccc(N(c4ccc5ccc6cc7oc8ccccc8c7cc6c5c4)c4cccc5oc6ccccc6c45)cc3)cc2)cc1 ; c1ccc(-c2cccc(-c3ccc(N(c4ccc5ccc6cc7oc8ccccc8c7cc6c5c4)c4cccc5oc6ccccc6c45)cc3)c2)cc1] 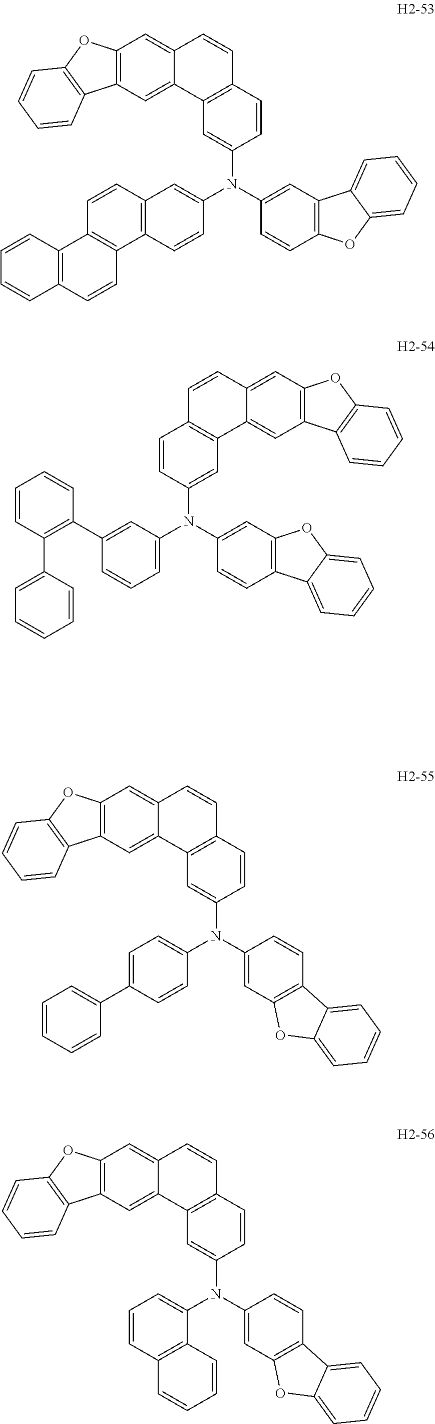 [SMILES: c1ccc2c(c1)ccc1c3ccc(N(c4ccc5ccc6cc7oc8ccccc8c7cc6c5c4)c4ccc5oc6ccccc6c5c4)cc3ccc21 ; c1ccc(-c2ccccc2-c2cccc(N(c3ccc4c(c3)oc3ccccc34)c3ccc4ccc5cc6oc7ccccc7c6cc5c4c3)c2)cc1 ; c1ccc(-c2ccc(N(c3ccc4c(c3)oc3ccccc34)c3ccc4ccc5cc6oc7ccccc7c6cc5c4c3)cc2)cc1 ; c1ccc2c(N(c3ccc4c(c3)oc3ccccc34)c3ccc4ccc5cc6oc7ccccc7c6cc5c4c3)cccc2c1] 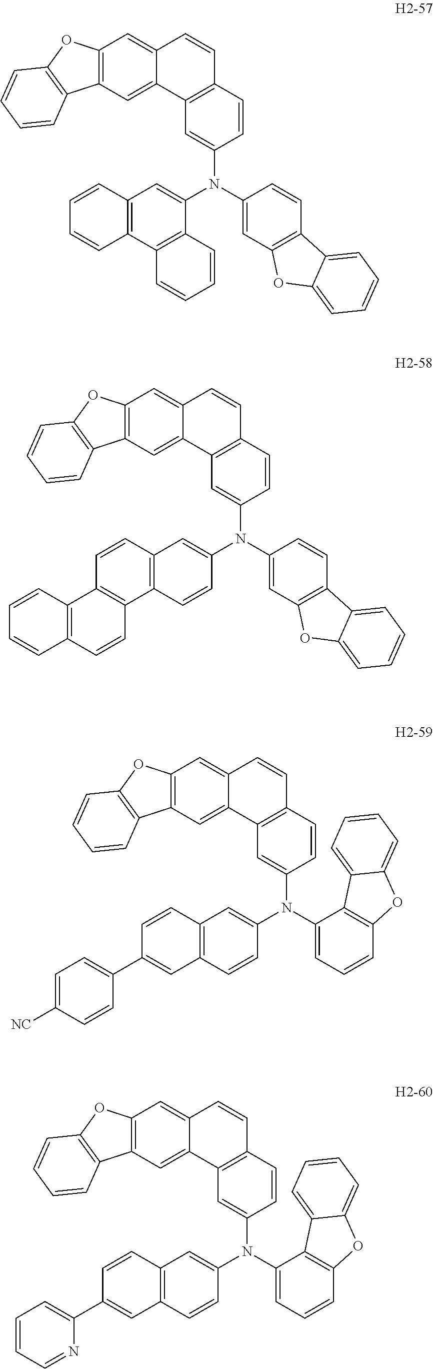 [SMILES: c1ccc2c(c1)cc(N(c1ccc3c(c1)oc1ccccc13)c1ccc3ccc4cc5oc6ccccc6c5cc4c3c1)c1ccccc12 ; c1ccc2c(c1)ccc1c3ccc(N(c4ccc5c(c4)oc4ccccc45)c4ccc5ccc6cc7oc8ccccc8c7cc6c5c4)cc3ccc21 ; N#Cc1ccc(-c2ccc3cc(N(c4ccc5ccc6cc7oc8ccccc8c7cc6c5c4)c4cccc5oc6ccccc6c45)ccc3c2)cc1 ; c1ccc(-c2ccc3cc(N(c4ccc5ccc6cc7oc8ccccc8c7cc6c5c4)c4cccc5oc6ccccc6c45)ccc3c2)nc1] 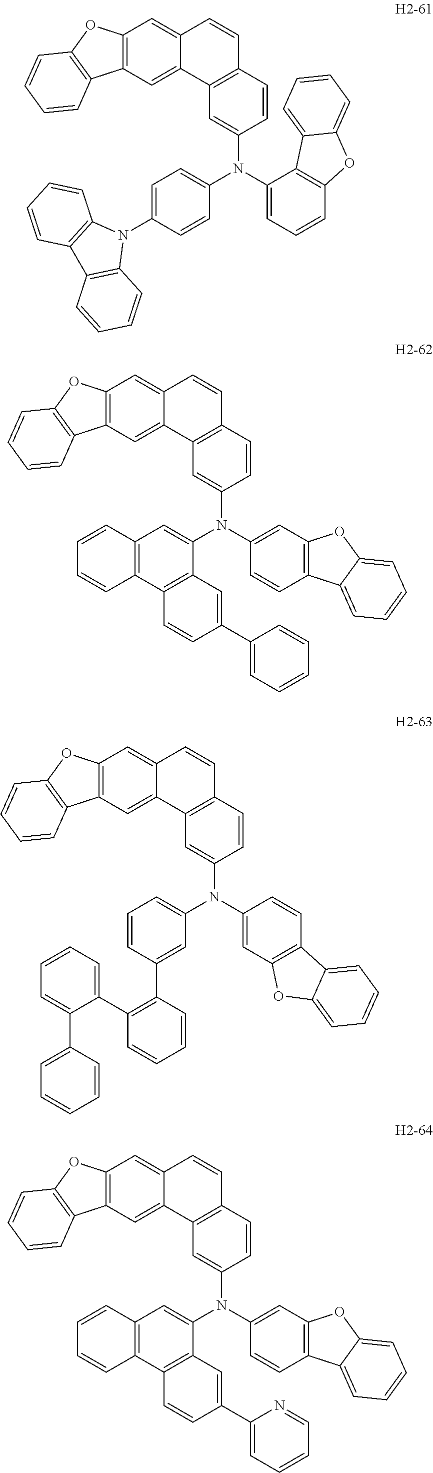 [SMILES: c1ccc2c(c1)oc1cc3ccc4ccc(N(c5ccc(-n6c7ccccc7c7ccccc76)cc5)c5cccc6oc7ccccc7c56)cc4c3cc12 ; c1ccc(-c2ccc3c(c2)c(N(c2ccc4c(c2)oc2ccccc24)c2ccc4ccc5cc6oc7ccccc7c6cc5c4c2)cc2ccccc23)cc1 ; c1ccc(-c2ccccc2-c2ccccc2-c2cccc(N(c3ccc4c(c3)oc3ccccc34)c3ccc4ccc5cc6oc7ccccc7c6cc5c4c3)c2)cc1 ; c1ccc(-c2ccc3c(c2)c(N(c2ccc4c(c2)oc2ccccc24)c2ccc4ccc5cc6oc7ccccc7c6cc5c4c2)cc2ccccc23)nc1] 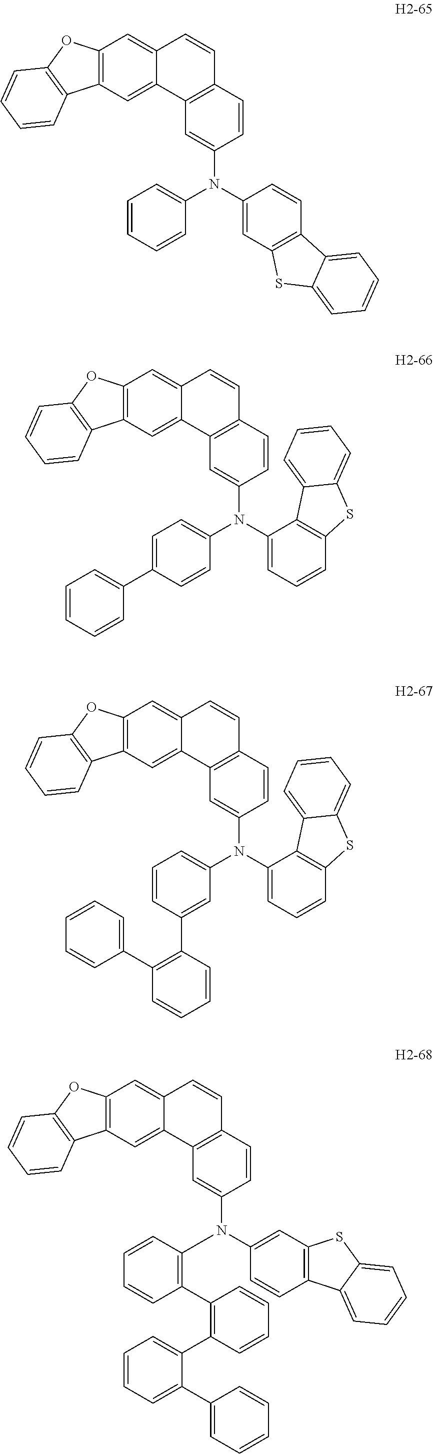 [SMILES: c1ccc(N(c2ccc3c(c2)sc2ccccc23)c2ccc3ccc4cc5oc6ccccc6c5cc4c3c2)cc1 ; c1ccc(-c2ccc(N(c3ccc4ccc5cc6oc7ccccc7c6cc5c4c3)c3cccc4sc5ccccc5c34)cc2)cc1 ; c1ccc(-c2ccccc2-c2cccc(N(c3ccc4ccc5cc6oc7ccccc7c6cc5c4c3)c3cccc4sc5ccccc5c34)c2)cc1 ; c1ccc(-c2ccccc2-c2ccccc2-c2ccccc2N(c2ccc3c(c2)sc2ccccc23)c2ccc3ccc4cc5oc6ccccc6c5cc4c3c2)cc1] 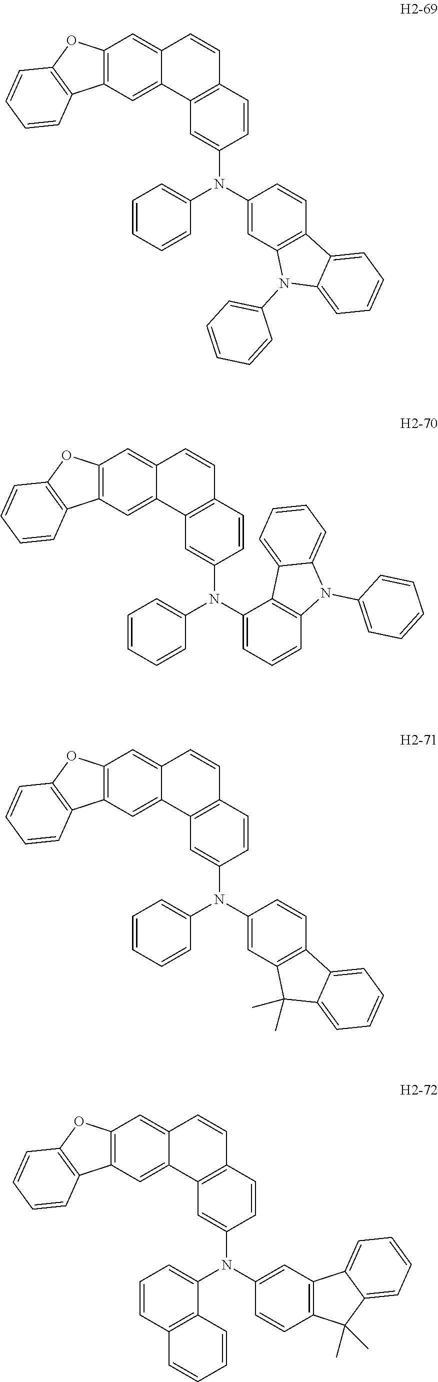 [SMILES: c1ccc(N(c2ccc3ccc4cc5oc6ccccc6c5cc4c3c2)c2ccc3c4ccccc4n(-c4ccccc4)c3c2)cc1 ; c1ccc(N(c2ccc3ccc4cc5oc6ccccc6c5cc4c3c2)c2cccc3c2c2ccccc2n3-c2ccccc2)cc1 ; CC1(C)c2ccccc2-c2ccc(N(c3ccccc3)c3ccc4ccc5cc6oc7ccccc7c6cc5c4c3)cc21 ; CC1(C)c2ccccc2-c2cc(N(c3ccc4ccc5cc6oc7ccccc7c6cc5c4c3)c3cccc4ccccc34)ccc21] 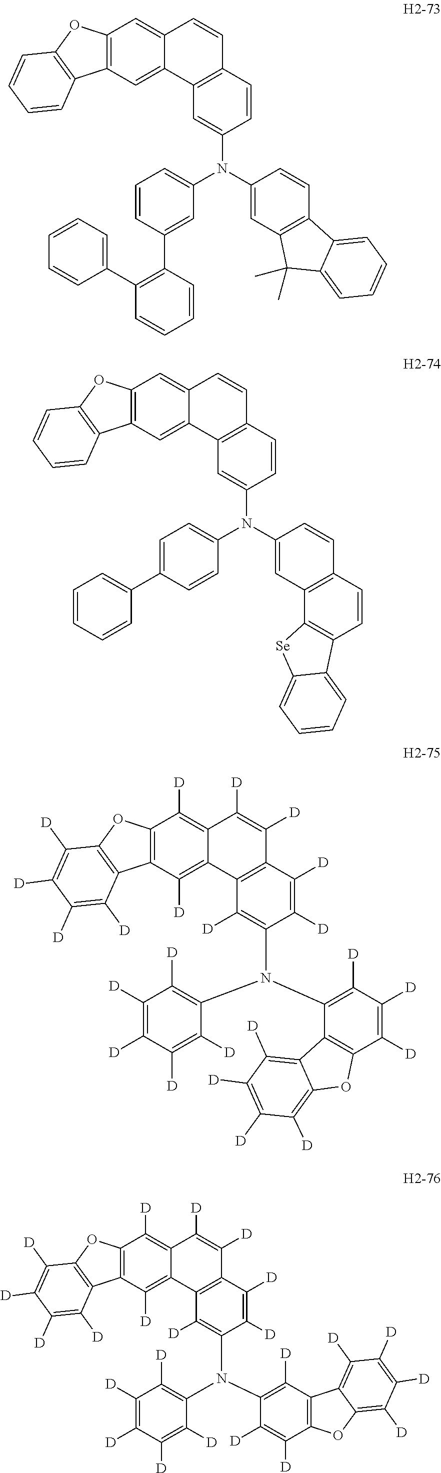 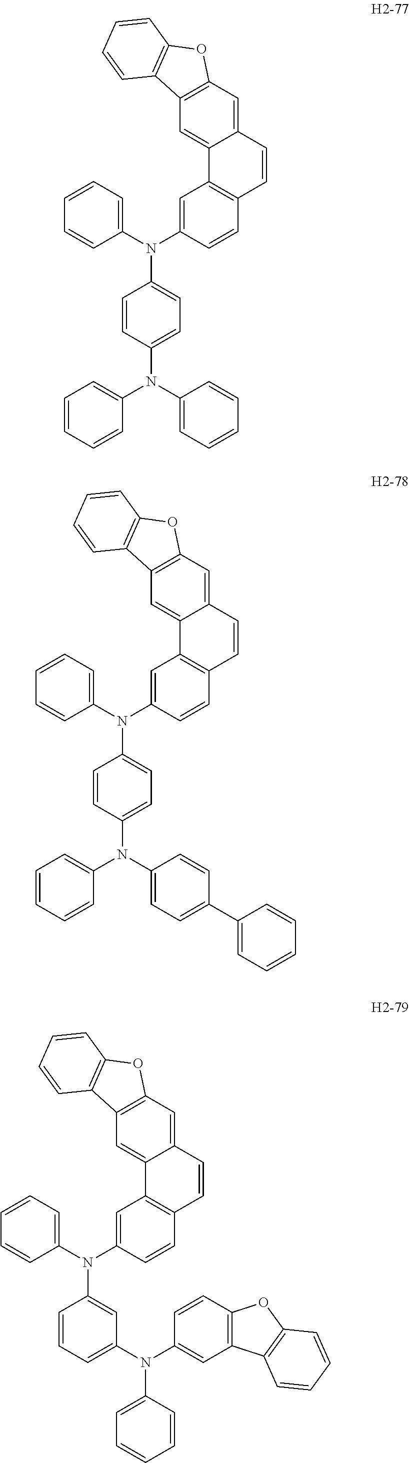 [SMILES: c1ccc(N(c2ccccc2)c2ccc(N(c3ccccc3)c3ccc4ccc5cc6oc7ccccc7c6cc5c4c3)cc2)cc1 ; c1ccc(-c2ccc(N(c3ccccc3)c3ccc(N(c4ccccc4)c4ccc5ccc6cc7oc8ccccc8c7cc6c5c4)cc3)cc2)cc1 ; c1ccc(N(c2cccc(N(c3ccccc3)c3ccc4oc5ccccc5c4c3)c2)c2ccc3ccc4cc5oc6ccccc6c5cc4c3c2)cc1] 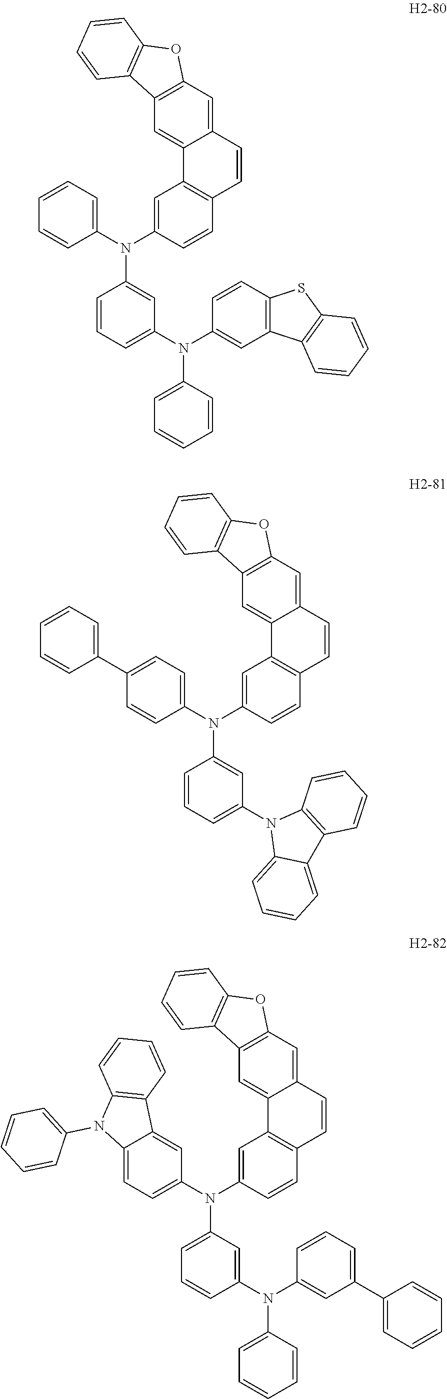 [SMILES: c1ccc(N(c2cccc(N(c3ccccc3)c3ccc4sc5ccccc5c4c3)c2)c2ccc3ccc4cc5oc6ccccc6c5cc4c3c2)cc1 ; c1ccc(-c2ccc(N(c3cccc(-n4c5ccccc5c5ccccc54)c3)c3ccc4ccc5cc6oc7ccccc7c6cc5c4c3)cc2)cc1 ; c1ccc(-c2cccc(N(c3ccccc3)c3cccc(N(c4ccc5ccc6cc7oc8ccccc8c7cc6c5c4)c4ccc5c(c4)c4ccccc4n5-c4ccccc4)c3)c2)cc1] 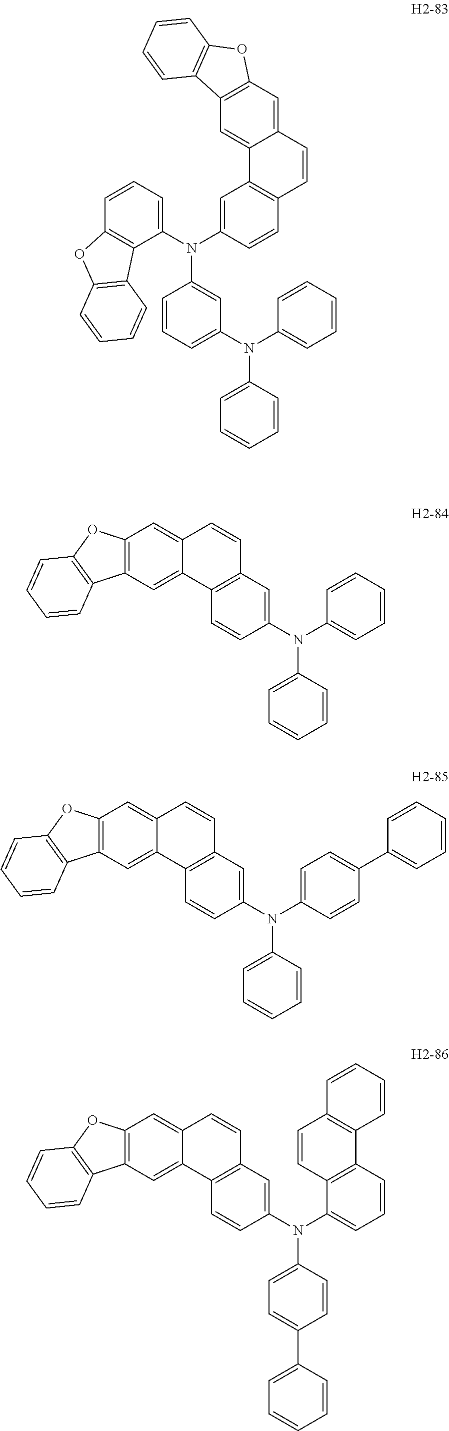 [SMILES: c1ccc(N(c2ccccc2)c2cccc(N(c3ccc4ccc5cc6oc7ccccc7c6cc5c4c3)c3cccc4oc5ccccc5c34)c2)cc1 ; c1ccc(N(c2ccccc2)c2ccc3c(ccc4cc5oc6ccccc6c5cc43)c2)cc1 ; c1ccc(-c2ccc(N(c3ccccc3)c3ccc4c(ccc5cc6oc7ccccc7c6cc54)c3)cc2)cc1 ; c1ccc(-c2ccc(N(c3ccc4c(ccc5cc6oc7ccccc7c6cc54)c3)c3cccc4c3ccc3ccccc34)cc2)cc1] 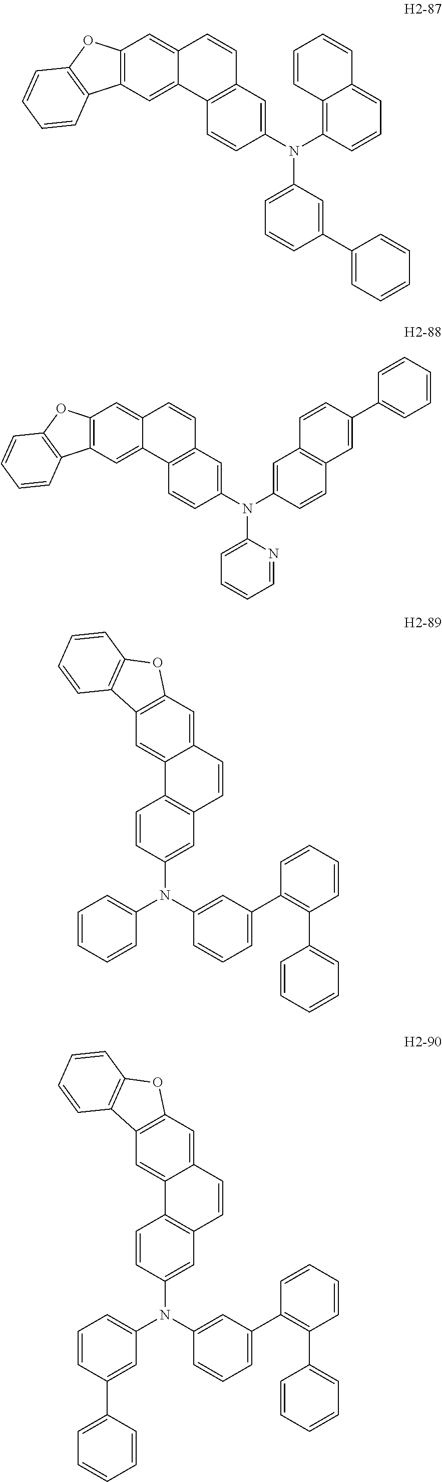 [SMILES: c1ccc(-c2cccc(N(c3ccc4c(ccc5cc6oc7ccccc7c6cc54)c3)c3cccc4ccccc34)c2)cc1 ; c1ccc(-c2ccc3cc(N(c4ccc5c(ccc6cc7oc8ccccc8c7cc65)c4)c4ccccn4)ccc3c2)cc1 ; c1ccc(-c2ccccc2-c2cccc(N(c3ccccc3)c3ccc4c(ccc5cc6oc7ccccc7c6cc54)c3)c2)cc1 ; c1ccc(-c2cccc(N(c3cccc(-c4ccccc4-c4ccccc4)c3)c3ccc4c(ccc5cc6oc7ccccc7c6cc54)c3)c2)cc1] 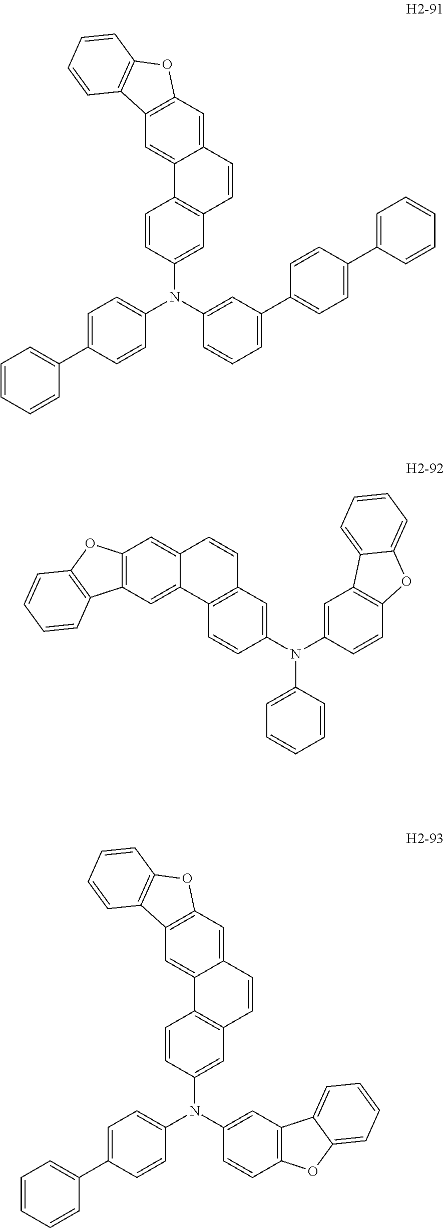 [SMILES: c1ccc(-c2ccc(-c3cccc(N(c4ccc(-c5ccccc5)cc4)c4ccc5c(ccc6cc7oc8ccccc8c7cc65)c4)c3)cc2)cc1 ; c1ccc(N(c2ccc3c(ccc4cc5oc6ccccc6c5cc43)c2)c2ccc3oc4ccccc4c3c2)cc1 ; c1ccc(-c2ccc(N(c3ccc4c(ccc5cc6oc7ccccc7c6cc54)c3)c3ccc4oc5ccccc5c4c3)cc2)cc1] 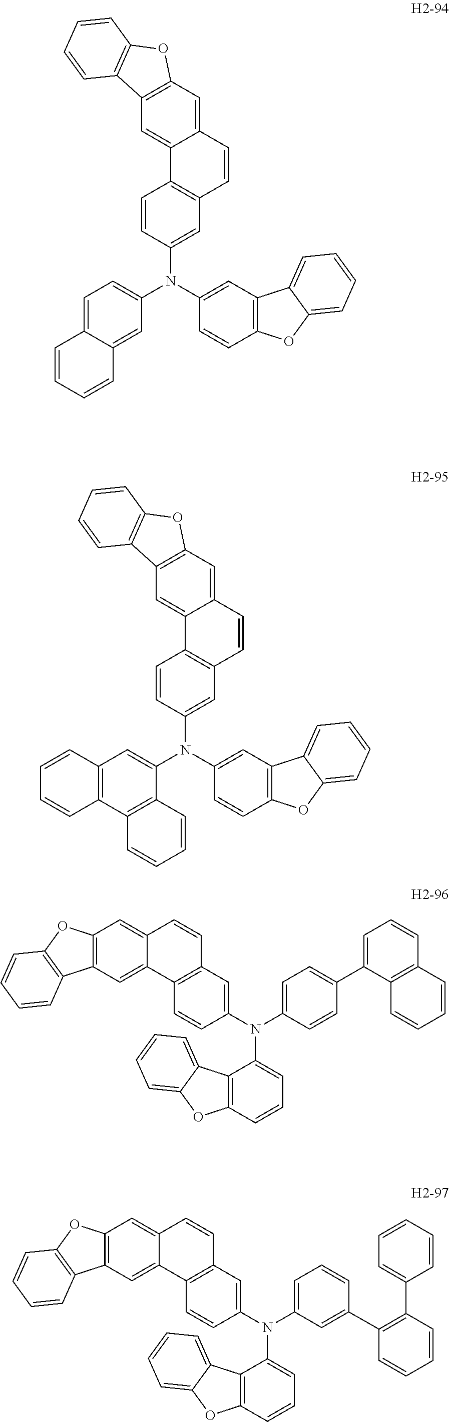 [SMILES: c1ccc2cc(N(c3ccc4c(ccc5cc6oc7ccccc7c6cc54)c3)c3ccc4oc5ccccc5c4c3)ccc2c1 ; c1ccc2c(c1)cc(N(c1ccc3c(ccc4cc5oc6ccccc6c5cc43)c1)c1ccc3oc4ccccc4c3c1)c1ccccc12 ; c1ccc2c(-c3ccc(N(c4ccc5c(ccc6cc7oc8ccccc8c7cc65)c4)c4cccc5oc6ccccc6c45)cc3)cccc2c1 ; c1ccc(-c2ccccc2-c2cccc(N(c3ccc4c(ccc5cc6oc7ccccc7c6cc54)c3)c3cccc4oc5ccccc5c34)c2)cc1] 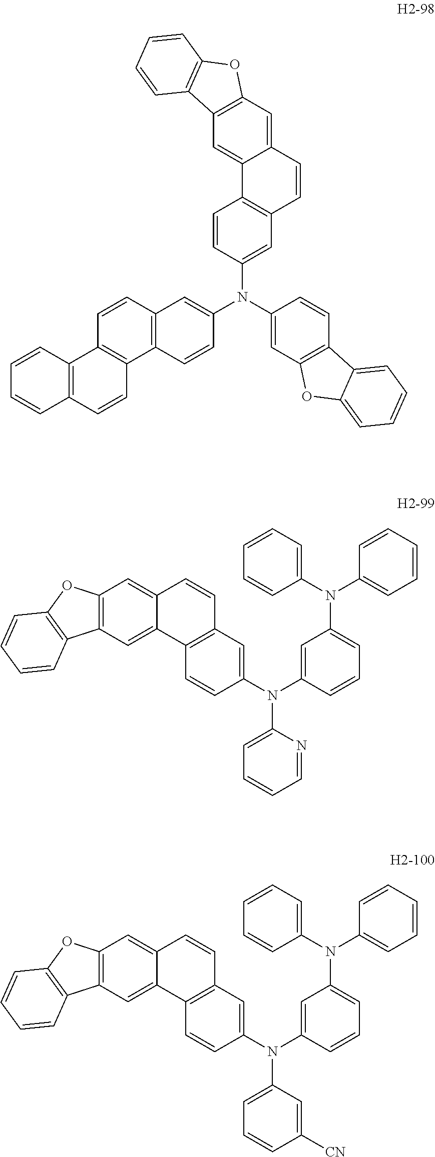 [SMILES: c1ccc2c(c1)ccc1c3ccc(N(c4ccc5c(ccc6cc7oc8ccccc8c7cc65)c4)c4ccc5c(c4)oc4ccccc45)cc3ccc21 ; c1ccc(N(c2ccccc2)c2cccc(N(c3ccc4c(ccc5cc6oc7ccccc7c6cc54)c3)c3ccccn3)c2)cc1 ; N#Cc1cccc(N(c2cccc(N(c3ccccc3)c3ccccc3)c2)c2ccc3c(ccc4cc5oc6ccccc6c5cc43)c2)c1] 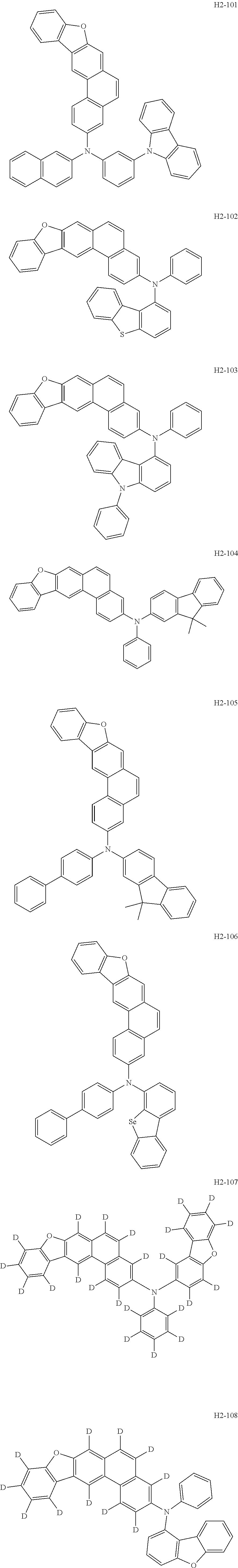 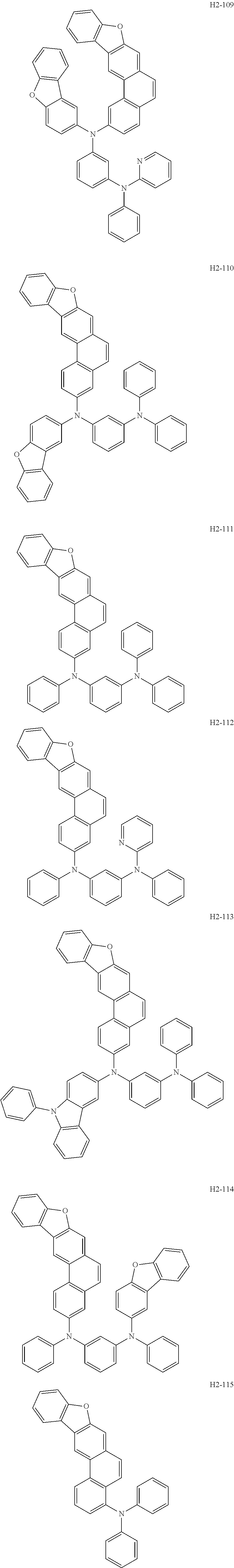 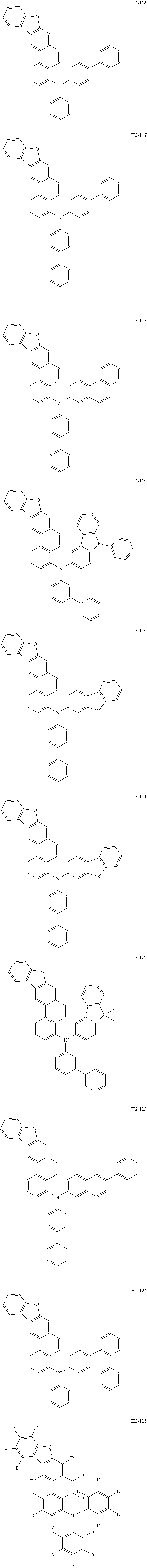 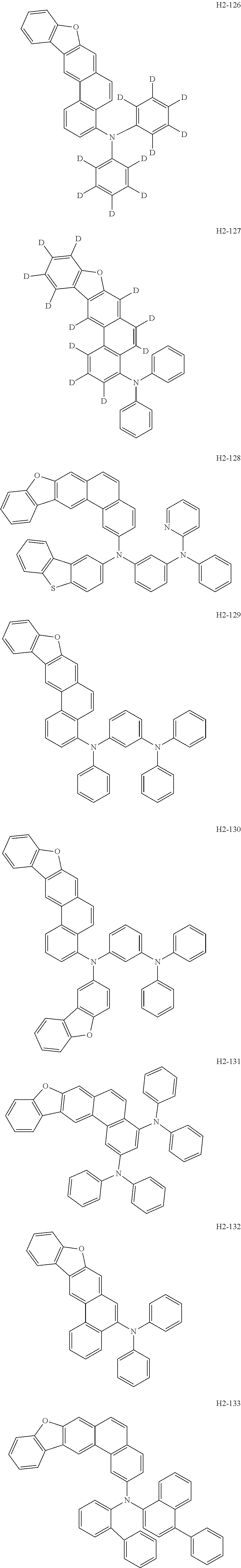 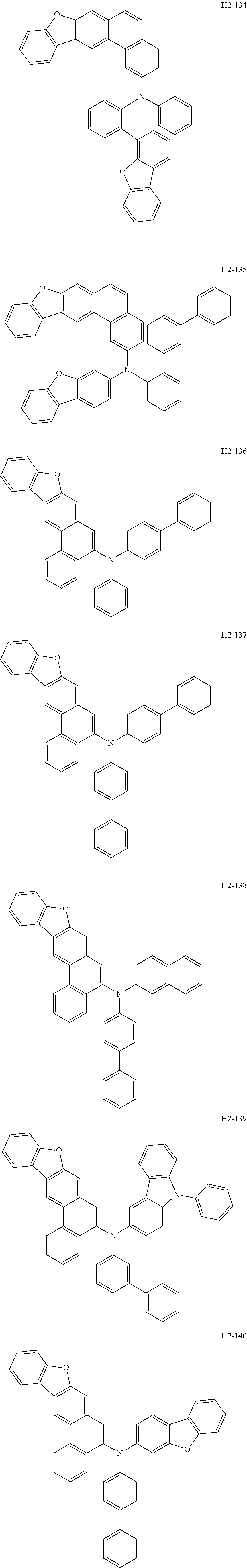 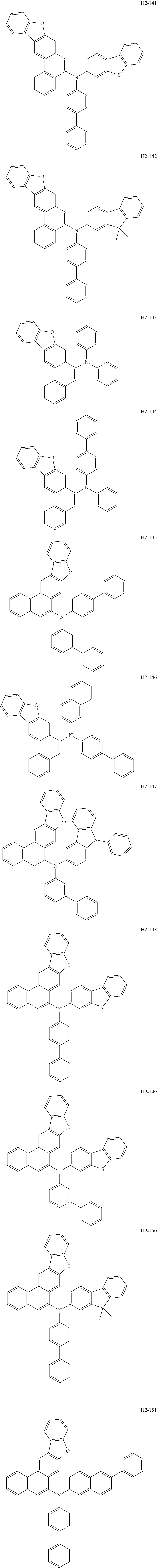 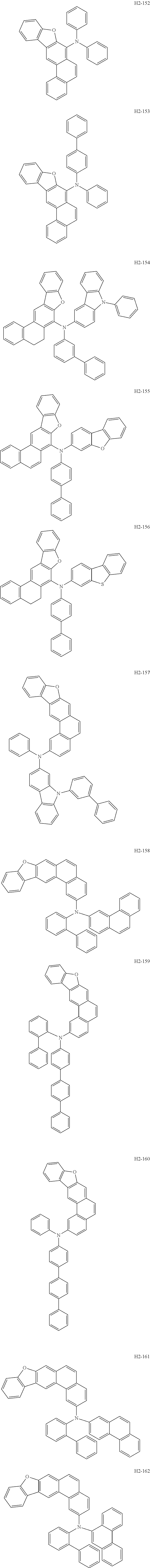 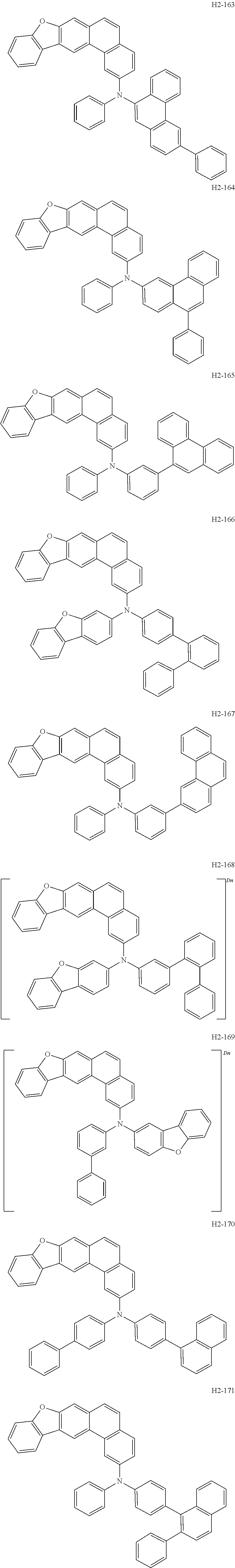 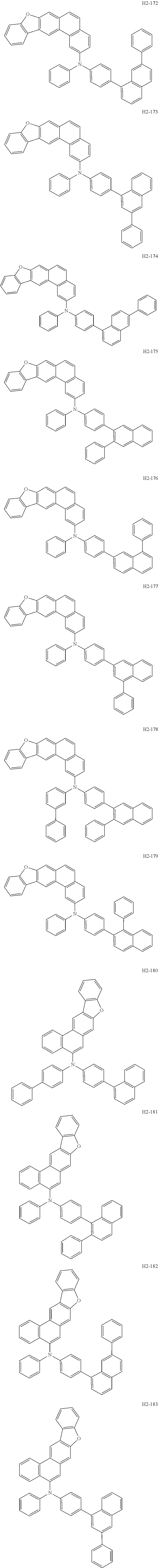 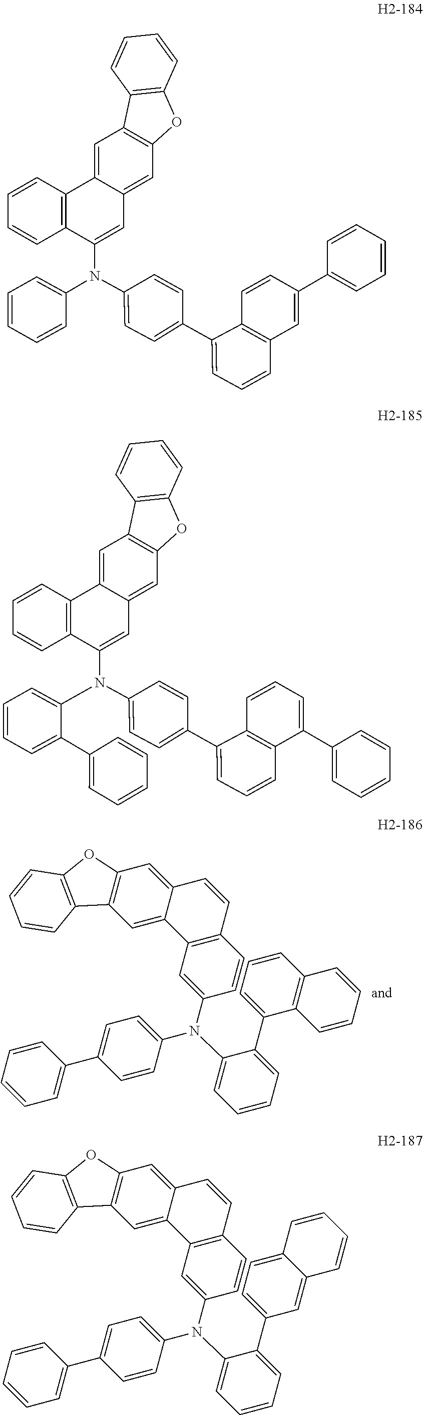 [SMILES: c1ccc(-c2ccc3c(-c4ccc(N(c5ccccc5)c5cc6cc7oc8ccccc8c7cc6c6ccccc56)cc4)cccc3c2)cc1 ; c1ccc(-c2ccccc2N(c2ccc(-c3cccc4c(-c5ccccc5)cccc34)cc2)c2cc3cc4oc5ccccc5c4cc3c3ccccc23)cc1 ; c1ccc(-c2ccc(N(c3ccc4ccc5cc6oc7ccccc7c6cc5c4c3)c3ccccc3-c3cccc4ccccc34)cc2)cc1 ; c1ccc(-c2ccc(N(c3ccc4ccc5cc6oc7ccccc7c6cc5c4c3)c3ccccc3-c3ccc4ccccc4c3)cc2)cc1]
wherein in the compounds above, Dₙ means that n hydrogen atoms are replaced with deuterium, wherein n is an integer from 1 to the maximum number of hydrogen atoms in the compound.

10. The organic electroluminescent device according to claim 1, wherein the compound represented by Formula 3 is selected from the following compounds: 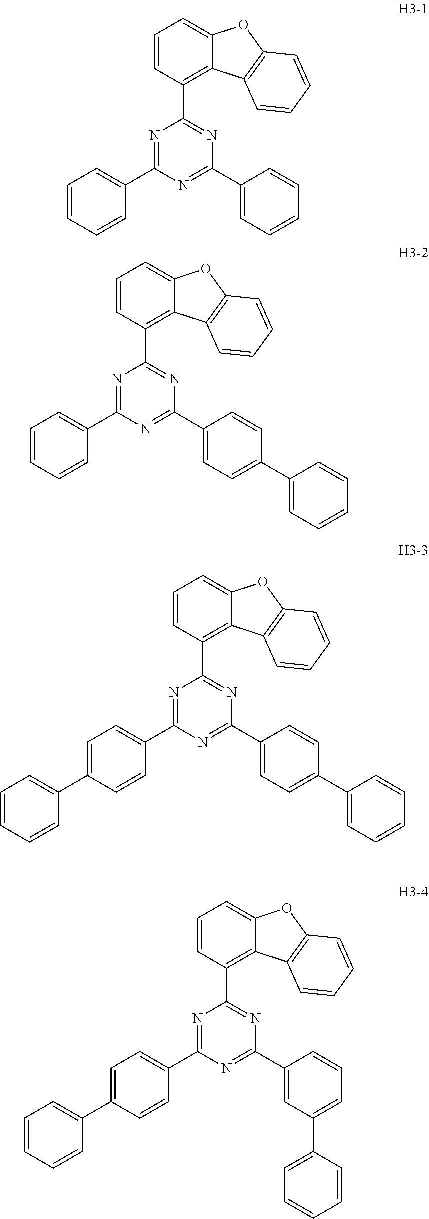 [SMILES: c1ccc(-c2nc(-c3ccccc3)nc(-c3cccc4oc5ccccc5c34)n2)cc1 ; c1ccc(-c2ccc(-c3nc(-c4ccccc4)nc(-c4cccc5oc6ccccc6c45)n3)cc2)cc1 ; c1ccc(-c2ccc(-c3nc(-c4ccc(-c5ccccc5)cc4)nc(-c4cccc5oc6ccccc6c45)n3)cc2)cc1 ; c1ccc(-c2ccc(-c3nc(-c4cccc(-c5ccccc5)c4)nc(-c4cccc5oc6ccccc6c45)n3)cc2)cc1] 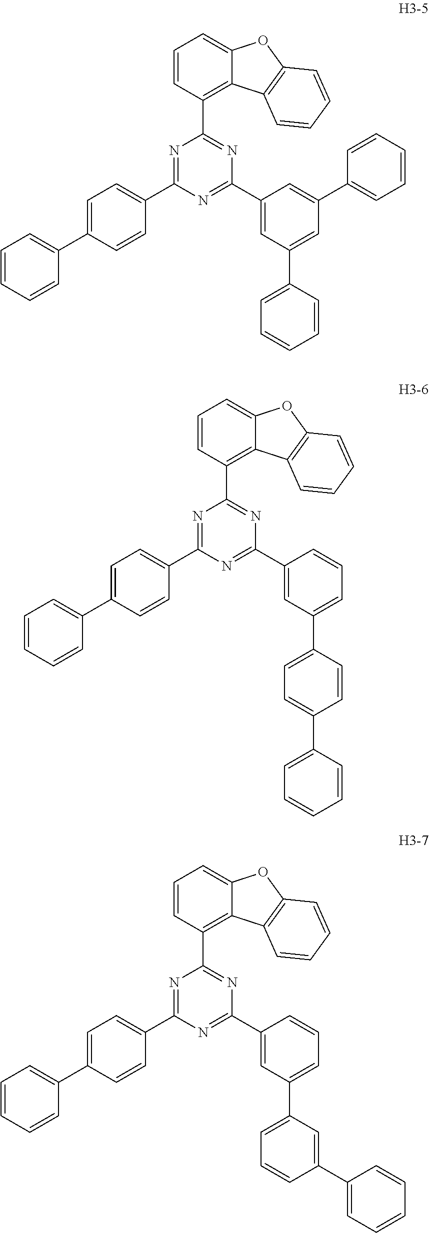 [SMILES: c1ccc(-c2ccc(-c3nc(-c4cc(-c5ccccc5)cc(-c5ccccc5)c4)nc(-c4cccc5oc6ccccc6c45)n3)cc2)cc1 ; c1ccc(-c2ccc(-c3cccc(-c4nc(-c5ccc(-c6ccccc6)cc5)nc(-c5cccc6oc7ccccc7c56)n4)c3)cc2)cc1 ; c1ccc(-c2ccc(-c3nc(-c4cccc(-c5cccc(-c6ccccc6)c5)c4)nc(-c4cccc5oc6ccccc6c45)n3)cc2)cc1] 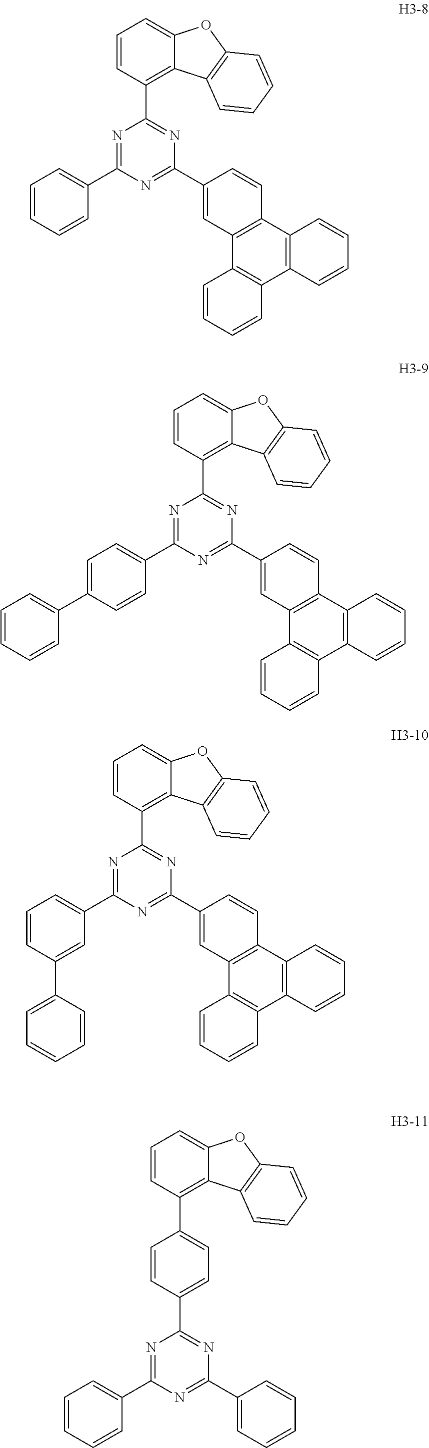 [SMILES: c1ccc(-c2nc(-c3ccc4c5ccccc5c5ccccc5c4c3)nc(-c3cccc4oc5ccccc5c34)n2)cc1 ; c1ccc(-c2ccc(-c3nc(-c4ccc5c6ccccc6c6ccccc6c5c4)nc(-c4cccc5oc6ccccc6c45)n3)cc2)cc1 ; c1ccc(-c2cccc(-c3nc(-c4ccc5c6ccccc6c6ccccc6c5c4)nc(-c4cccc5oc6ccccc6c45)n3)c2)cc1 ; c1ccc(-c2nc(-c3ccccc3)nc(-c3ccc(-c4cccc5oc6ccccc6c45)cc3)n2)cc1] 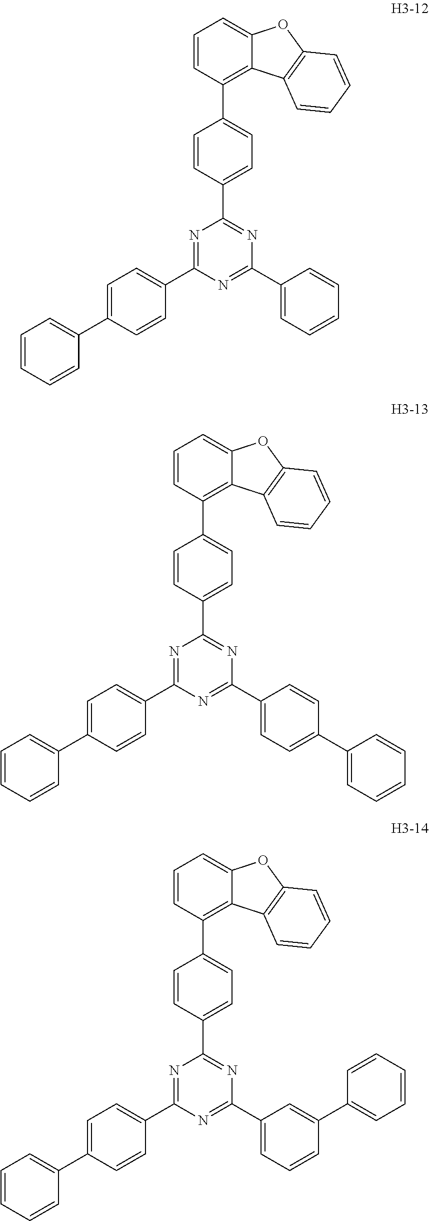 [SMILES: c1ccc(-c2ccc(-c3nc(-c4ccccc4)nc(-c4ccc(-c5cccc6oc7ccccc7c56)cc4)n3)cc2)cc1 ; c1ccc(-c2ccc(-c3nc(-c4ccc(-c5ccccc5)cc4)nc(-c4ccc(-c5cccc6oc7ccccc7c56)cc4)n3)cc2)cc1 ; c1ccc(-c2ccc(-c3nc(-c4ccc(-c5cccc6oc7ccccc7c56)cc4)nc(-c4cccc(-c5ccccc5)c4)n3)cc2)cc1] 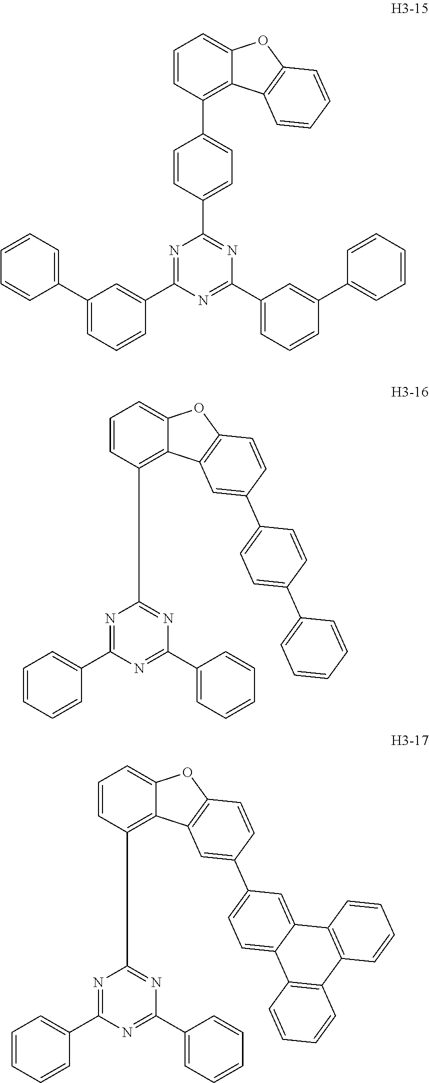 [SMILES: c1ccc(-c2cccc(-c3nc(-c4ccc(-c5cccc6oc7ccccc7c56)cc4)nc(-c4cccc(-c5ccccc5)c4)n3)c2)cc1 ; c1ccc(-c2ccc(-c3ccc4oc5cccc(-c6nc(-c7ccccc7)nc(-c7ccccc7)n6)c5c4c3)cc2)cc1 ; c1ccc(-c2nc(-c3ccccc3)nc(-c3cccc4oc5ccc(-c6ccc7c8ccccc8c8ccccc8c7c6)cc5c34)n2)cc1] 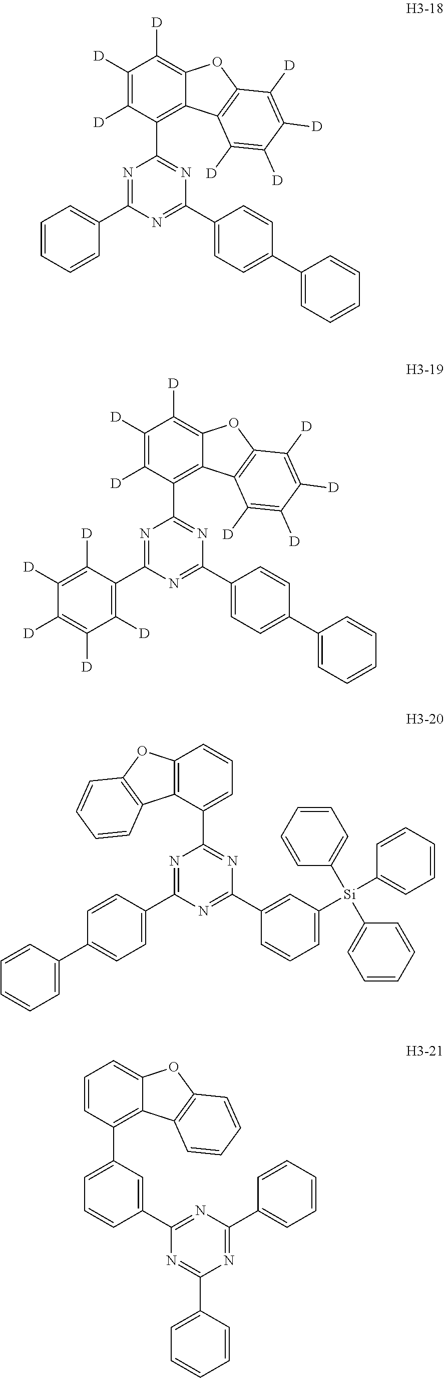 [SMILES: [2H]c1c([2H])c([2H])c2c(oc3c([2H])c([2H])c([2H])c(-c4nc(-c5ccccc5)nc(-c5ccc(-c6ccccc6)cc5)n4)c32)c1[2H] ; [2H]c1c([2H])c([2H])c(-c2nc(-c3ccc(-c4ccccc4)cc3)nc(-c3c([2H])c([2H])c([2H])c4oc5c([2H])c([2H])c([2H])c([2H])c5c34)n2)c([2H])c1[2H] ; c1ccc(-c2ccc(-c3nc(-c4cccc([Si](c5ccccc5)(c5ccccc5)c5ccccc5)c4)nc(-c4cccc5oc6ccccc6c45)n3)cc2)cc1 ; c1ccc(-c2nc(-c3ccccc3)nc(-c3cccc(-c4cccc5oc6ccccc6c45)c3)n2)cc1] 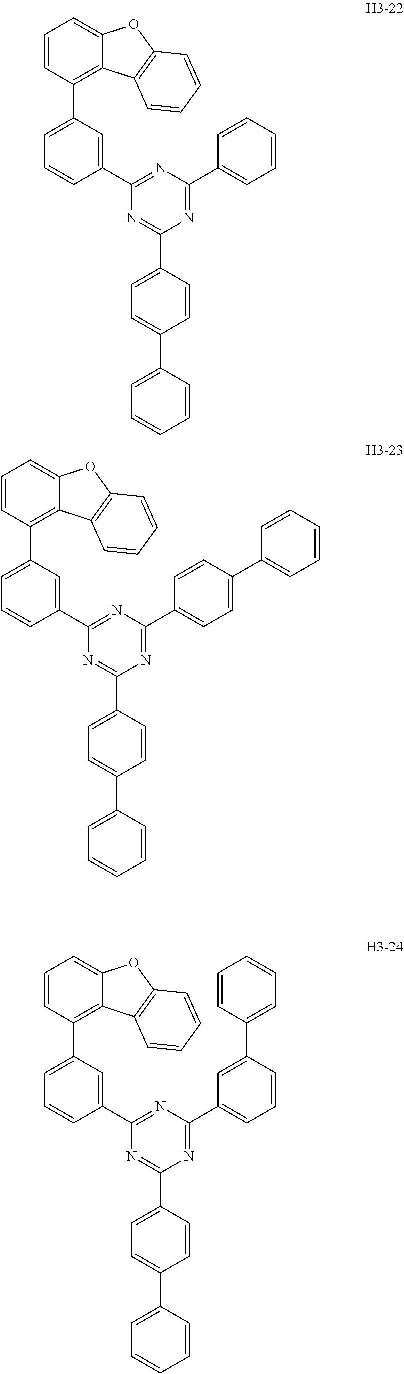 [SMILES: c1ccc(-c2ccc(-c3nc(-c4ccccc4)nc(-c4cccc(-c5cccc6oc7ccccc7c56)c4)n3)cc2)cc1 ; c1ccc(-c2ccc(-c3nc(-c4ccc(-c5ccccc5)cc4)nc(-c4cccc(-c5cccc6oc7ccccc7c56)c4)n3)cc2)cc1 ; c1ccc(-c2ccc(-c3nc(-c4cccc(-c5ccccc5)c4)nc(-c4cccc(-c5cccc6oc7ccccc7c56)c4)n3)cc2)cc1] 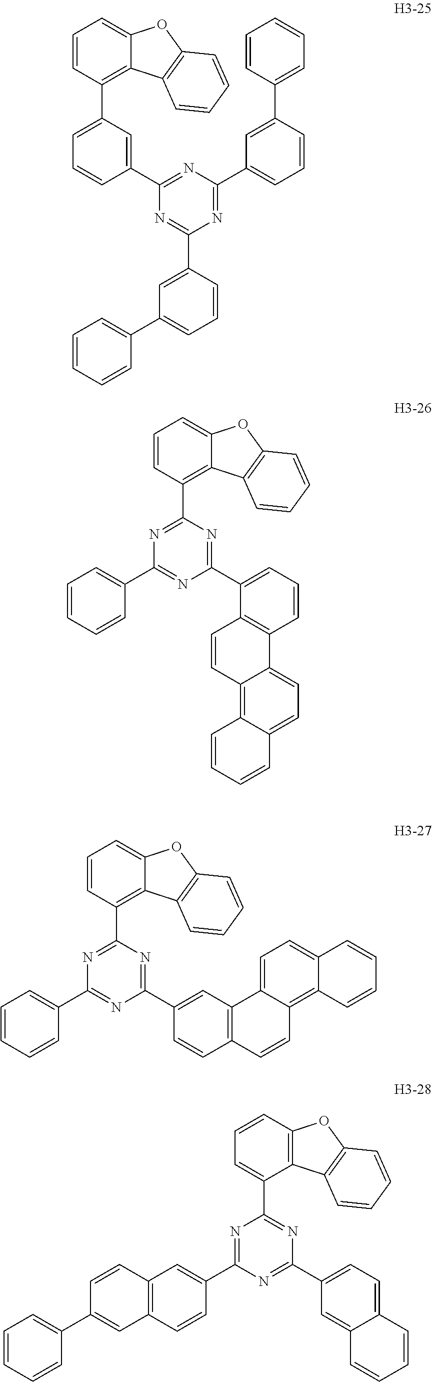 [SMILES: c1ccc(-c2cccc(-c3nc(-c4cccc(-c5ccccc5)c4)nc(-c4cccc(-c5cccc6oc7ccccc7c56)c4)n3)c2)cc1 ; c1ccc(-c2nc(-c3cccc4c3ccc3c5ccccc5ccc43)nc(-c3cccc4oc5ccccc5c34)n2)cc1 ; c1ccc(-c2nc(-c3ccc4ccc5c6ccccc6ccc5c4c3)nc(-c3cccc4oc5ccccc5c34)n2)cc1 ; c1ccc(-c2ccc3cc(-c4nc(-c5ccc6ccccc6c5)nc(-c5cccc6oc7ccccc7c56)n4)ccc3c2)cc1] 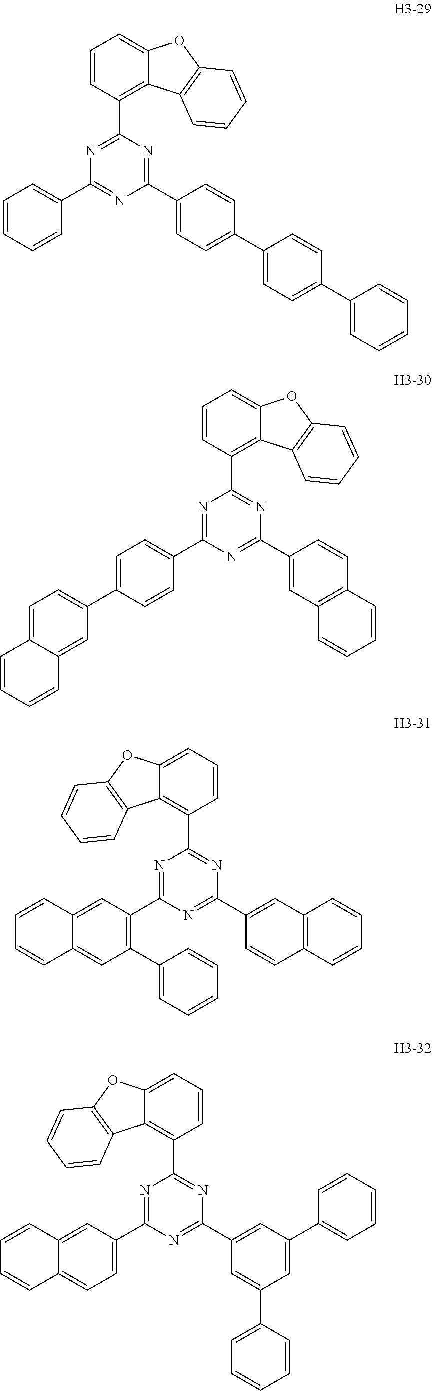 [SMILES: c1ccc(-c2ccc(-c3ccc(-c4nc(-c5ccccc5)nc(-c5cccc6oc7ccccc7c56)n4)cc3)cc2)cc1 ; c1ccc2cc(-c3ccc(-c4nc(-c5ccc6ccccc6c5)nc(-c5cccc6oc7ccccc7c56)n4)cc3)ccc2c1 ; c1ccc(-c2cc3ccccc3cc2-c2nc(-c3ccc4ccccc4c3)nc(-c3cccc4oc5ccccc5c34)n2)cc1 ; c1ccc(-c2cc(-c3ccccc3)cc(-c3nc(-c4ccc5ccccc5c4)nc(-c4cccc5oc6ccccc6c45)n3)c2)cc1] 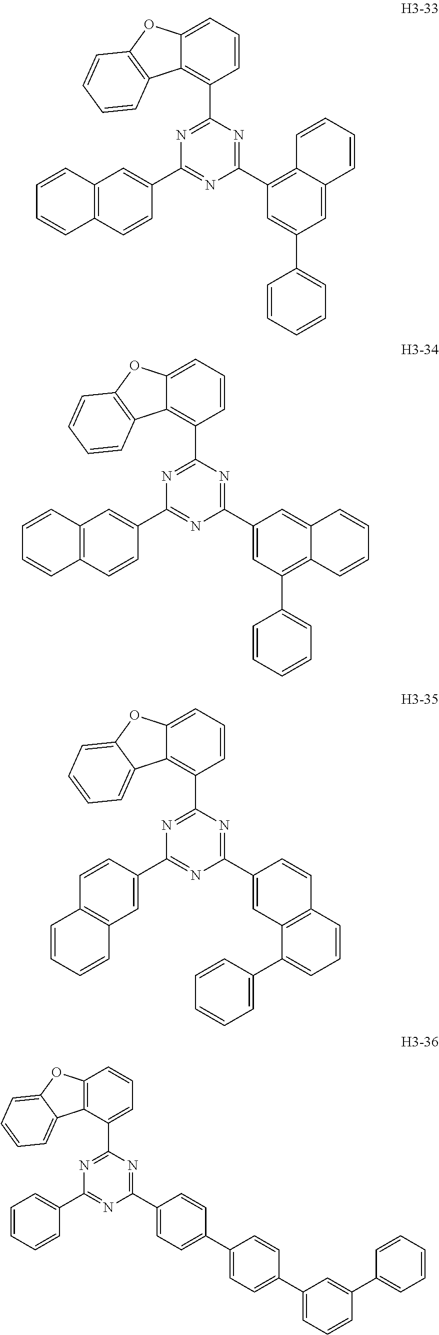 [SMILES: c1ccc(-c2cc(-c3nc(-c4ccc5ccccc5c4)nc(-c4cccc5oc6ccccc6c45)n3)c3ccccc3c2)cc1 ; c1ccc(-c2cc(-c3nc(-c4ccc5ccccc5c4)nc(-c4cccc5oc6ccccc6c45)n3)cc3ccccc23)cc1 ; c1ccc(-c2cccc3ccc(-c4nc(-c5ccc6ccccc6c5)nc(-c5cccc6oc7ccccc7c56)n4)cc23)cc1 ; c1ccc(-c2cccc(-c3ccc(-c4ccc(-c5nc(-c6ccccc6)nc(-c6cccc7oc8ccccc8c67)n5)cc4)cc3)c2)cc1] 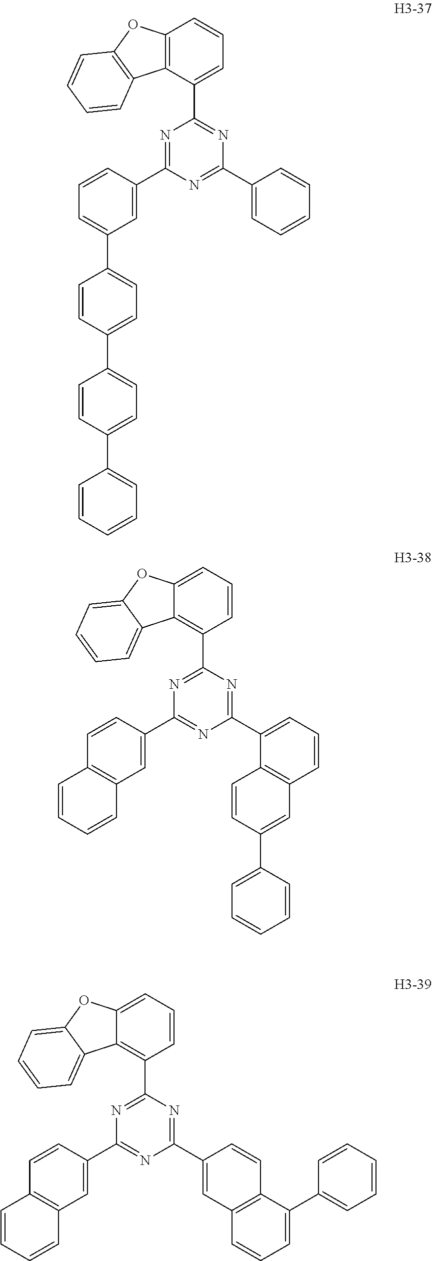 [SMILES: c1ccc(-c2ccc(-c3ccc(-c4cccc(-c5nc(-c6ccccc6)nc(-c6cccc7oc8ccccc8c67)n5)c4)cc3)cc2)cc1 ; c1ccc(-c2ccc3c(-c4nc(-c5ccc6ccccc6c5)nc(-c5cccc6oc7ccccc7c56)n4)cccc3c2)cc1 ; c1ccc(-c2cccc3cc(-c4nc(-c5ccc6ccccc6c5)nc(-c5cccc6oc7ccccc7c56)n4)ccc23)cc1] 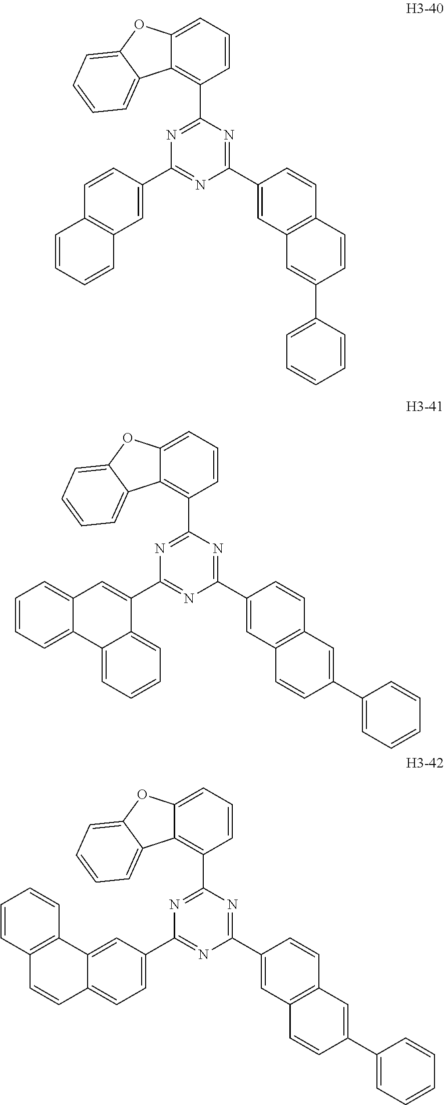 [SMILES: c1ccc(-c2ccc3ccc(-c4nc(-c5ccc6ccccc6c5)nc(-c5cccc6oc7ccccc7c56)n4)cc3c2)cc1 ; c1ccc(-c2ccc3cc(-c4nc(-c5cc6ccccc6c6ccccc56)nc(-c5cccc6oc7ccccc7c56)n4)ccc3c2)cc1 ; c1ccc(-c2ccc3cc(-c4nc(-c5ccc6ccc7ccccc7c6c5)nc(-c5cccc6oc7ccccc7c56)n4)ccc3c2)cc1] 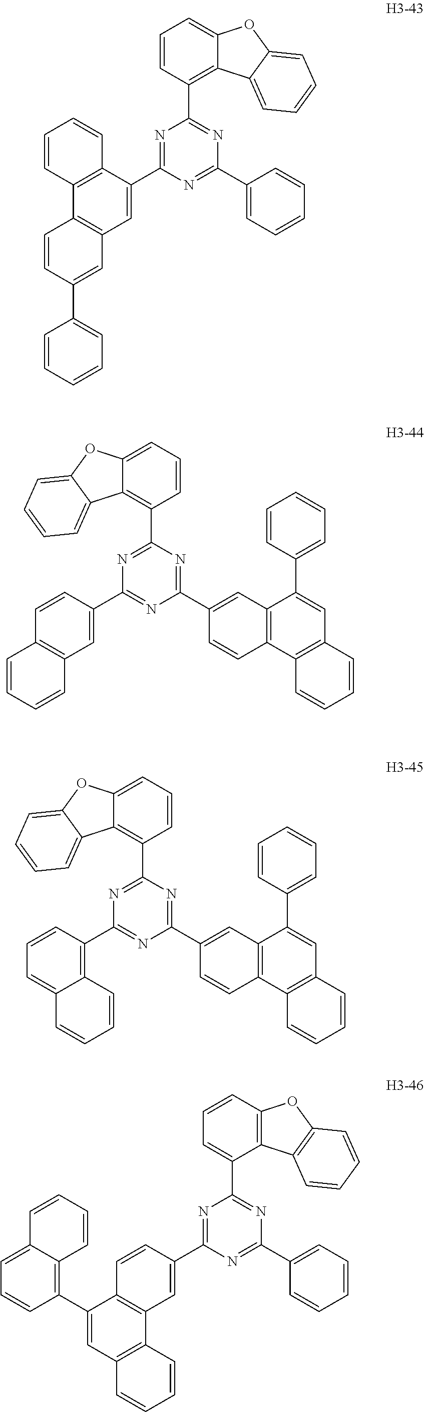 [SMILES: c1ccc(-c2ccc3c(c2)cc(-c2nc(-c4ccccc4)nc(-c4cccc5oc6ccccc6c45)n2)c2ccccc23)cc1 ; c1ccc(-c2cc3ccccc3c3ccc(-c4nc(-c5ccc6ccccc6c5)nc(-c5cccc6oc7ccccc7c56)n4)cc23)cc1 ; c1ccc(-c2cc3ccccc3c3ccc(-c4nc(-c5cccc6ccccc56)nc(-c5cccc6oc7ccccc7c56)n4)cc23)cc1 ; c1ccc(-c2nc(-c3ccc4c(-c5cccc6ccccc56)cc5ccccc5c4c3)nc(-c3cccc4oc5ccccc5c34)n2)cc1] 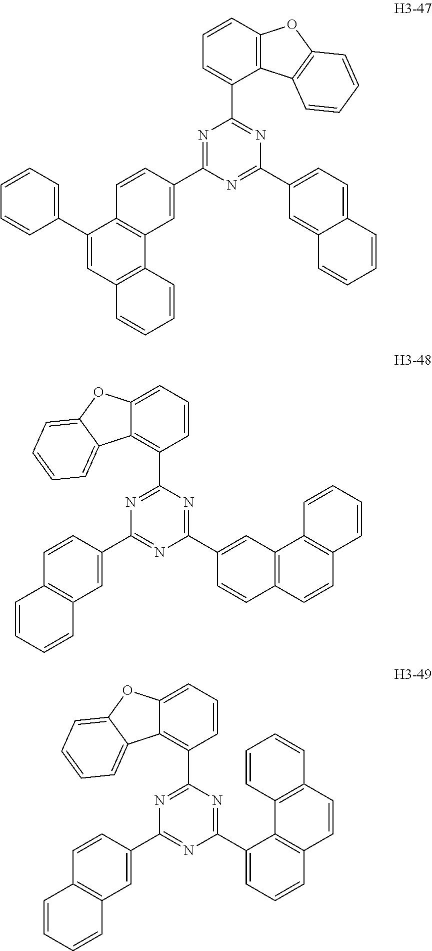 [SMILES: c1ccc(-c2cc3ccccc3c3cc(-c4nc(-c5ccc6ccccc6c5)nc(-c5cccc6oc7ccccc7c56)n4)ccc23)cc1 ; c1ccc2cc(-c3nc(-c4ccc5ccc6ccccc6c5c4)nc(-c4cccc5oc6ccccc6c45)n3)ccc2c1 ; c1ccc2cc(-c3nc(-c4cccc5ccc6ccccc6c45)nc(-c4cccc5oc6ccccc6c45)n3)ccc2c1] 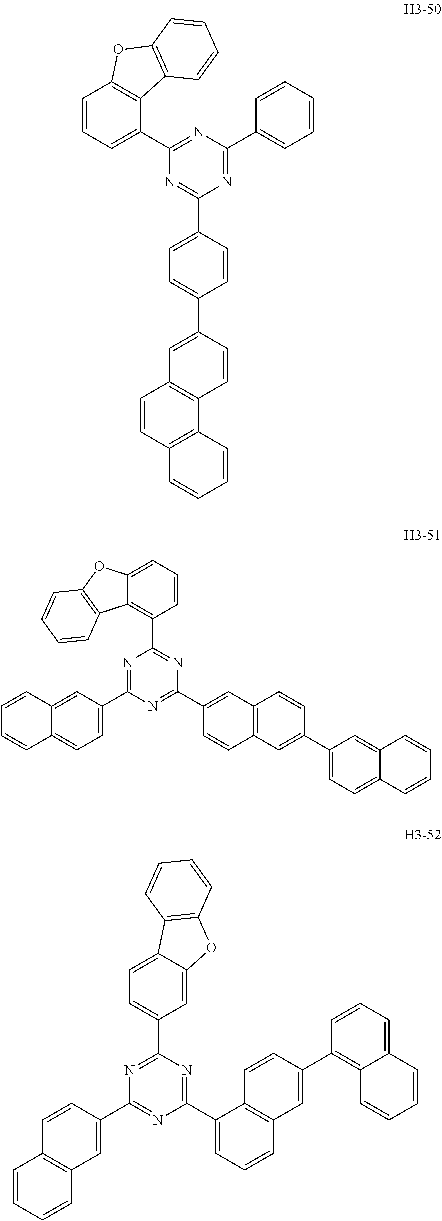 [SMILES: c1ccc(-c2nc(-c3ccc(-c4ccc5c(ccc6ccccc65)c4)cc3)nc(-c3cccc4oc5ccccc5c34)n2)cc1 ; c1ccc2cc(-c3ccc4cc(-c5nc(-c6ccc7ccccc7c6)nc(-c6cccc7oc8ccccc8c67)n5)ccc4c3)ccc2c1 ; c1ccc2cc(-c3nc(-c4ccc5c(c4)oc4ccccc45)nc(-c4cccc5cc(-c6cccc7ccccc67)ccc45)n3)ccc2c1] 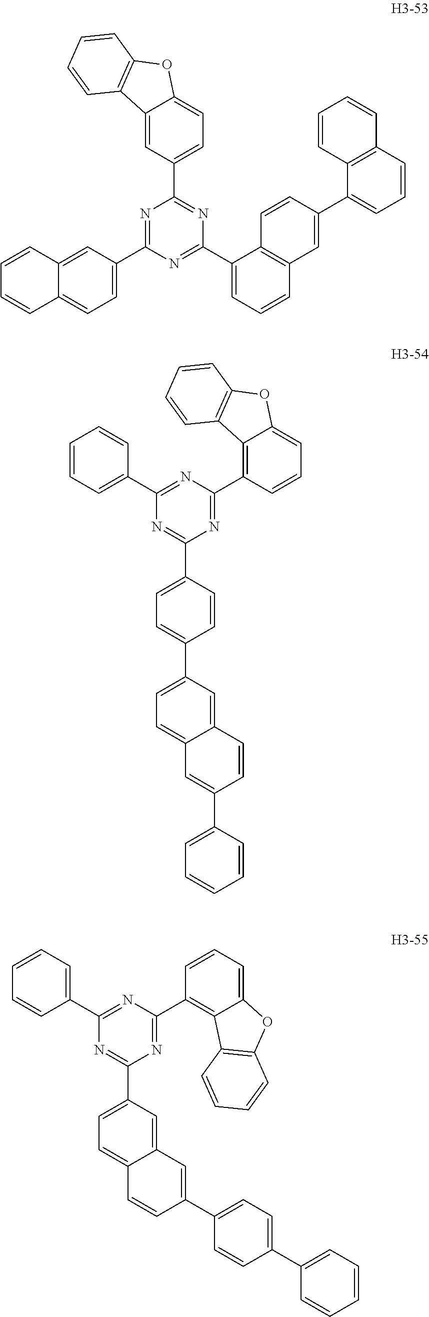 [SMILES: c1ccc2cc(-c3nc(-c4ccc5oc6ccccc6c5c4)nc(-c4cccc5cc(-c6cccc7ccccc67)ccc45)n3)ccc2c1 ; c1ccc(-c2ccc3cc(-c4ccc(-c5nc(-c6ccccc6)nc(-c6cccc7oc8ccccc8c67)n5)cc4)ccc3c2)cc1 ; c1ccc(-c2ccc(-c3ccc4ccc(-c5nc(-c6ccccc6)nc(-c6cccc7oc8ccccc8c67)n5)cc4c3)cc2)cc1] 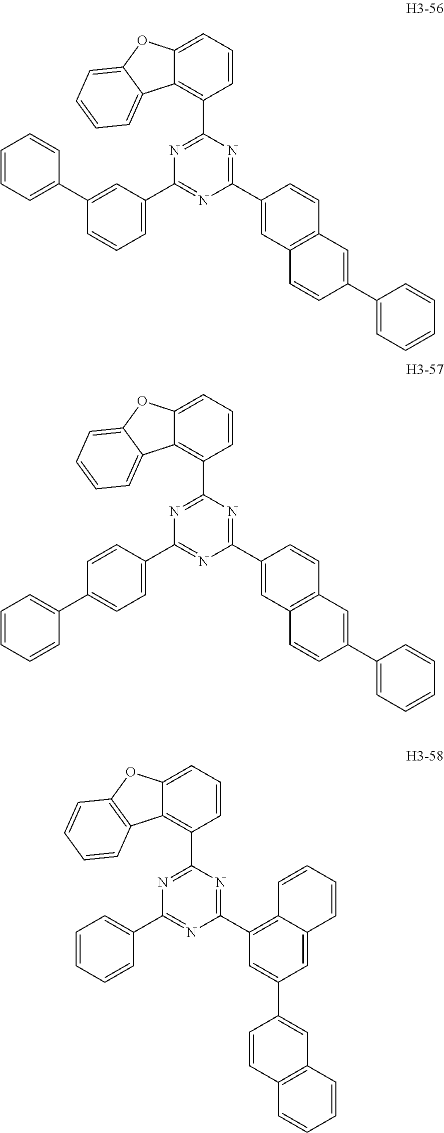 [SMILES: c1ccc(-c2cccc(-c3nc(-c4ccc5cc(-c6ccccc6)ccc5c4)nc(-c4cccc5oc6ccccc6c45)n3)c2)cc1 ; c1ccc(-c2ccc(-c3nc(-c4ccc5cc(-c6ccccc6)ccc5c4)nc(-c4cccc5oc6ccccc6c45)n3)cc2)cc1 ; c1ccc(-c2nc(-c3cc(-c4ccc5ccccc5c4)cc4ccccc34)nc(-c3cccc4oc5ccccc5c34)n2)cc1] 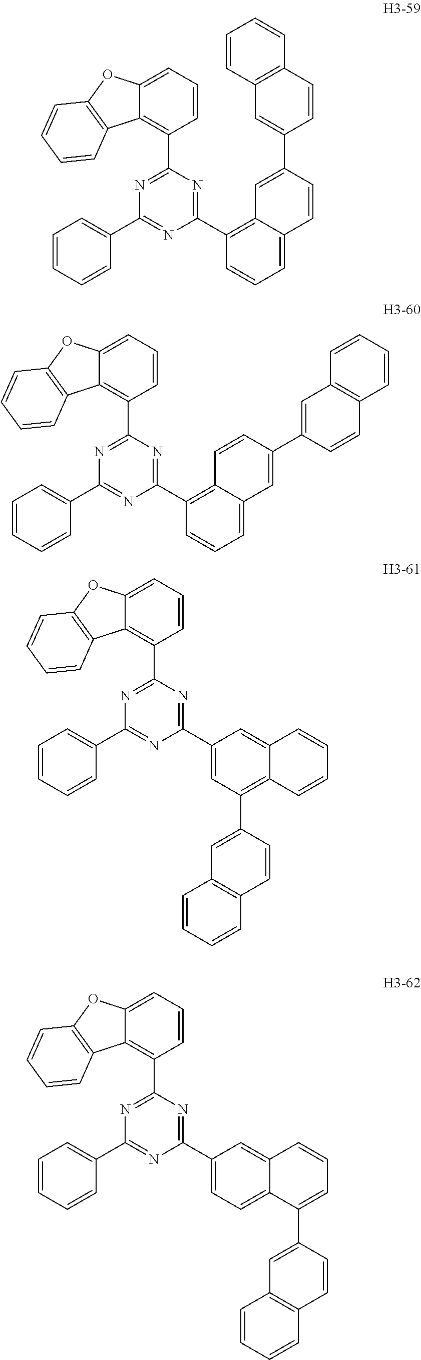 [SMILES: c1ccc(-c2nc(-c3cccc4ccc(-c5ccc6ccccc6c5)cc34)nc(-c3cccc4oc5ccccc5c34)n2)cc1 ; c1ccc(-c2nc(-c3cccc4cc(-c5ccc6ccccc6c5)ccc34)nc(-c3cccc4oc5ccccc5c34)n2)cc1 ; c1ccc(-c2nc(-c3cc(-c4ccc5ccccc5c4)c4ccccc4c3)nc(-c3cccc4oc5ccccc5c34)n2)cc1 ; c1ccc(-c2nc(-c3ccc4c(-c5ccc6ccccc6c5)cccc4c3)nc(-c3cccc4oc5ccccc5c34)n2)cc1] 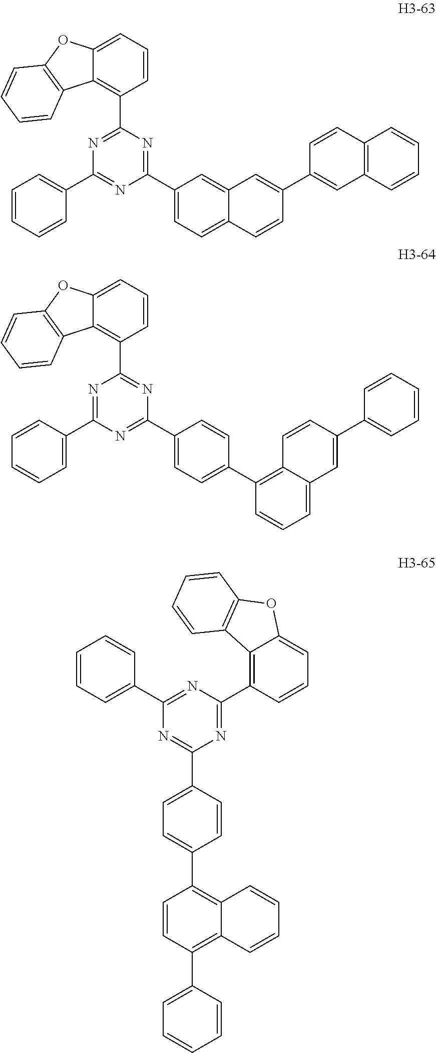 [SMILES: c1ccc(-c2nc(-c3ccc4ccc(-c5ccc6ccccc6c5)cc4c3)nc(-c3cccc4oc5ccccc5c34)n2)cc1 ; c1ccc(-c2ccc3c(-c4ccc(-c5nc(-c6ccccc6)nc(-c6cccc7oc8ccccc8c67)n5)cc4)cccc3c2)cc1 ; c1ccc(-c2nc(-c3ccc(-c4ccc(-c5ccccc5)c5ccccc45)cc3)nc(-c3cccc4oc5ccccc5c34)n2)cc1] 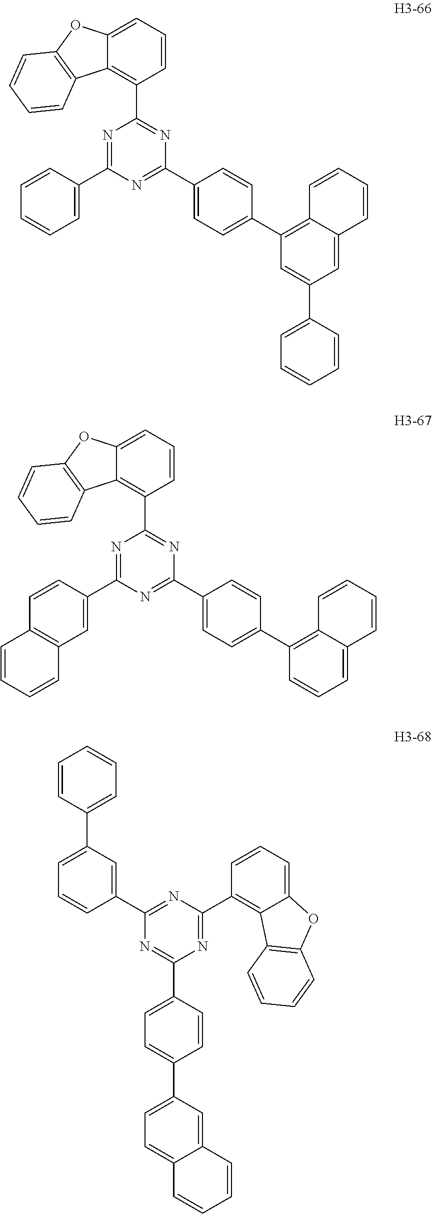 [SMILES: c1ccc(-c2cc(-c3ccc(-c4nc(-c5ccccc5)nc(-c5cccc6oc7ccccc7c56)n4)cc3)c3ccccc3c2)cc1 ; c1ccc2cc(-c3nc(-c4ccc(-c5cccc6ccccc56)cc4)nc(-c4cccc5oc6ccccc6c45)n3)ccc2c1 ; c1ccc(-c2cccc(-c3nc(-c4ccc(-c5ccc6ccccc6c5)cc4)nc(-c4cccc5oc6ccccc6c45)n3)c2)cc1] 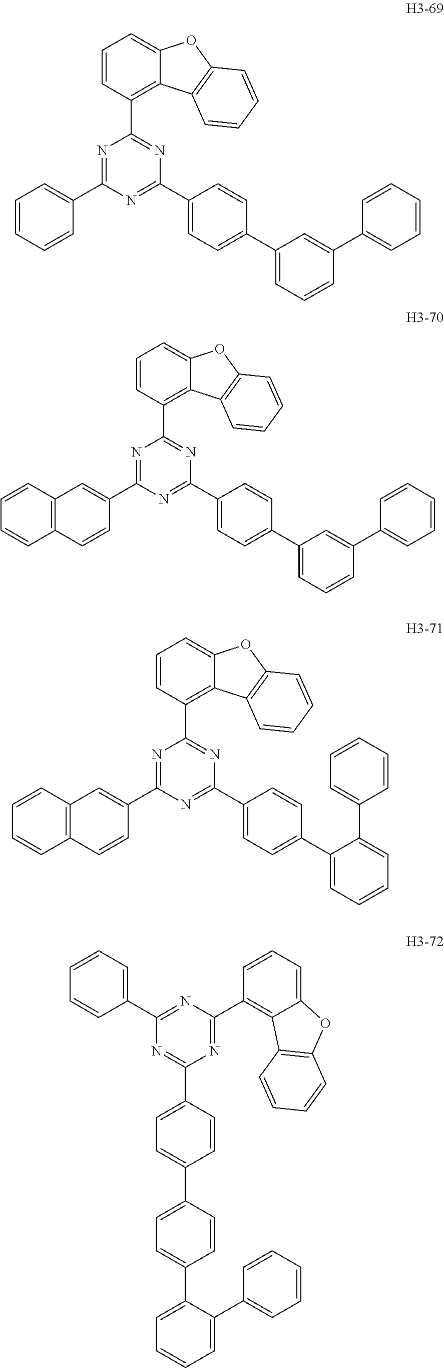 [SMILES: c1ccc(-c2cccc(-c3ccc(-c4nc(-c5ccccc5)nc(-c5cccc6oc7ccccc7c56)n4)cc3)c2)cc1 ; c1ccc(-c2cccc(-c3ccc(-c4nc(-c5ccc6ccccc6c5)nc(-c5cccc6oc7ccccc7c56)n4)cc3)c2)cc1 ; c1ccc(-c2ccccc2-c2ccc(-c3nc(-c4ccc5ccccc5c4)nc(-c4cccc5oc6ccccc6c45)n3)cc2)cc1 ; c1ccc(-c2nc(-c3ccc(-c4ccc(-c5ccccc5-c5ccccc5)cc4)cc3)nc(-c3cccc4oc5ccccc5c34)n2)cc1] 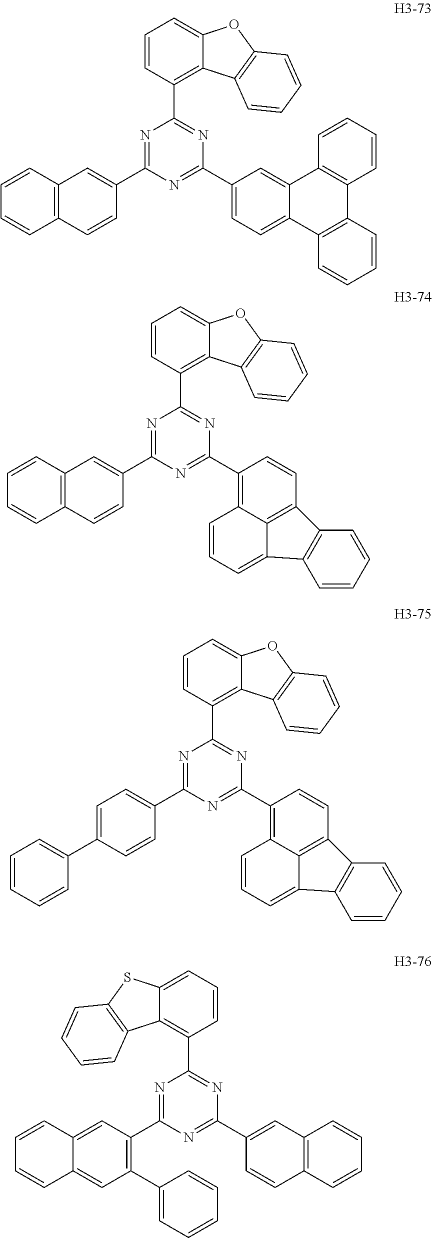 [SMILES: c1ccc2cc(-c3nc(-c4ccc5c6ccccc6c6ccccc6c5c4)nc(-c4cccc5oc6ccccc6c45)n3)ccc2c1 ; c1ccc2c(c1)-c1cccc3c(-c4nc(-c5ccc6ccccc6c5)nc(-c5cccc6oc7ccccc7c56)n4)ccc-2c13 ; c1ccc(-c2ccc(-c3nc(-c4ccc5c6c(cccc46)-c4ccccc4-5)nc(-c4cccc5oc6ccccc6c45)n3)cc2)cc1 ; c1ccc(-c2cc3ccccc3cc2-c2nc(-c3ccc4ccccc4c3)nc(-c3cccc4sc5ccccc5c34)n2)cc1] 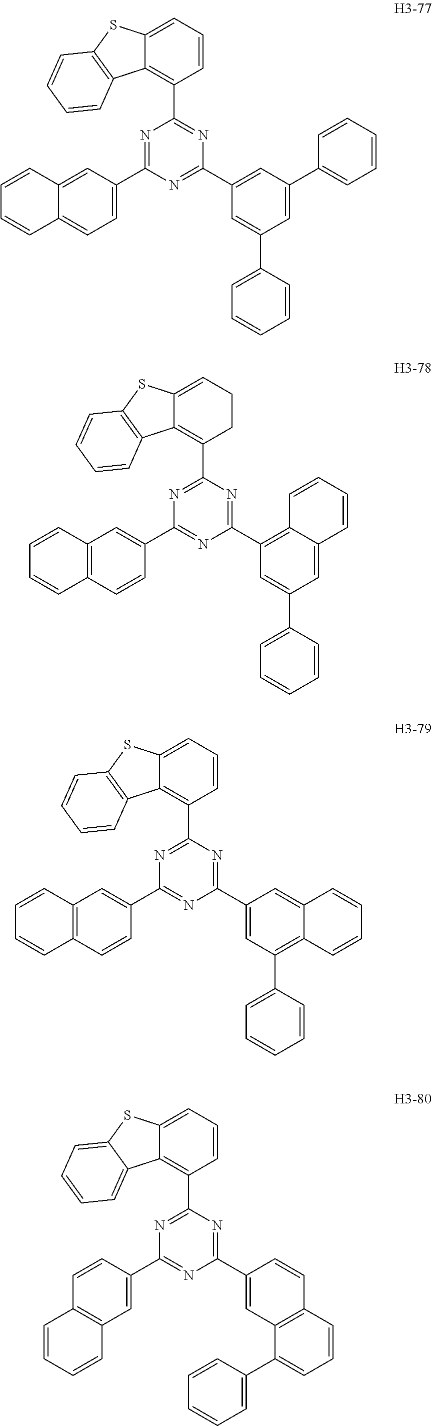 [SMILES: c1ccc(-c2cc(-c3ccccc3)cc(-c3nc(-c4ccc5ccccc5c4)nc(-c4cccc5sc6ccccc6c45)n3)c2)cc1 ; C1=c2sc3ccccc3c2=C(c2nc(-c3ccc4ccccc4c3)nc(-c3cc(-c4ccccc4)cc4ccccc34)n2)CC1 ; c1ccc(-c2cc(-c3nc(-c4ccc5ccccc5c4)nc(-c4cccc5sc6ccccc6c45)n3)cc3ccccc23)cc1 ; c1ccc(-c2cccc3ccc(-c4nc(-c5ccc6ccccc6c5)nc(-c5cccc6sc7ccccc7c56)n4)cc23)cc1] 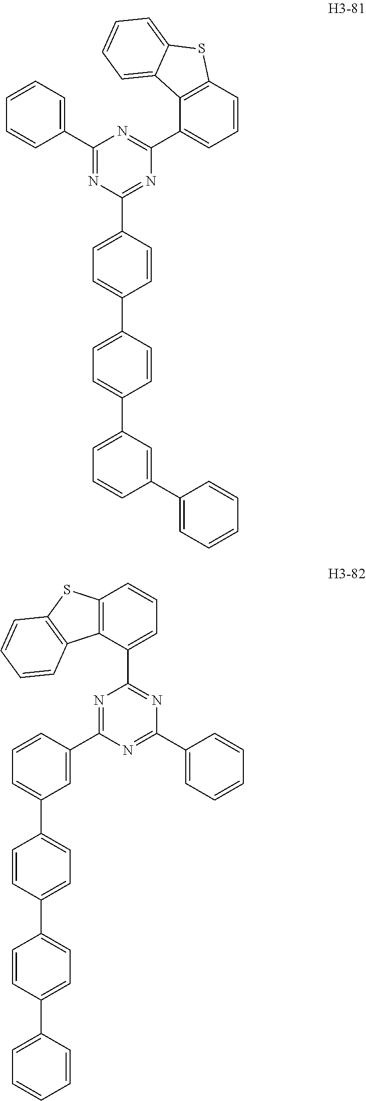 [SMILES: c1ccc(-c2cccc(-c3ccc(-c4ccc(-c5nc(-c6ccccc6)nc(-c6cccc7sc8ccccc8c67)n5)cc4)cc3)c2)cc1 ; c1ccc(-c2ccc(-c3ccc(-c4cccc(-c5nc(-c6ccccc6)nc(-c6cccc7sc8ccccc8c67)n5)c4)cc3)cc2)cc1] 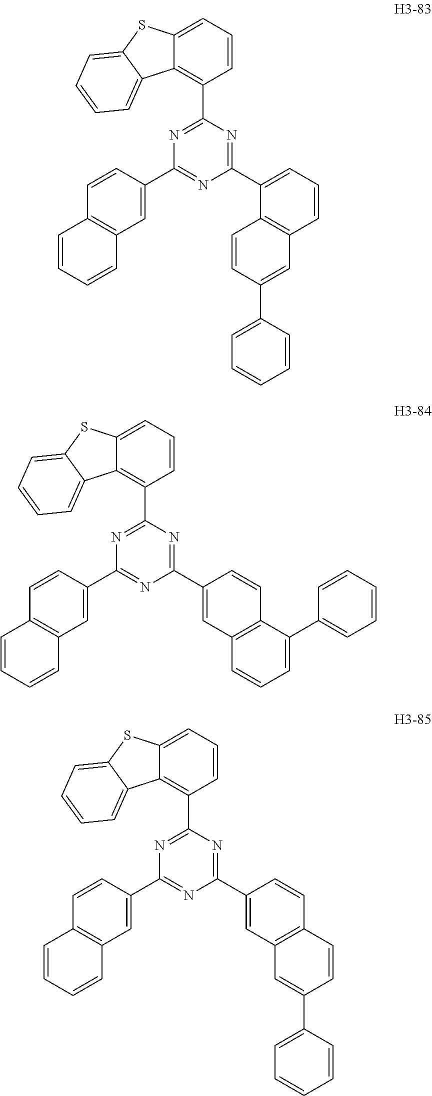 [SMILES: c1ccc(-c2ccc3c(-c4nc(-c5ccc6ccccc6c5)nc(-c5cccc6sc7ccccc7c56)n4)cccc3c2)cc1 ; c1ccc(-c2cccc3cc(-c4nc(-c5ccc6ccccc6c5)nc(-c5cccc6sc7ccccc7c56)n4)ccc23)cc1 ; c1ccc(-c2ccc3ccc(-c4nc(-c5ccc6ccccc6c5)nc(-c5cccc6sc7ccccc7c56)n4)cc3c2)cc1] 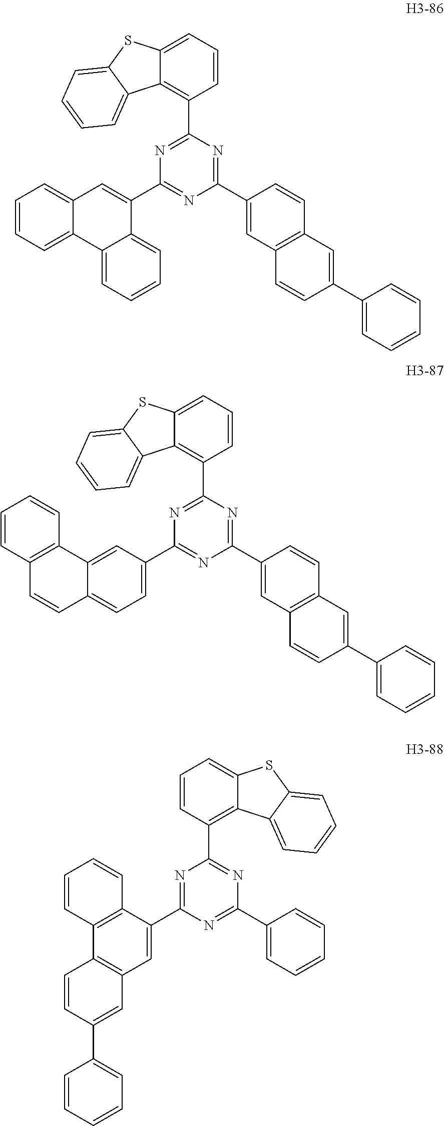 [SMILES: c1ccc(-c2ccc3cc(-c4nc(-c5cc6ccccc6c6ccccc56)nc(-c5cccc6sc7ccccc7c56)n4)ccc3c2)cc1 ; c1ccc(-c2ccc3cc(-c4nc(-c5ccc6ccc7ccccc7c6c5)nc(-c5cccc6sc7ccccc7c56)n4)ccc3c2)cc1 ; c1ccc(-c2ccc3c(c2)cc(-c2nc(-c4ccccc4)nc(-c4cccc5sc6ccccc6c45)n2)c2ccccc23)cc1] 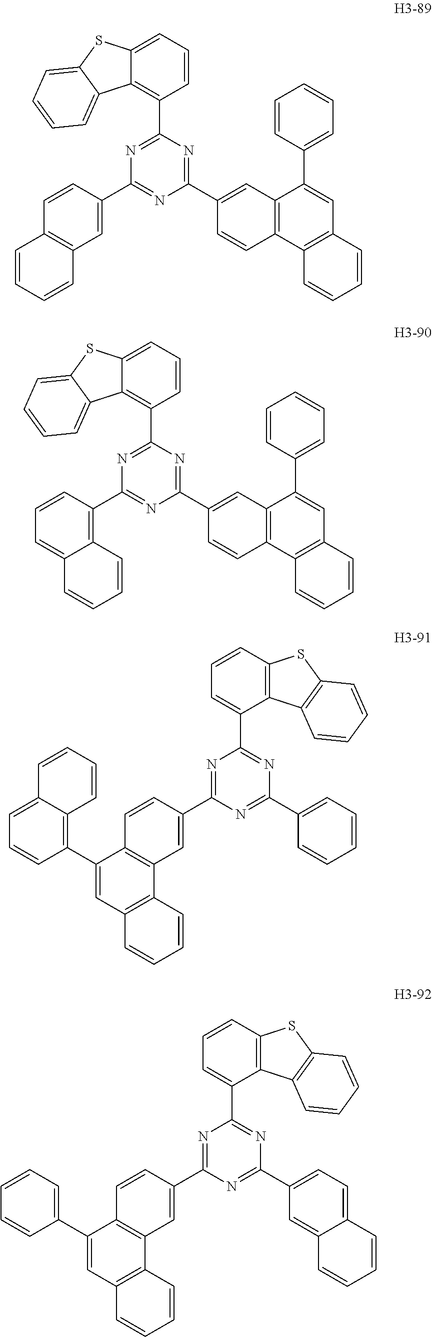 [SMILES: c1ccc(-c2cc3ccccc3c3ccc(-c4nc(-c5ccc6ccccc6c5)nc(-c5cccc6sc7ccccc7c56)n4)cc23)cc1 ; c1ccc(-c2cc3ccccc3c3ccc(-c4nc(-c5cccc6ccccc56)nc(-c5cccc6sc7ccccc7c56)n4)cc23)cc1 ; c1ccc(-c2nc(-c3ccc4c(-c5cccc6ccccc56)cc5ccccc5c4c3)nc(-c3cccc4sc5ccccc5c34)n2)cc1 ; c1ccc(-c2cc3ccccc3c3cc(-c4nc(-c5ccc6ccccc6c5)nc(-c5cccc6sc7ccccc7c56)n4)ccc23)cc1] 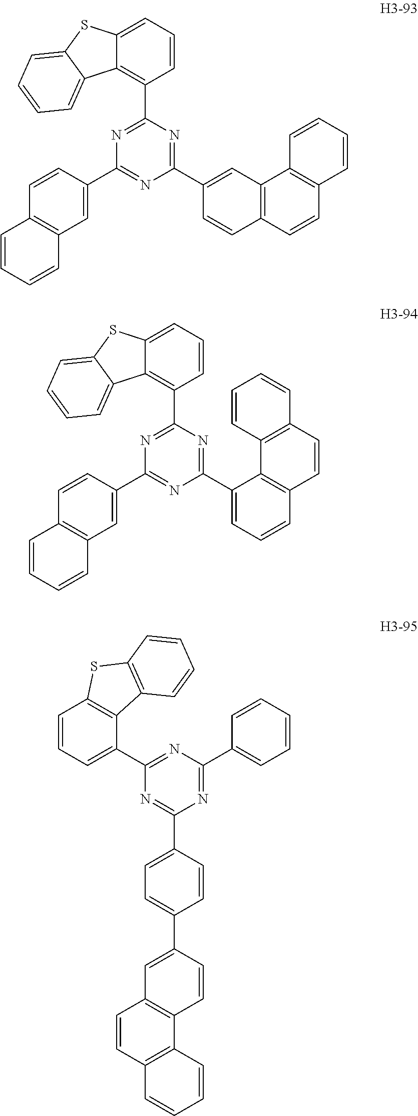 [SMILES: c1ccc2cc(-c3nc(-c4ccc5ccc6ccccc6c5c4)nc(-c4cccc5sc6ccccc6c45)n3)ccc2c1 ; c1ccc2cc(-c3nc(-c4cccc5ccc6ccccc6c45)nc(-c4cccc5sc6ccccc6c45)n3)ccc2c1 ; c1ccc(-c2nc(-c3ccc(-c4ccc5c(ccc6ccccc65)c4)cc3)nc(-c3cccc4sc5ccccc5c34)n2)cc1] 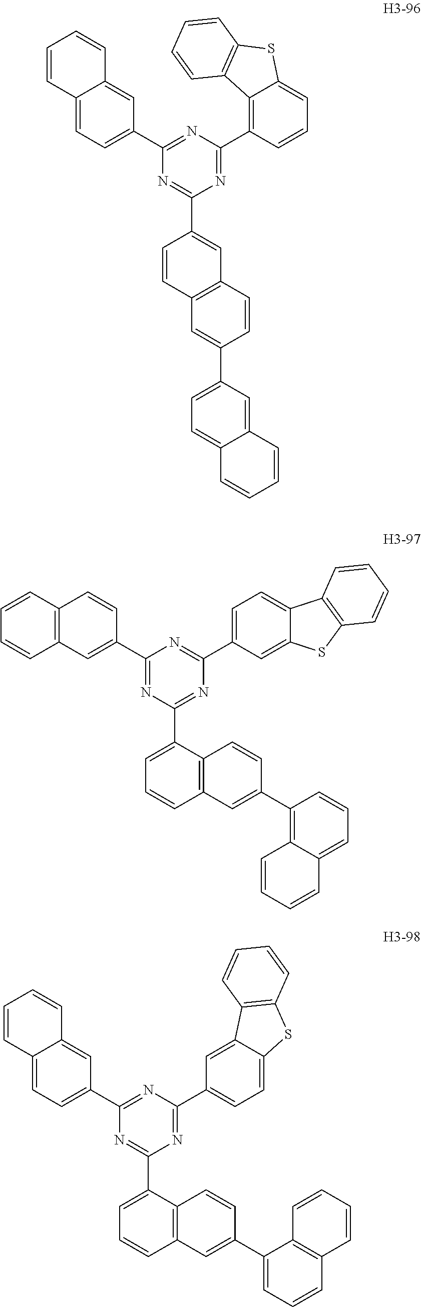 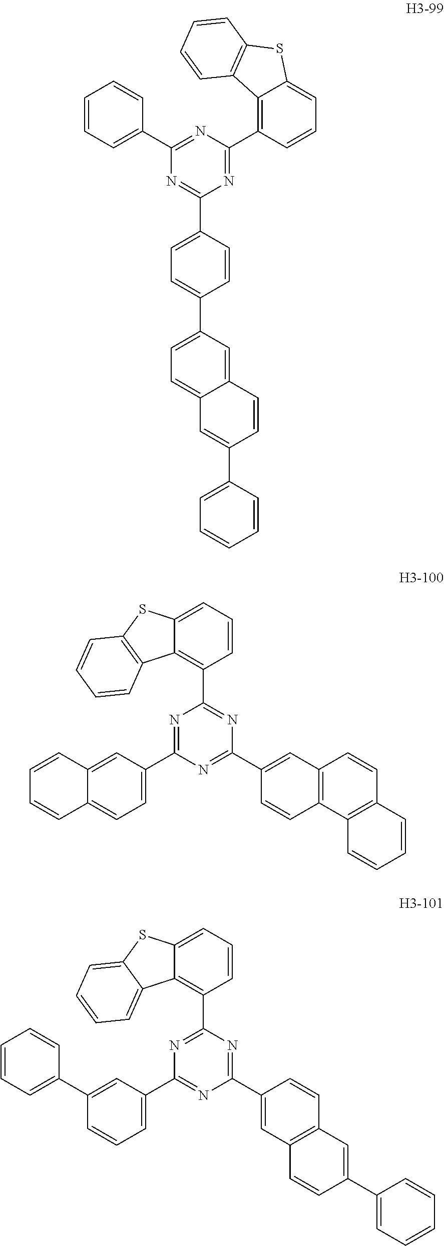 [SMILES: c1ccc(-c2ccc3cc(-c4ccc(-c5nc(-c6ccccc6)nc(-c6cccc7sc8ccccc8c67)n5)cc4)ccc3c2)cc1 ; c1ccc2cc(-c3nc(-c4ccc5c(ccc6ccccc65)c4)nc(-c4cccc5sc6ccccc6c45)n3)ccc2c1 ; c1ccc(-c2cccc(-c3nc(-c4ccc5cc(-c6ccccc6)ccc5c4)nc(-c4cccc5sc6ccccc6c45)n3)c2)cc1] 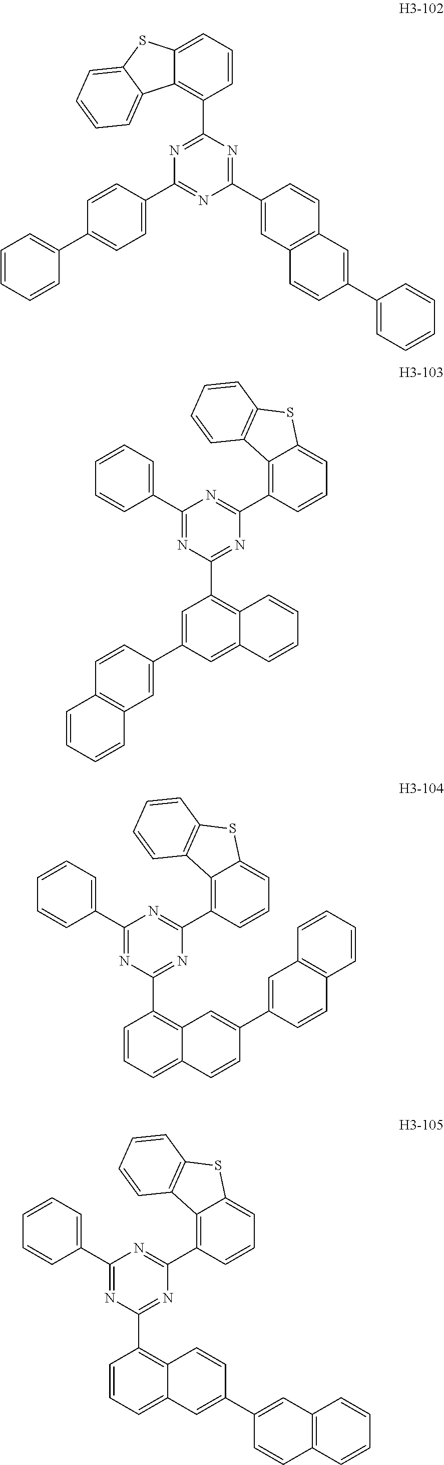 [SMILES: c1ccc(-c2ccc(-c3nc(-c4ccc5cc(-c6ccccc6)ccc5c4)nc(-c4cccc5sc6ccccc6c45)n3)cc2)cc1 ; c1ccc(-c2nc(-c3cc(-c4ccc5ccccc5c4)cc4ccccc34)nc(-c3cccc4sc5ccccc5c34)n2)cc1 ; c1ccc(-c2nc(-c3cccc4ccc(-c5ccc6ccccc6c5)cc34)nc(-c3cccc4sc5ccccc5c34)n2)cc1 ; c1ccc(-c2nc(-c3cccc4cc(-c5ccc6ccccc6c5)ccc34)nc(-c3cccc4sc5ccccc5c34)n2)cc1] 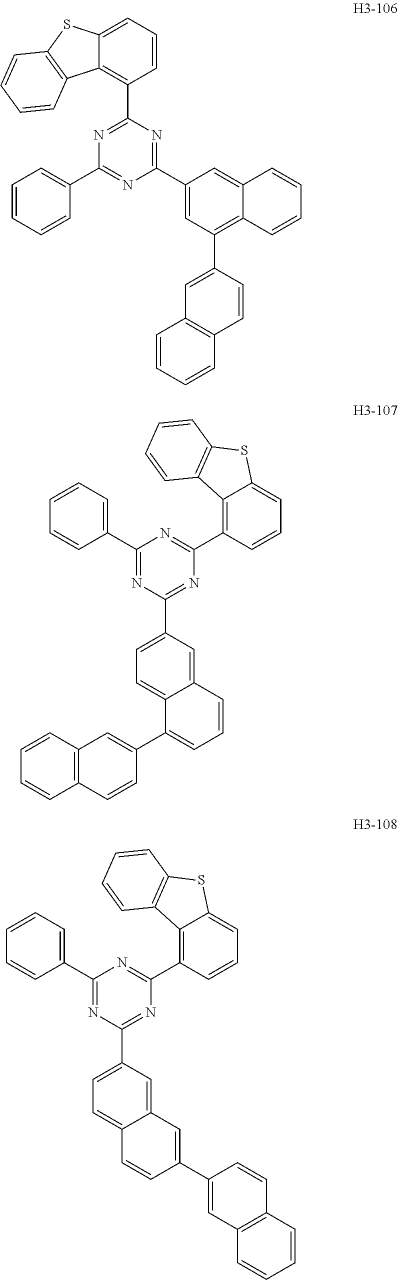 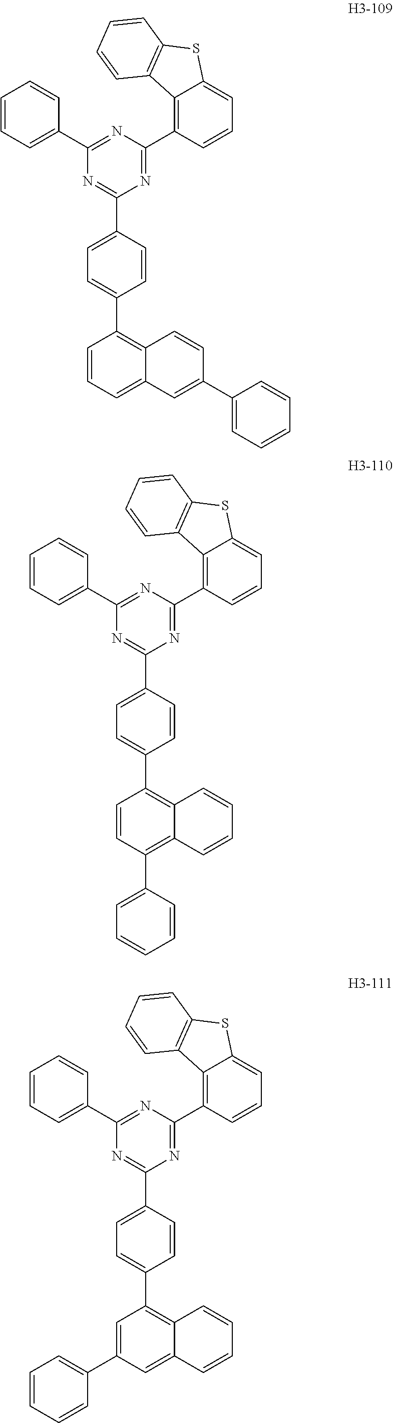 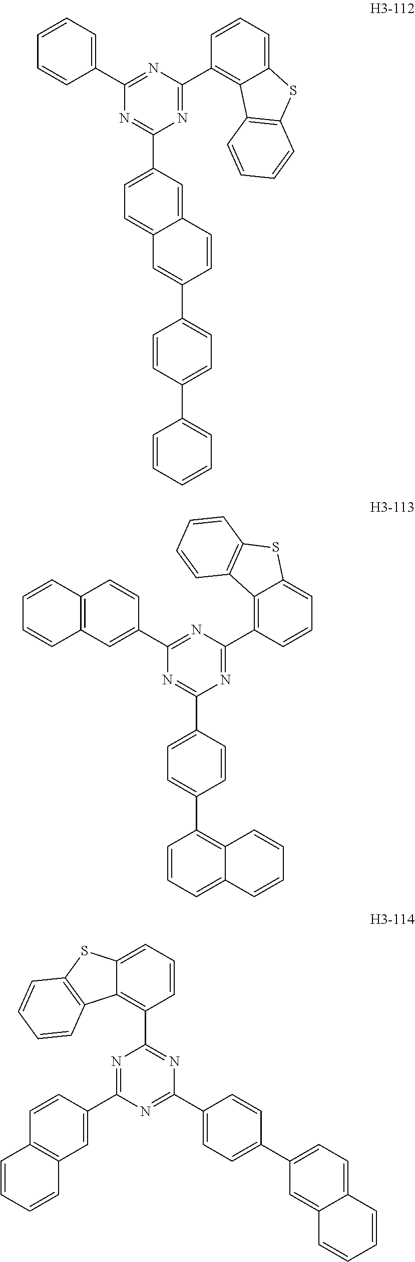 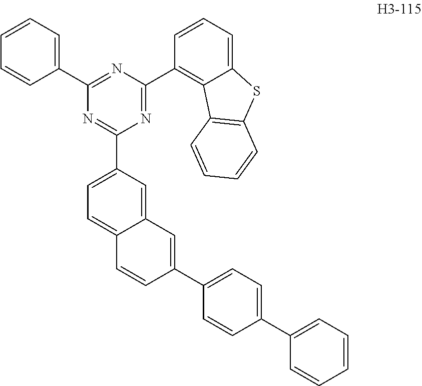 [SMILES: c1ccc(-c2ccc(-c3ccc4ccc(-c5nc(-c6ccccc6)nc(-c6cccc7sc8ccccc8c67)n5)cc4c3)cc2)cc1] 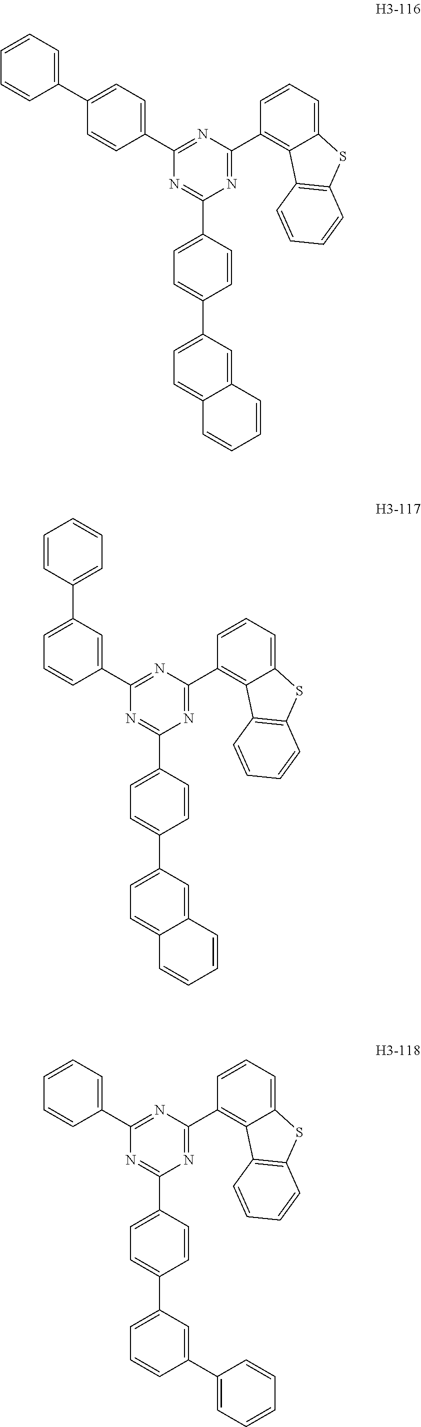 [SMILES: c1ccc(-c2ccc(-c3nc(-c4ccc(-c5ccc6ccccc6c5)cc4)nc(-c4cccc5sc6ccccc6c45)n3)cc2)cc1 ; c1ccc(-c2cccc(-c3nc(-c4ccc(-c5ccc6ccccc6c5)cc4)nc(-c4cccc5sc6ccccc6c45)n3)c2)cc1 ; c1ccc(-c2cccc(-c3ccc(-c4nc(-c5ccccc5)nc(-c5cccc6sc7ccccc7c56)n4)cc3)c2)cc1] 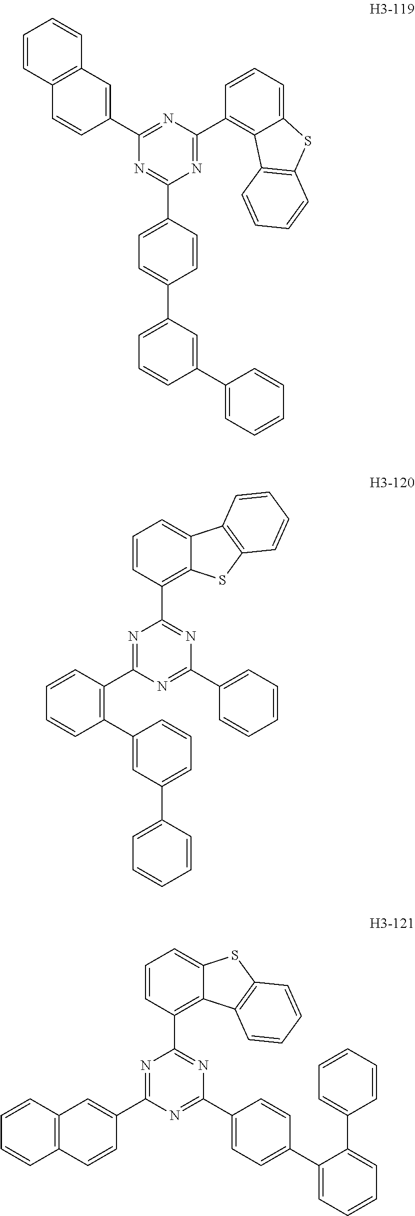 [SMILES: c1ccc(-c2cccc(-c3ccc(-c4nc(-c5ccc6ccccc6c5)nc(-c5cccc6sc7ccccc7c56)n4)cc3)c2)cc1 ; c1ccc(-c2cccc(-c3ccccc3-c3nc(-c4ccccc4)nc(-c4cccc5c4sc4ccccc45)n3)c2)cc1 ; c1ccc(-c2ccccc2-c2ccc(-c3nc(-c4ccc5ccccc5c4)nc(-c4cccc5sc6ccccc6c45)n3)cc2)cc1] 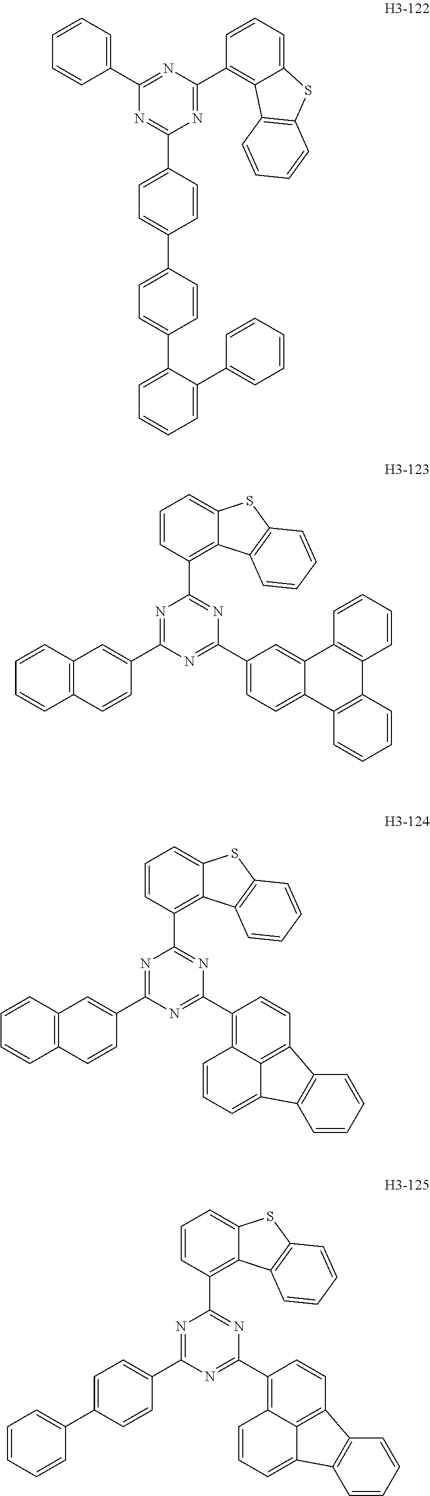 [SMILES: c1ccc(-c2nc(-c3ccc(-c4ccc(-c5ccccc5-c5ccccc5)cc4)cc3)nc(-c3cccc4sc5ccccc5c34)n2)cc1 ; c1ccc2cc(-c3nc(-c4ccc5c6ccccc6c6ccccc6c5c4)nc(-c4cccc5sc6ccccc6c45)n3)ccc2c1 ; c1ccc2c(c1)-c1cccc3c(-c4nc(-c5ccc6ccccc6c5)nc(-c5cccc6sc7ccccc7c56)n4)ccc-2c13 ; c1ccc(-c2ccc(-c3nc(-c4ccc5c6c(cccc46)-c4ccccc4-5)nc(-c4cccc5sc6ccccc6c45)n3)cc2)cc1] 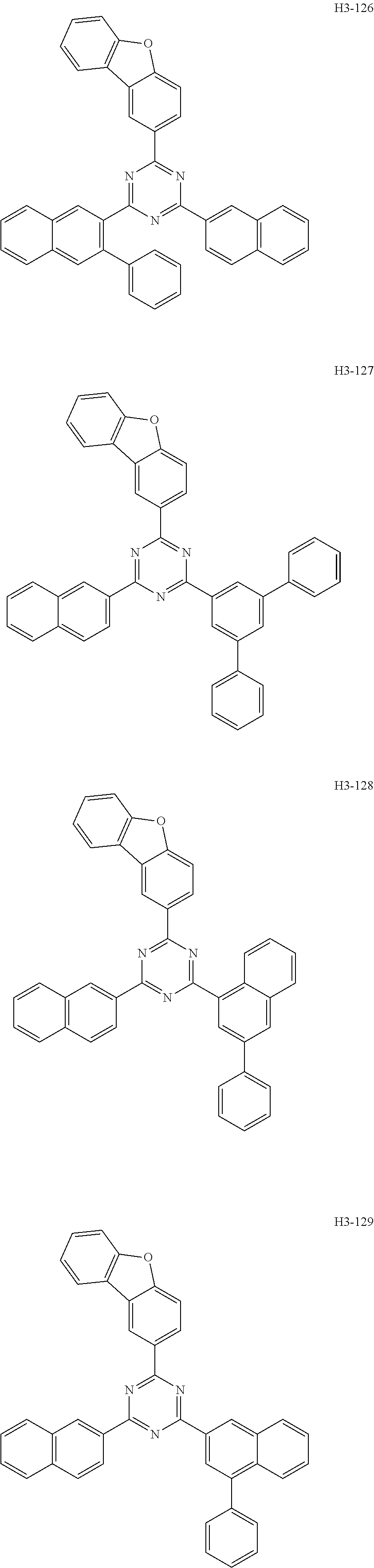 [SMILES: c1ccc(-c2cc3ccccc3cc2-c2nc(-c3ccc4ccccc4c3)nc(-c3ccc4oc5ccccc5c4c3)n2)cc1 ; c1ccc(-c2cc(-c3ccccc3)cc(-c3nc(-c4ccc5ccccc5c4)nc(-c4ccc5oc6ccccc6c5c4)n3)c2)cc1 ; c1ccc(-c2cc(-c3nc(-c4ccc5ccccc5c4)nc(-c4ccc5oc6ccccc6c5c4)n3)c3ccccc3c2)cc1 ; c1ccc(-c2cc(-c3nc(-c4ccc5ccccc5c4)nc(-c4ccc5oc6ccccc6c5c4)n3)cc3ccccc23)cc1] 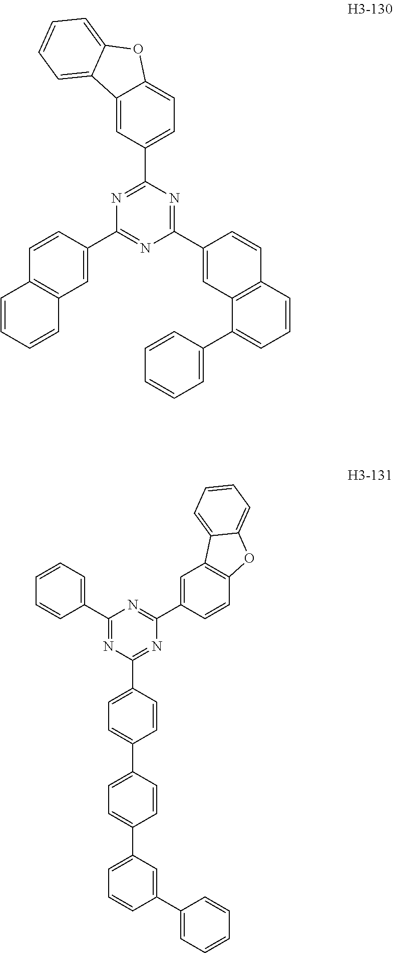 [SMILES: c1ccc(-c2cccc3ccc(-c4nc(-c5ccc6ccccc6c5)nc(-c5ccc6oc7ccccc7c6c5)n4)cc23)cc1 ; c1ccc(-c2cccc(-c3ccc(-c4ccc(-c5nc(-c6ccccc6)nc(-c6ccc7oc8ccccc8c7c6)n5)cc4)cc3)c2)cc1] 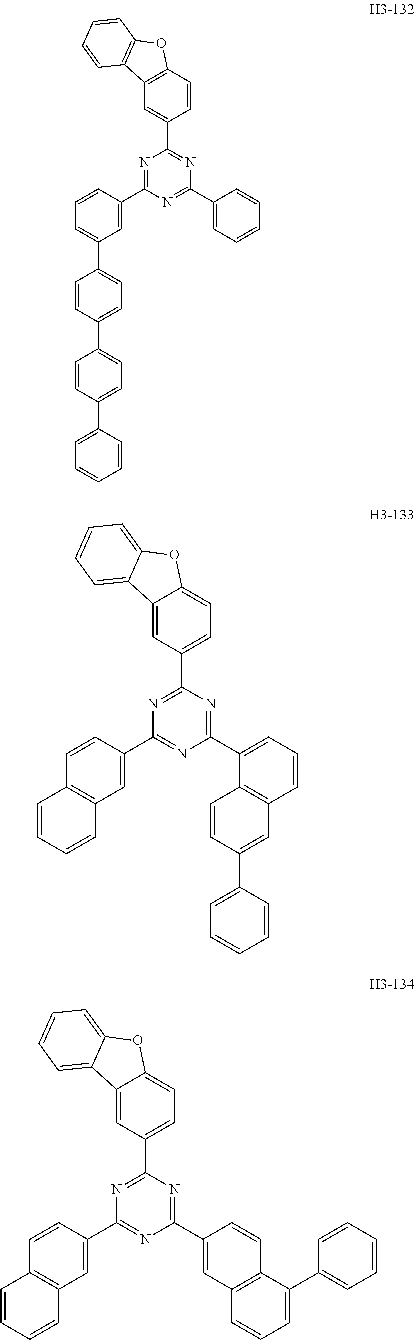 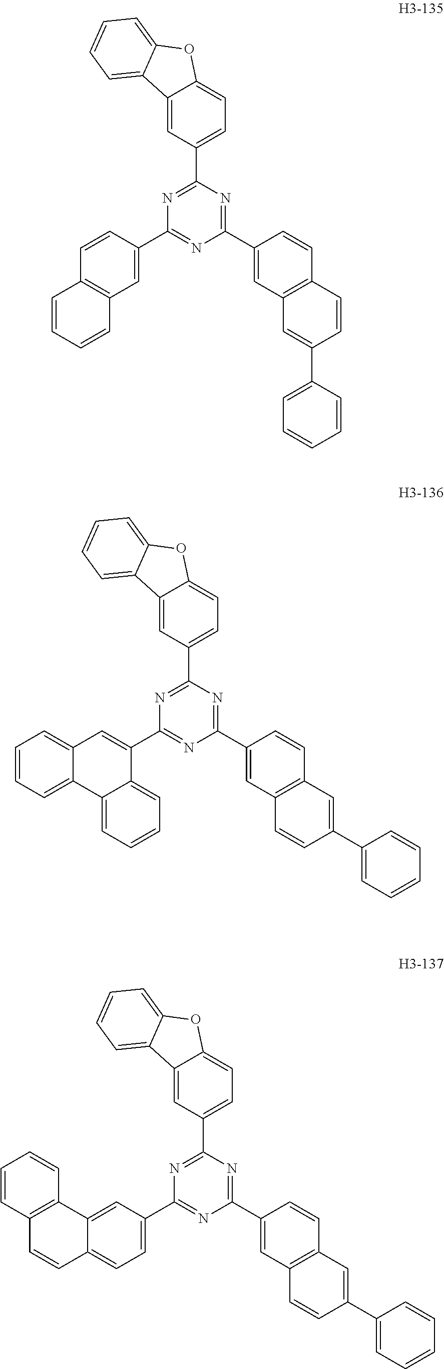 [SMILES: c1ccc(-c2ccc3ccc(-c4nc(-c5ccc6ccccc6c5)nc(-c5ccc6oc7ccccc7c6c5)n4)cc3c2)cc1 ; c1ccc(-c2ccc3cc(-c4nc(-c5ccc6oc7ccccc7c6c5)nc(-c5cc6ccccc6c6ccccc56)n4)ccc3c2)cc1 ; c1ccc(-c2ccc3cc(-c4nc(-c5ccc6ccc7ccccc7c6c5)nc(-c5ccc6oc7ccccc7c6c5)n4)ccc3c2)cc1] 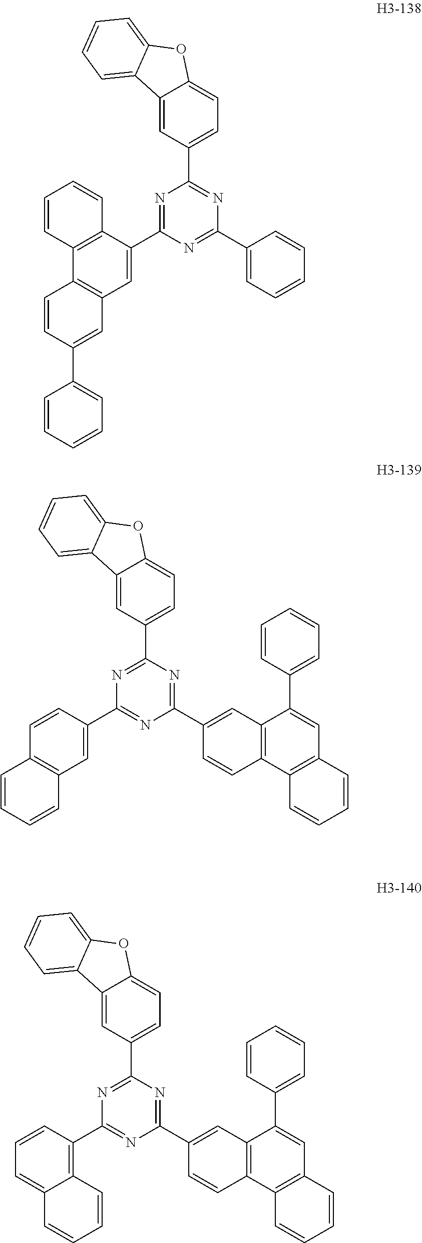 [SMILES: c1ccc(-c2ccc3c(c2)cc(-c2nc(-c4ccccc4)nc(-c4ccc5oc6ccccc6c5c4)n2)c2ccccc23)cc1 ; c1ccc(-c2cc3ccccc3c3ccc(-c4nc(-c5ccc6ccccc6c5)nc(-c5ccc6oc7ccccc7c6c5)n4)cc23)cc1 ; c1ccc(-c2cc3ccccc3c3ccc(-c4nc(-c5ccc6oc7ccccc7c6c5)nc(-c5cccc6ccccc56)n4)cc23)cc1] 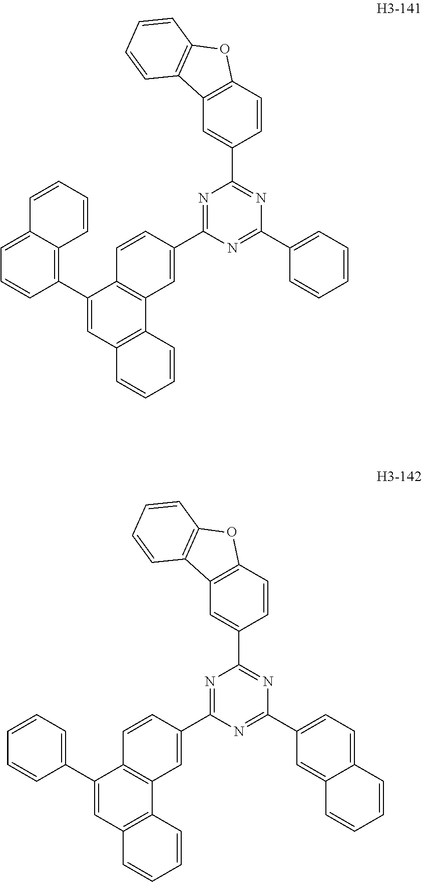 [SMILES: c1ccc(-c2nc(-c3ccc4oc5ccccc5c4c3)nc(-c3ccc4c(-c5cccc6ccccc56)cc5ccccc5c4c3)n2)cc1 ; c1ccc(-c2cc3ccccc3c3cc(-c4nc(-c5ccc6ccccc6c5)nc(-c5ccc6oc7ccccc7c6c5)n4)ccc23)cc1] 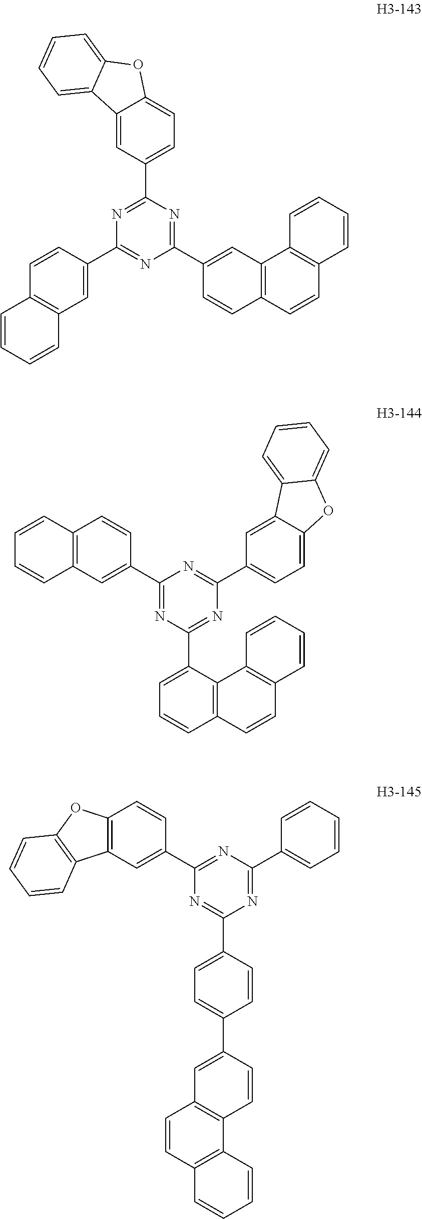 [SMILES: c1ccc2cc(-c3nc(-c4ccc5ccc6ccccc6c5c4)nc(-c4ccc5oc6ccccc6c5c4)n3)ccc2c1 ; c1ccc2cc(-c3nc(-c4ccc5oc6ccccc6c5c4)nc(-c4cccc5ccc6ccccc6c45)n3)ccc2c1 ; c1ccc(-c2nc(-c3ccc(-c4ccc5c(ccc6ccccc65)c4)cc3)nc(-c3ccc4oc5ccccc5c4c3)n2)cc1] 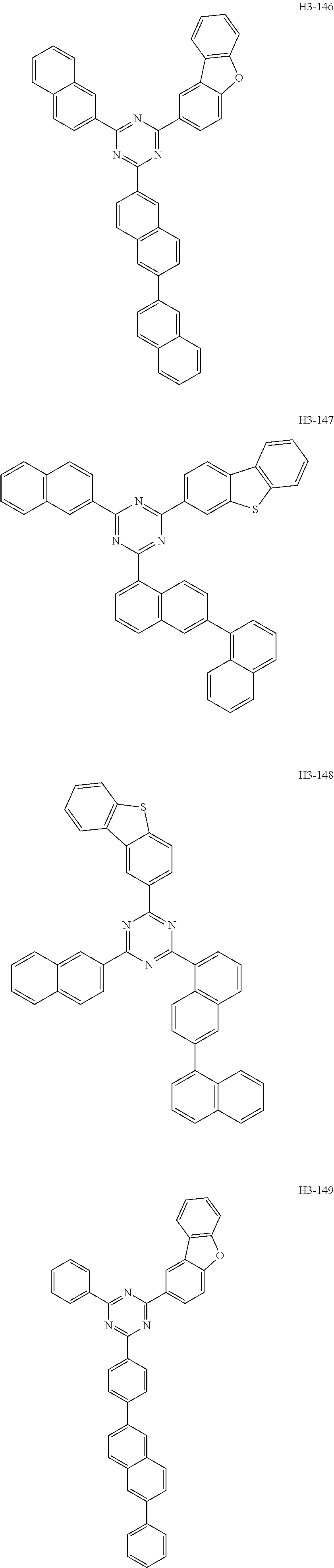 [SMILES: c1ccc2cc(-c3ccc4cc(-c5nc(-c6ccc7ccccc7c6)nc(-c6ccc7oc8ccccc8c7c6)n5)ccc4c3)ccc2c1 ; c1ccc2cc(-c3nc(-c4ccc5c(c4)sc4ccccc45)nc(-c4cccc5cc(-c6cccc7ccccc67)ccc45)n3)ccc2c1 ; c1ccc2cc(-c3nc(-c4ccc5sc6ccccc6c5c4)nc(-c4cccc5cc(-c6cccc7ccccc67)ccc45)n3)ccc2c1 ; c1ccc(-c2ccc3cc(-c4ccc(-c5nc(-c6ccccc6)nc(-c6ccc7oc8ccccc8c7c6)n5)cc4)ccc3c2)cc1] 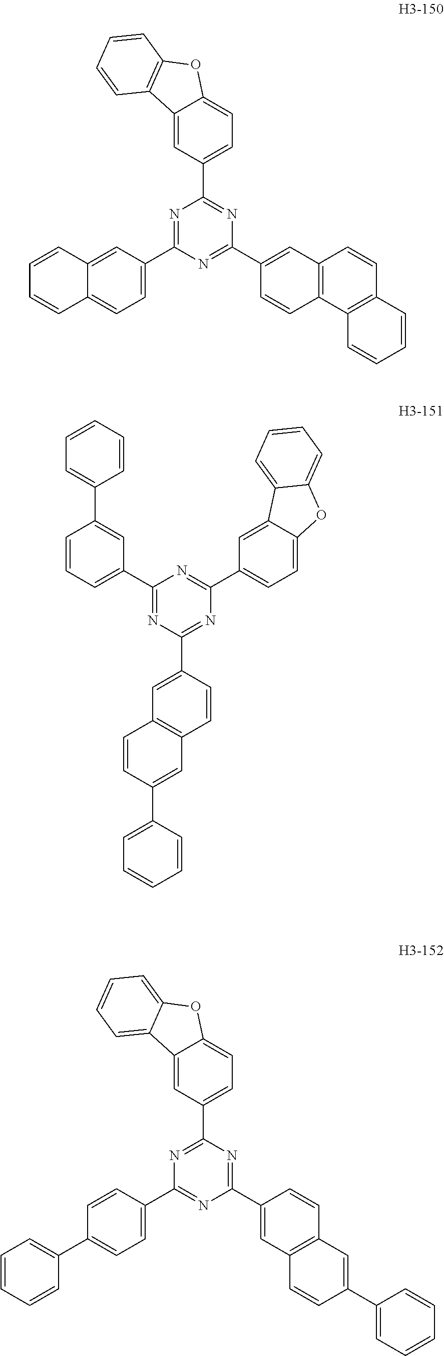 [SMILES: c1ccc2cc(-c3nc(-c4ccc5c(ccc6ccccc65)c4)nc(-c4ccc5oc6ccccc6c5c4)n3)ccc2c1 ; c1ccc(-c2cccc(-c3nc(-c4ccc5cc(-c6ccccc6)ccc5c4)nc(-c4ccc5oc6ccccc6c5c4)n3)c2)cc1 ; c1ccc(-c2ccc(-c3nc(-c4ccc5cc(-c6ccccc6)ccc5c4)nc(-c4ccc5oc6ccccc6c5c4)n3)cc2)cc1] 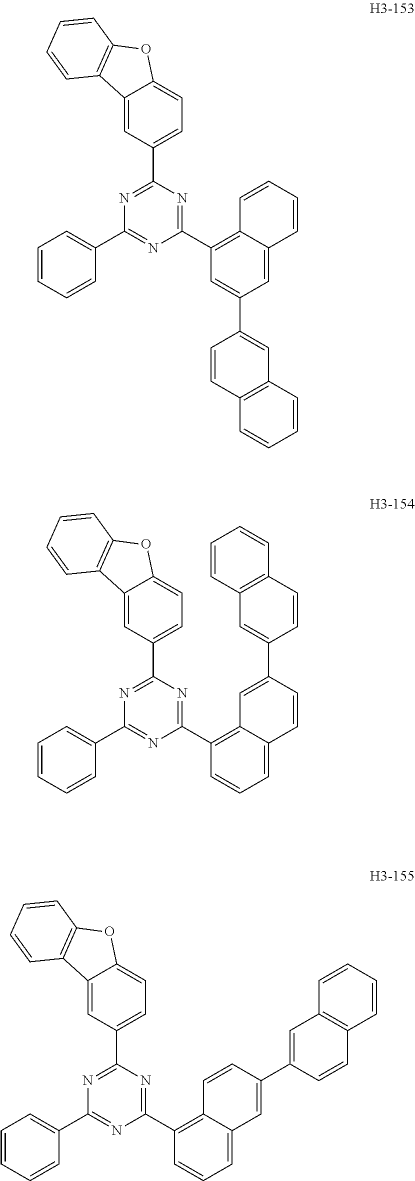 [SMILES: c1ccc(-c2nc(-c3ccc4oc5ccccc5c4c3)nc(-c3cc(-c4ccc5ccccc5c4)cc4ccccc34)n2)cc1 ; c1ccc(-c2nc(-c3ccc4oc5ccccc5c4c3)nc(-c3cccc4ccc(-c5ccc6ccccc6c5)cc34)n2)cc1 ; c1ccc(-c2nc(-c3ccc4oc5ccccc5c4c3)nc(-c3cccc4cc(-c5ccc6ccccc6c5)ccc34)n2)cc1] 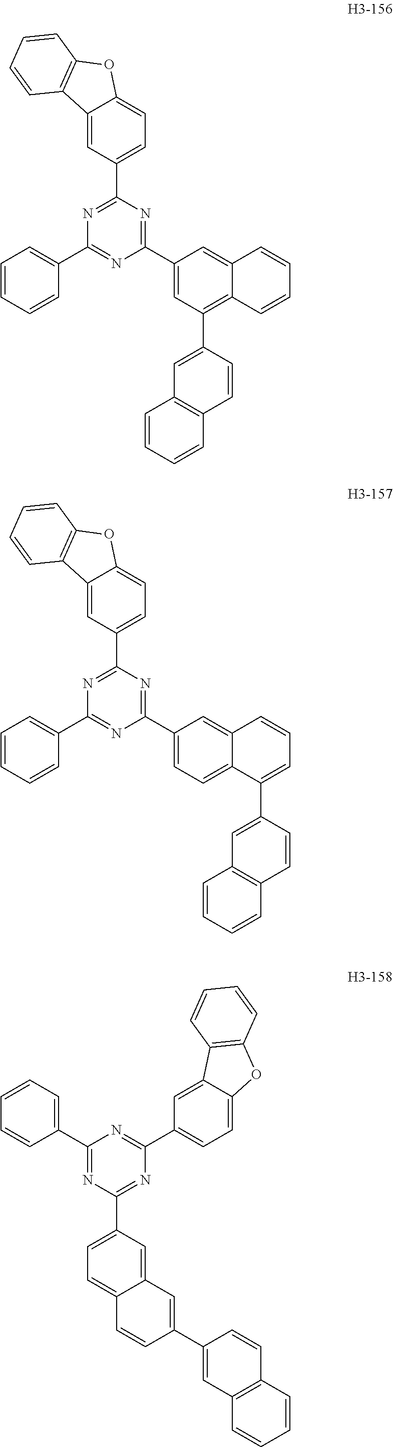 [SMILES: c1ccc(-c2nc(-c3cc(-c4ccc5ccccc5c4)c4ccccc4c3)nc(-c3ccc4oc5ccccc5c4c3)n2)cc1 ; c1ccc(-c2nc(-c3ccc4c(-c5ccc6ccccc6c5)cccc4c3)nc(-c3ccc4oc5ccccc5c4c3)n2)cc1 ; c1ccc(-c2nc(-c3ccc4ccc(-c5ccc6ccccc6c5)cc4c3)nc(-c3ccc4oc5ccccc5c4c3)n2)cc1] 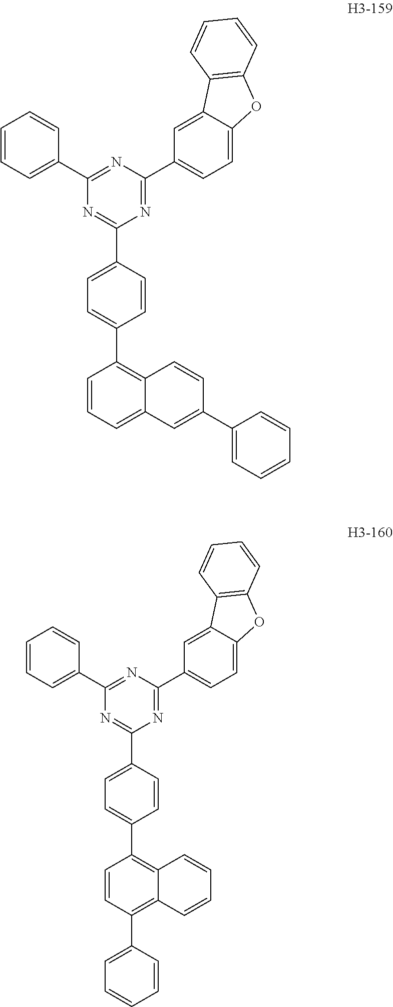 [SMILES: c1ccc(-c2ccc3c(-c4ccc(-c5nc(-c6ccccc6)nc(-c6ccc7oc8ccccc8c7c6)n5)cc4)cccc3c2)cc1 ; c1ccc(-c2nc(-c3ccc(-c4ccc(-c5ccccc5)c5ccccc45)cc3)nc(-c3ccc4oc5ccccc5c4c3)n2)cc1] 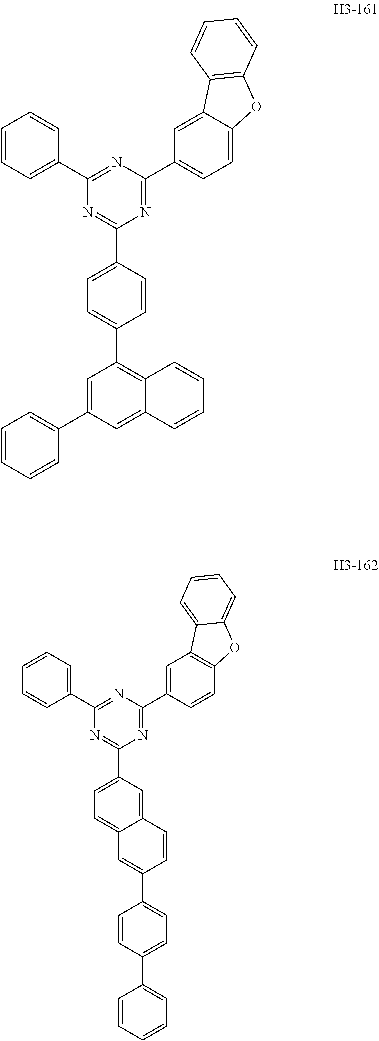 [SMILES: c1ccc(-c2cc(-c3ccc(-c4nc(-c5ccccc5)nc(-c5ccc6oc7ccccc7c6c5)n4)cc3)c3ccccc3c2)cc1 ; c1ccc(-c2ccc(-c3ccc4cc(-c5nc(-c6ccccc6)nc(-c6ccc7oc8ccccc8c7c6)n5)ccc4c3)cc2)cc1] 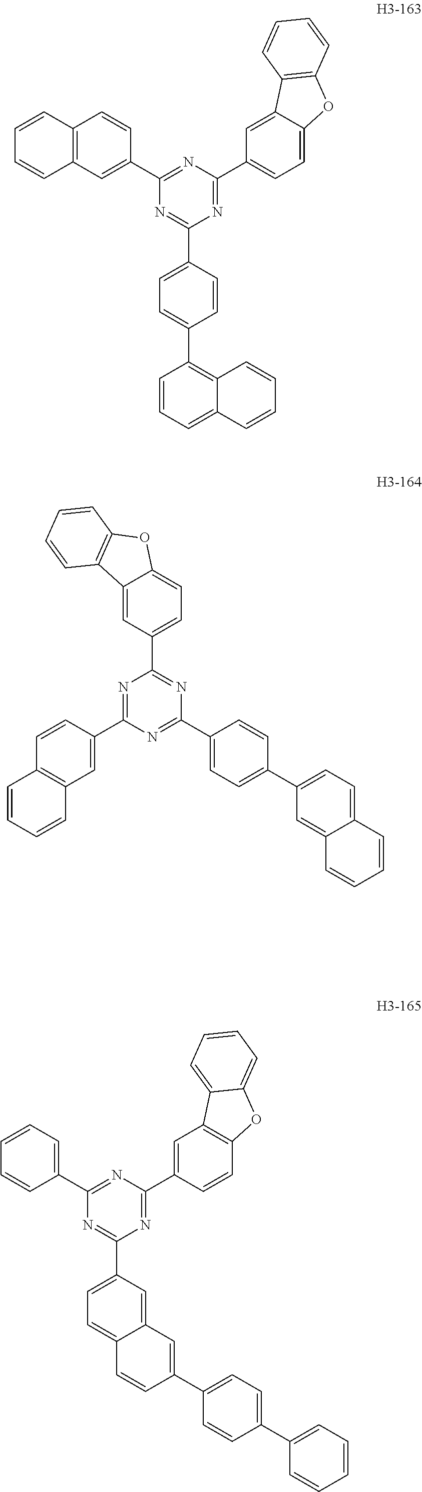 [SMILES: c1ccc2cc(-c3nc(-c4ccc(-c5cccc6ccccc56)cc4)nc(-c4ccc5oc6ccccc6c5c4)n3)ccc2c1 ; c1ccc2cc(-c3ccc(-c4nc(-c5ccc6ccccc6c5)nc(-c5ccc6oc7ccccc7c6c5)n4)cc3)ccc2c1 ; c1ccc(-c2ccc(-c3ccc4ccc(-c5nc(-c6ccccc6)nc(-c6ccc7oc8ccccc8c7c6)n5)cc4c3)cc2)cc1] 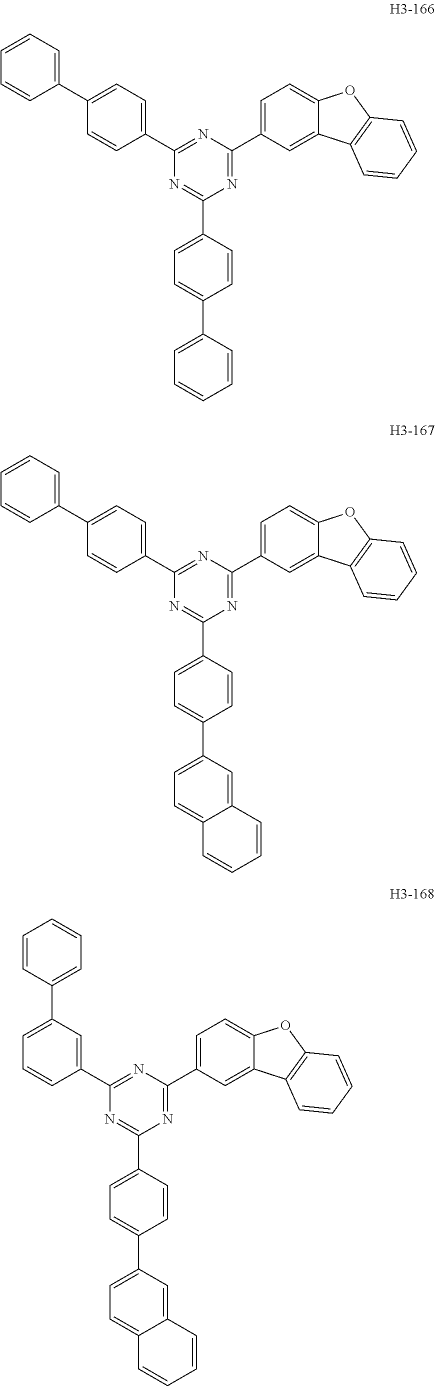 [SMILES: c1ccc(-c2ccc(-c3nc(-c4ccc(-c5ccccc5)cc4)nc(-c4ccc5oc6ccccc6c5c4)n3)cc2)cc1 ; c1ccc(-c2ccc(-c3nc(-c4ccc(-c5ccc6ccccc6c5)cc4)nc(-c4ccc5oc6ccccc6c5c4)n3)cc2)cc1 ; c1ccc(-c2cccc(-c3nc(-c4ccc(-c5ccc6ccccc6c5)cc4)nc(-c4ccc5oc6ccccc6c5c4)n3)c2)cc1] 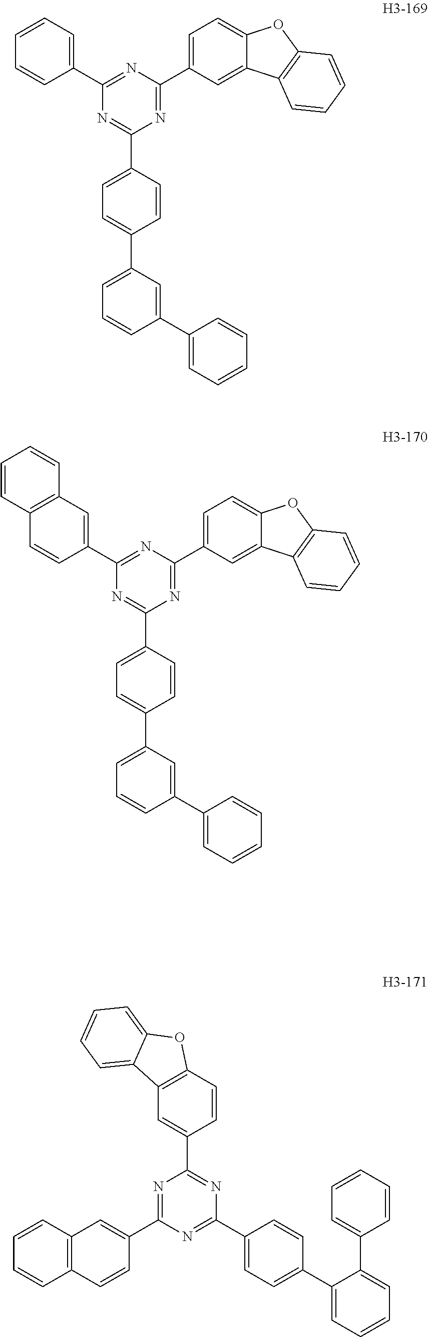 [SMILES: c1ccc(-c2cccc(-c3ccc(-c4nc(-c5ccccc5)nc(-c5ccc6oc7ccccc7c6c5)n4)cc3)c2)cc1 ; c1ccc(-c2cccc(-c3ccc(-c4nc(-c5ccc6ccccc6c5)nc(-c5ccc6oc7ccccc7c6c5)n4)cc3)c2)cc1 ; c1ccc(-c2ccccc2-c2ccc(-c3nc(-c4ccc5ccccc5c4)nc(-c4ccc5oc6ccccc6c5c4)n3)cc2)cc1] 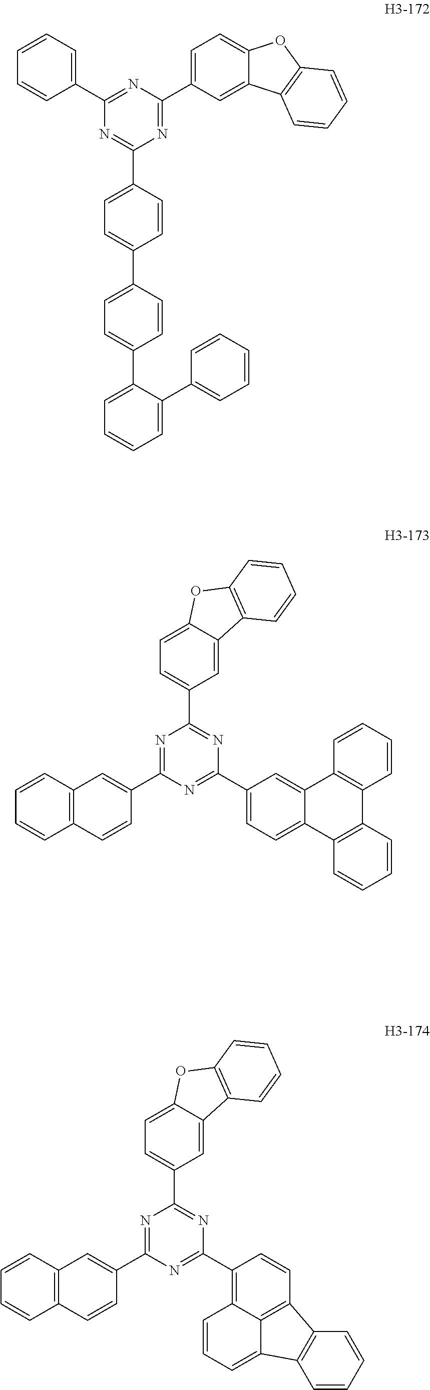 [SMILES: c1ccc(-c2nc(-c3ccc(-c4ccc(-c5ccccc5-c5ccccc5)cc4)cc3)nc(-c3ccc4oc5ccccc5c4c3)n2)cc1 ; c1ccc2cc(-c3nc(-c4ccc5oc6ccccc6c5c4)nc(-c4ccc5c6ccccc6c6ccccc6c5c4)n3)ccc2c1 ; c1ccc2c(c1)-c1cccc3c(-c4nc(-c5ccc6ccccc6c5)nc(-c5ccc6oc7ccccc7c6c5)n4)ccc-2c13] 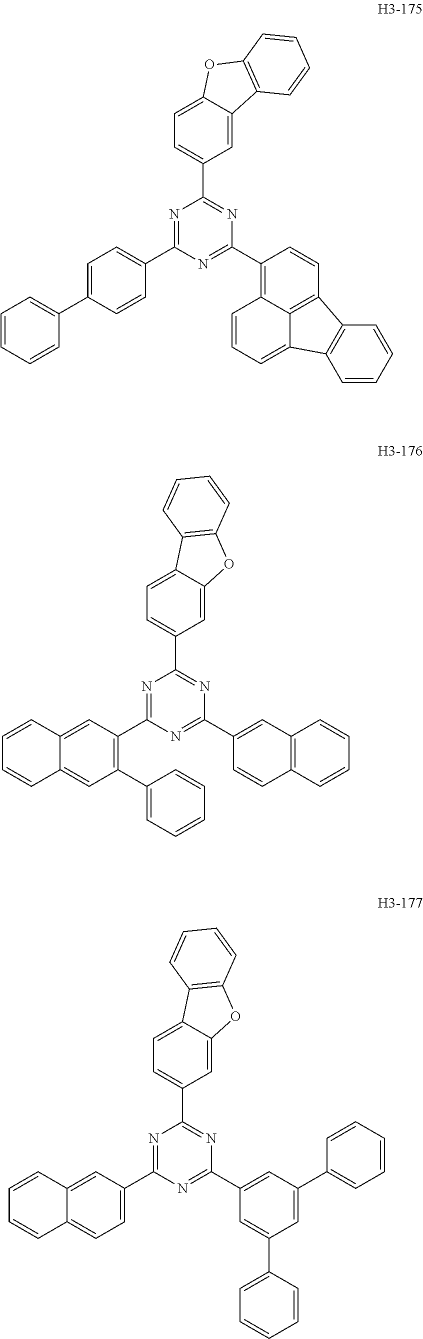 [SMILES: c1ccc(-c2ccc(-c3nc(-c4ccc5oc6ccccc6c5c4)nc(-c4ccc5c6c(cccc46)-c4ccccc4-5)n3)cc2)cc1 ; c1ccc(-c2cc3ccccc3cc2-c2nc(-c3ccc4ccccc4c3)nc(-c3ccc4c(c3)oc3ccccc34)n2)cc1 ; c1ccc(-c2cc(-c3ccccc3)cc(-c3nc(-c4ccc5ccccc5c4)nc(-c4ccc5c(c4)oc4ccccc45)n3)c2)cc1] 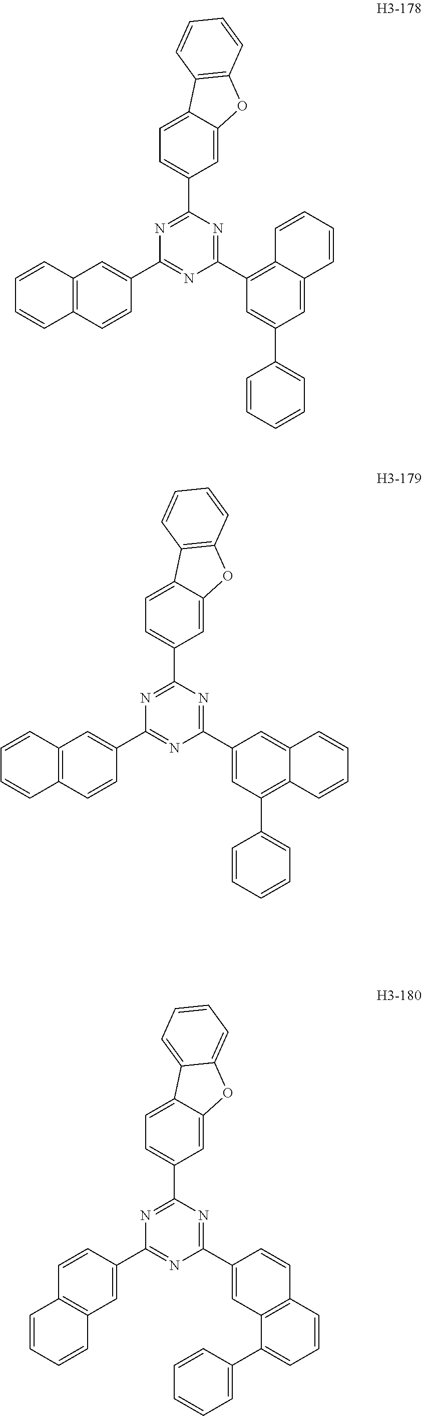 [SMILES: c1ccc(-c2cc(-c3nc(-c4ccc5ccccc5c4)nc(-c4ccc5c(c4)oc4ccccc45)n3)c3ccccc3c2)cc1 ; c1ccc(-c2cc(-c3nc(-c4ccc5ccccc5c4)nc(-c4ccc5c(c4)oc4ccccc45)n3)cc3ccccc23)cc1 ; c1ccc(-c2cccc3ccc(-c4nc(-c5ccc6ccccc6c5)nc(-c5ccc6c(c5)oc5ccccc56)n4)cc23)cc1] 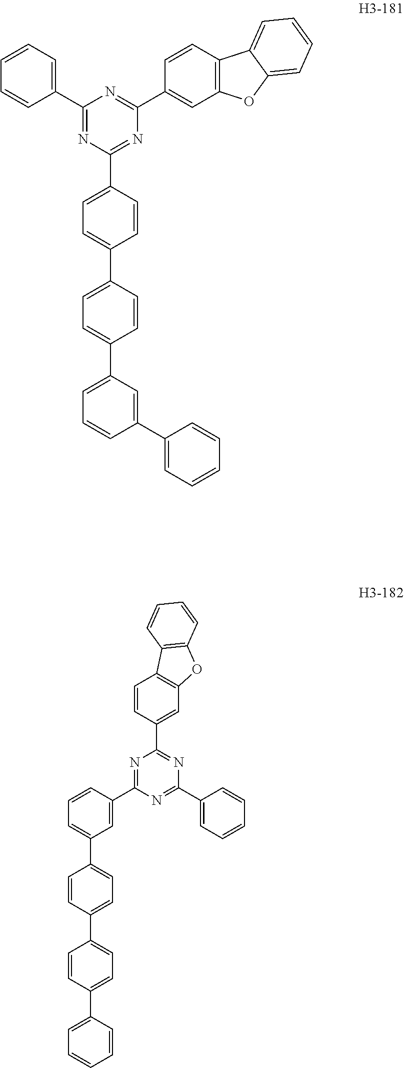 [SMILES: c1ccc(-c2cccc(-c3ccc(-c4ccc(-c5nc(-c6ccccc6)nc(-c6ccc7c(c6)oc6ccccc67)n5)cc4)cc3)c2)cc1 ; c1ccc(-c2ccc(-c3ccc(-c4cccc(-c5nc(-c6ccccc6)nc(-c6ccc7c(c6)oc6ccccc67)n5)c4)cc3)cc2)cc1] 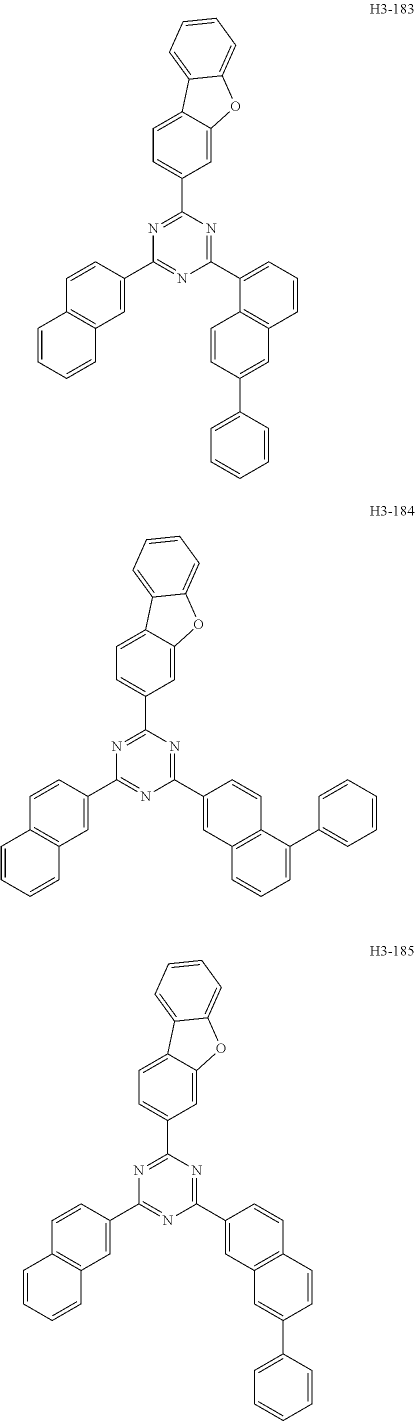 [SMILES: c1ccc(-c2ccc3c(-c4nc(-c5ccc6ccccc6c5)nc(-c5ccc6c(c5)oc5ccccc56)n4)cccc3c2)cc1 ; c1ccc(-c2cccc3cc(-c4nc(-c5ccc6ccccc6c5)nc(-c5ccc6c(c5)oc5ccccc56)n4)ccc23)cc1 ; c1ccc(-c2ccc3ccc(-c4nc(-c5ccc6ccccc6c5)nc(-c5ccc6c(c5)oc5ccccc56)n4)cc3c2)cc1] 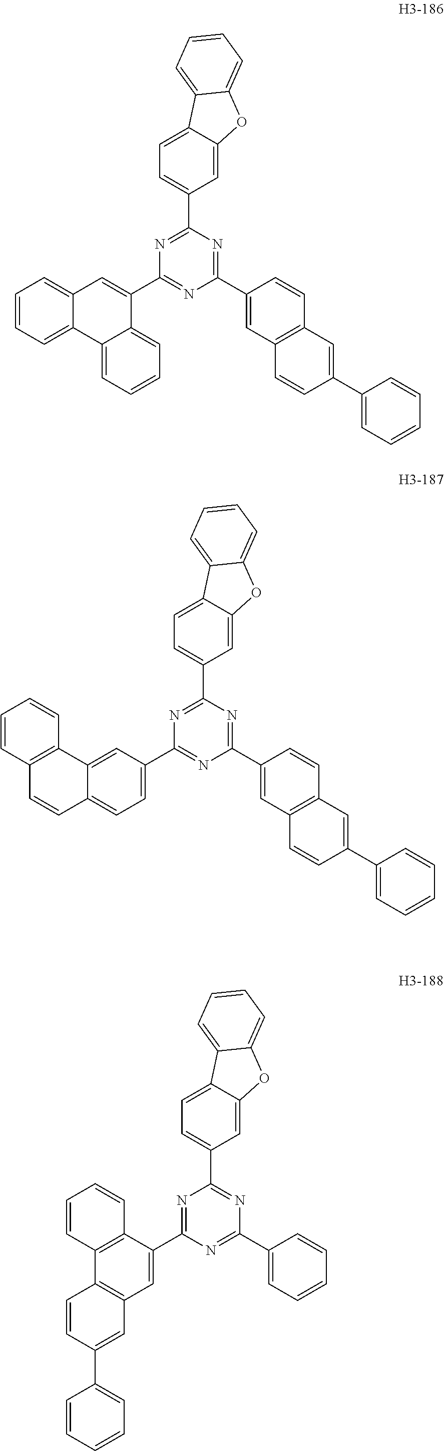 [SMILES: c1ccc(-c2ccc3cc(-c4nc(-c5ccc6c(c5)oc5ccccc56)nc(-c5cc6ccccc6c6ccccc56)n4)ccc3c2)cc1 ; c1ccc(-c2ccc3cc(-c4nc(-c5ccc6c(c5)oc5ccccc56)nc(-c5ccc6ccc7ccccc7c6c5)n4)ccc3c2)cc1 ; c1ccc(-c2ccc3c(c2)cc(-c2nc(-c4ccccc4)nc(-c4ccc5c(c4)oc4ccccc45)n2)c2ccccc23)cc1] 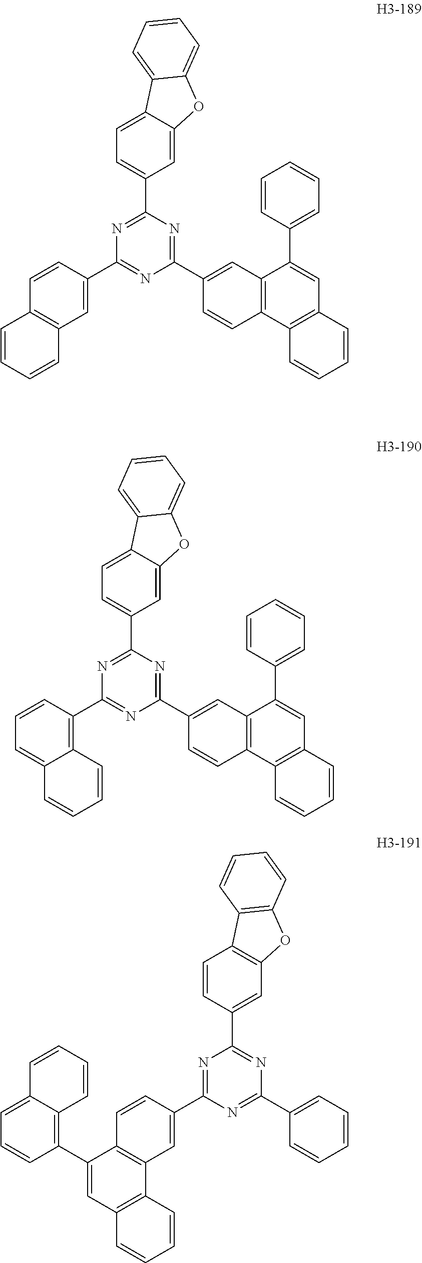 [SMILES: c1ccc(-c2cc3ccccc3c3ccc(-c4nc(-c5ccc6ccccc6c5)nc(-c5ccc6c(c5)oc5ccccc56)n4)cc23)cc1 ; c1ccc(-c2cc3ccccc3c3ccc(-c4nc(-c5ccc6c(c5)oc5ccccc56)nc(-c5cccc6ccccc56)n4)cc23)cc1 ; c1ccc(-c2nc(-c3ccc4c(c3)oc3ccccc34)nc(-c3ccc4c(-c5cccc6ccccc56)cc5ccccc5c4c3)n2)cc1] 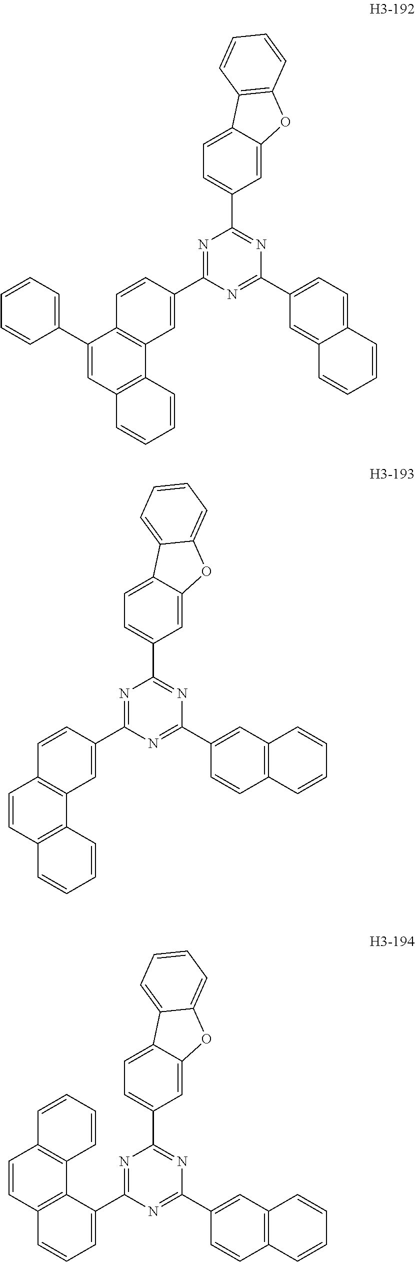 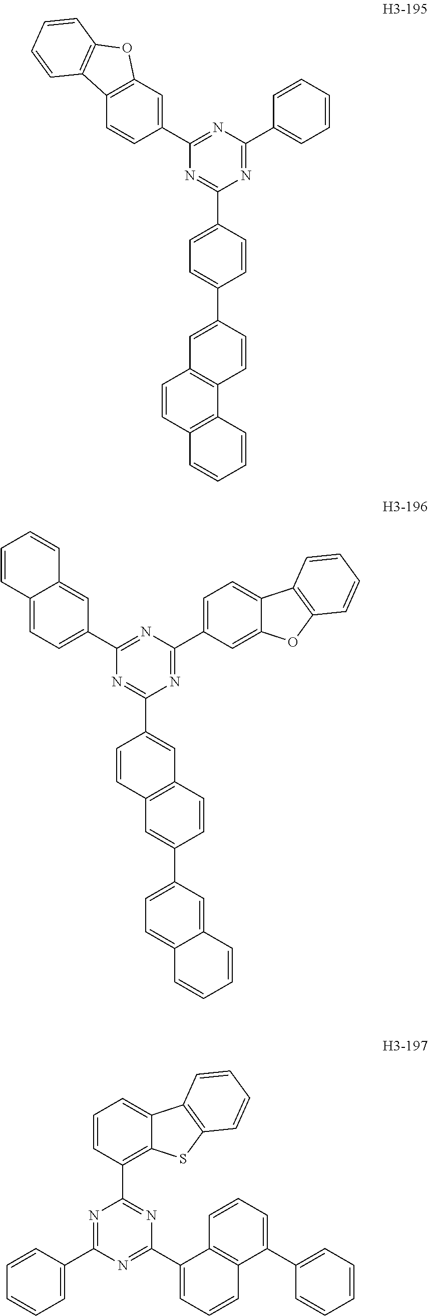 [SMILES: c1ccc(-c2nc(-c3ccc(-c4ccc5c(ccc6ccccc65)c4)cc3)nc(-c3ccc4c(c3)oc3ccccc34)n2)cc1 ; c1ccc2cc(-c3ccc4cc(-c5nc(-c6ccc7ccccc7c6)nc(-c6ccc7c(c6)oc6ccccc67)n5)ccc4c3)ccc2c1 ; c1ccc(-c2nc(-c3cccc4c(-c5ccccc5)cccc34)nc(-c3cccc4c3sc3ccccc34)n2)cc1] 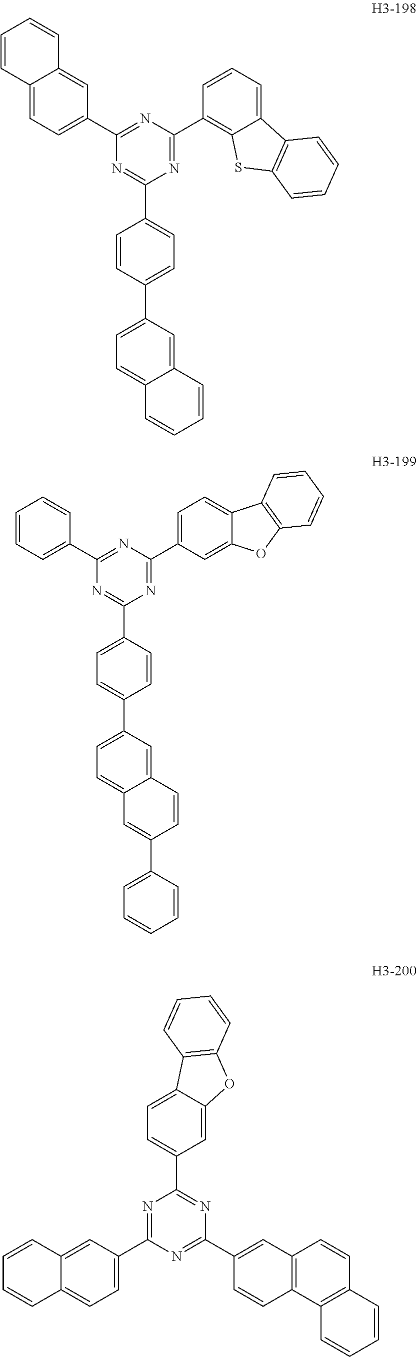 [SMILES: c1ccc2cc(-c3ccc(-c4nc(-c5ccc6ccccc6c5)nc(-c5cccc6c5sc5ccccc56)n4)cc3)ccc2c1 ; c1ccc(-c2ccc3cc(-c4ccc(-c5nc(-c6ccccc6)nc(-c6ccc7c(c6)oc6ccccc67)n5)cc4)ccc3c2)cc1 ; c1ccc2cc(-c3nc(-c4ccc5c(ccc6ccccc65)c4)nc(-c4ccc5c(c4)oc4ccccc45)n3)ccc2c1] 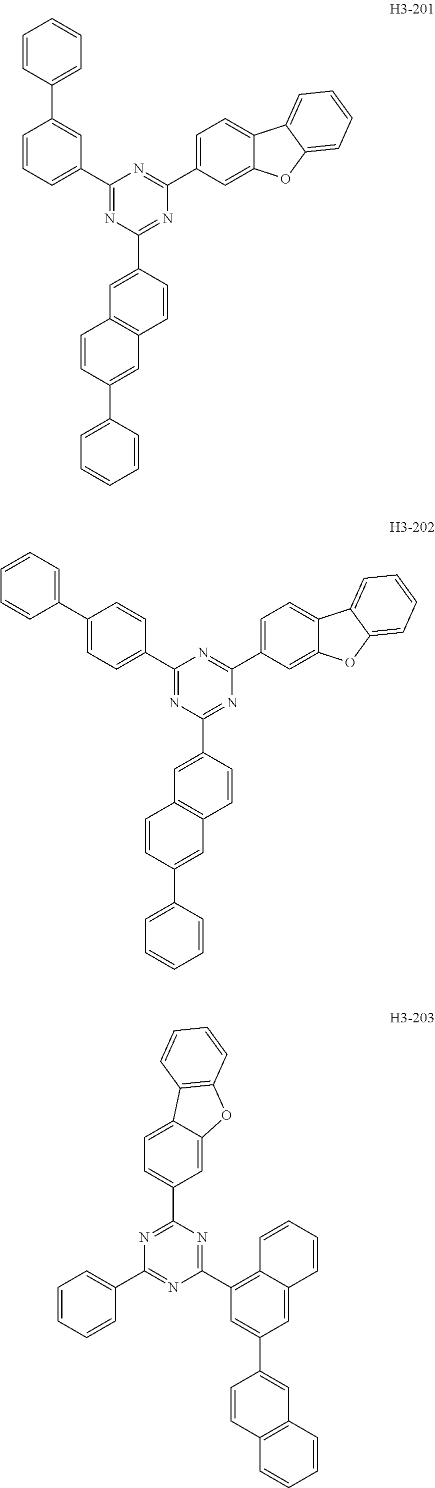 [SMILES: c1ccc(-c2cccc(-c3nc(-c4ccc5cc(-c6ccccc6)ccc5c4)nc(-c4ccc5c(c4)oc4ccccc45)n3)c2)cc1 ; c1ccc(-c2ccc(-c3nc(-c4ccc5cc(-c6ccccc6)ccc5c4)nc(-c4ccc5c(c4)oc4ccccc45)n3)cc2)cc1 ; c1ccc(-c2nc(-c3ccc4c(c3)oc3ccccc34)nc(-c3cc(-c4ccc5ccccc5c4)cc4ccccc34)n2)cc1] 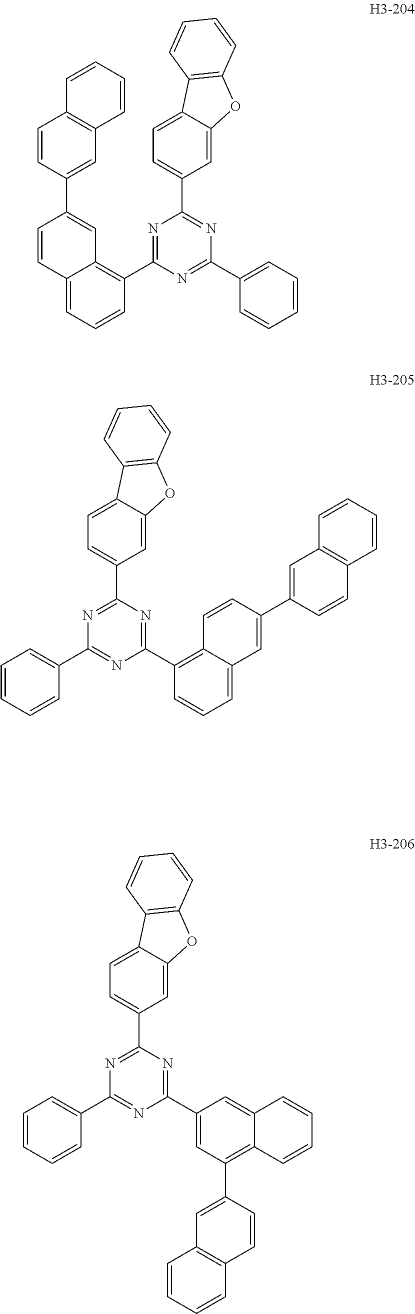 [SMILES: c1ccc(-c2nc(-c3ccc4c(c3)oc3ccccc34)nc(-c3cccc4ccc(-c5ccc6ccccc6c5)cc34)n2)cc1 ; c1ccc(-c2nc(-c3ccc4c(c3)oc3ccccc34)nc(-c3cccc4cc(-c5ccc6ccccc6c5)ccc34)n2)cc1 ; c1ccc(-c2nc(-c3cc(-c4ccc5ccccc5c4)c4ccccc4c3)nc(-c3ccc4c(c3)oc3ccccc34)n2)cc1] 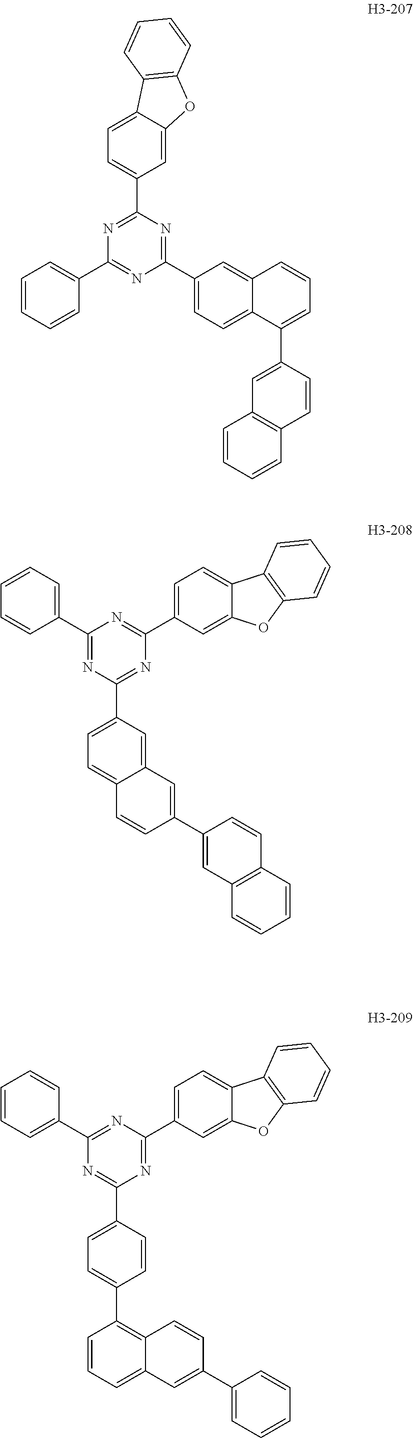 [SMILES: c1ccc(-c2nc(-c3ccc4c(-c5ccc6ccccc6c5)cccc4c3)nc(-c3ccc4c(c3)oc3ccccc34)n2)cc1 ; c1ccc(-c2nc(-c3ccc4ccc(-c5ccc6ccccc6c5)cc4c3)nc(-c3ccc4c(c3)oc3ccccc34)n2)cc1 ; c1ccc(-c2ccc3c(-c4ccc(-c5nc(-c6ccccc6)nc(-c6ccc7c(c6)oc6ccccc67)n5)cc4)cccc3c2)cc1] 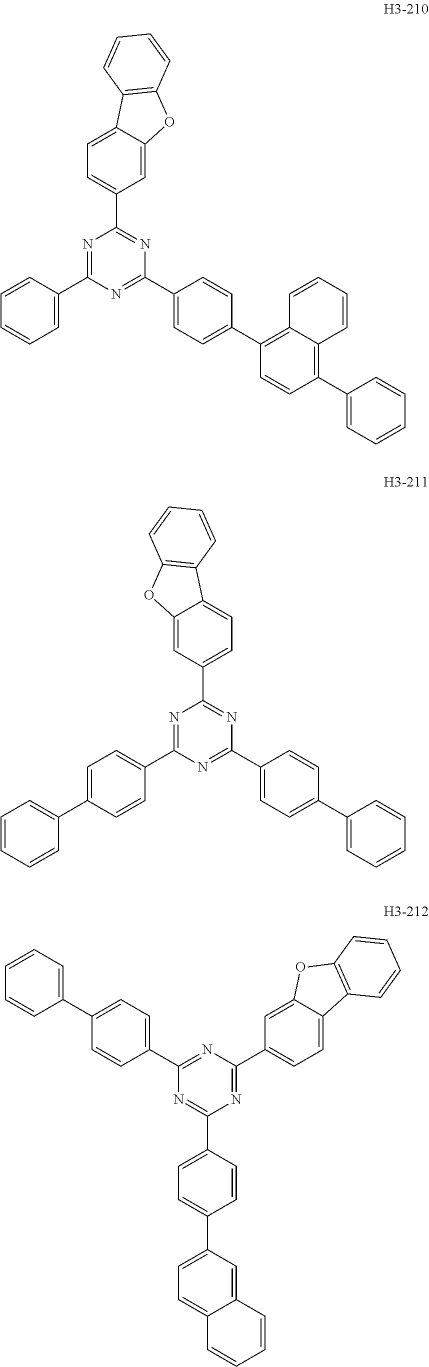 [SMILES: c1ccc(-c2nc(-c3ccc(-c4ccc(-c5ccccc5)c5ccccc45)cc3)nc(-c3ccc4c(c3)oc3ccccc34)n2)cc1 ; c1ccc(-c2ccc(-c3nc(-c4ccc(-c5ccccc5)cc4)nc(-c4ccc5c(c4)oc4ccccc45)n3)cc2)cc1 ; c1ccc(-c2ccc(-c3nc(-c4ccc(-c5ccc6ccccc6c5)cc4)nc(-c4ccc5c(c4)oc4ccccc45)n3)cc2)cc1] 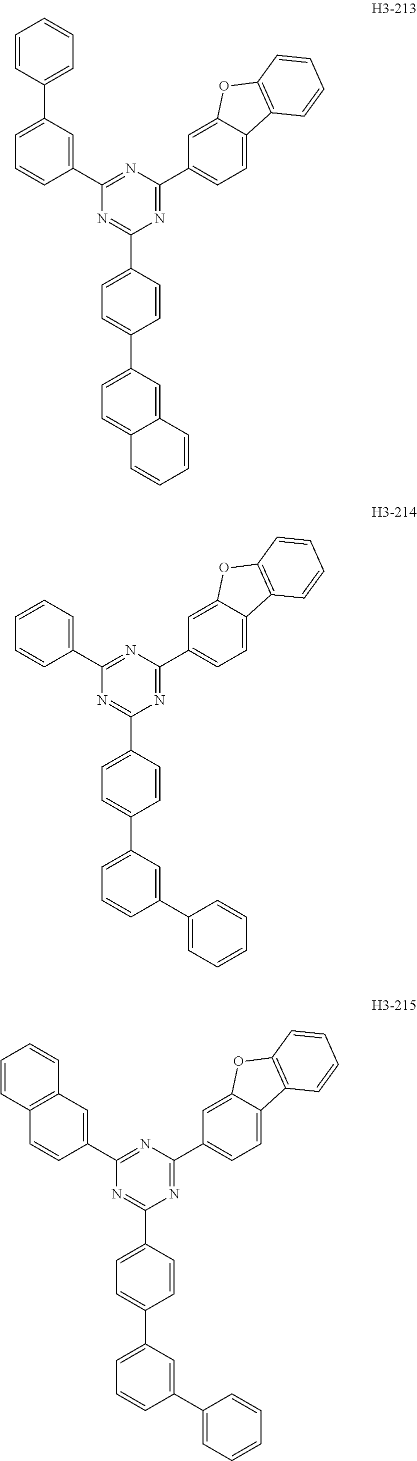 [SMILES: c1ccc(-c2cccc(-c3nc(-c4ccc(-c5ccc6ccccc6c5)cc4)nc(-c4ccc5c(c4)oc4ccccc45)n3)c2)cc1 ; c1ccc(-c2cccc(-c3ccc(-c4nc(-c5ccccc5)nc(-c5ccc6c(c5)oc5ccccc56)n4)cc3)c2)cc1 ; c1ccc(-c2cccc(-c3ccc(-c4nc(-c5ccc6ccccc6c5)nc(-c5ccc6c(c5)oc5ccccc56)n4)cc3)c2)cc1] 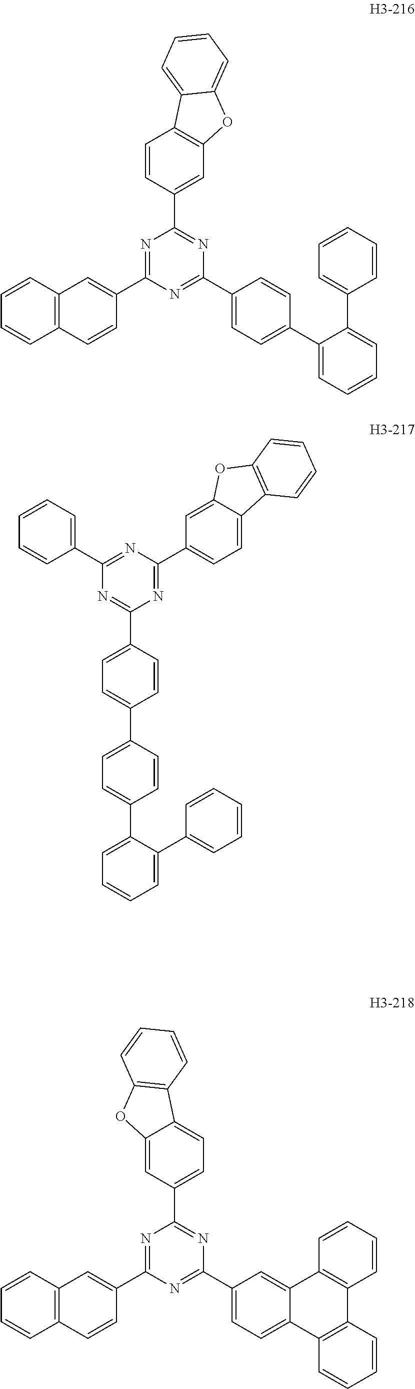 [SMILES: c1ccc(-c2ccccc2-c2ccc(-c3nc(-c4ccc5ccccc5c4)nc(-c4ccc5c(c4)oc4ccccc45)n3)cc2)cc1 ; c1ccc(-c2nc(-c3ccc(-c4ccc(-c5ccccc5-c5ccccc5)cc4)cc3)nc(-c3ccc4c(c3)oc3ccccc34)n2)cc1 ; c1ccc2cc(-c3nc(-c4ccc5c(c4)oc4ccccc45)nc(-c4ccc5c6ccccc6c6ccccc6c5c4)n3)ccc2c1] 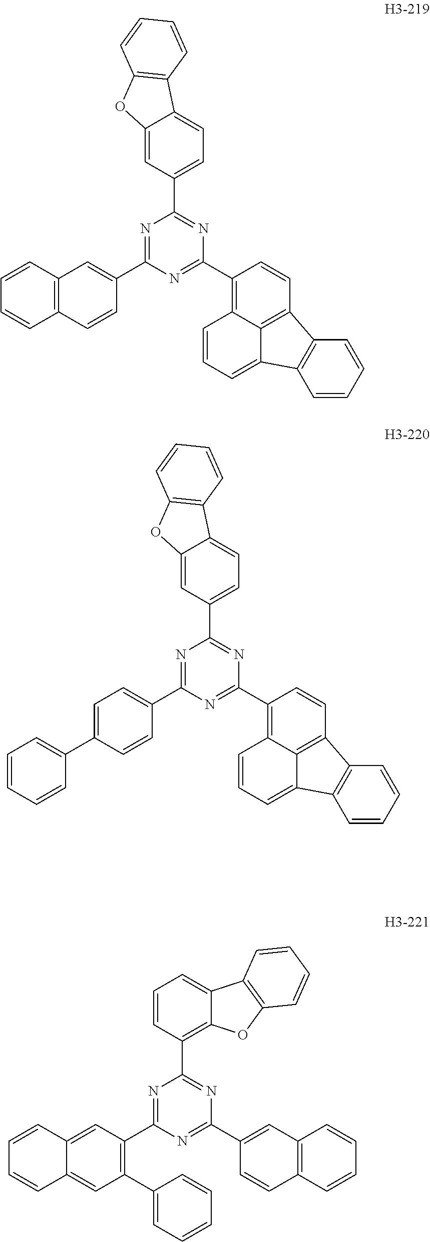 [SMILES: c1ccc2c(c1)-c1cccc3c(-c4nc(-c5ccc6ccccc6c5)nc(-c5ccc6c(c5)oc5ccccc56)n4)ccc-2c13 ; c1ccc(-c2ccc(-c3nc(-c4ccc5c(c4)oc4ccccc45)nc(-c4ccc5c6c(cccc46)-c4ccccc4-5)n3)cc2)cc1 ; c1ccc(-c2cc3ccccc3cc2-c2nc(-c3ccc4ccccc4c3)nc(-c3cccc4c3oc3ccccc34)n2)cc1] 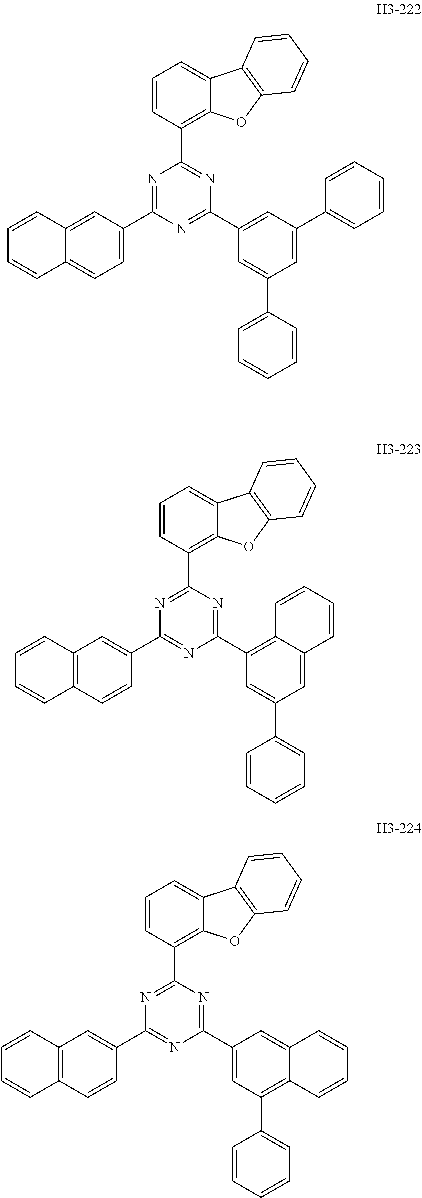 [SMILES: c1ccc(-c2cc(-c3ccccc3)cc(-c3nc(-c4ccc5ccccc5c4)nc(-c4cccc5c4oc4ccccc45)n3)c2)cc1 ; c1ccc(-c2cc(-c3nc(-c4ccc5ccccc5c4)nc(-c4cccc5c4oc4ccccc45)n3)c3ccccc3c2)cc1 ; c1ccc(-c2cc(-c3nc(-c4ccc5ccccc5c4)nc(-c4cccc5c4oc4ccccc45)n3)cc3ccccc23)cc1] 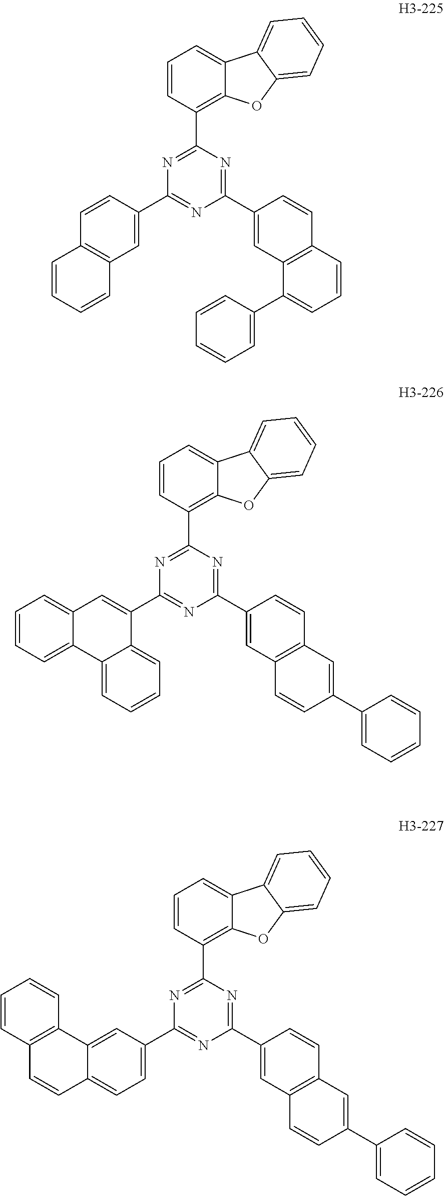 [SMILES: c1ccc(-c2cccc3ccc(-c4nc(-c5ccc6ccccc6c5)nc(-c5cccc6c5oc5ccccc56)n4)cc23)cc1 ; c1ccc(-c2ccc3cc(-c4nc(-c5cc6ccccc6c6ccccc56)nc(-c5cccc6c5oc5ccccc56)n4)ccc3c2)cc1 ; c1ccc(-c2ccc3cc(-c4nc(-c5ccc6ccc7ccccc7c6c5)nc(-c5cccc6c5oc5ccccc56)n4)ccc3c2)cc1] 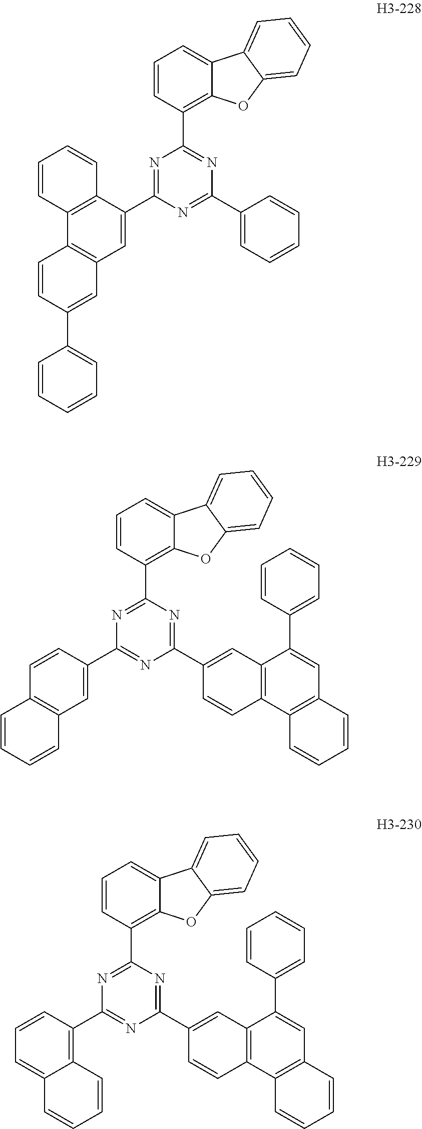 [SMILES: c1ccc(-c2ccc3c(c2)cc(-c2nc(-c4ccccc4)nc(-c4cccc5c4oc4ccccc45)n2)c2ccccc23)cc1 ; c1ccc(-c2cc3ccccc3c3ccc(-c4nc(-c5ccc6ccccc6c5)nc(-c5cccc6c5oc5ccccc56)n4)cc23)cc1 ; c1ccc(-c2cc3ccccc3c3ccc(-c4nc(-c5cccc6ccccc56)nc(-c5cccc6c5oc5ccccc56)n4)cc23)cc1] 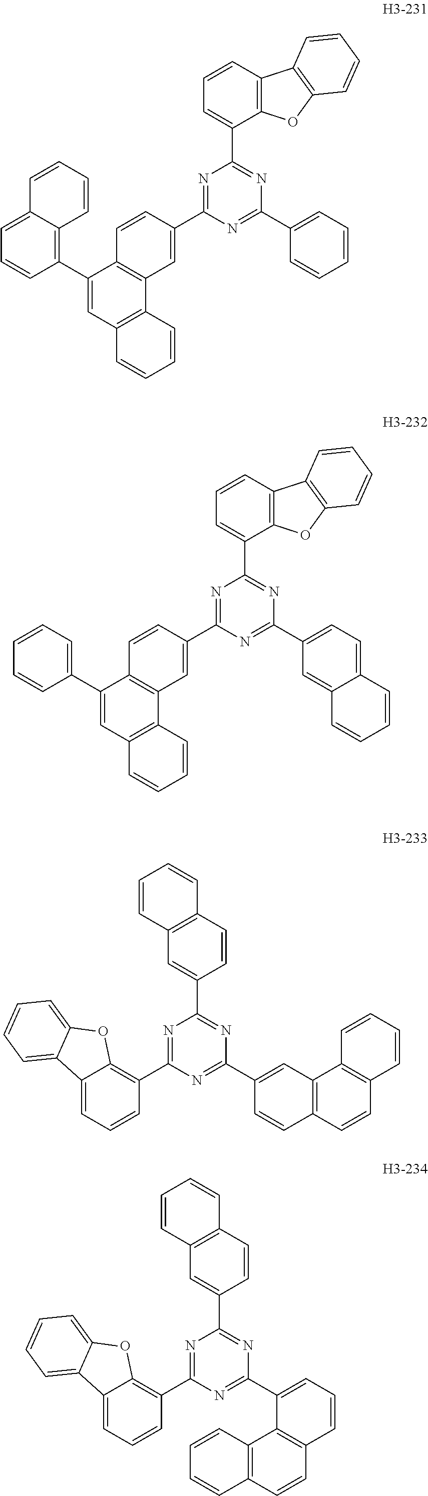 [SMILES: c1ccc(-c2nc(-c3ccc4c(-c5cccc6ccccc56)cc5ccccc5c4c3)nc(-c3cccc4c3oc3ccccc34)n2)cc1 ; c1ccc(-c2cc3ccccc3c3cc(-c4nc(-c5ccc6ccccc6c5)nc(-c5cccc6c5oc5ccccc56)n4)ccc23)cc1 ; c1ccc2cc(-c3nc(-c4ccc5ccc6ccccc6c5c4)nc(-c4cccc5c4oc4ccccc45)n3)ccc2c1 ; c1ccc2cc(-c3nc(-c4cccc5c4oc4ccccc45)nc(-c4cccc5ccc6ccccc6c45)n3)ccc2c1] 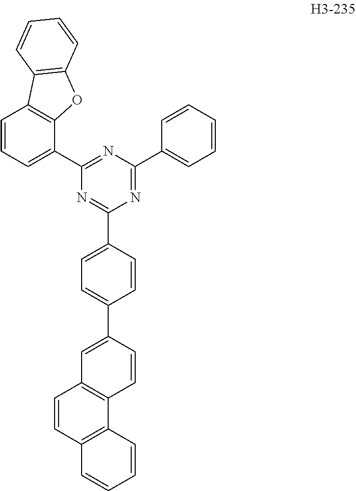 [SMILES: c1ccc(-c2nc(-c3ccc(-c4ccc5c(ccc6ccccc65)c4)cc3)nc(-c3cccc4c3oc3ccccc34)n2)cc1] 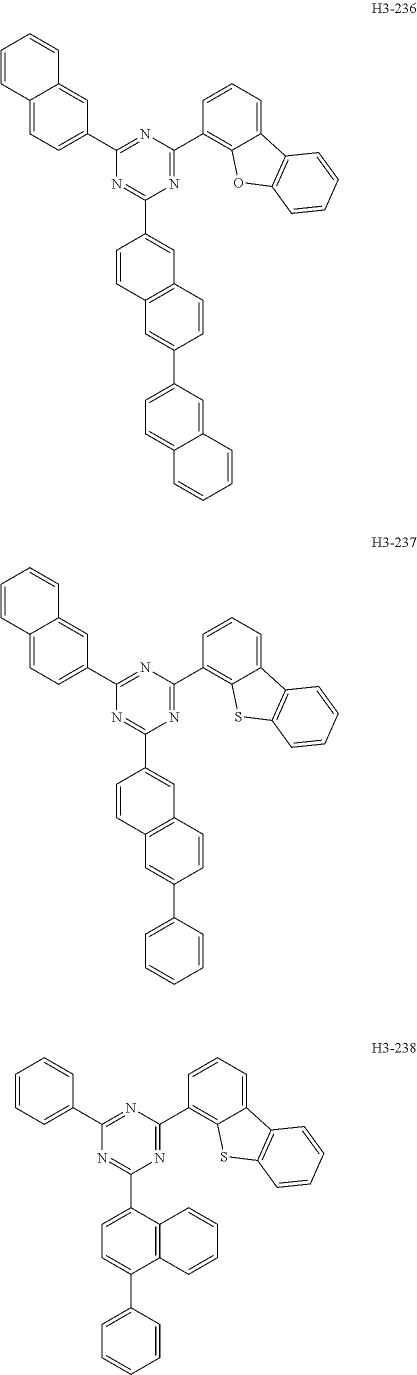 [SMILES: c1ccc2cc(-c3ccc4cc(-c5nc(-c6ccc7ccccc7c6)nc(-c6cccc7c6oc6ccccc67)n5)ccc4c3)ccc2c1 ; c1ccc(-c2ccc3cc(-c4nc(-c5ccc6ccccc6c5)nc(-c5cccc6c5sc5ccccc56)n4)ccc3c2)cc1 ; c1ccc(-c2nc(-c3ccc(-c4ccccc4)c4ccccc34)nc(-c3cccc4c3sc3ccccc34)n2)cc1] 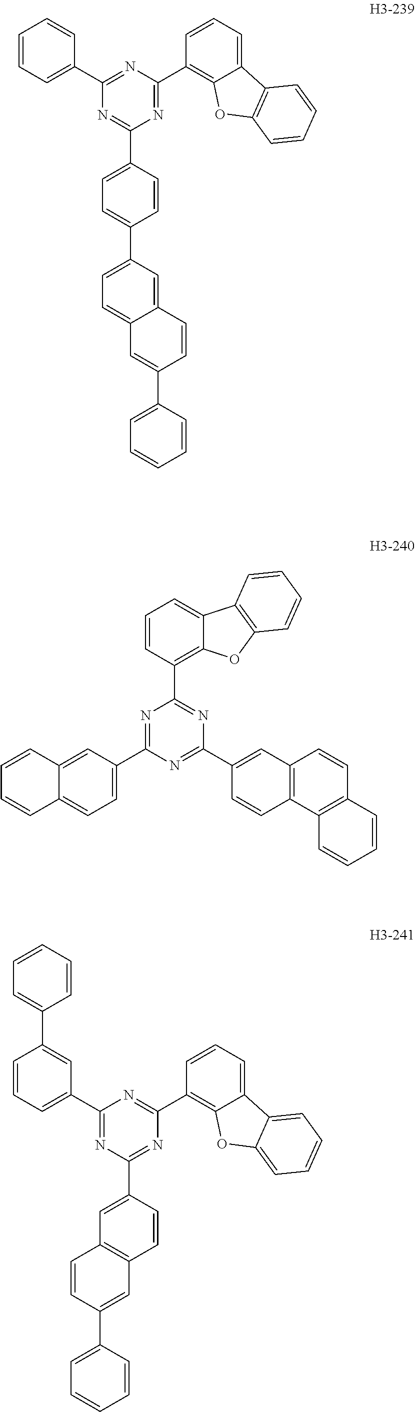 [SMILES: c1ccc(-c2ccc3cc(-c4ccc(-c5nc(-c6ccccc6)nc(-c6cccc7c6oc6ccccc67)n5)cc4)ccc3c2)cc1 ; c1ccc2cc(-c3nc(-c4ccc5c(ccc6ccccc65)c4)nc(-c4cccc5c4oc4ccccc45)n3)ccc2c1 ; c1ccc(-c2cccc(-c3nc(-c4ccc5cc(-c6ccccc6)ccc5c4)nc(-c4cccc5c4oc4ccccc45)n3)c2)cc1] 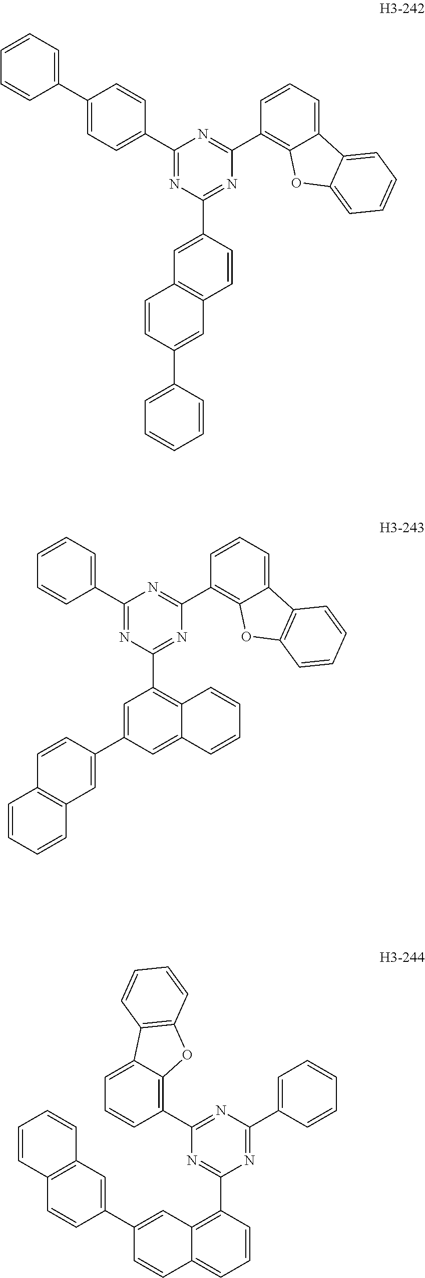 [SMILES: c1ccc(-c2ccc(-c3nc(-c4ccc5cc(-c6ccccc6)ccc5c4)nc(-c4cccc5c4oc4ccccc45)n3)cc2)cc1 ; c1ccc(-c2nc(-c3cc(-c4ccc5ccccc5c4)cc4ccccc34)nc(-c3cccc4c3oc3ccccc34)n2)cc1 ; c1ccc(-c2nc(-c3cccc4ccc(-c5ccc6ccccc6c5)cc34)nc(-c3cccc4c3oc3ccccc34)n2)cc1] 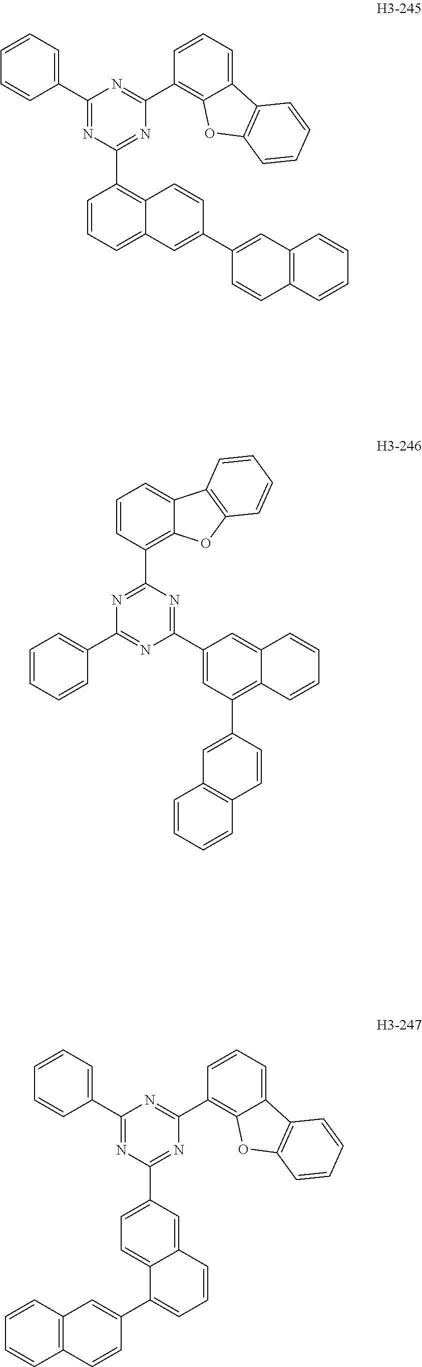 [SMILES: c1ccc(-c2nc(-c3cccc4cc(-c5ccc6ccccc6c5)ccc34)nc(-c3cccc4c3oc3ccccc34)n2)cc1 ; c1ccc(-c2nc(-c3cc(-c4ccc5ccccc5c4)c4ccccc4c3)nc(-c3cccc4c3oc3ccccc34)n2)cc1 ; c1ccc(-c2nc(-c3ccc4c(-c5ccc6ccccc6c5)cccc4c3)nc(-c3cccc4c3oc3ccccc34)n2)cc1] 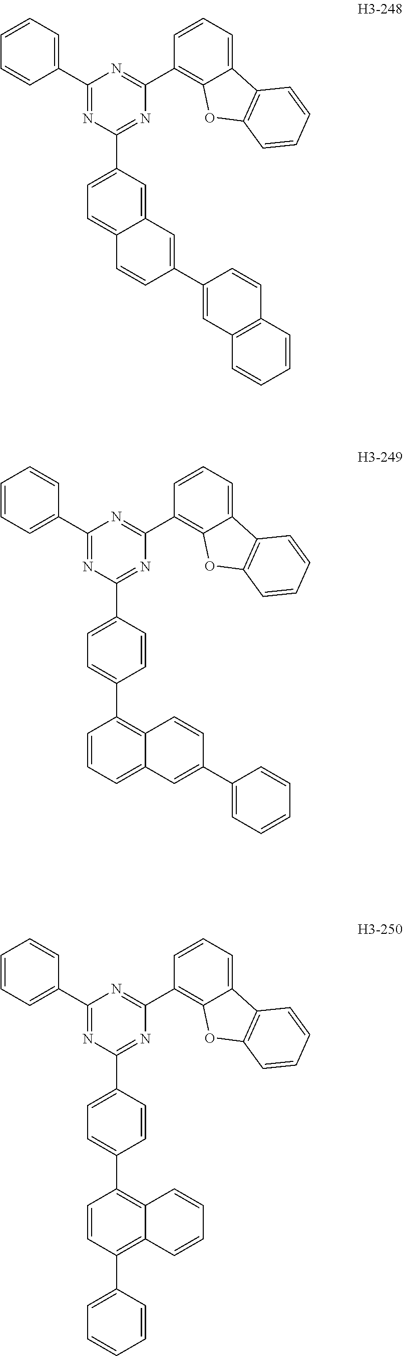 [SMILES: c1ccc(-c2nc(-c3ccc4ccc(-c5ccc6ccccc6c5)cc4c3)nc(-c3cccc4c3oc3ccccc34)n2)cc1 ; c1ccc(-c2ccc3c(-c4ccc(-c5nc(-c6ccccc6)nc(-c6cccc7c6oc6ccccc67)n5)cc4)cccc3c2)cc1 ; c1ccc(-c2nc(-c3ccc(-c4ccc(-c5ccccc5)c5ccccc45)cc3)nc(-c3cccc4c3oc3ccccc34)n2)cc1] 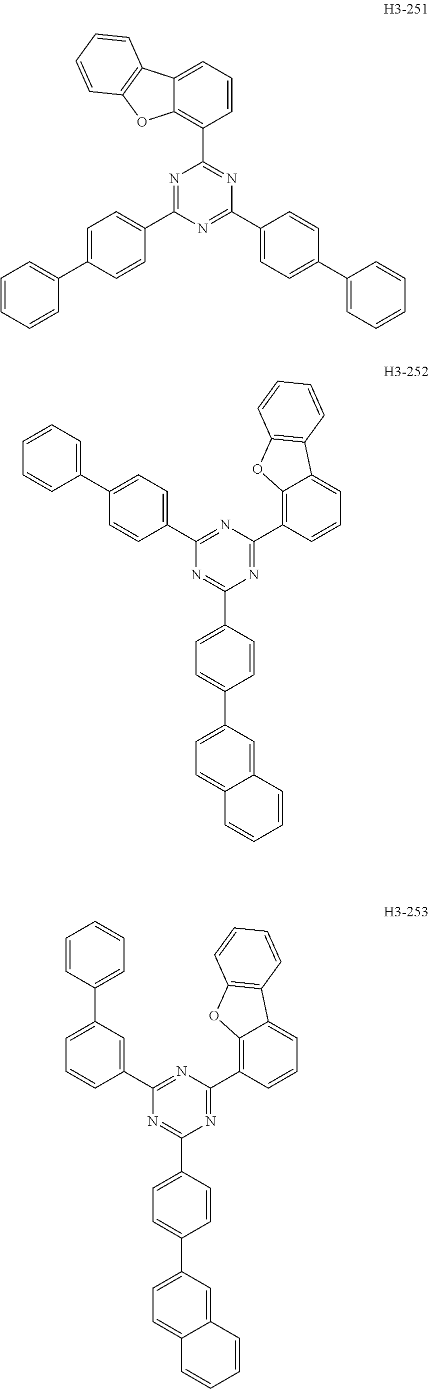 [SMILES: c1ccc(-c2ccc(-c3nc(-c4ccc(-c5ccccc5)cc4)nc(-c4cccc5c4oc4ccccc45)n3)cc2)cc1 ; c1ccc(-c2ccc(-c3nc(-c4ccc(-c5ccc6ccccc6c5)cc4)nc(-c4cccc5c4oc4ccccc45)n3)cc2)cc1 ; c1ccc(-c2cccc(-c3nc(-c4ccc(-c5ccc6ccccc6c5)cc4)nc(-c4cccc5c4oc4ccccc45)n3)c2)cc1] 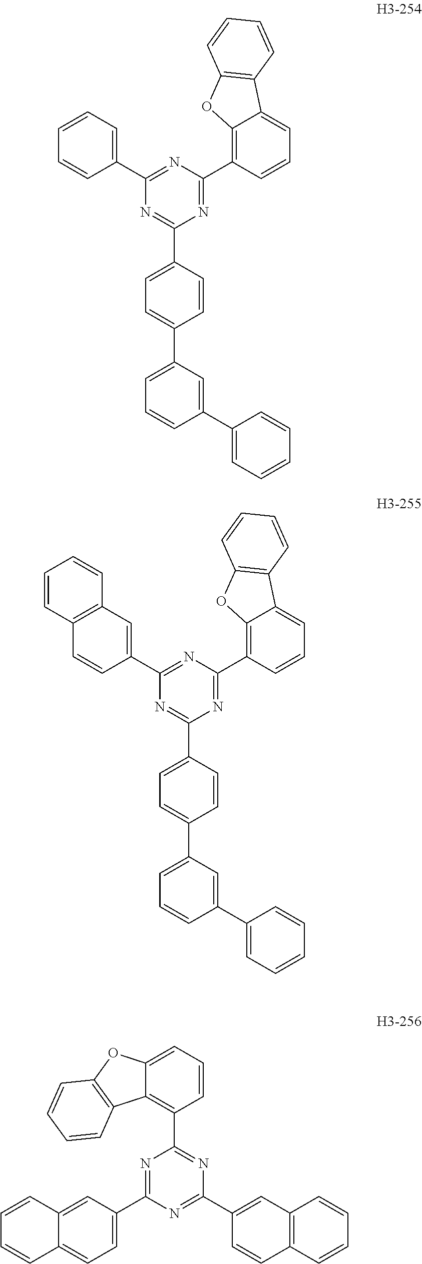 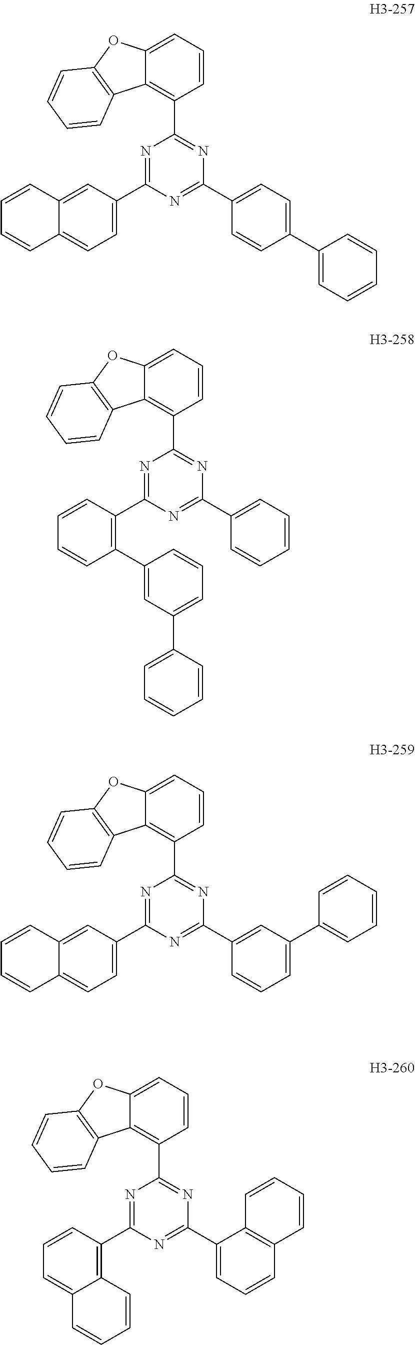 [SMILES: c1ccc(-c2ccc(-c3nc(-c4ccc5ccccc5c4)nc(-c4cccc5oc6ccccc6c45)n3)cc2)cc1 ; c1ccc(-c2cccc(-c3ccccc3-c3nc(-c4ccccc4)nc(-c4cccc5oc6ccccc6c45)n3)c2)cc1 ; c1ccc(-c2cccc(-c3nc(-c4ccc5ccccc5c4)nc(-c4cccc5oc6ccccc6c45)n3)c2)cc1 ; c1ccc2c(-c3nc(-c4cccc5ccccc45)nc(-c4cccc5oc6ccccc6c45)n3)cccc2c1] 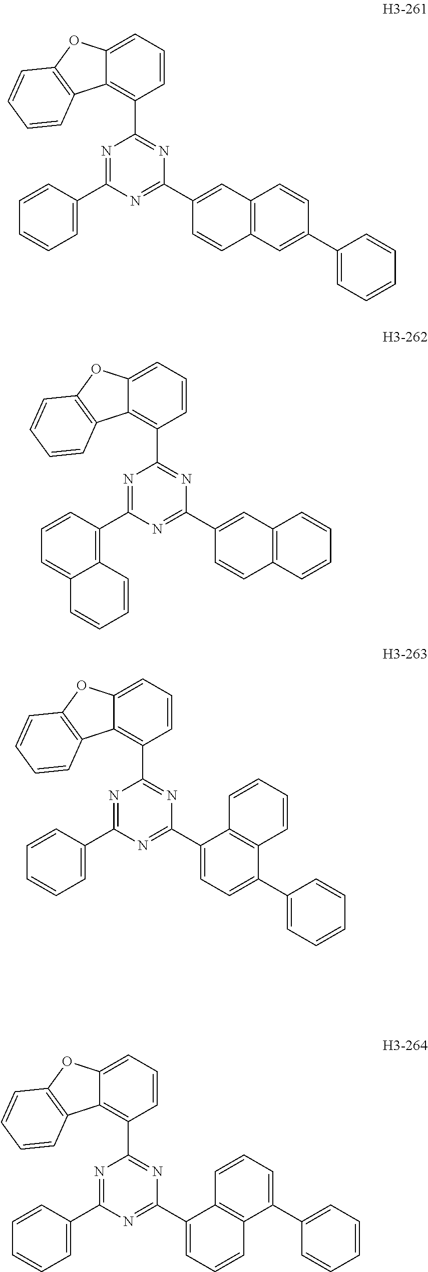 [SMILES: c1ccc(-c2ccc3cc(-c4nc(-c5ccccc5)nc(-c5cccc6oc7ccccc7c56)n4)ccc3c2)cc1 ; c1ccc2cc(-c3nc(-c4cccc5ccccc45)nc(-c4cccc5oc6ccccc6c45)n3)ccc2c1 ; c1ccc(-c2nc(-c3ccc(-c4ccccc4)c4ccccc34)nc(-c3cccc4oc5ccccc5c34)n2)cc1 ; c1ccc(-c2nc(-c3cccc4c(-c5ccccc5)cccc34)nc(-c3cccc4oc5ccccc5c34)n2)cc1] 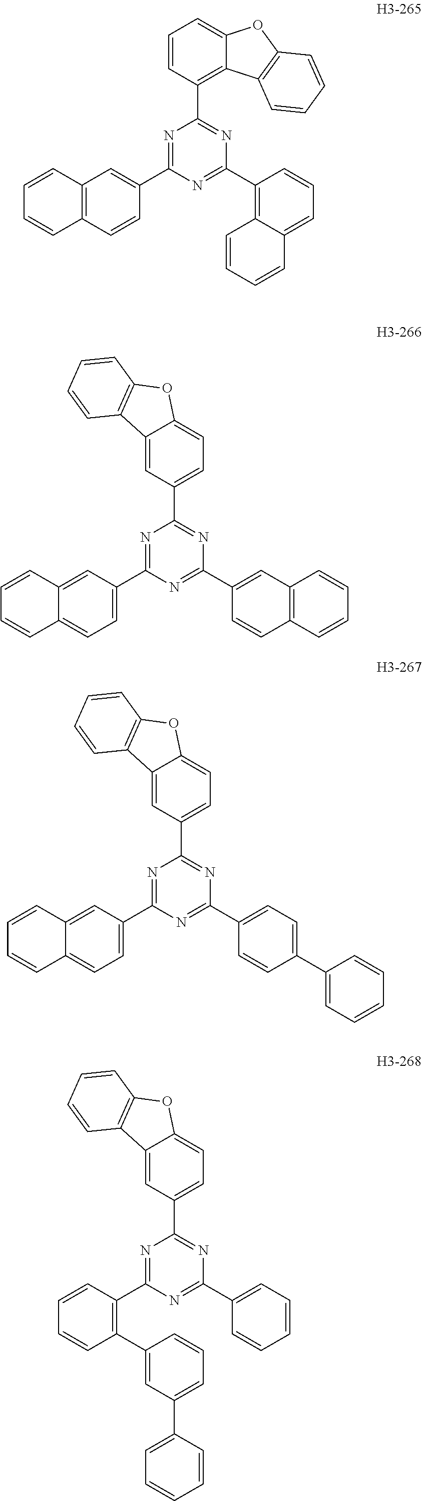 [SMILES: c1ccc2cc(-c3nc(-c4cccc5ccccc45)nc(-c4cccc5oc6ccccc6c45)n3)ccc2c1 ; c1ccc2cc(-c3nc(-c4ccc5ccccc5c4)nc(-c4ccc5oc6ccccc6c5c4)n3)ccc2c1 ; c1ccc(-c2ccc(-c3nc(-c4ccc5ccccc5c4)nc(-c4ccc5oc6ccccc6c5c4)n3)cc2)cc1 ; c1ccc(-c2cccc(-c3ccccc3-c3nc(-c4ccccc4)nc(-c4ccc5oc6ccccc6c5c4)n3)c2)cc1] 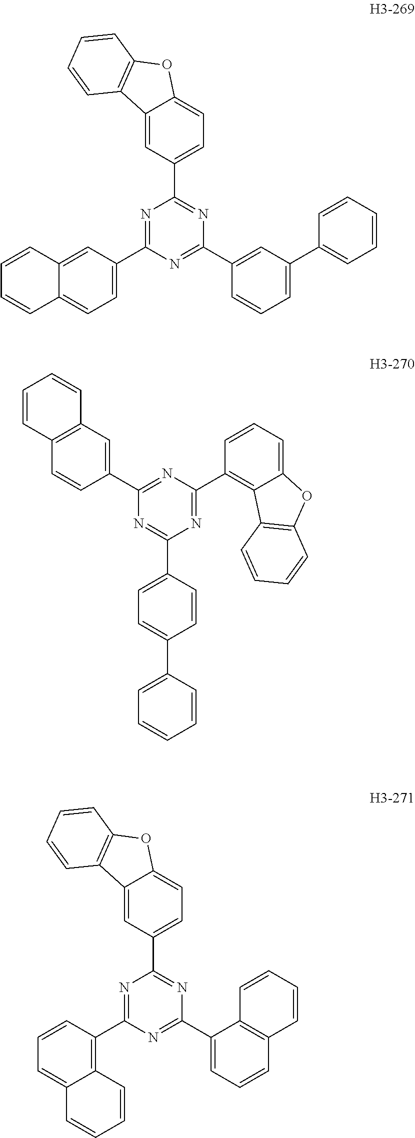 [SMILES: c1ccc(-c2cccc(-c3nc(-c4ccc5ccccc5c4)nc(-c4ccc5oc6ccccc6c5c4)n3)c2)cc1 ; c1ccc(-c2ccc(-c3nc(-c4ccc5ccccc5c4)nc(-c4cccc5oc6ccccc6c45)n3)cc2)cc1 ; c1ccc2c(-c3nc(-c4ccc5oc6ccccc6c5c4)nc(-c4cccc5ccccc45)n3)cccc2c1] 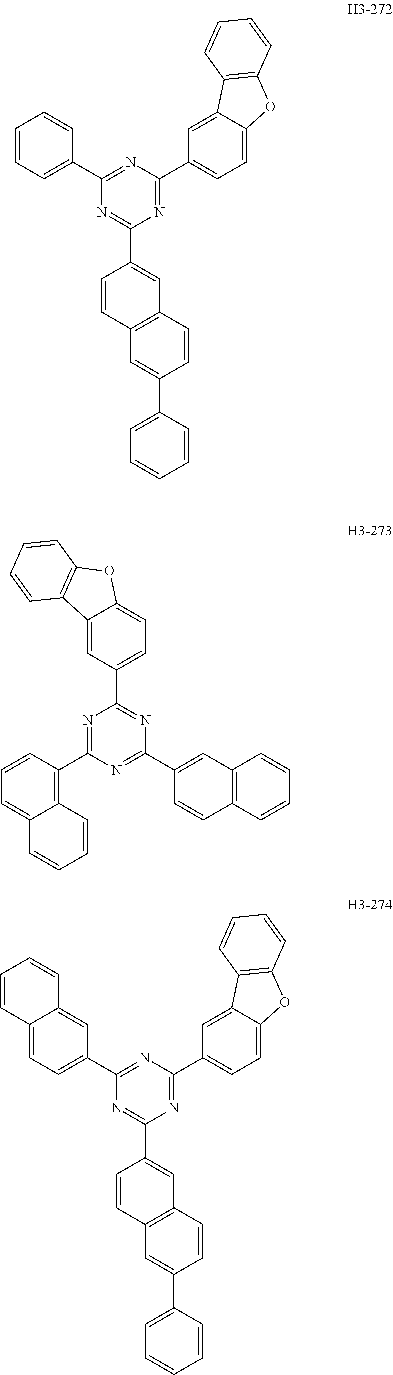 [SMILES: c1ccc(-c2ccc3cc(-c4nc(-c5ccccc5)nc(-c5ccc6oc7ccccc7c6c5)n4)ccc3c2)cc1 ; c1ccc2cc(-c3nc(-c4ccc5oc6ccccc6c5c4)nc(-c4cccc5ccccc45)n3)ccc2c1 ; c1ccc(-c2ccc3cc(-c4nc(-c5ccc6ccccc6c5)nc(-c5ccc6oc7ccccc7c6c5)n4)ccc3c2)cc1] 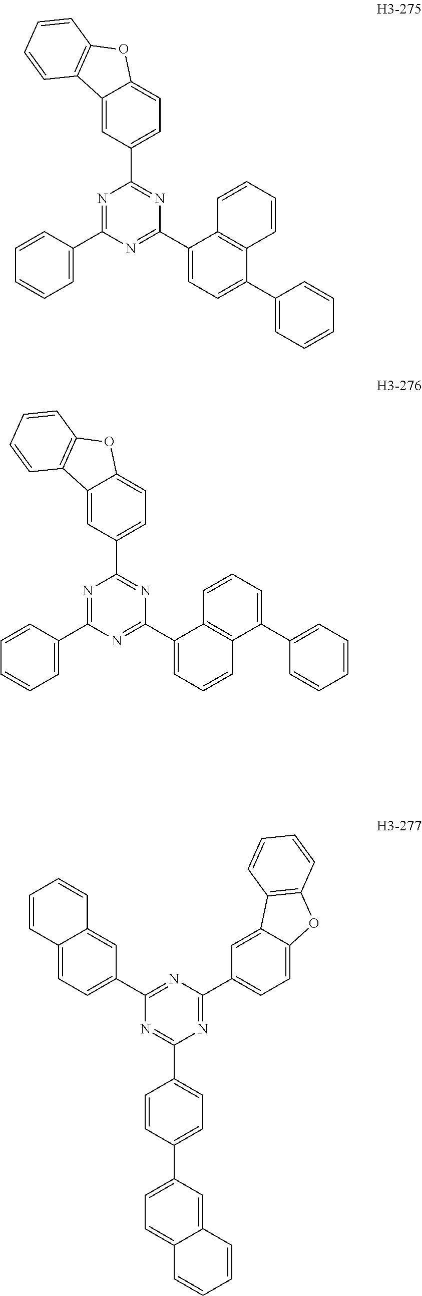 [SMILES: c1ccc(-c2nc(-c3ccc4oc5ccccc5c4c3)nc(-c3ccc(-c4ccccc4)c4ccccc34)n2)cc1 ; c1ccc(-c2nc(-c3ccc4oc5ccccc5c4c3)nc(-c3cccc4c(-c5ccccc5)cccc34)n2)cc1 ; c1ccc2cc(-c3ccc(-c4nc(-c5ccc6ccccc6c5)nc(-c5ccc6oc7ccccc7c6c5)n4)cc3)ccc2c1] 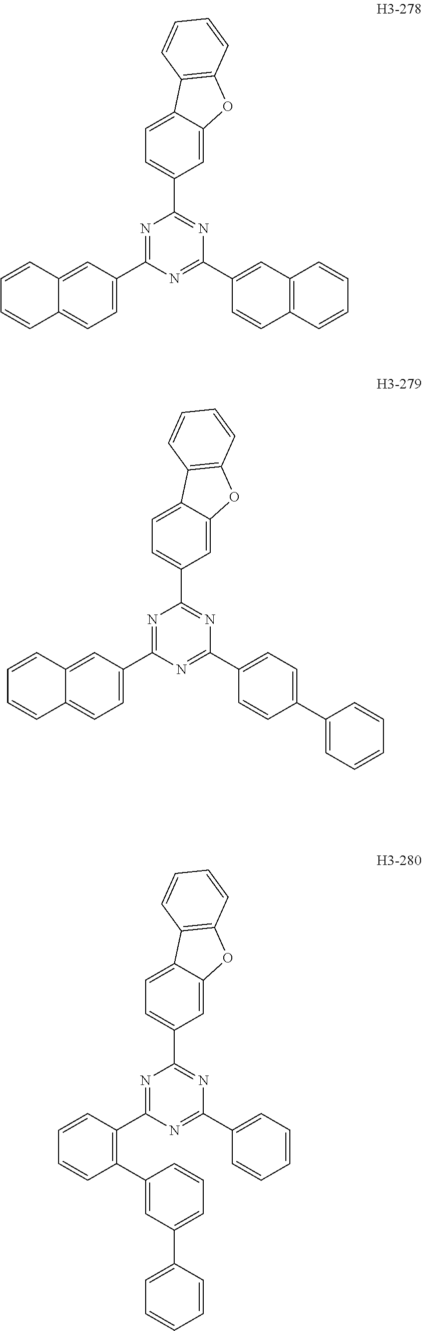 [SMILES: c1ccc2cc(-c3nc(-c4ccc5ccccc5c4)nc(-c4ccc5c(c4)oc4ccccc45)n3)ccc2c1 ; c1ccc(-c2ccc(-c3nc(-c4ccc5ccccc5c4)nc(-c4ccc5c(c4)oc4ccccc45)n3)cc2)cc1 ; c1ccc(-c2cccc(-c3ccccc3-c3nc(-c4ccccc4)nc(-c4ccc5c(c4)oc4ccccc45)n3)c2)cc1] 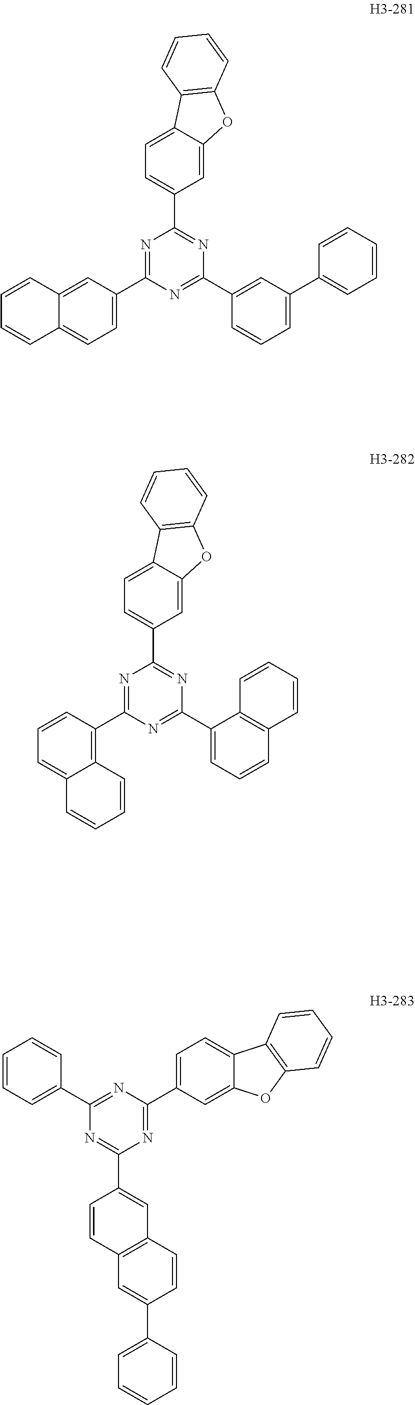 [SMILES: c1ccc(-c2cccc(-c3nc(-c4ccc5ccccc5c4)nc(-c4ccc5c(c4)oc4ccccc45)n3)c2)cc1 ; c1ccc2c(-c3nc(-c4ccc5c(c4)oc4ccccc45)nc(-c4cccc5ccccc45)n3)cccc2c1 ; c1ccc(-c2ccc3cc(-c4nc(-c5ccccc5)nc(-c5ccc6c(c5)oc5ccccc56)n4)ccc3c2)cc1] 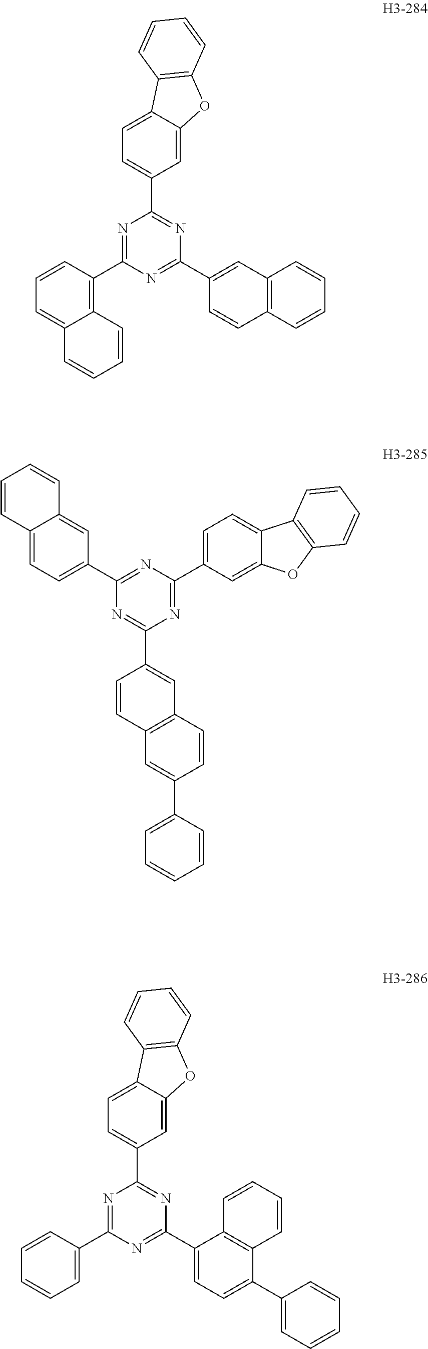 [SMILES: c1ccc2cc(-c3nc(-c4ccc5c(c4)oc4ccccc45)nc(-c4cccc5ccccc45)n3)ccc2c1 ; c1ccc(-c2ccc3cc(-c4nc(-c5ccc6ccccc6c5)nc(-c5ccc6c(c5)oc5ccccc56)n4)ccc3c2)cc1 ; c1ccc(-c2nc(-c3ccc4c(c3)oc3ccccc34)nc(-c3ccc(-c4ccccc4)c4ccccc34)n2)cc1] 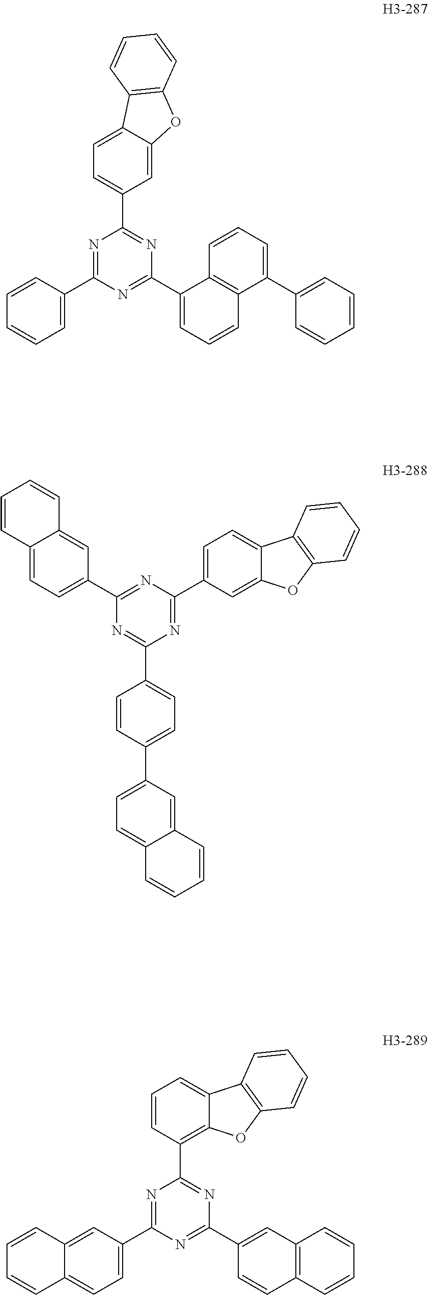 [SMILES: c1ccc(-c2nc(-c3ccc4c(c3)oc3ccccc34)nc(-c3cccc4c(-c5ccccc5)cccc34)n2)cc1 ; c1ccc2cc(-c3ccc(-c4nc(-c5ccc6ccccc6c5)nc(-c5ccc6c(c5)oc5ccccc56)n4)cc3)ccc2c1 ; c1ccc2cc(-c3nc(-c4ccc5ccccc5c4)nc(-c4cccc5c4oc4ccccc45)n3)ccc2c1] 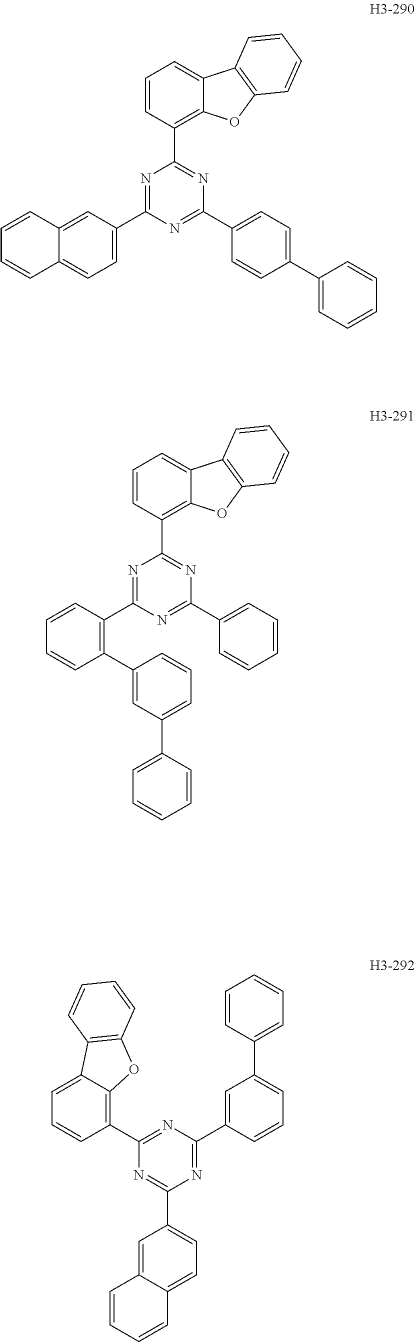 [SMILES: c1ccc(-c2ccc(-c3nc(-c4ccc5ccccc5c4)nc(-c4cccc5c4oc4ccccc45)n3)cc2)cc1 ; c1ccc(-c2cccc(-c3ccccc3-c3nc(-c4ccccc4)nc(-c4cccc5c4oc4ccccc45)n3)c2)cc1 ; c1ccc(-c2cccc(-c3nc(-c4ccc5ccccc5c4)nc(-c4cccc5c4oc4ccccc45)n3)c2)cc1] 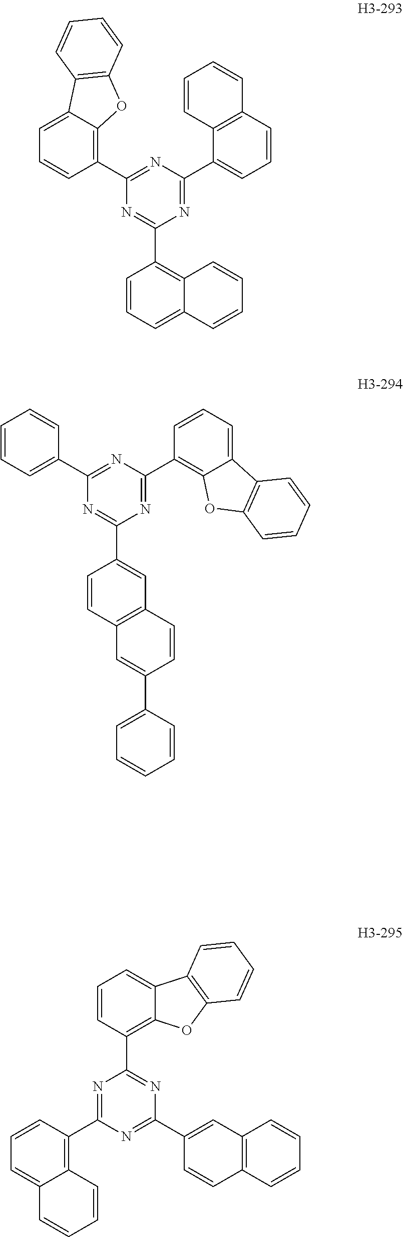 [SMILES: c1ccc2c(-c3nc(-c4cccc5ccccc45)nc(-c4cccc5c4oc4ccccc45)n3)cccc2c1 ; c1ccc(-c2ccc3cc(-c4nc(-c5ccccc5)nc(-c5cccc6c5oc5ccccc56)n4)ccc3c2)cc1 ; c1ccc2cc(-c3nc(-c4cccc5ccccc45)nc(-c4cccc5c4oc4ccccc45)n3)ccc2c1] 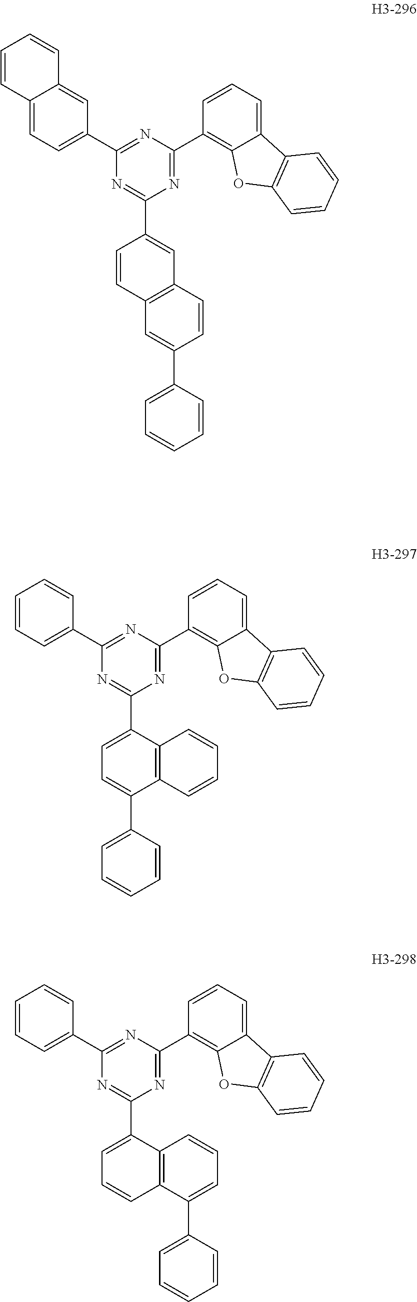 [SMILES: c1ccc(-c2ccc3cc(-c4nc(-c5ccc6ccccc6c5)nc(-c5cccc6c5oc5ccccc56)n4)ccc3c2)cc1 ; c1ccc(-c2nc(-c3ccc(-c4ccccc4)c4ccccc34)nc(-c3cccc4c3oc3ccccc34)n2)cc1 ; c1ccc(-c2nc(-c3cccc4c(-c5ccccc5)cccc34)nc(-c3cccc4c3oc3ccccc34)n2)cc1] 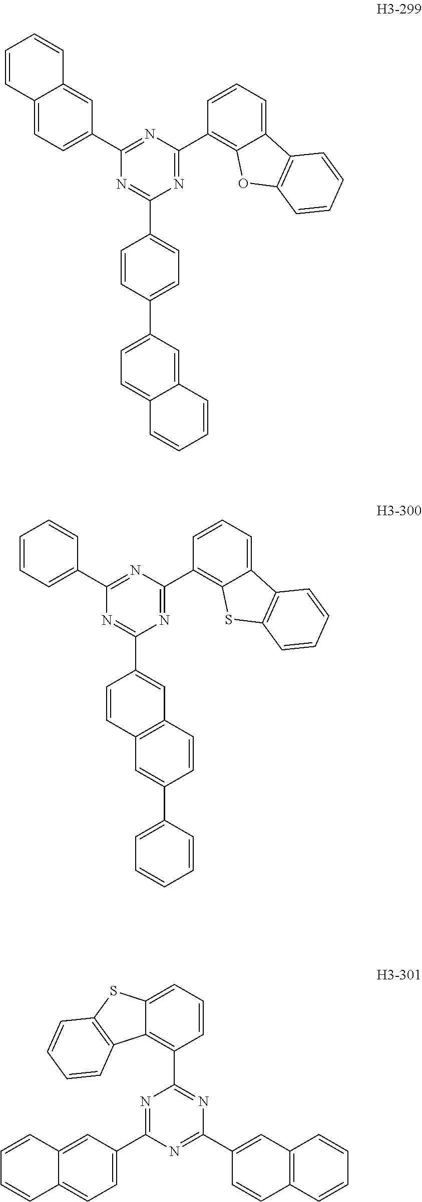 [SMILES: c1ccc2cc(-c3ccc(-c4nc(-c5ccc6ccccc6c5)nc(-c5cccc6c5oc5ccccc56)n4)cc3)ccc2c1 ; c1ccc(-c2ccc3cc(-c4nc(-c5ccccc5)nc(-c5cccc6c5sc5ccccc56)n4)ccc3c2)cc1 ; c1ccc2cc(-c3nc(-c4ccc5ccccc5c4)nc(-c4cccc5sc6ccccc6c45)n3)ccc2c1] 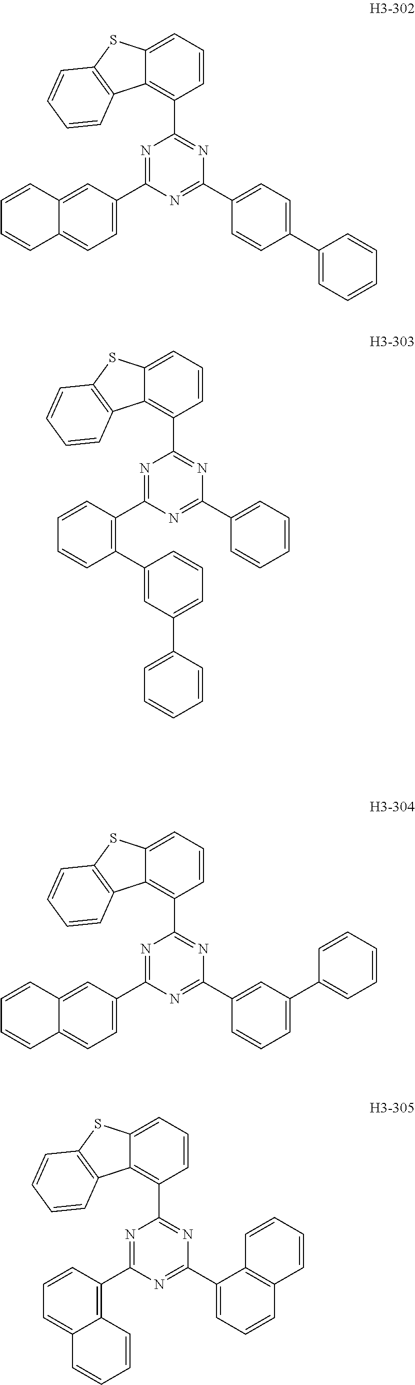 [SMILES: c1ccc(-c2ccc(-c3nc(-c4ccc5ccccc5c4)nc(-c4cccc5sc6ccccc6c45)n3)cc2)cc1 ; c1ccc(-c2cccc(-c3ccccc3-c3nc(-c4ccccc4)nc(-c4cccc5sc6ccccc6c45)n3)c2)cc1 ; c1ccc(-c2cccc(-c3nc(-c4ccc5ccccc5c4)nc(-c4cccc5sc6ccccc6c45)n3)c2)cc1 ; c1ccc2c(-c3nc(-c4cccc5ccccc45)nc(-c4cccc5sc6ccccc6c45)n3)cccc2c1] 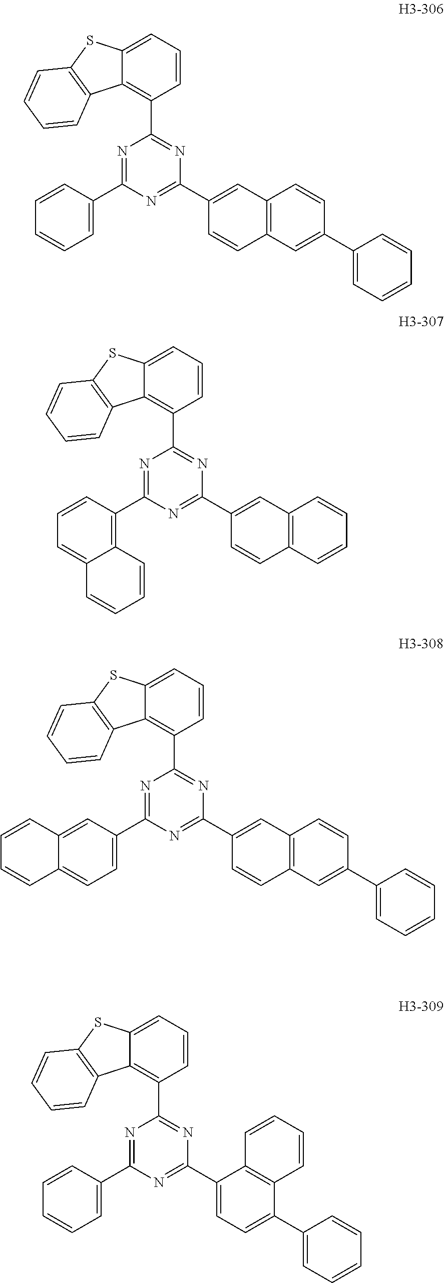 [SMILES: c1ccc(-c2ccc3cc(-c4nc(-c5ccccc5)nc(-c5cccc6sc7ccccc7c56)n4)ccc3c2)cc1 ; c1ccc2cc(-c3nc(-c4cccc5ccccc45)nc(-c4cccc5sc6ccccc6c45)n3)ccc2c1 ; c1ccc(-c2ccc3cc(-c4nc(-c5ccc6ccccc6c5)nc(-c5cccc6sc7ccccc7c56)n4)ccc3c2)cc1 ; c1ccc(-c2nc(-c3ccc(-c4ccccc4)c4ccccc34)nc(-c3cccc4sc5ccccc5c34)n2)cc1] 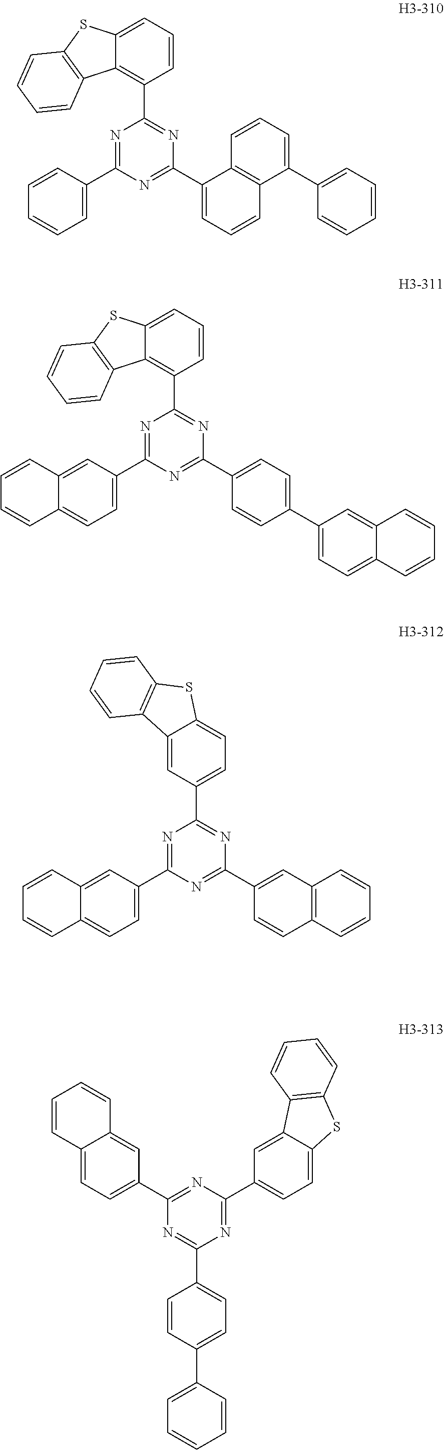 [SMILES: c1ccc(-c2nc(-c3cccc4c(-c5ccccc5)cccc34)nc(-c3cccc4sc5ccccc5c34)n2)cc1 ; c1ccc2cc(-c3ccc(-c4nc(-c5ccc6ccccc6c5)nc(-c5cccc6sc7ccccc7c56)n4)cc3)ccc2c1 ; c1ccc2cc(-c3nc(-c4ccc5ccccc5c4)nc(-c4ccc5sc6ccccc6c5c4)n3)ccc2c1 ; c1ccc(-c2ccc(-c3nc(-c4ccc5ccccc5c4)nc(-c4ccc5sc6ccccc6c5c4)n3)cc2)cc1] 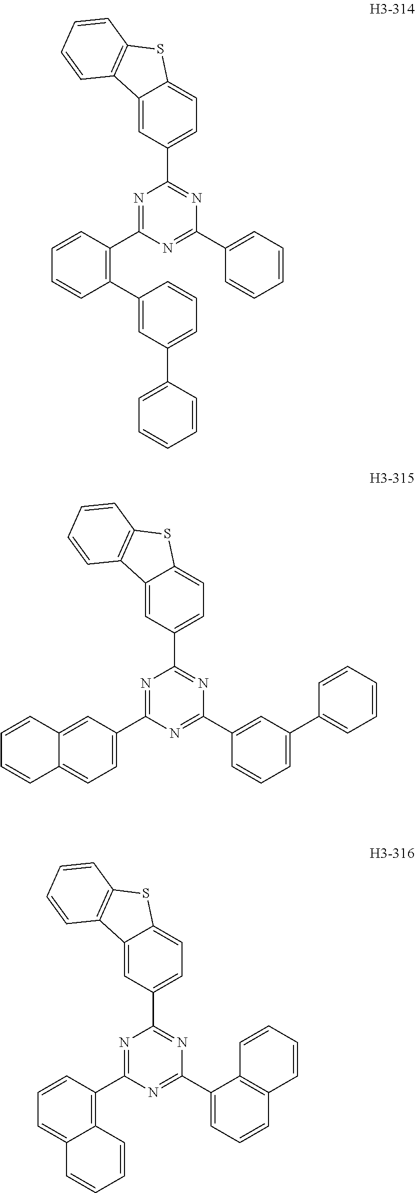 [SMILES: c1ccc(-c2cccc(-c3ccccc3-c3nc(-c4ccccc4)nc(-c4ccc5sc6ccccc6c5c4)n3)c2)cc1 ; c1ccc(-c2cccc(-c3nc(-c4ccc5ccccc5c4)nc(-c4ccc5sc6ccccc6c5c4)n3)c2)cc1 ; c1ccc2c(-c3nc(-c4ccc5sc6ccccc6c5c4)nc(-c4cccc5ccccc45)n3)cccc2c1] 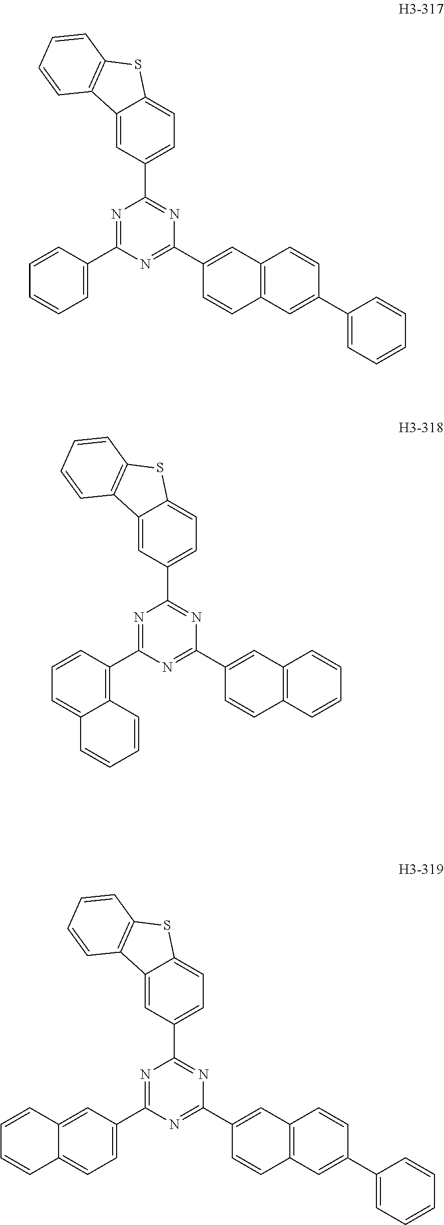 [SMILES: c1ccc(-c2ccc3cc(-c4nc(-c5ccccc5)nc(-c5ccc6sc7ccccc7c6c5)n4)ccc3c2)cc1 ; c1ccc2cc(-c3nc(-c4ccc5sc6ccccc6c5c4)nc(-c4cccc5ccccc45)n3)ccc2c1 ; c1ccc(-c2ccc3cc(-c4nc(-c5ccc6ccccc6c5)nc(-c5ccc6sc7ccccc7c6c5)n4)ccc3c2)cc1] 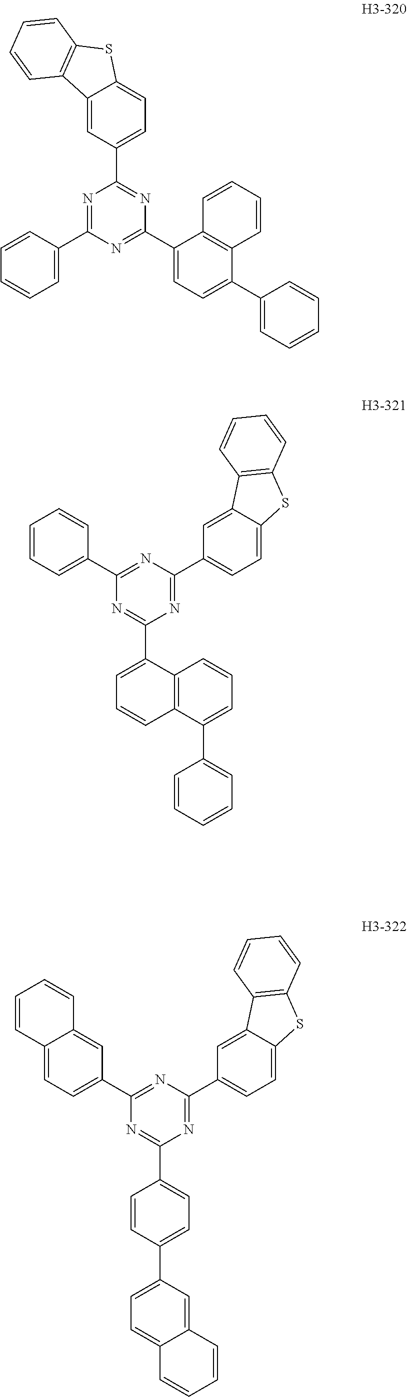 [SMILES: c1ccc(-c2nc(-c3ccc4sc5ccccc5c4c3)nc(-c3ccc(-c4ccccc4)c4ccccc34)n2)cc1 ; c1ccc(-c2nc(-c3ccc4sc5ccccc5c4c3)nc(-c3cccc4c(-c5ccccc5)cccc34)n2)cc1 ; c1ccc2cc(-c3ccc(-c4nc(-c5ccc6ccccc6c5)nc(-c5ccc6sc7ccccc7c6c5)n4)cc3)ccc2c1] 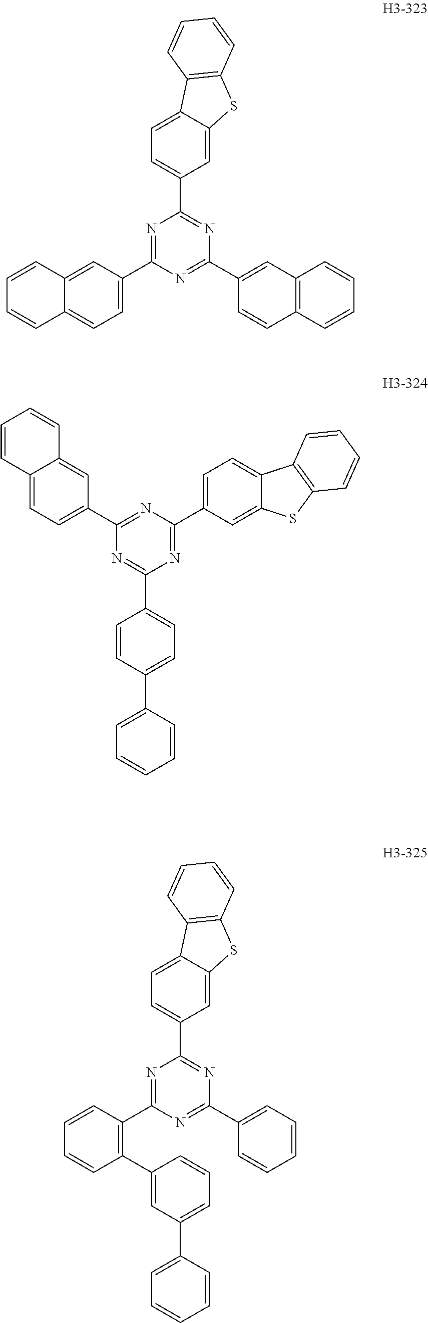 [SMILES: c1ccc2cc(-c3nc(-c4ccc5ccccc5c4)nc(-c4ccc5c(c4)sc4ccccc45)n3)ccc2c1 ; c1ccc(-c2ccc(-c3nc(-c4ccc5ccccc5c4)nc(-c4ccc5c(c4)sc4ccccc45)n3)cc2)cc1 ; c1ccc(-c2cccc(-c3ccccc3-c3nc(-c4ccccc4)nc(-c4ccc5c(c4)sc4ccccc45)n3)c2)cc1] 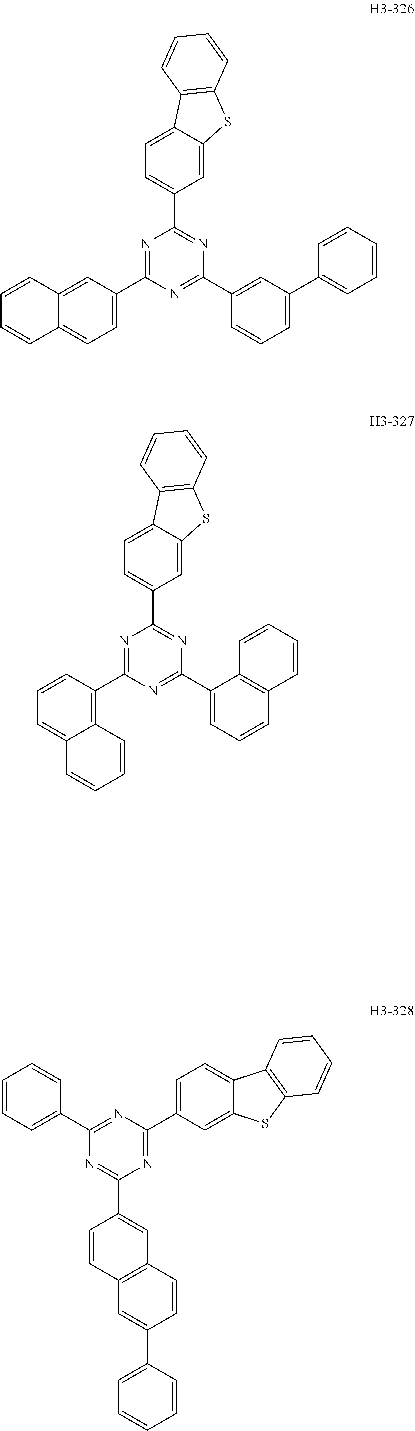 [SMILES: c1ccc(-c2cccc(-c3nc(-c4ccc5ccccc5c4)nc(-c4ccc5c(c4)sc4ccccc45)n3)c2)cc1 ; c1ccc2c(-c3nc(-c4ccc5c(c4)sc4ccccc45)nc(-c4cccc5ccccc45)n3)cccc2c1 ; c1ccc(-c2ccc3cc(-c4nc(-c5ccccc5)nc(-c5ccc6c(c5)sc5ccccc56)n4)ccc3c2)cc1] 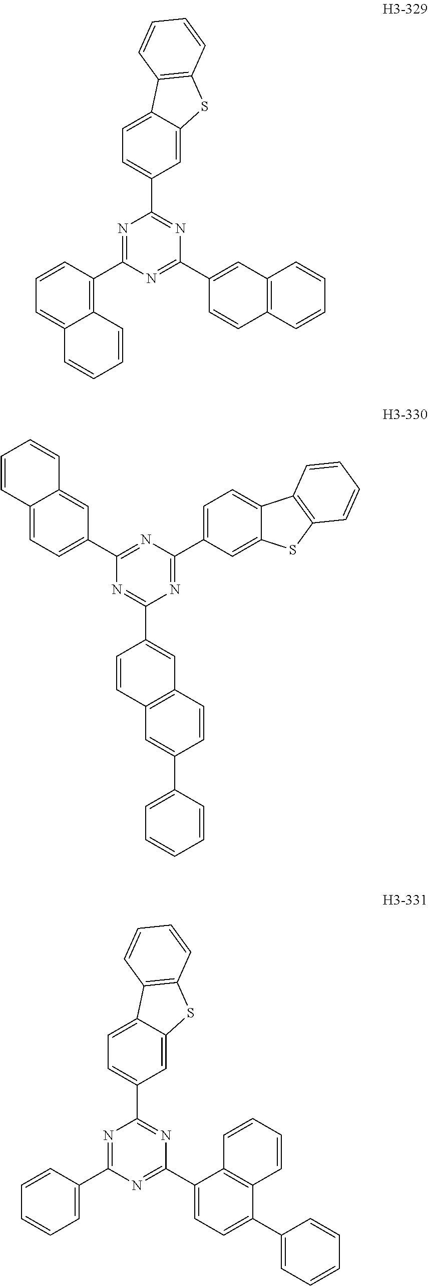 [SMILES: c1ccc2cc(-c3nc(-c4ccc5c(c4)sc4ccccc45)nc(-c4cccc5ccccc45)n3)ccc2c1 ; c1ccc(-c2ccc3cc(-c4nc(-c5ccc6ccccc6c5)nc(-c5ccc6c(c5)sc5ccccc56)n4)ccc3c2)cc1 ; c1ccc(-c2nc(-c3ccc4c(c3)sc3ccccc34)nc(-c3ccc(-c4ccccc4)c4ccccc34)n2)cc1] 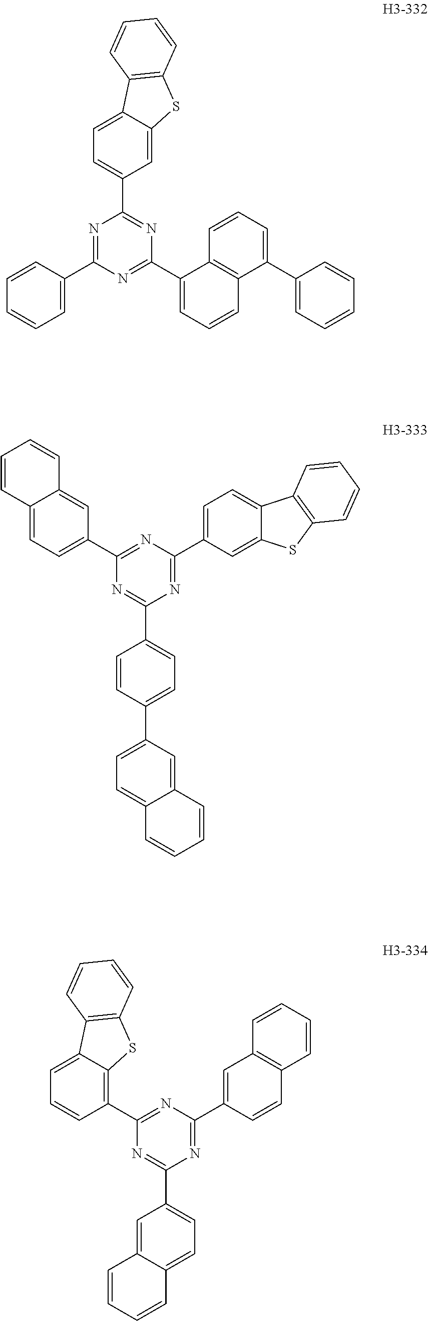 [SMILES: c1ccc(-c2nc(-c3ccc4c(c3)sc3ccccc34)nc(-c3cccc4c(-c5ccccc5)cccc34)n2)cc1 ; c1ccc2cc(-c3ccc(-c4nc(-c5ccc6ccccc6c5)nc(-c5ccc6c(c5)sc5ccccc56)n4)cc3)ccc2c1 ; c1ccc2cc(-c3nc(-c4ccc5ccccc5c4)nc(-c4cccc5c4sc4ccccc45)n3)ccc2c1] 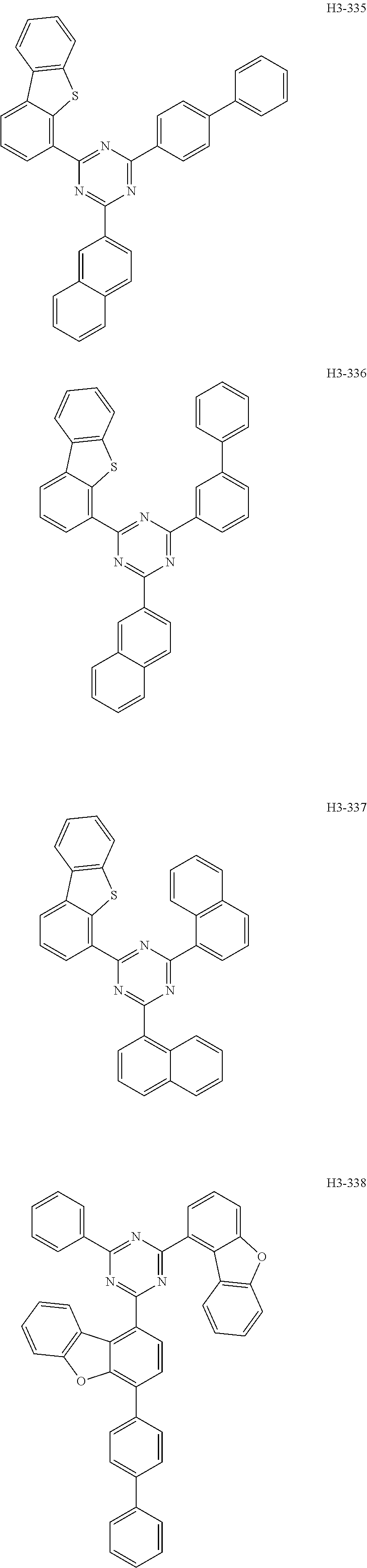 [SMILES: c1ccc(-c2ccc(-c3nc(-c4ccc5ccccc5c4)nc(-c4cccc5c4sc4ccccc45)n3)cc2)cc1 ; c1ccc(-c2cccc(-c3nc(-c4ccc5ccccc5c4)nc(-c4cccc5c4sc4ccccc45)n3)c2)cc1 ; c1ccc2c(-c3nc(-c4cccc5ccccc45)nc(-c4cccc5c4sc4ccccc45)n3)cccc2c1 ; c1ccc(-c2ccc(-c3ccc(-c4nc(-c5ccccc5)nc(-c5cccc6oc7ccccc7c56)n4)c4c3oc3ccccc34)cc2)cc1] 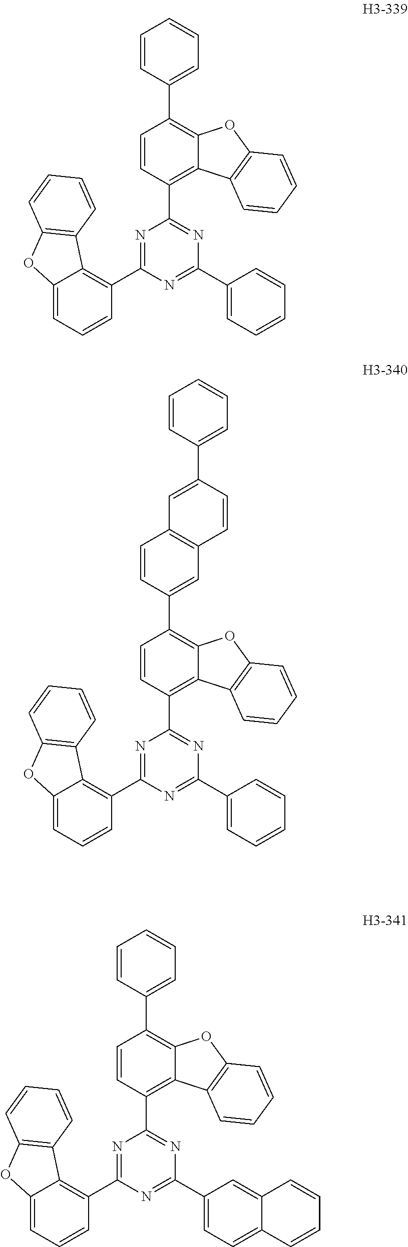 [SMILES: c1ccc(-c2nc(-c3cccc4oc5ccccc5c34)nc(-c3ccc(-c4ccccc4)c4oc5ccccc5c34)n2)cc1 ; c1ccc(-c2ccc3cc(-c4ccc(-c5nc(-c6ccccc6)nc(-c6cccc7oc8ccccc8c67)n5)c5c4oc4ccccc45)ccc3c2)cc1 ; c1ccc(-c2ccc(-c3nc(-c4ccc5ccccc5c4)nc(-c4cccc5oc6ccccc6c45)n3)c3c2oc2ccccc23)cc1] 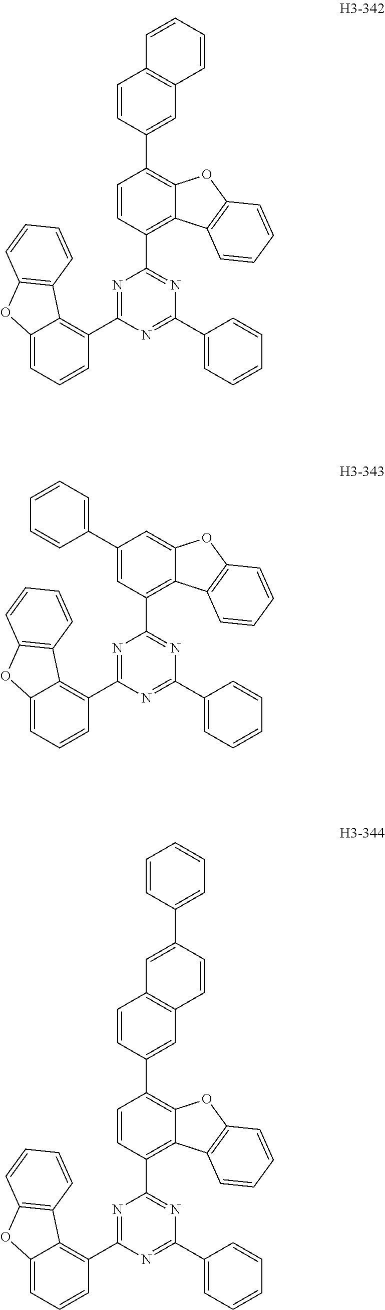 [SMILES: c1ccc(-c2nc(-c3cccc4oc5ccccc5c34)nc(-c3ccc(-c4ccc5ccccc5c4)c4oc5ccccc5c34)n2)cc1 ; c1ccc(-c2cc(-c3nc(-c4ccccc4)nc(-c4cccc5oc6ccccc6c45)n3)c3c(c2)oc2ccccc23)cc1 ; c1ccc(-c2ccc3cc(-c4ccc(-c5nc(-c6ccccc6)nc(-c6cccc7oc8ccccc8c67)n5)c5c4oc4ccccc45)ccc3c2)cc1] 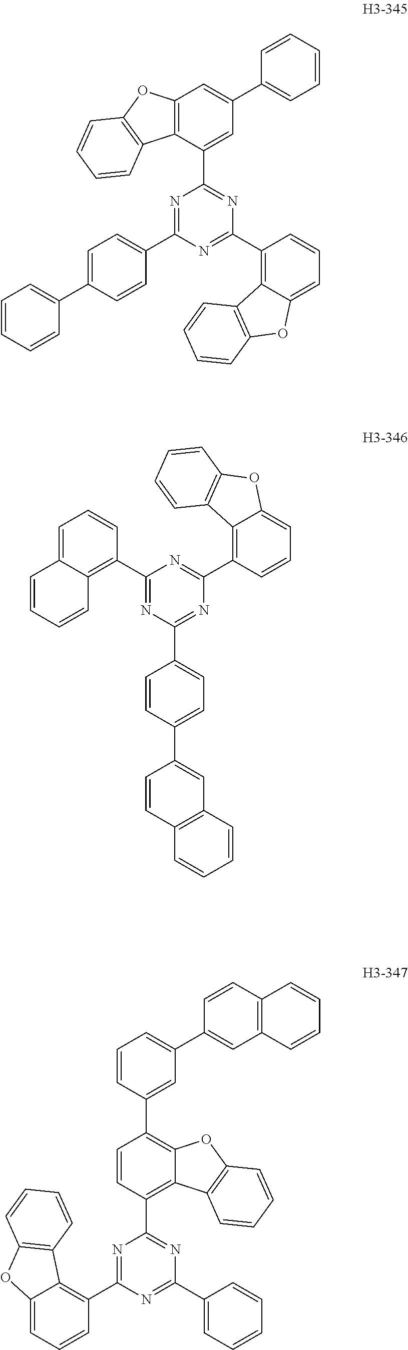 [SMILES: c1ccc(-c2ccc(-c3nc(-c4cccc5oc6ccccc6c45)nc(-c4cc(-c5ccccc5)cc5oc6ccccc6c45)n3)cc2)cc1 ; c1ccc2cc(-c3ccc(-c4nc(-c5cccc6ccccc56)nc(-c5cccc6oc7ccccc7c56)n4)cc3)ccc2c1 ; c1ccc(-c2nc(-c3cccc4oc5ccccc5c34)nc(-c3ccc(-c4cccc(-c5ccc6ccccc6c5)c4)c4oc5ccccc5c34)n2)cc1] 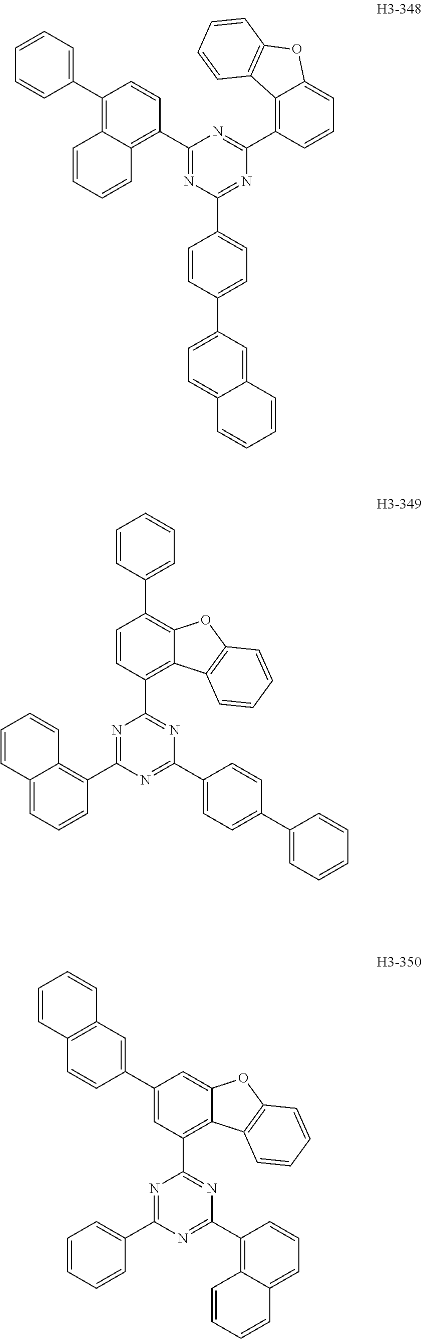 [SMILES: c1ccc(-c2ccc(-c3nc(-c4ccc(-c5ccc6ccccc6c5)cc4)nc(-c4cccc5oc6ccccc6c45)n3)c3ccccc23)cc1 ; c1ccc(-c2ccc(-c3nc(-c4cccc5ccccc45)nc(-c4ccc(-c5ccccc5)c5oc6ccccc6c45)n3)cc2)cc1 ; c1ccc(-c2nc(-c3cccc4ccccc34)nc(-c3cc(-c4ccc5ccccc5c4)cc4oc5ccccc5c34)n2)cc1] 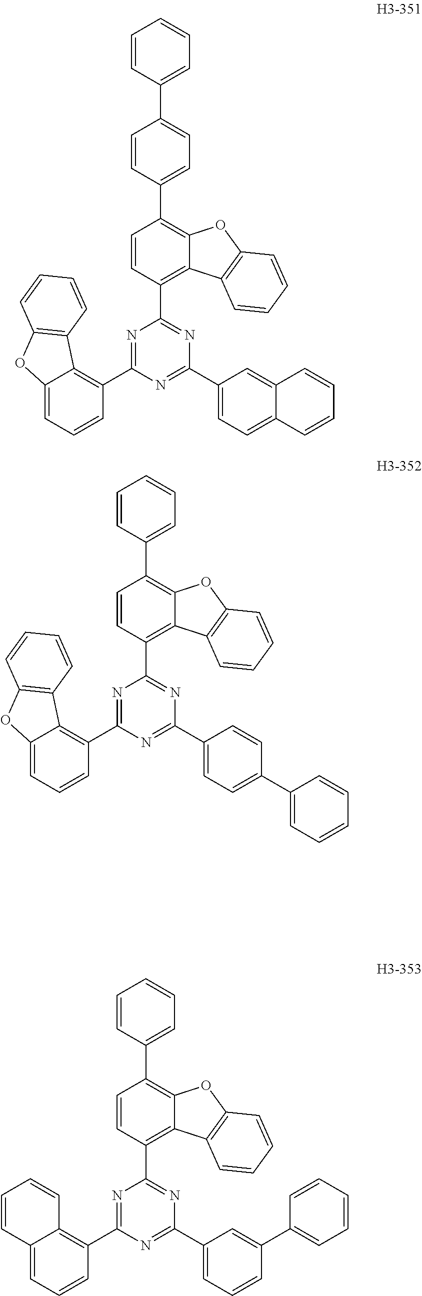 [SMILES: c1ccc(-c2ccc(-c3ccc(-c4nc(-c5ccc6ccccc6c5)nc(-c5cccc6oc7ccccc7c56)n4)c4c3oc3ccccc34)cc2)cc1 ; c1ccc(-c2ccc(-c3nc(-c4cccc5oc6ccccc6c45)nc(-c4ccc(-c5ccccc5)c5oc6ccccc6c45)n3)cc2)cc1 ; c1ccc(-c2cccc(-c3nc(-c4cccc5ccccc45)nc(-c4ccc(-c5ccccc5)c5oc6ccccc6c45)n3)c2)cc1] 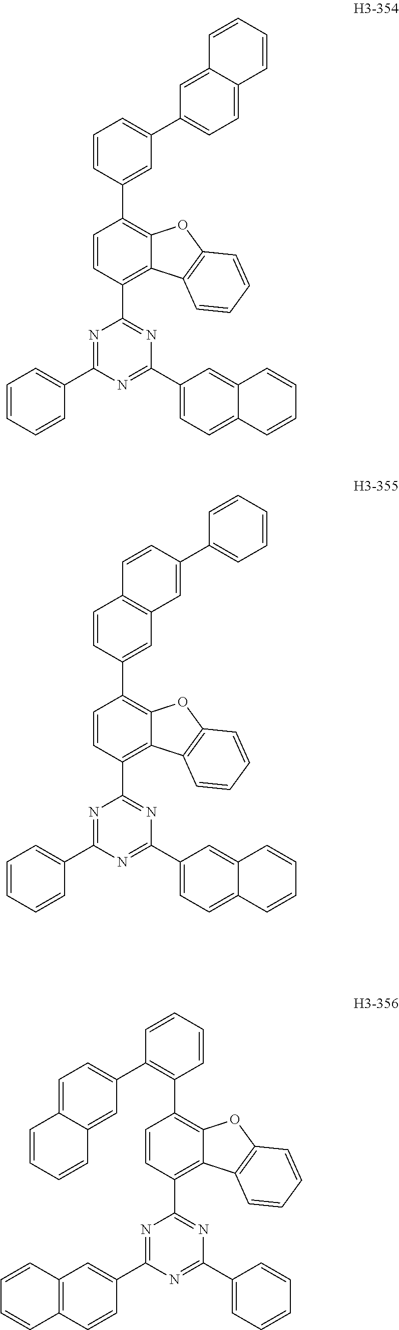 [SMILES: c1ccc(-c2nc(-c3ccc4ccccc4c3)nc(-c3ccc(-c4cccc(-c5ccc6ccccc6c5)c4)c4oc5ccccc5c34)n2)cc1 ; c1ccc(-c2ccc3ccc(-c4ccc(-c5nc(-c6ccccc6)nc(-c6ccc7ccccc7c6)n5)c5c4oc4ccccc45)cc3c2)cc1 ; c1ccc(-c2nc(-c3ccc4ccccc4c3)nc(-c3ccc(-c4ccccc4-c4ccc5ccccc5c4)c4oc5ccccc5c34)n2)cc1] 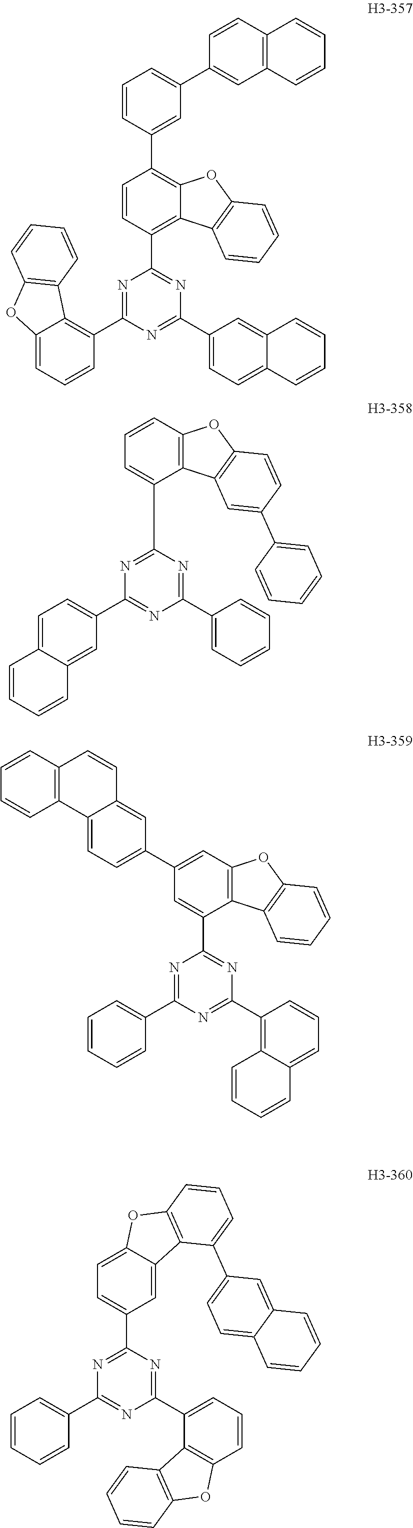 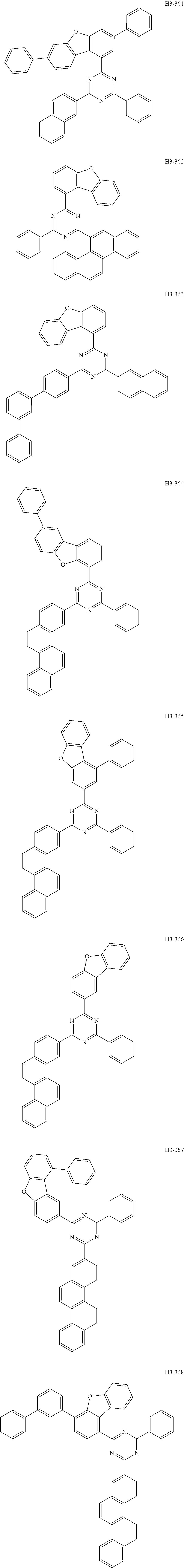 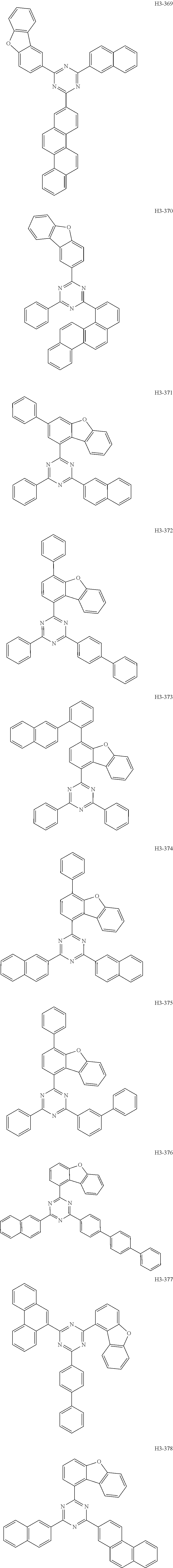 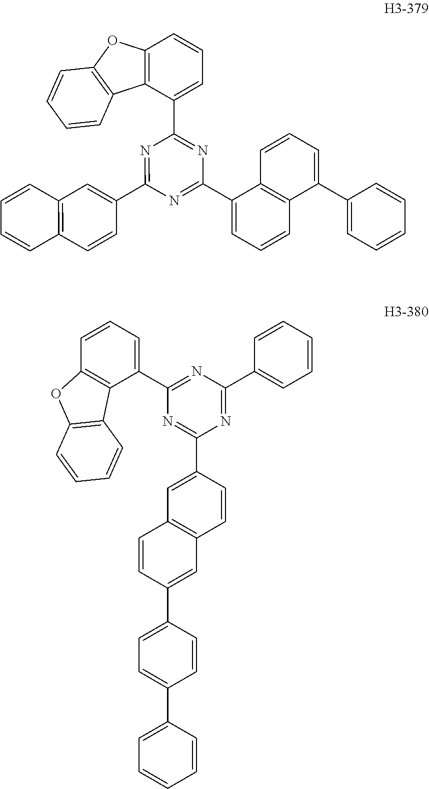 [SMILES: c1ccc(-c2cccc3c(-c4nc(-c5ccc6ccccc6c5)nc(-c5cccc6oc7ccccc7c56)n4)cccc23)cc1 ; c1ccc(-c2ccc(-c3ccc4cc(-c5nc(-c6ccccc6)nc(-c6cccc7oc8ccccc8c67)n5)ccc4c3)cc2)cc1] 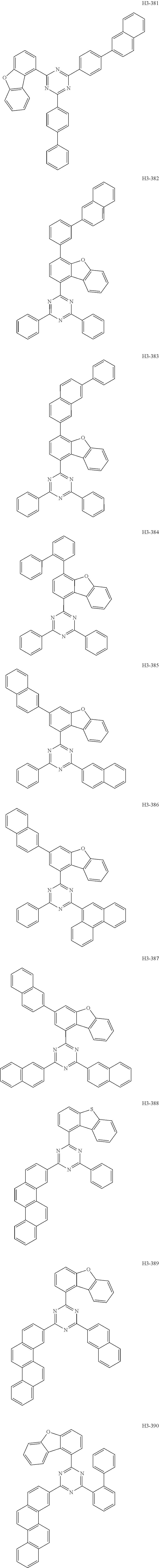 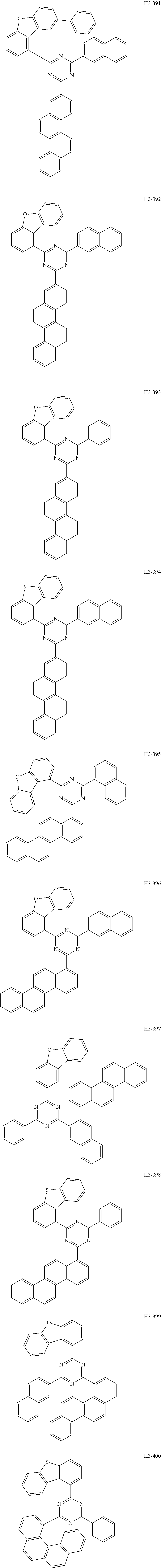 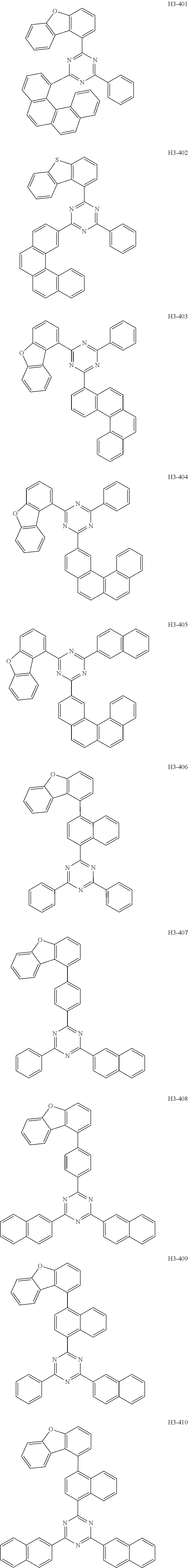 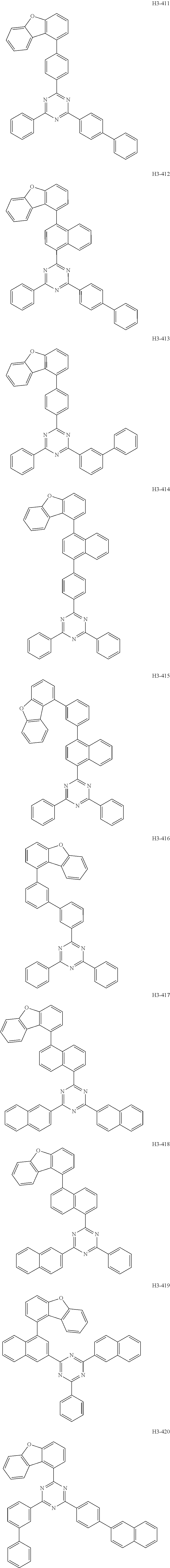 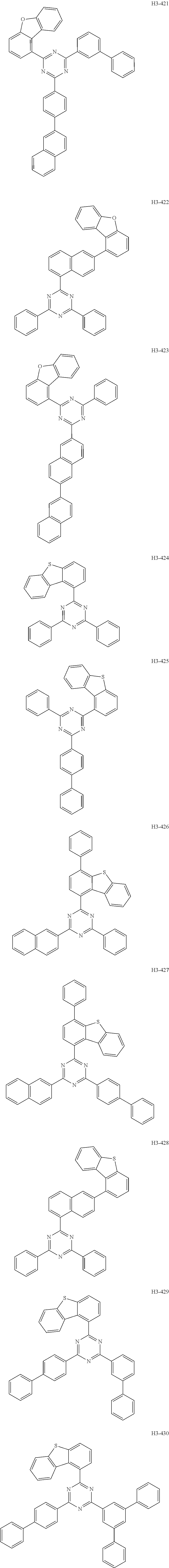 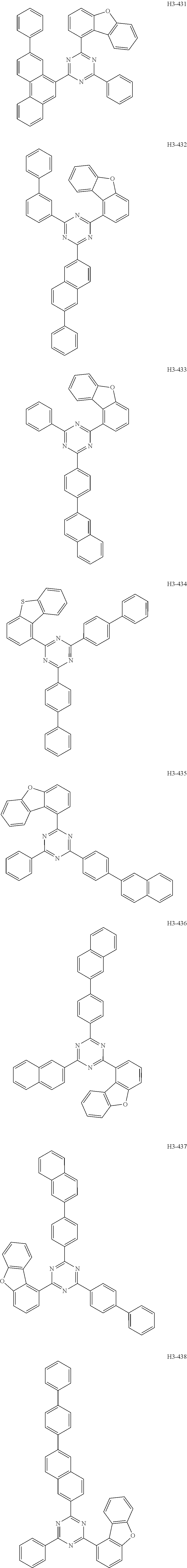 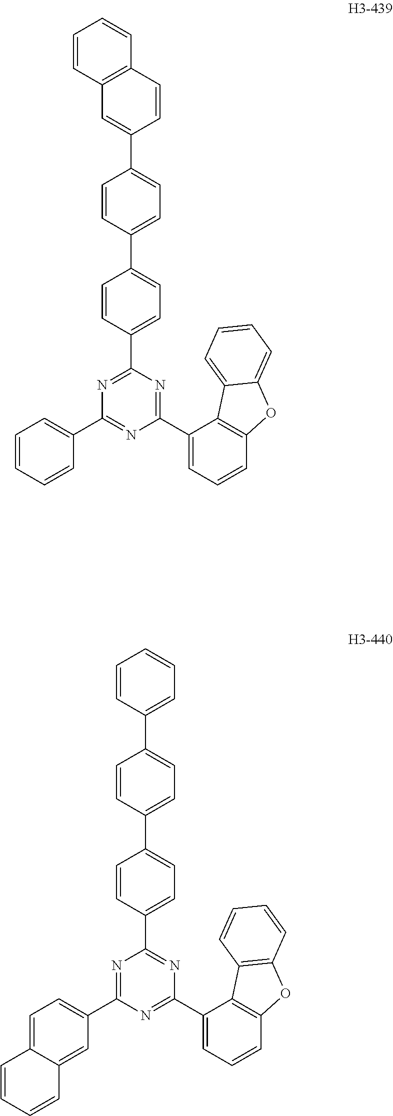 [SMILES: c1ccc(-c2nc(-c3ccc(-c4ccc(-c5ccc6ccccc6c5)cc4)cc3)nc(-c3cccc4oc5ccccc5c34)n2)cc1 ; c1ccc(-c2ccc(-c3ccc(-c4nc(-c5ccc6ccccc6c5)nc(-c5cccc6oc7ccccc7c56)n4)cc3)cc2)cc1] 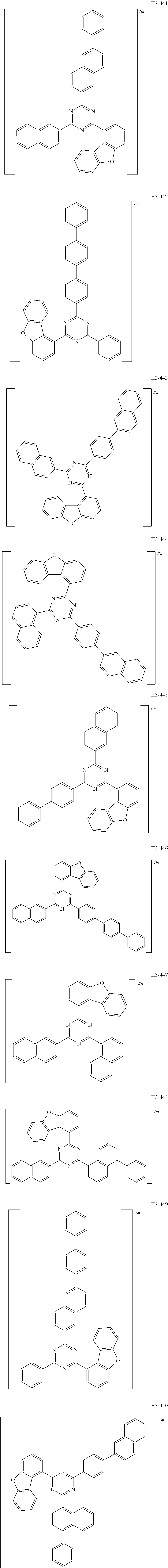 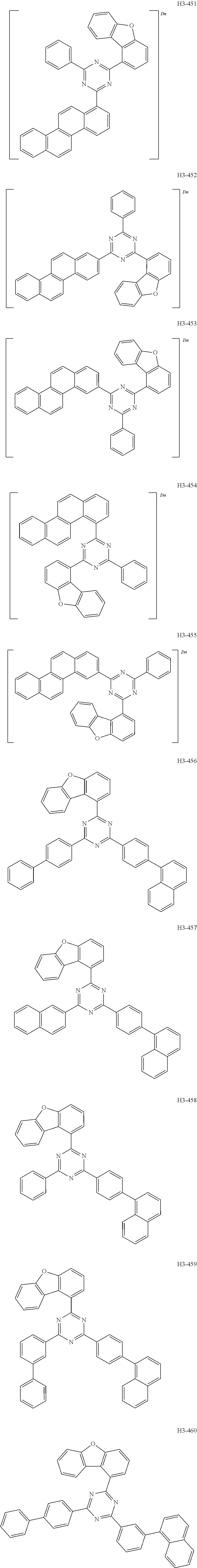 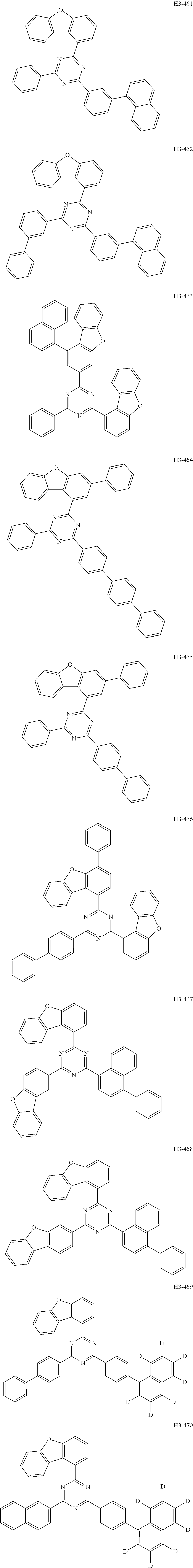 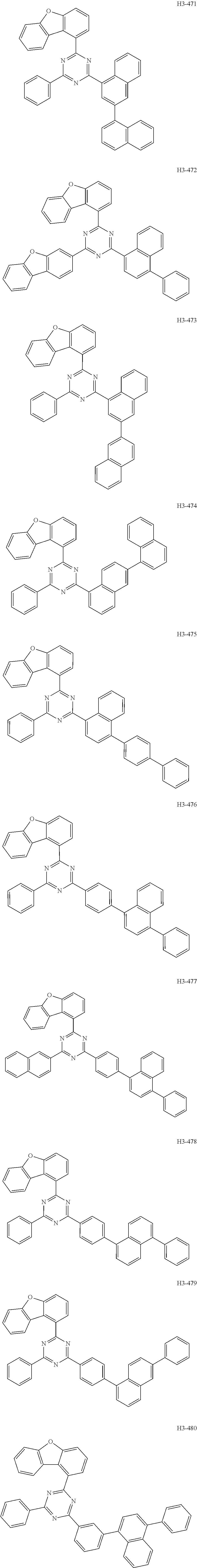 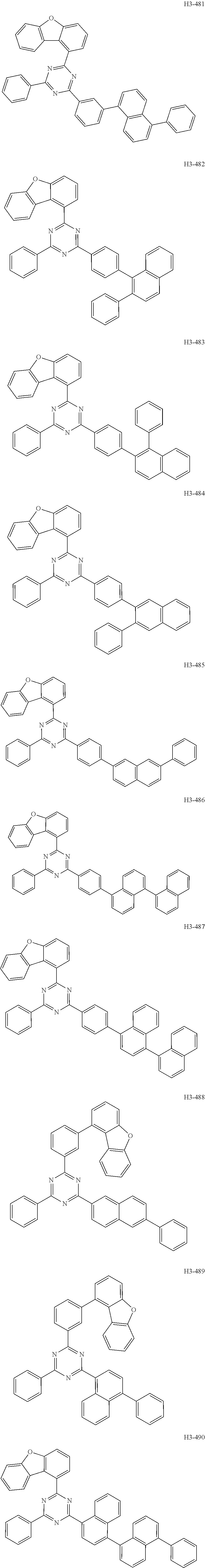 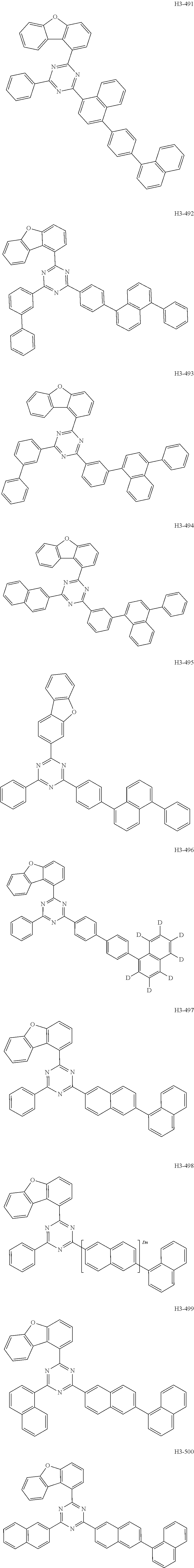 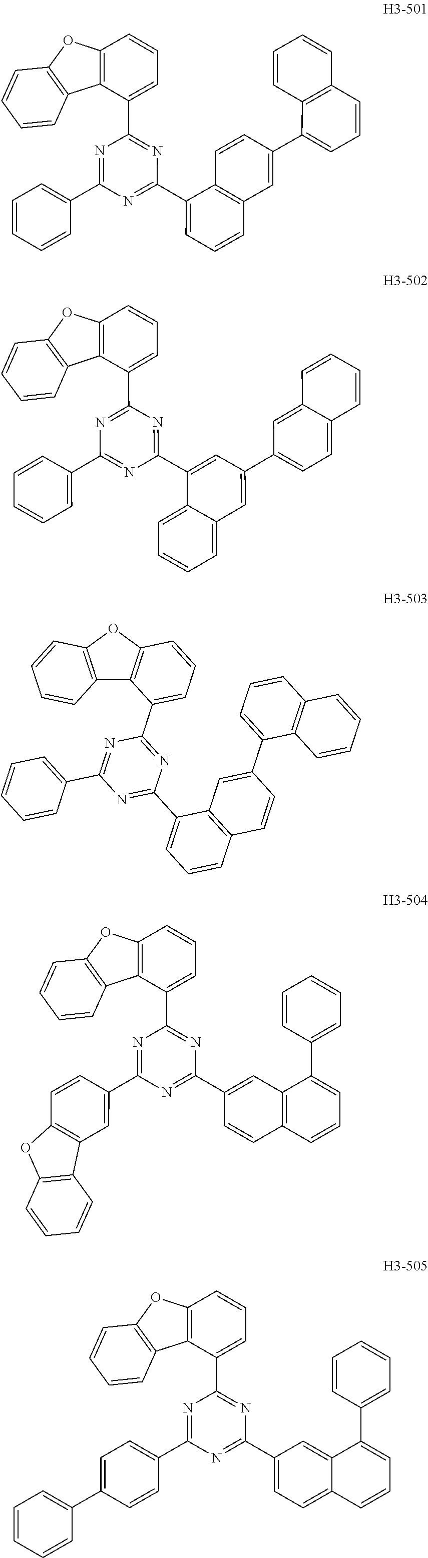 [SMILES: c1ccc(-c2nc(-c3cccc4cc(-c5cccc6ccccc56)ccc34)nc(-c3cccc4oc5ccccc5c34)n2)cc1 ; c1ccc(-c2nc(-c3cc(-c4ccc5ccccc5c4)cc4ccccc34)nc(-c3cccc4oc5ccccc5c34)n2)cc1 ; c1ccc(-c2nc(-c3cccc4ccc(-c5cccc6ccccc56)cc34)nc(-c3cccc4oc5ccccc5c34)n2)cc1 ; c1ccc(-c2cccc3ccc(-c4nc(-c5ccc6oc7ccccc7c6c5)nc(-c5cccc6oc7ccccc7c56)n4)cc23)cc1 ; c1ccc(-c2ccc(-c3nc(-c4ccc5cccc(-c6ccccc6)c5c4)nc(-c4cccc5oc6ccccc6c45)n3)cc2)cc1] 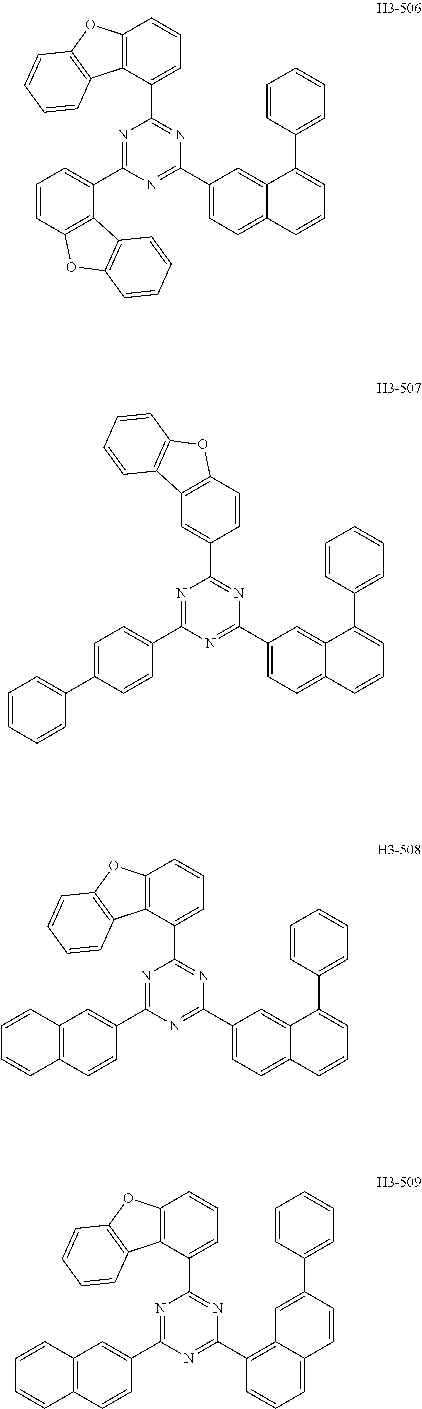 [SMILES: c1ccc(-c2cccc3ccc(-c4nc(-c5cccc6oc7ccccc7c56)nc(-c5cccc6oc7ccccc7c56)n4)cc23)cc1 ; c1ccc(-c2ccc(-c3nc(-c4ccc5cccc(-c6ccccc6)c5c4)nc(-c4ccc5oc6ccccc6c5c4)n3)cc2)cc1 ; c1ccc(-c2cccc3ccc(-c4nc(-c5ccc6ccccc6c5)nc(-c5cccc6oc7ccccc7c56)n4)cc23)cc1 ; c1ccc(-c2ccc3cccc(-c4nc(-c5ccc6ccccc6c5)nc(-c5cccc6oc7ccccc7c56)n4)c3c2)cc1] 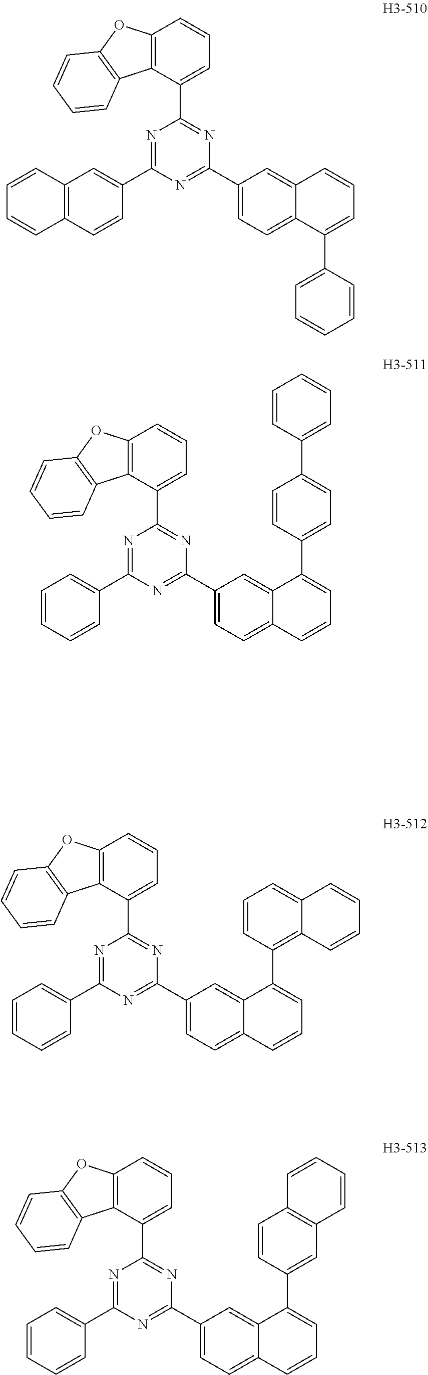 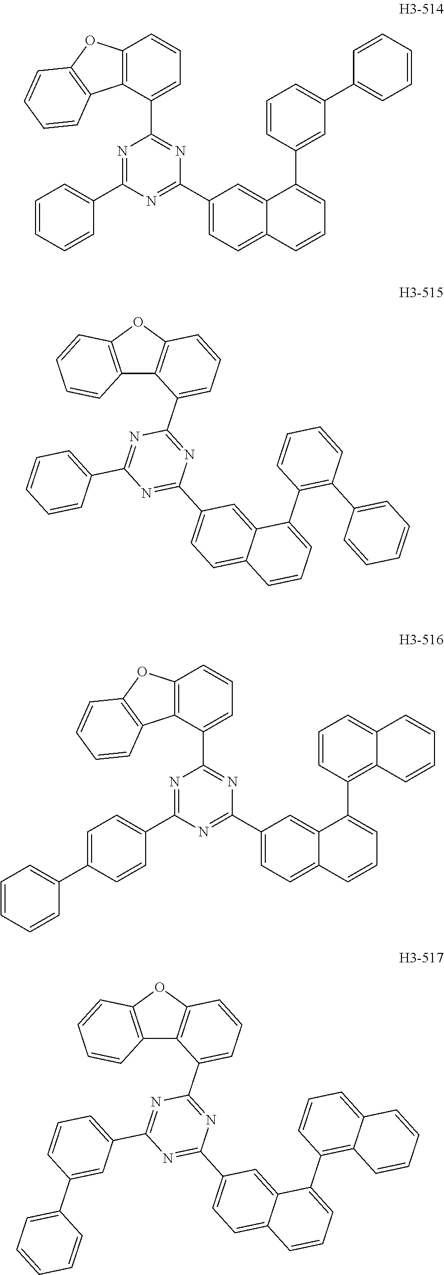 [SMILES: c1ccc(-c2cccc(-c3cccc4ccc(-c5nc(-c6ccccc6)nc(-c6cccc7oc8ccccc8c67)n5)cc34)c2)cc1 ; c1ccc(-c2nc(-c3ccc4cccc(-c5ccccc5-c5ccccc5)c4c3)nc(-c3cccc4oc5ccccc5c34)n2)cc1 ; c1ccc(-c2ccc(-c3nc(-c4ccc5cccc(-c6cccc7ccccc67)c5c4)nc(-c4cccc5oc6ccccc6c45)n3)cc2)cc1 ; c1ccc(-c2cccc(-c3nc(-c4ccc5cccc(-c6cccc7ccccc67)c5c4)nc(-c4cccc5oc6ccccc6c45)n3)c2)cc1] 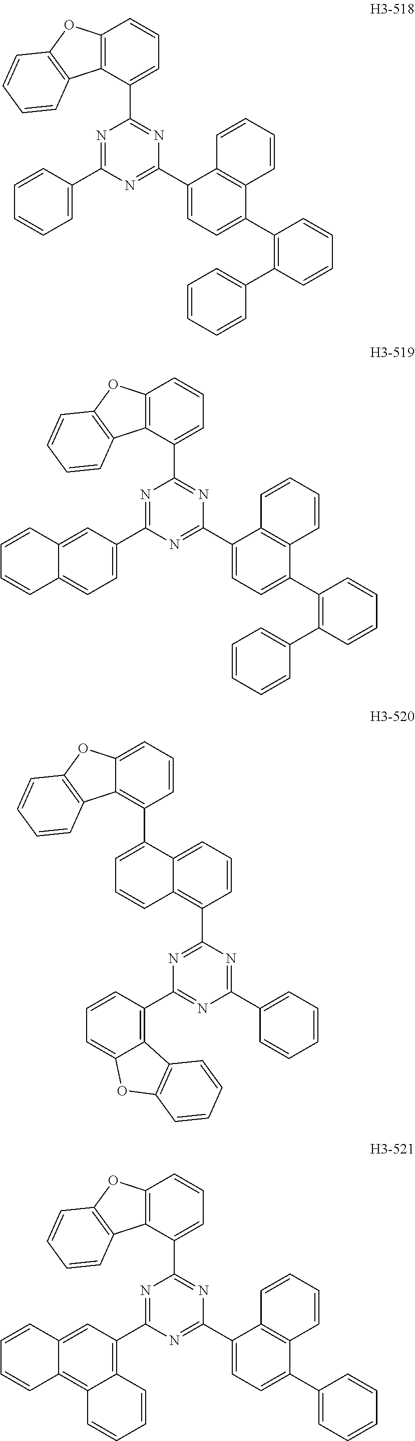 [SMILES: c1ccc(-c2nc(-c3ccc(-c4ccccc4-c4ccccc4)c4ccccc34)nc(-c3cccc4oc5ccccc5c34)n2)cc1 ; c1ccc(-c2ccccc2-c2ccc(-c3nc(-c4ccc5ccccc5c4)nc(-c4cccc5oc6ccccc6c45)n3)c3ccccc23)cc1 ; c1ccc(-c2nc(-c3cccc4c(-c5cccc6oc7ccccc7c56)cccc34)nc(-c3cccc4oc5ccccc5c34)n2)cc1 ; c1ccc(-c2ccc(-c3nc(-c4cc5ccccc5c5ccccc45)nc(-c4cccc5oc6ccccc6c45)n3)c3ccccc23)cc1] 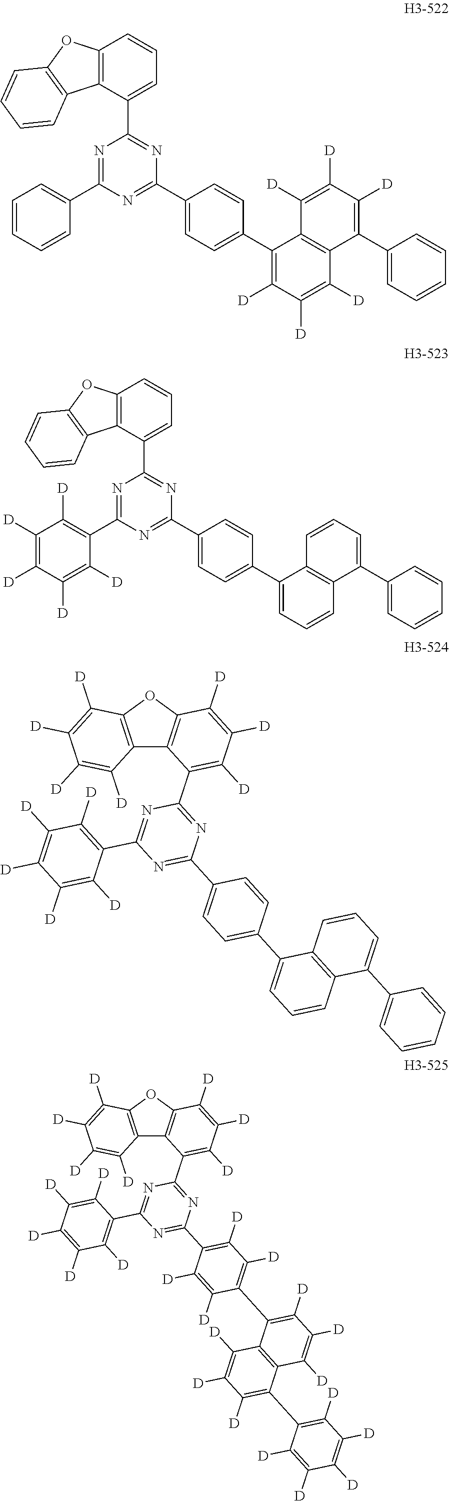 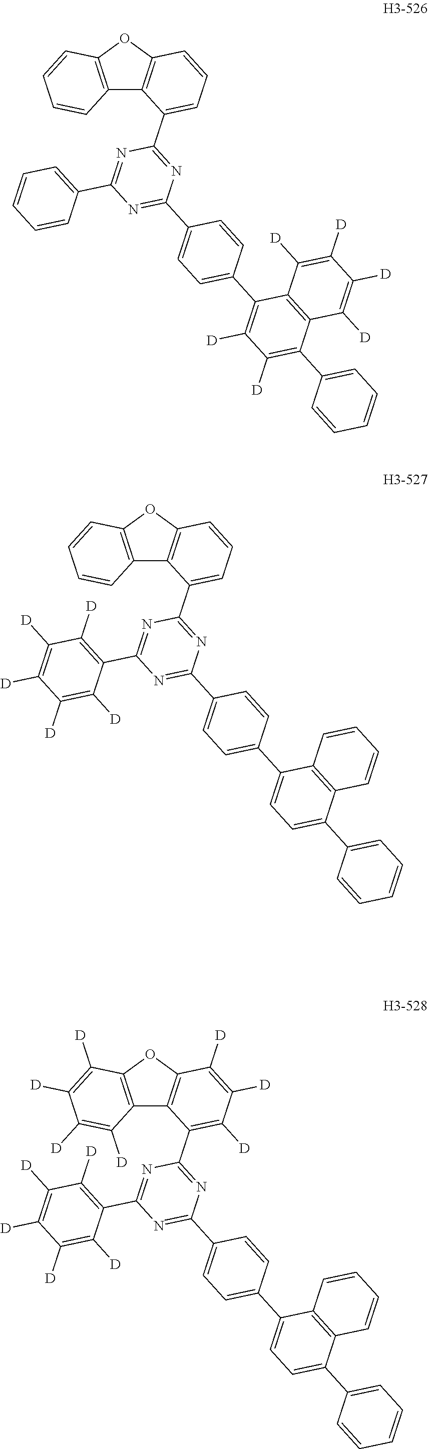 [SMILES: [2H]c1c([2H])c([2H])c2c(-c3ccc(-c4nc(-c5ccccc5)nc(-c5cccc6oc7ccccc7c56)n4)cc3)c([2H])c([2H])c(-c3ccccc3)c2c1[2H] ; [2H]c1c([2H])c([2H])c(-c2nc(-c3ccc(-c4ccc(-c5ccccc5)c5ccccc45)cc3)nc(-c3cccc4oc5ccccc5c34)n2)c([2H])c1[2H] ; [2H]c1c([2H])c([2H])c(-c2nc(-c3ccc(-c4ccc(-c5ccccc5)c5ccccc45)cc3)nc(-c3c([2H])c([2H])c([2H])c4oc5c([2H])c([2H])c([2H])c([2H])c5c34)n2)c([2H])c1[2H]] 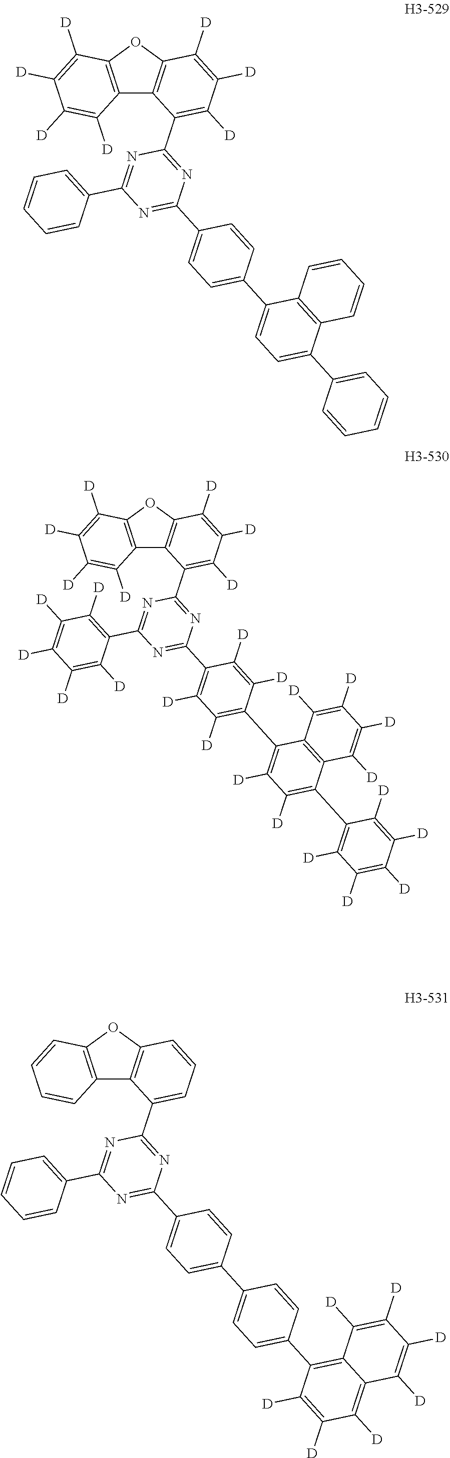 [SMILES: [2H]c1c([2H])c([2H])c2c(oc3c([2H])c([2H])c([2H])c(-c4nc(-c5ccccc5)nc(-c5ccc(-c6ccc(-c7ccccc7)c7ccccc67)cc5)n4)c32)c1[2H] ; [2H]c1c([2H])c([2H])c(-c2nc(-c3c([2H])c([2H])c(-c4c([2H])c([2H])c(-c5c([2H])c([2H])c([2H])c([2H])c5[2H])c5c([2H])c([2H])c([2H])c([2H])c45)c([2H])c3[2H])nc(-c3c([2H])c([2H])c([2H])c4oc5c([2H])c([2H])c([2H])c([2H])c5c34)n2)c([2H])c1[2H] ; [2H]c1c([2H])c([2H])c2c(-c3ccc(-c4ccc(-c5nc(-c6ccccc6)nc(-c6cccc7oc8ccccc8c67)n5)cc4)cc3)c([2H])c([2H])c([2H])c2c1[2H]] 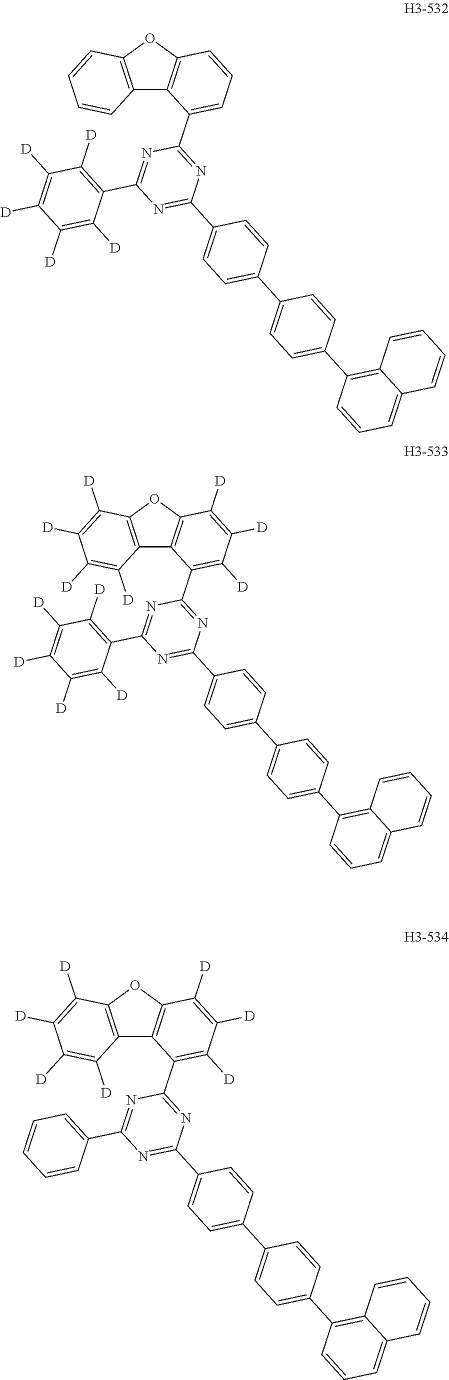 [SMILES: [2H]c1c([2H])c([2H])c(-c2nc(-c3ccc(-c4ccc(-c5cccc6ccccc56)cc4)cc3)nc(-c3cccc4oc5ccccc5c34)n2)c([2H])c1[2H] ; [2H]c1c([2H])c([2H])c(-c2nc(-c3ccc(-c4ccc(-c5cccc6ccccc56)cc4)cc3)nc(-c3c([2H])c([2H])c([2H])c4oc5c([2H])c([2H])c([2H])c([2H])c5c34)n2)c([2H])c1[2H] ; [2H]c1c([2H])c([2H])c2c(oc3c([2H])c([2H])c([2H])c(-c4nc(-c5ccccc5)nc(-c5ccc(-c6ccc(-c7cccc8ccccc78)cc6)cc5)n4)c32)c1[2H]] 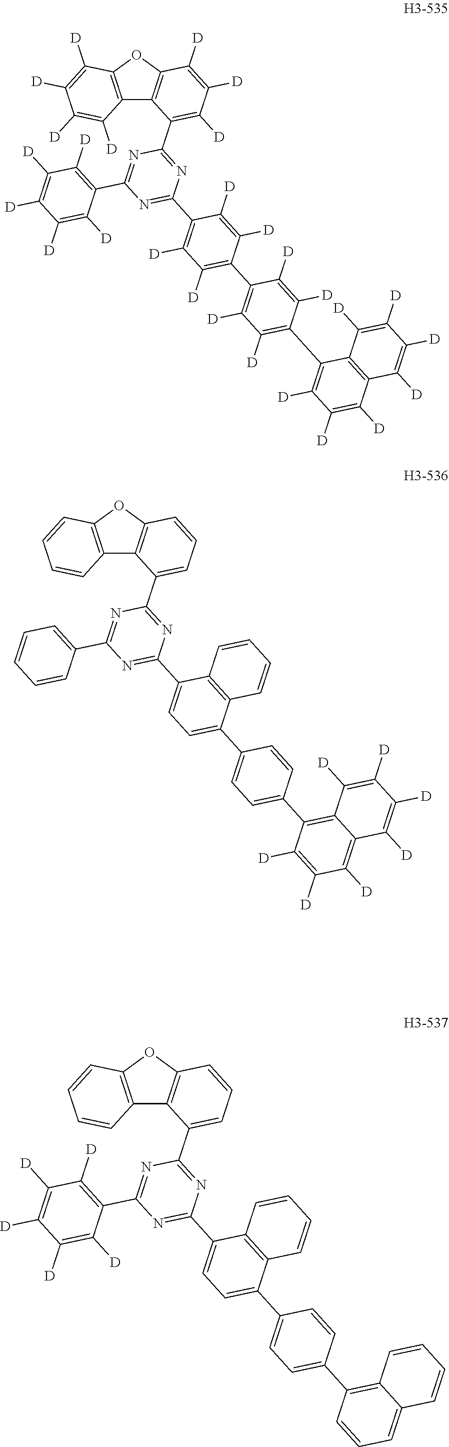 [SMILES: [2H]c1c([2H])c([2H])c(-c2nc(-c3c([2H])c([2H])c(-c4c([2H])c([2H])c(-c5c([2H])c([2H])c([2H])c6c([2H])c([2H])c([2H])c([2H])c56)c([2H])c4[2H])c([2H])c3[2H])nc(-c3c([2H])c([2H])c([2H])c4oc5c([2H])c([2H])c([2H])c([2H])c5c34)n2)c([2H])c1[2H] ; [2H]c1c([2H])c([2H])c2c(-c3ccc(-c4ccc(-c5nc(-c6ccccc6)nc(-c6cccc7oc8ccccc8c67)n5)c5ccccc45)cc3)c([2H])c([2H])c([2H])c2c1[2H] ; [2H]c1c([2H])c([2H])c(-c2nc(-c3ccc(-c4ccc(-c5cccc6ccccc56)cc4)c4ccccc34)nc(-c3cccc4oc5ccccc5c34)n2)c([2H])c1[2H]] 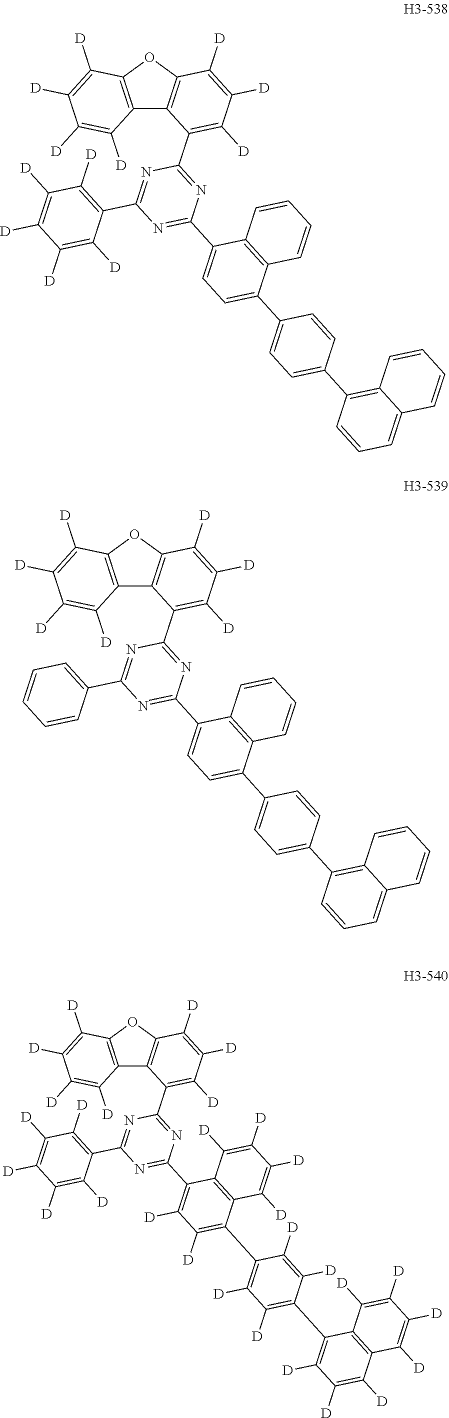 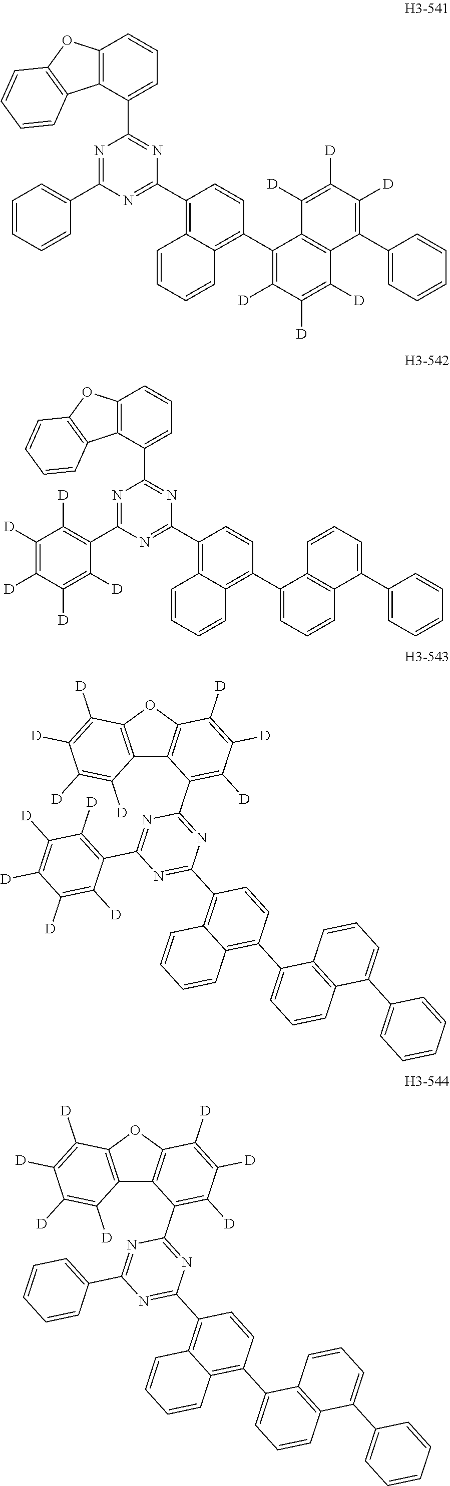 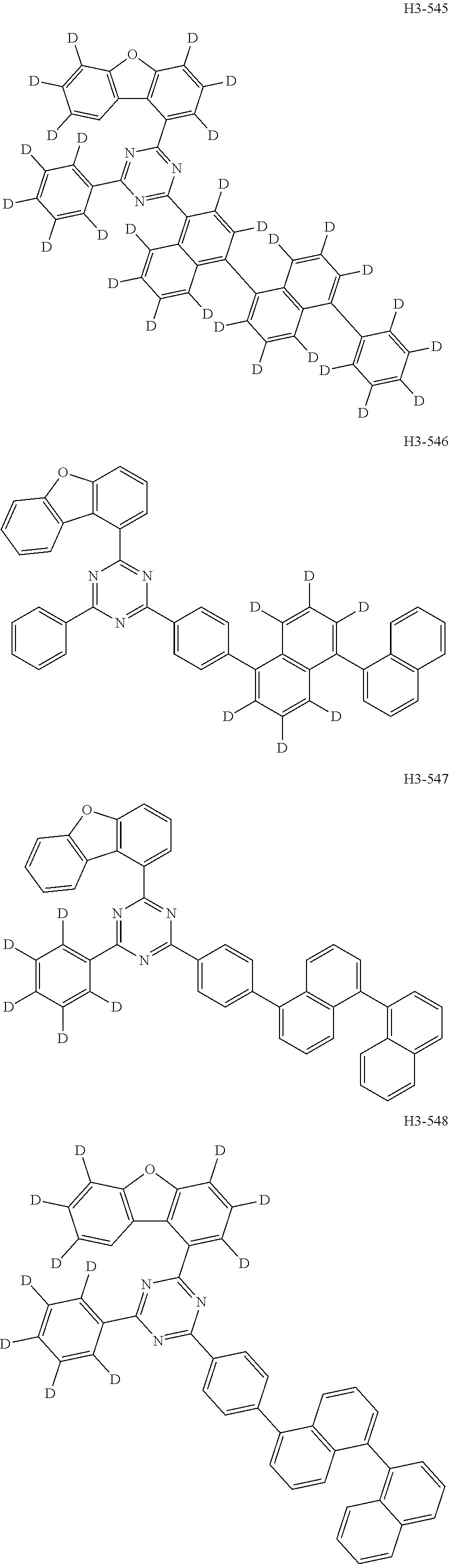 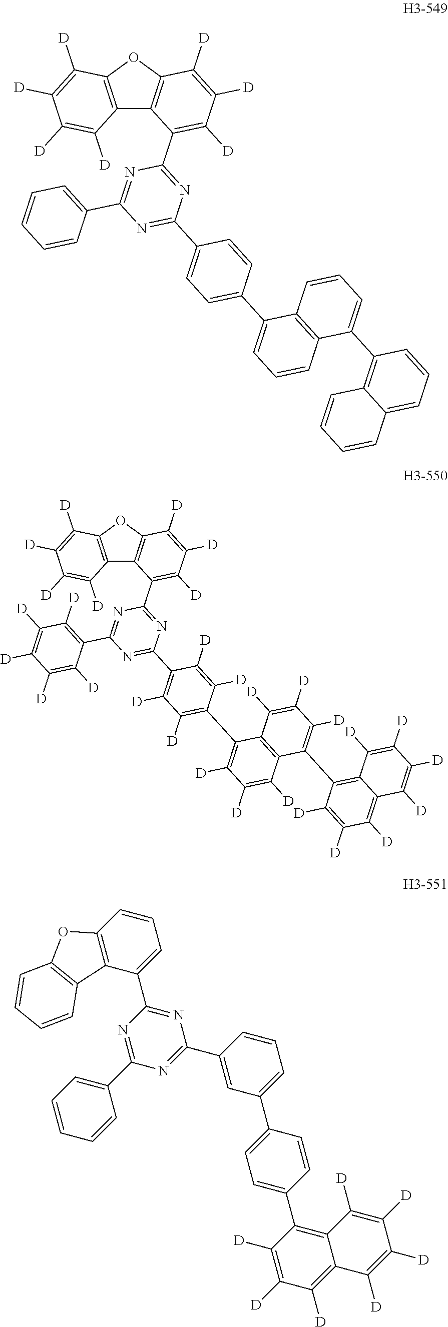 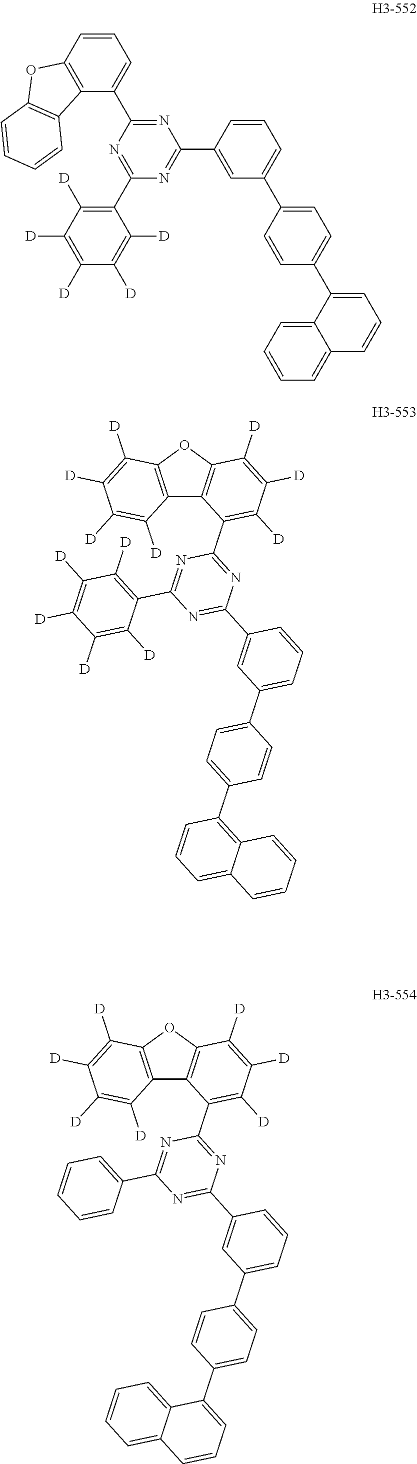 [SMILES: [2H]c1c([2H])c([2H])c(-c2nc(-c3cccc(-c4ccc(-c5cccc6ccccc56)cc4)c3)nc(-c3cccc4oc5ccccc5c34)n2)c([2H])c1[2H] ; [2H]c1c([2H])c([2H])c(-c2nc(-c3cccc(-c4ccc(-c5cccc6ccccc56)cc4)c3)nc(-c3c([2H])c([2H])c([2H])c4oc5c([2H])c([2H])c([2H])c([2H])c5c34)n2)c([2H])c1[2H] ; [2H]c1c([2H])c([2H])c2c(oc3c([2H])c([2H])c([2H])c(-c4nc(-c5ccccc5)nc(-c5cccc(-c6ccc(-c7cccc8ccccc78)cc6)c5)n4)c32)c1[2H]] 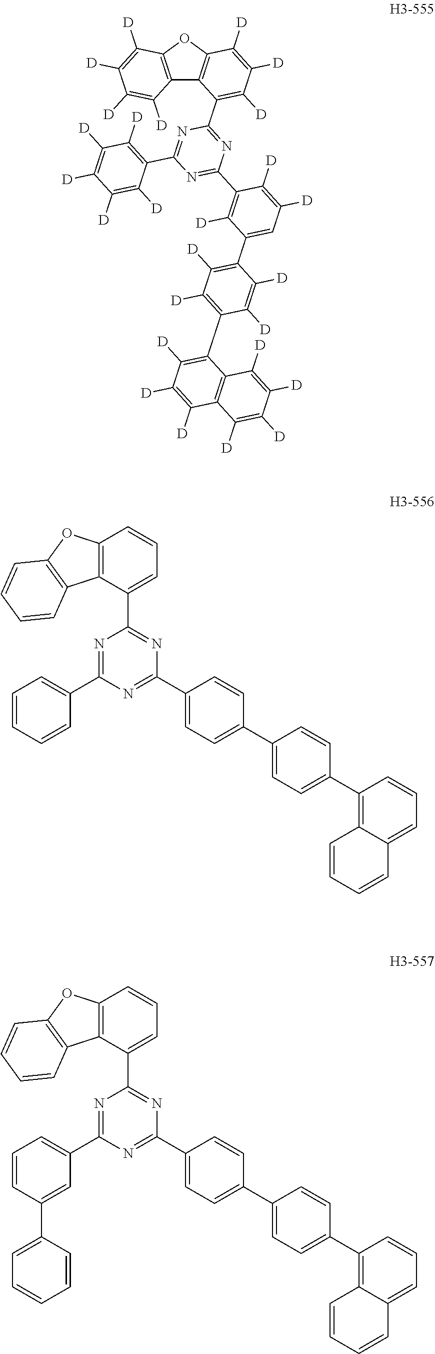 [SMILES: [2H]c1cc(-c2c([2H])c([2H])c(-c3c([2H])c([2H])c([2H])c4c([2H])c([2H])c([2H])c([2H])c34)c([2H])c2[2H])c([2H])c(-c2nc(-c3c([2H])c([2H])c([2H])c([2H])c3[2H])nc(-c3c([2H])c([2H])c([2H])c4oc5c([2H])c([2H])c([2H])c([2H])c5c34)n2)c1[2H] ; c1ccc(-c2nc(-c3ccc(-c4ccc(-c5cccc6ccccc56)cc4)cc3)nc(-c3cccc4oc5ccccc5c34)n2)cc1 ; c1ccc(-c2cccc(-c3nc(-c4ccc(-c5ccc(-c6cccc7ccccc67)cc5)cc4)nc(-c4cccc5oc6ccccc6c45)n3)c2)cc1] 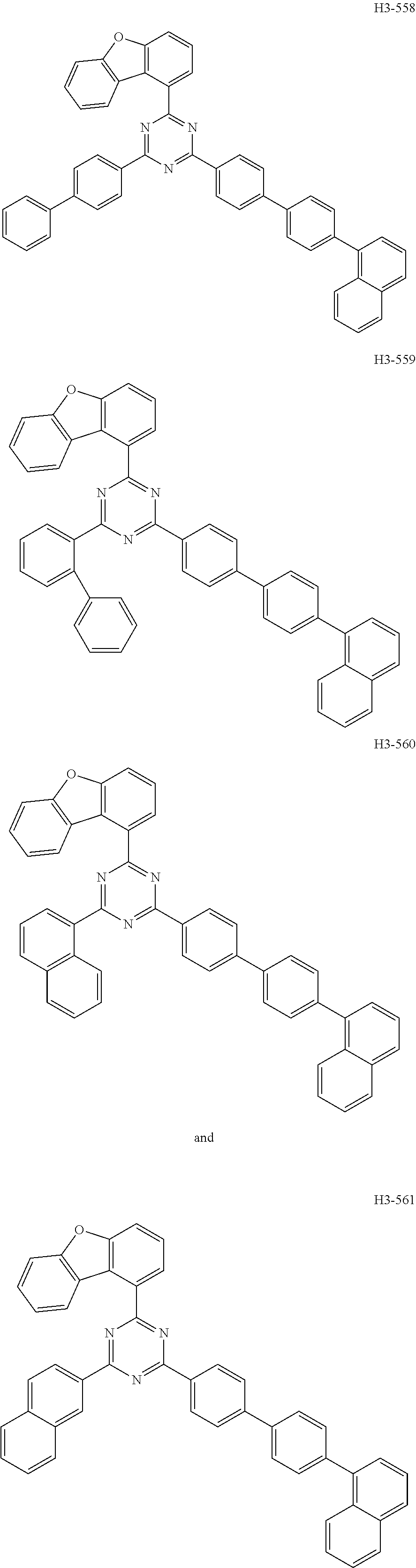 [SMILES: c1ccc(-c2ccc(-c3nc(-c4ccc(-c5ccc(-c6cccc7ccccc67)cc5)cc4)nc(-c4cccc5oc6ccccc6c45)n3)cc2)cc1 ; c1ccc(-c2ccccc2-c2nc(-c3ccc(-c4ccc(-c5cccc6ccccc56)cc4)cc3)nc(-c3cccc4oc5ccccc5c34)n2)cc1 ; c1ccc2c(-c3ccc(-c4ccc(-c5nc(-c6cccc7ccccc67)nc(-c6cccc7oc8ccccc8c67)n5)cc4)cc3)cccc2c1 ; c1ccc2cc(-c3nc(-c4ccc(-c5ccc(-c6cccc7ccccc67)cc5)cc4)nc(-c4cccc5oc6ccccc6c45)n3)ccc2c1]
wherein in the compounds above, Dₙ means that n hydrogen atoms are replaced with deuterium, wherein n is an integer from 1 to the maximum number of hydrogen atoms in the compound.

11. The organic electroluminescent device according to claim 1, wherein the layer comprising the compound represented by Formula 1 in the hole transport band is a hole transport layer, a hole auxiliary layer, an electron-blocking layer, or a light-emitting auxiliary layer.

12. The organic electroluminescent device according to claim 1, further comprising an additional compound in the light-emitting layer, which is different from the compound represented by Formulas 2 and 3.

13. The organic electroluminescent device according to claim 1, wherein the light-emitting layer includes a red light-emitting layer.

14. An organic electroluminescent compound represented by the following compounds.

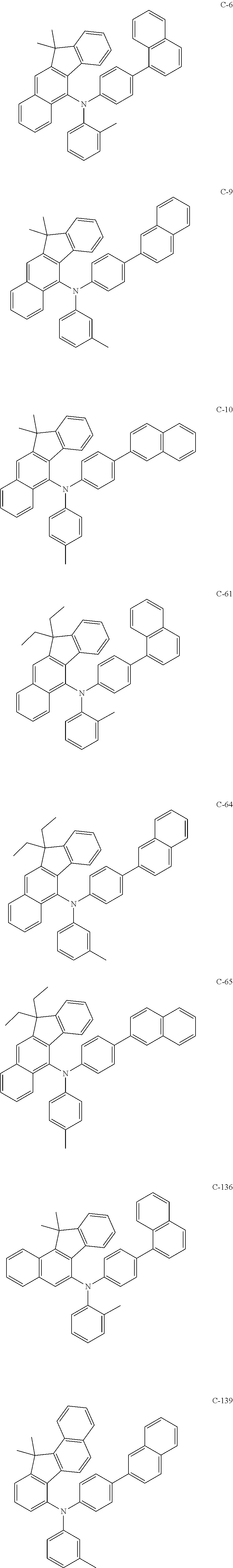

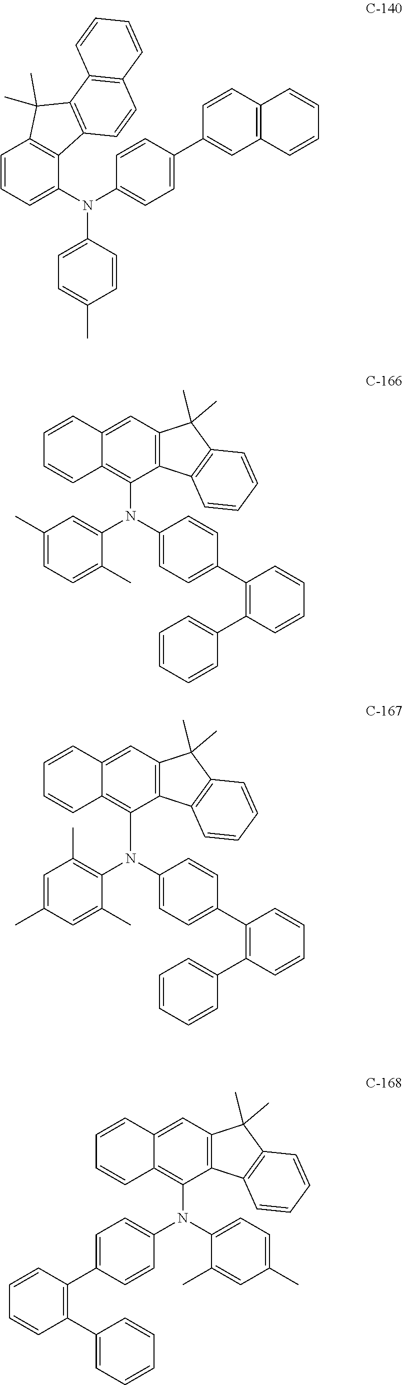

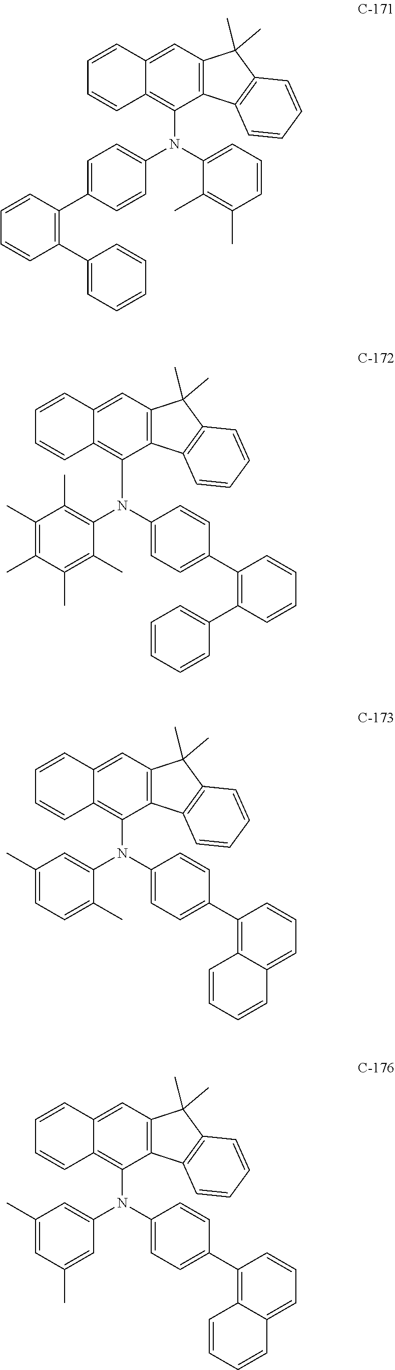 [SMILES: Cc1cccc(N(c2ccc(-c3ccccc3-c3ccccc3)cc2)c2c3c(cc4ccccc24)C(C)(C)c2ccccc2-3)c1C ; Cc1c(C)c(C)c(N(c2ccc(-c3ccccc3-c3ccccc3)cc2)c2c3c(cc4ccccc24)C(C)(C)c2ccccc2-3)c(C)c1C ; Cc1ccc(C)c(N(c2ccc(-c3cccc4ccccc34)cc2)c2c3c(cc4ccccc24)C(C)(C)c2ccccc2-3)c1 ; Cc1cc(C)cc(N(c2ccc(-c3cccc4ccccc34)cc2)c2c3c(cc4ccccc24)C(C)(C)c2ccccc2-3)c1]

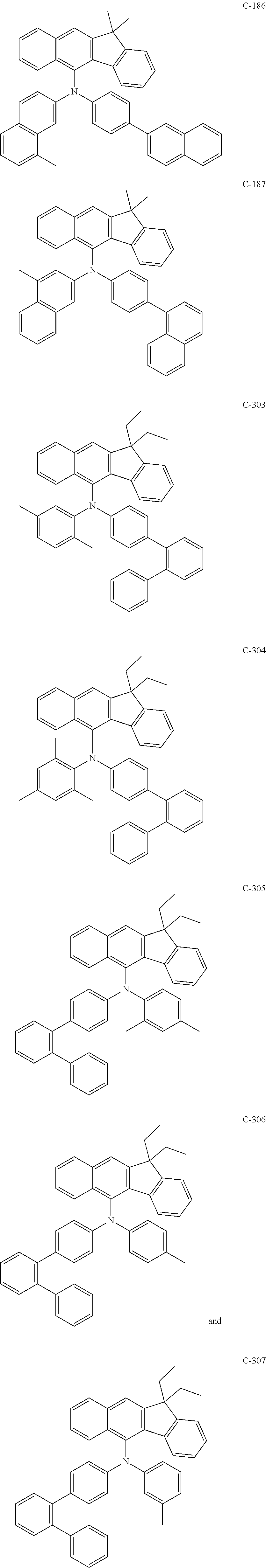

15. An organic electroluminescent material comprising the organic electroluminescent compound according to claim 14.

16. An organic electroluminescent device comprising the organic electroluminescent compound according to claim 14.

17. The organic electroluminescent device according to claim 16, wherein the organic electroluminescent compound is included in at least one layer selected from a light-emitting layer, a first hole transport layer, a second hole transport layer, a hole auxiliary layer, an electron-blocking layer, and a light-emitting auxiliary layer.
